(19) United States
(12) Patent Application Publication
(10) Pub. No.: US 2024/0284795 A1
(43) Pub. Date: Aug. 22, 2024

(54) LIGHT EMITTING ELEMENT AND FUSED POLYCYCLIC COMPOUND FOR THE LIGHT EMITTING ELEMENT

(71) Applicant: Samsung Display Co., Ltd., Yongin-si (KR)

(72) Inventors: Hirokazu KUWABARA, Yokohama (JP); Keigo HOSHI, Yokohama (JP); Ryuhei FURUE, Yokohama (JP)

(73) Assignee: Samsung Display Co., Ltd., Yongin-si (KR)

(21) Appl. No.: 18/483,645

(22) Filed: Oct. 10, 2023

(30) Foreign Application Priority Data
Jan. 18, 2023 (KR) 10-2023-0007361

(51) Int. Cl. H10K 85/60; C09K 11/06

(52) U.S. Cl. CPC H10K 85/658; C09K 11/06; H10K 85/6572; H10K 2101/20

(57) ABSTRACT

Embodiments provide a fused polycyclic compound and a light emitting element that includes the fused polycyclic compound. The light emitting element includes a first electrode, a second electrode disposed on the first electrode, and at least one functional layer disposed between the first electrode and the second electrode, wherein the at least one functional layer includes the fused polycyclic compound. The fused polycyclic compound is represented by Formula 1, which is explained in the specification.

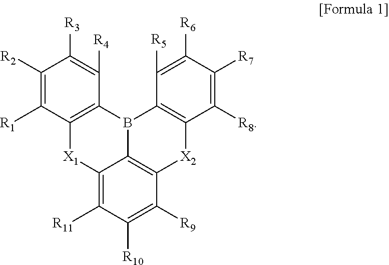

### CROSS-REFERENCE TO RELATED APPLICATION(S)

This application claims priority to and benefits of Korean Patent Application No. 10-2023-0007361 under 35 U.S.C. § 119, filed on Jan. 18, 2023 in the Korean Intellectual Property Office, the entire contents of which are incorporated herein by reference.

### BACKGROUND

### 1. Technical Field

The disclosure relates to a light emitting element and a fused polycyclic compound used in the light emitting element.

### 2. Description of the Related Art

Active development continues for an organic electroluminescence display as an image display. An organic electroluminescence display is different from a liquid crystal display in that it is a so-called self-luminescent display in which holes and electrons respectively injected from a first electrode and a second electrode recombine in an emission layer so that a light emitting material including an organic compound in the emission layer emits light to achieve display.

In the application of an organic electroluminescence device to a display device, there is a demand for an organic electroluminescence device having a low driving voltage, high emission efficiency, and a long lifetime, and continuous development is required on materials for an organic electroluminescence device that is capable of stably achieving such characteristics.

In order to implement an organic electroluminescence device with high efficiency, technologies pertaining to phosphorescence emission, which uses triplet state energy, or to fluorescence emission, which uses triplet-triplet annihilation (TTA) in which singlet excitons are generated by the collision of triplet excitons, are being developed. Development is currently directed to thermally activated delayed fluorescence (TADF) materials which use delayed fluorescence phenomenon.

### SUMMARY

The disclosure provides a light emitting element having improved emission properties and element lifetime.

The disclosure also provides a fused polycyclic compound which is capable of improving emission properties and lifetime of a light emitting element.

An embodiment provides a light emitting element which may include a first electrode, a second electrode disposed on the first electrode, and at least one functional layer disposed between the first electrode and the second electrode, wherein the at least one functional layer may include a fused polycyclic compound represented by Formula 1.

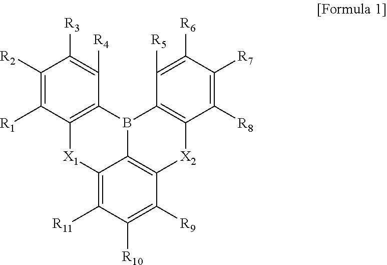

In Formula 1, X₁ and X₂ may each independently be O, S, or N(Rₓ); R₁ to R₁₁ and Rₓ may each independently be a hydrogen atom, a deuterium atom, a halogen atom, a cyano group, a hydroxyl group, a substituted or unsubstituted oxy group, a substituted or unsubstituted thio group, a substituted or unsubstituted boron group, a substituted or unsubstituted silyl group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, a substituted or unsubstituted heteroaryl group of 2 to 30 ring-forming carbon atoms, a group represented by Formula 2, or combined with an adjacent group to form a ring; and at least one of R₉ to R₁₁ may each independently be a group represented by Formula 2.

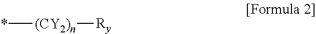

In Formula 2, Y may be a hydrogen atom or a deuterium atom; Ry may be a substituted or unsubstituted alkyl group of 1 to 20 carbon atoms; n may be an integer from 3 to 20; and *- represents a bond to Formula 1.

In an embodiment, the at least one functional layer may include an emission layer, a hole transport region disposed between the first electrode and the emission layer, and an electron transport region disposed between the emission layer and the second electrode; and the emission layer may include the fused polycyclic compound.

In an embodiment, the emission layer may emit delayed fluorescence.

In an embodiment, the emission layer may emit light having a central wavelength in a range of about 430 nm to about 490 nm.

In an embodiment, in Formula 2, Ry may be a linear or branched alkyl group of 1 to 10 carbon atoms, a deuterium-substituted linear alkyl group of 1 to 10 carbon atoms, or a deuterium-substituted branched alkyl group of 1 to 10 carbon atoms.

In an embodiment, in Formula 2, Ry may be a group represented by one of Formula 3-1 to Formula 3-11.

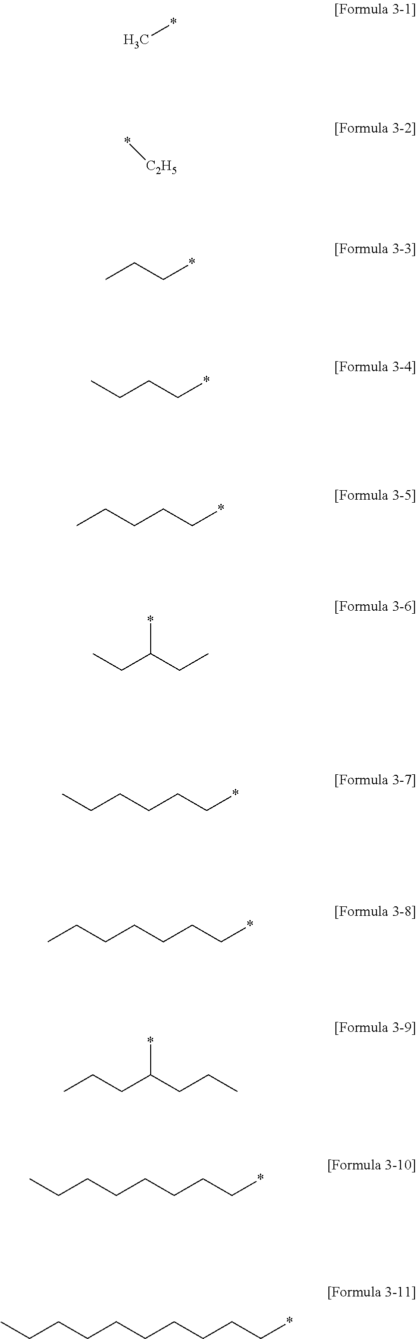

In Formula 3-1 to Formula 3-11, at least one hydrogen atom may be optionally substituted with a deuterium atom.

In an embodiment, the fused polycyclic compound may be represented by Formula 1-1.

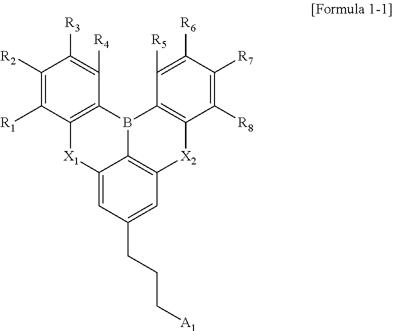

In Formula 1-1, A₁ may be a substituted or unsubstituted linear alkyl group of 1 to 10 carbon atoms or a substituted or unsubstituted branched alkyl group of 1 to 10 carbon atoms; R₁ to R₈, Rₓ, X₁, and X₂ are the same as defined in Formula 1; and at least one hydrogen atom may be optionally substituted with a deuterium atom.

In an embodiment, the fused polycyclic compound may be represented by Formula 1-2 or Formula 1-3.

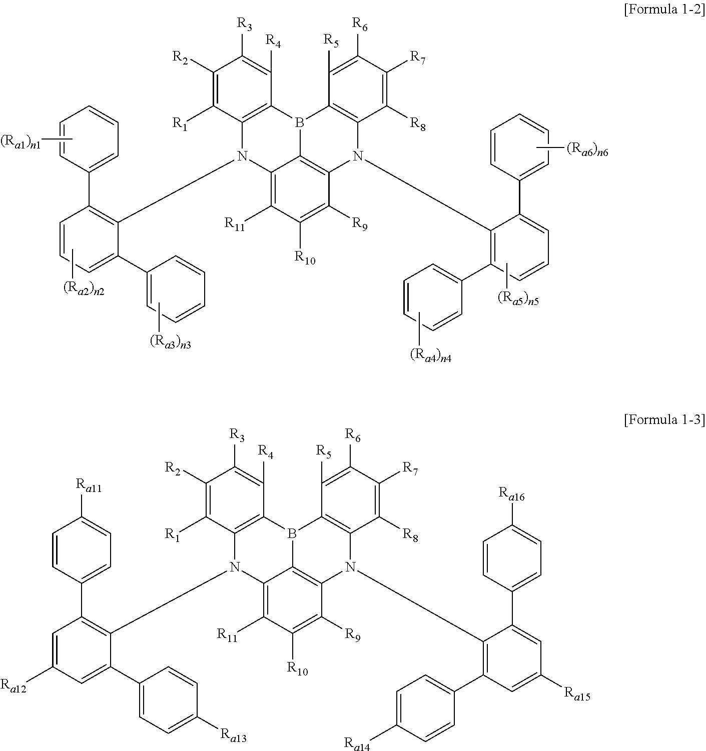

In Formula 1-2 and Formula 1-3, Rₐ₁ to Rₐ₆ and Rₐ₁₁ to Rₐ₁₆ may each independently be a hydrogen atom, a deuterium atom, a halogen atom, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms; n1, n3, n4, and n6 may each independently be an integer from 0 to 5; n2 and n5 may each independently be an integer from 0 to 3; and R₁ to R₁₁ are the same as defined in Formula 1.

In an embodiment, in Formula 1, at least one of R₁ to R₄ may each independently be a group represented by Formula 2, Formula 4-1, or Formula 4-2; and at least one of R₅ to R₈ may each independently be a group represented by Formula 2, Formula 4-1, or Formula 4-2.

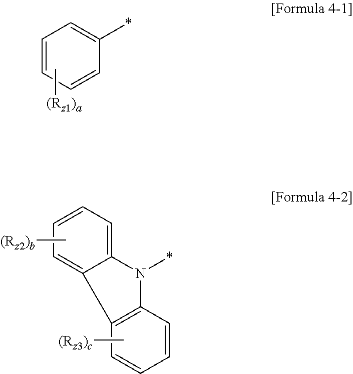

In Formula 4-1 and Formula 4-2, R_{z1} to R_{z3} may each independently be a hydrogen atom, a deuterium atom, a halogen atom, a substituted or unsubstituted linear alkyl group of 1 to 20 carbon atoms, or a substituted or unsubstituted branched alkyl group of 1 to 20 carbon atoms; a may be an integer from 0 to 5; and b and c may each independently be an integer from 0 to 4.

In an embodiment, the fused polycyclic compound may be represented by one of Formula 1-4 to Formula 1-6.

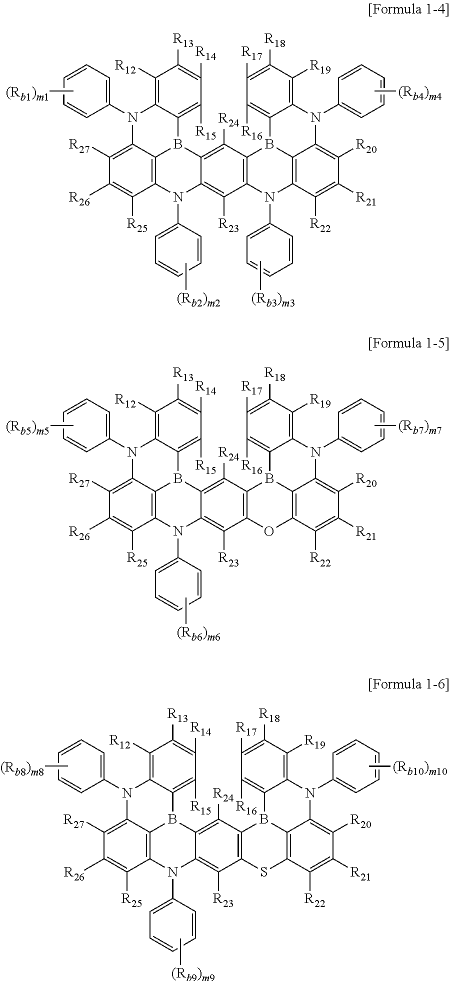

In Formula 1-4 to Formula 1-6, R₁₂ to R₂₇ may each independently be a hydrogen atom, a deuterium atom, a halogen atom, a cyano group, a hydroxyl group, a substituted or unsubstituted oxy group, a substituted or unsubstituted thio group, a substituted or unsubstituted boron group, a substituted or unsubstituted silyl group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, a substituted or unsubstituted heteroaryl group of 2 to 30 ring-forming carbon atoms, or a group represented by Formula 2; R_{b1} to R_{b10} may each independently be a hydrogen atom, a deuterium atom, a halogen atom, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms; m1 to m10 may each independently be an integer from 0 to 5; at least one of R₂₅ to R₂₇ may each independently be a group represented by Formula 2; and at least one hydrogen atom may be optionally substituted with a deuterium atom.

In an embodiment, the fused polycyclic compound may be represented by Formula 1-7 or Formula 1-8.

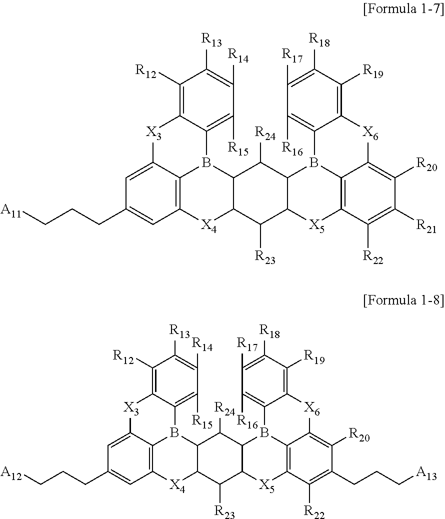

In Formula 1-7 and Formula 1-8, X₃ to X₆ may each independently be O, S, or N(Rₓ); A₁₁ to A₁₃ may each independently be a substituted or unsubstituted linear alkyl group of 1 to 10 carbon atoms or a substituted or unsubstituted branched alkyl group of 1 to 10 carbon atoms; R₁₂ to R₂₄ may each independently be a hydrogen atom, a deuterium atom, a halogen atom, a cyano group, a hydroxyl group, a substituted or unsubstituted oxy group, a substituted or unsubstituted thio group, a substituted or unsubstituted boron group, a substituted or unsubstituted silyl group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, a substituted or unsubstituted heteroaryl group of 2 to 30 ring-forming carbon atoms, or a group represented by Formula 2; Rₓ is the same as defined in Formula 1; and at least one hydrogen atom may be optionally substituted with a deuterium atom.

In an embodiment, the fused polycyclic compound may include at least one compound selected from Compound Group 1, which is explained below.

An embodiment provides a fused polycyclic compound which may be represented by Formula 1, which is explained herein.

In an embodiment, in Formula 2, Ry may be a group represented by one of Formula 3-1 to Formula 3-11, which are explained herein.

In an embodiment, the fused polycyclic compound represented by Formula 1 may be represented by Formula 1-1, which is explained herein.

In an embodiment, the fused polycyclic compound represented by Formula 1 may be represented by Formula 1-2 or Formula 1-3, which are explained herein.

In an embodiment, in Formula 1, at least one of R₁ to R₄ may each independently be a group represented by Formula 2, Formula 4-1, or Formula 4-2; and at least one of R₅ to R₈ may each independently be a group represented by Formula 2, Formula 4-1, or Formula 4-2, which are explained herein.

In an embodiment, the fused polycyclic compound represented by Formula 1 may be represented by one of Formula 1-4 to Formula 1-6, which are explained herein.

In an embodiment, the fused polycyclic compound represented by Formula 1 may be represented by Formula 1-7 or Formula 1-8, which are explained herein.

In an embodiment, the fused polycyclic compound represented by Formula 1 may be selected from Compound Group 1, which is explained below.

It is to be understood that the embodiments above are described in a generic and explanatory sense only and not for the purposes of limitation, and the disclosure is not limited to the embodiments described above.

### BRIEF DESCRIPTION OF THE DRAWINGS

The accompanying drawings are included to provide a further understanding of the embodiments, and are incorporated in and constitute a part of this specification. The drawings illustrate embodiments of the disclosure and principles thereof. The above and other aspects and features of the disclosure will become more apparent by describing in detail embodiments thereof with reference to the accompanying drawings, in which:

FIG. 1 is a schematic plan view of a display apparatus according to an embodiment;

FIG. 2 is a schematic cross-sectional view of a display apparatus according to an embodiment;

FIG. 3 is a schematic cross-sectional view of a light emitting element according to an embodiment;

FIG. 4 is a schematic cross-sectional view of a light emitting element according to an embodiment;

FIG. 5 is a schematic cross-sectional view of a light emitting element according to an embodiment;

FIG. 6 is a schematic cross-sectional view of a light emitting element according to an embodiment;

FIG. 7 is a schematic cross-sectional view of a display apparatus according to an embodiment;

FIG. 8 is a schematic cross-sectional view of a display apparatus according to an embodiment;

FIG. 9 is a schematic cross-sectional view of a display apparatus according to an embodiment;

FIG. 10 is a schematic cross-sectional view of a display apparatus according to an embodiment; and

FIG. 11 is a schematic diagram of an interior of a vehicle including a display apparatus according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like reference numbers and reference characters refer to like elements throughout.

In the specification, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the specification, when an element is “directly on,” “directly connected to,” or “directly coupled to” another element, there are no intervening elements present. For example, “directly on” may mean that two layers or two elements are disposed without an additional element such as an adhesion element therebetween.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group consisting of” for the purpose of its meaning and interpretation. For example, “at least one of A, B, and C” may be understood to mean A only, B only, C only, or any combination of two or more of A, B, and C, such as ABC, ACC, BC, or CC. When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within +20%, +10%, or +5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

In the specification, the term “substituted or unsubstituted” may describe a group that is substituted or unsubstituted with at least one substituent selected from the group consisting of a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. Each of the substituents listed above may itself be substituted or unsubstituted. For example, a biphenyl group may be interpreted as an aryl group, or it may be interpreted as a phenyl group substituted with a phenyl group.

In the specification, the term “combined with an adjacent group to form a ring” may be interpreted as a group that is bonded to an adjacent group to form a substituted or unsubstituted hydrocarbon ring or a substituted or unsubstituted heterocycle. The hydrocarbon ring may be an aliphatic hydrocarbon ring or an aromatic hydrocarbon ring. The heterocycle may be an aliphatic heterocycle or an aromatic heterocycle. The hydrocarbon ring and the heterocycle may each independently be monocyclic or polycyclic. A ring that is formed by adjacent groups being bonded to each other may itself be connected to another ring to form a spiro structure.

In the specification, the term “adjacent group” may be interpreted as a substituent that is substituted for an atom which is directly linked to an atom substituted with a corresponding substituent, as another substituent that is substituted for an atom which is substituted with a corresponding substituent, or as a substituent that is sterically positioned at the nearest position to a corresponding substituent. For example, two methyl groups in 1,2-dimethylbenzene may be interpreted as “adjacent groups” to each other, and two ethyl groups in 1,1-diethylcyclopentane may be interpreted as “adjacent groups” to each other. For example, two methyl groups in 4,5-dimethylphenanthrene may be interpreted as “adjacent groups” to each other.

In the specification, examples of a halogen atom may include a fluorine atom, a chlorine atom, a bromine atom, or an iodine atom.

In the specification, an alkyl group may be linear or branched. The number of carbon atoms in an alkyl group may be 1 to 50, 1 to 30, 1 to 20, 1 to 10, or 1 to 6. Examples of an alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2.2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but embodiments are not limited thereto.

In the specification, a cycloalkyl group may be a cyclic alkyl group. The number of carbon atoms in a cycloalkyl group may be 3 to 50, 3 to 30, 3 to 20, or 3 to 10. Examples of a cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, etc., but embodiments are not limited thereto.

In the specification, an alkenyl group may be a hydrocarbon group including at least one carbon-carbon double bond in the middle or at a terminus of an alkyl group having 2 or more carbon atoms. An alkenyl group may be linear or branched. The number of carbon atoms in an alkenyl group is not particularly limited, but may be 2 to 30, 2 to 20, or 2 to 10. Examples of an alkenyl group may include a vinyl group, a 1-butenyl group, a 1-pentenyl group, a 1,3-butadienyl aryl group, a styrenyl group, a styryl vinyl group, etc., but embodiments are not limited thereto.

In the specification, an alkynyl group may be a hydrocarbon group including at least one carbon-carbon triple bond in the middle or at a terminus of an alkyl group having 2 or more carbon atoms. An alkynyl group may be linear or branched. The number of carbon atoms in an alkynyl group is not particularly limited, but may be 2 to 30, 2 to 20, or 2 to 10. Examples of an alkynyl group may include an ethynyl group, a propynyl group, etc., but embodiments are not limited thereto.

In the specification, the hydrocarbon ring group may be any functional group or substituent derived from an aliphatic hydrocarbon ring. For example, a hydrocarbon ring group may be a saturated hydrocarbon ring group having 5 to 20 ring-forming carbon atoms.

In the specification, an aryl group may be any functional group or substituent derived from an aromatic hydrocarbon ring. An aryl group may be monocyclic or polycyclic. The number of ring-forming carbon atoms in an aryl group may be 6 to 30, 6 to 20, or 6 to 15. Examples of an aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., but embodiments are not limited thereto.

In the specification, a fluorenyl group may be substituted, and two substituents may be bonded to each other to form a spiro structure. Examples of a substituted fluorenyl group may include the groups shown below. However, embodiments are not limited thereto.

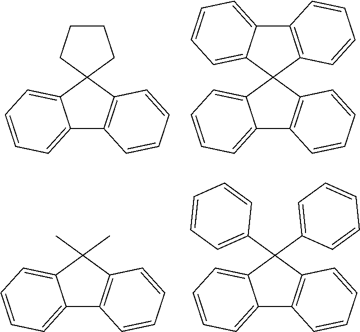

In the specification, a heterocyclic group may be any functional group or substituent derived from a ring including at least one of B. O. N. P. Si. S. and Se as a heteroatom. A heterocyclic group may be an aliphatic heterocyclic group or an aromatic heterocyclic group. An aromatic heterocyclic group may be a heteroaryl group. An aliphatic heterocycle and an aromatic heterocycle may each independently be monocyclic or polycyclic.

In the specification, a heterocyclic group may include at least one of B, O, N, P, Si, S. and Se as a heteroatom. If a heterocyclic group include two or more heteroatoms, the two or more heteroatoms may be the same as or different from each other. A heterocyclic group may be monocyclic or polycyclic. A heterocyclic group may be a heteroaryl group. The number of ring-forming carbon atoms in a heterocyclic group may be 2 to 30, 2 to 20, or 2 to 10.

In the specification, an aliphatic heterocyclic group may include at least one of B, O, N. P. Si, S, and Se as a heteroatom. The number of ring-forming carbon atoms in an aliphatic heterocyclic group may be 2 to 30, 2 to 20, or 2 to 10. Examples of an aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., but embodiments are not limited thereto.

In the specification, a heteroaryl group may include at least one of B. O. N. P. Si, S. and Se as a heteroatom. If a heteroaryl group includes two or more heteroatoms, the two or more heteroatoms may be the same as or different from each other. A heteroaryl group may be monocyclic or polycyclic. The number of ring-forming carbon atoms in a heteroaryl group may be 2 to 30, 2 to 20, or 2 to 10. Examples of a heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzoimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., but embodiments are not limited thereto.

In the specification, the above description of an aryl group may be applied to an arylene group, except that an arylene group is a divalent group. The above description of a heteroaryl group may be applied to a heteroarylene group, except that a heteroarylene group is a divalent group.

In the specification, a silyl group may be an alkylsilyl group or an arylsilyl group. Examples of a silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc., but embodiments are not limited thereto.

In the specification, the number of ring-forming carbon atoms in a carbonyl group is not particularly limited, but may be 1 to 40, 1 to 30, or 1 to 20. For example, a carbonyl group may have one of the following structures, but embodiments are not limited thereto.

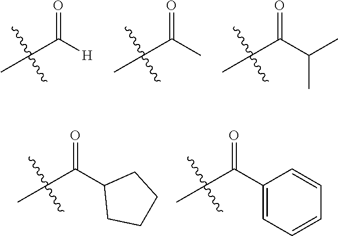

In the specification, the number of carbon atoms in a sulfinyl group or a sulfonyl group is not particularly limited, but may be 1 to 30. A sulfinyl group may be an alkyl sulfinyl group or an aryl sulfinyl group. A sulfonyl group may be an alkyl sulfonyl group or an aryl sulfonyl group.

In the specification, a thio group may be an alkylthio group or an arylthio group. A thio group may be a sulfur atom that is bonded to an alkyl group or an aryl group as defined above. Examples of a thio group may include a methylthio group, an ethylthio group, a propylthio group, a pentylthio group, a hexylthio group, an octylthio group, a dodecylthio group, a cyclopentylthio group, a cyclohexylthio group, a phenylthio group, or a naphthylthio group, but embodiments are not limited thereto.

In the specification, an oxy group may be an oxygen atom that is bonded to an alkyl group or an aryl group as defined above. An oxy group may be an alkoxy group or an aryl oxy group. An alkoxy group may be linear, branched, or cyclic. The number of carbon atoms in an alkoxy group is not particularly limited, but may be, for example, 1 to 20 or 1 to 10. Examples of an oxy group may include a methoxy group, an ethoxy group, an n-propoxy group, an isopropoxy group, a butoxy group, a pentyloxy group, a hexyloxy group, an octyloxy group, a nonyloxy group, a decyloxy group, a benzyloxy group, etc., but embodiments are not limited thereto.

In the specification, a boron group may be a boron atom that is bonded to an alkyl group or an aryl group as defined above. A boron group may be an alkyl boron group or an aryl boron group. Examples of a boron group may include a dimethylboron group, a trimethylboron group, a t-butyldimethylboron group, a diphenylboronic group, a phenylboron group, etc., but embodiments are not limited thereto.

In the specification, the number of carbon atoms in an amine group is not particularly limited, but may be 1 to 30. An amine group may be an alkyl amine group or an aryl amine group. Examples of an amine group may include a methylamine group, a dimethylamine group, a phenylamine group, a diphenylamine group, a naphthylamine group, a 9-methyl-anthracenylamine group, etc., but embodiments are not limited thereto.

In the specification, an alkyl group within an alkylthio group, an alkylsulfoxy group, an alkylaryl group, an alkylamino group, an alkyl boron group, an alkyl silyl group, or an alkyl amine group may be the same as an example of an alkyl group as described above.

In the specification, an aryl group within an aryloxy group, an arylthio group, an arylsulfoxy group, an arylamino group, an arylboron group, an arylsilyl group, or an arylamine group may be the same as an example of an aryl group as described above.

In the specification, a direct linkage may be a single bond.

In the specification, the symbols

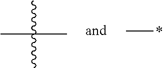

each represent a bond to a neighboring atom in a corresponding formula or moiety.

Hereinafter, embodiments will be described with reference to the accompanying drawings.

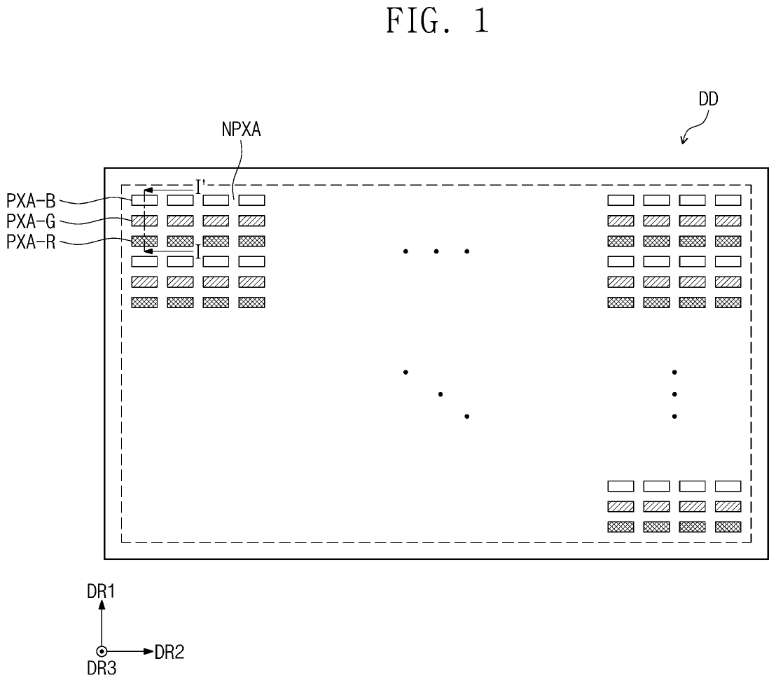

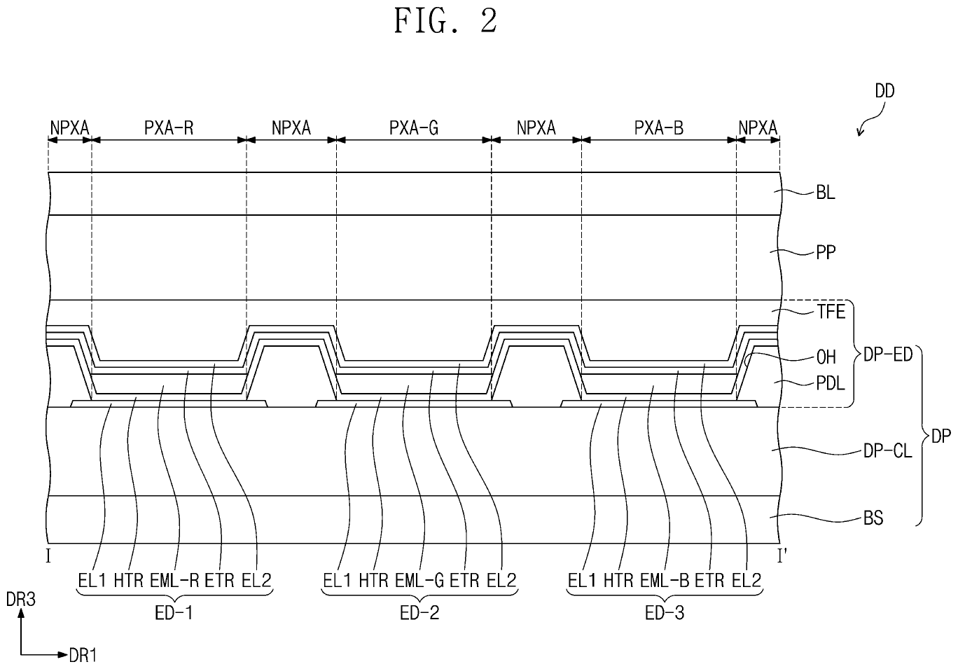

FIG. 1 is a schematic plan view of a display apparatus DD according to an embodiment. FIG. 2 is a schematic cross-sectional view of a display apparatus DD according to an embodiment. FIG. 2 is a schematic cross-sectional view illustrating a part taken along line I-I′ in FIG. 1.

The display apparatus DD may include a display panel DP and an optical layer PP disposed on the display panel DP. The display panel DP includes light emitting elements ED-1, ED-2, and ED-3. The display apparatus DD may include multiples of each of the light emitting elements ED-1, ED-2, and ED-3. The optical layer PP may be disposed on the display panel DP to control light that is reflected at the display panel DP from an external light. The optical layer PP may include, for example, a polarization layer or a color filter layer. Although not shown in the drawings, in an embodiment, the optical layer PP may be omitted from the display apparatus DD.

A base substrate BL may be disposed on the optical layer PP. The base substrate BL may provide a base surface on which the optical layer PP is disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

The display apparatus DD according to an embodiment may further include a filling layer (not shown). The filling layer (not shown) may be disposed between a display device layer DP-ED and the base substrate BL. The filling layer (not shown) may be an organic material layer. The filling layer (not shown) may include at least one of an acrylic-based resin, a silicone-based resin, and an epoxy-based resin.

The display panel DP may include a base layer BS, a circuit layer DP-CL provided on the base layer BS, and the display device layer DP-ED. The display device layer DP-ED may include a pixel defining film PDL, light emitting elements ED-1, ED-2, and ED-3 disposed between portions of the pixel defining film PDL, and an encapsulation layer TFE disposed on the light emitting elements ED-1, ED-2, and ED-3.

The base layer BS may provide a base surface on which the display device layer DP-ED is disposed. The base layer BS may be a glass substrate, a metal substrate, a plastic substrate, etc. However, embodiments are not limited thereto, and the base layer BS may include an inorganic layer, an organic layer, or a composite material layer.

In an embodiment, the circuit layer DP-CL is disposed on the base layer BS, and the circuit layer DP-CL may include transistors (not shown). The transistors (not shown) may each include a control electrode, an input electrode, and an output electrode. For example, the circuit layer DP-CL may include a switching transistor and a driving transistor for driving the light emitting elements ED-1, ED-2, and ED-3 of the display device layer DP-ED.

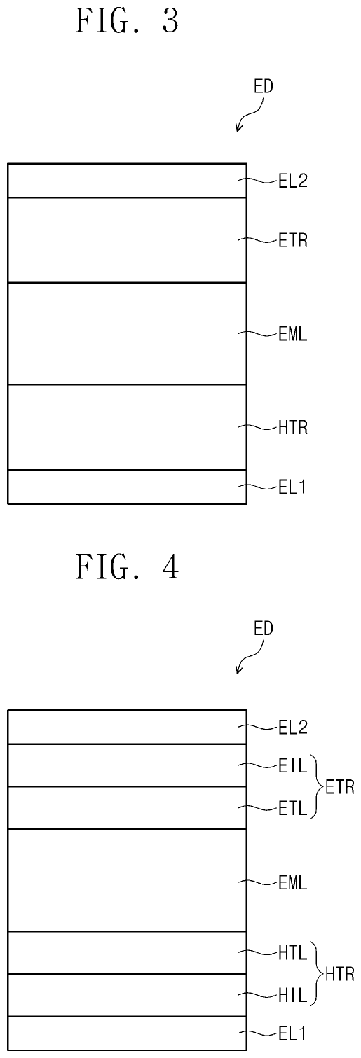

The light emitting elements ED-1, ED-2, and ED-3 may each have a structure of a light emitting element ED of an embodiment according to any of FIGS. 3 to 6, which will be described later. The light emitting elements ED-1, ED-2, and ED-3 may each include a first electrode EL1, a hole transport region HTR, emission layers EML-R, EML-G, and EML-B, an electron transport region ETR, and a second electrode EL2.

FIG. 2 illustrates an embodiment in which the emission layers EML-R, EML-G, and EML-B of the light emitting elements ED-1, ED-2, and ED-3 are disposed in openings OH defined in the pixel defining film PDL, and the hole transport region HTR, the electron transport region ETR, and the second electrode EL2 are each provided as a common layer for all of the light emitting elements ED-1, ED-2, and ED-3. However, embodiments are not limited thereto. Although not illustrated in FIG. 2, in an embodiment, the hole transport region HTR and the electron transport region ETR may each be provided by being patterned in the openings OH defined in the pixel defining film PDL. For example, in an embodiment, the hole transport region HTR, the emission layers EML-R, EML-G, and EML-B, and the electron transport region ETR of the light emitting elements ED-1, ED-2, and ED-3 may each be provided by being patterned through an inkjet printing method.

The encapsulation layer TFE may cover the light emitting elements ED-1, ED-2, and ED-3. The encapsulation layer TFE may seal the display device layer DP-ED. The encapsulation layer TFE may be a thin film encapsulation layer. The encapsulation layer TFE may be formed of a single layer or of multiple layers. The encapsulation layer TFE may include at least one insulation layer. The encapsulation layer TFE according to an embodiment may include at least one inorganic film (hereinafter, an encapsulation-inorganic film). In an embodiment, the encapsulation layer TFE may include at least one organic film (hereinafter, an encapsulation-organic film) and at least one encapsulation-inorganic film.

The encapsulation-inorganic film protects the display device layer DP-ED from moisture and/or oxygen, and the encapsulation-organic film protects the display device layer DP-ED from foreign substances such as dust particles. The encapsulation-inorganic film may include silicon nitride, silicon oxynitride, silicon oxide, titanium oxide, aluminum oxide, or the like, but embodiments are not limited thereto. The encapsulation-organic film may include an acrylic-based compound, an epoxy-based compound, or the like. The encapsulation-organic film may include a photopolymerizable organic material, but embodiments are not limited thereto.

The encapsulation layer TFE may be disposed on the second electrode EL2 and may be disposed to fill the openings OH.

Referring to FIGS. 1 and 2, the display apparatus DD may include non-light emitting regions NPXA and light emitting regions PXA-R, PXA-G, and PXA-B. The light emitting regions PXA-R. PXA-G, and PXA-B may each be a region that emits light generated from each of the light emitting elements ED-1, ED-2, and ED-3. The light emitting regions PXA-R, PXA-G, and PXA-B may be spaced apart from each other in a plan view.

The light emitting regions PXA-R. PXA-G, and PXA-B may each be a region separated by the pixel defining film PDL. The non-light emitting regions NPXA may be areas between the adjacent light emitting areas PXA-R, PXA-G, and PXA-B, and which correspond to the pixel defining film PDL. In an embodiment, the light emitting regions PXA-R, PXA-G, and PXA-B may each correspond to a pixel. The pixel defining film PDL may separate the light emitting elements ED-1. ED-2, and ED-3. The emission layers EML-R, EML-G, and EML-B of the light emitting elements ED-1, ED-2, and ED-3 may be disposed in openings OH defined by the pixel defining film PDL and separated from each other.

The light emitting regions PXA-R. PXA-G, and PXA-B may be arranged into groups according to the color of light generated from the light emitting elements ED-1, ED-2, and ED-3. In the display apparatus DD according to an embodiment illustrated in FIGS. 1 and 2, three light emitting regions PXA-R. PXA-G, and PXA-B, which respectively emit red light, green light, and blue light, are illustrated as an example. For example, the display apparatus DD may include a red light emitting region PXA-R, a green light emitting region PXA-G, and a blue light emitting region PXA-B, which are distinct from one another.

In the display apparatus DD according to an embodiment, the light emitting elements ED-1, ED-2, and ED-3 may emit light having wavelengths that are different from each other. For example, in an embodiment, the display apparatus DD may include a first light emitting element ED-1 that emits red light, a second light emitting element ED-2 that emits green light, and a third light emitting element ED-3 that emits blue light. For example, the red light emitting region PXA-R, the green light emitting region PXA-G, and the blue light emitting region PXA-B of the display apparatus DD may respectively correspond to the first light emitting element ED-1, the second light emitting element ED-2, and the third light emitting element ED-3.

However, embodiments are not limited thereto, and the first to third light emitting elements ED-1, ED-2, and ED-3 may emit light in a same wavelength range or at least one light emitting element may emit light in a wavelength range that is different from the remainder. For example, the first to third light emitting elements ED-1, ED-2, and ED-3 may each emit blue light.

The light emitting regions PXA-R. PXA-G, and PXA-B in the display apparatus DD according to an embodiment may be arranged in a stripe configuration. Referring to FIG. 1, the red light emitting regions PXA-R, the green light emitting regions PXA-G, and the blue light emitting regions PXA-B may be respectively arranged along a second directional axis DR2. In another embodiment, the red light emitting region PXA-R, the green light emitting region PXA-G, and the blue light emitting region PXA-B may be alternately arranged in this repeating order along a first directional axis DR1.

FIGS. 1 and 2 illustrate that the light emitting regions PXA-R, PXA-G, and PXA-B all have a similar area, but embodiments are not limited thereto. In an embodiment, the light emitting regions PXA-R. PXA-G, and PXA-B may be different in size or shape from each other, according to a wavelength range of emitted light. The areas of the light emitting regions PXA-R. PXA-G, and PXA-B may be areas in a plan view that are defined by the first directional axis DR1 and the second directional axis DR2.

An arrangement of the light emitting regions PXA-R, PXA-G, and PXA-B is not limited to the configuration illustrated in FIG. 1, and the order in which the red light emitting region PXA-R, the green light emitting region PXA-G, and the blue light emitting region PXA-B are arranged may be provided in various combinations according to the display quality characteristics that are required for the display apparatus DD. For example, the light emitting regions PXA-R. PXA-G, and PXA-B may be arranged in a pentile configuration (such as PENTILE™) or in a diamond configuration (such as Diamond Pixel™).

The areas of the light emitting regions PXA-R. PXA-G, and PXA-B may be different in size from each other. For example, in an embodiment, an area of a green light emitting region PXA-G may be smaller than an area of a blue light emitting region PXA-B, but embodiments are not limited thereto.

Hereinafter, FIG. 3 to FIG. 6 are each a schematic cross-sectional view of a light emitting element according to an embodiment. The light emitting element ED according to an embodiment may include a first electrode EL1, a hole transport region HTR, an emission layer EML, an electron transport region ETR, and a second electrode EL2.

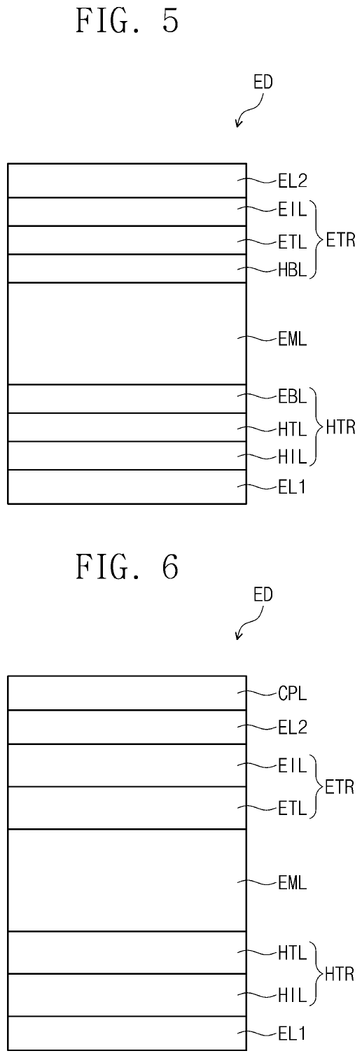

In comparison to FIG. 3, FIG. 4 a schematic cross-sectional view of a light emitting element ED according to an embodiment, in which a hole transport region HTR includes a hole injection layer HIL and a hole transport layer HTL, and an electron transport region ETR includes an electron injection layer EIL and an electron transport layer ETL. In comparison to FIG. 3, FIG. 5 is a schematic cross-sectional view of a light emitting element ED according to an embodiment, in which a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. In comparison to FIG. 4, FIG. 6 is a schematic cross-sectional view of a light emitting element ED according to an embodiment that includes a capping layer CPL disposed on a second electrode EL2.

The first electrode EL1 has conductivity. The first electrode EL1 may be formed of a metal material, a metal alloy, or a conductive compound. The first electrode EL1 may be an anode or a cathode. However, embodiments are not limited thereto. In an embodiment, the first electrode EL1 may be a pixel electrode. The first electrode EL1 may be a transmissive electrode, a transflective electrode, or a reflective electrode. The first electrode EL1 may include Ag, Mg, Cu, Al, Pt, Pd, Au, Ni, Nd, Ir, Cr, Li, Ca, LiF, Mo, Ti, W. In, Sn, Zn, an oxide thereof, a compound thereof, or a mixture thereof.

If the first electrode EL1 is a transmissive electrode, the first electrode EL1 may include a transparent metal oxide such as indium tin oxide (ITO), indium zinc oxide (IZO), zinc oxide (ZnO), or indium tin zinc oxide (ITZO). If the first electrode EL1 is a transflective electrode or a reflective electrode, the first electrode EL1 may include Ag. Mg. Cu, Al, Pt, Pd, Au, Ni, Nd, Ir, Cr, Li, Ca, LiF/Ca (a stacked structure of LiF and Ca), LiF/Al (a stacked structure of LiF and Al), Mo. Ti, W, a compound thereof, or a mixture thereof (e.g., a mixture of Ag and Mg). In another embodiment, the first electrode EL1 may have a multilayer structure including a reflective film or a transflective film formed of the above-described materials, and a transparent conductive film formed of ITO, IZO, ZnO, ITZO, etc. For example, the first electrode EL1 may have a three-layer structure of ITO/Ag/ITO, but embodiments are not limited thereto. In an embodiment, the first electrode EL1 may include the above-described metal materials, combinations of at least two metal materials of the above-described metal materials, oxides of the above-described metal materials, or the like. A thickness of the first electrode EL1 may be in a range of about 700 Å to about 10,000 Å. For example, the thickness of the first electrode EL1 may be in a range of about 1,000 Å to about 3,000 Å.

The hole transport region HTR may be provided on the first electrode EL1. The hole transport region HTR may include at least one of a hole injection layer HIL, a hole transport layer HTL, a buffer layer (not shown), an emission-auxiliary layer (not shown), or an electron blocking layer EBL. A thickness of the hole transport region HTR may be in a range of about 50 Å to about 15,000 Å.

The hole transport region HTR may be a layer consisting of a single material, a layer including different materials, or a structure including multiple layers including different materials.

In embodiments, the hole transport region HTR may have a single layer structure of a hole injection layer HIL or a hole transport layer HTL, or may have a single layer structure formed of a hole injection material and a hole transport material. In embodiments, the hole transport region HTR may have a single layer structure formed of different materials, or a may have structure in which a hole injection layer HIL/hole transport layer HTL, a hole injection layer HIL/hole transport layer HTL/buffer layer (not shown), a hole injection layer HIL/buffer layer (not shown), a hole transport layer HTL/buffer layer (not shown), or a hole injection layer HIL/hole transport layer HTL/electron blocking layer EBL are stacked in its respective stated order from the first electrode EL1, but embodiments are not limited thereto.

The hole transport region HTR may be formed using various methods such as a vacuum deposition method, a spin coating method, a cast method, a Langmuir-Blodgett (LB) method, an inkjet printing method, a laser printing method, and a laser induced thermal imaging (LITI) method.

In the light emitting element ED according to an embodiment, the hole transport region HTR may include a compound represented by Formula H-1:

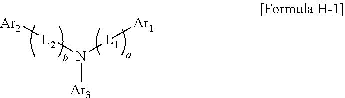

In Formula H-1, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. In Formula H-1, a and b may each independently be an integer from 0 to 10. When a or b is 2 or greater, multiple Li groups or multiple L₂ groups may each independently be a substituted or unsubstituted arylene group having 6 to 30 ring-forming carbon atoms or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms or a substituted or unsubstituted heteroaryl group having 2 to 30 ring-forming carbon atoms. In Formula H-1, Ar₃ may be a substituted or unsubstituted aryl group having 6 to 30 ring-forming carbon atoms or a substituted or unsubstituted heteroaryl group having 2 to 30 ring-forming carbon atoms.

In an embodiment, a compound represented by Formula H-1 may be a monoamine compound. In an embodiment, a compound represented by Formula H-1 may be a diamine compound in which at least one of Ar₁ to Ar₃ includes an amine group as a substituent. In another embodiment, a compound represented by Formula H-1 may be a carbazole-based compound in which at least one of Ar₁ and Ar₂ includes a substituted or unsubstituted carbazole group, or may be a fluorene-based compound in which at least one of Ar₁ and Ar₂ includes a substituted or unsubstituted fluorene group.

The compound represented by Formula H-1 may be any compound selected from Compound Group H. However, the compounds listed in Compound Group H are only examples, and the compound represented by Formula H-1 is not limited to Compound Group H:

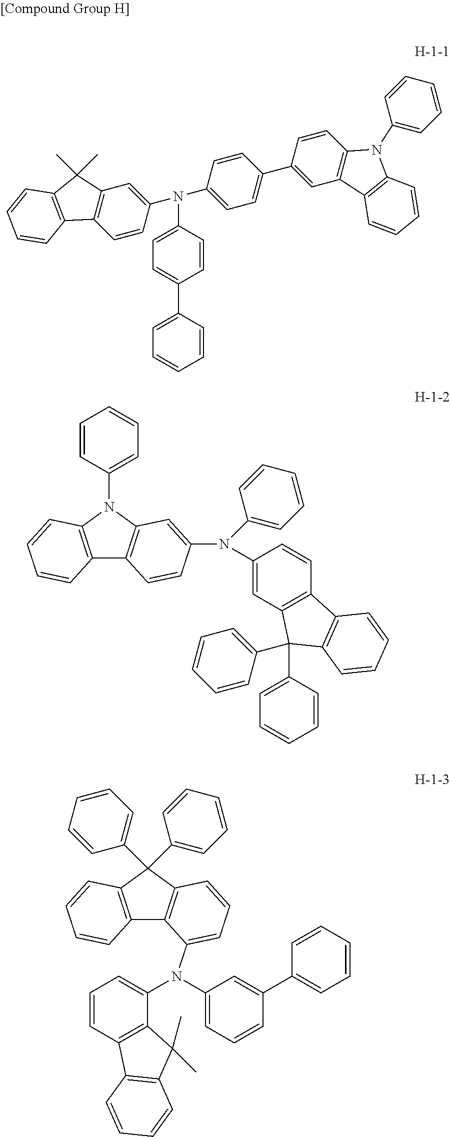 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21]

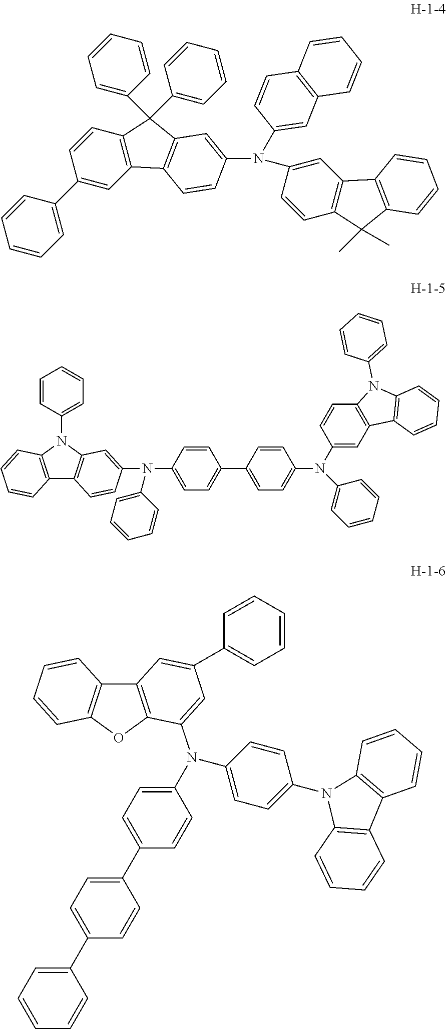 [SMILES: CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21 ; c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1]

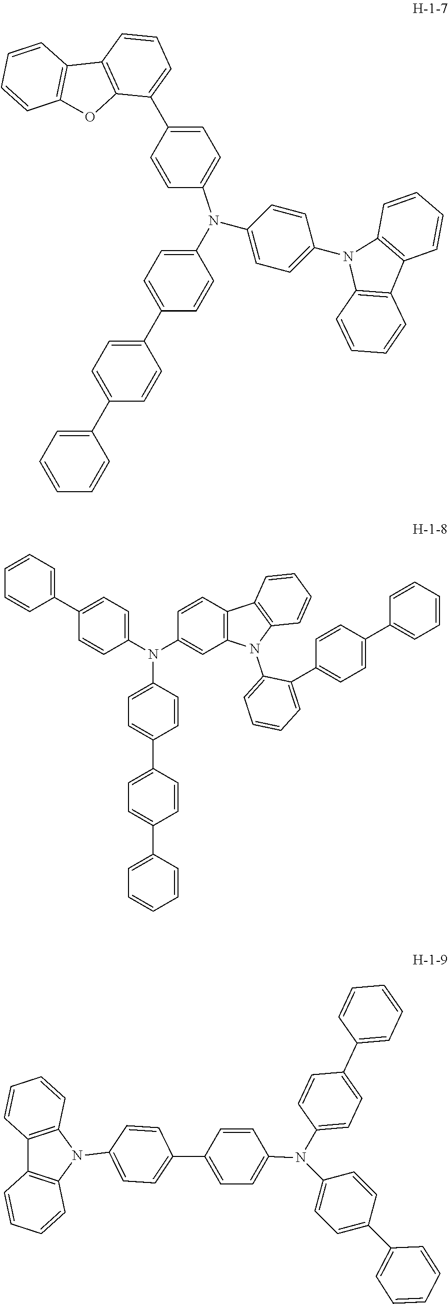 [SMILES: c1ccc(-c2ccc(-c3ccc(N(c4ccc(-c5cccc6c5oc5ccccc56)cc4)c4ccc(-n5c6ccccc6c6ccccc65)cc4)cc3)cc2)cc1 ; c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

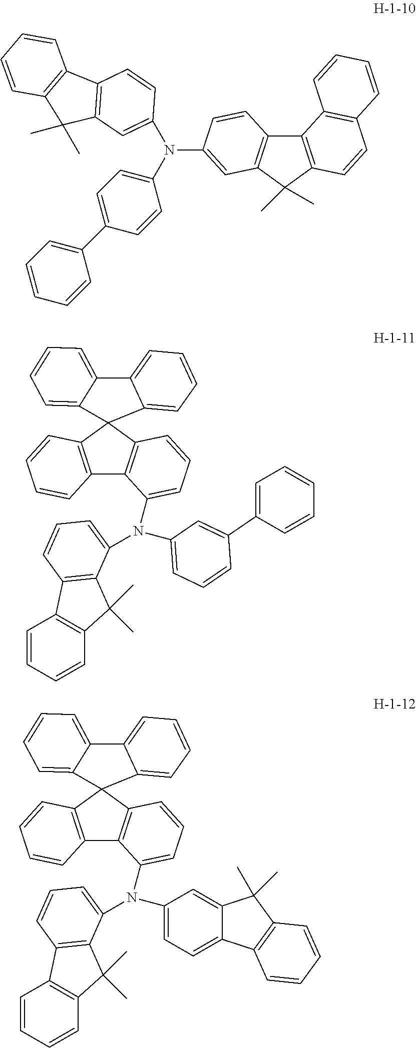

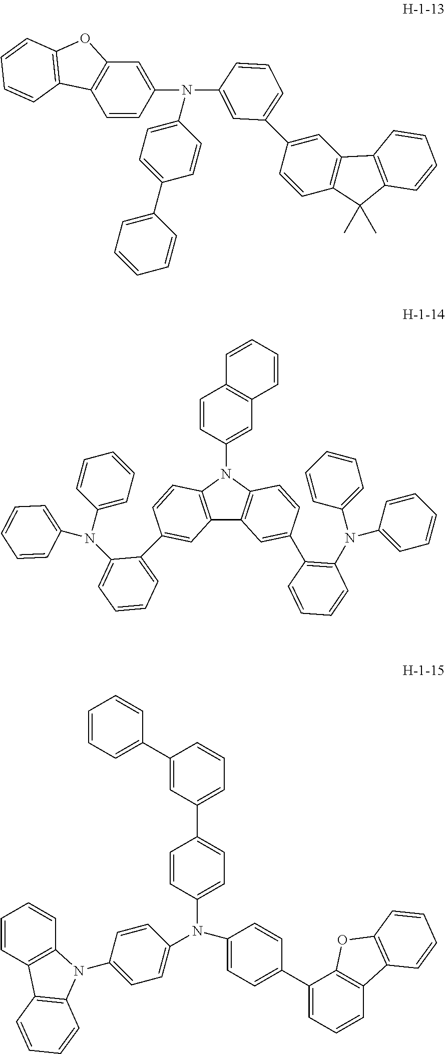 [SMILES: CC1(C)c2ccccc2-c2cc(-c3cccc(N(c4ccc(-c5ccccc5)cc4)c4ccc5c(c4)oc4ccccc45)c3)ccc21 ; c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1]

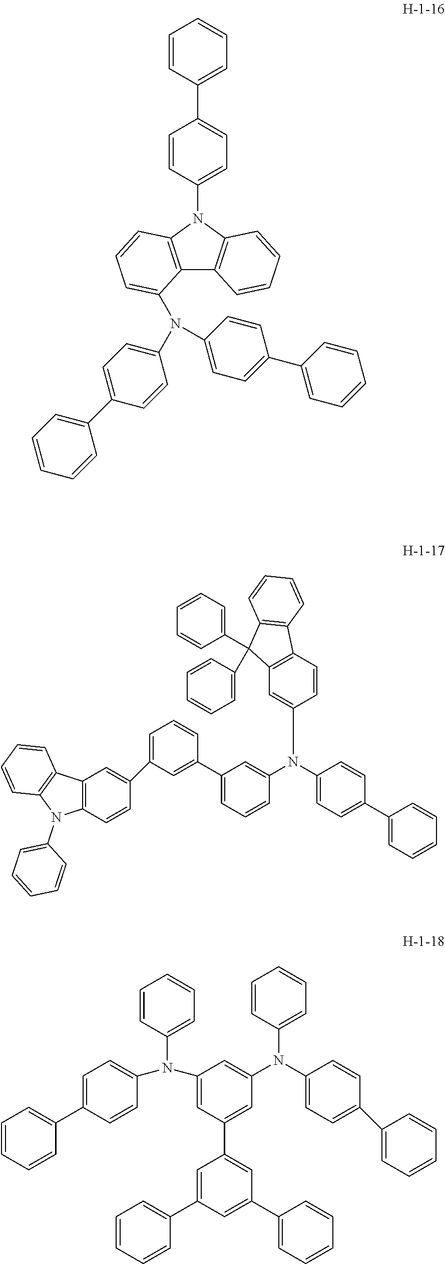 [SMILES: c1ccc(-c2ccc(N(c3ccc(-c4ccccc4)cc3)c3cccc4c3c3ccccc3n4-c3ccc(-c4ccccc4)cc3)cc2)cc1 ; c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1]

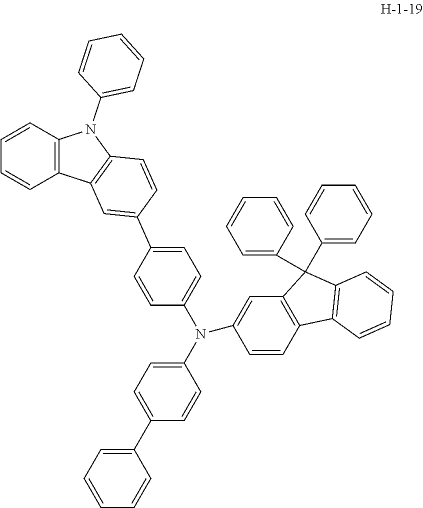 [SMILES: c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may include a phthalocyanine compound such as copper phthalocyanine; N1,N1′-([1,l′-biphenyl]-4,4′-diyl)bis(N1-phenyl-N⁴,N⁴-di-m-tolylbenzene-1,4-diamine) (DNTPD), 4,4′,4″-[tris(3-methylphenyl)phenylamino]triphenylamine (m-MTDATA), 4,4′,4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N.N′-di(naphthalene-1-yl)-N.N′-diphenyl-benzidine (NPB), triphenylamine-containing polyetherketone (TPAPEK), 4-isopropyl-4′-methyldiphenyliodonium[tetrakis(pentafluorophenyl)borate], dipyrazino[2,3-f: 2′,3′-h]quinoxaline-2,3,6,7,10,11-hexacarbonitrile (HATCN), etc.

The hole transport region HTR may include a carbazole-based derivative such as N-phenyl carbazole or polyvinyl carbazole, a fluorene-based derivative, a triphenylamine-based derivative such as N,N′-bis(3-methylphenyl)-N,N′-diphenyl-[1,1-biphenyl]-4,4′-diamine (TPD) or 4,4′,4″-tris(N-carbazolyl)triphenylamine (TCTA), N,N′-di(naphthalene-1-yl)-N,N′-diphenyl-benzidine (NPB), 4,4′-cyclohexylidene bis[N,N-bis(4-methylphenyl]benzenamine](TAPC), 4,4′-bis[N,N′-(3-tolyl)amino]-3,3′-dimethylbiphenyl (HMTPD), 1,3-bis(N-carbazolyl)benzene (mCP), etc.

The hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport region HTR may include the above-described compounds of the hole transport region in at least one of a hole injection layer HIL, a hole transport layer HTL, and an electron blocking layer EBL.

A thickness of the hole transport region HTR may be in a range of about 100 Å to about 10,000 Å. For example, the thickness of the hole transport region HTR may be in a range of about 100 Å to about 5,000 Å. When the hole transport region HTR includes a hole injection layer HIL, the hole injection layer HIL may have a thickness in a range of about 30 Å to about 1,000 Å. When the hole transport region HTR includes a hole transport layer HTL, the hole transport layer HTL may have a thickness in a range of about 250 Å to about 1,000 Å. When the hole transport region HTR includes an electron blocking layer EBL, the electron blocking layer EBL may have a thickness in a range of about 10 Å to about 1,000 Å. If the thicknesses of the hole transport region HTR, the hole injection layer HIL, the hole transport layer HTL, and the electron blocking layer EBL satisfy the above-described ranges, satisfactory hole transport properties may be achieved without a substantial increase in driving voltage.

The hole transport region HTR may further include a charge generating material to increase conductivity, in addition to the above-described materials. The charge generating material may be dispersed uniformly or non-uniformly in the hole transport region HTR. The charge generating material may be, for example, a p-dopant. The p-dopant may include at least one of a halogenated metal compound, a quinone derivative, a metal oxide, or a cyano group-containing compound, but embodiments are not limited thereto.

For example, the p-dopant may include a metal halide compound such as CuI or RbI, a quinone derivative such as tetracyanoquinodimethane (TCNQ) or 2,3,5,6-tetrafluoro-7,7′8,8-tetracyanoquinodimethane (F4-TCNQ), a metal oxide such as tungsten oxide or molybdenum oxide, a cyano group-containing compound such as dipyrazino[2,3-f: 2′,3′-h]quinoxaline-2,3,6,7,10,11-hexacarbonitrile (HATCN) or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., but embodiments are not limited thereto.

As described above, the hole transport region HTR may further include at least one of a buffer layer (not shown) or an electron blocking layer EBL, in addition to a hole injection layer HIL and a hole transport layer HTL. The buffer layer (not shown) may compensate for a resonance distance according to a wavelength of light emitted from the emission layer EML and may thus increase light emission efficiency. A material that may be included in the hole transport region HTR may be used as a material in the buffer layer (not shown). The electron blocking layer EBL may prevent the injection of electrons from an electron transport region ETR to the hole transport region HTR.

The emission layer EML may be provided on the hole transport region HTR. The emission layer EML may have a thickness in a range of about 100 Å to about 1,000 Å. For example, the emission layer EML may have a thickness in a range of about 100 Å to about 300 Å. The emission layer EML may be a layer consisting of a single material, a layer including different materials, or a structure including multiple layers including different materials.

The light emitting element ED may include a fused polycyclic compound represented by Formula 1 in at least one functional layer disposed between the first electrode EL1 and the second electrode EL2. In the light emitting element ED, the emission layer EML may include the fused polycyclic compound according to an embodiment. In an embodiment, the emission layer EML may include the fused polycyclic compound as a dopant. The fused polycyclic compound may be a dopant material in the emission layer EML. In the description, the fused polycyclic compound according to an embodiment, which will be explained later, may be referred to as a first compound.

The fused polycyclic compound may include a structure of multiple aromatic rings that are fused via a boron atom and two heteroatoms. The fused polycyclic compound may include a structure of first to third aromatic rings that are fused via a boron atom, a first heteroatom, and a second heteroatom. The first to third aromatic rings may each be connected to the boron atom, the first aromatic ring and the third aromatic ring may be connected via the first heteroatom, and the second aromatic ring and the third aromatic ring may be connected via the second heteroatom. In an embodiment, the first to third aromatic rings may each be a six-membered aromatic hydrocarbon ring. For example, the first to third aromatic rings may each be a benzene ring. In an embodiment, the first heteroatom and the second heteroatom may be each independently an oxygen atom (O), a sulfur atom (S), or a nitrogen atom (N). In the specification, the fused structure of the first to third aromatic rings that are fused via the boron atom, the first heteroatom, and the second heteroatom may be referred to as a “fused ring core”.

The fused polycyclic compound includes a first substituent connected to the fused ring core. The first substituent is connected to the third aromatic ring. The first substituent may be directly connected to the third aromatic ring without a linking moiety. The first substituent includes a saturated linear hydrocarbon moiety having 4 or more carbon atoms. The first substituent includes a first moiety of a linear alkyl group having 3 or more carbon atoms, and a second moiety of a linear or branched alkyl group having 1 or more carbon atoms. The first moiety may be directly connected to the third aromatic ring, and the second moiety may be directly connected to the first moiety.

The fused polycyclic compound according to an embodiment may be represented by Formula 1.

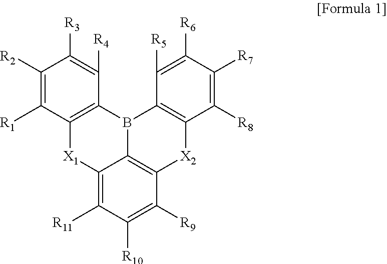

The fused polycyclic compound according to an embodiment, represented by Formula 1, may have a structure of three aromatic rings that are fused via a boron atom, a first heteroatom, and a second heteroatom.

In Formula 1, X₁ and X₂ may each independently be O, S, or N(Rₓ). For example, X₁ and X₂ may each independently be N(Rₓ).

In Formula 1, R₁ to Run and Rₓ may each independently be a hydrogen atom, a deuterium atom, a halogen atom, a cyano group, a hydroxyl group, a substituted or unsubstituted oxy group, a substituted or unsubstituted thio group, a substituted or unsubstituted boron group, a substituted or unsubstituted silyl group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, a substituted or unsubstituted heteroaryl group of 2 to 30 ring-forming carbon atoms, a group represented by Formula 2, or combined with an adjacent group to form a ring.

For example, R₁, R₃, R₄, R₅, R₆, R₈, R₉, and R₁₁ may each independently be a hydrogen atom or a deuterium atom; R₂ and R₇ may each independently be a substituted or unsubstituted phenyl group or a substituted or unsubstituted carbazole group; R₁₀ may be a group represented by Formula 2; and Rₓ may be a substituted or unsubstituted aryl group of 6 to 30 ring-forming carbon atoms. For example, in Formula 1, adjacent groups R₆ and R₇ may be combined with each other to form a heterocycle including a boron atom or the like as a ring-forming atom. For example, R₆ may correspond to a boron group substituted with a phenyl group or the like; R₇ may correspond to an amine group, an oxy group, or a thio group; and R₆ and R₇ may be combined with each other to additionally provide a heterocycle including a boron atom.

In the specification, in Formula 1, a benzene ring that includes R₁ to R₄ may correspond to the above-described first aromatic ring, a benzene ring that includes R₅ to R₈ may correspond to the above-described second aromatic ring, and a benzene ring that includes R₉ to R₁₁ may correspond to the above-described third aromatic ring. In the specification, in Formula 1. X₁ and X₂ may respectively correspond to the above-described first heteroatom and second heteroatom.

In Formula 1, at least one of R₉ to R₁₁ may each independently be a group represented by Formula 2.

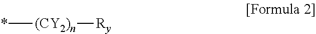

In Formula 2, Y is a hydrogen atom or a deuterium atom.

In Formula 2, Ry may be a substituted or unsubstituted alkyl group of 1 to 20 carbon atoms. In an embodiment, in Formula 2, Ry may be an unsubstituted linear alkyl group of 1 to 10 carbon atoms, an unsubstituted branched alkyl group of 1 to 10 carbon atoms, a deuterium-substituted linear alkyl group of 1 to 10 carbon atoms, or a deuterium-substituted branched alkyl group of 1 to 10 carbon atoms. For example, Ry may be a substituted or unsubstituted methyl group, a substituted or unsubstituted ethyl group, a substituted or unsubstituted n-propyl group, a substituted or unsubstituted n-butyl group, a substituted or unsubstituted n-pentyl group, a substituted or unsubstituted 3-methylpentyl group, a substituted or unsubstituted n-hexyl group, a substituted or unsubstituted n-heptyl group, a substituted or unsubstituted 4-methylheptyl group, a substituted or unsubstituted n-octyl group, a substituted or unsubstituted n-nonyl group, or a substituted or unsubstituted n-decyl group, and if Ry is substituted, a substituent may be a hydrogen atom, a deuterium atom, or an unsubstituted methyl group.

In Formula 2, n may be an integer from 3 to 20. For example, n may be an integer from 3 to 10.

In Formula 2,

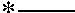 [SMILES: *C]

represents a bond to Formula 1.

In the specification, Formula 2 may correspond to the first substituent. In the specification, in Formula 2, (CY₂)ₙ may correspond to the above-described first moiety, and R_{y} may correspond to the above-described second moiety.

In an embodiment, in Formula 2, R_{y} may be a group represented by one of Formula 3-1 to Formula 3-11.

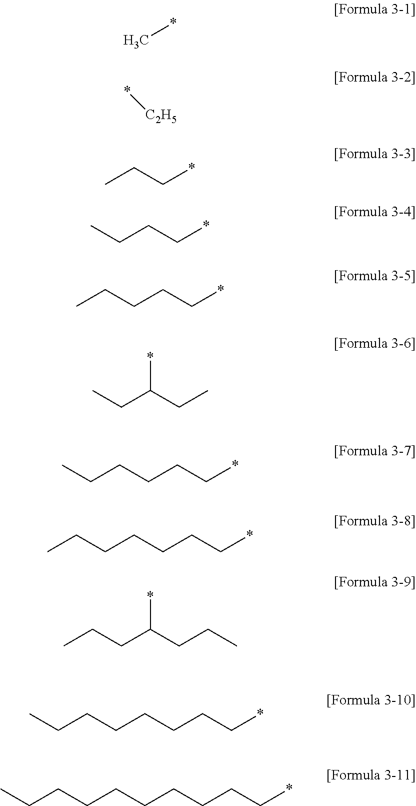

Formula 3-1 to Formula 3-11 represent cases where in Formula 2, R_{y} is further defined. Formula 3-1 to Formula 3-11 represent cases where in Formula 2, R_{y} is a methyl group, an ethyl group, a n-propyl group, a n-butyl group, a n-pentyl group, a 3-methylpentyl group, a n-hexyl group, a n-heptyl group, a 4-methylheptyl group, a n-octyl group, or a n-decyl group, respectively.

In Formula 3-1 to Formula 3-11, at least one hydrogen atom may be optionally substituted with a deuterium atom.

In an embodiment, the fused polycyclic compound represented by Formula 1 may be represented by Formula 1-1.

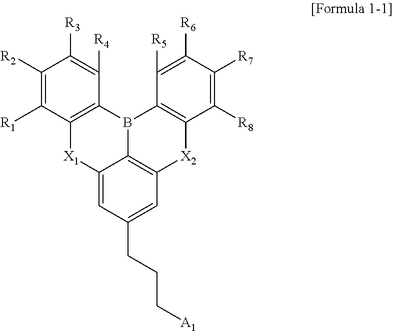

Formula 1-1 represents a case where R₉, R₁₀, and R₁₁ in Formula 1 are further defined. Formula 1-1 represents a case where in Formula 1, R₉ and Ru are each a hydrogen atom, and R₁₀ is an n-propyl group substituted with A₁. Formula 1-1 represents a case where in Formula 1, R₁₀ is a substituent represented by Formula 2.

In Formula 1-1, A₁ may be a substituted or unsubstituted linear alkyl group of 1 to 10 carbon atoms, or a substituted or unsubstituted branched alkyl group of 1 to 10 carbon atoms. For example, A₁ may be a methyl group, an ethyl group, a n-propyl group, a n-butyl group, a n-pentyl group, a n-hexyl group, a n-heptyl group, a n-octyl group, a n-nonyl group, or a n-decyl group.

In Formula 1-1, R₁ to R₈, Rₓ, X₁, and X₂ are the same as defined in Formula 1.

In Formula 1-1, at least one hydrogen atom may be optionally substituted with a deuterium atom.

In an embodiment, the fused polycyclic compound represented by Formula 1 may be represented by Formula 1-2.

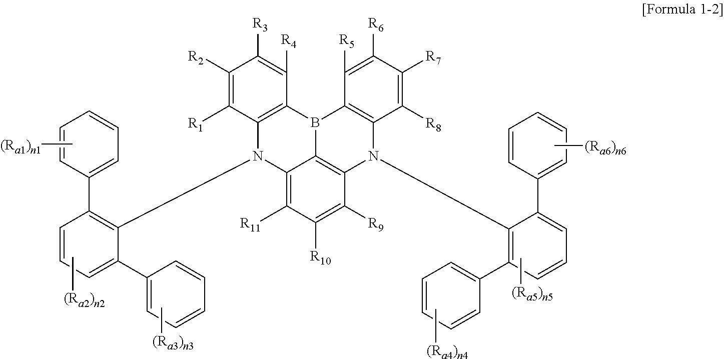

Formula 1-2 represents a case where in Formula 1, X₁, X₂, and Rₓ are further defined. Formula 1-2 represents a case where in Formula 1, X₁ and X₂ are each N(Rₓ), and Rₓ is a substituted or unsubstituted terphenyl group.

In Formula 1-2, Rₐ₁ to Rₐ₆ may each independently be a hydrogen atom, a deuterium atom, a halogen atom, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. For example, Rₐ₁ to Rₐ₆ may each independently be a hydrogen atom, a deuterium atom, a substituted or unsubstituted t-butyl group, or a substituted or unsubstituted phenyl group.

In Formula 1-2, n1 and n3 may each independently be an integer from 0 to 5. If n1 and n3 are each 0, the fused polycyclic compound may not be substituted with Rₐ₁ and Rₐ₃. A case where n1 and n3 are each 5 and all Rₐ₁ groups and Rₐ₃ groups are hydrogen atoms may be the same as a case where n1 and n3 are each 0. If n1 and n3 are each 2 or more, multiple groups of each of Rₐ₁ and Rₐ₃ may be the same as each other, or at least one group thereof may be different from the remainder.

In Formula 1-2, n4 and n6 may each independently be an integer from 0 to 5. If n4 and n6 are each 0, the fused polycyclic compound may not be substituted with Rₐ₄ and Rₐ₆. A case where n4 and n6 are each 5 and all Rₐ₄ groups and Rₐ₆ groups are hydrogen atoms may be the same as a case where n4 and n6 are each 0. If n4 and n6 are each 2 or more, multiple groups of each of Rₐ₄ and Rₐ₆ may be the same as each other, or at least one group thereof may be different from the remainder.

In Formula 1-2, n2 and n5 may each independently be an integer from 0 to 3. If n2 and n5 are each 0, the fused polycyclic compound may not be substituted with Rₐ₂ and Rₐ₅. A case where n2 and n5 are each 3 and all Rₐ₂ groups and Rₐ₅ groups are hydrogen atoms may be the same as a case where n2 and n5 are each 0. If n2 and n5 are each 2 or more, multiple groups of each of Rₐ₂ and Rₐ₅ may be the same as each other, or at least one group thereof may be different from the remainder.

In Formula 1-2, R₁ to R₁₁ are the same as defined in Formula 1.

In an embodiment, the fused polycyclic compound represented by Formula 1 may be represented by Formula 1-3.

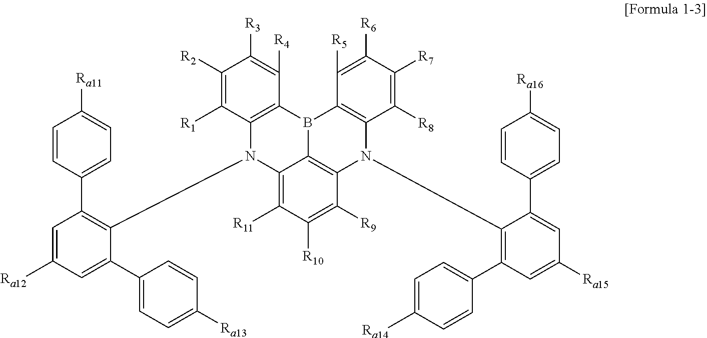

Formula 1-3 represents a case where in Formula 1-2, Rₐ₁ to Rₐ₆ are further defined and n1 to n6 are further defined. Formula 1-3 represents a case where in Formula 1-2, n1 to n6 are each 1, or a case where in Formula 1-2, n1, n3, n4, and n6 are each 5, n2 and n5 are each 3, four of each of Rₐ₁, Rₐ₃, Rₐ₄, and Rₐ₆ and two of each of Rₐ₂ and Rₐ₅ are each a hydrogen atom. Formula 1-3 represents a case where in Formula 1-2, the bonding positions of Rₐ₁ to Rₐ₆ are further defined.

In Formula 1-3, Rₐ₁₁ to Rₐ₁₆ may each independently be a hydrogen atom, a deuterium atom, a halogen atom, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. For example, Rₐ₁₁, Rₐ₁₃, Rₐ₁₄, and Rₐ₁₆ may each independently be a hydrogen atom, a substituted or unsubstituted phenyl group, or a substituted or unsubstituted biphenyl group; and Rₐ₁₂ and Rₐ₁₅ may each independently be a hydrogen atom, or a substituted or unsubstituted t-butyl group.

In Formula 1-3, R₁ to R₁₁ are the same as defined in Formula 1.

In an embodiment, in Formula 1, at least one of R₁ to R₄ may each independently be a group represented by Formula 2, Formula 4-1, or Formula 4-2; and at least one of R₅ to R₈ may each independently be a group represented by Formula 2, Formula 4-1, or Formula 4-2. For example, in Formula 1, R₂ and R₇ may each independently be a group represented by Formula 4-1 or Formula 4-2.

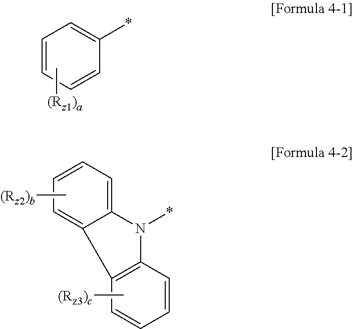

In Formula 4-1, R_{z1} may be a hydrogen atom, a deuterium atom, a halogen atom, a substituted or unsubstituted linear alkyl group of 1 to 20 carbon atoms, or a substituted or unsubstituted branched alkyl group of 1 to 20 carbon atoms. For example, R_{z1} may be a hydrogen atom, a deuterium atom, an unsubstituted n-butyl group, an unsubstituted t-butyl group, or an unsubstituted n-pentyl group.

In Formula 4-2, R₂₂ and R_{z3} may each independently be a hydrogen atom, a deuterium atom, a halogen atom, a substituted or unsubstituted linear alkyl group of 1 to 20 carbon atoms, or a substituted or unsubstituted branched alkyl group of 1 to 20 carbon atoms. For example, R₂₂ and R_{z3} may each independently be a hydrogen atom, a deuterium atom, an unsubstituted n-butyl group, an unsubstituted t-butyl group, or an unsubstituted n-pentyl group.

In Formula 4-1, a may be an integer from 0 to 5. If a is 0, the fused polycyclic compound may not be substituted with R_{z1}. A case where a is 5 and all R_{z1} groups are hydrogen atoms may be the same as a case where a is 0. If a is 2 or more, multiple R_{z1} groups may be the same as each other, or at least one group thereof may be different from the remainder.

In Formula 4-2, b and c may each independently be an integer from 0 to 4. If b and c are each 0, the fused polycyclic compound may not be substituted with R₂₂ and R_{z3}. A case where b and c are each 4 and all R₂₂ groups and R_{z3} groups are hydrogen atoms may be the same as a case where b and c are each 0. If b and c are each 2 or more, multiple groups of each of R₂₂ and R_{z3} may be the same as each other, or at least one group thereof may be different from the remainder.

In an embodiment, the fused polycyclic compound represented by Formula 1 may be represented by one of Formula 1-4 to Formula 1-6.

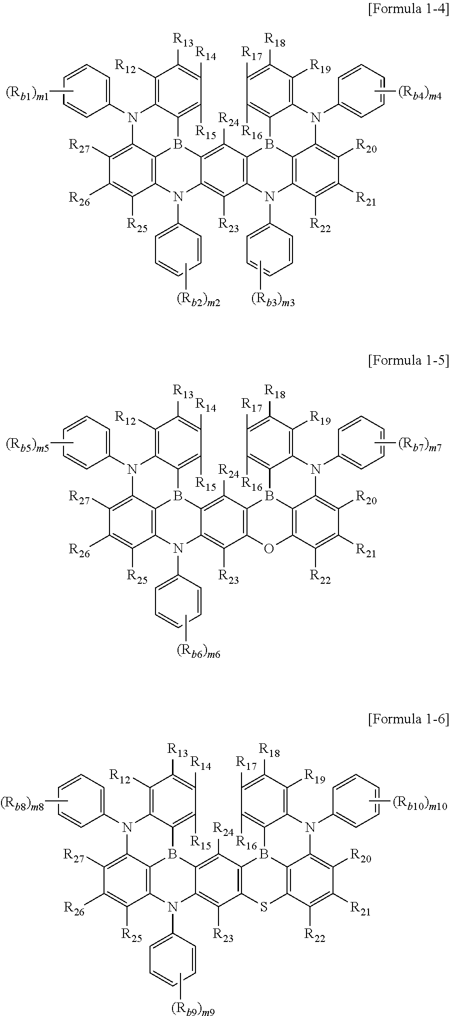

Formula 1-4 to Formula 1-6 each represent a case where in Formula 1, X₁ and X₂ are further defined, and R₂ and R₃ (or R₆ and R₇) are further defined. Formula 1-4 to Formula 1-6 each represent a case where R₂ and R₃ (or R₆ and R₇) are further defined, and a heterocycle including a boron atom is additionally fused to the fused ring core. Formula 1-4 to Formula 1-6 each represent a case where a heterocycle including a boron atom is fused to the first or second aromatic ring.

In Formula 1-4 to Formula 1-6, R₁₂ to R₂₇ may each independently be a hydrogen atom, a deuterium atom, a halogen atom, a cyano group, a hydroxyl group, a substituted or unsubstituted oxy group, a substituted or unsubstituted thio group, a substituted or unsubstituted boron group, a substituted or unsubstituted silyl group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or a group represented by Formula 2. For example, R₁₂ to R₂₅ and R₂₇ may each independently be a hydrogen atom or a deuterium atom; and R₂₆ may be a substituted or unsubstituted linear alkyl group of 1 to 20 carbon atoms or a group represented by Formula 2.

In Formula 1-4 to Formula 1-6, at least one of R₂₅ to R₂₇ may each independently be a group represented by Formula 2.

In Formula 1-4 to Formula 1-6, R_{b1} to R_{b10} may each independently be a hydrogen atom, a deuterium atom, a halogen atom, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. For example, R_{b1} to R_{b10} may each independently be a hydrogen atom, a deuterium atom, a substituted or unsubstituted t-butyl group, or a substituted or unsubstituted phenyl group.

In Formula 1-4, m1 to m4 may each independently be an integer from 0 to 5. If m1 to m4 are each 0, the fused polycyclic compound may not be substituted with R_{b1} to R_{b4}. A case where m1 to m4 are each 5 and all groups of R_{b1} to R_{b4} are hydrogen atoms may be the same as a case where m1 to m4 are each 0. If m1 to m4 are each 2 or more, multiple groups of each of R_{b1} to R_{b4} may be the same as each other, or at least one group thereof may be different from the remainder.

In Formula 1-5, m5 to m7 may each independently be an integer from 0 to 5. If m5 to m7 are each 0, the fused polycyclic compound may not be substituted with R_{b5} to R_{b7}. A case where m5 to m7 are each 5 and all groups of R_{b5} to R_{b7} are hydrogen atoms may be the same as a case where m5 to m7 are each 0. If m5 to m7 are each 2 or more, multiple groups of each of R_{b5} to R_{b7} may be the same as each other, or at least one group thereof may be different from the remainder.

In Formula 1-6, m8 to m10 may each independently be an integer from 0 to 5. If m8 to m10 are each 0, the fused polycyclic compound may not be substituted with R_{b5} to R_{b10}. A case where m8 to m10 are each 5 and all groups of R_{b5} to R_{b10} are hydrogen atoms may be the same as a case where m8 to m10 are each 0. If m8 to m10 are each 2 or more, multiple groups of each of R_{b8} to R_{b10} may be the same as each other, or at least one group thereof may be different from the remainder.

In Formula 1-4 to Formula 1-6, at least one hydrogen atom may be optionally substituted with a deuterium atom.

In an embodiment, the fused polycyclic compound represented by Formula 1 may be represented by Formula 1-7 or Formula 1-8.

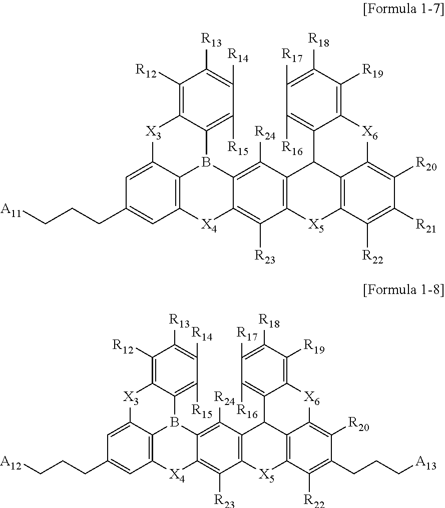

Formula 1-7 and Formula 1-8 each represent a case where in Formula 1, R₁₀ is further defined, and R₂ and R₃ (or R₆ and R₇) are further defined. Formula 1-7 and Formula 1-8 each represent a case where R₂ and R₃ (or R₆ and R₇) are further defined, and a heterocycle including a boron atom is additionally fused to the fused ring core. Formula 1-7 and Formula 1-8 each represent a case where a heterocycle including a boron atom is fused to the first or second aromatic ring. Formula 1-7 and Formula 1-8 each represent a case where in Formula 1, R₁₀ is a n-propenyl group substituted with A₁₁ and A₁₂, respectively.

In Formula 1-7 and Formula 1-8, X₃ to X₆ may each independently be O, S or N(Rₓ). For example, in Formula 1-7 and Formula 1-8, X₃ to X₆ may each independently be N(Rₓ).

In Formula 1-7 and Formula 1-8, R₁₂ to R₂₄ may each independently be a hydrogen atom, a deuterium atom, a halogen atom, a cyano group, a hydroxyl group, a substituted or unsubstituted oxy group, a substituted or unsubstituted thio group, a substituted or unsubstituted boron group, a substituted or unsubstituted silyl group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, a substituted or unsubstituted heteroaryl group of 2 to 30 ring-forming carbon atoms, or a group represented by Formula 2. For example, R₁₂ to R₂₄ may each independently be a hydrogen atom or a deuterium atom.

In Formula 1-7 and Formula 1-8, Rₓ is the same as defined in Formula 1.

In Formula 1-7 and Formula 1-8, at least one hydrogen atom may be optionally substituted with a deuterium atom.

In an embodiment, the fused polycyclic compound may be any compound selected from Compound Group 1. In an embodiment, in the light emitting element ED, the at least one functional layer may include at least one fused polycyclic compound among selected from Compound Group 1.

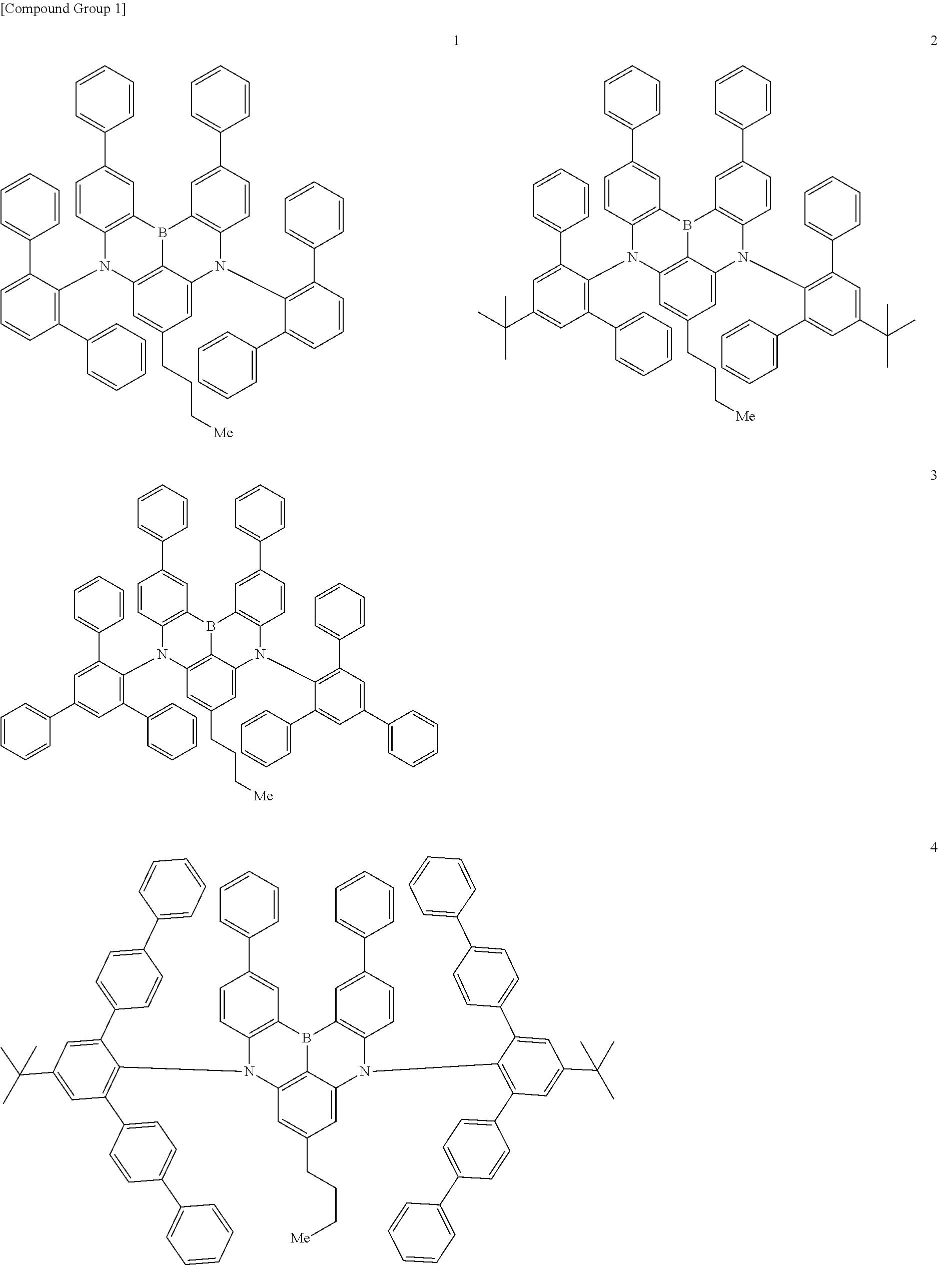

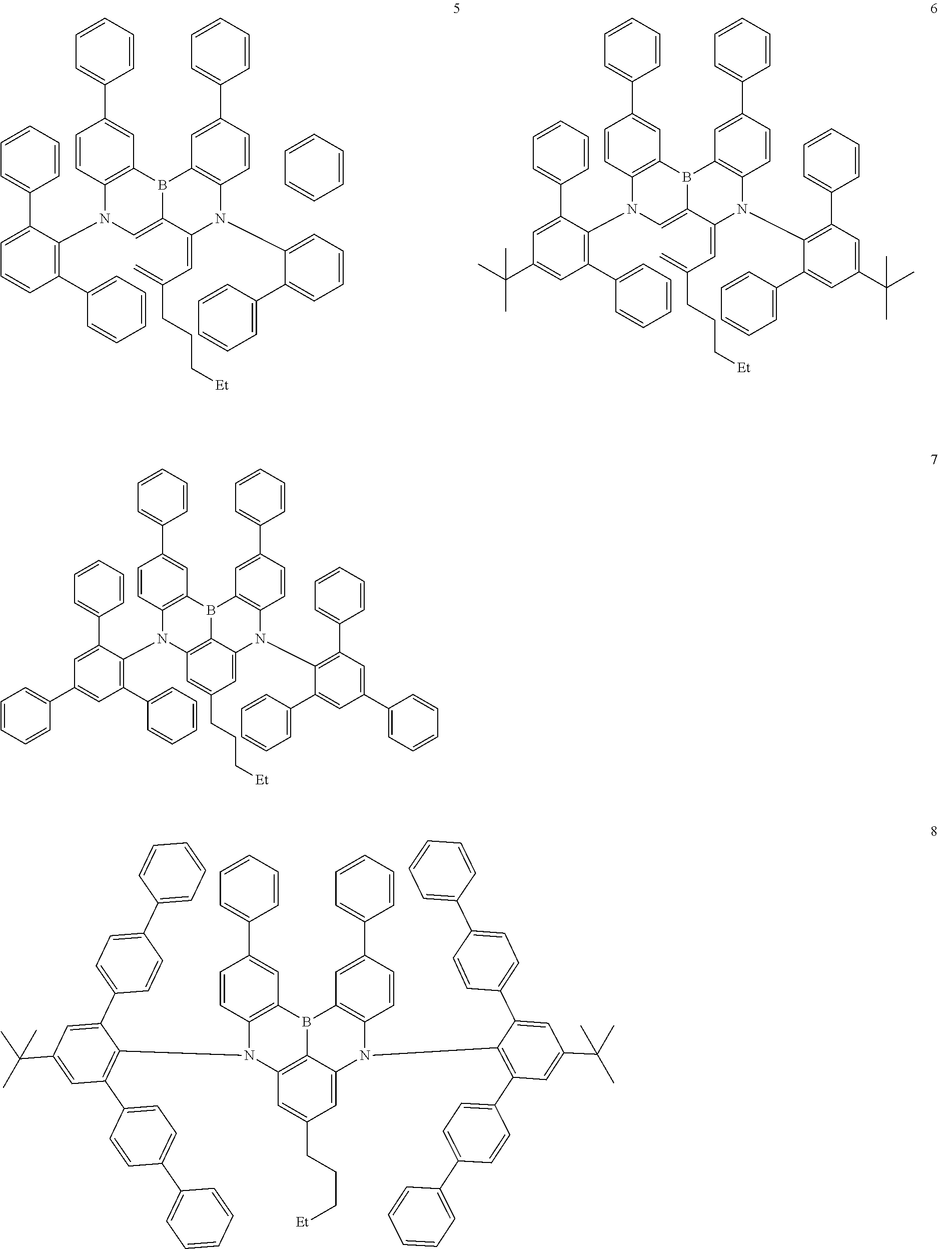

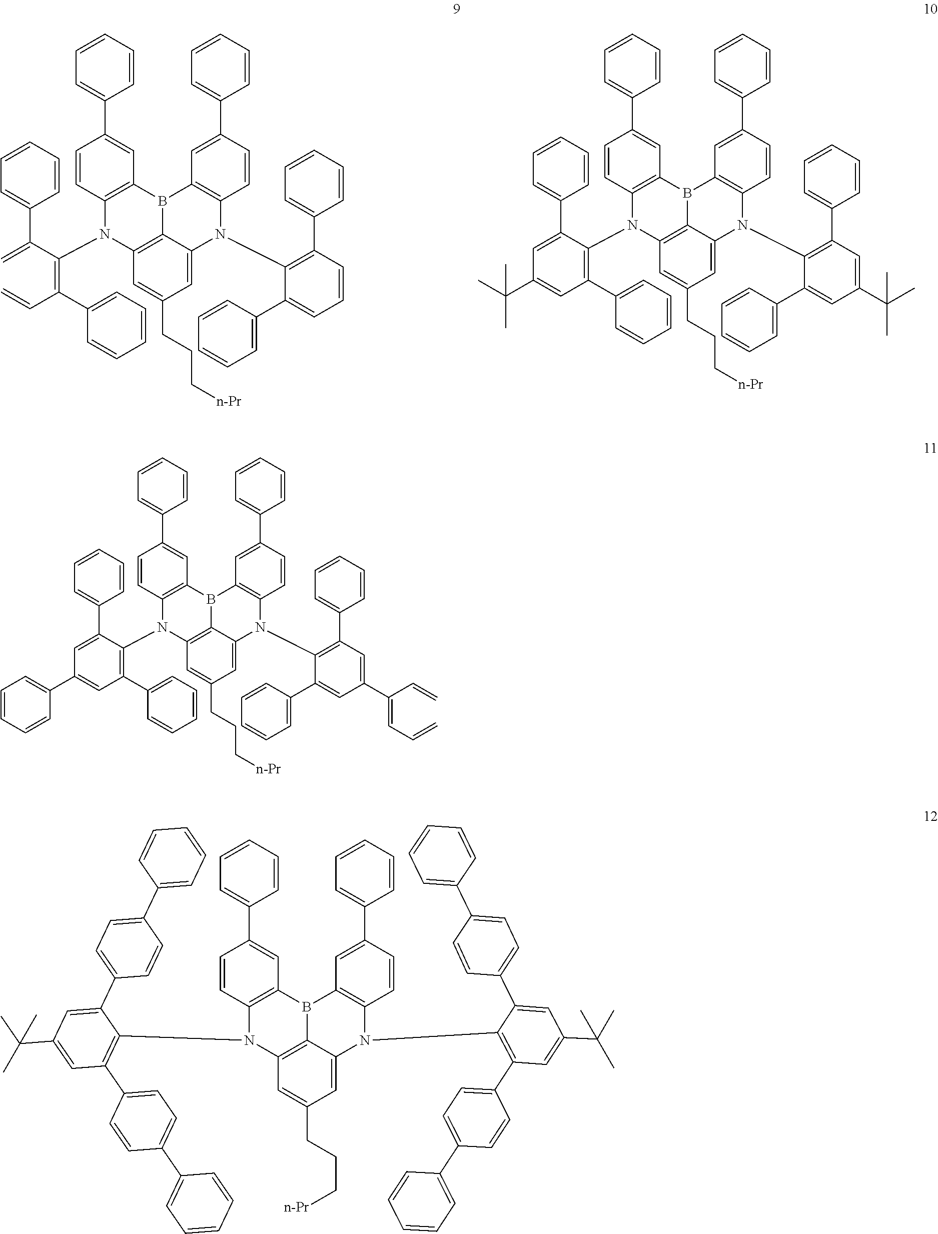

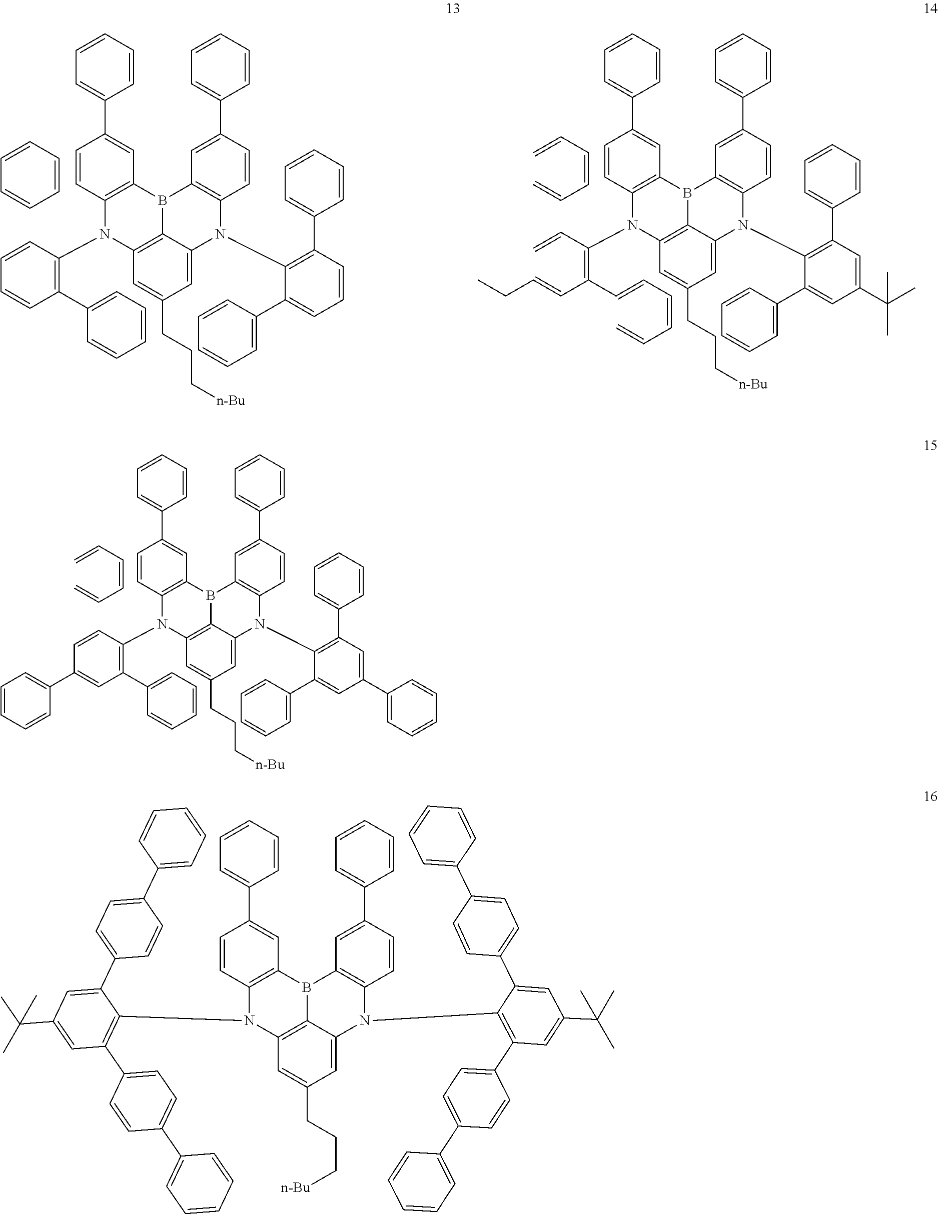

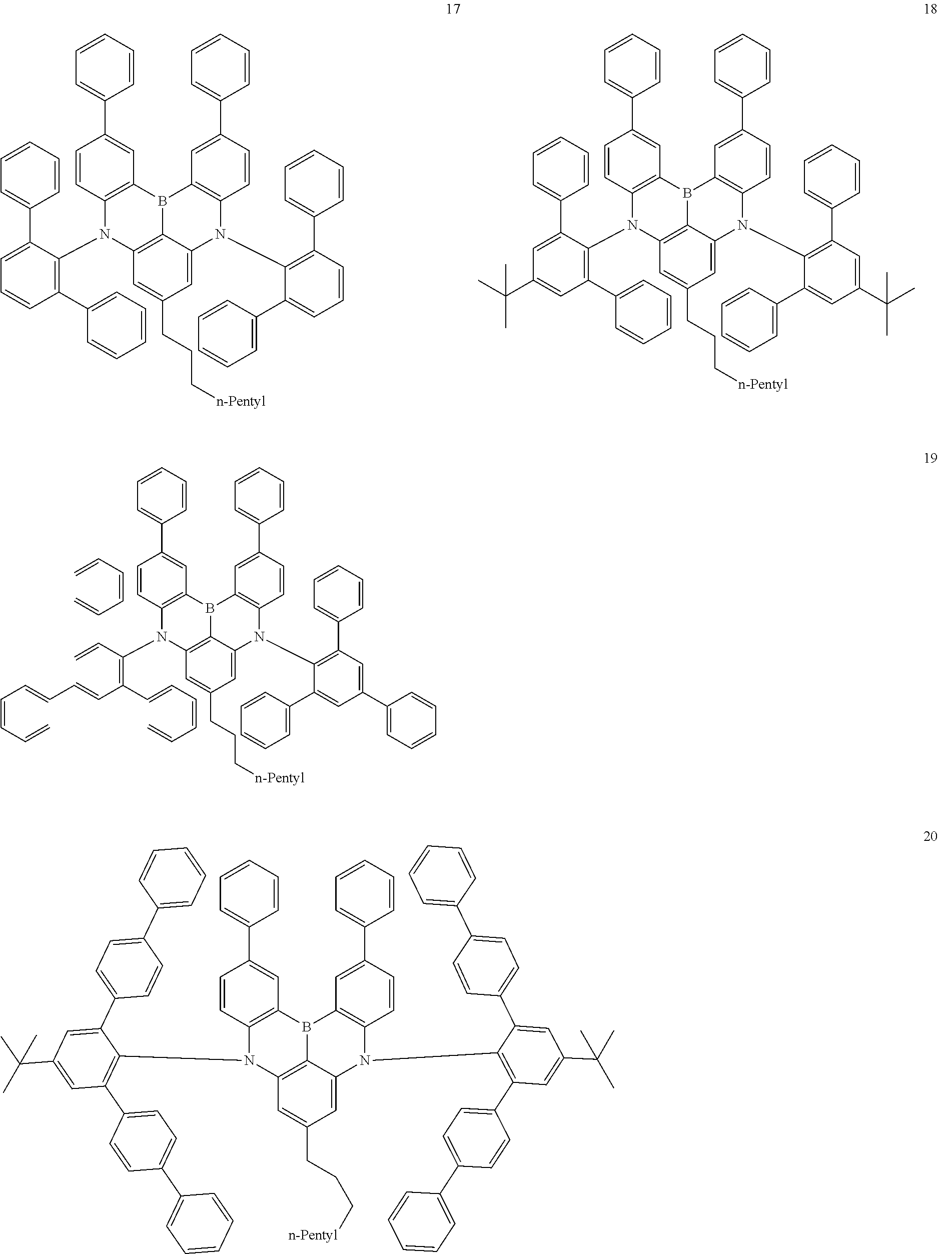

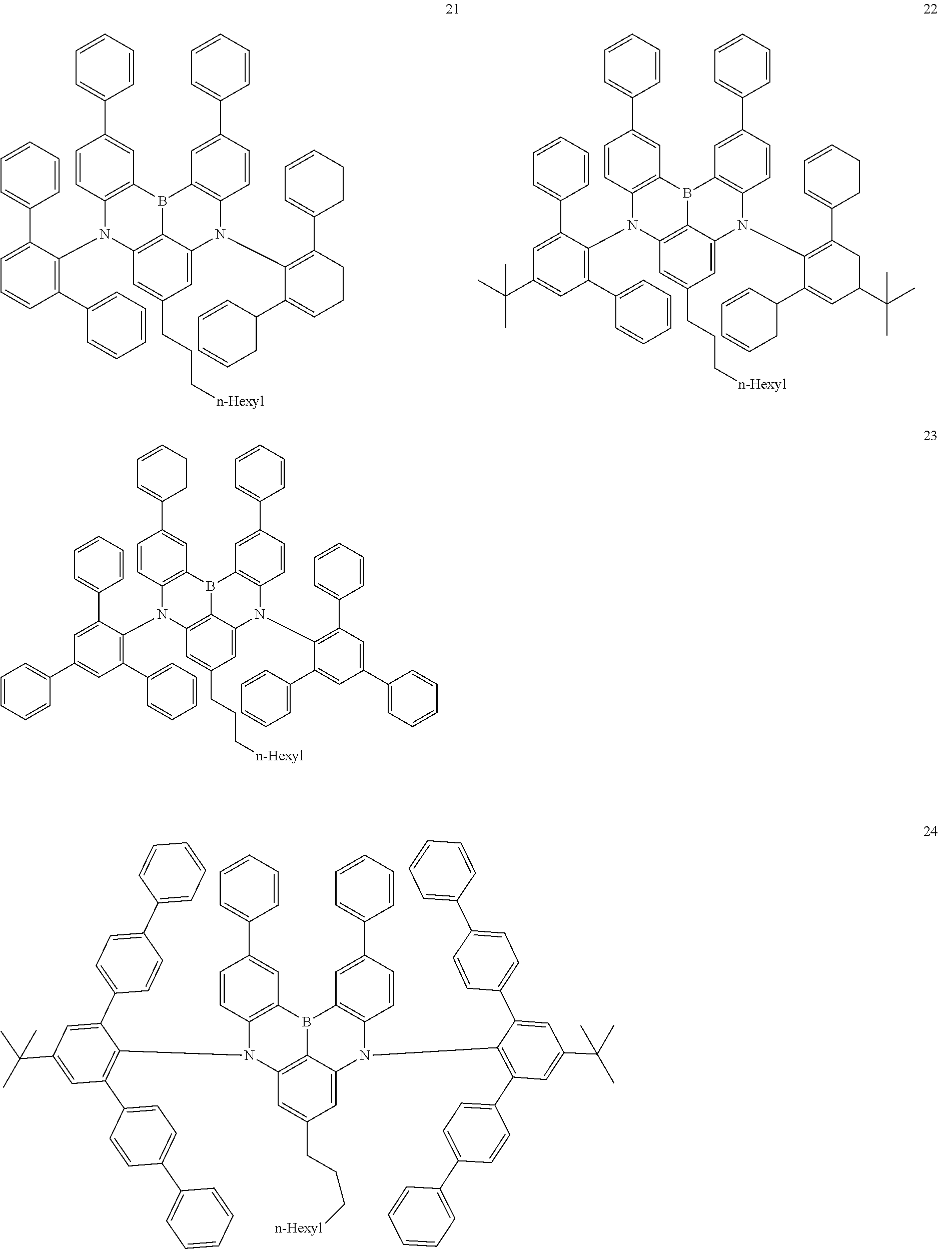

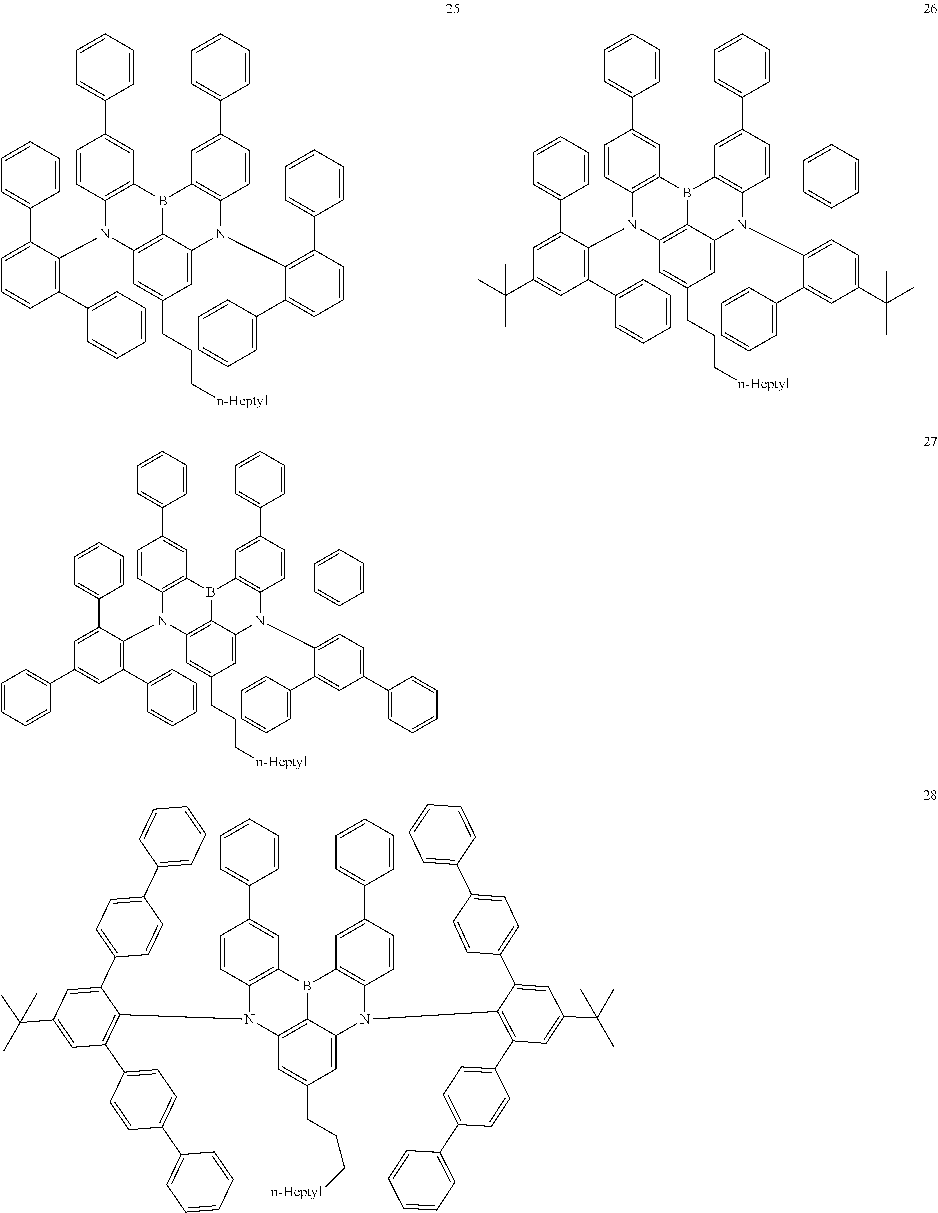

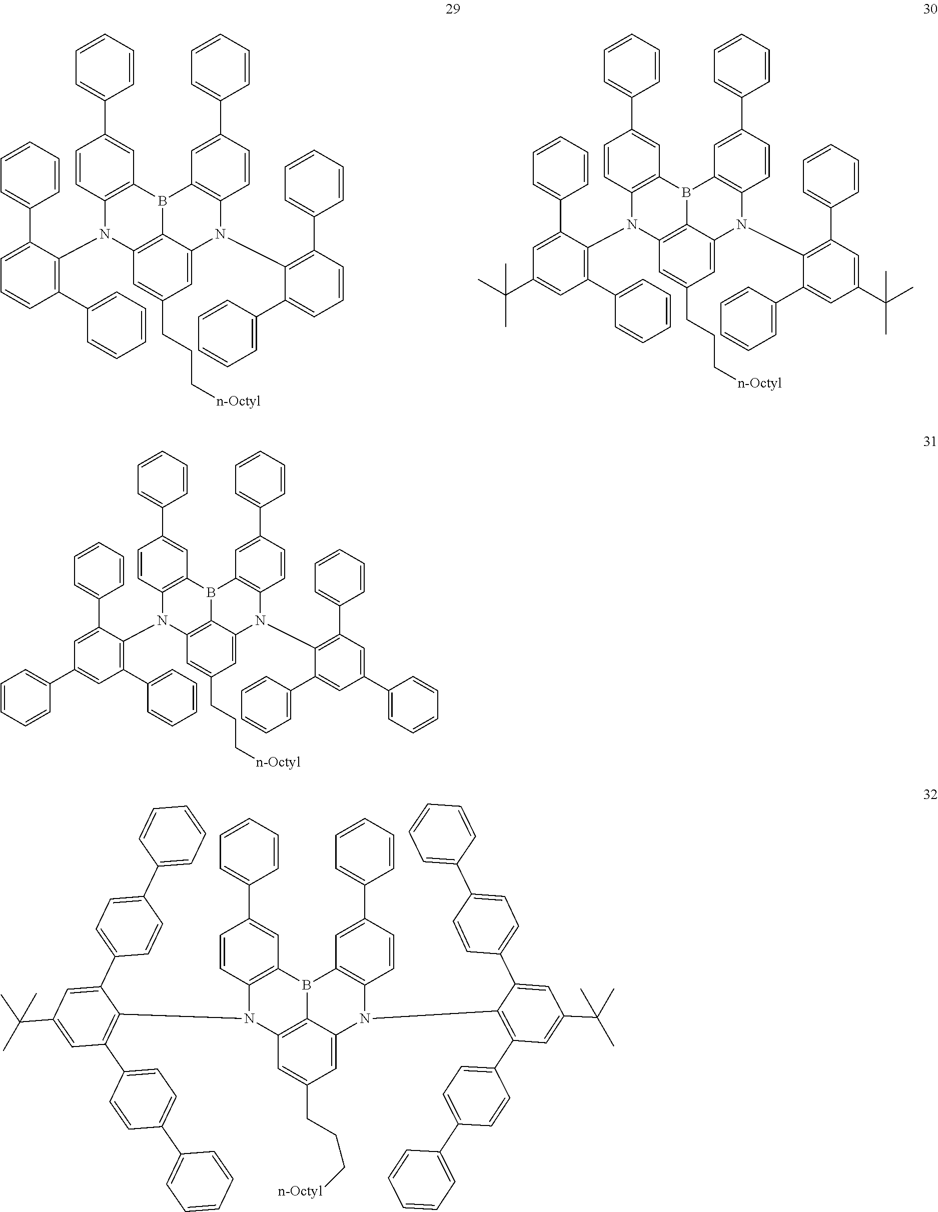

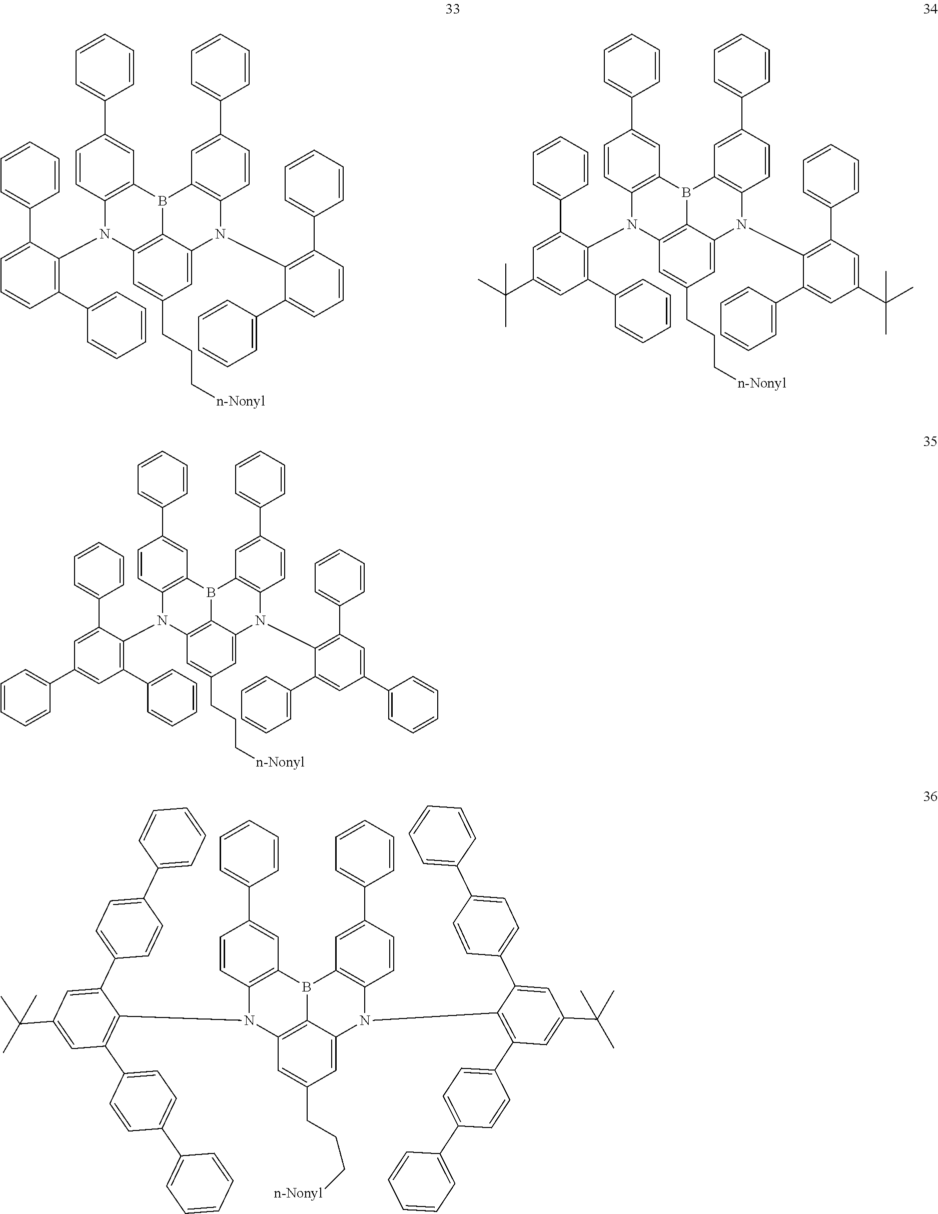

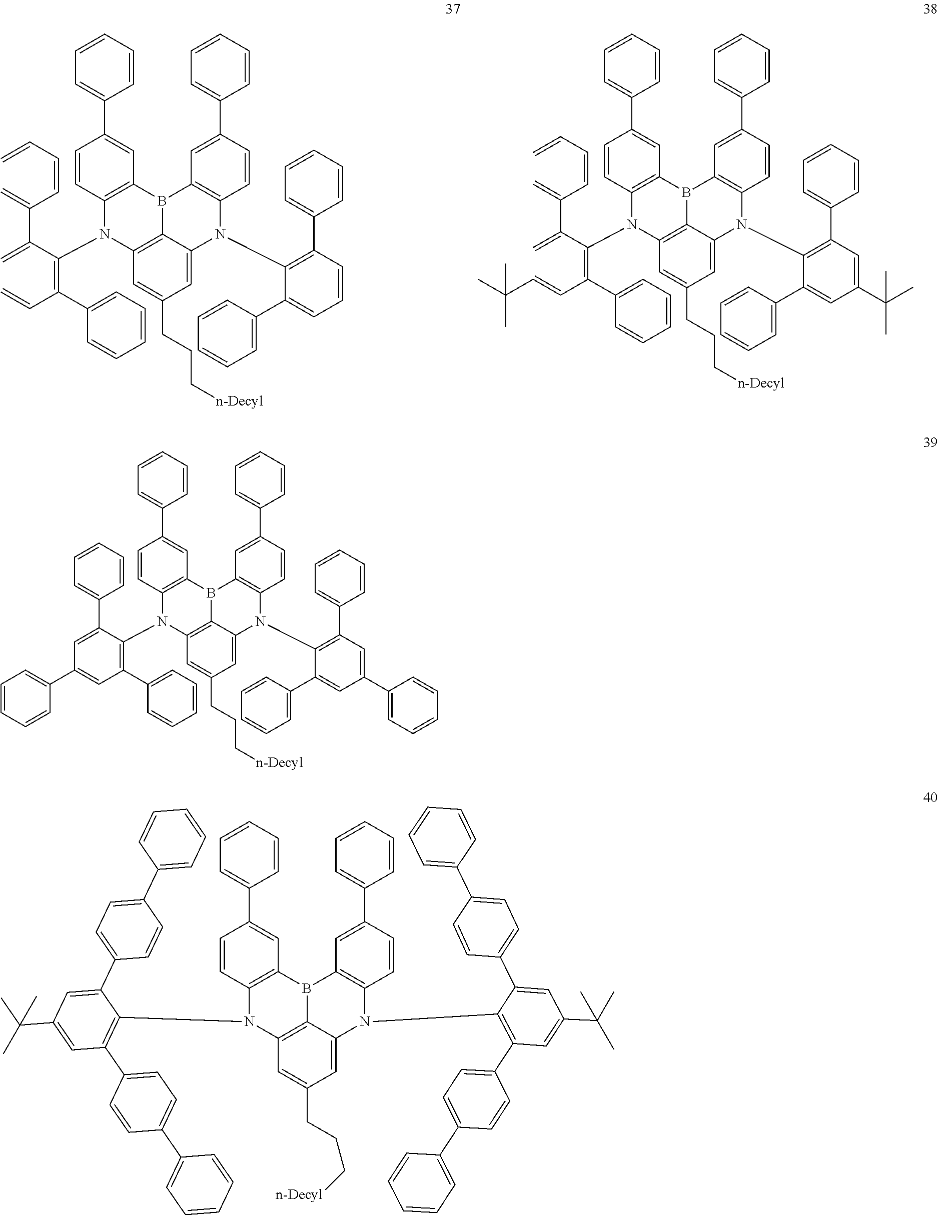

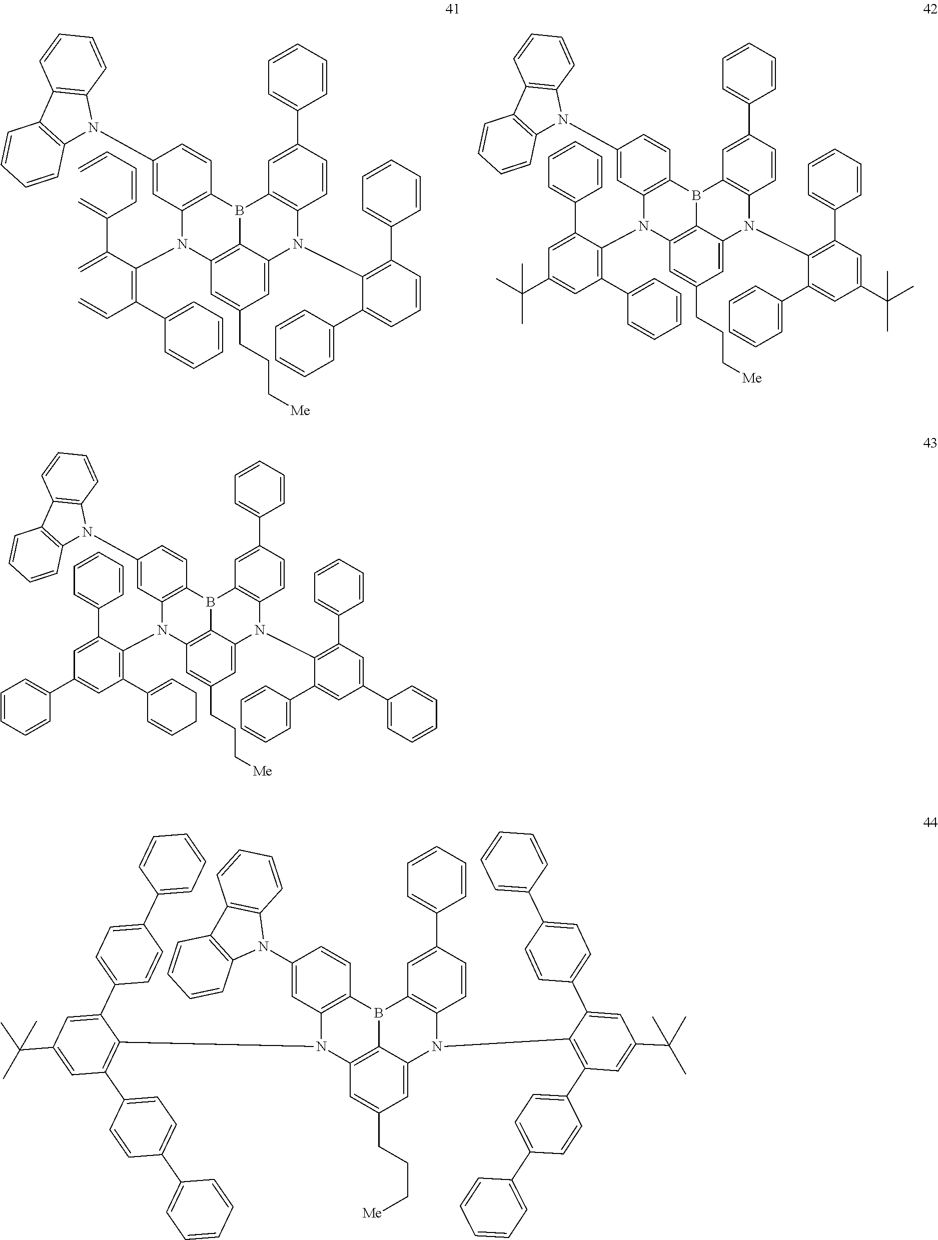

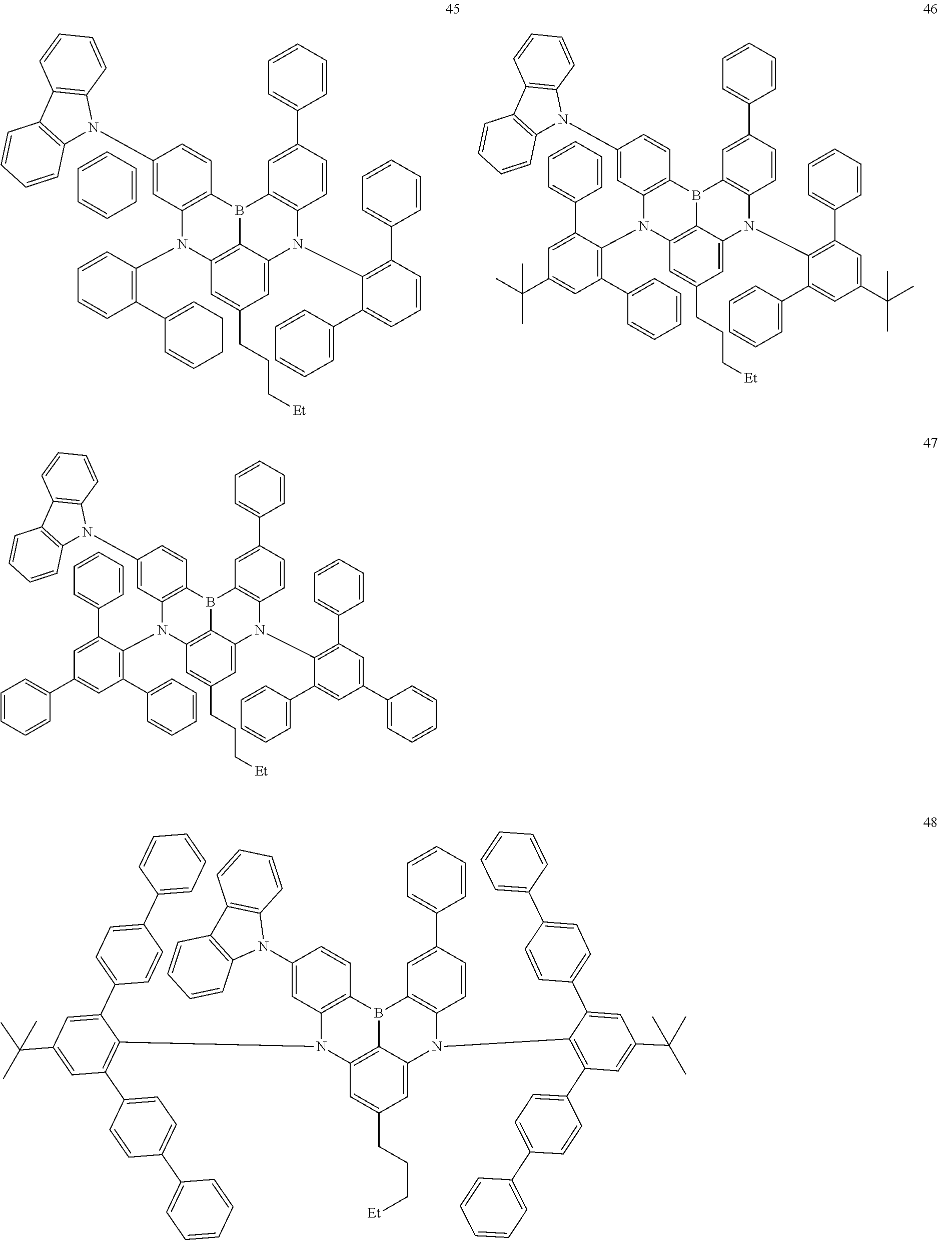

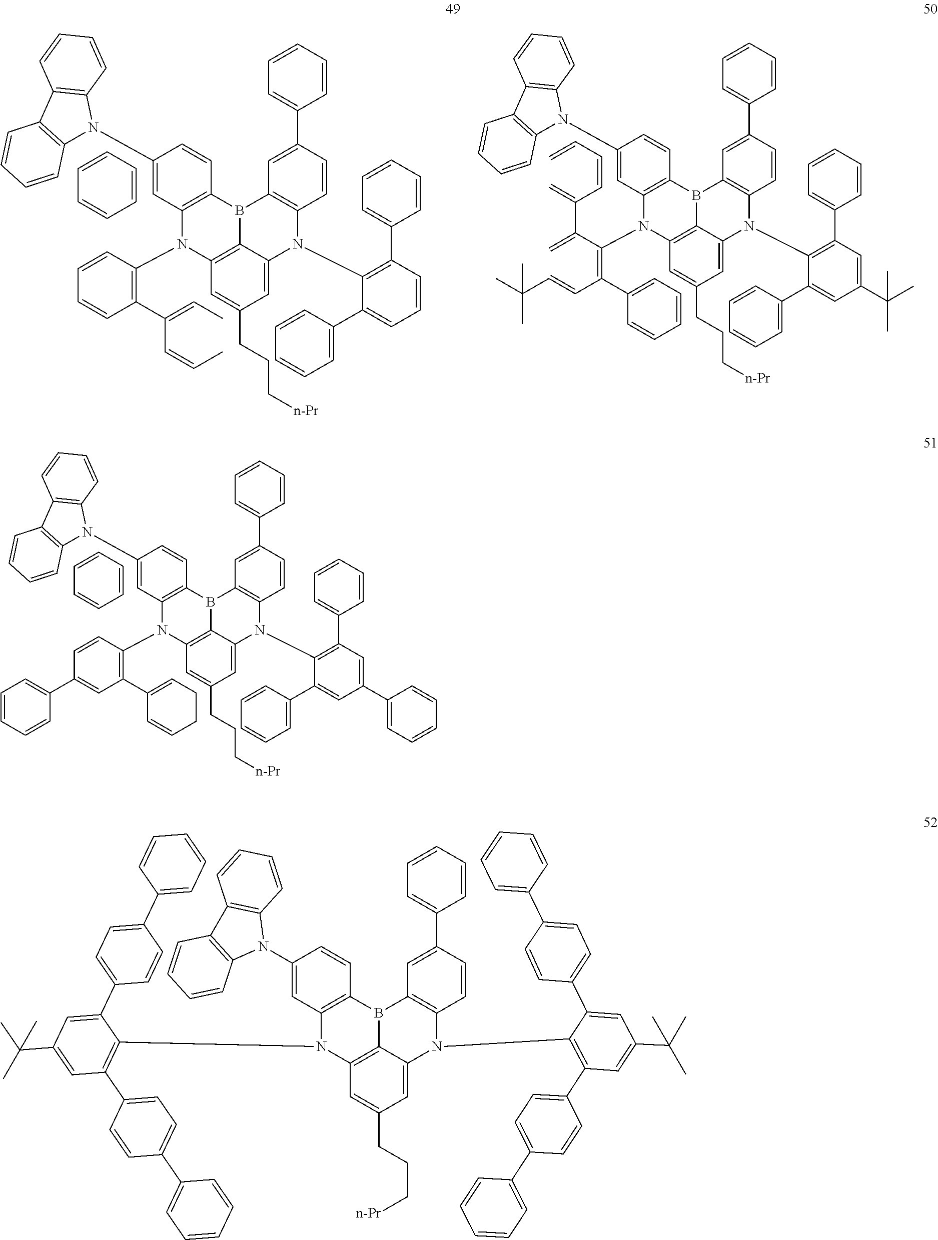

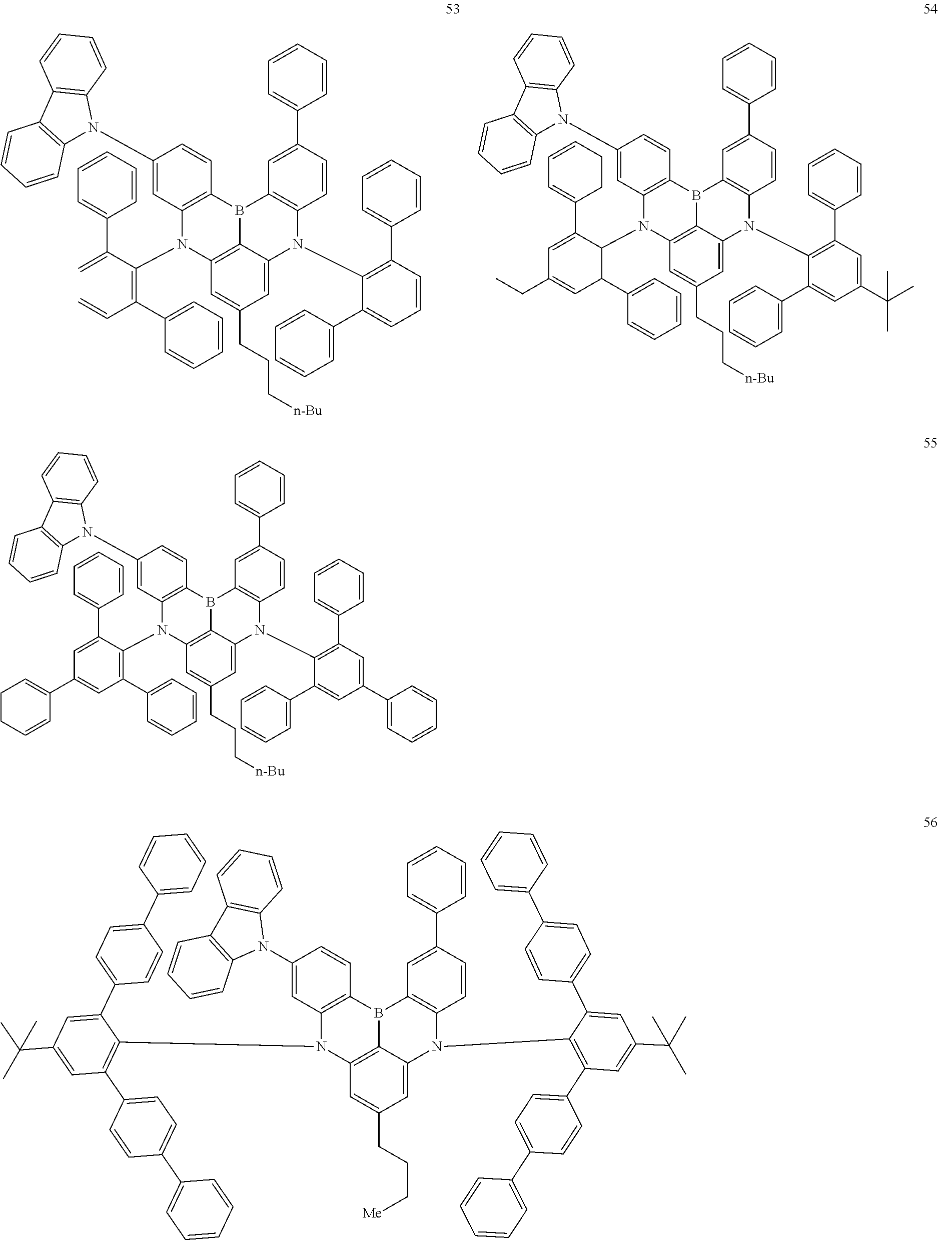

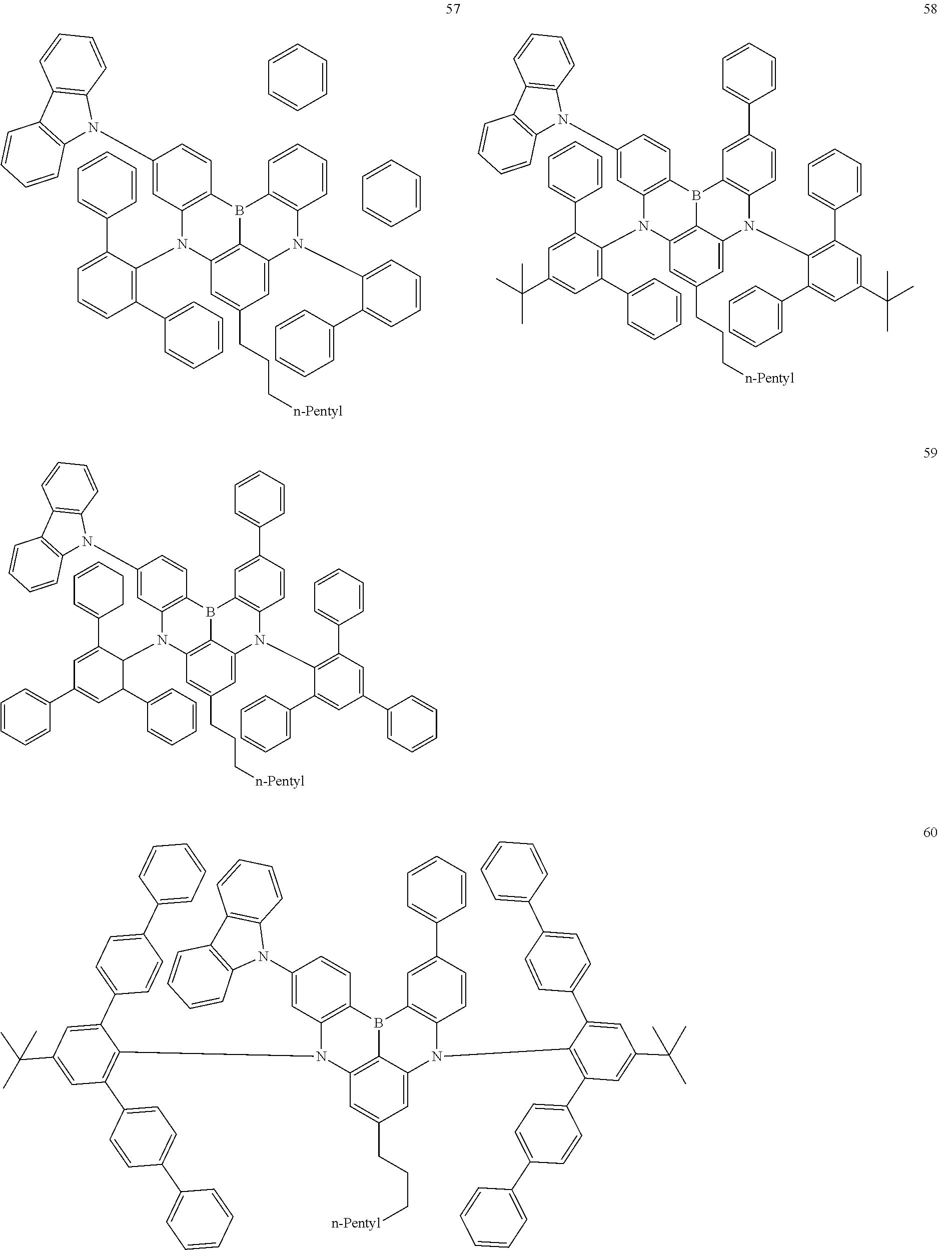

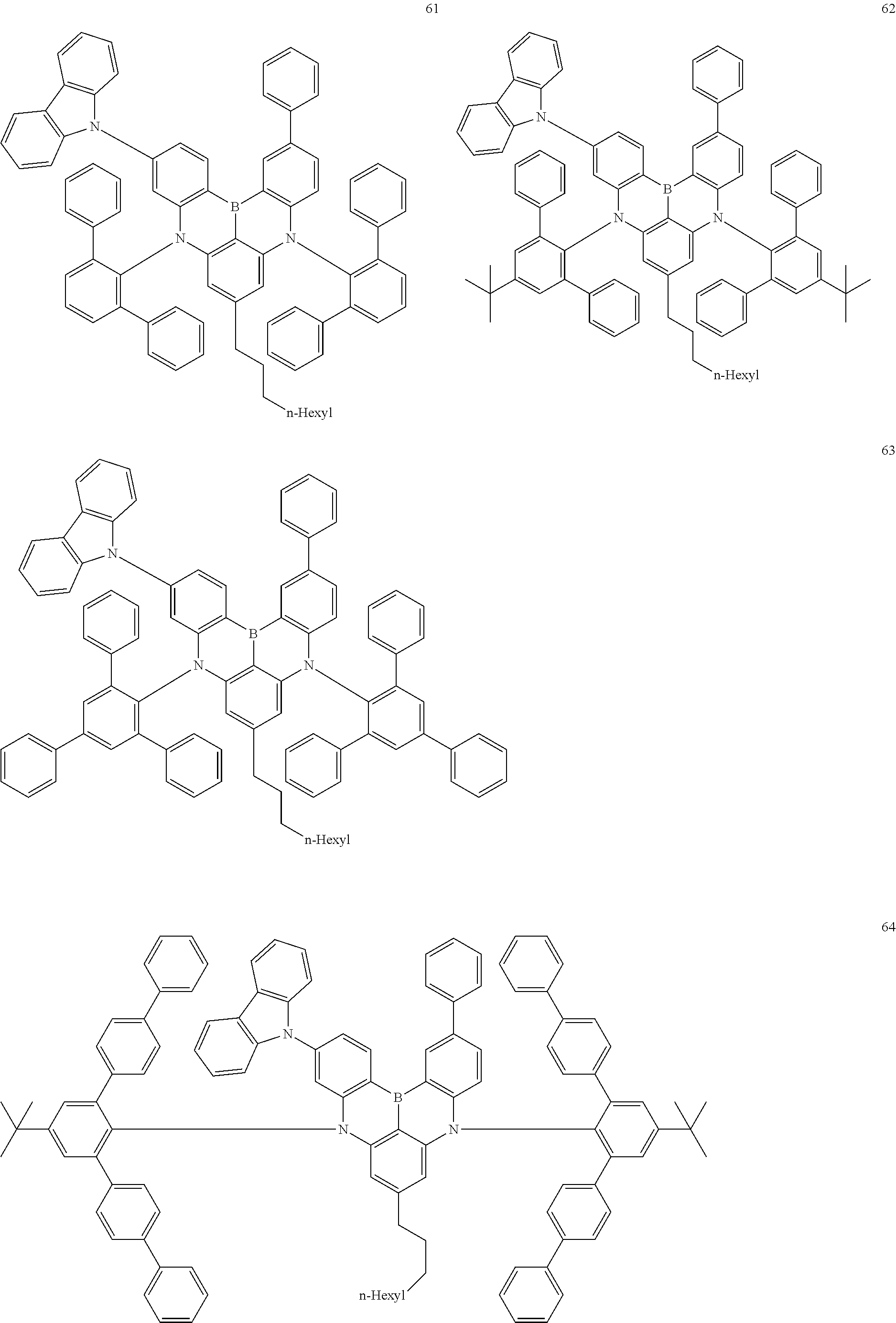

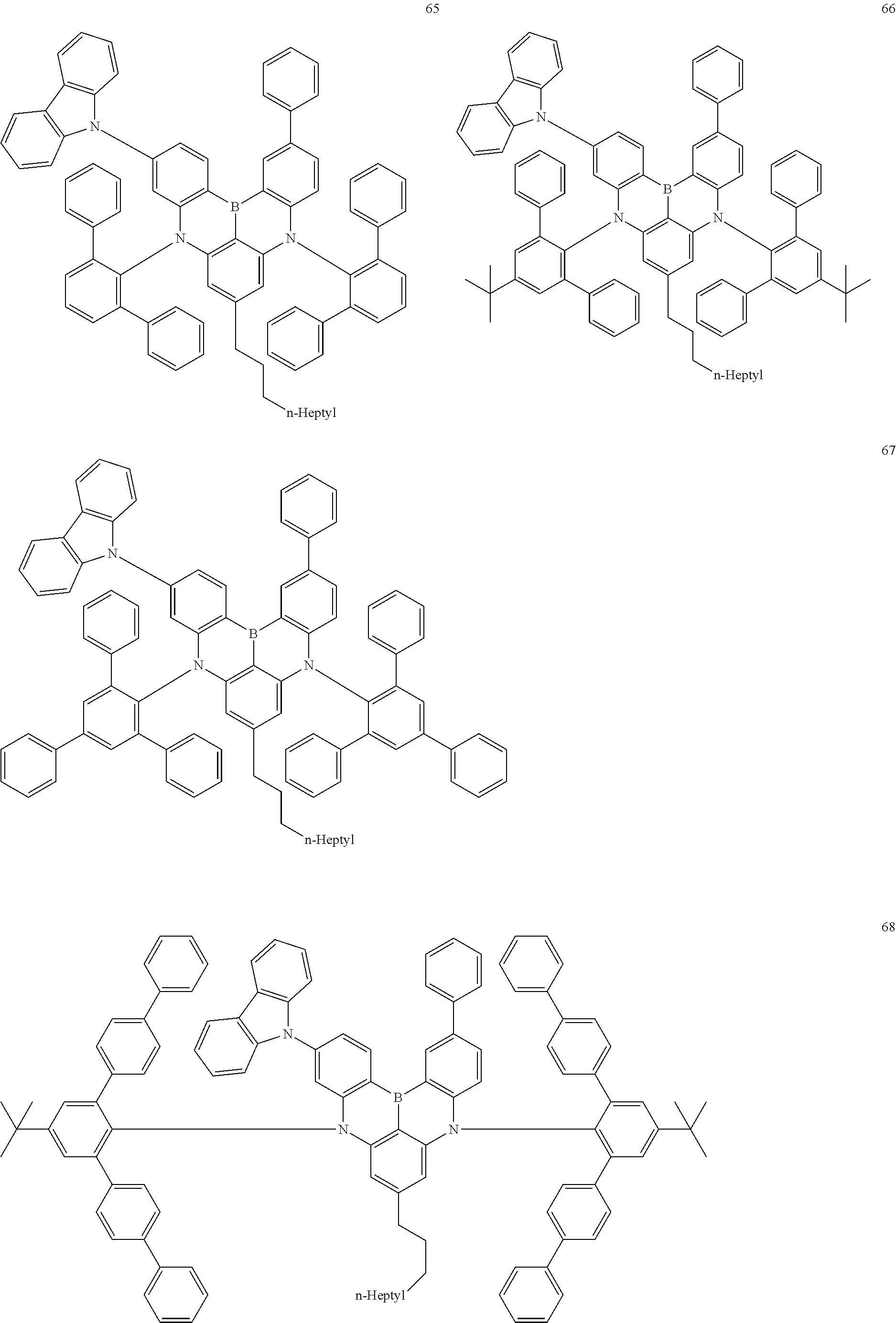

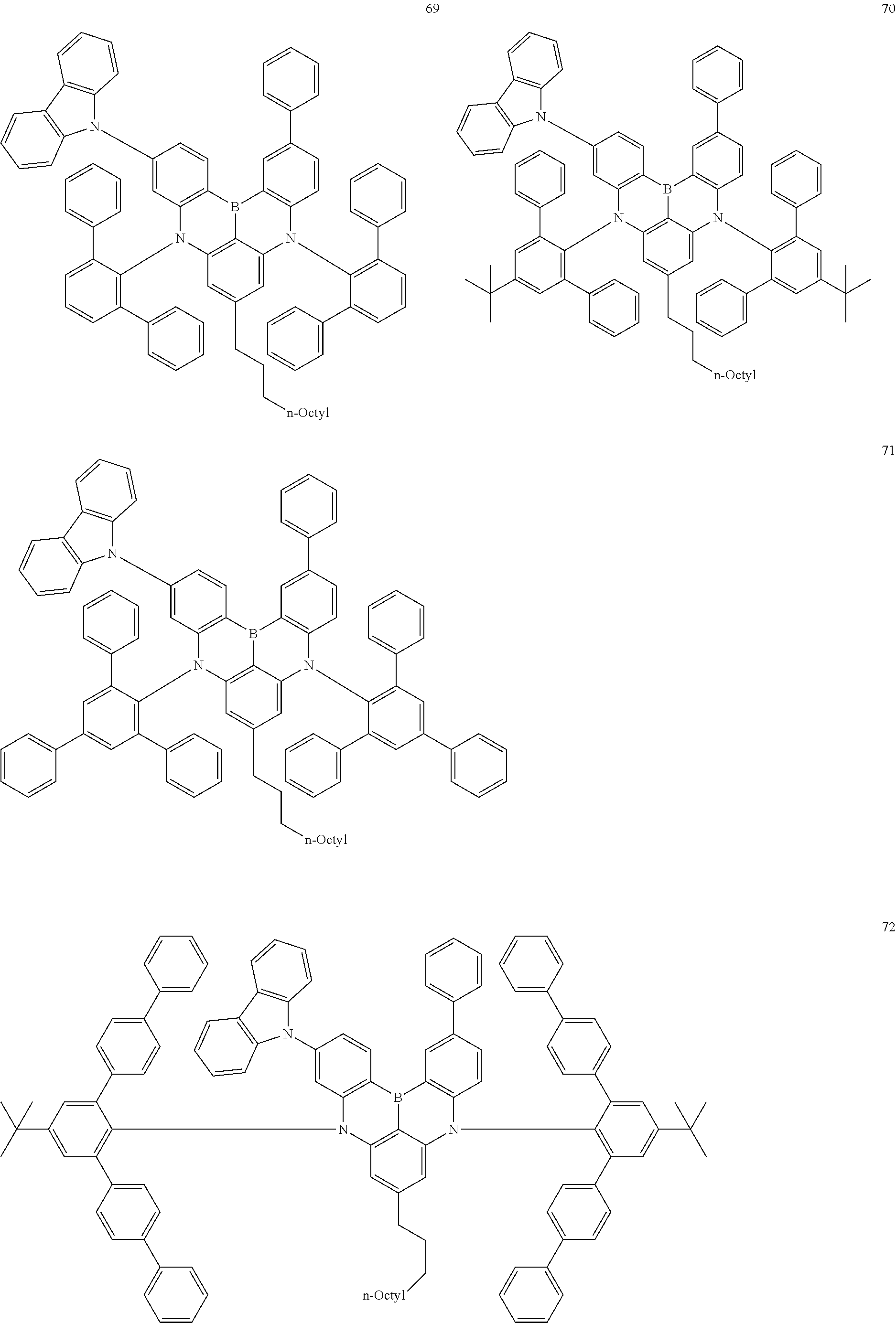

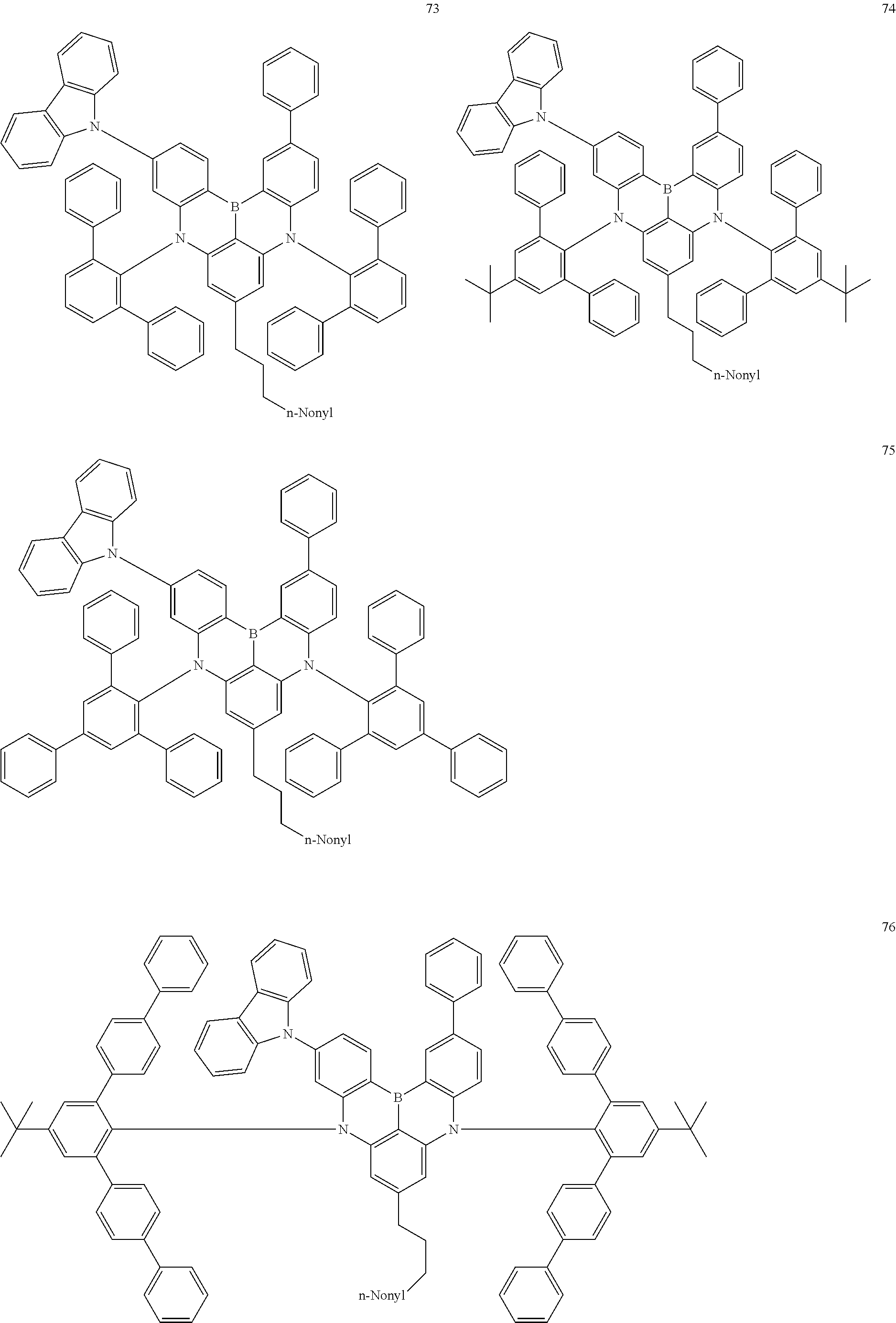

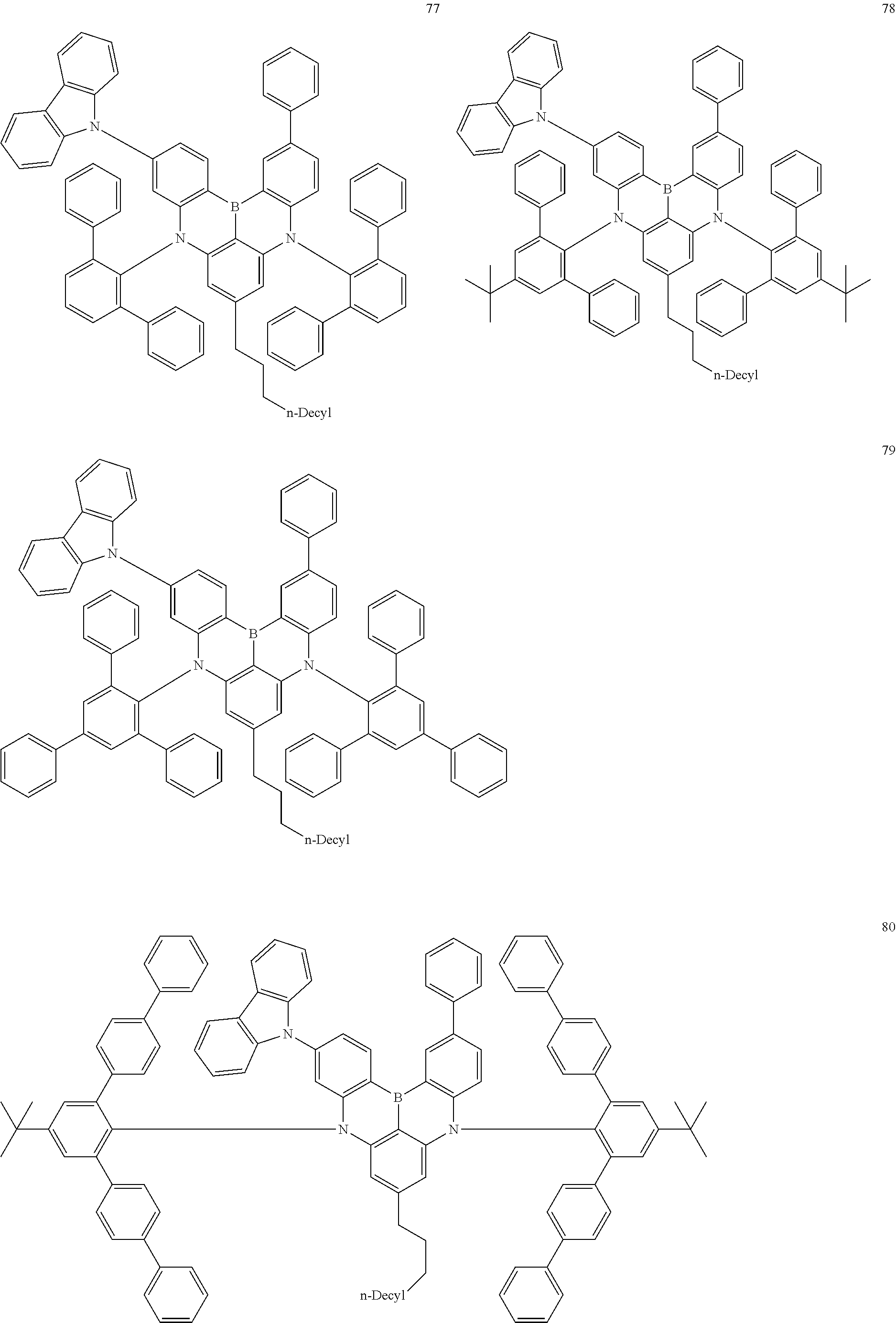

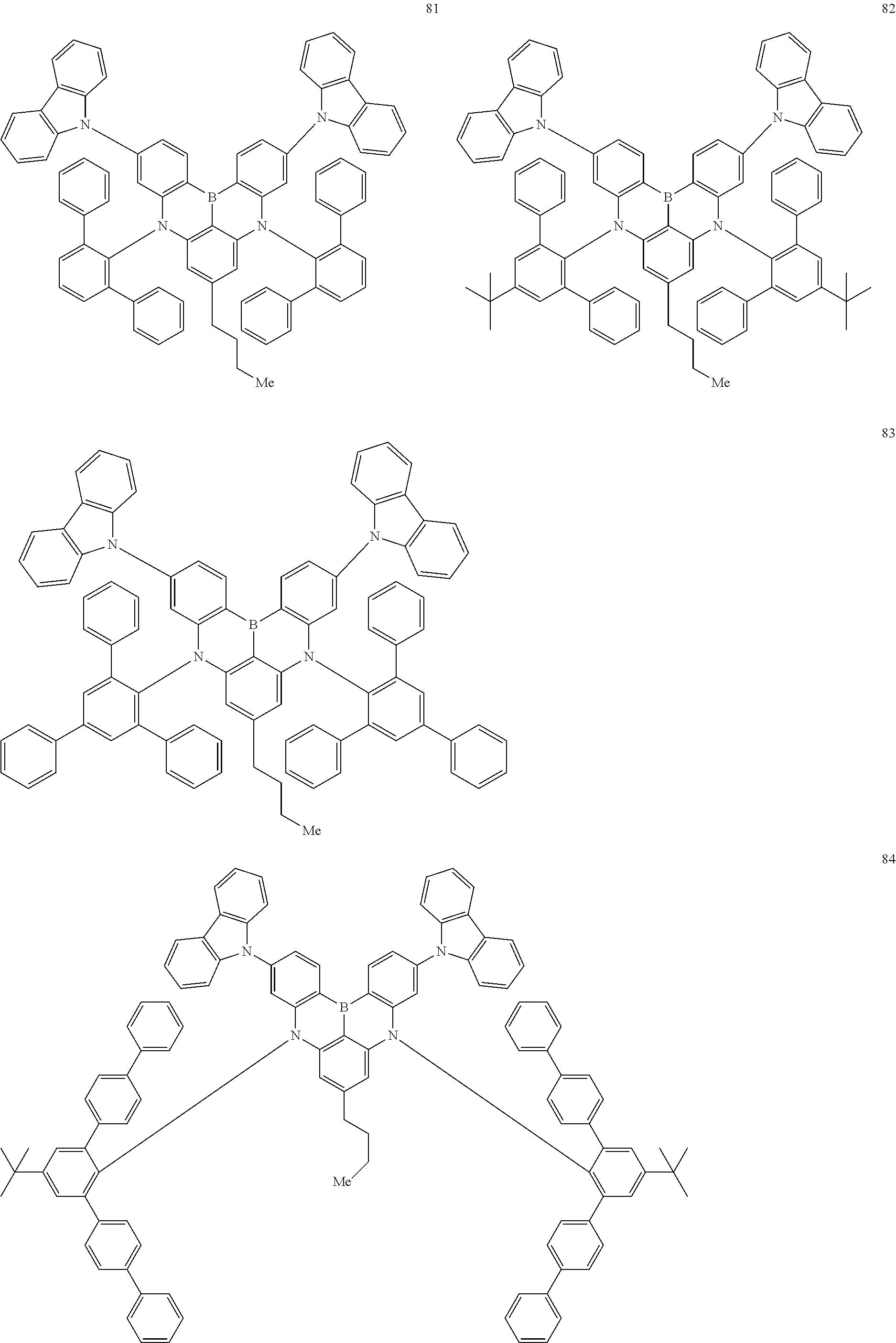

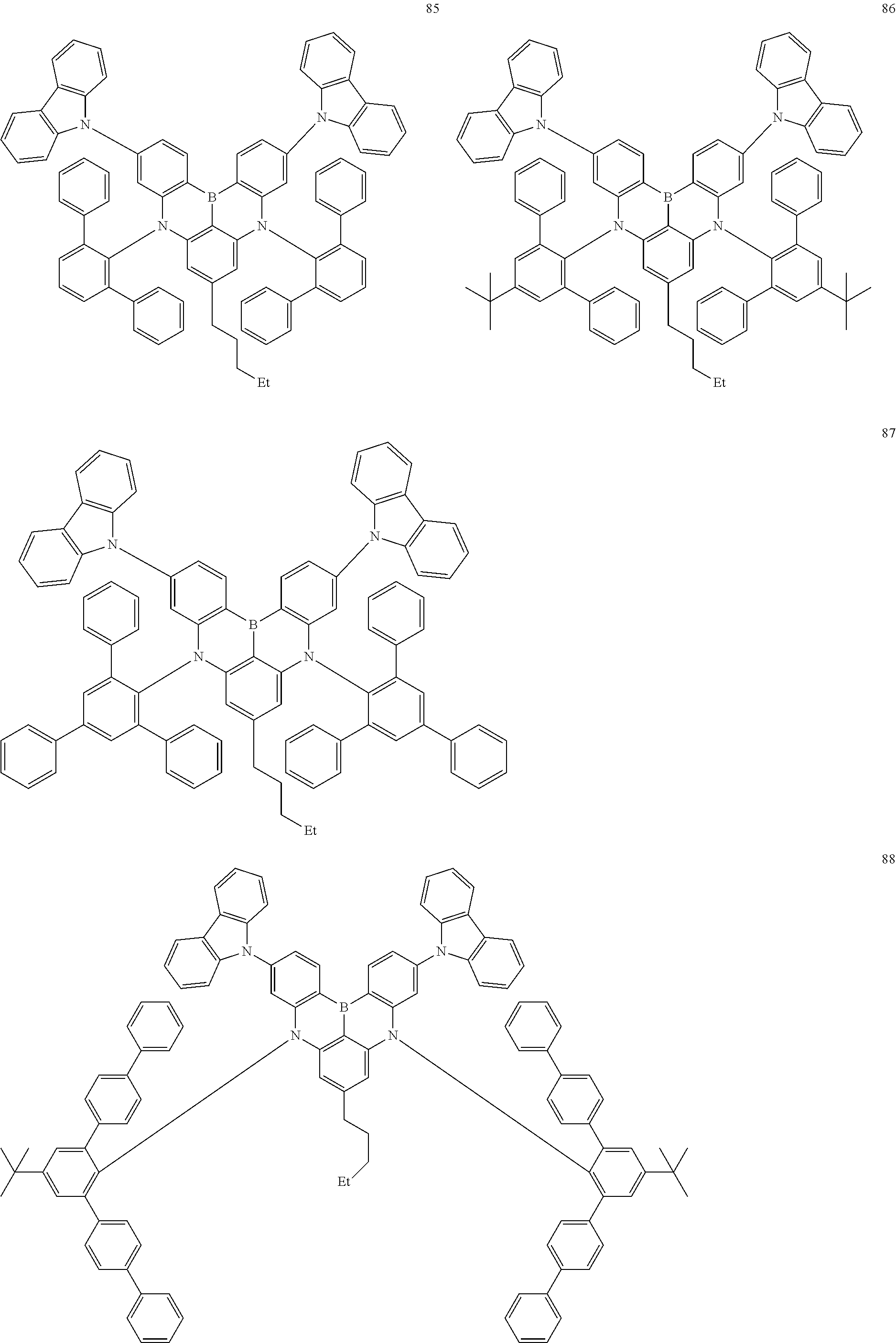

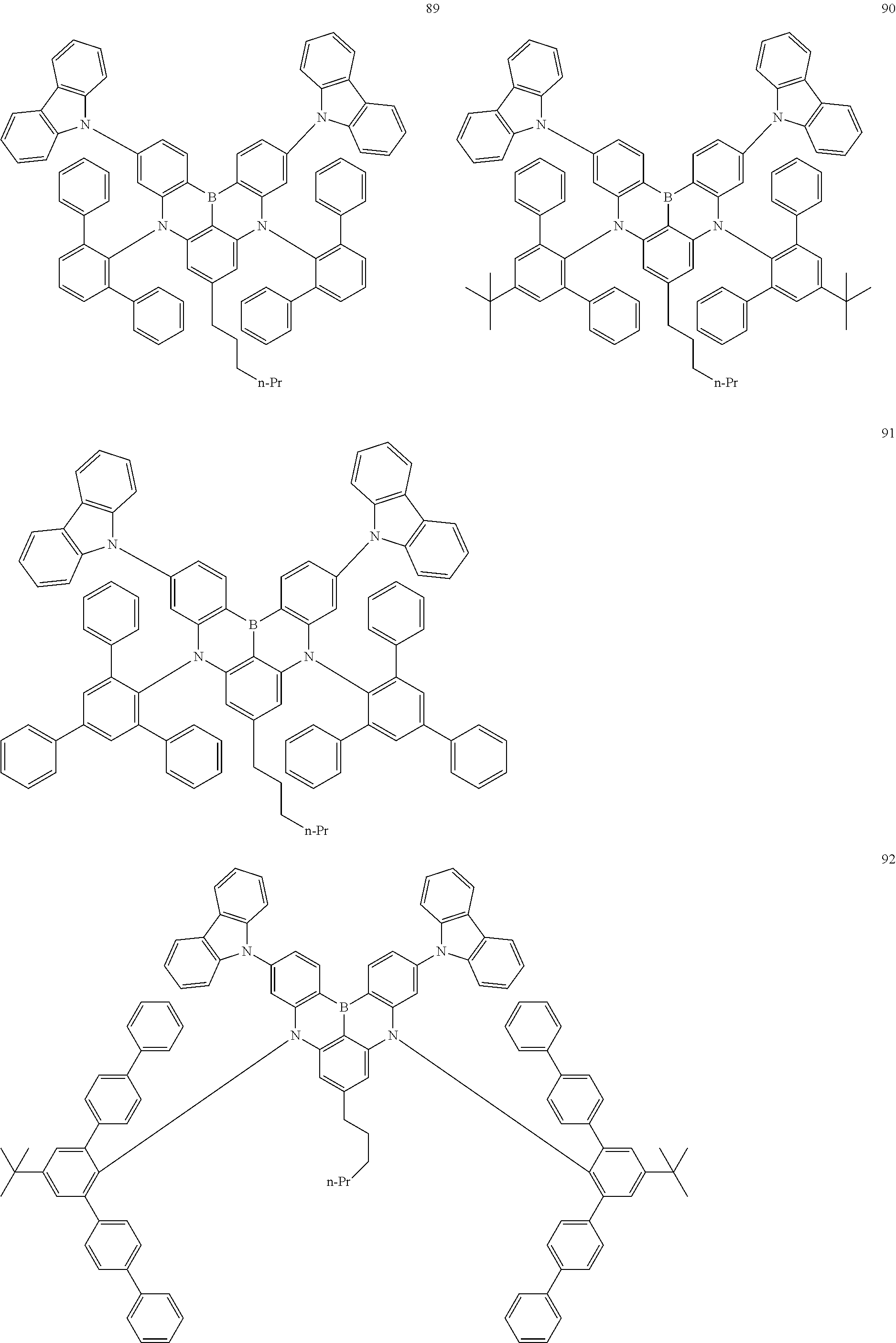

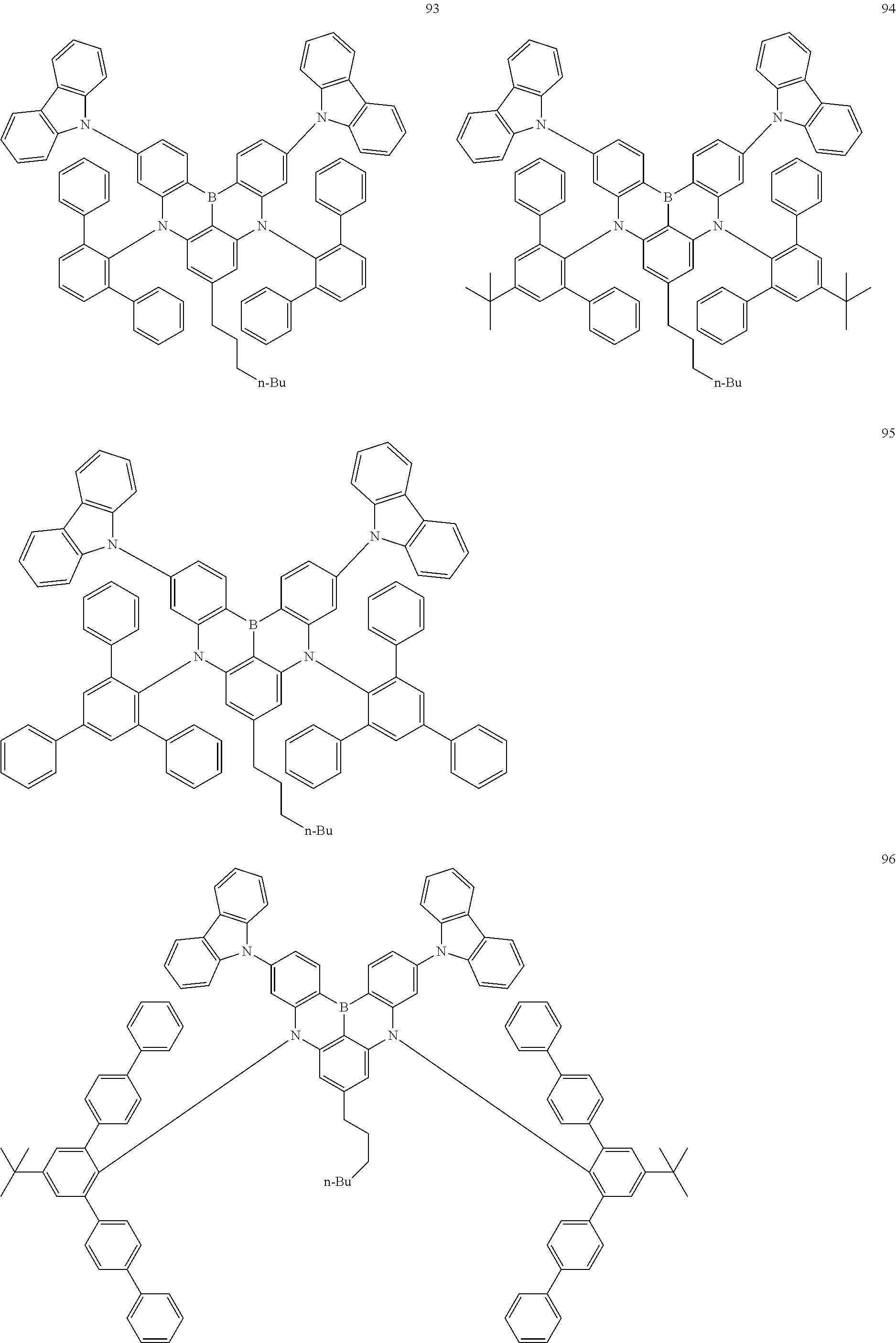

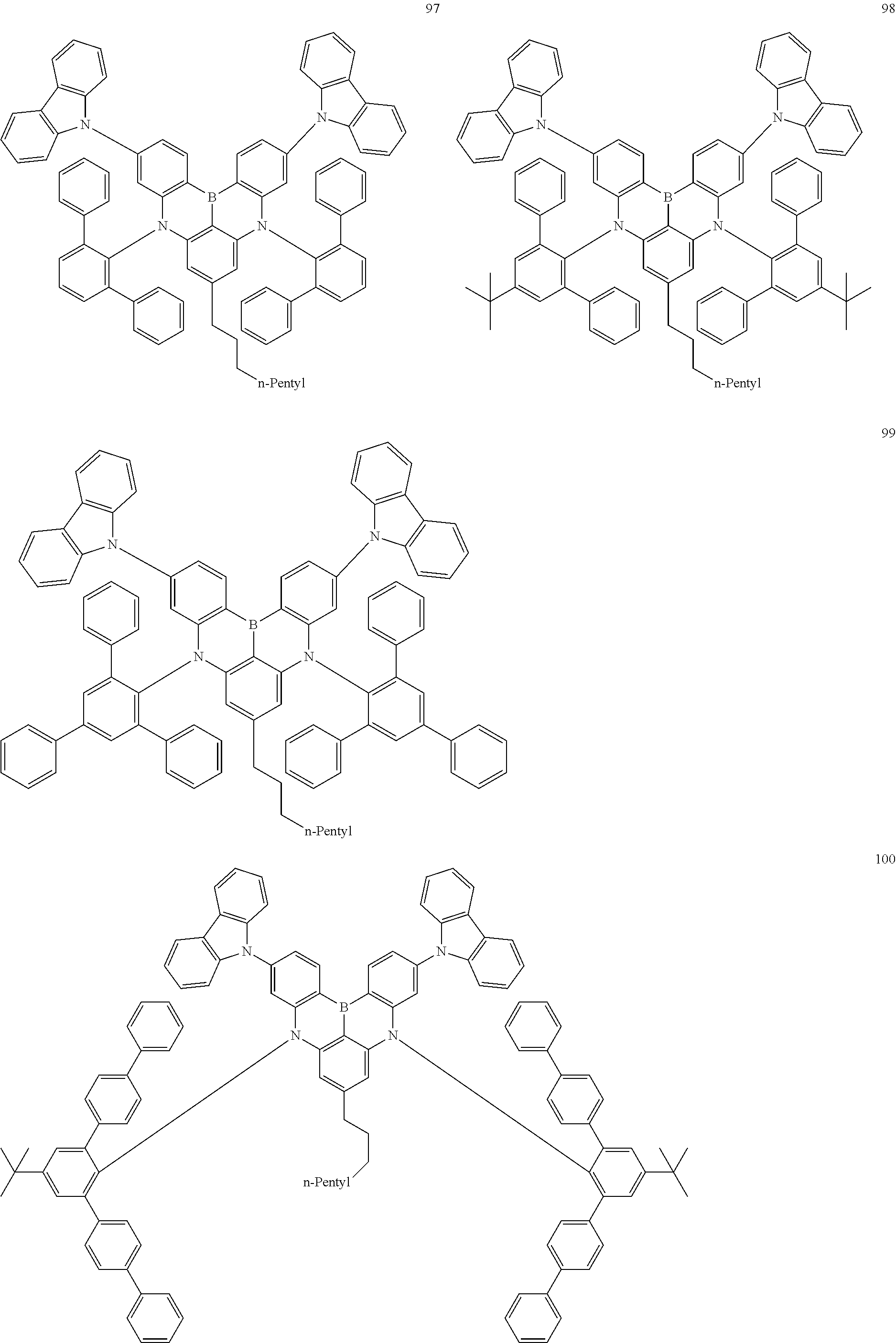

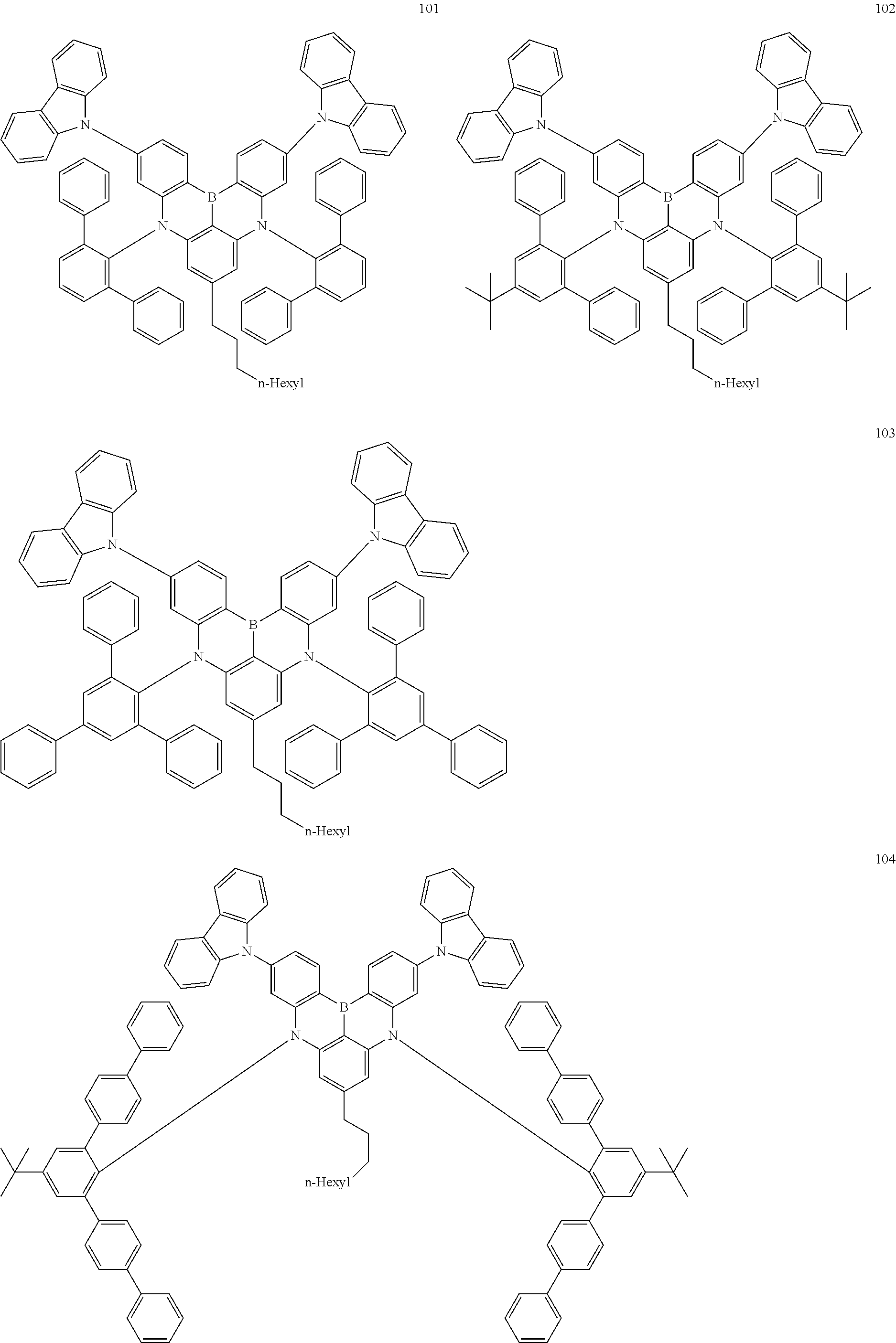

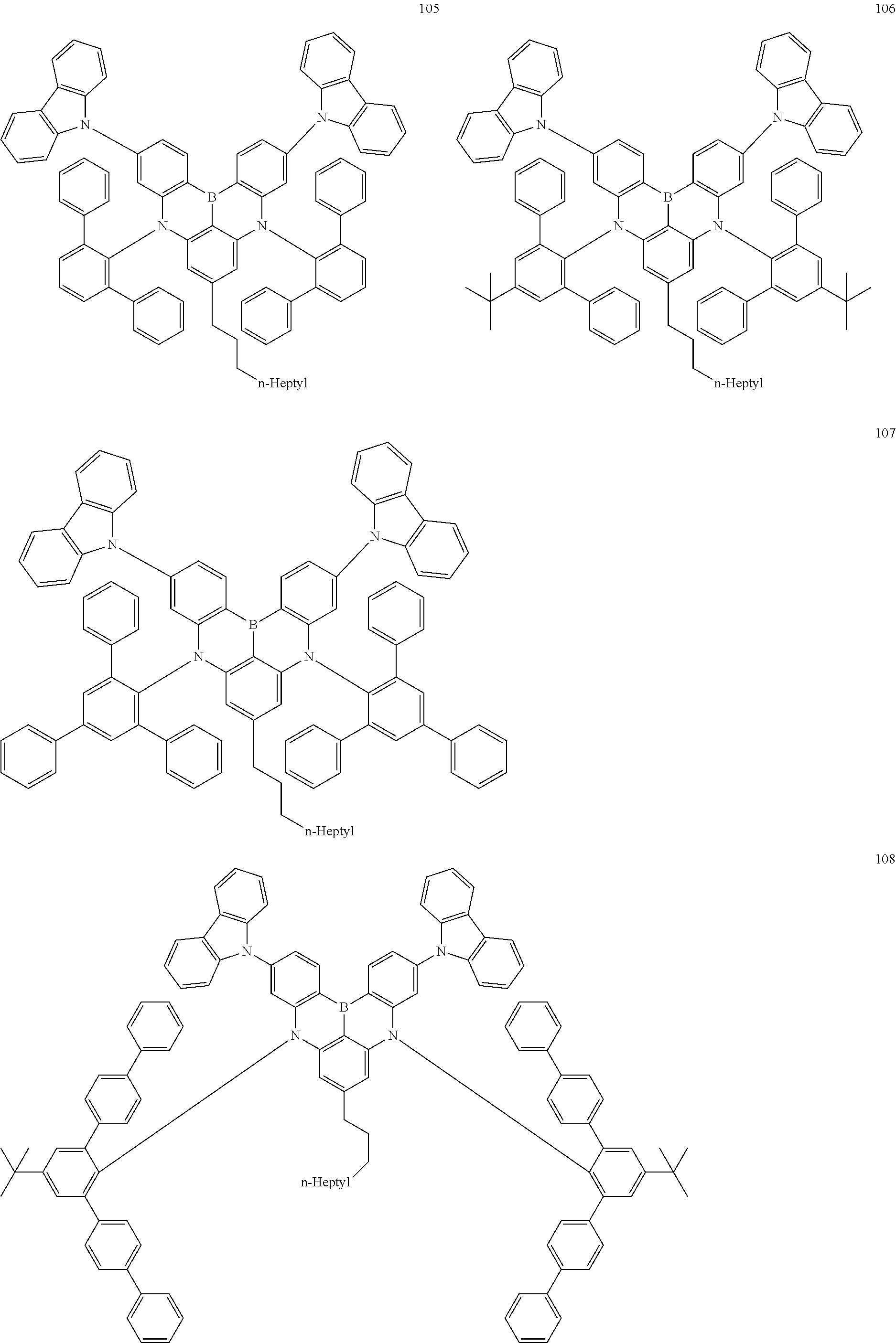

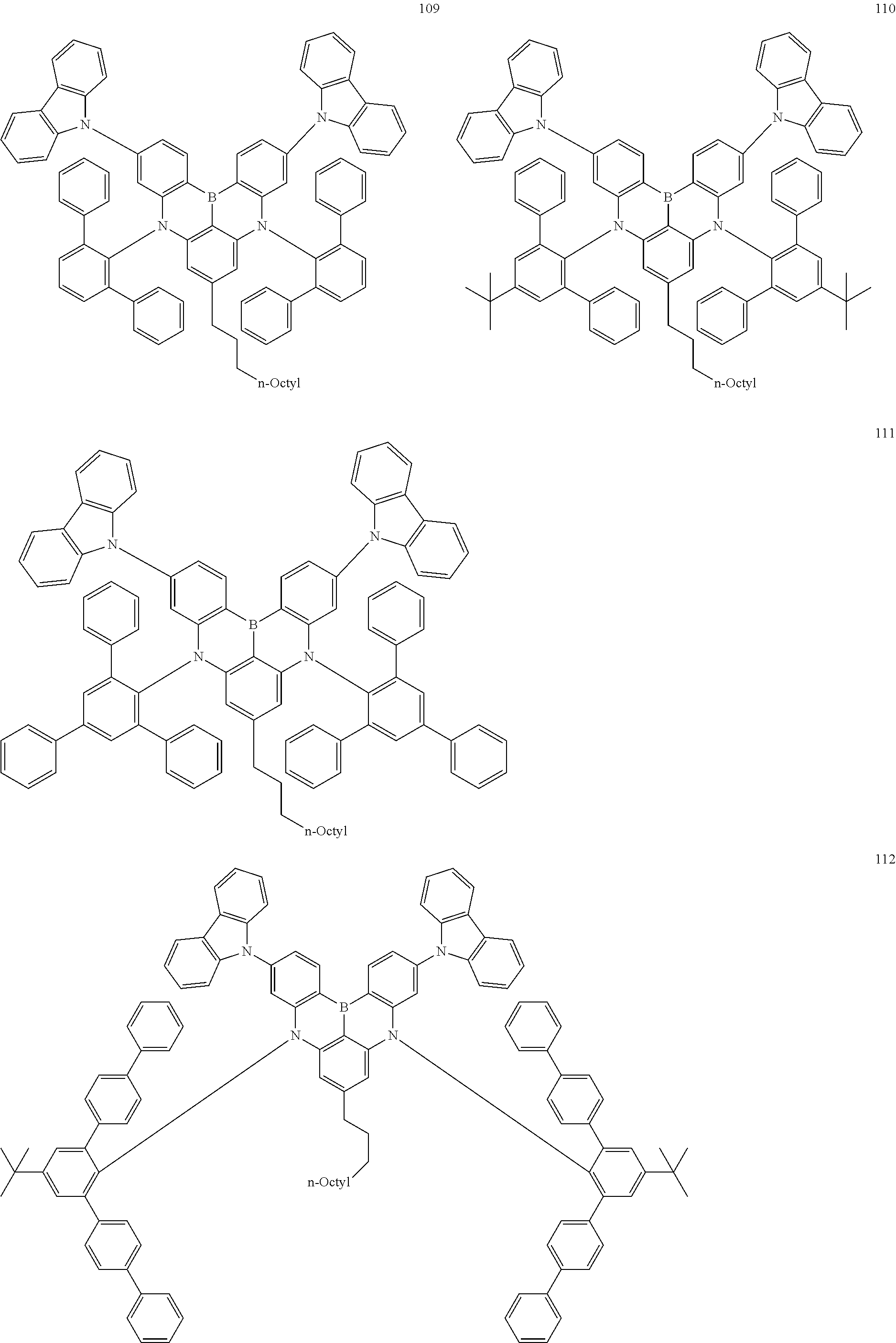

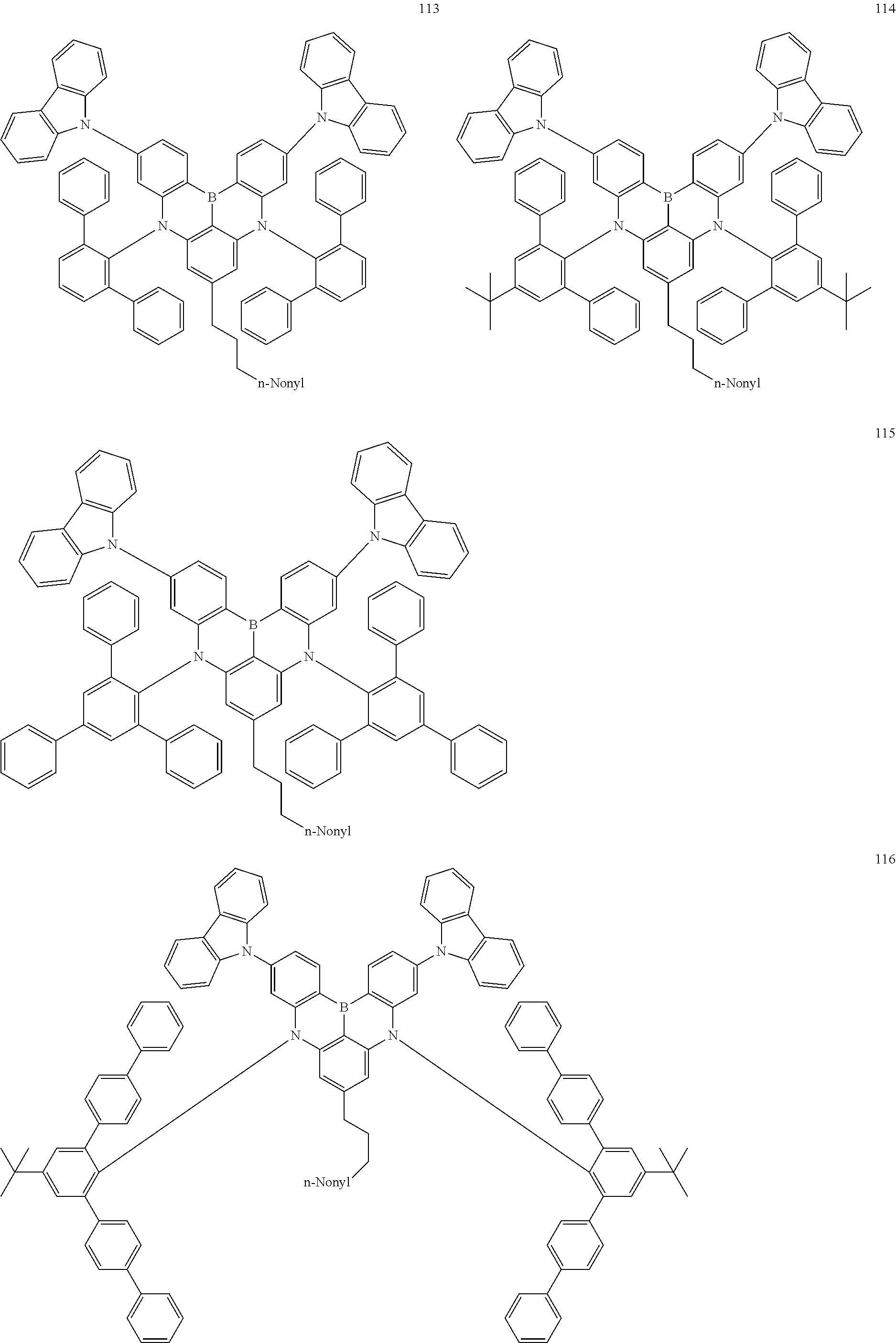

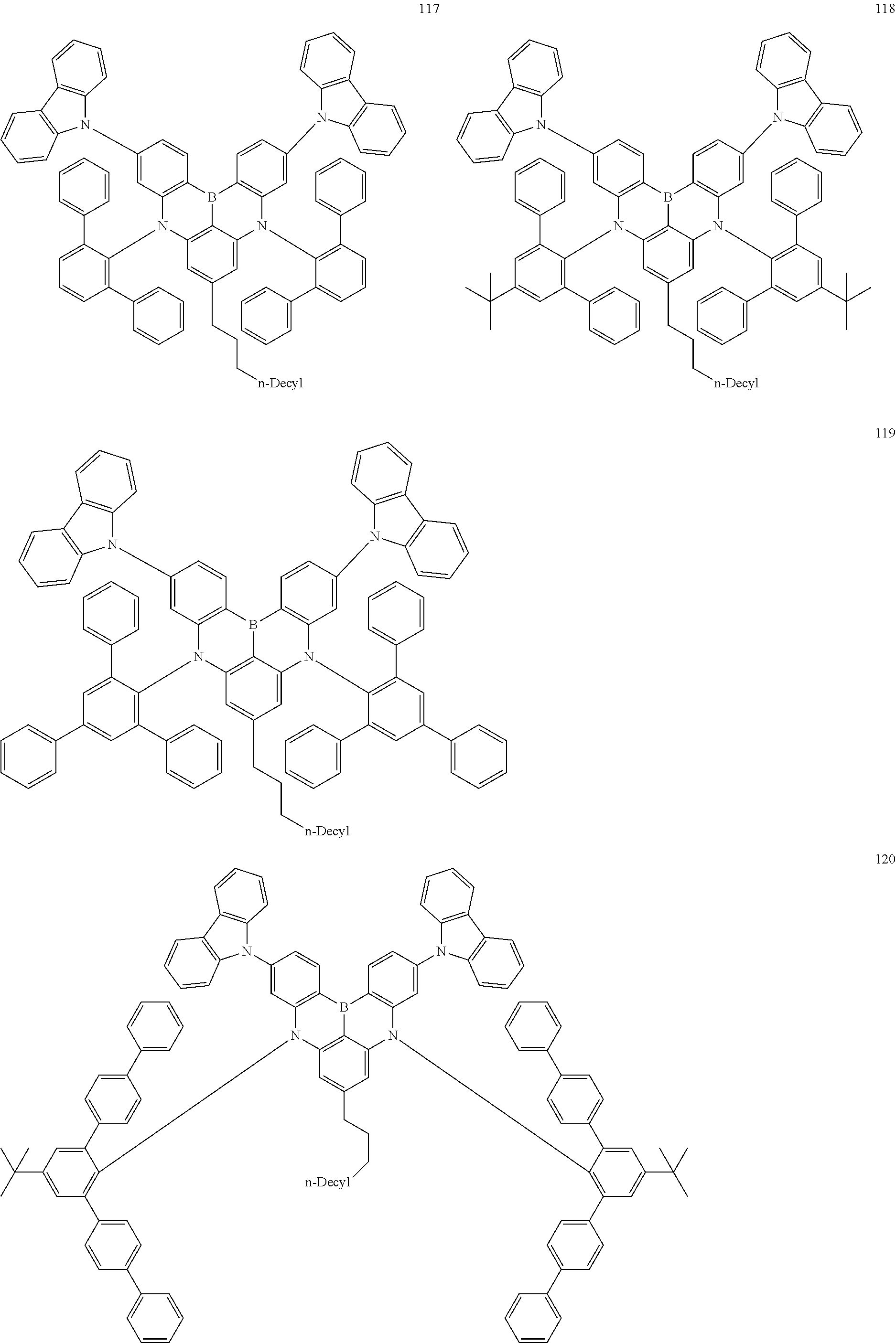

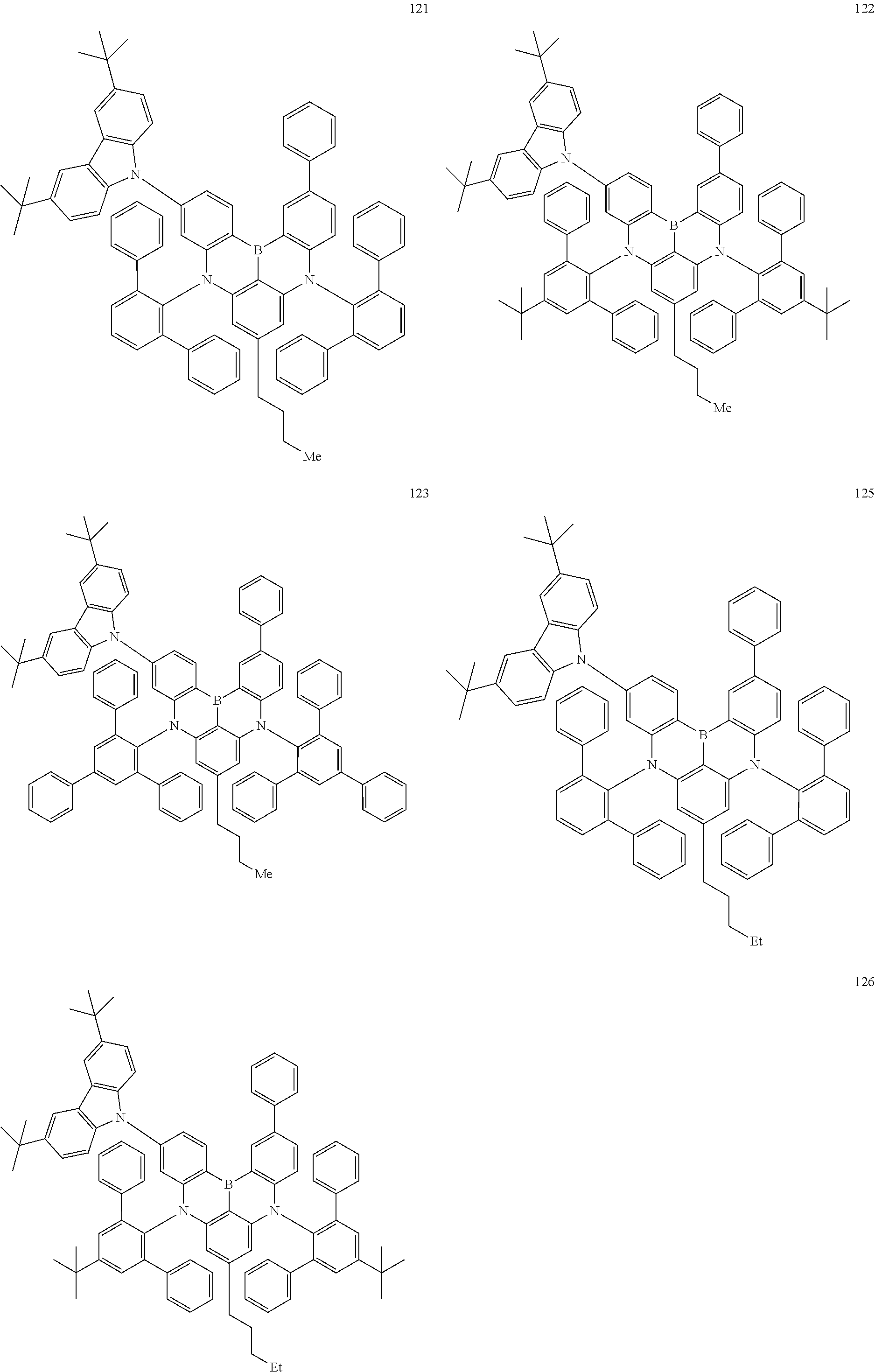

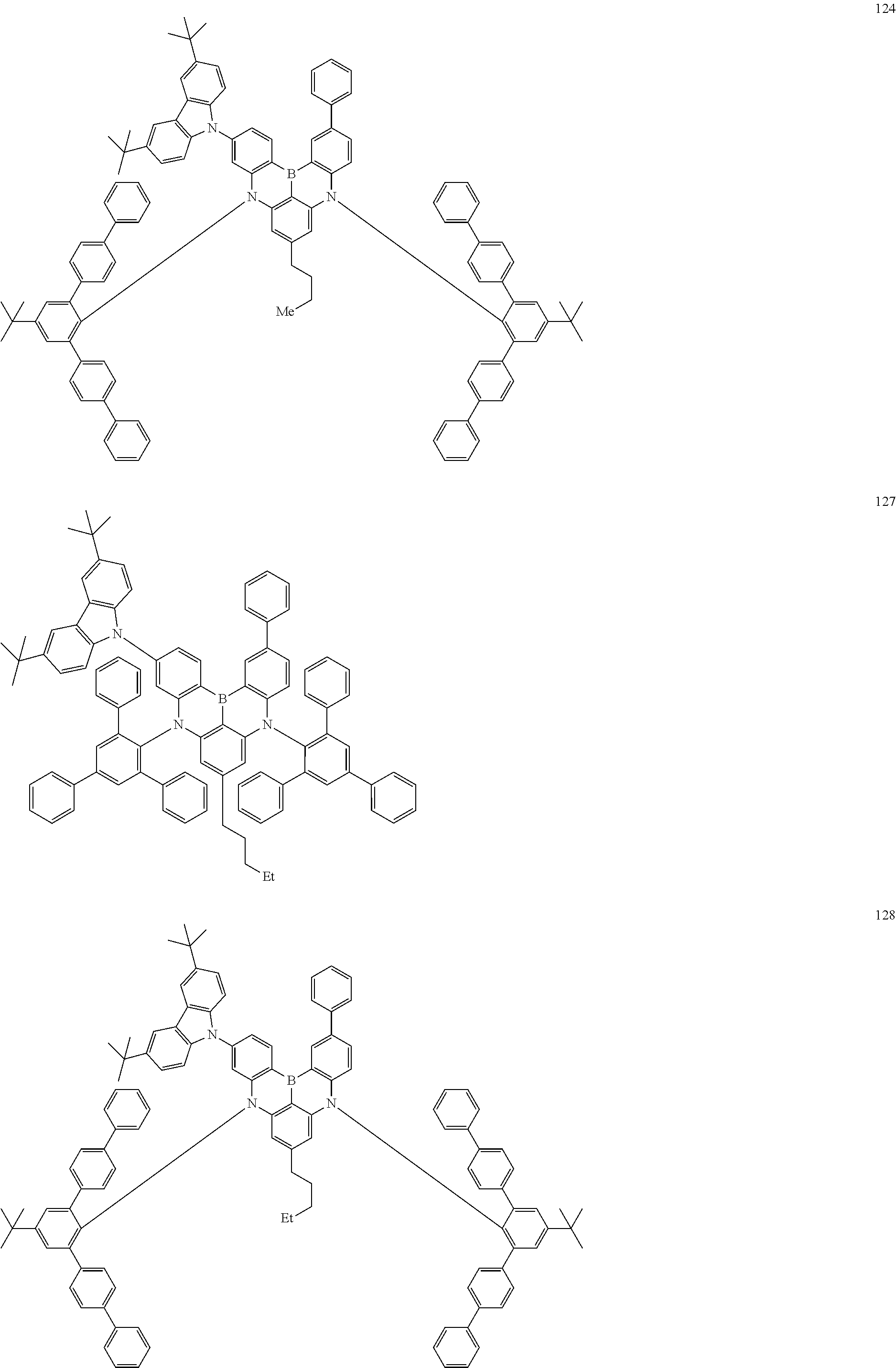

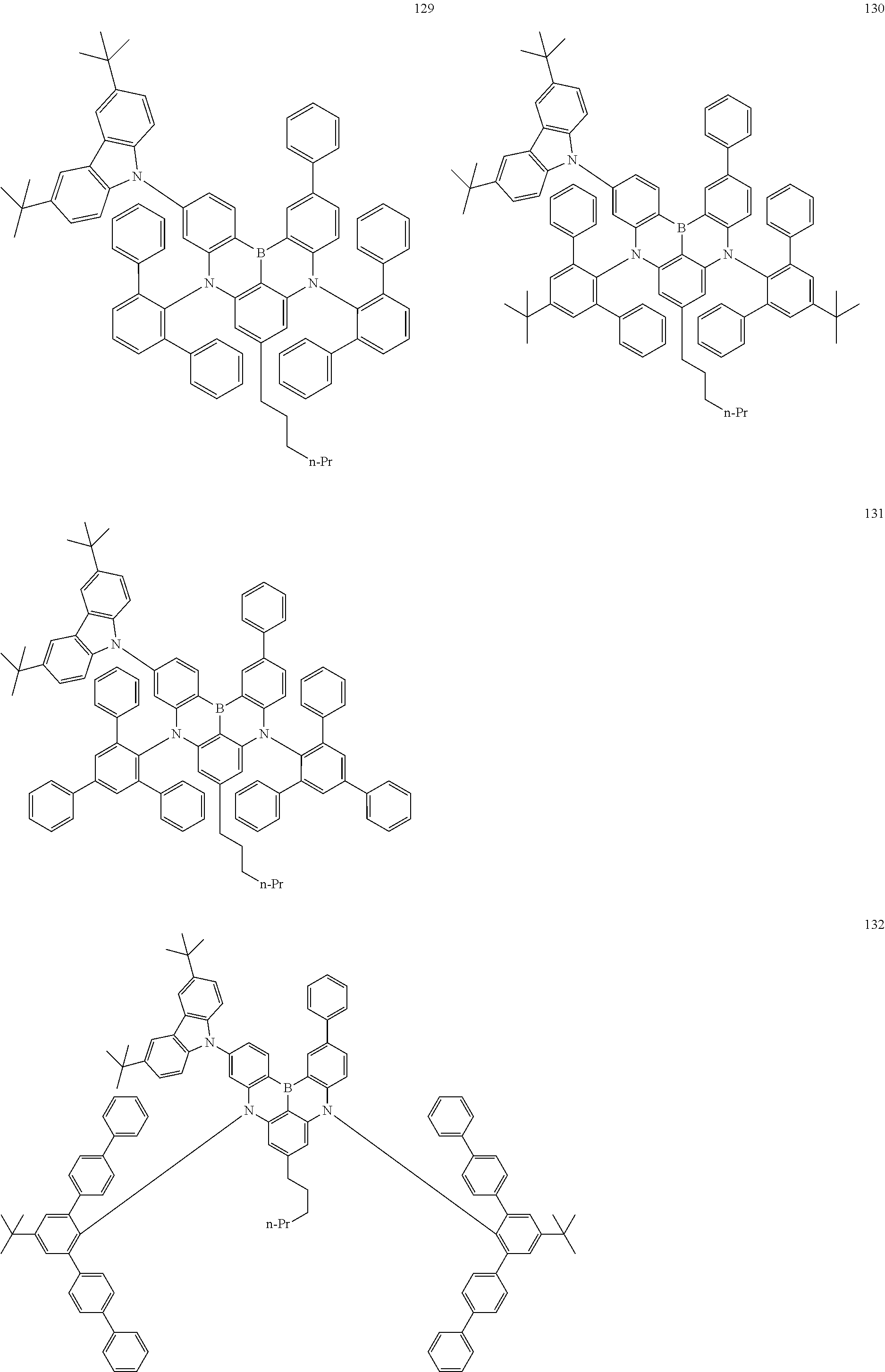

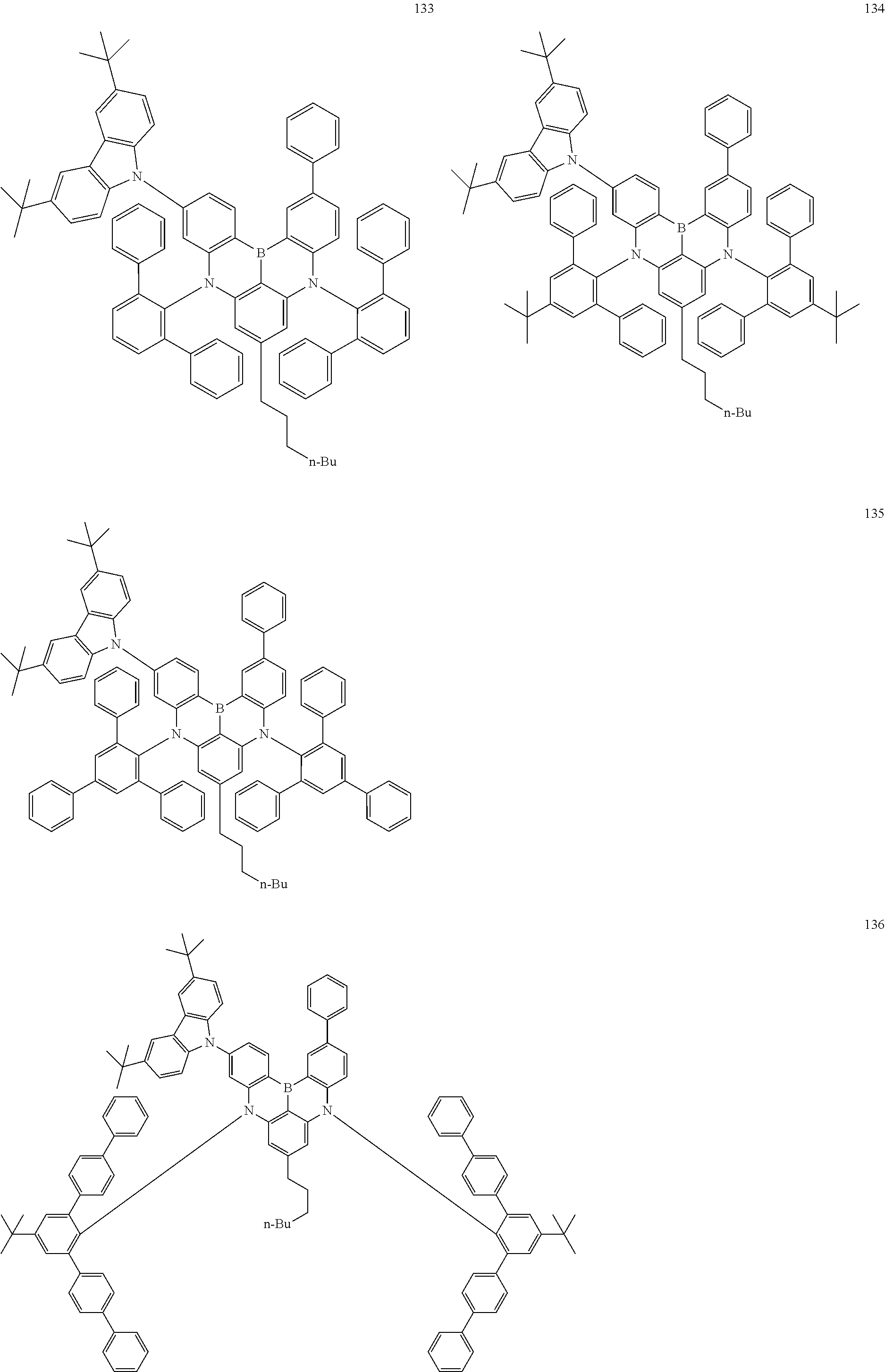

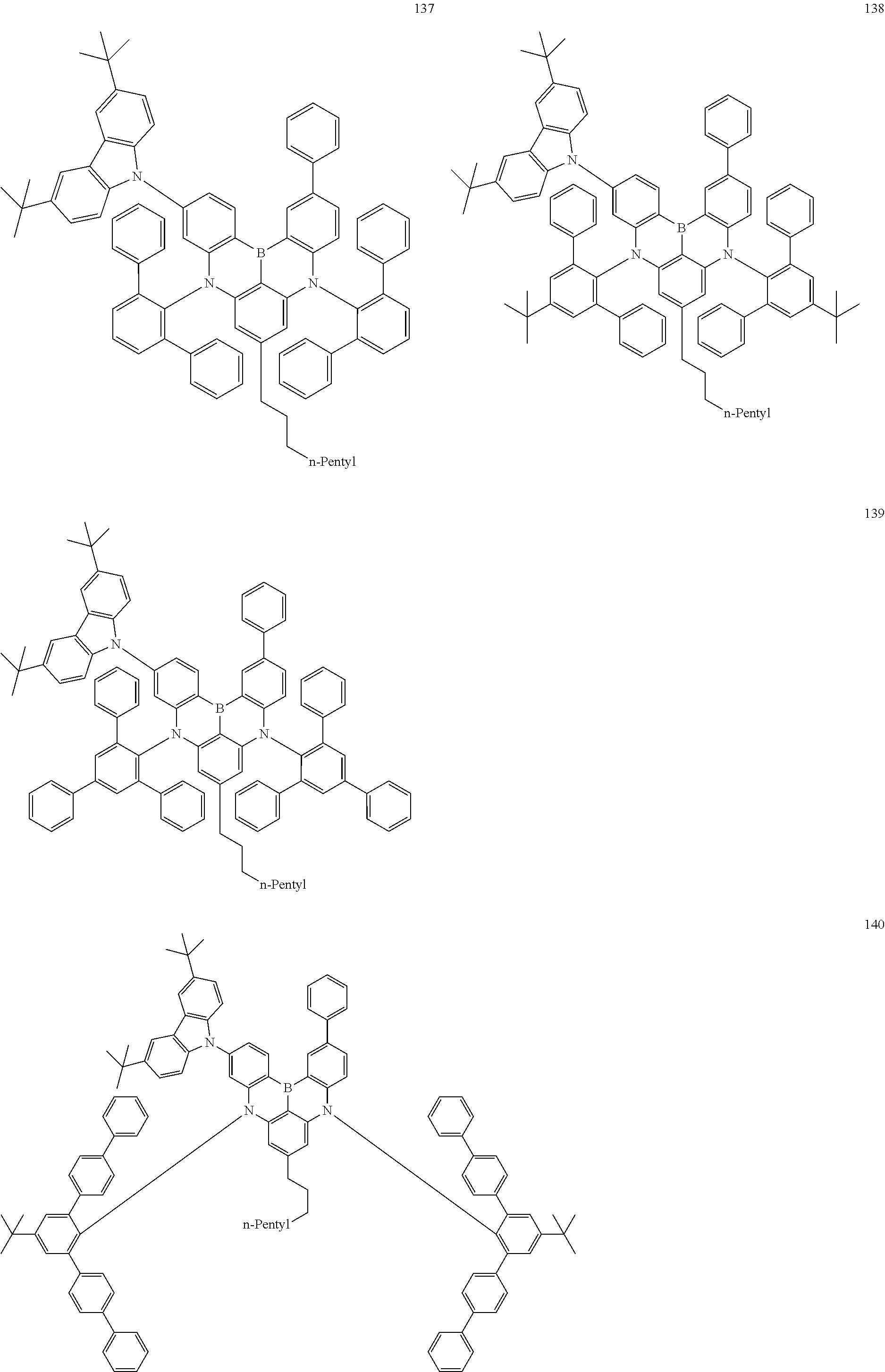

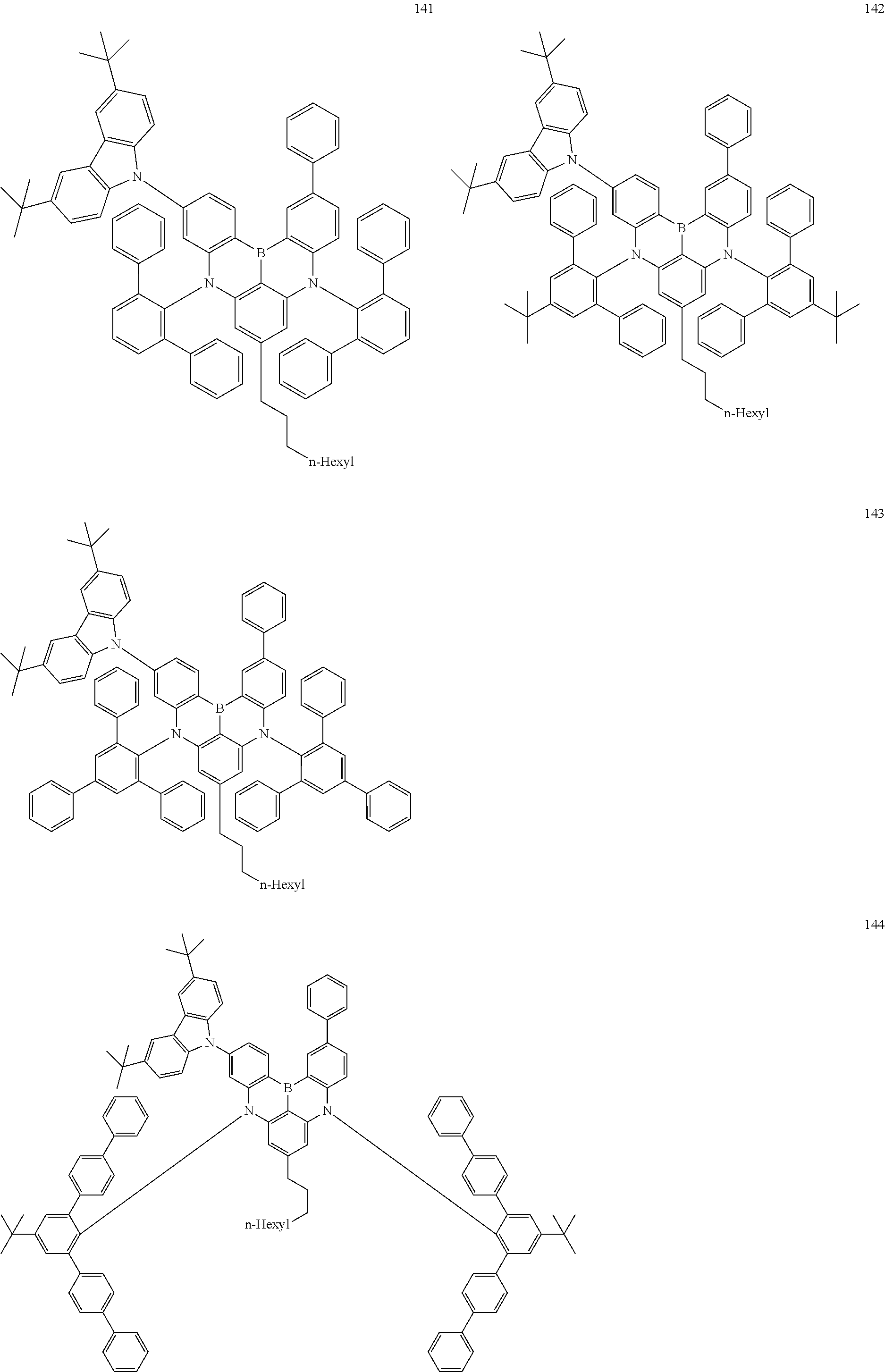

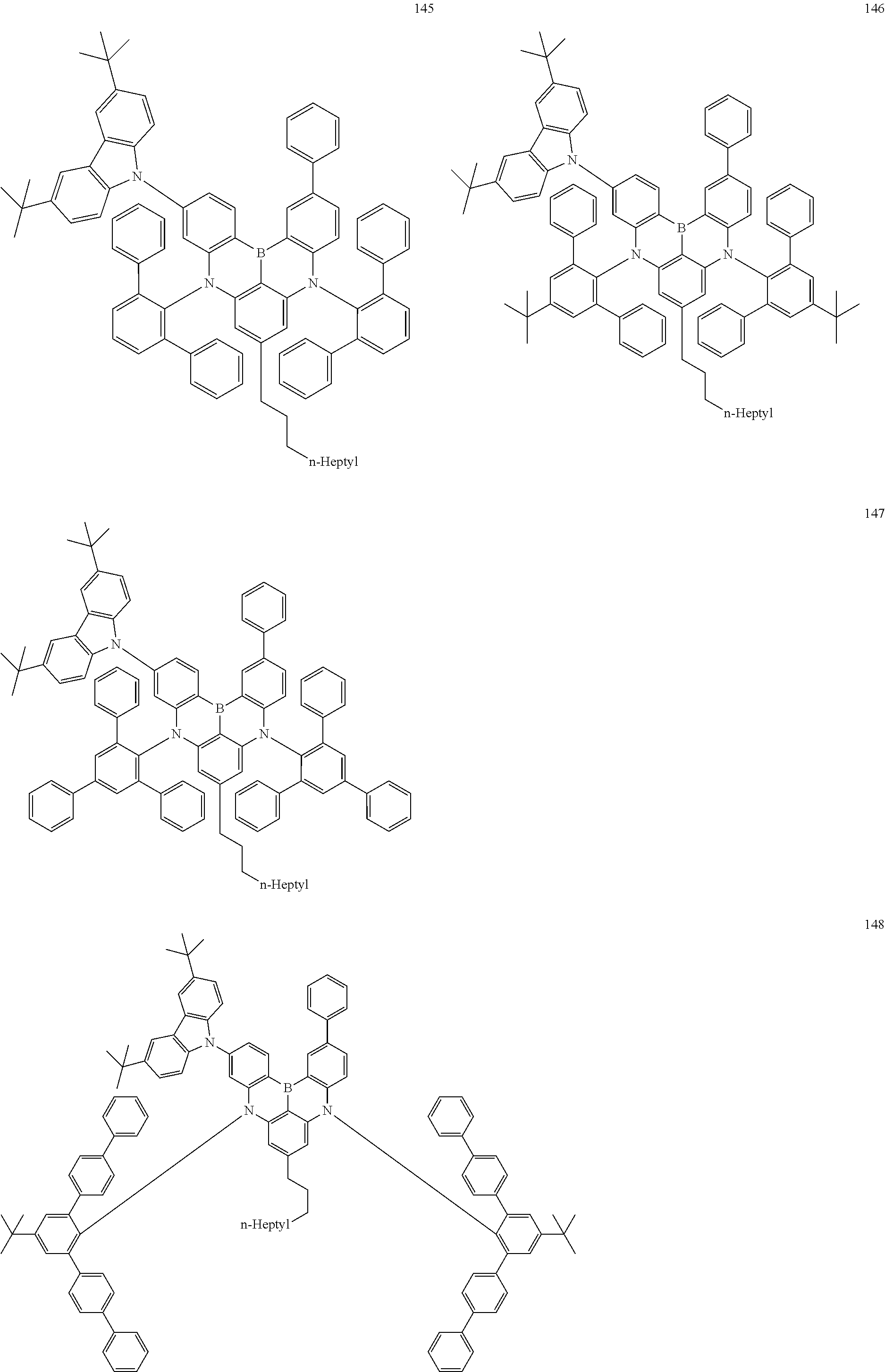

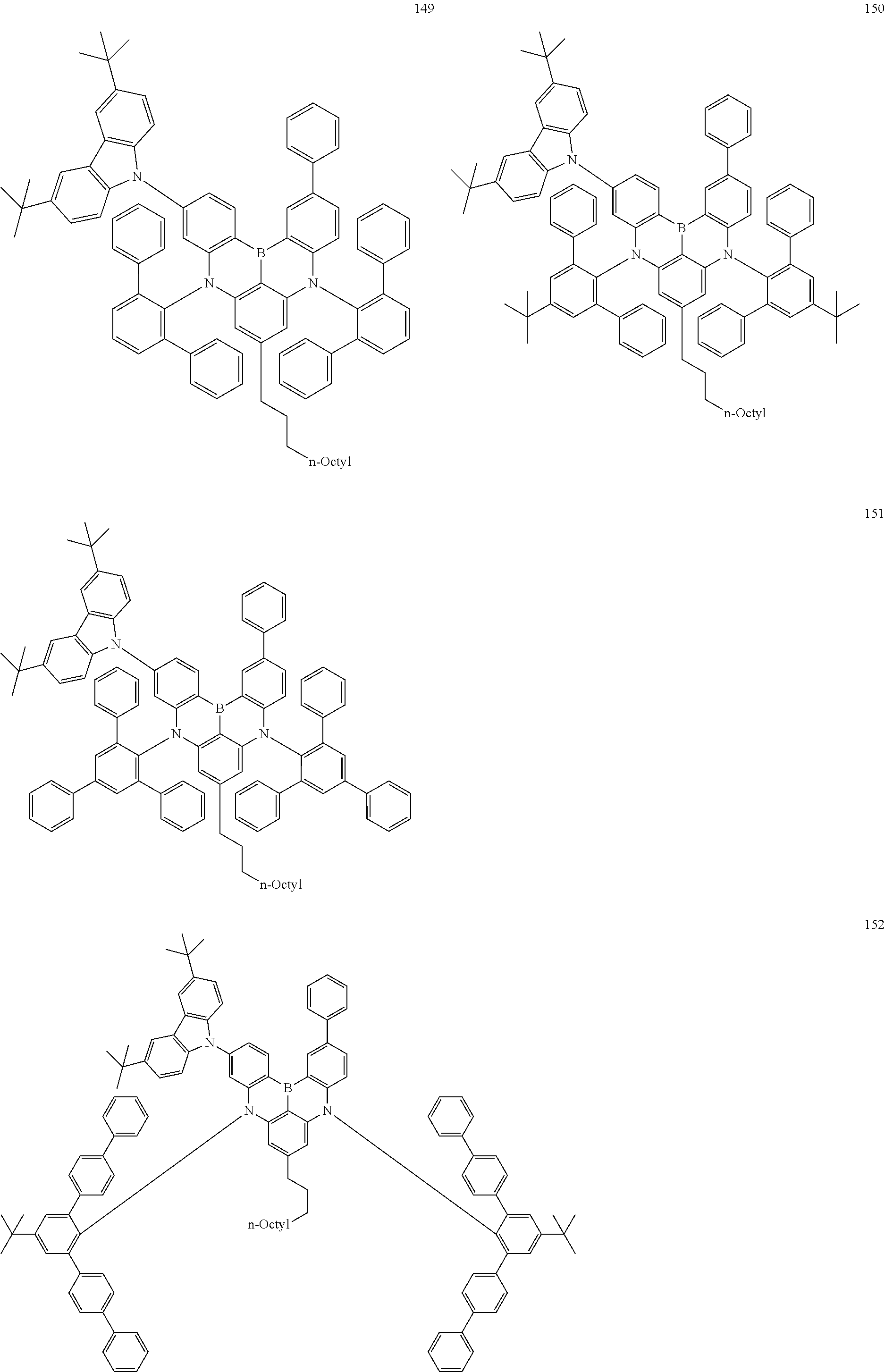

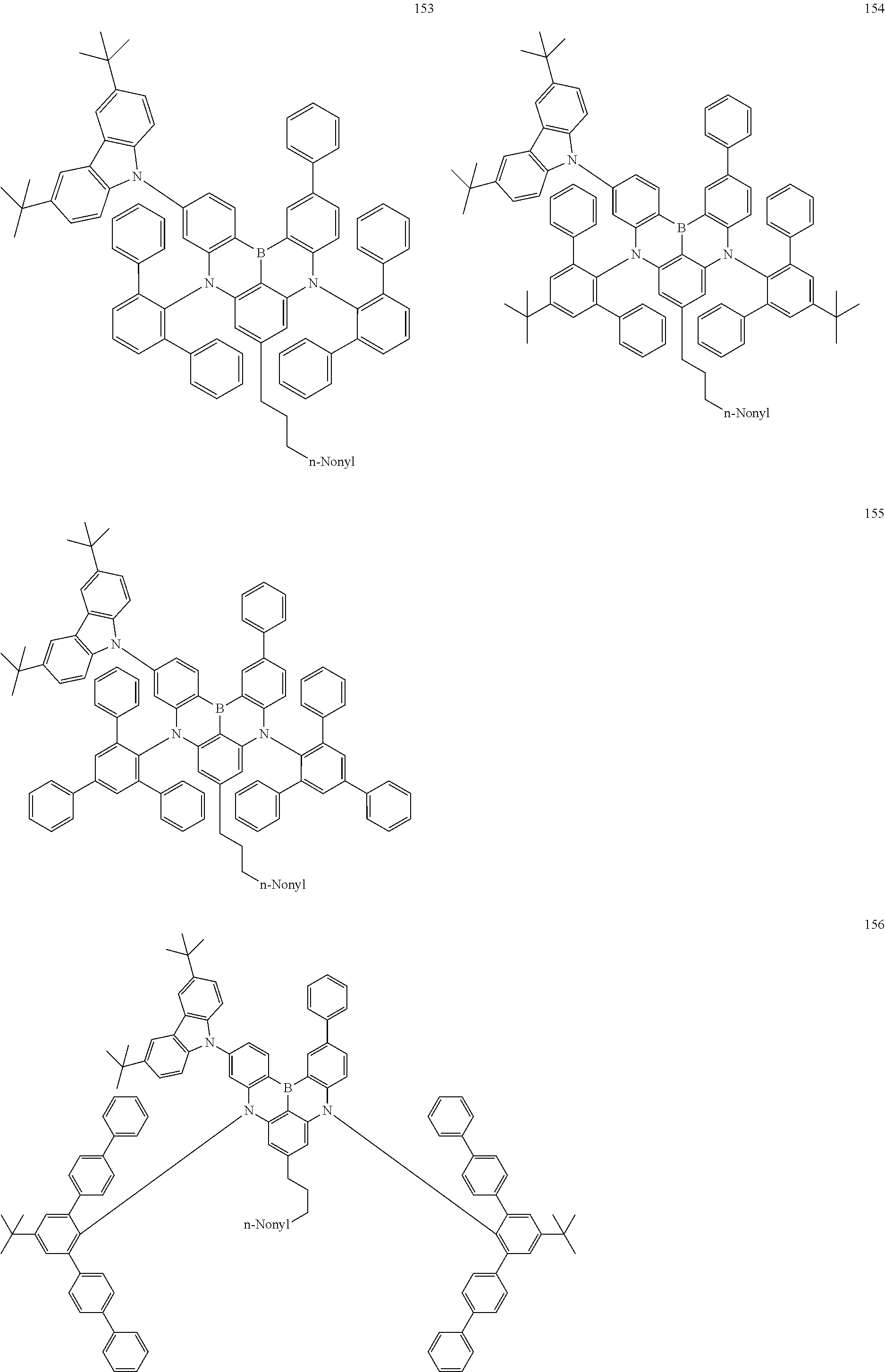

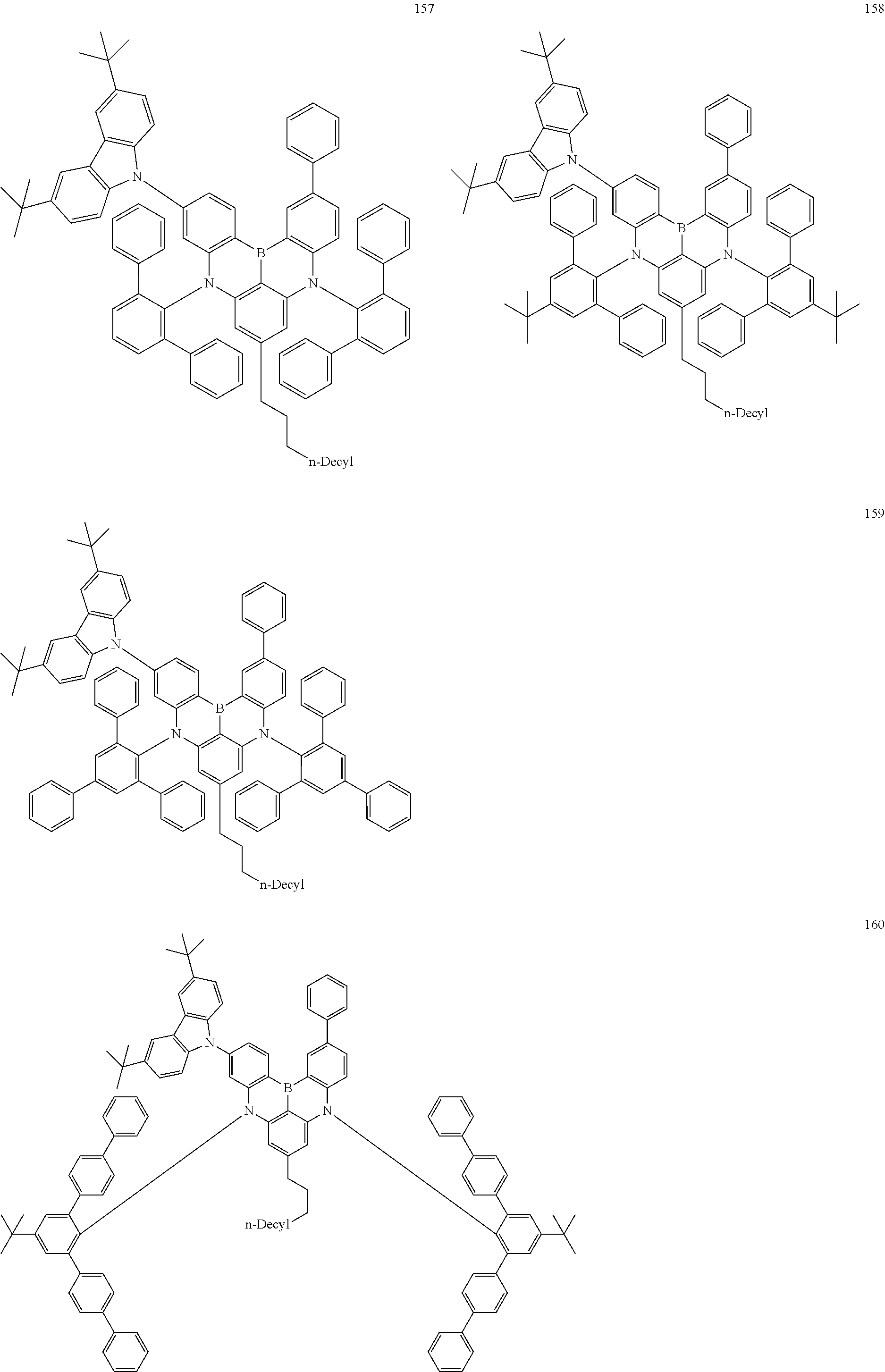

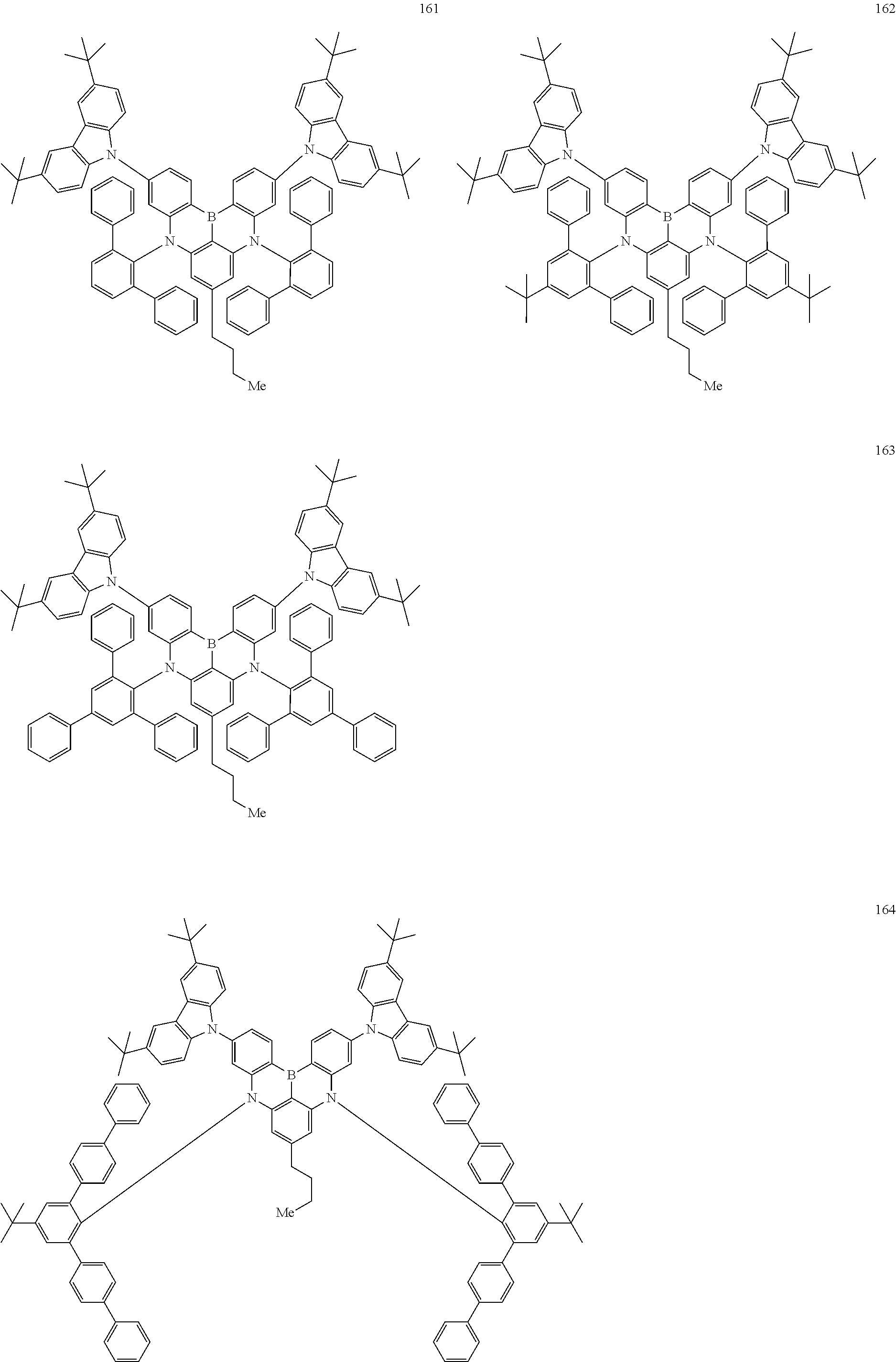

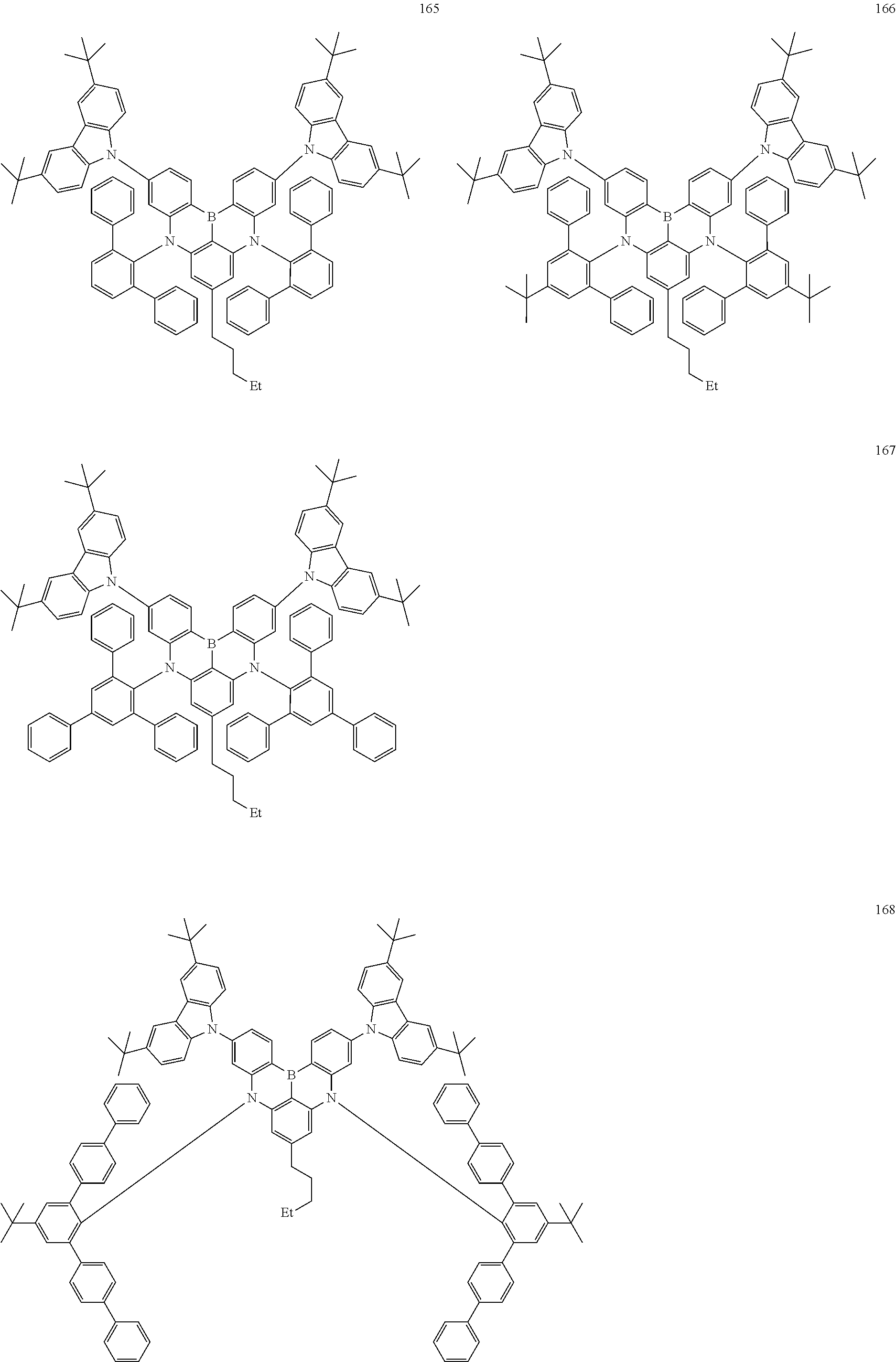

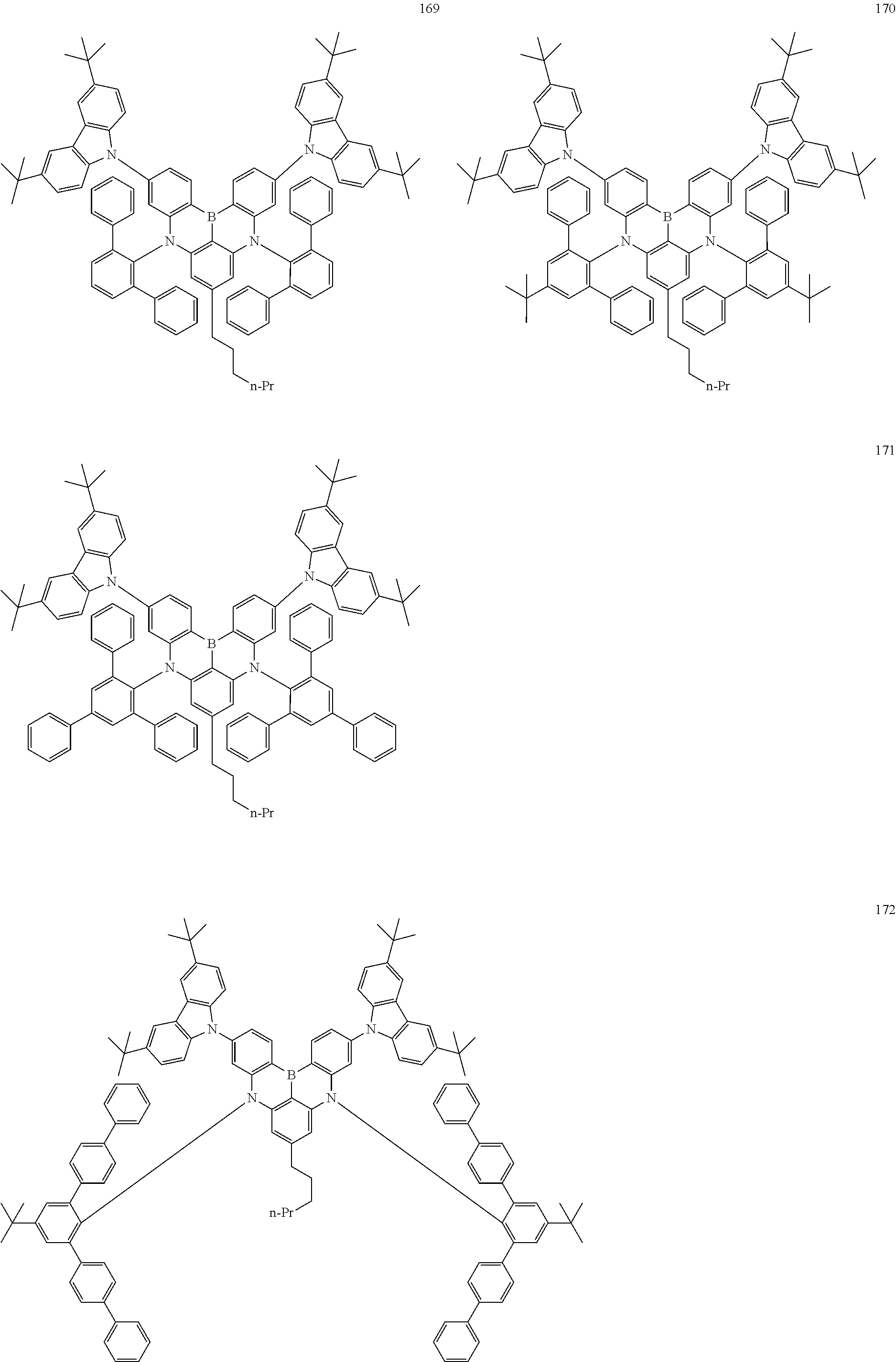

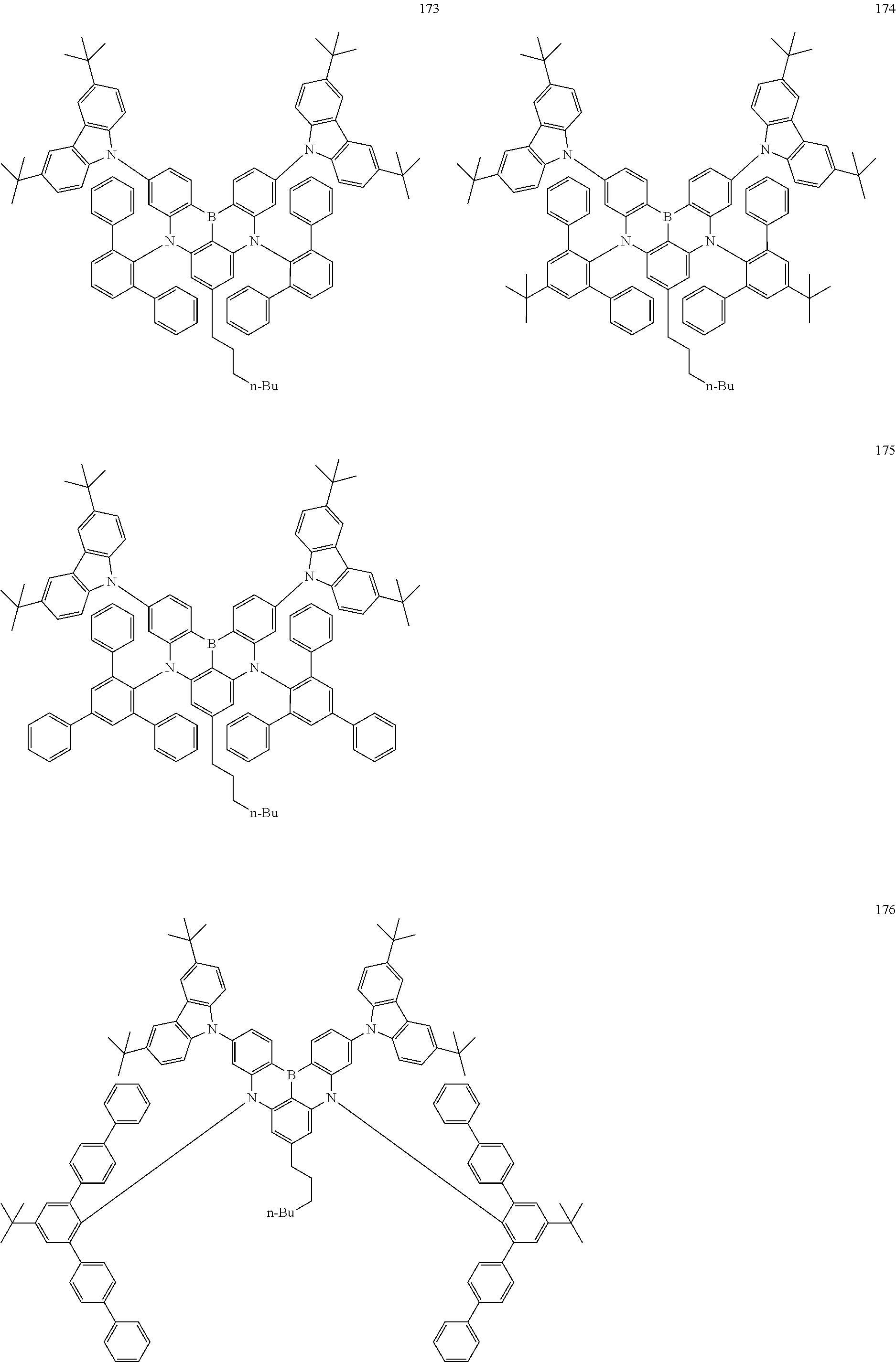

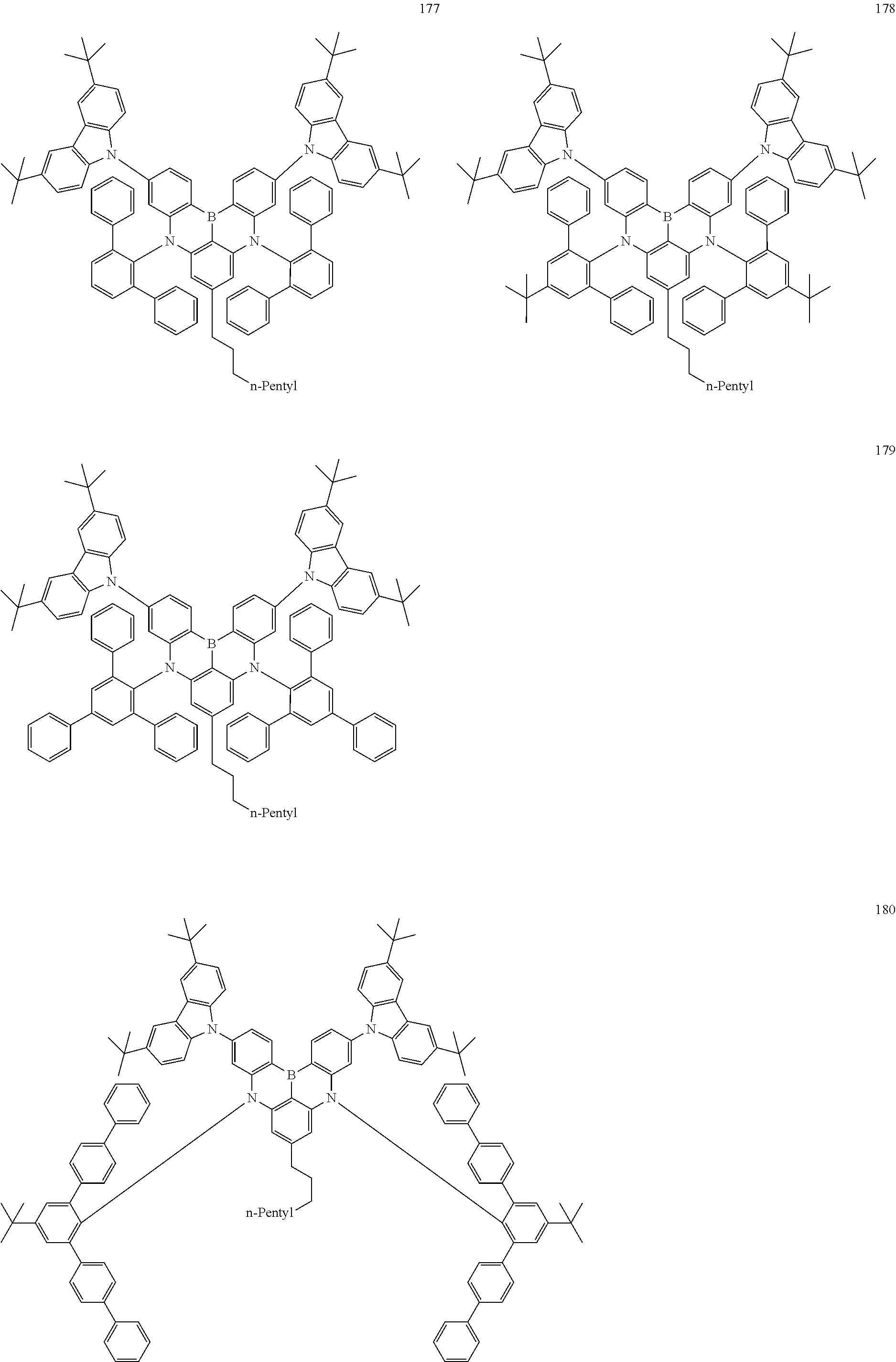

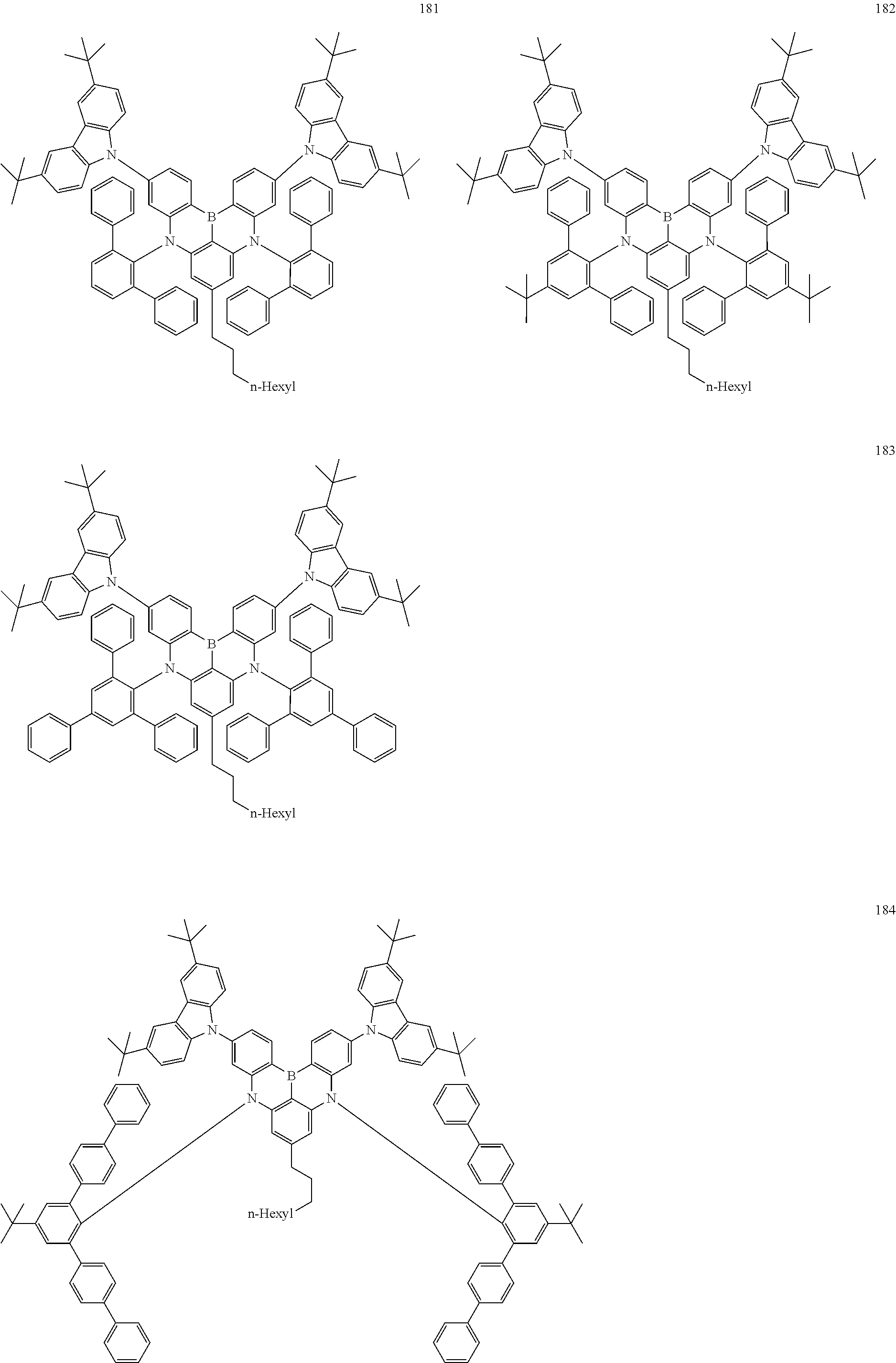

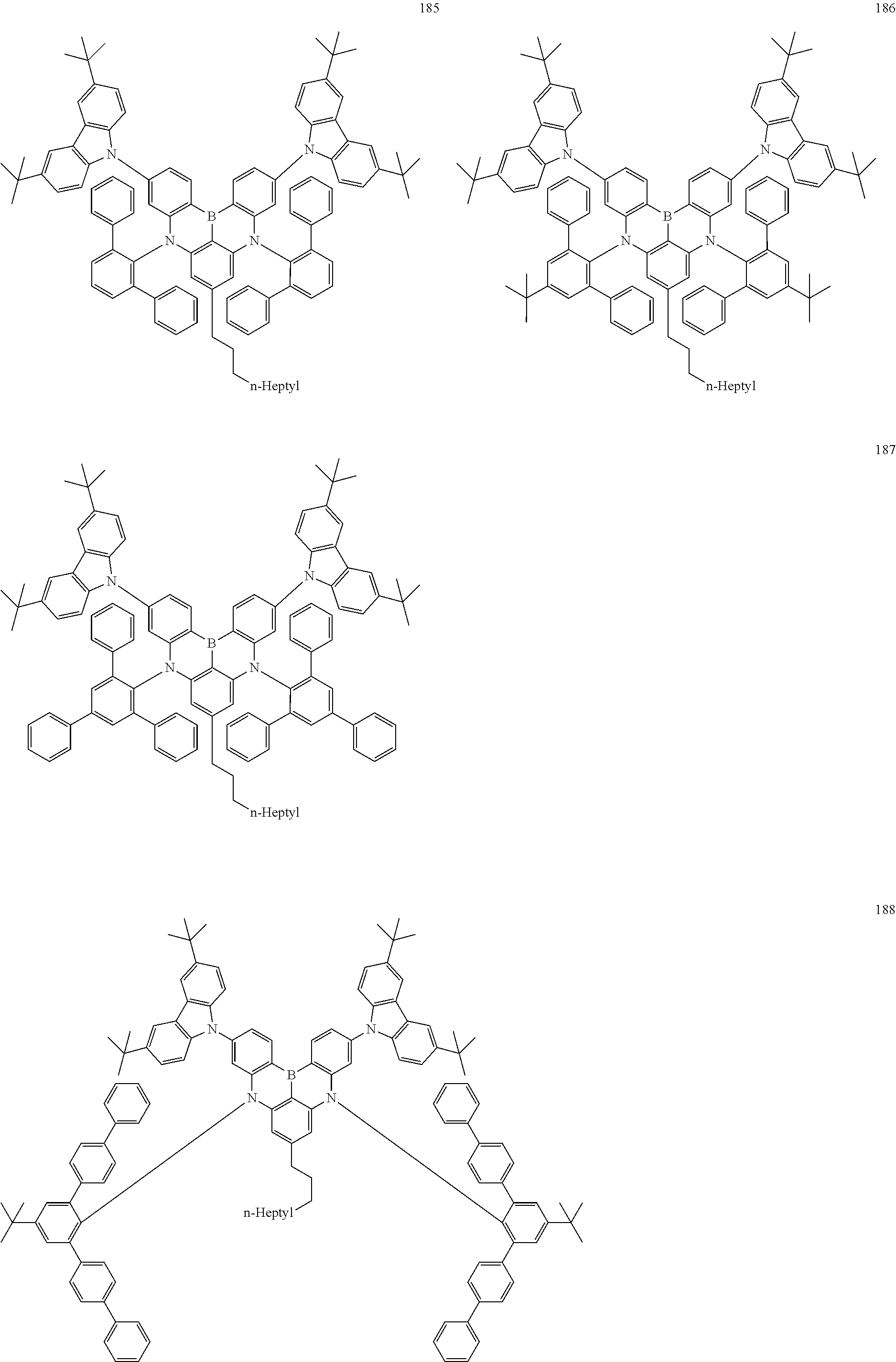

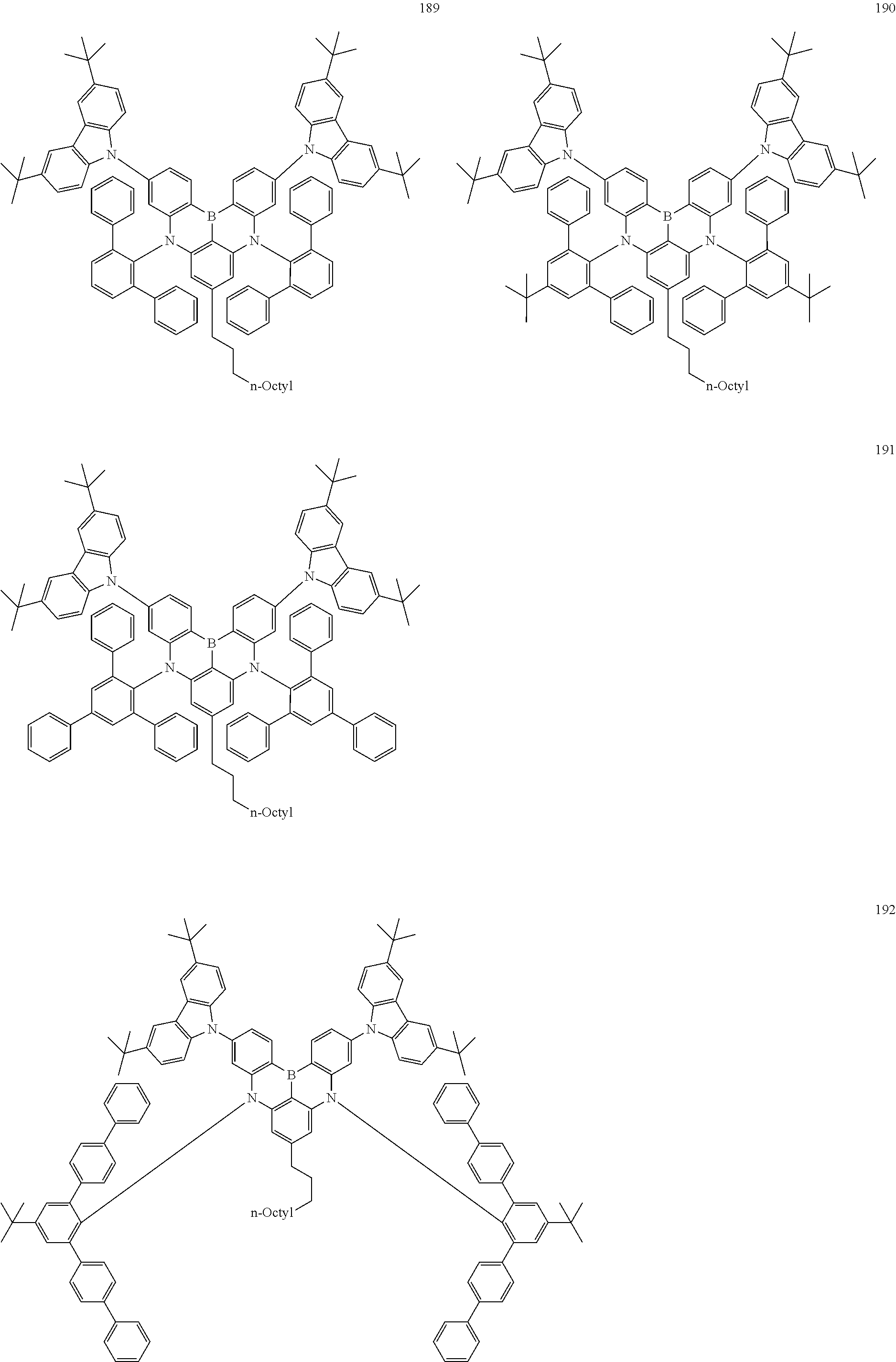

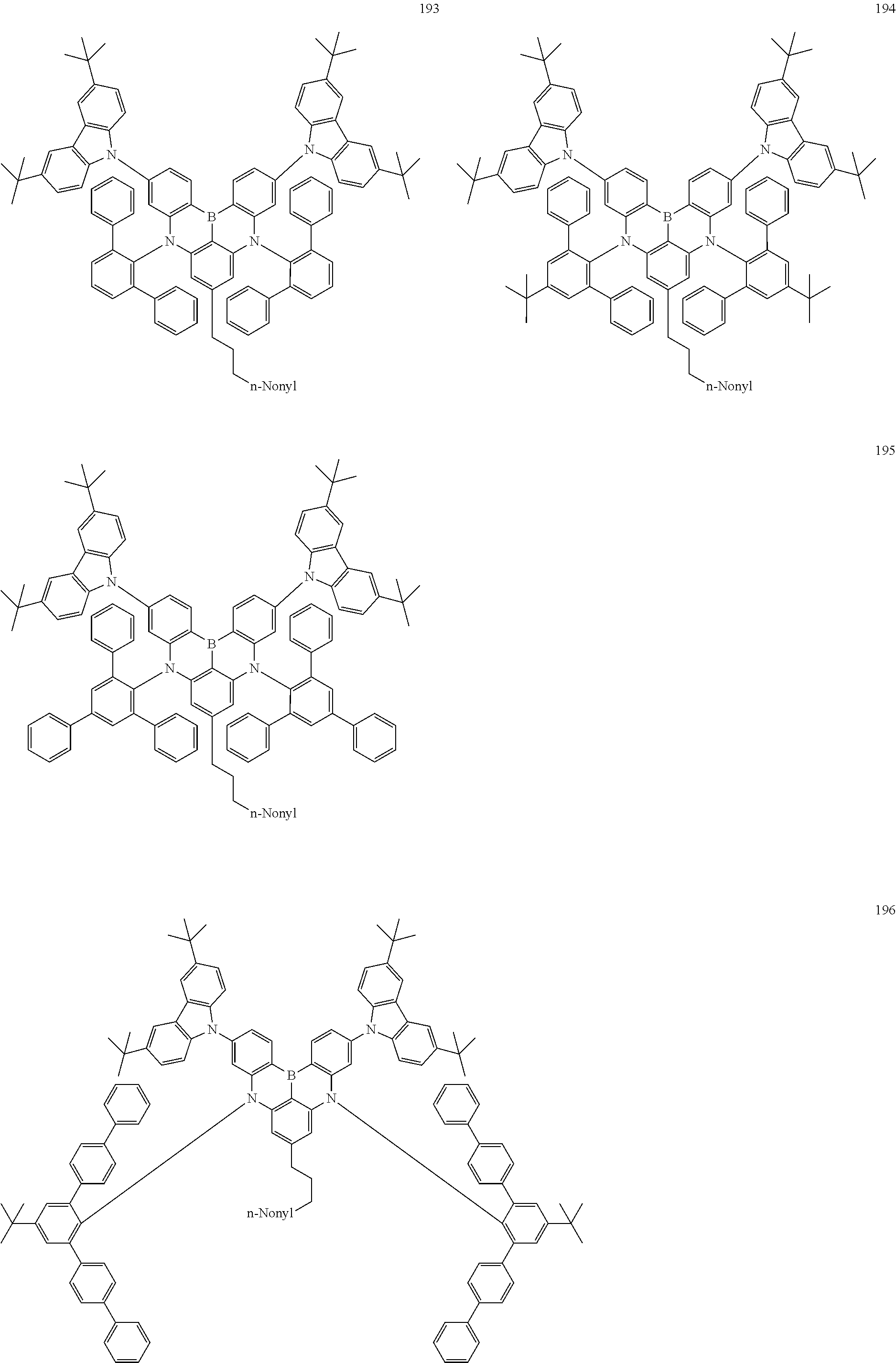

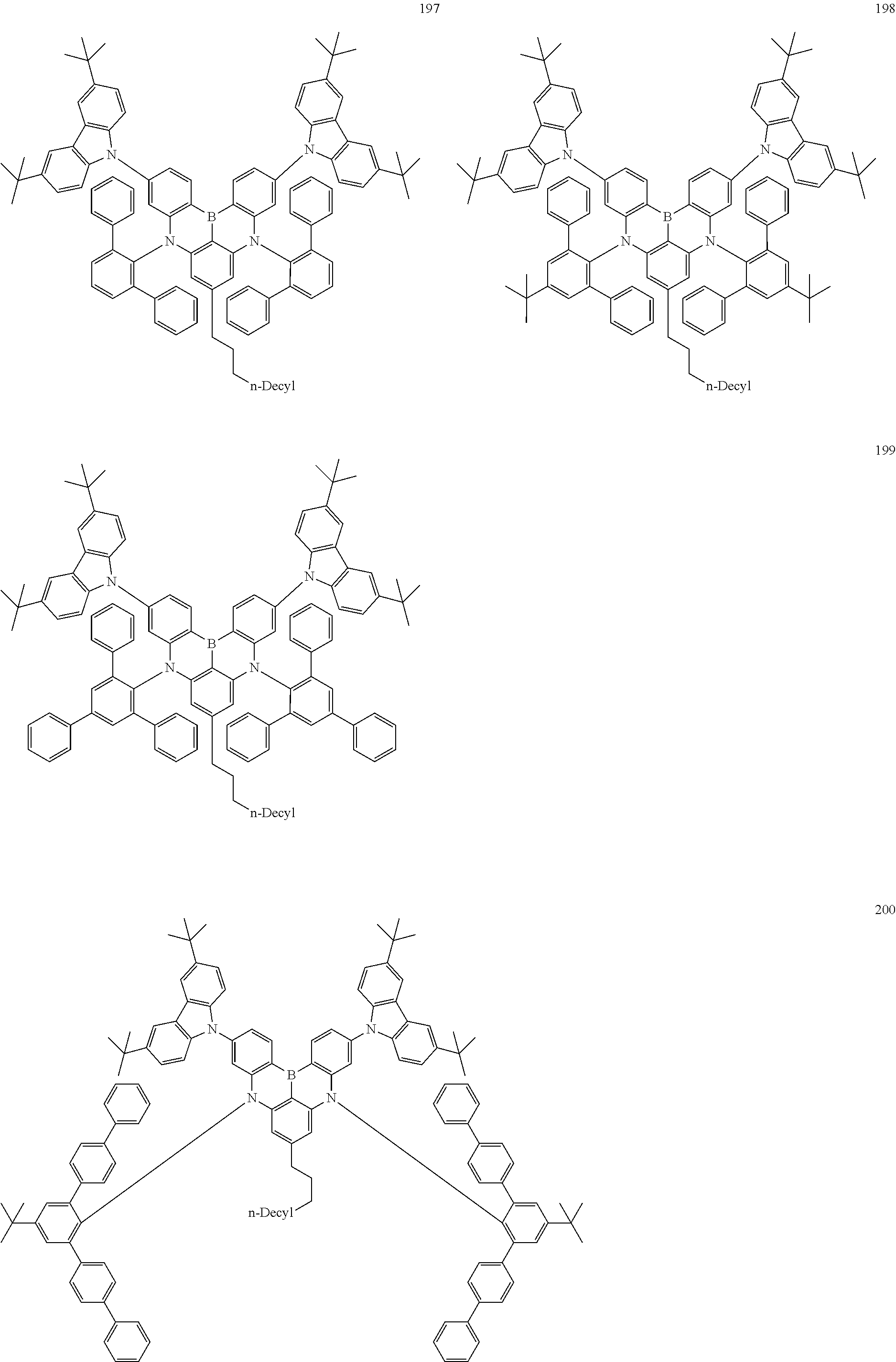

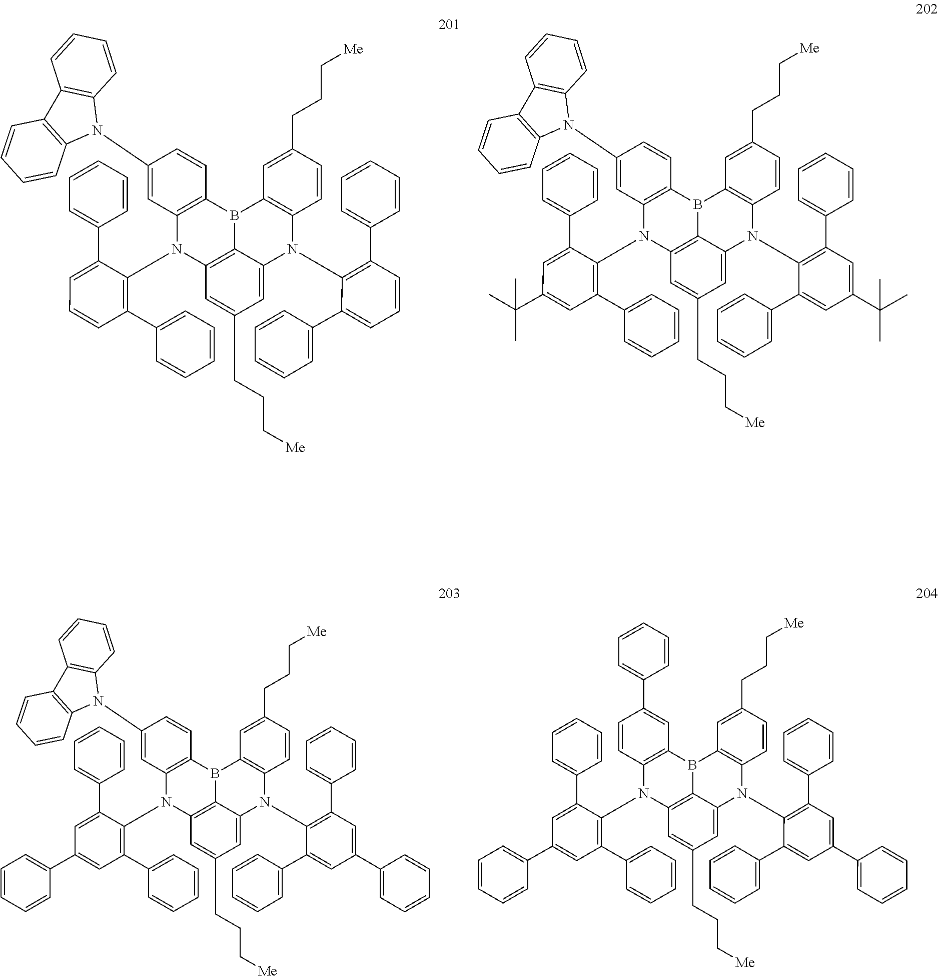

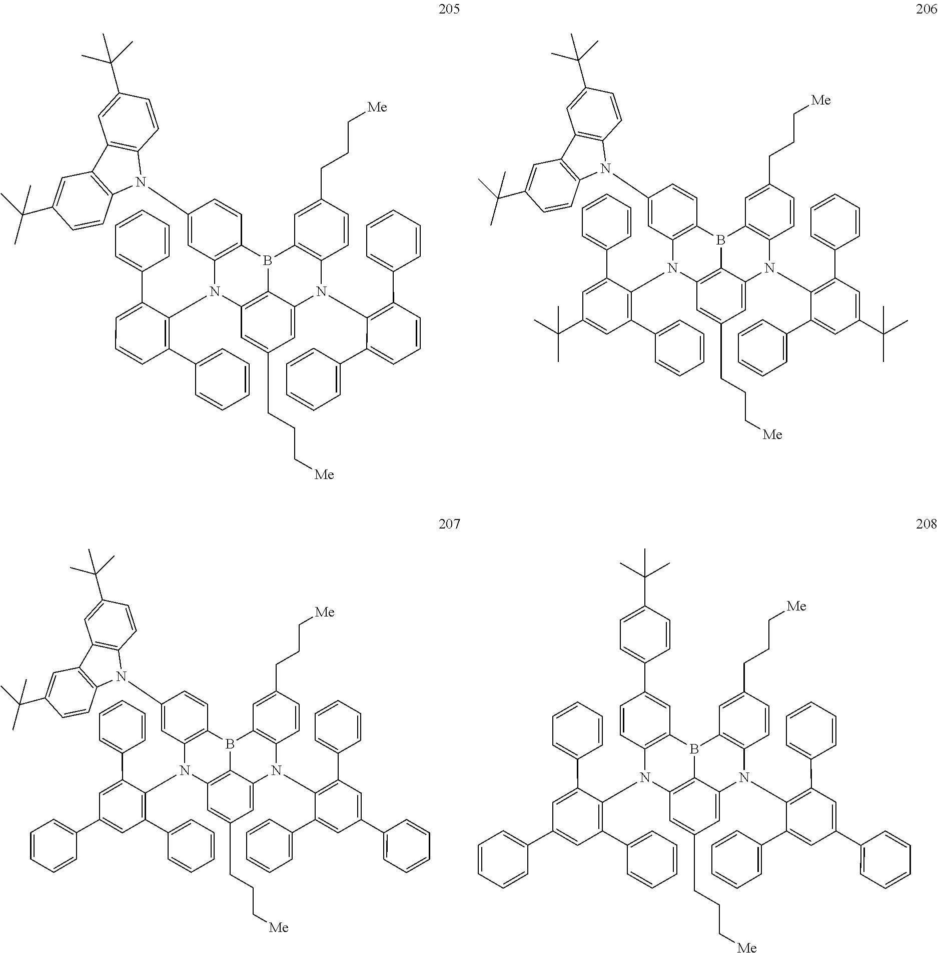

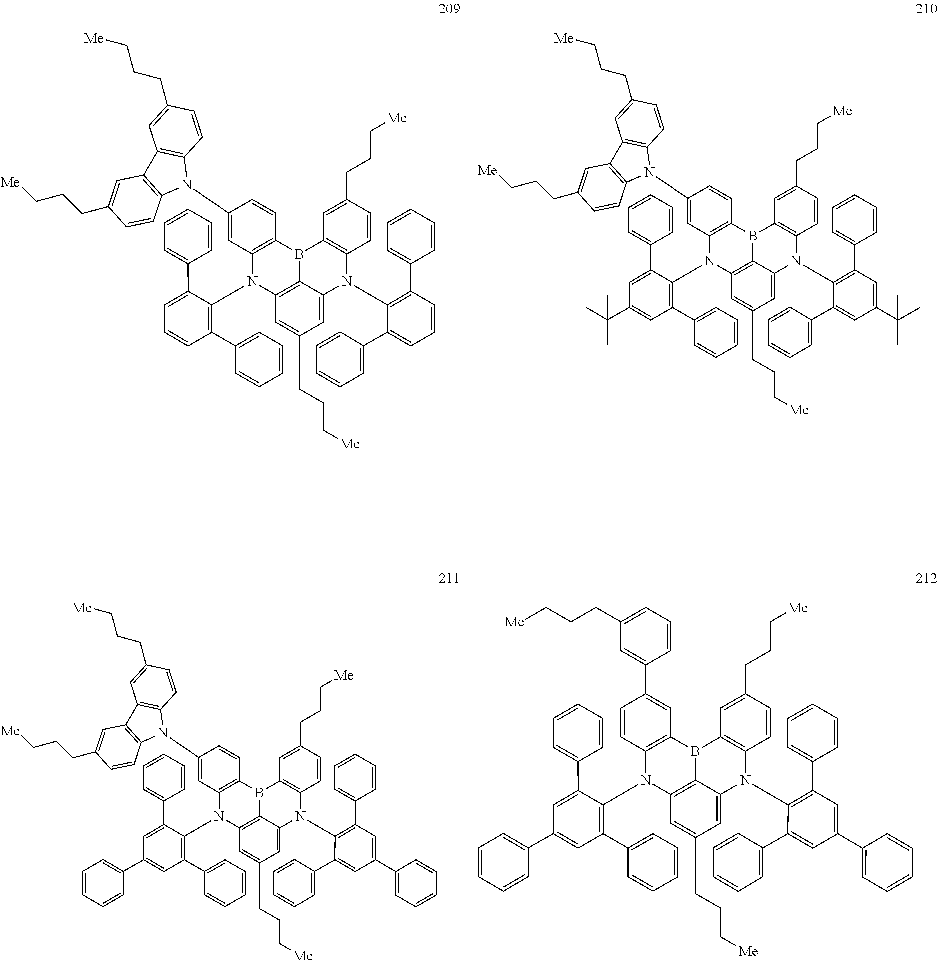

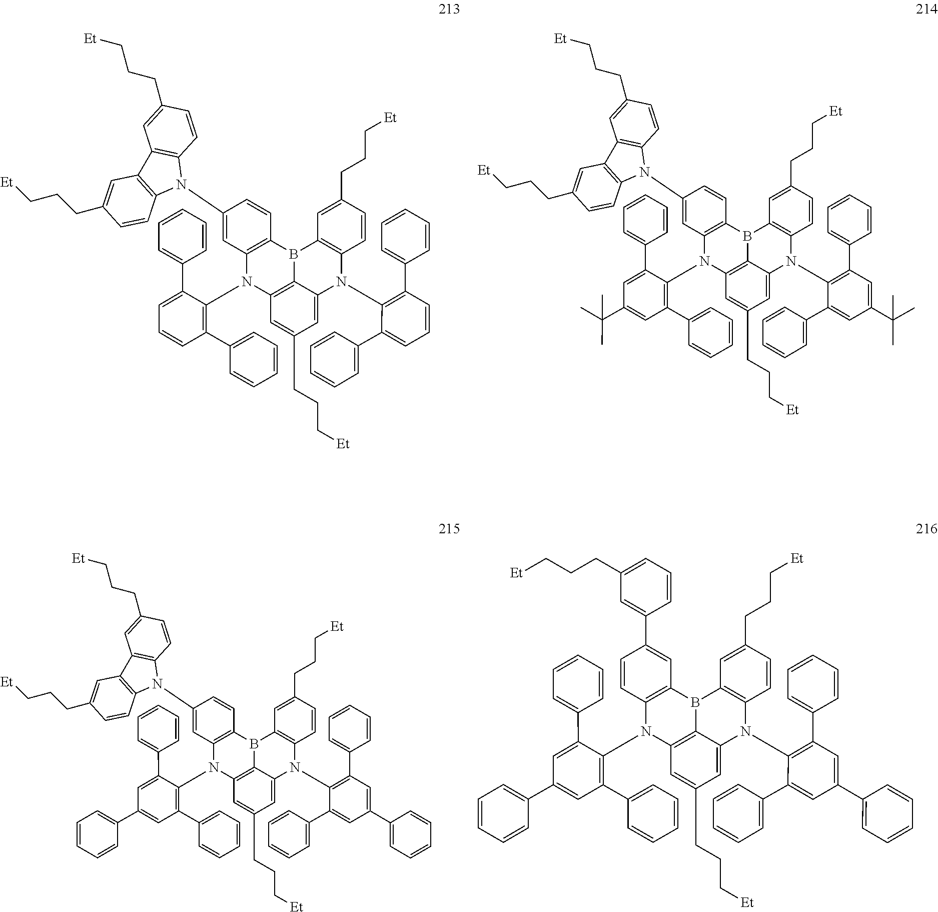

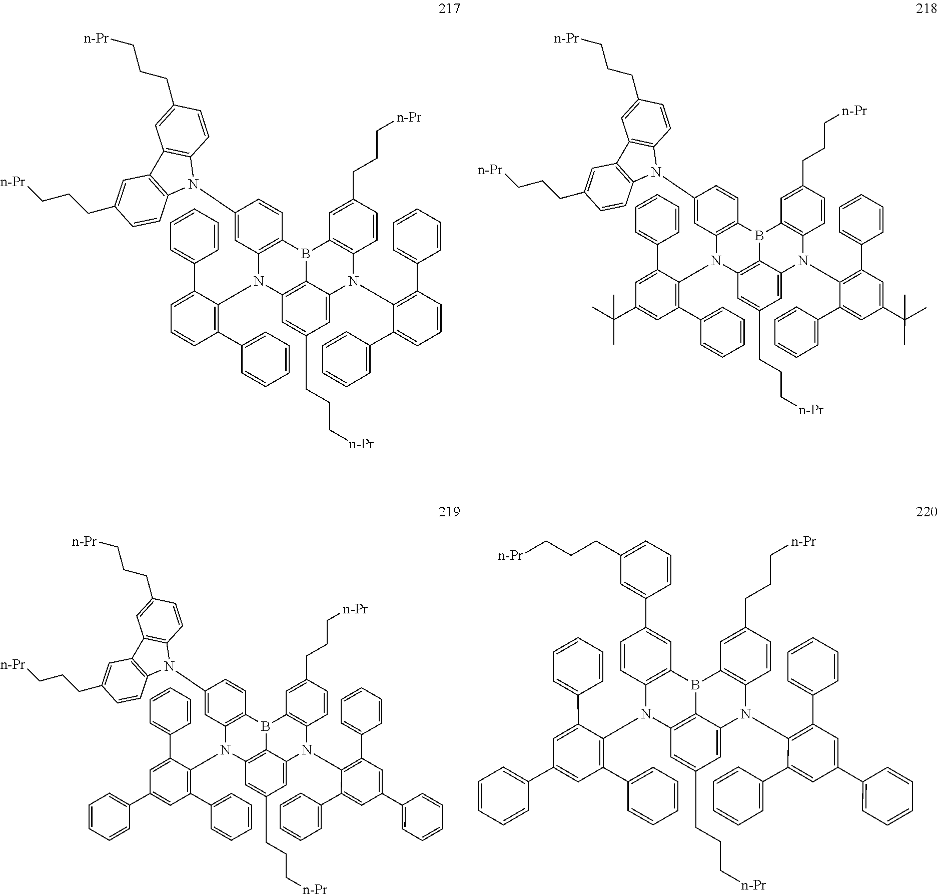

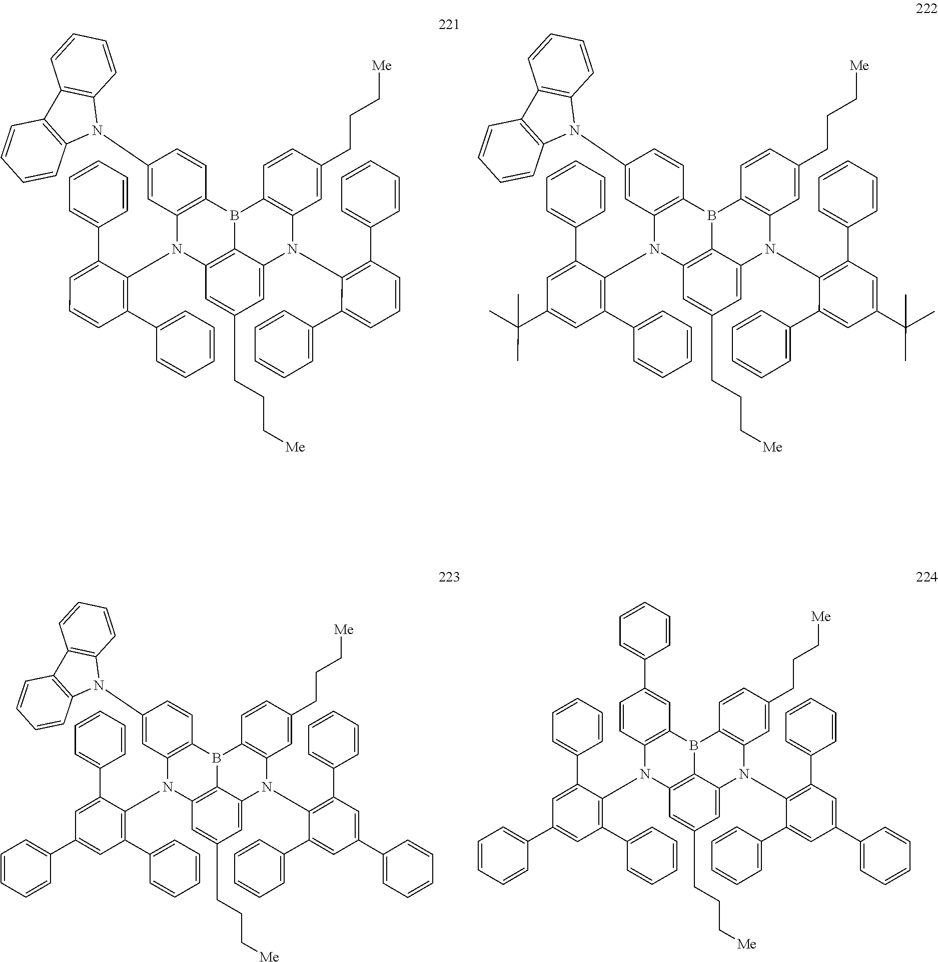

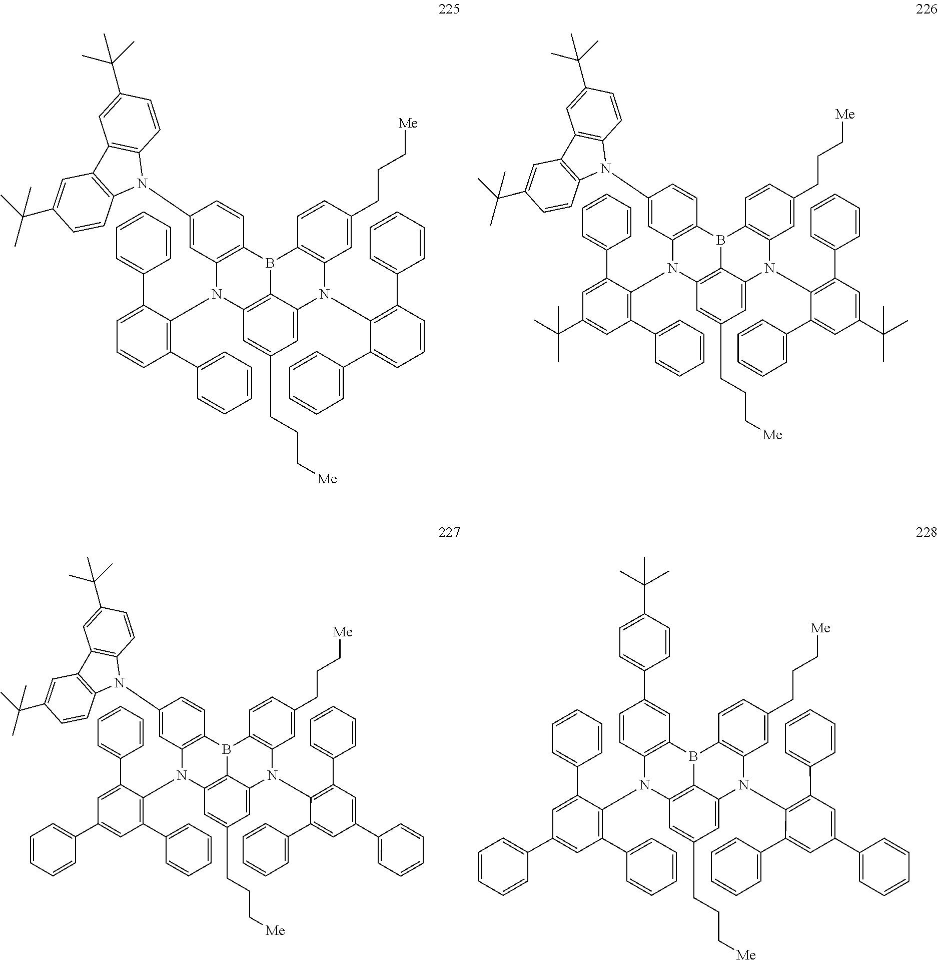

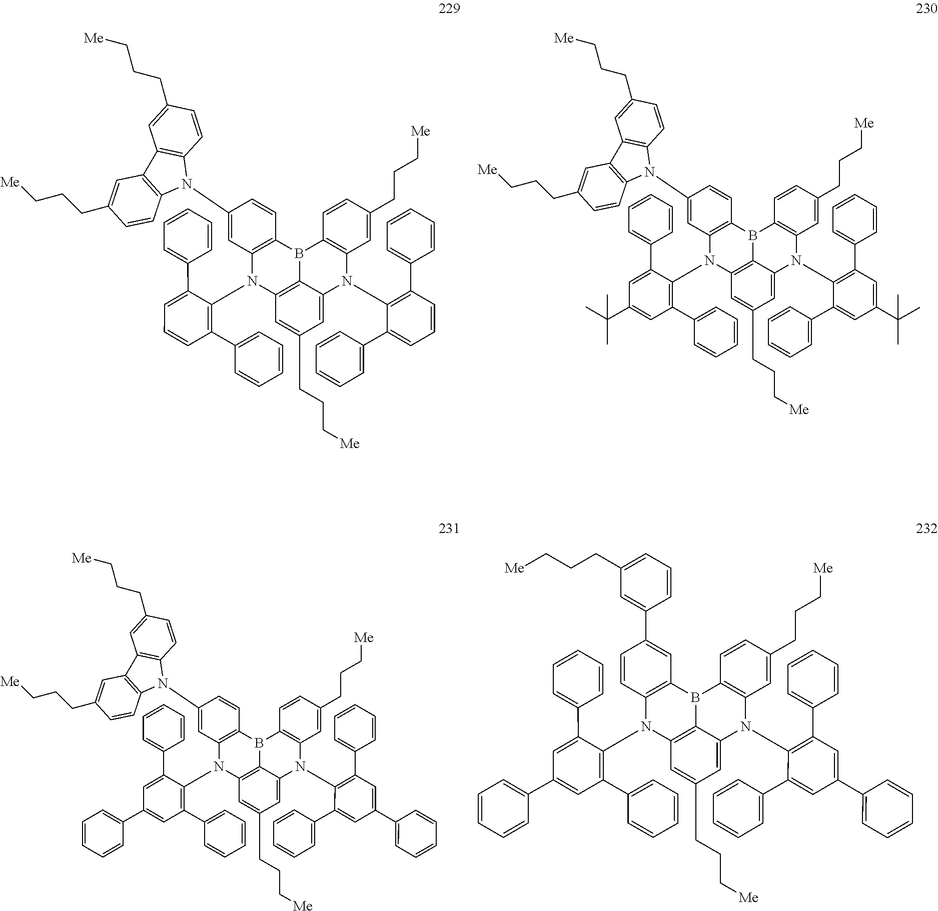

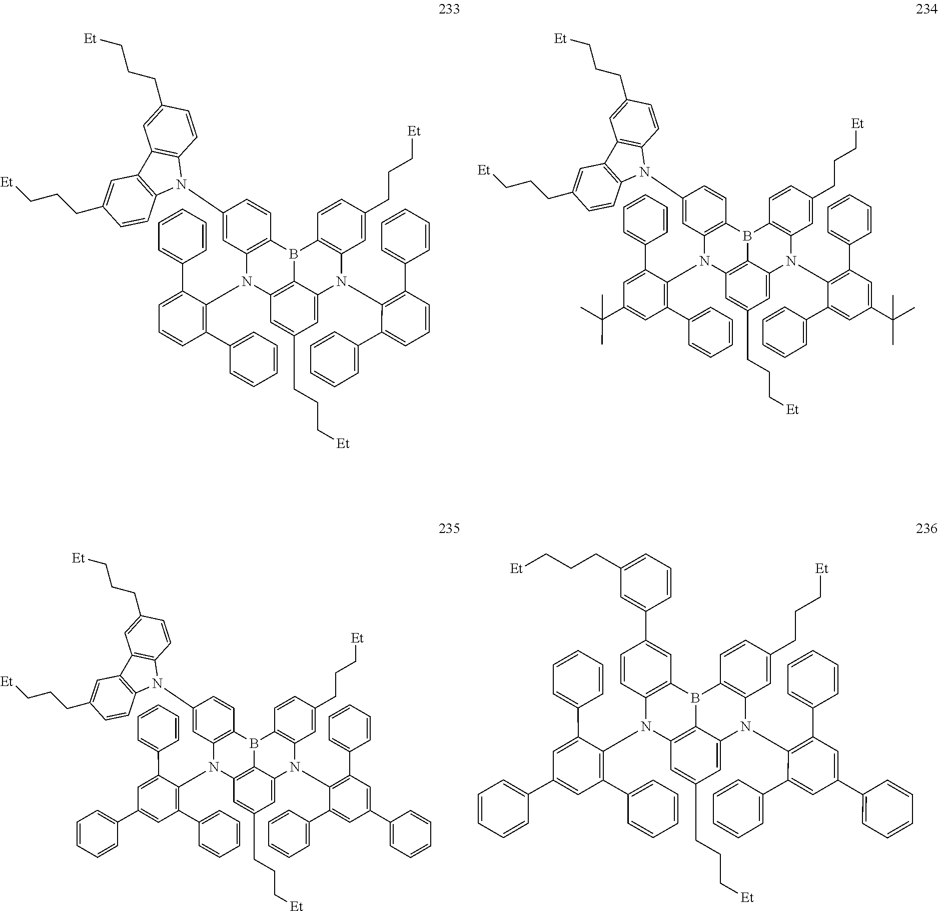

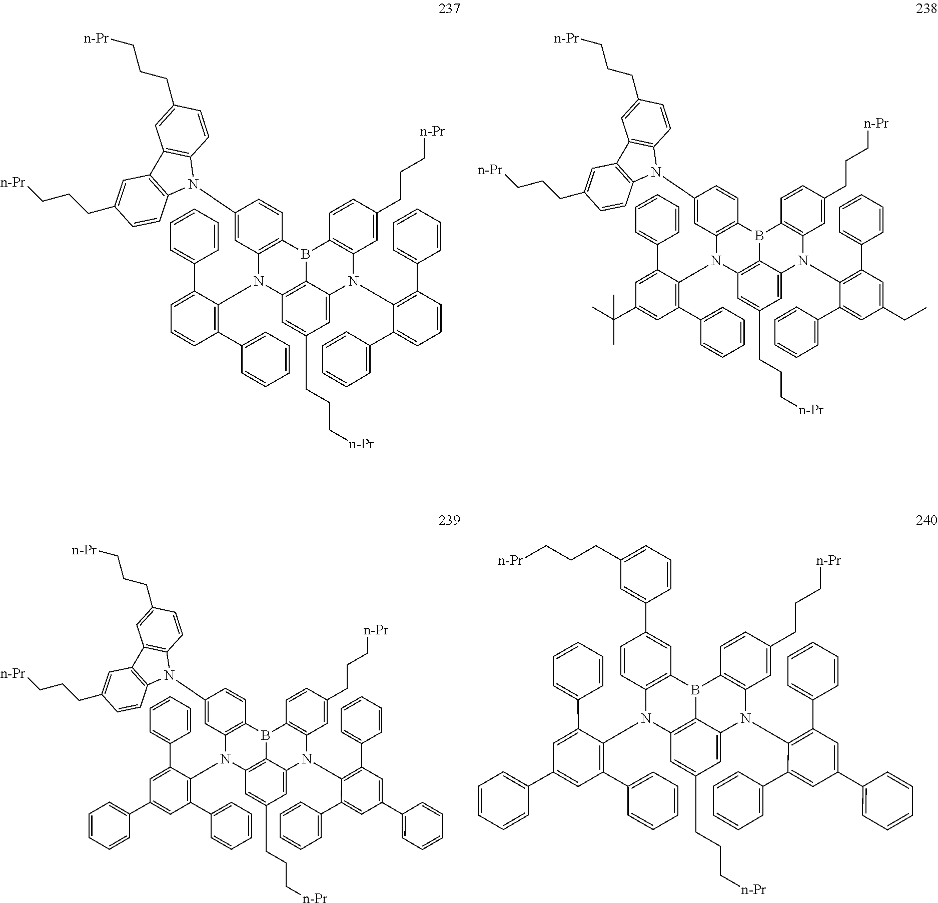

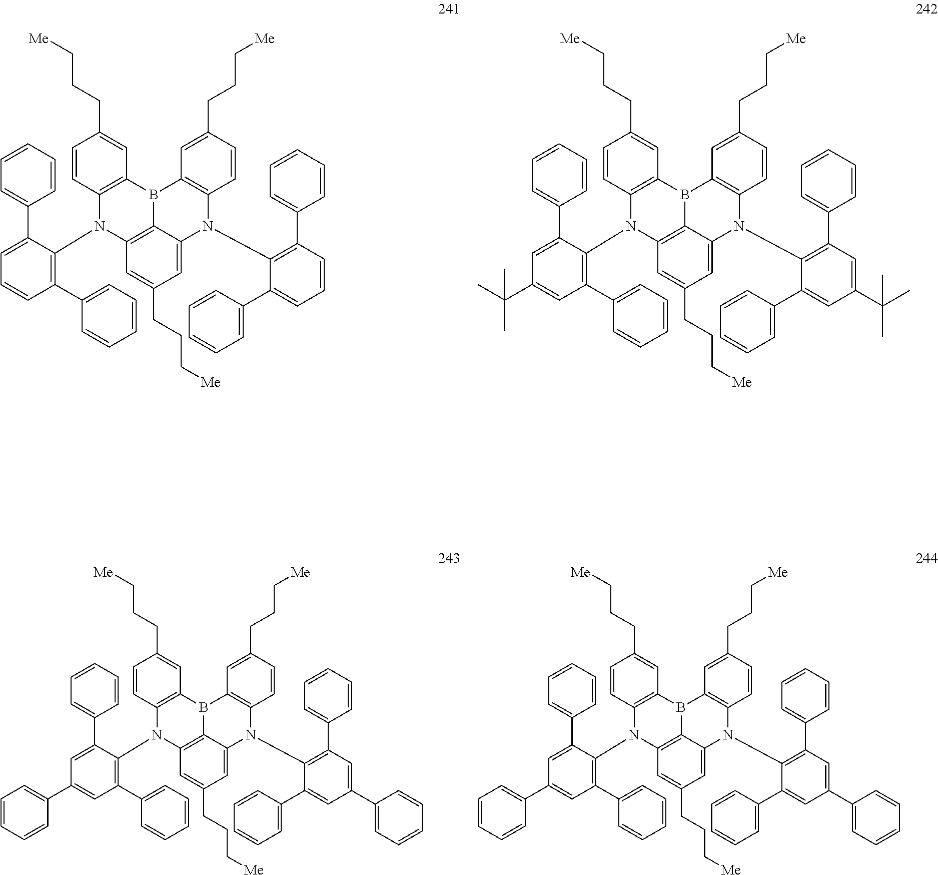

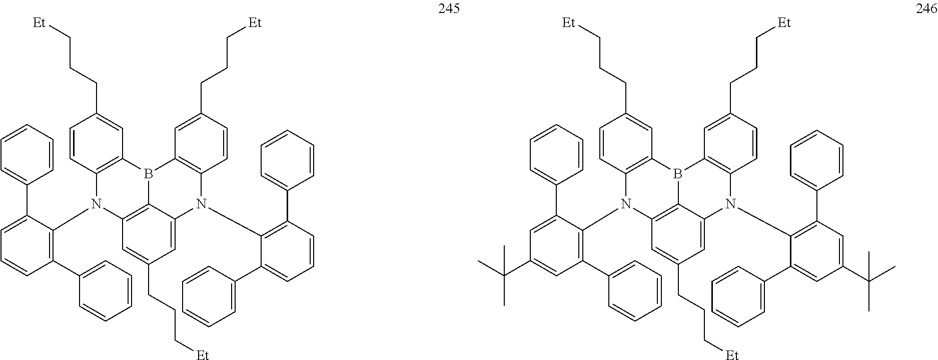 [SMILES: CCCCCc1ccc2c(c1)B1c3cc(CCCCC)ccc3N(c3c(-c4ccccc4)cccc3-c3ccccc3)c3cc(CCCCC)cc(c31)N2c1c(-c2ccccc2)cccc1-c1ccccc1 ; CCCCCc1ccc2c(c1)B1c3cc(CCCCC)ccc3N(c3c(-c4ccccc4)cc(C(C)(C)C)cc3-c3ccccc3)c3cc(CCCCC)cc(c31)N2c1c(-c2ccccc2)cc(C(C)(C)C)cc1-c1ccccc1]

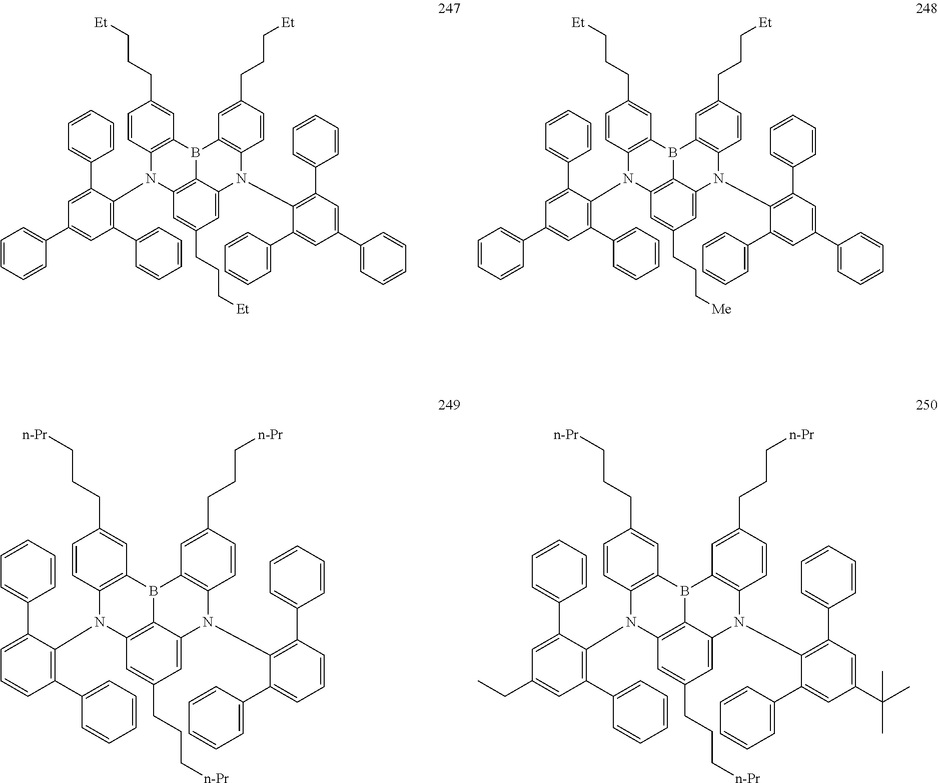

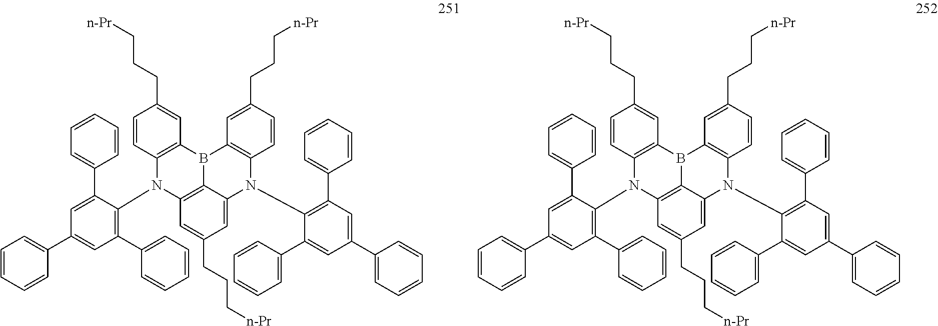

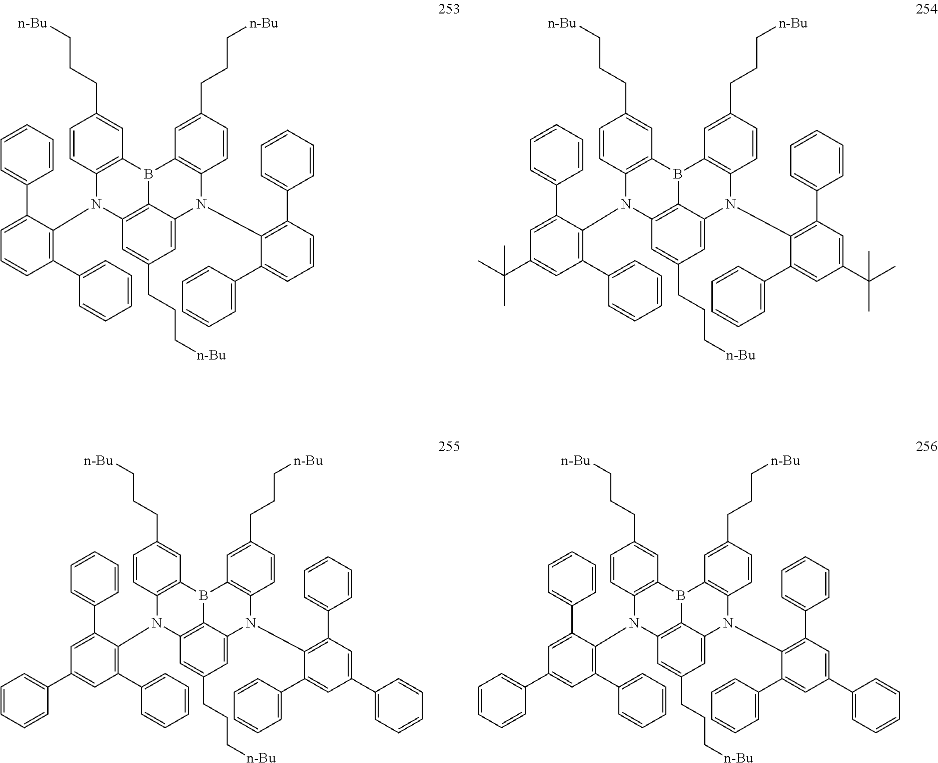

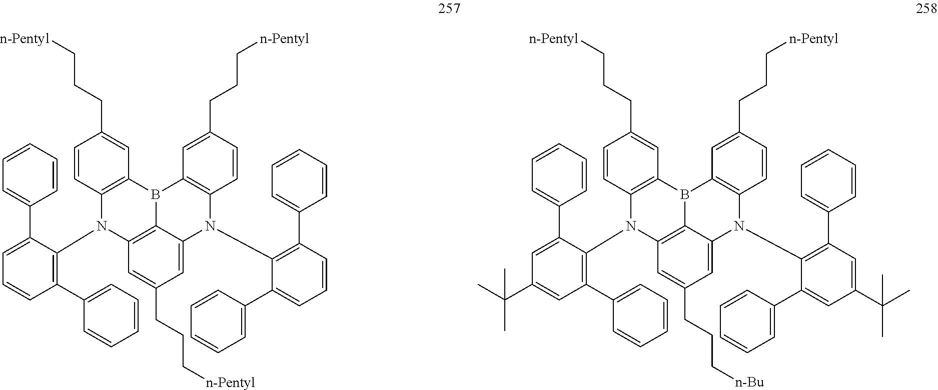

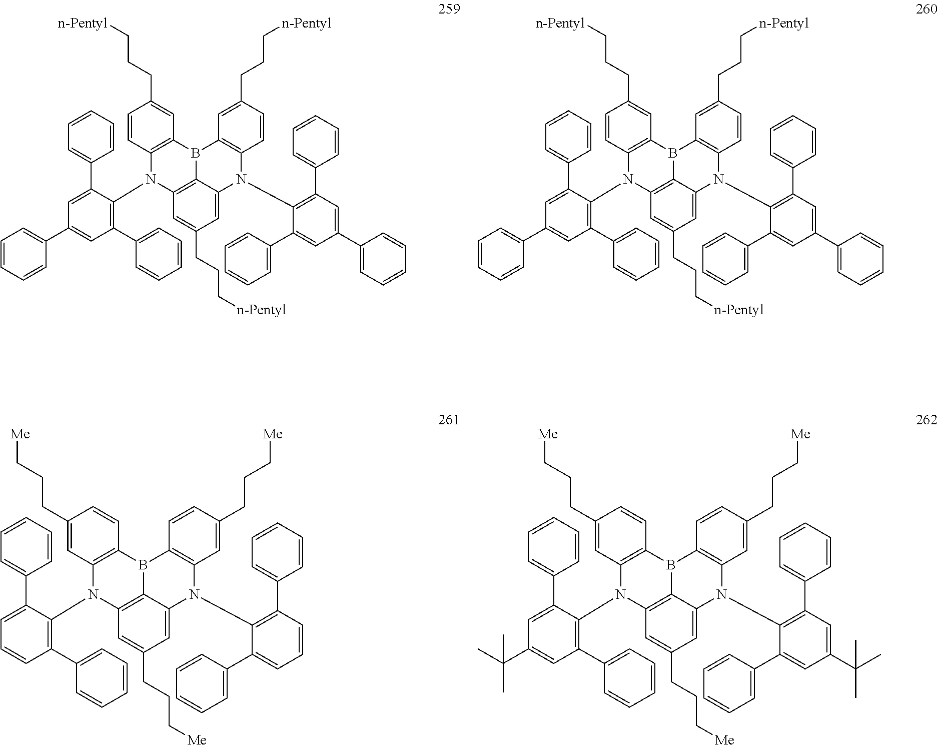

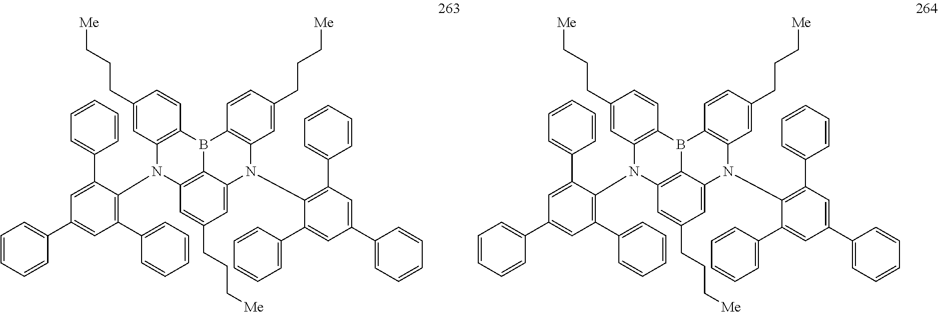 [SMILES: CCCCc1ccc2c(c1)N(c1c(-c3ccccc3)cc(-c3ccccc3)cc1-c1ccccc1)c1cc(CCCC)cc3c1B2c1ccc(CCCC)cc1N3c1c(-c2ccccc2)cc(-c2ccccc2)cc1-c1ccccc1 ; CCCCc1ccc2c(c1)N(c1c(-c3ccccc3)cc(-c3ccccc3)cc1-c1ccccc1)c1cc(CCCC)cc3c1B2c1ccc(CCCC)cc1N3c1c(-c2ccccc2)cc(-c2ccccc2)cc1-c1ccccc1]

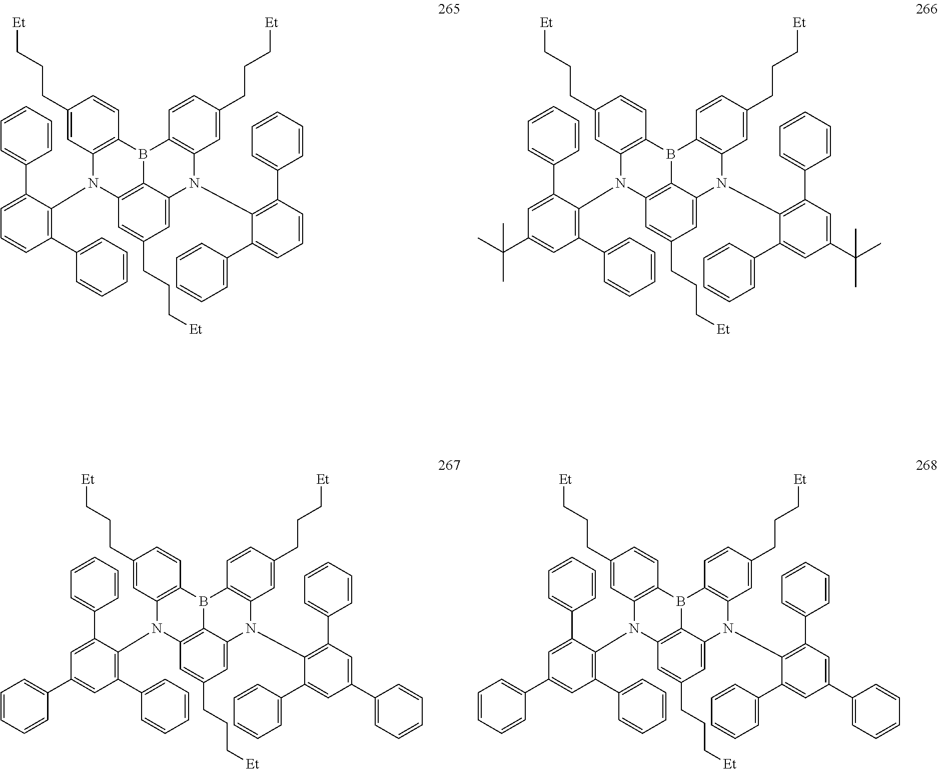

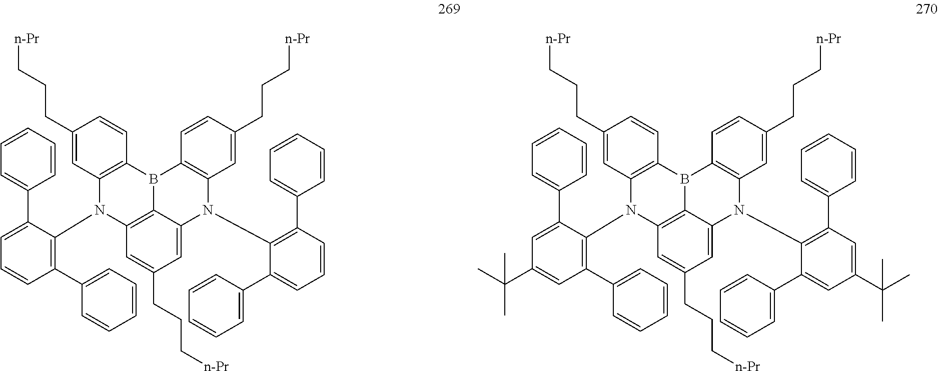

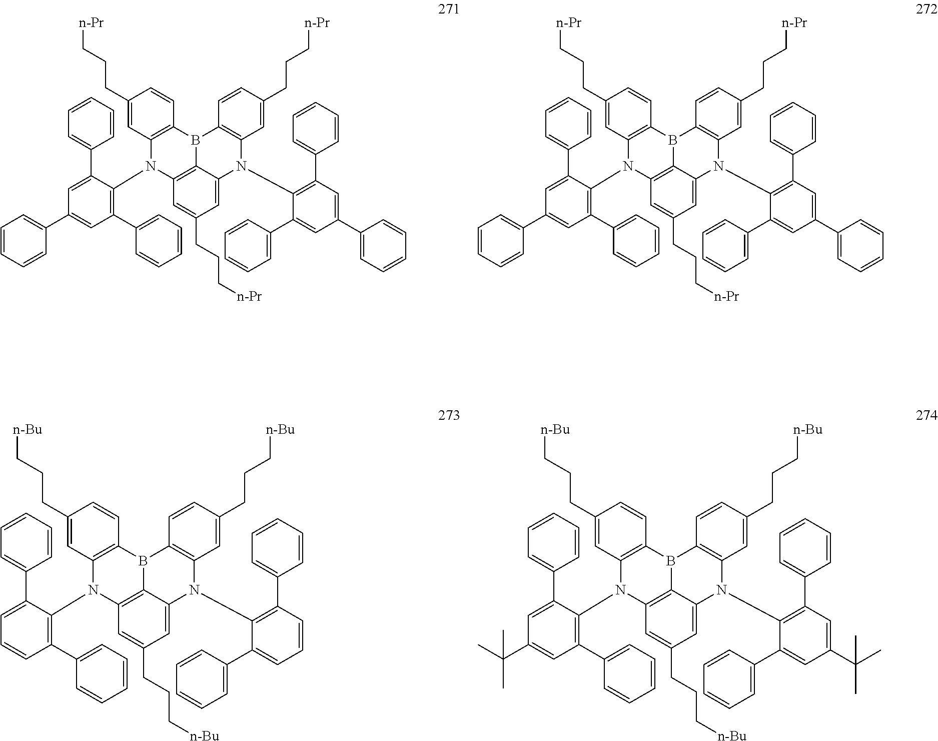

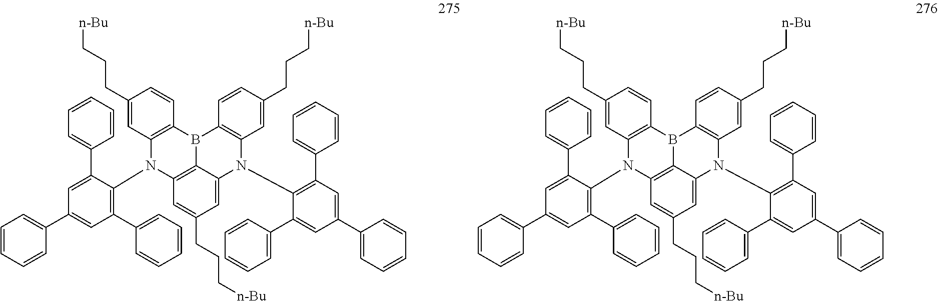

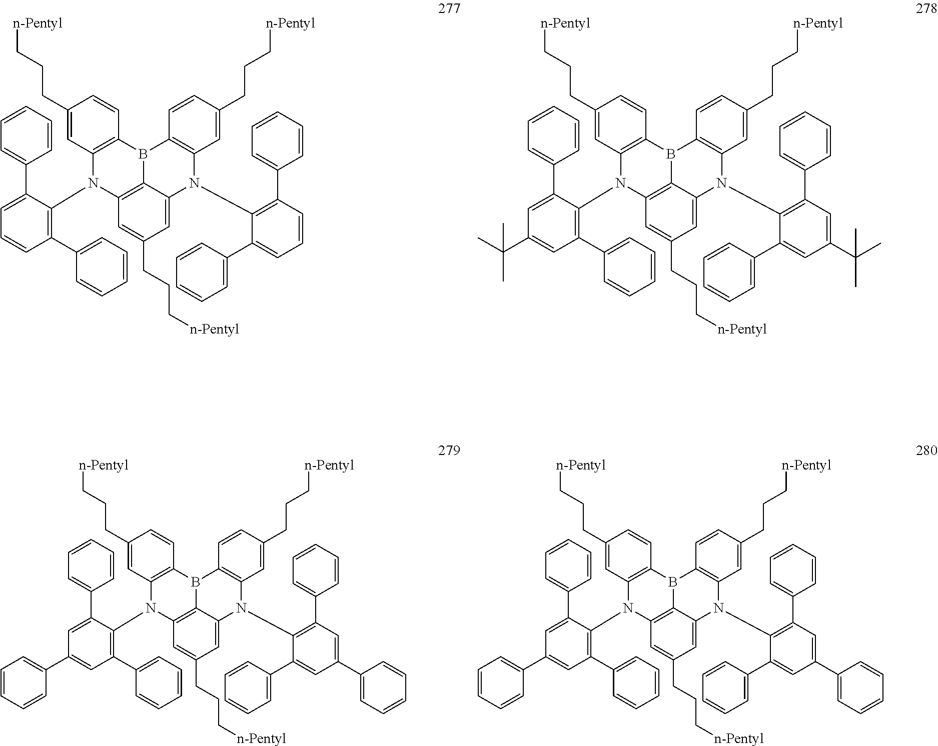

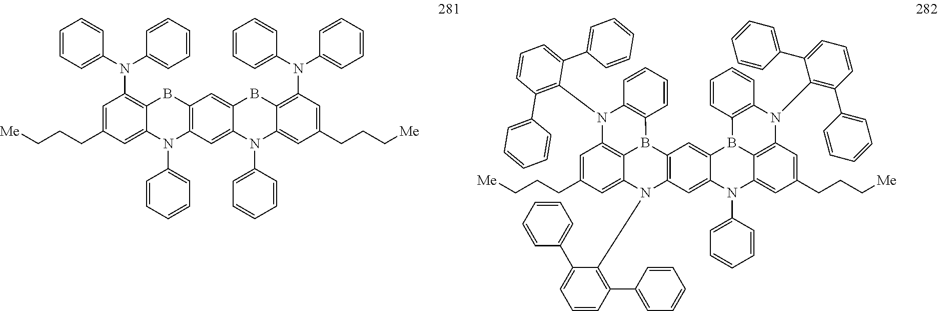

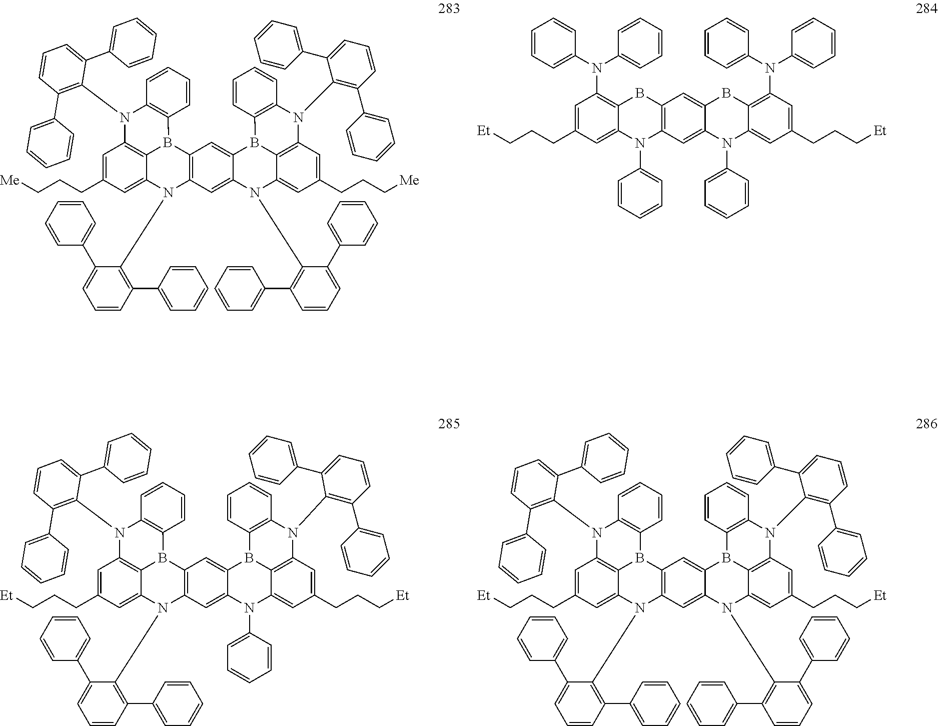

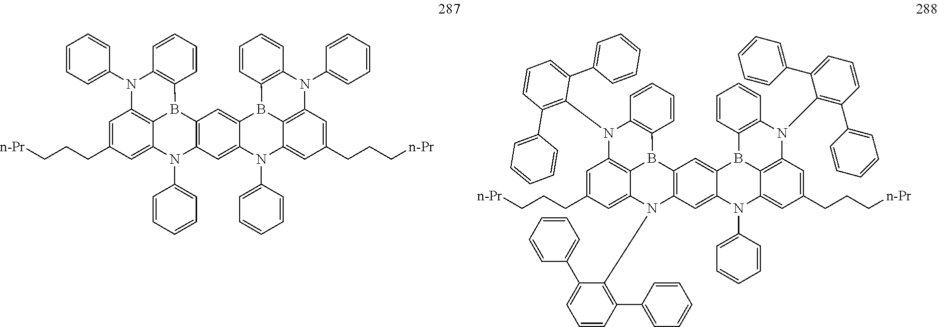

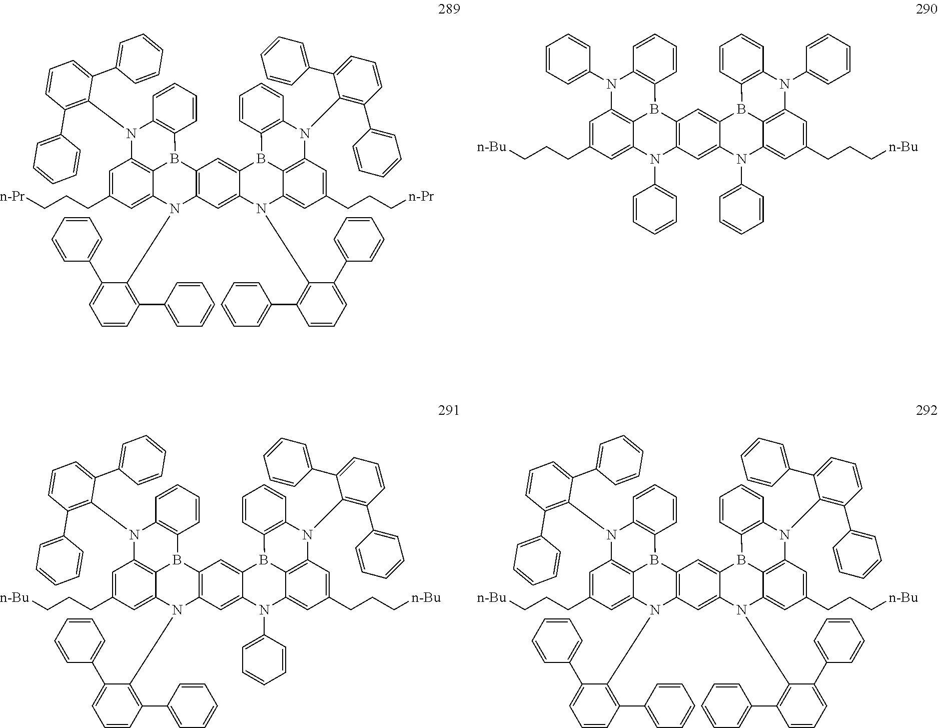

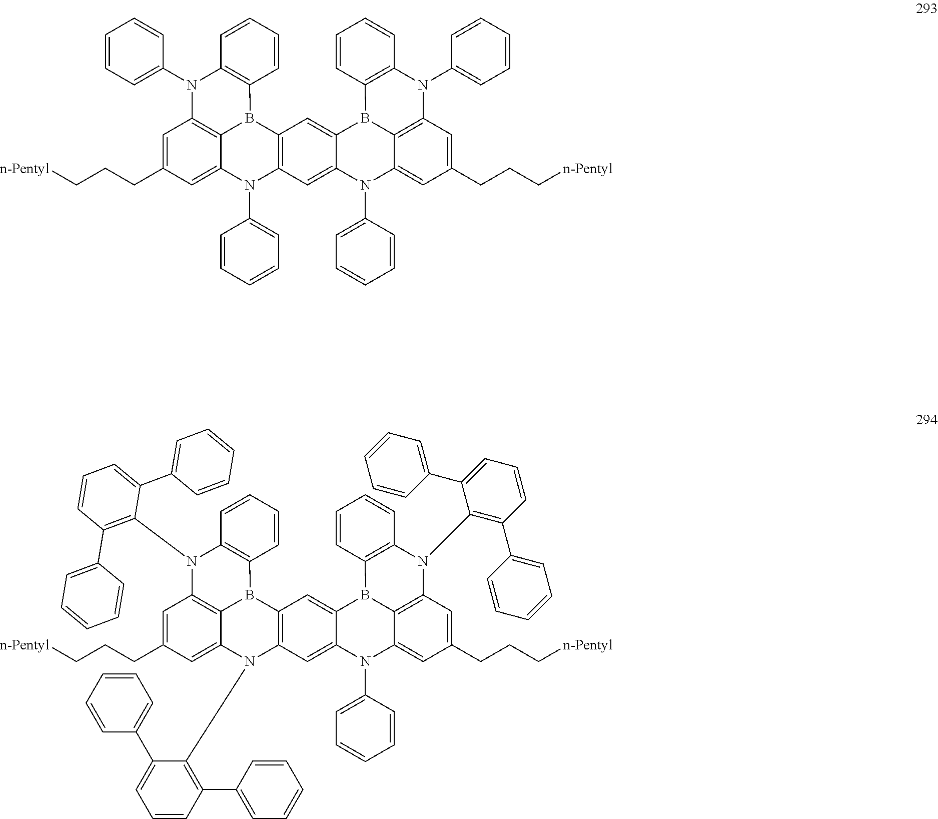

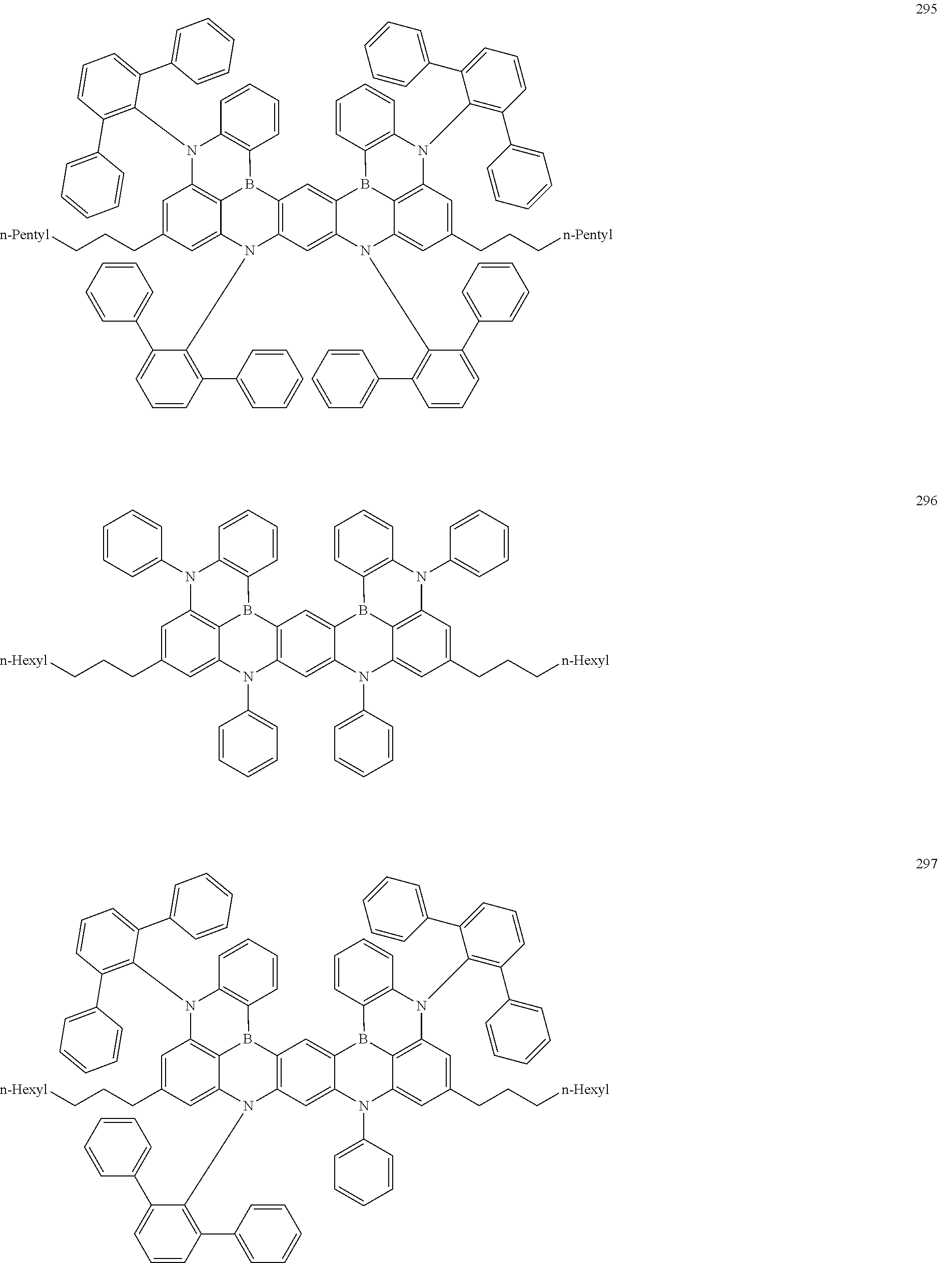

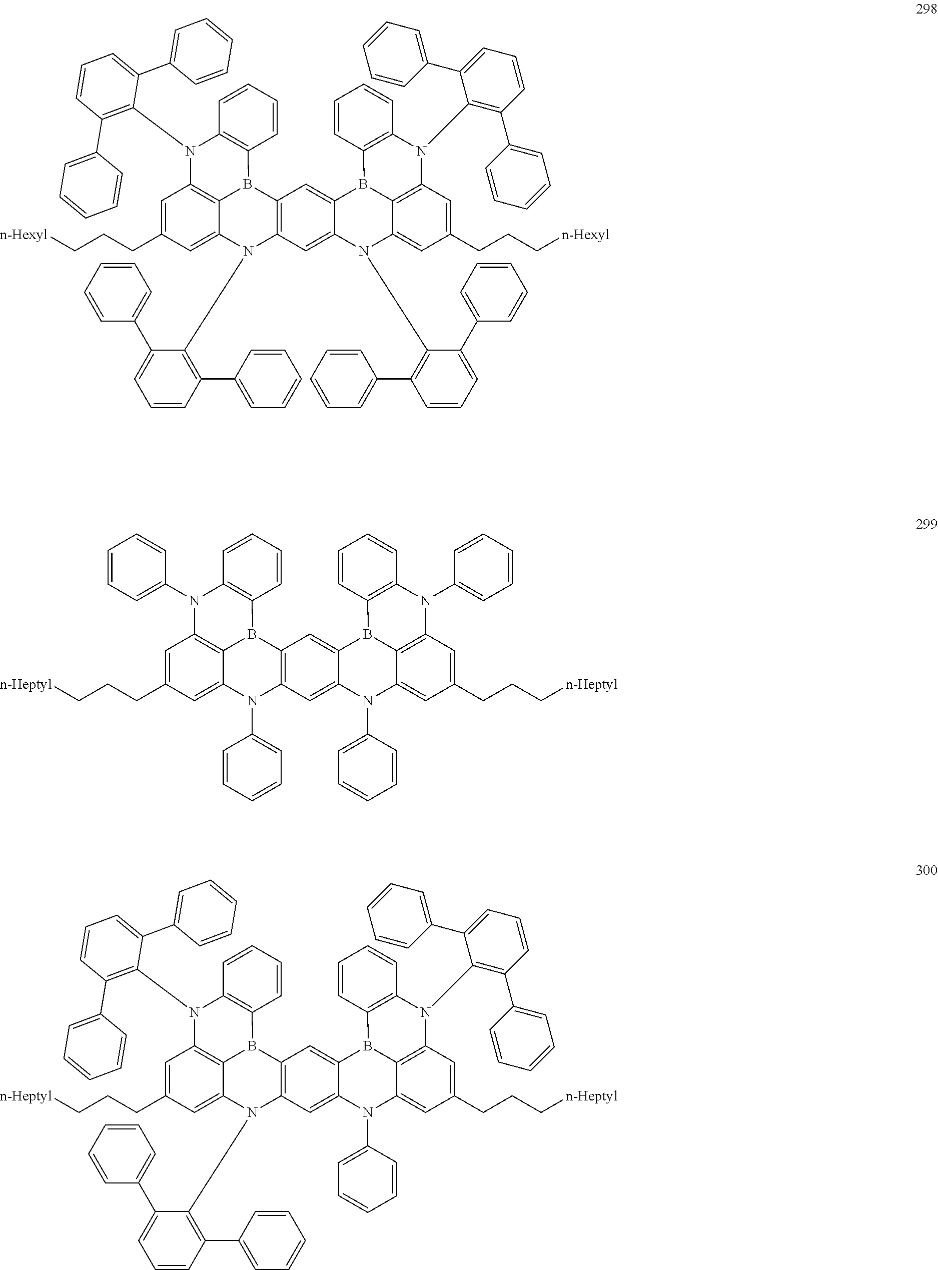

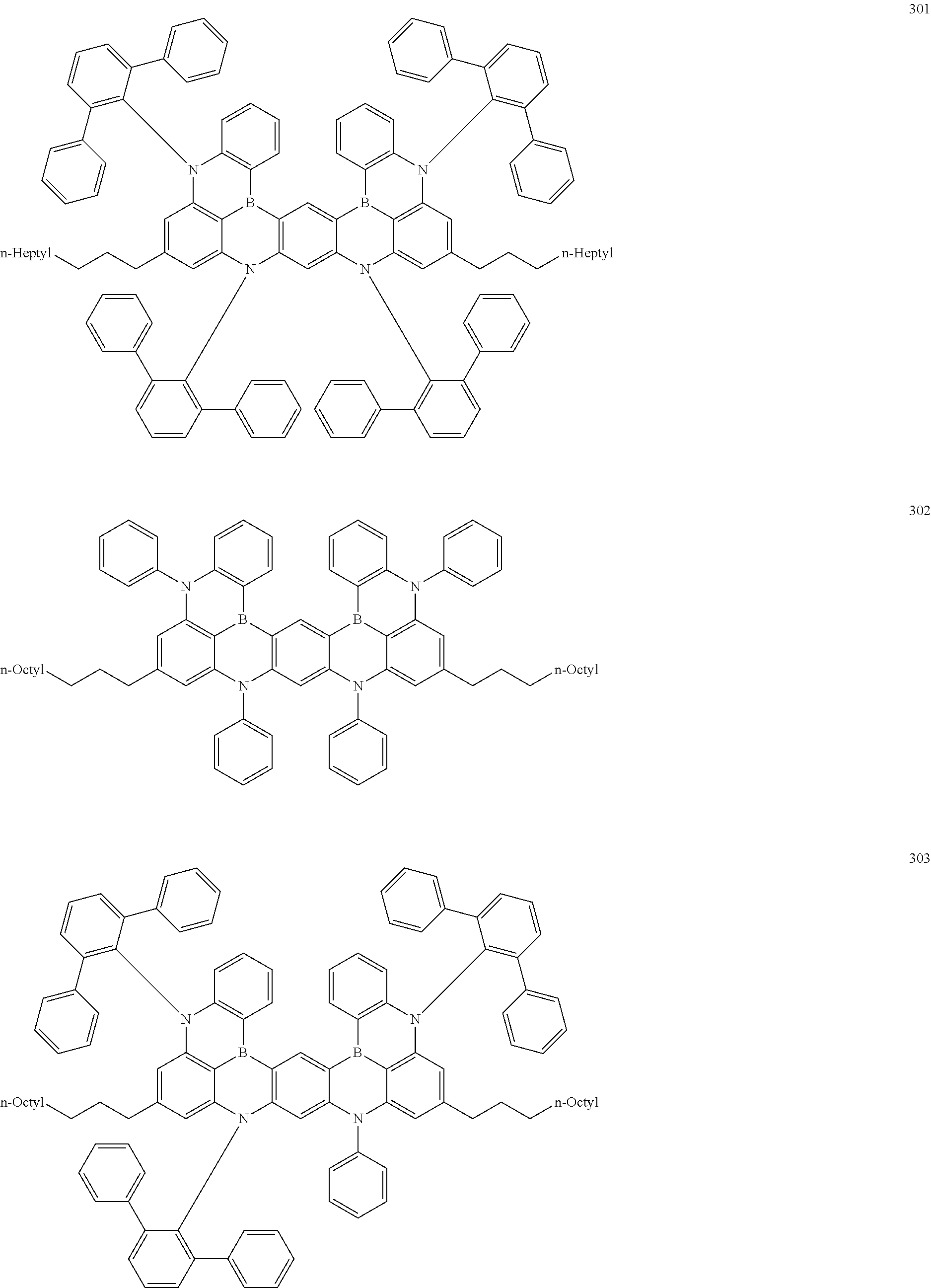

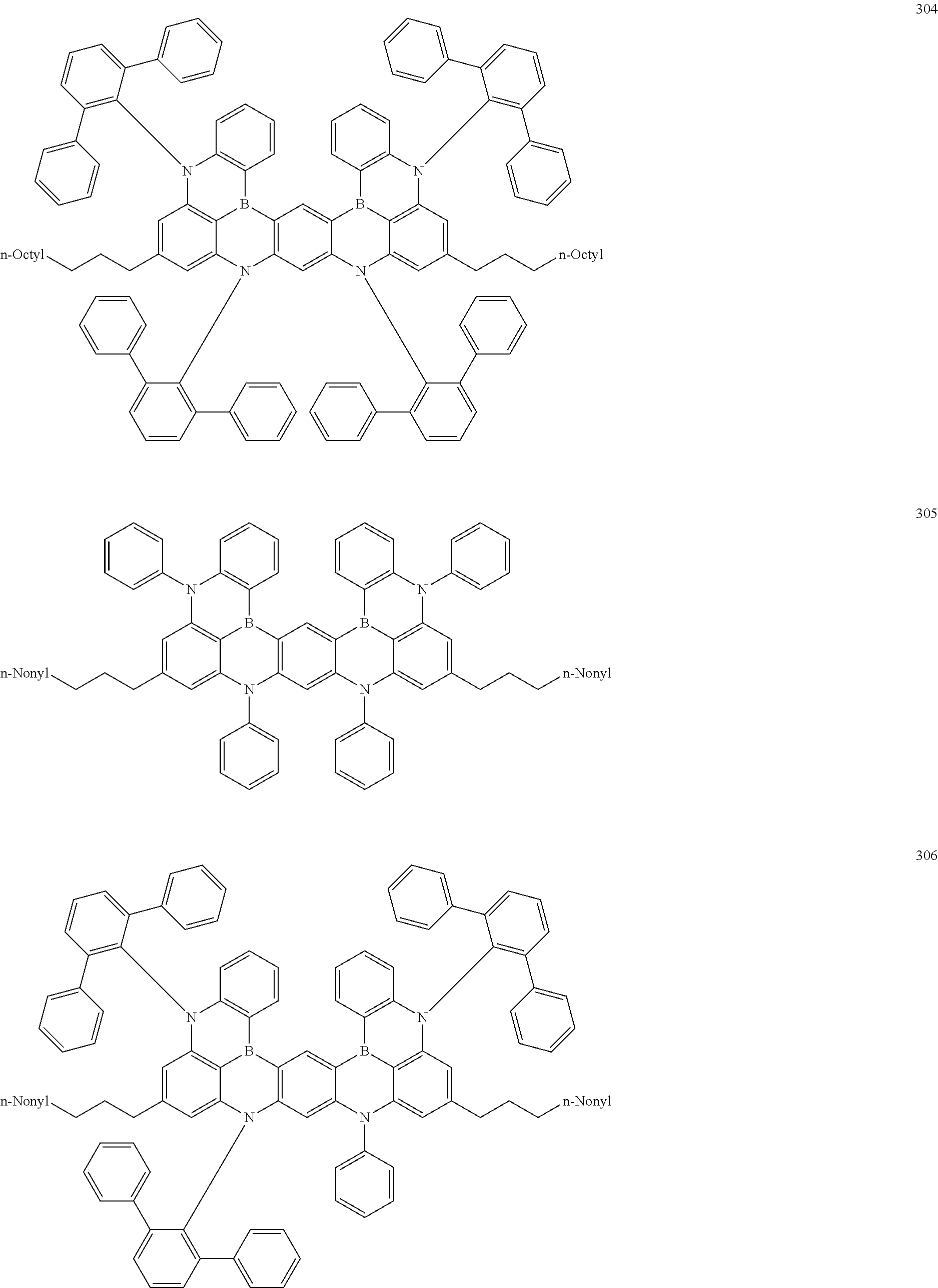

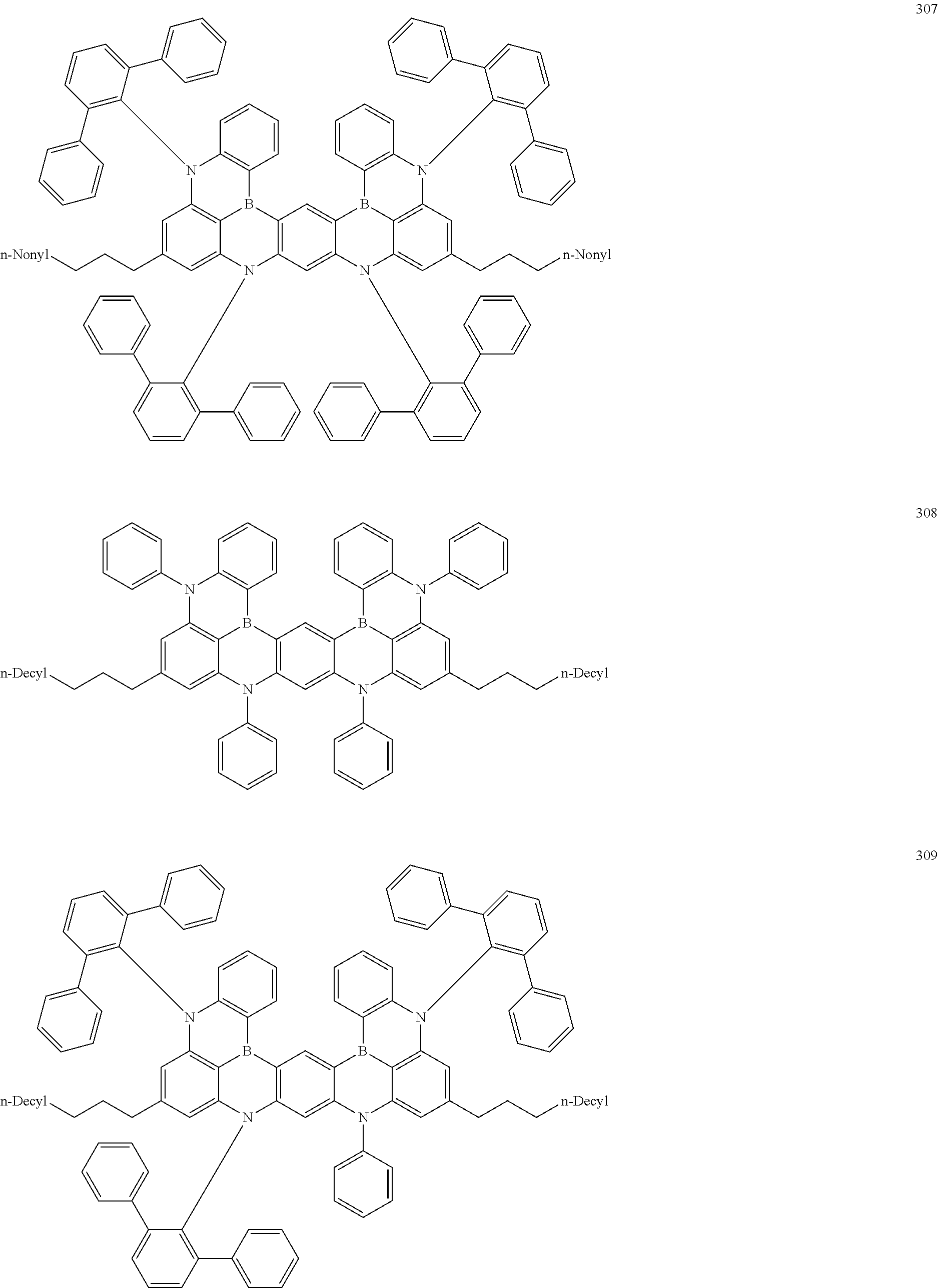

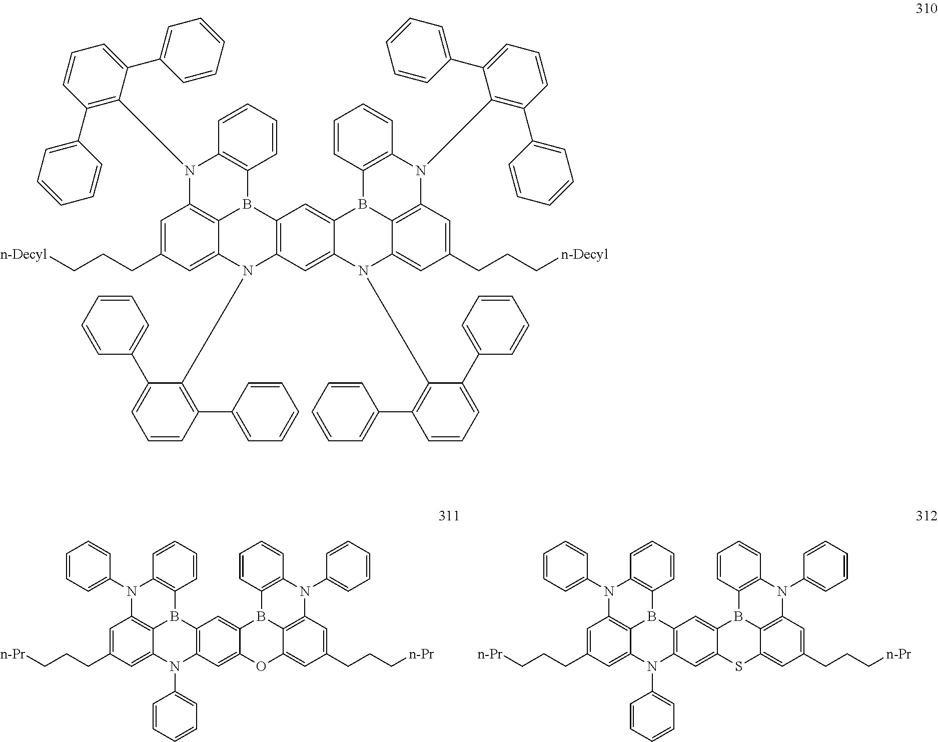

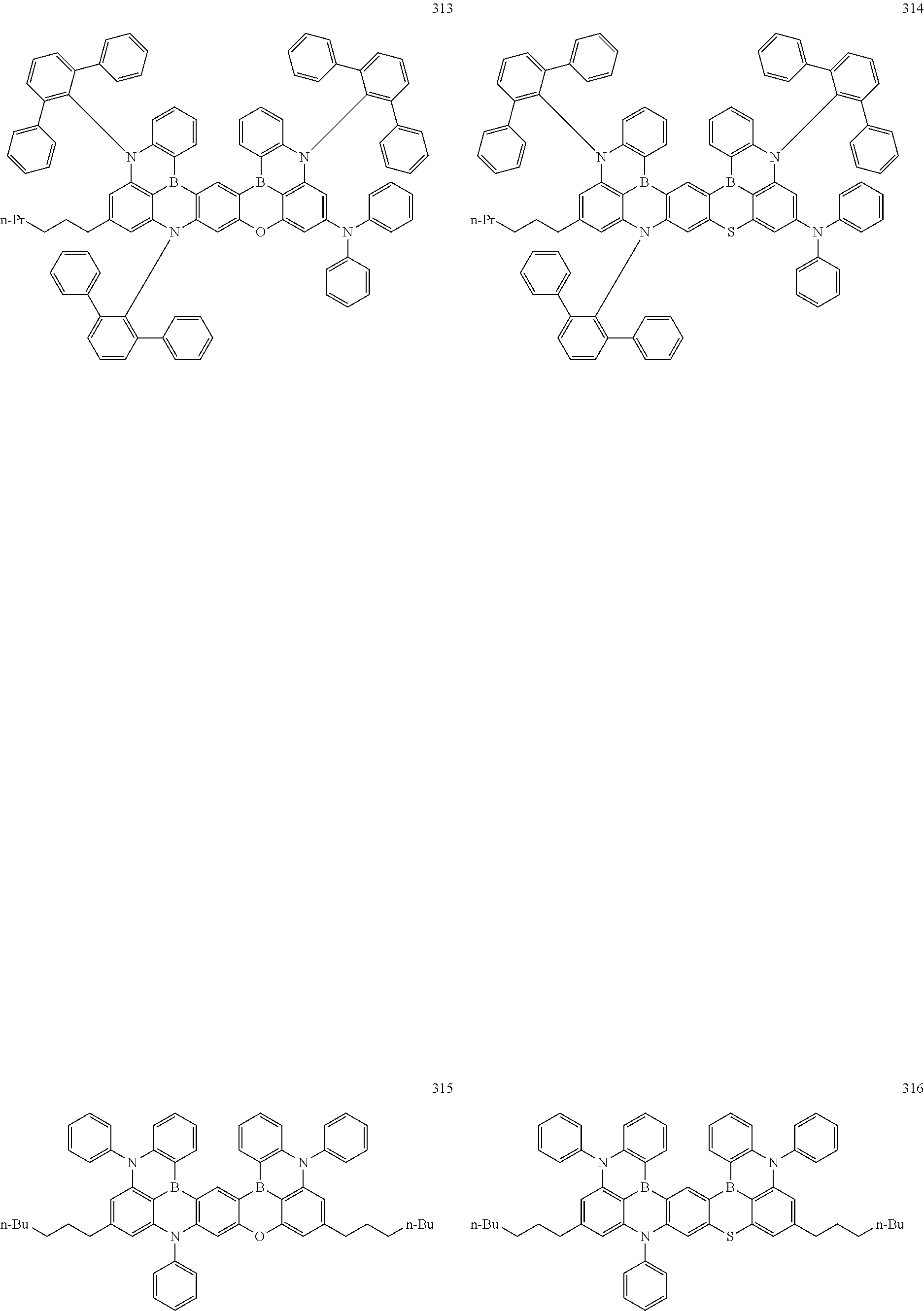

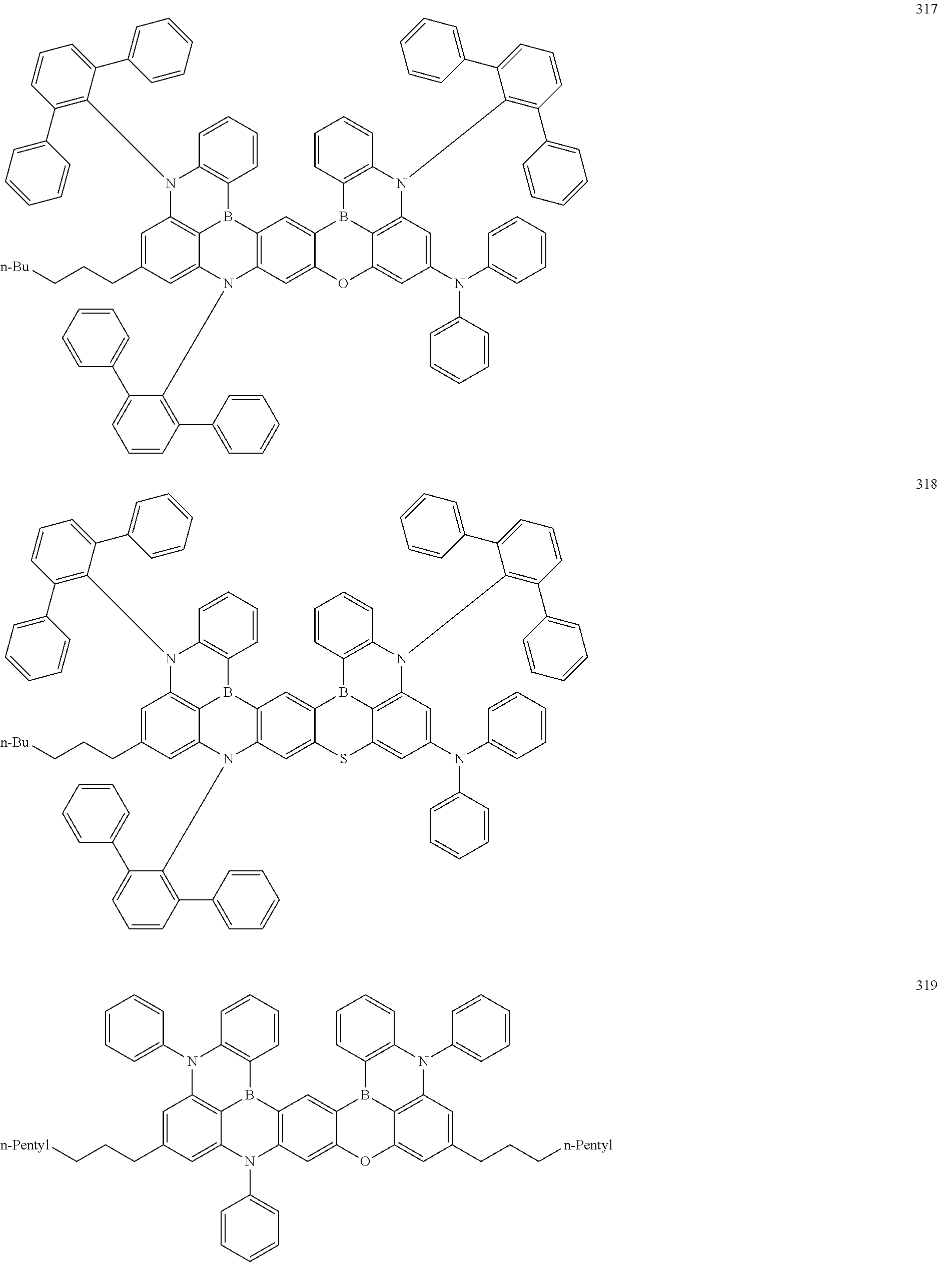

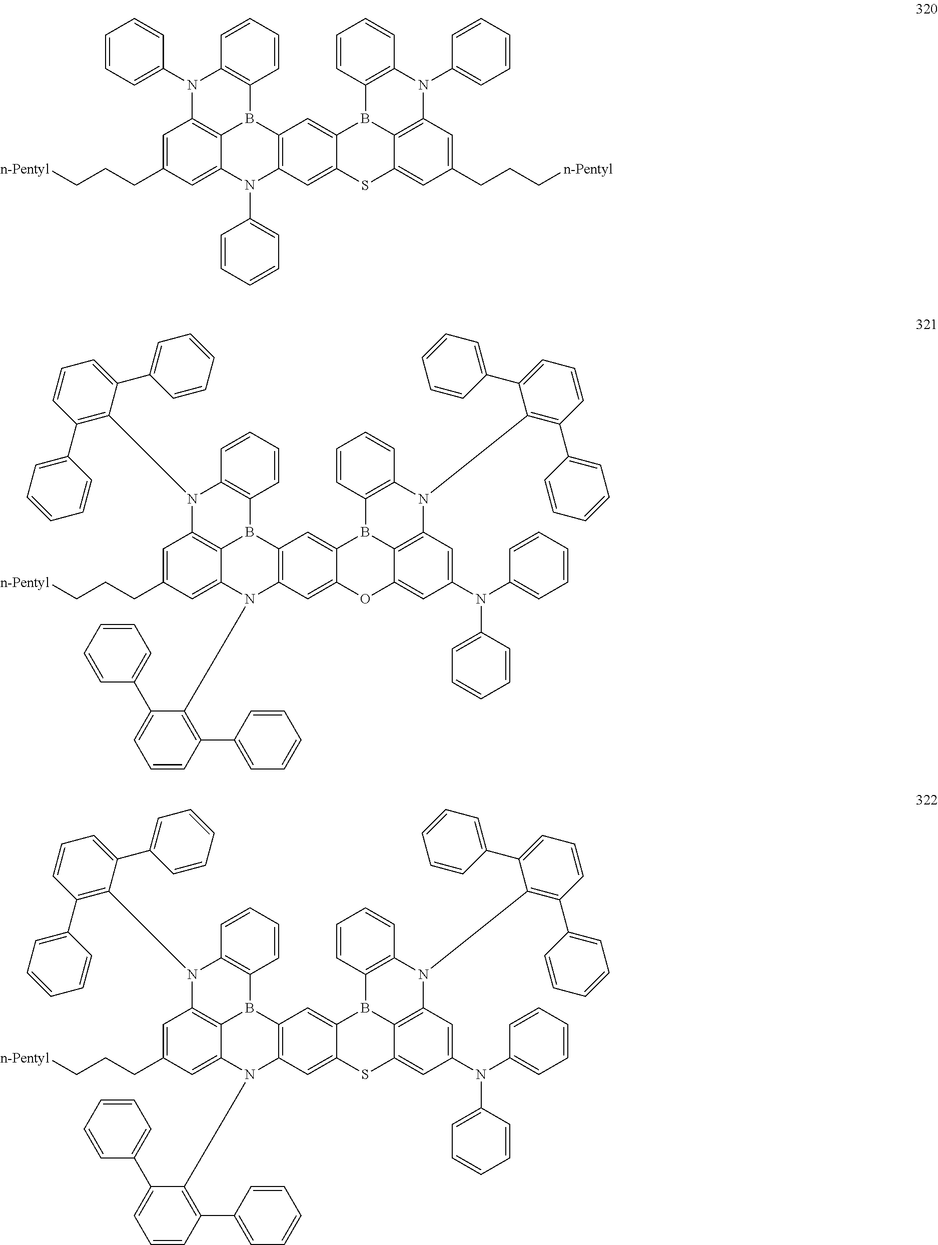

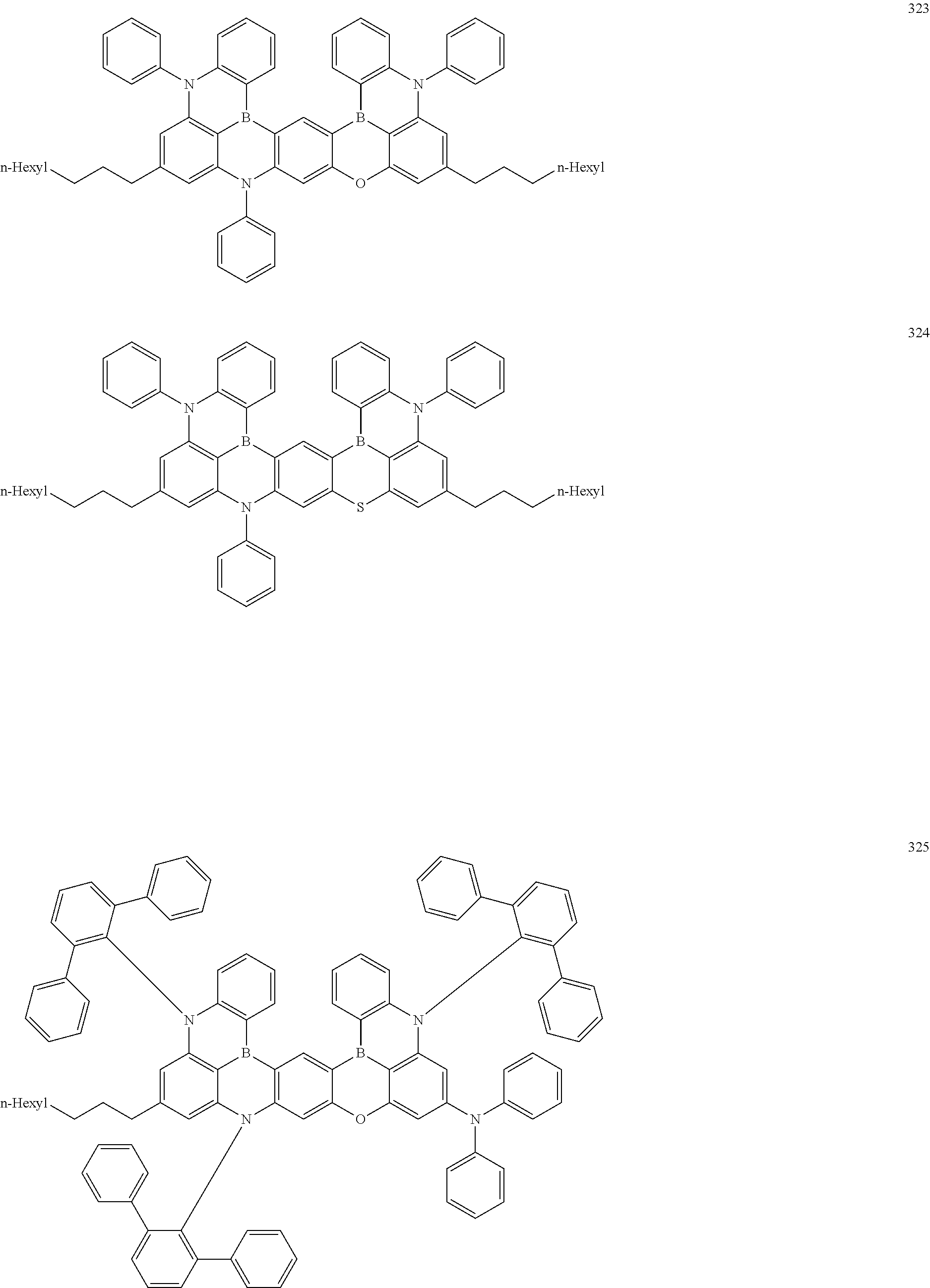

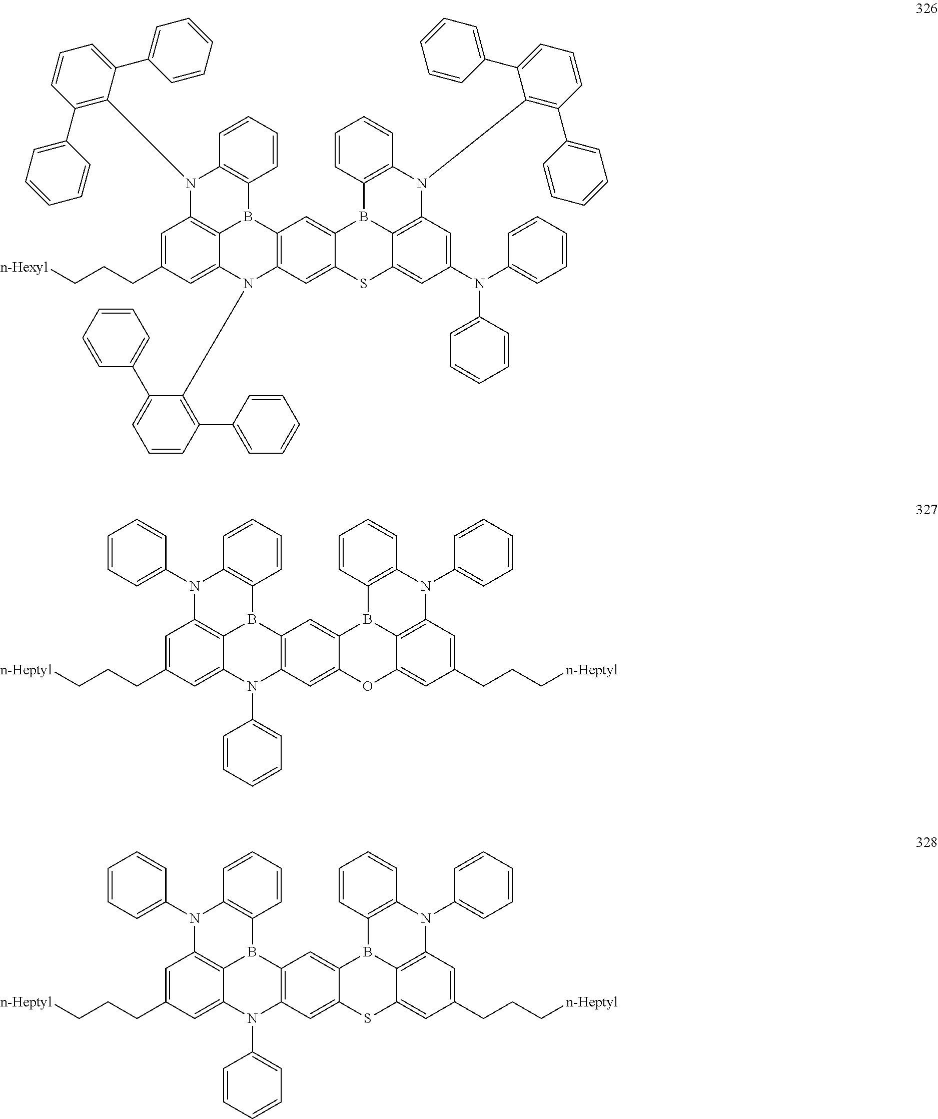

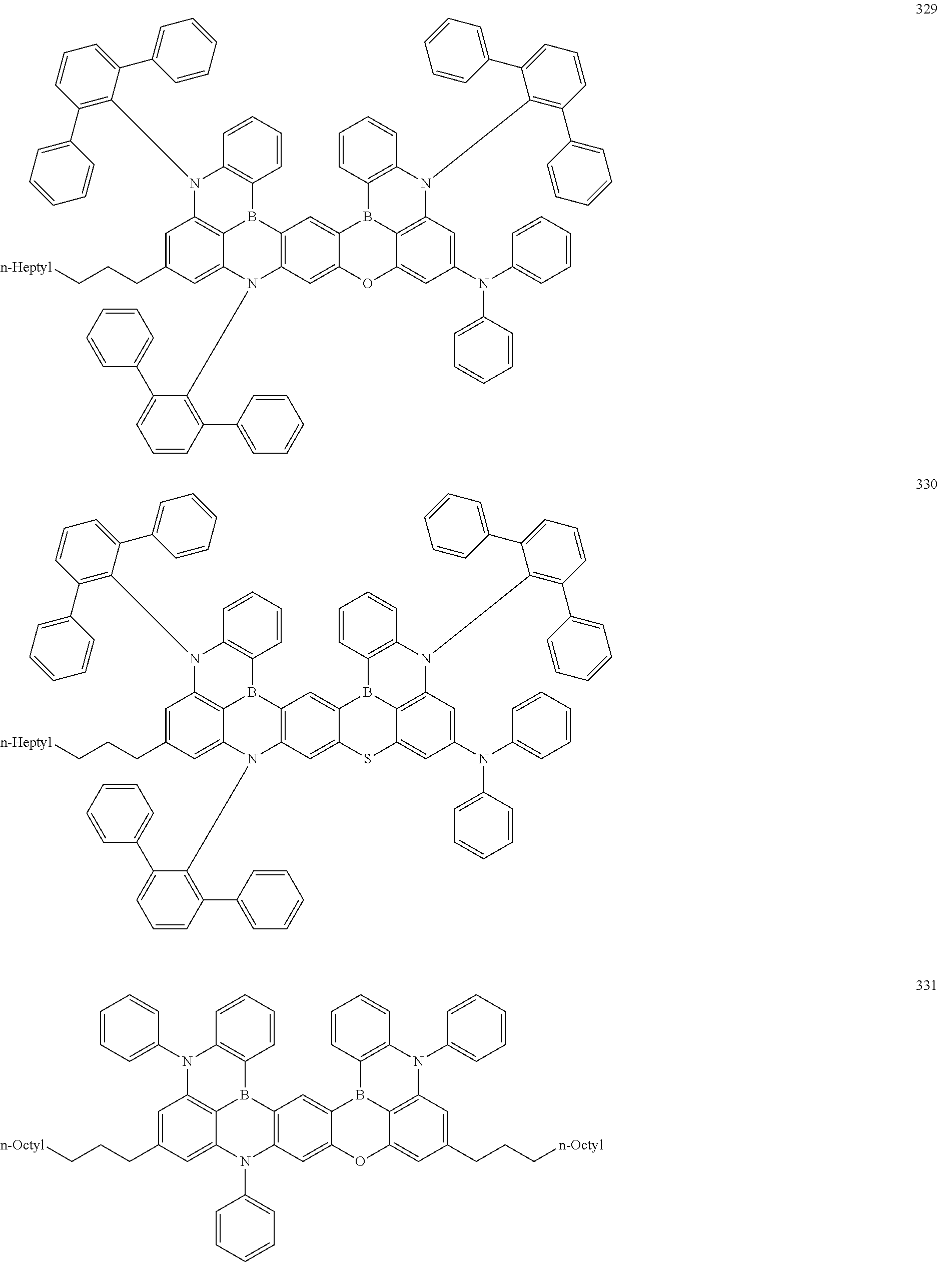

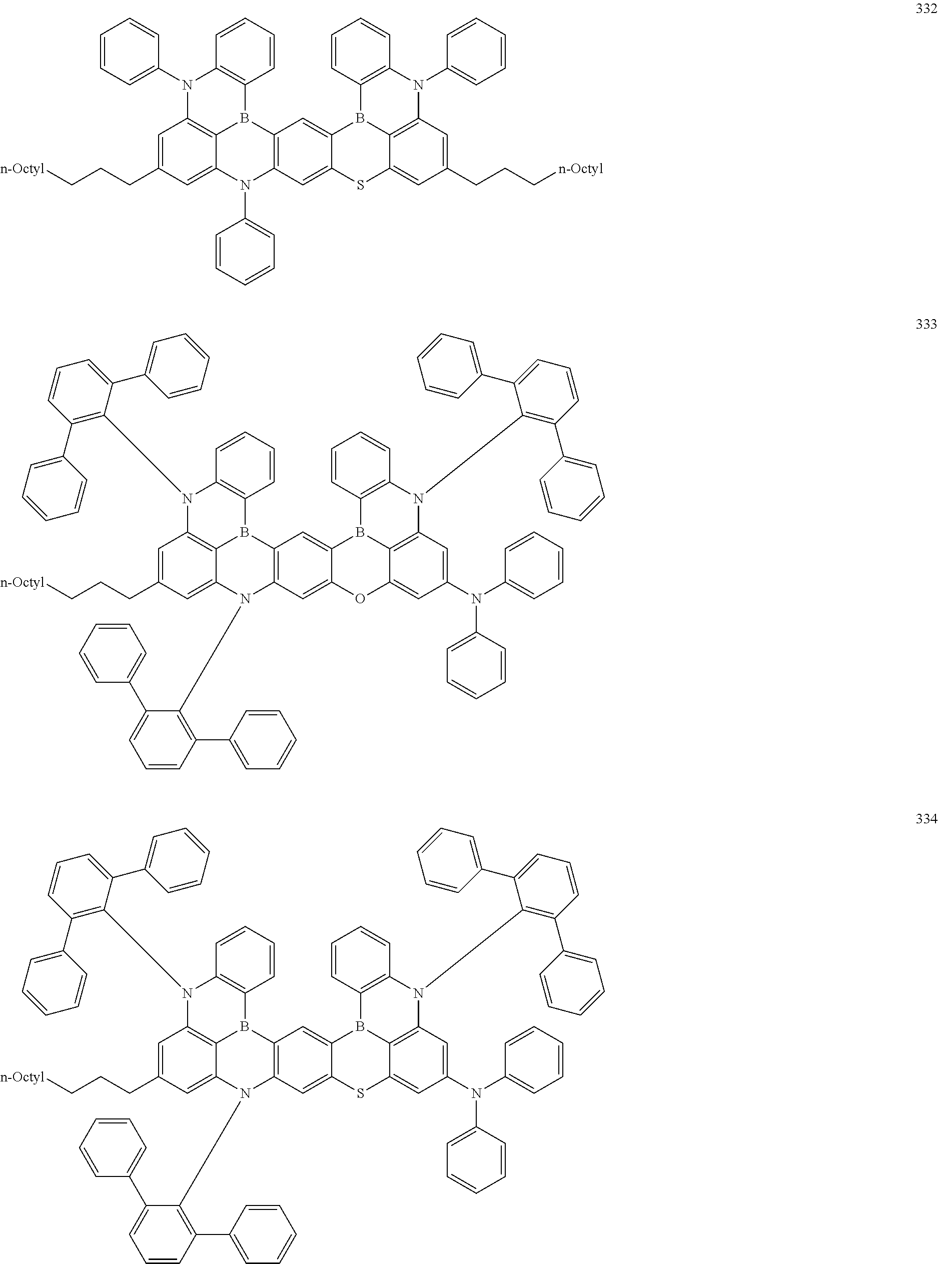

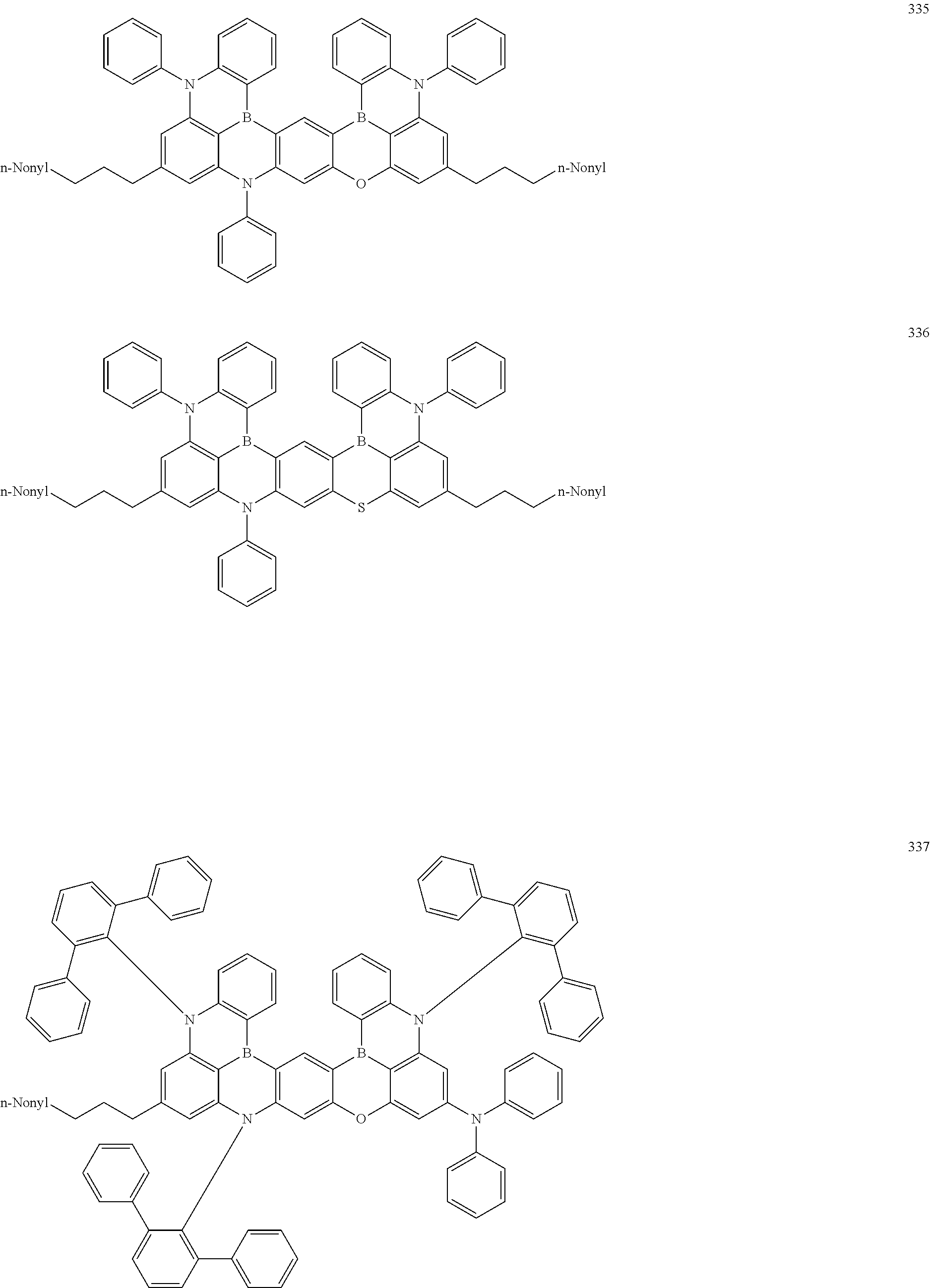

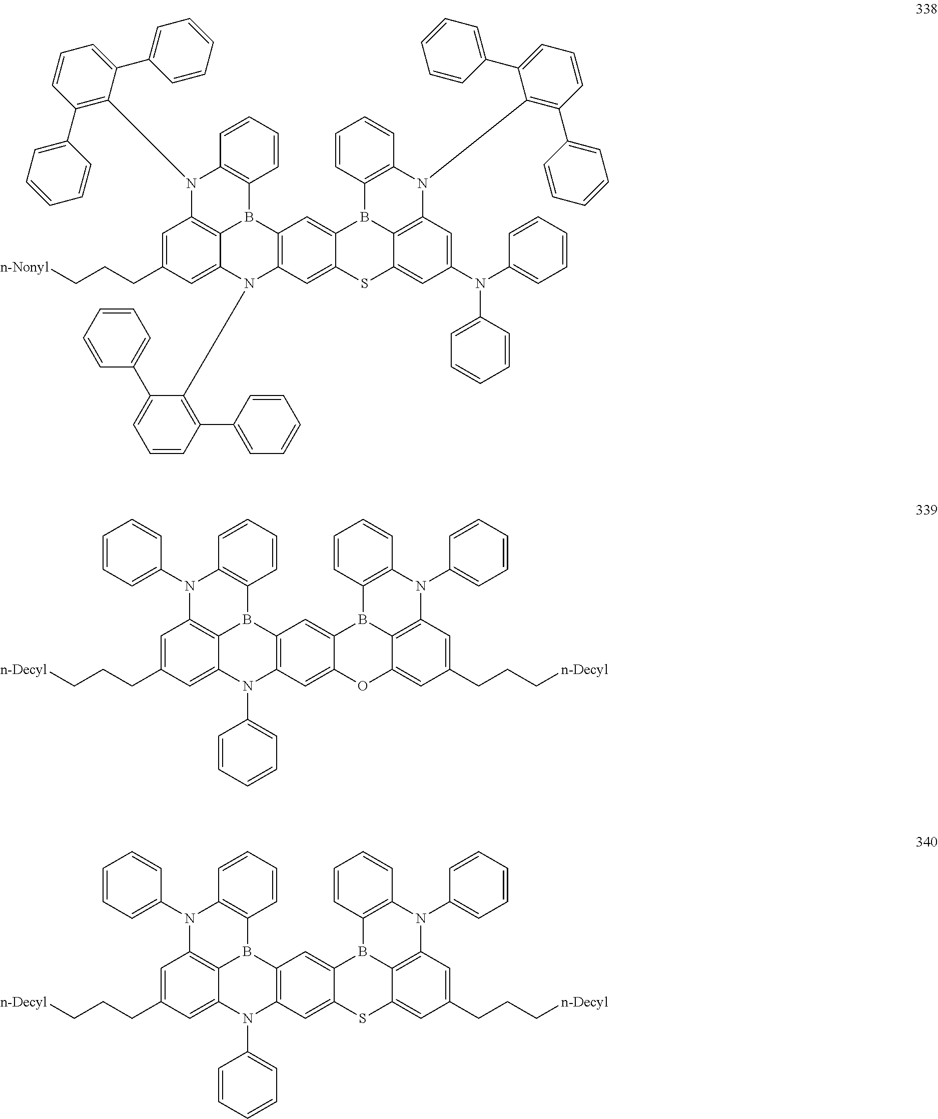

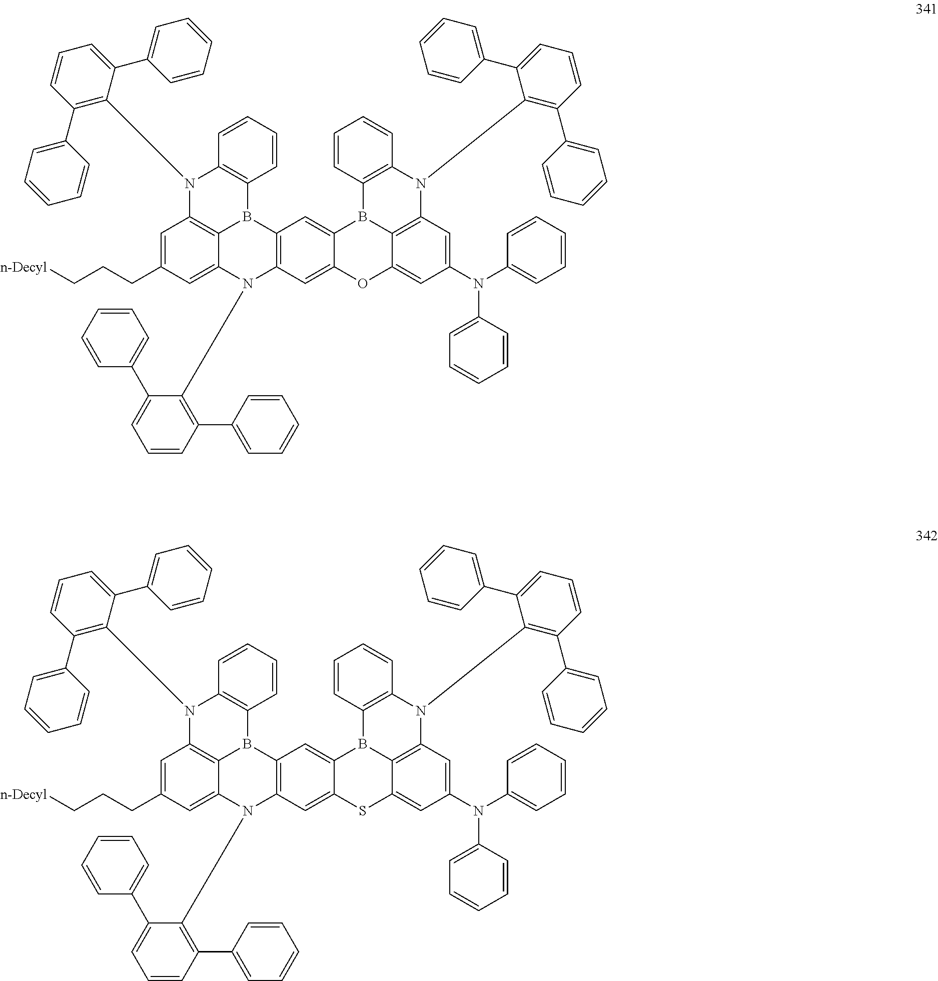

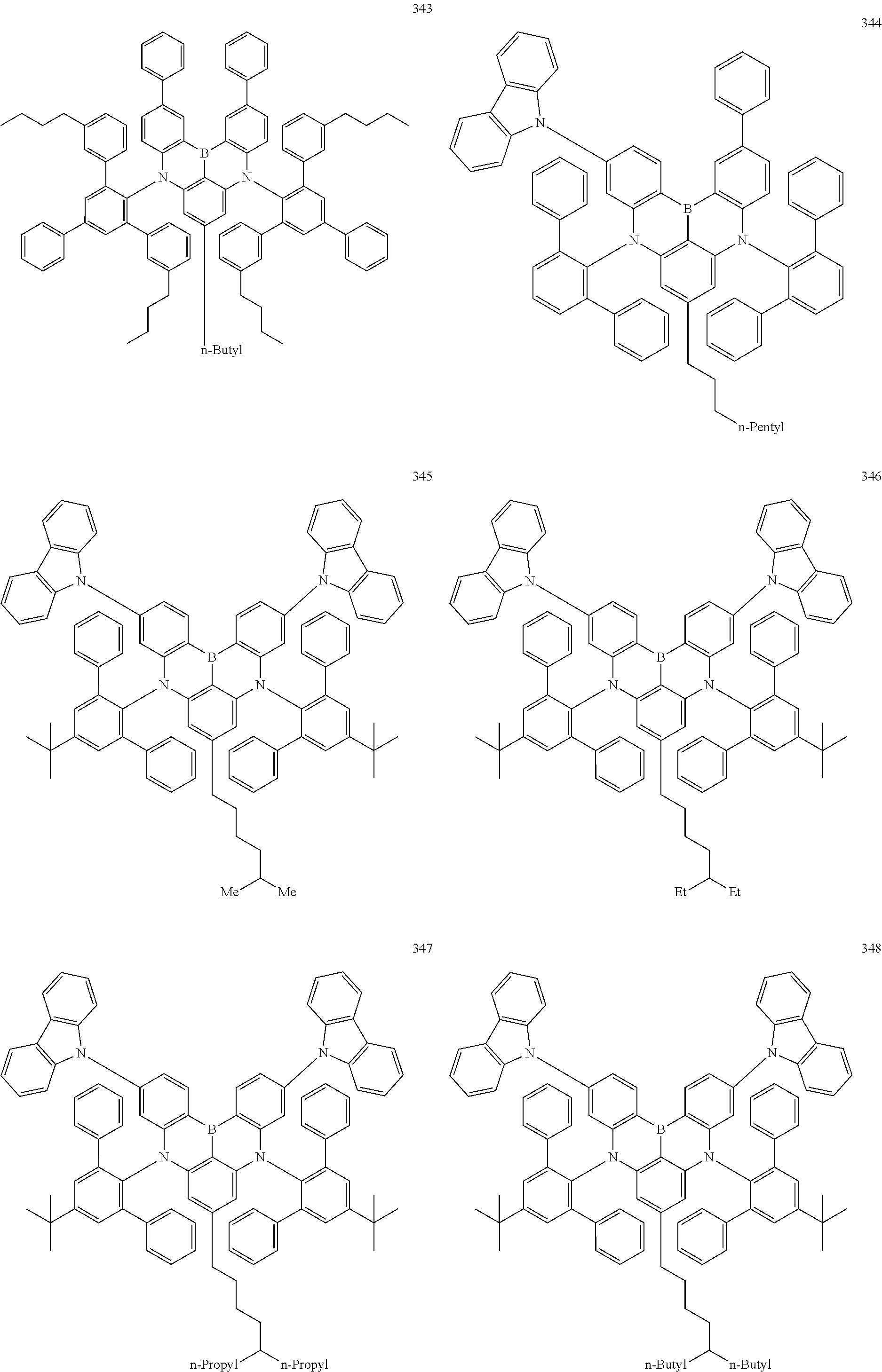

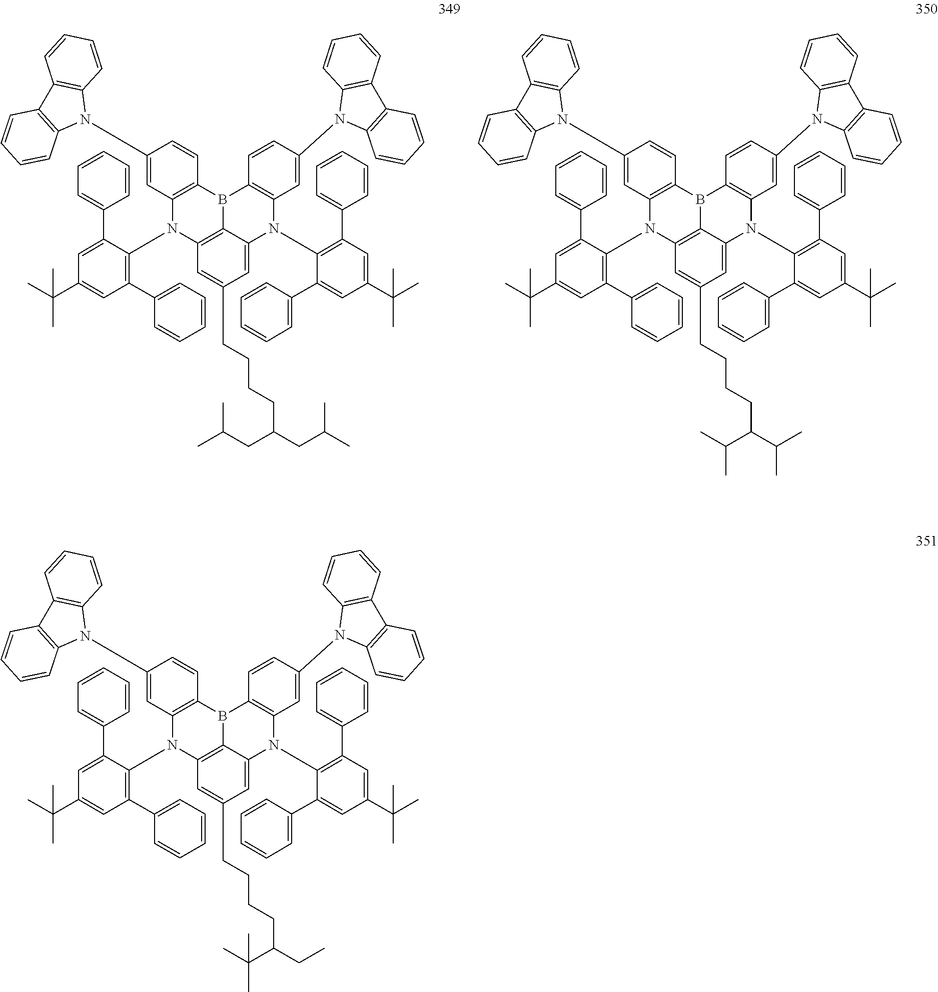

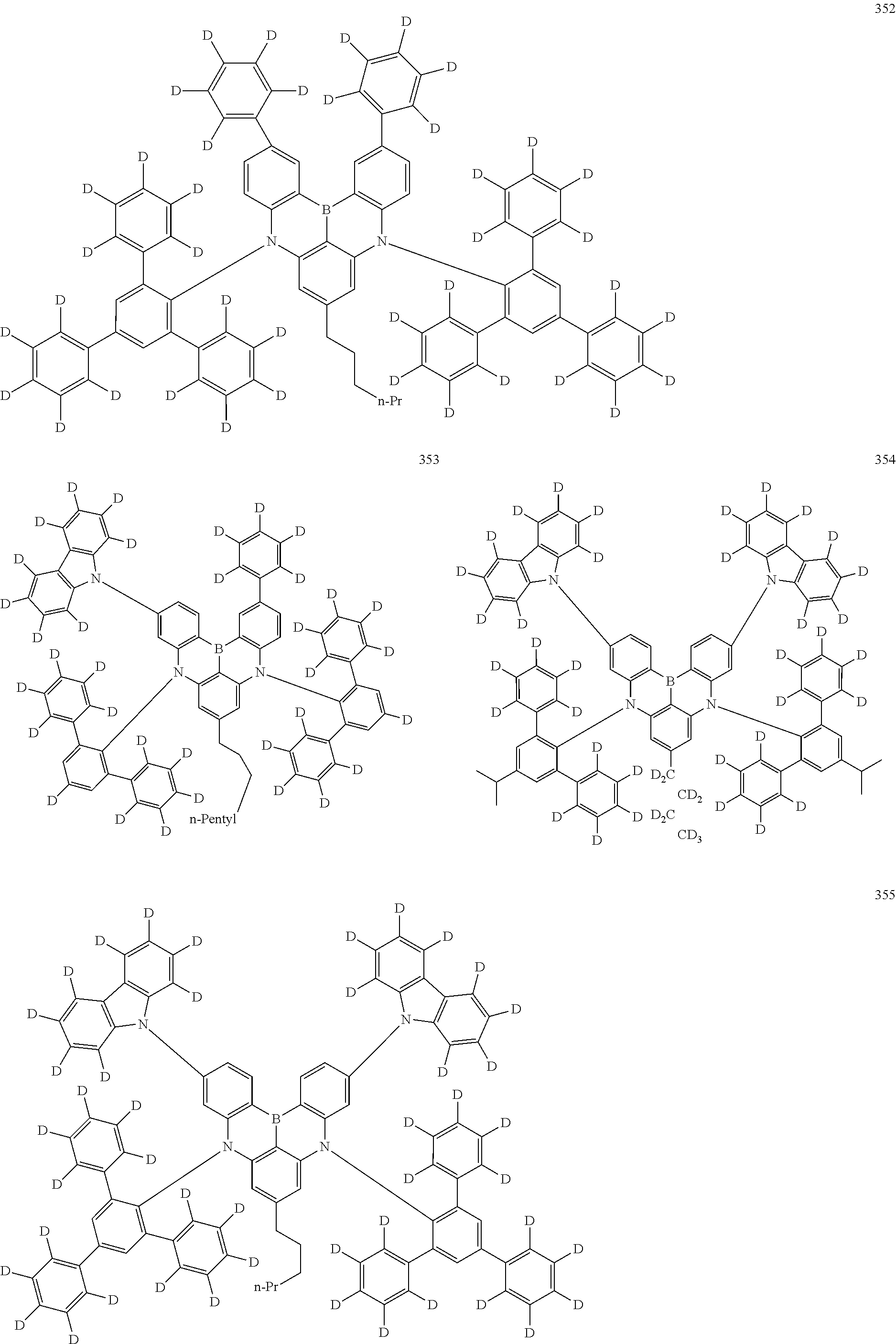

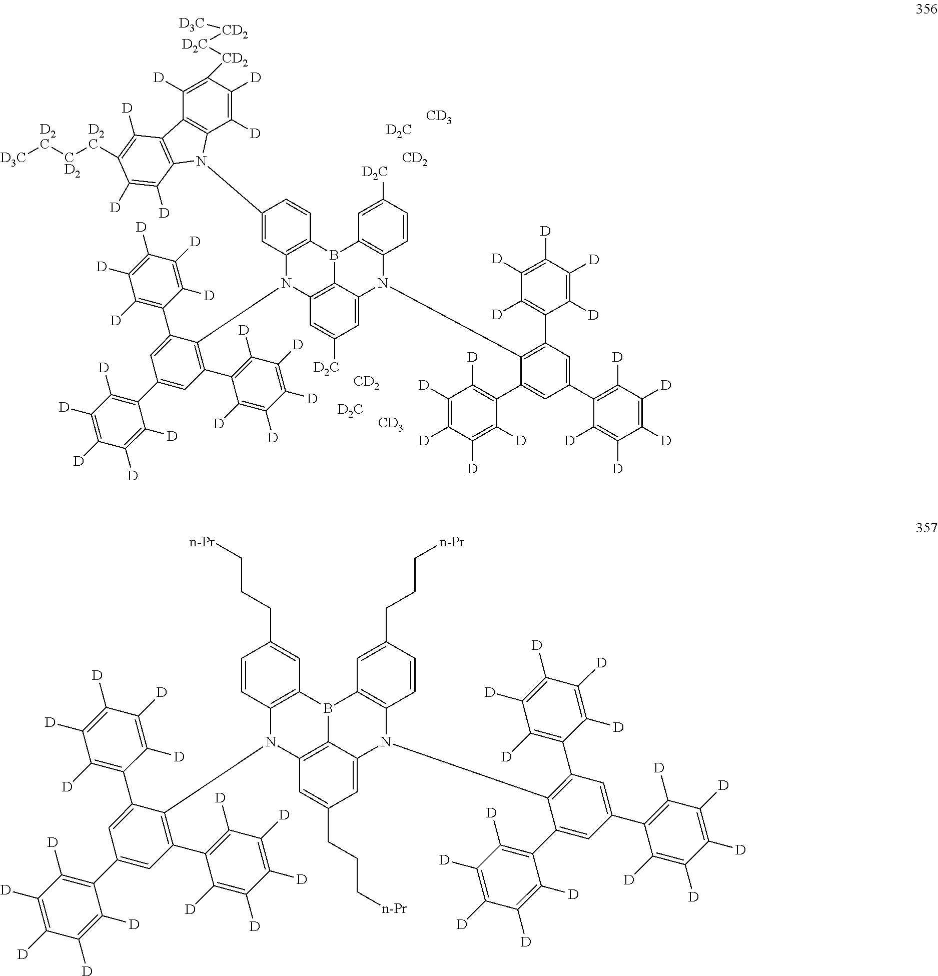

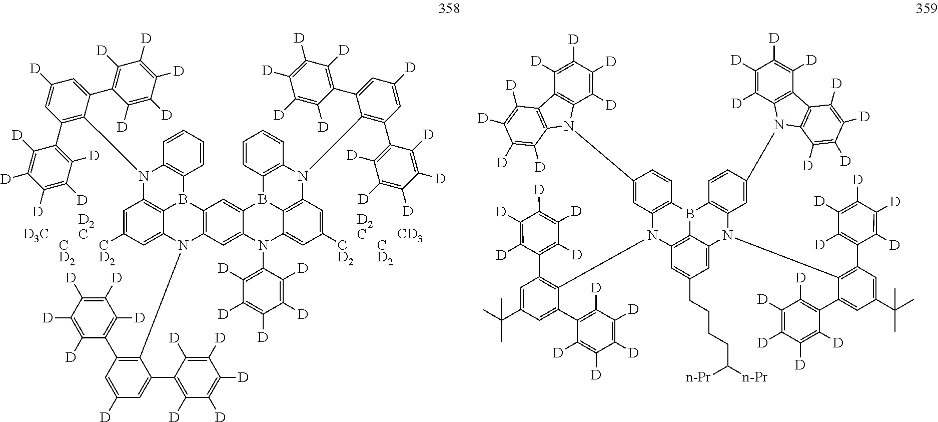

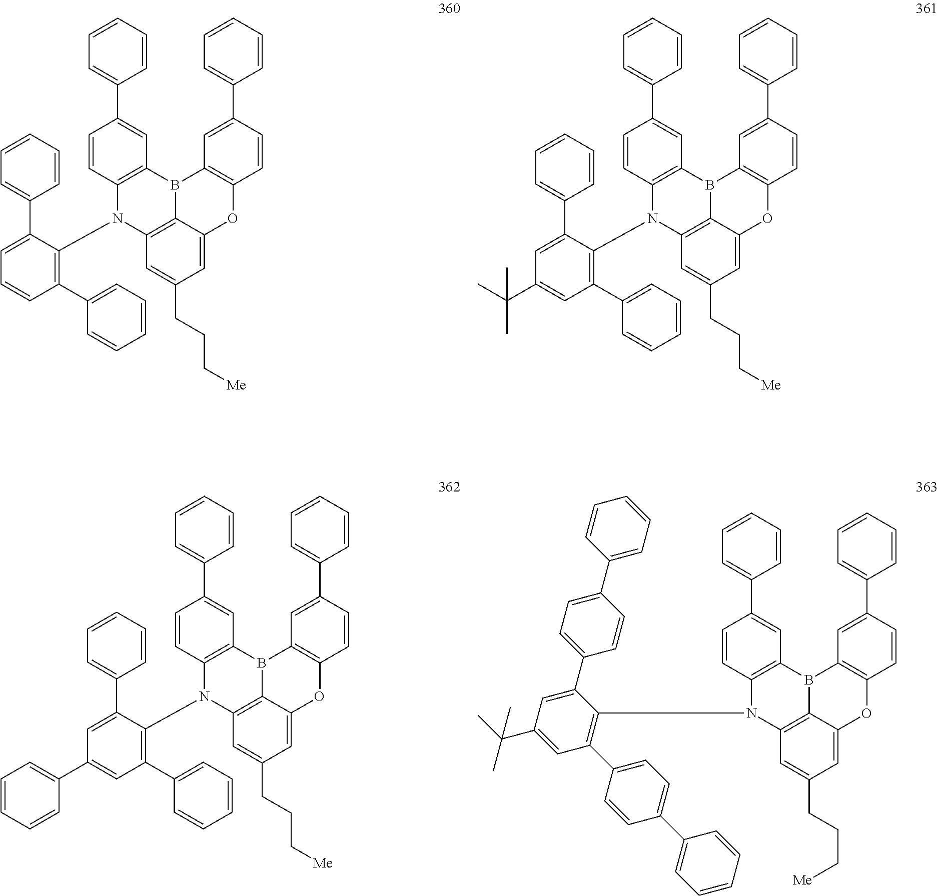 [SMILES: CCCCc1cc2c3c(c1)N(c1c(-c4ccccc4)cccc1-c1ccccc1)c1ccc(-c4ccccc4)cc1B3c1cc(-c3ccccc3)ccc1O2 ; CCCCc1cc2c3c(c1)N(c1c(-c4ccccc4)cc(C(C)(C)C)cc1-c1ccccc1)c1ccc(-c4ccccc4)cc1B3c1cc(-c3ccccc3)ccc1O2 ; CCCCc1cc2c3c(c1)N(c1c(-c4ccccc4)cc(-c4ccccc4)cc1-c1ccccc1)c1ccc(-c4ccccc4)cc1B3c1cc(-c3ccccc3)ccc1O2 ; CCCCc1cc2c3c(c1)N(c1c(-c4ccc(-c5ccccc5)cc4)cc(C(C)(C)C)cc1-c1ccc(-c4ccccc4)cc1)c1ccc(-c4ccccc4)cc1B3c1cc(-c3ccccc3)ccc1O2]

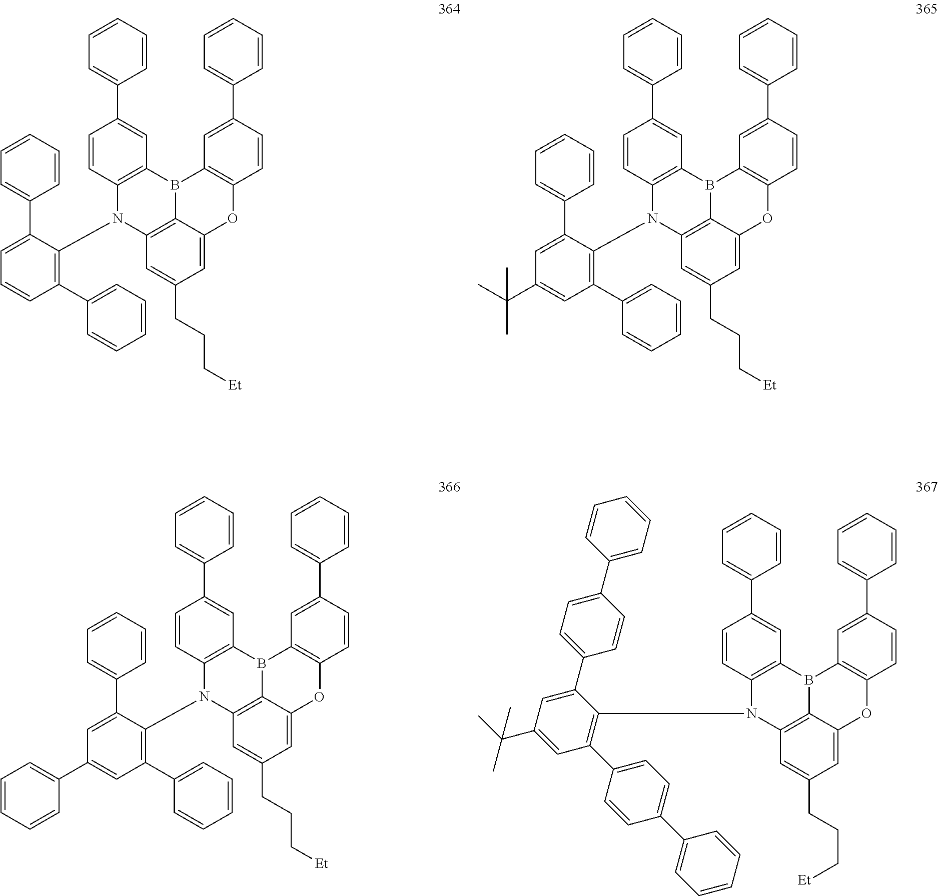 [SMILES: CCCCCc1cc2c3c(c1)N(c1c(-c4ccccc4)cccc1-c1ccccc1)c1ccc(-c4ccccc4)cc1B3c1cc(-c3ccccc3)ccc1O2 ; CCCCCc1cc2c3c(c1)N(c1c(-c4ccccc4)cc(C(C)(C)C)cc1-c1ccccc1)c1ccc(-c4ccccc4)cc1B3c1cc(-c3ccccc3)ccc1O2 ; CCCCCc1cc2c3c(c1)N(c1c(-c4ccccc4)cc(-c4ccccc4)cc1-c1ccccc1)c1ccc(-c4ccccc4)cc1B3c1cc(-c3ccccc3)ccc1O2 ; CCCCCc1cc2c3c(c1)N(c1c(-c4ccc(-c5ccccc5)cc4)cc(C(C)(C)C)cc1-c1ccc(-c4ccccc4)cc1)c1ccc(-c4ccccc4)cc1B3c1cc(-c3ccccc3)ccc1O2]

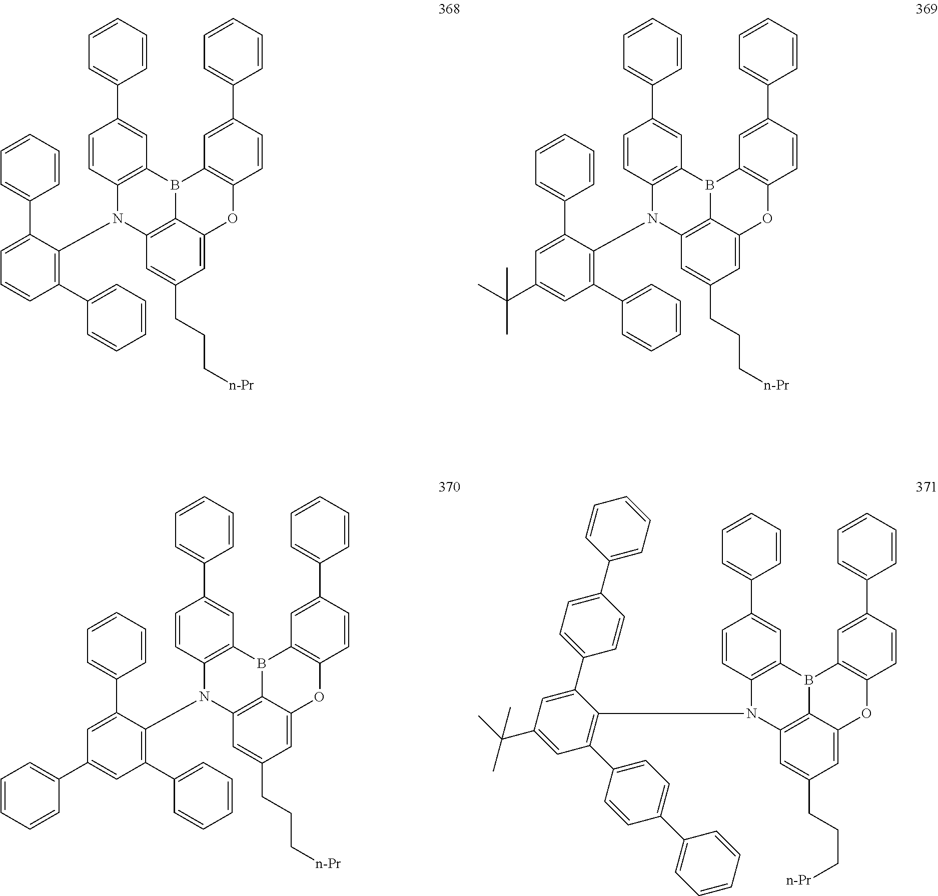

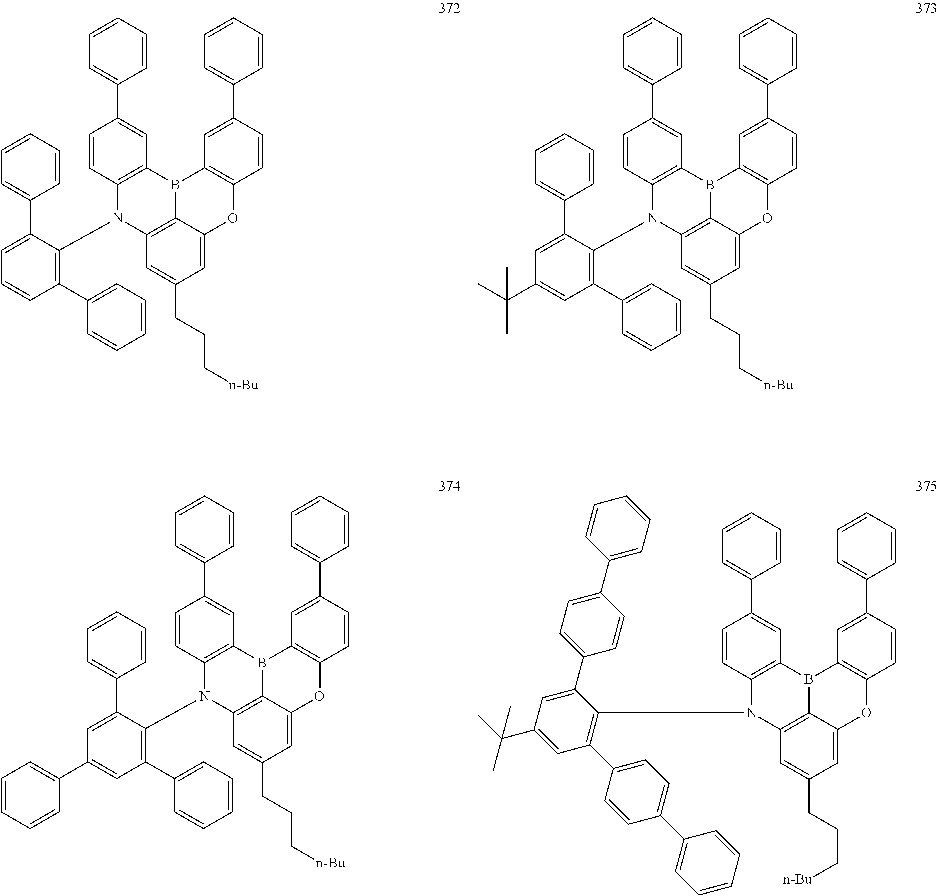

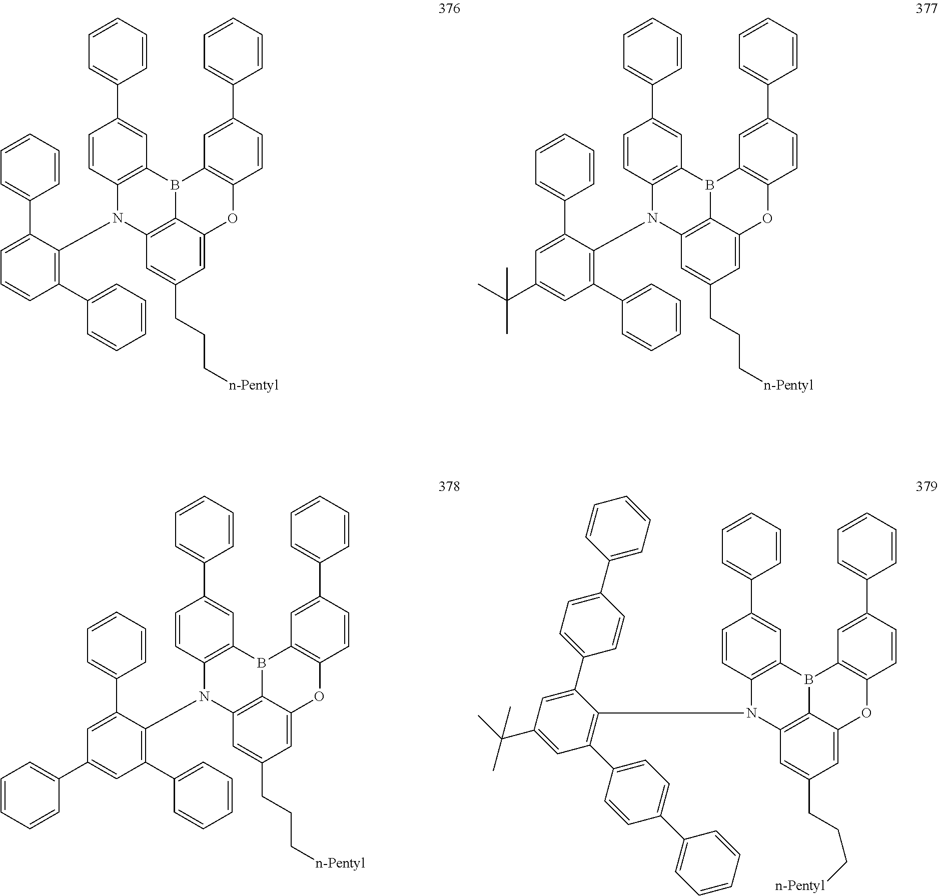

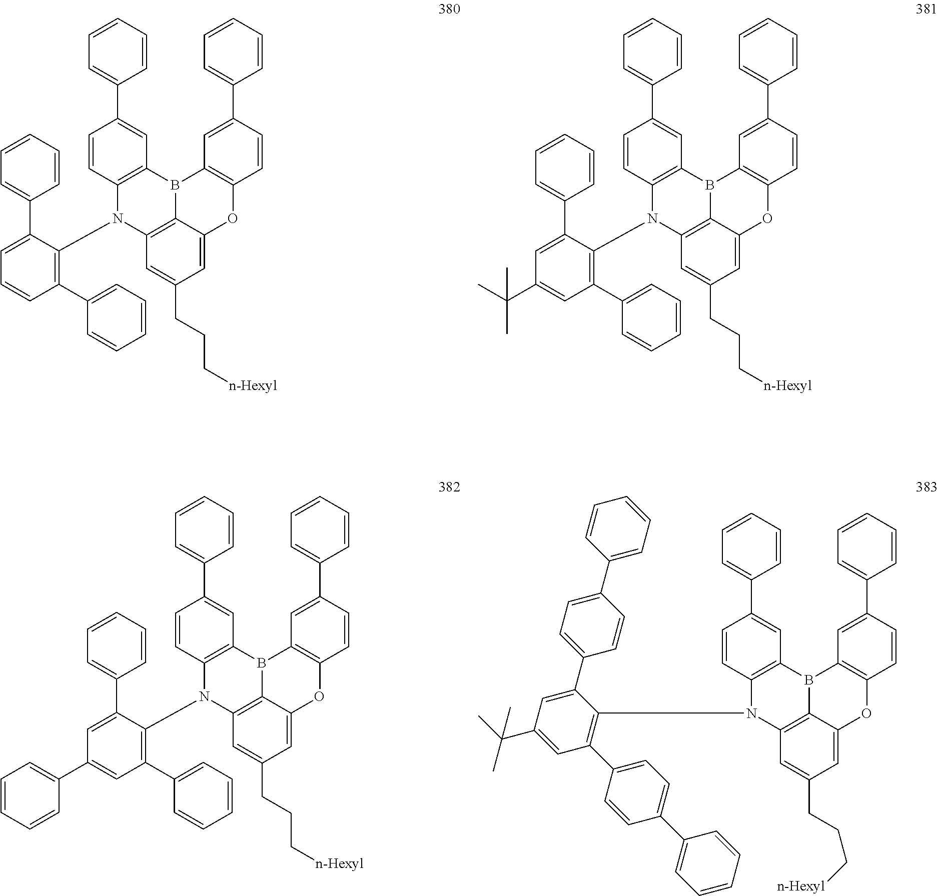

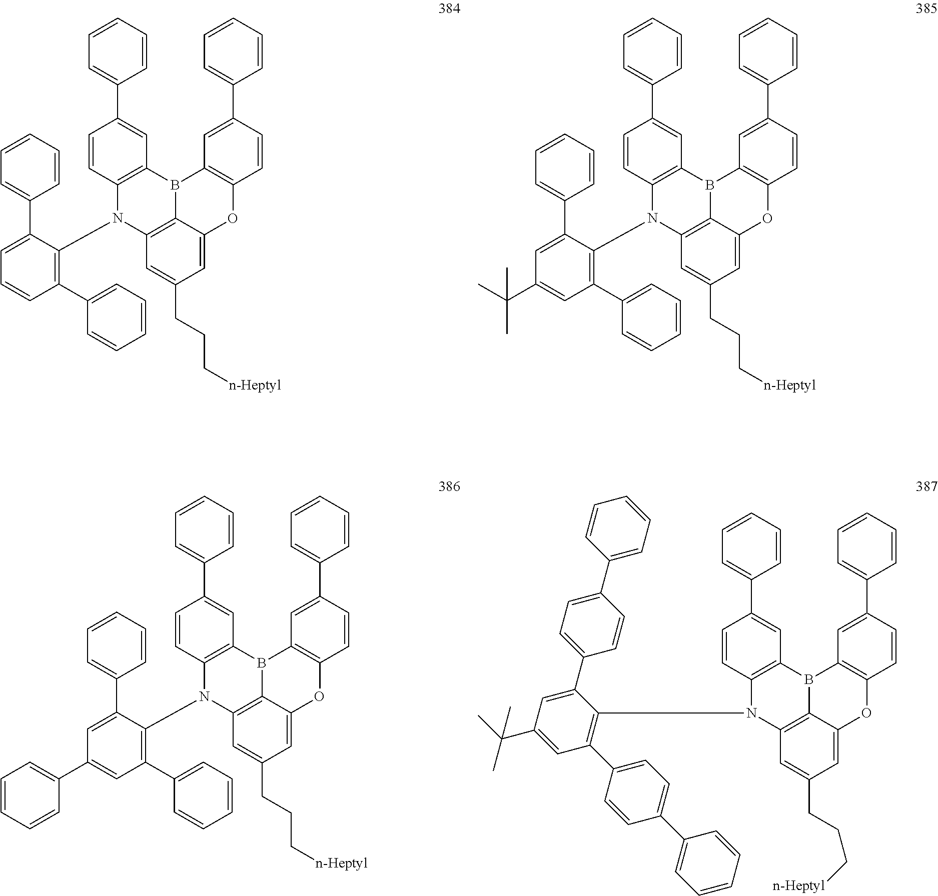

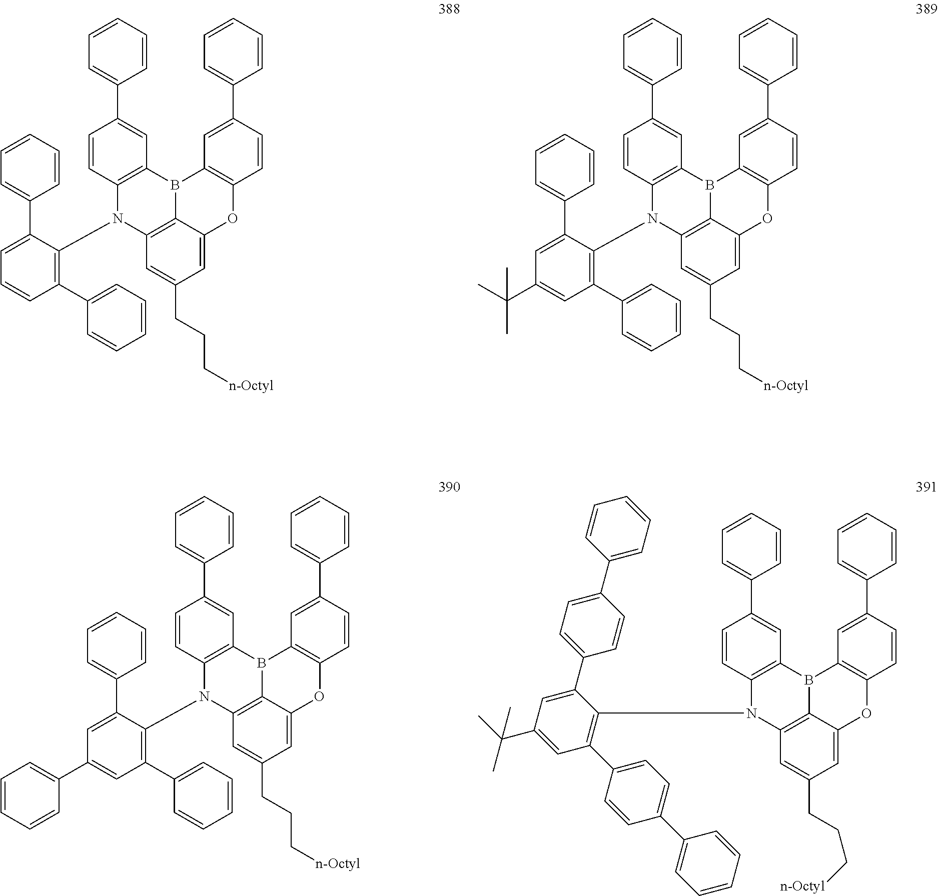

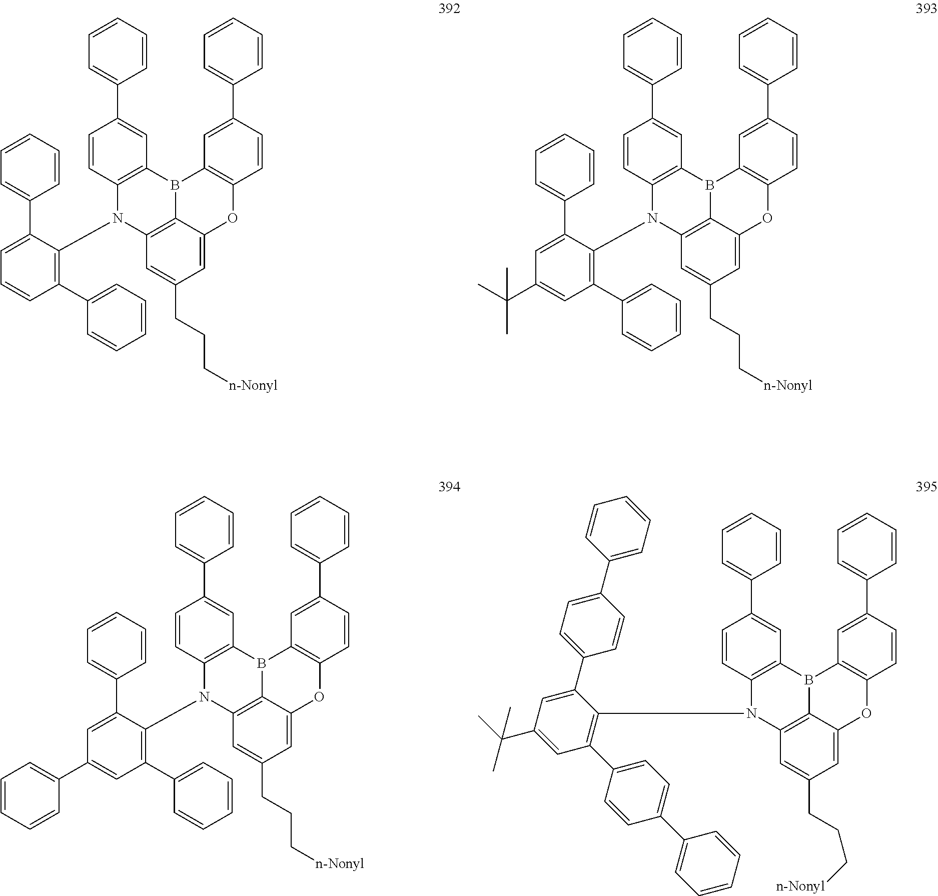

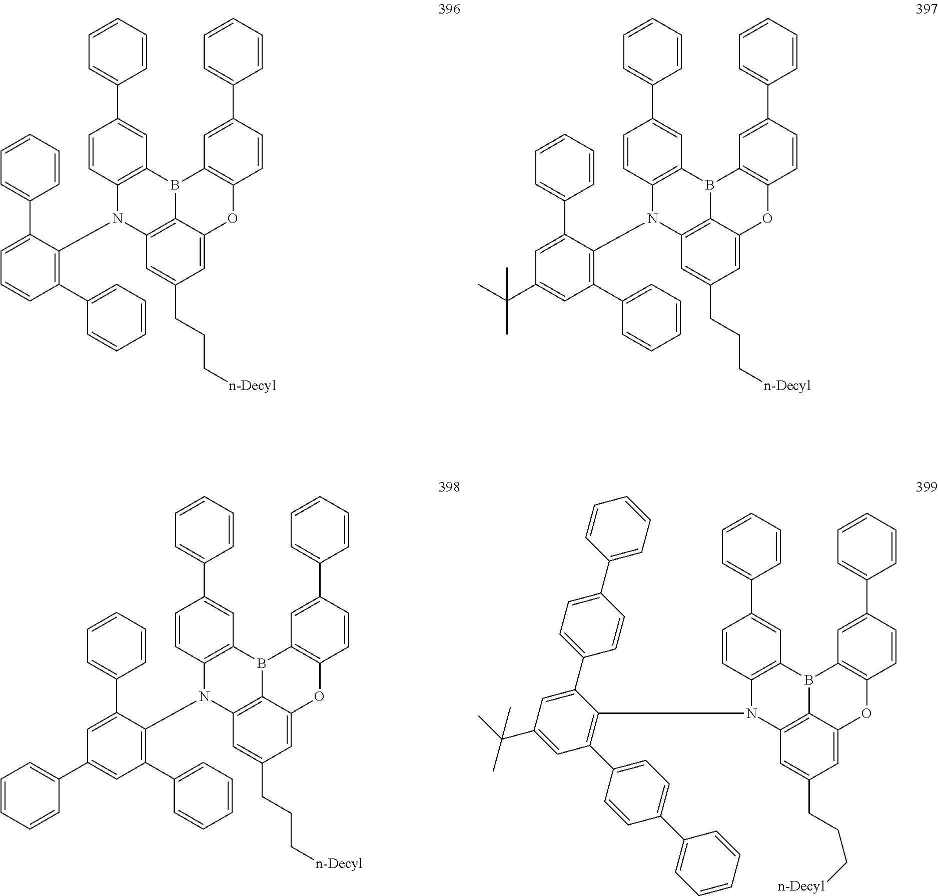

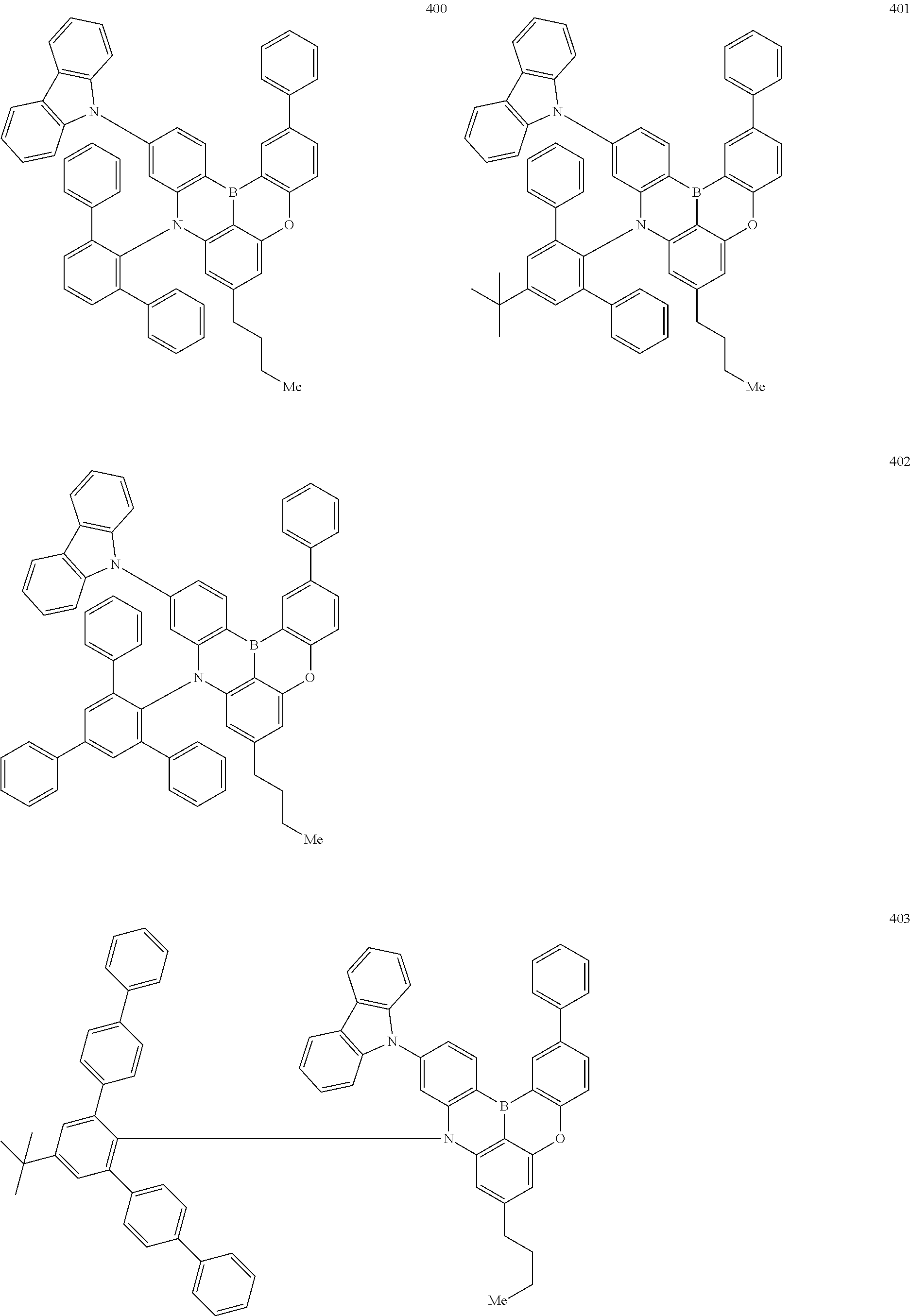 [SMILES: CCCCc1cc2c3c(c1)N(c1c(-c4ccccc4)cccc1-c1ccccc1)c1cc(-n4c5ccccc5c5ccccc54)ccc1B3c1cc(-c3ccccc3)ccc1O2 ; CCCCc1cc2c3c(c1)N(c1c(-c4ccccc4)cc(C(C)(C)C)cc1-c1ccccc1)c1cc(-n4c5ccccc5c5ccccc54)ccc1B3c1cc(-c3ccccc3)ccc1O2 ; CCCCc1cc2c3c(c1)N(c1c(-c4ccccc4)cc(-c4ccccc4)cc1-c1ccccc1)c1cc(-n4c5ccccc5c5ccccc54)ccc1B3c1cc(-c3ccccc3)ccc1O2 ; CCCCc1cc2c3c(c1)N(c1c(-c4ccc(-c5ccccc5)cc4)cc(C(C)(C)C)cc1-c1ccc(-c4ccccc4)cc1)c1cc(-n4c5ccccc5c5ccccc54)ccc1B3c1cc(-c3ccccc3)ccc1O2]

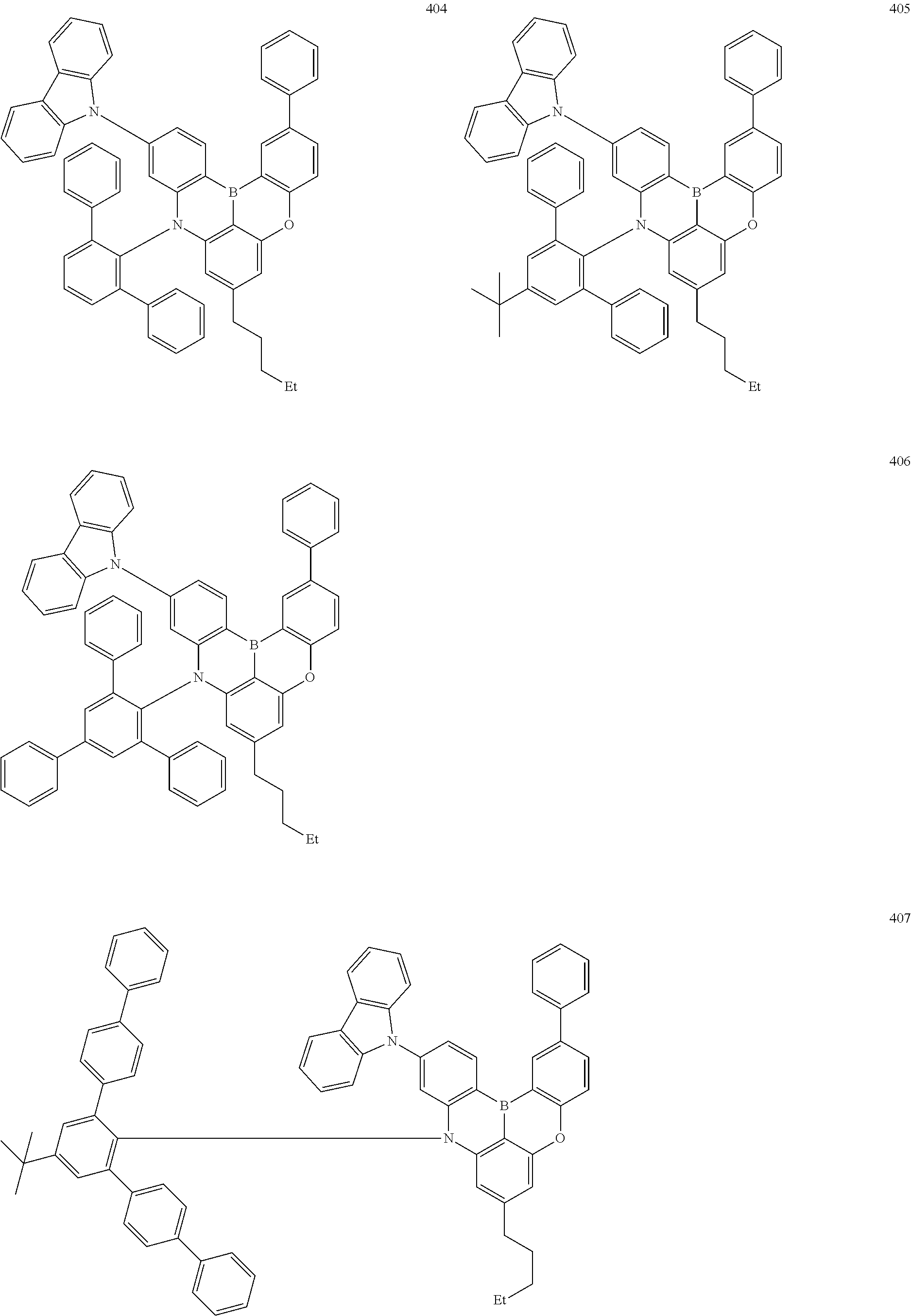 [SMILES: CCCCCc1cc2c3c(c1)N(c1c(-c4ccccc4)cccc1-c1ccccc1)c1cc(-n4c5ccccc5c5ccccc54)ccc1B3c1cc(-c3ccccc3)ccc1O2 ; CCCCCc1cc2c3c(c1)N(c1c(-c4ccccc4)cc(C(C)(C)C)cc1-c1ccccc1)c1cc(-n4c5ccccc5c5ccccc54)ccc1B3c1cc(-c3ccccc3)ccc1O2 ; CCCCCc1cc2c3c(c1)N(c1c(-c4ccccc4)cc(-c4ccccc4)cc1-c1ccccc1)c1cc(-n4c5ccccc5c5ccccc54)ccc1B3c1cc(-c3ccccc3)ccc1O2 ; CCCCCc1cc2c3c(c1)N(c1c(-c4ccc(-c5ccccc5)cc4)cc(C(C)(C)C)cc1-c1ccc(-c4ccccc4)cc1)c1cc(-n4c5ccccc5c5ccccc54)ccc1B3c1cc(-c3ccccc3)ccc1O2]

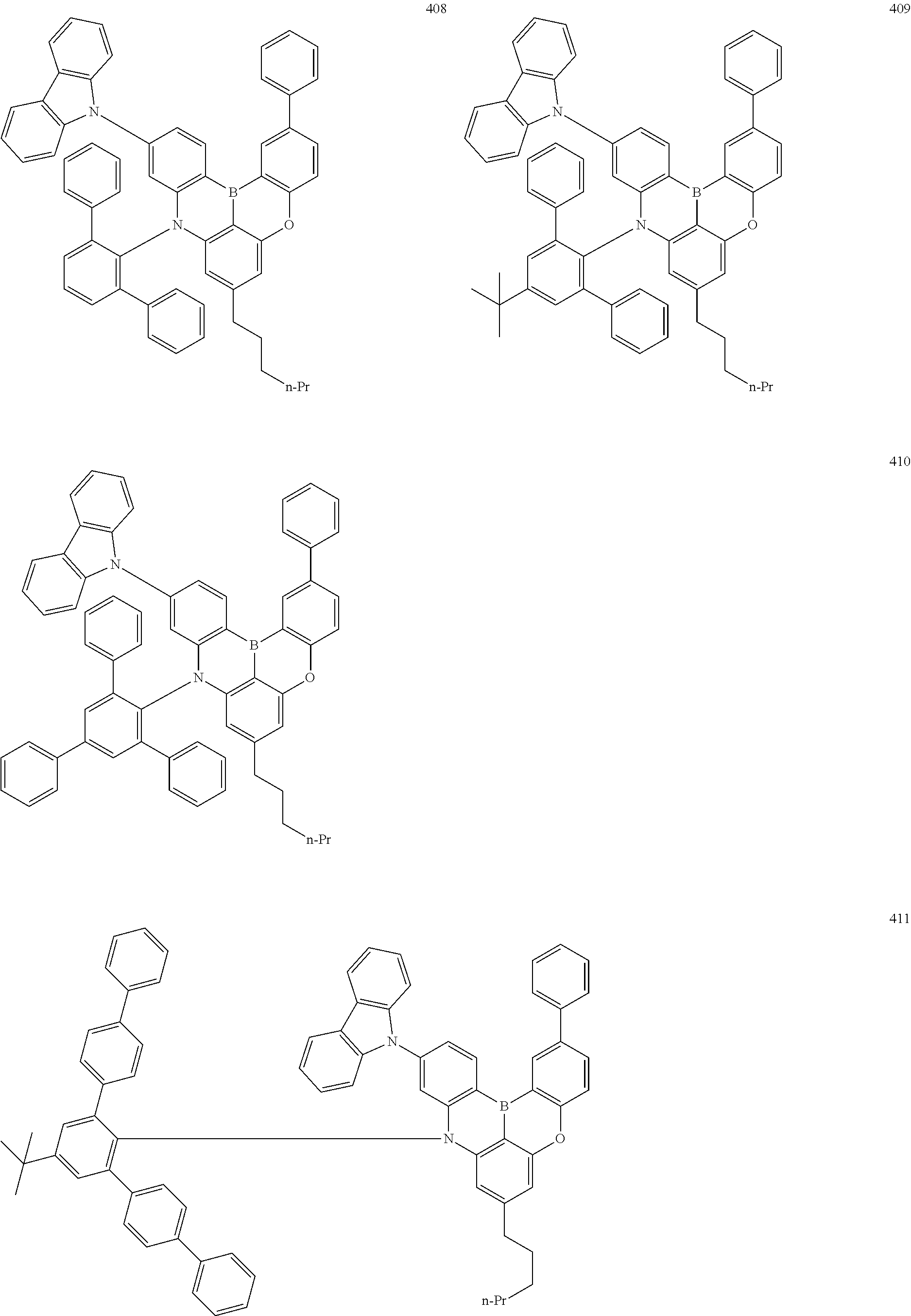

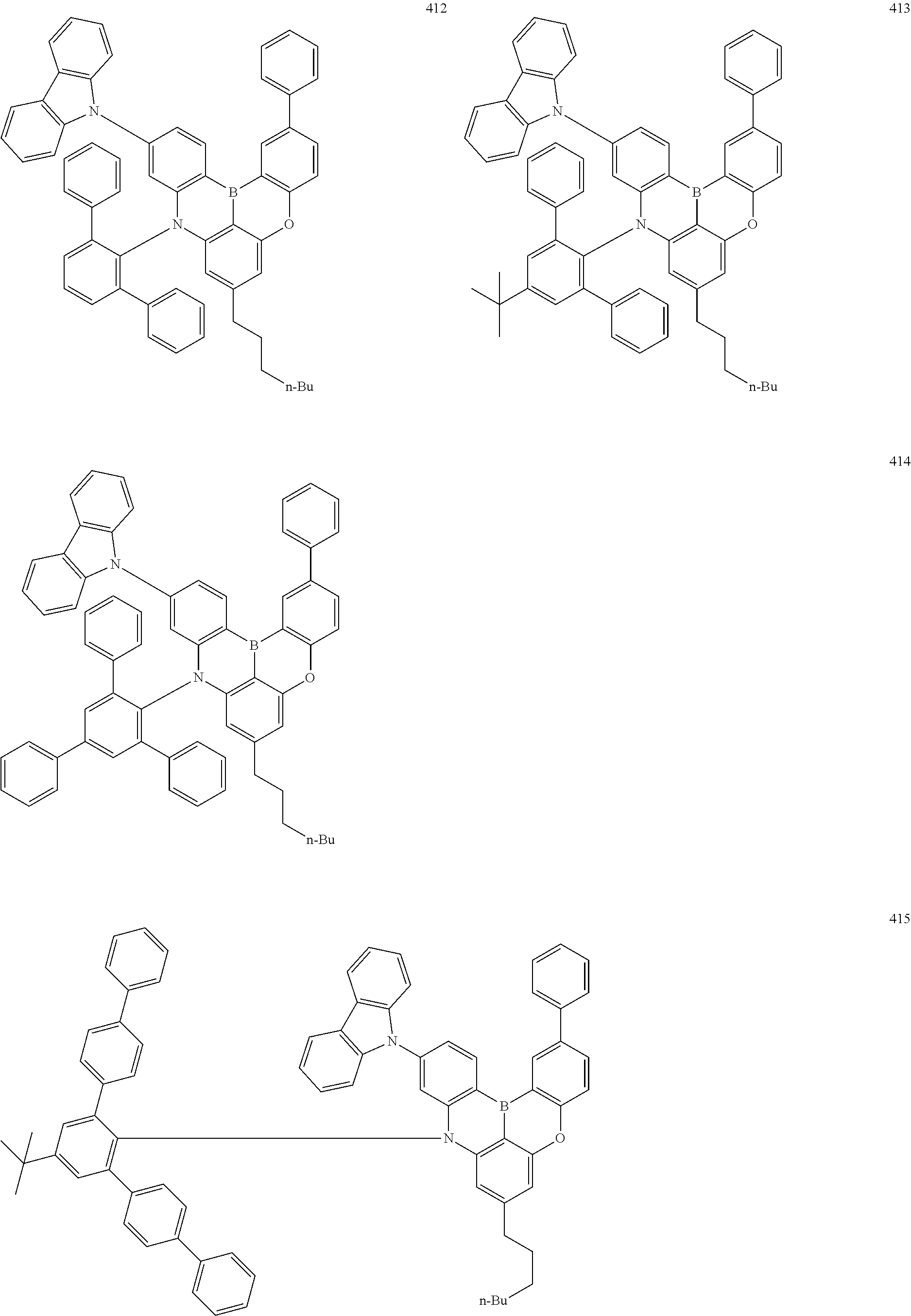

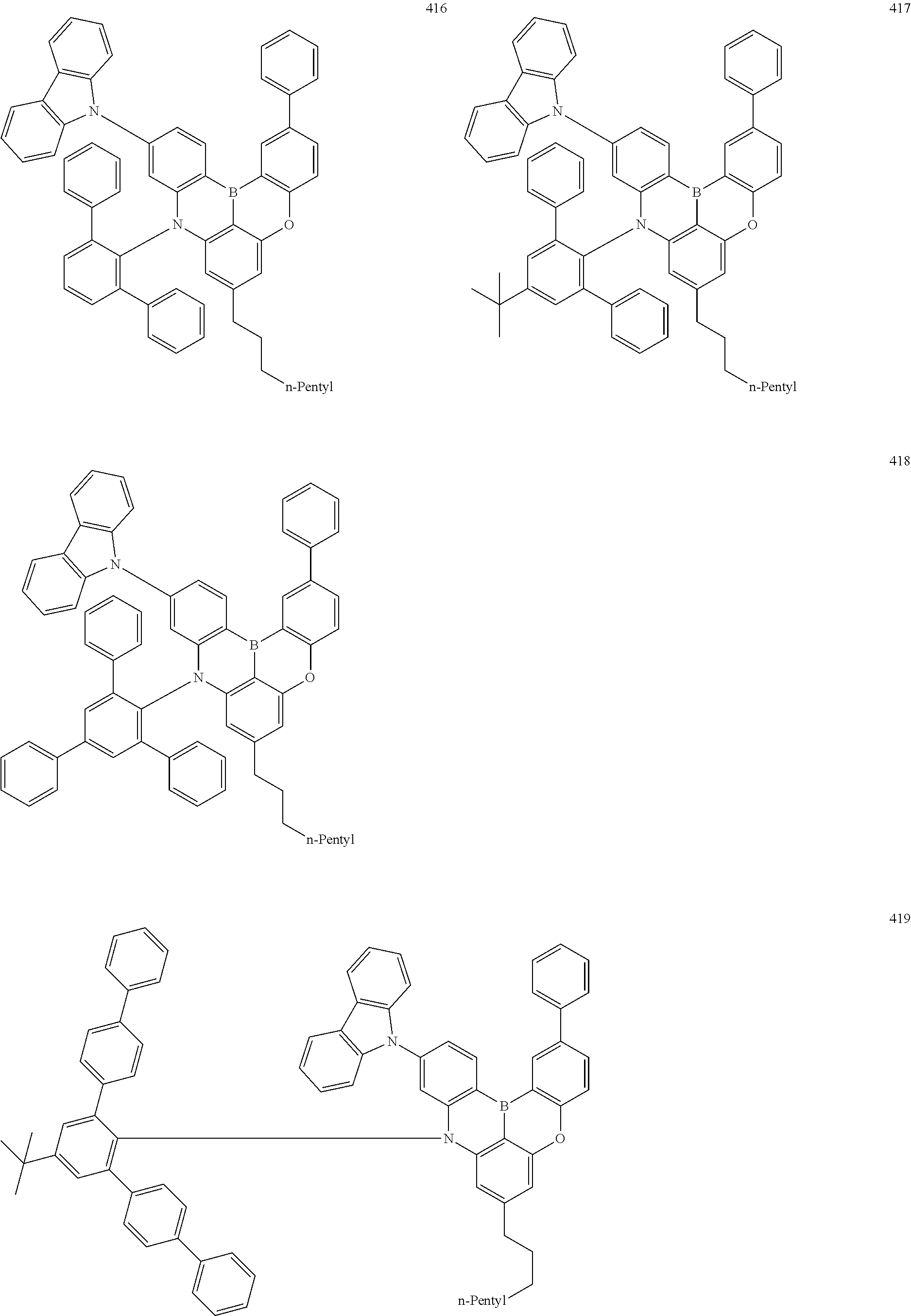

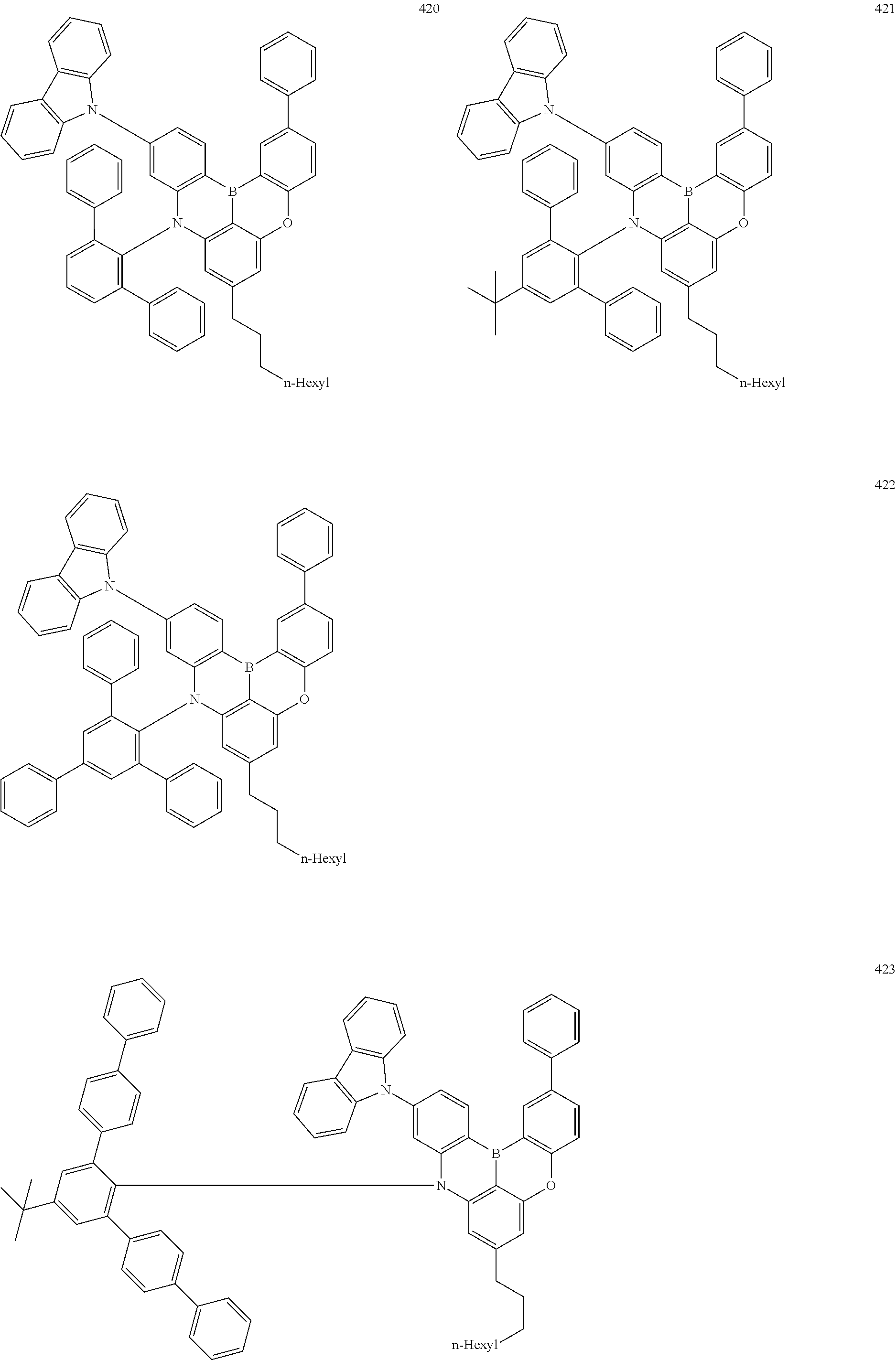

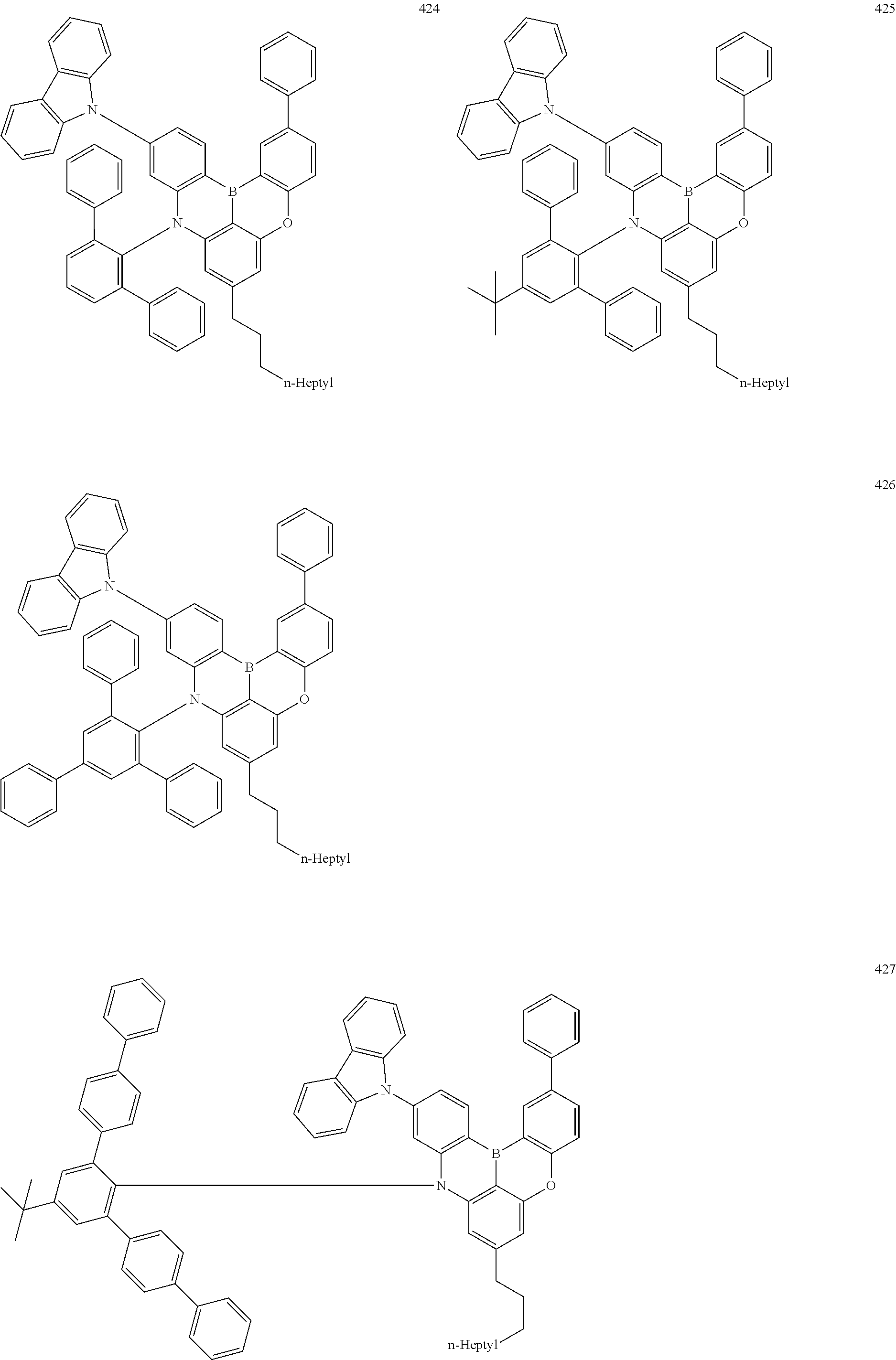

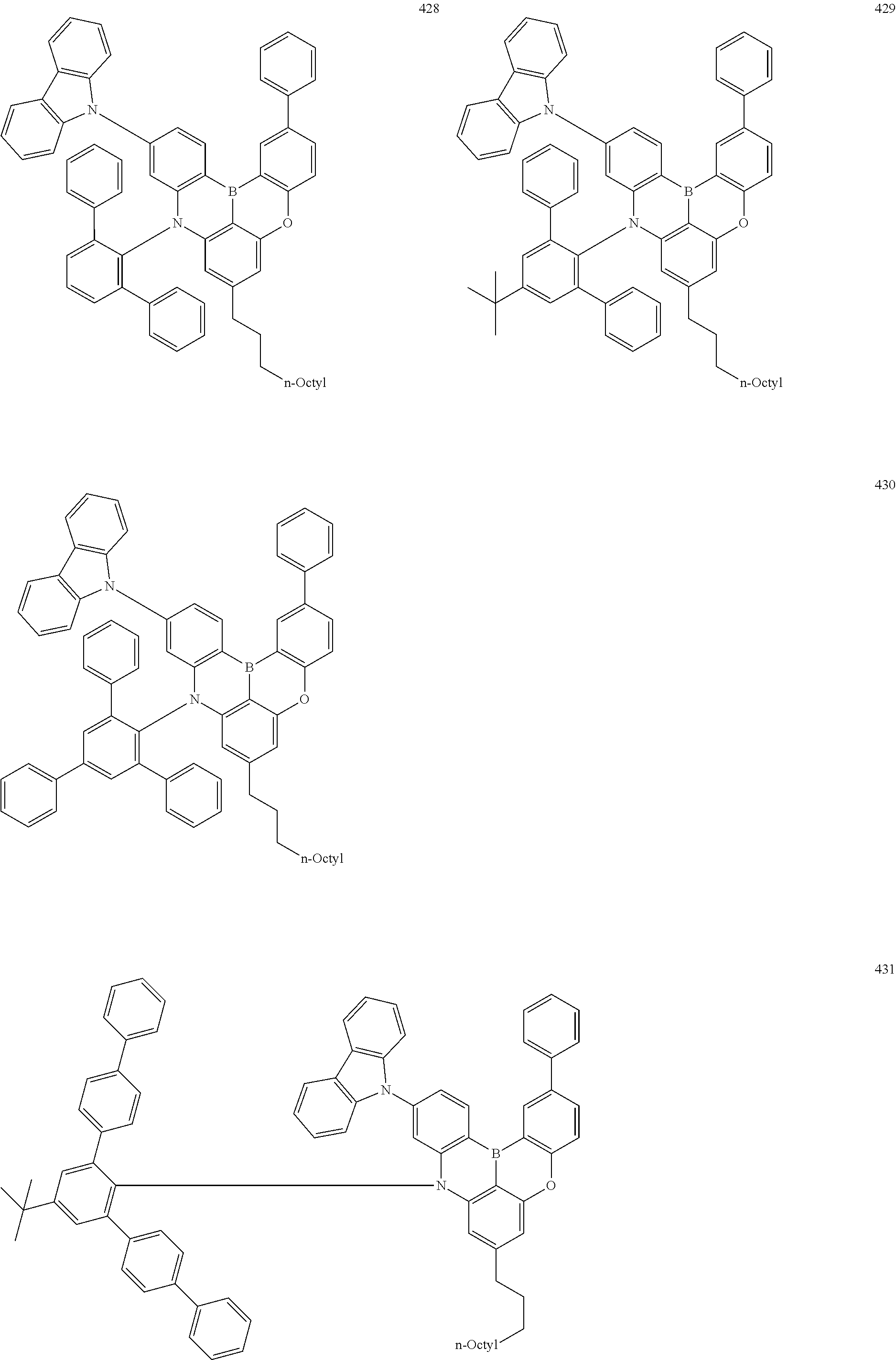

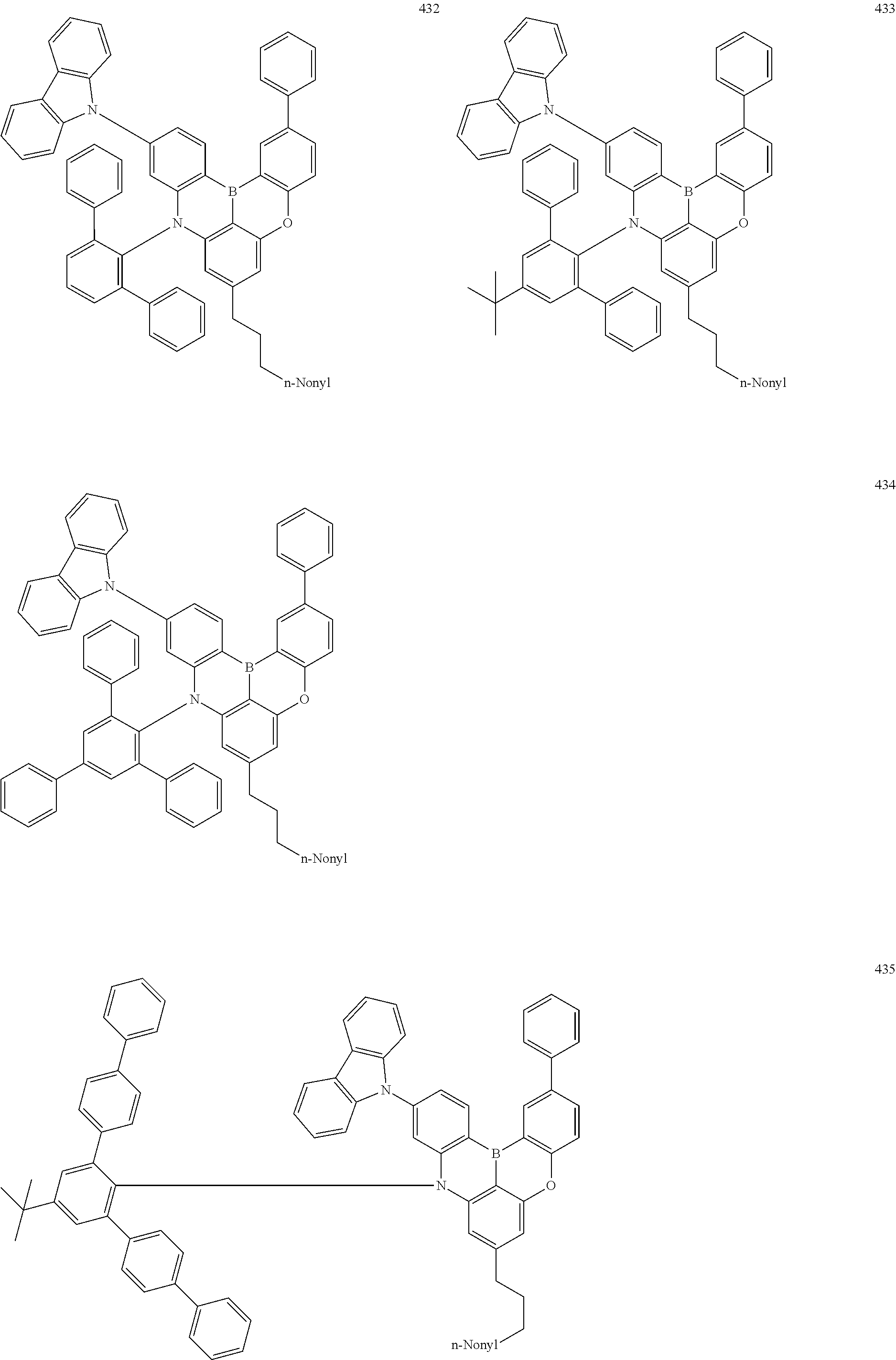

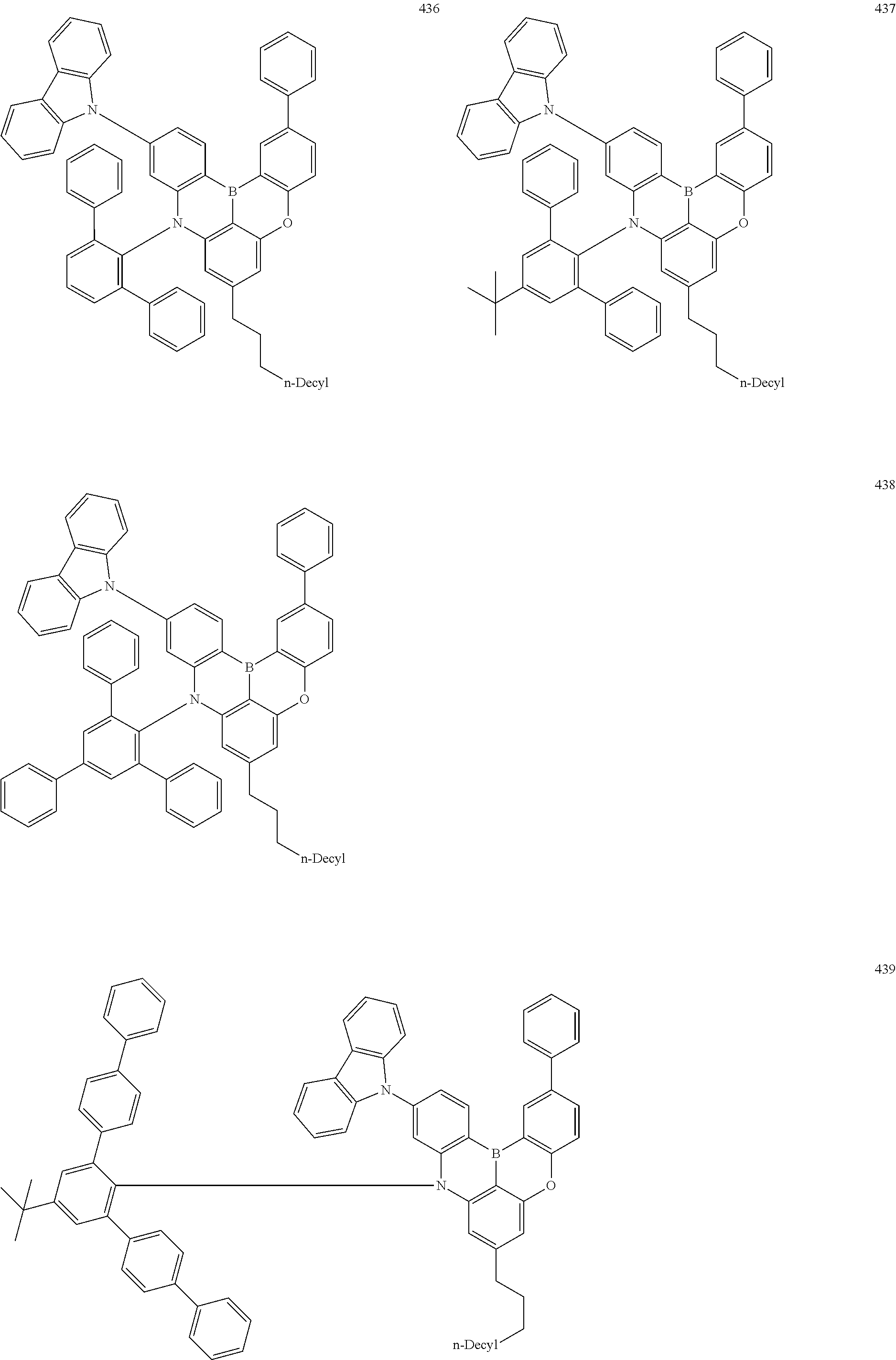

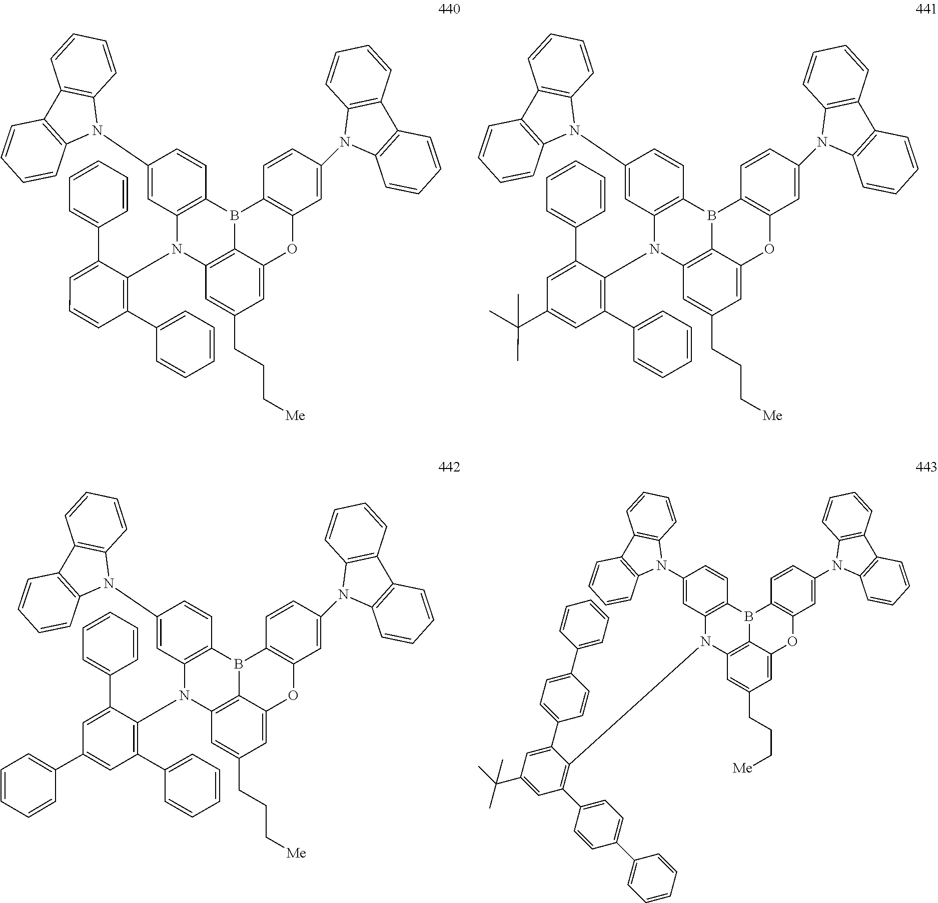

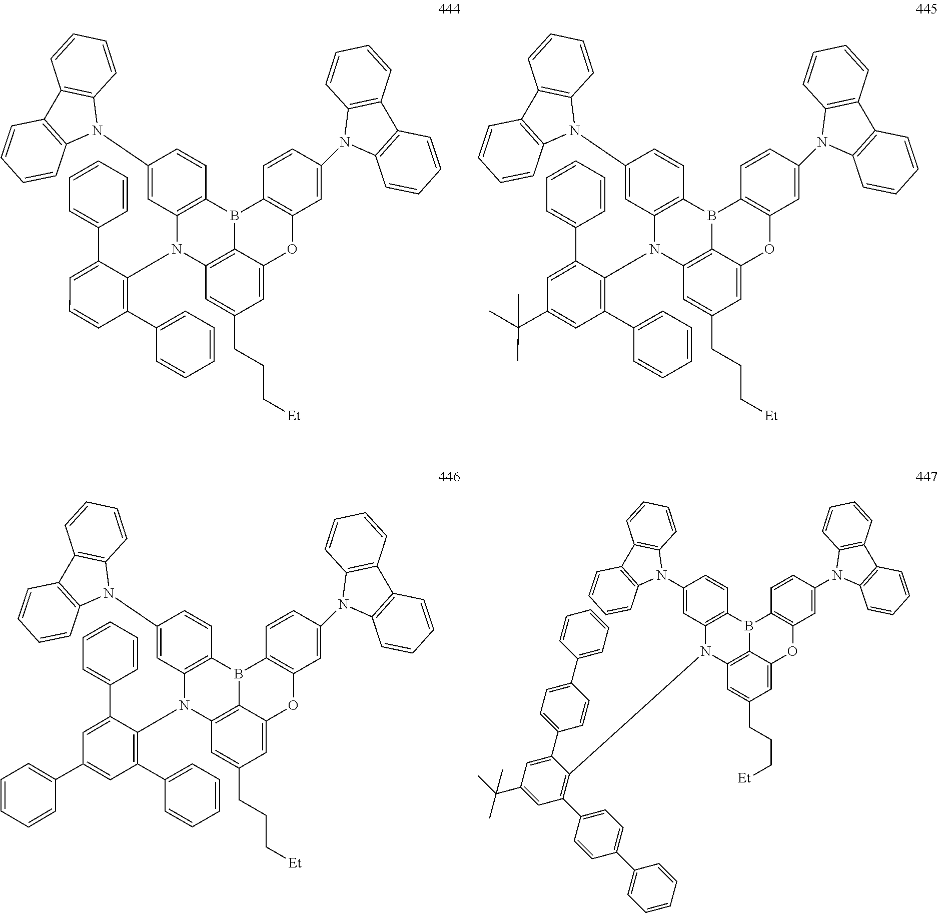

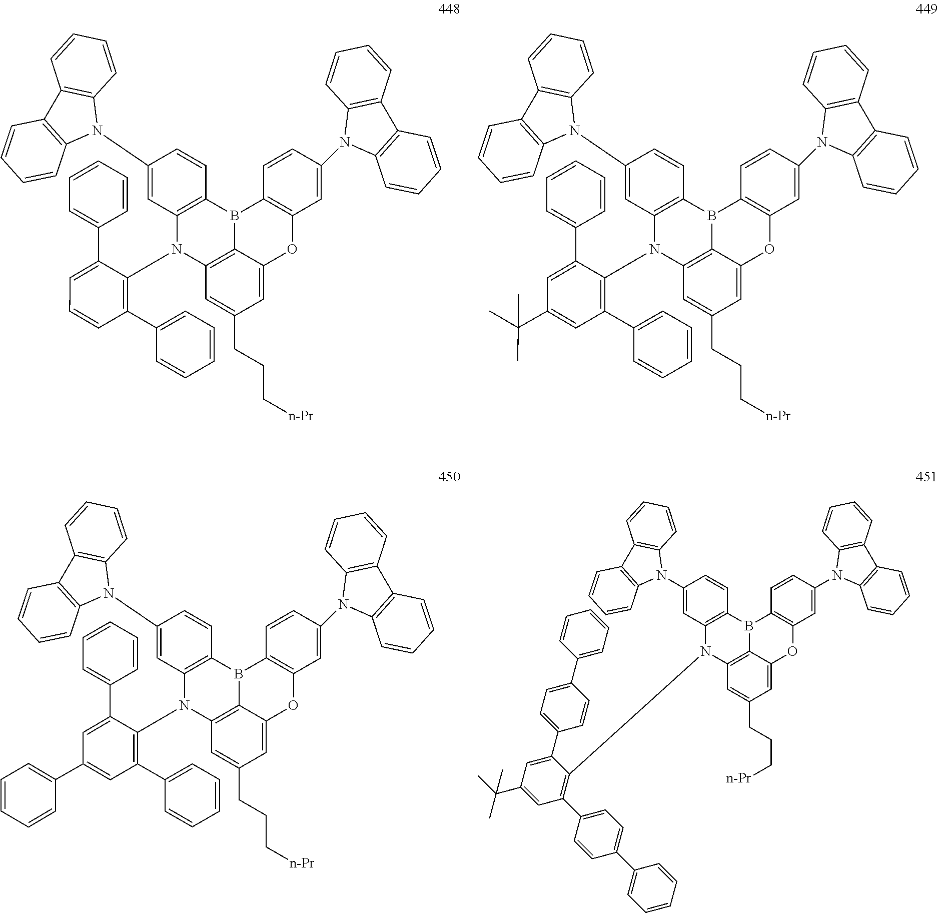

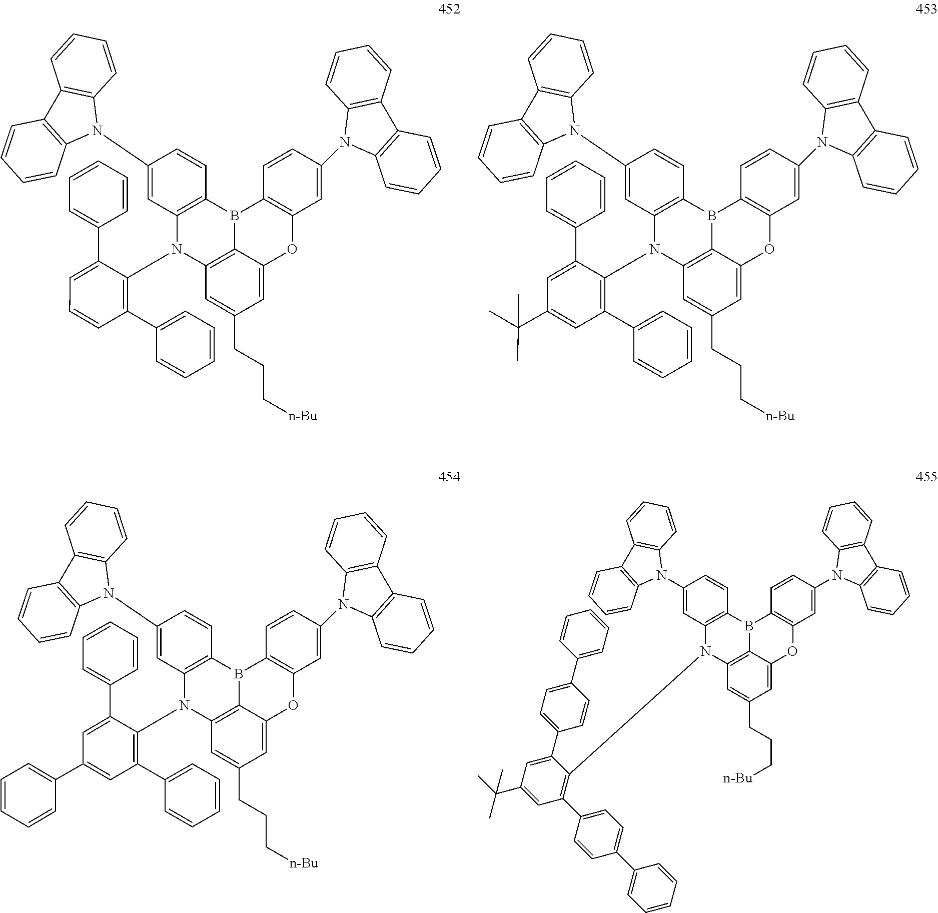

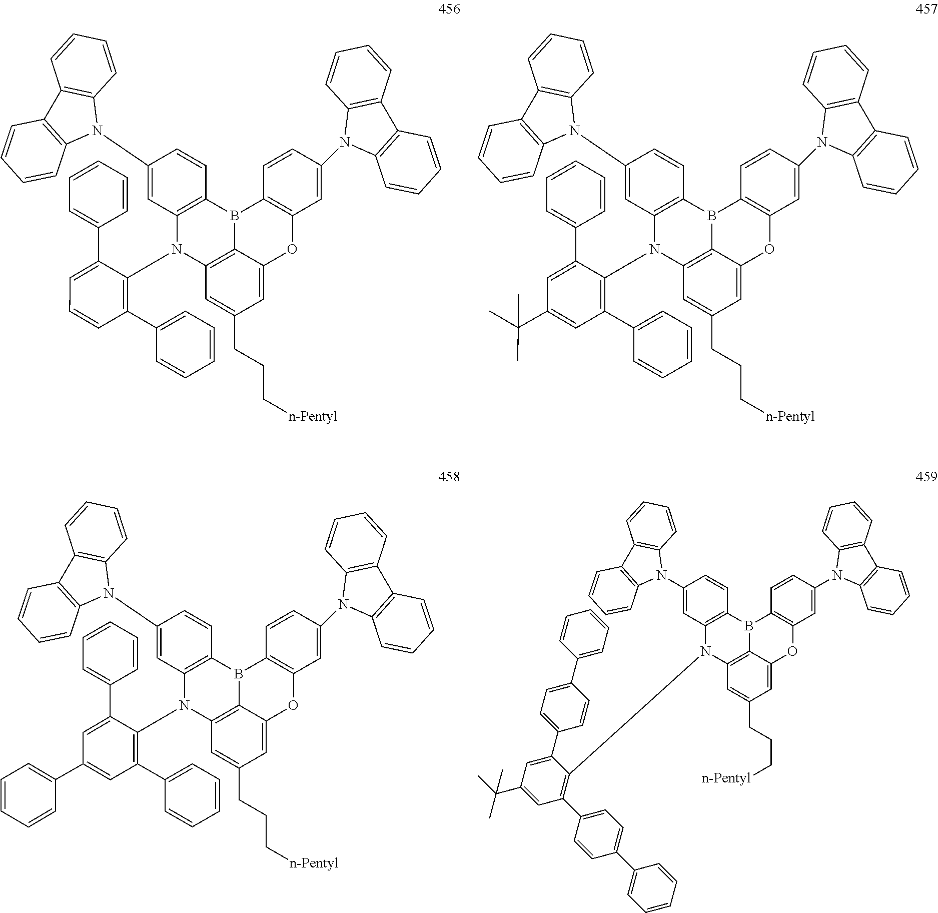

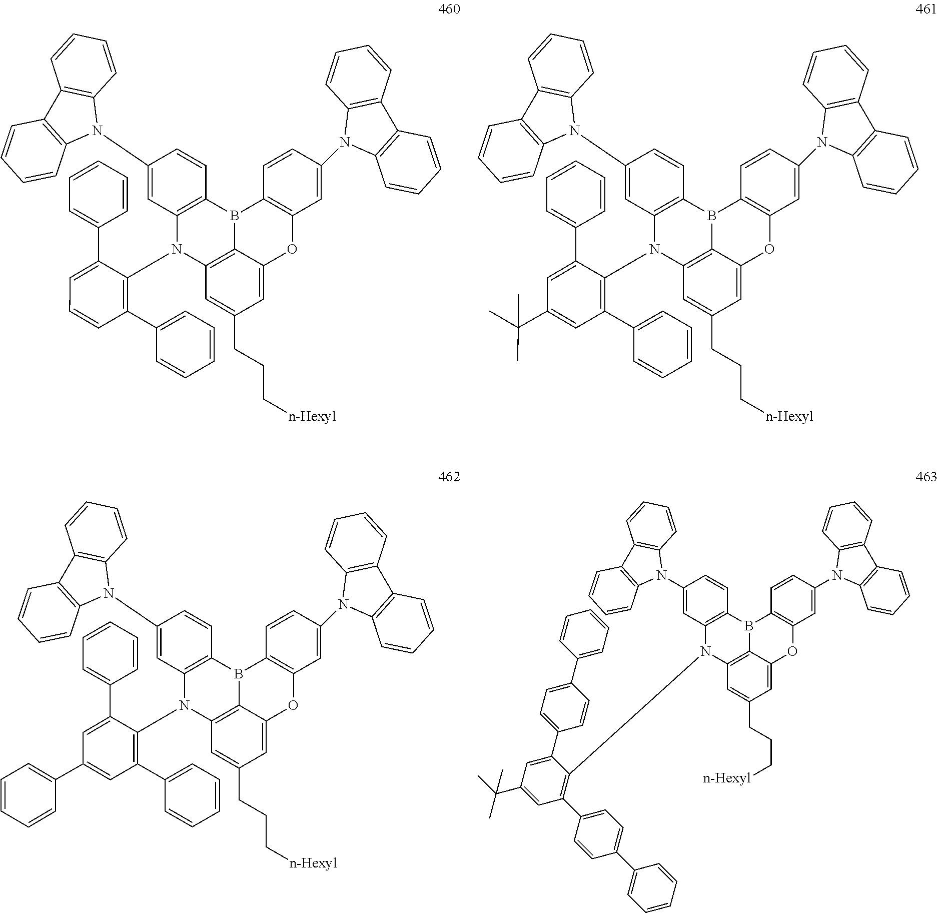

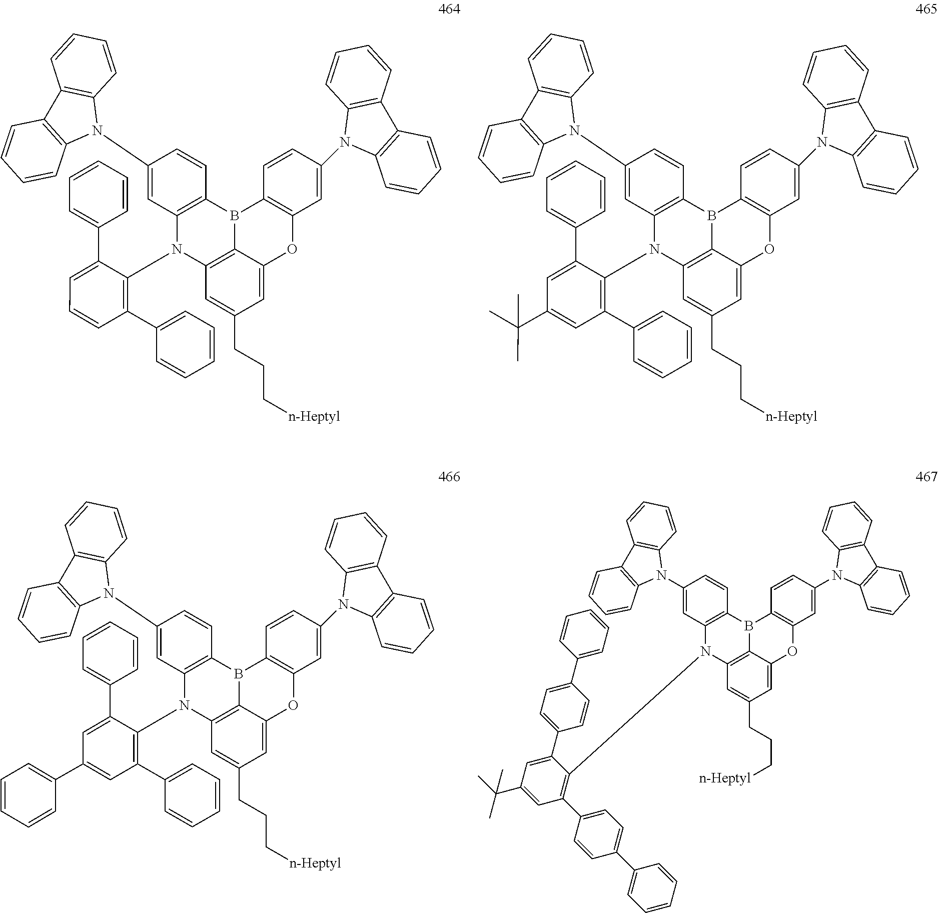

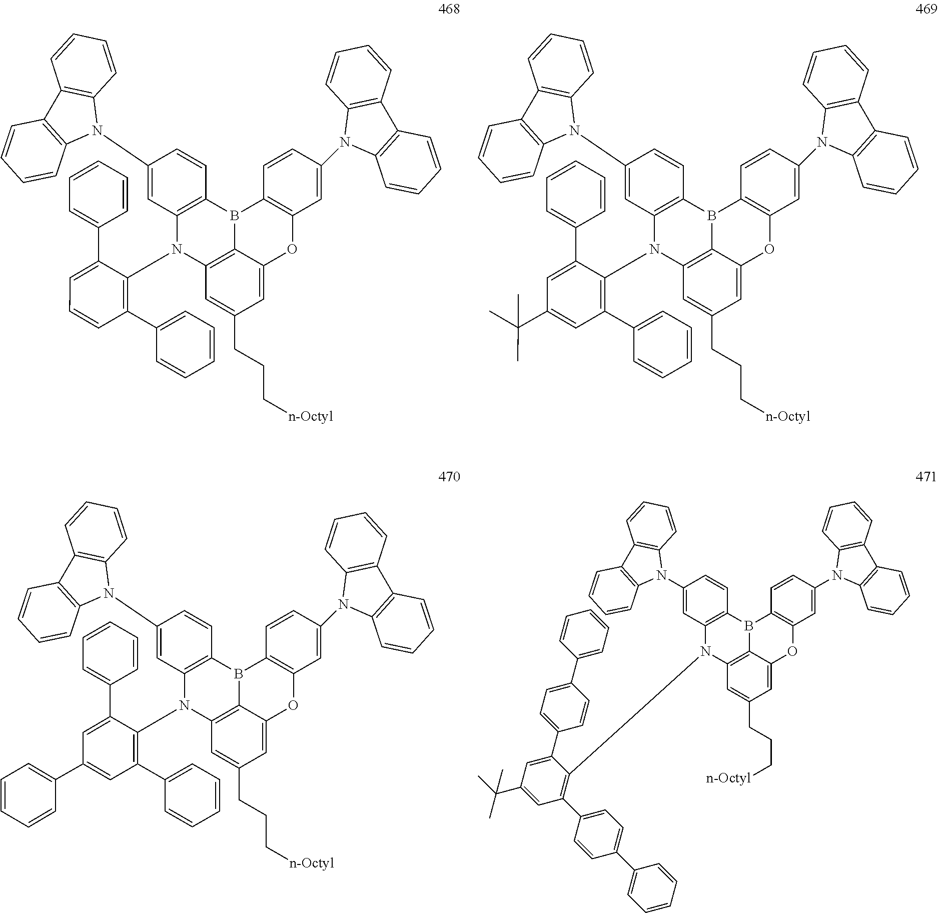

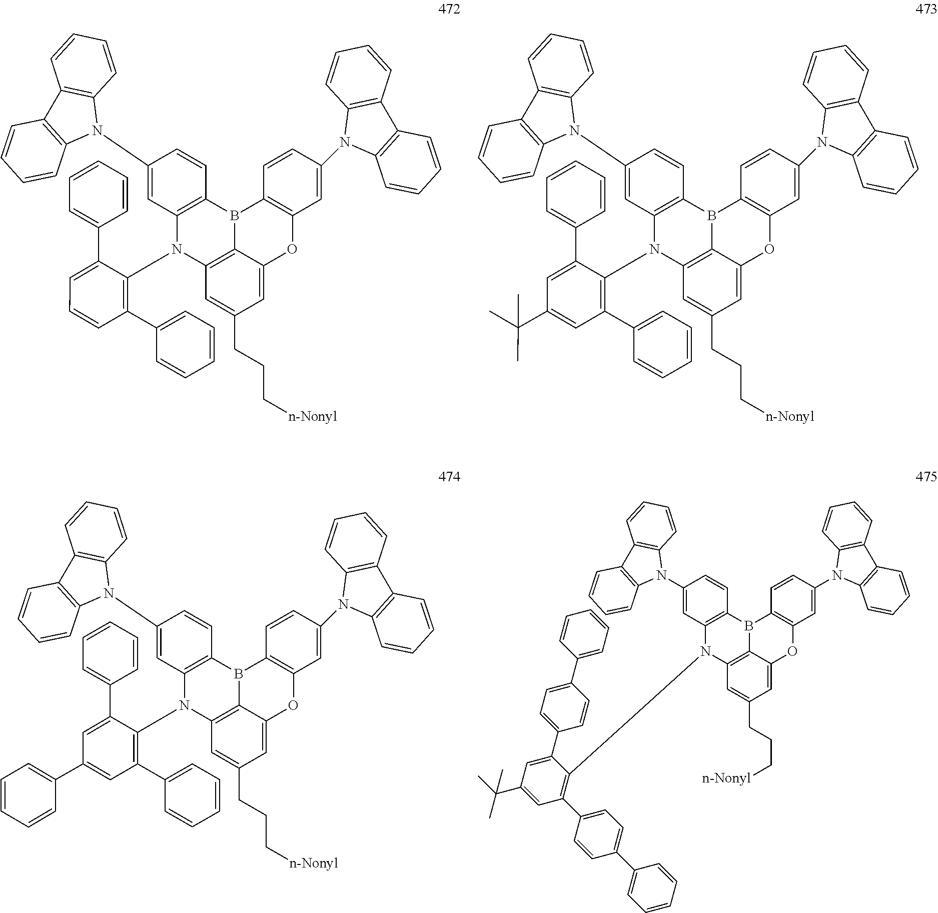

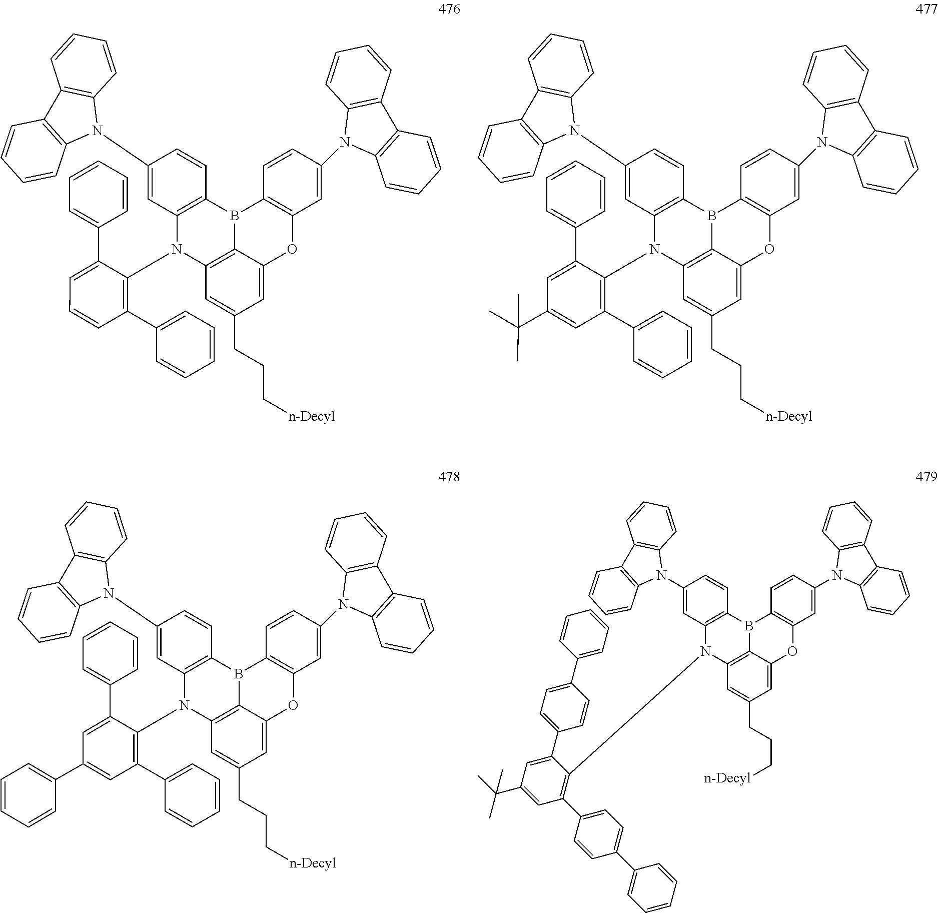

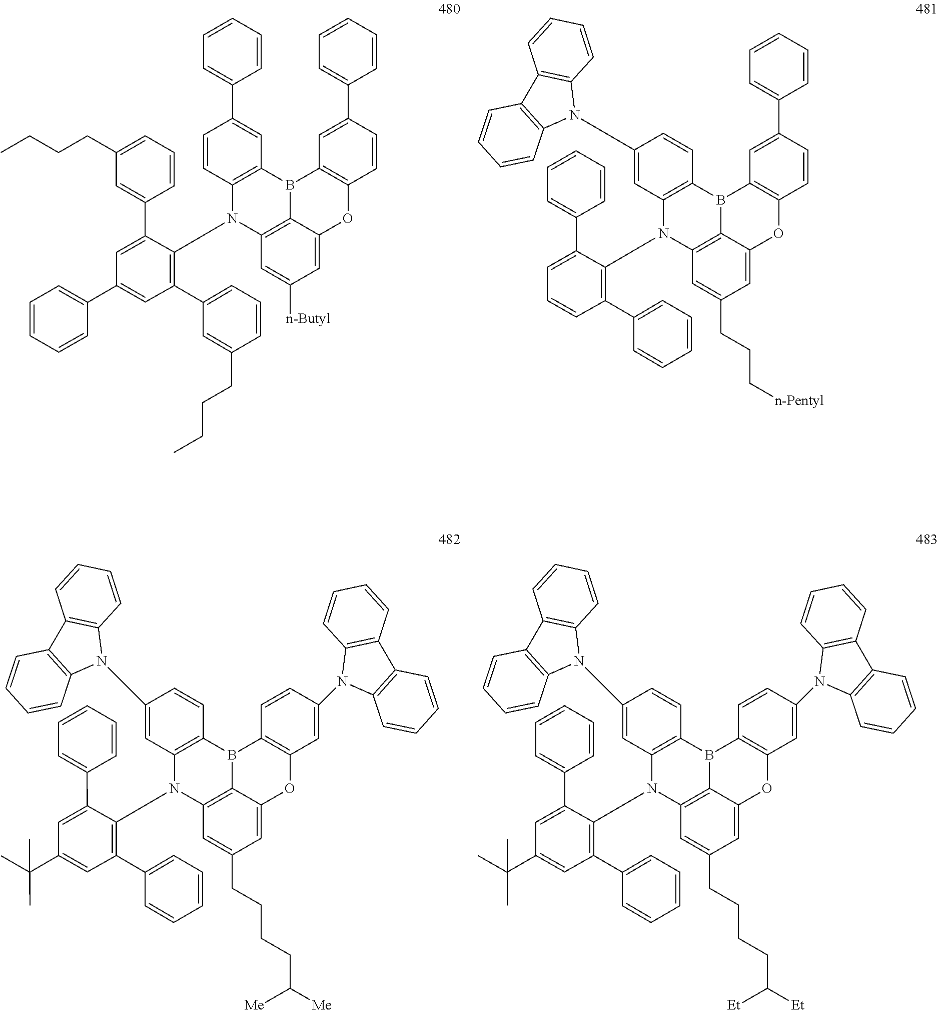

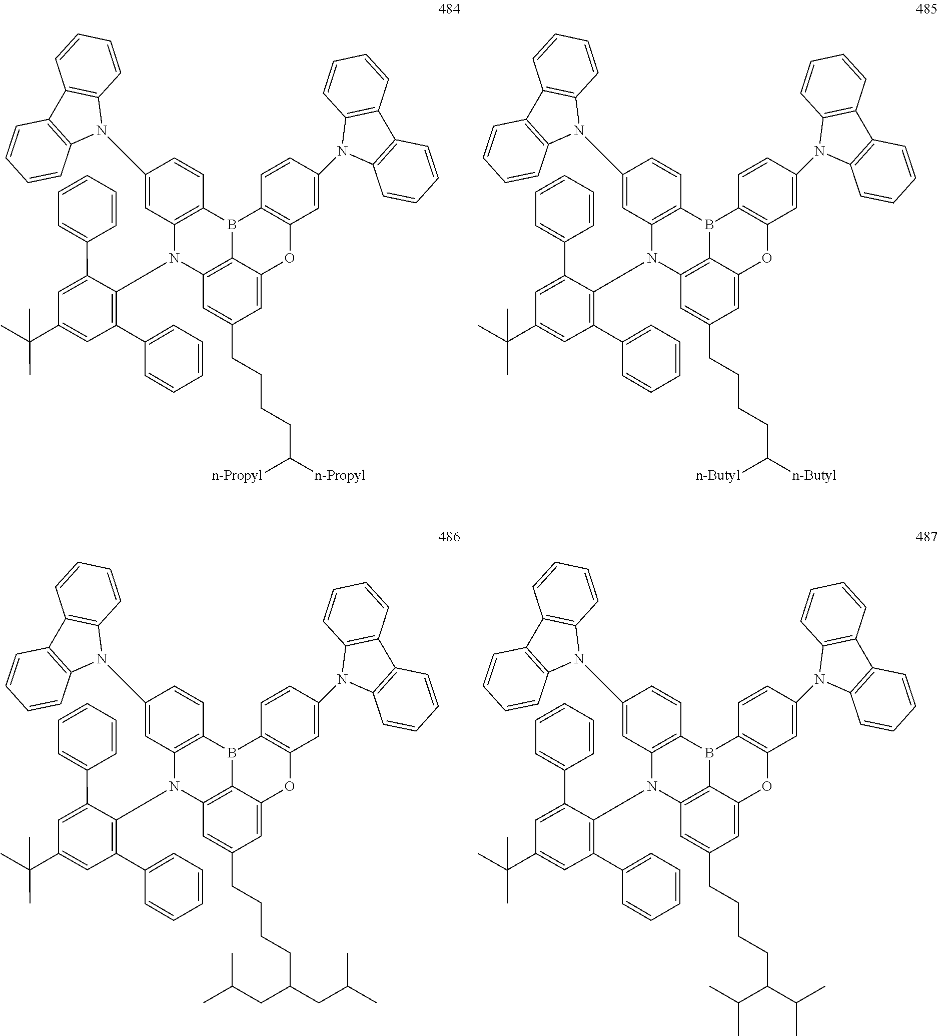

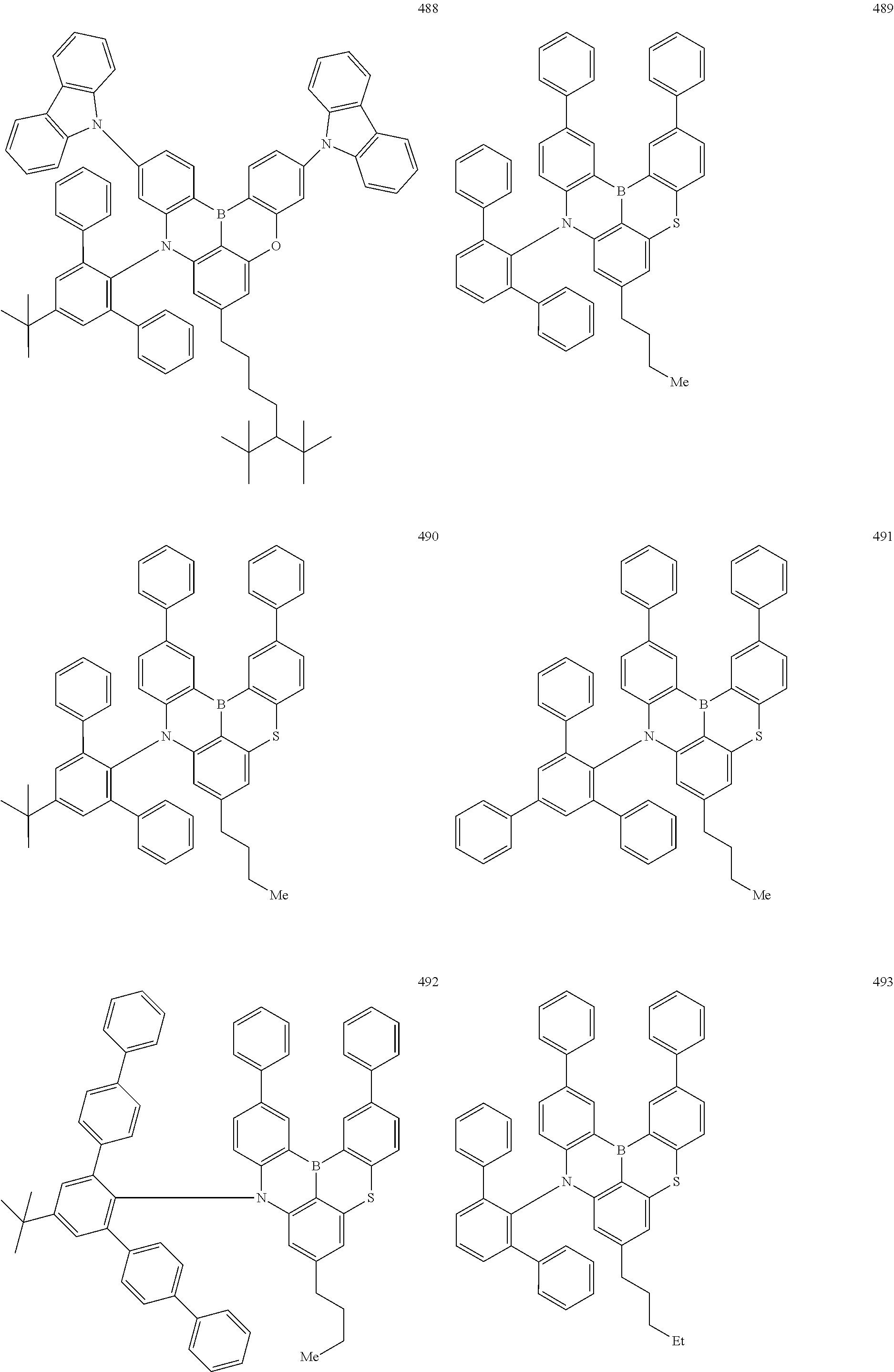

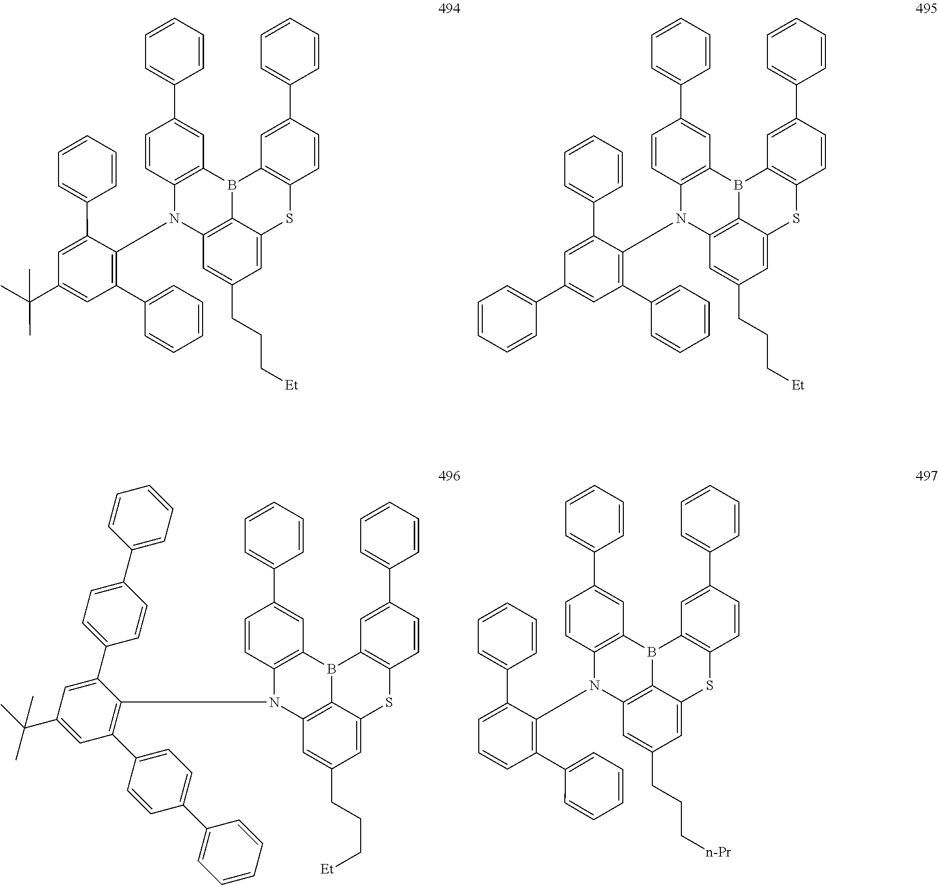

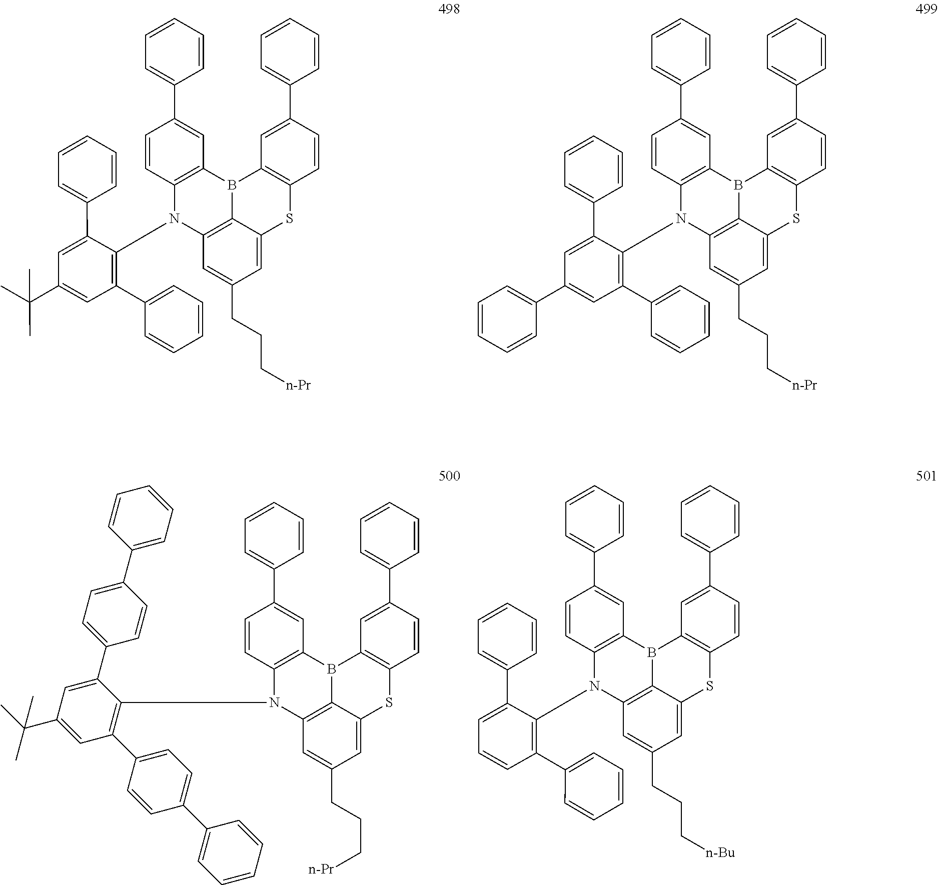

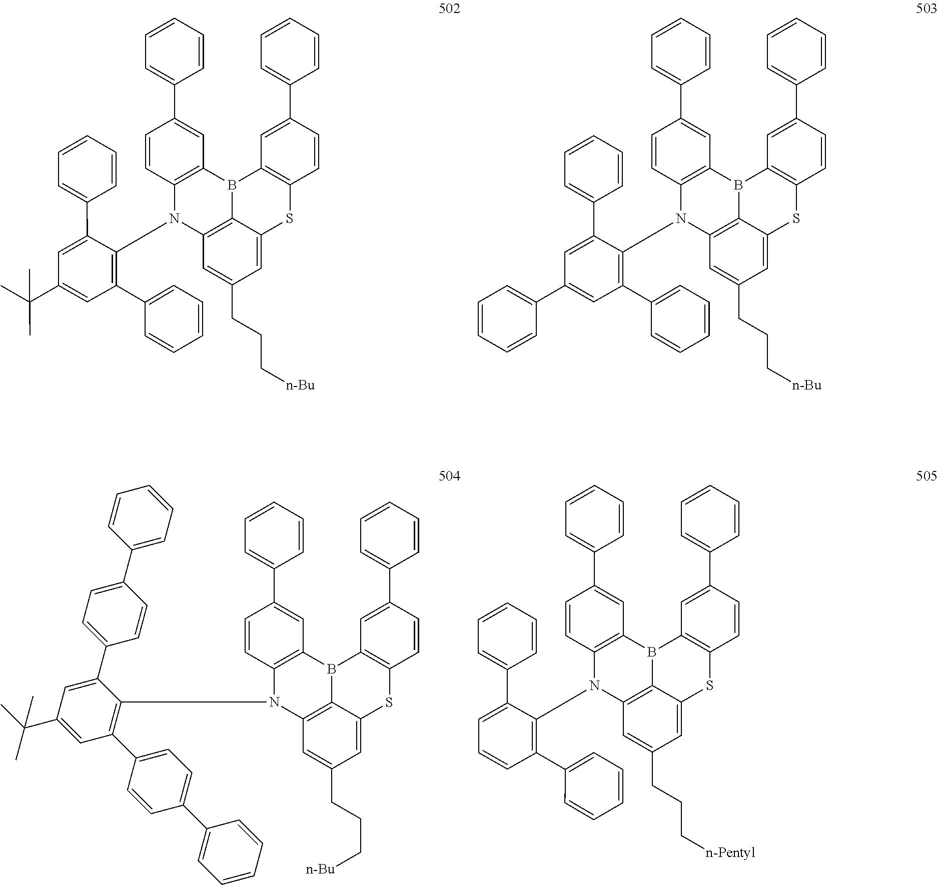

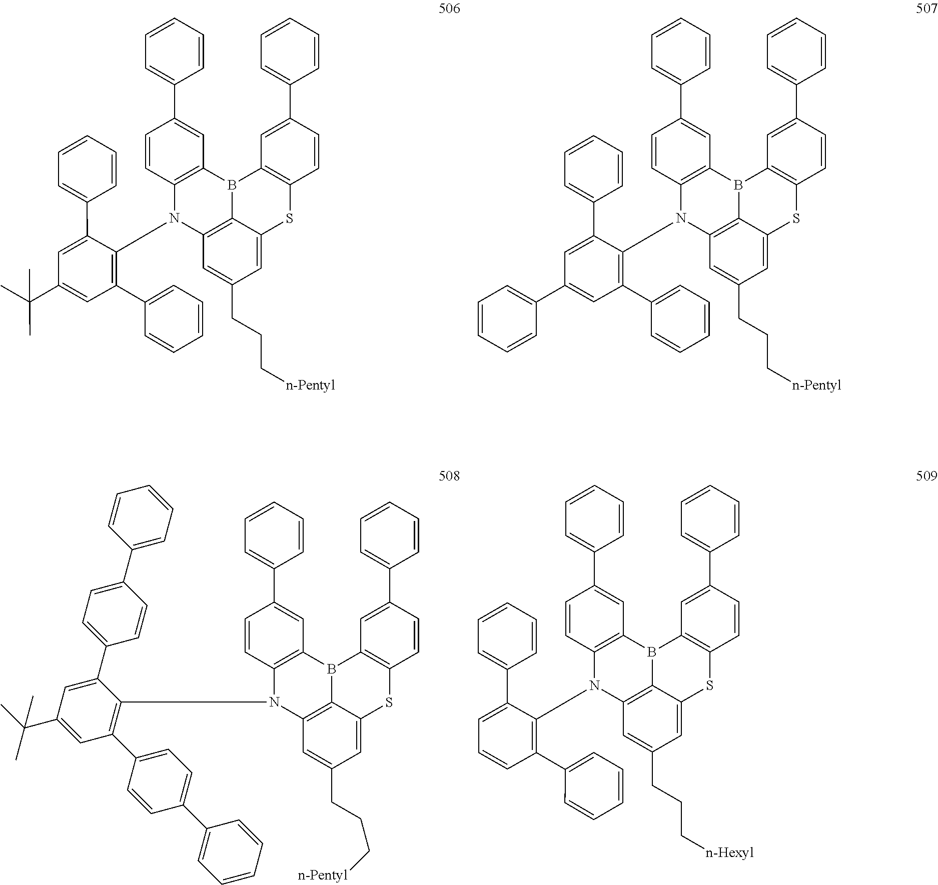

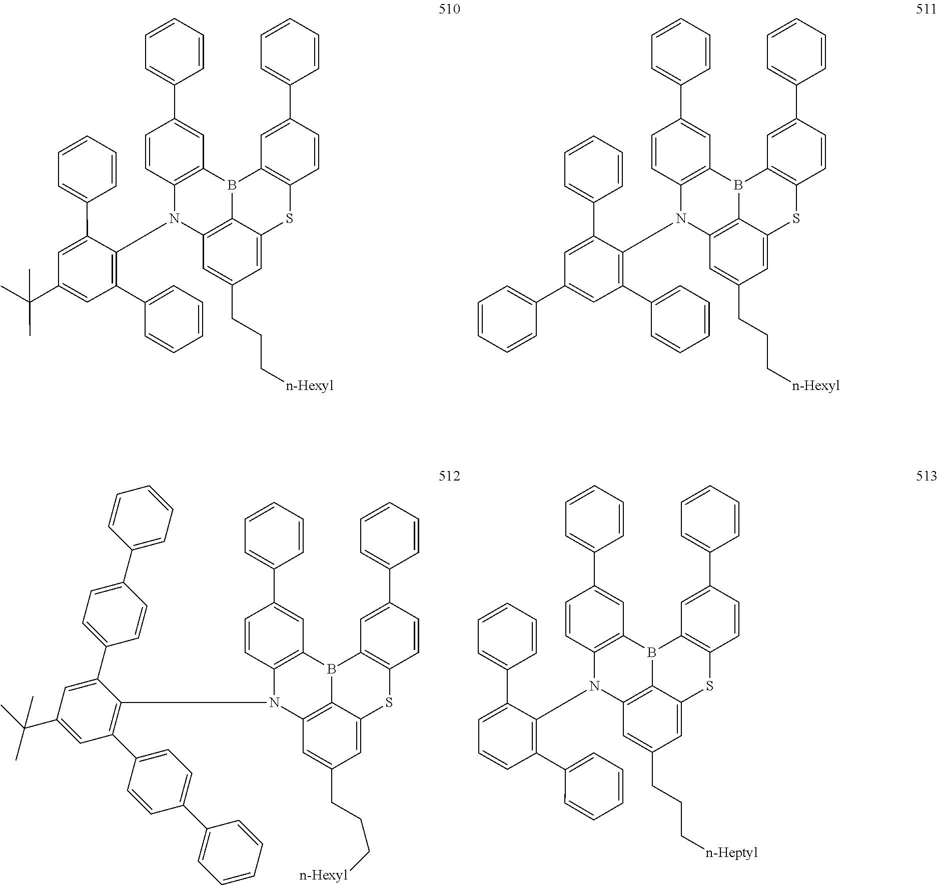

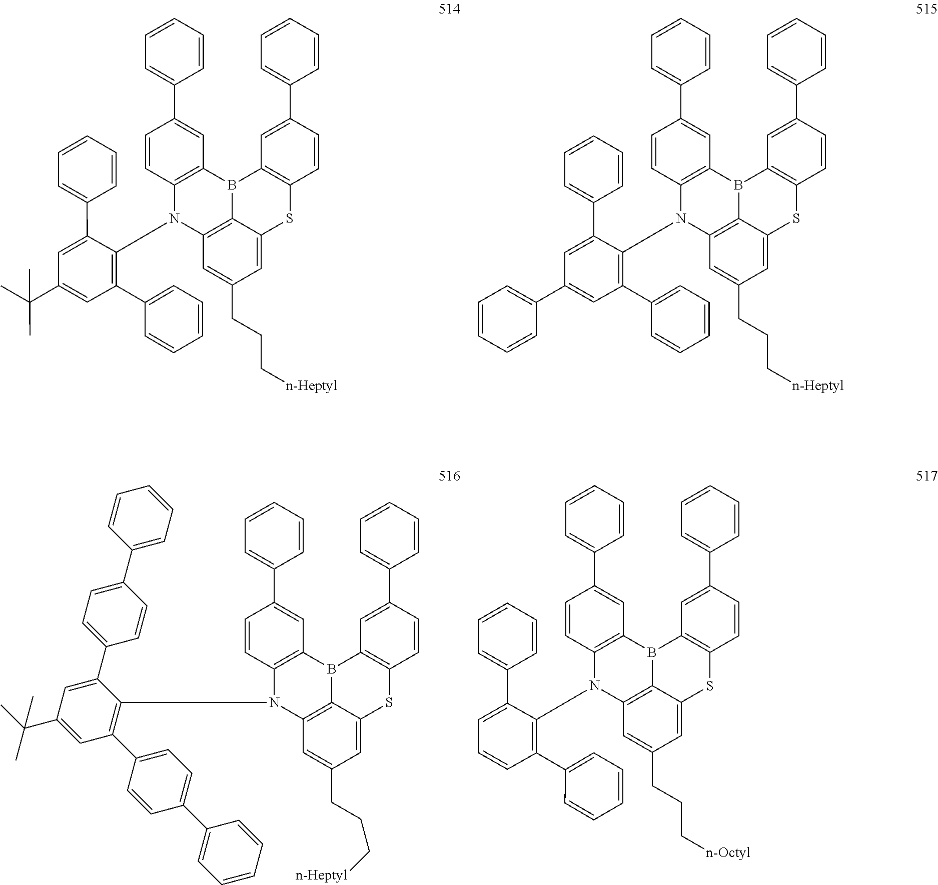

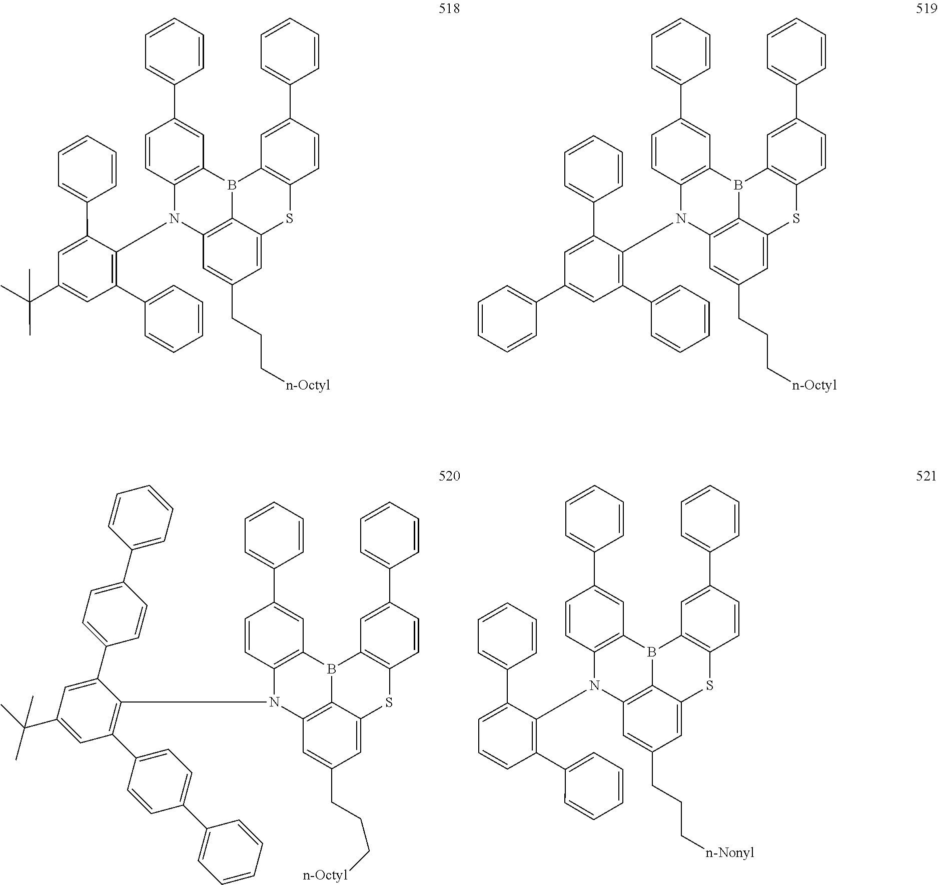

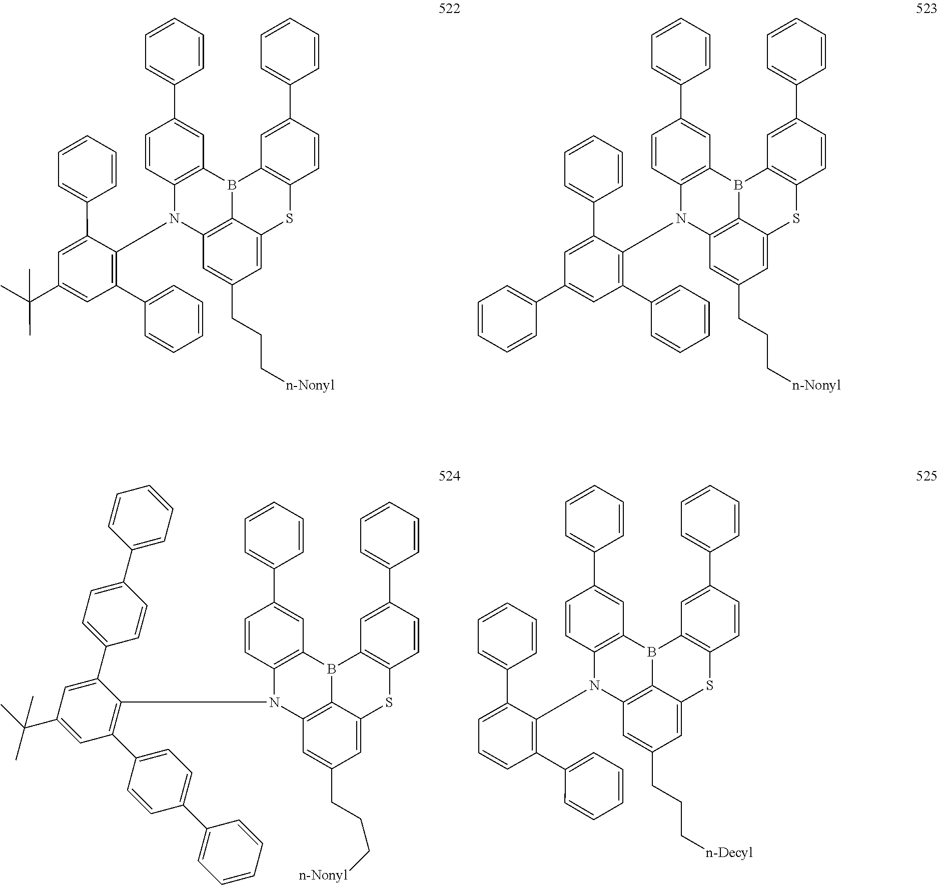

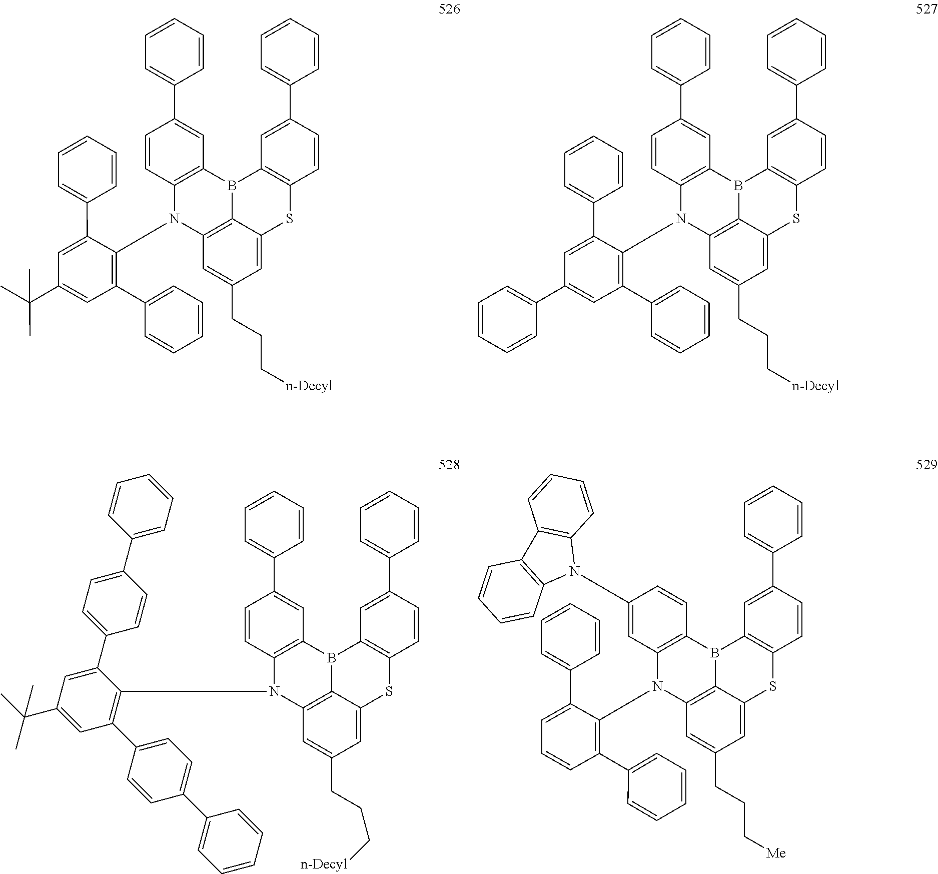

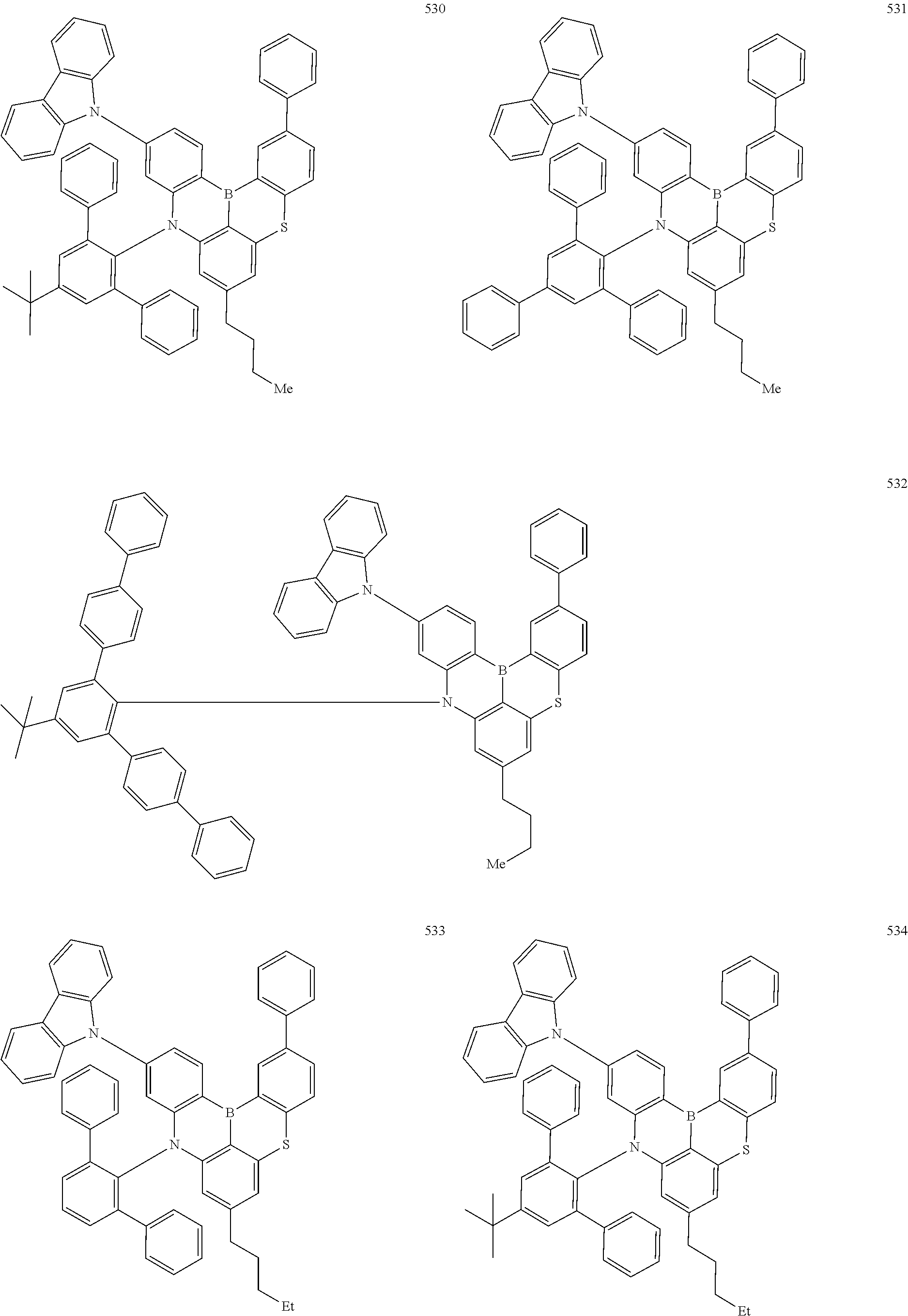

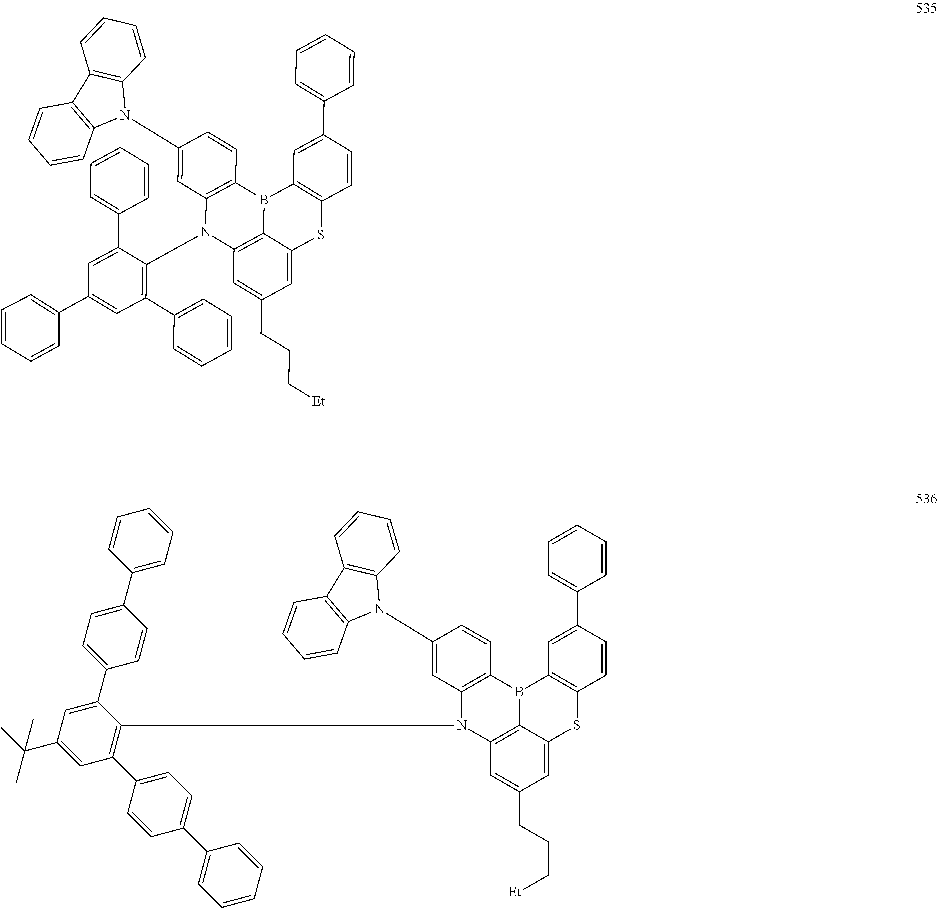 [SMILES: CCCCCc1cc2c3c(c1)N(c1c(-c4ccccc4)cc(-c4ccccc4)cc1-c1ccccc1)c1cc(-n4c5ccccc5c5ccccc54)ccc1B3c1cc(-c3ccccc3)ccc1S2 ; CCCCCc1cc2c3c(c1)N(c1c(-c4ccc(-c5ccccc5)cc4)cc(C(C)(C)C)cc1-c1ccc(-c4ccccc4)cc1)c1cc(-n4c5ccccc5c5ccccc54)ccc1B3c1cc(-c3ccccc3)ccc1S2]

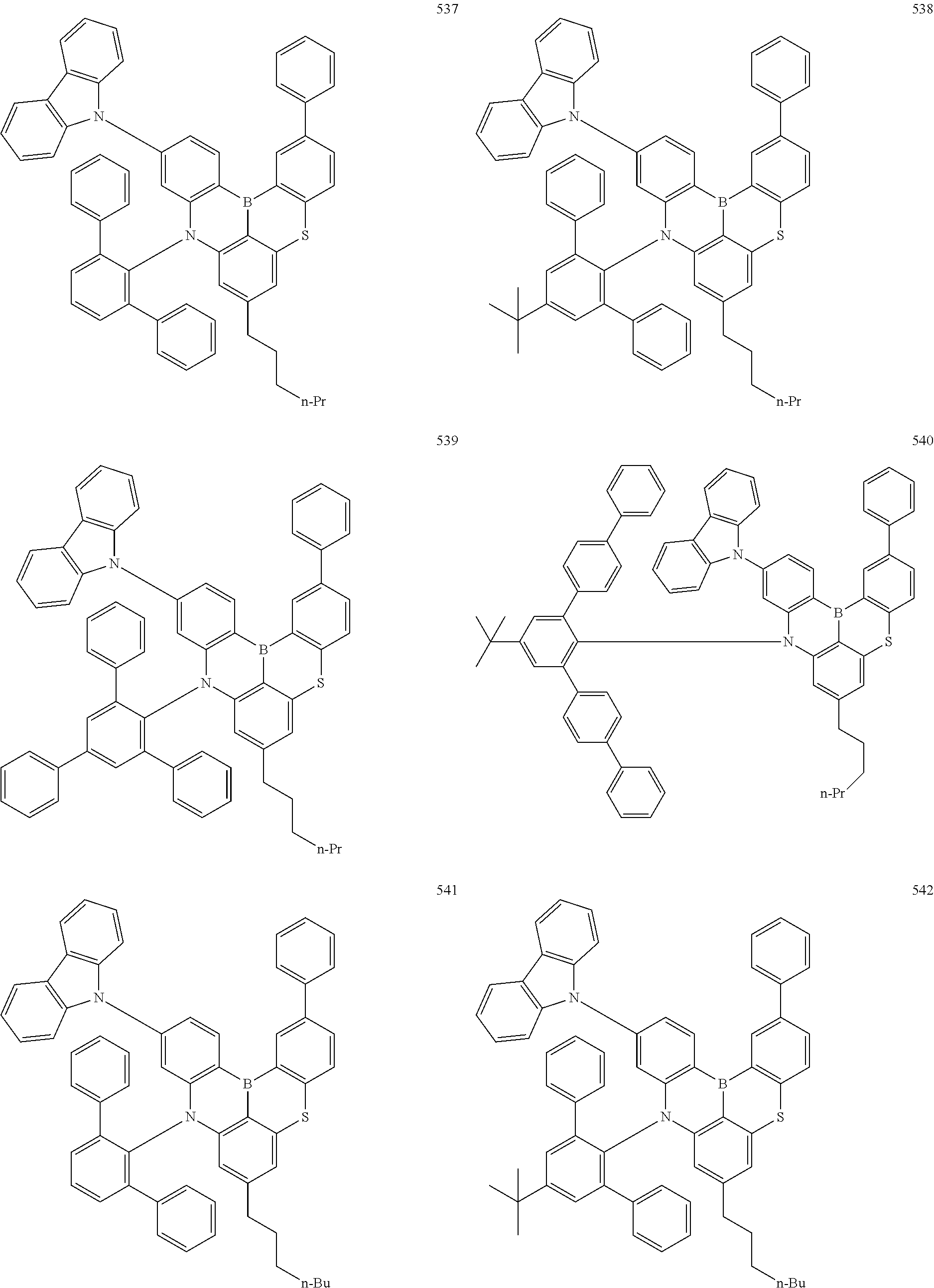

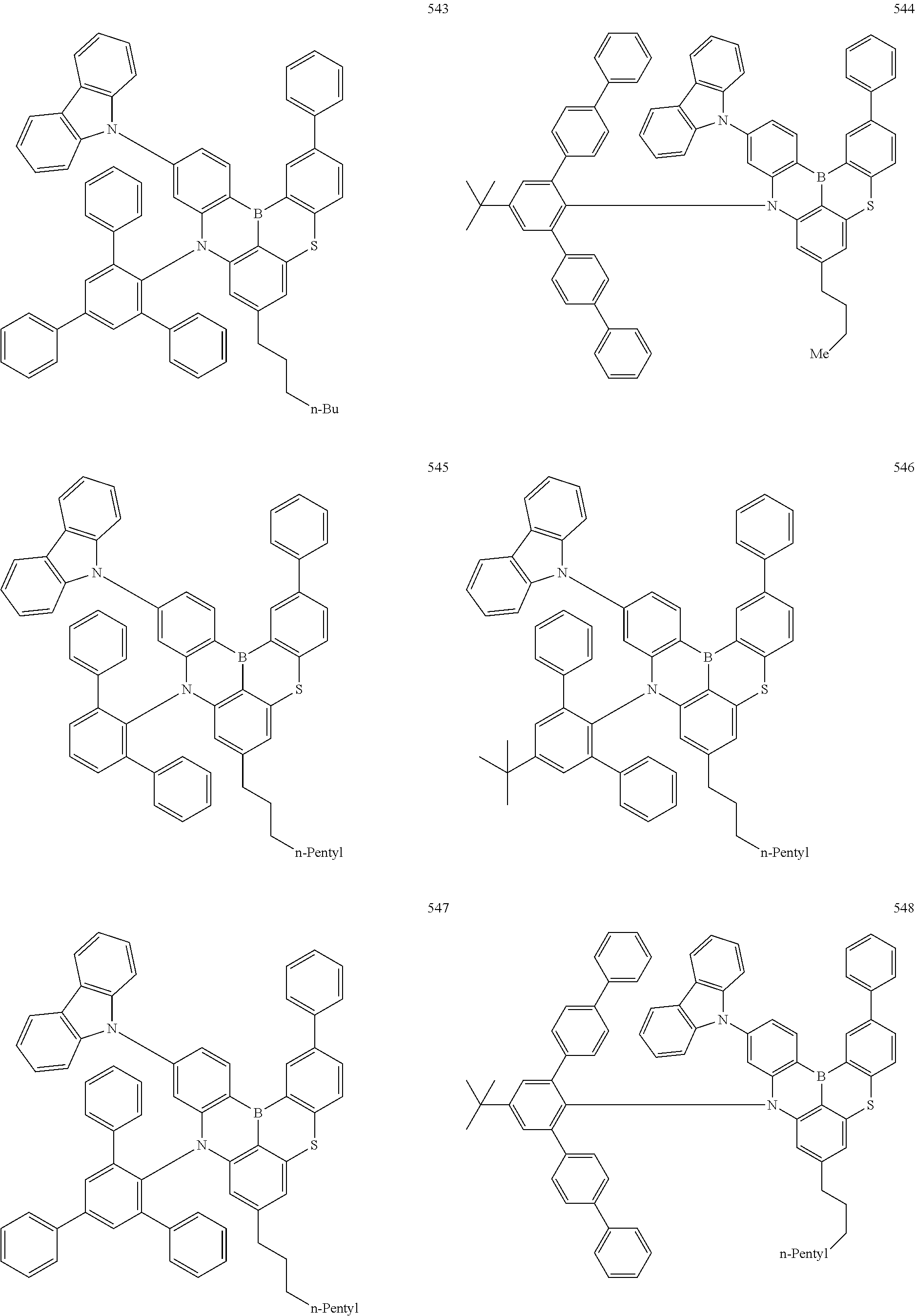

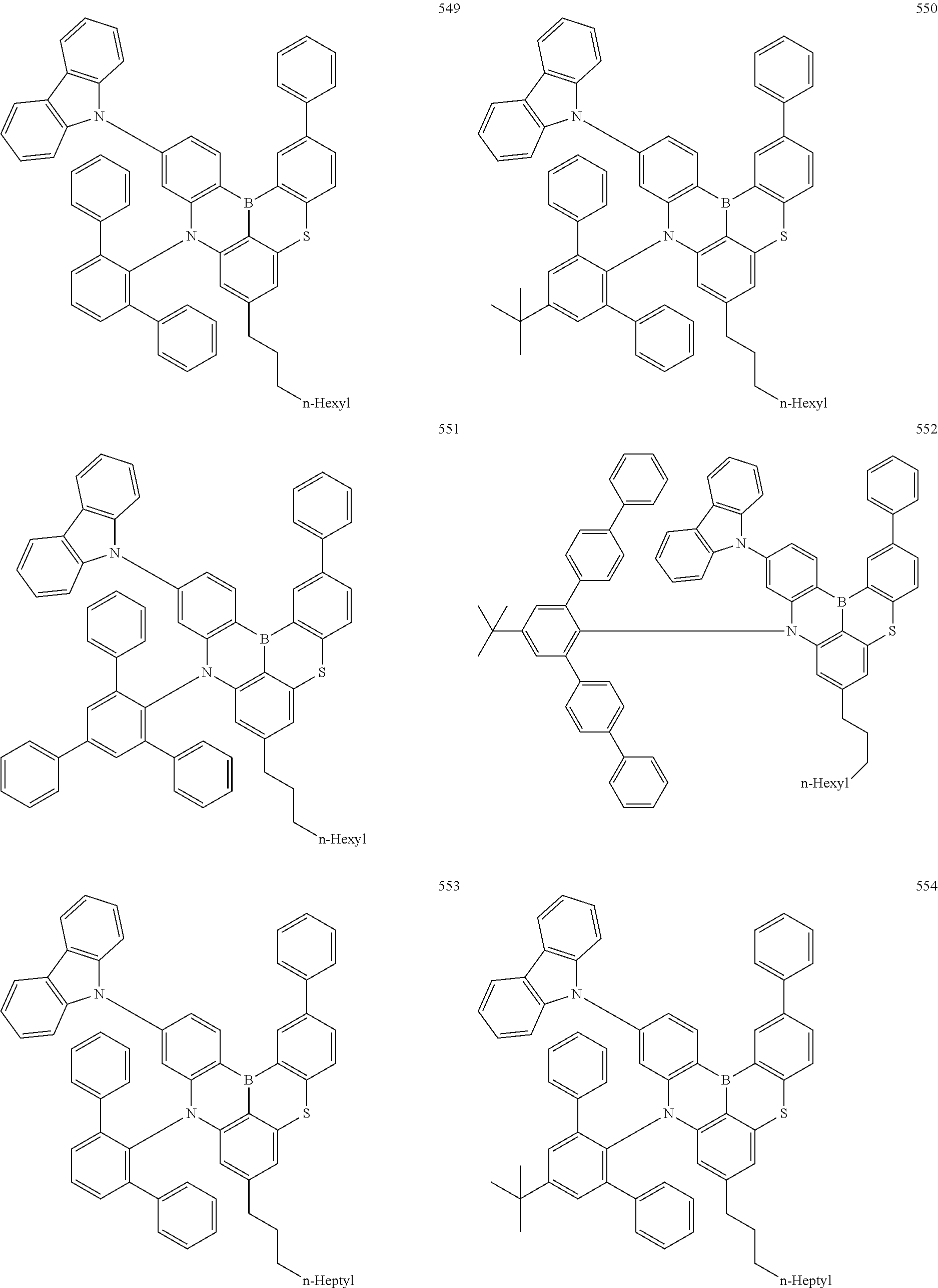

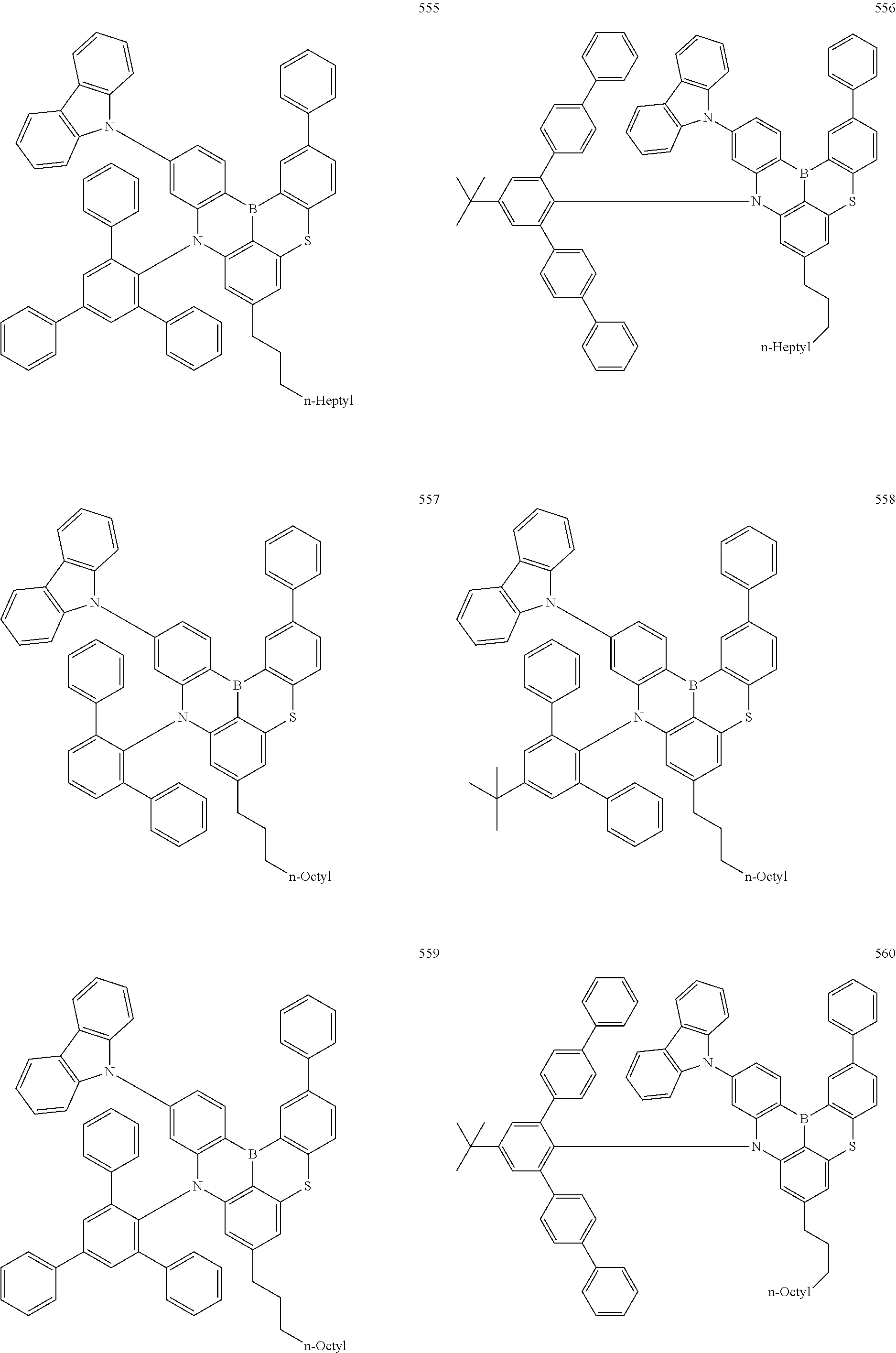

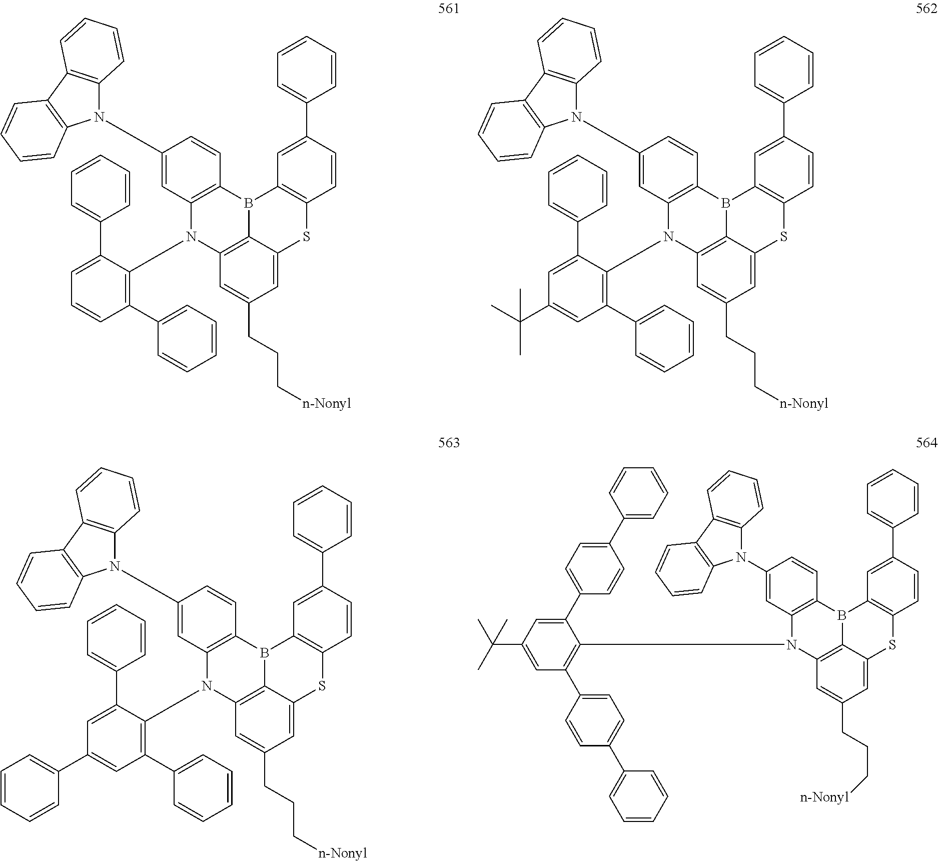

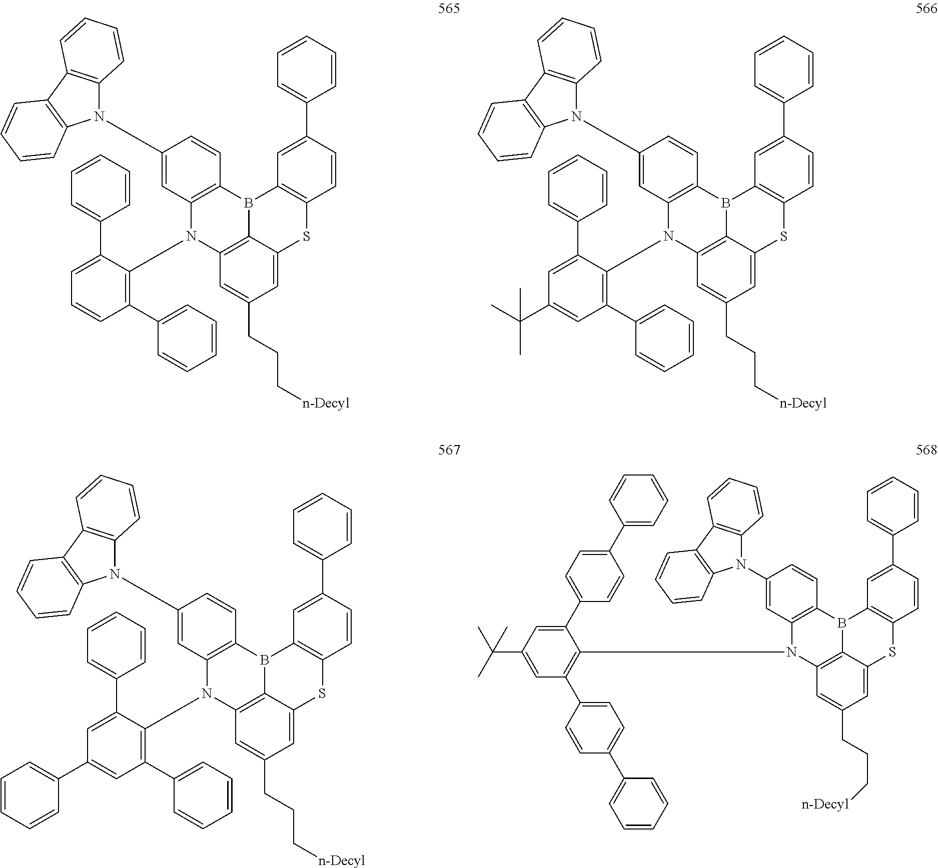

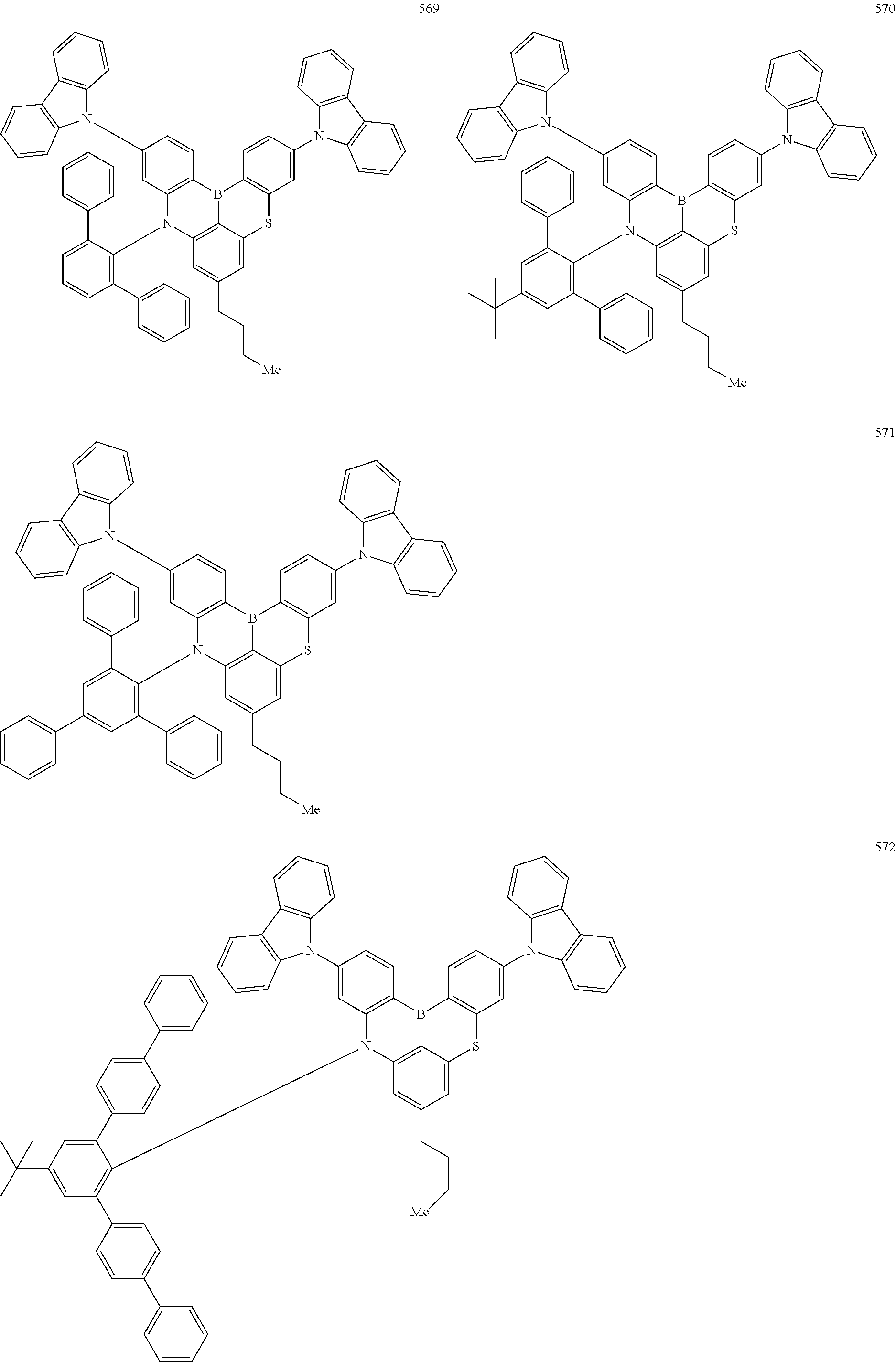

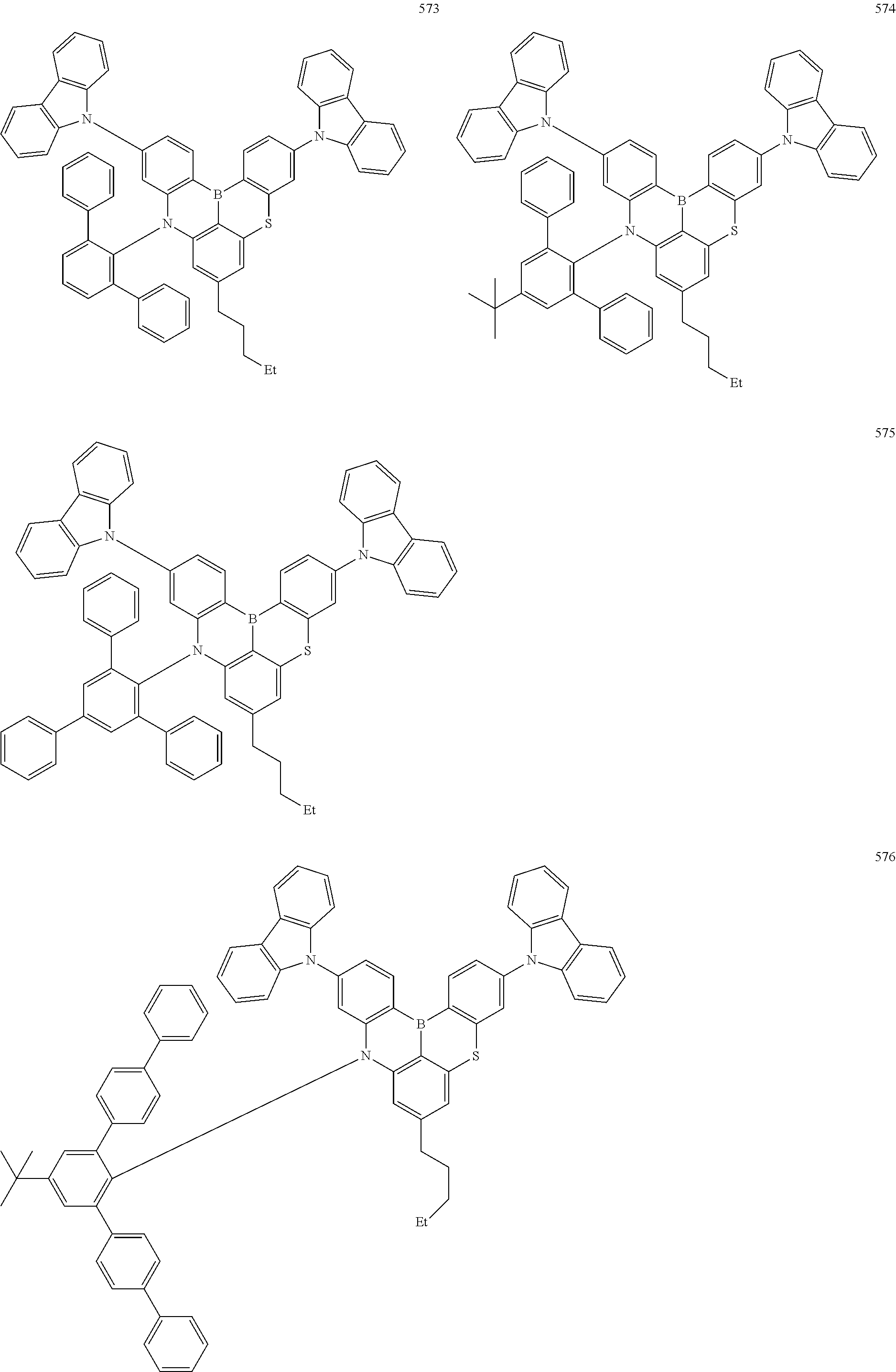

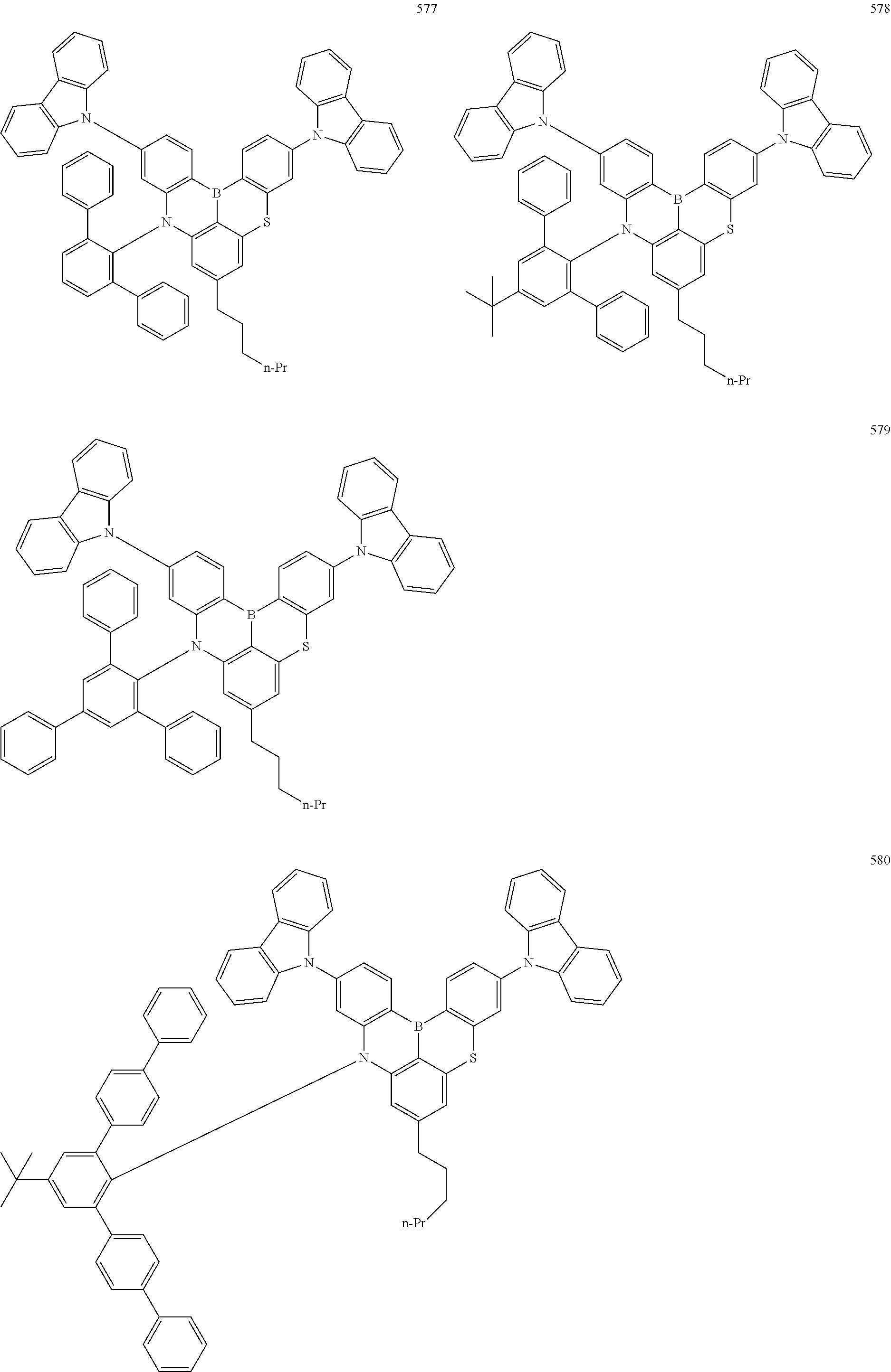

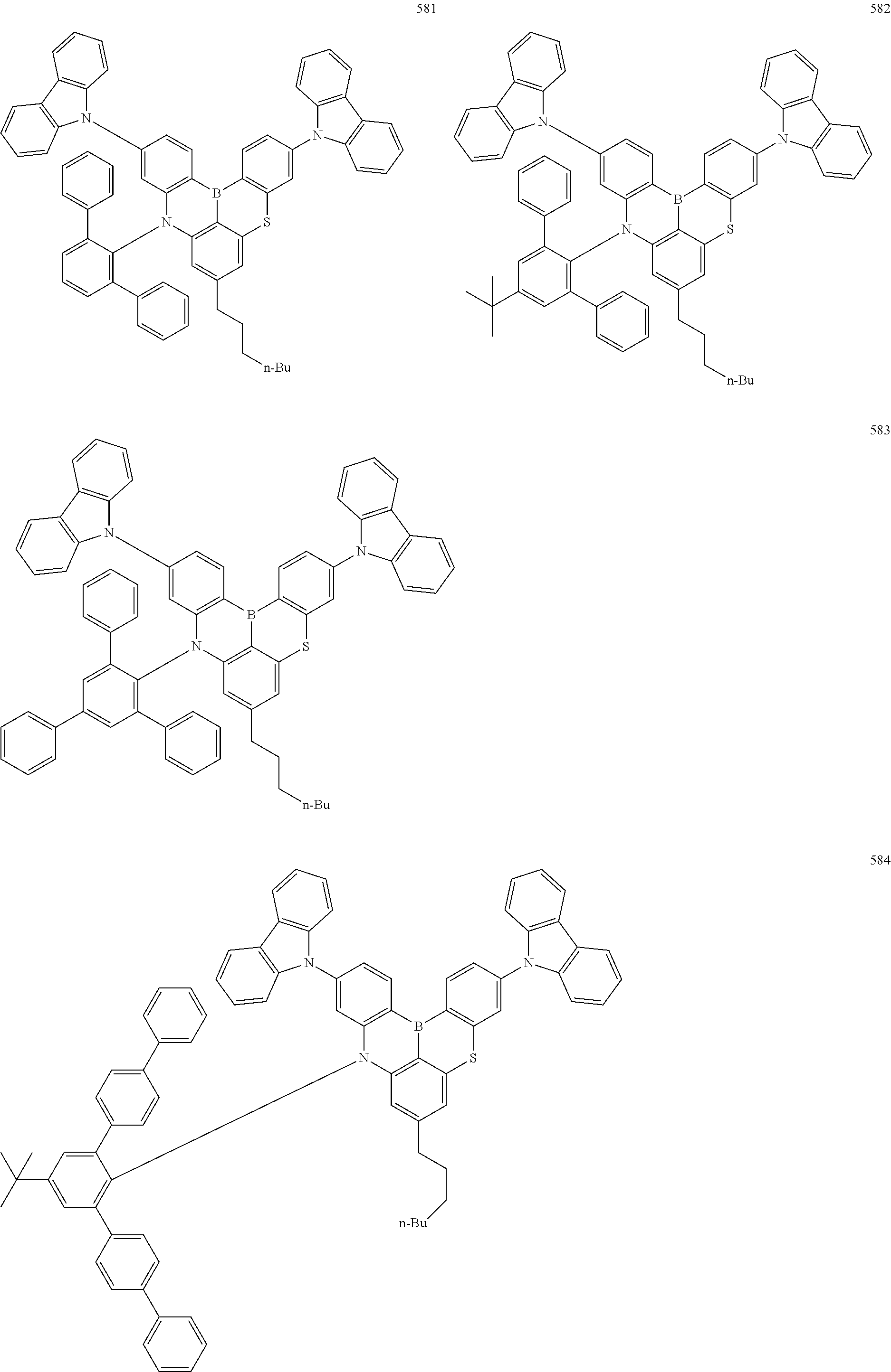

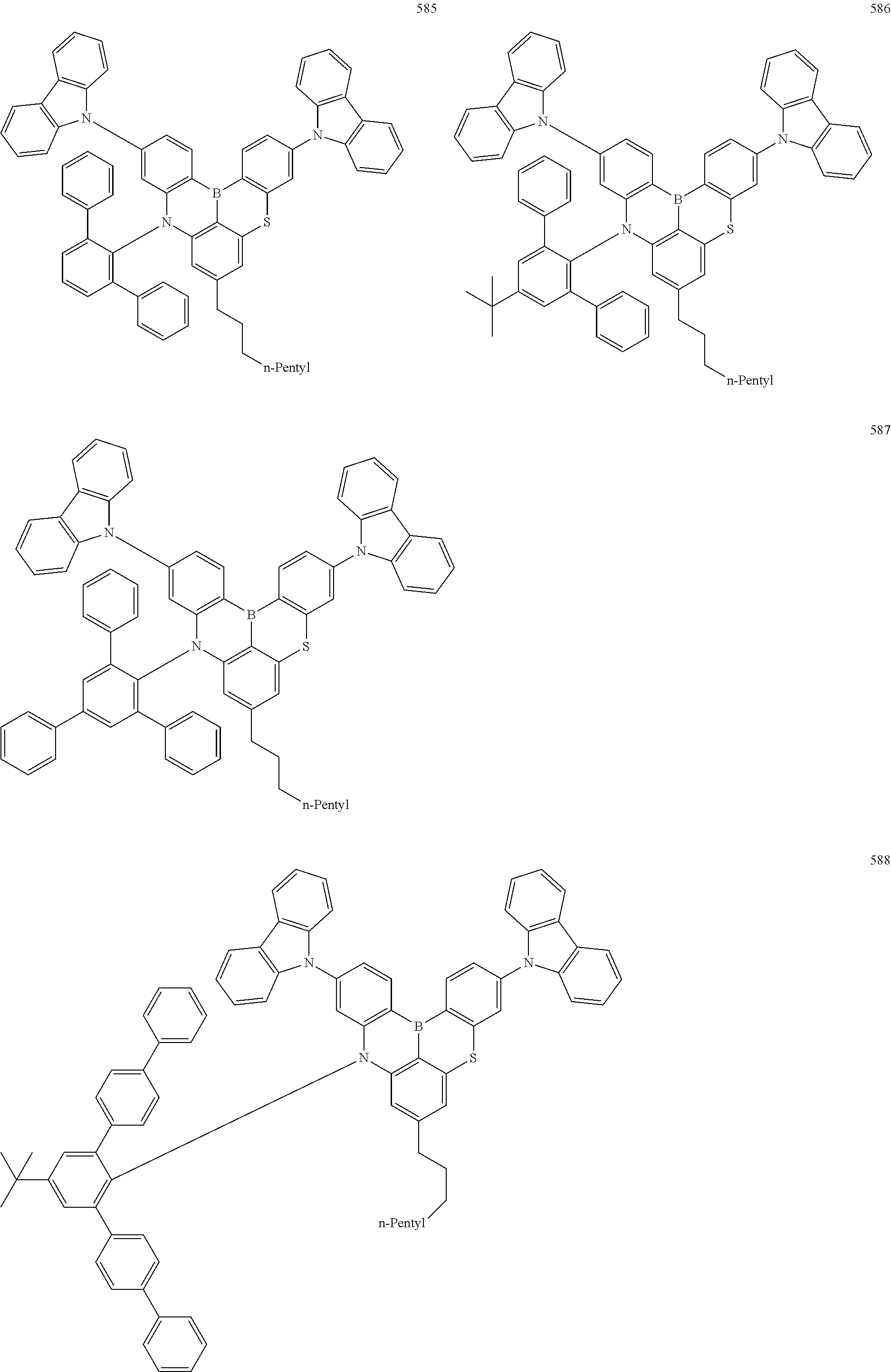

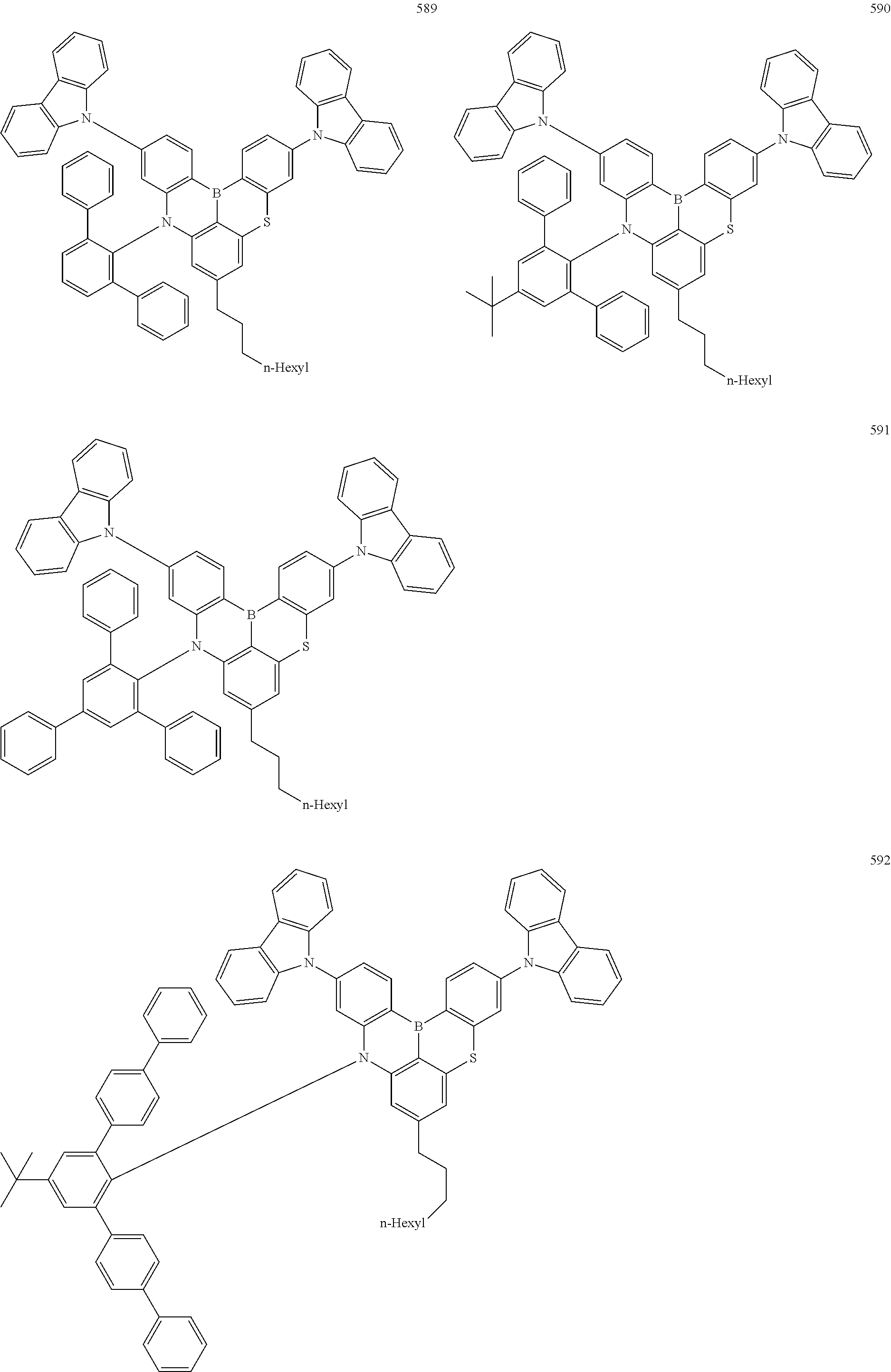

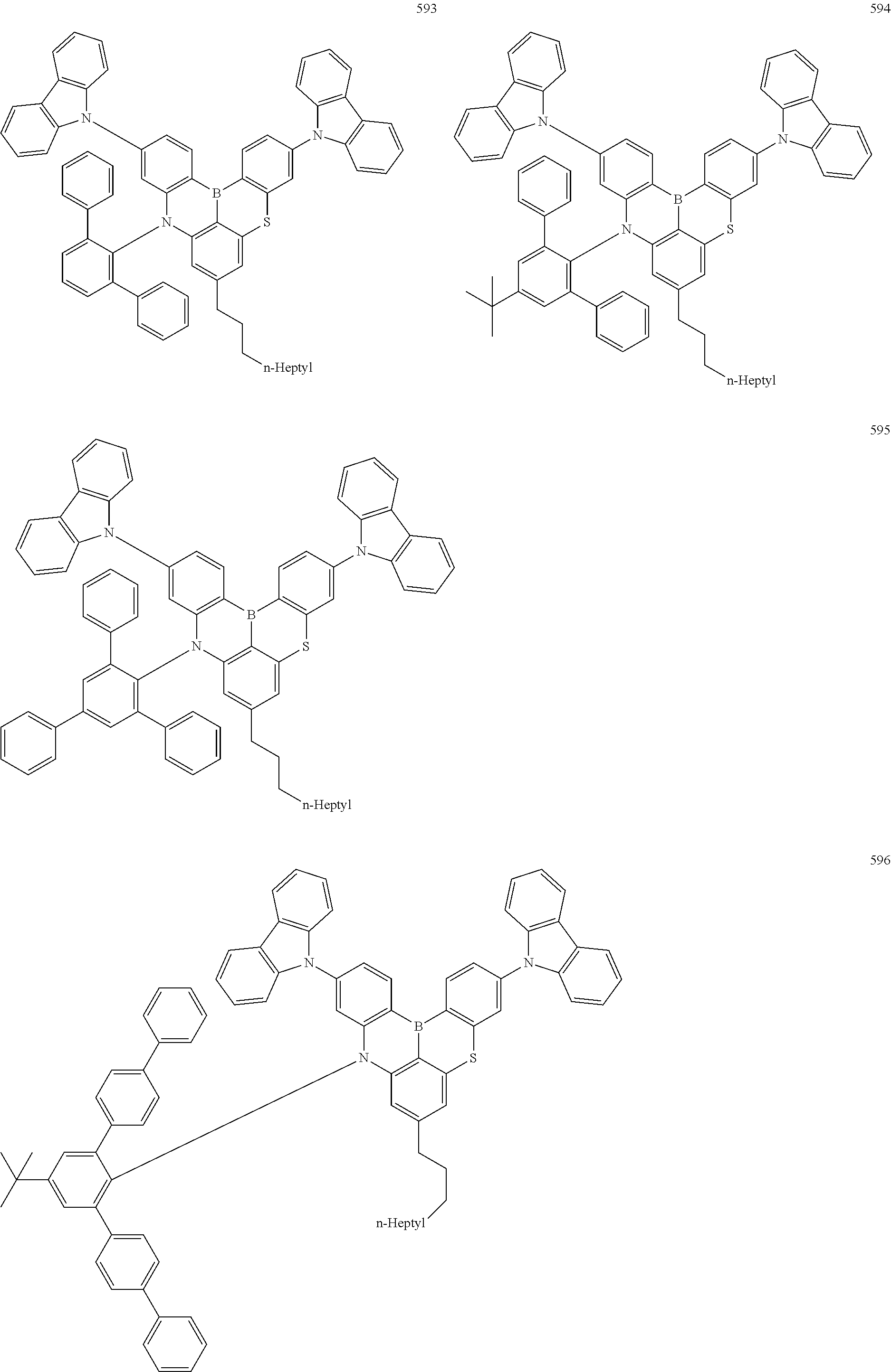

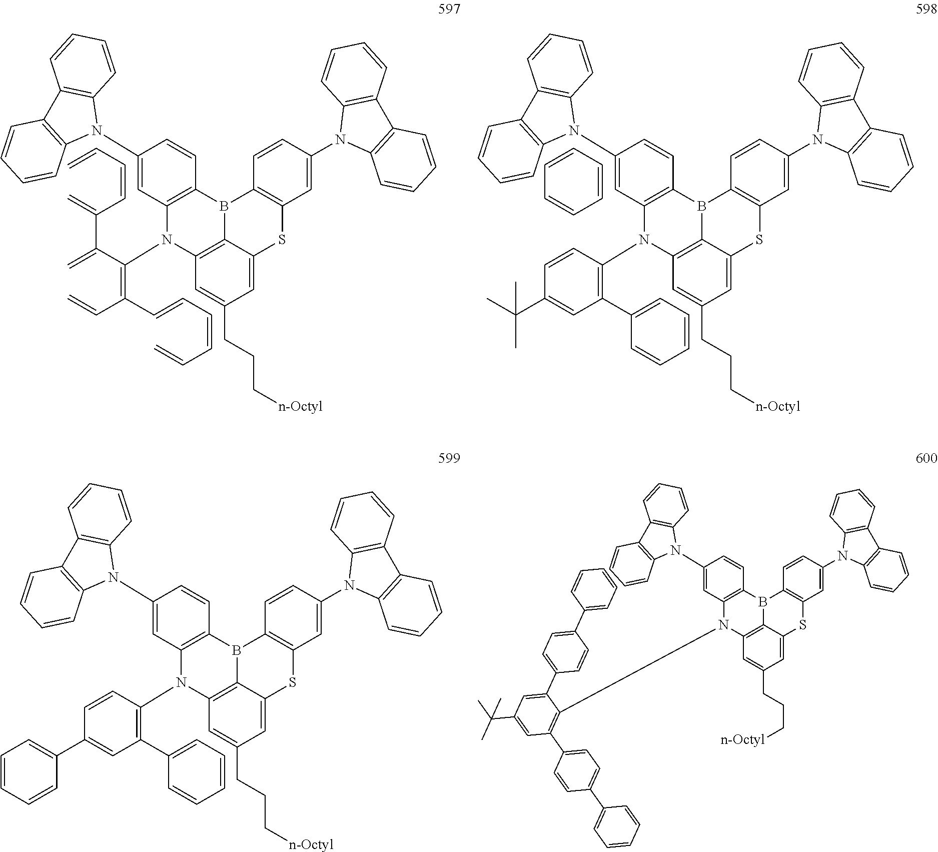

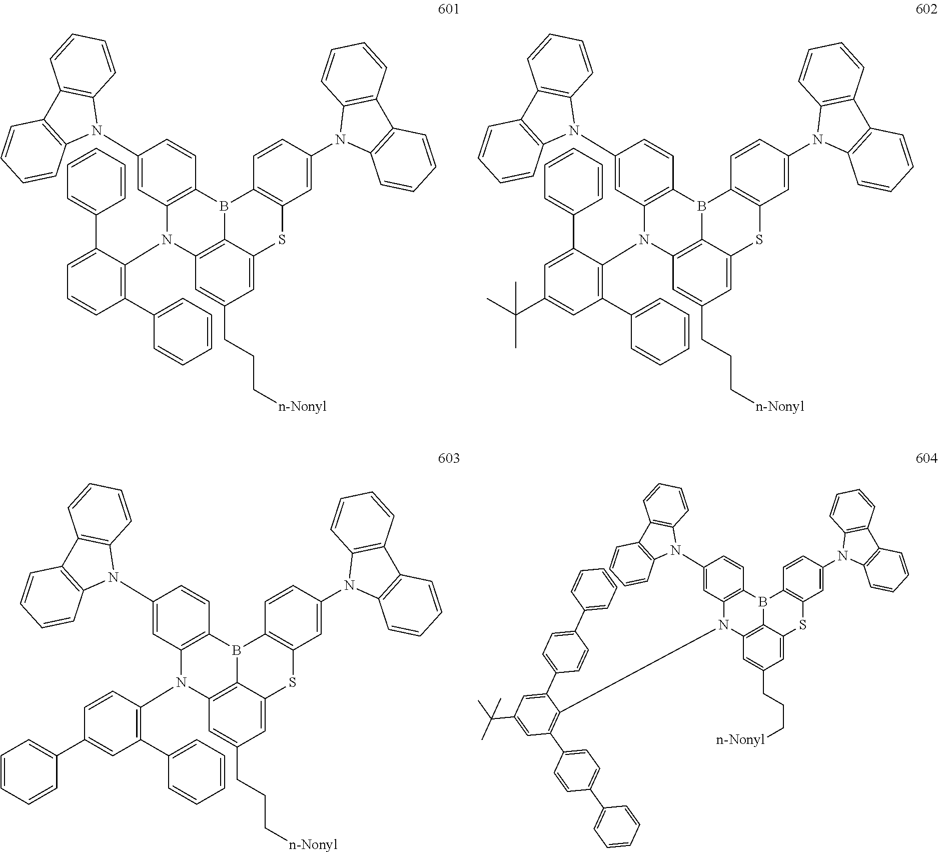

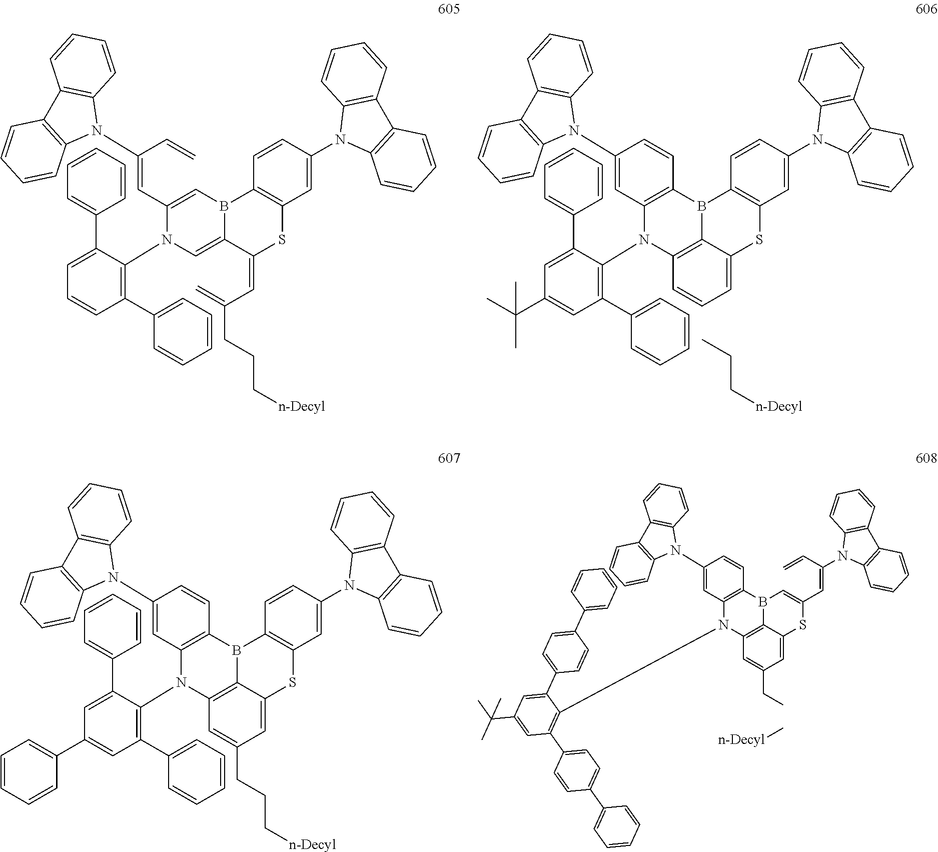

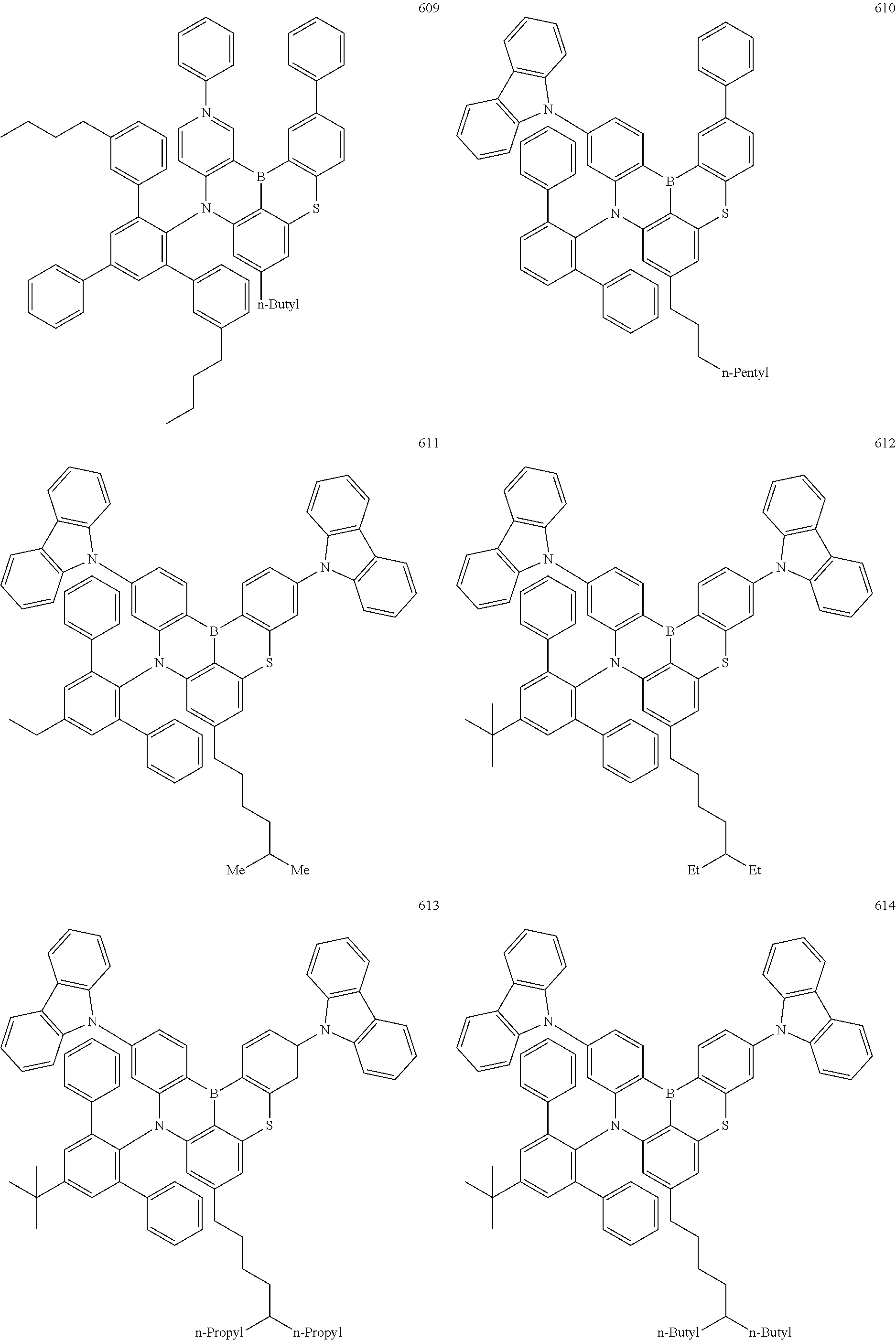

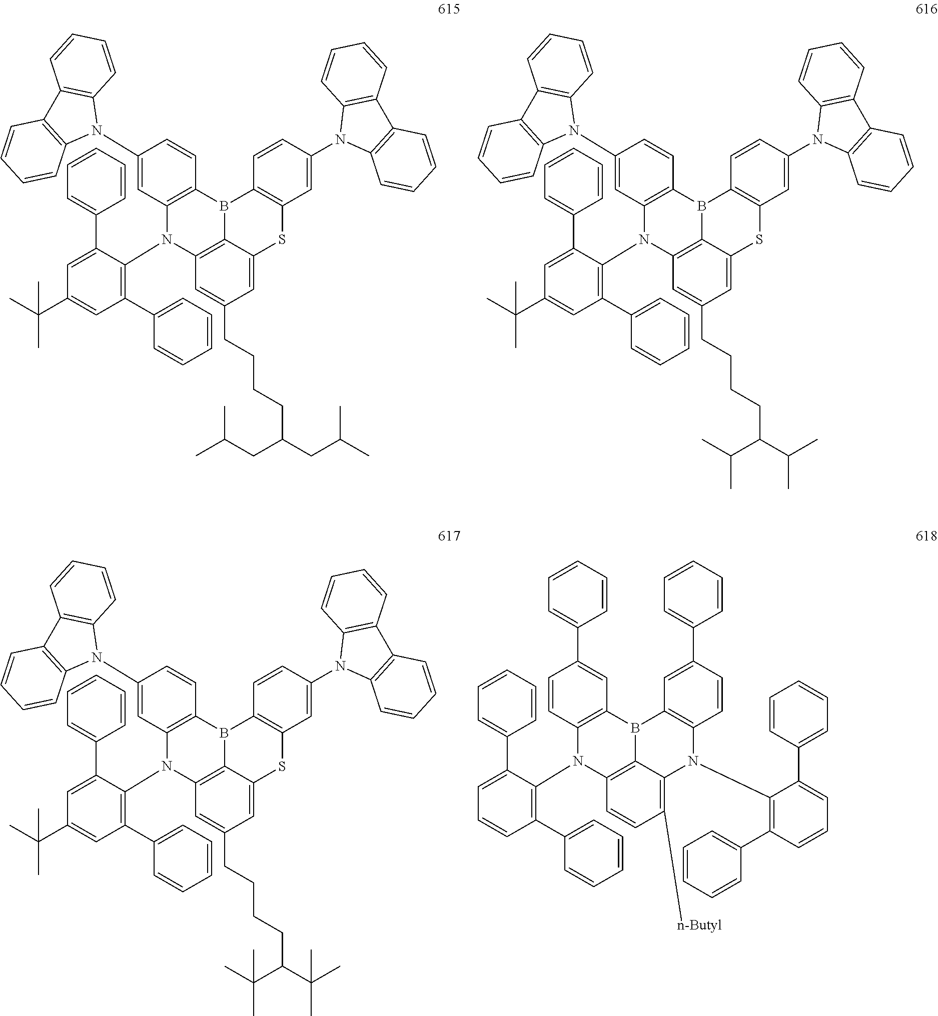

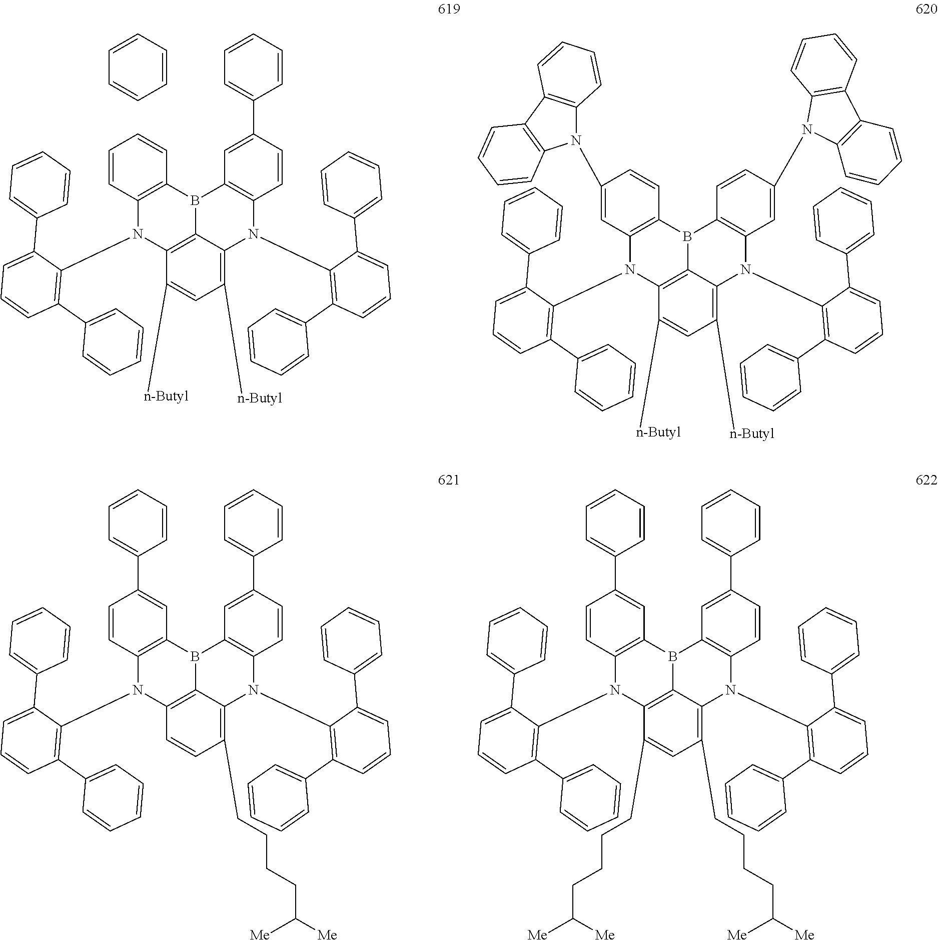

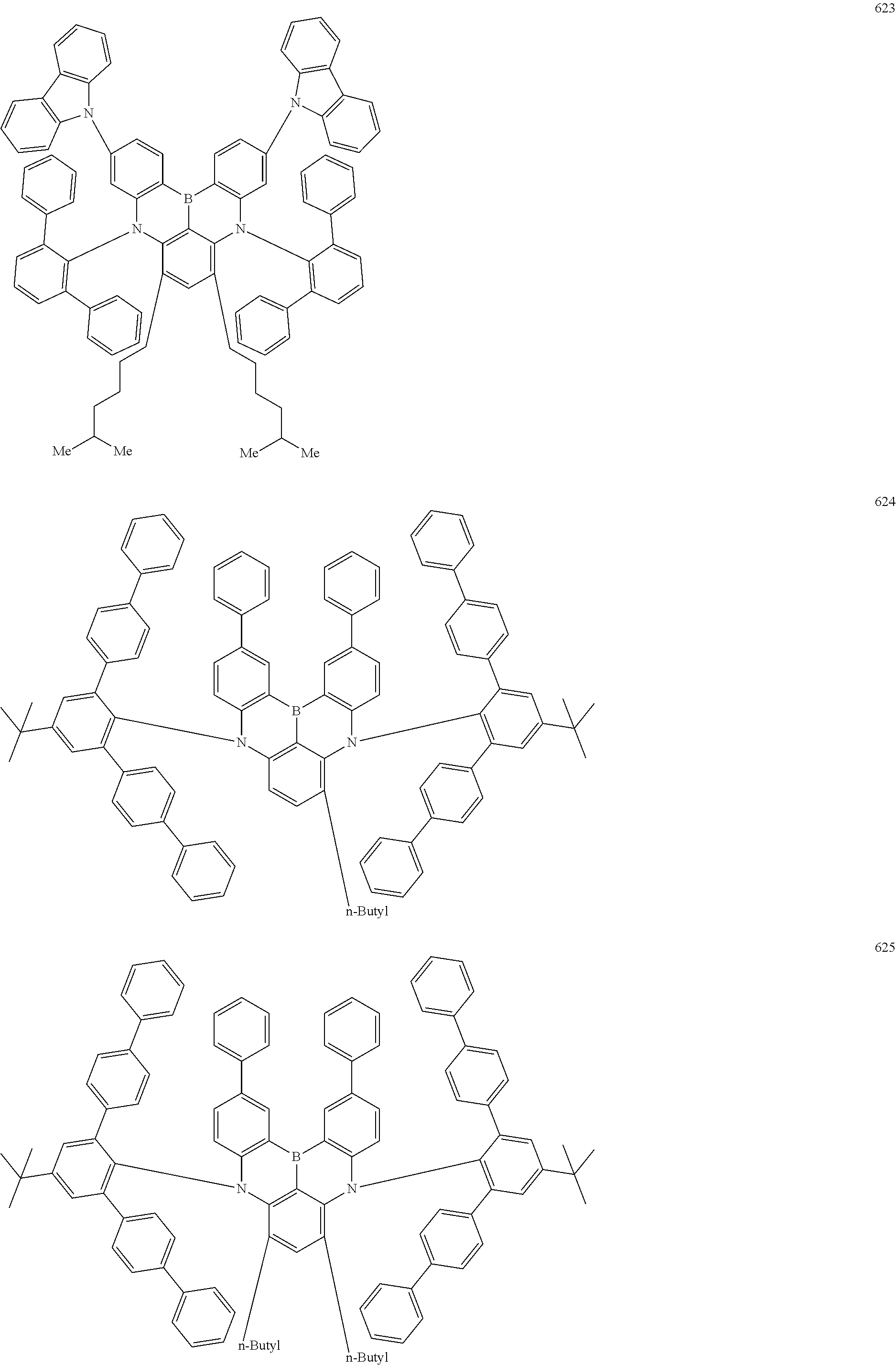

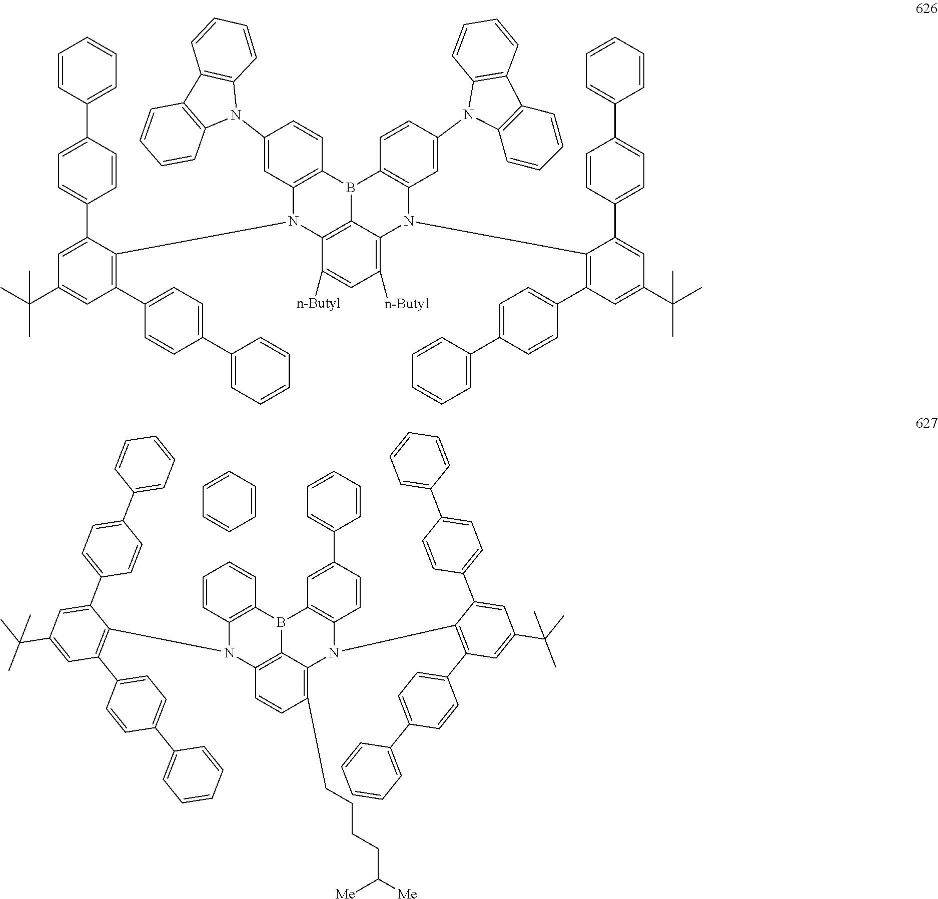

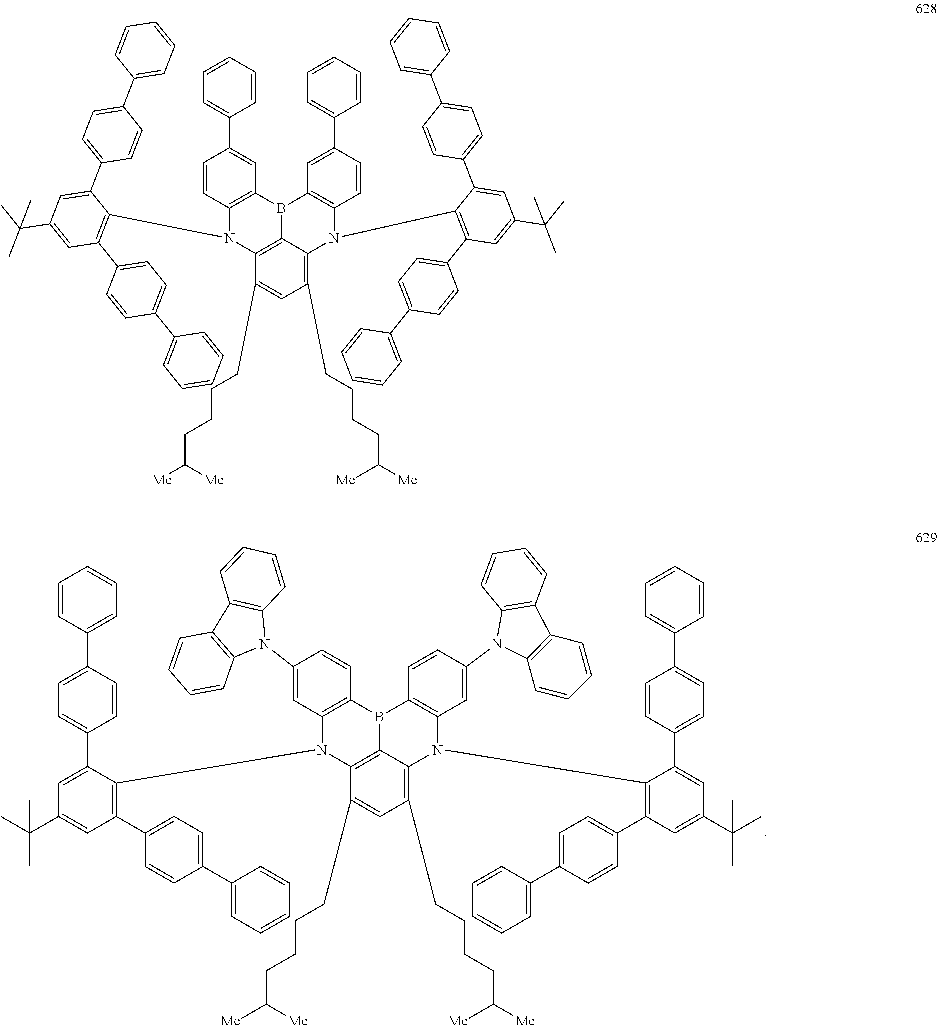

In Compound Group 1, D represents a deuterium atom, Me represents an unsubstituted methyl group, Et represents an unsubstituted ethyl group, n-Pr represents an n-propyl group, n-Bu and n-Butyl each represent an n-butyl group, n-Pentyl represents an n-pentyl group, n-Hexyl represents an n-hexyl group, n-Heptyl represents an n-heptyl group, n-Octyl represents an n-octyl group, n-Nonyl represents an n-nonyl group, and n-Decyl represents an n-decyl group.

The fused polycyclic compound represented by Formula 1 has a structure of a fused ring core that includes a first substituent, and may thus contribute to improved emission properties and long lifetime.

The fused polycyclic compound represented by Formula 1 may include a fused ring core of first to third aromatic rings that are fused via a boron atom, a first heteroatom, and a second heteroatom, and may have a structure in which a first substituent is bonded to the third aromatic ring. The first substituent may include a linear alkyl group of 4 or more carbon atoms.

Since the fused polycyclic compound has a structure of a fused ring core including a first substituent, improved emission properties and element-life characteristics may be achieved. Since the fused polycyclic compound includes a first substituent, intermolecular interaction may be suppressed through steric hindrance effects, and aggregation may be controlled. Accordingly, emission efficiency may be increased, and layer-forming quality during the formation of an organic layer of a light emitting element ED may be improved. According to an embodiment, the fused ring core includes a first substituent having a low radical dissociation rate, the concentration of a triplet excitation state may be reduced, and deterioration may be reduced to achieve long lifetime. By the inclusion of a first substituent having 4 or more carbon atoms, distance between adjacent molecules may increase to suppress Dexter energy transfer, and the deterioration of lifetime may be suppressed. Accordingly, if the fused polycyclic compound is applied to an emission layer EML of the light emitting element ED, emission properties may be improved, and element lifetime may be improved.

A full width at half maximum (FWHM) of an emission spectrum of the fused polycyclic compound represented by Formula 1 may be in a range of about 10 to 50 nm. For example, a FWHM of an emission spectrum of the fused polycyclic compound represented by Formula 1 may be in a range of about 20 to 40 nm. Since the FWHM of an emission spectrum of the fused polycyclic compound has the above-described range, and if applied to a light emitting element, emission efficiency may be improved. If the fused polycyclic compound is used as a material for a blue light emitting element, element lifetime may be improved.

The fused polycyclic compound may be a material for emitting thermally activated delayed fluorescence (TADF). The fused polycyclic compound may be a thermally activated delayed fluorescence dopant having a difference (ΔE_{ST}) between a lowest triplet excitation energy level (T1 level) and a lowest singlet excitation energy level (S1 level) equal to or less than about 0.6 cV. For example, the fused polycyclic compound may be a thermally activated delayed fluorescence dopant having a difference (ΔE_{ST}) between a lowest triplet excitation energy level (T1 level) and a lowest singlet excitation energy level (S1 level) equal to or less than about 0.2 cV.

The fused polycyclic compound may be a light-emitting material having a central wavelength in a range of about 430 nm to about 490 nm. For example, the fused polycyclic compound may be a blue thermally activated delayed fluorescence (TADF) dopant. However, embodiments are not limited thereto, and if the fused polycyclic compound is used as a light-emitting material, the first dopant may be used as a dopant material emitting light in various wavelength regions, such as a red emitting dopant or a green emitting dopant.

In the light emitting element ED, the emission layer EML may emit delayed fluorescence. For example, the emission layer EML may emit thermally activated delayed fluorescence (TADF).

The emission layer EML of the light emitting element ED may emit blue light. In an embodiment, the emission layer EML of the light emitting element ED may emit blue light having a wavelength equal to or less than about 490 nm. In an embodiment, when an emission layer EML of the light emitting element ED includes a fused polycyclic compound represented by Formula 1, the emission layer EML may emit light having a central wavelength in a range of about 430 nm to about 490 nm. However, embodiments are not limited thereto, and the emission layer EML may emit green light or red light.

The fused polycyclic compound may be included in an emission layer EML. The fused polycyclic compound may be included in an emission layer EML as a dopant material. The fused polycyclic compound may be a thermally activated delayed fluorescence emitting material. The fused polycyclic compound may be used as a thermally activated delayed fluorescence dopant. For example, in the light emitting element ED, the emission layer EML may include at least one fused polycyclic compound selected from Compound Group 1 as a thermally activated delayed fluorescence dopant. However, the use of the fused polycyclic compound is not limited thereto.

In an embodiment, the emission layer EML may include multiple compounds. In an embodiment, the emission layer EML may include the fused polycyclic compound represented by Formula 1 as a first compound, and at least one of a second compound represented by Formula HT-1, a third compound represented by Formula ET-1, or a fourth compound represented by Formula D-1 below:

In an embodiment, the emission layer EML may include the first compound represented by Formula 1, and may further include at least one of a second compound represented by Formula HT-1, a third compound represented by Formula ET-1, or a fourth compound represented by Formula D-1.

In an embodiment, the emission layer EML may further include a second compound represented by Formula HT-1. In an embodiment, the second compound may be used as a hole transporting host material in the emission layer EML.

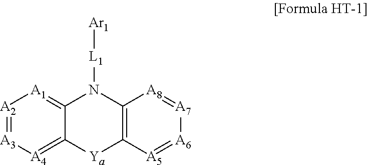

In Formula HT-1, A₁ to A₈ may each independently be N or C(R₅₁). For example, all of A₁ to A₈ may each independently be C(R₅₁). In an embodiment, one A₁ to A₈ may be N, and the remainder of A₁ to A₈ may each independently be C(R₅₁).

In Formula HT-1, L₁ may be a direct linkage, a substituted or unsubstituted arylene group having 6 to 30 ring-forming carbon atoms, or a substituted or unsubstituted heteroarylene group having 2 to 30 ring-forming carbon atoms. For example, Li may be a direct linkage, a substituted or unsubstituted phenylene group, a substituted or unsubstituted divalent biphenyl group, a substituted or unsubstituted divalent carbazole group, etc., but embodiments are not limited thereto.

In Formula HT-1, Ya may be a direct linkage, C(R₅₂)(R₅₃), or Si(R₅₄)(R₅₅). For example, the two benzene rings that are bonded to the nitrogen atom in Formula HT-1 may be bonded to each other via a direct linkage,

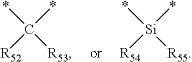

In Formula HT-1, when Ya is a direct linkage, the second compound represented by Formula HT-1 may include a carbazole moiety.

In Formula HT-1, Ar₁ may be a substituted or unsubstituted aryl group having 6 to 30 ring-forming carbon atoms or a substituted or unsubstituted heteroaryl group having 2 to 30 ring-forming carbon atoms. For example, Ar₁ may be a substituted or unsubstituted carbazole group, a substituted or unsubstituted dibenzofuran group, a substituted or unsubstituted dibenzothiophene group, a substituted or unsubstituted biphenyl group, etc., but embodiments are not limited thereto.

In Formula HT-1, R₅₁ to R₅₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, a substituted or unsubstituted heteroaryl group having 2 to 60 ring-forming carbon atoms, or bonded to an adjacent group to form a ring. For example, R₅₁ to R₅₅ may each independently be a hydrogen atom or a deuterium atom. For example, R₅₁ to R₅₅ may each independently be an unsubstituted methyl group or an unsubstituted phenyl group.

In an embodiment, the second compound represented by Formula HT-1 may be selected from Compound Group 2. In an embodiment, in the light emitting element ED, the second compound may include at least one compound selected from Compound Group 2.

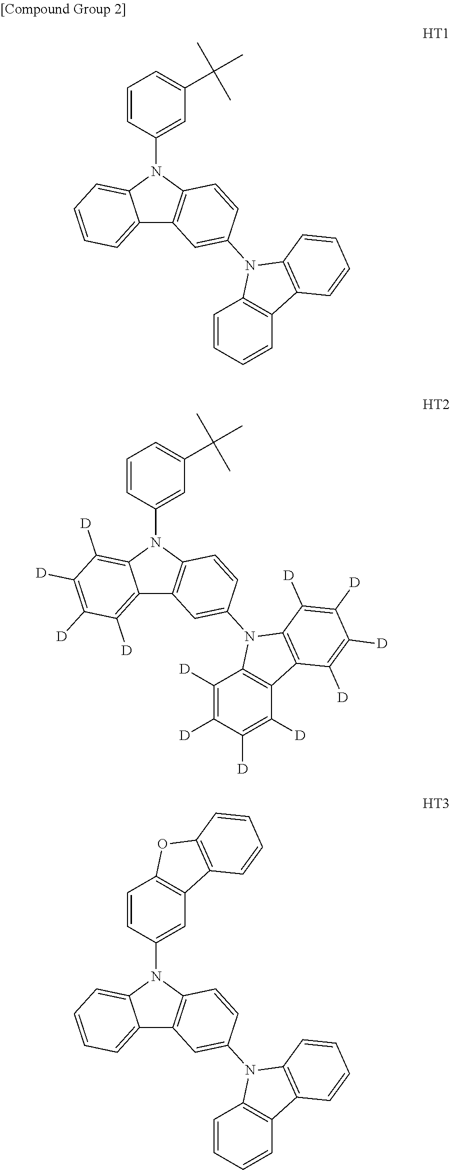 [SMILES: CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12]

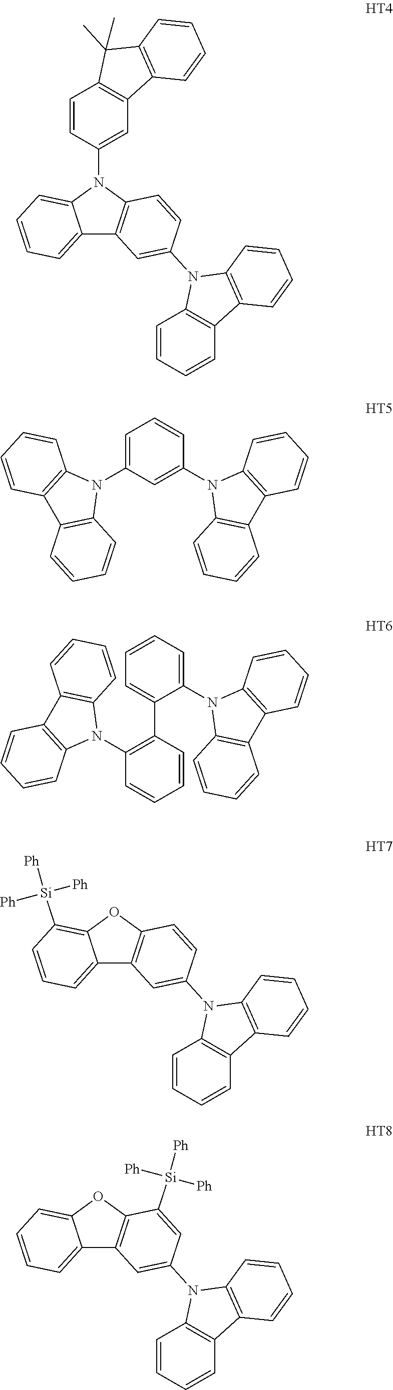 [SMILES: CC1(C)c2ccccc2-c2cc(-n3c4ccccc4c4cc(-n5c6ccccc6c6ccccc65)ccc43)ccc21 ; c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1 ; c1ccc([Si](c2ccccc2)(c2ccccc2)c2cc(-n3c4ccccc4c4ccccc43)cc3c2oc2ccccc23)cc1]

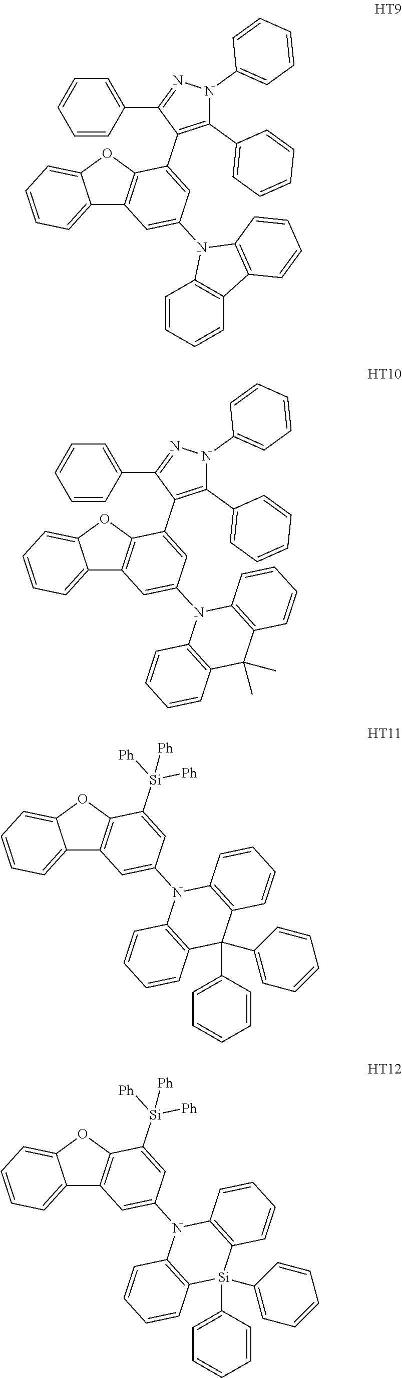

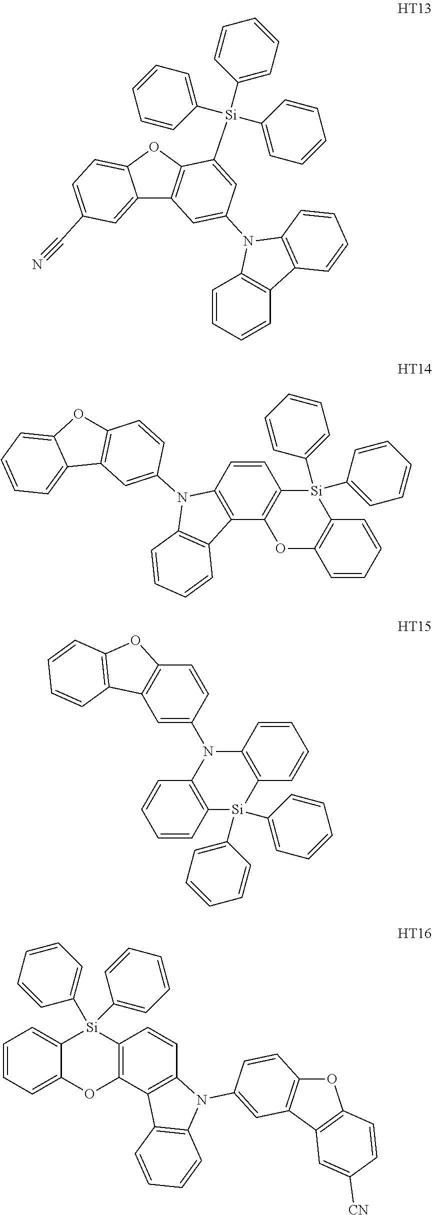 [SMILES: N#Cc1ccc2oc3c([Si](c4ccccc4)(c4ccccc4)c4ccccc4)cc(-n4c5ccccc5c5ccccc54)cc3c2c1 ; c1ccc([Si]2(c3ccccc3)c3ccccc3Oc3c2ccc2c3c3ccccc3n2-c2ccc3oc4ccccc4c3c2)cc1 ; c1ccc([Si]2(c3ccccc3)c3ccccc3N(c3ccc4oc5ccccc5c4c3)c3ccccc32)cc1 ; N#Cc1ccc2oc3ccc(-n4c5ccccc5c5c6c(ccc54)[Si](c4ccccc4)(c4ccccc4)c4ccccc4O6)cc3c2c1]

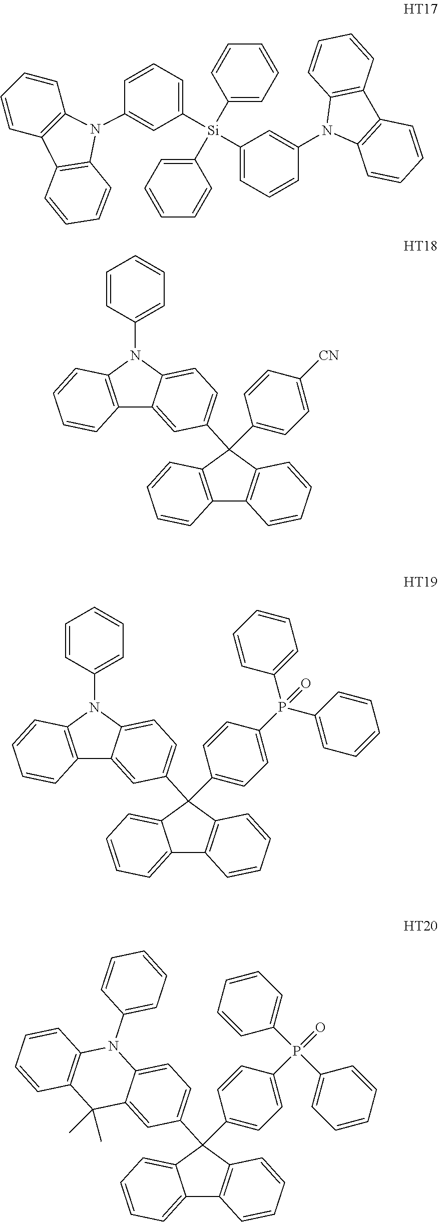

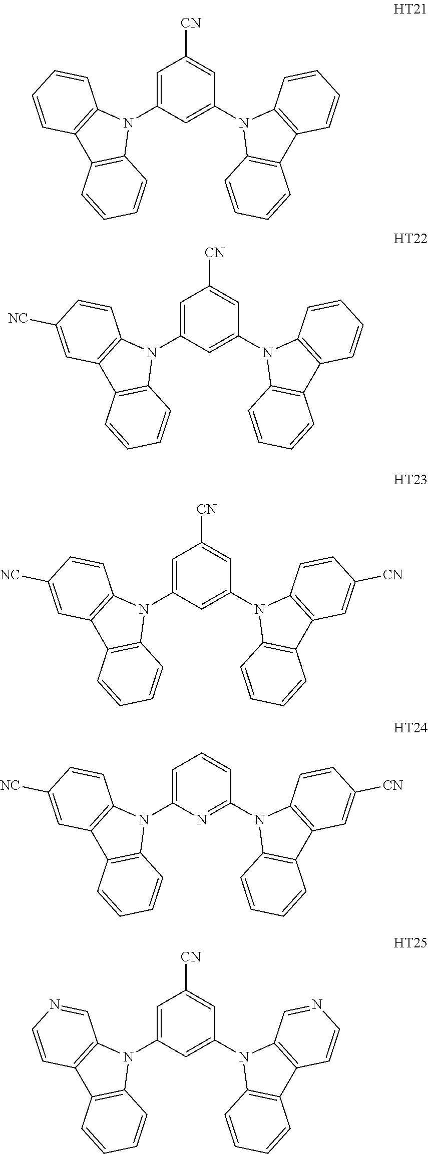 [SMILES: N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1 ; N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1 ; N#Cc1cc(-n2c3ccccc3c3ccncc32)cc(-n2c3ccccc3c3ccncc32)c1]

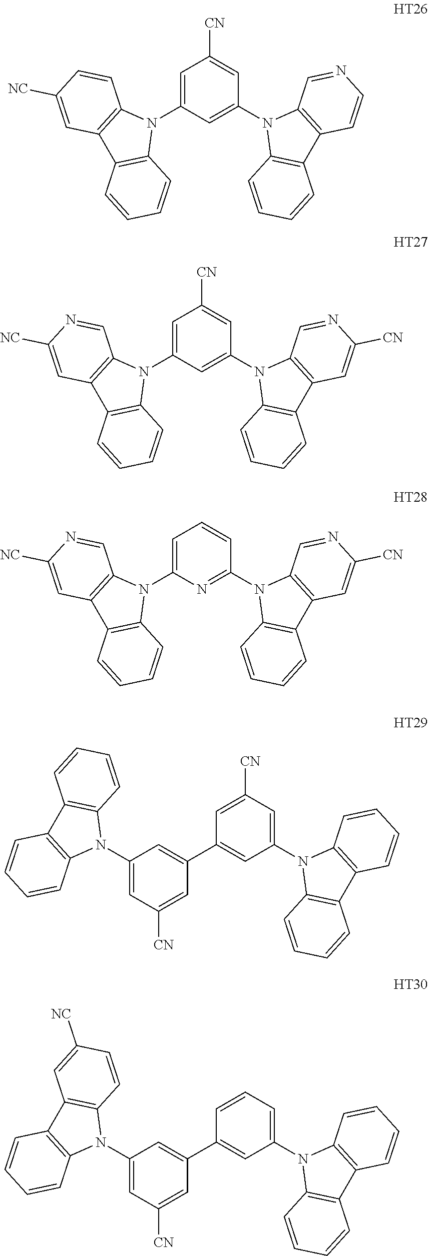 [SMILES: N#Cc1cc(-n2c3ccccc3c3cc(C#N)ccc32)cc(-n2c3ccccc3c3ccncc32)c1 ; N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1 ; N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1]

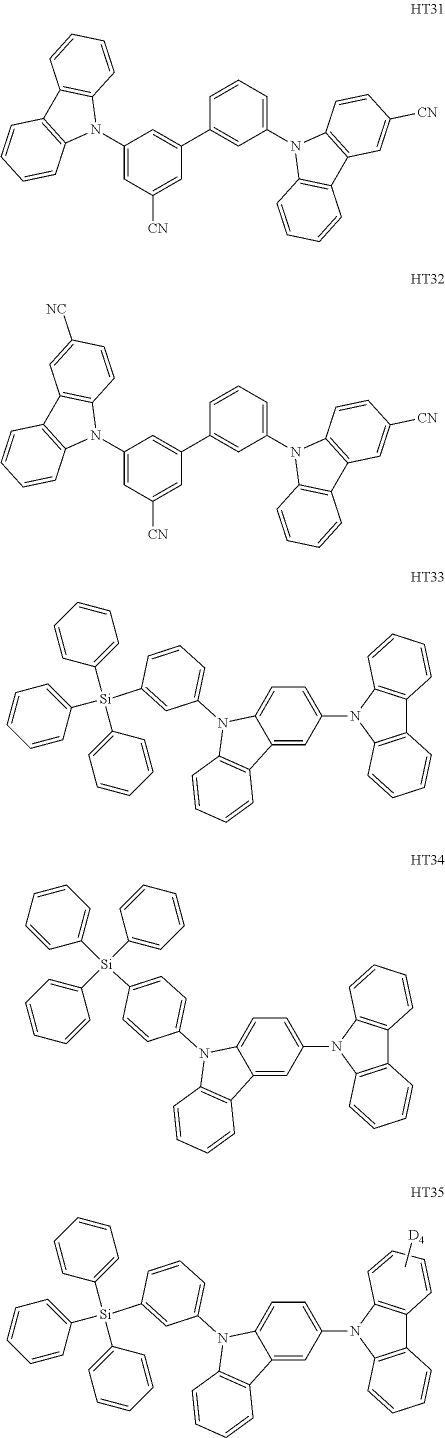

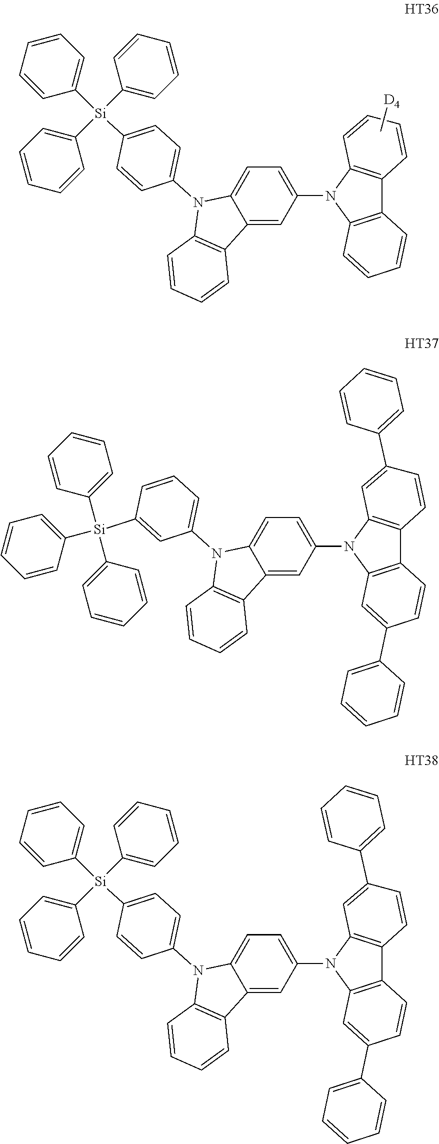

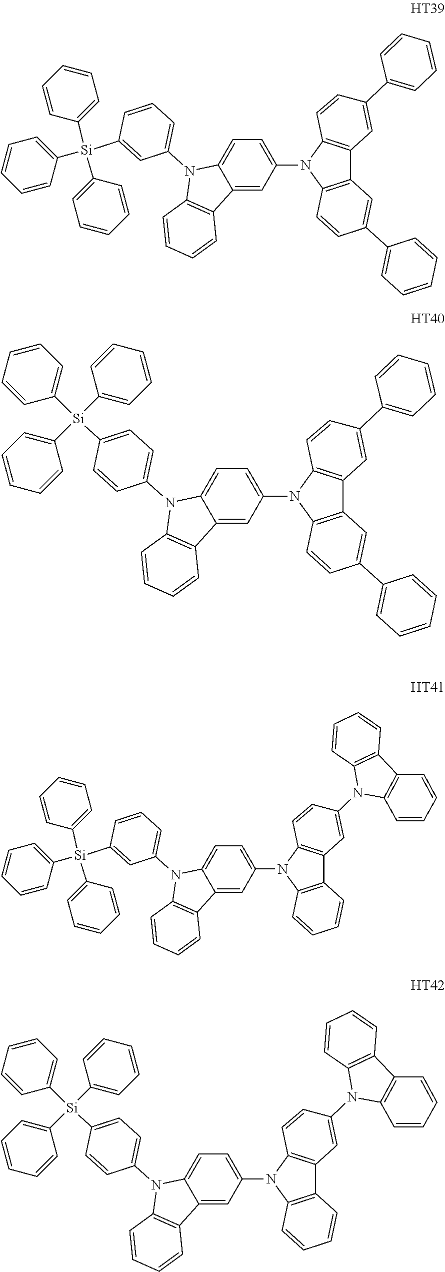 [SMILES: c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1 ; c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1]

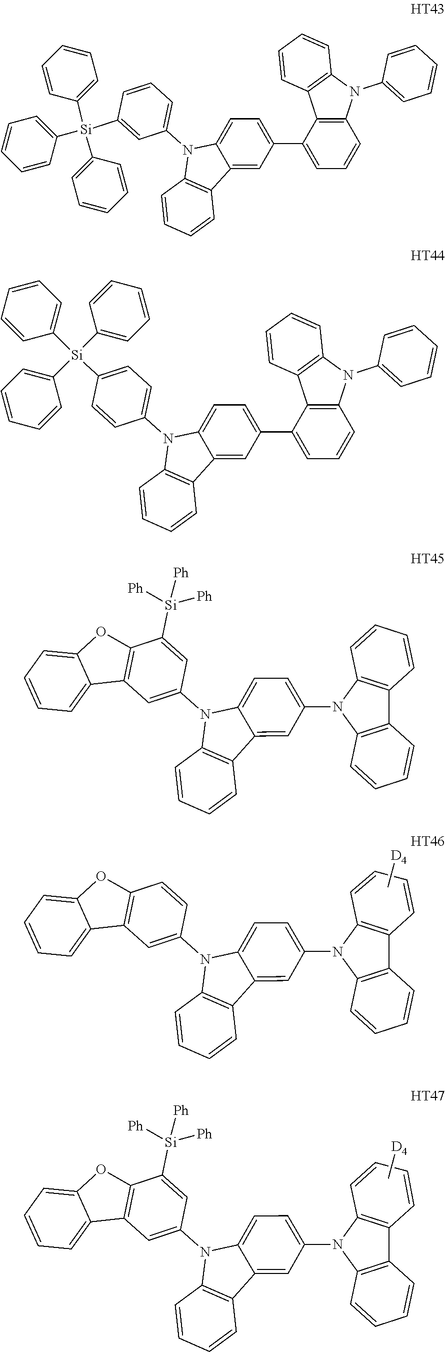

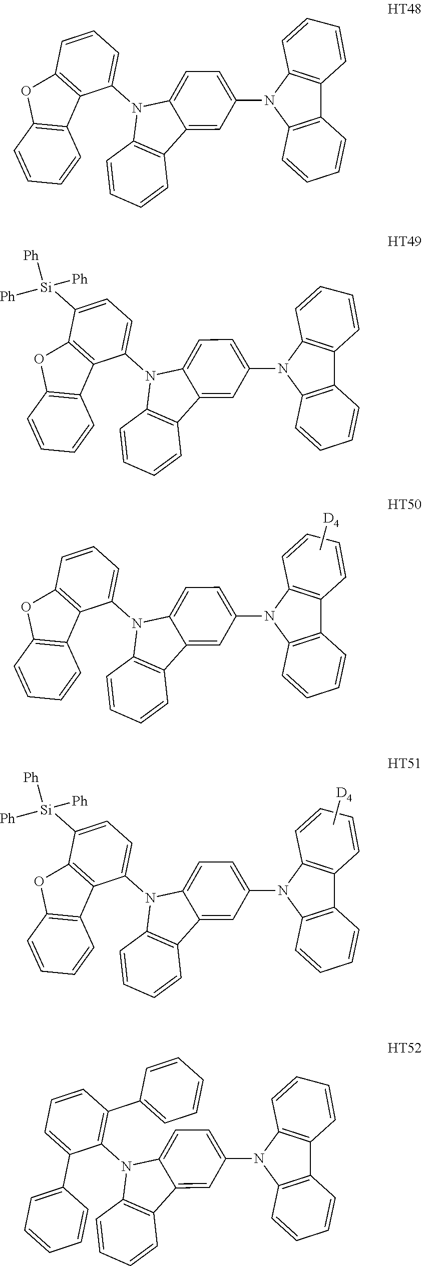

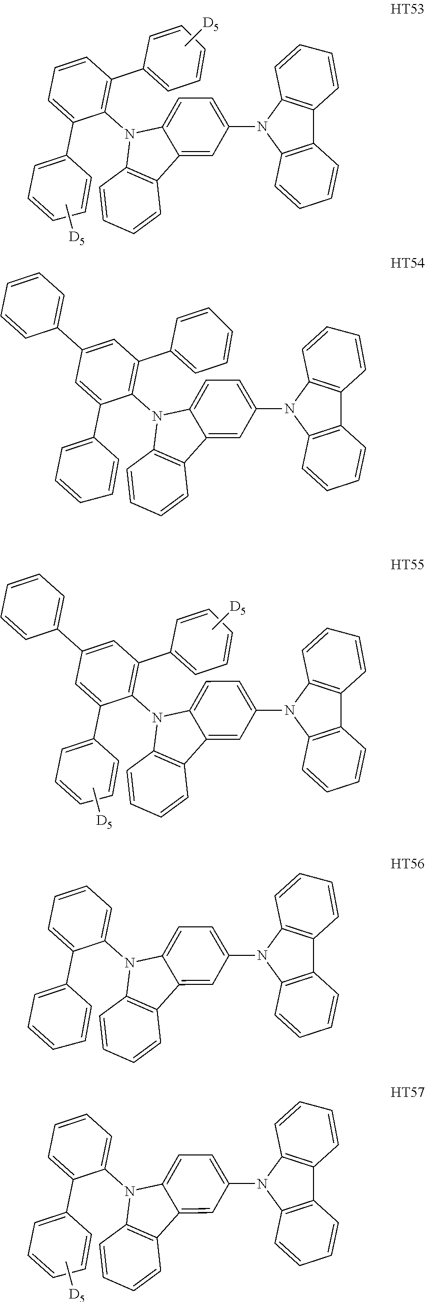

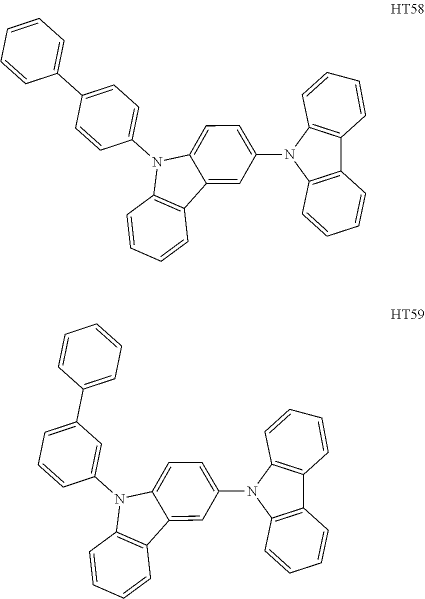 [SMILES: c1ccc(-c2ccc(-n3c4ccccc4c4cc(-n5c6ccccc6c6ccccc65)ccc43)cc2)cc1 ; c1ccc(-c2cccc(-n3c4ccccc4c4cc(-n5c6ccccc6c6ccccc65)ccc43)c2)cc1]

In Compound Group 2, D represents a deuterium atom, and Ph represents a substituted or unsubstituted phenyl group. For example, in Compound Group 2, Ph may represent an unsubstituted phenyl group.

In an embodiment, the emission layer EML may further include a third compound represented by Formula ET-1. In an embodiment, the third compound may be used as an electron transport host material in the emission layer EML.

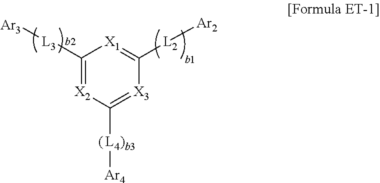

In Formula ET-1, at least one of X₁ to X₃ may each be N, and the remainder of X₁ to X₃ may each independently be C(R₅₆). For example, one of X₁ to X₃ may be N, and the remainder of X₁ to X₃ may each independently be C(R₅₆). Thus, the third compound represented by Formula ET-1 may include a pyridine moiety. As another example, two of X₁ to X₃ may each be N, and the remainder of X₁ to X₃ may be C(R₅₆). Thus, the third compound represented by Formula ET-1 may include a pyrimidine moiety. As yet another example, X₁ to X₃ may each be N. Thus, the third compound represented by Formula ET-1 may include a triazine moiety.

In Formula ET-1, R₅₆ may be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms.

In Formula ET-1, b1 to b3 may each independently be an integer from 0 to 10.

In Formula ET-1, Ar₂ to Ar₄ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Ar₂ to Ar₄ may each independently be a substituted or unsubstituted phenyl group or a substituted or unsubstituted carbazole group.

In Formula ET-1, L₂ to L₄ may each independently be a direct linkage, a substituted or unsubstituted arylene group having 6 to 30 ring-forming carbon atoms, or a substituted or unsubstituted heteroarylene group having 2 to 30 ring-forming carbon atoms. When b1 to b3 are each 2 or greater, L₂ to L₄ may each independently be a substituted or unsubstituted arylene group having 6 to 30 ring-forming carbon atoms or a substituted or unsubstituted heteroarylene group having 2 to 30 ring-forming carbon atoms.

In an embodiment, the third compound represented by Formula ET-1 may be selected from Compound Group 3. In an embodiment, in the light emitting element ED, the third compound may include at least one compound selected from Compound Group 3.

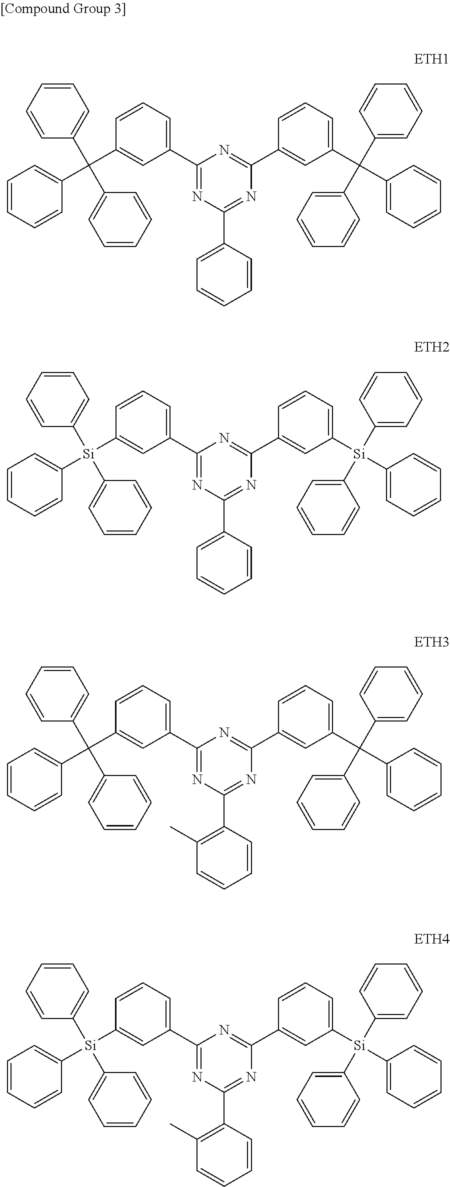 [SMILES: c1ccc(-c2nc(-c3cccc(C(c4ccccc4)(c4ccccc4)c4ccccc4)c3)nc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)nc(-c2cccc([Si](c3ccccc3)(c3ccccc3)c3ccccc3)c2)n1]

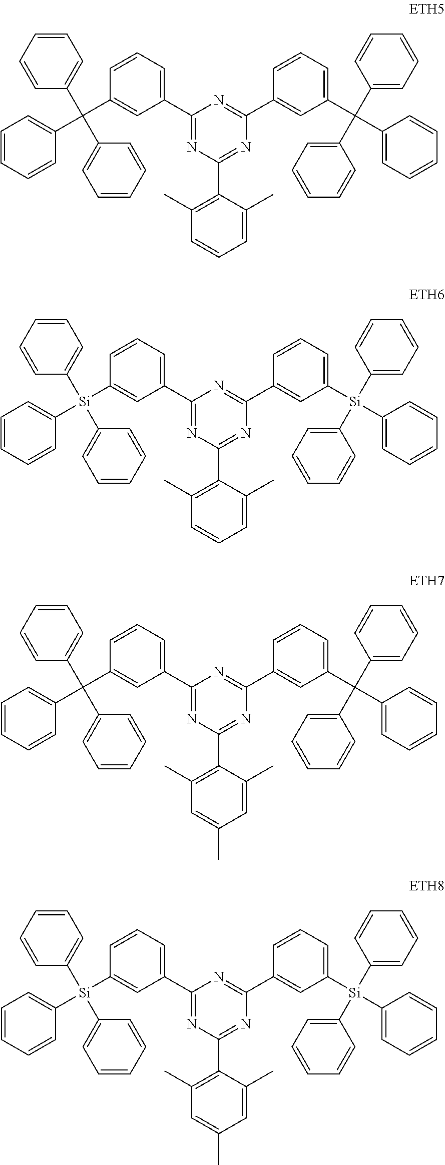 [SMILES: Cc1cccc(C)c1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)nc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)nc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)nc(-c3cccc([Si](c4ccccc4)(c4ccccc4)c4ccccc4)c3)n2)c(C)c1]

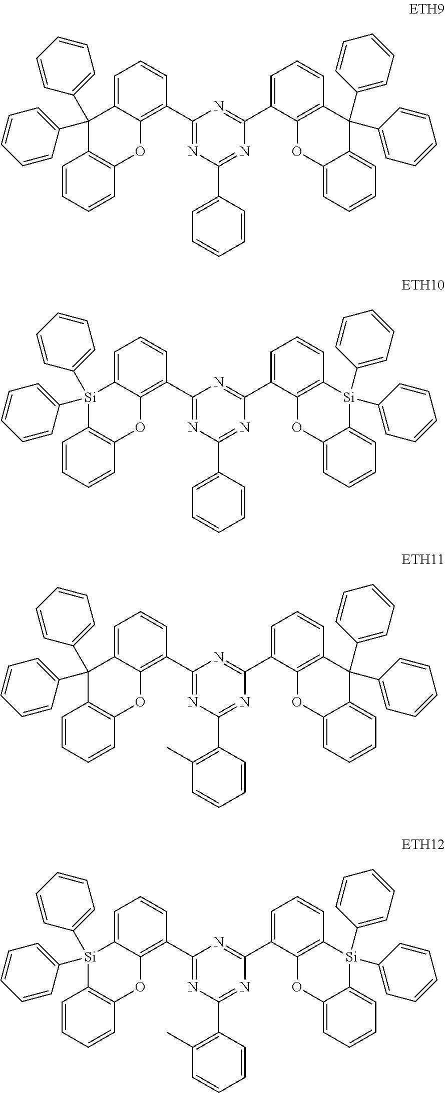 [SMILES: c1ccc(-c2nc(-c3cccc4c3Oc3ccccc3C4(c3ccccc3)c3ccccc3)nc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1]

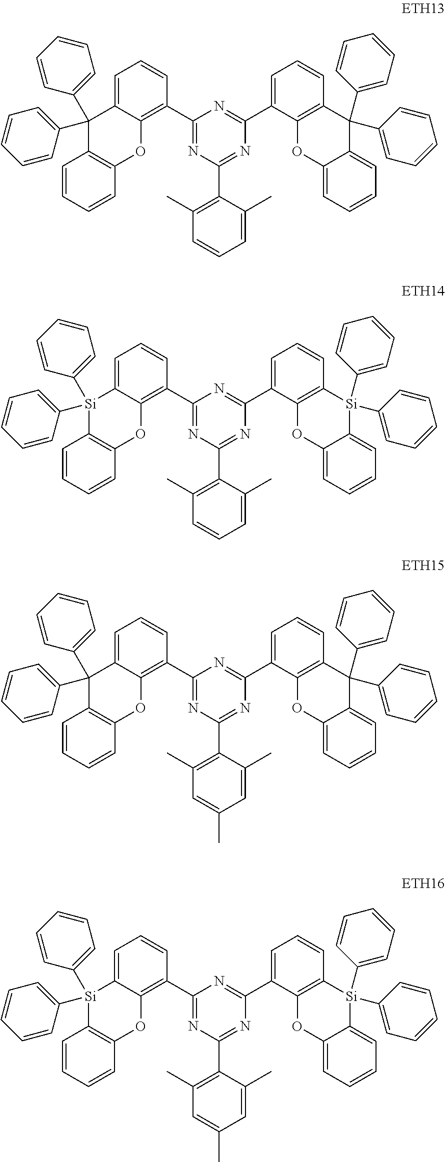 [SMILES: Cc1cccc(C)c1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)nc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)c(C)c1]

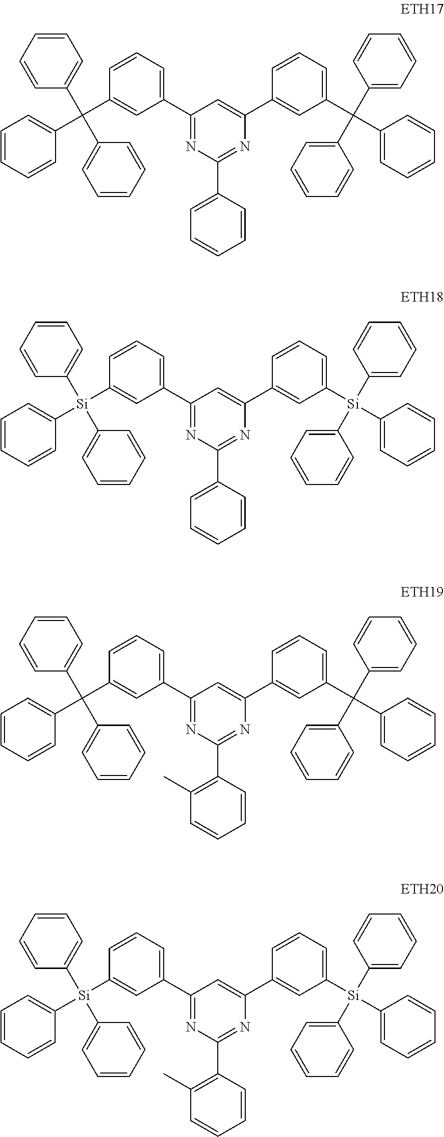 [SMILES: c1ccc(-c2nc(-c3cccc(C(c4ccccc4)(c4ccccc4)c4ccccc4)c3)cc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)cc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)cc(-c2cccc([Si](c3ccccc3)(c3ccccc3)c3ccccc3)c2)n1]

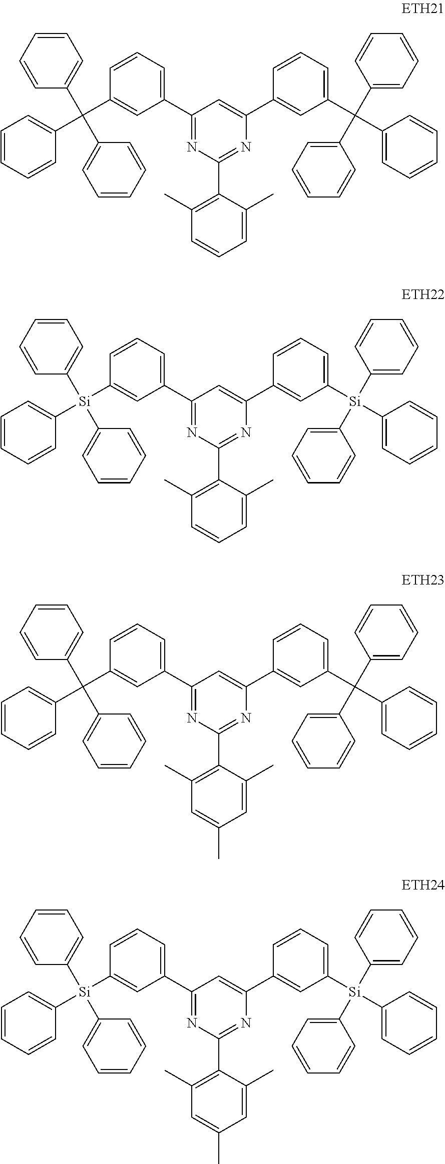 [SMILES: Cc1cccc(C)c1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)cc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)cc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)cc(-c3cccc([Si](c4ccccc4)(c4ccccc4)c4ccccc4)c3)n2)c(C)c1]

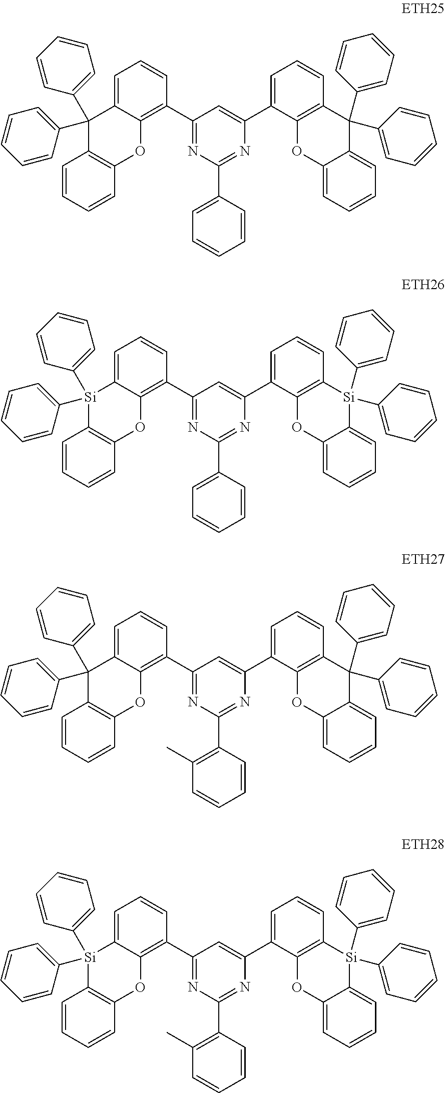 [SMILES: c1ccc(-c2nc(-c3cccc4c3Oc3ccccc3C4(c3ccccc3)c3ccccc3)cc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1]

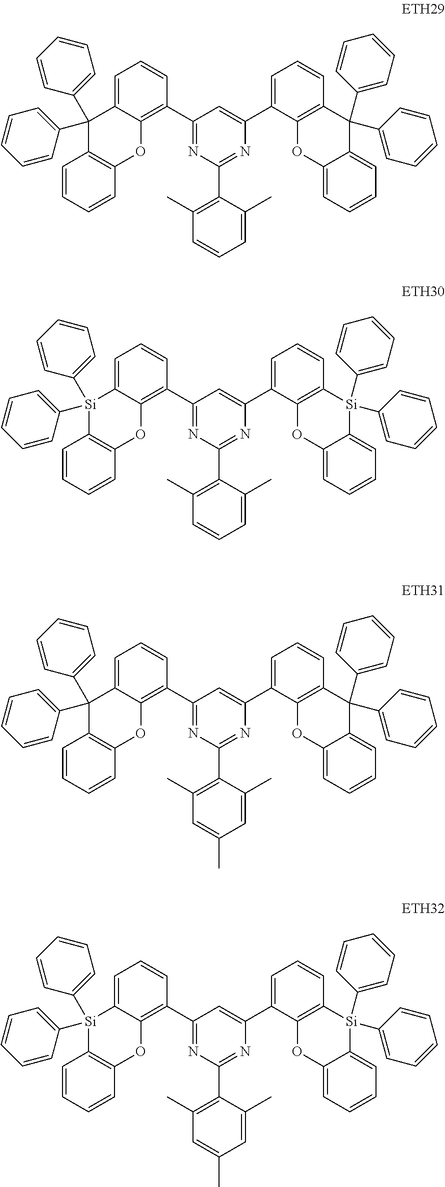 [SMILES: Cc1cccc(C)c1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)cc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)c(C)c1]

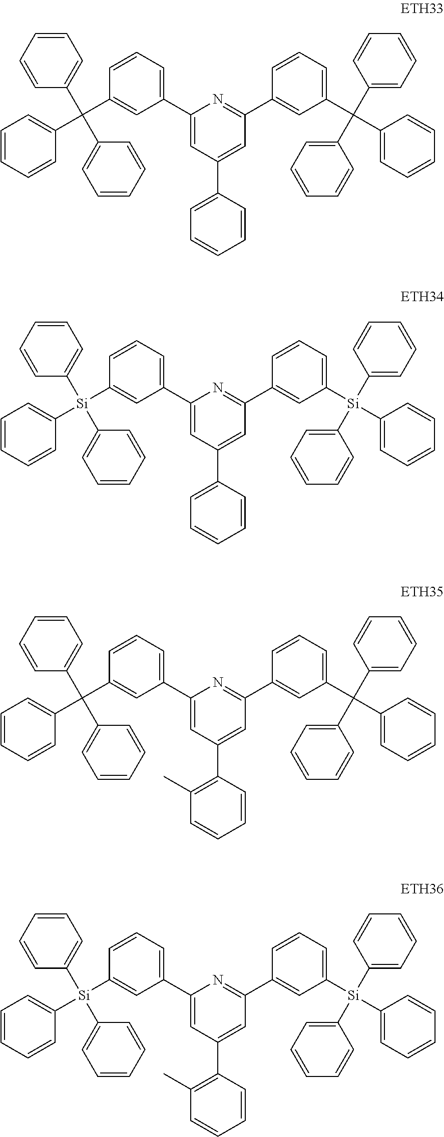 [SMILES: c1ccc(-c2cc(-c3cccc(C(c4ccccc4)(c4ccccc4)c4ccccc4)c3)nc(-c3cccc(C(c4ccccc4)(c4ccccc4)c4ccccc4)c3)c2)cc1 ; c1ccc(-c2cc(-c3cccc([Si](c4ccccc4)(c4ccccc4)c4ccccc4)c3)nc(-c3cccc([Si](c4ccccc4)(c4ccccc4)c4ccccc4)c3)c2)cc1 ; Cc1ccccc1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1ccccc1-c1cc(-c2cccc([Si](c3ccccc3)(c3ccccc3)c3ccccc3)c2)nc(-c2cccc([Si](c3ccccc3)(c3ccccc3)c3ccccc3)c2)c1]

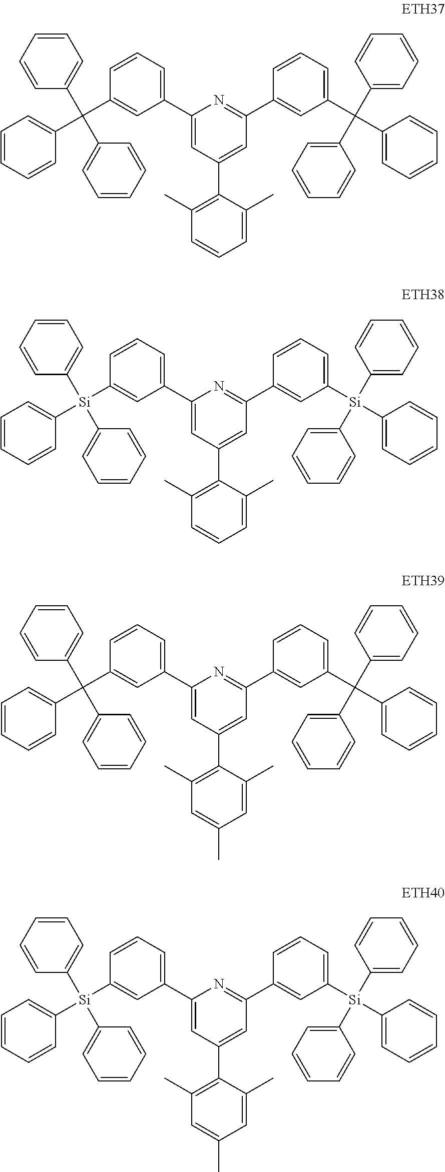 [SMILES: Cc1cccc(C)c1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1cccc(C)c1-c1cc(-c2cccc([Si](c3ccccc3)(c3ccccc3)c3ccccc3)c2)nc(-c2cccc([Si](c3ccccc3)(c3ccccc3)c3ccccc3)c2)c1 ; Cc1cc(C)c(-c2cc(-c3cccc(C(c4ccccc4)(c4ccccc4)c4ccccc4)c3)nc(-c3cccc(C(c4ccccc4)(c4ccccc4)c4ccccc4)c3)c2)c(C)c1 ; Cc1cc(C)c(-c2cc(-c3cccc([Si](c4ccccc4)(c4ccccc4)c4ccccc4)c3)nc(-c3cccc([Si](c4ccccc4)(c4ccccc4)c4ccccc4)c3)c2)c(C)c1]

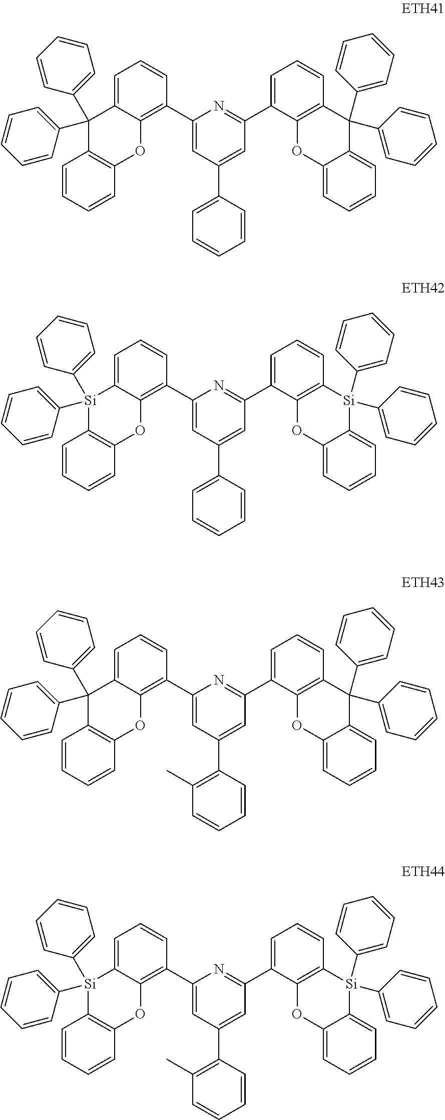 [SMILES: c1ccc(-c2cc(-c3cccc4c3Oc3ccccc3C4(c3ccccc3)c3ccccc3)nc(-c3cccc4c3Oc3ccccc3C4(c3ccccc3)c3ccccc3)c2)cc1 ; c1ccc(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)cc1 ; Cc1ccccc1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1ccccc1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1]

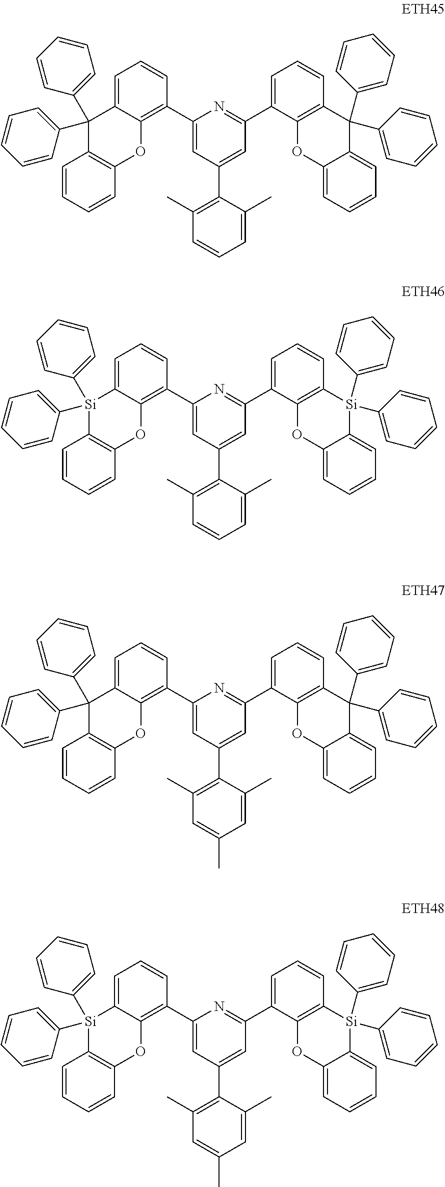 [SMILES: Cc1cccc(C)c1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1cccc(C)c1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1 ; Cc1cc(C)c(-c2cc(-c3cccc4c3Oc3ccccc3C4(c3ccccc3)c3ccccc3)nc(-c3cccc4c3Oc3ccccc3C4(c3ccccc3)c3ccccc3)c2)c(C)c1 ; Cc1cc(C)c(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)c(C)c1]

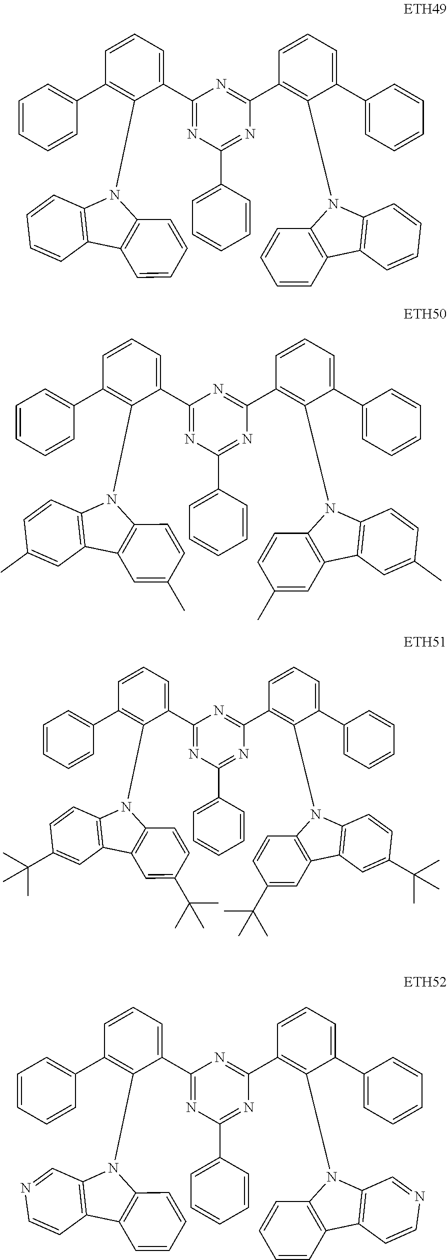

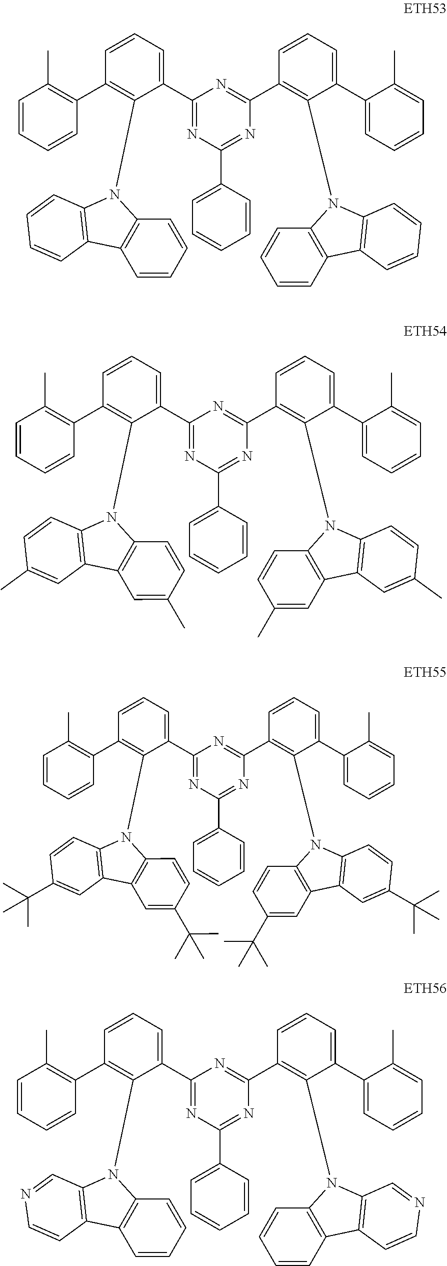

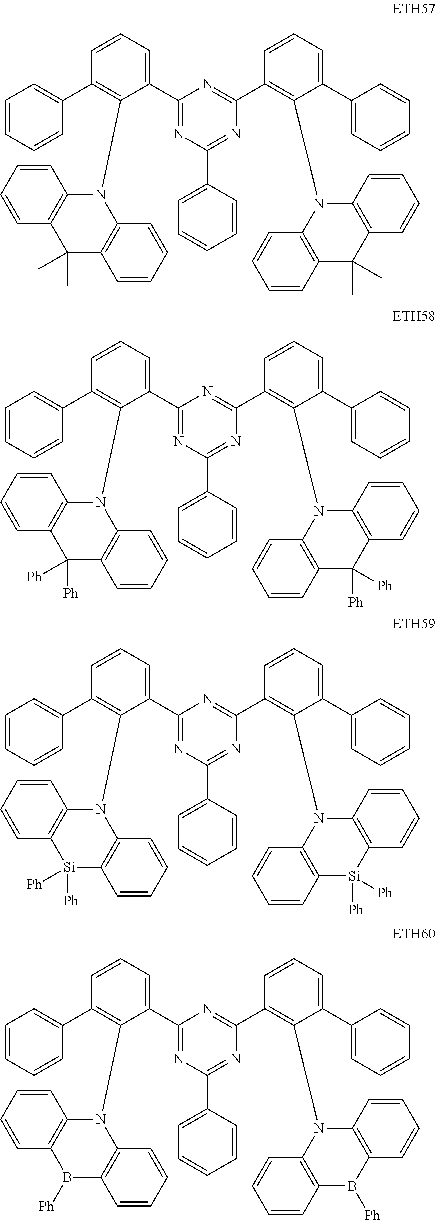

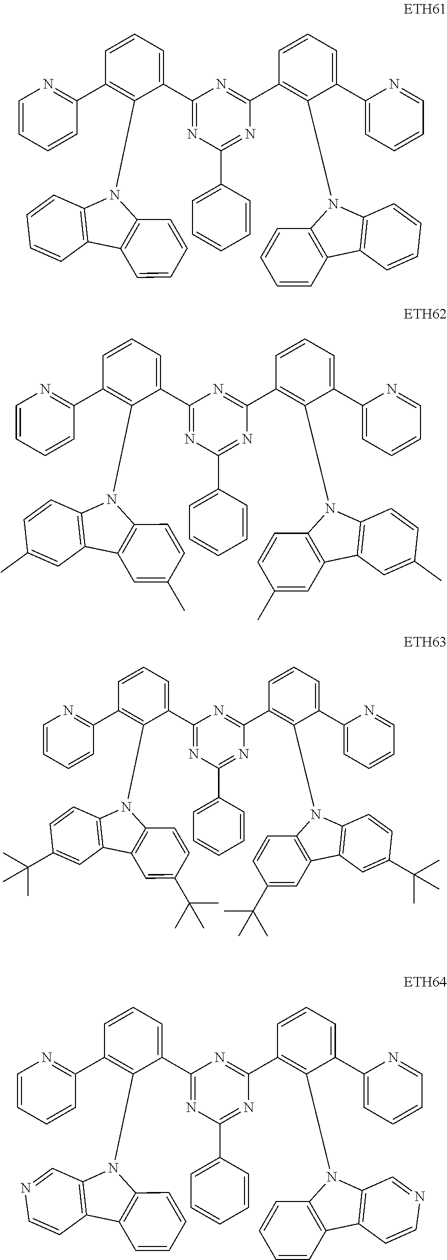

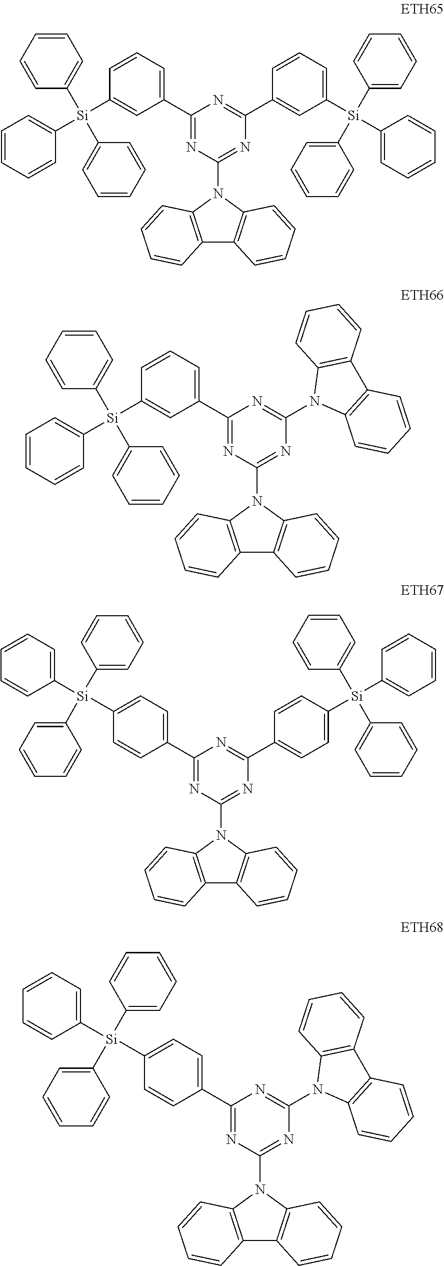

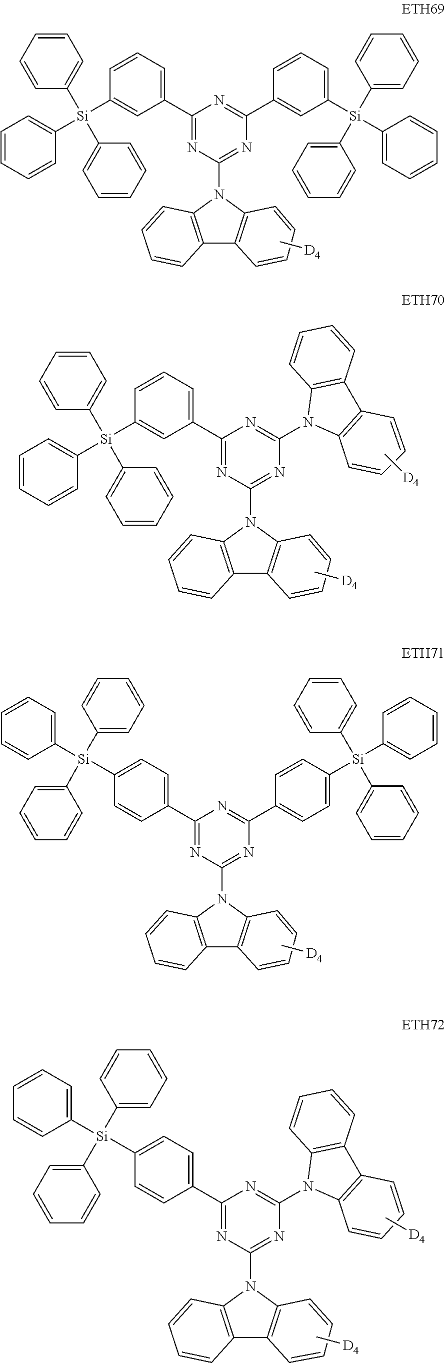

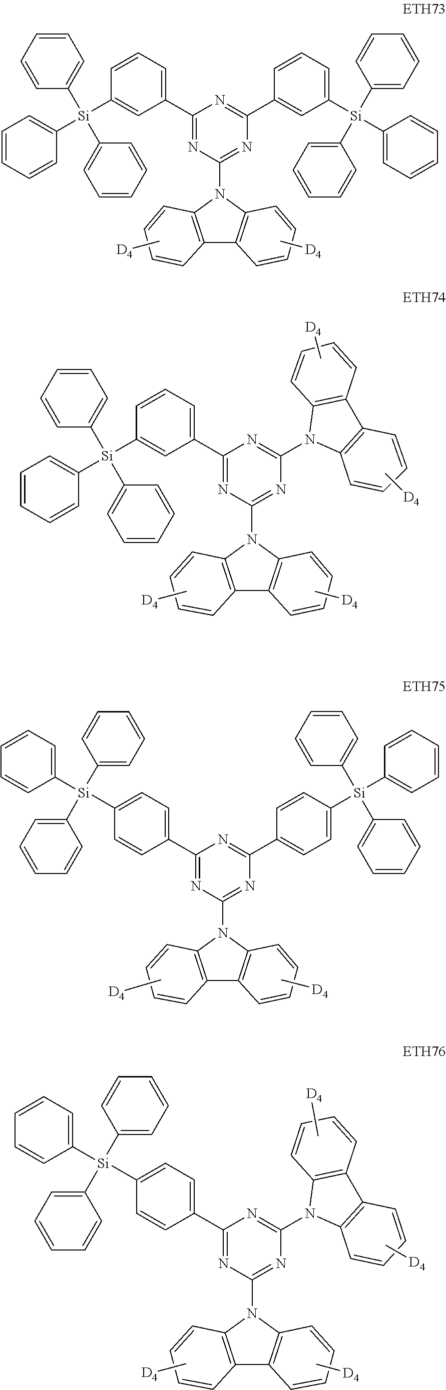

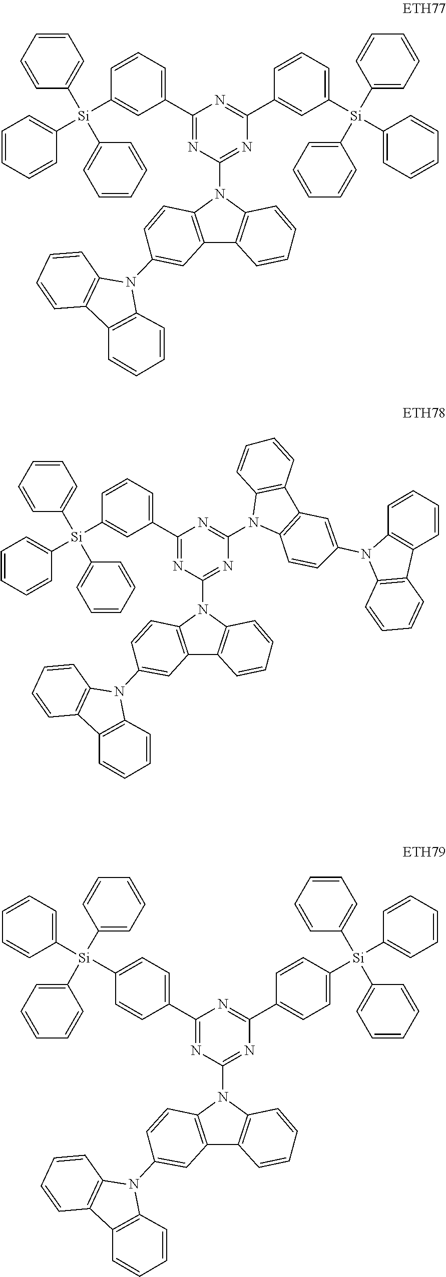 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5cc(-n6c7ccccc7c7ccccc76)ccc54)n3)c2)cc1 ; c1ccc([Si](c2ccccc2)(c2ccccc2)c2cccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5cc(-n6c7ccccc7c7ccccc76)ccc54)n3)cc2)cc1]

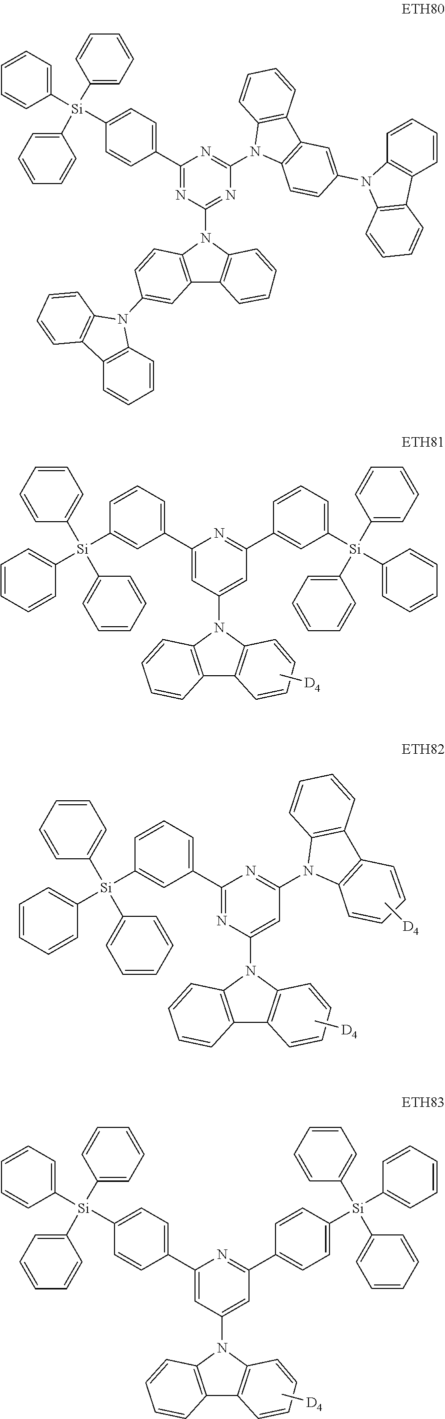

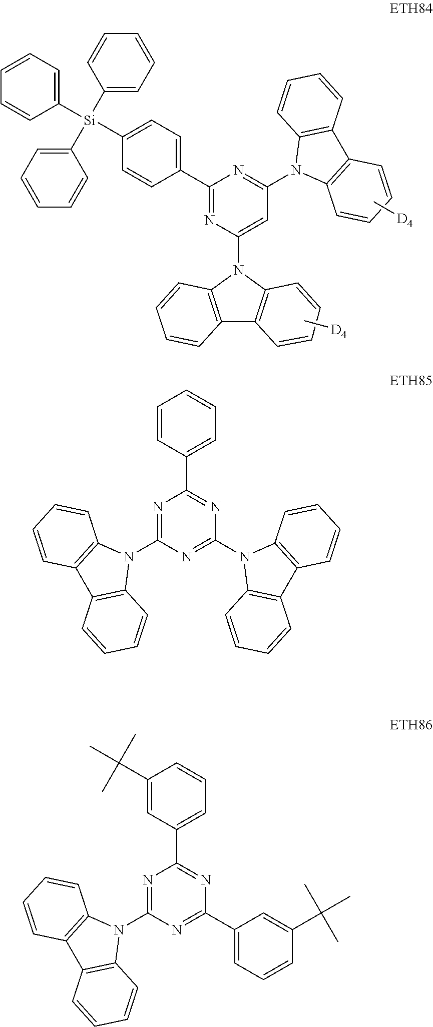

In Compound Group 3, D represents a deuterium atom, and Ph represents an unsubstituted phenyl group.

In an embodiment, the emission layer EML may include the second compound and the third compound, and the second compound and the third compound may form an exciplex. In the emission layer EML, an exciplex may be formed by a hole transport host and an electron transport host. A triplet energy level of the exciplex formed by a hole transporting host and an electron transporting host may correspond to a difference between a lowest unoccupied molecular orbital (LUMO) energy level of the electron transporting host and a highest occupied molecular orbital (HOMO) energy level of the hole transporting host.

For example, an absolute value of a triplet energy level (T1) of the exciplex formed by the hole transporting host and the electron transporting host may be in a range of about 2.4 eV to about 3.0 eV. The triplet energy level of the exciplex may have a value that is smaller than an energy gap of each host material. The exciplex may have a triplet energy level less than or equal to about 3.0 eV, which is an energy gap between the hole transporting host and the electron transporting host.

In an embodiment, the emission layer EML may include a fourth compound, in addition to the first compound, the second compound, and the third compound as described above. The fourth compound may be used as a phosphorescent sensitizer in the emission layer EML. Energy may be transferred from the fourth compound to the first compound, thereby emitting light.

The emission layer EML may include, as a fourth compound, an organometallic complex that includes platinum (Pt) as a central metal atom and ligands connected to the central metal atom. In an embodiment, the emission layer EML may further include a fourth compound represented by Formula D-1:

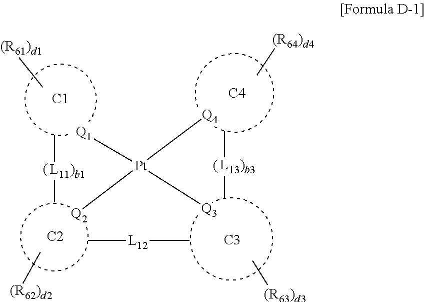

In Formula D-1, Q₁ to Q₄ may each independently be C or N.

In Formula D-1, C1 to C4 may each independently be a substituted or unsubstituted hydrocarbon ring having 5 to 30 ring-forming carbon atoms or a substituted or unsubstituted heterocycle having 2 to 30 ring-forming carbon atoms.

In Formula D-1, L₁ to L₁₃ may each independently be a direct linkage,

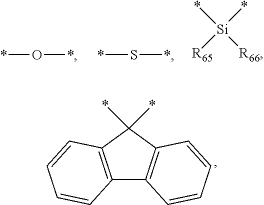

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms. In L₁ to L₁₃,

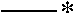 [SMILES: *C]

represents a bond to one of C1 to C4.

In Formula D-1, b1 to b3 may each independently be 0 or 1. If b1 is 0, C1 and C2 may not be directly linked to each other. If b2 is 0, C2 and C3 may not be directly linked to each other. If b3 is 0, C3 and C4 may not be directly linked to each other.

In Formula D-1, R₆₁ to R₆₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, a substituted or unsubstituted heteroaryl group having 2 to 60 ring-forming carbon atoms, or bonded to an adjacent group to form a ring. For example, R₆₁ to R₆₆ may each independently be a substituted or unsubstituted methyl group or a substituted or unsubstituted t-butyl group.

In Formula D-1, d1 to d4 may each independently be an integer from 0 to 4. In Formula D-1, if d1 to d4 are each 0, the fourth compound may not be substituted with any of R₆₁ to R₆₄. A case where d1 to d4 are each 4 and groups of each of R₆₁ to R₆₄ are hydrogen atoms may be the same as a case where d1 to d4 are each 0. When d1 to d4 each 2 or more, multiple groups of each of R₆₁ to R₆₄ may be the same as each other, or at least one group thereof may be different from the remainder.

In an embodiment, in Formula D-1, C1 to C4 may each independently be a substituted or unsubstituted hydrocarbon ring or a substituted or unsubstituted heterocycle that is represented by one of Formula C-1 to Formula C-4:

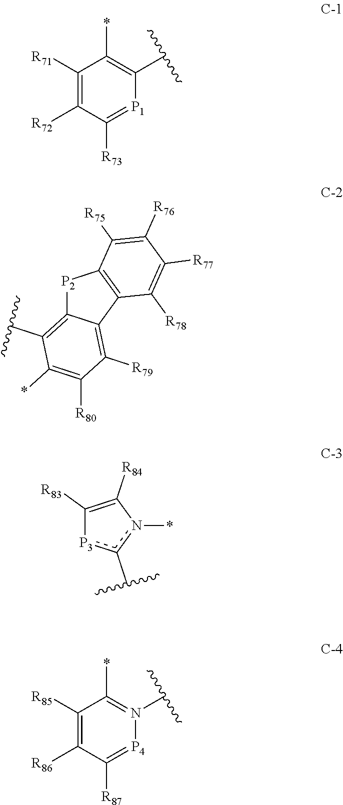

In Formula C-1 to Formula C-4, P₁ may be

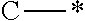 [SMILES: *C]

C(R₇₄), P₂ may be

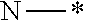 [SMILES: *N]

or N(R₈₁), P₃ may be

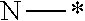 [SMILES: *N]

or N(R₈₂), and P₄ may De

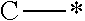 [SMILES: *C]

### or C(R₈₈).

In Formula C-1 to Formula C-4, R₇₁ to R₈₈ may each independently be a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring.

In Formula C-1 to Formula C-4,

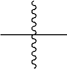

represents a bond to Pt, which is a central metal atom, and

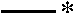 [SMILES: *C]

represents a bond to a neighboring cyclic group (C1 to C4) or to a linker (L₁₁ to L₁₃).

In an embodiment, the emission layer EML may include the first compound represented by Formula 1, and at least one of the second compound, the third compound, and the fourth compound. In an embodiment, the emission layer EML may include the first compound, the second compound, and the third compound. In the emission layer EML, the second compound and the third compound may form an exciplex, and energy may be transferred from the exciplex to the first compound, thereby emitting light.

In another embodiment, the emission layer EML may include the first compound, the second compound, the third compound, and the fourth compound. In the emission layer EML, the second compound and the third compound may form an exciplex, and energy may be transferred from the exciplex to the fourth compound and the first compound, thereby emitting light. In an embodiment, the fourth compound may be a sensitizer. The fourth compound included in the emission layer EML of the light emitting element ED may serve as a sensitizer to transfer energy from the host to the first compound, which is a light emitting dopant. For example, the fourth compound, which serves as an auxiliary dopant, accelerates energy transfer to the first compound, which serves as a light emitting dopant, thereby increasing an emission ratio of the first compound. Therefore, the emission layer EML may have improved luminous efficiency. When energy transfer to the first compound is increased, excitons formed in the emission layer EML may not accumulate inside the emission layer EML and may emit light rapidly, so that deterioration of the device may be reduced. Therefore, the service life of the light emitting element ED may increase.

The light emitting element ED may include the first compound, the second compound, the third compound, and the fourth compound, and the emission layer EML may include the combination of two host materials and two dopant materials. In the light emitting element ED, the emission layer EML may include the second compound and the third compound, which are two different hosts, the first compound which emits delayed fluorescence, and the fourth compound which includes an organometallic complex, and thus the light emitting element ED may exhibit excellent luminous efficiency characteristics.

In an embodiment, the fourth compound represented by Formula D-1 may be selected from Compound Group 4. In an embodiment, in the light emitting element ED, the fourth compound may include at least one compound selected from Compound Group 4.

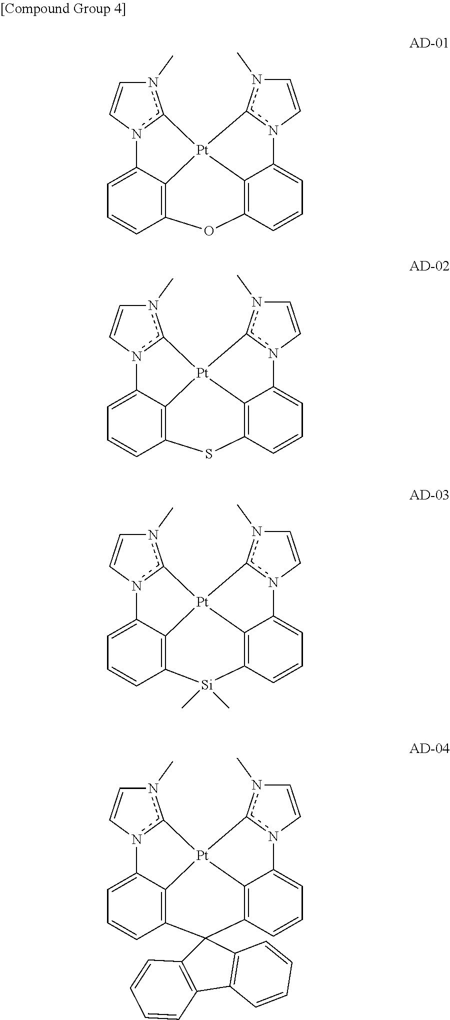

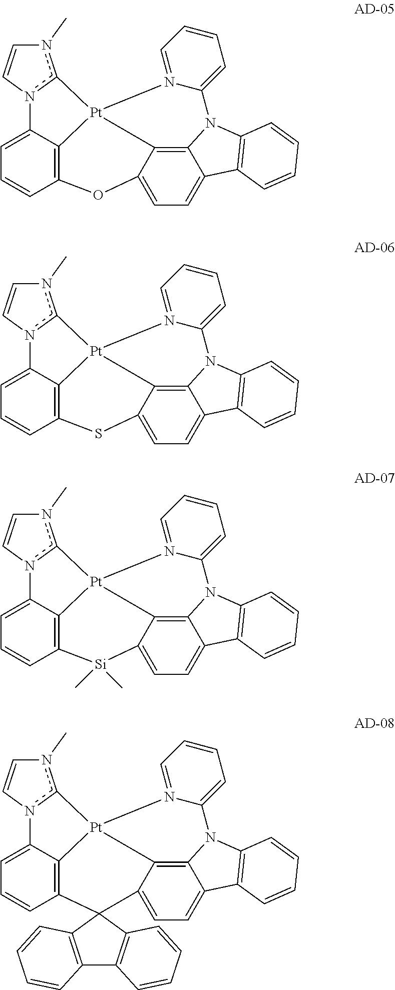

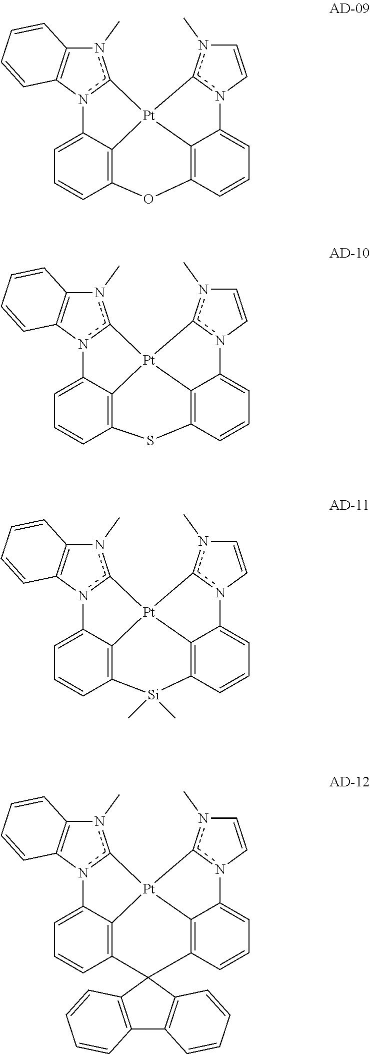

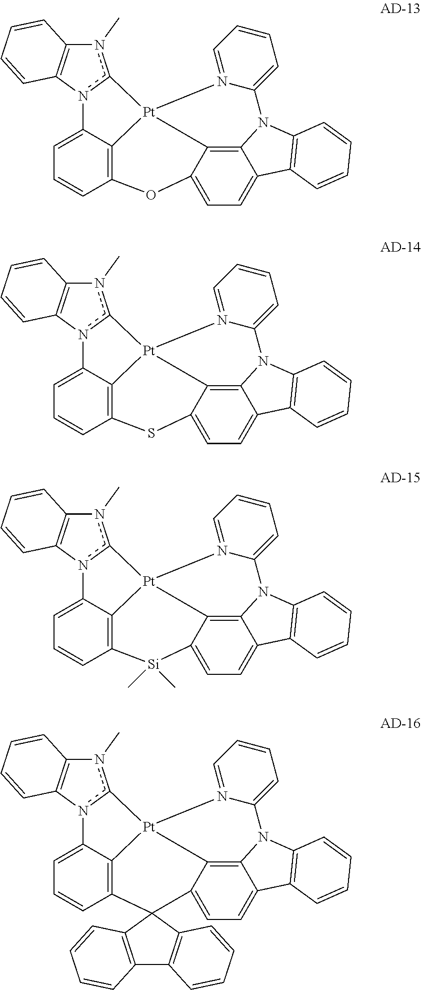

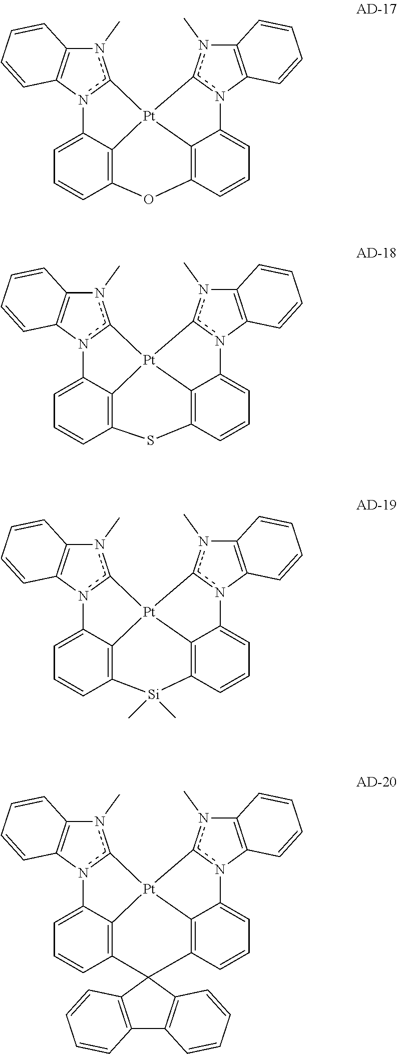

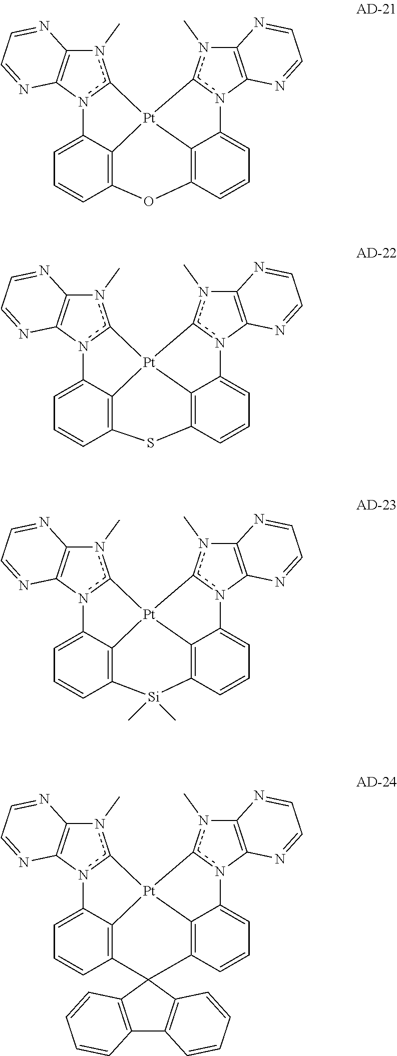

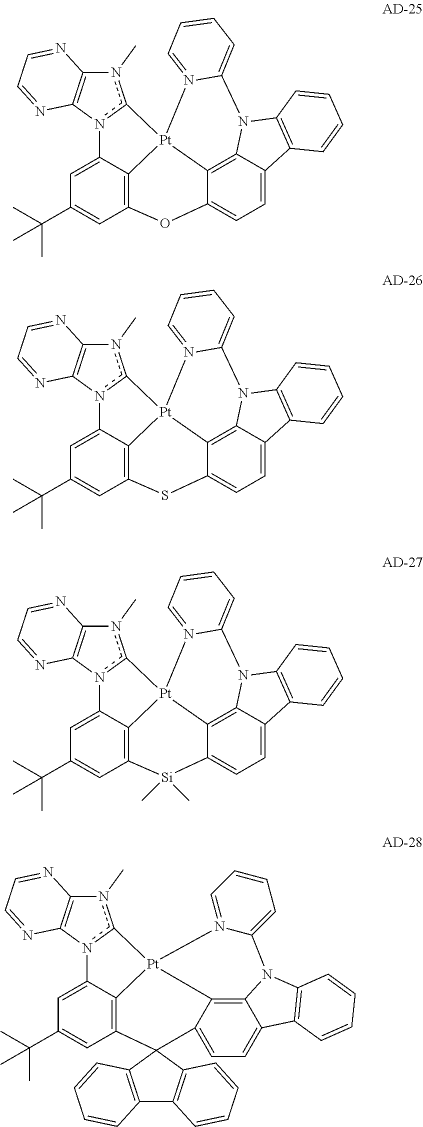

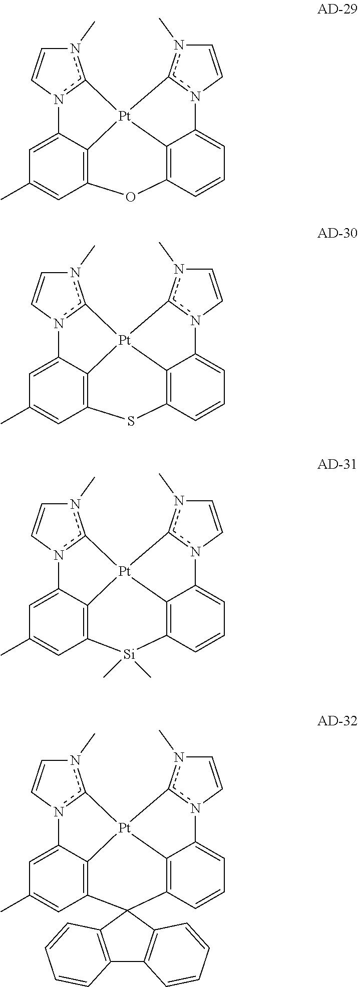

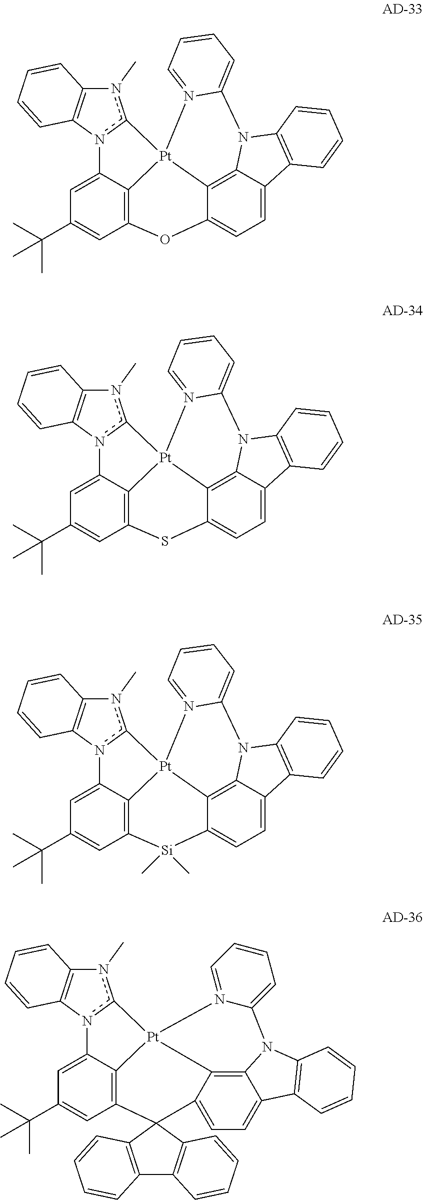

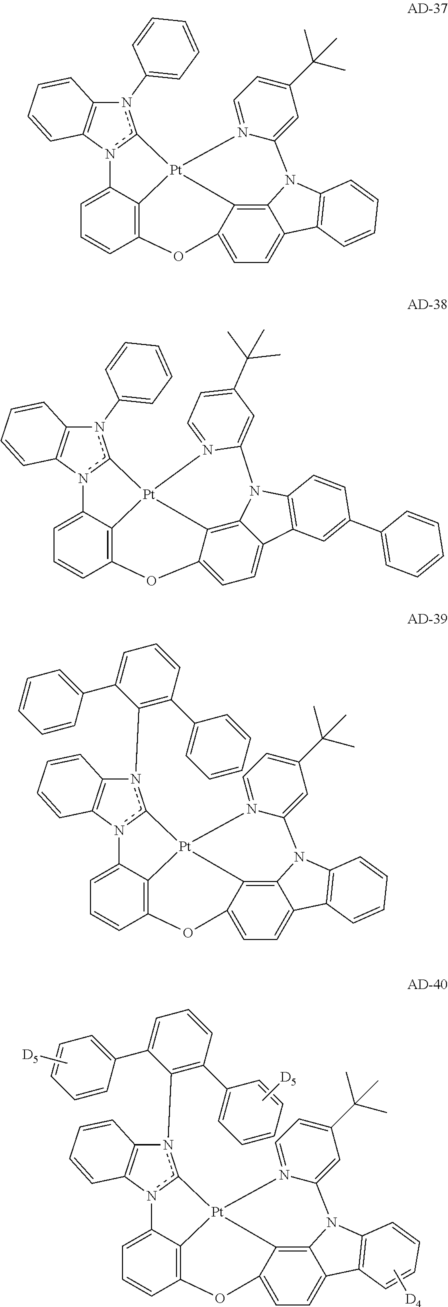

In Compound Group 4, D represents a deuterium atom.

In an embodiment, the light emitting element ED may include multiple emission layers. The emission layers may be provided as a stack of emission layer, so that the light emitting element ED including multiple emission layers may emit white light. The light emitting element ED including multiple emission layers may be a light emitting element having a tandem structure. When the light emitting element ED includes multiple emission layers, at least one emission layer EML may include the first compound represented by Formula 1. In an embodiment, when the light emitting element ED includes multiple emission layers, at least one emission layer EML may include the first compound, the second compound, the third compound, and the fourth compound as described above.

When the emission layer EML in the light emitting element ED includes the first compound, the second compound, and the third compound, an amount of the first compound may be in a range of about 0.1 wt % to about 5 wt %, with respect to a total weight of the first compound, the second compound, and the third compound. However, embodiments are not limited thereto. When an amount of the first compound satisfies the above-described range, energy transfer from the second compound and the third compound to the first compound may increase, and thus the luminous efficiency and device service life may increase.

The combined amounts of the second compound and the third compound in the emission layer EML may be the remainder of the total weight of the first compound, the second compound, and the third compound, excluding the amount of the first compound. For example, a total amount of the second compound and the third compound in the emission layer EML may be in a range of about 65 wt % to about 95 wt %, with respect to a total weight of the first compound, the second compound, and the third compound.

Within the total amount of the second compound and the third compound in the emission layer EML, a weight ratio of the second compound to the third compound may be in a range of about 3:7 to about 7:3.

When the amounts of the second compound and the third compound satisfy the above-described ranges and ratios, a charge balance characteristic in the emission layer EML may be improved, and thus the luminous efficiency and device service life may increase. When the amounts of the second compound and the third compound deviate from the above-described ranges and ratios, charge balance in the emission layer EML may not be achieved, and thus the luminous efficiency may be reduced and the device may readily deteriorate.

When the emission layer EML includes the fourth compound, an amount of the fourth compound in the emission layer EML may be in a range of about 10 wt % to about 30 wt %, with respect to a total weight of the first compound, the second compound, the third compound, and the fourth compound. However, embodiments are not limited thereto. When an amount of the fourth compound satisfies the above-described range, energy transfer from the host to the first compound, which is a light emitting dopant, may increase, so that a luminous ratio may be improved, and thus, luminous efficiency of the emission layer EML may be improved. When the amounts of first compound, the second compound, the third compound, and the fourth compound included in the emission layer EML satisfy the above-described ranges and ratios, excellent luminous efficiency and long service life may be achieved.

In the light emitting element ED, the emission layer EML may include an anthracene derivative, a pyrene derivative, a fluoranthene derivative, a chrysene derivative, a dihydrobenzanthracene derivative, or a triphenylene derivative. For example, the emission layer EML may include an anthracene derivative or a pyrene derivative.

In the light emitting element ED according to embodiments as shown in each of FIGS. 3 to 6, the emission layer EML may further include a host and a dopant of the related art, in addition to the above-described host and dopant.

In an embodiment, the emission layer EML may include a compound represented by Formula E-1. The compound represented by Formula E-1 may be used as a fluorescent host material.

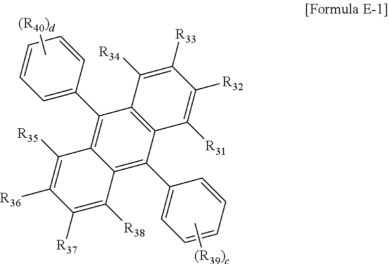

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring. For example, in Formula E-1, R₃₁ to Rao may be bonded to an adjacent group to form a saturated hydrocarbon ring, an unsaturated hydrocarbon ring, a saturated heterocycle, or an unsaturated heterocycle.

In Formula E-1, c and d may each independently be an integer from 0 to 5.

In an embodiment, the compound represented by Formula E-1 may be any compound selected from Compound E1 to Compound E19:

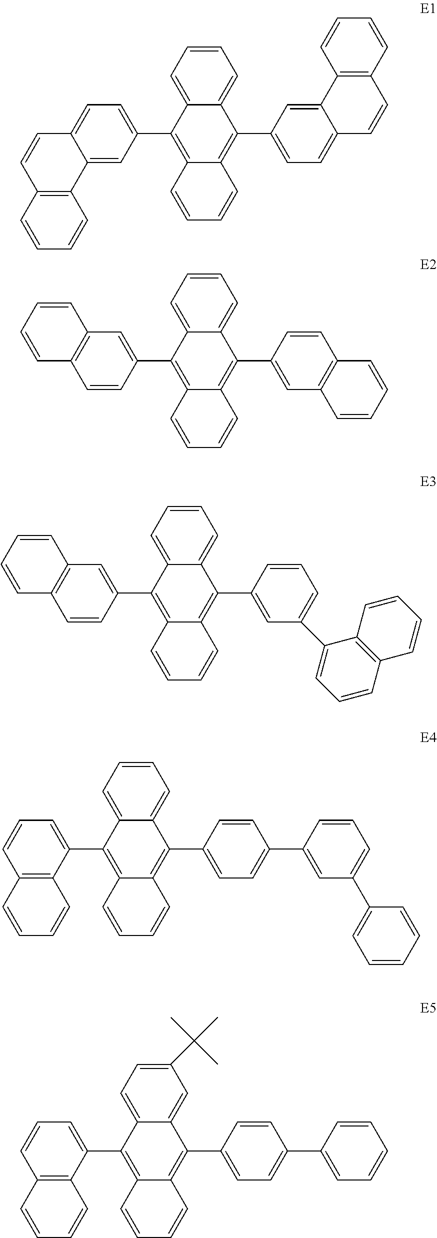

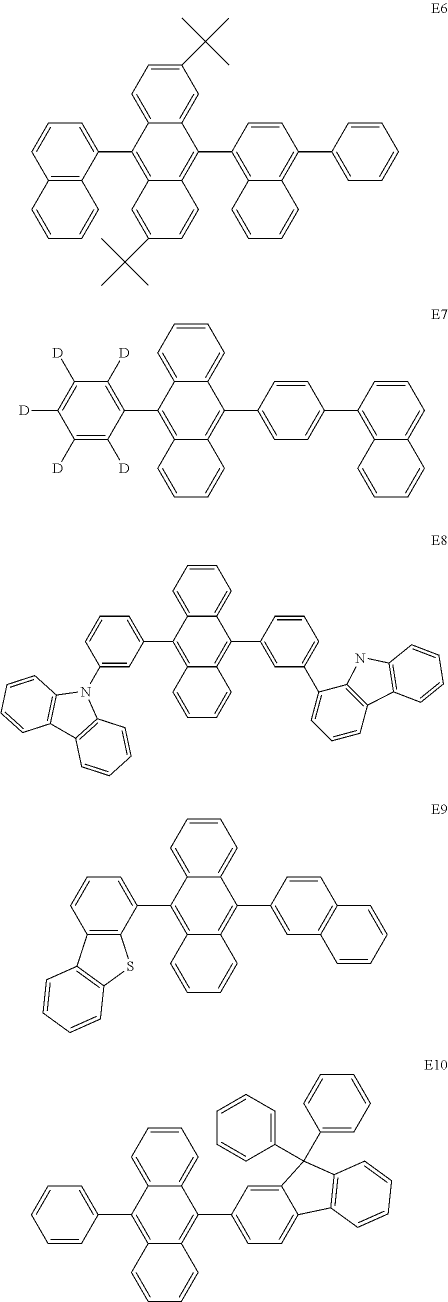

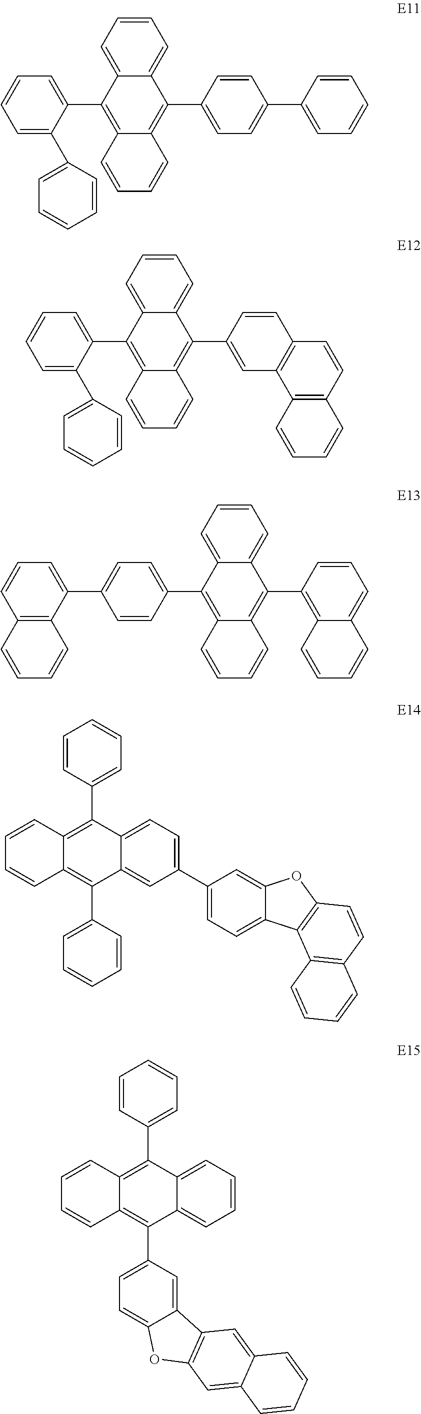

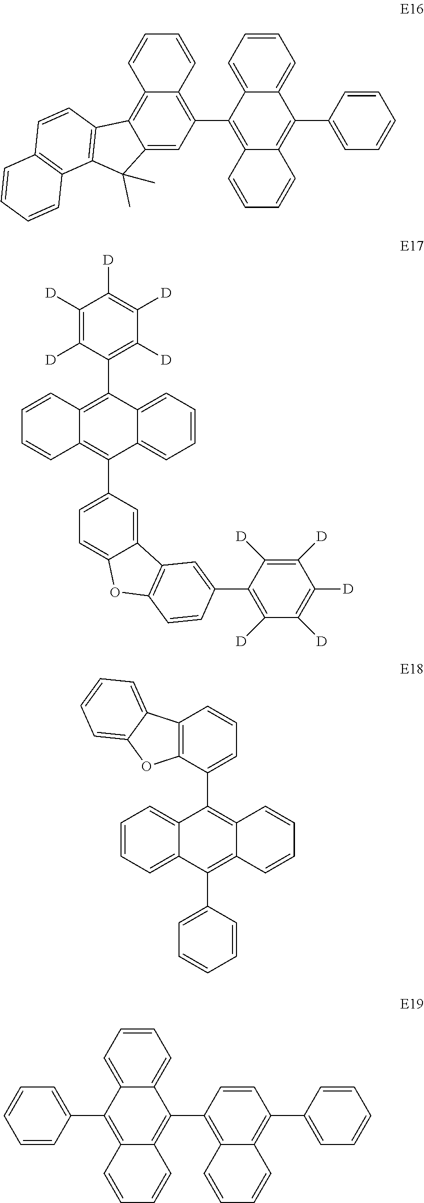

In an embodiment, the emission layer EML may include a compound represented by Formula E-2a or Formula E-2b. The compound represented by Formula E-2a or Formula E-2b may be used as a phosphorescent host material.

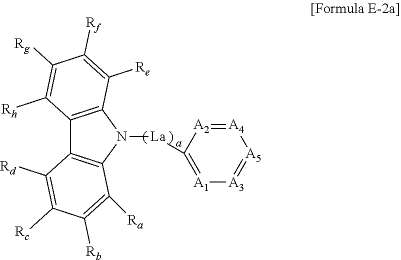

In Formula E-2a, a may be an integer from 0 to 10; and La may be a direct linkage, a substituted or unsubstituted arylene group having 6 to 30 ring-forming carbon atoms, or a substituted or unsubstituted heteroarylene group having 2 to 30 ring-forming carbon atoms. When a is 2 or greater, multiple La groups may each independently be a substituted or unsubstituted arylene group having 6 to 30 ring-forming carbon atoms or a substituted or unsubstituted heteroarylene group having 2 to 30 ring-forming carbon atoms.

In Formula E-2a, A₁ to A₈ may each independently be N or C(Rᵢ). In Formula E-2a, Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring. For example, Rₐ to Rᵢ may be bonded to an adjacent group to form a hydrocarbon ring or a heterocycle including N, O, S, etc., as a ring-forming atom.

In Formula E-2a, two or three of A₁ to A₈ may each be N, and the remainder of A₁ to A₈ may each independently be C(Rᵢ).

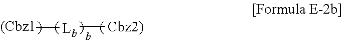

In Formula E-2b, Cbz1 and Cbz2 may each independently be an unsubstituted carbazole group or a carbazole group substituted with an aryl group having 6 to 30 ring-forming carbon atoms. In Formula E-2b, L_{b} may be a direct linkage, a substituted or unsubstituted arylene group having 6 to 30 ring-forming carbon atoms, or a substituted or unsubstituted heteroarylene group having 2 to 30 ring-forming carbon atoms. In Formula E-2b, b may be an integer from 0 to 10; and when b is 2 or more, multiple L_{b} groups may each independently be a substituted or unsubstituted arylene group having 6 to 30 ring-forming carbon atoms or a substituted or unsubstituted heteroarylene group having 2 to 30 ring-forming carbon atoms.

The compound represented by Formula E-2a or Formula E-2b may be any compound selected from Compound Group E-2. However, the compounds listed in Compound Group E-2 are only examples, and the compound represented by Formula E-2a or Formula E-2b is not limited to Compound Group E-2.

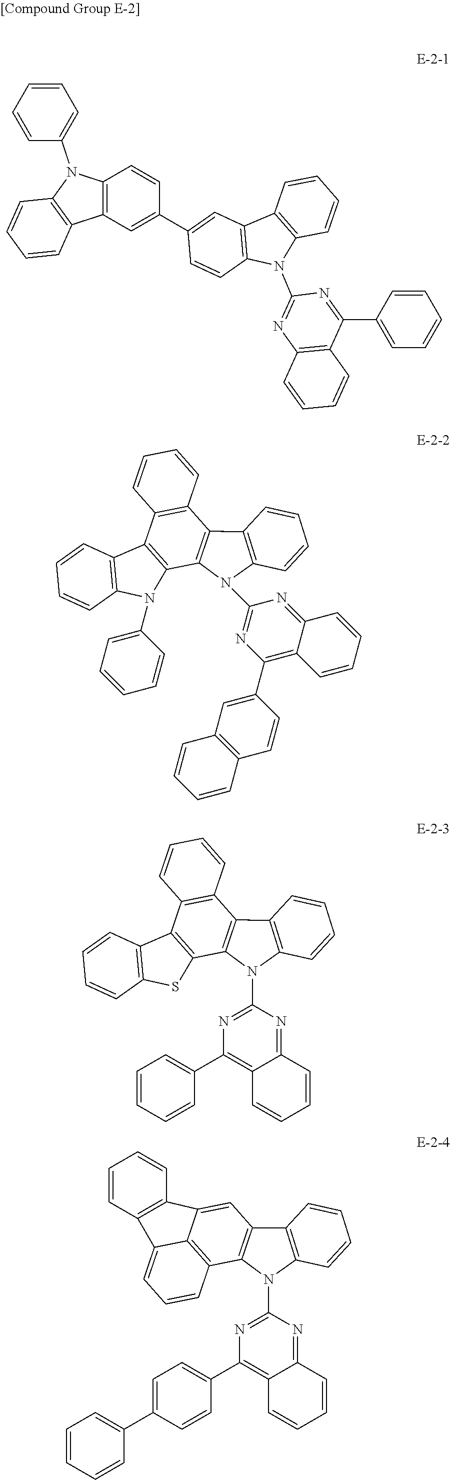

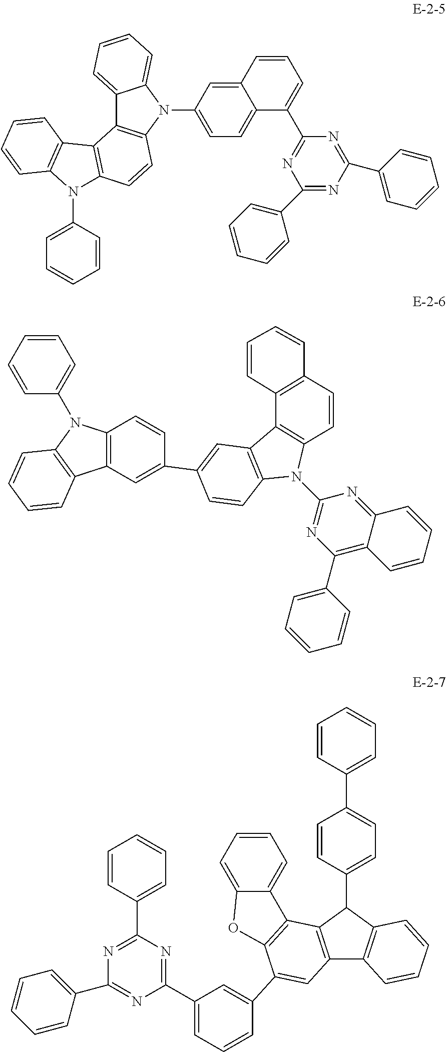 [SMILES: c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1 ; c1ccc(-c2ccc(C3c4ccccc4-c4cc(-c5cccc(-c6nc(-c7ccccc7)nc(-c7ccccc7)n6)c5)c5oc6ccccc6c5c43)cc2)cc1]

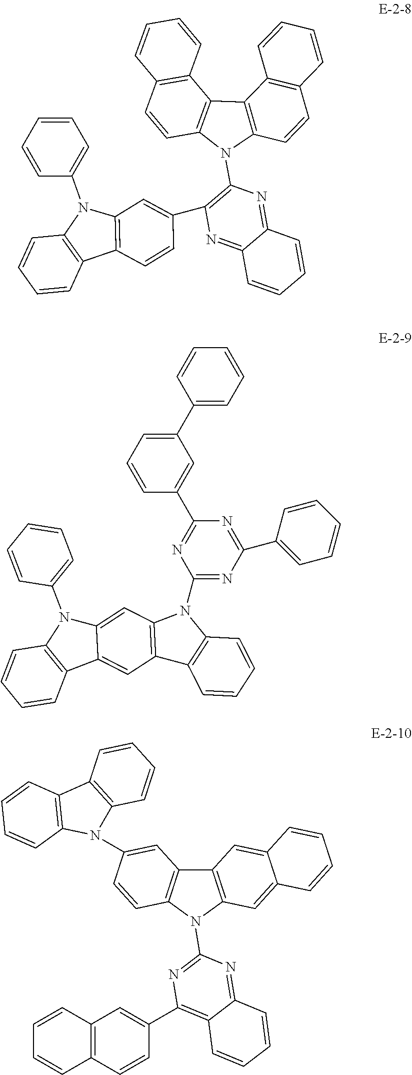 [SMILES: c1ccc(-n2c3ccccc3c3ccc(-c4nc5ccccc5nc4-n4c5ccc6ccccc6c5c5c6ccccc6ccc54)cc32)cc1 ; c1ccc(-c2cccc(-c3nc(-c4ccccc4)nc(-n4c5ccccc5c5cc6c7ccccc7n(-c7ccccc7)c6cc54)n3)c2)cc1 ; c1ccc2cc(-c3nc(-n4c5ccc(-n6c7ccccc7c7ccccc76)cc5c5cc6ccccc6cc54)nc4ccccc34)ccc2c1]

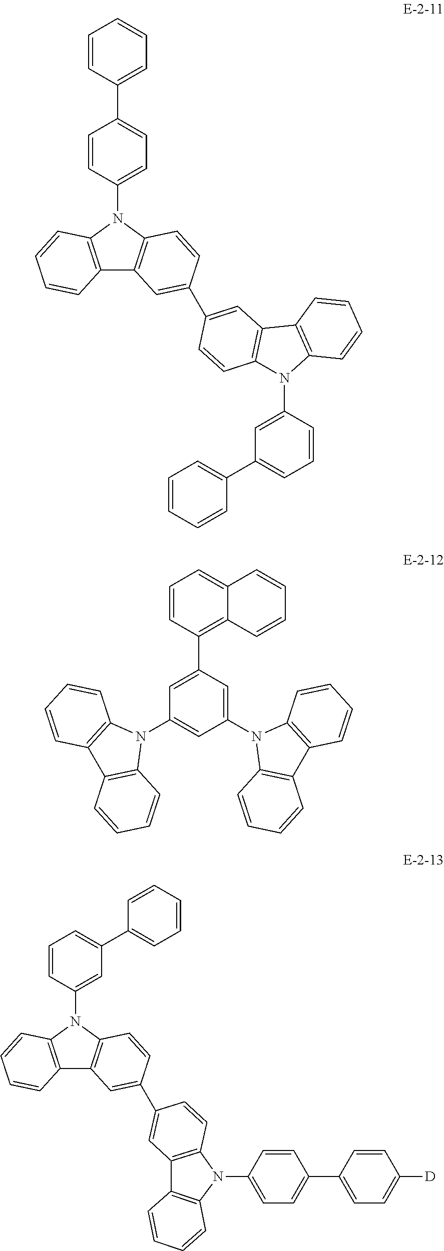

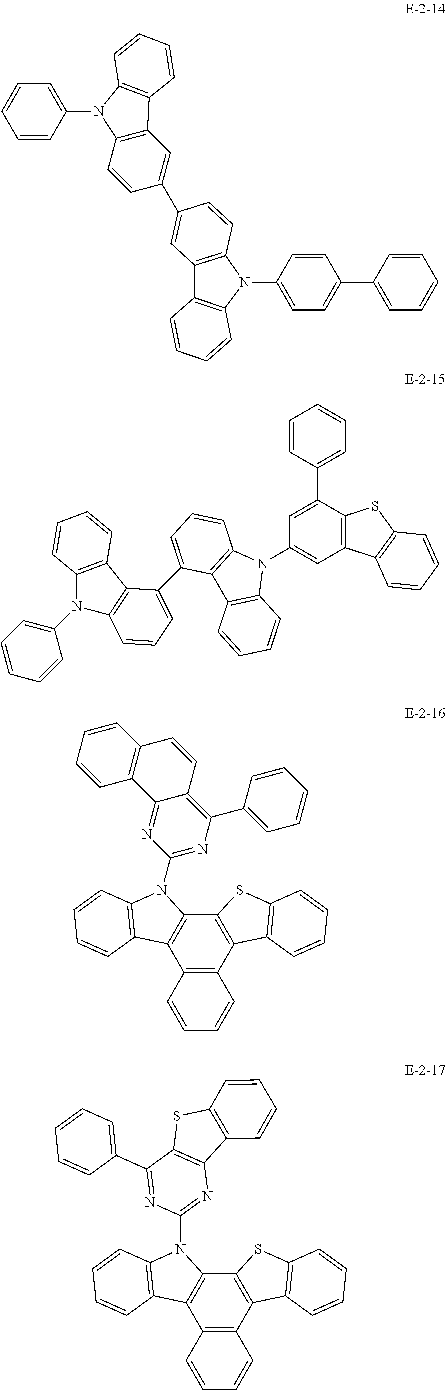 [SMILES: c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1 ; c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6sc5c43)nc3c2sc2ccccc23)cc1]

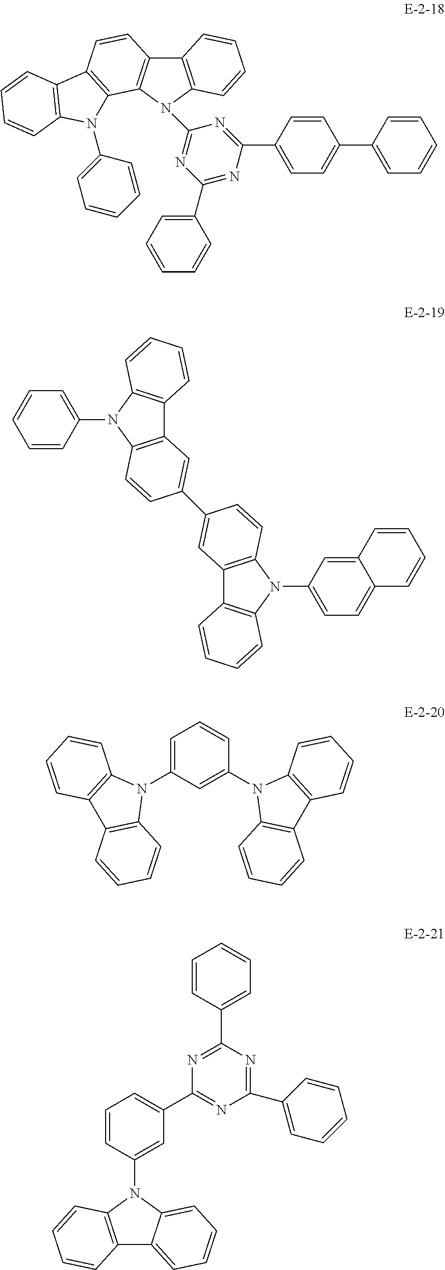 [SMILES: c1ccc(-c2ccc(-c3nc(-c4ccccc4)nc(-n4c5ccccc5c5ccc6c7ccccc7n(-c7ccccc7)c6c54)n3)cc2)cc1 ; c1ccc(-n2c3ccccc3c3cc(-c4ccc5c(c4)c4ccccc4n5-c4ccc5ccccc5c4)ccc32)cc1 ; c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1]

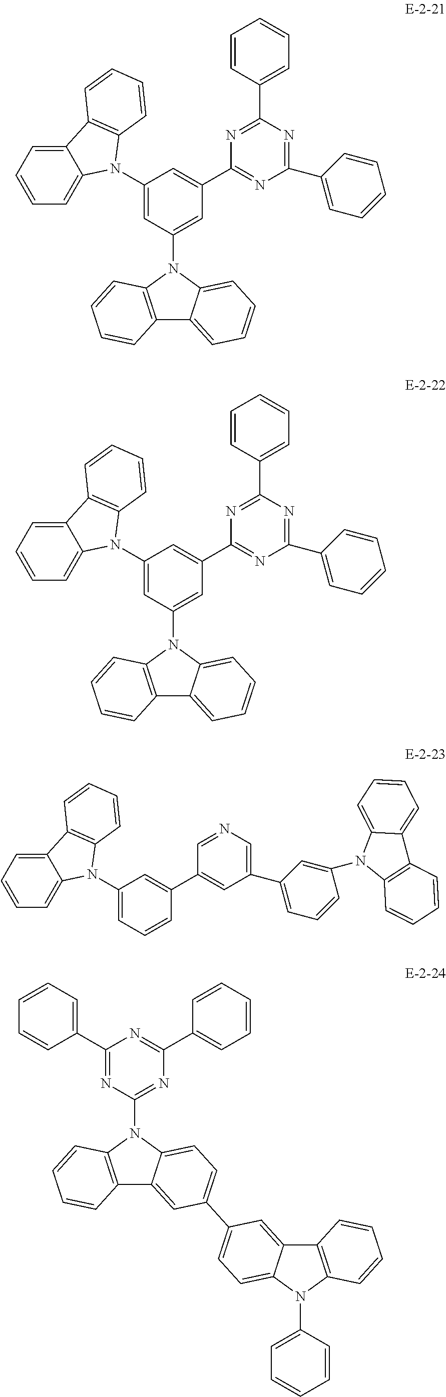 [SMILES: c1ccc(-c2nc(-c3ccccc3)nc(-c3cc(-n4c5ccccc5c5ccccc54)cc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may further include a material of the related art as a host material. For example, the emission layer EML may include, as a host material, at least one of bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), and 1,3,5-tris(1-phenyl-1H-benzo[d]imidazole-2-yl)benzene (TPBi). However, embodiments are not limited thereto. For example, tris(8-hydroxyquinolino)aluminum (Alq₃), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH₂), hexaphenylcyclotrisiloxane (DPSiO₃), octaphenylcyclotetrasiloxane (DPSiO₄), etc. may be used as a host material.

In an embodiment, the emission layer EML may include a compound represented by Formula M-a. The compound represented by Formula M-a may be used as a phosphorescent dopant material.

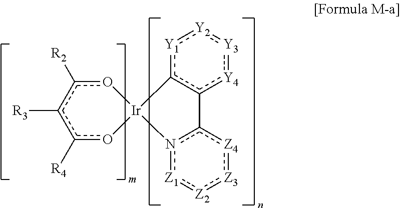

In Formula M-1, Y₁ to Y₄ and Z₁ to Z₄ may each independently be C(R₁) or N; and R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring. In Formula M-a, m may be 0 or 1, and n may be 2 or 3. In Formula M-a, when m is 0, n may be 3, and when m is 1, n may be 2.

The compound represented by Formula M-a may be any compound selected from Compound M-a1 to Compound M-a25. However, Compounds M-a1 to M-a25 are only examples, and the compound represented by Formula M-a is not limited to Compounds M-a1 to M-a25.

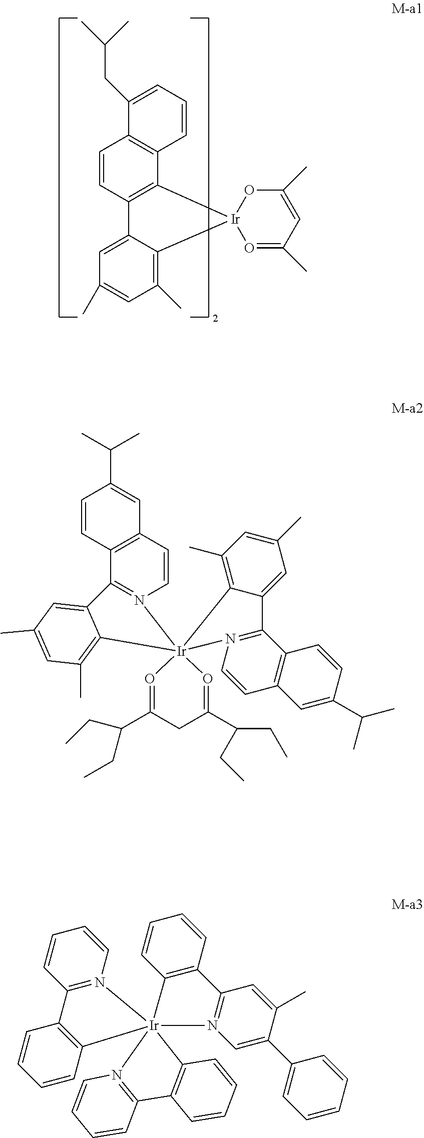

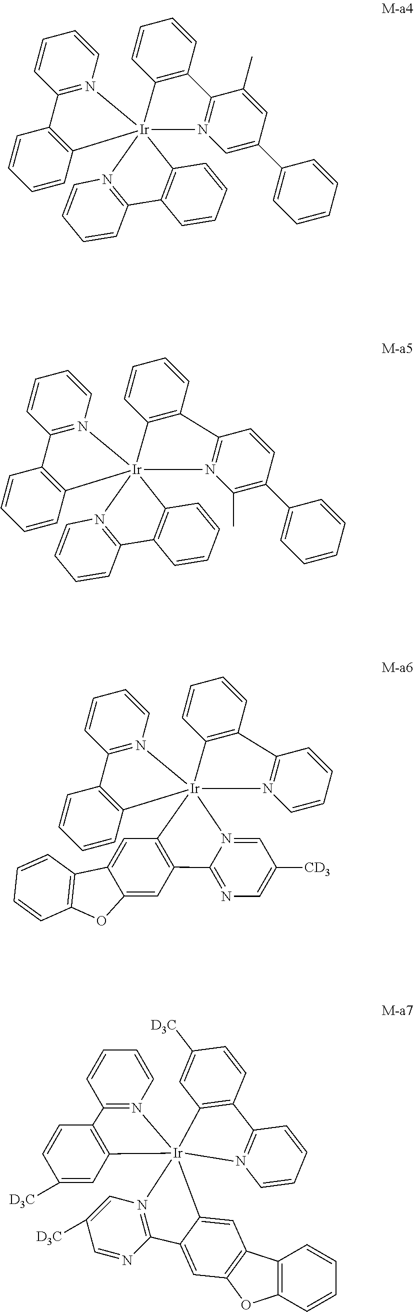

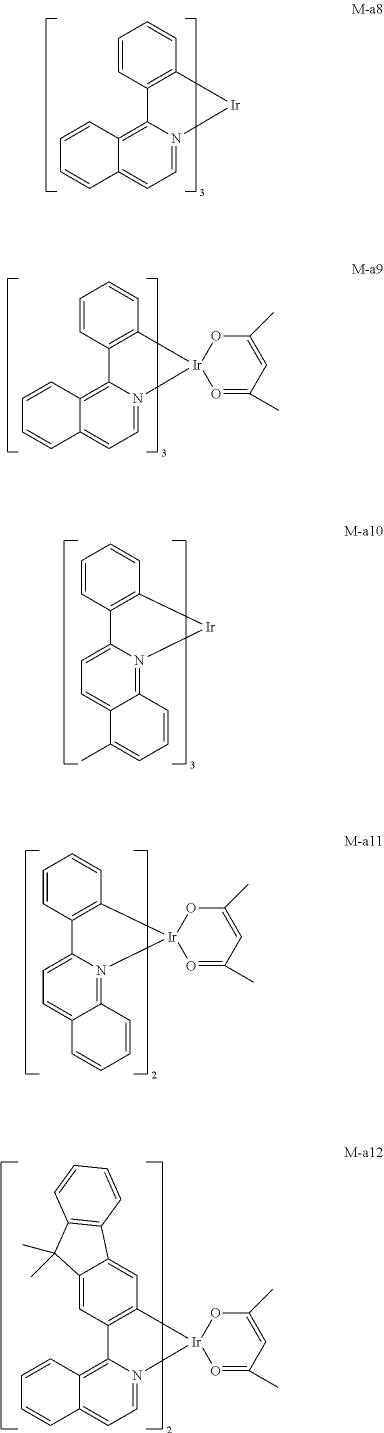

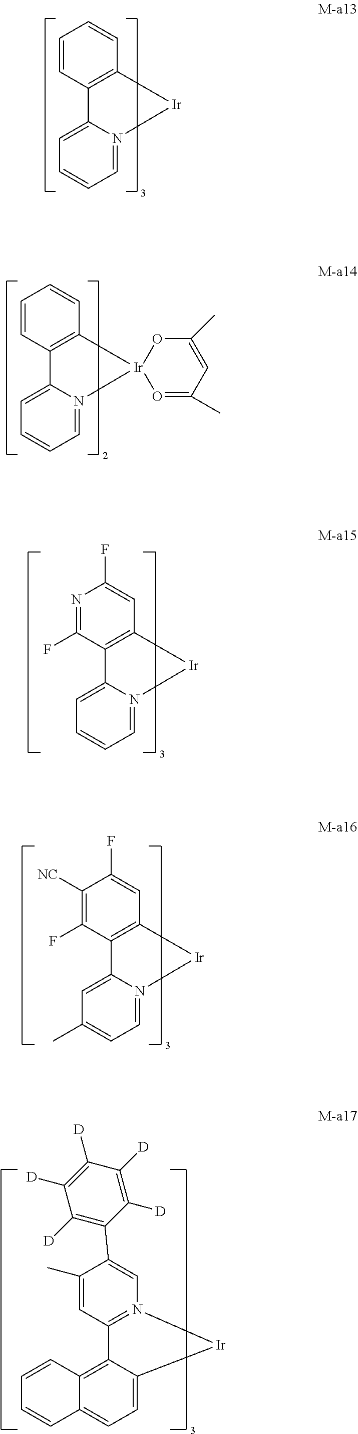

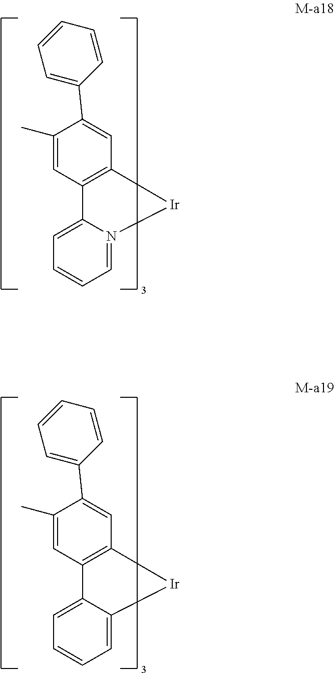

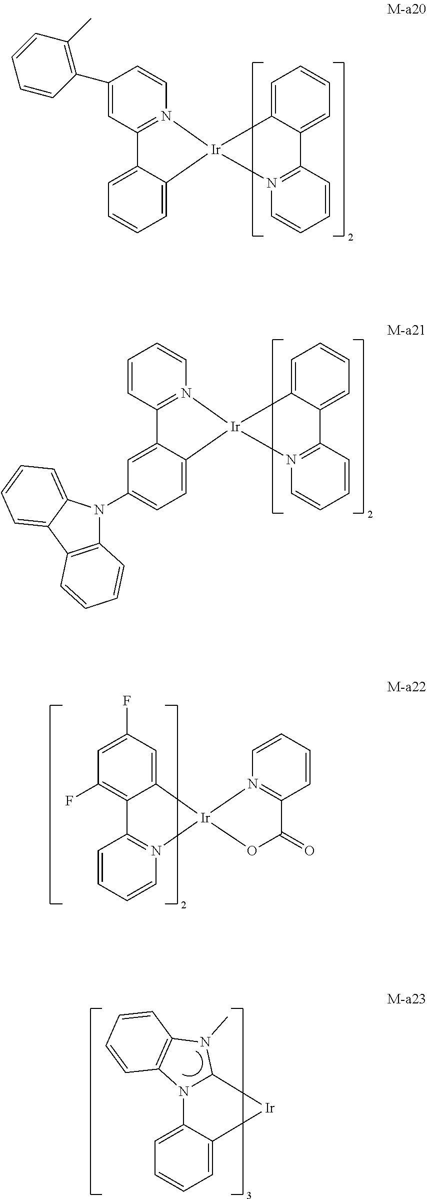

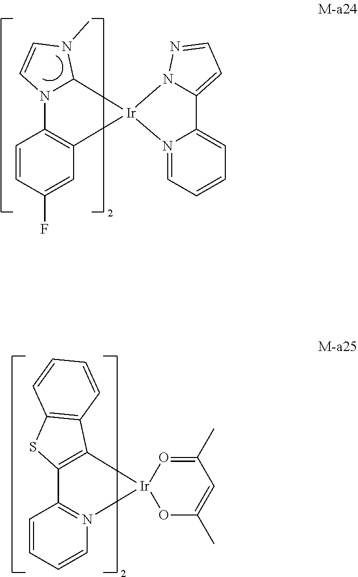

In an embodiment, the emission layer EML may include a compound represented by one of Formula F-a to Formula F-c. The compound represented by one of Formula F-a to Formula F-c may be used as a fluorescence dopant material.

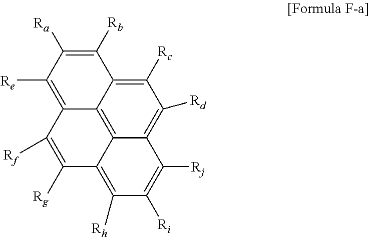

In Formula F-a, two of Rₐ to Rⱼ may each independently be substituted with a group represented by

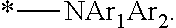

The remainder of Tₐ to Rⱼ which are not substituted with the group represented by

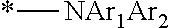

may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In the group represented by

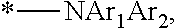

Ar₁ and Ar₂ may each independently be a substituted or unsubstituted aryl group having 6 to 30 ring-forming carbon atoms or a substituted or unsubstituted heteroaryl group having 2 to 30 ring-forming carbon atoms. For example, at least one of Ar₁ and Ar₂ may be a heteroaryl group including O or S as a ring-forming atom.

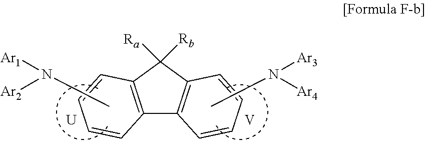

In Formula F-b, Rₐ and R_{b} may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring. In Formula F-b, Ar₁ to Ar₄ may each independently be a substituted or unsubstituted aryl group having 6 to 30 ring-forming carbon atoms or a substituted or unsubstituted heteroaryl group having 2 to 30 ring-forming carbon atoms. For example, at least one of Ar₁ to Ar₄ may be a heteroaryl group including O or S as a ring-forming atom.

In Formula F-b, U and V may each independently be a substituted or unsubstituted hydrocarbon ring having 5 to 30 ring-forming carbon atoms or a substituted or unsubstituted heterocycle having 2 to 30 ring-forming carbon atoms.

In Formula F-b, the number of rings represented by U and V may each independently be 0 or 1. When the number of U or V is 1, a fused ring may be present at a portion indicated by U or V, and when the number of U or V is 0, a fused ring may not be present at the portion indicated by U or V. When the number of U is 0 and the number of V is 1, or when the number of U is 1 and the number of V is 0, the fused ring having a fluorene core of Formula F-b may be a cyclic compound having four rings. When the number of U and V is each 0, a fused ring having a fluorene core of Formula F-b may be a cyclic compound having three rings. When the number of U and V is each 1, a fused ring having a fluorene core of Formula F-b may be a cyclic compound having five rings.

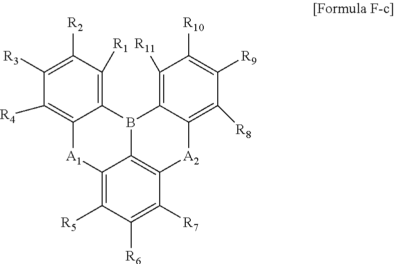

In Formula F-c, A₁ and A₂ may each independently be O, S, Se, or N(Rₘ); and Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In Formula F-c. R₁ to R₁₁ may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring.

In Formula F-c. A₁ and A₂ may each independently be bonded to a substituent of an adjacent ring to form a fused ring. For example, when A₁ and A₂ are each independently N(Rₘ), A₁ may be bonded to R₄ or R₅ to form a ring. For example, A₂ may be bonded to R₇ or R₈ to form a ring.

In an embodiment, the emission layer EML may further include, as a dopant material of the related art, a styryl derivative (e.g., 1,4-bis[2-(3-N-ethylcarbazolyl)vinyl]benzene (BCzVB), 4-(di-p-tolylamino)-4′-[(di-p-tolylamino)styryl]stilbene (DPAVB), and N-(4-((E)-2-(6-((E)-4-(diphenylamino)styryl)naphthalen-2-yl)vinyl)phenyl)-N-phenylbenzenamine (N-BDAVBi), 4,4′-bis[2-(4-(N,N-diphenylamino)phenyl)vinyl]biphenyl (DPAVBi), perylene or a derivative thereof (e.g., 2,5,8,11-tetra-t-butylperylene (TBP)), pyrene or a derivative thereof (e.g., 1,1-dipyrene, 1,4-dipyrenylbenzene, 1,4-bis(N,N-diphenylamino)pyrene), etc.

The emission layer EML may further include a phosphorescence dopant material of the related art. For example, a metal complex including iridium (Ir), platinum (Pt), osmium (Os), gold (Au), titanium (Ti), zirconium (Zr), hafnium (Hf), europium (Eu), terbium (Tb), or thulium (Tm) may be used as a phosphorescent dopant. For example, iridium(III) bis(4,6-difluorophenylpyridinato-N,C2) (FIrpic), bis(2,4-difluorophenylpyridinato)-tetrakis(1-pyrazolyl)borate iridium(III) (Fir6), or platinum octaethyl porphyrin (PtOEP) may be used as a phosphorescent dopant. However, embodiments are not limited thereto.

In an embodiment, the emission layer EML may include a quantum dot. The quantum dot may be a Group II-VI compound, a Group III-VI compound, a Group I-III-VI compound, a Group III-V compound, a Group III-II-V compound, a Group IV-VI compound, a Group IV element, a Group IV compound, or a combination thereof.

Examples of a Group II-VI compound may include: a binary compound selected from the group consisting of CdSe, CdTe, CdS, ZnS, ZnSe, ZnTe, ZnO, HgS, HgSe, HgTe, MgSe, MgS, and a mixture thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof; or any combination thereof.

Examples of a Group III-VI compound may include: a binary compound such as In₂S₃ or In₂Se₃; a ternary compound such as InGaS₃ or InGaSe₃; or any combination thereof.

Examples of a Group I-III-VI compound may include: a ternary compound selected from the group consisting of AgInS, AgInS₂, CuInS, CuInS₂, AgGaS₂, CuGaS₂ CuGaO₂, AgGaO₂, AgAIO₂, and a mixture thereof; a quaternary compound such as AgInGaS₂ or CuInGaS₂; or any combination thereof.

Examples of a Group III-V compound may include: a binary compound selected from the group consisting of GaN, GaP, GaAs, GaSb, AlN, AIP, AlAs, AlSb, InN, InP, InAs, InSb, and a mixture thereof; a ternary compound selected from the group consisting of GaNP, GaNAs, GaNSb, GaPAs, GaPSb, AlNP, AlNAs, AlNSb, AlPAs, AlPSb, InGaP, InAIP, InNP, InNAs, InNSb, InPAs, InPSb, and a mixture thereof; a quaternary compound selected from the group consisting of GaAINP, GaAINAs, GaAINSb, GaAlPAs, GaAlPSb, GaInNP, GaInNAs, GaInNSb, GalnPAs, GaInPSb, InAINP, InAINAs, InAINSb, InAlPAs, InAlPSb, and a mixture thereof; or any combination thereof. In an embodiment, a Group III-V compound may further include a Group II metal. For example, InZnP, etc., may be selected as a Group III-II-V compound.

Examples of a Group IV-VI compound may include: a binary compound selected from the group consisting of SnS, SnSe, SnTe, PbS, PbSe, PbTe, and a mixture thereof; a ternary compound selected from the group consisting of SnSeS, SnSeTe, SnSTe, PbSeS, PbSeTe, PbSTe, SnPbS, SnPbSe, SnPbTe, and a mixture thereof; a quaternary compound selected from the group consisting of SnPbSSe, SnPbSeTe, SnPbSTe, and a mixture thereof; or any combination thereof. Examples of a Group IV element may include Si, Ge, and a mixture thereof. Examples of a Group IV compound may include a binary compound selected from the group consisting of SiC, SiGe, and a mixture thereof.

Each element included in a polynary compound, such as a binary compound, a ternary compound, or a quaternary compound, may be present in a particle at a uniform concentration distribution or at a non-uniform concentration distribution. For example, a formula may indicate the elements included in a compound, but an elemental ratio in the compound may be different. For example, AgInGaS₂ may mean AgInxGa₁₋ₓS₂ (where x is a real number from 0 to 1).

In an embodiment, a quantum dot may have a single structure, in which the concentration of each element included in the quantum dot is uniform, or a quantum dot may have a core-shell structure in which a quantum dot surrounds another quantum dot. For example, a material included in the core may be different from a material included in the shell.

The shell of the quantum dot may serve as a protection layer to prevent the chemical deformation of the core to maintain semiconductor properties, and/or may serve as a charging layer to impart electrophoresis properties to the quantum dot. The shell may be a single layer or multiple layers. An interface between the core and the shell may have a concentration gradient in which the concentration of an element that is present in the shell decreases towards the core.

In embodiments, the quantum dot may have the above-described core/shell structure including a core including nanocrystals and a shell surrounding the core. Examples of a shell of a quantum dot may include a metal oxide, a non-metal oxide, a semiconductor compound, or a combination thereof.

Examples of a metal oxide or a non-metal oxide may include: a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO; a ternary compound such as MgAl₂O₄, CoFe₂O₄, NiFe₂O₄, or CoMn₂O₄; or any combination thereof. However, embodiments are not limited thereto.

Examples of a semiconductor compound may include CdS, CdSe, CdTe, ZnS, ZnSe, ZnTe, ZnSeS. ZnTeS, GaAs, GaP, GaSb, HgS, HgSe, HgTe, InAs, InP, InGaP, InSb, AlAs, AlP. AlSb, etc., but embodiments are not limited thereto.

The quantum dot may have a full width at half maximum (FWHM) of an emission wavelength spectrum equal to or less than about 45 nm. For example, the quantum dot may have a FWHM of an emission wavelength spectrum equal to or less than about 40 nm. For example, the quantum dot may have a FWHM of an emission wavelength spectrum equal to or less than about 30 nm. Color purity or color reproducibility may be improved in any of the above ranges. Light emitted through a quantum dot may be emitted in all directions, so that a wide viewing angle may be improved.

The form of a quantum dot is not particularly limited and may be any form used in the related art. For example, the quantum dot may have a spherical shape, a pyramidal shape, a multi-arm shape, or a cubic shape, or the quantum dot may be in the form of nanoparticles, nanotubes, nanowires, nanofibers, nanoplate particles, etc.

As a size of the quantum dot is adjusted or an elemental ratio of a quantum dot compound is adjusted, it is possible to control the energy band gap, and thus light in various wavelength ranges may be obtained from a quantum dot emission layer. Therefore, a quantum dot as described above (using different sizes of quantum dots or different elemental ratios in a quantum dot compound) may be implemented, so that a light emitting element may emit light in various wavelengths. For example, a size of a quantum dot or an elemental ratio of a quantum dot compound may each independently be adjusted to emit red light, green light, and/or blue light. For example, quantum dots may be configured to emit white light by combining various colors of light.

In the light emitting elements ED according to an embodiment as shown in each of FIGS. 3 to 6, the electron transport region ETR may be provided on the emission layer EML. The electron transport region ETR may include at least one of a hole blocking layer HBL, an electron transport layer ETL, and an electron injection layer EIL, but embodiments are not limited thereto.

The electron transport region ETR may be a layer consisting of a single material, a layer including different materials, or a structure including multiple layers including different materials.

For example, the electron transport region ETR may have a single layer structure of an electron injection layer EIL or an electron transport layer ETL, or may have a single layer structure formed of an electron injection material and an electron transport material. In other embodiments, the electron transport region ETR may have a single layer structure formed of different materials, or may have a structure in which an electron transport layer ETL/electron injection layer EIL, or a hole blocking layer HBL/electron transport layer ETL/electron injection layer EIL are stacked in its respective stated order from the emission layer EML, but embodiments are not limited thereto. The electron transport region ETR may have a thickness in a range of about 1,000 Å to about 1,500 Å.

The electron transport region ETR may be formed using various methods such as a vacuum deposition method, a spin coating method, a cast method, a Langmuir-Blodgett (LB) method, an inkjet printing method, a laser printing method, and a laser induced thermal imaging (LITI) method.

In the light emitting element ED according to an embodiment, the electron transport region ETR may include a compound represented by Formula ET-2:

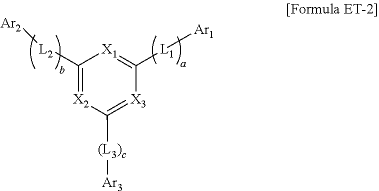

In Formula ET-2, at least one of X₁ to X₃ may each be N; and the remainder of X₁ to X₃ may each independently be C(Rₐ). In Formula ET-2, Rₐ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In Formula ET-2, Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-2, a to c may each independently be an integer from 0 to 10. In Formula ET-2, Li to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms. When a to c are each 2 or more, multiple groups of each of Li to L₃ may each independently be a substituted or unsubstituted arylene group having 6 to 30 ring-forming carbon atoms or a substituted or unsubstituted heteroarylene group having 2 to 30 ring-forming carbon atoms.

The electron transport region ETR may include an anthracene-based compound. However, embodiments are not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzimidazol-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,08)-(1,1′-biphenyl-4-olato)aluminum(bis(benzoquinolin-10-olate) (Bebq₂), 9,10-di(naphthalene-2-yl)anthracene (ADN), 1,3-bis[3,5-di(pyridin-3-yl)phenyl]benzene (BmPyPhB), or a mixture thereof.

In an embodiment, the electron transport region ETR may include at least one compound selected from Compound ET1 to Compound ET36:

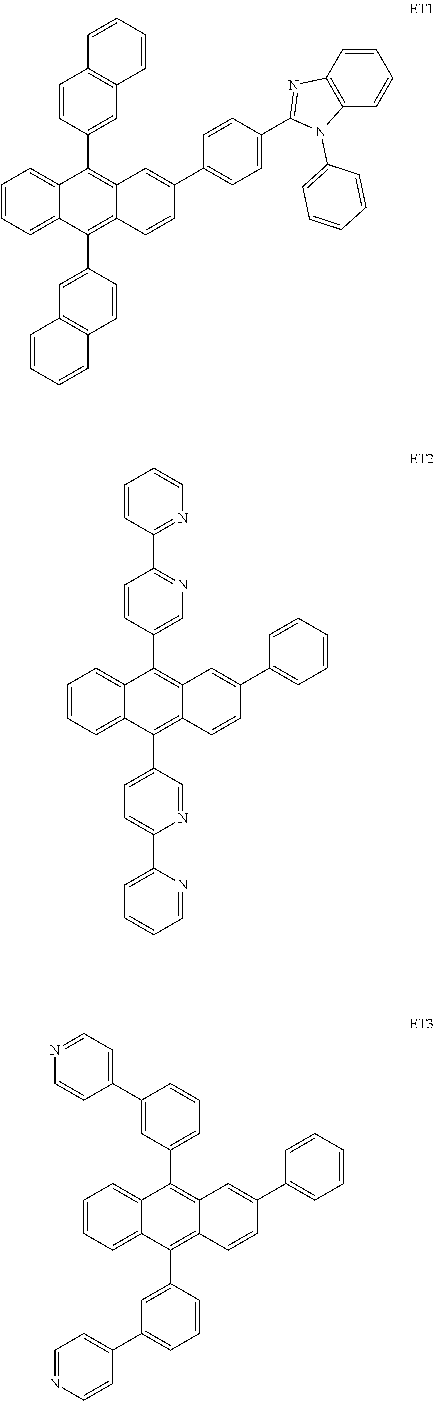 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

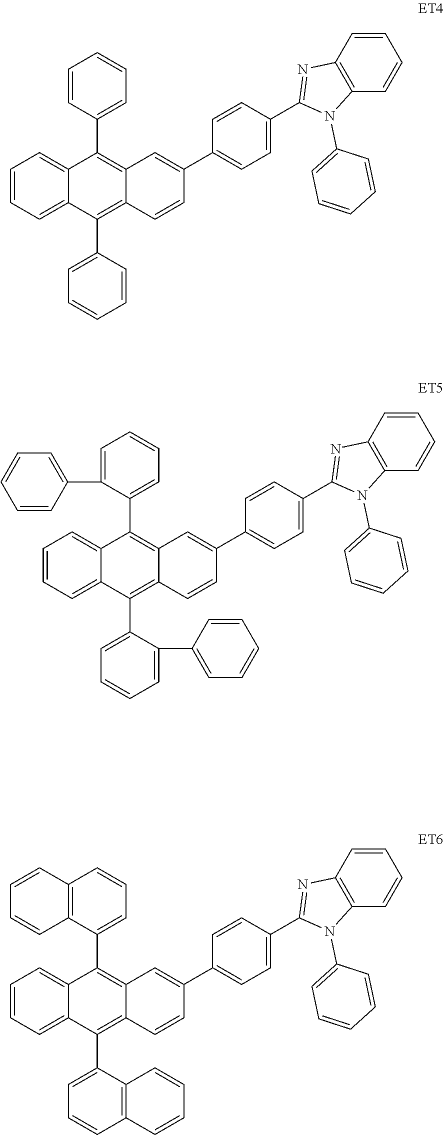 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

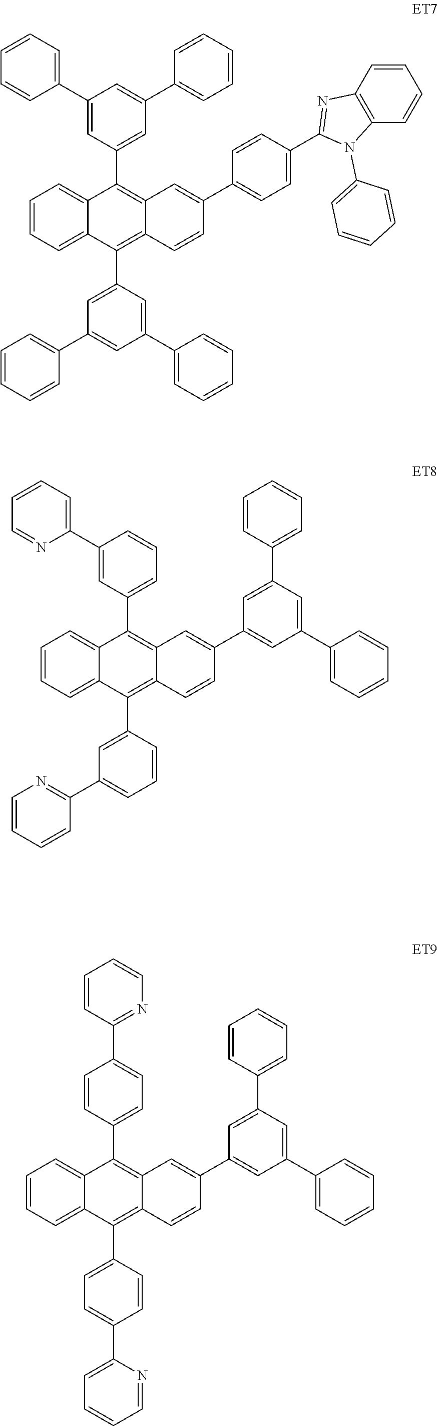 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

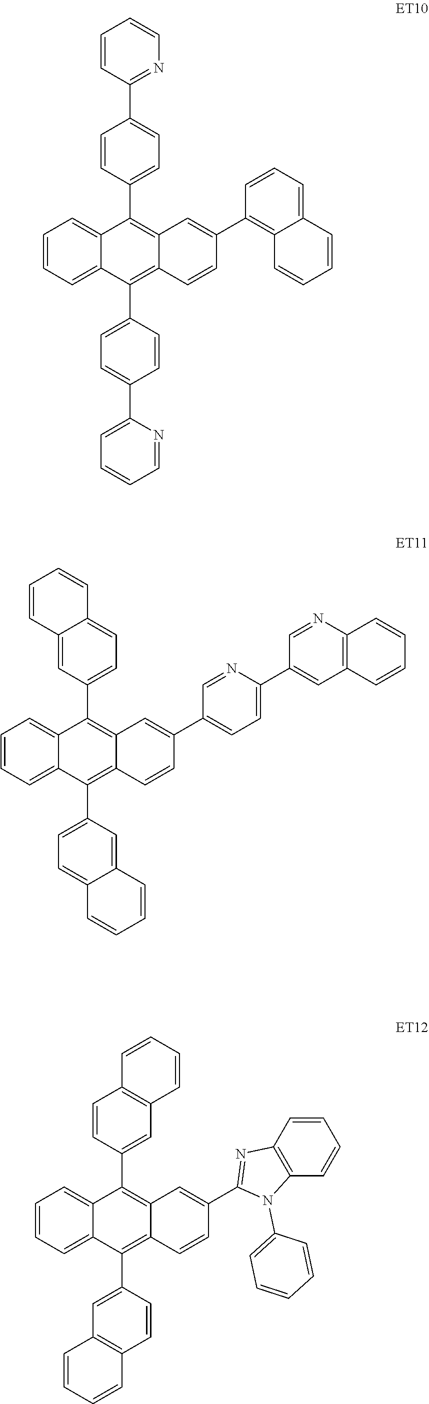 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

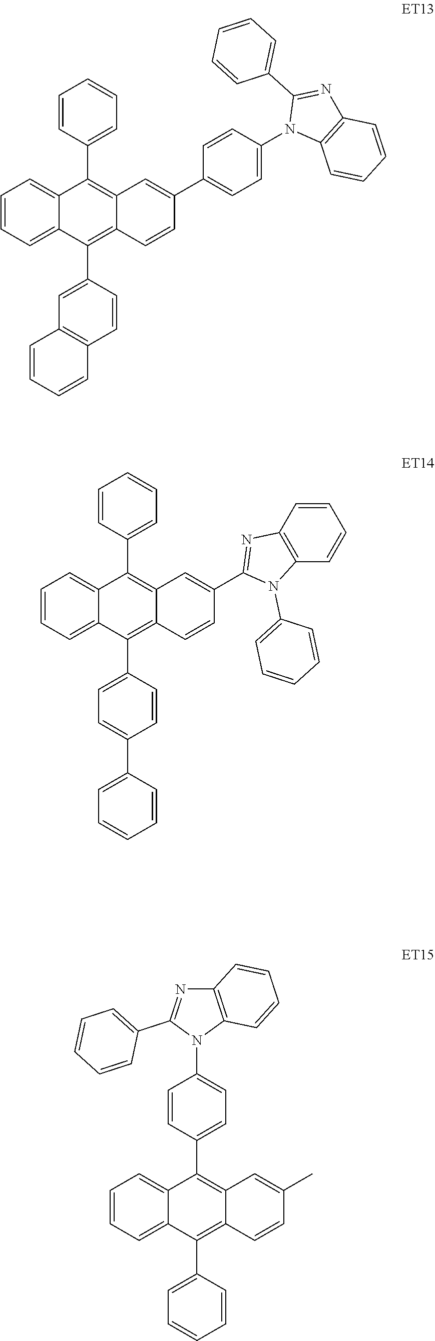 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1]

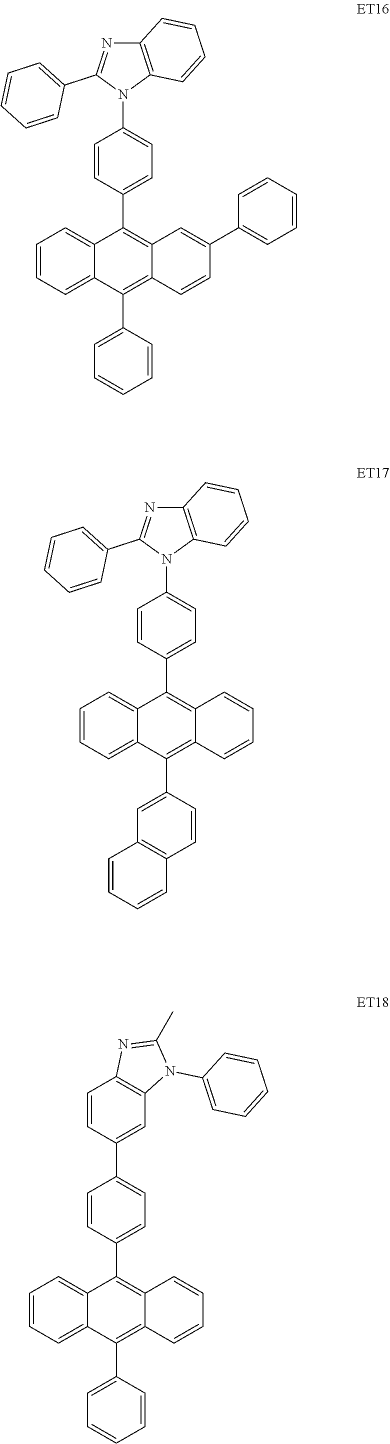 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

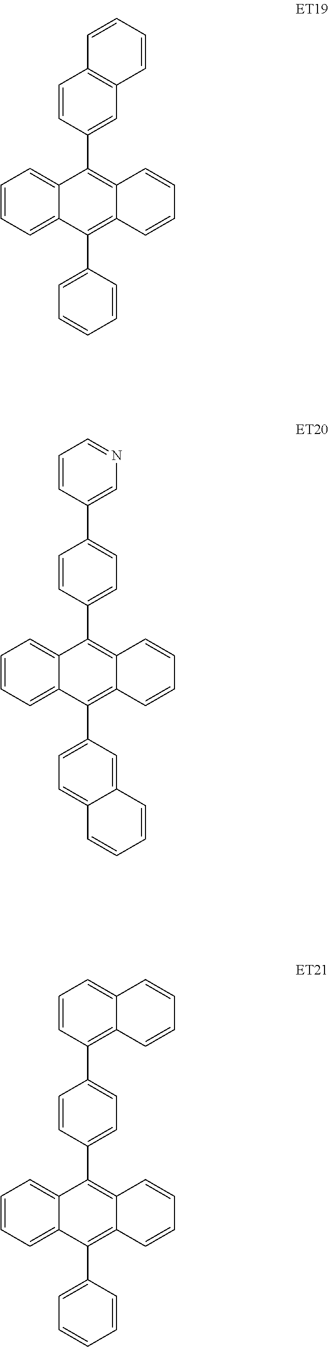

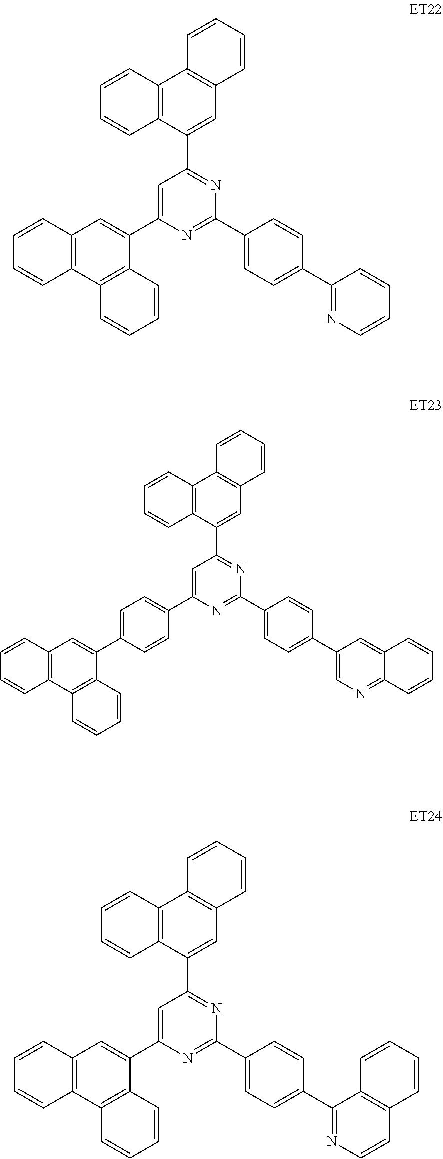 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1]

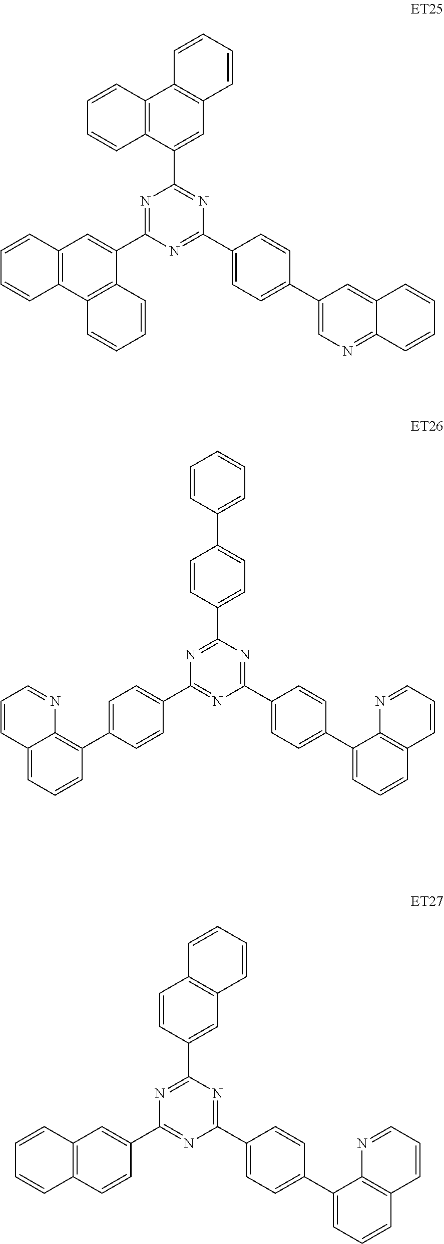 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

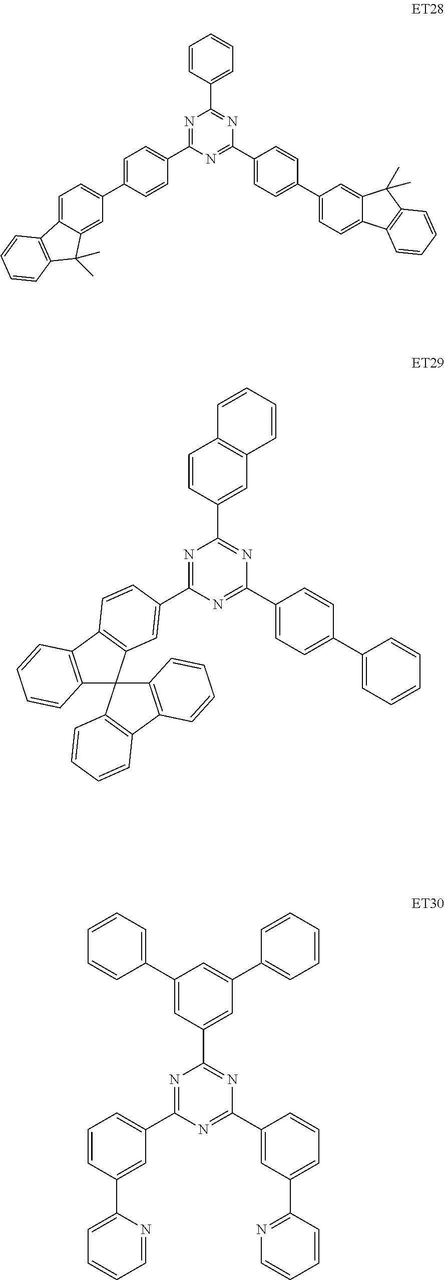 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3nc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

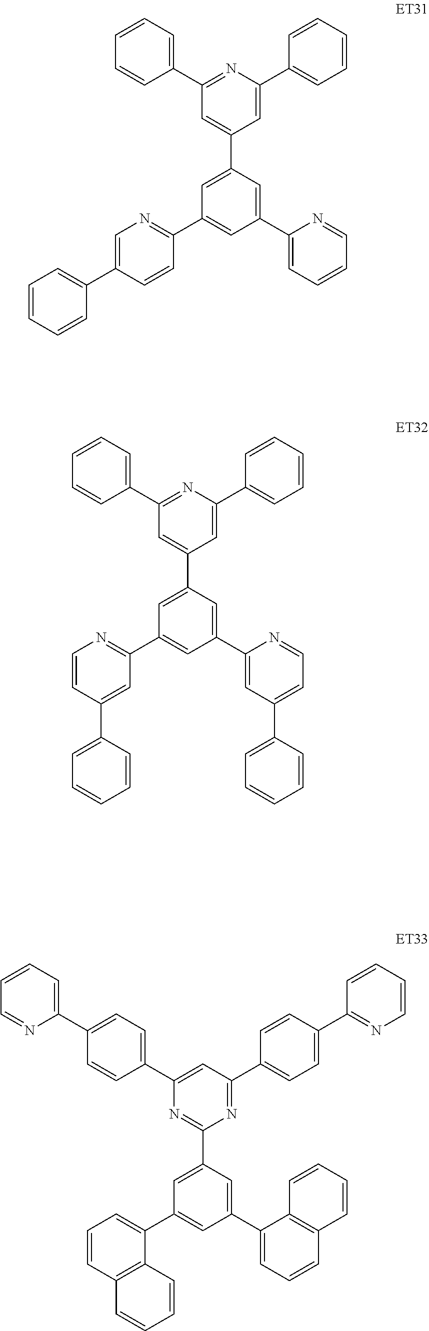 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

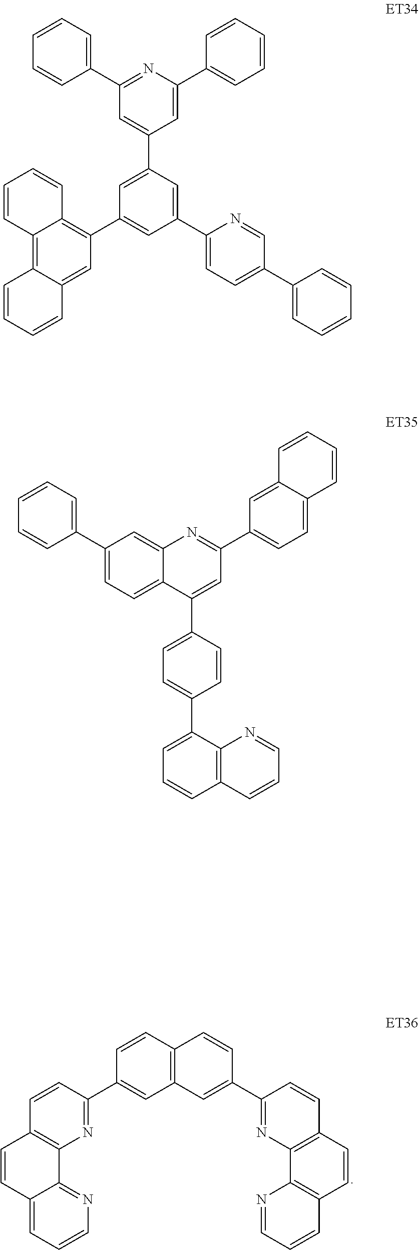 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

In an embodiment, the electron transport region ETR may include: a metal halide such as LiF, NaCl, CsF, RbCI, RbI, CuI, and KI; a lanthanide metal such as Yb; or a co-deposited material of a metal halide and a lanthanide metal. For example, the electron transport region ETR may include KI:Yb, RbI: Yb, LiF: Yb, etc., as a co-deposited material. The electron transport region ETR may be formed of a metal oxide such as Li₂O or BaO, or 8-hydroxyl-lithium quinolate (Liq), etc., but embodiments are not limited thereto. The electron transport region ETR may also be formed of a mixture material of an electron transport material and an insulating organometallic salt. The insulating organometallic salt may be a material having an energy band gap equal to or greater than about 4 eV. For example, the insulating organometallic salt may include a metal acetate, a metal benzoate, a metal acetoacetate, a metal acetylacetonate, or a metal stearate.

The electron transport region ETR may further include at least one of 2,9-dimethyl-4,7-diphenyl-1,10-phenanthroline (BCP), diphenyl(4-(triphenylsilyl)phenyl)phosphine oxide (TSPO₁), or 4,7-diphenyl-1,10-phenanthroline (Bphen) in addition to the above-described materials, but embodiments are not limited thereto.

The electron transport region ETR may include the above-described compounds of the hole transport region in at least one of an electron injection layer EIL, an electron transport layer ETL, and a hole blocking layer HBL.

When the electron transport region ETR includes an electron transport layer ETL, the electron transport layer ETL may have a thickness in a range of about 100 Å to about 1,000 Å. For example, the electron transport layer ETL may have a thickness in a range of about 150 Å to about 500 Å. If the thickness of the electron transport layer ETL satisfies any of the aforementioned ranges, satisfactory electron transport characteristics may be obtained without a substantial increase in driving voltage. When the electron transport region ETR includes an electron injection layer EIL, the electron injection layer EIL may have a thickness in a range of about 1 Å to about 100 Å. For example, the electron injection layer EIL may have a thickness in a range of about 3 Å to about 90 Å. If the thickness of the electron injection layer EIL satisfies any of the above-described ranges, satisfactory electron injection characteristics may be obtained without a substantial increase in driving voltage.

The second electrode EL2 may be provided on the electron transport region ETR. The second electrode EL2 may be a common electrode. The second electrode EL2 may be a cathode or an anode, but embodiments are not limited thereto. For example, when the first electrode EL1 is an anode, the second electrode EL2 may be a cathode, and when the first electrode EL1 is a cathode, the second electrode EL2 may be an anode.

The second electrode EL2 may be a transmissive electrode, a transflective electrode, or a reflective electrode. When the second electrode EL2 is a transmissive electrode, the second electrode EL2 may be formed of a transparent metal oxide, for example, indium tin oxide (ITO), indium zinc oxide (IZO), zinc oxide (ZnO), indium tin zinc oxide (ITZO), etc.

When the second electrode EL2 is a transflective electrode or a reflective electrode, the second electrode EL2 may include Ag. Mg. Cu, Al, Pt, Pd, Au, Ni, Nd, Ir, Cr, Li, Ca, LiF/Ca, LiF/Al, Mo, Ti, Yb, W, a compound thereof, or a mixture thereof (e.g., AgMg, AgYb, or MgYb). In an embodiment, the second electrode EL2 may have a multilayer structure including a reflective film or a transflective film formed of the above-described materials, and a transparent conductive film formed of ITO, IZO, ZnO, ITZO, etc. For example, the second electrode EL2 may include the above-described metal materials, combinations of at least two metal materials of the above-described metal materials, oxides of the above-described metal materials, or the like.

Although not shown in the drawings, the second electrode EL2 may be electrically connected to an auxiliary electrode. If the second electrode EL2 is electrically connected to an auxiliary electrode, resistance of the second electrode EL2 may decrease.

In an embodiment, the light emitting element ED may further include a capping layer CPL disposed on the second electrode EL2. The capping layer CPL may be a multilayer or a single layer.

In an embodiment, the capping layer CPL may include an organic layer or an inorganic layer. For example, when the capping layer CPL includes an inorganic material, the inorganic material may include an alkaline metal compound (e.g., LiF), an alkaline earth metal compound (e.g., MgF₂), SiON, SiNx, SiOy, etc.

For example, when the capping layer CPL includes an organic material, the organic material may include a-NPD, NPB, TPD, m-MTDATA, Alq₃, CuPc, N⁴,N⁴,N^{4′},N^{4′}-tetra(biphenyl-4-yl)biphenyl-4,4′-diamine (TPD15), 4,4′,4″-tris(carbazol-9-yl)triphenylamine (TCTA), etc., or may include an epoxy resin, or an acrylate such as methacrylate. However, embodiments are not limited thereto. In an embodiment, the capping layer CPL may include at least one of Compounds P₁ to P₅:

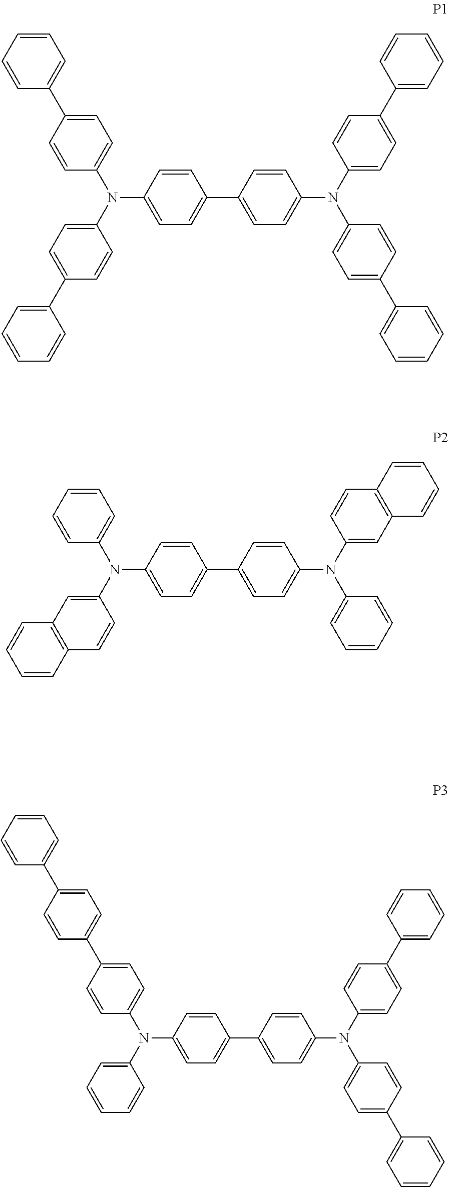 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1]

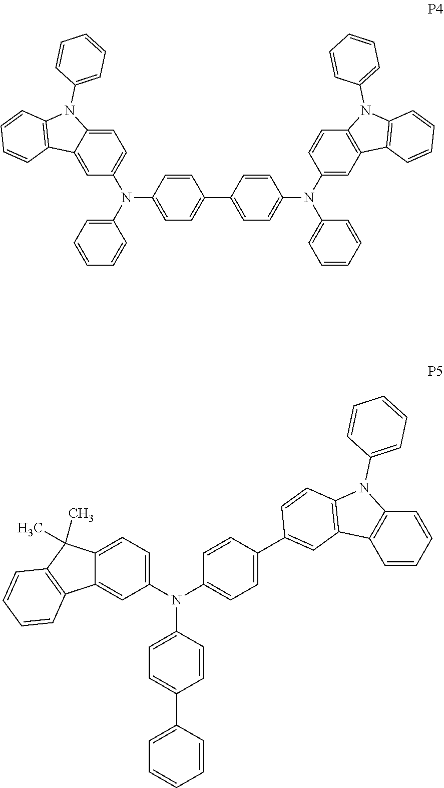 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC1(C)c2ccccc2-c2cc(N(c3ccc(-c4ccccc4)cc3)c3ccc(-c4ccc5c(c4)c4ccccc4n5-c4ccccc4)cc3)ccc21]

A refractive index of the capping layer CPL may be equal to or greater than about 1.6. For example, the refractive index of the capping layer CPL may be equal to or greater than about 1.6 with respect to light in a wavelength range of about 550 nm to about 660 nm.

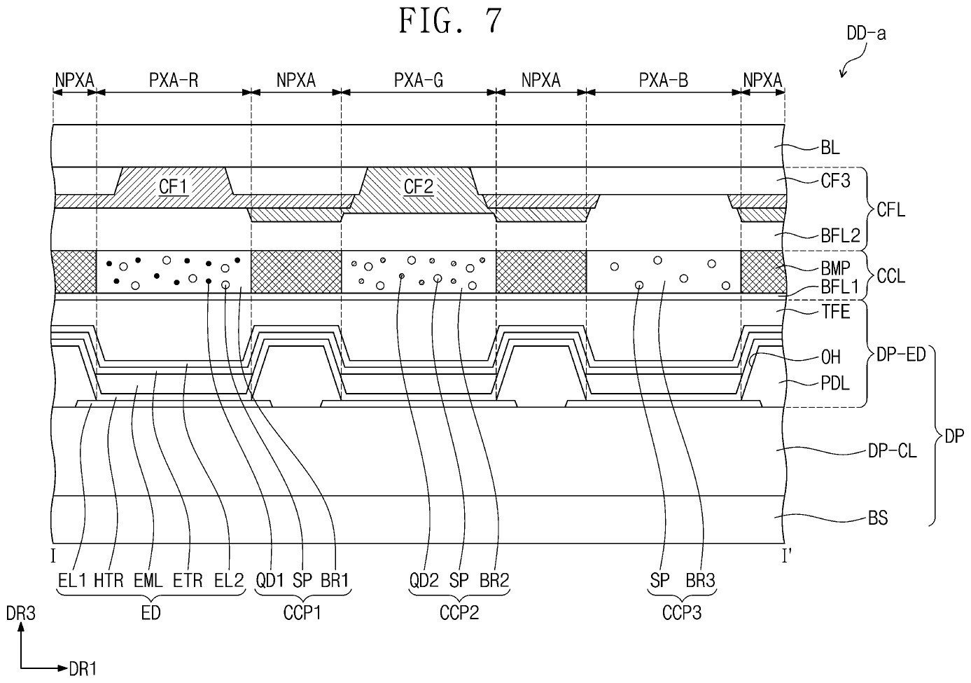

FIGS. 7 to 10 are each a schematic cross-sectional view of a display apparatus according to an embodiment. In the descriptions of the display apparatuses according to embodiments as shown in FIGS. 7 to 10, the features which have been described above with respect to FIGS. 1 to 6 will not be explained again, and the differing features will be described.

Referring to FIG. 7, the display apparatus DD-a according to an embodiment may include a display panel DP including a display device layer DP-ED, a light control layer CCL disposed on the display panel DP, and a color filter layer CFL.

In an embodiment shown in FIG. 7, the display panel DP may include a base layer BS, a circuit layer DP-CL provided on the base layer BS, and the display device layer DP-ED, and the display device layer DP-ED may include a light emitting element ED.

The light emitting element ED may include a first electrode EL1, a hole transport region HTR disposed on the first electrode EL1, an emission layer EML disposed on the hole transport region HTR, an electron transport region ETR disposed on the emission layer EML, and a second electrode EL2 disposed on the electron transport region ETR. In embodiments, a structure of the light emitting element ED shown in FIG. 7 may be the same as a structure of a light emitting element ED according to one of FIGS. 3 to 6 as described above.

Referring to FIG. 7, the emission layer EML may be disposed in an opening OH defined in a pixel defining film PDL. For example, the emission layer EML, which is separated by the pixel defining film PDL and correspondingly provided to each of the light emitting regions PXA-R. PXA-G, and PXA-B, may emit light in a same wavelength range. In the display apparatus DD-a, the emission layer EML may emit blue light. Although not shown in the drawings, in an embodiment, the emission layer EML may be provided as a common layer for each of the light emitting regions PXA-R. PXA-G, and PXA-B.

The light control layer CCL may be disposed on the display panel DP. The light control layer CCL may include a light conversion body. The light conversion body may be a quantum dot, a phosphor, or the like. The light conversion body may convert the wavelength of a provided light and may emit the resulting light. For example, the light control layer CCL may be a layer including a quantum dot or a layer including a phosphor.

The light control layer CCL may include light control parts CCP1, CCP2, and CCP3. The light control parts CCP1, CCP2, and CCP3 may be spaced apart from each other.

Referring to FIG. 7, divided patterns BMP may be disposed between the light control parts CCP1, CCP2, and CCP3, which are spaced apart from each other, but embodiments are not limited thereto. In FIG. 7, it is shown that the divided patterns BMP do not overlap the light control parts CCP1, CCP2, and CCP3, but the edges of the light control parts CCP1, CCP2, and CCP3 may overlap at least a portion of the divided patterns BMP.

The light control layer CCL may include a first light control part CCP1 including a first quantum dot QD1 that converts first color light provided from the light emitting element ED into second color light, a second light control part CCP2 including a second quantum dot QD2 that converts the first color light into third color light, and a third light control part CCP3 that transmits the first color light.

In an embodiment, the first light control part CCP1 may provide red light, which is the second color light, and the second light control part CCP2 may provide green light, which is the third color light. The third light control part CCP3 may provide blue light by transmitting the blue light which is the first color light provided from the light emitting element ED. For example, the first quantum dot QD1 may be a red quantum dot, and the second quantum dot QD2 may be a green quantum dot. The quantum dots QD1 and QD2 may each be a quantum dot as described above.

The light control layer CCL may further include a scatterer SP. The first light control part CCP1 may include the first quantum dot QD1 and the scatterer SP, the second light control part CCP2 may include the second quantum dot QD2 and the scatterer SP, and the third light control part CCP3 may not include a quantum dot but may include the scatterer SP.

The scatterer SP may be inorganic particles. For example, the scatterer SP may include at least one of TiO₂, ZnO, Al₂O₃, SiO₂, and hollow silica. The scatterer SP may include one of TiO₂, ZnO, Al₂O₃, SiO₂, and hollow silica, or may be a mixture of at least two materials selected from TiO₂, ZnO, Al₂O₃, SiO₂, and hollow silica.

The first light control part CCP1, the second light control part CCP2, and the third light control part CCP3 may each include base resins BR1, BR2, and BR3, in which the quantum dots QD1 and QD2 and the scatterer SP are dispersed. In an embodiment, the first light control part CCP1 may include the first quantum dot QD1 and the scatterer SP dispersed in a first base resin BR1, the second light control part CCP2 may include the second quantum dot QD2 and the scatterer SP dispersed in a second base resin BR2, and the third light control part CCP3 may include the scatterer SP dispersed in a third base resin BR3.

The base resins BR1, BR2, and BR3 are media in which the quantum dots QD1 and QD2 and the scatterer SP are dispersed, and may be formed of various resin compositions, which may be generally referred to as a binder. For example, the base resins BR1, BR2, and BR3 may be acrylic-based resins, urethane-based resins, silicone-based resins, epoxy-based resins, etc. The base resins BR1, BR2, and BR3 may each be a transparent resin. In an embodiment, the first base resin BR1, the second base resin BR2, and the third base resin BR3 may be the same as or different from each other.

The light control layer CCL may include a barrier layer BFL1. The barrier layer BFL1 may prevent the penetration of moisture and/or oxygen (hereinafter, referred to as ‘moisture/oxygen’). The barrier layer BFL1 may block the light control parts CCP1, CCP2, and CCP3 from exposure to moisture/oxygen. The barrier layer BFL1 may cover the light control parts CCP1, CCP2, and CCP3. A barrier layer BFL2 may be provided between the light control parts CCP1, CCP2, and CCP3 and the color filter layer CFL.

The barrier layers BFL1 and BFL2 may each independently include at least one inorganic layer. For example, the barrier layers BFL1 and BFL2 may each independently include an inorganic material. For example, the barrier layers BFL1 and BFL2 may each independently include a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, a silicon oxynitride, a metal thin film which secures a transmittance, etc. The barrier layers BFL1 and BFL2 may each independently further include an organic film. The barrier layers BFL1 and BFL2 may each be formed of a single layer or of multiple layers.

In the display apparatus DD-a, the color filter layer CFL may be disposed on the light control layer CCL. In an embodiment, the color filter layer CFL may be directly disposed on the light control layer CCL. For example, the barrier layer BFL2 may be omitted.

The color filter layer CFL may include filters CF1, CF2, and CF3. The color filter layer CFL may include a first filter CF1 that transmits second color light, a second filter CF2 that transmits third color light, and a third filter CF3 that transmits first color light. For example, the first filter CF1 may be a red filter, the second filter CF2 may be a green filter, and the third filter CF3 may be a blue filter. The filters CF1, CF2, and CF3 may each include a polymeric photosensitive resin and a pigment or dye. The first filter CF1 may include a red pigment or dye, the second filter CF2 may include a green pigment or dye, and the third filter CF3 may include a blue pigment or dye.

However, embodiments are not limited thereto, and the third filter CF3 may not include a pigment or dye. The third filter CF3 may include a polymeric photosensitive resin and may not include a pigment or dye. The third filter CF3 may be transparent. The third filter CF3 may be formed of a transparent photosensitive resin.

In an embodiment, the first filter CF1 and the second filter CF2 may each be a yellow filter. The first filter CF1 and the second filter CF2 may not be separated but may be provided as one filter.

Although not shown in the drawings, the color filter layer CFL may further include a light shielding part (not shown). The light shielding part (not shown) may be a black matrix. The light shielding part (not shown) may include an organic light shielding material or an inorganic light shielding material, each including a black pigment or dye. The light shielding part (not shown) may prevent light leakage, and may separate boundaries between adjacent filters CF1, CF2, and CF3.

The first to third filters CF1, CF2, and CF3 may be disposed to respectively correspond to the red light emitting region PXA-R, the green light emitting region PXA-G, and the blue light emitting region PXA-B.

A base substrate BL may be disposed on the color filter layer CFL. The base substrate BL may provide a base surface on which the color filter layer CFL, the light control layer CCL, and the like are disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

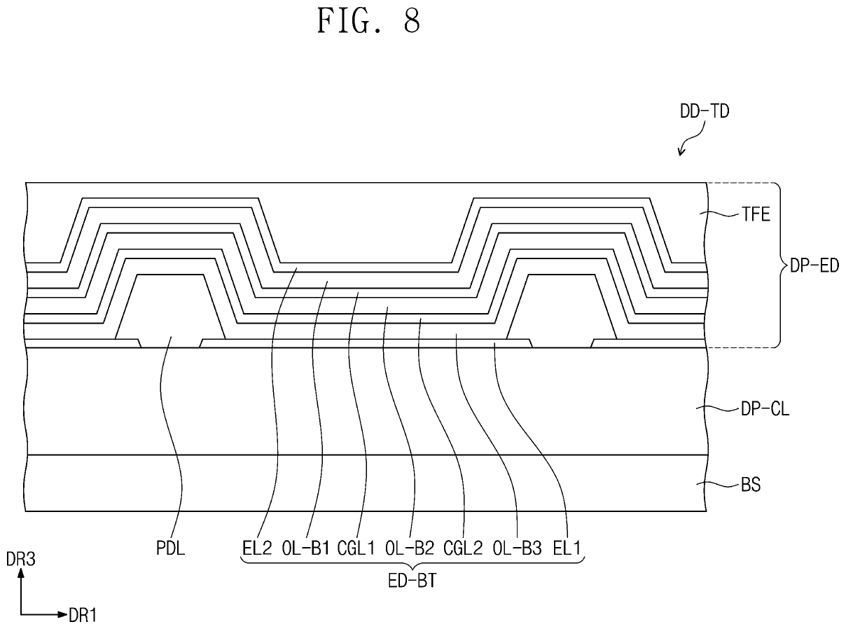

FIG. 8 is a schematic cross-sectional view of a portion of a display apparatus according to an embodiment. In the display apparatus DD-TD according to an embodiment, the light emitting element ED-BT may include light emitting structures OL-B1, OL-B2, and OL-B3. The light emitting element ED-BT may include a first electrode EL1 and a second electrode EL2 which face each other, and the light emitting structures OL-B1, OL-B2, and OL-B3 stacked in a thickness direction between the first electrode EL1 and the second electrode EL2. The light emitting structures OL-B1, OL-B2, and OL-B3 may each include an emission layer EML (FIG. 7), and a hole transport region HTR and an electron transport region ETR disposed with the emission layer EML (FIG. 7) located therebetween.

For example, the light emitting element ED-BT included in the display apparatus DD-TD may be a light emitting element having a tandem structure and including multiple emission layers.

In an embodiment illustrated in FIG. 8, light emitted from each of the light emitting structures OL-B1, OL-B2, and OL-B3 may be blue light. However, embodiments are not limited thereto, and the light emitted from each of the light emitting structures OL-B1, OL-B2, and OL-B3 may have wavelength ranges that are different from each other. For example, the light emitting element ED-BT that includes the light emitting structures OL-B1, OL-B2, and OL-B3, which emit light having wavelength ranges that are different from each other, may emit white light.

Charge generation layers CGL1 and CGL2 may each be disposed between adjacent light emitting structures among the light emitting structures OL-B1, OL-B2, and OL-B3. Charge generation layers CGL1 and CGL2 may each independently include a p-type charge generation layer and/or an n-type charge generation layer.

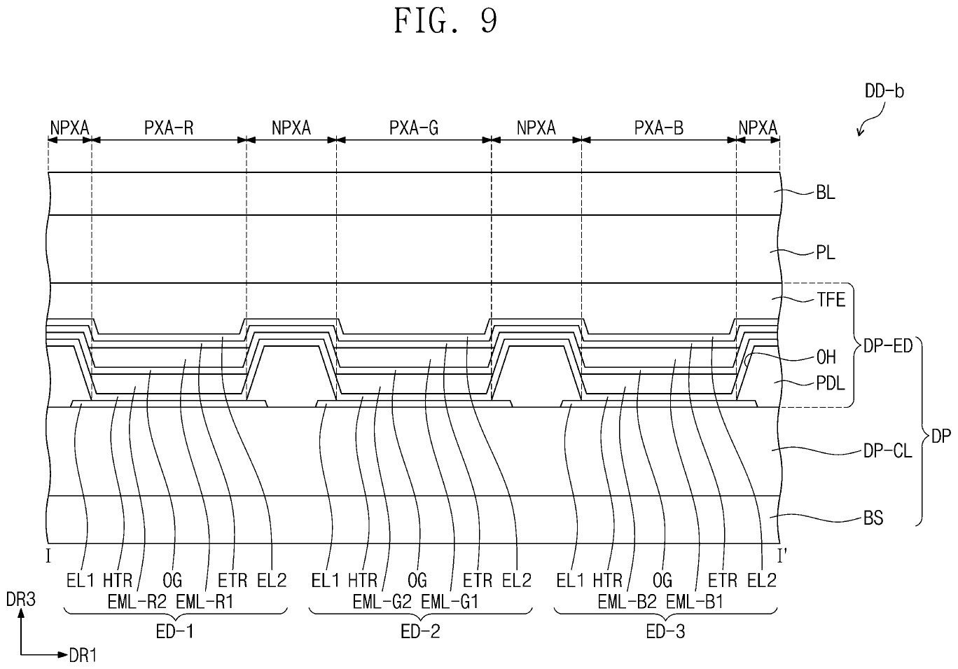

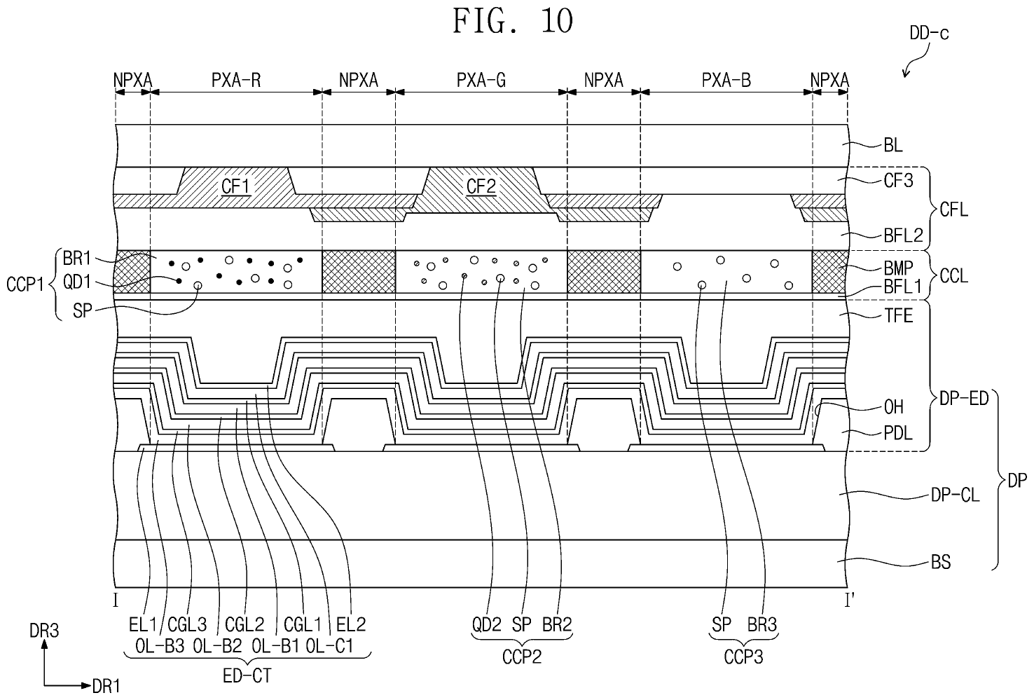

Referring to FIG. 9, the display apparatus DD-b according to an embodiment may include light emitting elements ED-1, ED-2, and ED-3 in which two emission layers are stacked. In comparison to the display apparatus DD shown in FIG. 2, the embodiment shown in FIG. 9 is different at least in that the first to third light emitting elements ED-1, ED-2, and ED-3 each include two emission layers that are stacked in a thickness direction. In each of the first to third light emitting elements ED-1, ED-2, and ED-3, the two emission layers may emit light in a same wavelength region.

The first light emitting element ED-1 may include a first red emission layer EML-R₁ and a second red emission layer EML-R₂. The second light emitting element ED-2 may include a first green emission layer EML-G1 and a second green emission layer EML-G2. The third light emitting element ED-3 may include a first blue emission layer EML-B1 and a second blue emission layer EML-B2. An emission auxiliary part OG may be disposed between the first red emission layer EML-R₁ and the second red emission layer EML-R₂, between the first green emission layer EML-G1 and the second green emission layer EML-G2, and between the first blue emission layer EML-B1 and the second blue emission layer EML-B2.

The emission auxiliary part OG may be a single layer or a multilayer. The emission auxiliary part OG may include a charge generation layer. For example, the emission auxiliary part OG may include an electron transport region, a charge generation layer, and a hole transport region, which may be stacked in that order. The emission auxiliary part OG may be provided as a common layer for all of the first to third light emitting elements ED-1, ED-2, and ED-3. However, embodiments are not limited thereto, and the emission auxiliary part OG may be provided by being patterned in the openings OH defined in the pixel defining film PDL.

The first red emission layer EML-R₁, the first green emission layer EML-G1, and the first blue emission layer EML-B1 may be each disposed between the emission auxiliary part OG and the electron transport region ETR. The second red emission layer EML-R₂, the second green emission layer EML-G2, and the second blue emission layer EML-B2 may each be disposed between the hole transport region HTR and the emission auxiliary part OG.

For example, the first light emitting element ED-1 may include the first electrode EL1, the hole transport region HTR, the second red emission layer EML-R₂, the emission auxiliary part OG, the first red emission layer EML-R₁, the electron transport region ETR, and the second electrode EL2, which are stacked in that order. The second light emitting element ED-2 may include the first electrode EL1, the hole transport region HTR, the second green emission layer EML-G2, the emission auxiliary part OG, the first green emission layer EML-G1, the electron transport region ETR, and the second electrode EL2, which are stacked in that order. The third light emitting element ED-3 may include the first electrode EL1, the hole transport region HTR, the second blue emission layer EML-B2, the emission auxiliary part OG, the first blue emission layer EML-B1, the electron transport region ETR, and the second electrode EL2, which are stacked in that order.

An optical auxiliary layer PL may be disposed on the display device layer DP-ED. The optical auxiliary layer PL may include a polarizing layer. The optical auxiliary layer PL may be disposed on the display panel DP and may control light that is reflected at the display panel DP from an external light. Although not shown in the drawings, in an embodiment, the optical auxiliary layer PL may be omitted from the display apparatus DD-b.

In contrast to FIGS. 8 and 9, FIG. 10 shows a display apparatus DD-c that is different at least in that it includes four light emitting structures OL-B1, OL-B2, OL-B3, and OL-C1. A light emitting element ED-CT may include a first electrode EL1 and a second electrode EL2 which face each other, and first to fourth light emitting structures OL-B1, OL-B2, OL-B3, and OL-C1 that are stacked in a thickness direction between the first electrode EL1 and the second electrode EL2. Charge generation layers CGL1, CGL2, and CGL3 may each be disposed between adjacent light emitting structures among the first to fourth light emitting structures OL-B1, OL-B2, OL-B3, and OL-C1. Among the four light emitting structures, the first to third light emitting structures OL-B1, OL-B2, and OL-B3 may each emit blue light, and the fourth light emitting structure OL-C1 may emit green light. However, embodiments are not limited thereto, and the first to fourth light emitting structures OL-B1, OL-B2, OL-B3, and OL-C1 may emit light having different wavelength regions from each other.

The charge generation layers CGL1, CGL2, and CGL3 which are disposed between adjacent light emitting structures among the first to fourth light emitting structures OL-B1, OL-B2, OL-B3, and OL-C1 may each independently include a p-type charge generation layer and/or an n-type charge generation layer.

In the display apparatus DD-c, at least one of the light emitting structures OL-B1. OL-B2, OL-B3, and OL-C1 may each independently include the fused polycyclic compound according to an embodiment. For example, in an embodiment, at least one of the first to third light emitting structures OL-B1, OL-B2, and OL-B3 may each independently include the fused polycyclic compound.

The light emitting element ED according to an embodiment may include the fused polycyclic compound represented by Formula 1 in at least one functional layer disposed between the first electrode EL1 and the second electrode EL2, thereby exhibiting excellent luminous efficiency and improved service life characteristics. For example, the emission layer EML of the light emitting element ED may include the fused polycyclic compound, and the light emitting element ED may exhibit long service life characteristics.

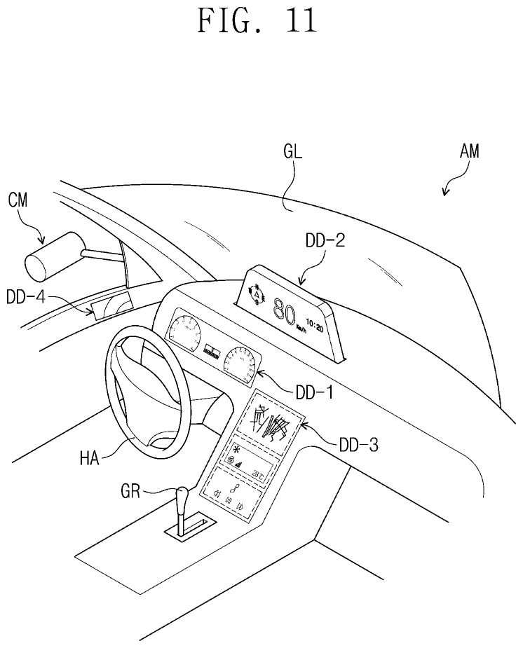

FIG. 11 is a schematic perspective view of a vehicle AM in which first to fourth display apparatuses DD-1, DD-2, DD-3, and DD-4 are disposed. At least one of the first to fourth display apparatuses DD-1, DD-2, DD-3, and DD-4 may have a structure according to one of display apparatuses DD, DD-TD, DD-a, DD-b, and DD-c, as described with reference to FIGS. 1.2, and 7 to 10.

FIG. 11 illustrates a vehicle AM, but this is only an example, and the first to fourth display apparatuses DD-1, DD-2, DD-3, and DD-4 may be disposed in various transportation means such as bicycles, motorcycles, trains, ships, and airplanes. In an embodiment, at least one of the first to fourth display apparatuses DD-1, DD-2, DD-3, and DD-4 having a structure according to one of display apparatuses DD, DD-TD, DD-a, DD-b, and DD-c may be employed in a personal computer, a laptop computer, a personal digital terminal, a game console, a portable electronic device, a television, a monitor, an outdoor billboard, or the like. However, these are merely presented as examples, and thus may be employed in other electronic apparatuses.

At least one of the first to fourth display apparatuses DD-1. DD-2, DD-3, and DD-4 may each independently include a light emitting element ED according to an embodiment as described in reference to FIGS. 3 to 6.

Referring to FIG. 11, the vehicle AM may include a steering wheel HA and a gearshift GR for driving the vehicle AM. The vehicle AM may include a front window GL that is disposed so as to face the driver.

The first display apparatus DD-1 may be disposed in a first region that overlaps the steering wheel HA. For example, the first display apparatus DD-1 may be a digital cluster which displays first information of the vehicle AM. The first information may include a first scale which indicates a driving speed of the vehicle AM, a second scale which indicates an engine speed (for example, as revolutions per minute (RPM)), a fuel gauge, etc. The first scale and the second scale may each be displayed as a digital image.

The second display apparatus DD-2 may be disposed in a second region facing the driver's seat and overlapping the front window GL. The driver's seat may be a seat where the steering wheel HA is disposed. For example, the second display apparatus DD-2 may be a head up display (HUD) that displays second information of the vehicle AM. The second display apparatus DD-2 may be optically transparent. The second information may include digital numbers that indicate a driving speed, and may further include information such as the current time. Although not shown in the drawings, in an embodiment, the second information of the second display apparatus DD-2 may be projected to the front window GL to be displayed.

The third display apparatus DD-3 may be disposed in a third region adjacent to the gearshift GR. For example, the third display apparatus DD-3 may be a center information display (CID) for a vehicle that displays third information, and the third display apparatus DD-3 may be disposed between the driver's seat and the passenger seat. The passenger seat may be a seat that is spaced apart from the driver's seat with the gearshift GR disposed therebetween. The third information may include information about traffic (e.g., navigation information), playing music or radio or a video (or an image), temperatures inside the vehicle AM, etc.

The fourth display apparatus DD-4 may be spaced apart from the steering wheel HA and the gearshift GR, and may be disposed in a fourth region adjacent to a side of the vehicle AM. For example, the fourth display apparatus DD-4 may be a digital side-view mirror that displays fourth information. The fourth display apparatus DD-4 may display an image outside the vehicle AM that is taken by a camera module CM disposed outside the vehicle AM. The fourth information may include an image outside of the vehicle AM.

The first to fourth information as described above are only presented as examples, and the first to fourth display apparatuses DD-1, DD-2, DD-3, and DD-4 may further display information about the interior and exterior of the vehicle AM. The first to fourth information may include information that is different from each other. However, embodiments are not limited thereto, and a part of the first to fourth information may include the same information as one another.

Hereinafter, a fused polycyclic according to an embodiment and a light emitting element according to an embodiment will be described with reference to the Examples and the Comparative Examples. The Examples described below are only provided as illustrations to assist in understanding the disclosure, and the scope thereof is not limited thereto.

### EXAMPLES

1. Synthesis of fused polycyclic compound

A synthesis method of the fused polycyclic compound according to an embodiment will be explained by illustrating the synthesis methods of Compounds 11, 57, 82, 92, 211, 252, 282, 347, 416, 611, 618, and 626. The synthesis methods of the fused polycyclic compounds as explained below are provided only as examples, and the synthesis methods of the fused polycyclic compound according to embodiments is not limited to the Examples below.

### (1) Synthesis of Compound 11

### (Synthesis of Intermediate 11-(1))

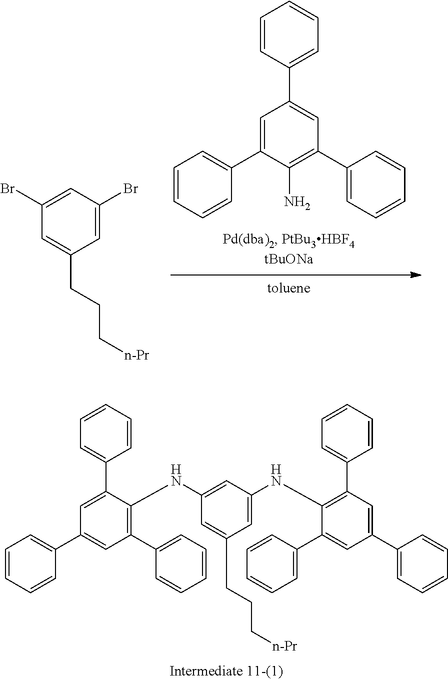

Under an Ar gas atmosphere, 1,3-dibromo-5-hexylbenzene (15.00 g, 46.86 mmol), 5′-phenyl-[1,1′:3′, 1″-terphenyl]-2′-amine (37.66 g, 117.16 mmol), Pd(dba)₂ (2.69 g, 4.69 mmol), (tBu)₃PHBF₄ (2.72 g, 9.37 mmol), and tBuONa (10.36 g, 107.79 mmol) were added to 234 ml of toluene, followed by heating and stirring at about 100° C. for about 8 hours. Water was added thereto, celite filtration was performed, layer separation was performed, and an organic layer was concentrated. Purification was performed by silica gel column chromatography to obtain Intermediate 11-(1) (30.79 g, yield 82%). In FAB-MS measurement, the molecular weight of Intermediate 11-(1) was 801.

### (Synthesis of Intermediate 11-(2))

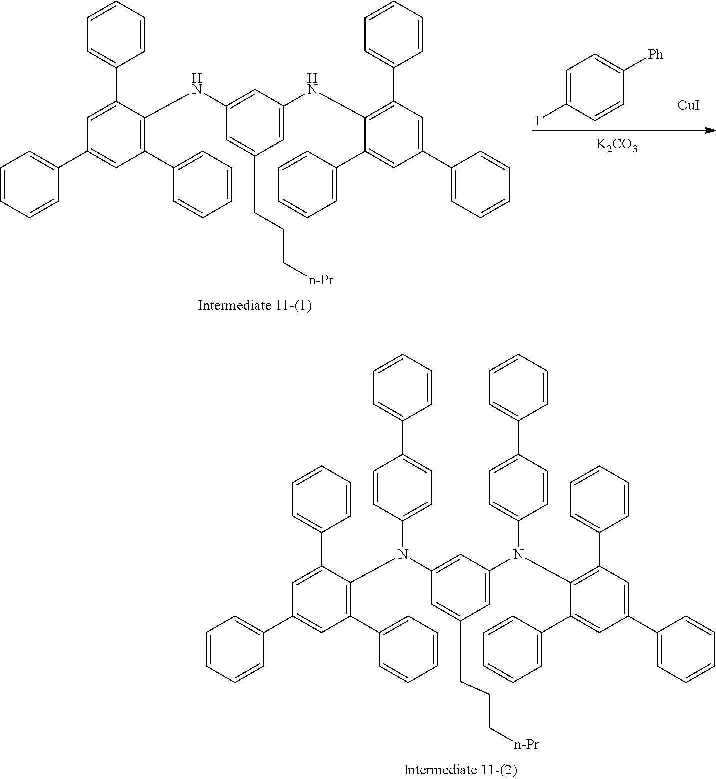

To Intermediate 11-(1) (20.52 g, 25.62 mmol), 4-iodo-1,1′-biphenyl (107.63 g, 384.23 mmol), CuI (10.24 g, 53.79 mmol), and K₂CO₃ (28.32 g, 204.92 mmol), about 10 ml of toluene was added, followed by heating for about 24 hours while keeping the outer temperature of about 215° C. The reaction solution was diluted with CH₂Cl₂, water was added thereto, celite filtration was performed, layer separation was performed, and an organic layer was concentrated. Purification was performed by silica gel column chromatography to obtain Intermediate 11-(2) (19.26 g, yield 68%). In FAB-MS measurement, the molecular weight of Intermediate 11-(2) was 1105.

### (Synthesis of Compound 11)

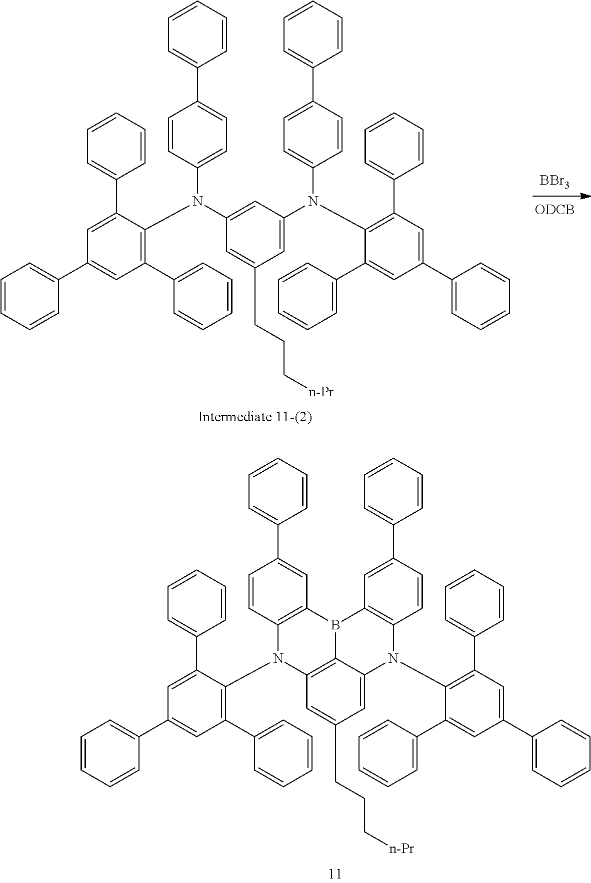

Under an Ar gas atmosphere, Intermediate 11-(2) (12.11 g, 10.95 mmol) was dissolved in ODCB (110 ml), and BBr₃ (5.49 g, 21.91 mmol) was added thereto, followed by heating and stirring at about 170° C. for about 10 hours. The reaction solution was cooled to room temperature, DIPEA (16.96 g, 131.45 mmol) was added thereto, water was added thereto, celite filtration was performed, layer separation was performed, and an organic layer was concentrated. Purification was performed by silica gel column chromatography to obtain Compound 11 (6.71 g, yield 55%). In FAB-MS measurement, the molecular weight of Compound 11 was 1113. Compound 11 was purified by sublimation (320° C., 2.1×10⁻³ Pa) during the manufacture of a light emitting element, which will be explained later, and device evaluation was conducted.

### (2) Synthesis of Compound 57

### (Synthesis of Intermediate 57-(1))

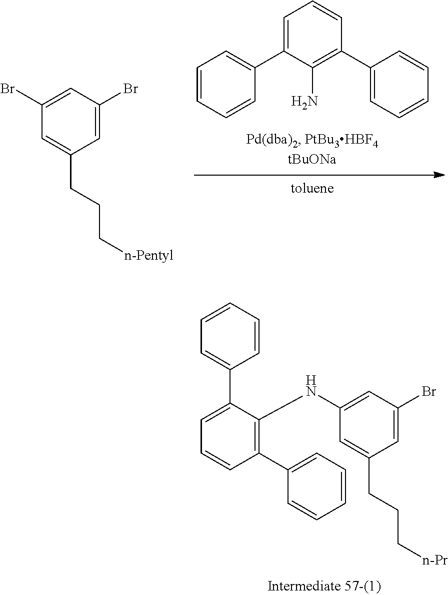

Under an Ar gas atmosphere, 1,3-dibromo-5-hexylbenzene (15 g, 43.09 mmol), [1,1′:3′,1″-terphenyl]-2′-amine (11.1 g, 45.24 mmol), Pd(dba)₂ (2.48 g, 4.31 mmol), (tBu)₃PHBF₄ (2.5 g, 8.62 mmol), and tBuONa (9.52 g, 99.1 mmol) were added to 215 ml of toluene, followed by heating and stirring at about 100° C. for about 8 hours. Water was added thereto, celite filtration was performed, layer separation was performed, and an organic layer was concentrated. Purification was performed by silica gel column chromatography to obtain Intermediate 57-(1) (16.56 g, yield 75%). In FAB-MS measurement, the molecular weight of Intermediate 57-(1) was 513.

### (Synthesis of Intermediate 57-(2))

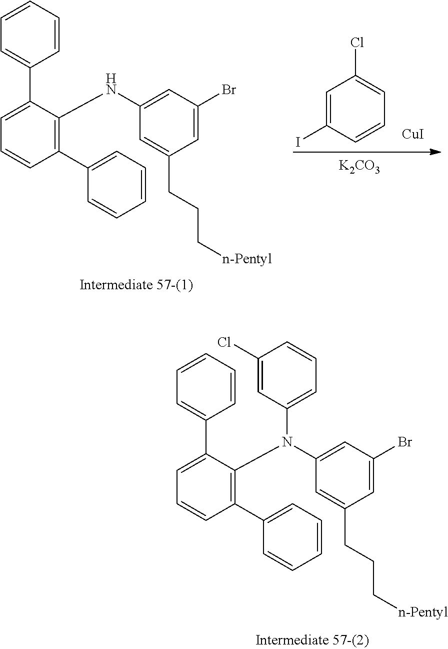

To Intermediate 57-(1) (20.03 g, 39.08 mmol), 1-chloro-3-iodobenzene (139.78 g, 586.2 mmol), CuI (15.63 g, 82.07 mmol), and K₂CO₃ (43.21 g, 312.64 mmol), about 10 ml of toluene was added, followed by heating for about 24 hours while keeping the outer temperature of about 215° C. The reaction solution was diluted with CH₂Cl₂, water was added thereto, celite filtration was performed, layer separation was performed, and an organic layer was concentrated. Purification was performed by silica gel column chromatography to obtain Intermediate 57-(2) (18.26 g, yield 75%). In FAB-MS measurement, the molecular weight of Intermediate 57-(2) was 623.

### (Synthesis of Intermediate 57-(3))

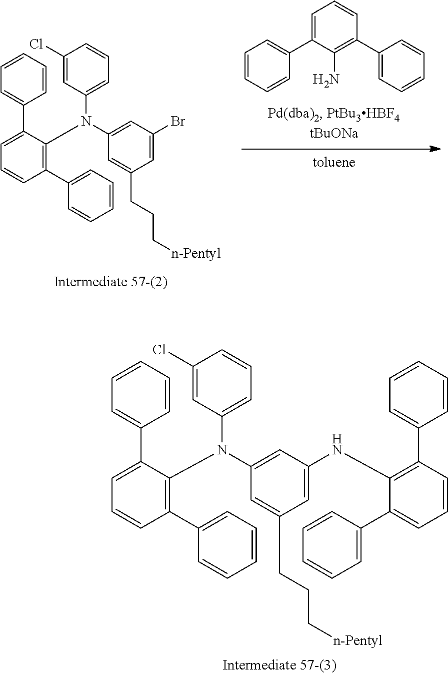

Under an Ar gas atmosphere, Intermediate 57-(2) (18.02 g, 28.92 mmol), [1,1′:3′,1″-terphenyl]-2′-amine (17.74 g, 72.3 mmol), Pd(dba)₂ (1.66 g, 2.89 mmol), (tBu)₃PHBF₄ (1.68 g, 5.78 mmol), and tBuONa (6.39 g, 66.52 mmol) were added to 144 ml of toluene, followed by heating and stirring at about 100° C. for about 8 hours. Water was added thereto, celite filtration was performed, layer separation was performed, and an organic layer was concentrated. Purification was performed by silica gel column chromatography to obtain Intermediate 57-(3) (17.76 g, yield 78%). In FAB-MS measurement, the molecular weight of Intermediate 57-(3) was 787.

### (Synthesis of Intermediate 57-(4))

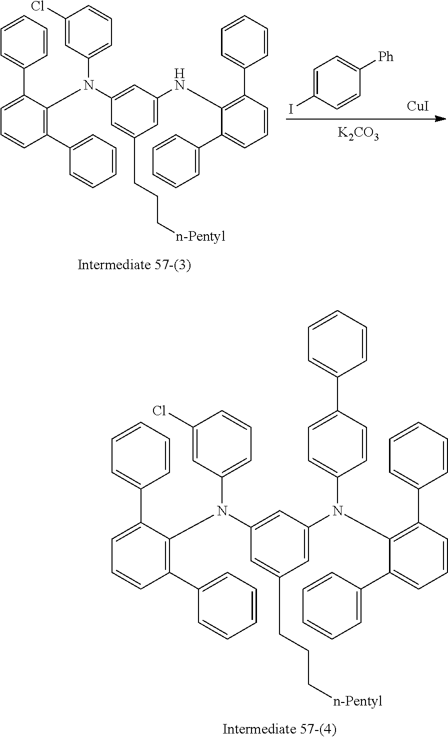

To Intermediate 57-(3) (17.01 g, 21.6 mmol), 4-iodo-1,1′-biphenyl (90.76 g, 324 mmol), CuI (8.64 g, 45.36 mmol), and K₂CO₃ (23.88 g, 172.8 mmol), about 10 ml of toluene was added, followed by heating for about 24 hours while keeping the outer temperature of about 215° C. The reaction solution was diluted with CH₂Cl₂, water was added thereto, celite filtration was performed, layer separation was performed, and an organic layer was concentrated. Purification was performed by silica gel column chromatography to obtain Intermediate 57-(4) (17.05 g, yield 84%). In FAB-MS measurement, the molecular weight of Intermediate 57-(4) was 940.

### (Synthesis of Intermediate 57-(5))

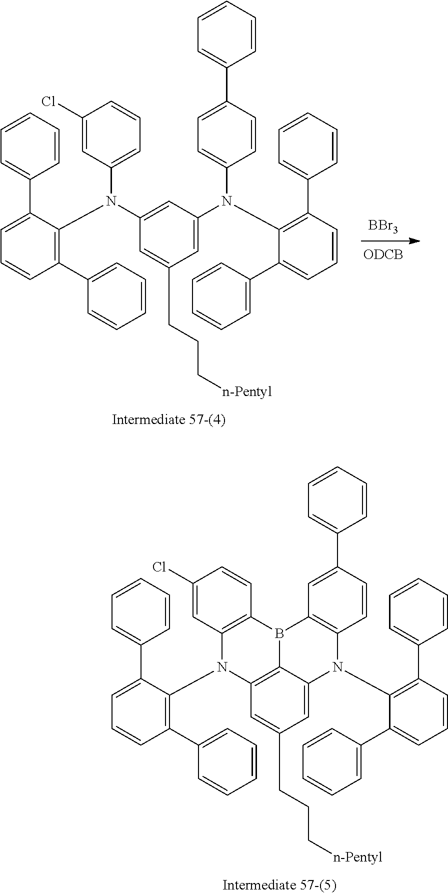

Under an Ar gas atmosphere, Intermediate 57-(4) (15.04 g, 16.01 mmol) was dissolved in ODCB (160 ml), and BBr₃ (8.02 g, 32.01 mmol) was added thereto, followed by heating and stirring at about 170° C. for about 10 hours. The reaction solution was cooled to room temperature, DIPEA (24.78 g, 192.07 mmol) was added thereto, water was added thereto, celite filtration was performed, layer separation was performed, and an organic layer was concentrated. Purification was performed by silica gel column chromatography to obtain Intermediate 57-(5) (5.76 g, yield 38%). In FAB-MS measurement, the molecular weight of Intermediate 57-(4) was 947.

### (Synthesis of Compound 57)

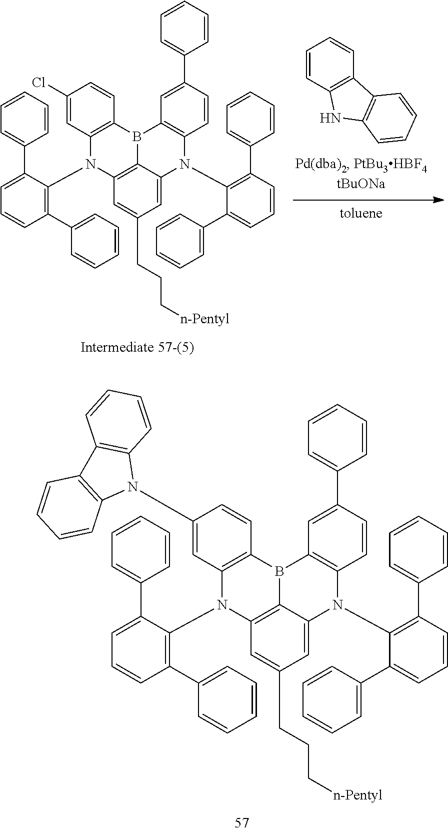

Under an Ar gas atmosphere, Intermediate 57-(5) (5.6 g, 5.91 mmol), 9H-carbazole (1.98 g, 11.82 mmol), Pd(dba)₂ (0.34 g, 0.59 mmol), (tBu)₃PHBF₄ (0.34 g, 1.18 mmol), and tBuONa (1.31 g, 13.59 mmol) were added to 29 ml of toluene, followed by heating and stirring at about 100° C. for about 8 hours. Water was added thereto, celite filtration was performed, layer separation was performed, and an organic layer was concentrated. Purification was performed by silica gel column chromatography to obtain Compound 57 (5.93 g, yield 93%). In FAB-MS measurement, the molecular weight of Compound 57 was 1078. Compound 57 was purified by sublimation (330° C., 2.7×10⁻³ Pa) during the manufacture of a light emitting element, which will be explained later, and device evaluation was conducted.

### (3) Synthesis of Compound 82

### (Synthesis of Intermediate 82-(1))

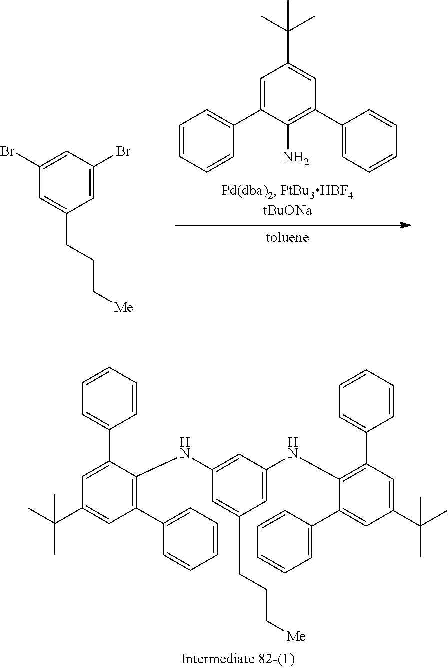 [SMILES: CCCCc1cc(Br)cc(Br)c1 ; CC(C)(C)c1cc(-c2ccccc2)c(N)c(-c2ccccc2)c1 ; CCCCc1cc(Nc2c(-c3ccccc3)cc(C(C)(C)C)cc2-c2ccccc2)cc(Nc2c(-c3ccccc3)cc(C(C)(C)C)cc2-c2ccccc2)c1]

Under an Ar gas atmosphere, 1,3-dibromo-5-butylbenzene (15.02 g, 24.11 mmol), 5′-(tert-butyl)-[1,1′:3′,1″-terphenyl]-2′-amine (18.17 g, 60.27 mmol), Pd(dba)₂ (1.39 g, 2.41 mmol), (tBu)₃PHBF₄ (1.4 g, 4.82 mmol), and tBuONa (5.33 g, 55.44 mmol) were added to 120 ml of toluene, followed by heating and stirring at about 100° C. for about 8 hours. Water was added thereto, celite filtration was performed, layer separation was performed, and an organic layer was concentrated. Purification was performed by silica gel column chromatography to obtain Intermediate 82-(1) (15.02 g, yield 85%). In FAB-MS measurement, the molecular weight of Intermediate 82-(1) was 733.

### (Synthesis of Intermediate 82-(2))

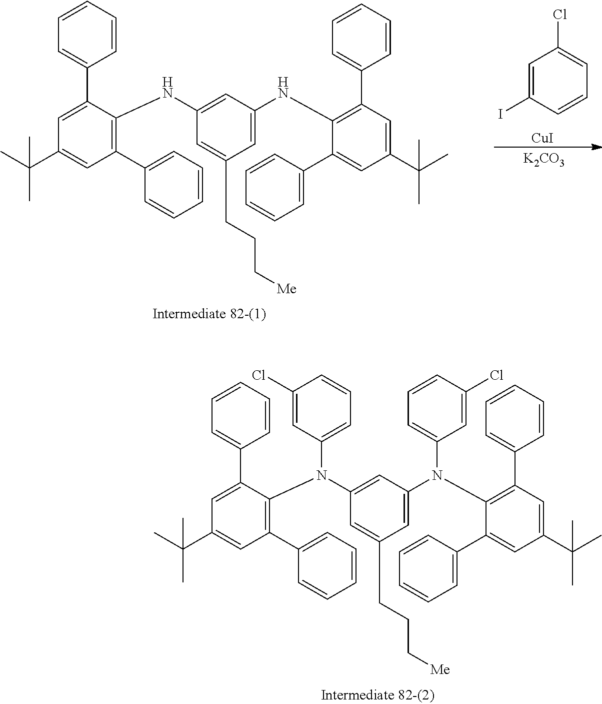

To Intermediate 82-(1) (16.54 g, 22.56 mmol), 1-chloro-3-iodobenzene (80.7 g, 338.44 mmol), CuI (9.02 g, 47.38 mmol), and K₂CO₃ (24.95 g, 180.5 mmol), about 10 ml of toluene was added, followed by heating for about 24 hours while keeping the outer temperature of about 215° C. The reaction solution was diluted with CH₂Cl₂, water was added thereto, celite filtration was performed, layer separation was performed, and an organic layer was concentrated. Purification was performed by silica gel column chromatography to obtain Intermediate 82-(2) (18.94 g, yield 88%). In FAB-MS measurement, the molecular weight of Intermediate 82-(2) was 954.

### (Synthesis of Intermediate 82-(3))

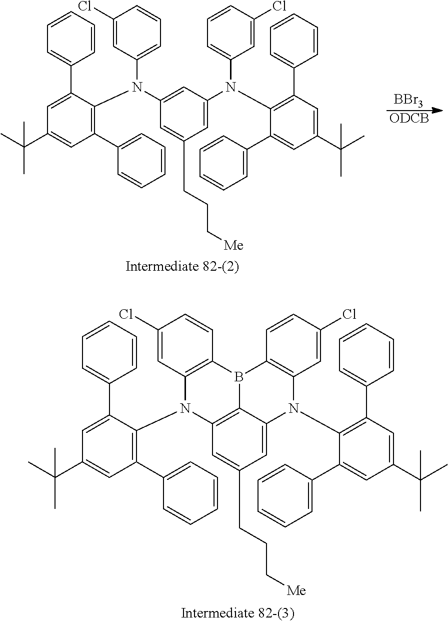

Under an Ar gas atmosphere, Intermediate 82-(2) (18.02 g, 18.89 mmol) was dissolved in ODCB (189 ml), and BBr₃ (9.46 g, 37.77 mmol) was added thereto, followed by heating and stirring at about 170° C. for about 10 hours. The reaction solution was cooled to room temperature, DIPEA (29.24 g, 226.63 mmol) was added thereto, water was added thereto, celite filtration was performed, layer separation was performed, and an organic layer was concentrated. Purification was performed by silica gel column chromatography to obtain Intermediate 82-(3) (5.81 g, yield 32%). In FAB-MS measurement, the molecular weight of Intermediate 83-(3) was 962.

### (Synthesis of Compound 82)

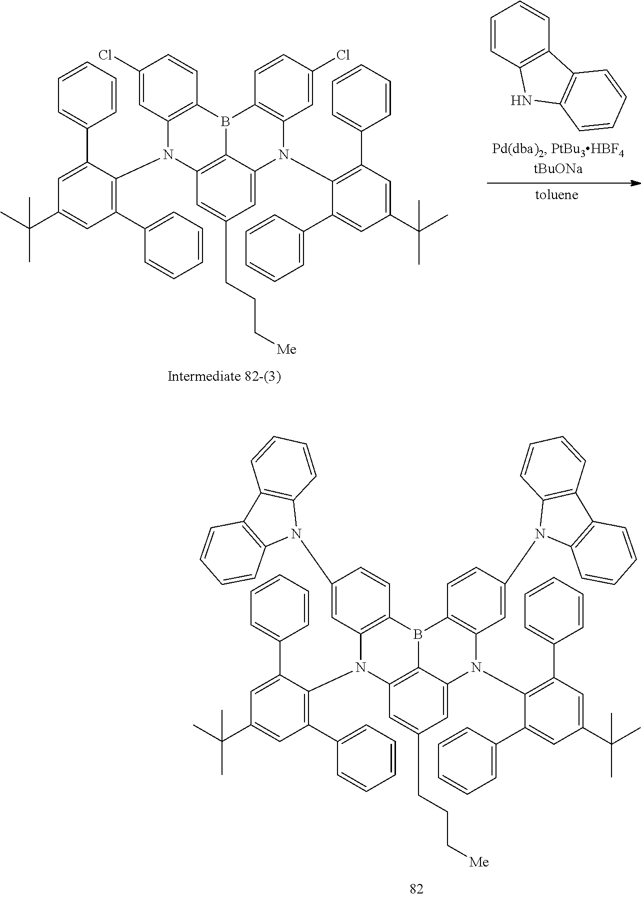

Under an Ar gas atmosphere, Intermediate 82-(3) (5.6 g, 5.82 mmol), 9H-carbazole (2.43 g, 14.55 mmol), Pd(dba)₂ (0.33 g, 0.58 mmol), (tBu)₃PHBF₄ (0.34 g, 1.16 mmol), and tBuONa (1.29 g, 13.39 mmol) were added to 29 ml of toluene, followed by heating and stirring at about 100° C. for about 8 hours. Water was added thereto, celite filtration was performed, layer separation was performed, and an organic layer was concentrated. Purification was performed by silica gel column chromatography to obtain Compound 82 (6.48 g, yield 91%). In FAB-MS measurement, the molecular weight of Compound 82 was 1223. Compound 82 was purified by sublimation (340° C., 3.2×10⁻³ Pa) during the manufacture of a light emitting element, which will be explained later, and device evaluation was conducted.

### (4) Synthesis of Compound 92

### (Synthesis of Intermediate 92-(1))

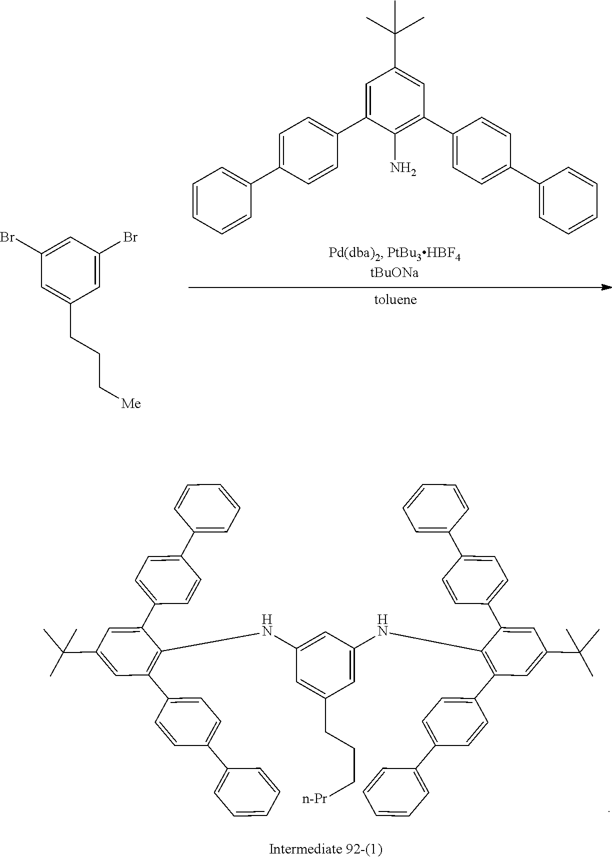

Under an Ar gas atmosphere, 1,3-dibromo-5-hexylbenzene (10.06 g, 31.43 mmol), 5″-(tert-butyl)-[1,1′:4′,1″:3″,1″:4″,1″-quinquephenyl]-2″-amine (35.64 g, 78.58 mmol), Pd(dba)₂ (1.81 g, 3.14 mmol), (tBu)₃PHBF₄ (1.82 g, 6.29 mmol), and tBuONa (6.95 g, 72.29 mmol) were added to 157 ml of toluene, followed by heating and stirring at about 100° C. for about 8 hours. Water was added thereto, celite filtration was performed, layer separation was performed, and an organic layer was concentrated. Purification was performed by silica gel column chromatography to obtain Intermediate 92-(1) (25.45 g, yield 76%). In FAB-MS measurement, the molecular weight of Intermediate 92-(1) was 1066.

### (Synthesis of Intermediate 92-(2))

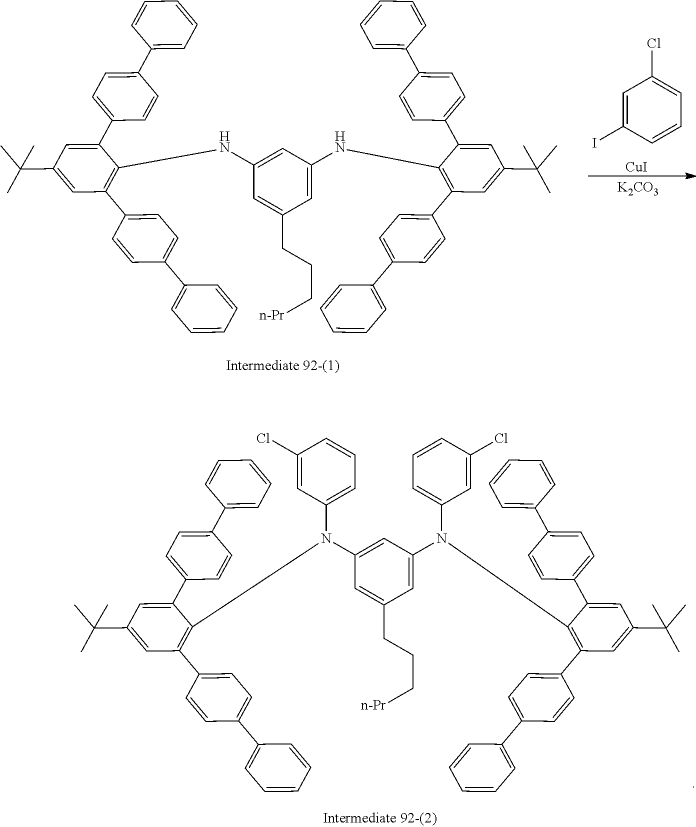

To Intermediate 92-(1) (20 g, 18.77 mmol), 1-chloro-3-iodobenzene (67.14 g, 281.56 mmol), CuI (7.51 g, 39.42 mmol), and K₂CO₃ (20.75 g, 150.16 mmol), about 10 ml of toluene was added, followed by heating for about 24 hours while keeping the outer temperature of about 215° C. The reaction solution was diluted with CH₂Cl₂, water was added thereto, celite filtration was performed, layer separation was performed, and an organic layer was concentrated. Purification was performed by silica gel column chromatography to obtain Intermediate 92-(2) (15.7 g, yield 65%). In FAB-MS measurement, the molecular weight of Intermediate 92-(2) was 1287.

### (Synthesis of Intermediate 92-(3))

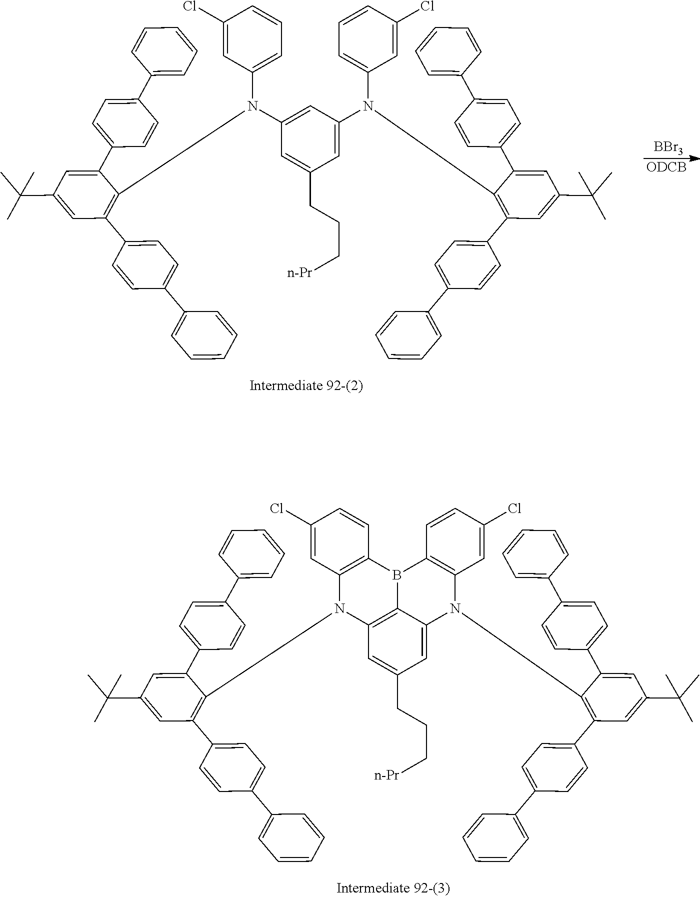

Under an Ar gas atmosphere, Intermediate 92-(2) (12.05 g, 9.37 mmol) was dissolved in ODCB (94 ml), and BBr₃ (4.69 g, 18.73 mmol) was added thereto, followed by heating and stirring at about 170° C. for about 10 hours. The reaction solution was cooled to room temperature, DIPEA (14.5 g, 112.39 mmol) was added thereto, water was added thereto, celite filtration was performed, layer separation was performed, and an organic layer was concentrated. Purification was performed by silica gel column chromatography to obtain Intermediate 92-(3) (3.03 g, yield 25%). In FAB-MS measurement, the molecular weight of Intermediate 92-(3) was 1294.

### (Synthesis of Compound 92)

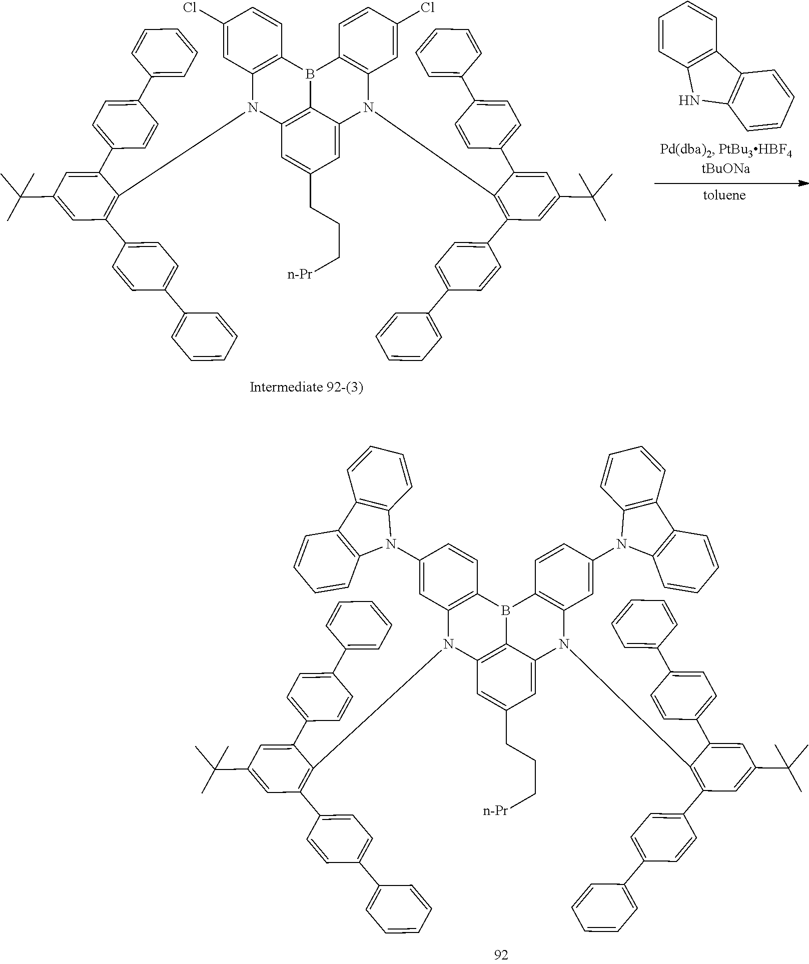

Under an Ar gas atmosphere, Intermediate 92-(3) (2.56 g, 1.98 mmol), 9H-carbazole (0.83 g, 4.94 mmol), Pd(dba)₂ (0.11 g, 0.2 mmol), (tBu)₃PHBF₄ (0.11 g, 0.4 mmol), and tBuONa (0.44 g, 4.55 mmol) were added to 9 ml of toluene, followed by heating and stirring at about 100° C. for about 8 hours. Water was added thereto, celite filtration was performed, layer separation was performed, and an organic layer was concentrated. Purification was performed by silica gel column chromatography to obtain Compound 92 (2.49 g, yield 81%). In FAB-MS measurement, the molecular weight of Compound 92 was 1556. Compound 92 was purified by sublimation (330° C., 2.5×10⁻³ Pa) during the manufacture of a light emitting element, which will be explained later, and device evaluation was conducted.

### (5) Synthesis of Compound 211

### (Synthesis of Intermediate 211-(1))

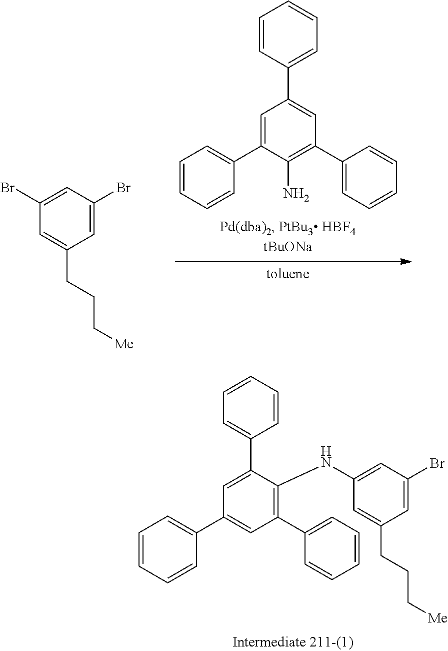 [SMILES: CCCCc1cc(Br)cc(Br)c1 ; Nc1c(-c2ccccc2)cc(-c2ccccc2)cc1-c1ccccc1 ; CCCCc1cc(Br)cc(Nc2c(-c3ccccc3)cc(-c3ccccc3)cc2-c2ccccc2)c1]

Under an Ar gas atmosphere, 1,3-dibromo-5-butylbenzene (15.05 g, 51.54 mmol), 5′-phenyl-[1,1′:3′,1″-terphenyl]-2′-amine (17.39 g, 54.12 mmol), Pd(dba)₂ (2.96 g, 5.15 mmol), (tBu)₃PHBF₄ (2.99 g, 10.31 mmol), and tBuONa (11.39 g, 118.54 mmol) were added to 257 ml of toluene, followed by heating and stirring at about 100° C. for about 8 hours. Water was added thereto, celite filtration was performed, layer separation was performed, and an organic layer was concentrated. Purification was performed by silica gel column chromatography to obtain Intermediate 211-(1) (20.04 g, yield 73%). In FAB-MS measurement, the molecular weight of Intermediate 211-(1) was 533.

### (Synthesis of Intermediate 211-(2))

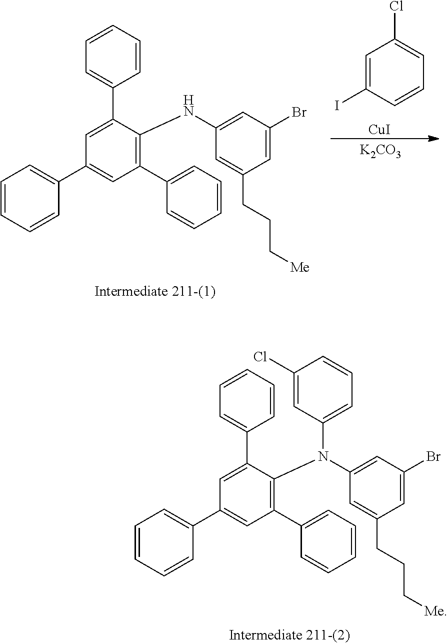

To Intermediate 211-(1) (19.54 g, 36.69 mmol), 1-chloro-3-iodobenzene (131.24 g, 550.39 mmol), CuI (14.68 g, 77.05 mmol), and K₂CO₃ (40.57 g, 293.54 mmol), about 10 ml of toluene was added, followed by heating for about 24 hours while keeping the outer temperature of about 215° C. The reaction solution was diluted with CH₂Cl₂, water was added thereto, celite filtration was performed, layer separation was performed, and an organic layer was concentrated. Purification was performed by silica gel column chromatography to obtain Intermediate 211-(2) (19.82 g, yield 84%). In FAB-MS measurement, the molecular weight of Intermediate 211-(2) was 643.

### (Synthesis of Intermediate 211-(3))

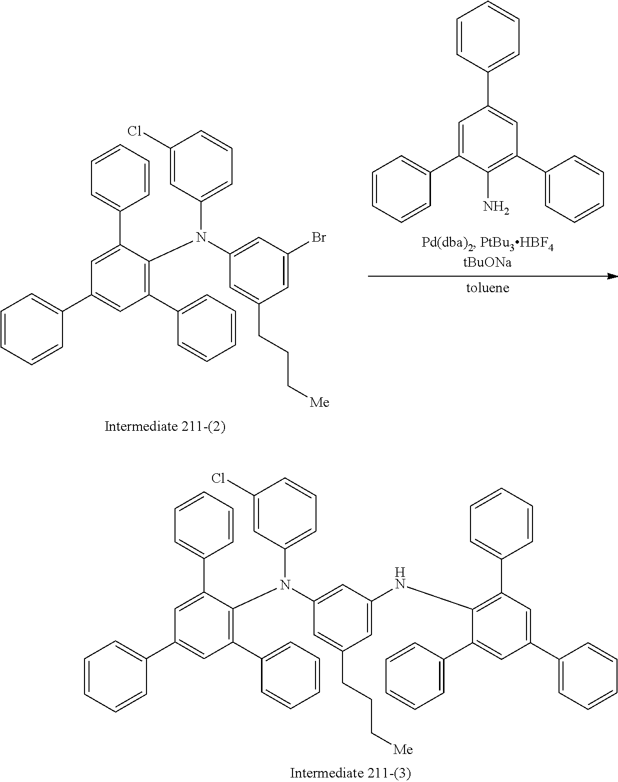 [SMILES: CCCCc1cc(Br)cc(N(c2cccc(Cl)c2)c2c(-c3ccccc3)cc(-c3ccccc3)cc2-c2ccccc2)c1 ; Nc1c(-c2ccccc2)cc(-c2ccccc2)cc1-c1ccccc1 ; CCCCc1cc(Nc2c(-c3ccccc3)cc(-c3ccccc3)cc2-c2ccccc2)cc(N(c2cccc(Cl)c2)c2c(-c3ccccc3)cc(-c3ccccc3)cc2-c2ccccc2)c1]

Under an Ar gas atmosphere, Intermediate 211-(2) (19.32 g, 30.04 mmol), 5′-phenyl-[1,1′:3′,1″-terphenyl]-2′-amine (10.14 g, 31.55 mmol), Pd(dba)₂ (1.73 g, 3 mmol), (tBu)₃PHBF₄ (1.74 g, 6.01 mmol), and tBuONa (6.64 g, 69.1 mmol) were added to 150 ml of toluene, followed by heating and stirring at about 100° C. for about 8 hours. Water was added thereto, celite filtration was performed, layer separation was performed, and an organic layer was concentrated. Purification was performed by silica gel column chromatography to obtain Intermediate 211-(3) (23.36 g, yield 88%). In FAB-MS measurement, the molecular weight of Intermediate 211-(3) was 884.

### (Synthesis of Intermediate 211-(4))

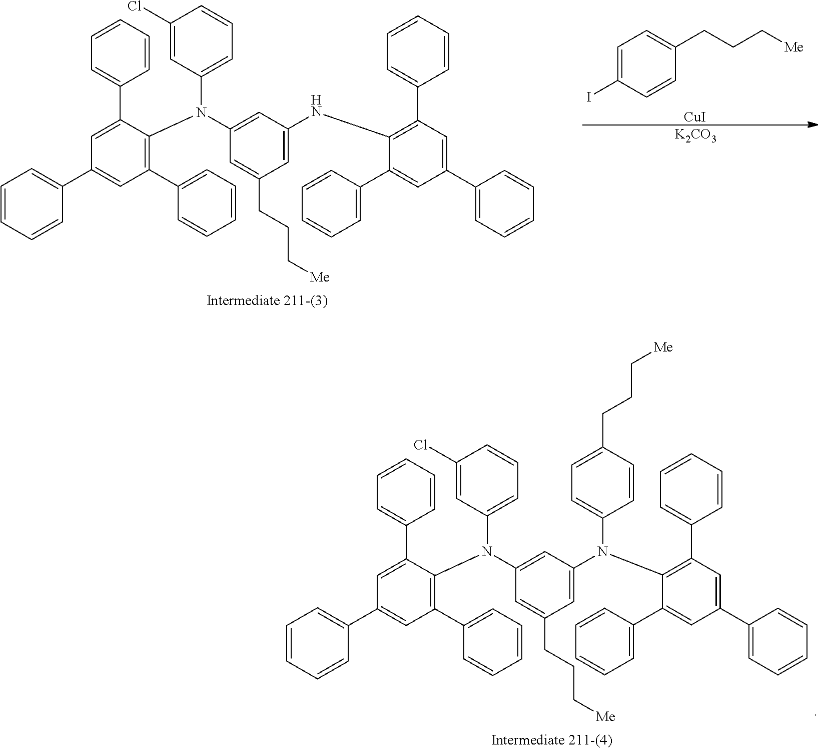

To Intermediate 211-(3) (22.22 g, 25.15 mmol), 1-butyl-4-iodobenzene (98.12 g, 377.22 mmol), CuI (10.06 g, 52.81 mmol), and K₂CO₃ (27.81 g, 201.18 mmol), about 10 ml of toluene was added, followed by heating for about 24 hours while keeping the outer temperature of about 215° C. The reaction solution was diluted with CH₂Cl₂, water was added thereto, celite filtration was performed, layer separation was performed, and an organic layer was concentrated. Purification was performed by silica gel column chromatography to obtain Intermediate 211-(4) (22.22 g, yield 87%). In FAB-MS measurement, the molecular weight of Intermediate 211-(4) was 1016.

### (Synthesis of Intermediate 211-(5))

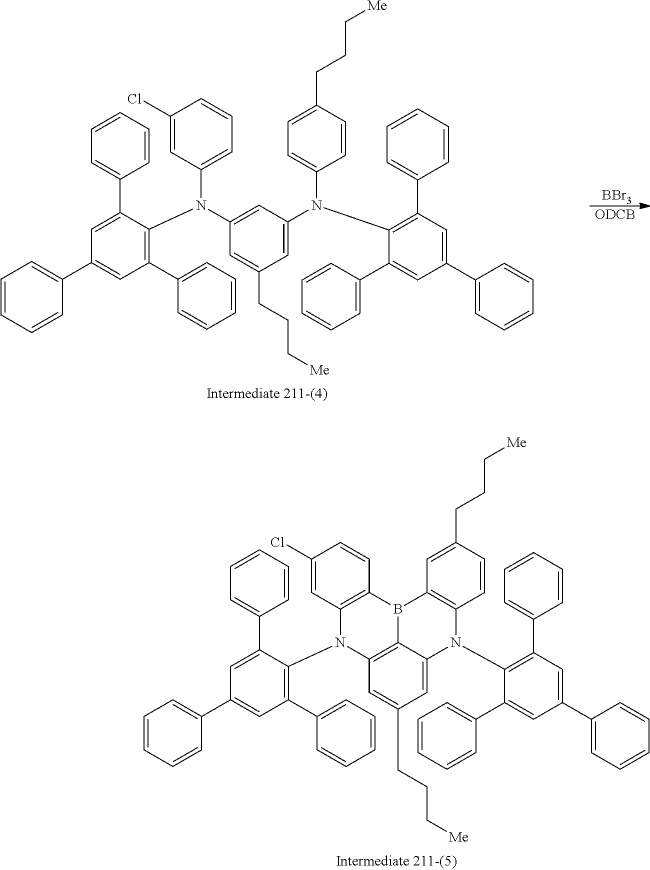 [SMILES: CCCCc1ccc(N(c2cc(CCCC)cc(N(c3cccc(Cl)c3)c3c(-c4ccccc4)cc(-c4ccccc4)cc3-c3ccccc3)c2)c2c(-c3ccccc3)cc(-c3ccccc3)cc2-c2ccccc2)cc1 ; "ODCB" ; "BBr3" ; CCCCc1ccc2c(c1)B1c3ccc(Cl)cc3N(c3c(-c4ccccc4)cc(-c4ccccc4)cc3-c3ccccc3)c3cc(CCCC)cc(c31)N2c1c(-c2ccccc2)cc(-c2ccccc2)cc1-c1ccccc1]

Under an Ar gas atmosphere, Intermediate 211-(4) (11.01 g, 10.84 mmol) was dissolved in ODCB (108 ml), and BBr₃ (5.43 g, 21.68 mmol) was added thereto, followed by heating and stirring at about 170° C. for about 10 hours. The reaction solution was cooled to room temperature, DIPEA (16.78 g, 130.07 mmol) was added thereto, water was added thereto, celite filtration was performed, layer separation was performed, and an organic layer was concentrated. Purification was performed by silica gel column chromatography to obtain Intermediate 211-(5) (5.21 g, yield 47%). In FAB-MS measurement, the molecular weight of Intermediate 211-(5) was 1024.

### (Synthesis of Compound 211)

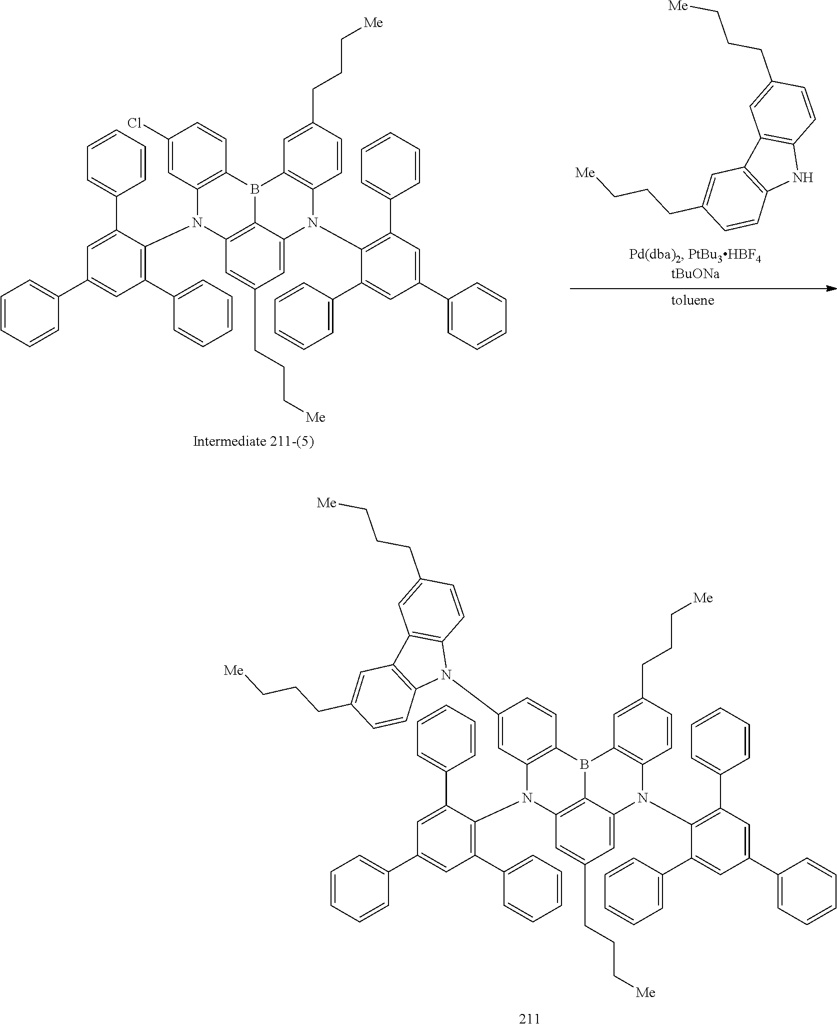 [SMILES: CCCCc1ccc2c(c1)B1c3ccc(Cl)cc3N(c3c(-c4ccccc4)cc(-c4ccccc4)cc3-c3ccccc3)c3cc(CCCC)cc(c31)N2c1c(-c2ccccc2)cc(-c2ccccc2)cc1-c1ccccc1 ; CCCCc1ccc2[nH]c3ccc(CCCC)cc3c2c1 ; CCCCc1ccc2c(c1)B1c3ccc(-n4c5ccc(CCCC)cc5c5cc(CCCC)ccc54)cc3N(c3c(-c4ccccc4)cc(-c4ccccc4)cc3-c3ccccc3)c3cc(CCCC)cc(c31)N2c1c(-c2ccccc2)cc(-c2ccccc2)cc1-c1ccccc1]

Under an Ar gas atmosphere, Intermediate 211-(5) (4.98 g, 4.87 mmol), 3,6-dibutyl-9H-carbazole (1.43 g, 5.11 mmol), Pd(dba)₂ (0.28 g, 0.49 mmol), (tBu)₃PHBF₄ (0.28 g, 0.97 mmol), and tBuONa (1.08 g, 11.19 mmol) were added to 24 ml of toluene, followed by heating and stirring at about 100° C. for about 8 hours. Water was added thereto, celite filtration was performed, layer separation was performed, and an organic layer was concentrated. Purification was performed by silica gel column chromatography to obtain Compound 211 (4.74 g, yield 77%). In FAB-MS measurement, the molecular weight of Compound 211 was 1267. Compound 211 was purified by sublimation (330° C., 2.3×10⁻³ Pa) during the manufacture of a light emitting element, which will be explained later, and device evaluation was conducted.

### (6) Synthesis of Compound 252

### (Synthesis of Intermediate 252-(1))

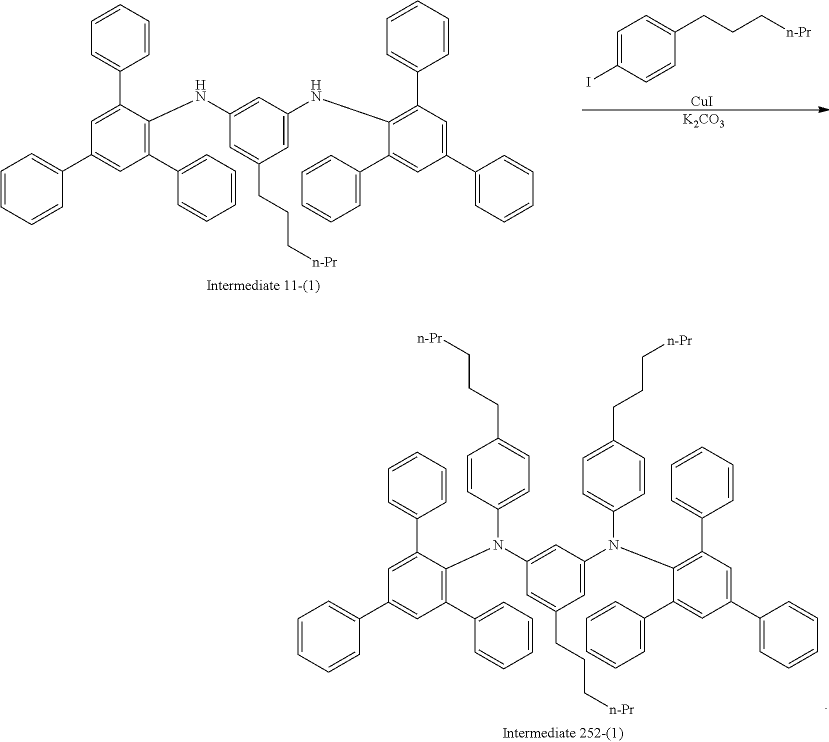

To Intermediate 11-(1) (10.22 g, 12.76 mmol), 1-hexyl-4-iodobenzene (55.15 g, 191.36 mmol), CuI (5.1 g, 26.79 mmol), and K₂CO₃ (14.11 g, 102.06 mmol), about 10 ml of toluene was added, followed by heating for about 24 hours while keeping the outer temperature of about 215° C. The reaction solution was diluted with CH₂Cl₂, water was added thereto, celite filtration was performed, layer separation was performed, and an organic layer was concentrated. Purification was performed by silica gel column chromatography to obtain Intermediate 252-(1) (11.24 g, yield 78%). In FAB-MS measurement, the molecular weight of Intermediate 252-(1) was 1129.

### (Synthesis of Compound 252)

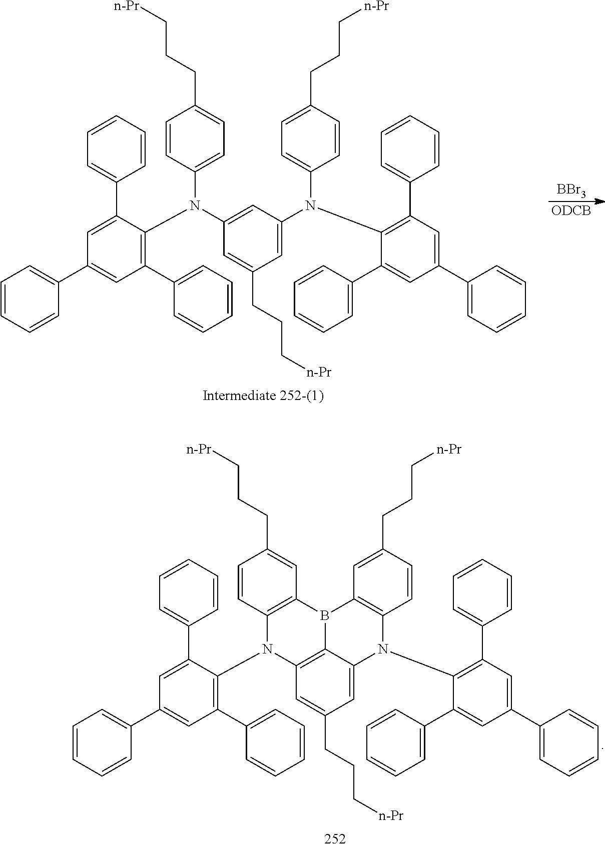

Under an Ar gas atmosphere, Intermediate 252-(1) (11.04 g, 9.84 mmol) was dissolved in ODCB (98 ml), and BBr₃ (4.93 g, 19.69 mmol) was added thereto, followed by heating and stirring at about 170° C. for about 10 hours. The reaction solution was cooled to room temperature, DIPEA (15.24 g, 118.12 mmol) was added thereto, water was added thereto, celite filtration was performed, layer separation was performed, and an organic layer was concentrated. Purification was performed by silica gel column chromatography to obtain Compound 252 (3.34 g, yield 30%). In FAB-MS measurement, the molecular weight of Compound 252 was 1129. Compound 252 was purified by sublimation (300° C., 2.2×10⁻³ Pa) during the manufacture of a light emitting element, which will be explained later, and device evaluation was conducted.

### (7) Synthesis of Compound 282

### (Synthesis of Intermediate 282-(1))

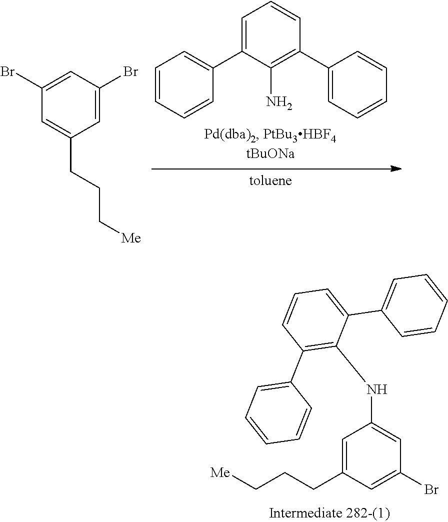

Under an Ar gas atmosphere, 1,3-dibromo-5-butylbenzene (15.44 g, 52.87 mmol), [1,1′:3′, 1″-terphenyl]-2′-amine (13.62 g, 55.52 mmol), Pd(dba)₂ (3.04 g, 5.29 mmol), (tBu)₃PHBF₄(3.07 g, 10.57 mmol), and tBuONa (11.69 g, 121.61 mmol) were added to 264 ml of toluene, followed by heating and stirring at about 100° C. for about 8 hours. Water was added thereto, celite filtration was performed, layer separation was performed, and an organic layer was concentrated. Purification was performed by silica gel column chromatography to obtain Intermediate 282-(1) (17.38 g, yield 72%). In FAB-MS measurement, the molecular weight of Intermediate 282-(1) was 456.

### (Synthesis of Intermediate 282-(2))

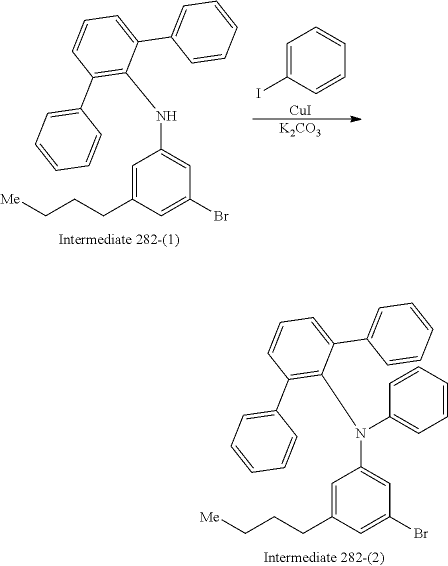

To Intermediate 282-(1) (17.02 g, 37.29 mmol), iodobenzene (114.11 g, 559.34 mmol), CuI (14.91 g, 78.31 mmol), and K₂CO₃ (41.23 g, 298.32 mmol), about 10 ml of toluene was added, followed by heating for about 24 hours while keeping the outer temperature of about 215° C. The reaction solution was diluted with CH₂Cl₂, water was added thereto, celite filtration was performed, layer separation was performed, and an organic layer was concentrated. Purification was performed by silica gel column chromatography to obtain Intermediate 282-(2) (18.07 g, yield 91%). In FAB-MS measurement, the molecular weight of Intermediate 282-(2) was 533.

### (Synthesis of Intermediate 282-(3))

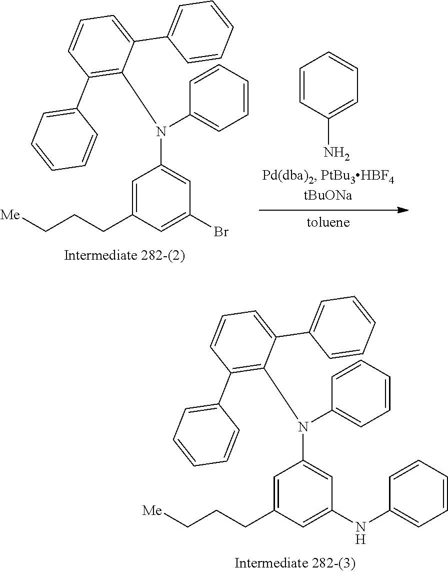 [SMILES: CCCCc1cc(Br)cc(N(c2ccccc2)c2c(-c3ccccc3)cccc2-c2ccccc2)c1 ; Nc1ccccc1 ; CCCCc1cc(Nc2ccccc2)cc(N(c2ccccc2)c2c(-c3ccccc3)cccc2-c2ccccc2)c1]

Under an Ar gas atmosphere, Intermediate 282-(2) (17.78 g, 33.39 mmol), aniline (3.26 g, 35.06 mmol), Pd(dba)₂ (1.92 g, 3.34 mmol), (tBu)₃PHBF₄ (1.94 g, 6.68 mmol), and tBuONa (7.38 g, 76.79 mmol) were added to 166 ml of toluene, followed by heating and stirring at about 100° C. for about 8 hours. Water was added thereto, celite filtration was performed, layer separation was performed, and an organic layer was concentrated. Purification was performed by silica gel column chromatography to obtain Intermediate 282-(3) (12.37 g, yield 68%). In FAB-MS measurement, the molecular weight of Intermediate 282-(3) was 545.

### (Synthesis of Intermediate 282-(4))

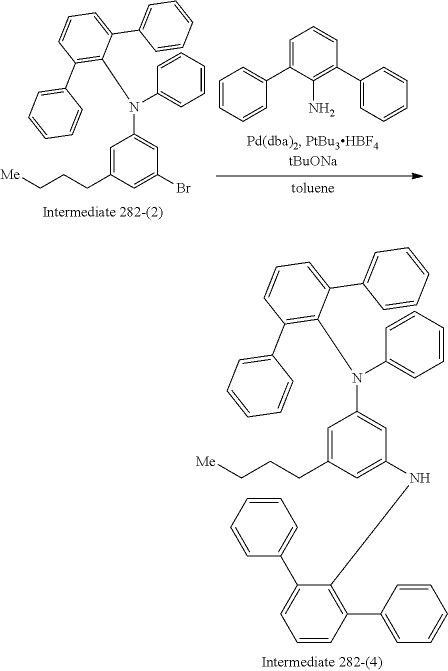

Under an Ar atmosphere, Intermediate 282-(2) (17.55 g, 32.96 mmol), [1,1′:3′,1″-terphenyl]-2′-amine (8.49 g, 34.6 mmol), Pd(dba)₂ (1.9 g, 3.3 mmol), (tBu)₃PHBF₄ (1.91 g, 6.59 mmol), and tBuONa (7.28 g, 75.8 mmol) were added to 164 ml of toluene, followed by heating and stirring at about 100° C. for about 8 hours. Water was added thereto, celite filtration was performed, layer separation was performed, and an organic layer was concentrated. Purification was performed by silica gel column chromatography to obtain Intermediate 282-(4) (19.98 g, yield 87%). In FAB-MS measurement, the molecular weight of Intermediate 282-(4) was 697.

### (Synthesis of Intermediate 282-(5))

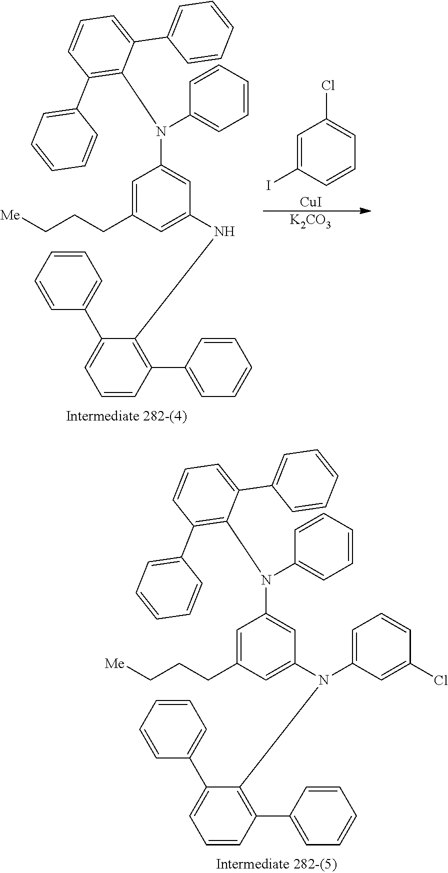

To Intermediate 282-(4) (19.55 g, 28.05 mmol), 1-chloro-3-iodobenzene (100.33 g, 420.77 mmol), CuI (11.22 g, 58.91 mmol), and K₂CO₃ (31.02 g, 224.41 mmol), about 10 ml of toluene was added, followed by heating for about 24 hours while keeping the outer temperature of about 215° C. The reaction solution was diluted with CH₂Cl₂, water was added thereto, celite filtration was performed, layer separation was performed, and an organic layer was concentrated. Purification was performed by silica gel column chromatography to obtain Intermediate 282-(5) (18.8 g, yield 83%). In FAB-MS measurement, the molecular weight of Intermediate 282-(5) was 807.

### (Synthesis of Intermediate 282-(6))

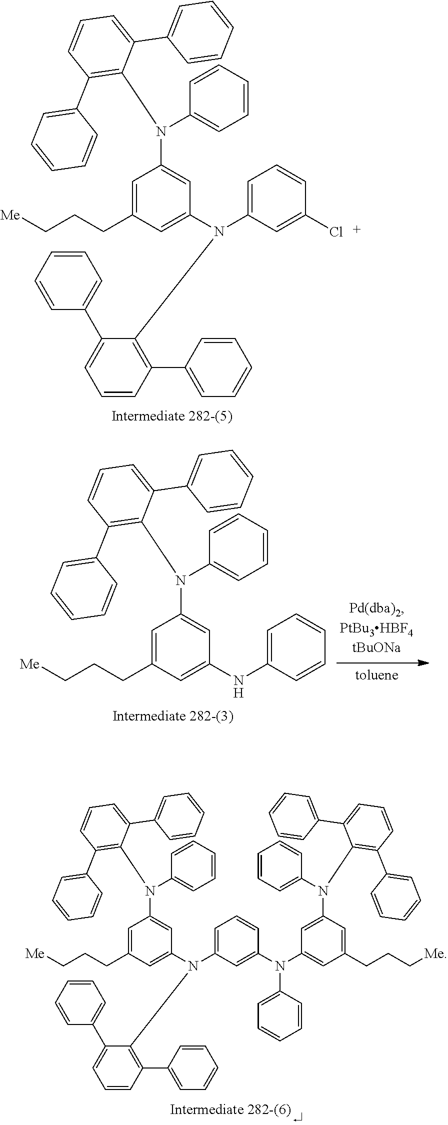 [SMILES: CCCCc1cc(N(c2ccccc2)c2c(-c3ccccc3)cccc2-c2ccccc2)cc(N(c2cccc(Cl)c2)c2c(-c3ccccc3)cccc2-c2ccccc2)c1 ; CCCCc1cc(Nc2ccccc2)cc(N(c2ccccc2)c2c(-c3ccccc3)cccc2-c2ccccc2)c1 ; CCCCc1cc(N(c2ccccc2)c2cccc(N(c3cc(CCCC)cc(N(c4ccccc4)c4c(-c5ccccc5)cccc4-c4ccccc4)c3)c3c(-c4ccccc4)cccc3-c3ccccc3)c2)cc(N(c2ccccc2)c2c(-c3ccccc3)cccc2-c2ccccc2)c1]

Under an Ar atmosphere, Intermediate 282-(5) (17.55 g, 21.73 mmol), Intermediate 282-(3) (11.84 g, 21.73 mmol), Pd(dba)₂ (1.25 g, 2.17 mmol), (tBu)₃PHBF₄ (1.26 g, 4.35 mmol), and tBuONa (4.8 g, 49.99 mmol) were added to 108 ml of toluene, followed by heating and stirring at about 100° C. for about 8 hours. Water was added thereto, celite filtration was performed, layer separation was performed, and an organic layer was concentrated. Purification was performed by silica gel column chromatography to obtain Intermediate 282-(6) (22.88 g, yield 80%). In FAB-MS measurement, the molecular weight of Intermediate 282-(6) was 1316.

### (Synthesis of Compound 282)

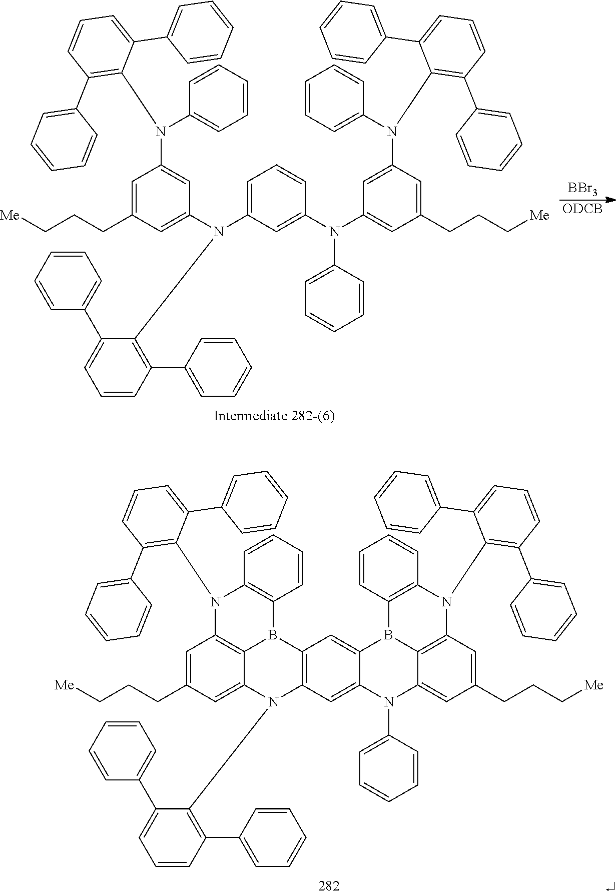

Under an Ar gas atmosphere, Intermediate 282-(6) (22.11 g, 19.71 mmol) was dissolved in ODCB (197 ml), and BBr₃ (19.75 g, 78.85 mmol) was added thereto, followed by heating and stirring at about 170° C. for about 10 hours. The reaction solution was cooled to room temperature, DIPEA (30.52 g, 236.55 mmol) was added thereto, water was added thereto, celite filtration was performed, layer separation was performed, and an organic layer was concentrated. Purification was performed by silica gel column chromatography to obtain Compound 282 (5.57 g, yield 25%). In FAB-MS measurement, the molecular weight of Compound 282 was 1129. Compound 282 was purified by sublimation (370° C., 2.3×10⁻³ Pa) during the manufacture of a light emitting element, which will be explained later, and device evaluation was conducted.

### (8) Synthesis of Compound 347

### (Synthesis of Intermediate 347-(1))

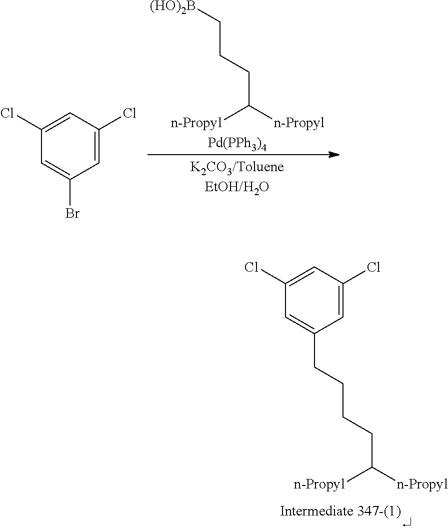

Under an Ar gas atmosphere, to 1-bromo-3,5-dichlorobenzene (10.04 g, 44.45 mmol), (4-pentylnonyl)boronic acid (43.06 g, 177.79 mmol), K₃PO₄ (18.87 g, 88.89 mmol), and Pd(Ph₃P)₄ (5.14 g, 4.44 mmol), 80.32 ml of toluene and 40.16 ml of a mixture of EtOH and water in a ratio of 1: 1 were added, followed by heating for about 24 hours while keeping the outer temperature of about 80° C. Celite filtration was performed, layer separation was performed, and an organic layer was concentrated. Purification was performed by silica gel column chromatography to obtain Intermediate 347-(1) (13.03 g, yield 89%). In FAB-MS measurement, the molecular weight of Intermediate 347-(1) was 329.

### (Synthesis of Intermediate 347-(2))

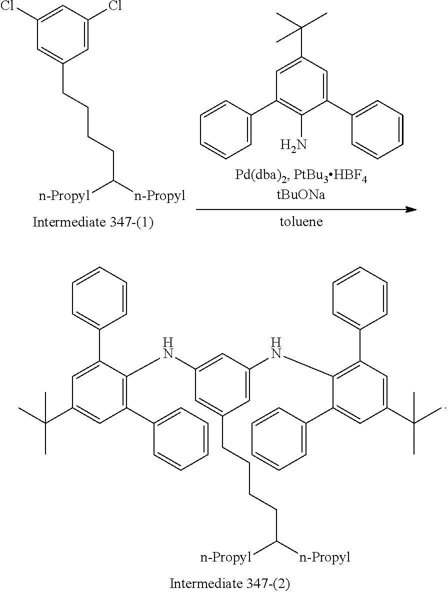

Under an Ar gas atmosphere, Intermediate 347-(1) (12.68 g, 38.5 mmol), 5′-(tert-butyl)-[1,1′:3′,1″-terphenyl]-2′-amine (24.37 g, 80.85 mmol), Pd(dba)₂ (2.21 g, 3.85 mmol), (tBu)₃PHBF₄ (2.23 g, 7.7 mmol), and tBuONa (8.51 g, 88.55 mmol) were added to 192 ml of toluene, followed by heating and stirring at about 100° C. for about 8 hours. Water was added thereto, celite filtration was performed, layer separation was performed, and an organic layer was concentrated. Purification was performed by silica gel column chromatography to obtain Intermediate 347-(2) (29.11 g, yield 88%). In FAB-MS measurement, the molecular weight of Intermediate 347-(2) was 859.

### (Synthesis of Intermediate 347-(3))

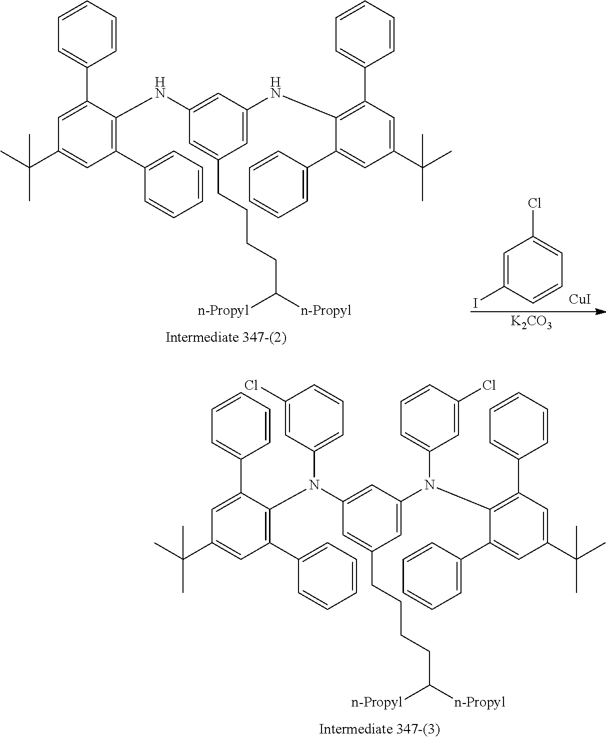

To Intermediate 347-(2) (14.52 g, 16.9 mmol), 1-chloro-3-iodobenzene (60.44 g, 253.46 mmol), CuI (6.76 g, 35.48 mmol), and K₂CO₃ (18.68 g, 135.18 mmol), about 10 ml of toluene was added, followed by heating for about 24 hours while keeping the outer temperature of about 215° C. The reaction solution was diluted with CH₂Cl₂, water was added, celite filtration was performed, layer separation was performed, and an organic layer was concentrated. Purification was performed by silica gel column chromatography to obtain Intermediate 347-(3) (15.33 g, yield 84%). In FAB-MS measurement, the molecular weight of Intermediate 347-(3) was 1080.

### (Synthesis of Intermediate 347-(4))

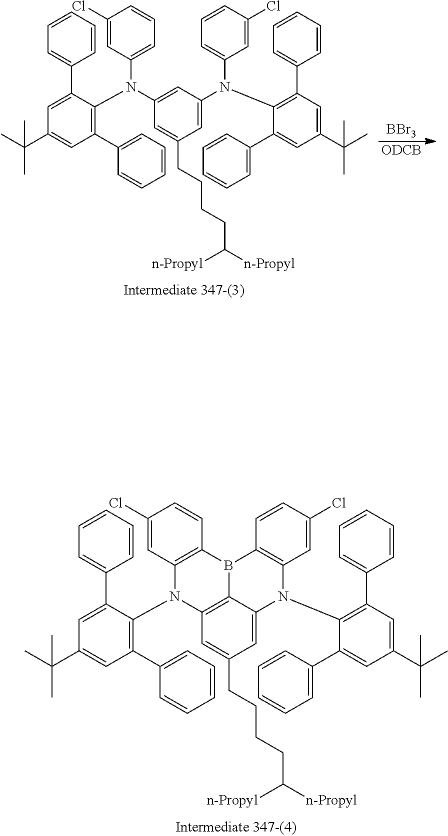

Under an Ar gas atmosphere, Intermediate 347-(3) (15.11 g, 13.99 mmol) was dissolved in ODCB (140 ml), and BBr₃ (14.01 g, 55.94 mmol) was added thereto, followed by heating and stirring at about 170° C. for about 10 hours. The reaction solution was cooled to room temperature, DIPEA (21.65 g, 167.83 mmol) was added thereto, water was added thereto, celite filtration was performed, layer separation was performed, and an organic layer was concentrated. Purification was performed by silica gel column chromatography to obtain Intermediate 347-(4) (6.24 g, yield 41%). In FAB-MS measurement, the molecular weight of Intermediate 347-(4) was 1088.

### (Synthesis of Compound 347)

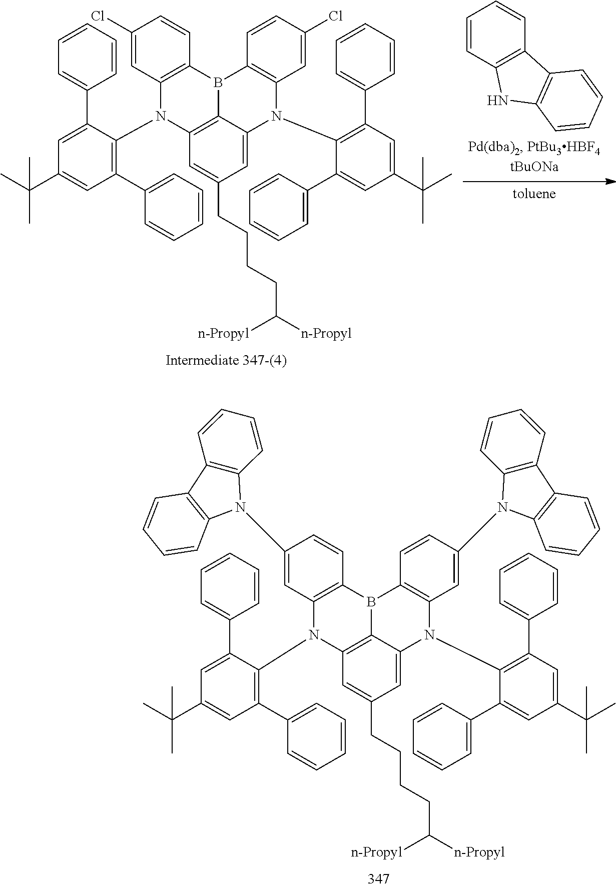

Under an Ar gas atmosphere, Intermediate 347-(4) (5.98 g, 5.5 mmol), 9H-carbazole (1.93 g, 11.54 mmol), Pd(dba)₂ (0.32 g, 0.55 mmol), (tBu)₃PHBF₄ (0.32 g, 1.1 mmol), tBuONa (1.21 g, 12.64 mmol) were added to 27 ml of toluene, followed by heating and stirring at about 100° C. for about 8 hours. Water was added thereto, celite filtration was performed, layer separation was performed, and an organic layer was concentrated. Purification was performed by silica gel column chromatography to obtain Compound 347 (5.71 g, yield 77%). In FAB-MS measurement, the molecular weight of Compound 347 was 1350. Compound 347 was purified by sublimation (330° C., 2.4×10⁻³ Pa) during the manufacture of a light emitting element, which will be explained later, and device evaluation was conducted.

### (9) Synthesis of Compound 416

### (Synthesis of Intermediate 416-(1))

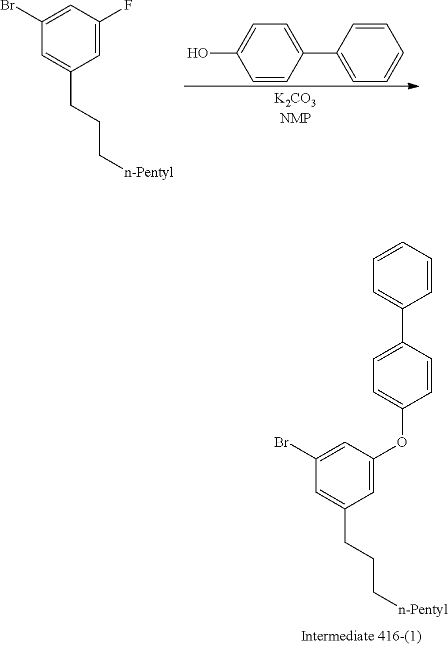

Under an Ar gas atmosphere, 1-bromo-3-fluoro-5-octylbenzene (15.04 g, 69.61 mmol), [1,1′-biphenyl]-4-ol (14.22 g, 83.53 mmol), and K₂CO₃ (43.29 g, 313.23 mmol) were added to 150 ml of NMP, followed by heating for about 24 hours while keeping the outer temperature of about 180° C. The reaction solution was diluted with CH₂Cl₂, water was added, celite filtration was performed, layer separation was performed, and an organic layer was concentrated. Purification was performed by silica gel column chromatography to obtain Intermediate 416-(1) (26.79 g, yield 88%). In FAB-MS measurement, the molecular weight of Intermediate 416-(1) was 437.

### (Synthesis of Intermediate 416-(2))

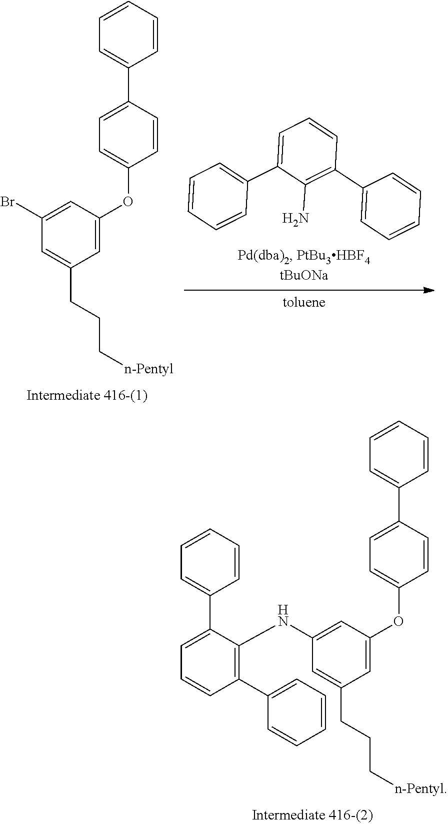

Under an Ar gas atmosphere, Intermediate 416-(1) (13.12 g, 29.99 mmol), [1,1′:3′,1″-terphenyl]-2′-amine (15.45 g, 62.99 mmol), Pd(dba)₂ (1.72 g, 3 mmol), (tBu)₃PHBF₄ (1.74 g, 6 mmol), and tBuONa (6.63 g, 68.99 mmol) were added to 149 ml of toluene, followed by heating and stirring at about 100° C. for about 8 hours. Water was added thereto, celite filtration was performed, layer separation was performed, and an organic layer was concentrated. Purification was performed by silica gel column chromatography to obtain Intermediate 416-(2) (16.43 g, yield 91%). In FAB-MS measurement, the molecular weight of Intermediate 416-(2) was 602.

### (Synthesis of Intermediate 416-(3))

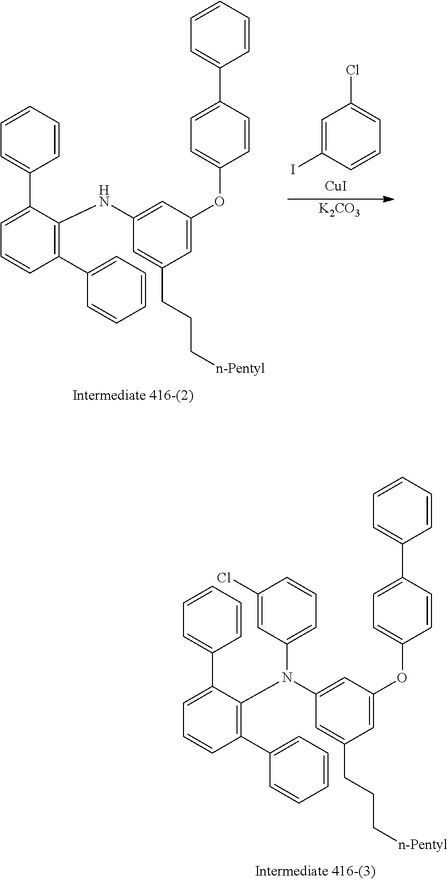

To Intermediate 416-(2) (15.59 g, 25.9 mmol), 1-chloro-3-iodobenzene (92.65 g, 388.56 mmol), CuI (10.36 g, 54.4 mmol), and K₂CO₃ (28.64 g, 207.23 mmol), about 10 ml of toluene was added, followed by heating for about 24 hours while keeping the outer temperature of about 215° C. The reaction solution was diluted with CH₂Cl₂, water was added, celite filtration was performed, layer separation was performed, and an organic layer was concentrated. Purification was performed by silica gel column chromatography to obtain Intermediate 416-(3) (14.95 g, yield 81%). In FAB-MS measurement, the molecular weight of Intermediate 416-(3) was 712.

### (Synthesis of Intermediate 416-(4))

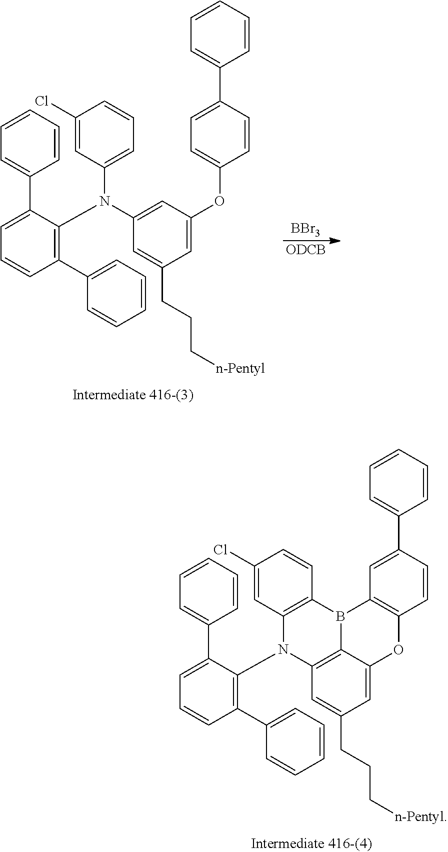

Under an Ar gas atmosphere, Intermediate 416-(3) (14.55 g, 20.42 mmol) was dissolved in ODCB (204 ml), and BBr₃ (20.47 g, 81.7 mmol) was added thereto, followed by heating and stirring at about 170° C. for about 10 hours. The reaction solution was cooled to room temperature, DIPEA (31.62 g, 245.1 mmol) was added thereto, water was added thereto, celite filtration was performed, layer separation was performed, and an organic layer was concentrated. Purification was performed by silica gel column chromatography to obtain Intermediate 416-(4) (7.06 g, yield 48%). In FAB-MS measurement, the molecular weight of Intermediate 416-(4) was 720.

### (Synthesis of Compound 416)

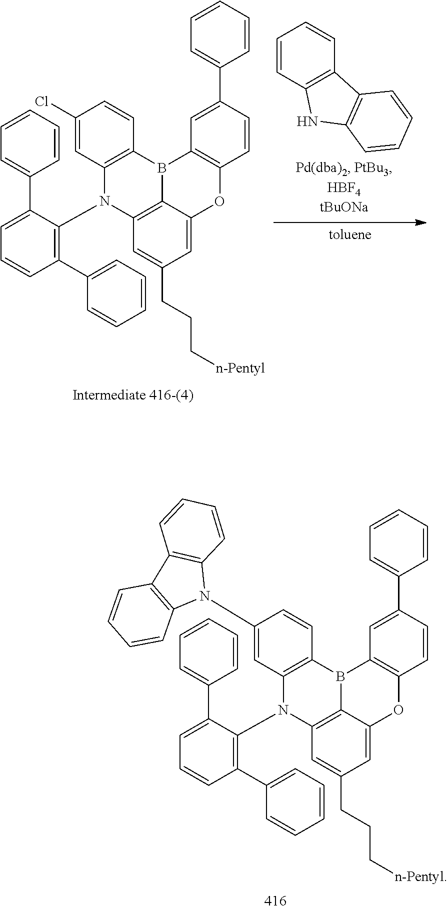

Under an Ar gas atmosphere, Intermediate 416-(4) (6.88 g, 9.55 mmol), 9H-carbazole (3.35 g, 20.06 mmol), Pd(dba)₂ (0.55 g, 0.96 mmol), (tBu)₃PHBF₄ (0.55 g, 1.91 mmol), and tBuONa (2.11 g, 21.97 mmol) were added to 47 ml of toluene, followed by heating and stirring at about 100° C. for about 8 hours. Water was added thereto, celite filtration was performed, layer separation was performed, and an organic layer was concentrated. Purification was performed by silica gel column chromatography to obtain Compound 416 (6.83 g, yield 84%). In FAB-MS measurement, the molecular weight of Compound 416 was 851. Compound 416 was purified by sublimation (310° C., 2.5×10⁻³ Pa) during the manufacture of a light emitting element, which will be explained later, and device evaluation was conducted.

### (10) Synthesis of Compound 611

### (Synthesis of Intermediate 611-(1))

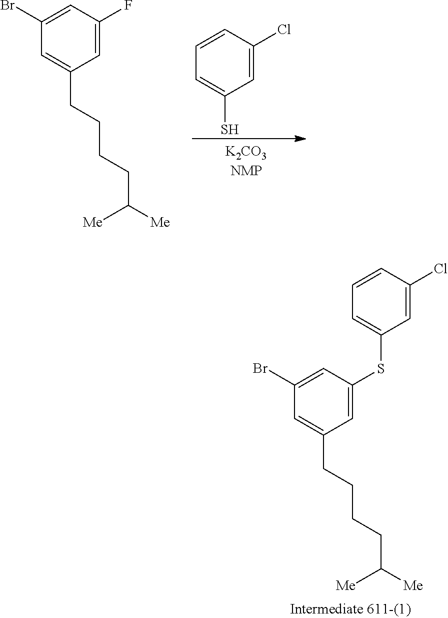 [SMILES: CC(C)CCCCc1cc(F)cc(Br)c1 ; Sc1cccc(Cl)c1 ; CC(C)CCCCc1cc(Br)cc(Sc2cccc(Cl)c2)c1]

Under an Ar gas atmosphere, 1-bromo-3-fluoro-5-(5-methylhexyl)benzene (15.33 g, 56.11 mmol), 3-chlorobenzenethiol (9.74 g, 67.34 mmol), and K₂CO₃ (34.9 g, 252.52 mmol) were added to 153 ml of NMP, followed by heating for about 24 hours while keeping the outer temperature of about 180° C. The reaction solution was diluted with CH₂Cl₂, water was added, celite filtration was performed, layer separation was performed, and an organic layer was concentrated. Purification was performed by silica gel column chromatography to obtain Intermediate 611-(1) (17.41 g, yield 78%). In FAB-MS measurement, the molecular weight of Intermediate 611-(1) was 398.

### (Synthesis of Intermediate 611-(2))

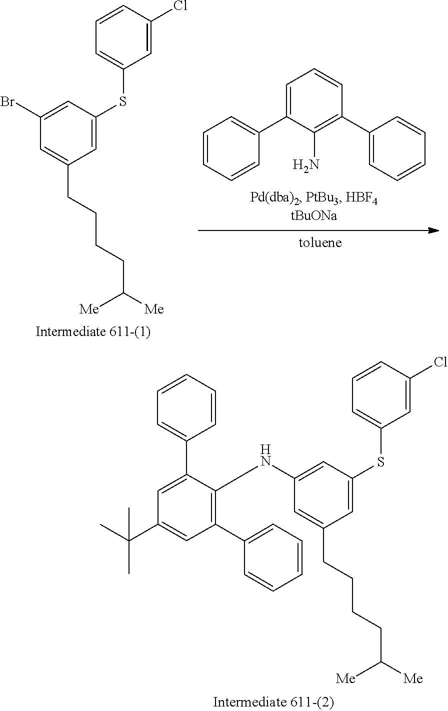 [SMILES: CC(C)CCCCc1cc(Br)cc(Sc2cccc(Cl)c2)c1 ; Nc1c(-c2ccccc2)cccc1-c1ccccc1 ; CC(C)CCCCc1cc(Nc2c(-c3ccccc3)cc(C(C)(C)C)cc2-c2ccccc2)cc(Sc2cccc(Cl)c2)c1]

Under an Ar gas atmosphere, Intermediate 611-(1) (17.22 g, 43.29 mmol), [1,1′:3′,1″-terphenyl]-2′-amine (26.55 g, 108.22 mmol), Pd(dba)₂ (2.49 g, 4.33 mmol), (tBu)₃PHBF₄ (2.51 g, 8.66 mmol), and tBuONa (9.57 g, 99.56 mmol) were added to 216 ml of toluene, followed by heating and stirring at about 100° C. for about 8 hours. Water was added thereto, celite filtration was performed, layer separation was performed, and an organic layer was concentrated. Purification was performed by silica gel column chromatography to obtain Intermediate 611-(2) (24.09 g, yield 90%). In FAB-MS measurement, the molecular weight of Intermediate 611-(2) was 618.

### (Synthesis of Intermediate 611-(3))

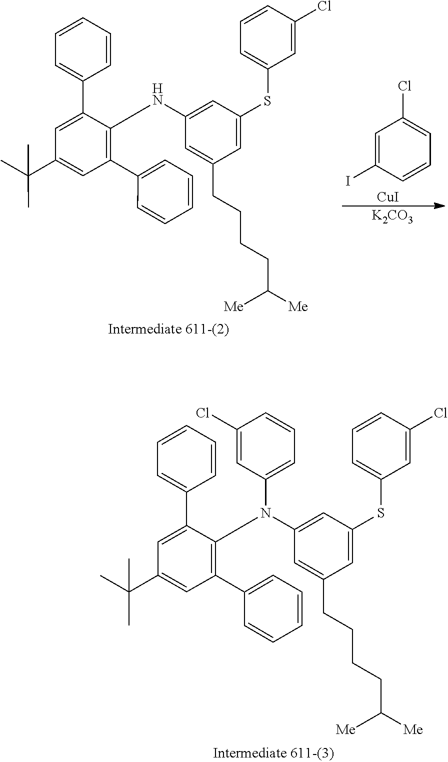

To Intermediate 611-(2) (11.55 g, 18.68 mmol), 1-chloro-3-iodobenzene (53.36 g, 280.19 mmol), CuI (7.47 g, 39.23 mmol), and K₂CO₃ (20.65 g, 149.44 mmol), about 10 ml of toluene was added, followed by heating for about 24 hours while keeping the outer temperature of about 215° C. The reaction solution was diluted with CH₂Cl₂, water was added, celite filtration was performed, layer separation was performed, and an organic layer was concentrated. Purification was performed by silica gel column chromatography to obtain Intermediate 611-(3) (11.3 g, yield 83%). In FAB-MS measurement, the molecular weight of Intermediate 611-(3) was 729.

### (Synthesis of Intermediate 611-(4))

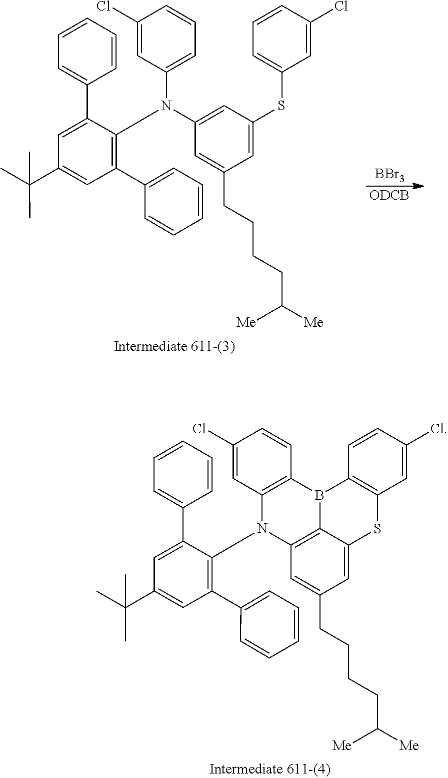 [SMILES: CC(C)CCCCc1cc(Sc2cccc(Cl)c2)cc(N(c2cccc(Cl)c2)c2c(-c3ccccc3)cc(C(C)(C)C)cc2-c2ccccc2)c1 ; "ODCB" ; "BBr3" ; CC(C)CCCCc1cc2c3c(c1)N(c1c(-c4ccccc4)cc(C(C)(C)C)cc1-c1ccccc1)c1cc(Cl)ccc1B3c1ccc(Cl)cc1S2]

Under an Ar atmosphere, Intermediate 611-(3) (11.01 g, 15.11 mmol) was dissolved in ODCB (151 ml), and BBr₃ (15.14 g, 60.42 mmol) was added thereto, followed by heating and stirring at about 170° C. for about 10 hours. The reaction solution was cooled to room temperature, DIPEA (23.38 g, 181.27 mmol) was added, water was added thereto, celite filtration was performed, layer separation was performed, and an organic layer was concentrated. Purification was performed by silica gel column chromatography to obtain Intermediate 611-(4) (3.89 g, yield 35%). In FAB-MS measurement, the molecular weight of Intermediate 611-(4) was 737.

### (Synthesis of Compound 611)

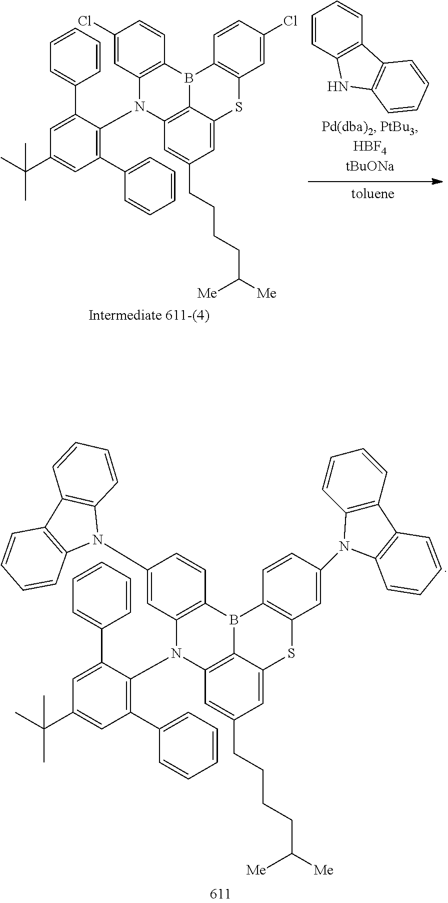

Under an Ar gas atmosphere, Intermediate 611-(4) (3.44 g, 4.67 mmol), 9H-carbazole (1.64 g, 9.81 mmol), Pd(dba)₂ (0.27 g, 0.47 mmol), (tBu)₃PHBF₄ (0.27 g, 0.93 mmol), and tBuONa (1.03 g, 10.74 mmol) were added to 23 ml of toluene, followed by heating and stirring at about 100° C. for about 8 hours. Water was added thereto, celite filtration was performed, layer separation was performed, and an organic layer was concentrated. Purification was performed by silica gel column chromatography to obtain Compound 611 (4.15 g, yield 89%). In FAB-MS measurement, the molecular weight of Compound 611 was 998. Compound 611 was purified by sublimation (310° C., 2.4×10⁻³ Pa) during the manufacture of a light emitting element, which will be explained later, and device evaluation was conducted.

### (11) Synthesis of Compound 618

### (Synthesis of Intermediate 618-(1))

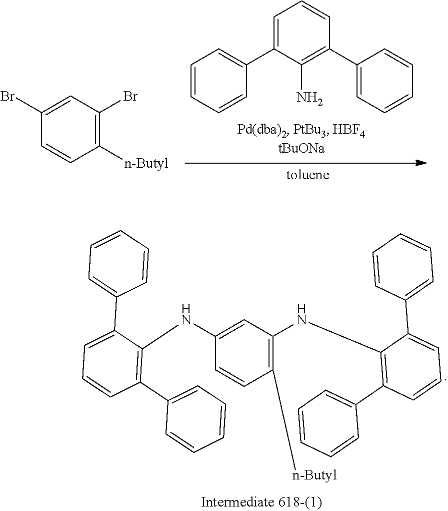

Under an Ar gas atmosphere, 2,4-dibromo-1-butylbenzene (12.01 g, 41.13 mmol), [1,1′:3′,1″-terphenyl]-2′-amine (25.23 g, 102.82 mmol), Pd(dba)₂ (2.36 g, 4.11 mmol), (tBu)₃PHBF₄ (2.39 g, 8.23 mmol), and tBuONa (11.86 g, 123.39 mmol) were added to 205 ml of toluene, followed by heating and stirring at about 100° C. for about 8 hours. Water was added thereto, celite filtration was performed, layer separation was performed, and an organic layer was concentrated. Purification was performed by silica gel column chromatography to obtain Intermediate 618-(1) (22.21 g, yield 87%). In FAB-MS measurement, the molecular weight of Intermediate 618-(1) was 621.

### (Synthesis of Intermediate 618-(2))

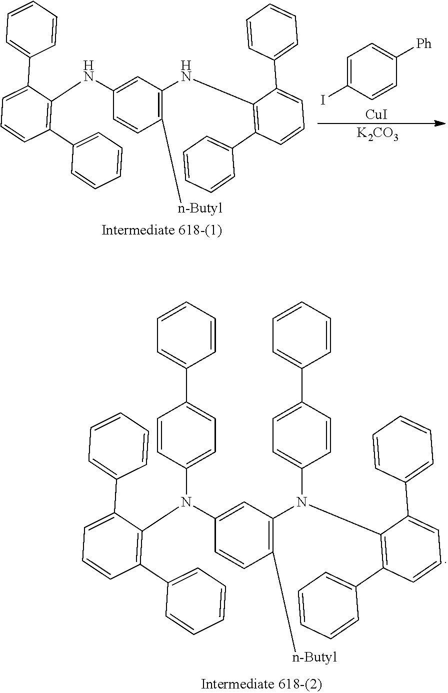

To Intermediate 618-(1) (11.11 g, 17.9 mmol), 4-iodo-1,1′-biphenyl (51.12 g, 268.43 mmol), CuI (7.16 g, 37.58 mmol), and K₂CO₃ (19.79 g, 143.16 mmol), about 10 ml of toluene was added, followed by heating for about 24 hours while keeping the outer temperature of about 215° C. The reaction solution was diluted with CH₂Cl₂, water was added, celite filtration was performed, layer separation was performed, and an organic layer was concentrated. Purification was performed by silica gel column chromatography to obtain Intermediate 618-(2) (12.42 g, yield 75%). In FAB-MS measurement, the molecular weight of Intermediate 618-(2) was 925.

### (Synthesis of Compound 618)

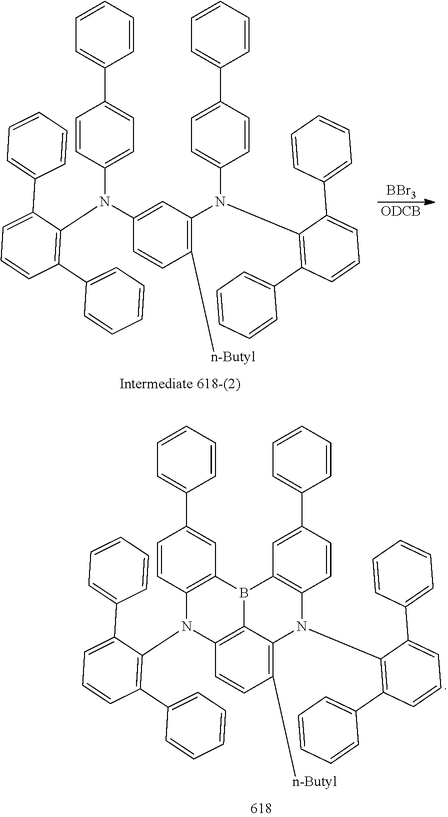

Under an Ar gas atmosphere, Intermediate 618-(2) (12.08 g, 13.06 mmol) was dissolved in ODCB (131 ml), and BBr₃ (13.08 g, 52.22 mmol) was added thereto, followed by heating and stirring at about 170° C. for about 10 hours. The reaction solution was cooled to room temperature, DIPEA (20.21 g, 156.67 mmol) was added thereto, water was added thereto, celite filtration was performed, layer separation was performed, and an organic layer was concentrated. Purification was performed by silica gel column chromatography to obtain Compound 618 (4.99 g, yield 41%). In FAB-MS measurement, the molecular weight of Compound 618 was 933.

Compound 618 was purified by sublimation (290° C., 2.2×10⁻³ Pa) during the manufacture of a light emitting element, which will be explained later, and device evaluation was conducted.

### (12) Synthesis of Compound 626

### (Synthesis of Intermediate 626-(1))

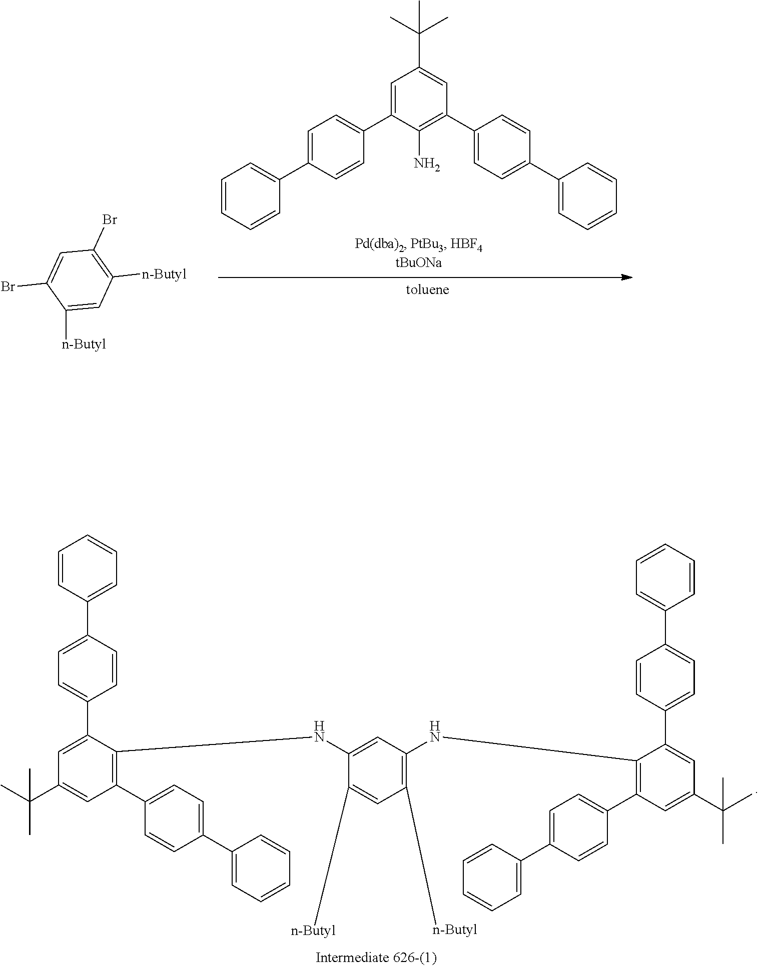

Under an Ar gas atmosphere, 1,5-dibromo-2,4-dipentylbenzene (10.02 g, 26.64 mmol), 5″-(tert-butyl)-[1,1′:4′,1″:3″,1″:4″, 1″-quinquephenyl]-2″-amine (30.21 g, 66.59 mmol), Pd(dba)₂ (1.53 g, 2.66 mmol), (tBu)₃PHBF₄ (1.55 g, 5.33 mmol), and tBuONa (7.68 g, 79.91 mmol) were added to 133 ml of toluene, followed by heating and stirring at about 100° C. for about 8 hours. Water was added thereto, celite filtration was performed, layer separation was performed, and an organic layer was concentrated. Purification was performed by silica gel column chromatography to obtain Intermediate 626-(1) (24.5 g, yield 82%). In FAB-MS measurement, the molecular weight of Intermediate 626-(1) was 1122.

### (Synthesis of Intermediate 626-(2))

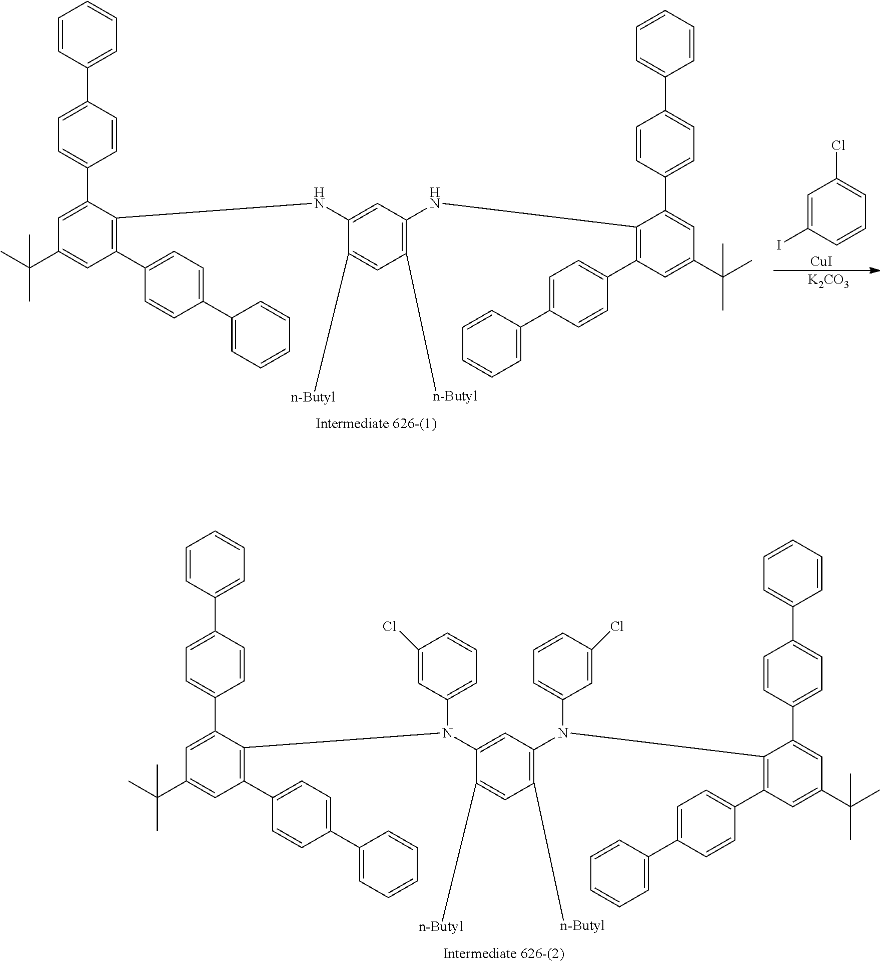

To Intermediate 626-(1) (12.14 g, 10.82 mmol), 1-chloro-3-iodobenzene (38.71 g, 162.36 mmol), CuI (4.33 g, 22.73 mmol), and K₂CO₃ (11.97 g, 86.59 mmol), about 10 ml of toluene was added, followed by heating for about 24 hours while keeping the outer temperature of about 215° C. The reaction solution was diluted with CH₂Cl₂, water was added, celite filtration was performed, layer separation was performed, and an organic layer was concentrated. Purification was performed by silica gel column chromatography to obtain Intermediate 626-(2) (10.46 g, yield 72%). In FAB-MS measurement, the molecular weight of Intermediate 626-(2) was 1343.

### (Synthesis of Intermediate 626-(3))

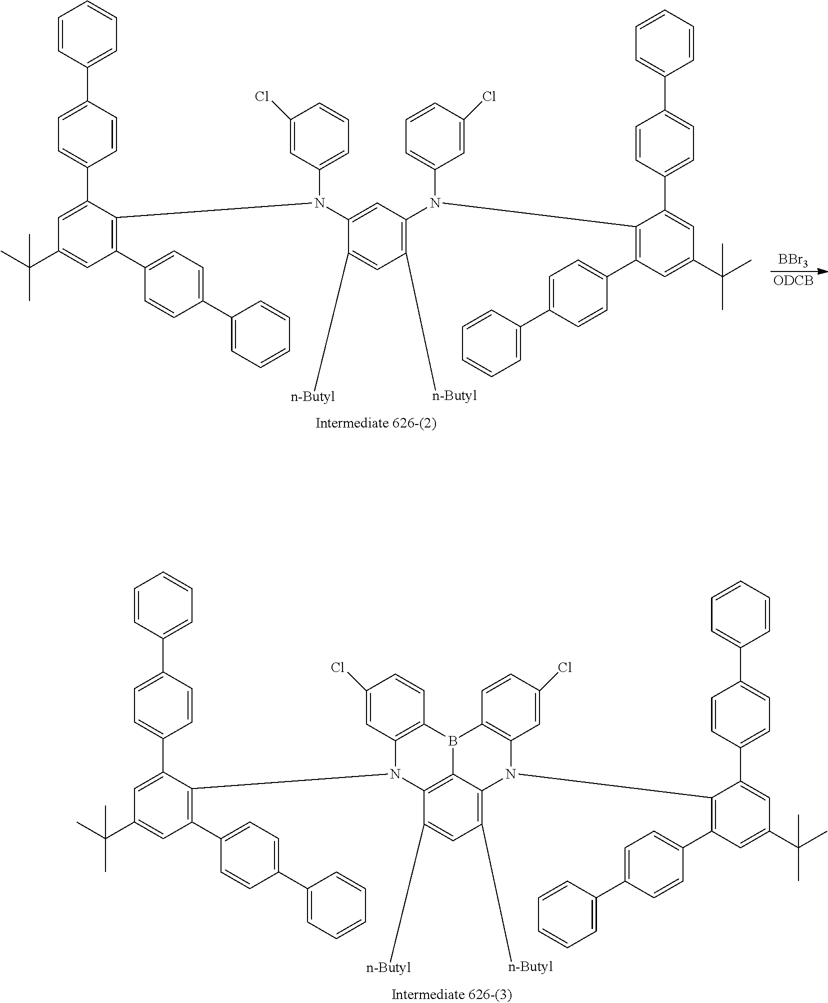

Under an Ar atmosphere, Intermediate 626-(2) (10.22 g, 7.61 mmol) was dissolved in ODCB (76 ml), and BBr₃ (7.63 g, 30.45 mmol) was added thereto, followed by heating and stirring at about 170° C. for about 10 hours. The reaction solution was cooled to room temperature, DIPEA (11.78 g, 91.34 mmol) was added thereto, water was added thereto, celite filtration was performed, layer separation was performed, and an organic layer was concentrated. Purification was performed by silica gel column chromatography to obtain Intermediate 626-(3) (3.7 g, yield 36%). In FAB-MS measurement, the molecular weight of Intermediate 626-(3) was 1350.

### (Synthesis of Compound 626)

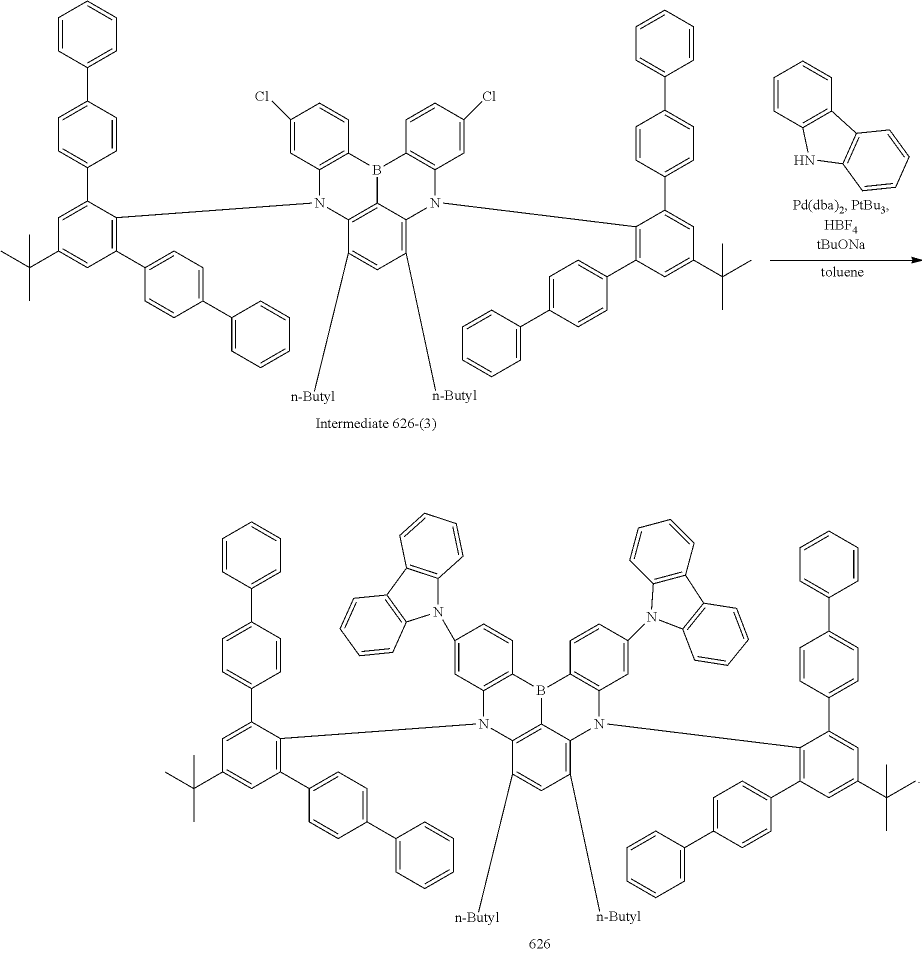

Under an Ar gas atmosphere, Intermediate 626-(3) (3.35 g, 2.48 mmol), 9H-carbazole (0.87 g, 5.21 mmol), Pd(dba)₂ (0.14 g, 0.25 mmol), (tBu)₃PHBF₄ (0.14 g, 0.5 mmol), and tBuONa (0.55 g, 5.71 mmol) were added to 12 ml of toluene, followed by heating and stirring at about 100° C. for about 8 hours. Water was added thereto, celite filtration was performed, layer separation was performed, and an organic layer was concentrated. Purification was performed by silica gel column chromatography to obtain Compound 626 (3.36 g, yield 84%). In FAB-MS measurement, the molecular weight of Compound 626 was 1612. Compound 626 was purified by sublimation (330° C., 2.6×10⁻³ Pa) during the manufacture of a light emitting element, which will be explained later, and device evaluation was conducted.

2. Manufacture and evaluation of light emitting element
(1) Manufacture of light emitting elements

The light emitting element according to an embodiment, including the fused polycyclic compound according to an embodiment in an emission layer, was manufactured by the method described below. Light emitting elements of Example 1 to Example 12 were manufactured using the fused polycyclic compounds of Example Compounds 11, 57, 82, 92, 211, 252, 282, 347, 416, 611, 618, and 626 as the dopant materials of an emission layer. Comparative Example 1 to Comparative Example 11 correspond to light emitting elements manufactured using Comparative Compound X₁ to Comparative Compound X₁₁ as the dopant materials of an emission layer.

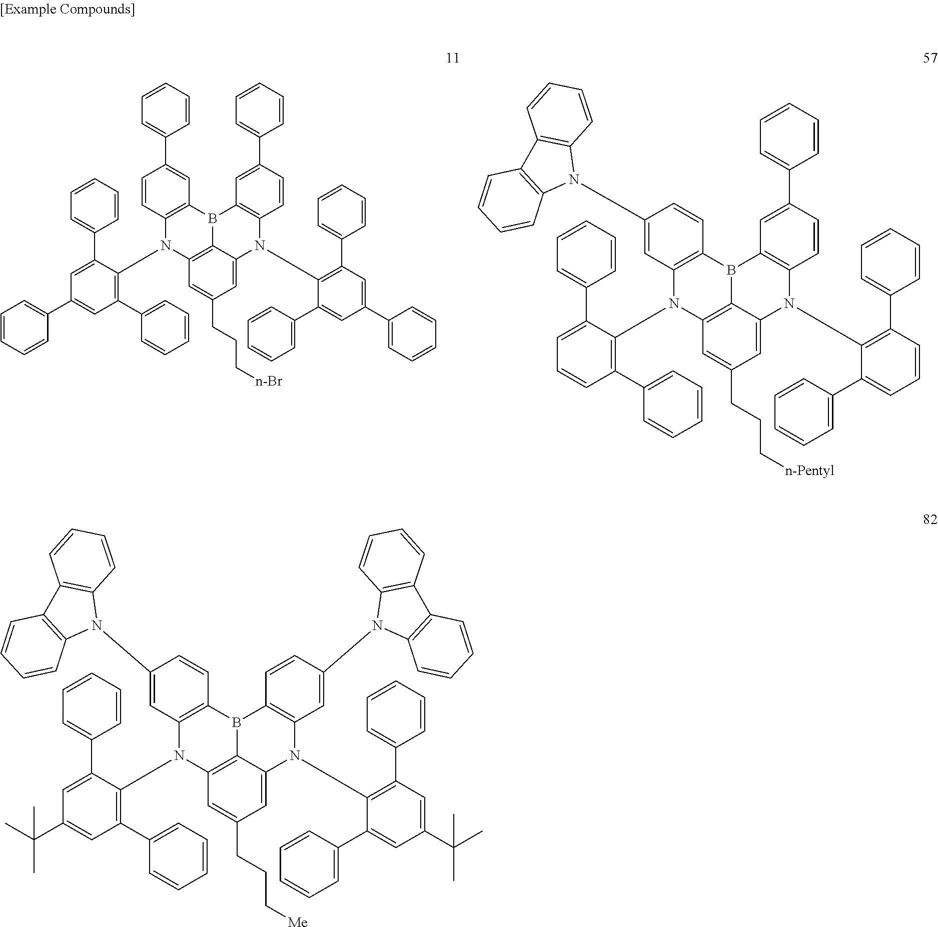

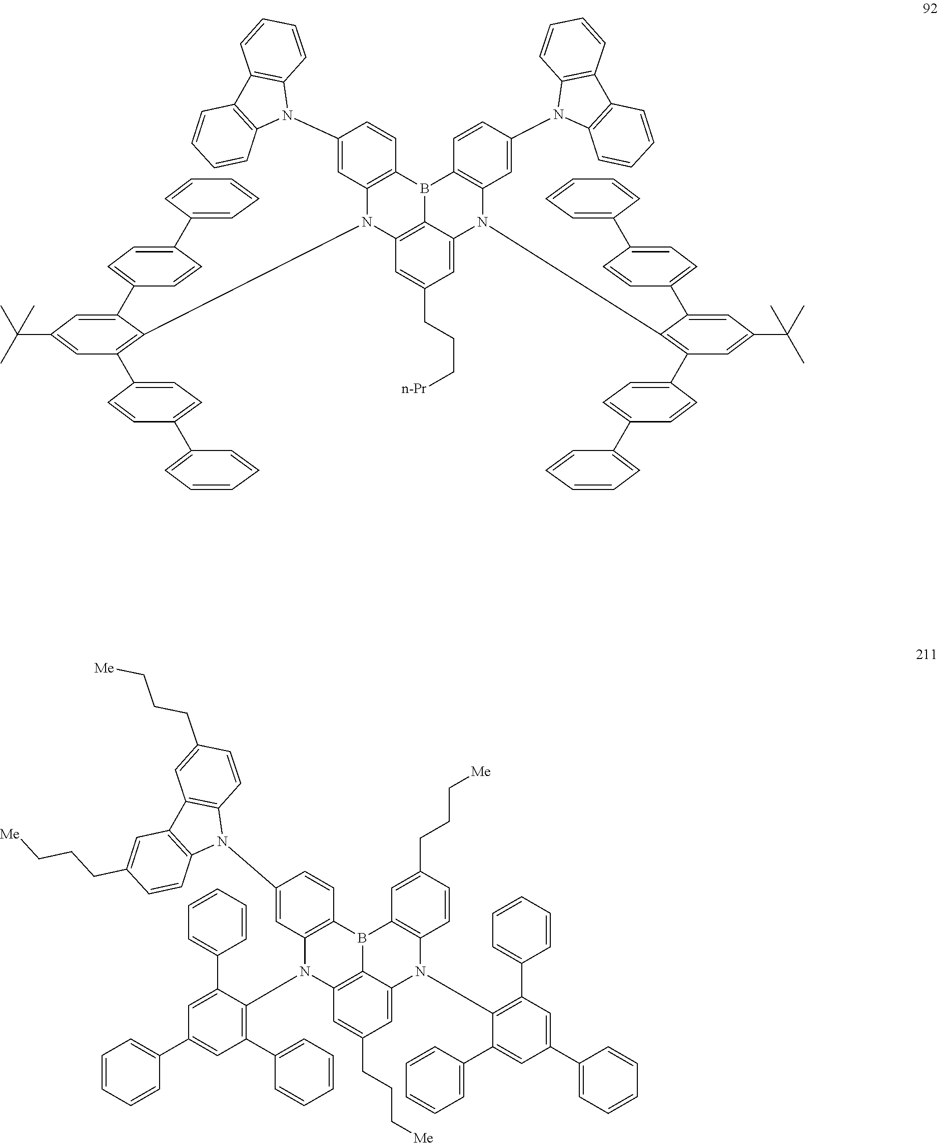

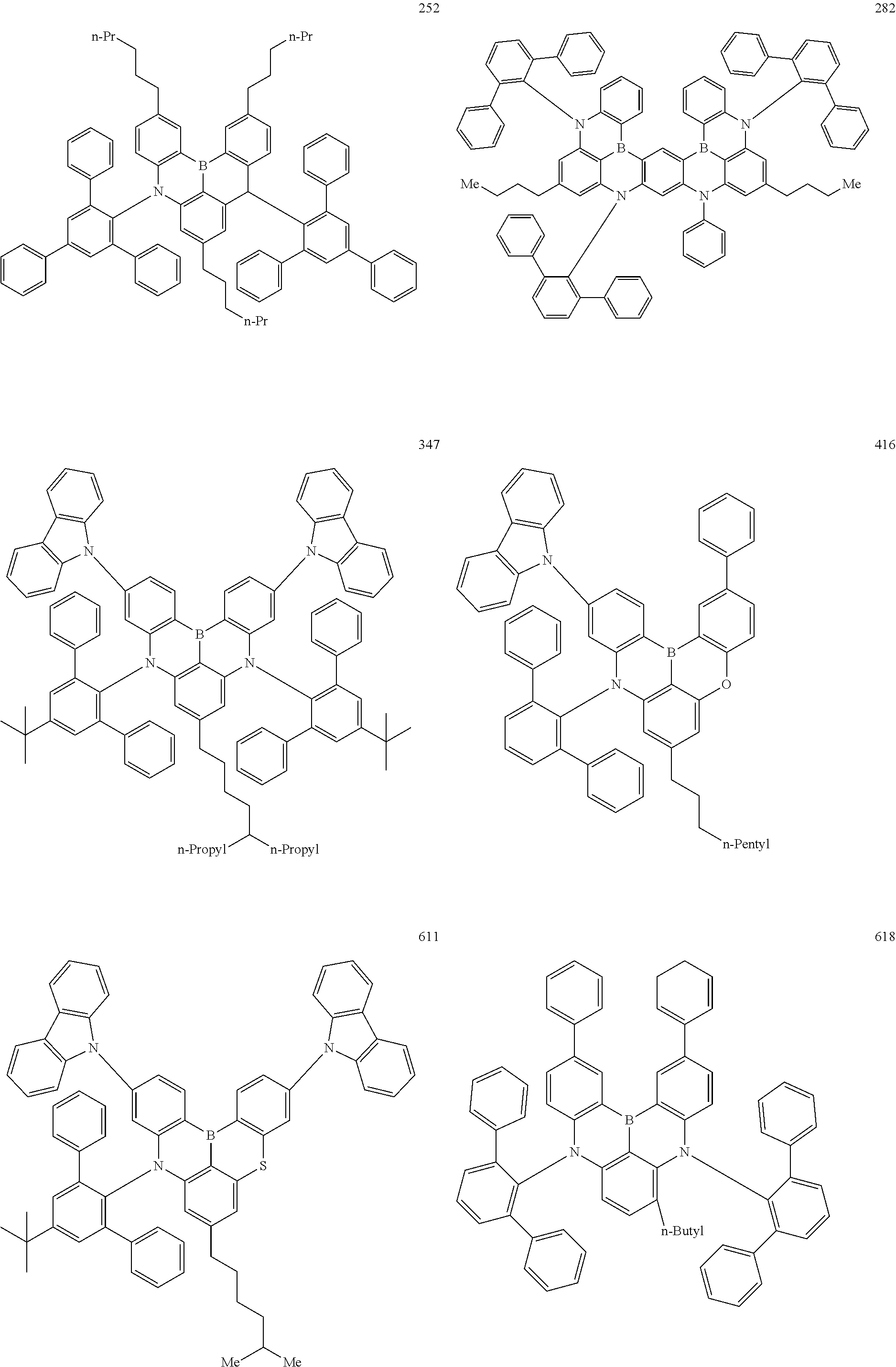

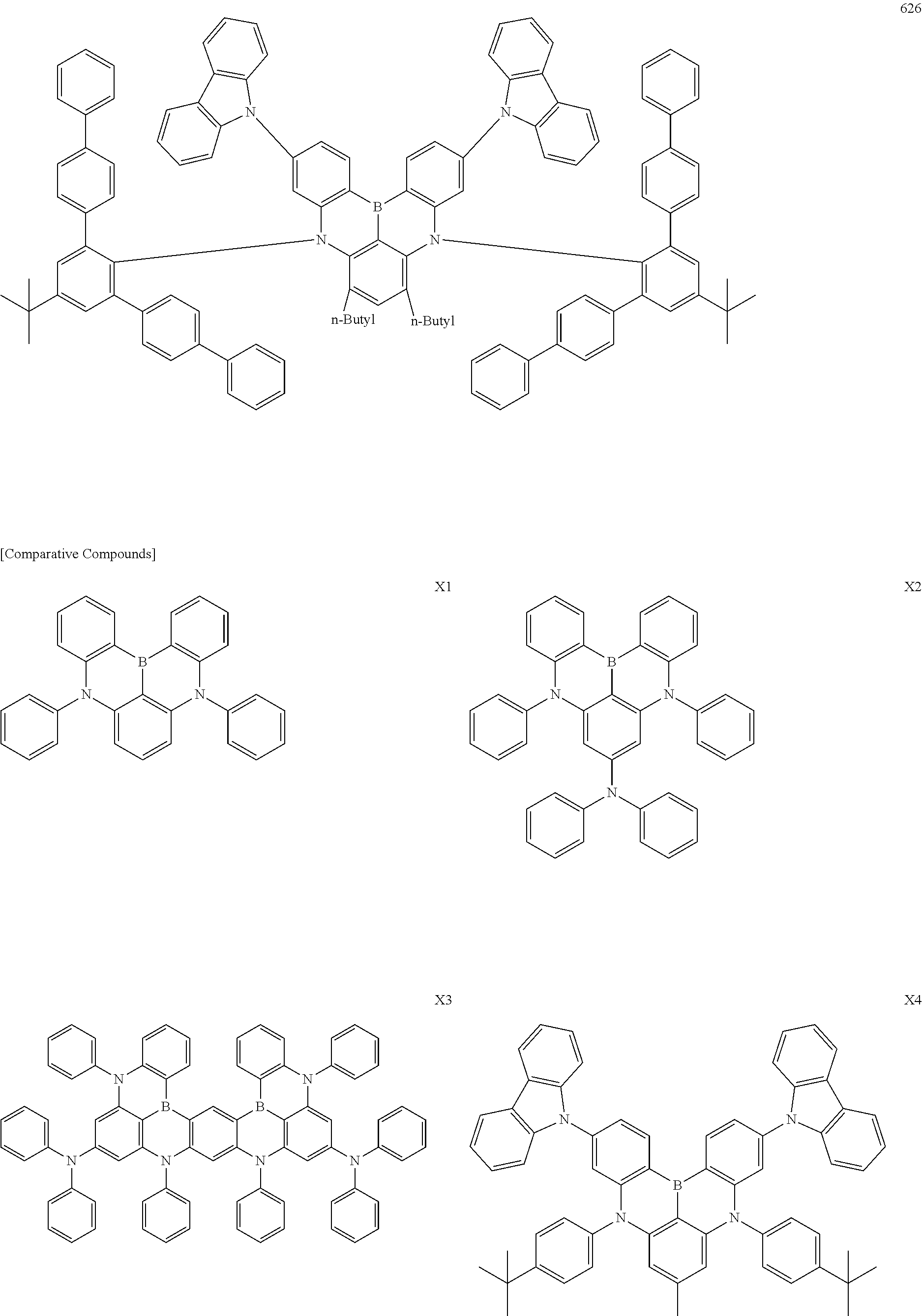

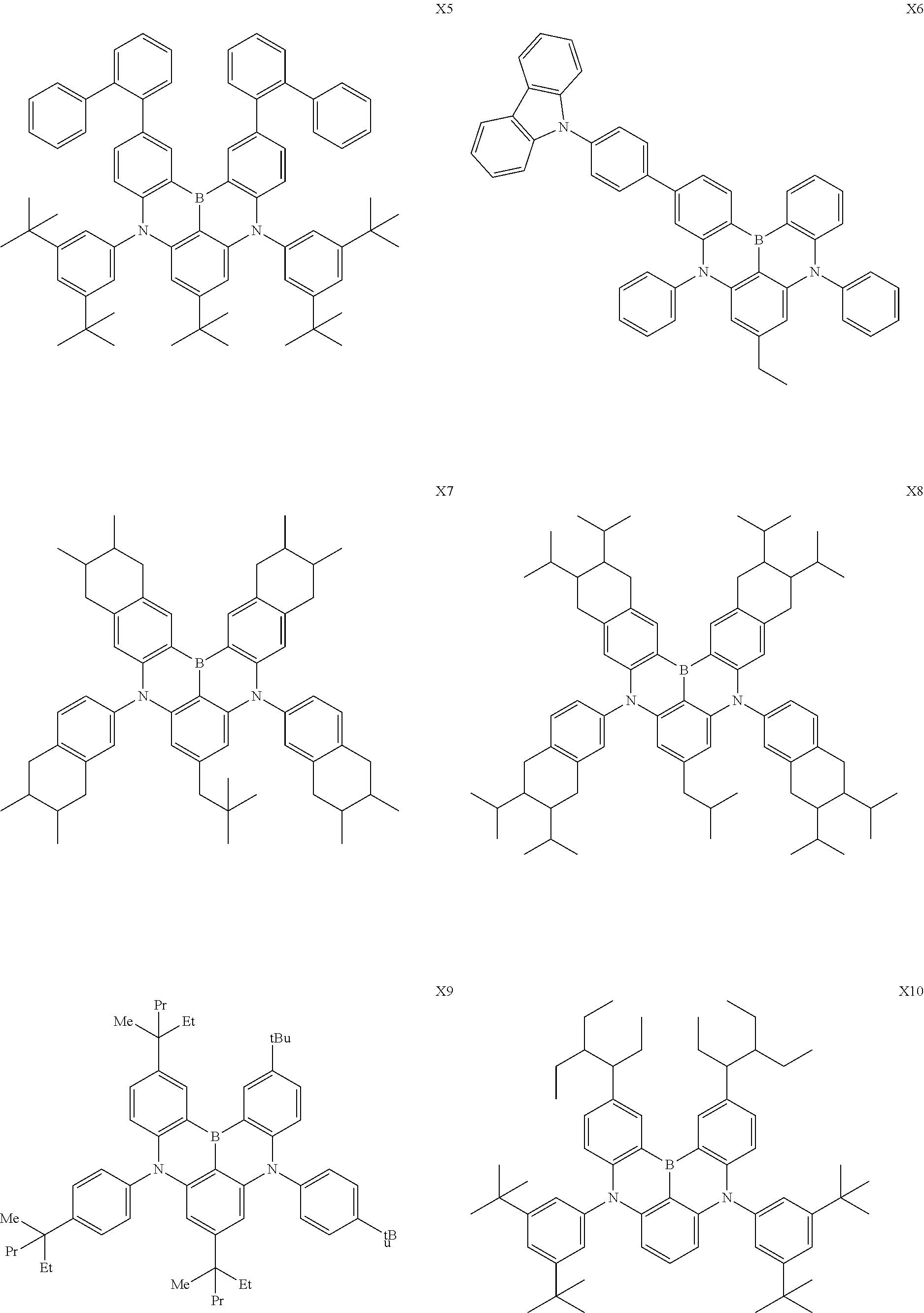

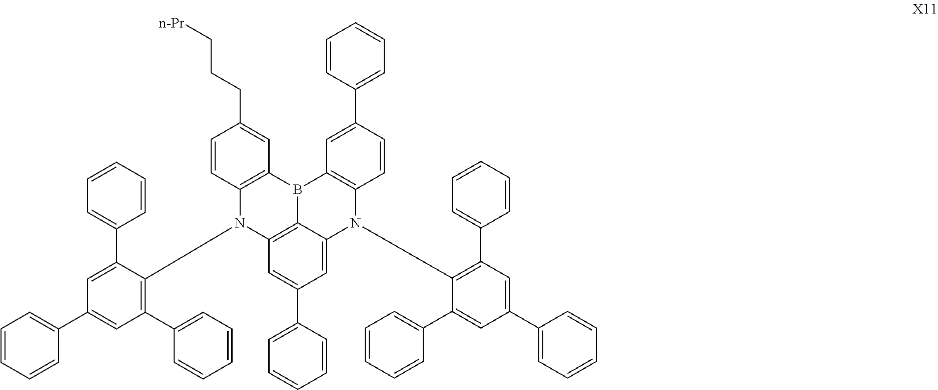

(Manufacture of light emitting element)

A first electrode with a thickness of about 150 nm was formed of ITO. A hole injection layer with a thickness of about 10 nm was formed of dipyrazino[2,3-f: 2′,3′-h]quinoxaline-2,3,6,7,10,11-hexacarbonitrile (HATCN) on the first electrode. A hole transport layer with a thickness of about 80 nm was formed of N,N′-bis(naphthalen-1-yl)-N,N′-bis(phenyl)-2,2″-dimethylbenzidine (a-NPD) on the hole injection layer. An emission auxiliary layer with a thickness of about 5 nm was formed of 1,3-bis(carbazole-9-yl)benzene (mCP) on the hole transport layer. An emission layer with a thickness of about 20 nm was formed by co-depositing 3,3′-di(9H-carbazol-9-yl)-1,1′-biphenyl (mCBP) and an Example Compound at a mass ratio of about 99:1 on the emission auxiliary layer. For the light emitting elements of the Comparative Examples, the Comparative Compounds were applied instead of an Example Compound. An electron transport layer with a thickness of about 30 nm was formed of 2,2′,2″-(1,3,5-benzinetriyl)-tris(1-phenyl-1-H-benzimidazole) (TPBi) on the emission layer. An electron injection layer with a thickness of about 0.5 nm was formed of LiF on the electron transport layer. A second electrode with a thickness of about 100 nm was formed of Al on the electron injection layer. All layers were formed by a vacuum deposition method.

The compounds used in the manufacture of the light emitting elements of the Examples and the Comparative Examples are shown below. The materials below were used after purchasing commercial products and performing sublimation purification.

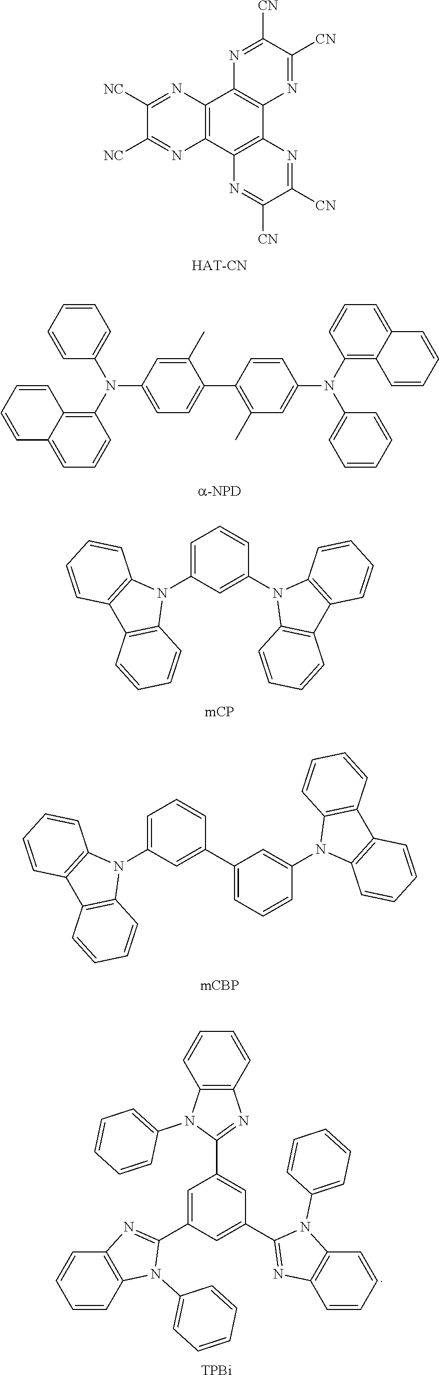

The maximum emission wavelength and lifetime of the light emitting elements manufactured using Example Compounds 11, 57, 82, 92, 211, 252, 282, 347, 416, 611, 618, and 626, and Comparative Compounds X₁ to X₁₁ were evaluated. In Table 1, the evaluation results on the light emitting elements of Examples 1 to 12, and Comparative Examples 1 to 11 are shown. For the evaluation of the elements, the maximum emission wavelength (2max) represents the maximum emission wavelength value on the emission spectrum of a light emitting element, the light attenuation time (μs) represents a value calculated from a time-resolved photoluminescence (TRPL) spectrum at room temperature for a thin film with a thickness of about 20 nm, composed of the dopants (about 1.0 wt %) of the Example Compounds or Comparative Compounds and host (mCBP, about 99 wt %), the roll-off value was calculated through {EQE₁ (external quantum efficiency at about 1 cd/m³)/EQE1000 (external quantum efficiency at about 1000 cd/m³)}×100, the relative element lifetime (LT50) was obtained by measuring time consumed to reach about 50% luminance in contrast to an initial luminance at about 1000 cd/m² and showing a relative numerical based on 1.0 of Comparative Example 3, and the results are shown in Table 1:

TABLE 1

| Element | | Maximum emission | Light | | Relative |
|---|---|---|---|---|---|
| manufacturing | | wavelength (λₘₐₓ, | attenuation time | Roll-off | element lifetime |
| example | Dopant | nm) | (μs) | (%) | (LT₅₀) |
| Example 1 | Compound 1 | 461 | 65 | 18.3 | 3.5 |
| Example 2 | Compound 57 | 460 | 42 | 13.5 | 4.2 |
| Example 3 | Compound 82 | 458 | 25 | 10.9 | 6.2 |
| Example 4 | Compound 92 | 458 | 25 | 11.0 | 6.5 |
| Example 5 | Compound 211 | 457 | 35 | 12.1 | 4.3 |
| Example 6 | Compound 252 | 457 | 30 | 10.2 | 5.2 |
| Example 7 | Compound 282 | 462 | 3 | 8.3 | 7.5 |
| Example 8 | Compound 347 | 458 | 26 | 11.0 | 5.9 |
| Example 9 | Compound 416 | 457 | 28 | 14.0 | 4.9 |
| Example 10 | Compound 611 | 460 | 15 | 8.0 | 6.9 |
| Example 11 | Compound 618 | 461 | 68 | 18.0 | 3.6 |
| Example 12 | Compound 626 | 459 | 25 | 11.0 | 6.1 |
| Comparative | Comparative | 457 | 130 | 33.2 | 0.30 |
| Example 1 | Compound X1 | | | | |
| Comparative | Comparative | 446 | 11.2 | 30.5 | 0.20 |
| Example 2 | Compound X2 | | | | |
| Comparative | Comparative | 467 | 5.5 | 13.5 | 1.00 |
| Example 3 | Compound X3 | | | | |
| Comparative | Comparative | 463 | 32 | 26.3 | 0.62 |
| Example 4 | Compound X4 | | | | |
| Comparative | Comparative | 465 | 38 | 38.4 | 0.45 |
| Example 5 | Compound X5 | | | | |
| Comparative | Comparative | 464 | 49 | 25.5 | 0.15 |
| Example 6 | Compound X6 | | | | |
| Comparative | Comparative | 464 | 37 | 38.2 | 0.05 |
| Example 7 | Compound X7 | | | | |
| Comparative | Comparative | 465 | 62 | 45.2 | 0.30 |
| Example 8 | Compound X8 | | | | |
| Comparative | Comparative | 458 | 77 | 32.2 | 0.25 |
| Example 9 | Compound X9 | | | | |
| Comparative | Comparative | 457 | 120 | 41.5 | 0.23 |
| Example 10 | Compound X10 | | | | |
| Comparative | Comparative | 467 | 180 | 45.6 | 0.35 |
| Example 11 | Compound X11 | | | | |

Referring to the results of Table 1, it could be confirmed that the Examples of the light emitting elements using the fused polycyclic compounds according to embodiments as light emitting materials showed improved emission efficiency and lifetime characteristics when compared to the Comparative Examples. The Example Compounds include a fused ring core in which first to third aromatic rings are fused with a boron atom and first and second heteroatoms, wherein a first substituent connected to the third aromatic ring is combined with the fused ring core, and triplet concentration may be reduced, deterioration due to intermolecular interaction may be reduced, and the increase of lifetime may be achieved. The light emitting element according to the Examples includes the fused polycyclic compound according to an embodiment as a light emitting dopant of a thermally activated delayed fluorescence (TADF) emitting element, and may achieve increased emission efficiency in a short wavelength range and increased lifetime. Referring to Inequation 1 below, the fused polycyclic compound according to an embodiment and the light emitting element according to an embodiment will be explained in particular. Inequation 1 shows the degree of how likely it is to become a radical according to the type of hydrocarbon by using the sign of inequality.

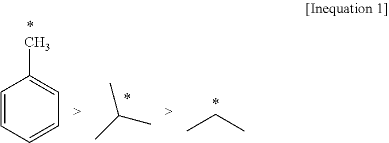

Referring to Inequation 1, it could be confirmed that the dissociation rate into radicals is relatively reduced in the order of aromatic hydrocarbon, branched hydrocarbon, and linear hydrocarbon. It could be confirmed that a linear hydrocarbon, for which dissociation into radicals is relatively difficult, is essentially included as a substituent of the fused ring core in the cases of the Example Compounds. Accordingly, in the cases of the Example Compounds, since a first substituent having a relatively low radical dissociation rate is combined with the fused ring core, radical concentration in a triplet excitation state is relatively low, deterioration in a radical state, such deterioration in a triplet excitation state, is reduced, and long lifetime may be achieved.

In the cases of the Example Compounds, since a first substituent is included in the fused ring core, lifetime deterioration due to intermolecular interaction may be reduced to achieve long lifetime. Since the first substituent included in the Example Compounds include a linear alkyl group structure having 4 or more carbon atoms, distance between adjacent molecules may be increased, exciton quenching phenomenon due to intermolecular stacking may be suppressed, and the lifetime characteristics may be improved by the avoidance of deterioration.

Referring to Comparative Examples 1 to 3 and 5 in Table 1, Comparative Compounds X₁ to X₃ and X₅ include a plate-type skeleton structure with one boron atom and two nitrogen atoms in the center, but do not include the first substituent according to embodiments in the plate-type skeleton. Accordingly, it could be confirmed that element lifetime was deteriorated. In the case of Comparative Example 2, a structure substituted with a diphenylamine group as a donor is included, and it is thought that the lifetime of the light emitting element of Comparative Example 2 was deteriorated even further. In the case of Comparative Compound X₅, an alkyl group is included as a substituent, but a t-butyl group, which is a branched alkyl group, is included, and it is thought that a dissociation rate into radicals is rapid, so that deterioration in a triplet excitation state occurs, and the lifetime of the light emitting element of Comparative Example 5 is deteriorated.

Referring to Comparative Examples 4, 6, and 8, Comparative Compounds X₄, X₆, and X₈ include a plate-type skeleton structure with one boron atom and two nitrogen atoms in the center and a linear alkyl group as the substituent of the plate-type skeleton. However, Comparative Compounds X₄. X₆, and X₈ do not include an alkyl group of 4 or more carbon atoms, which would constitute a linear structure. Accordingly, it could be confirmed that, if applied in an element, element lifetime was degraded. In the cases of Comparative Compounds X₄. X₆, and X₈, it is thought that an alkyl group of 3 or fewer carbon atoms is included as a substituent, and element deterioration due to intermolecular interaction is increased, and element lifetime of Comparative Examples 4, 6, and 8 was reduced.

Referring to Comparative Examples 7, 9, and 10, Comparative Compounds X₇, X₉, and X₁₀ include a plate-type skeleton structure with one boron atom and two nitrogen atoms in the center, but do not include the first substituent according to embodiments in the plate-type skeleton, and in case of being applied in an element, the element lifetime was deteriorated when compared to the Examples. Comparative Compounds X₇, X₉, and X₁₀ do not include the first substituent as the substituent of the plate-type skeleton but include a linear or branched alkyl group, and it is thought that the emission properties and element lifetime of Comparative Examples 7, 9, and 10 are deteriorated. Comparative Compounds X₇ and X₉ include an alkyl group as the substituent of the plate-type skeleton, but include a 2,2-dimethylpropyl group or a 4-ethyloctyl group instead of a linear alkyl group of 3 or more carbon atoms, thereby diverging from the embodiments. Accordingly, it is thought that the element lifetime of Comparative Examples 7 and 9 was deteriorated.

Referring to Comparative Example 11, Comparative Compound X₁₁ includes a plate-type skeleton structure with one boron atom and two nitrogen atoms in the center and includes a linear alkyl group of 3 or more carbon atoms as the substituent of the plate-type skeleton. However, the first substituent according to an embodiment is connected with the third aromatic ring of the fused ring core as the substituent of a donor type. In contrast, the alkyl group of Comparative Compound X₁₁ is connected with a ring corresponding to the second aromatic ring of the fused ring core. Accordingly, if applied to an element, it is thought that the element lifetime of Comparative Example 11 is relatively reduced, and an emission wavelength is increased.

The light emitting element of an embodiment may show improved element properties of high efficiency and long lifetime.

The fused polycyclic compound of an embodiment may be included in the emission layer of a light emitting element and may contribute to the increase of the efficiency and lifetime of the light emitting element.

Embodiments have been disclosed herein, and although terms are employed, they are used and are to be interpreted in a generic and descriptive sense only and not for the purposes of limitation. In some instances, as would be apparent to one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

What is claimed is:

1. A light emitting element, comprising:
a first electrode;
a second electrode disposed on the first electrode; and
at least one functional layer disposed between the first electrode and the second electrode, wherein
the at least one functional layer comprises a fused polycyclic compound represented by Formula 1: 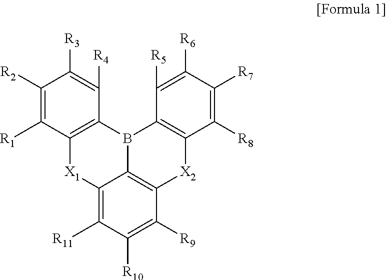
wherein in Formula 1,
X₁ and X₂ are each independently O, S, or N(Rₓ),
R₁ to R₁₁ and Rₓ are each independently a hydrogen atom, a deuterium atom, a halogen atom, a cyano group, a hydroxyl group, a substituted or unsubstituted oxy group, a substituted or unsubstituted thio group, a substituted or unsubstituted boron group, a substituted or unsubstituted silyl group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, a substituted or unsubstituted heteroaryl group of 2 to 30 ring-forming carbon atoms, a group represented by Formula 2, or combined with an adjacent group to form a ring, and
at least one of R₉ to Rn is each independently a group represented by Formula 2: 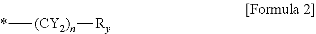
wherein in Formula 2,
Y is a hydrogen atom or a deuterium atom,
R_{y} is a substituted or unsubstituted alkyl group of 1 to 20 carbon atoms,
n is an integer from 3 to 20, and 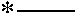 [SMILES: *C]
represents a bond to Formula 1.

2. The light emitting element of claim 1, wherein
the at least one functional layer comprises:
an emission layer;
a hole transport region disposed between the first electrode and the emission layer; and
an electron transport region disposed between the emission layer and the second electrode, and
the emission layer comprises the fused polycyclic compound.

3. The light emitting element of claim 2, wherein the emission layer emits delayed fluorescence.

4. The light emitting element of claim 2, wherein the emission layer emits light having a central wavelength in a range of about 430 nm to about 490 nm.

5. The light emitting element of claim 1, wherein in Formula 2, R_{y} is a linear or branched alkyl group of 1 to 10 carbon atoms, a deuterium-substituted linear alkyl group of 1 to 10 carbon atoms, or a deuterium-substituted branched alkyl group of 1 to 10 carbon atoms.

6. The light emitting element of claim 1, wherein in Formula 2, R_{y} is a group represented by one of Formula 3-1 to Formula 3-11: 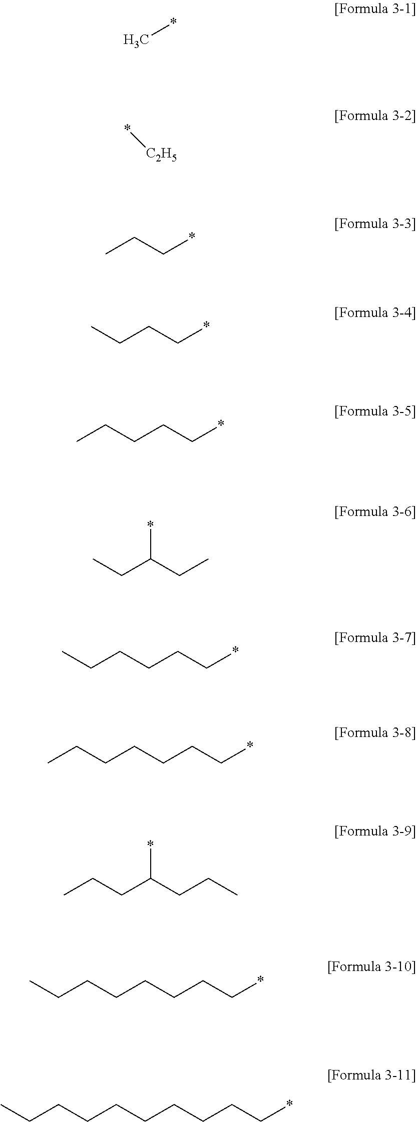
wherein in Formula 3-1 to Formula 3-11,
at least one hydrogen atom is optionally substituted with a deuterium atom.

7. The light emitting element of claim 1, wherein the fused polycyclic compound is represented by Formula 1-1: 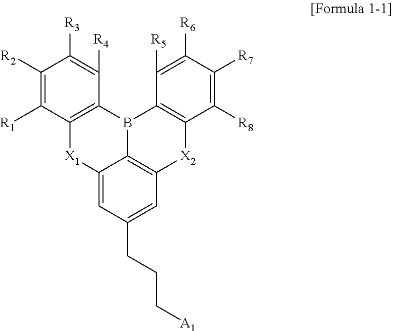
wherein in Formula 1-1,
A₁ is a substituted or unsubstituted linear alkyl group of 1 to 10 carbon atoms or a substituted or unsubstituted branched alkyl group of 1 to 10 carbon atoms,
R₁ to R₈, Rₓ, X₁, and X₂ are the same as defined in Formula 1, and
at least one hydrogen atom is optionally substituted with a deuterium atom.

8. The light emitting element of claim 1, wherein the fused polycyclic compound is represented by Formula 1-2 or Formula 1-3: 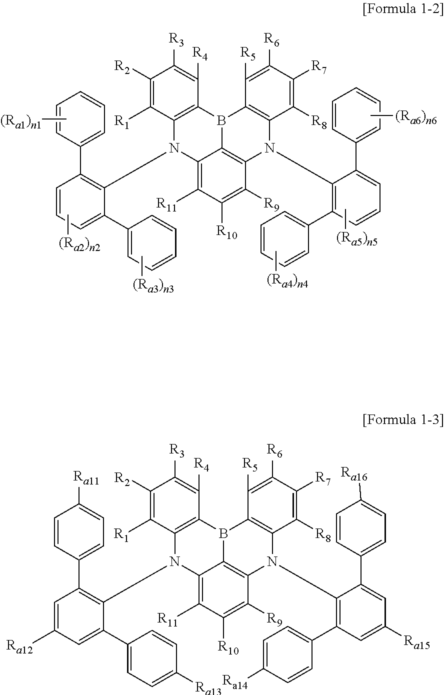
wherein in Formula 1-2 and Formula 1-3,
Rai to Rₐ₆ and Rₐ₁₁ to Rₐ₁₆ are each independently a hydrogen atom, a deuterium atom, a halogen atom, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
n1, n3, n4, and n6 are each independently an integer from 0 to 5,
n2 and n5 are each independently an integer from 0 to 3, and
R₁ to R₁₁ are the same as defined in Formula 1.

9. The light emitting element of claim 1, wherein in Formula 1,
at least one of R₁ to R₄ is each independently a group represented by Formula 2, Formula 4-1, or Formula 4-2, and
at least one of R₅ to R₈ is each independently a group represented by Formula 2, Formula 4-1, or Formula 4-2: 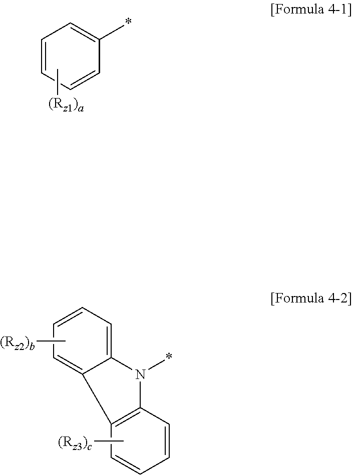
wherein in Formula 4-1 and Formula 4-2,
R_{z1} to R_{z3} are each independently a hydrogen atom, a deuterium atom, a halogen atom, a substituted or unsubstituted linear alkyl group of 1 to 20 carbon atoms, or a substituted or unsubstituted branched alkyl group of 1 to 20 carbon atoms,
a is an integer from 0 to 5, and
b and c are each independently an integer from 0 to 4.

10. The light emitting element of claim 1, wherein the fused polycyclic compound is represented by one of Formula 1-4 to Formula 1-6: 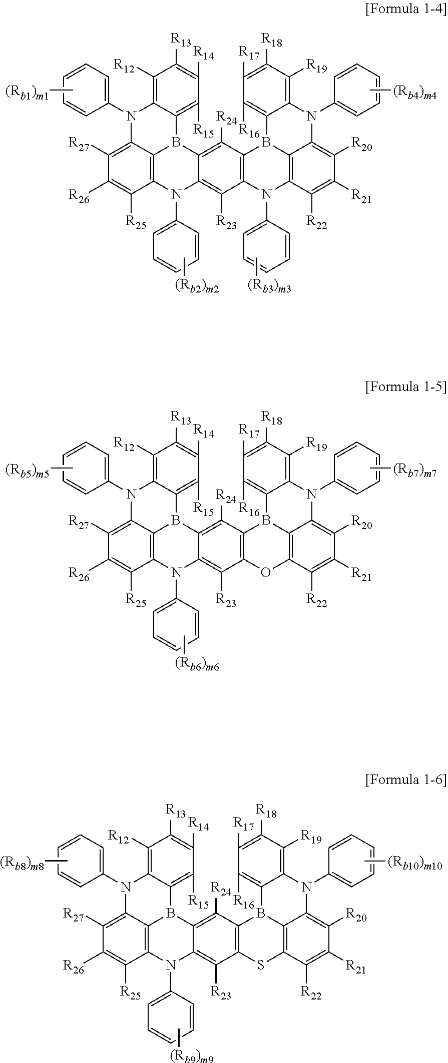
wherein in Formula 1-4 to Formula 1-6,
R₁₂ to R₂₇ are each independently a hydrogen atom, a deuterium atom, a halogen atom, a cyano group, a hydroxyl group, a substituted or unsubstituted oxy group, a substituted or unsubstituted thio group, a substituted or unsubstituted boron group, a substituted or unsubstituted silyl group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, a substituted or unsubstituted heteroaryl group of 2 to 30 ring-forming carbon atoms, or a group represented by Formula 2,
R_{b1} to R_{b10} are each independently a hydrogen atom, a deuterium atom, a halogen atom, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
m1 to m10 are each independently an integer from 0 to 5,
at least one of R₂₅ to R₂₇ is each independently a group represented by Formula 2, and
at least one hydrogen atom is optionally substituted with a deuterium atom.

11. The light emitting element of claim 1, wherein the fused polycyclic compound is represented by Formula 1-7 or Formula 1-8: 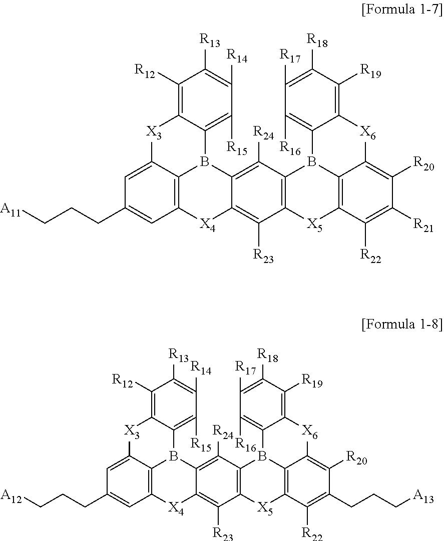
wherein in Formula 1-7 and Formula 1-8,
X₃ to X₆ are each independently O, S, or N(Rₓ),
A₁₁ to A₁₃ are each independently a substituted or unsubstituted linear alkyl group of 1 to 10 carbon atoms or a substituted or unsubstituted branched alkyl group of 1 to 10 carbon atoms,
R₁₂ to R₂₄ are each independently a hydrogen atom, a deuterium atom, a halogen atom, a cyano group, a hydroxyl group, a substituted or unsubstituted oxy group, a substituted or unsubstituted thio group, a substituted or unsubstituted boron group, a substituted or unsubstituted silyl group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, a substituted or unsubstituted heteroaryl group of 2 to 30 ring-forming carbon atoms, or a group represented by Formula 2,
Rₓ is the same as defined in Formula 1, and
at least one hydrogen atom is optionally substituted with a deuterium atom.

12. The light emitting element of claim 1, wherein the fused polycyclic compound comprises at least one compound selected from Compound Group 1: 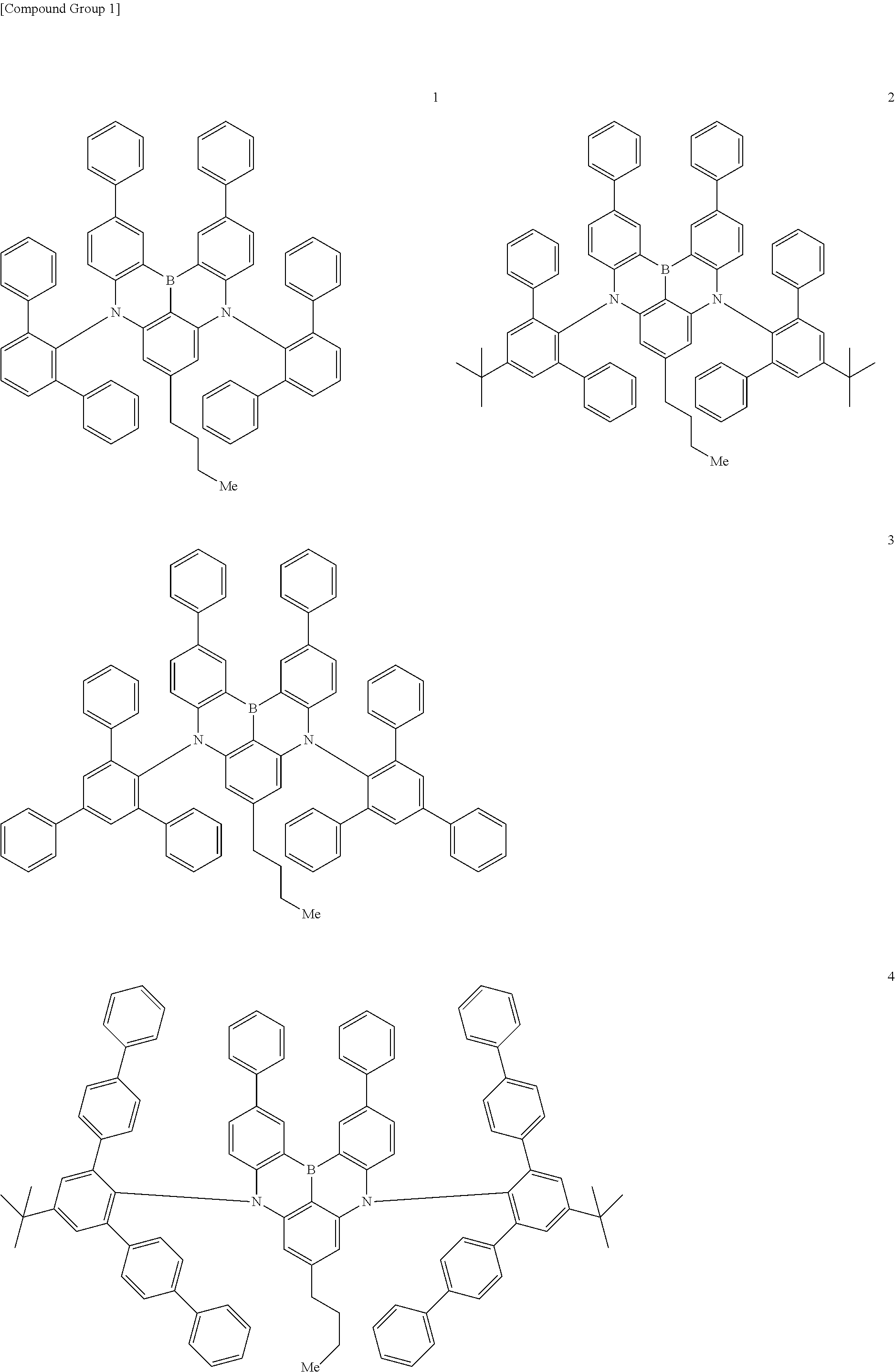 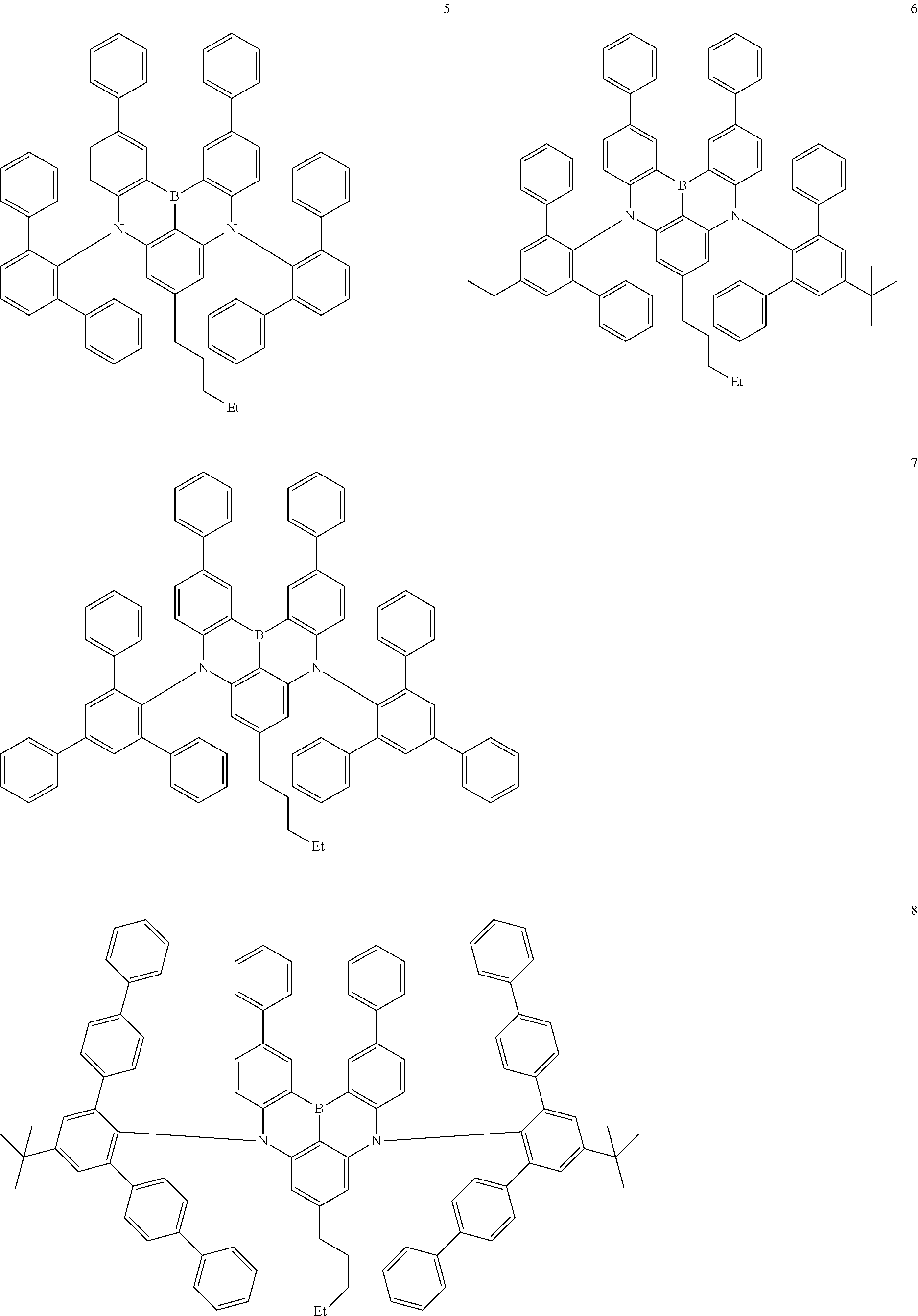 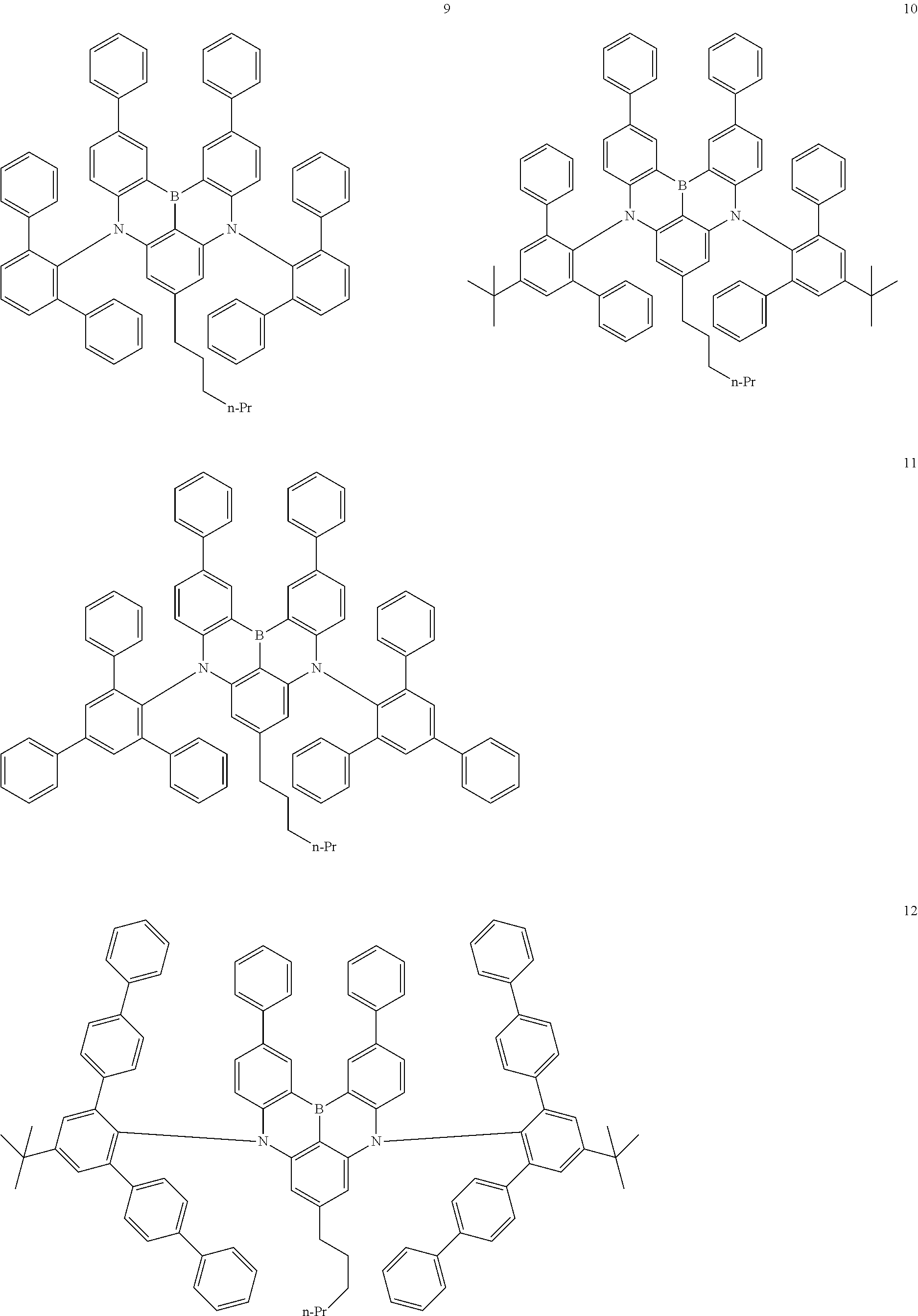 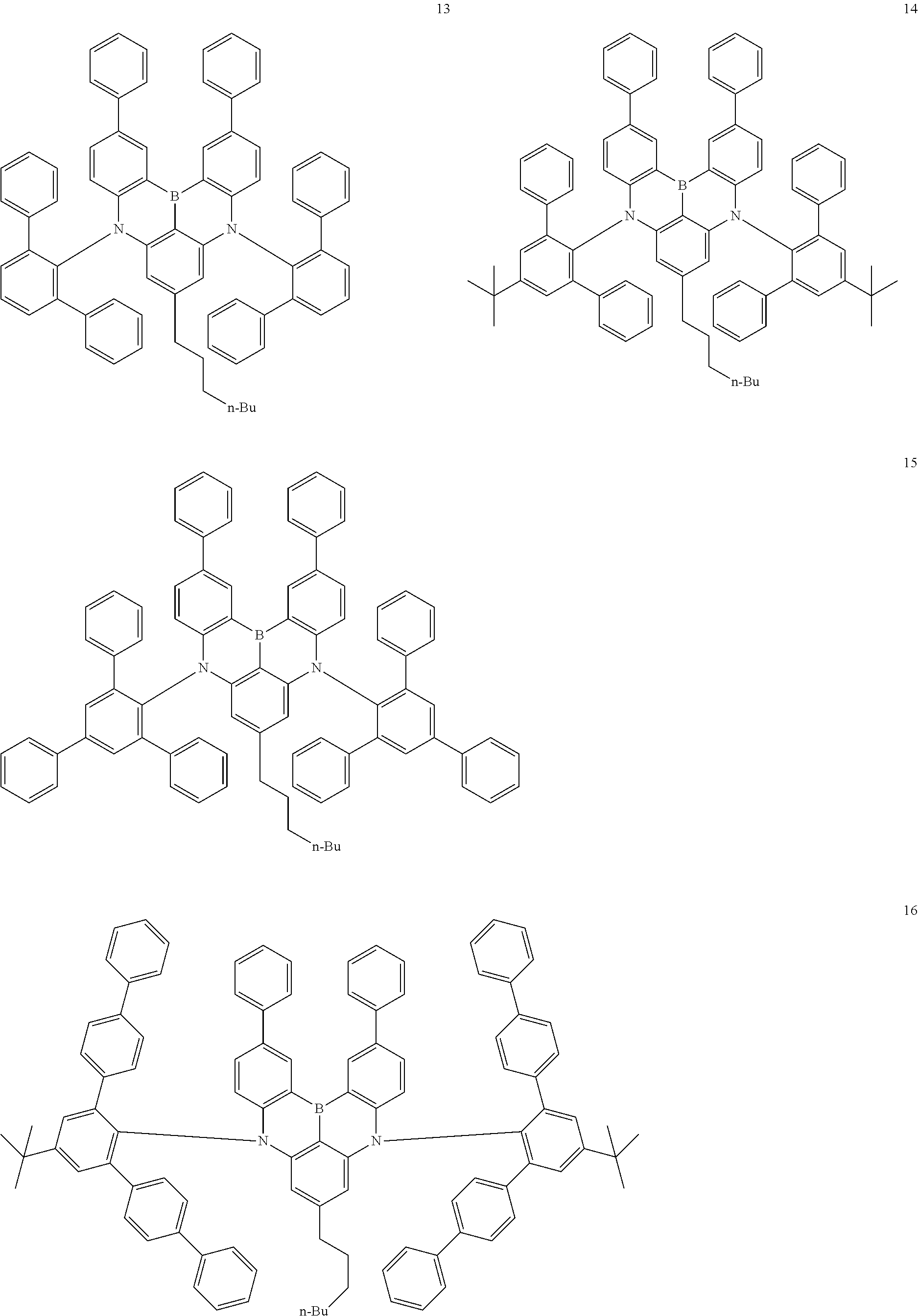 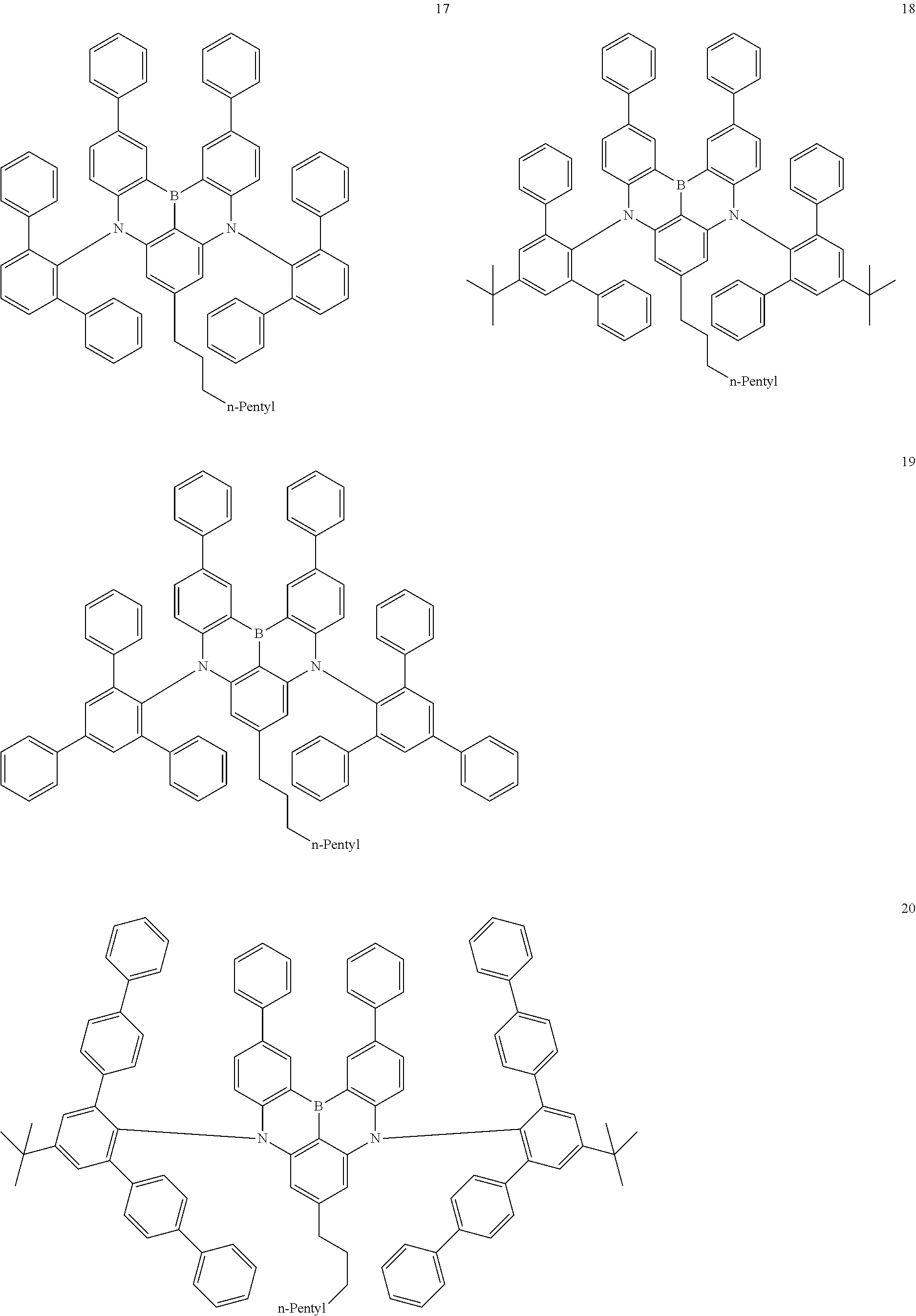 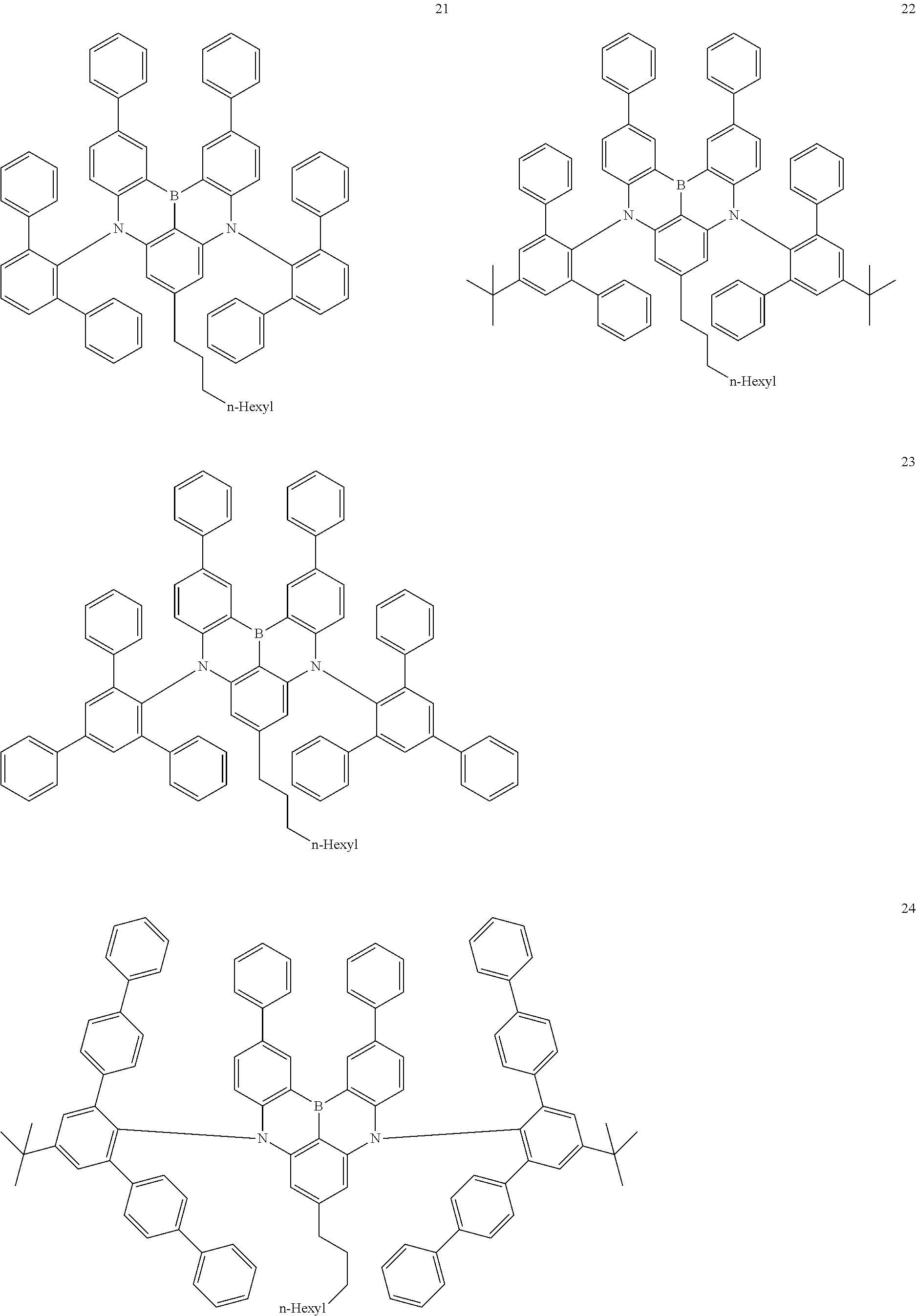 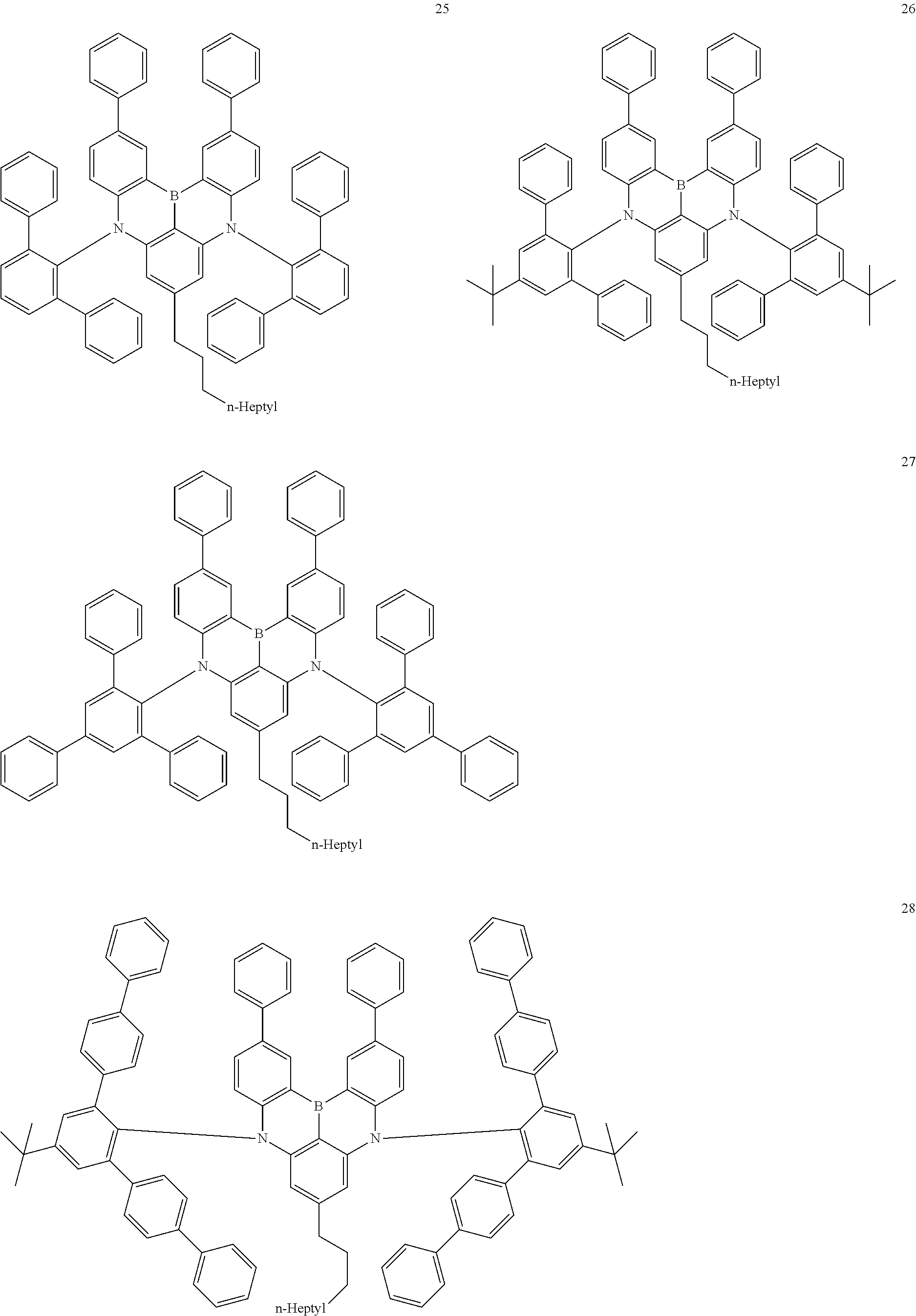 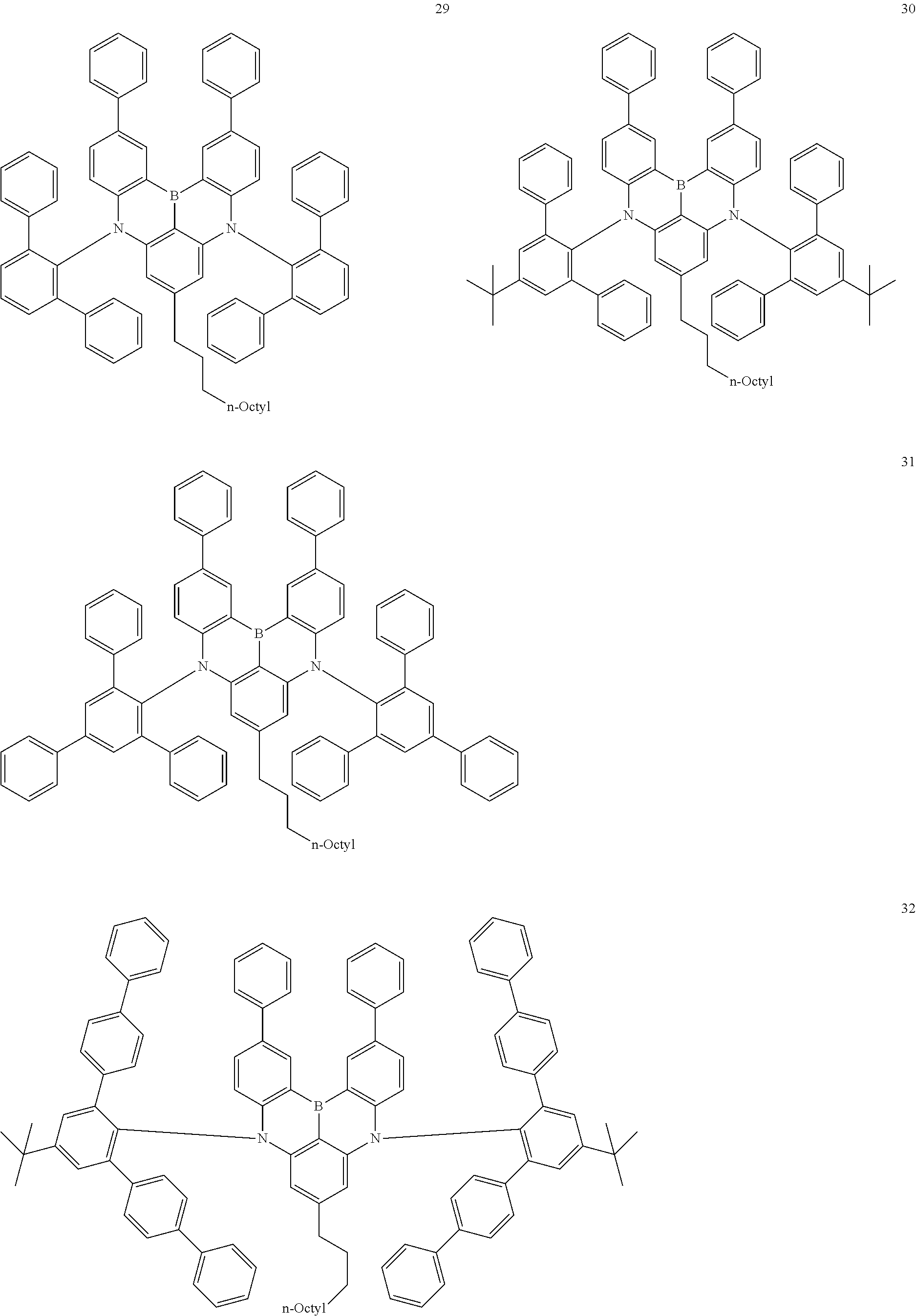 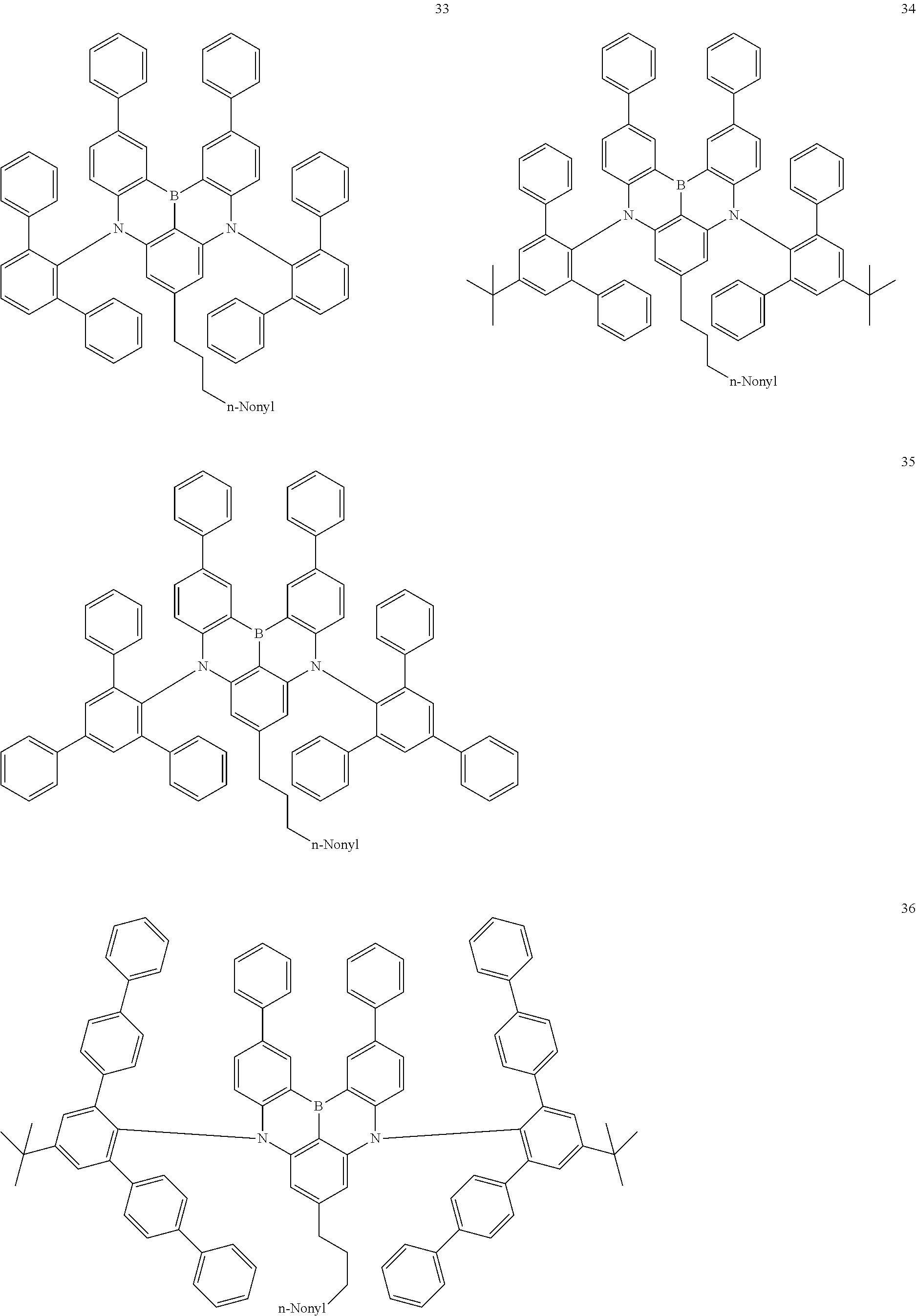 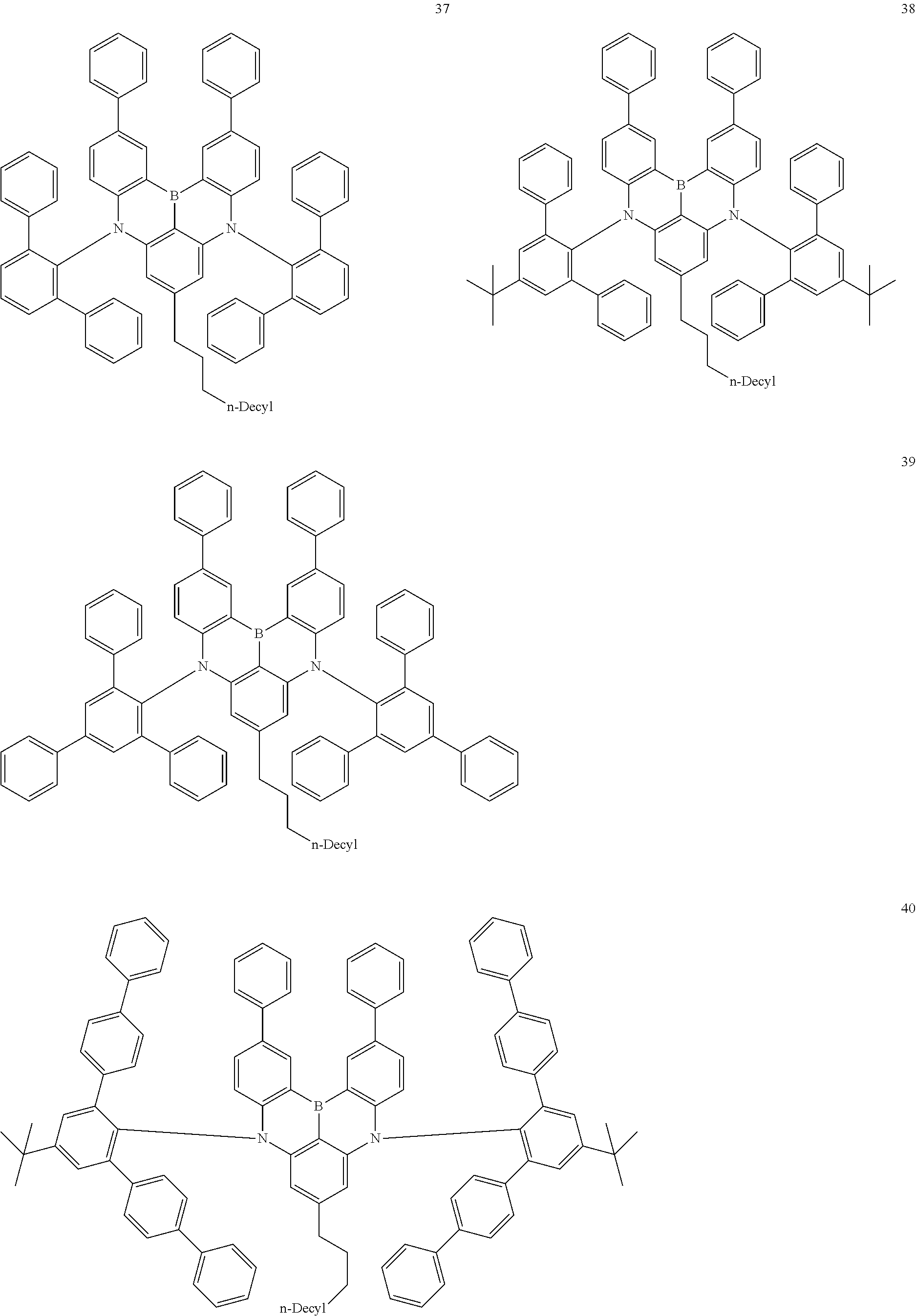 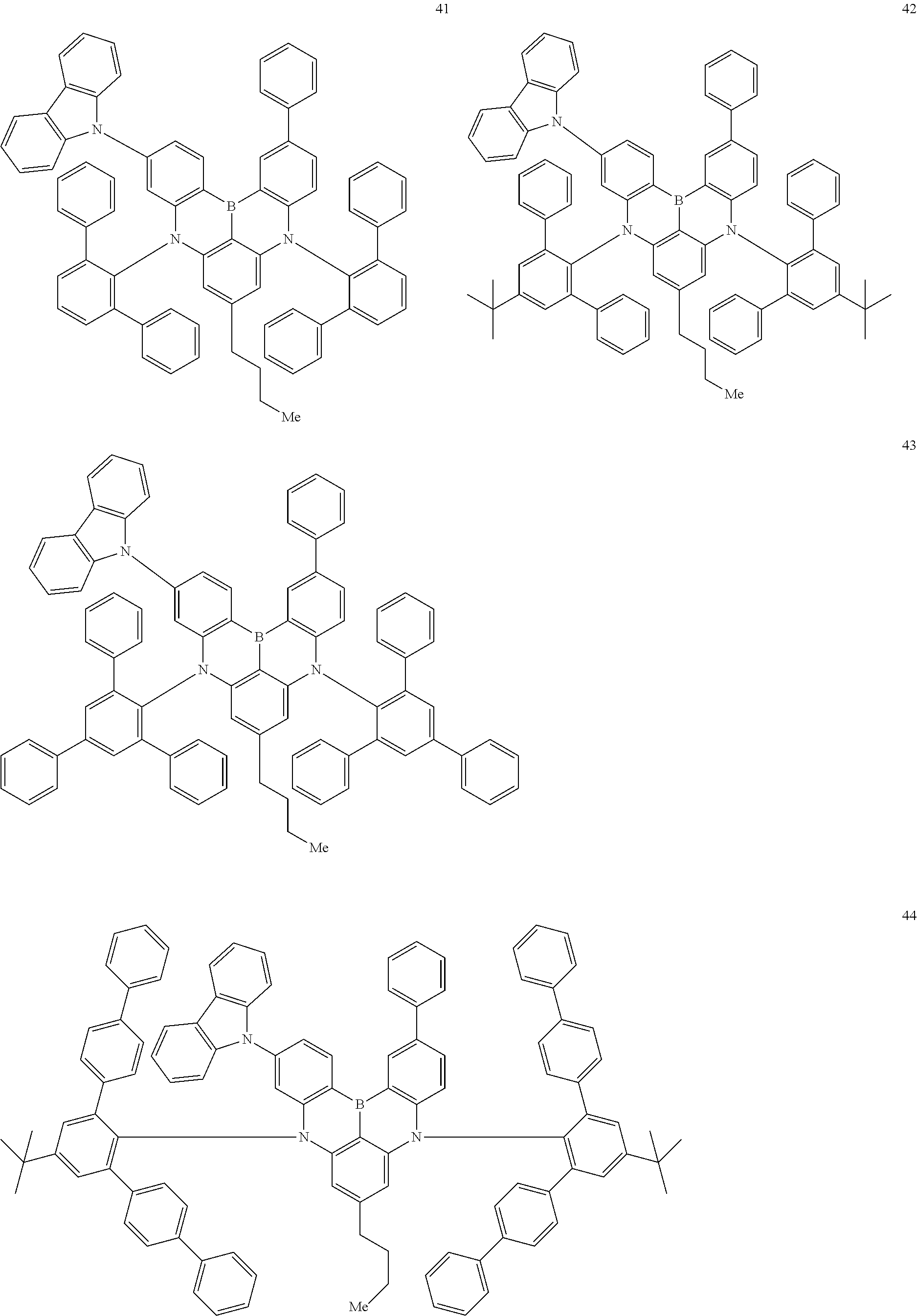 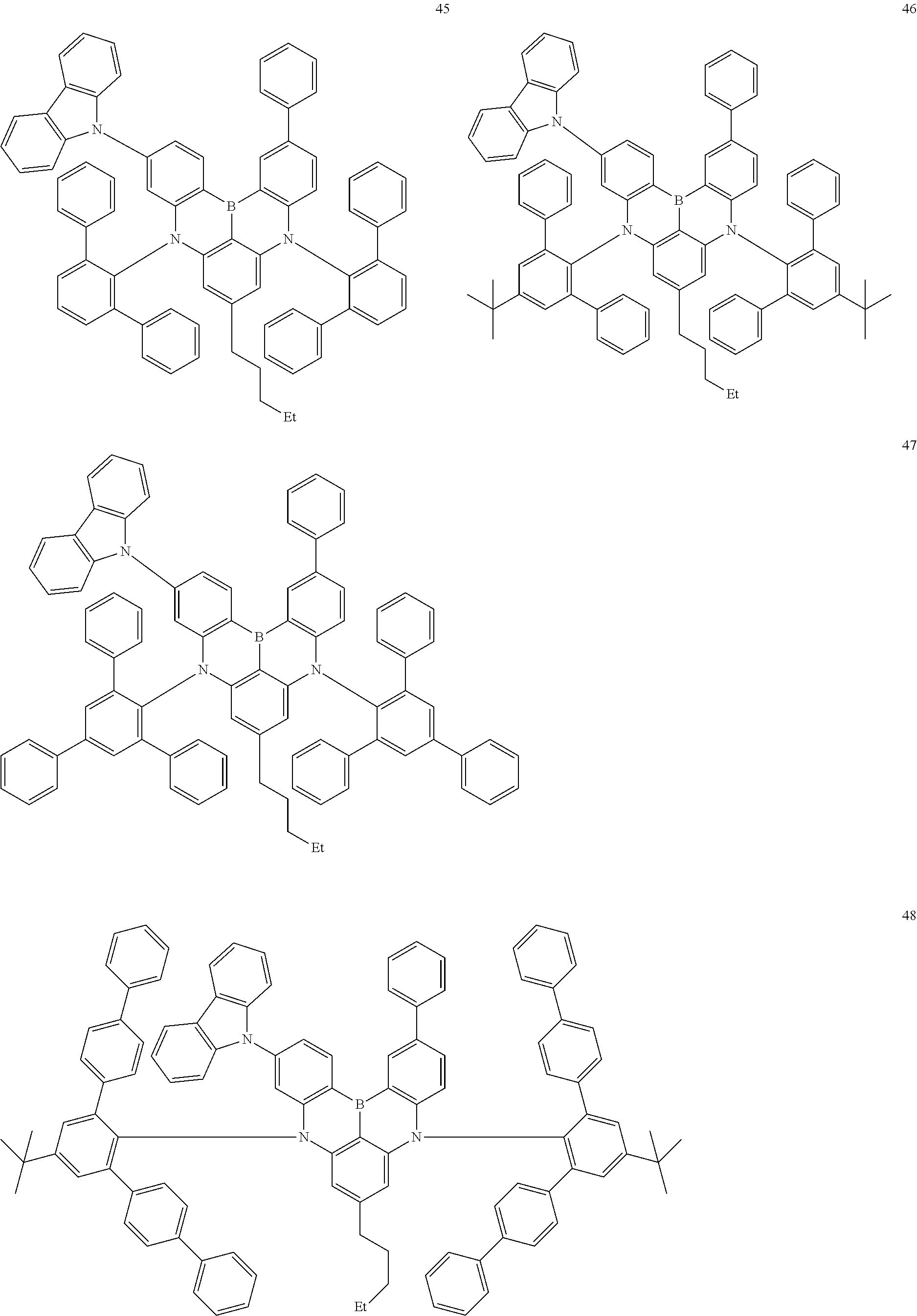 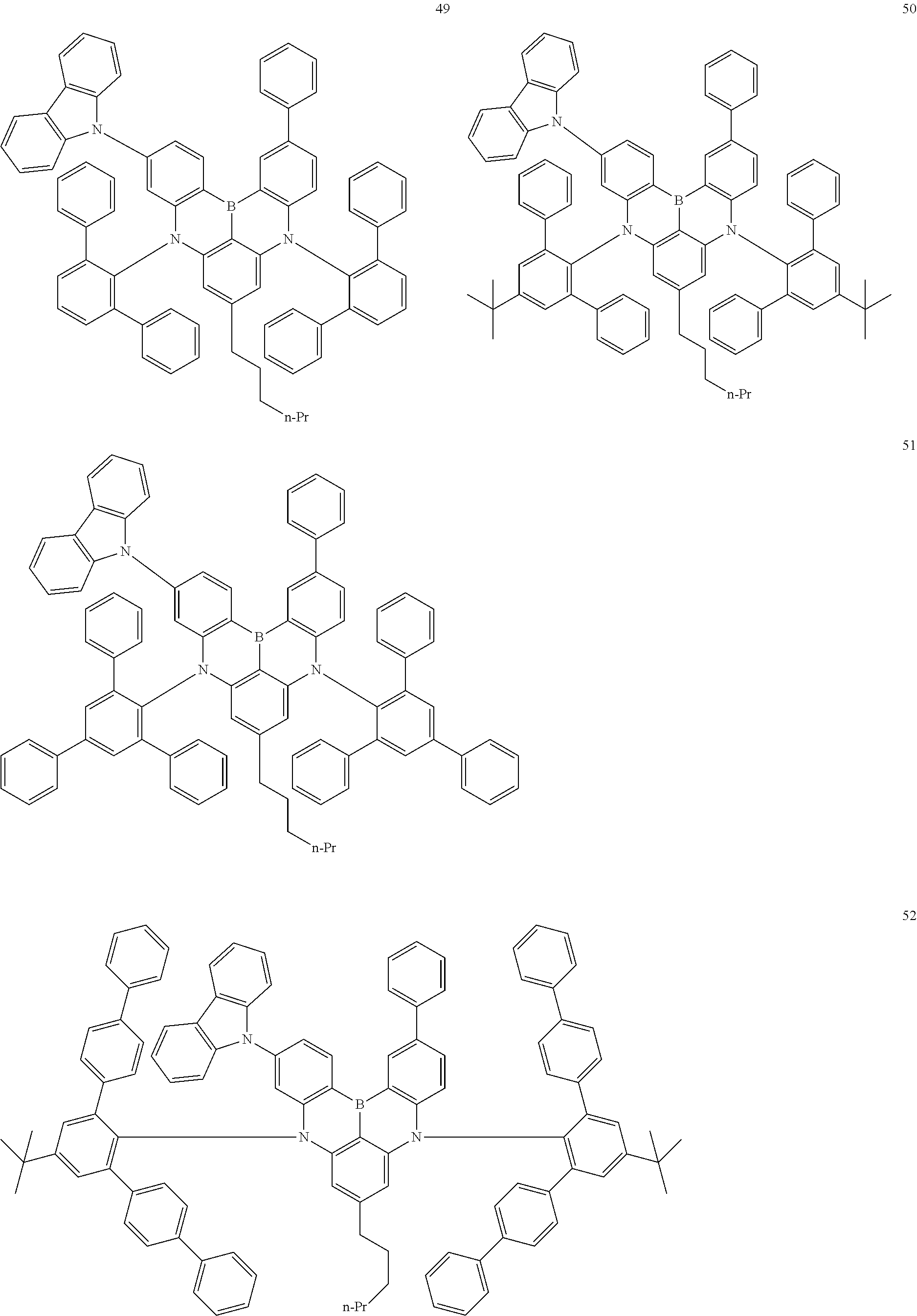 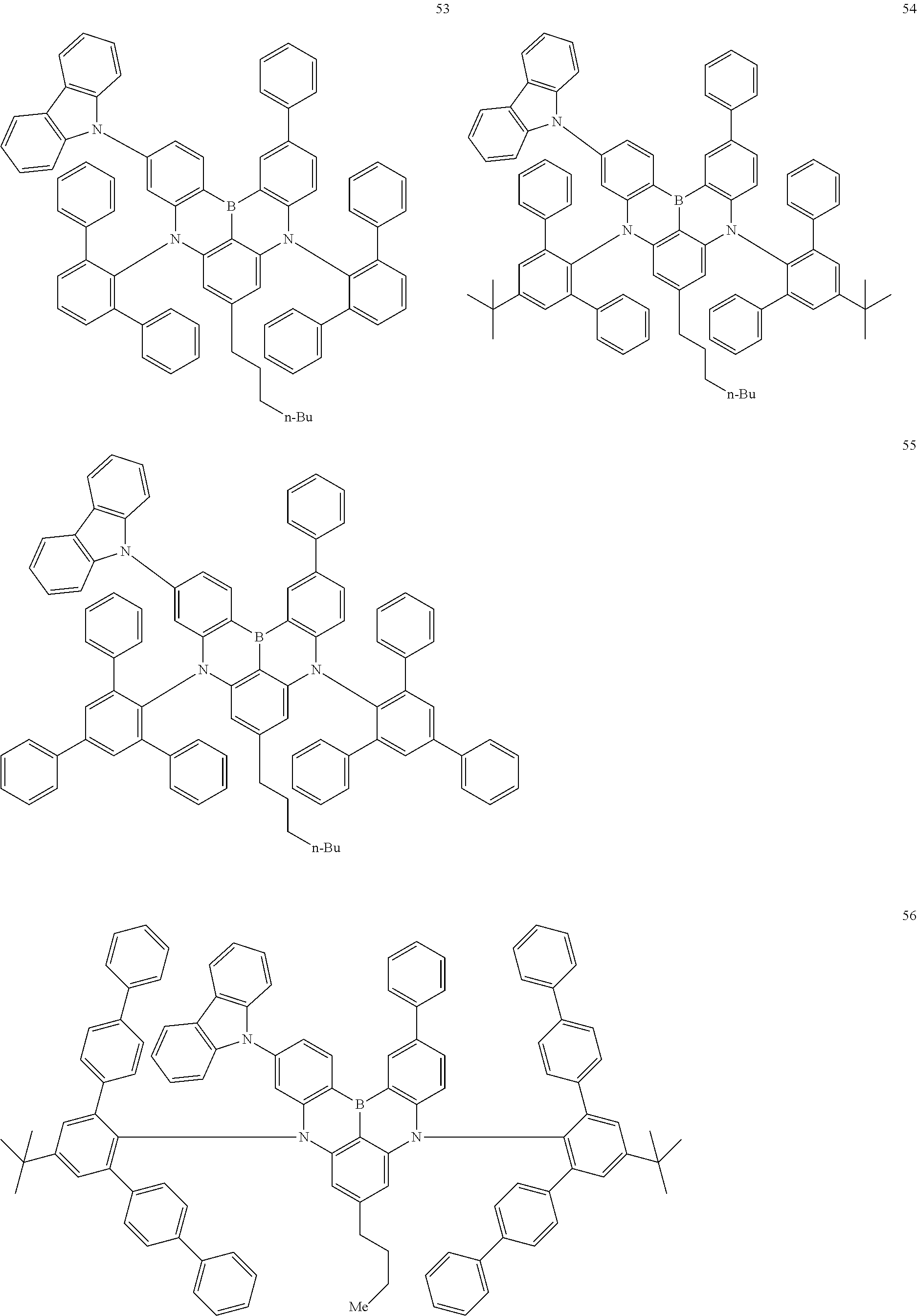 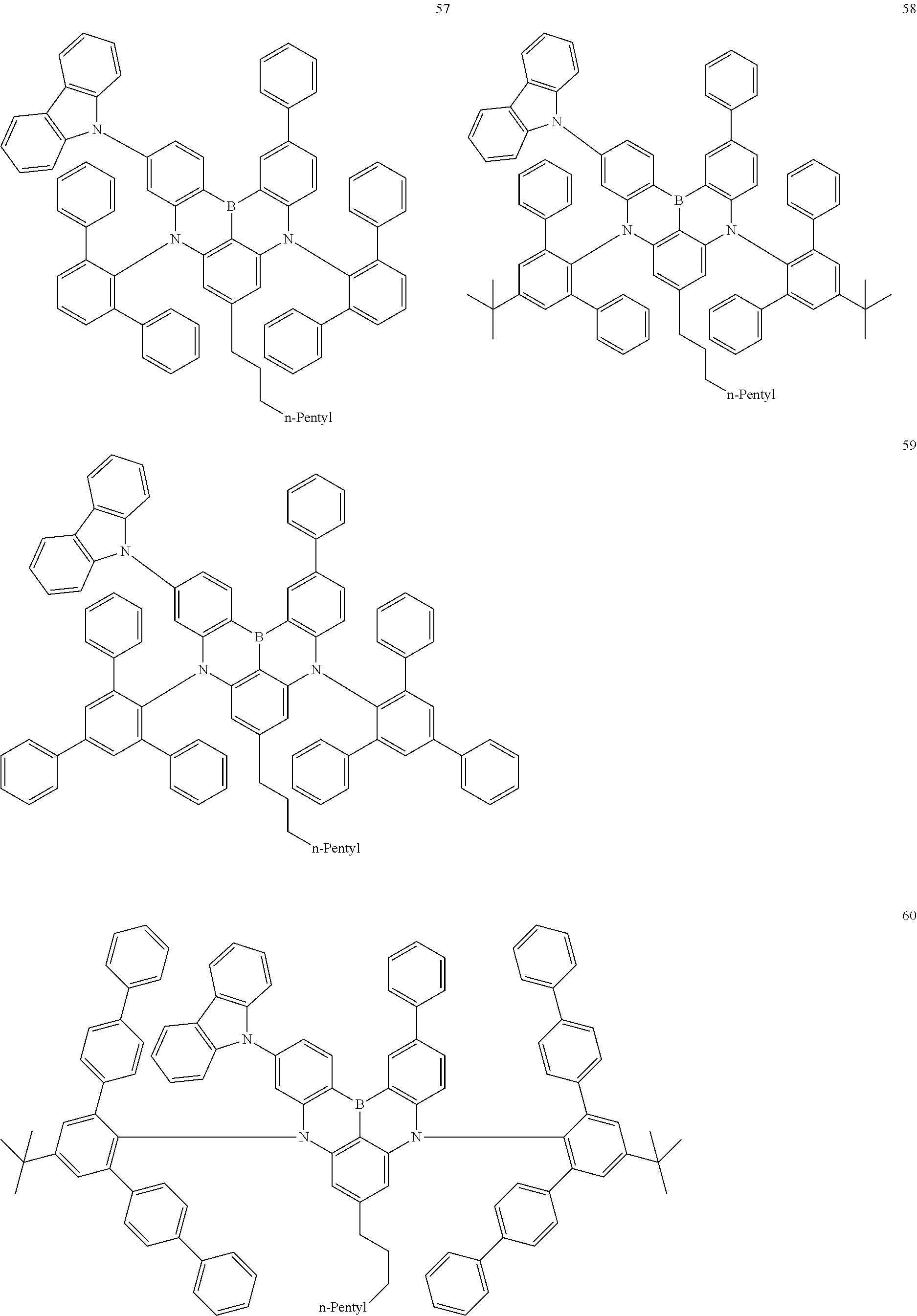 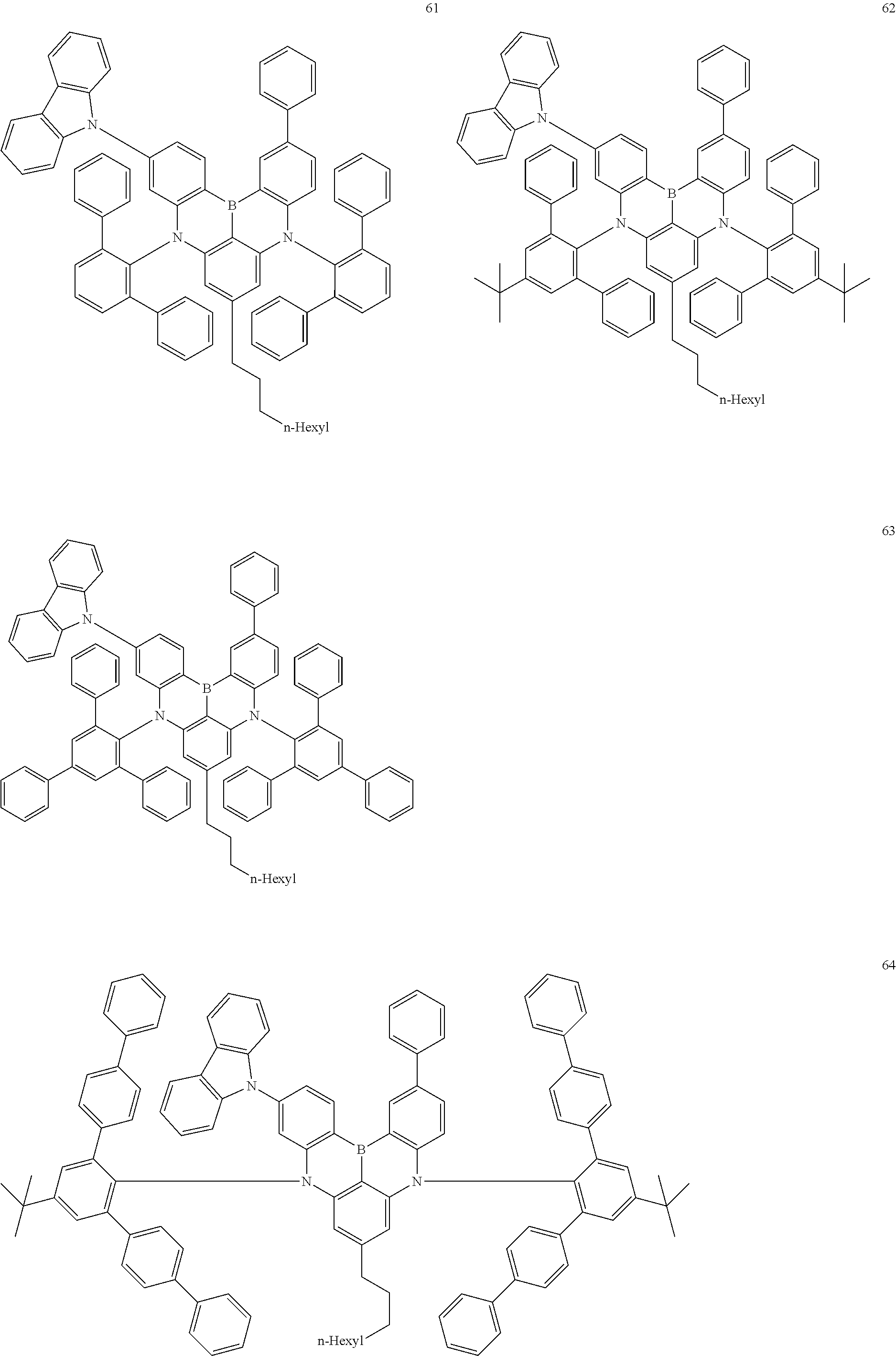 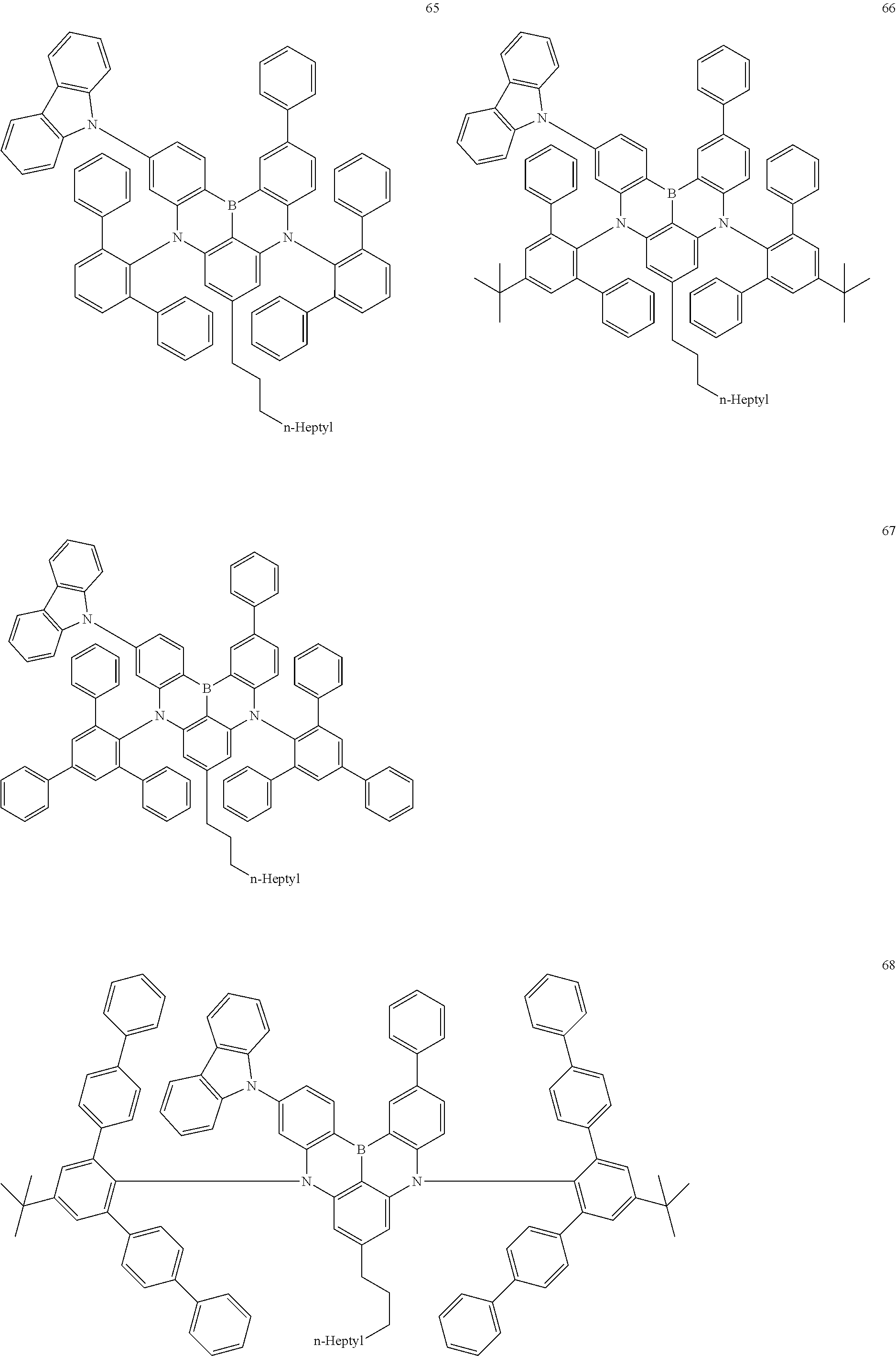 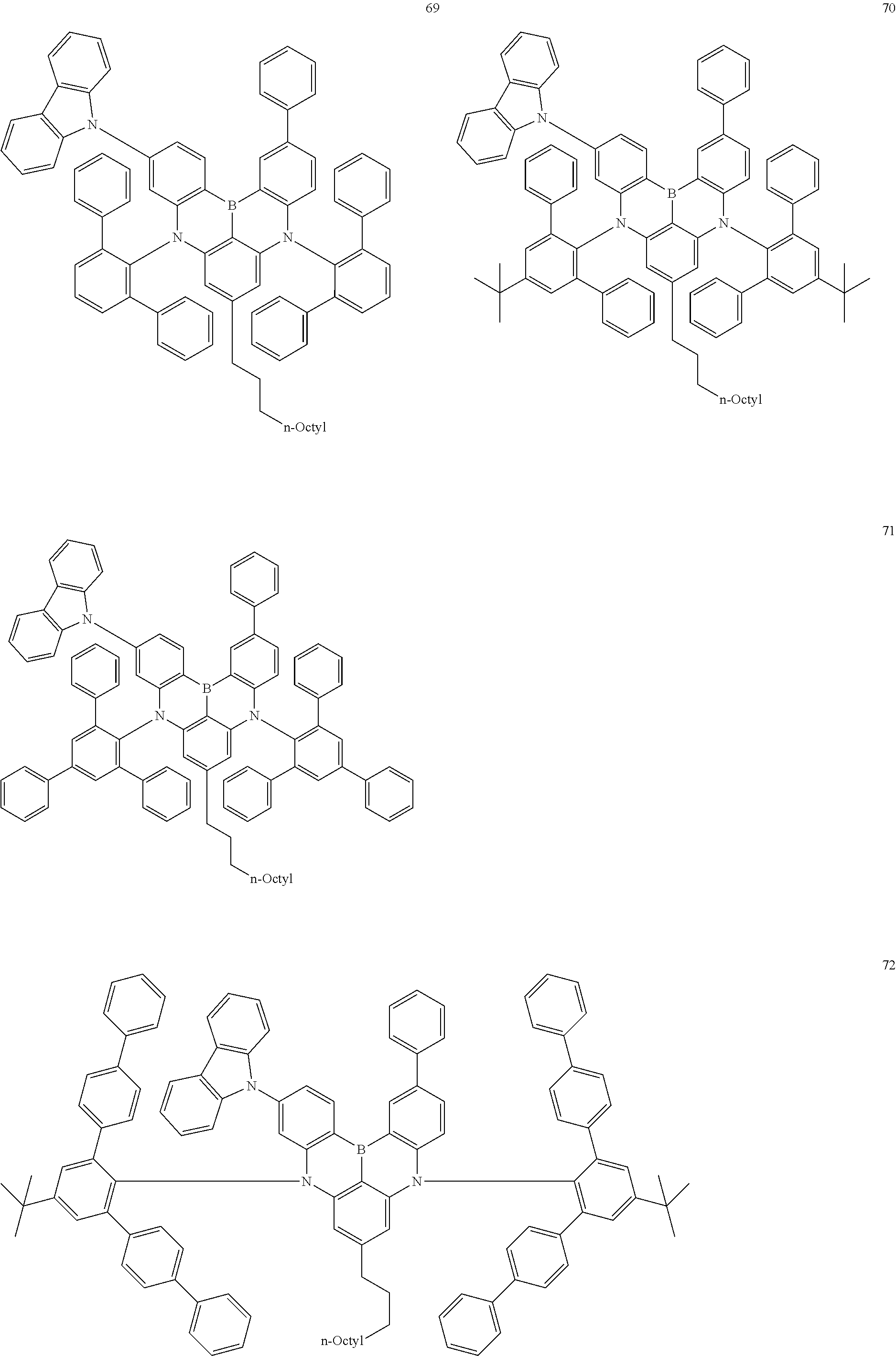 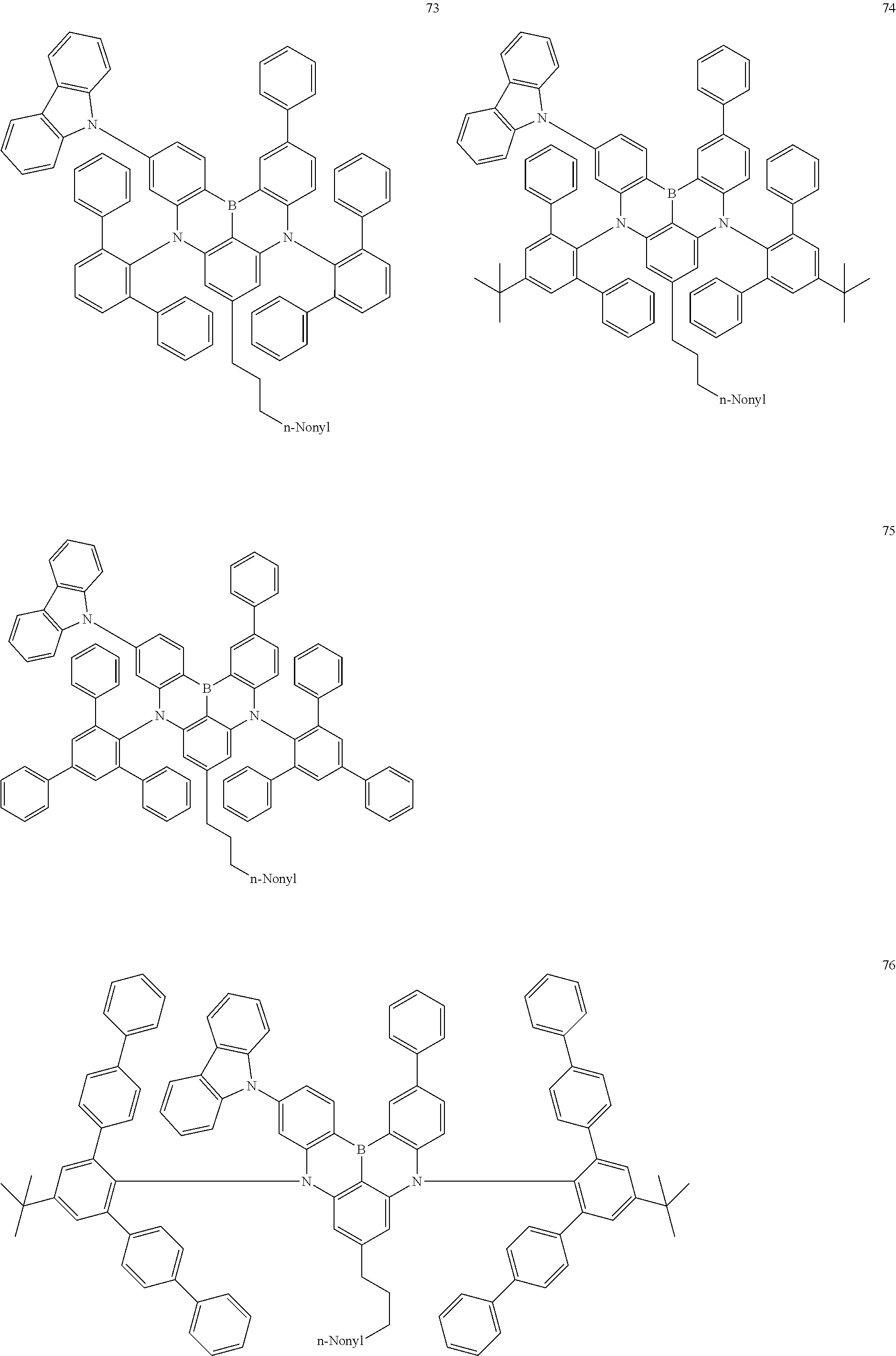 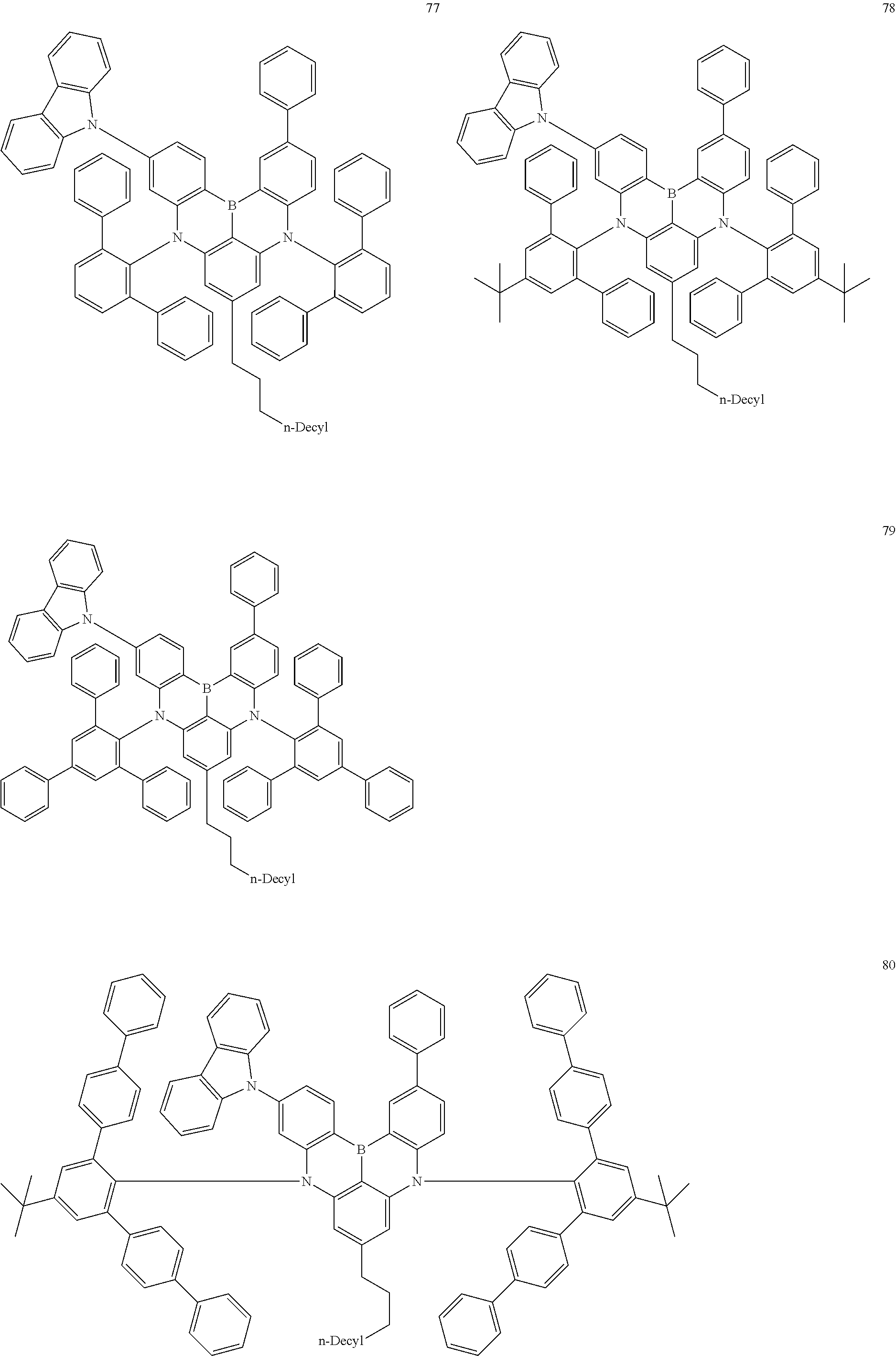 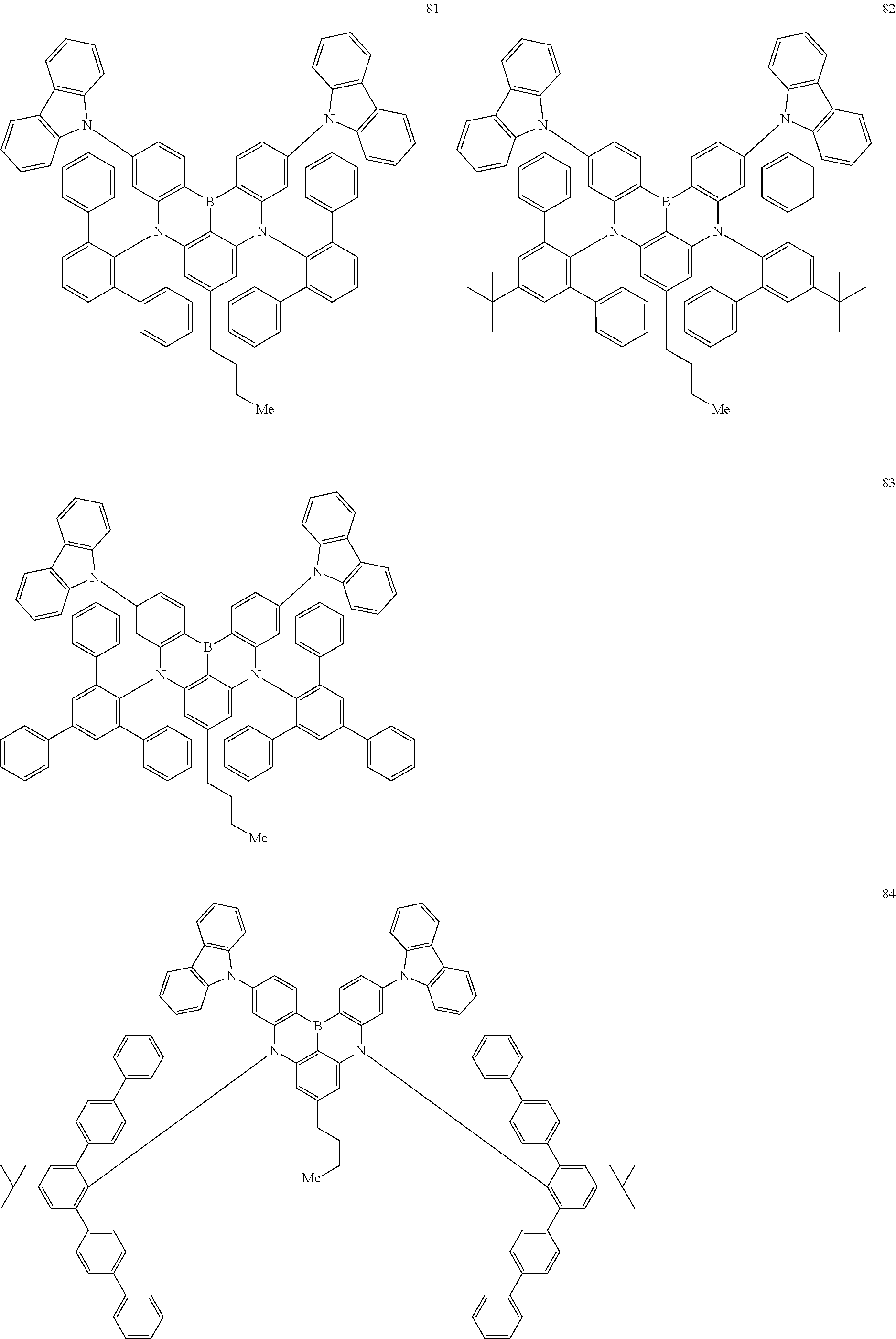 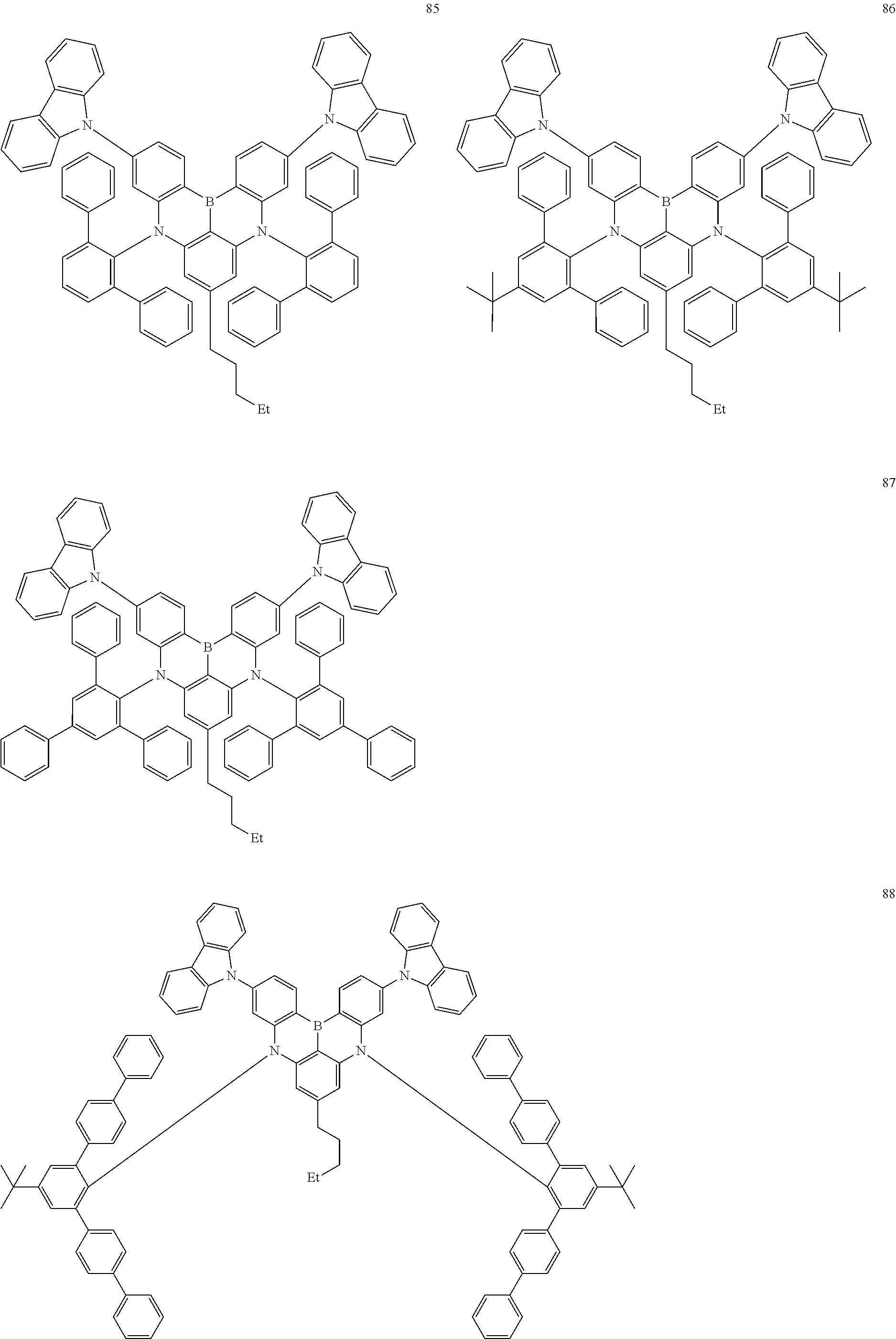 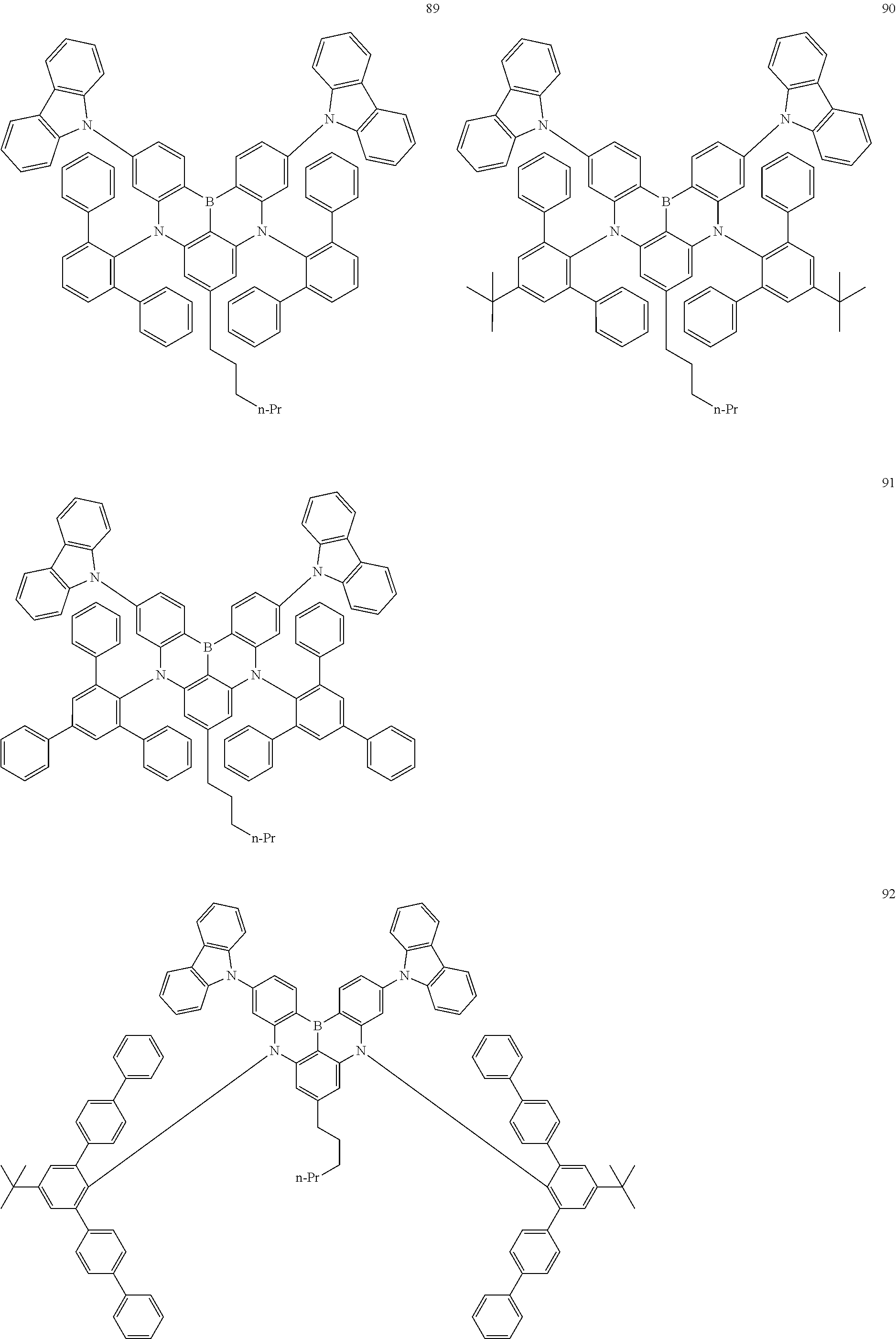 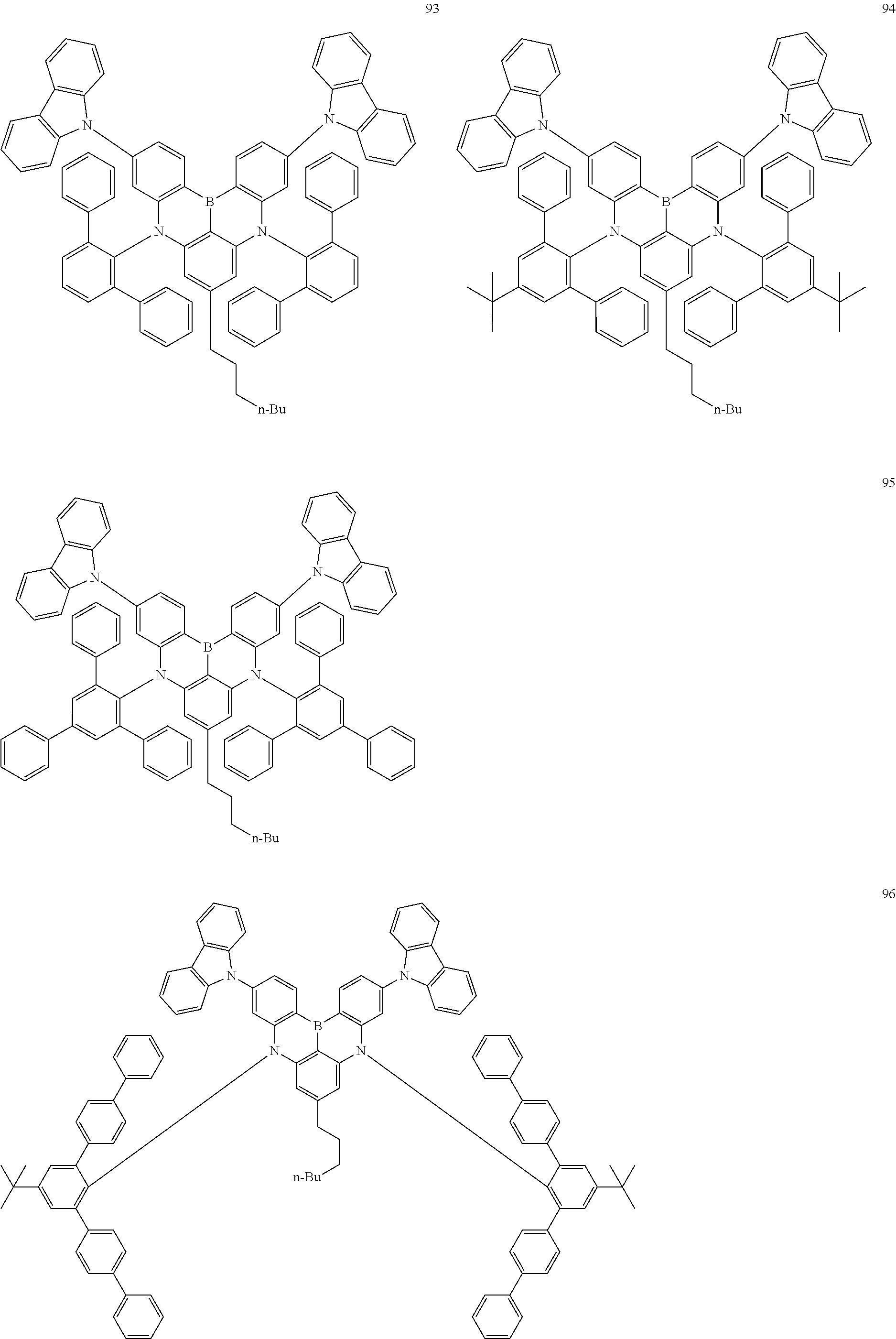 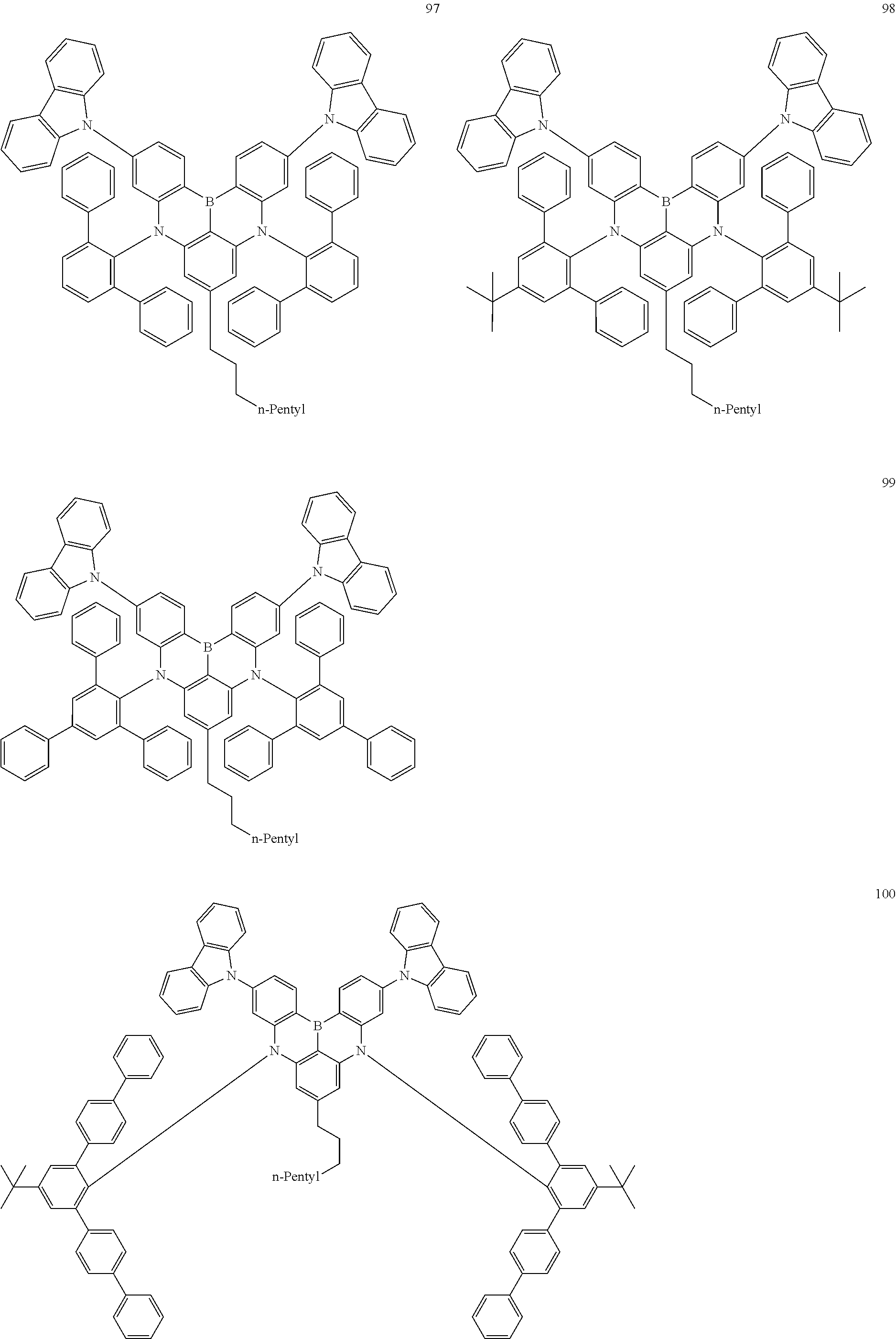 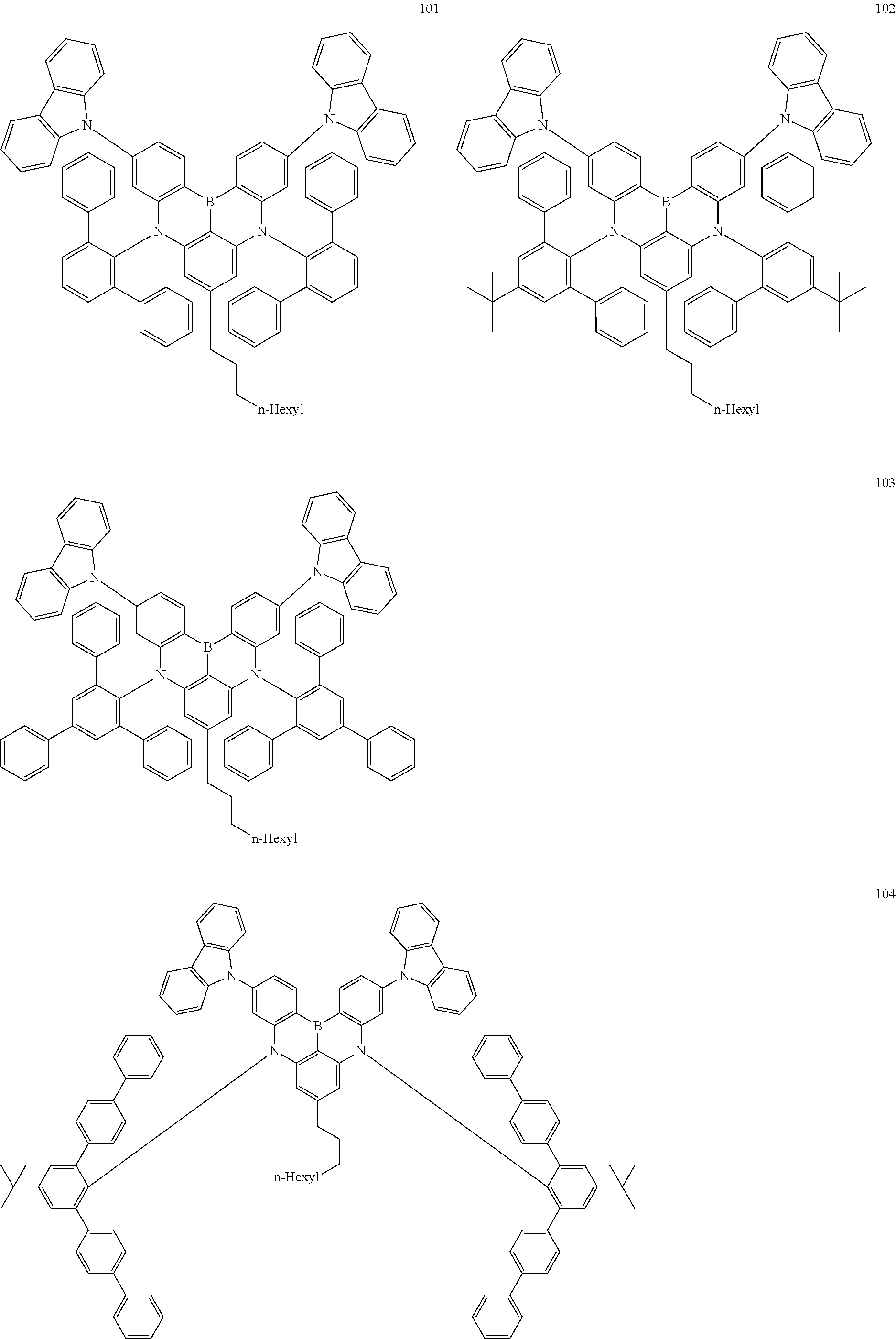 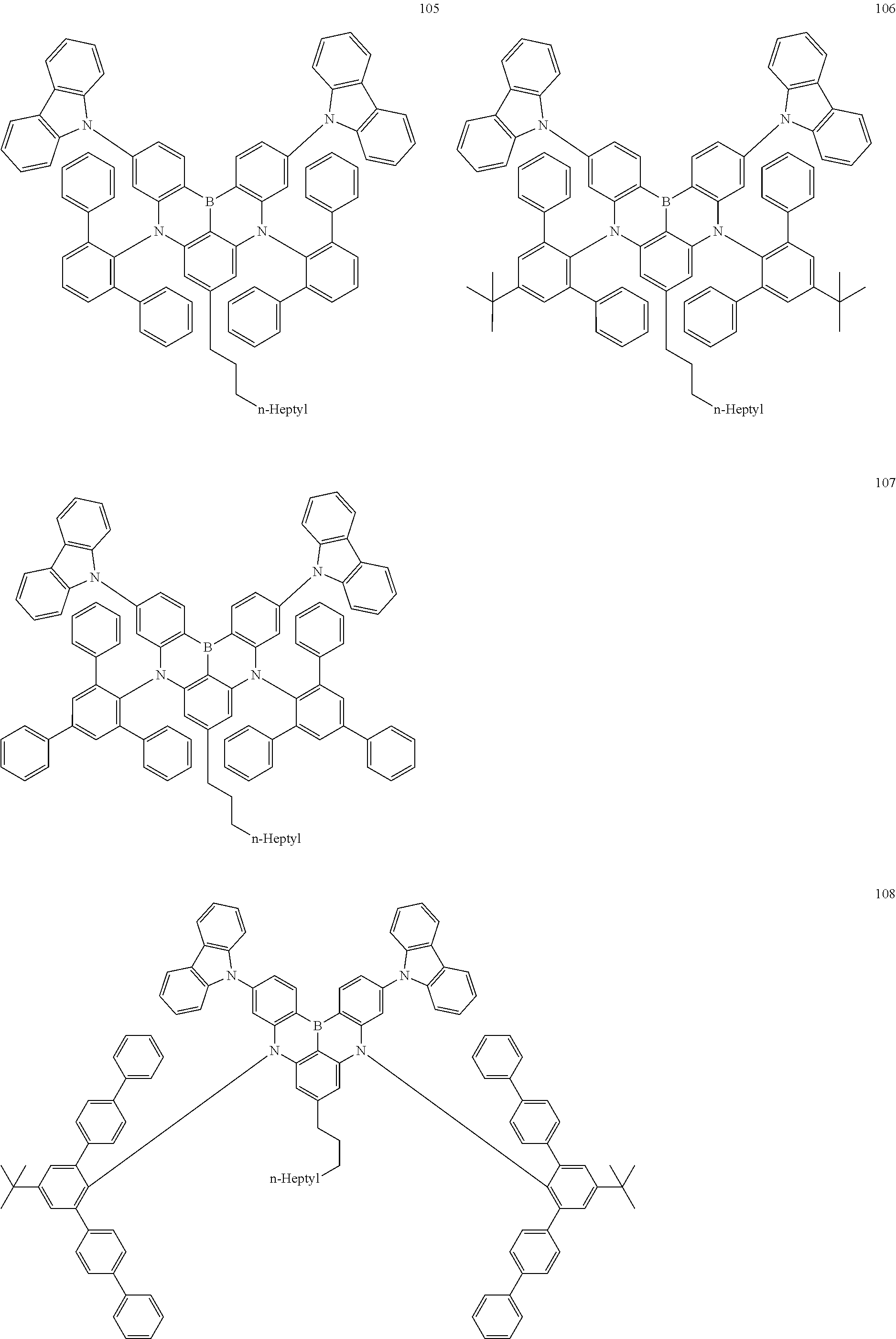 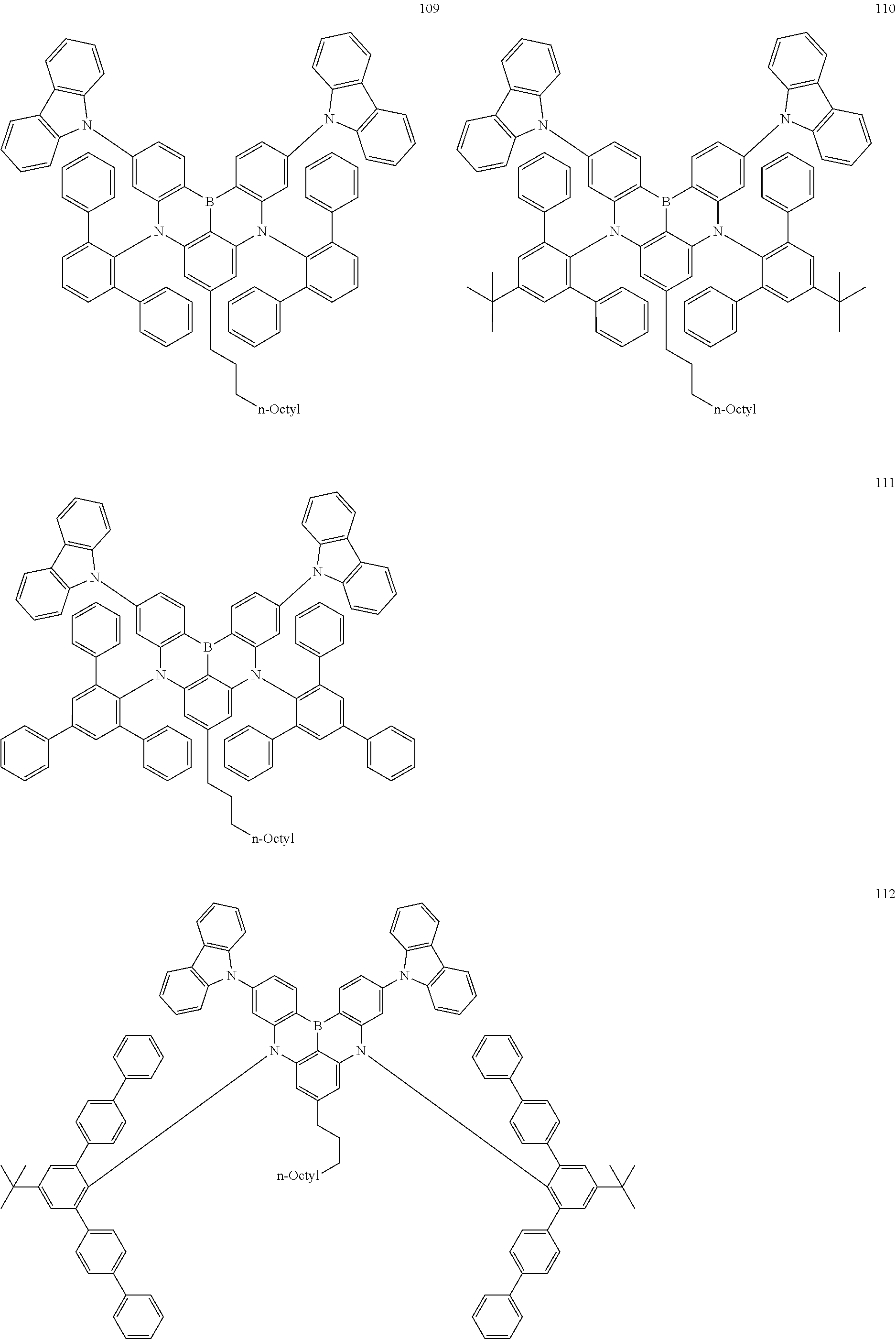 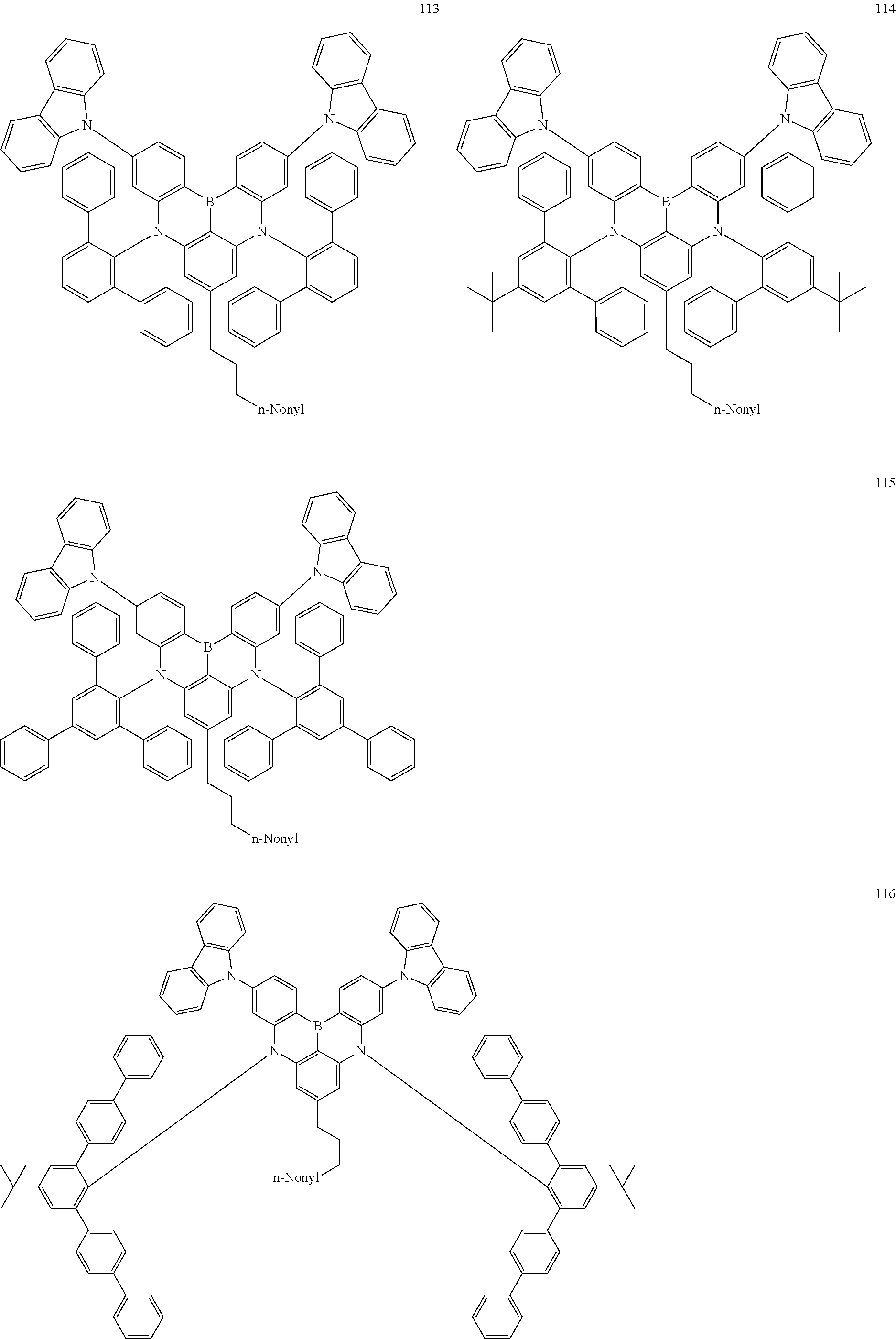 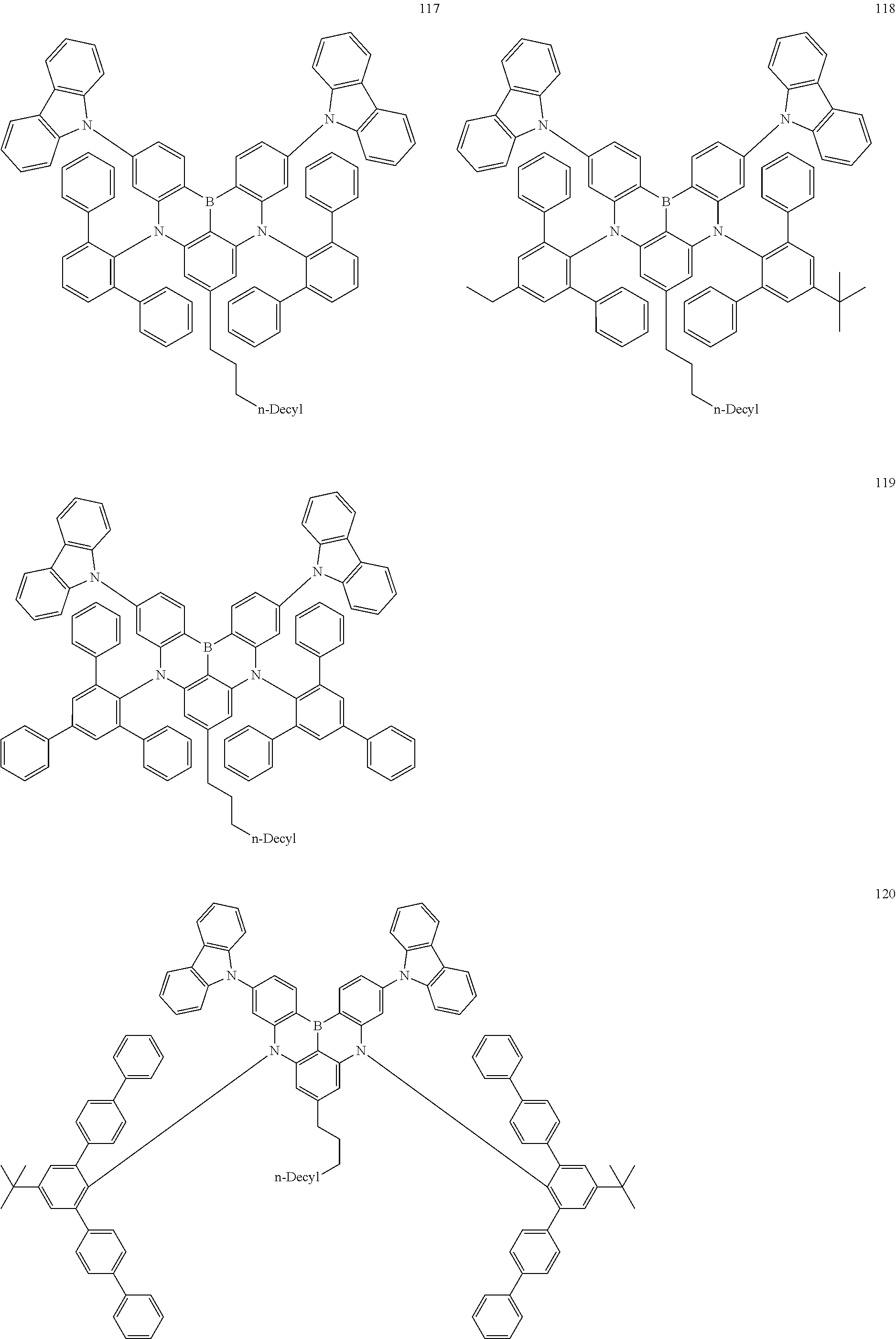 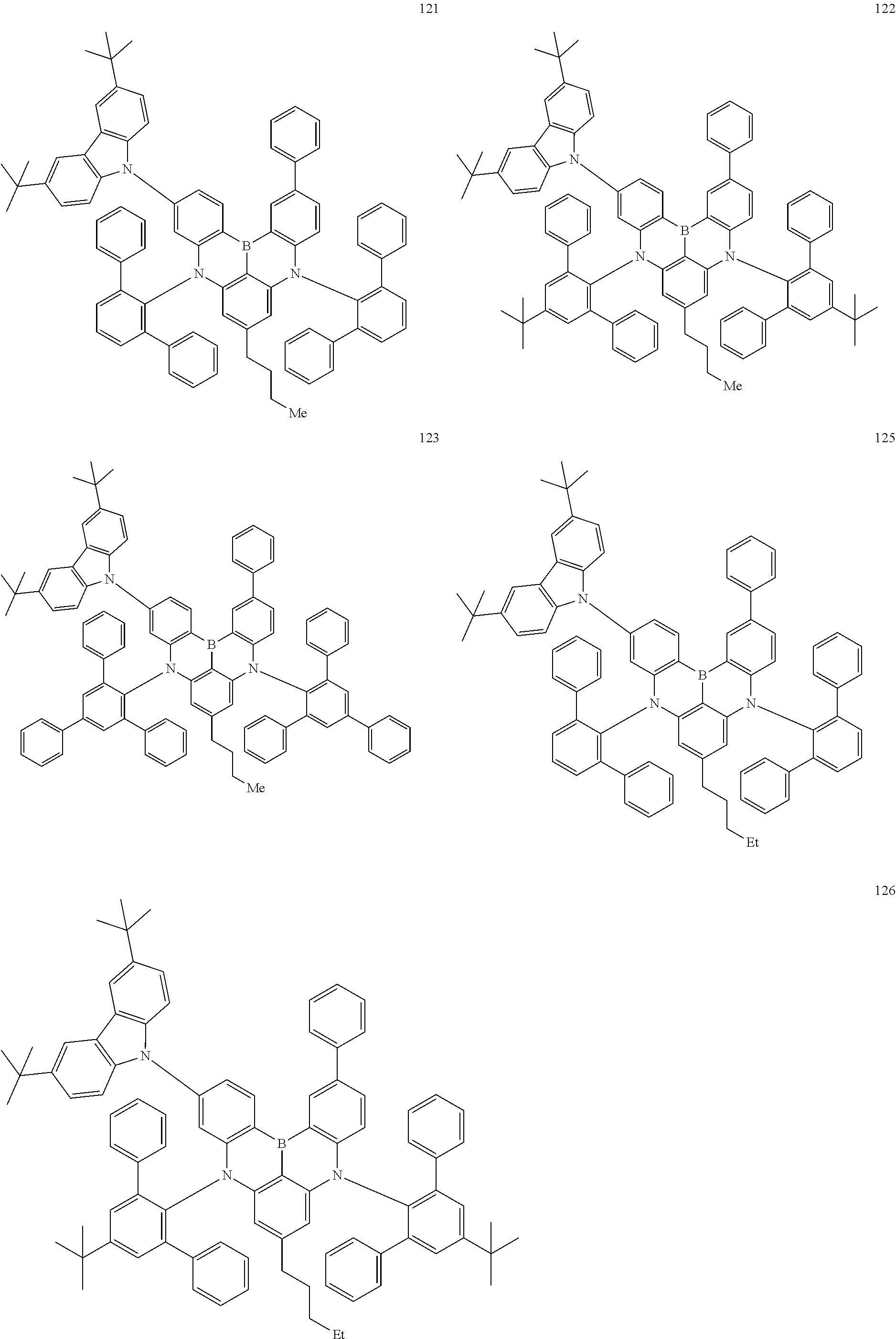 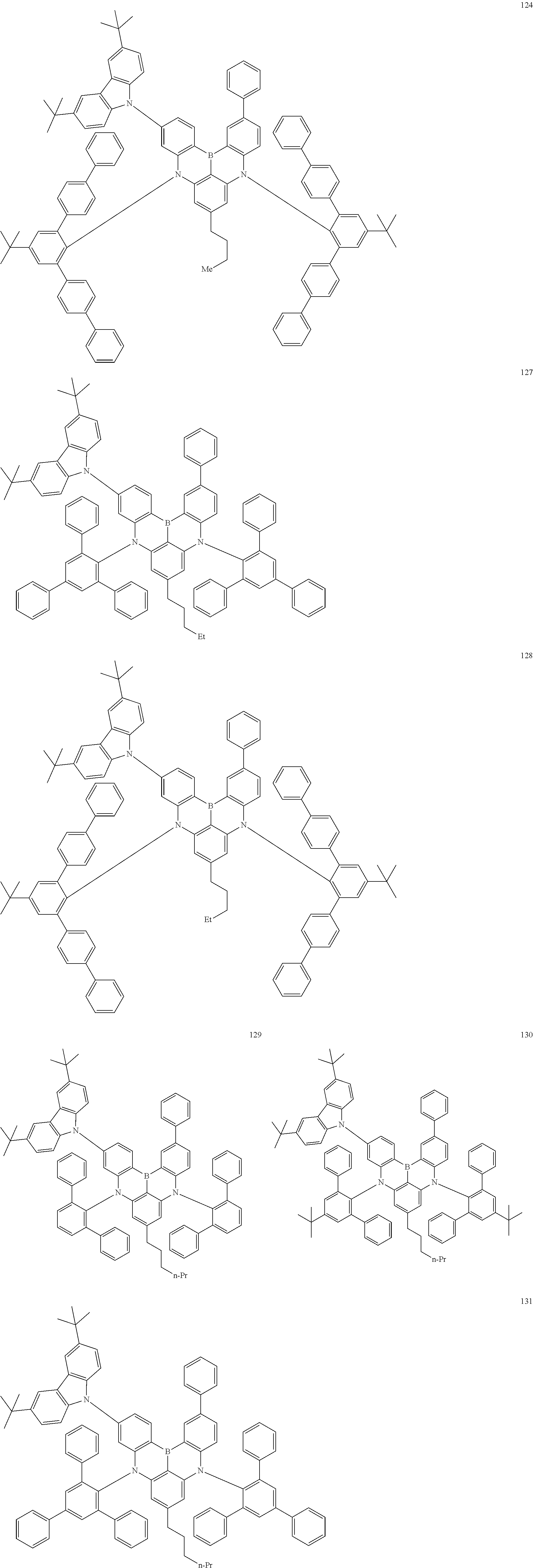 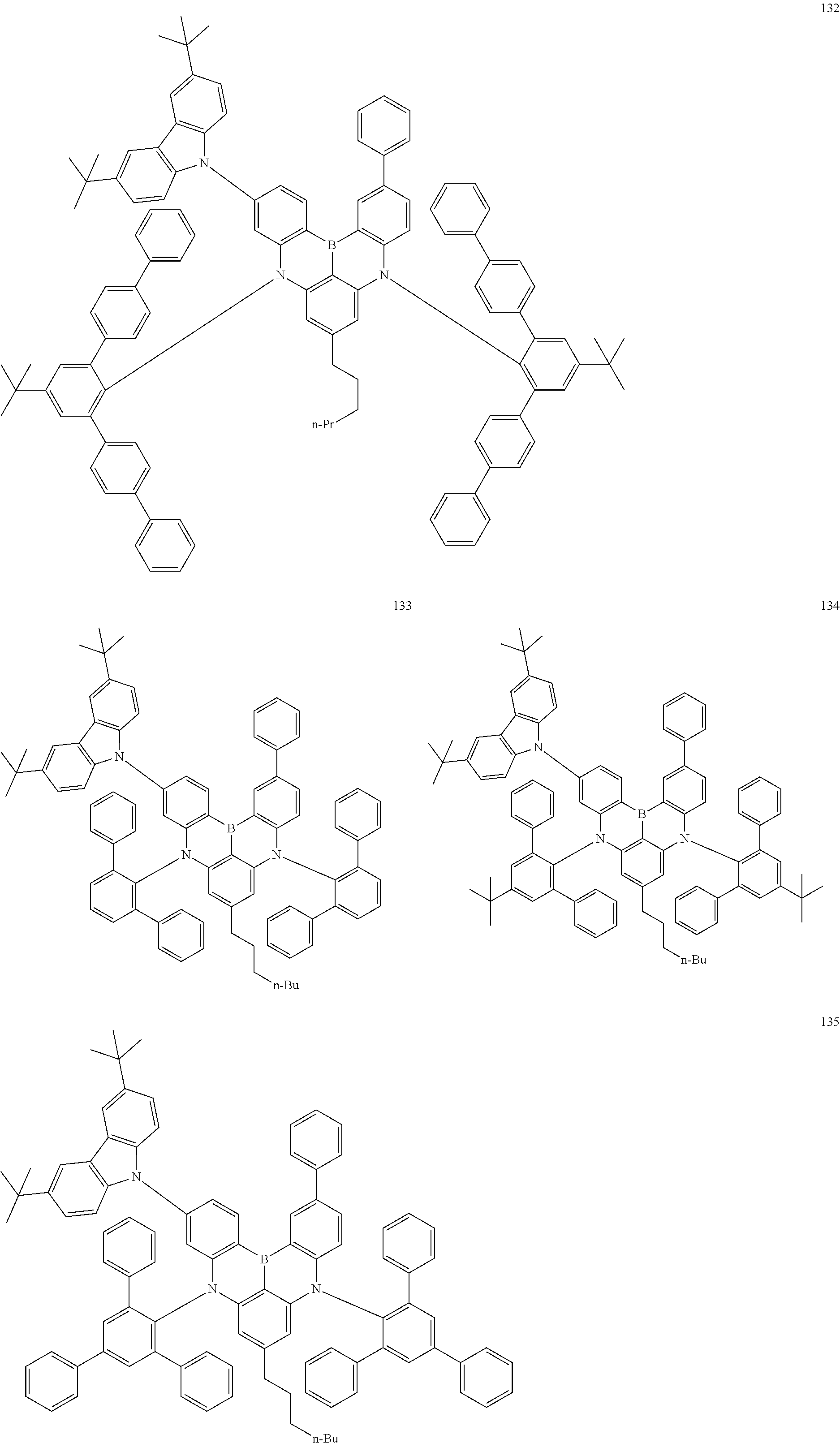 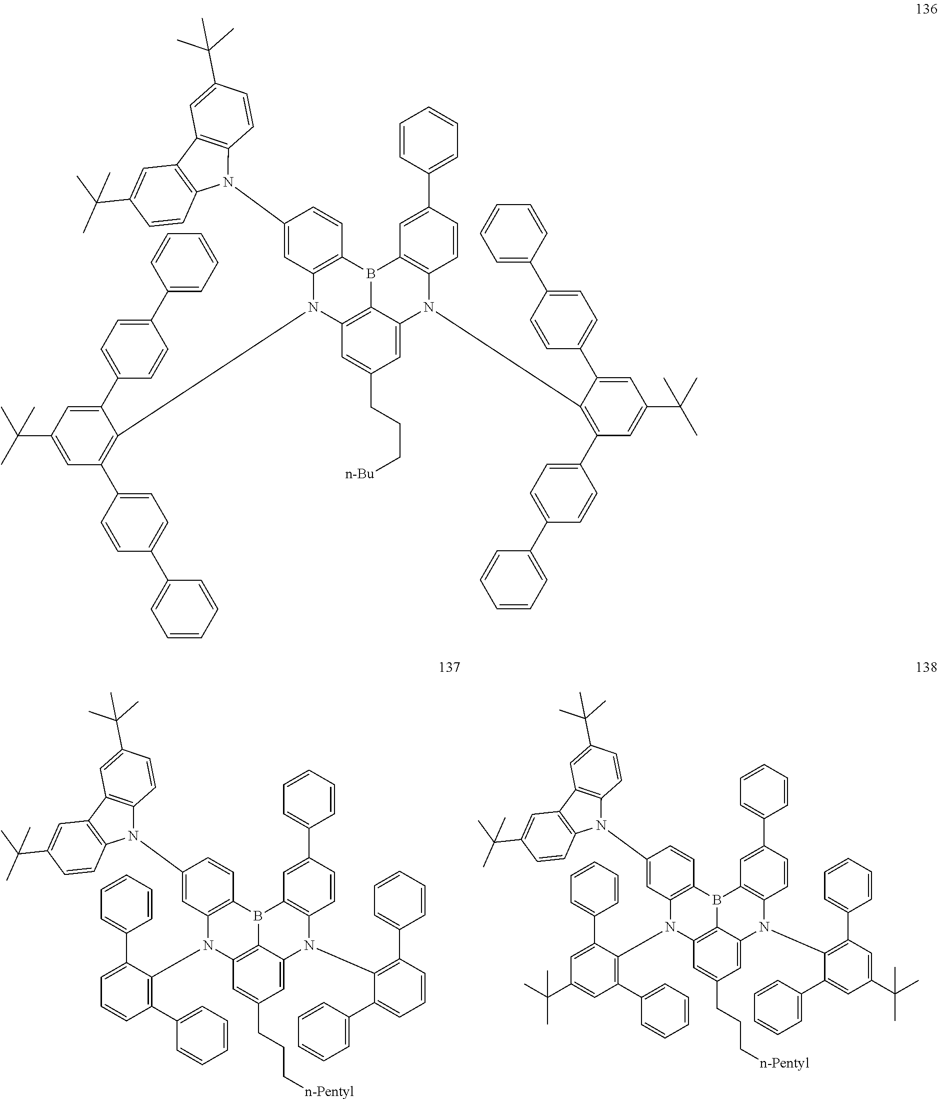 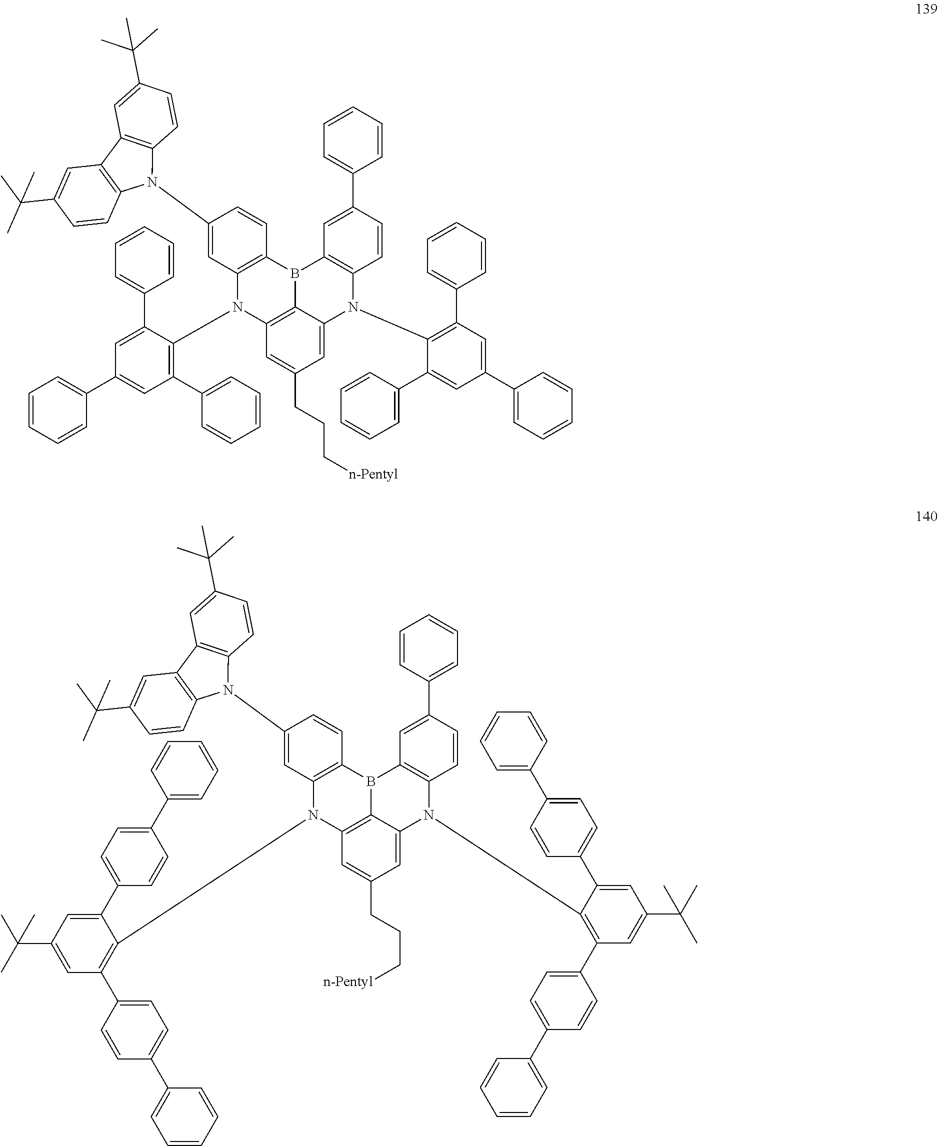 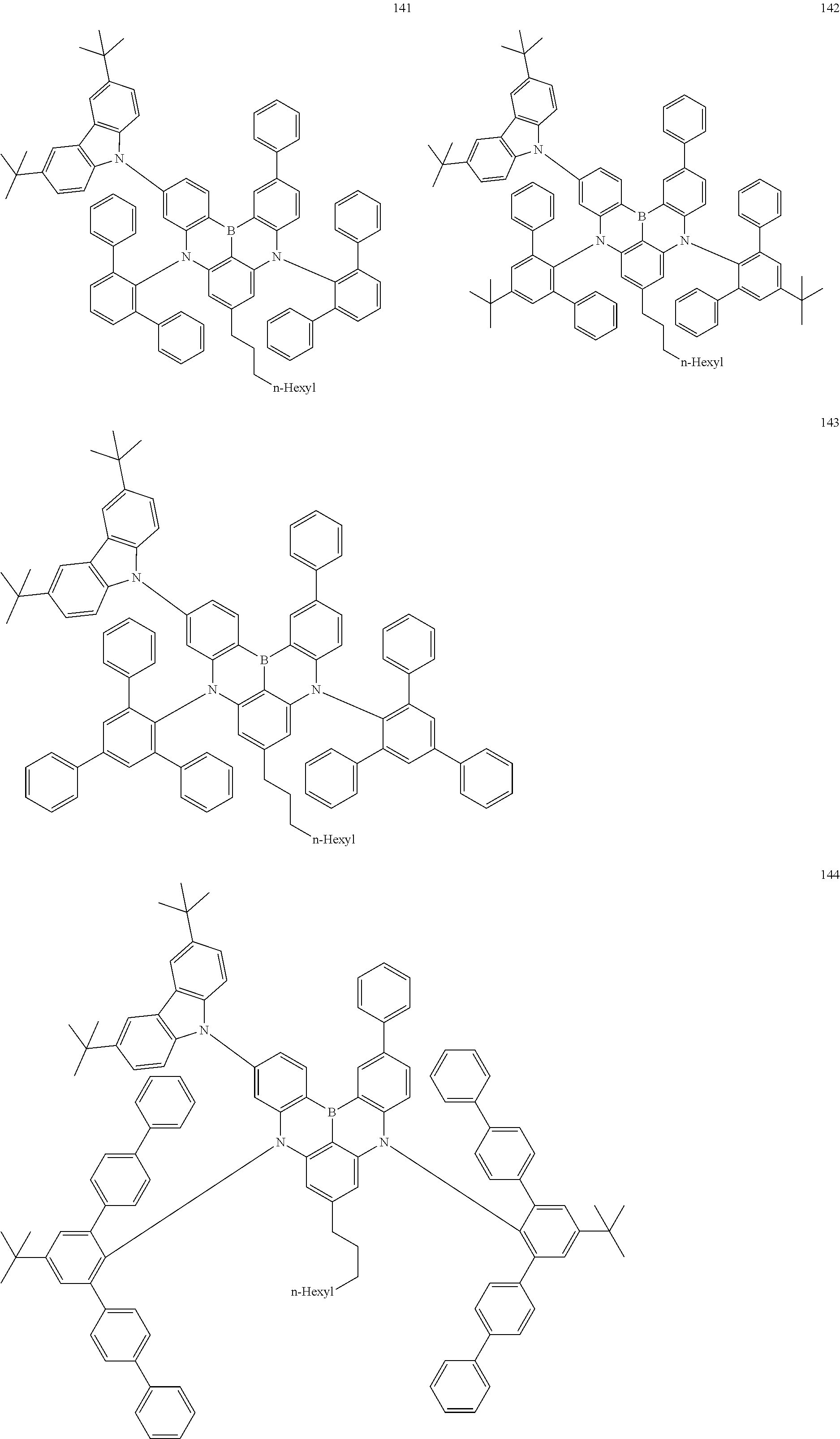 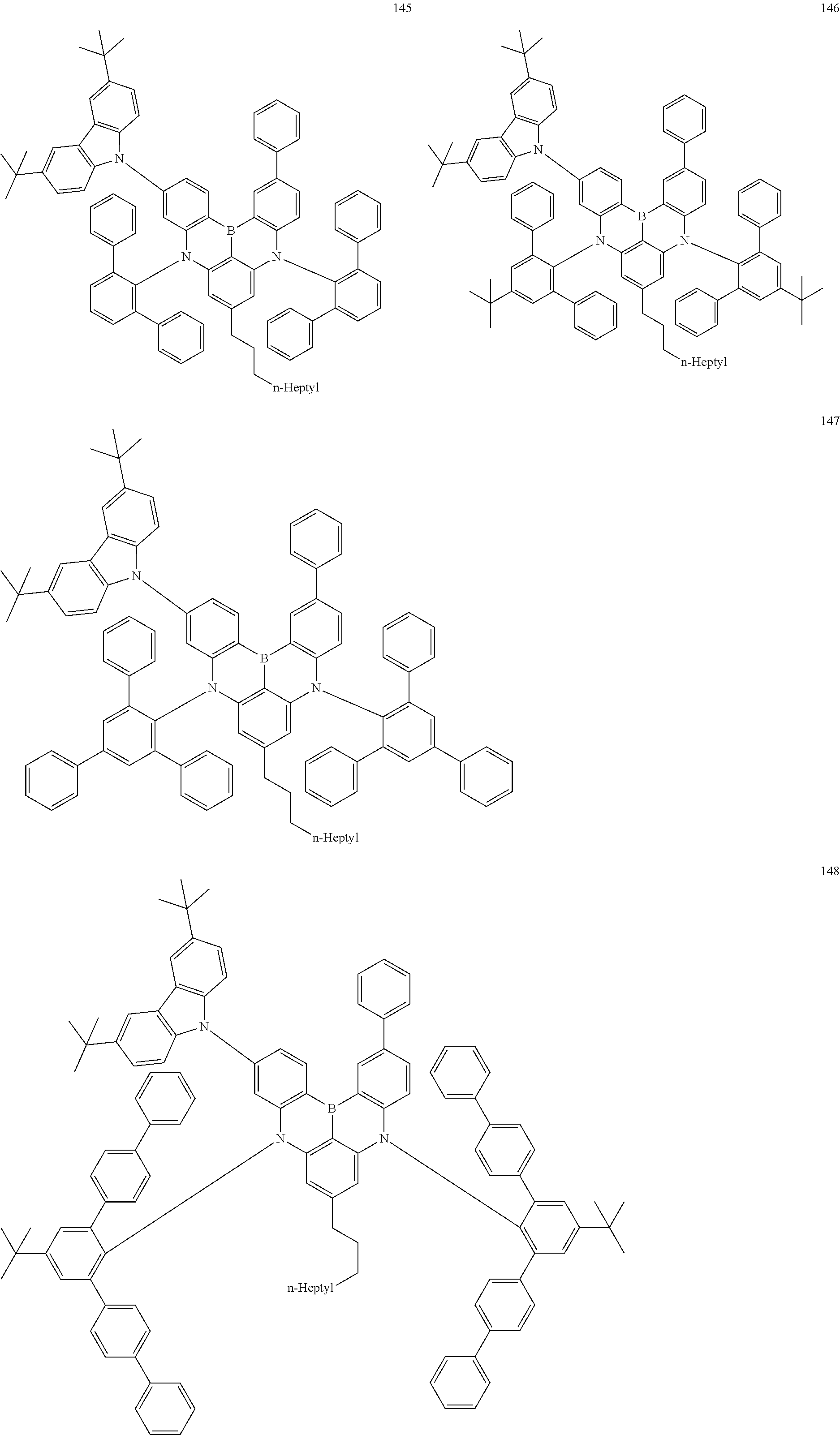 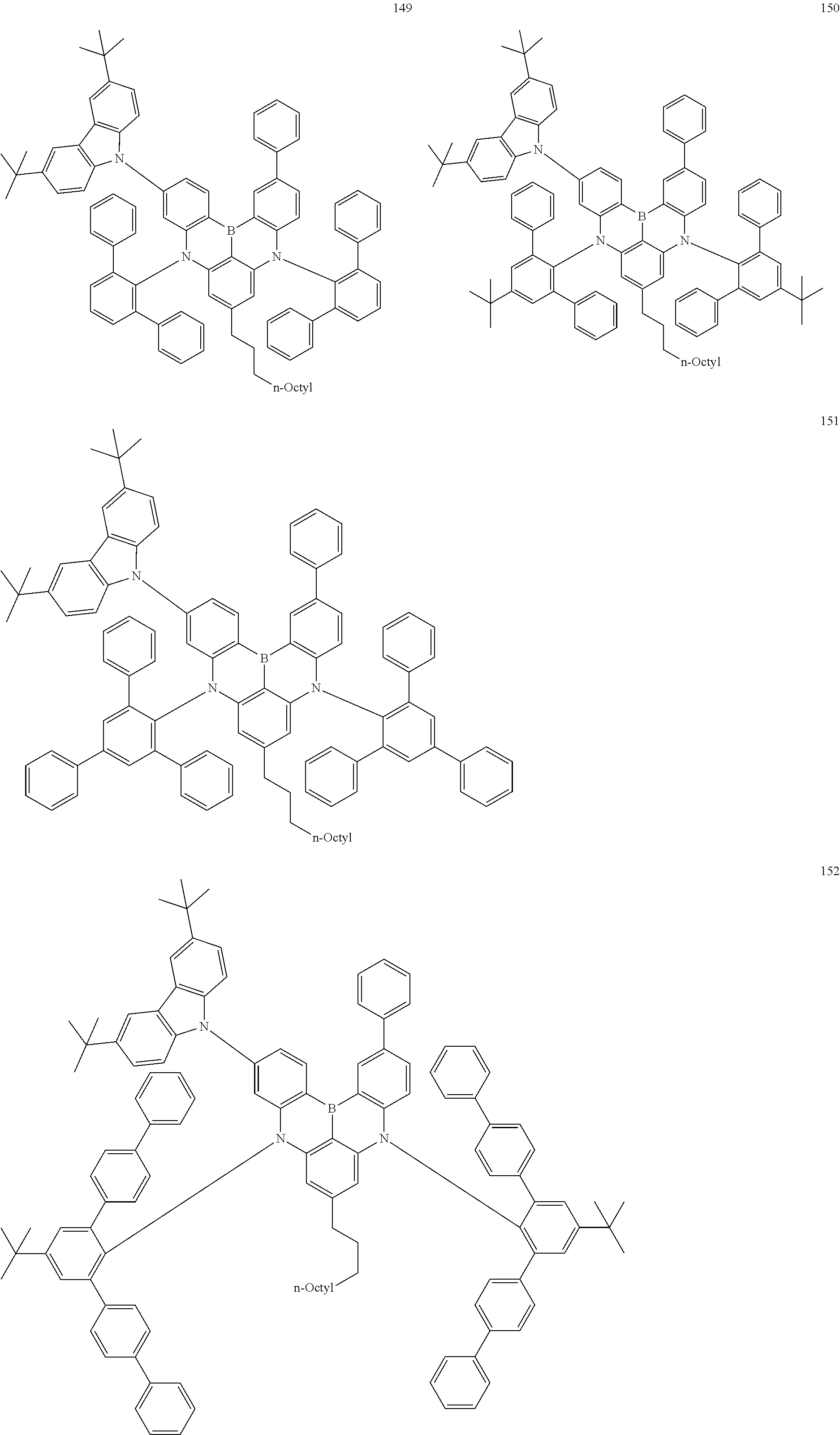 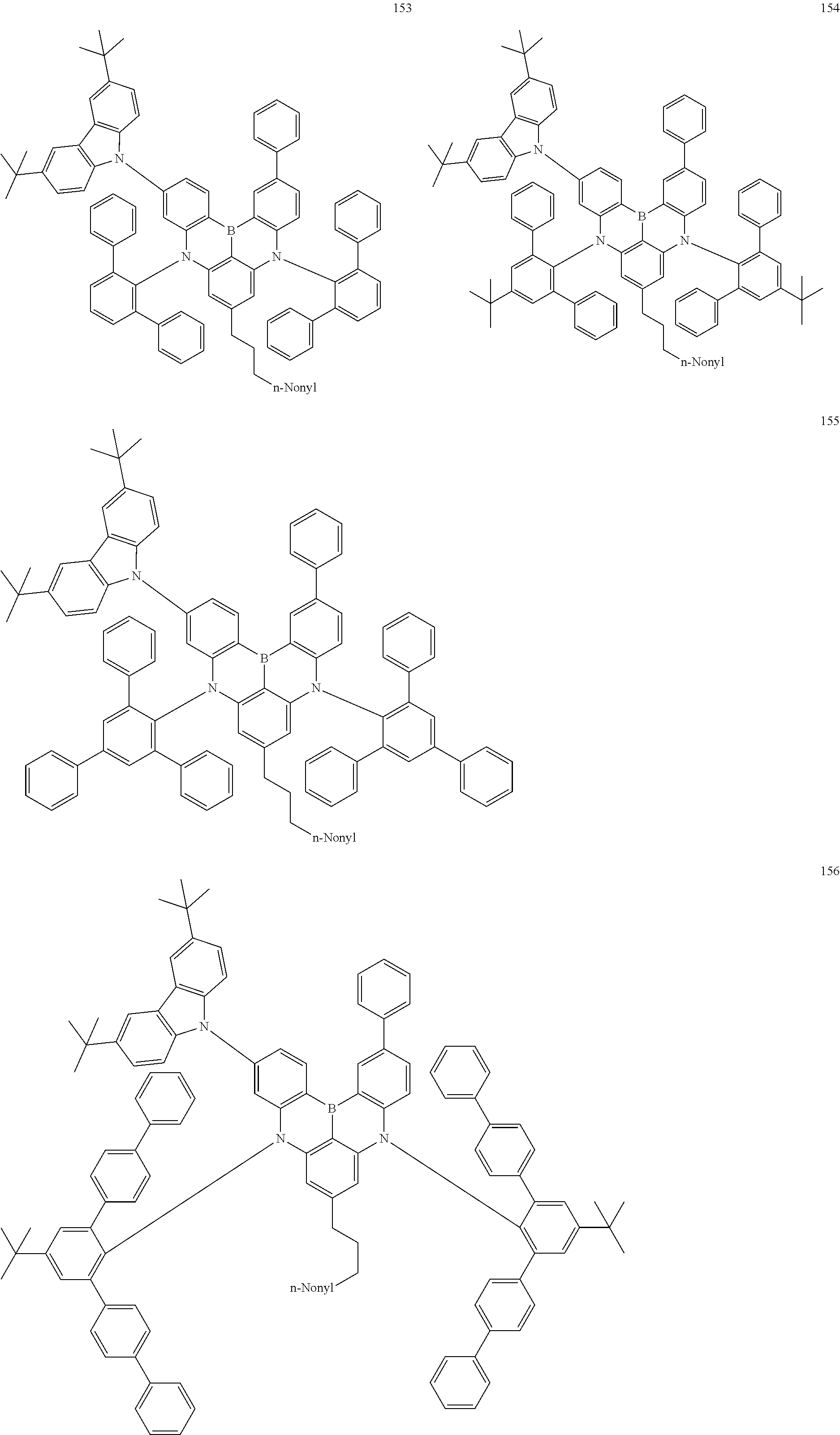 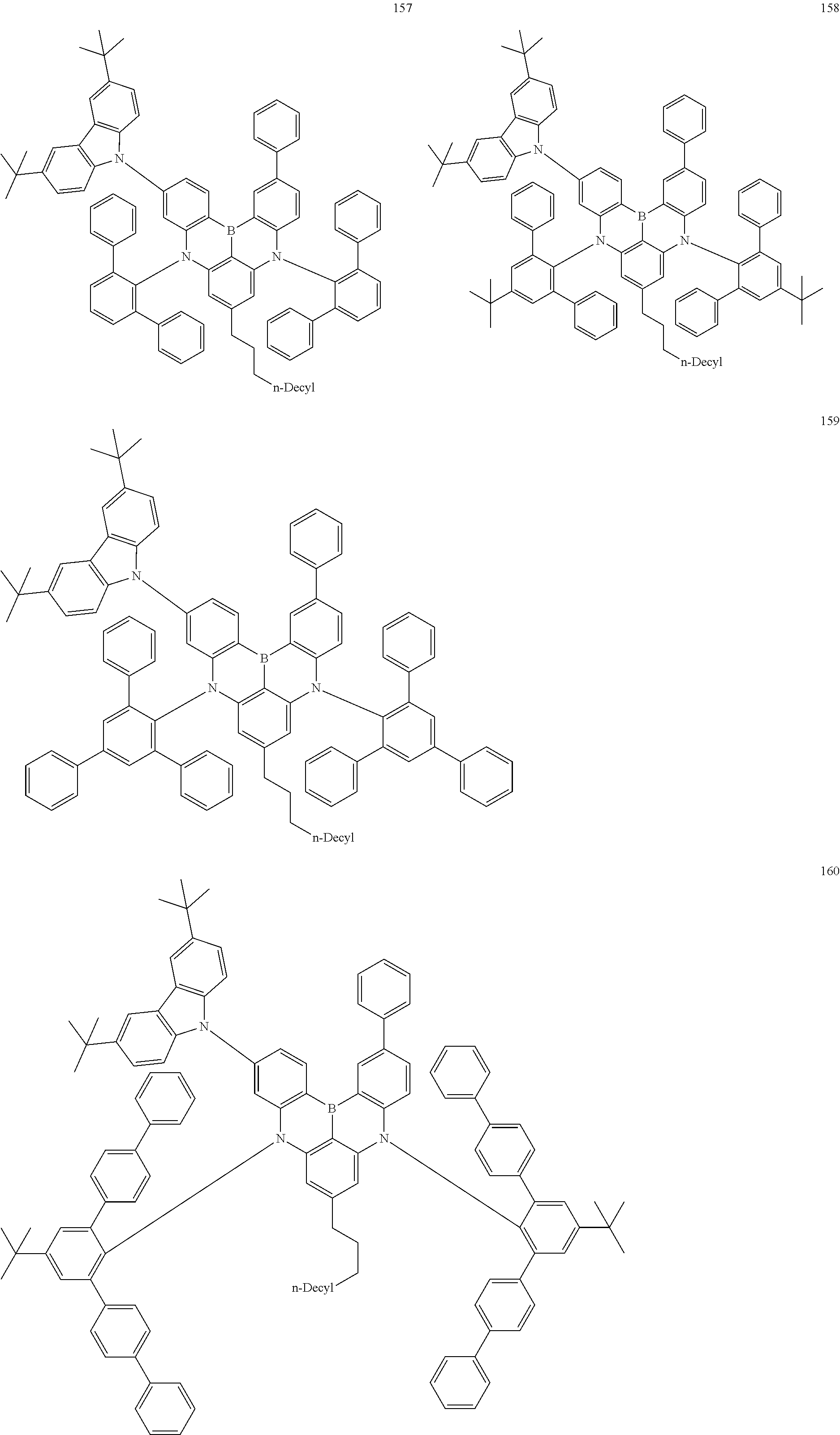 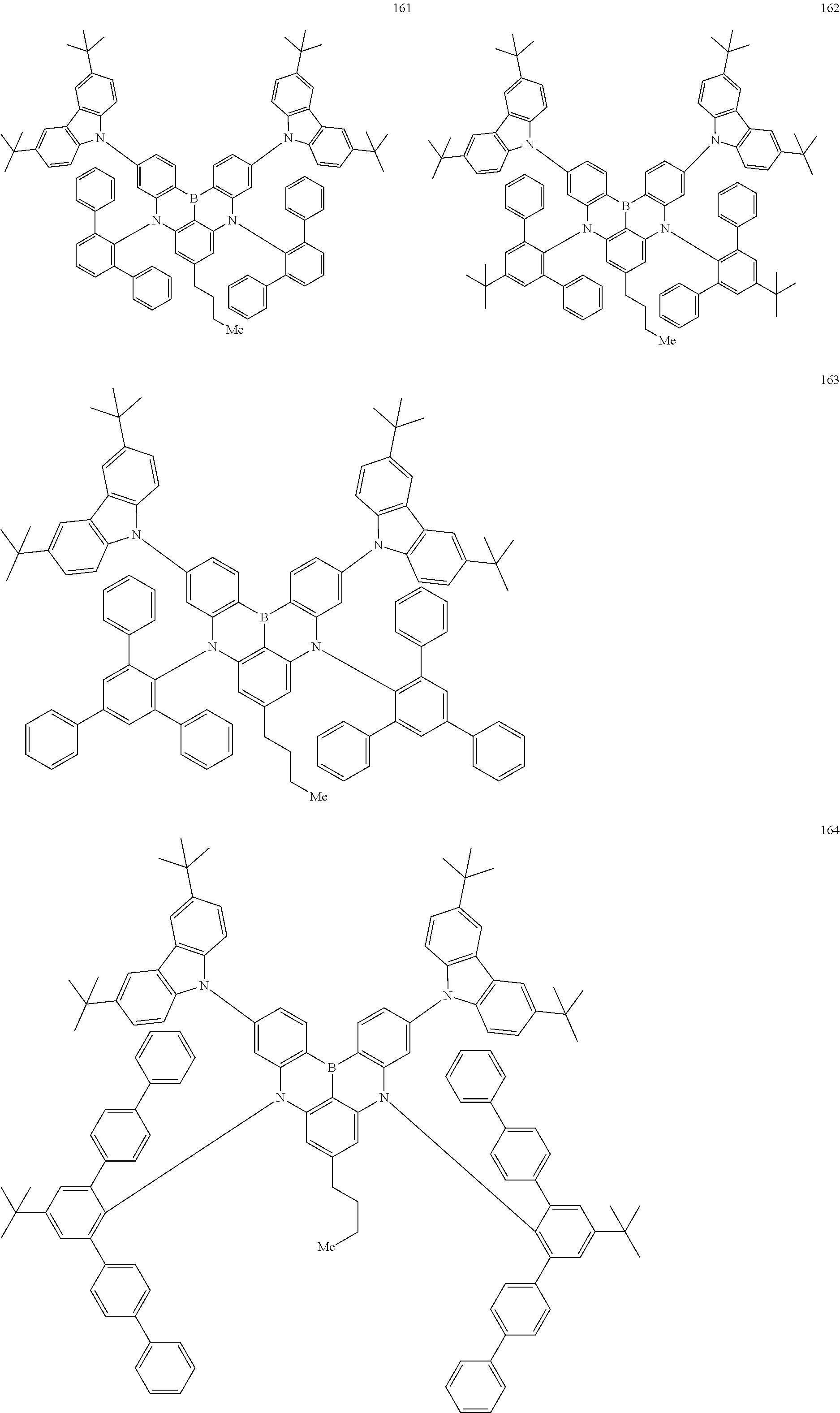 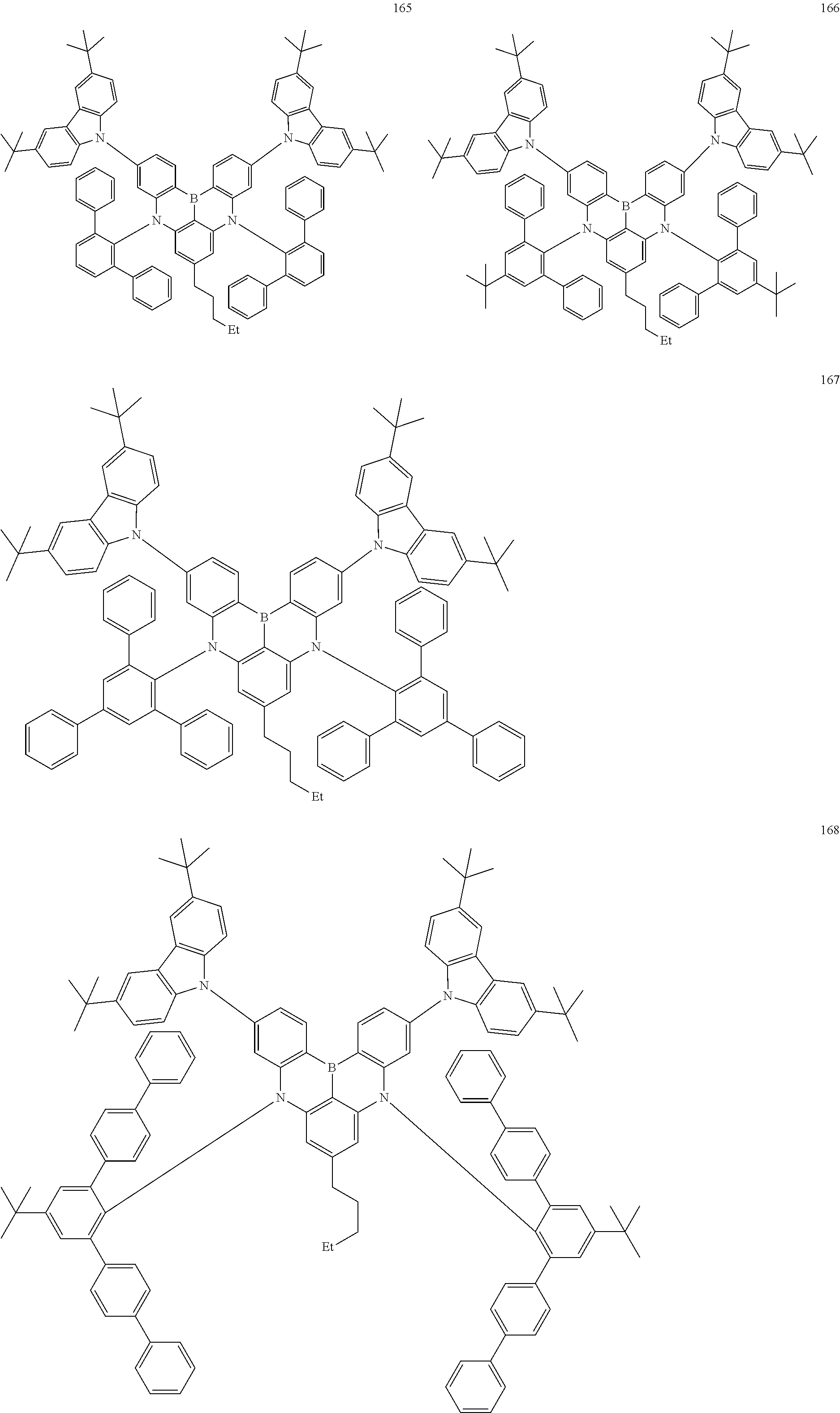 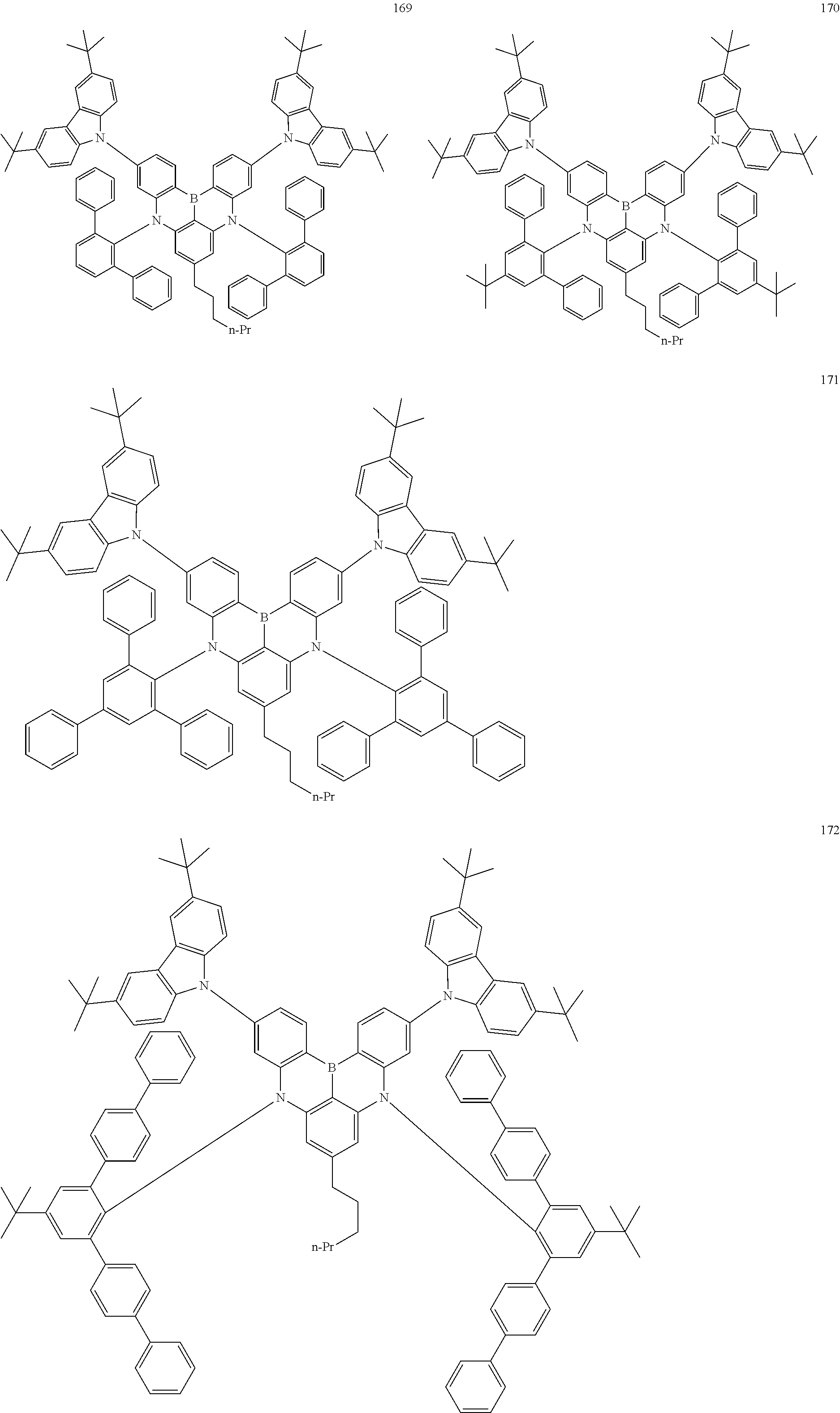 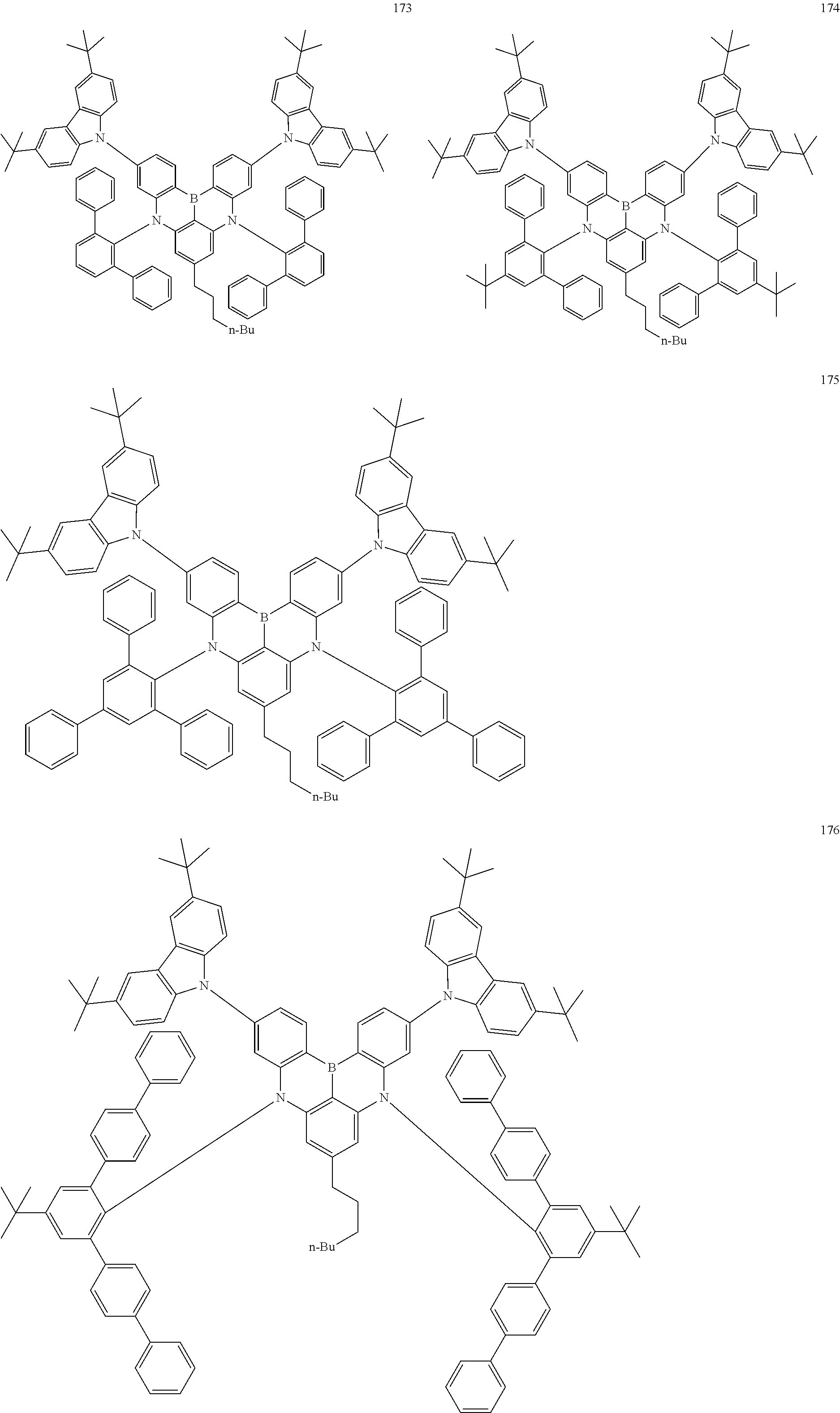 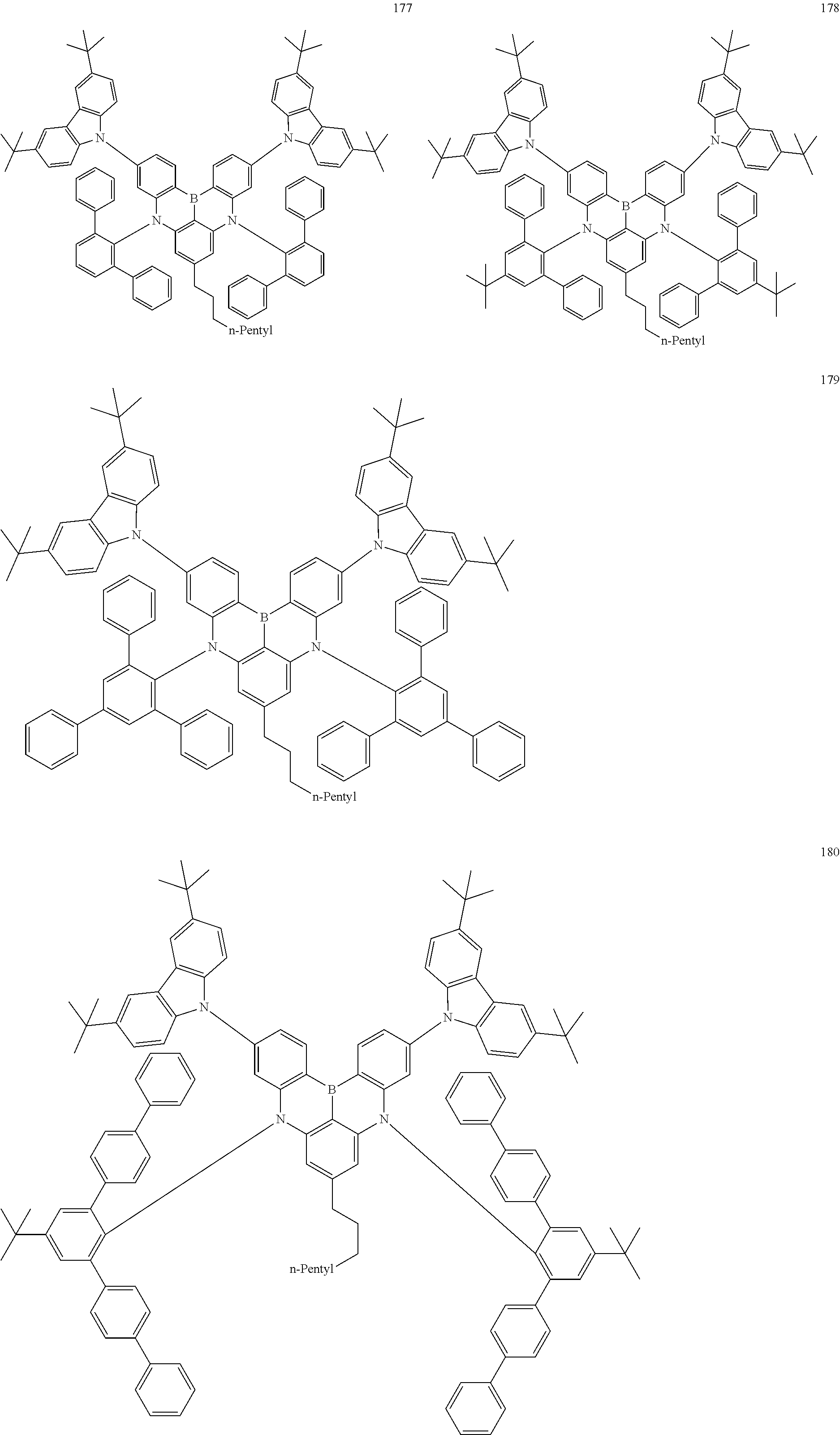 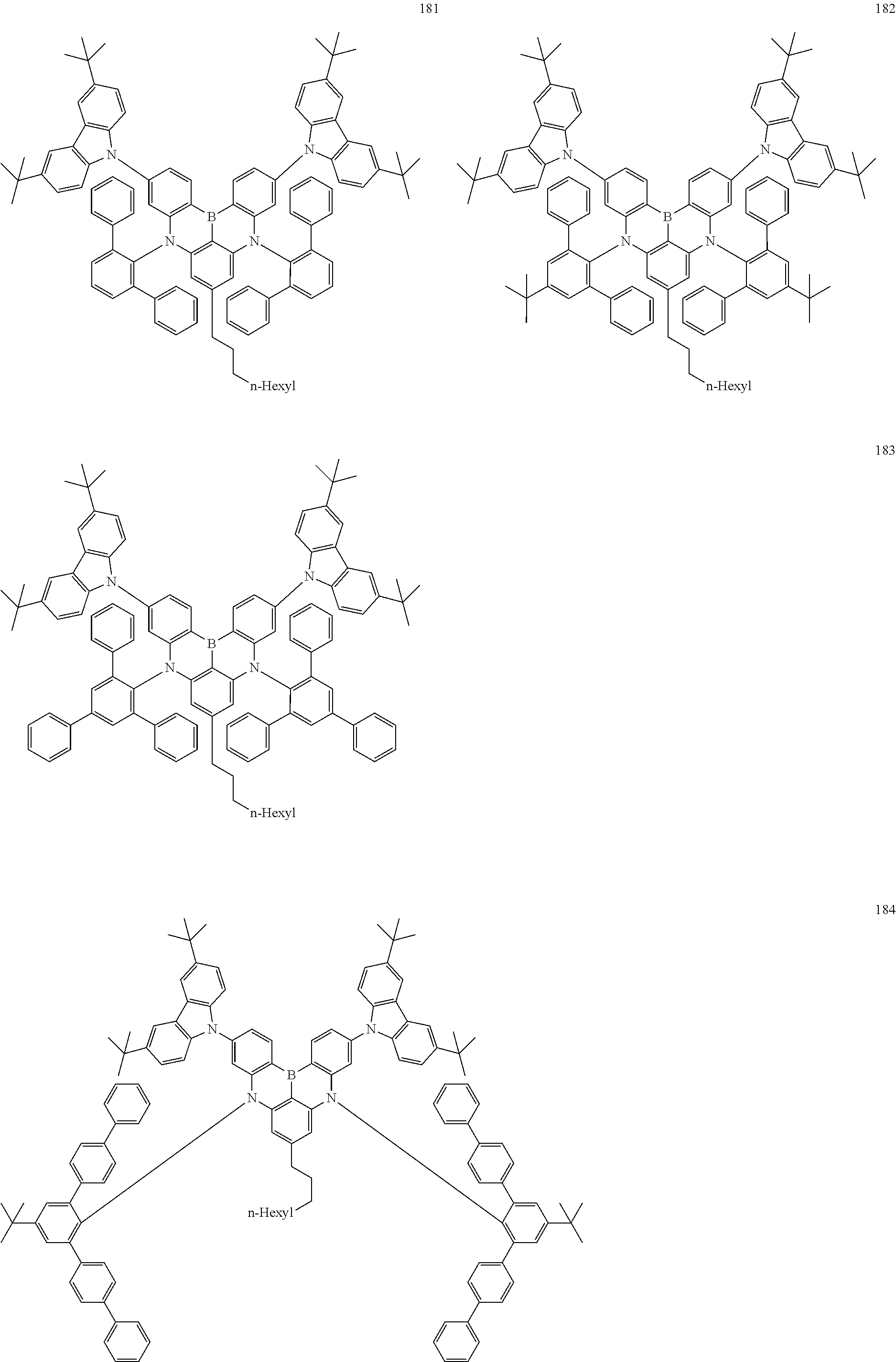 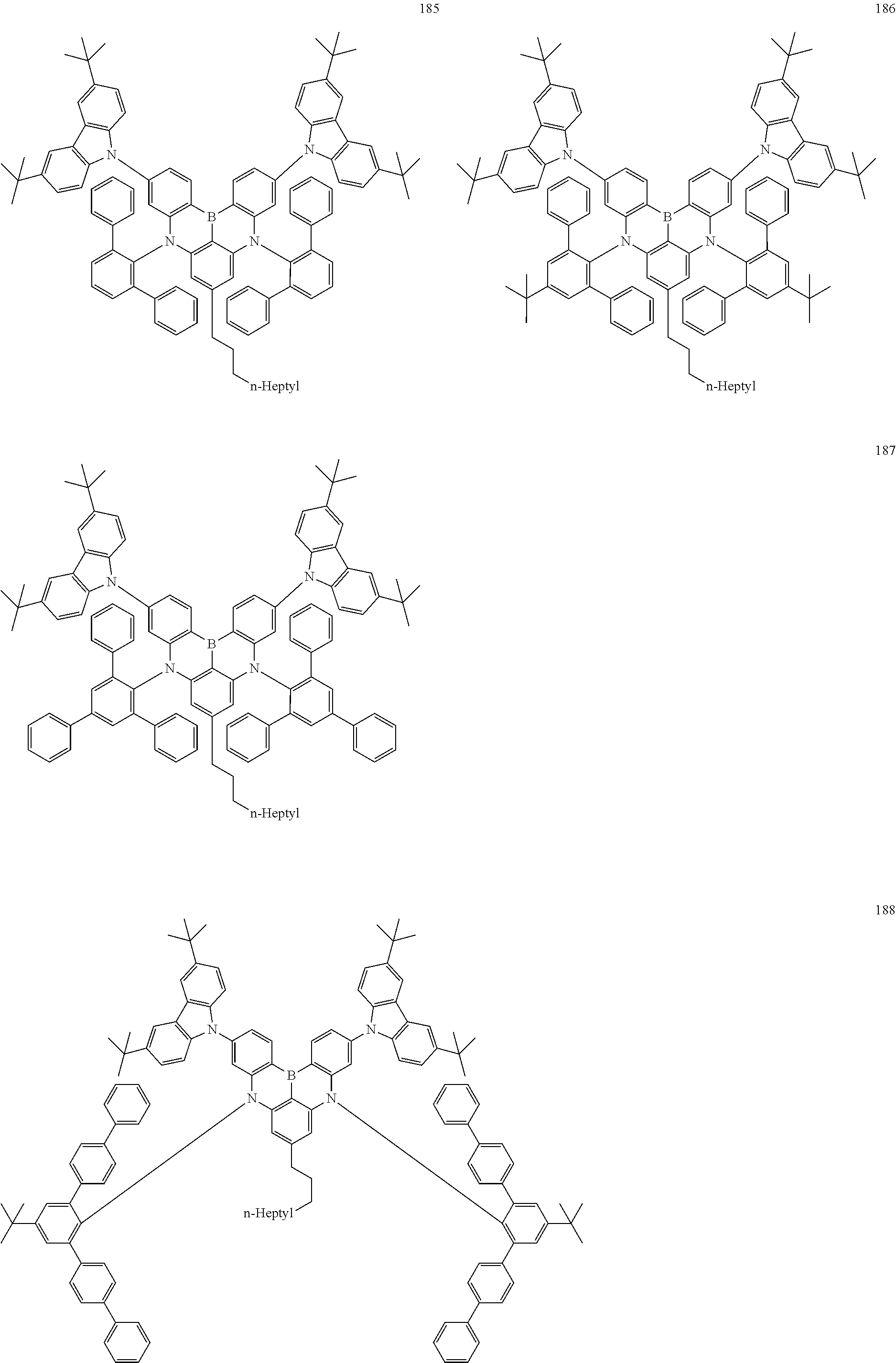 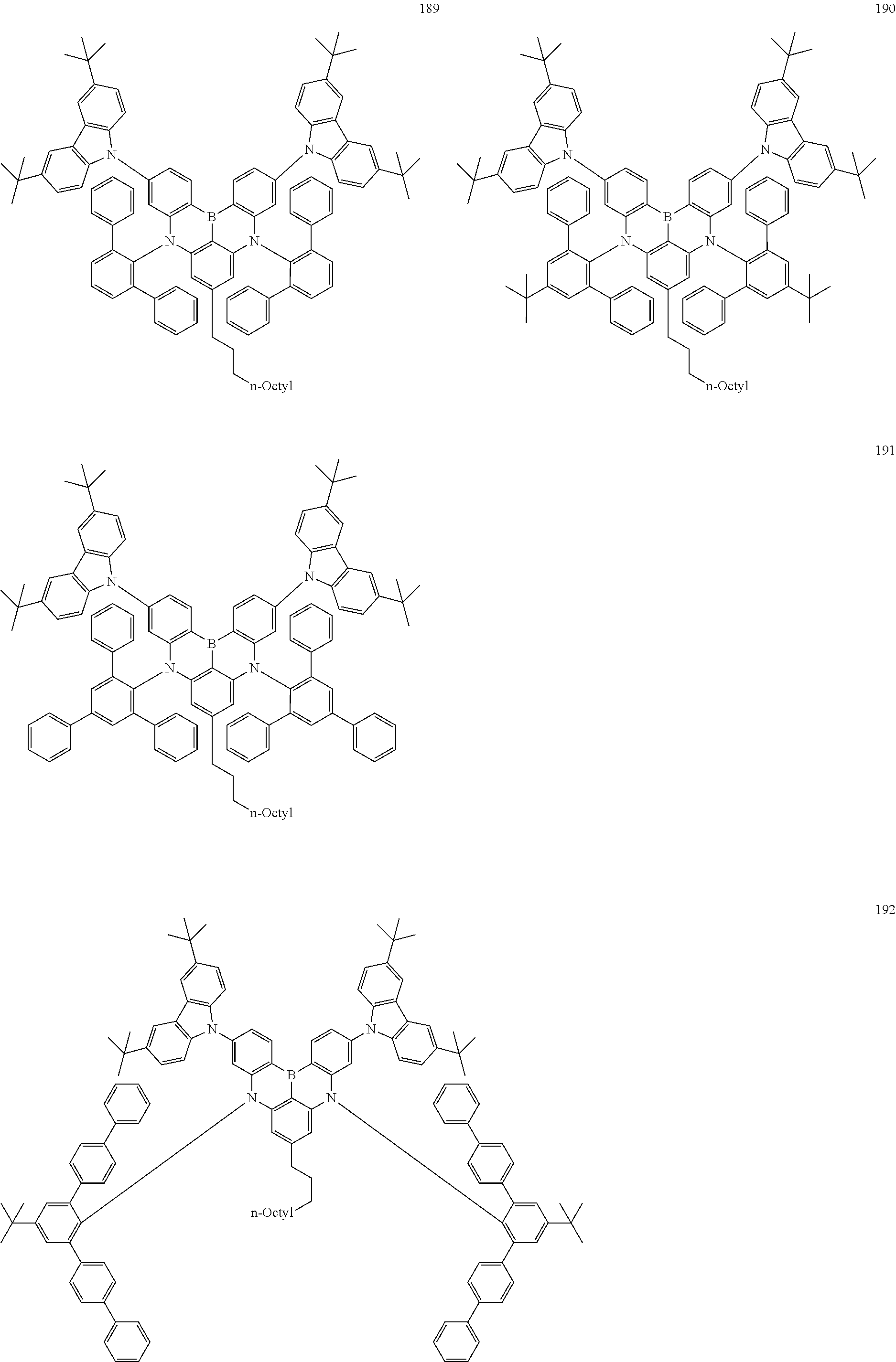 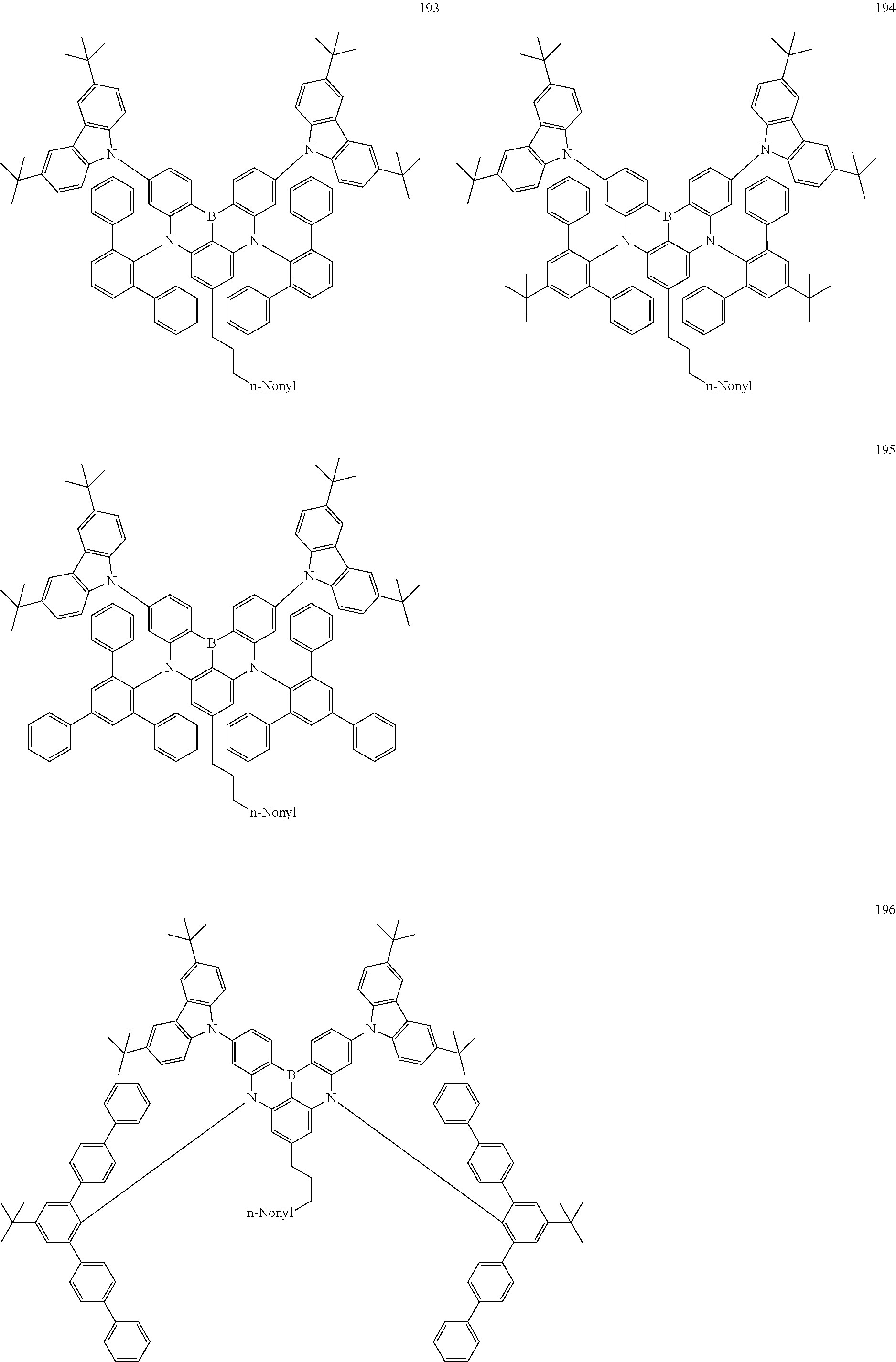 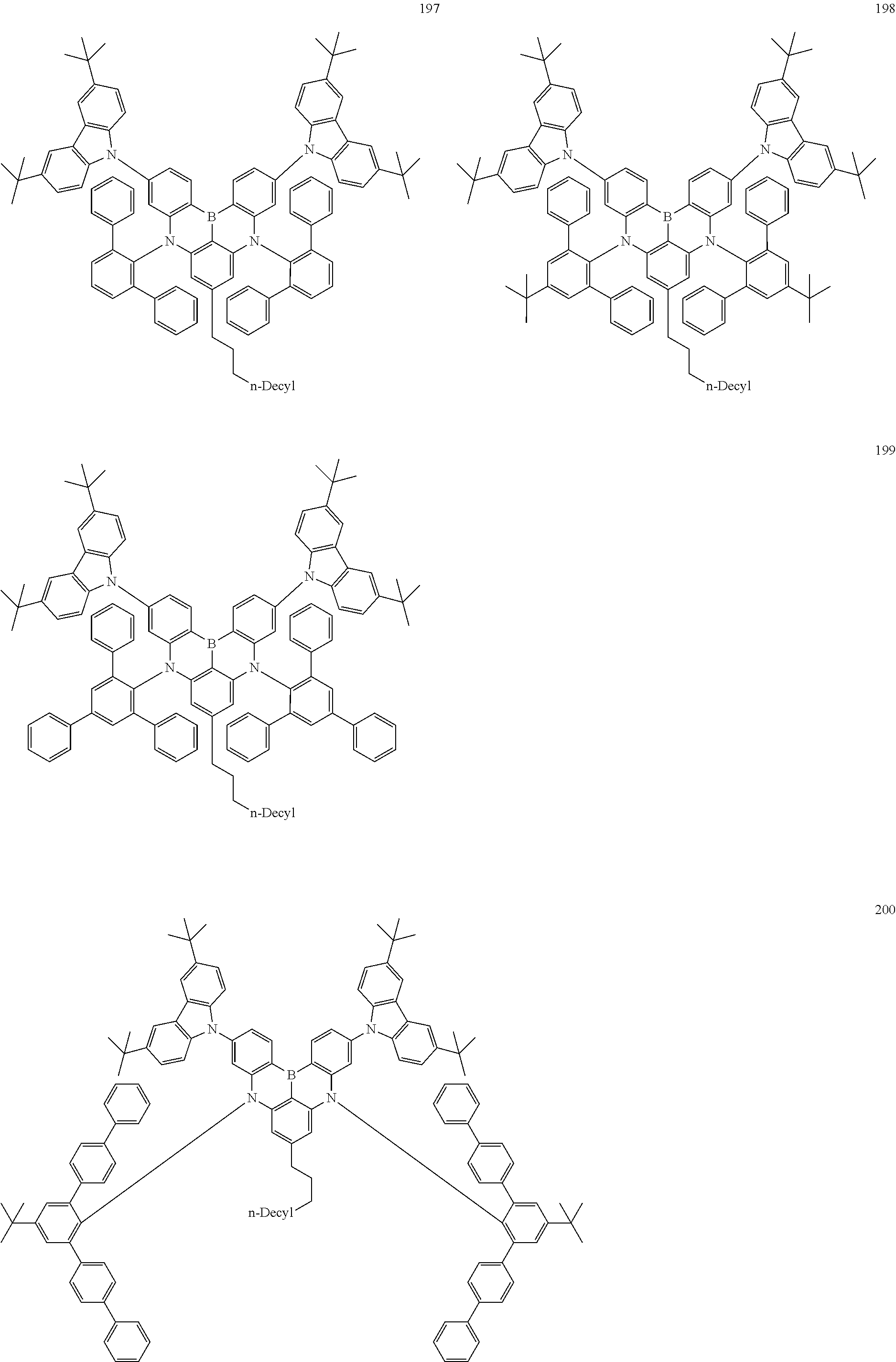 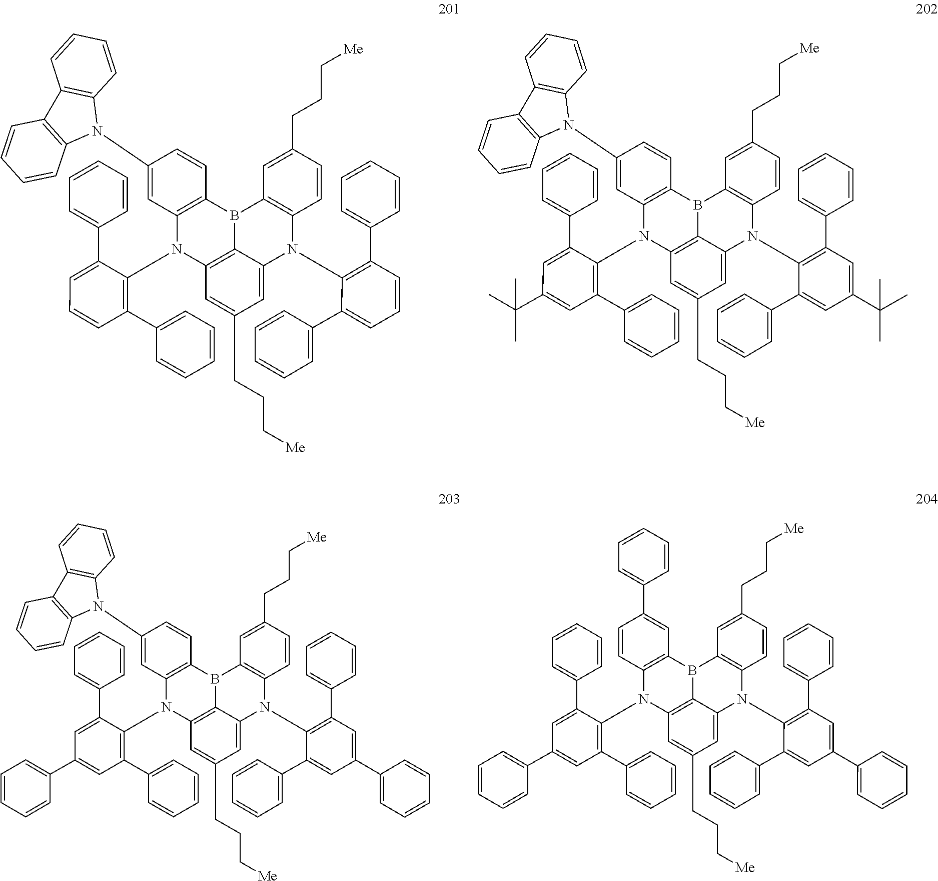 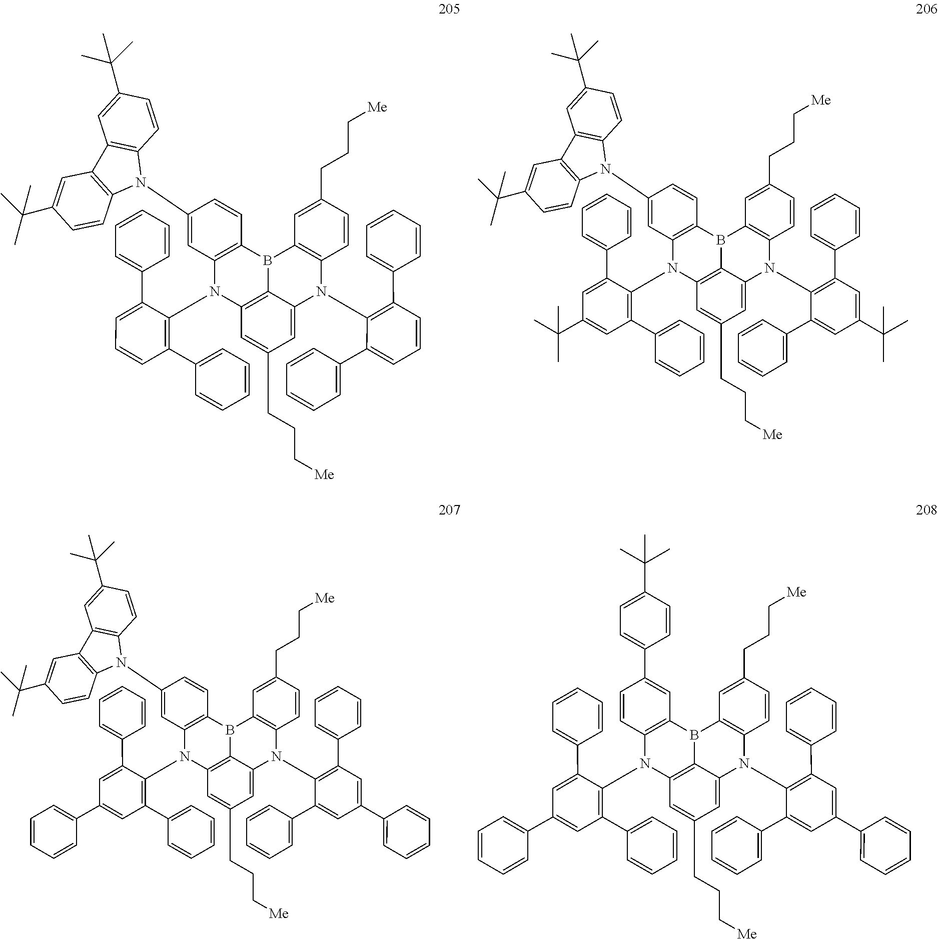 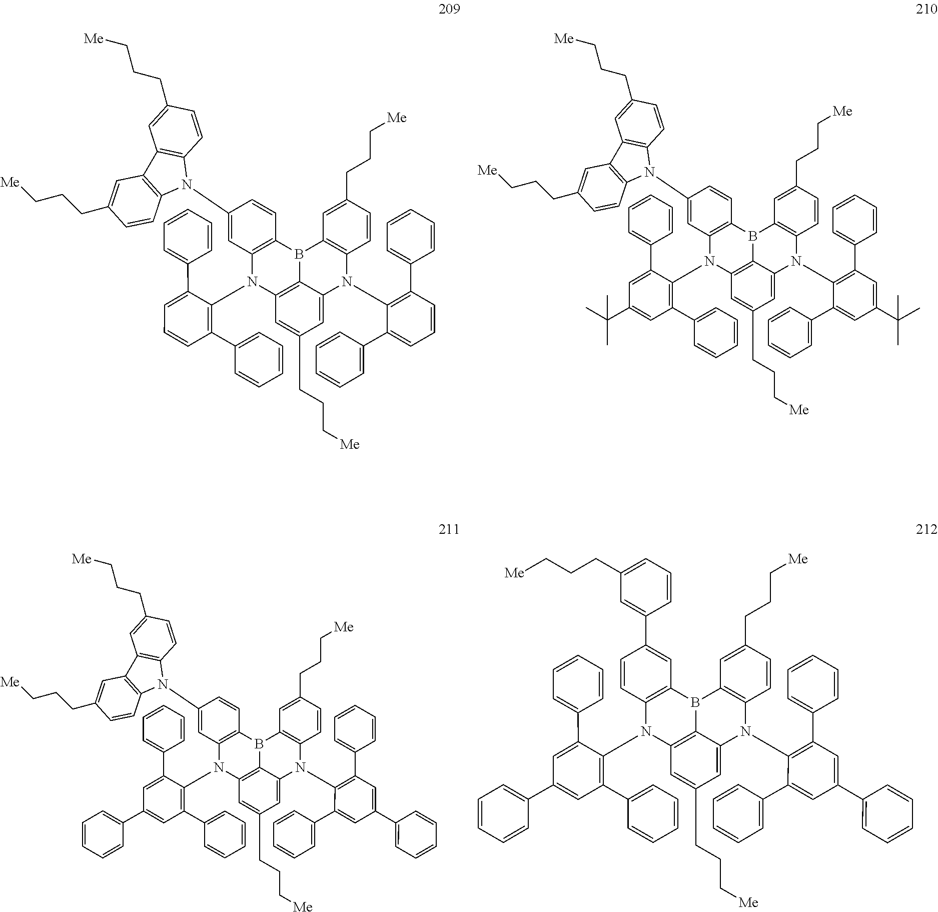 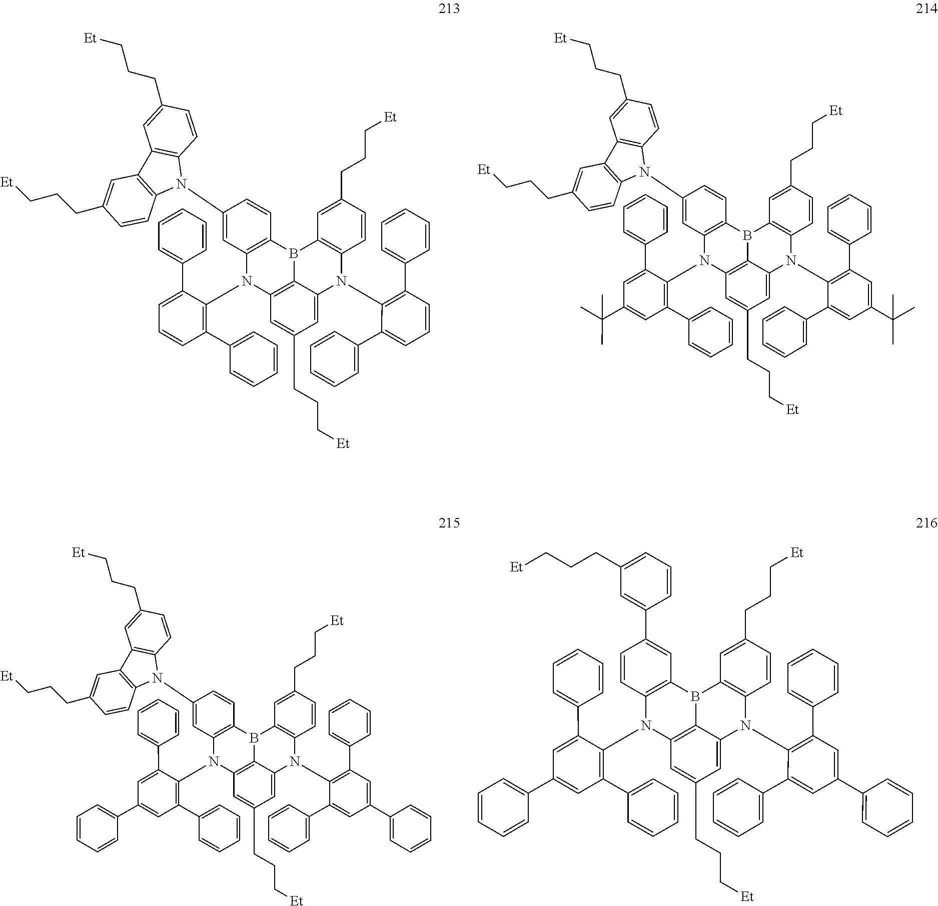 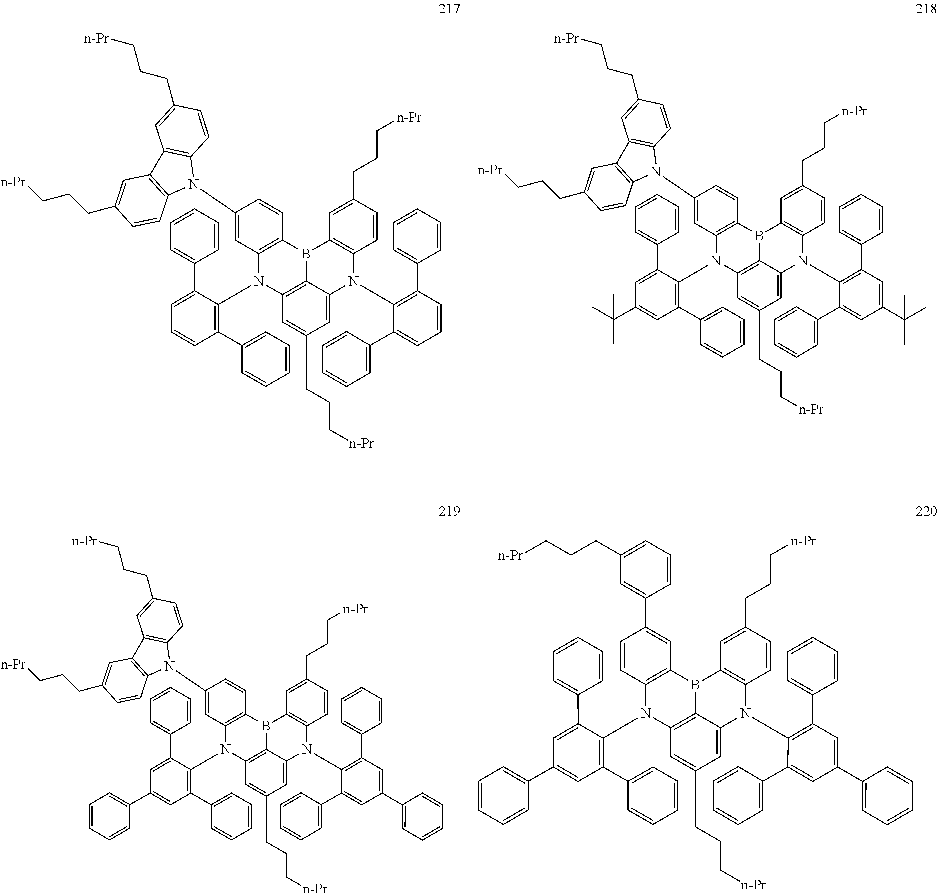 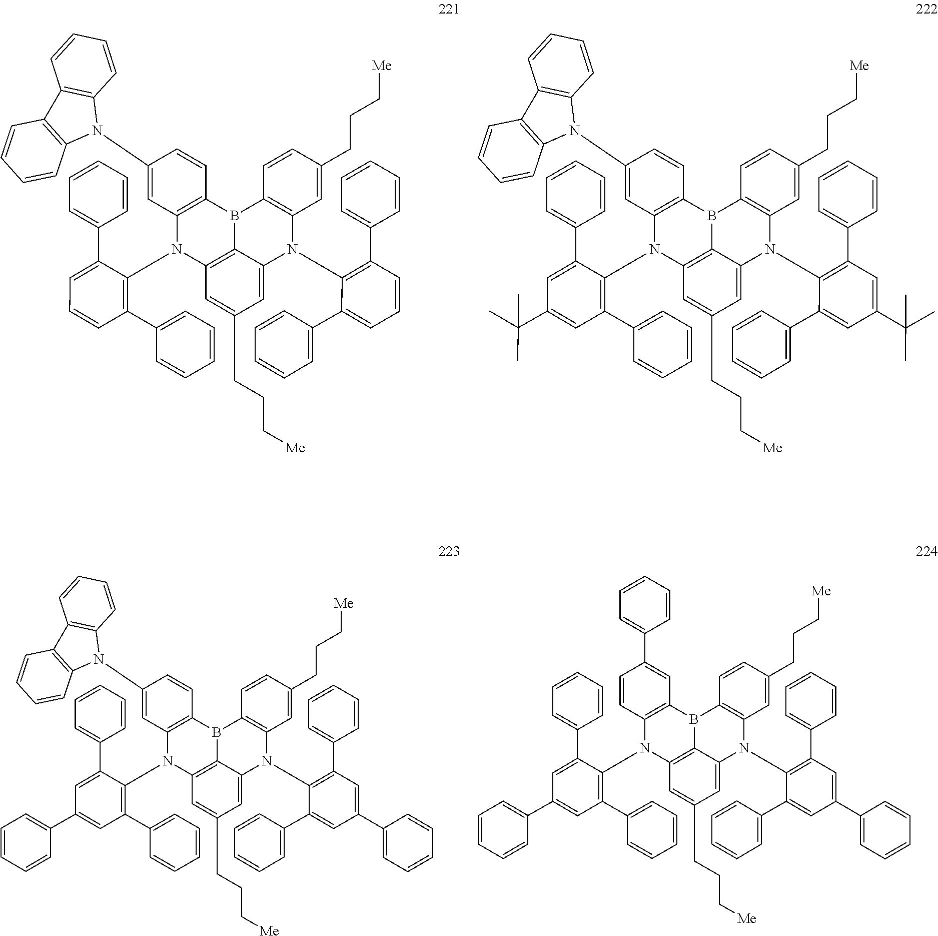 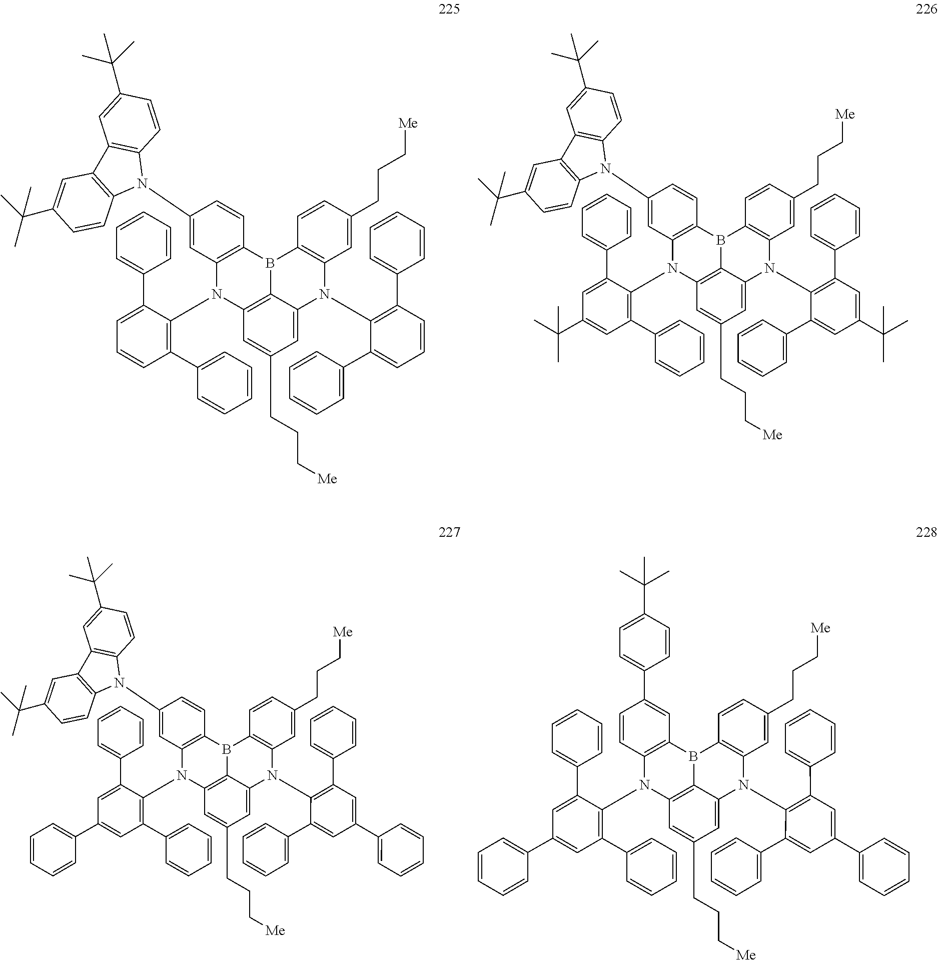 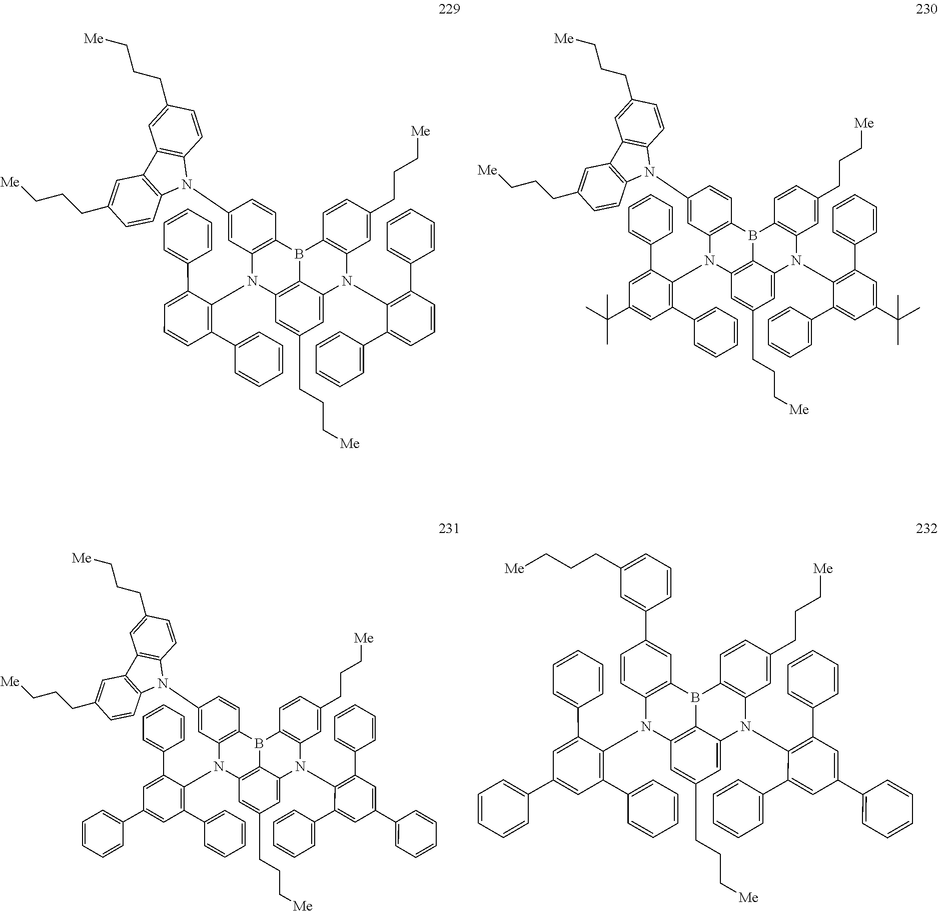 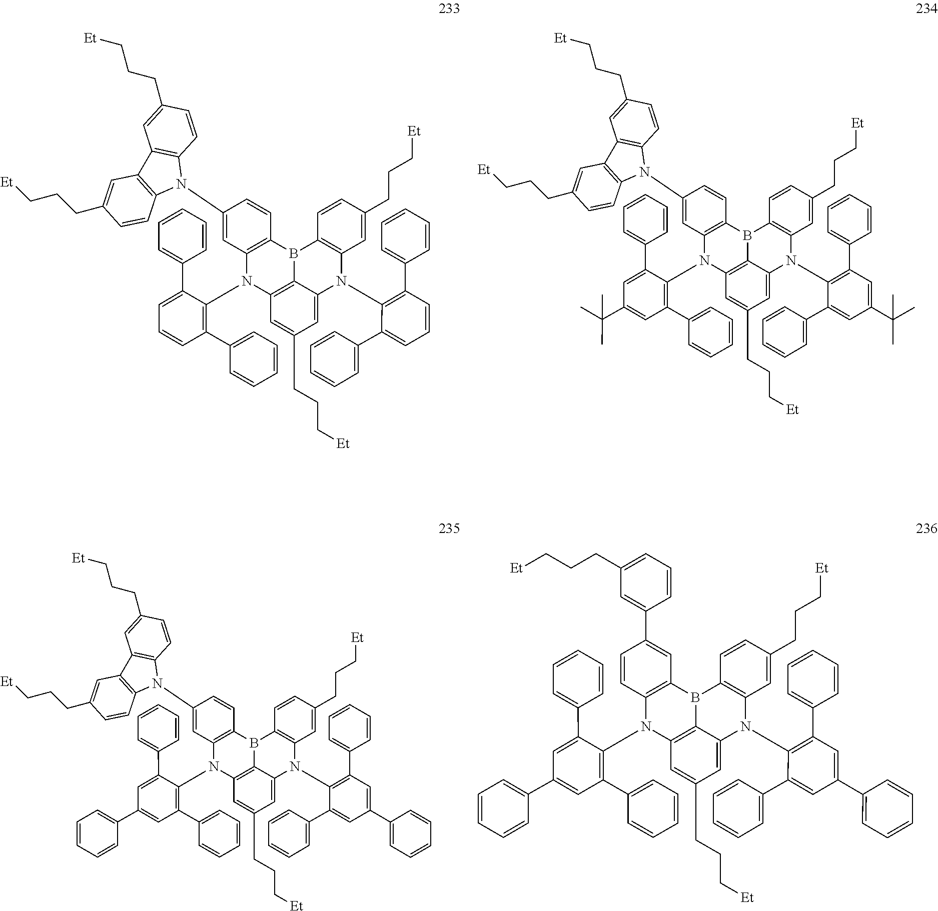 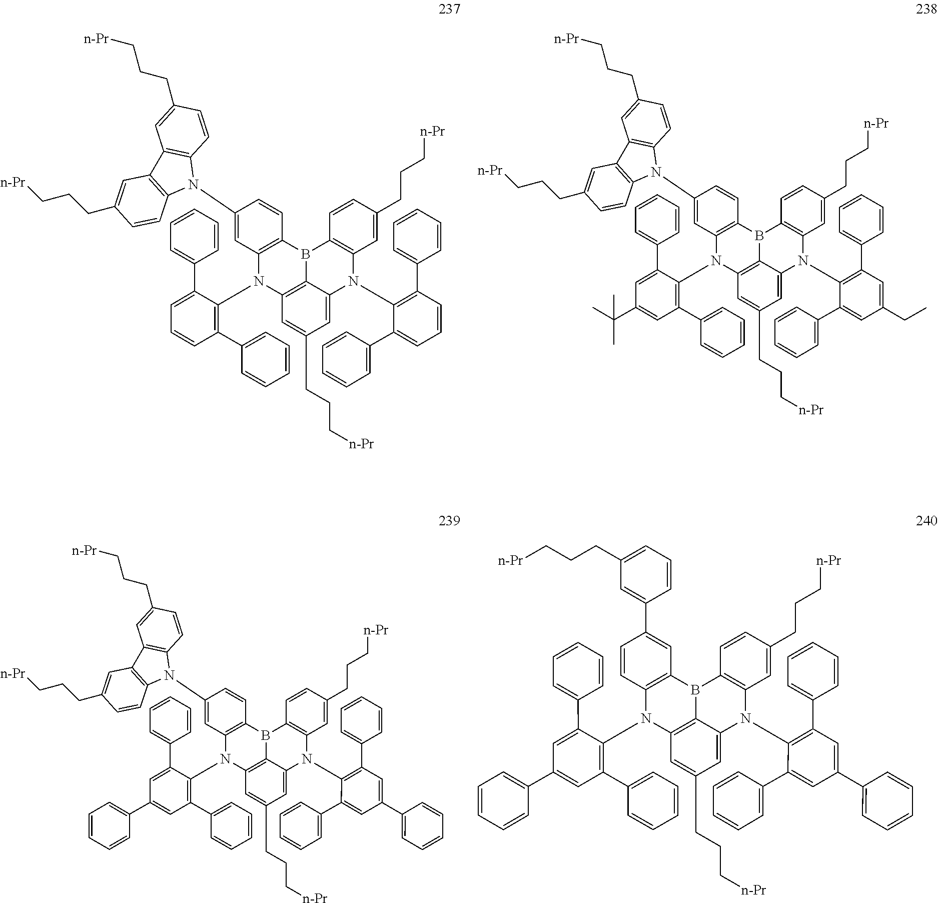 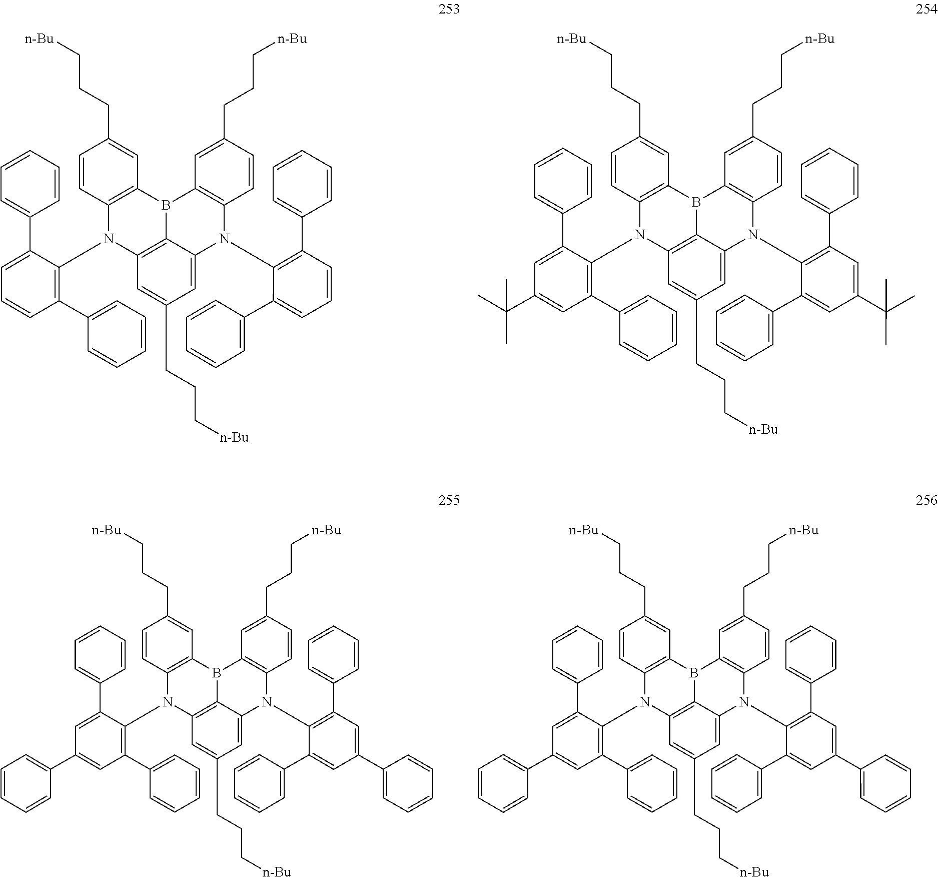 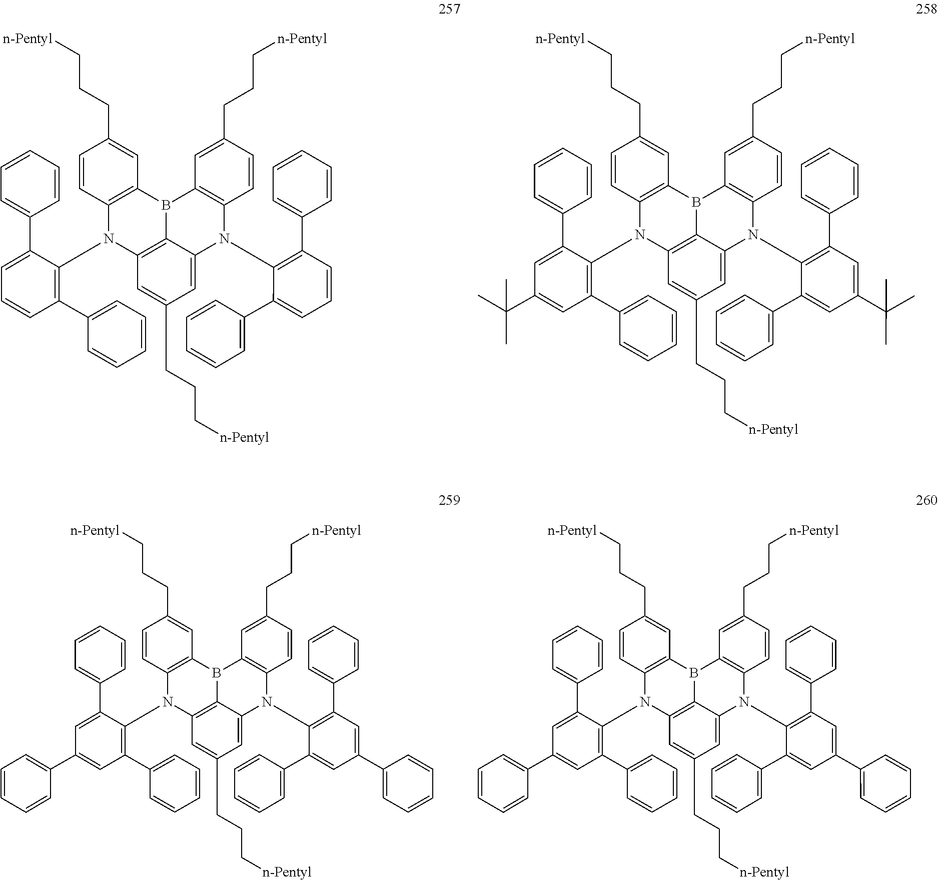 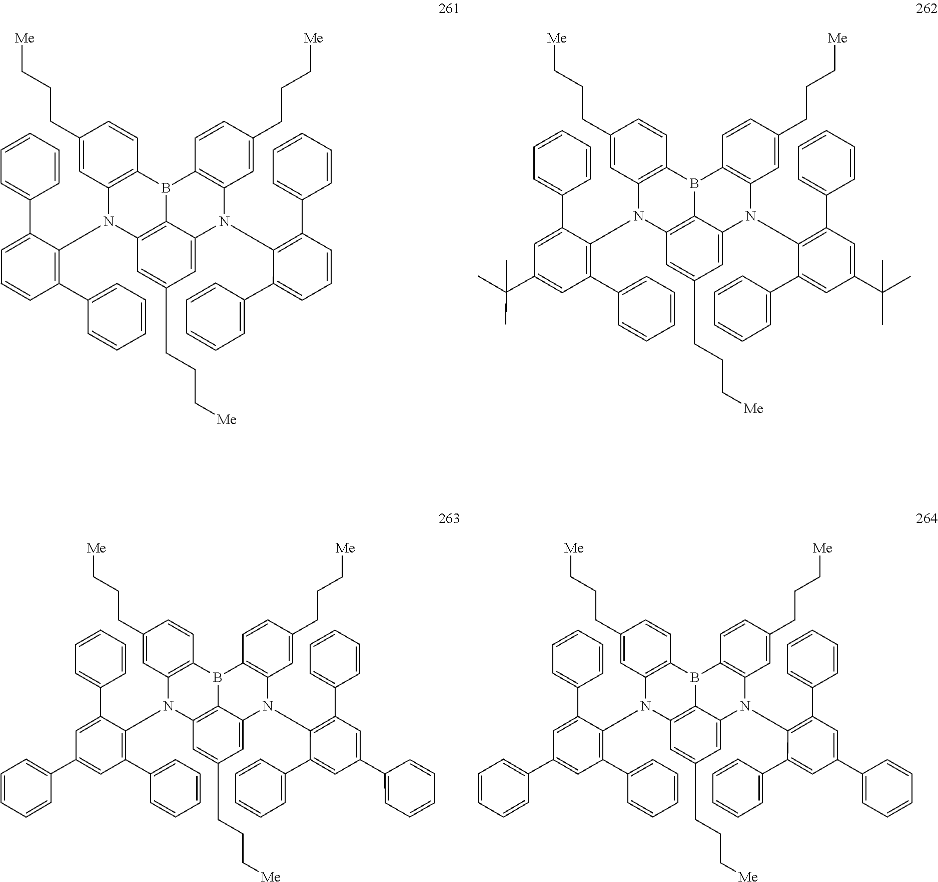 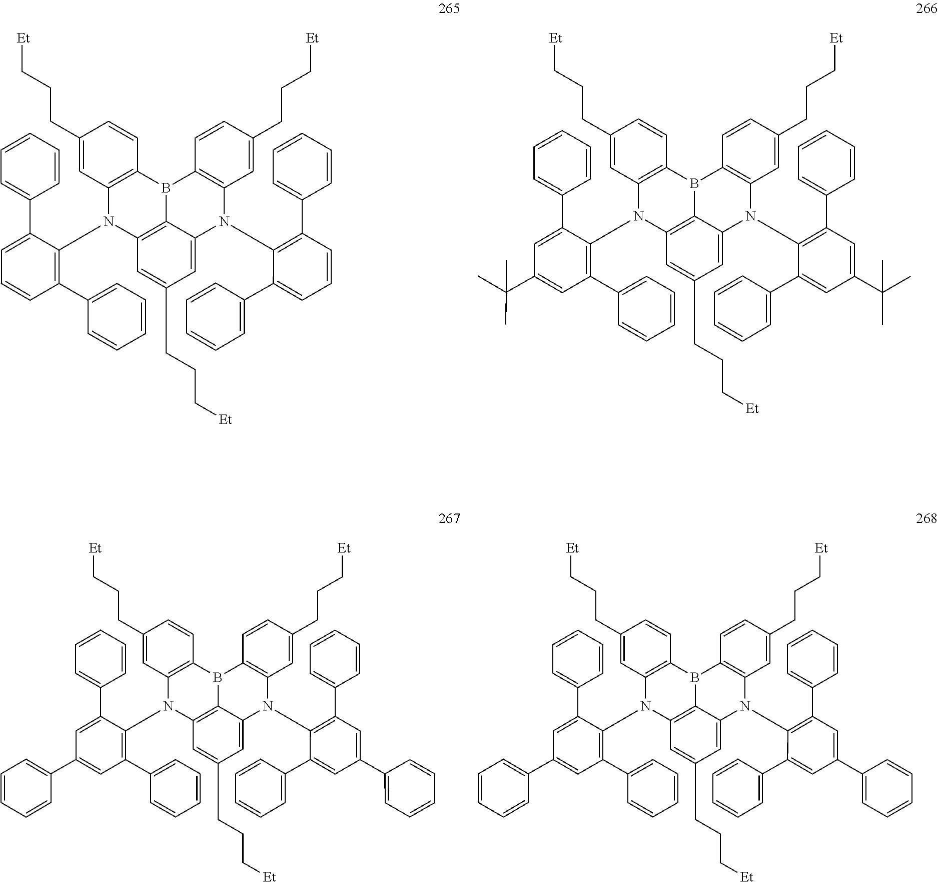 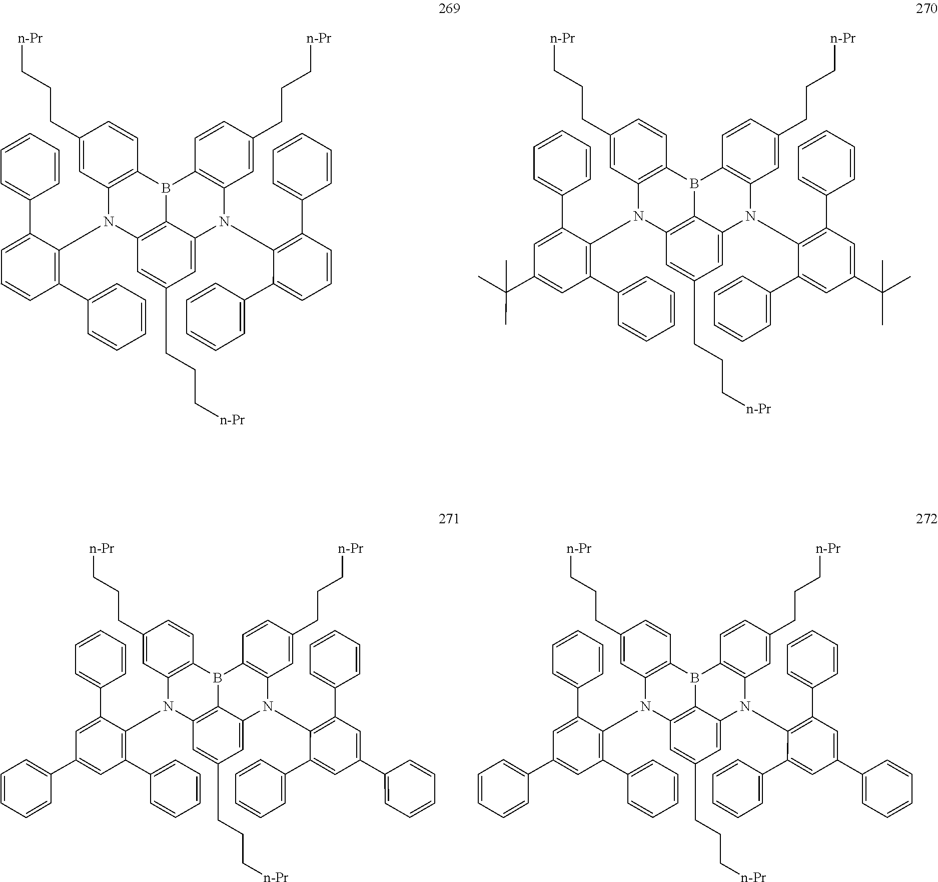 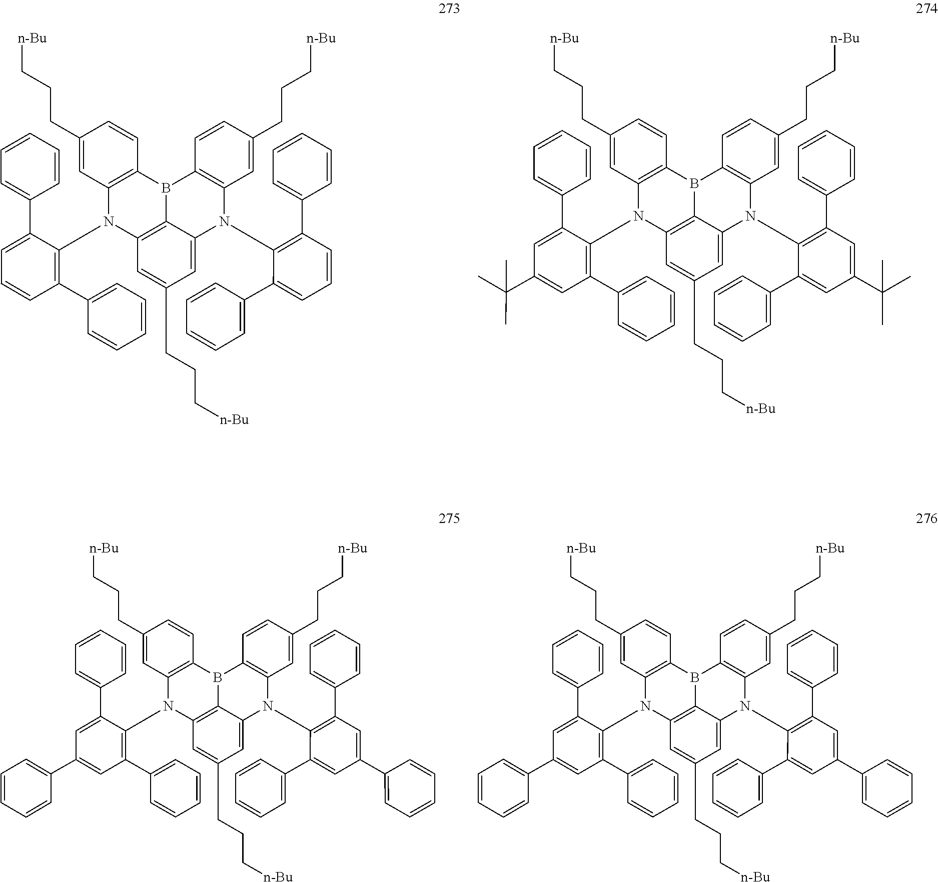 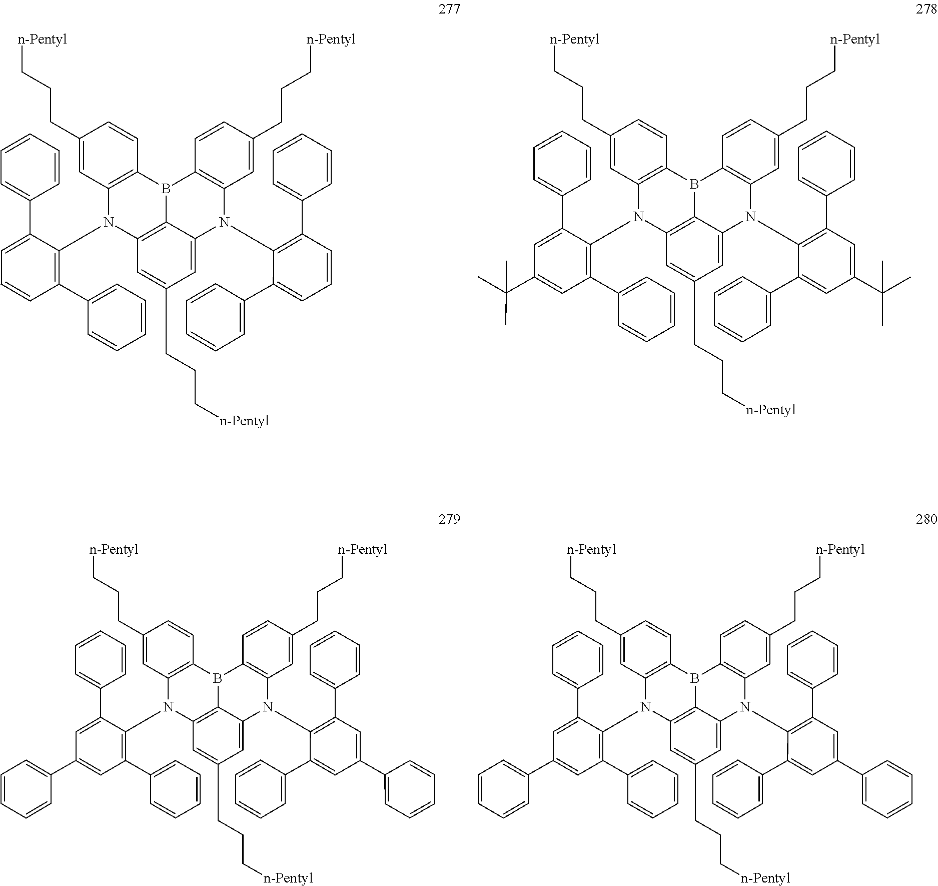 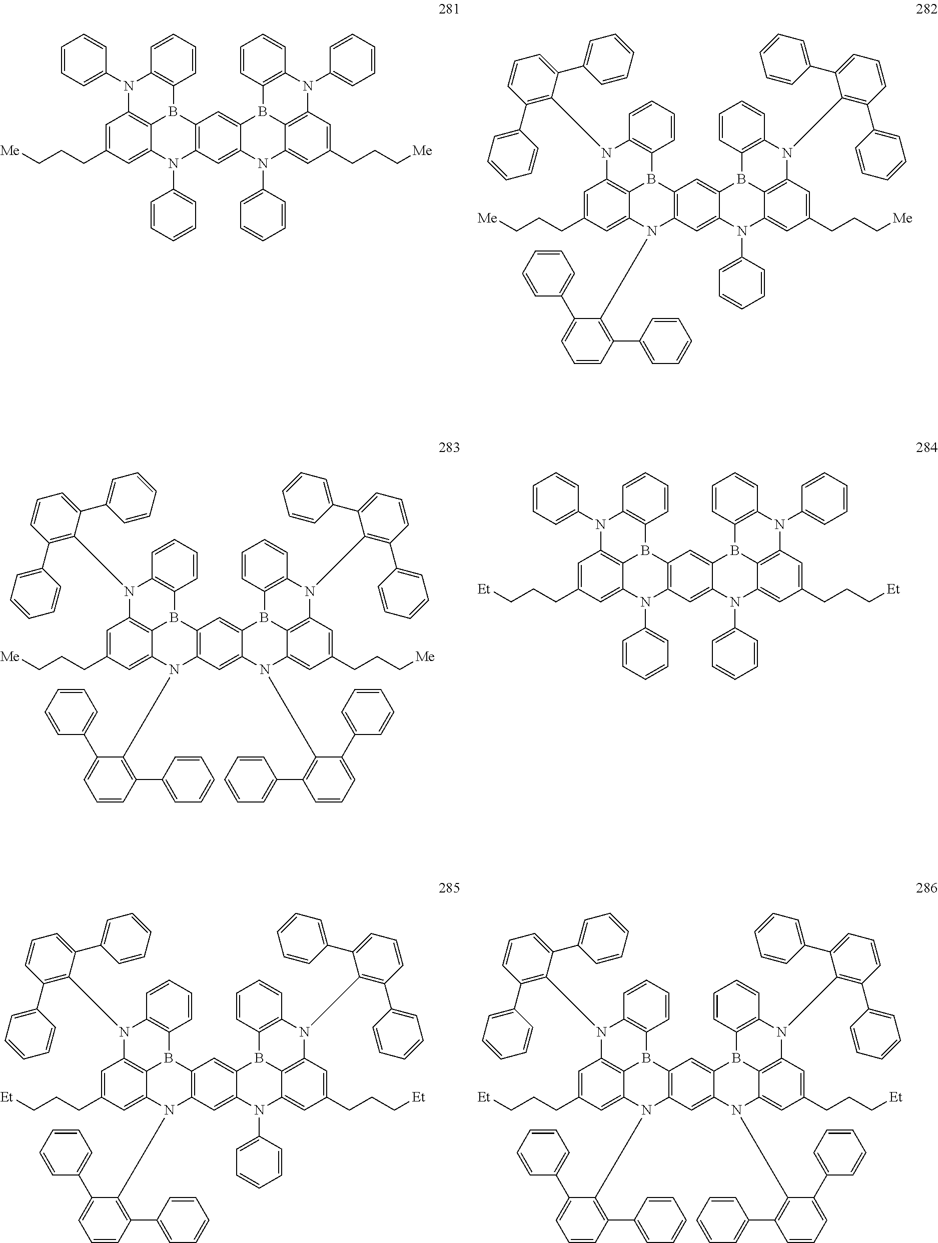 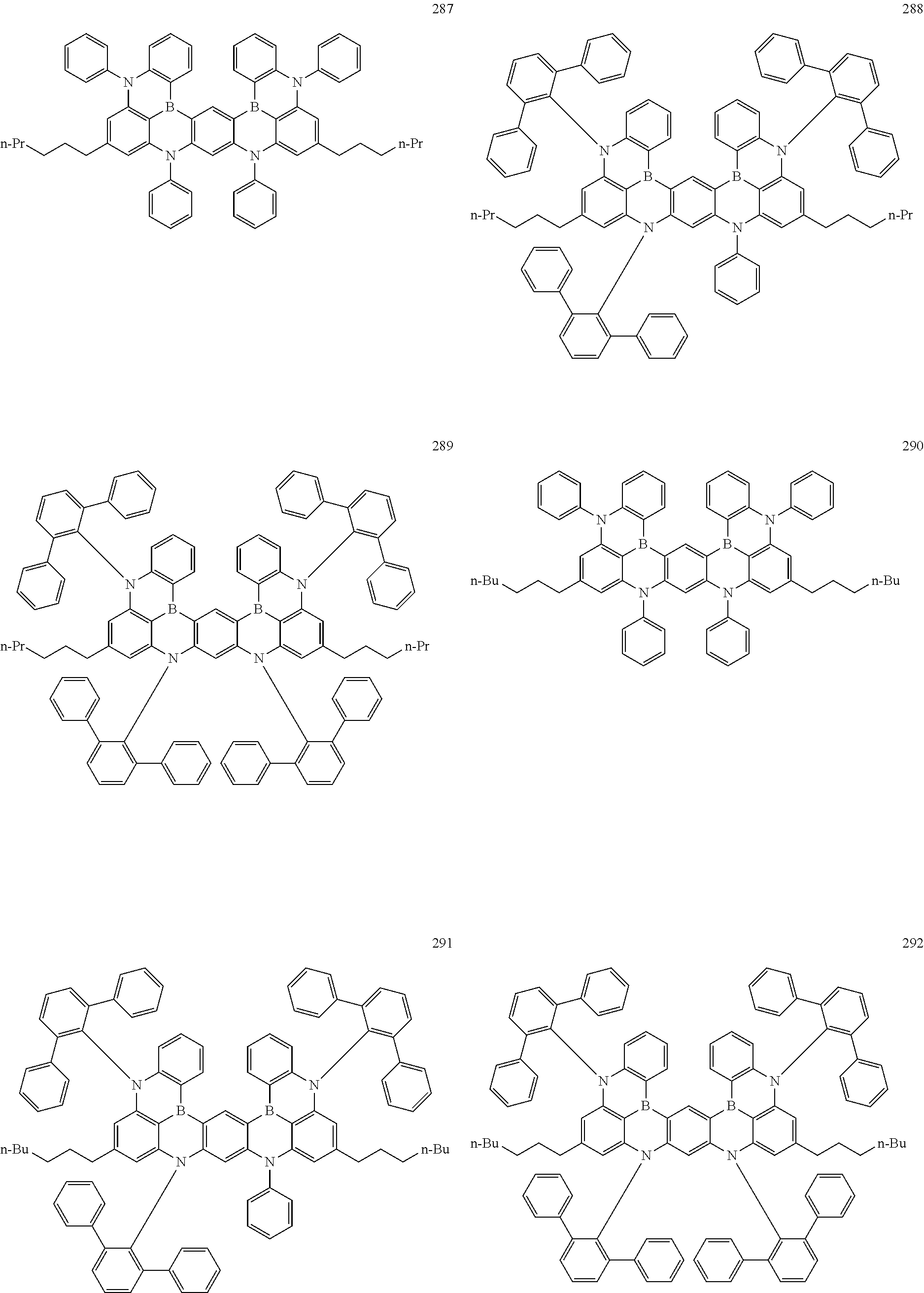 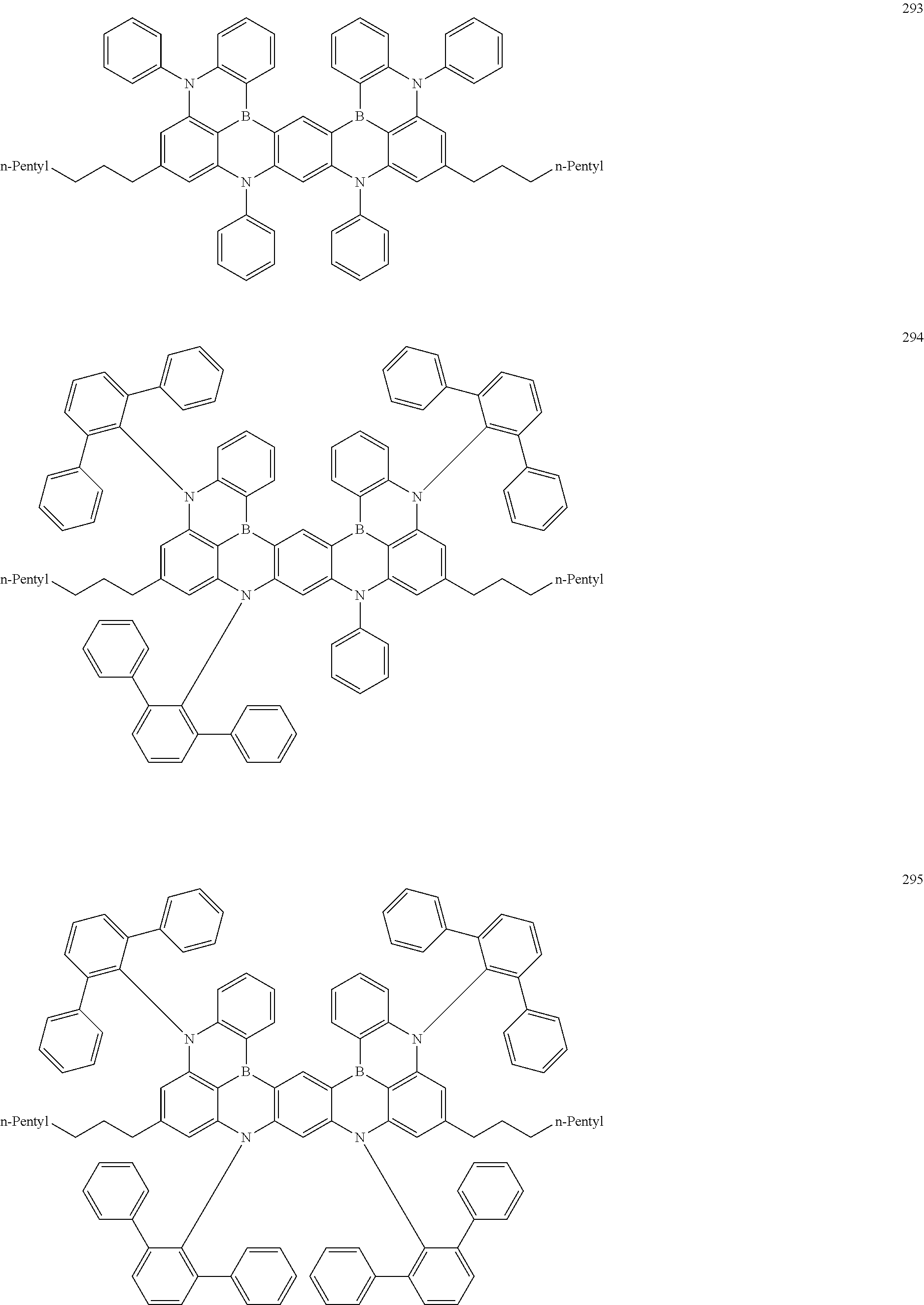 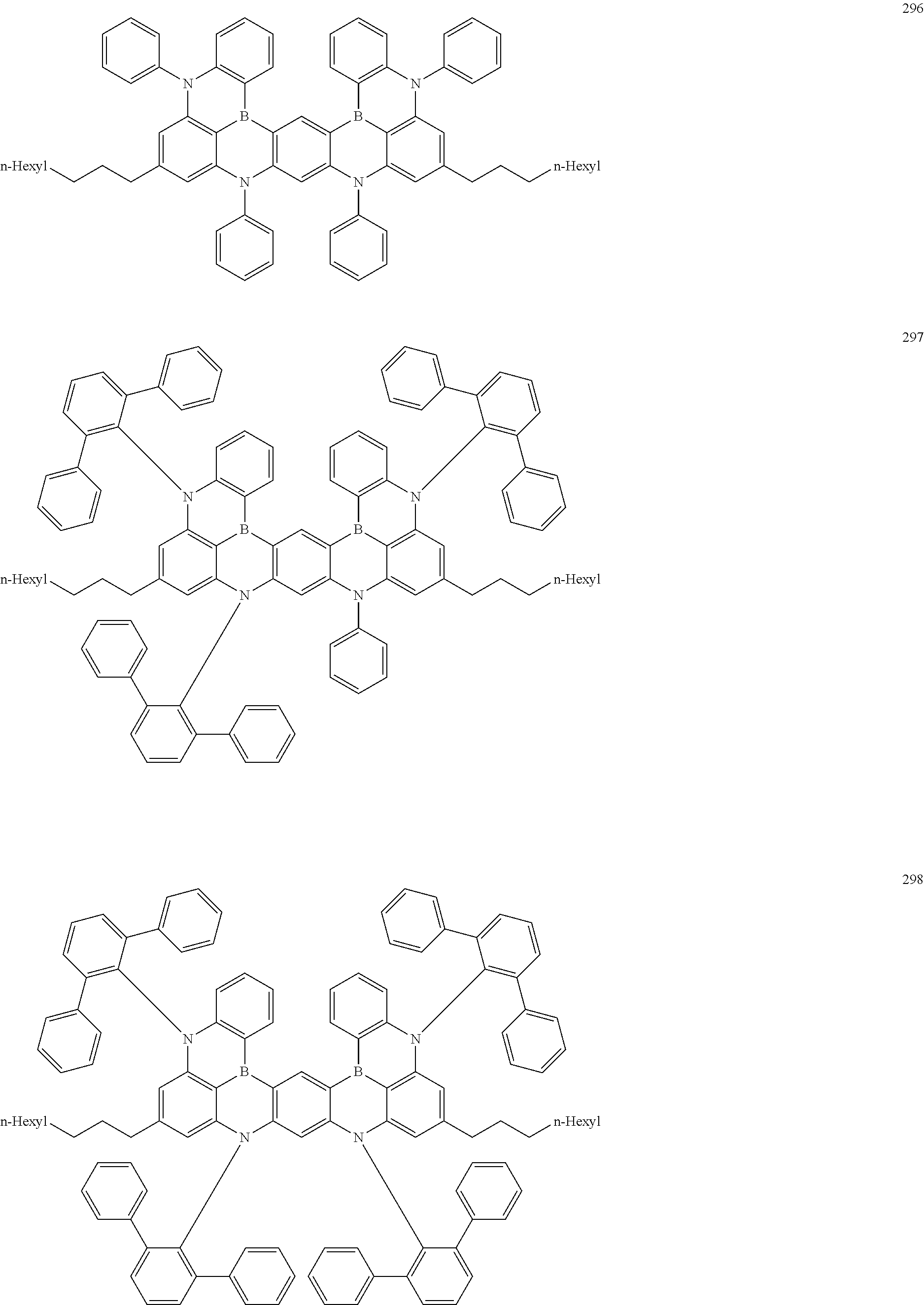 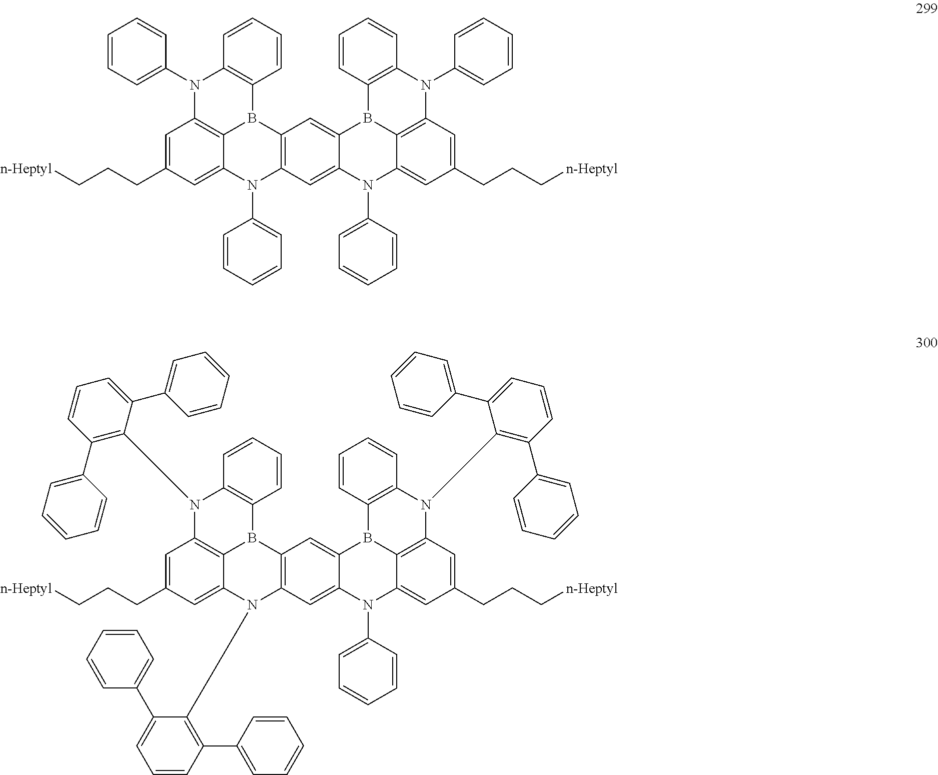 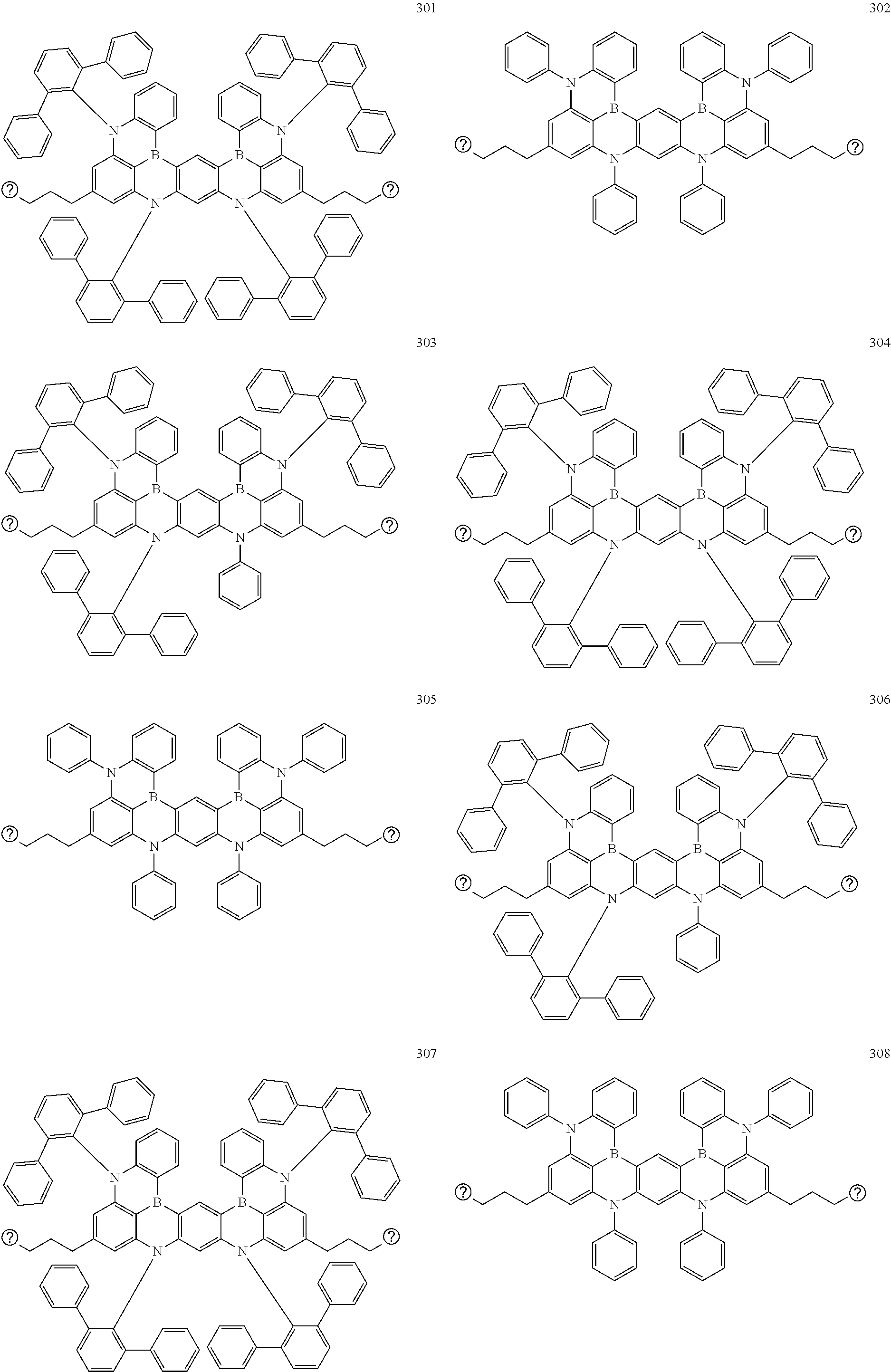 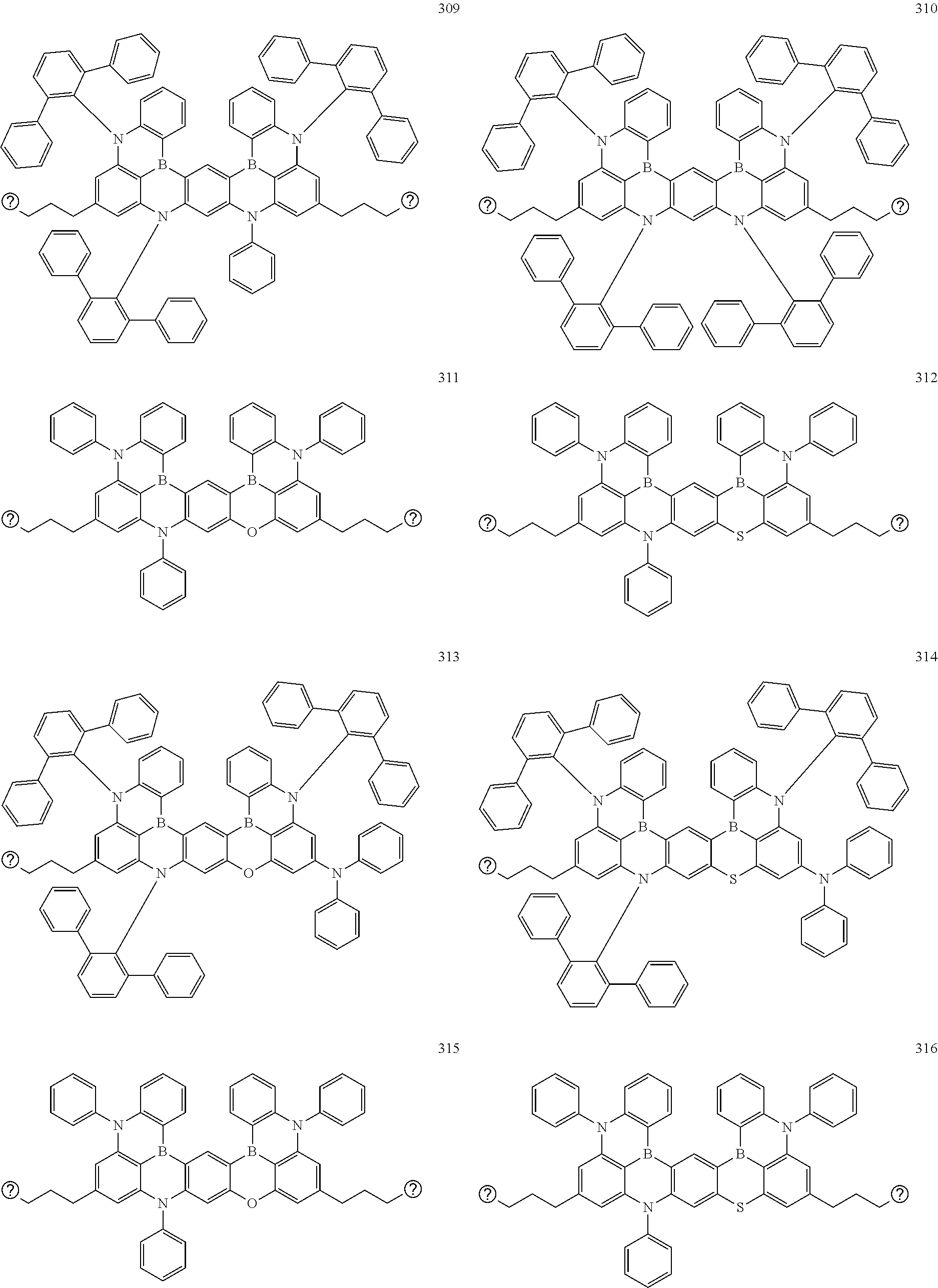 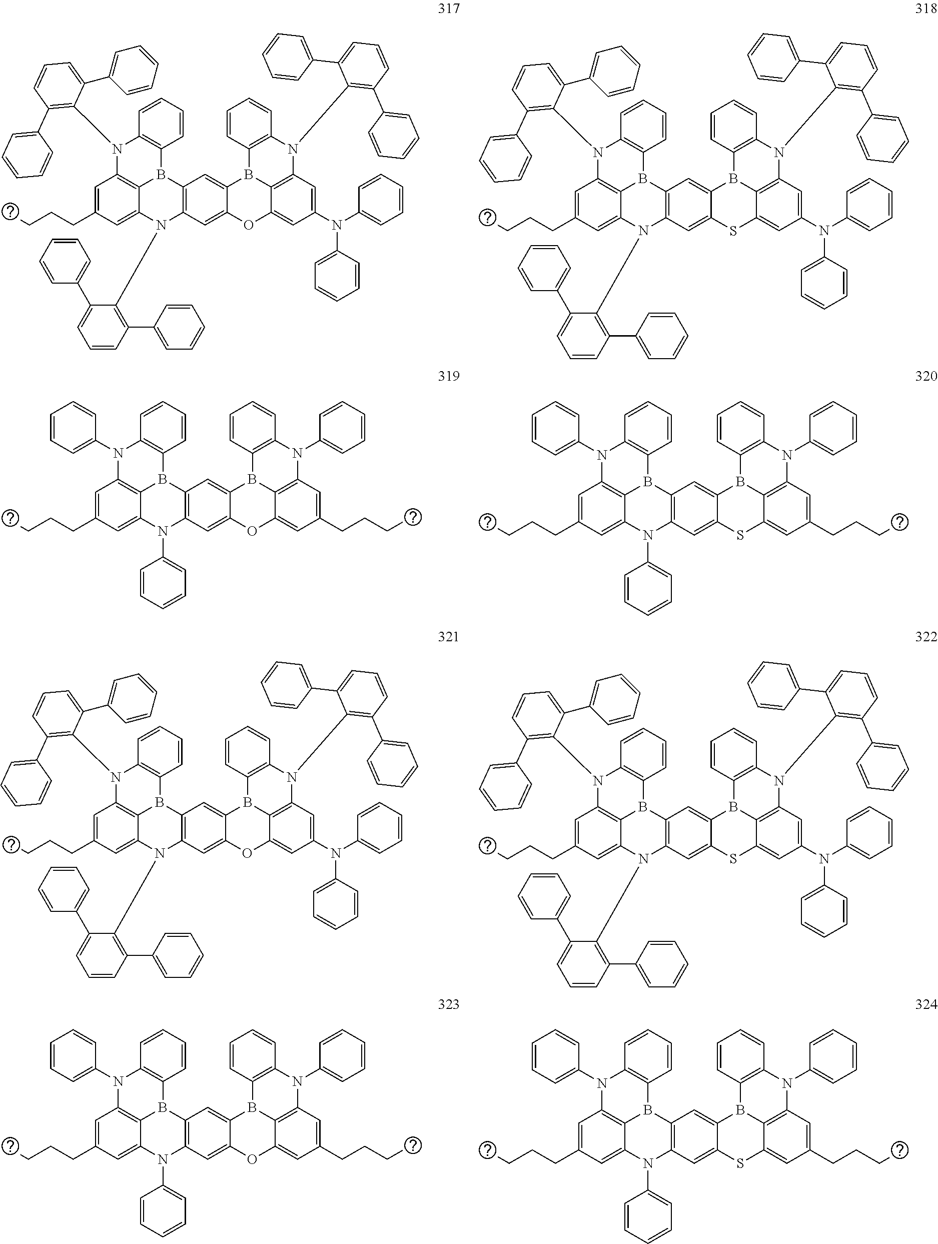 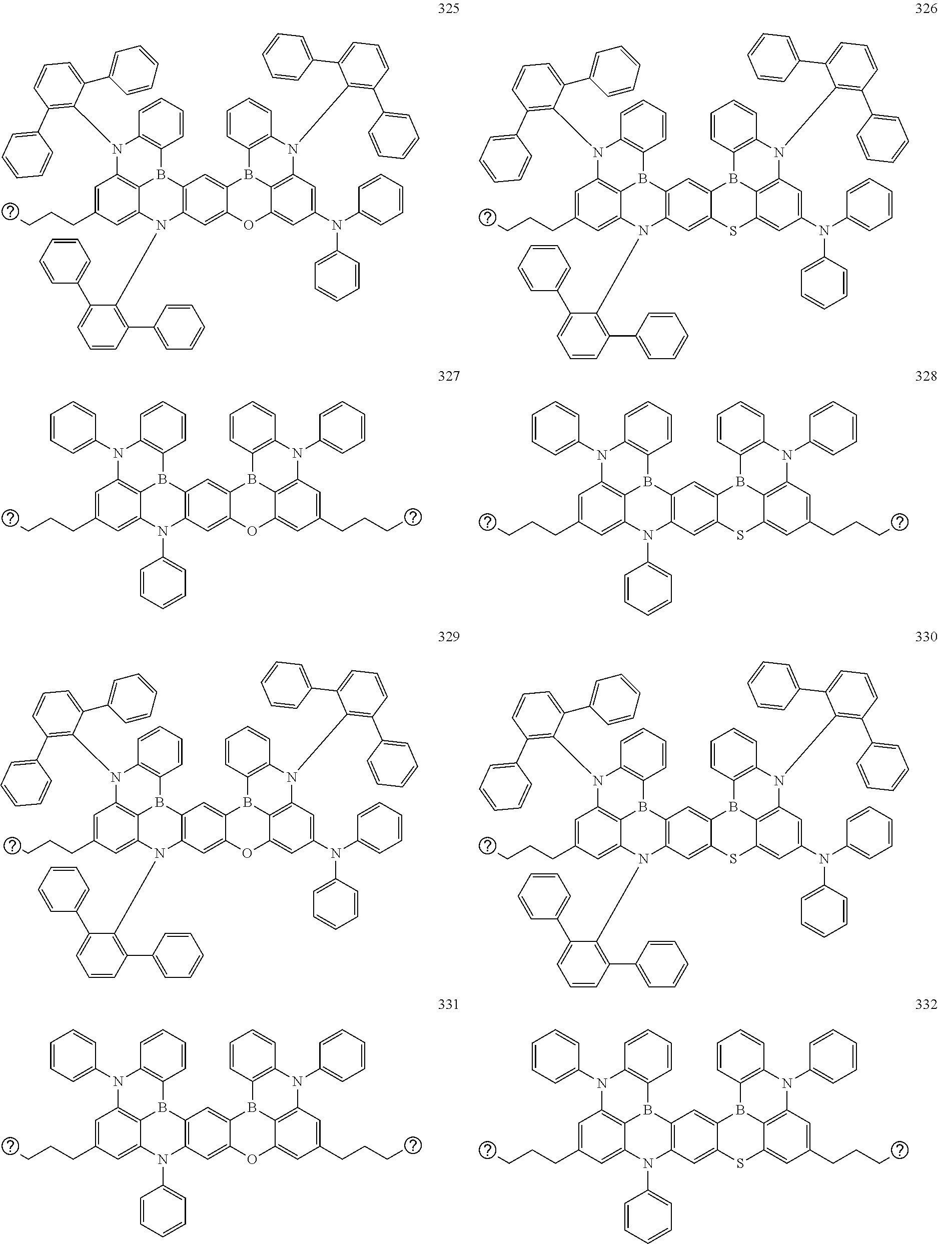 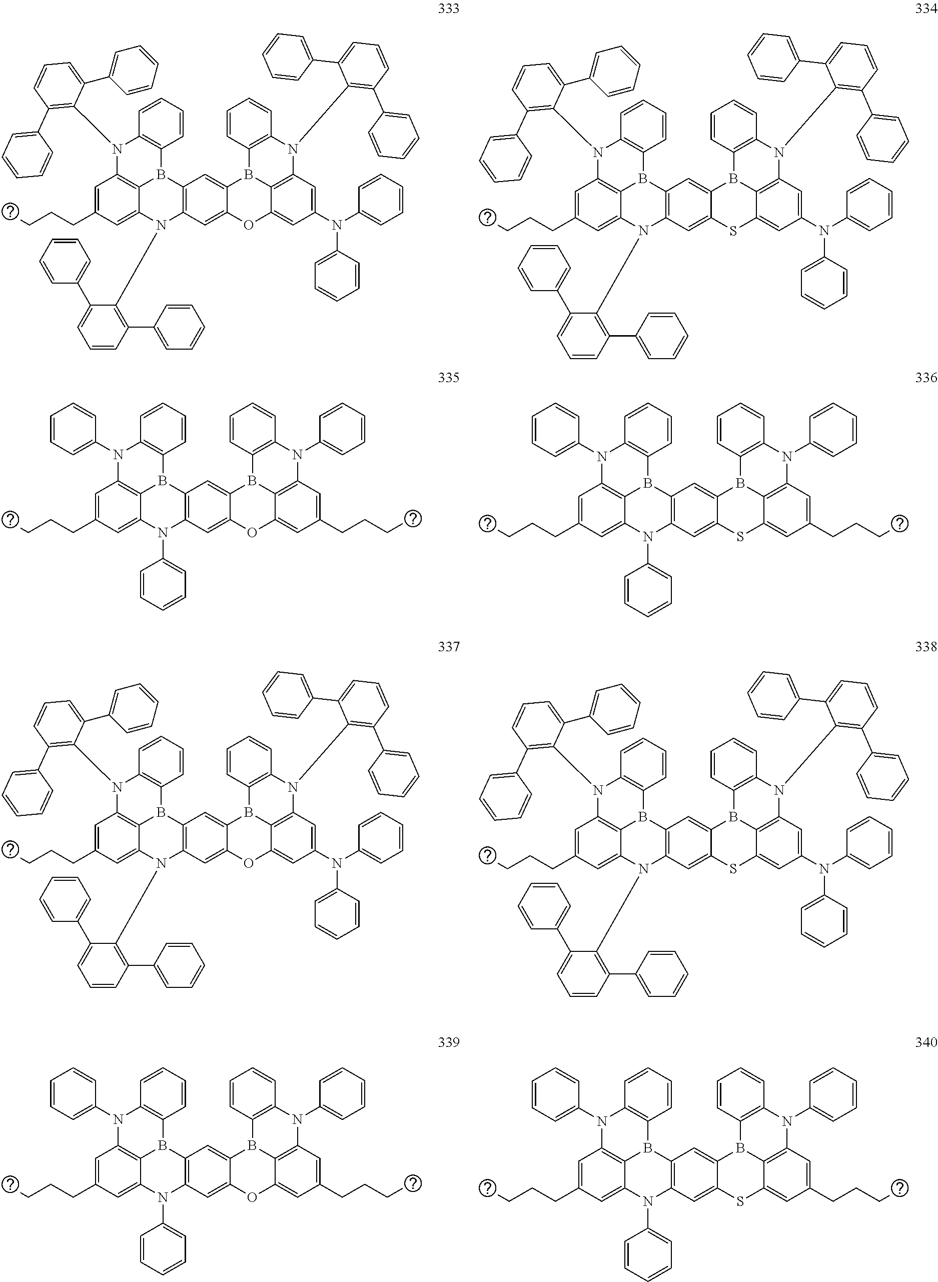 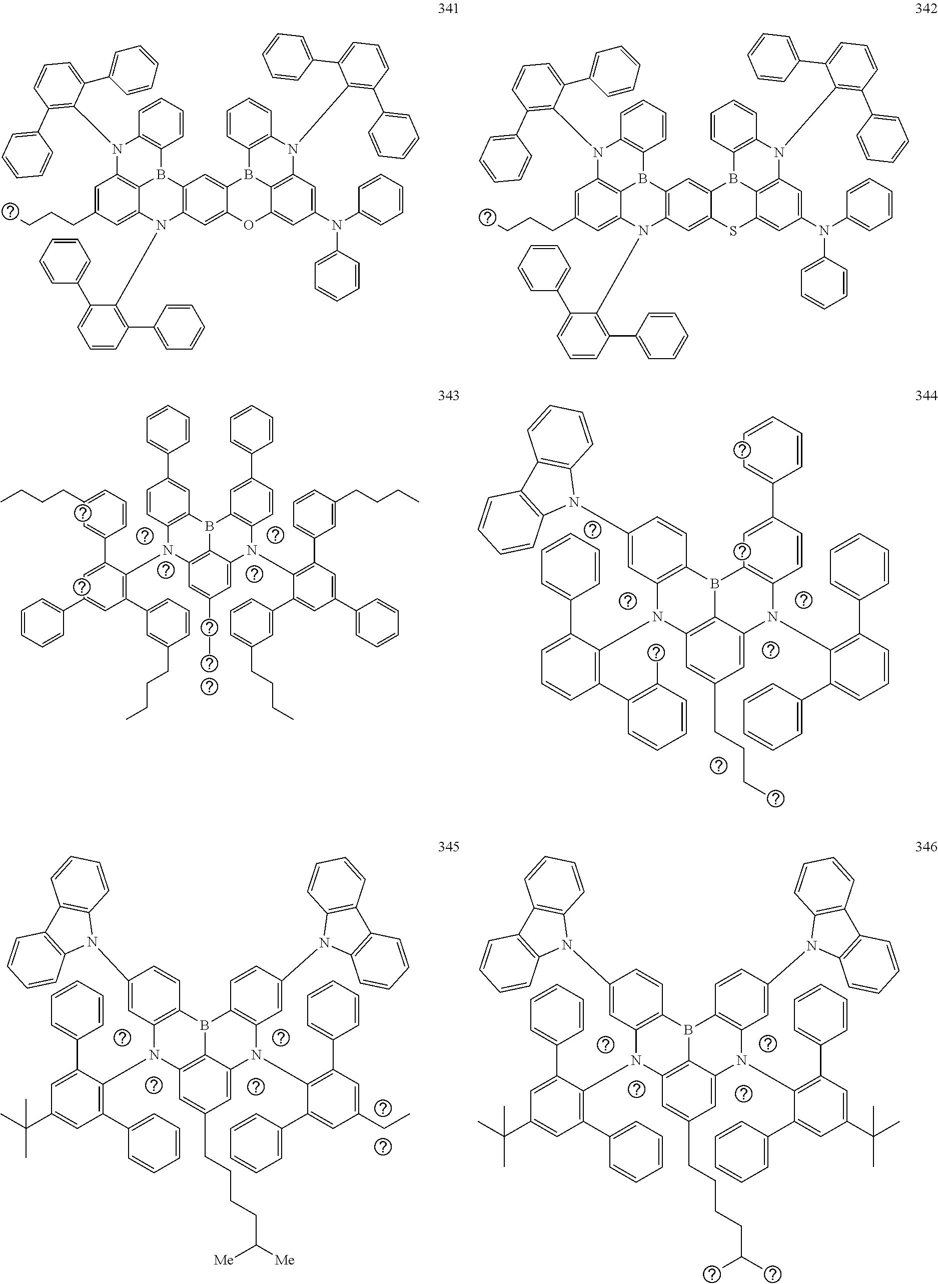 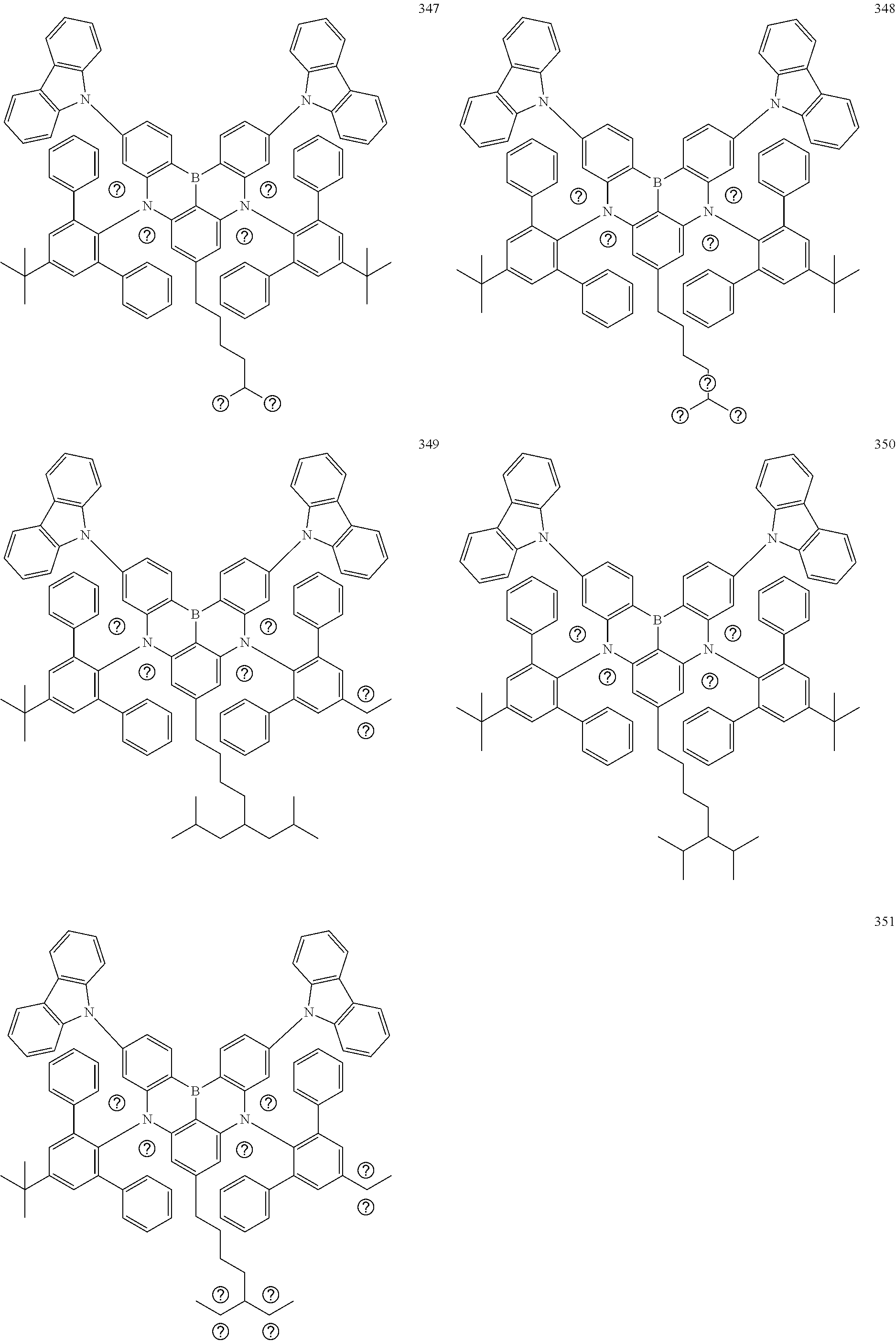 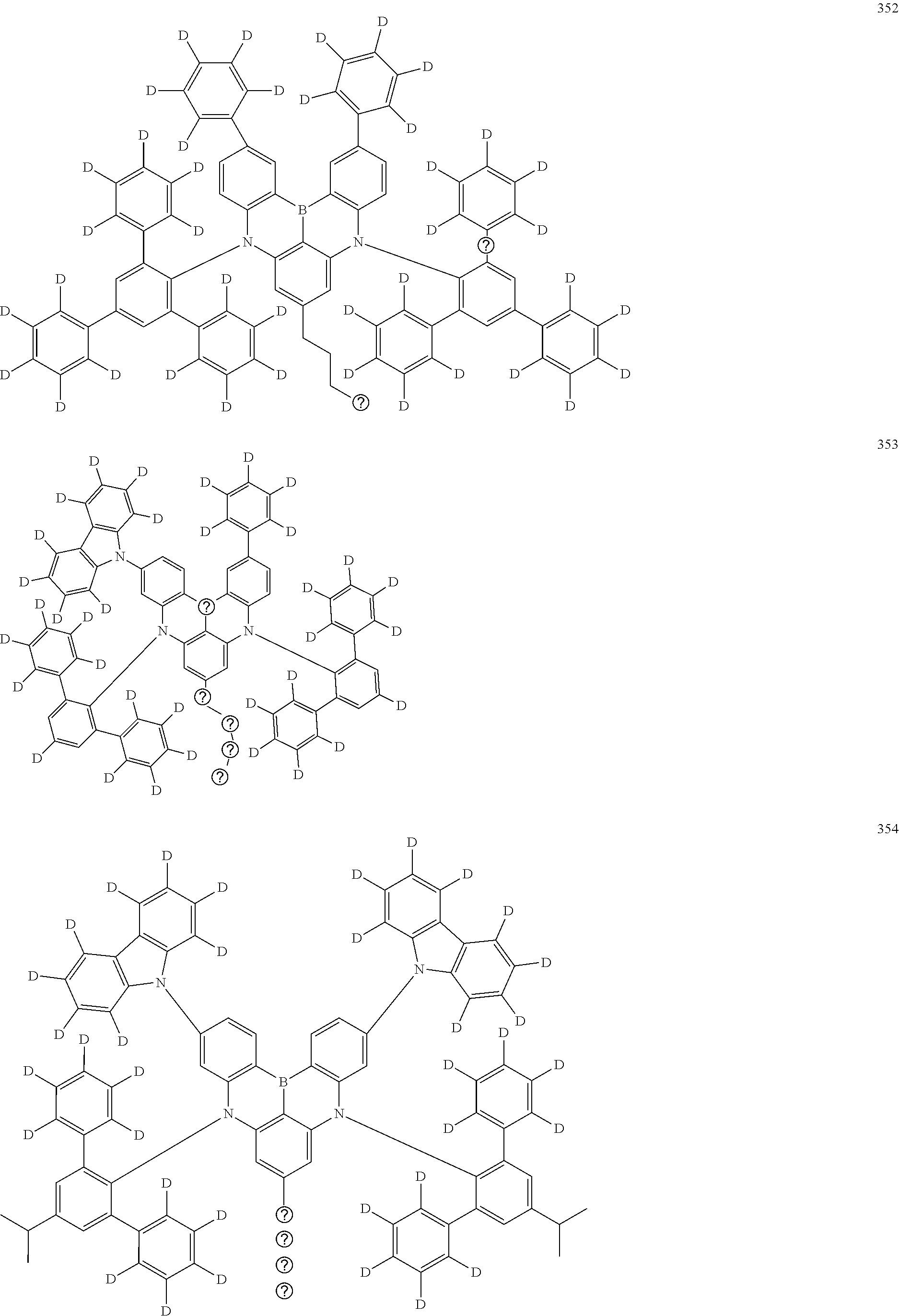 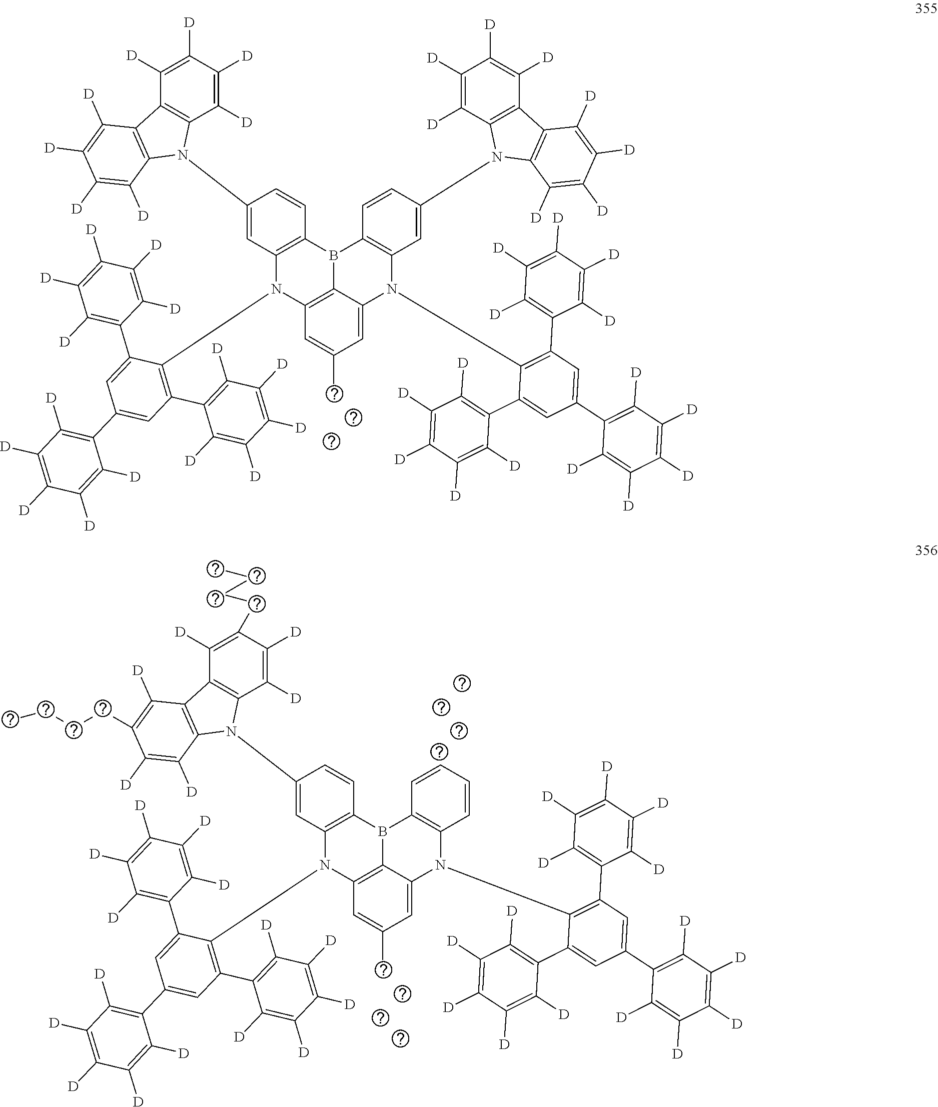 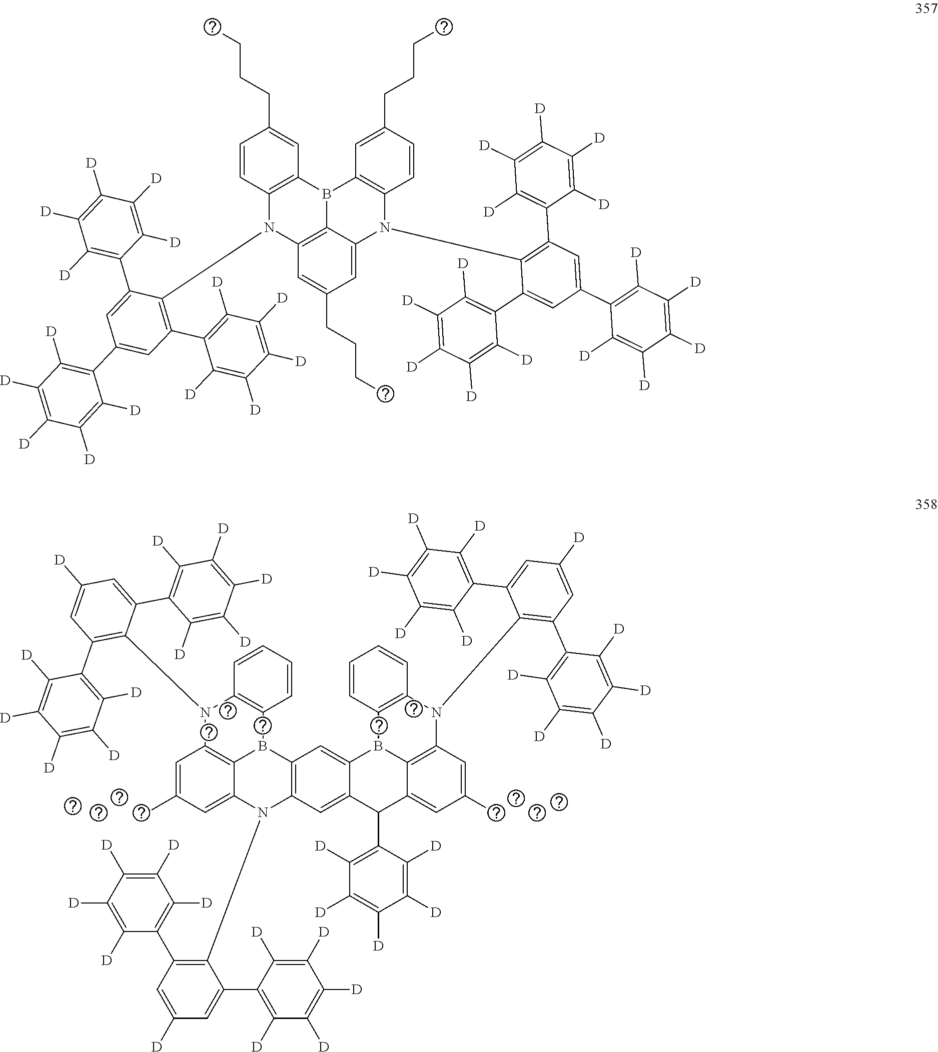 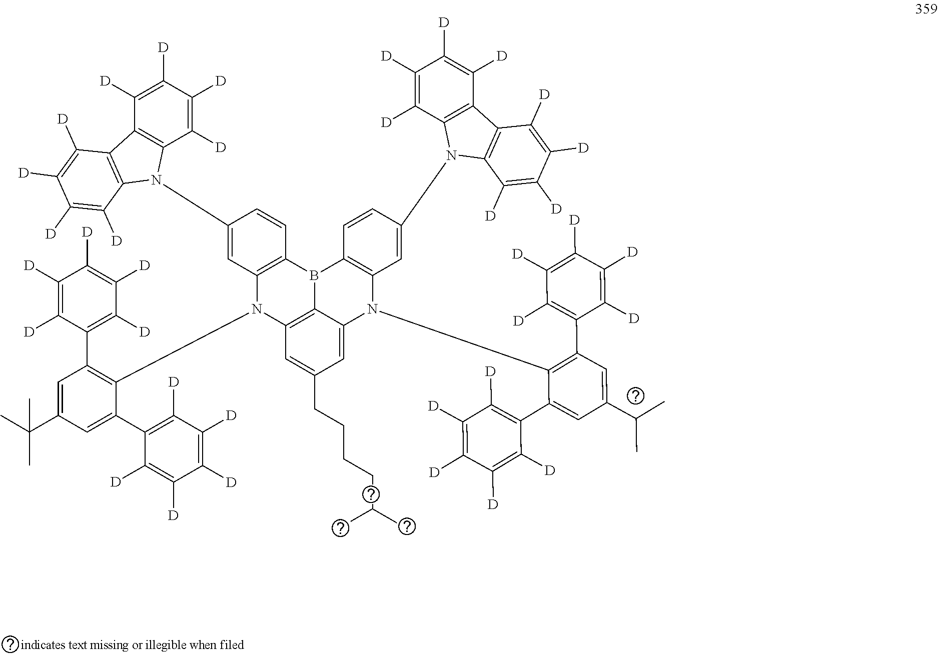 [SMILES: [2H]c1c([2H])c([2H])c(-c2cc(C(C)C)cc(-c3c([2H])c([2H])c([2H])c([2H])c3[2H])c2N2c3cc(-n4c5c([2H])c([2H])c([2H])c([2H])c5c5c([2H])c([2H])c([2H])c([2H])c54)ccc3B3c4ccc(-n5c6c([2H])c([2H])c([2H])c([2H])c6c6c([2H])c([2H])c([2H])c([2H])c65)cc4N(c4c(-c5c([2H])c([2H])c([2H])c([2H])c5[2H])cc(C(C)(C)C)cc4-c4c([2H])c([2H])c([2H])c([2H])c4[2H])c4cc(CCCCC(C)C)cc2c43)c([2H])c1[2H]] 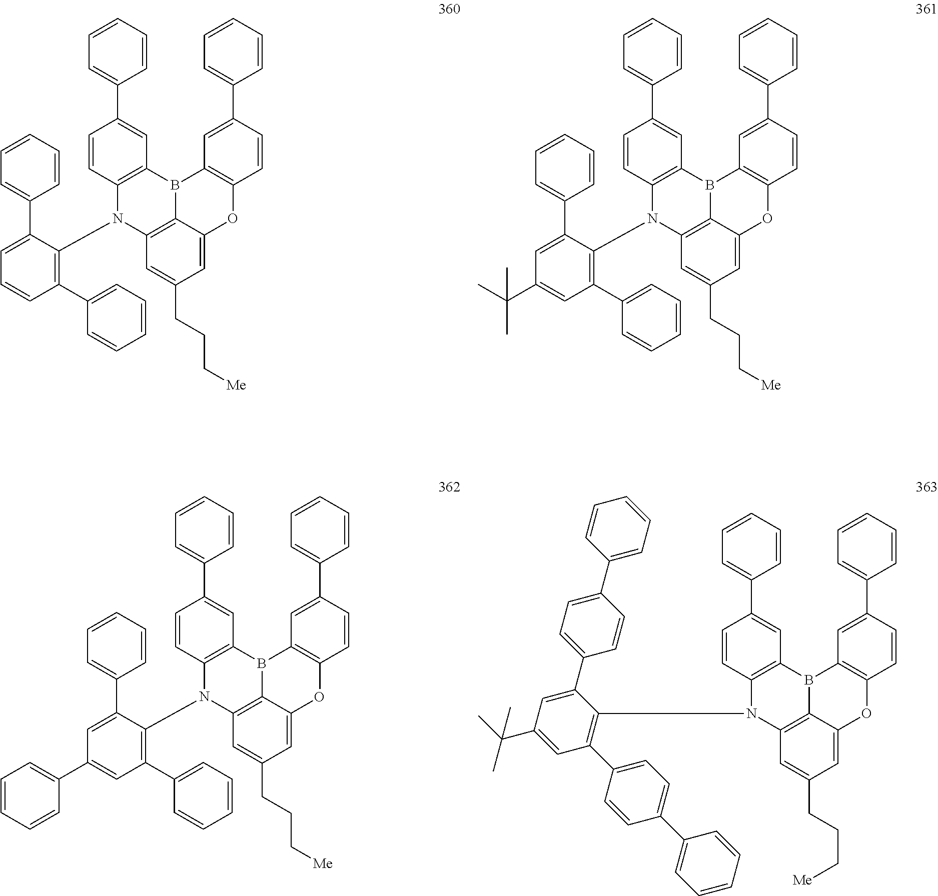 [SMILES: CCCCc1cc2c3c(c1)N(c1c(-c4ccccc4)cccc1-c1ccccc1)c1ccc(-c4ccccc4)cc1B3c1cc(-c3ccccc3)ccc1O2 ; CCCCc1cc2c3c(c1)N(c1c(-c4ccccc4)cc(C(C)(C)C)cc1-c1ccccc1)c1ccc(-c4ccccc4)cc1B3c1cc(-c3ccccc3)ccc1O2 ; CCCCc1cc2c3c(c1)N(c1c(-c4ccccc4)cc(-c4ccccc4)cc1-c1ccccc1)c1ccc(-c4ccccc4)cc1B3c1cc(-c3ccccc3)ccc1O2 ; CCCCc1cc2c3c(c1)N(c1c(-c4ccc(-c5ccccc5)cc4)cc(C(C)(C)C)cc1-c1ccc(-c4ccccc4)cc1)c1ccc(-c4ccccc4)cc1B3c1cc(-c3ccccc3)ccc1O2] 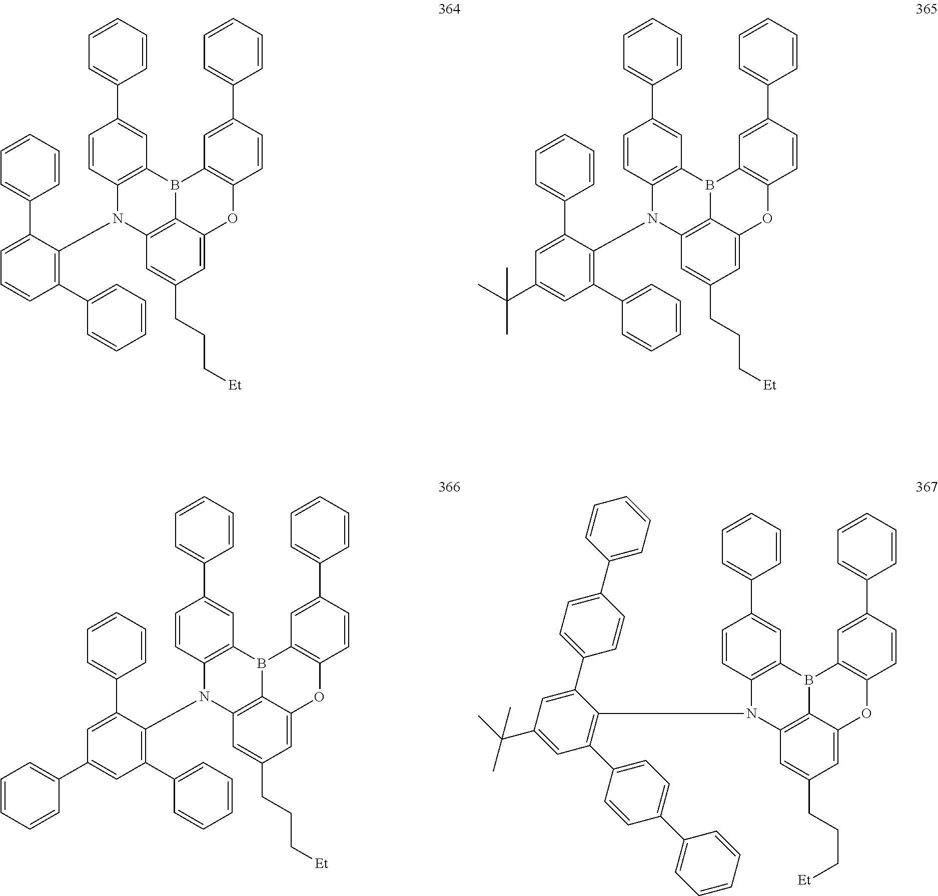 [SMILES: CCCCCc1cc2c3c(c1)N(c1c(-c4ccccc4)cccc1-c1ccccc1)c1ccc(-c4ccccc4)cc1B3c1cc(-c3ccccc3)ccc1O2 ; CCCCCc1cc2c3c(c1)N(c1c(-c4ccccc4)cc(C(C)(C)C)cc1-c1ccccc1)c1ccc(-c4ccccc4)cc1B3c1cc(-c3ccccc3)ccc1O2 ; CCCCCc1cc2c3c(c1)N(c1c(-c4ccccc4)cc(-c4ccccc4)cc1-c1ccccc1)c1ccc(-c4ccccc4)cc1B3c1cc(-c3ccccc3)ccc1O2 ; CCCCCc1cc2c3c(c1)N(c1c(-c4ccc(-c5ccccc5)cc4)cc(C(C)(C)C)cc1-c1ccc(-c4ccccc4)cc1)c1ccc(-c4ccccc4)cc1B3c1cc(-c3ccccc3)ccc1O2] 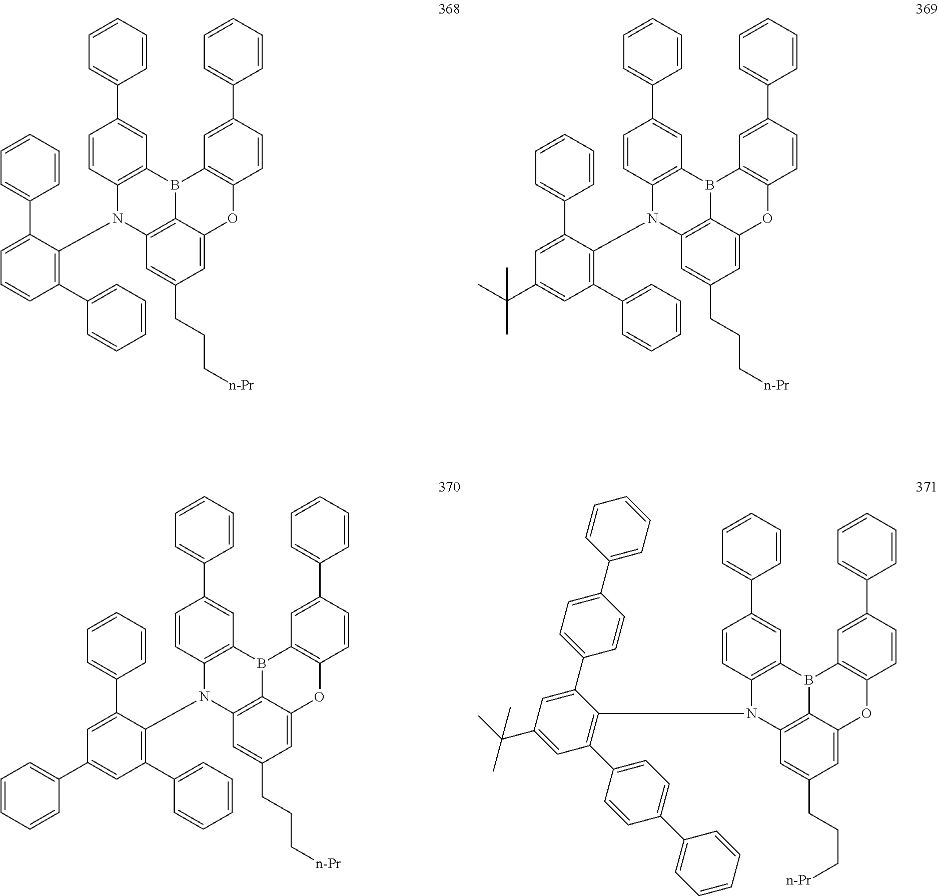 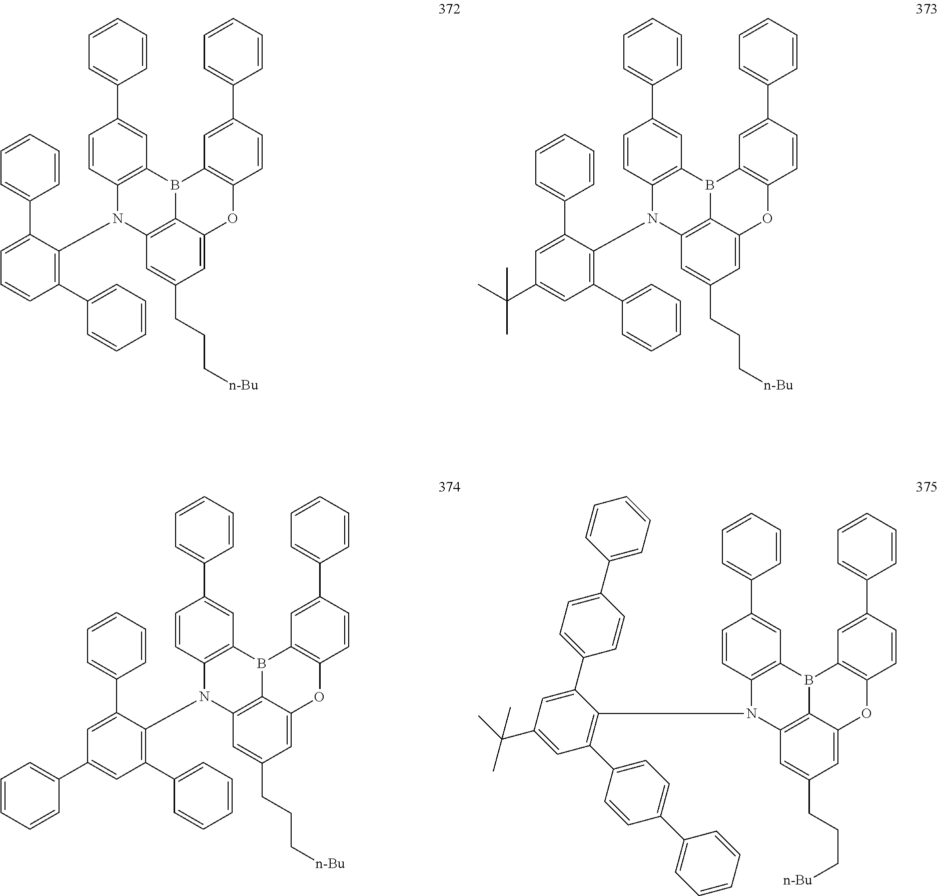 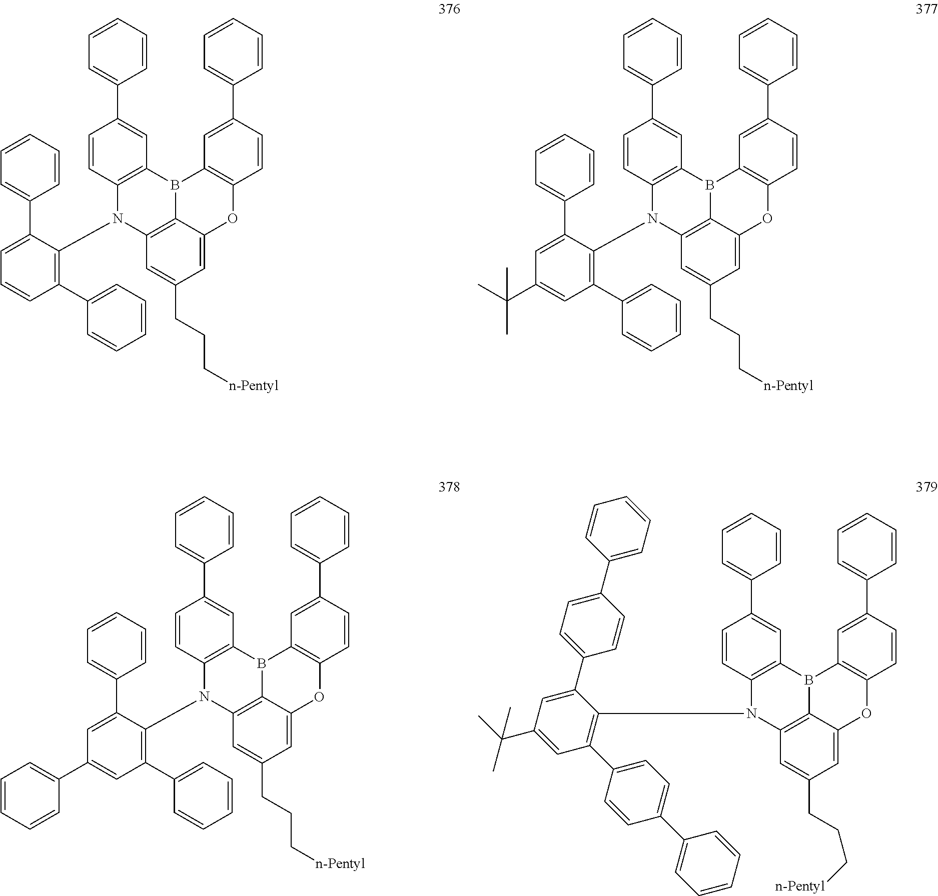 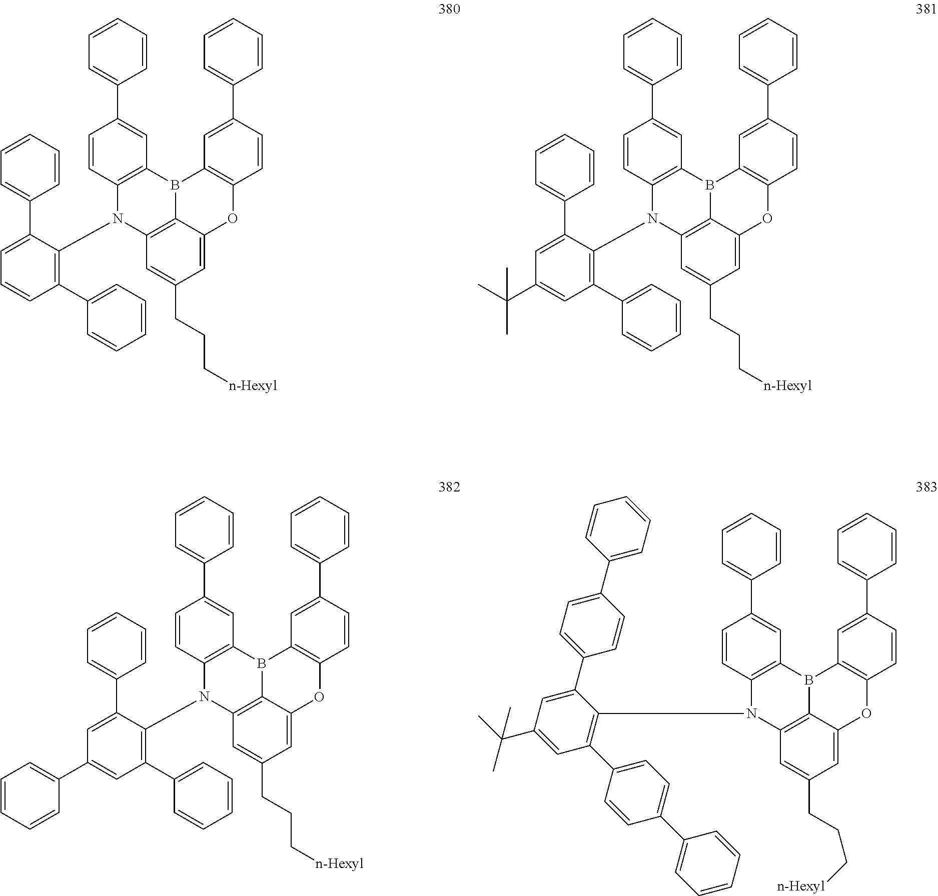 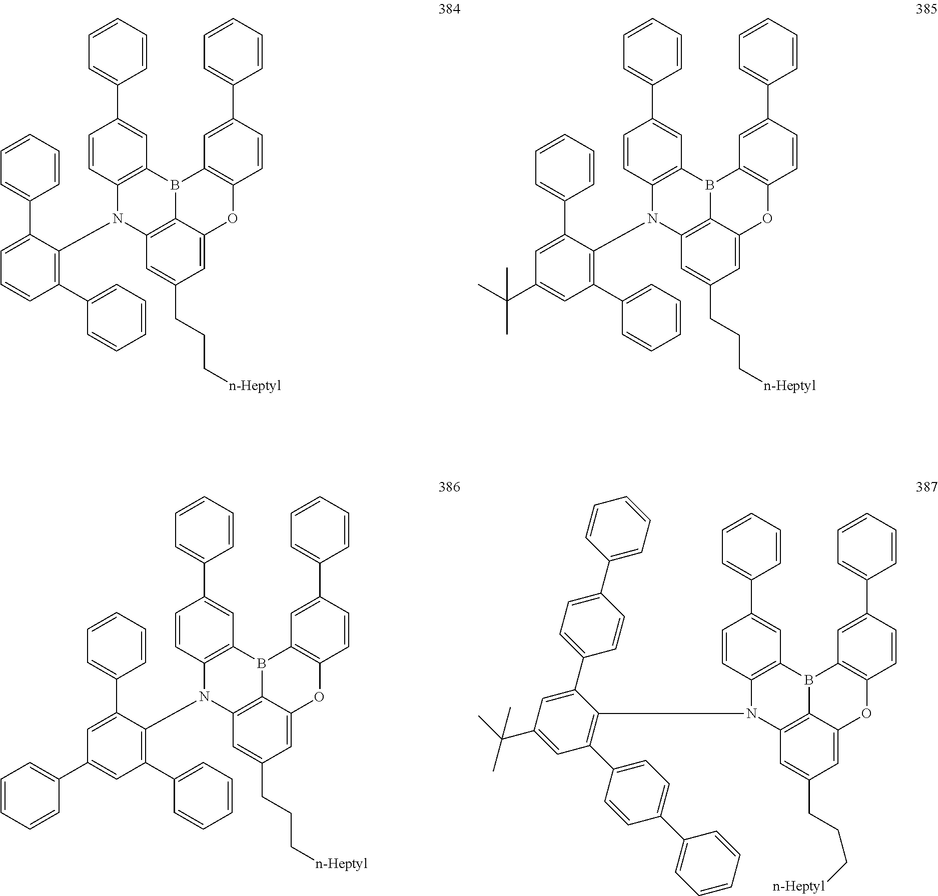 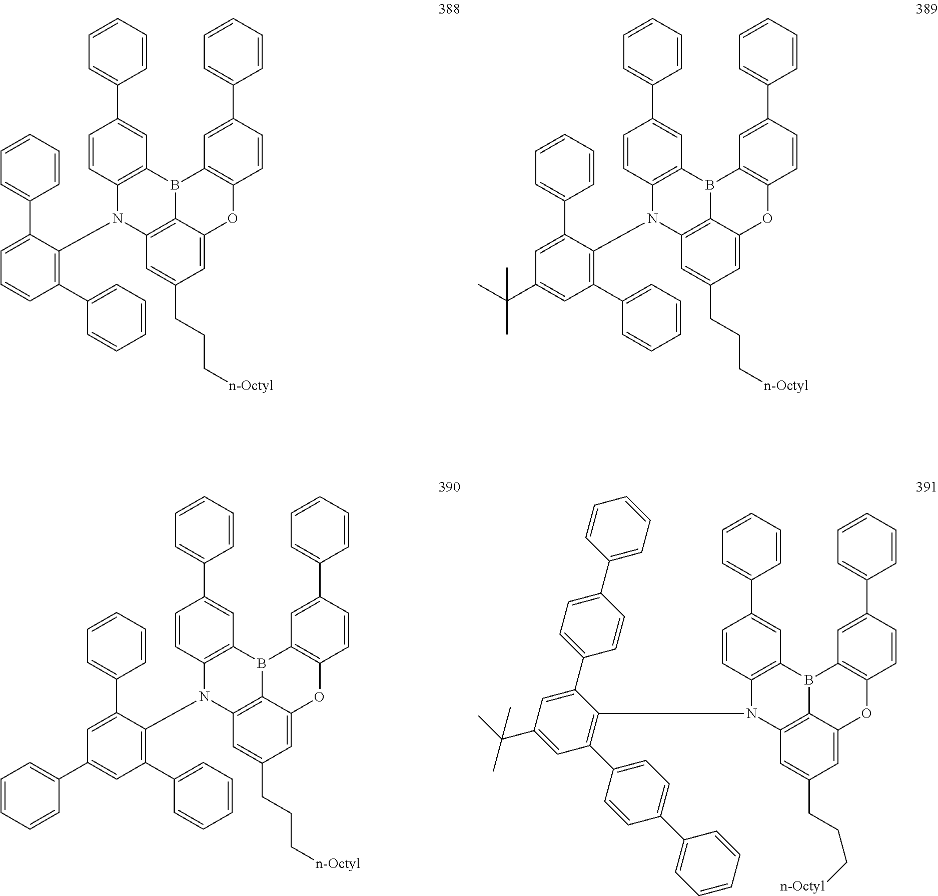 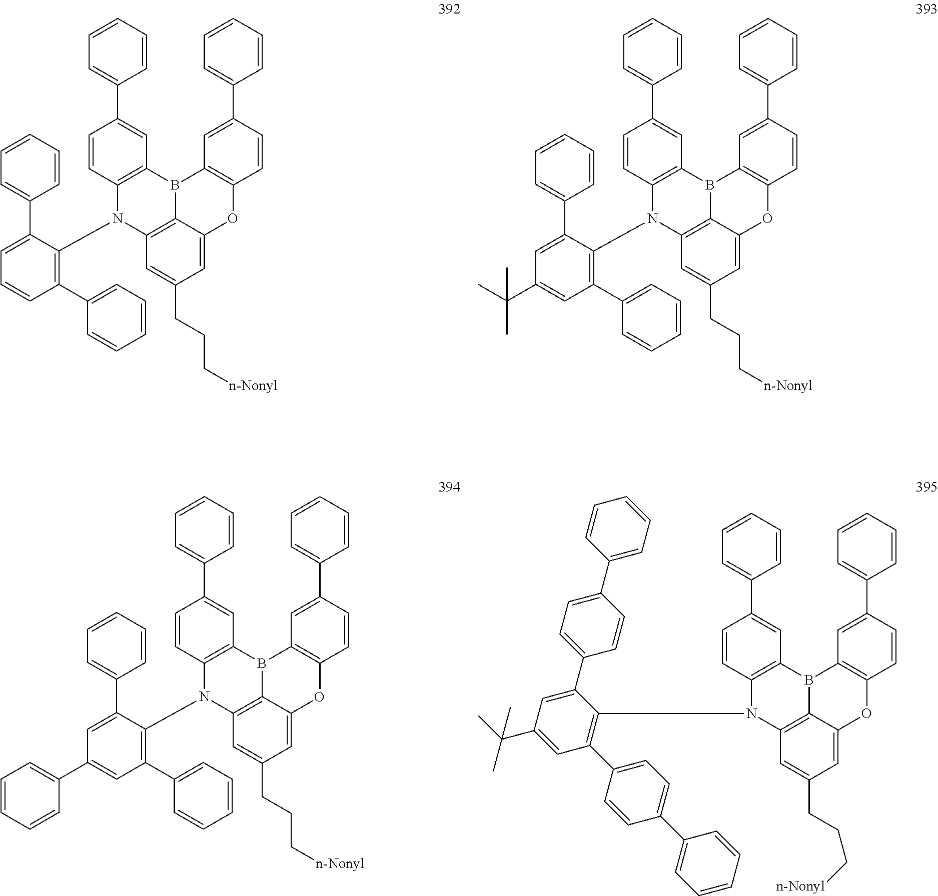 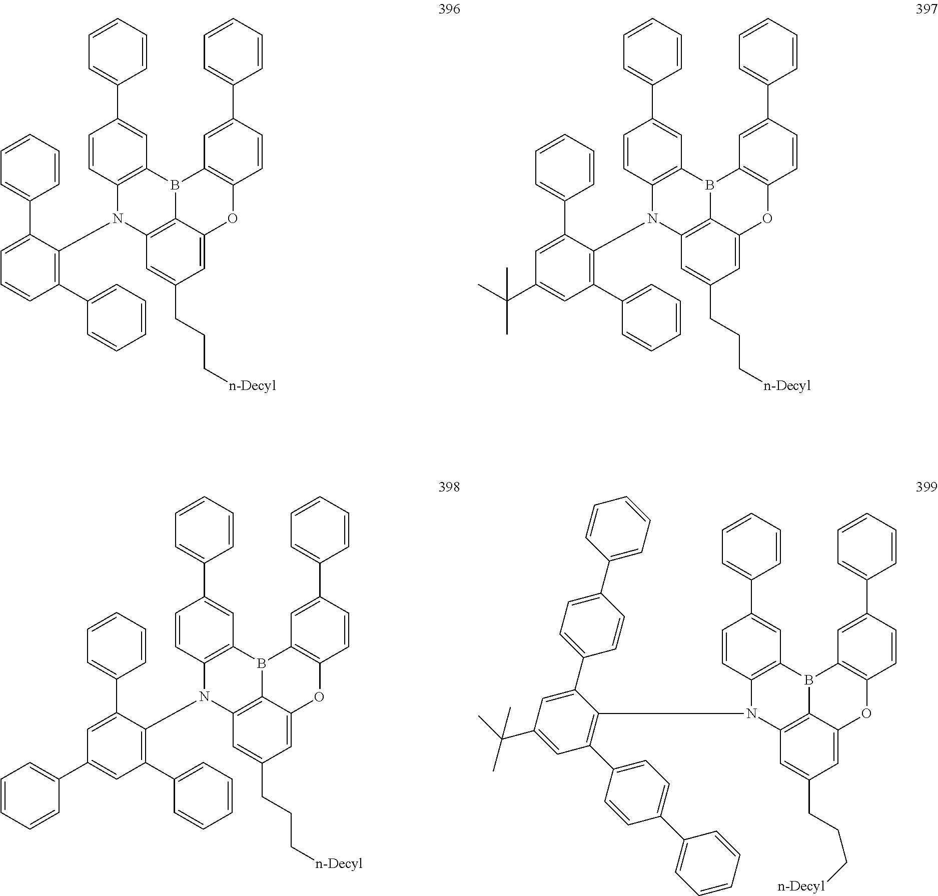 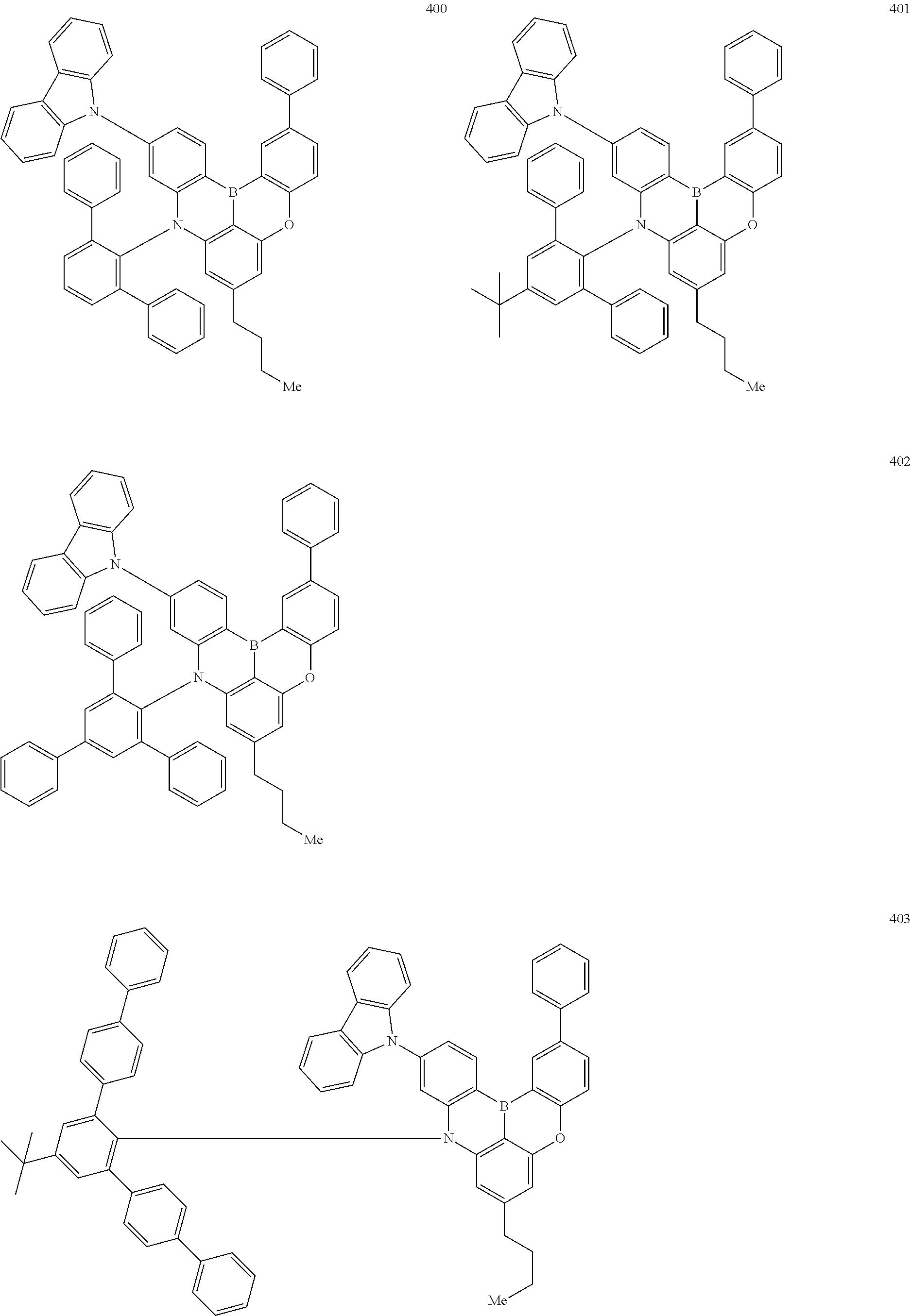 [SMILES: CCCCc1cc2c3c(c1)N(c1c(-c4ccccc4)cccc1-c1ccccc1)c1cc(-n4c5ccccc5c5ccccc54)ccc1B3c1cc(-c3ccccc3)ccc1O2 ; CCCCc1cc2c3c(c1)N(c1c(-c4ccccc4)cc(C(C)(C)C)cc1-c1ccccc1)c1cc(-n4c5ccccc5c5ccccc54)ccc1B3c1cc(-c3ccccc3)ccc1O2 ; CCCCc1cc2c3c(c1)N(c1c(-c4ccccc4)cc(-c4ccccc4)cc1-c1ccccc1)c1cc(-n4c5ccccc5c5ccccc54)ccc1B3c1cc(-c3ccccc3)ccc1O2 ; CCCCc1cc2c3c(c1)N(c1c(-c4ccc(-c5ccccc5)cc4)cc(C(C)(C)C)cc1-c1ccc(-c4ccccc4)cc1)c1cc(-n4c5ccccc5c5ccccc54)ccc1B3c1cc(-c3ccccc3)ccc1O2] 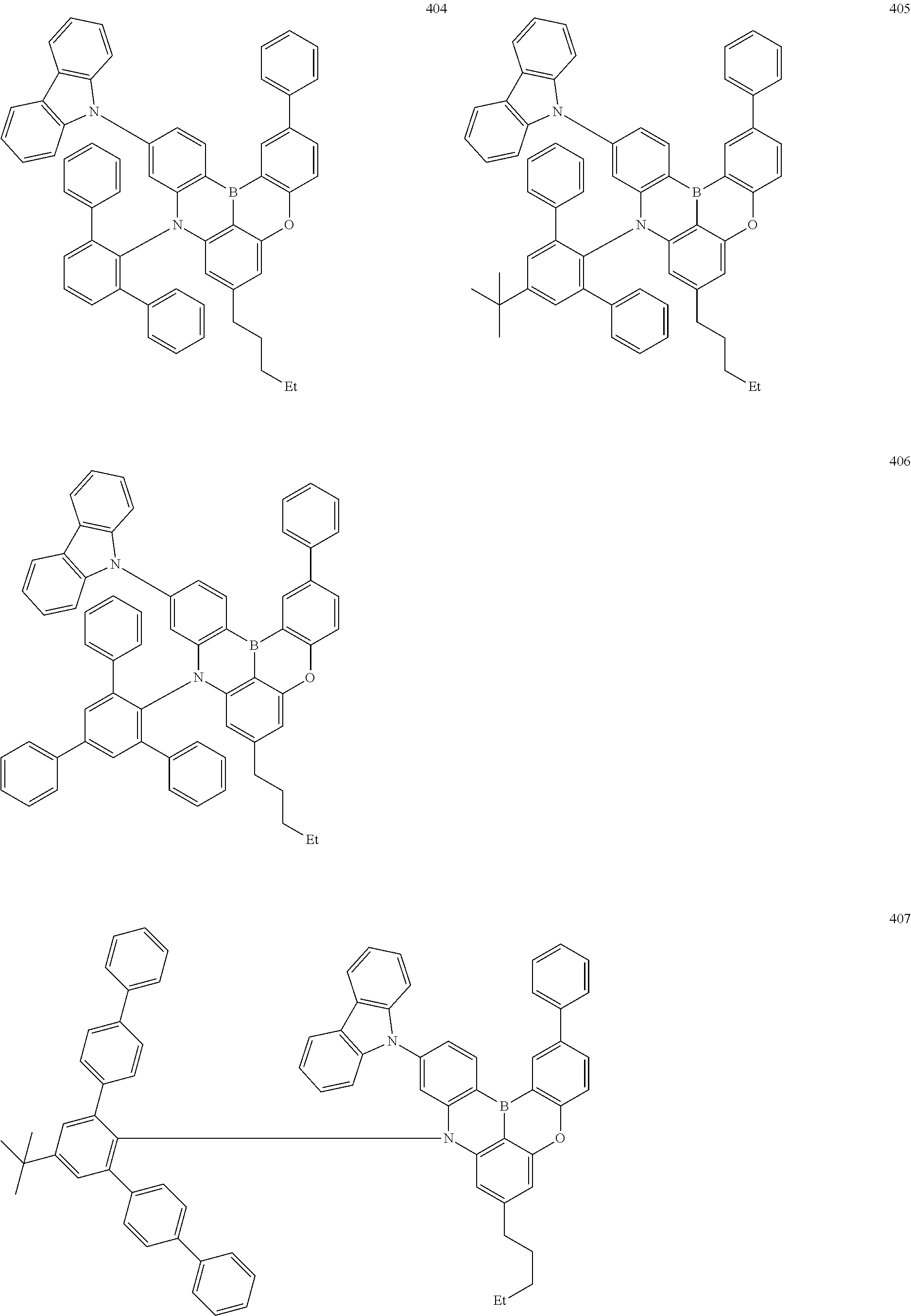 [SMILES: CCCCCc1cc2c3c(c1)N(c1c(-c4ccccc4)cccc1-c1ccccc1)c1cc(-n4c5ccccc5c5ccccc54)ccc1B3c1cc(-c3ccccc3)ccc1O2 ; CCCCCc1cc2c3c(c1)N(c1c(-c4ccccc4)cc(C(C)(C)C)cc1-c1ccccc1)c1cc(-n4c5ccccc5c5ccccc54)ccc1B3c1cc(-c3ccccc3)ccc1O2 ; CCCCCc1cc2c3c(c1)N(c1c(-c4ccccc4)cc(-c4ccccc4)cc1-c1ccccc1)c1cc(-n4c5ccccc5c5ccccc54)ccc1B3c1cc(-c3ccccc3)ccc1O2 ; CCCCCc1cc2c3c(c1)N(c1c(-c4ccc(-c5ccccc5)cc4)cc(C(C)(C)C)cc1-c1ccc(-c4ccccc4)cc1)c1cc(-n4c5ccccc5c5ccccc54)ccc1B3c1cc(-c3ccccc3)ccc1O2] 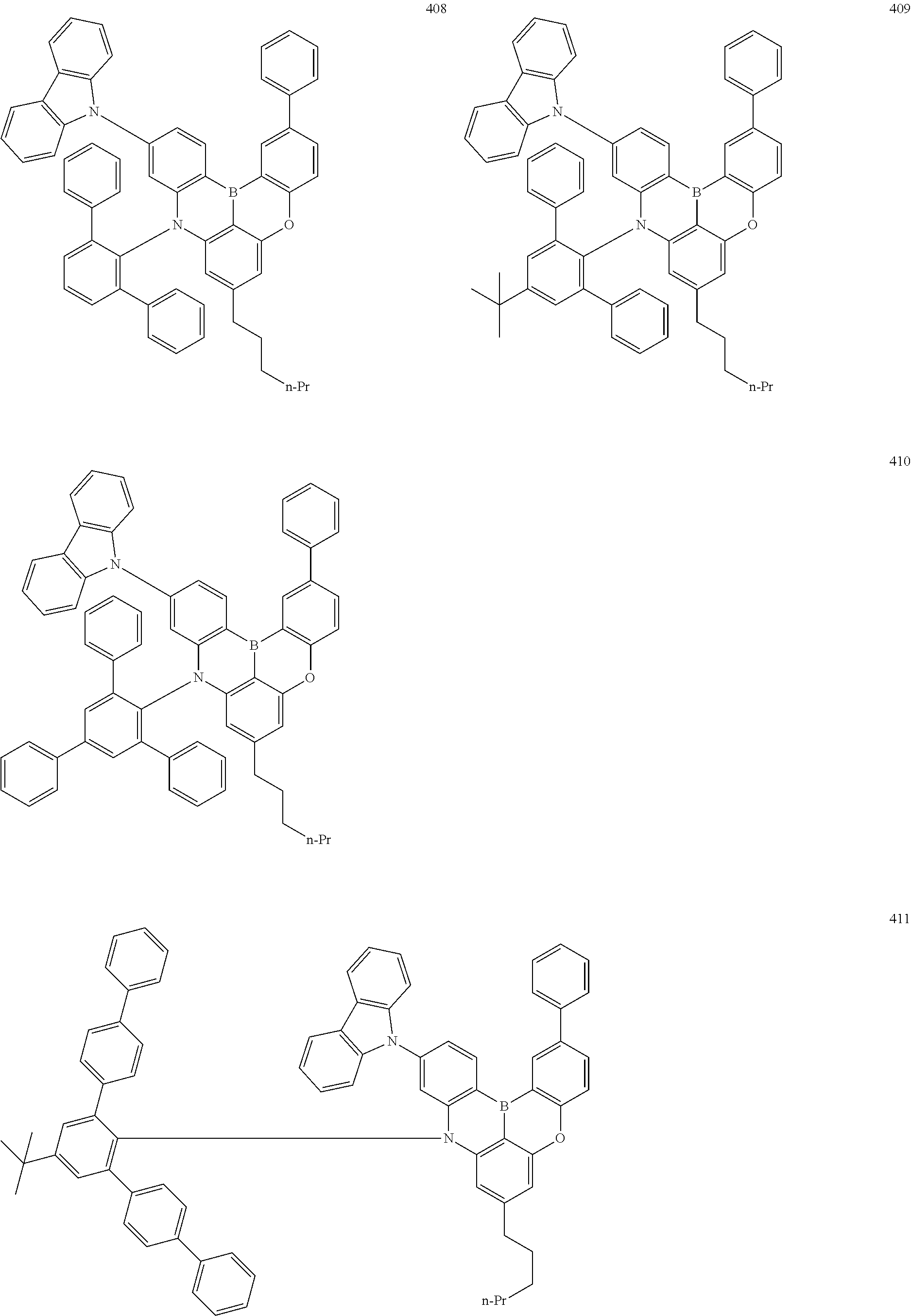 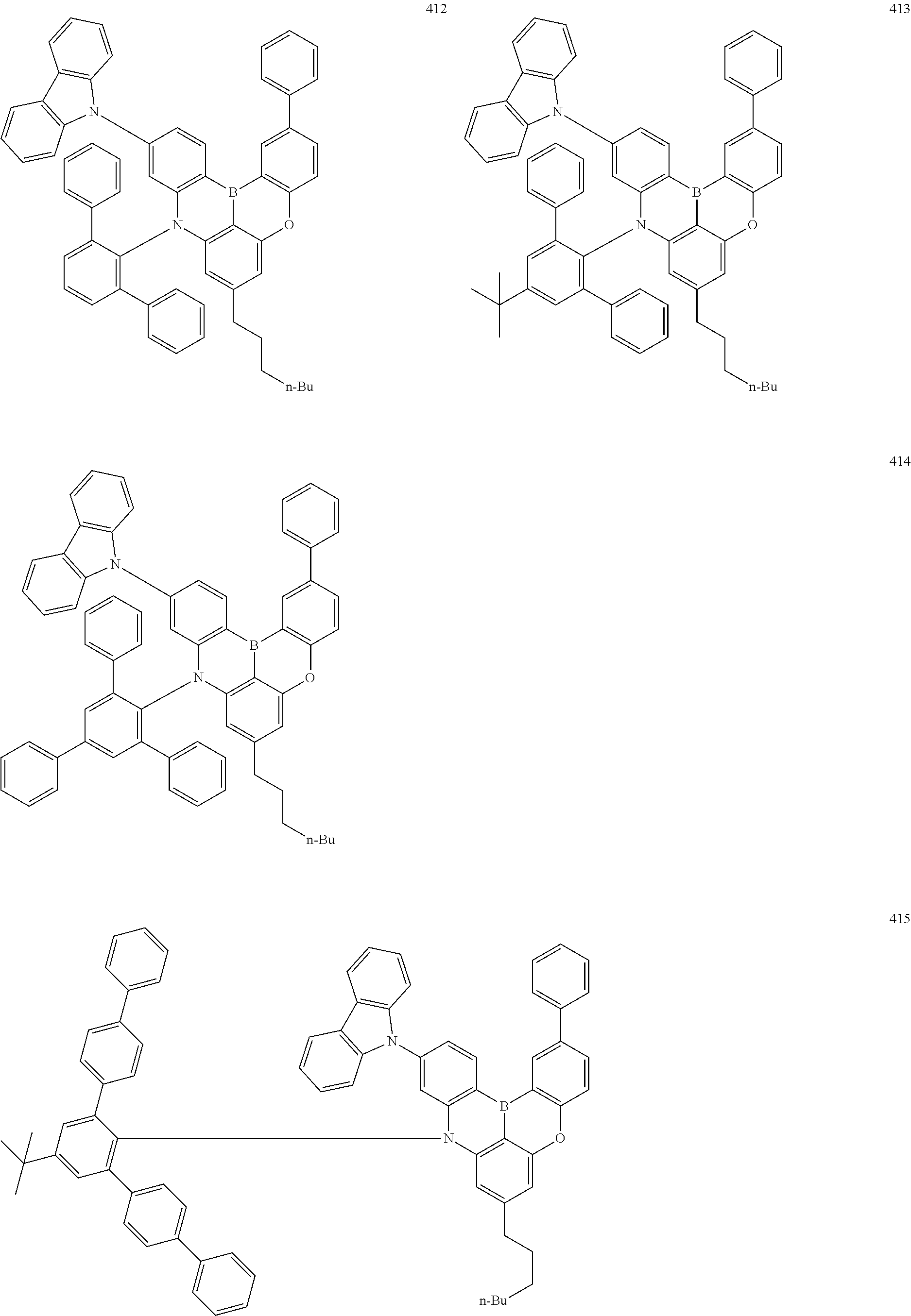 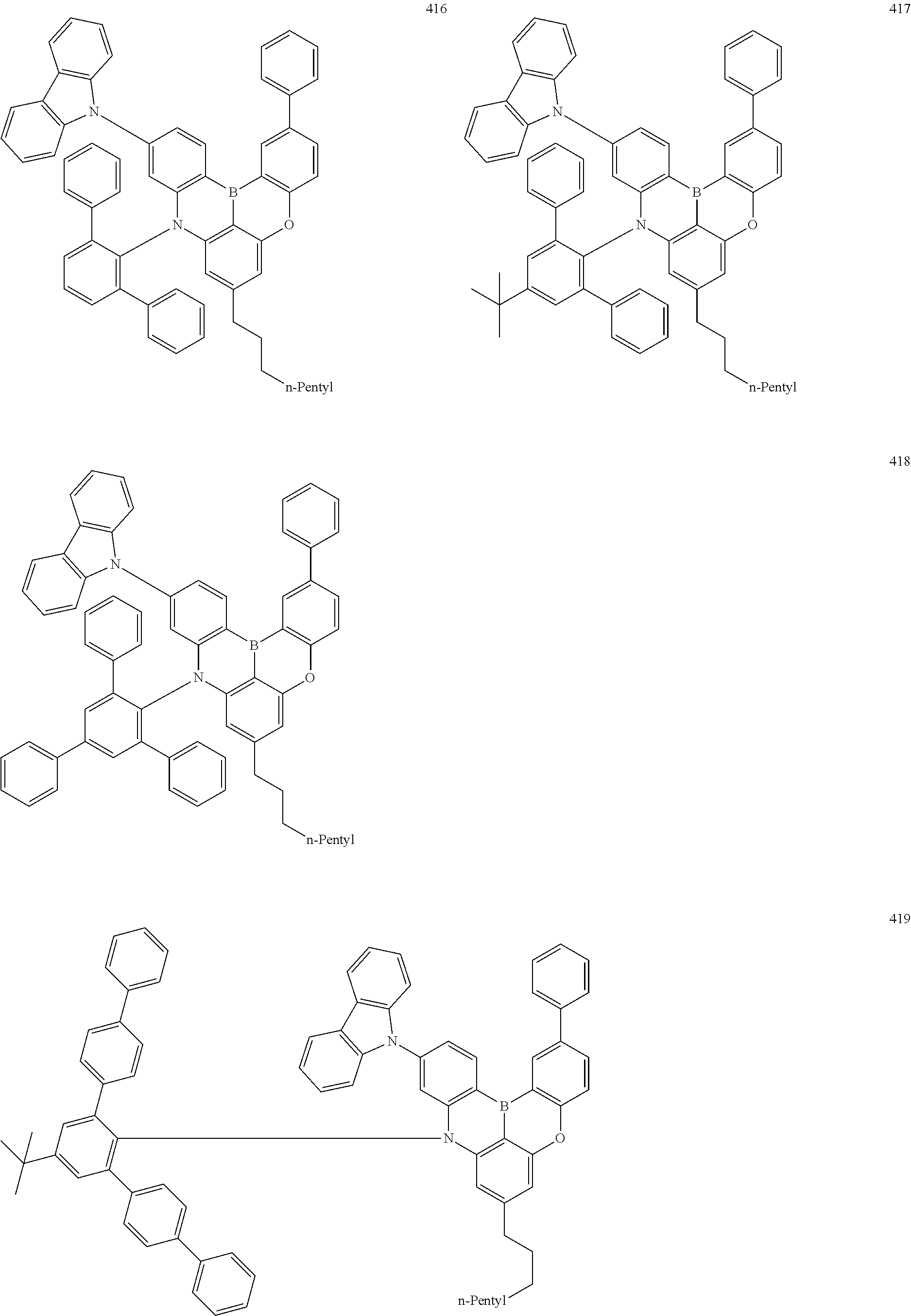 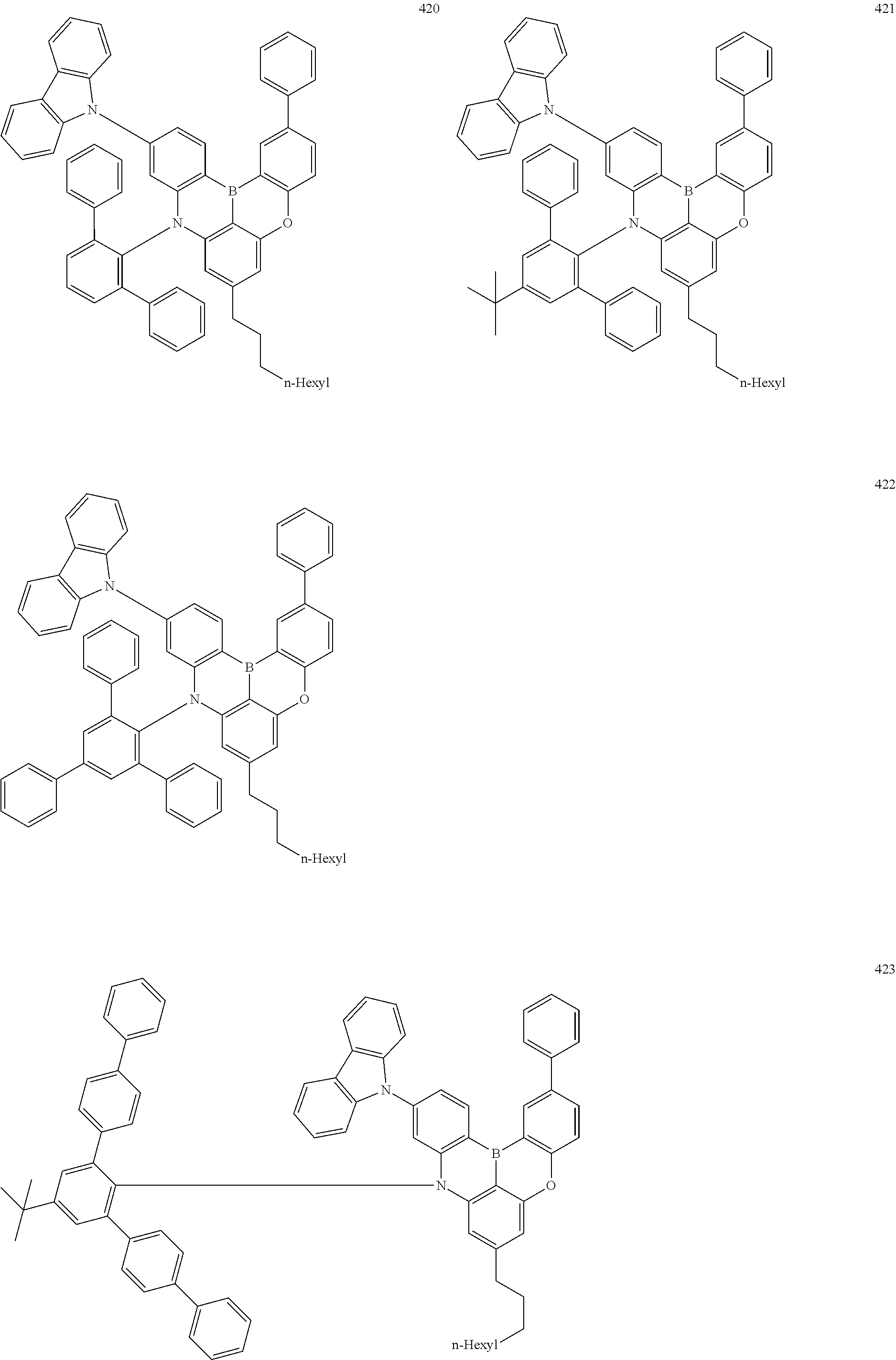 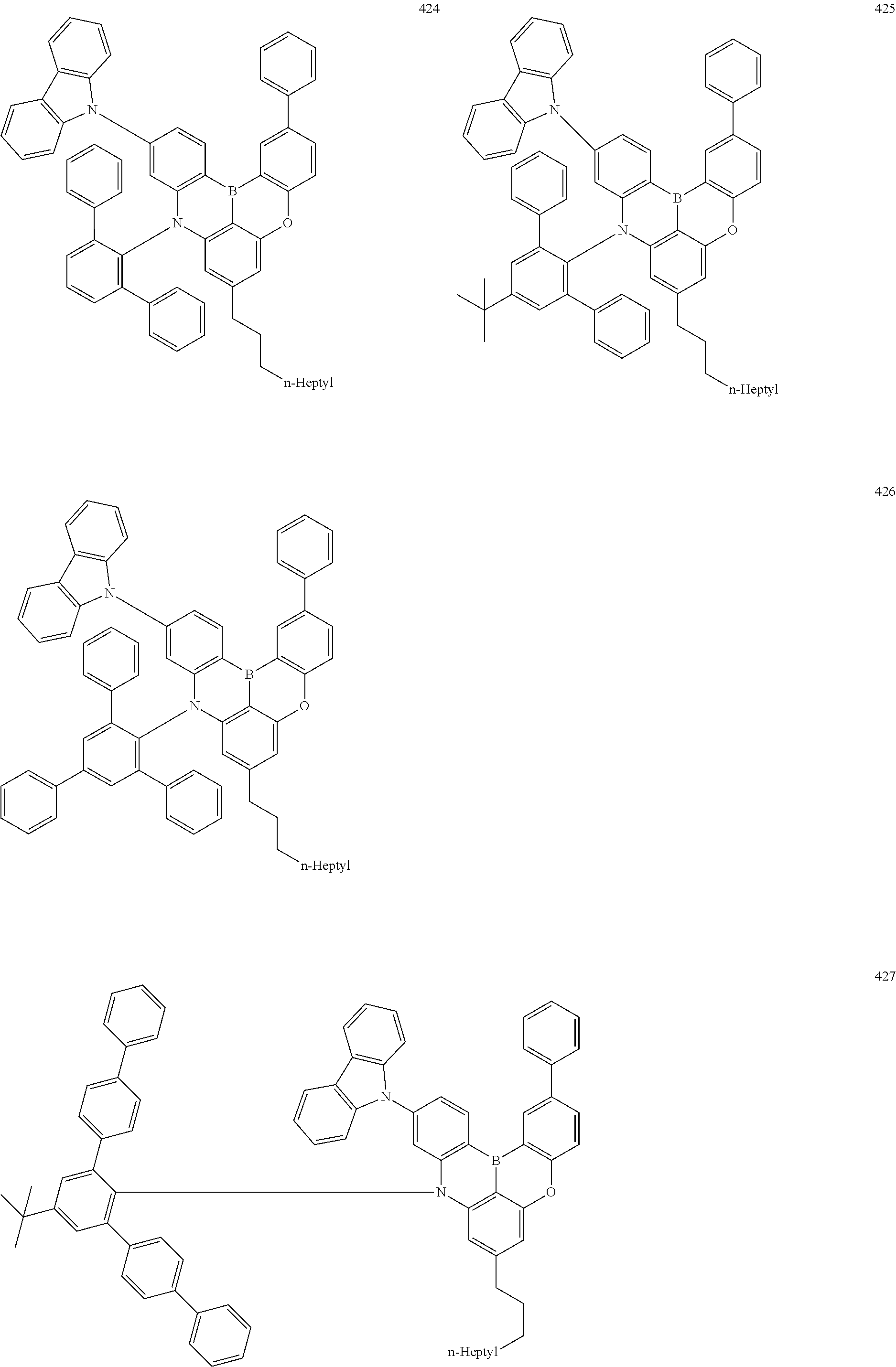 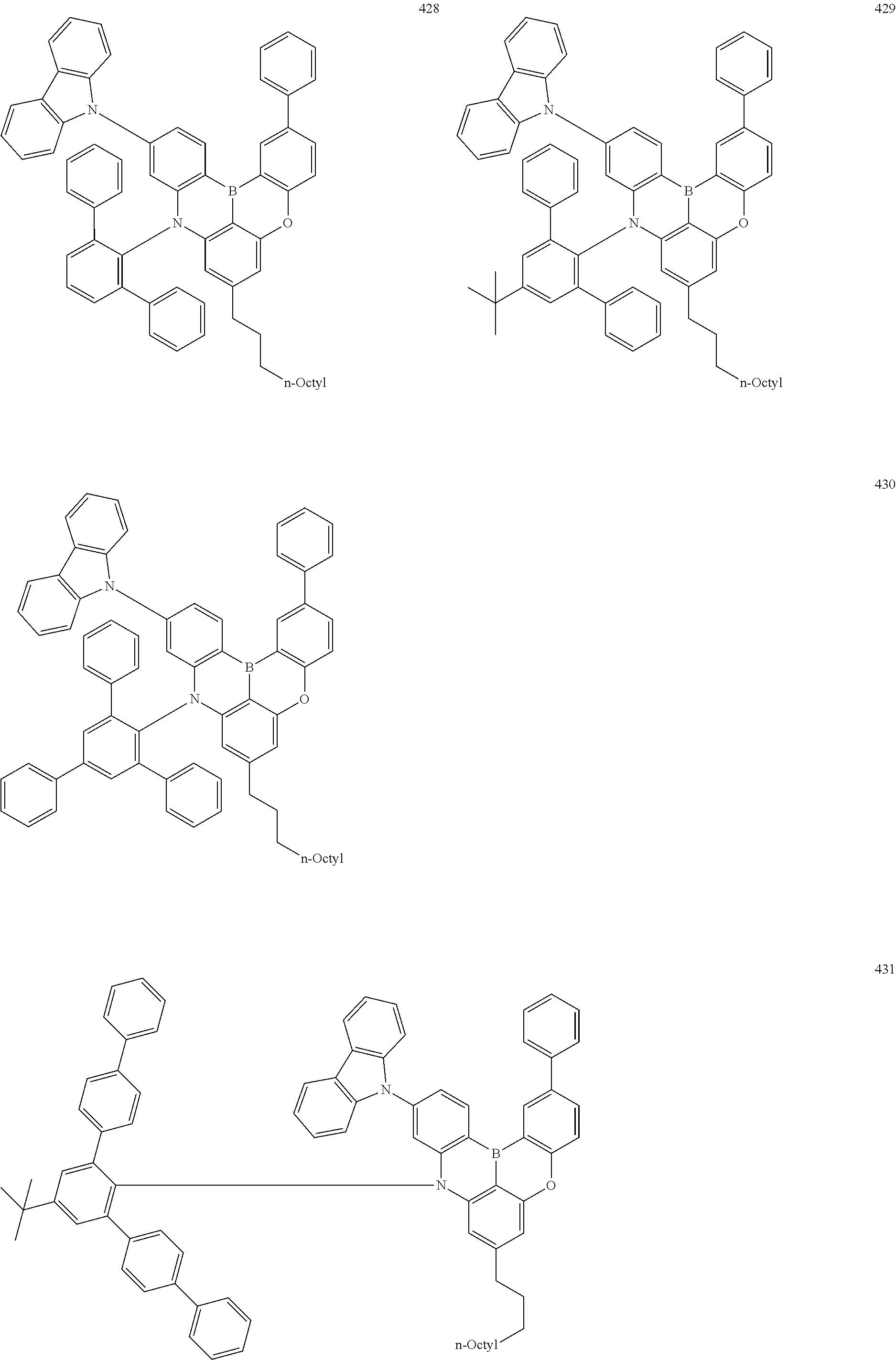 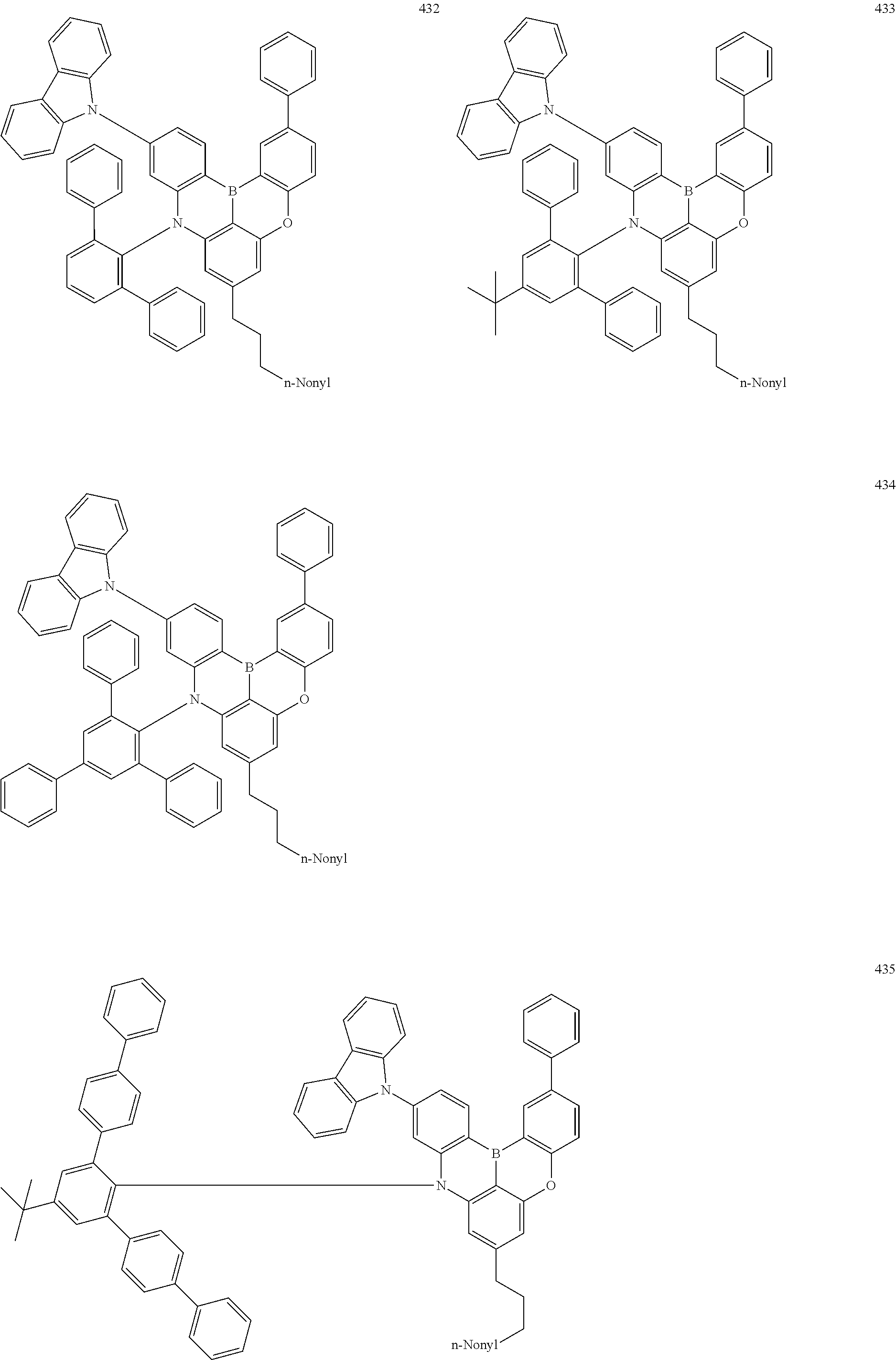 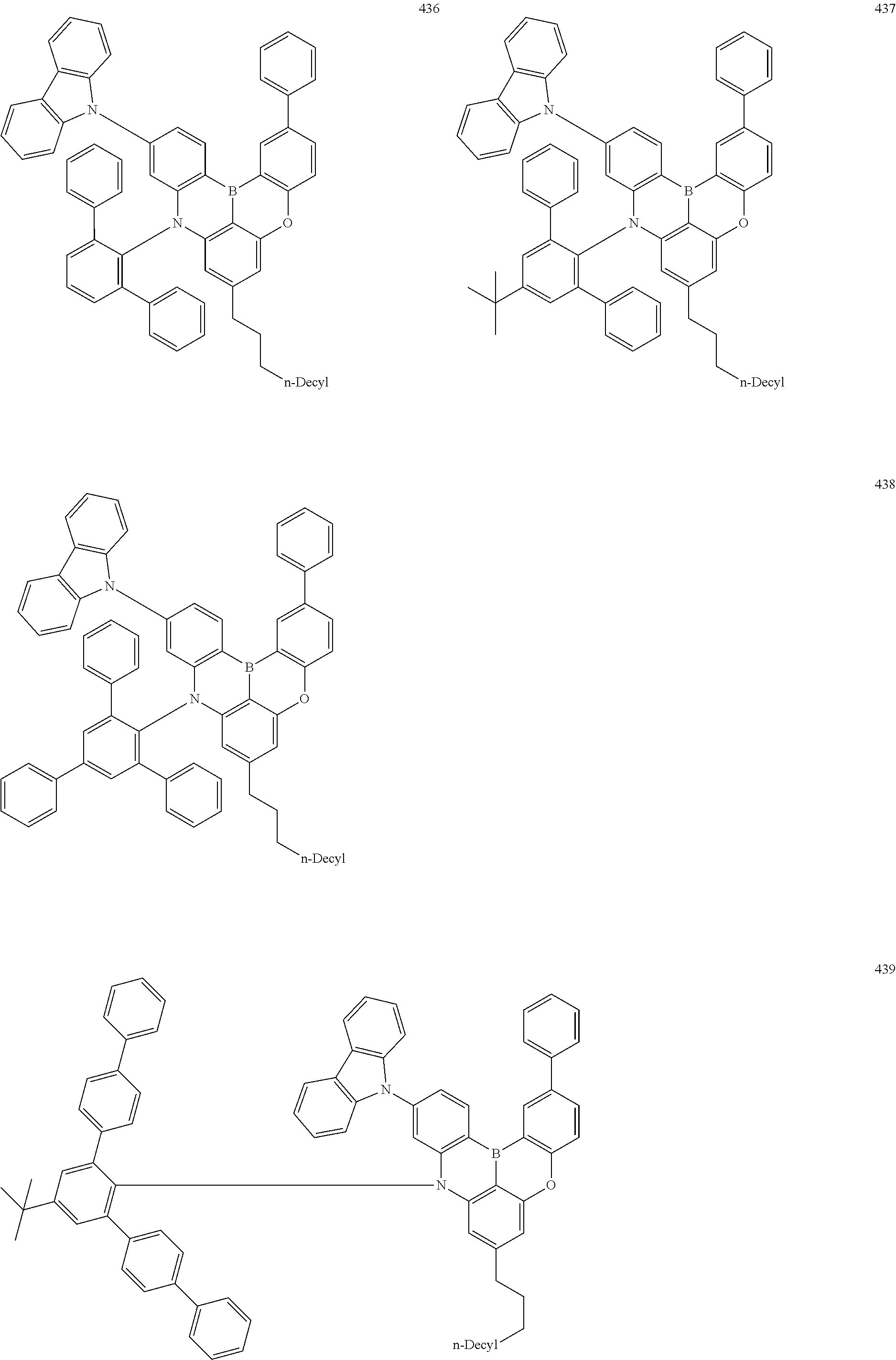 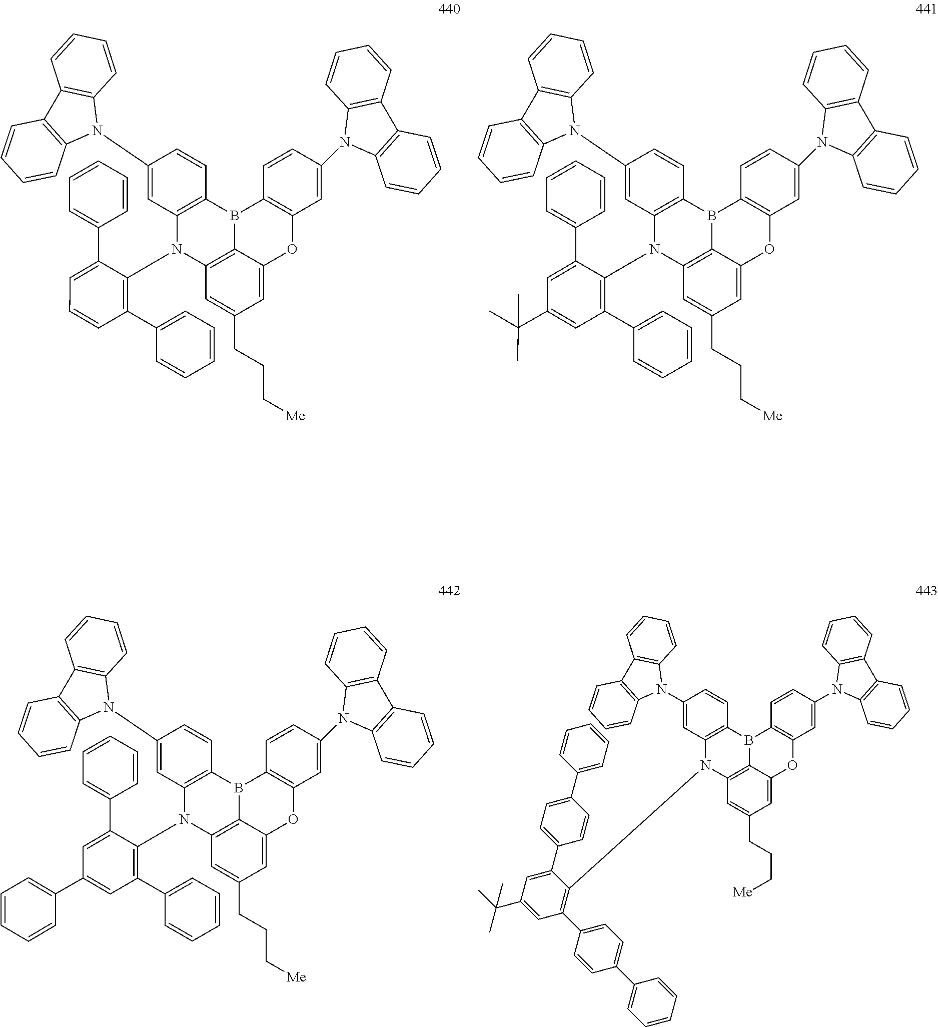 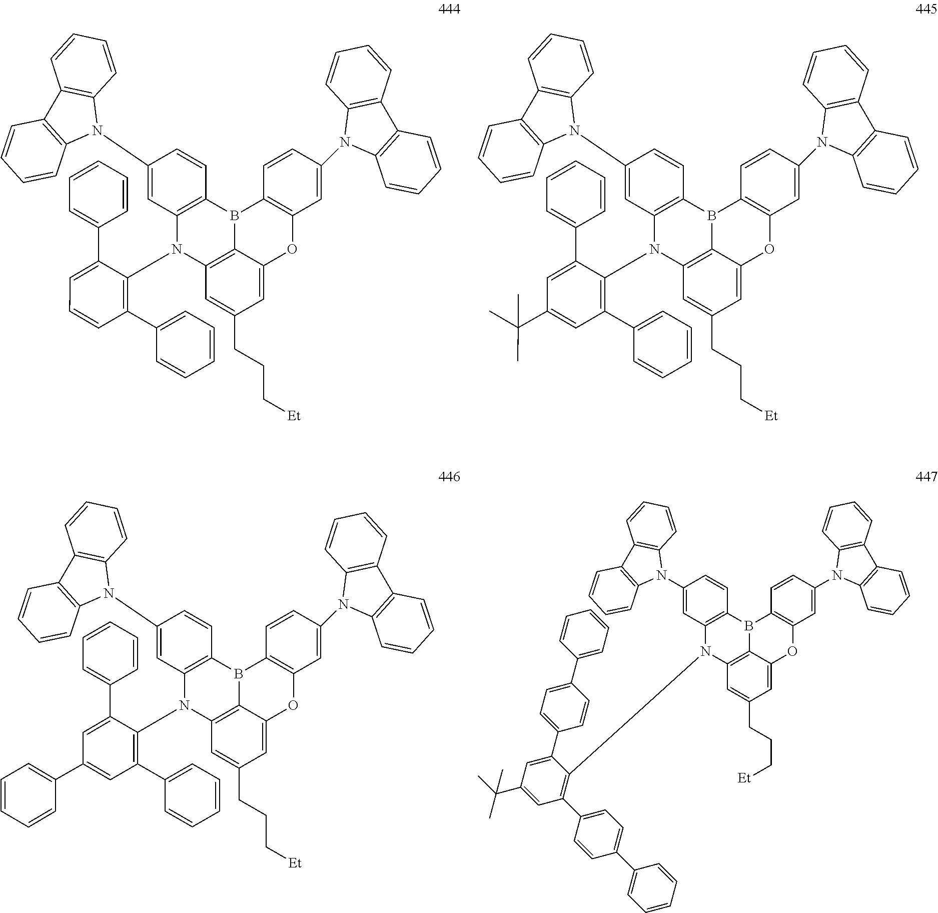 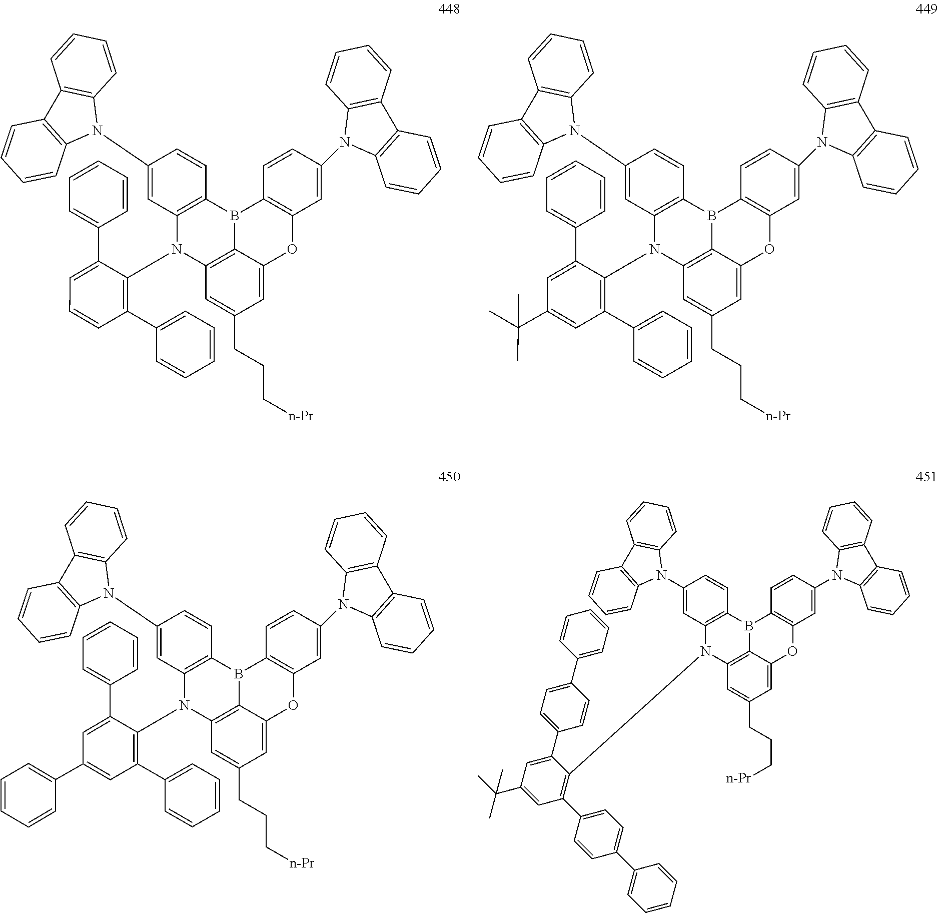 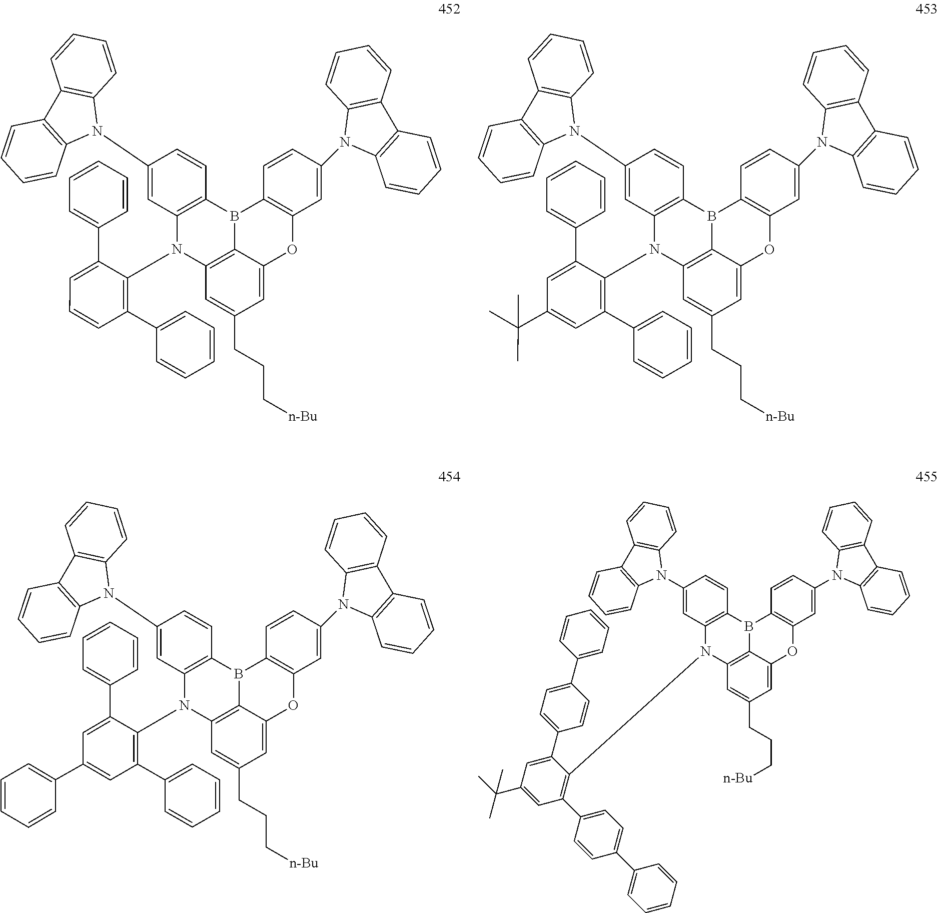 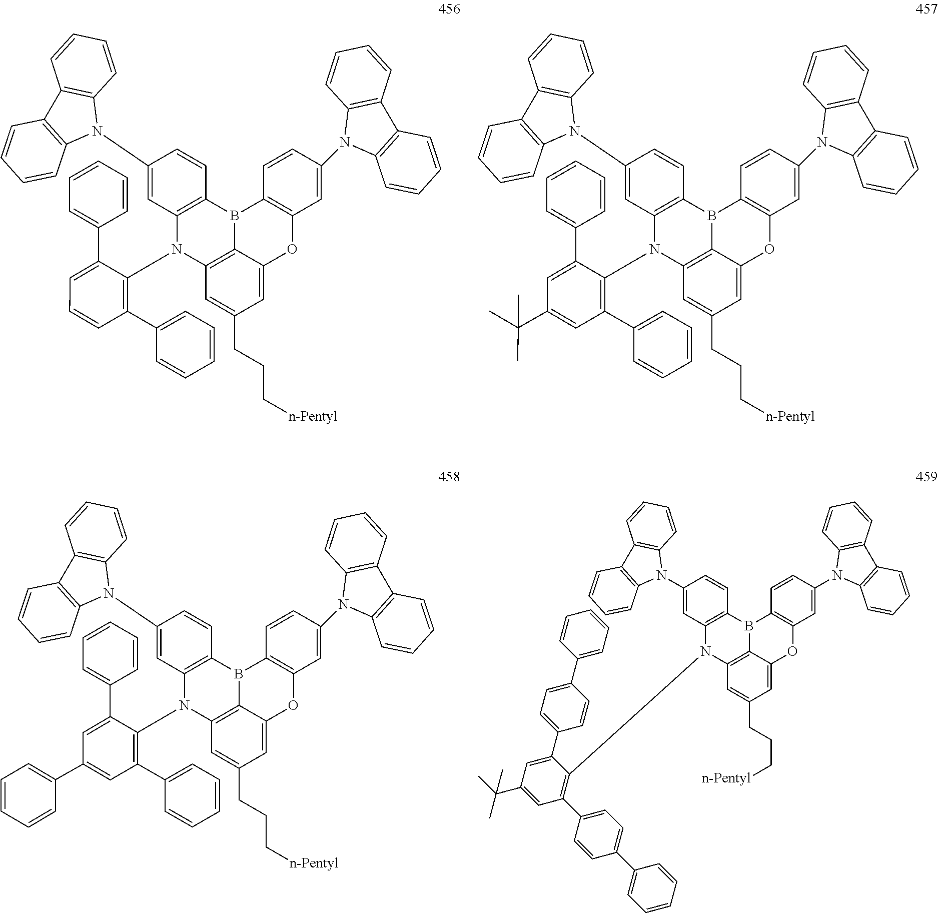 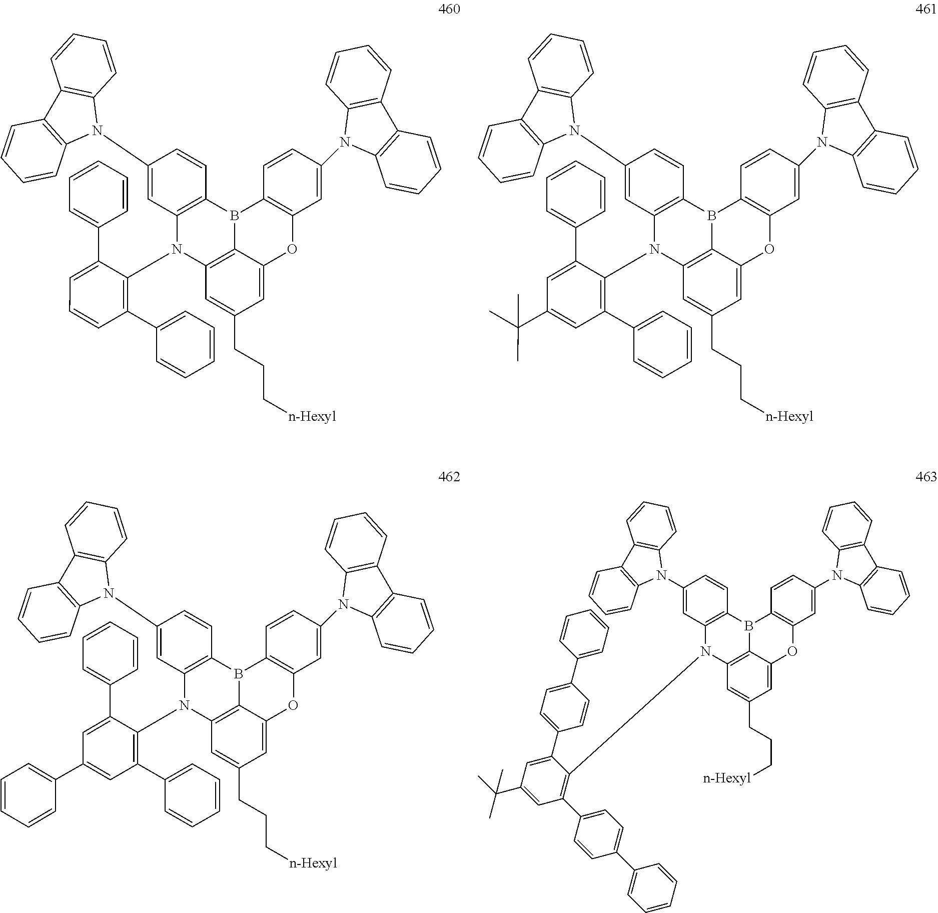 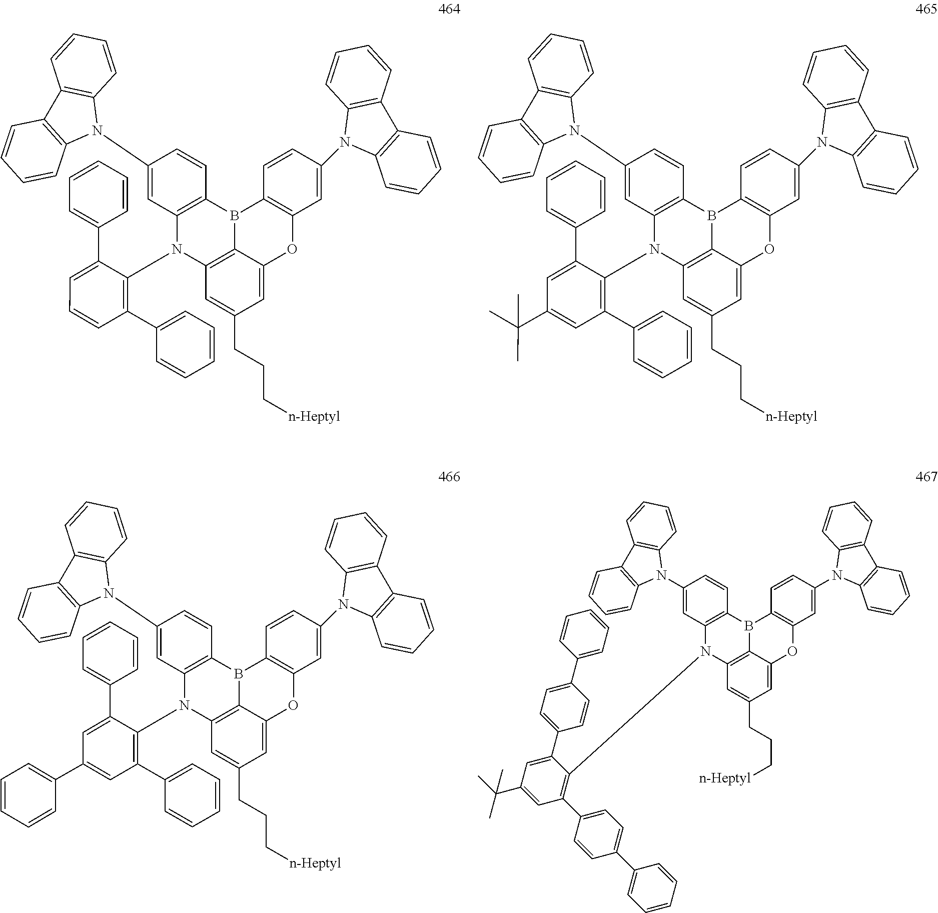 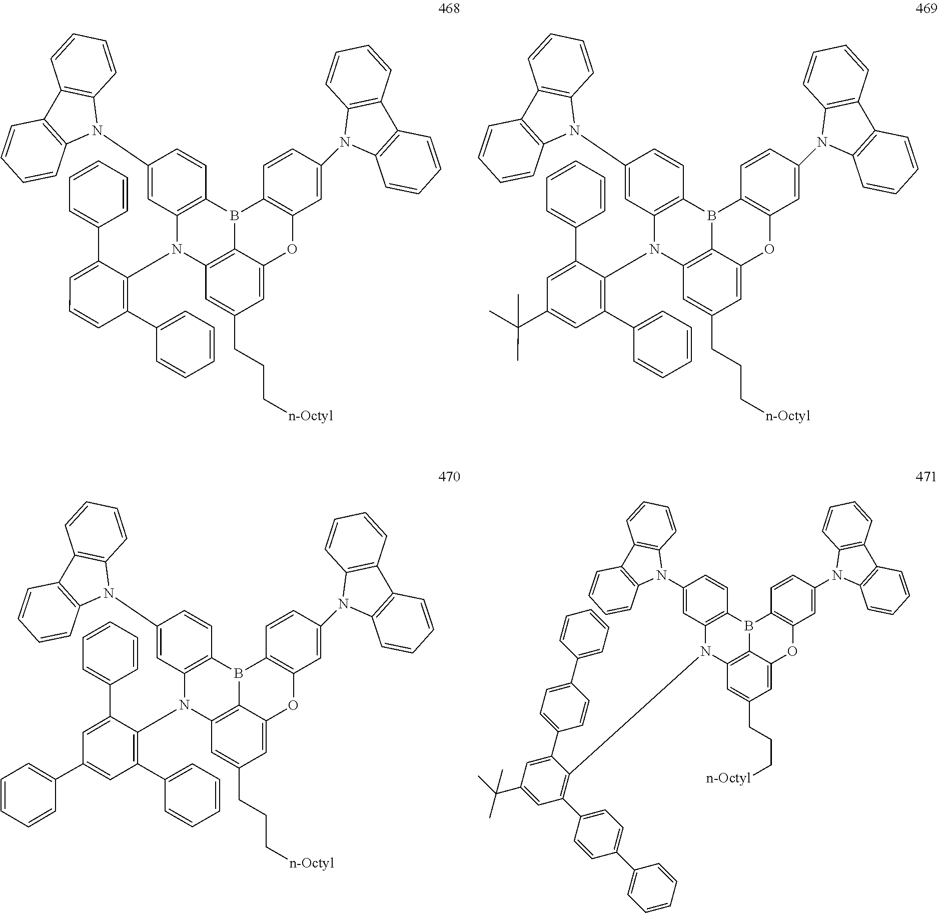 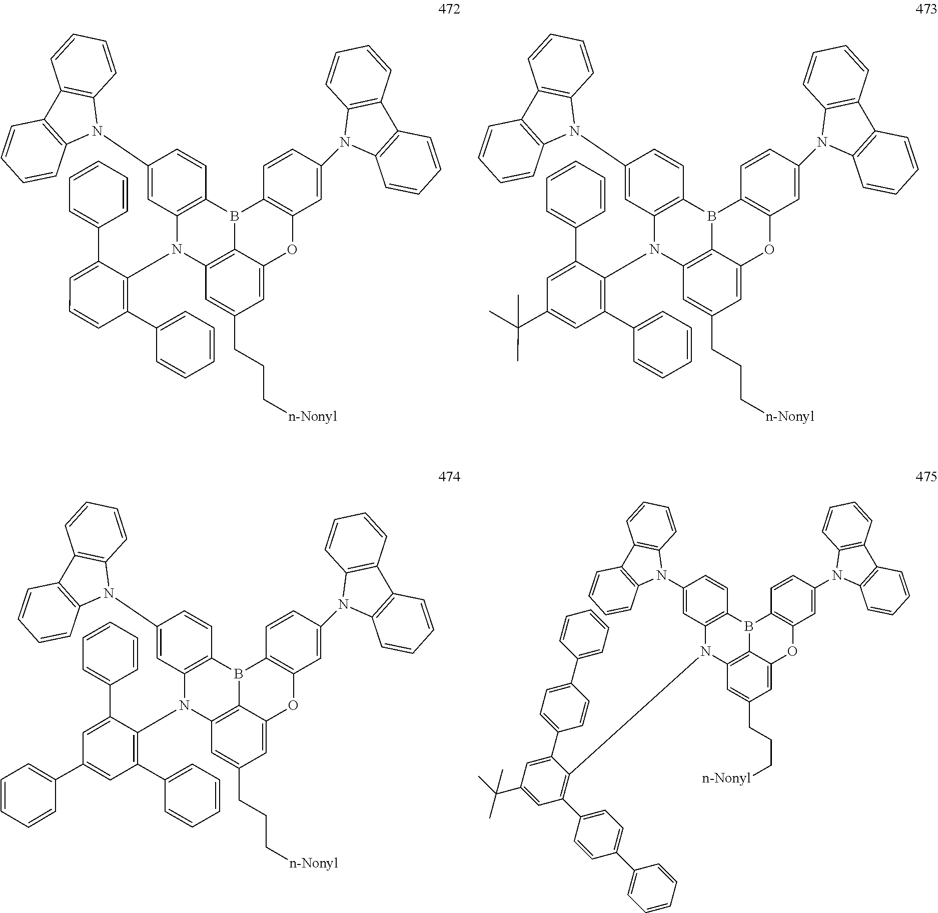 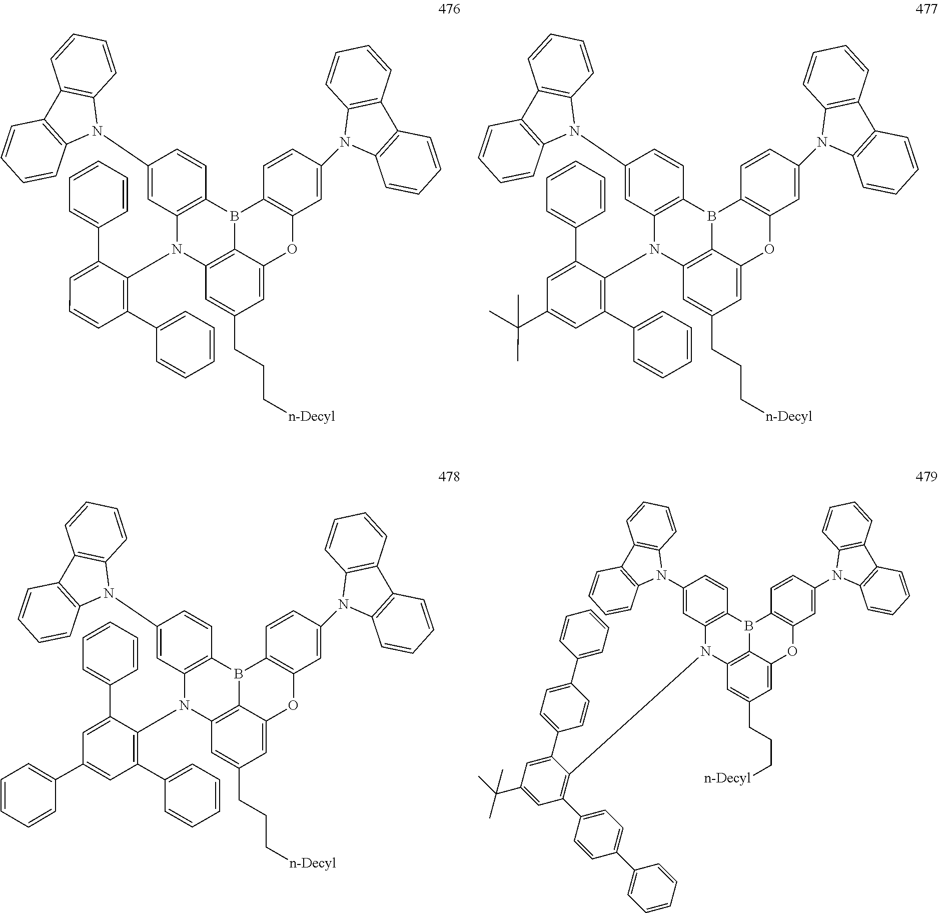 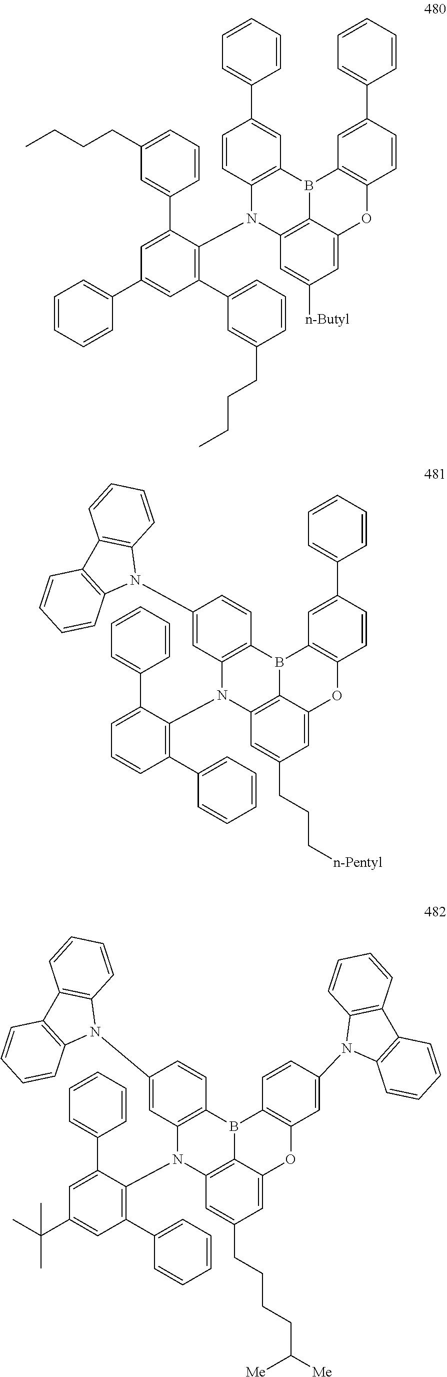 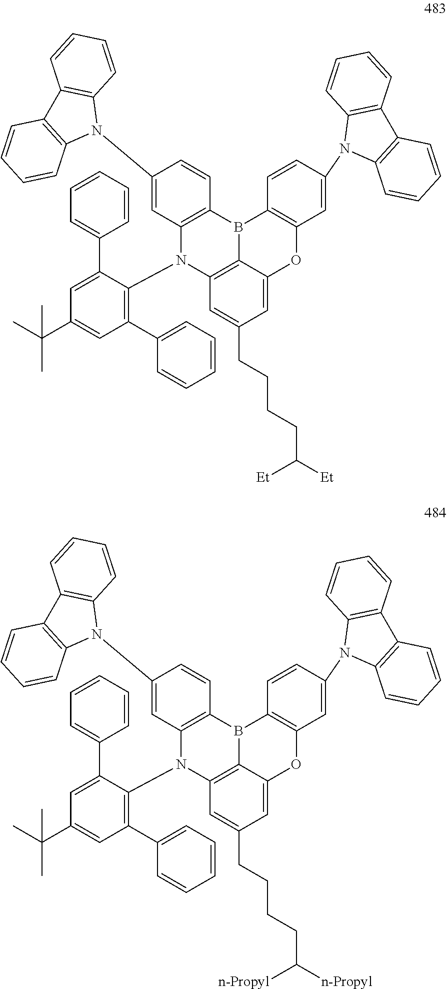 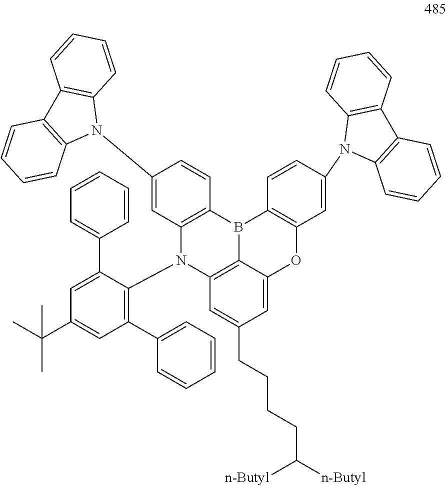 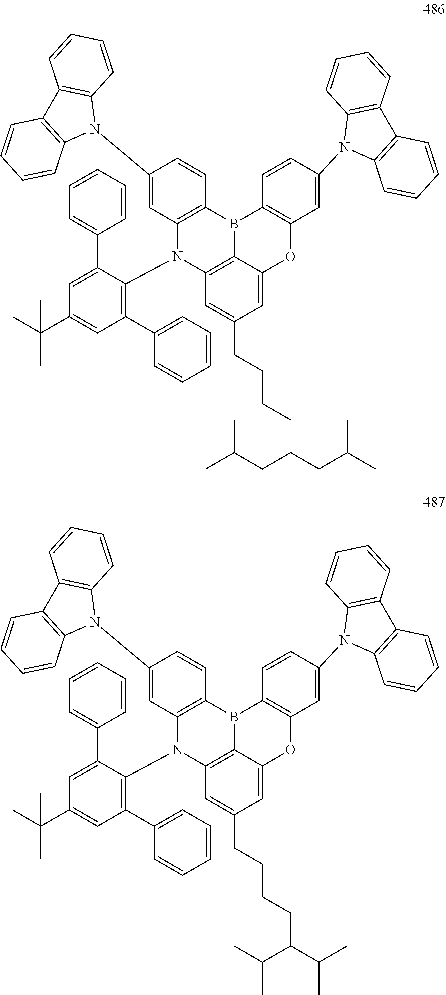 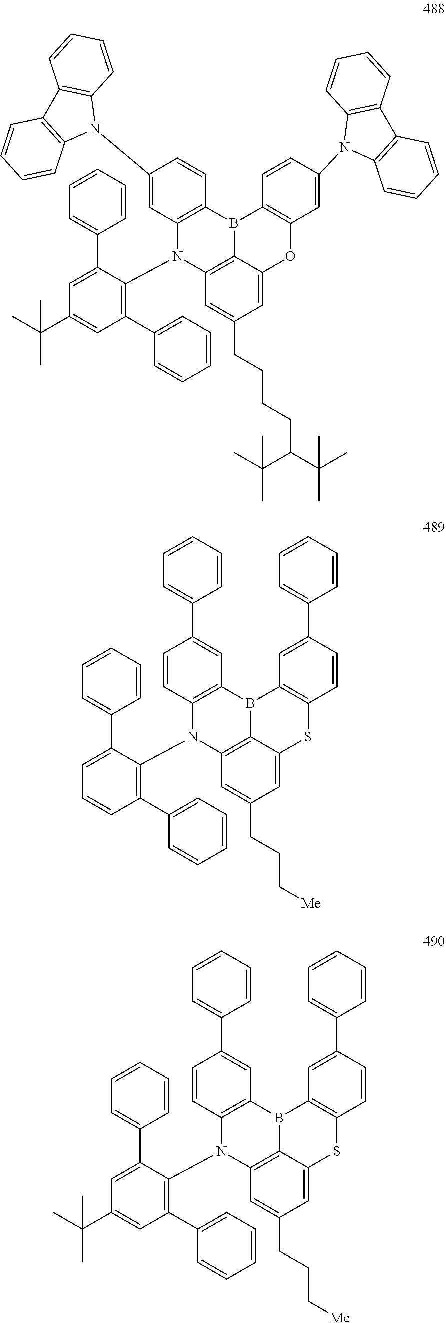 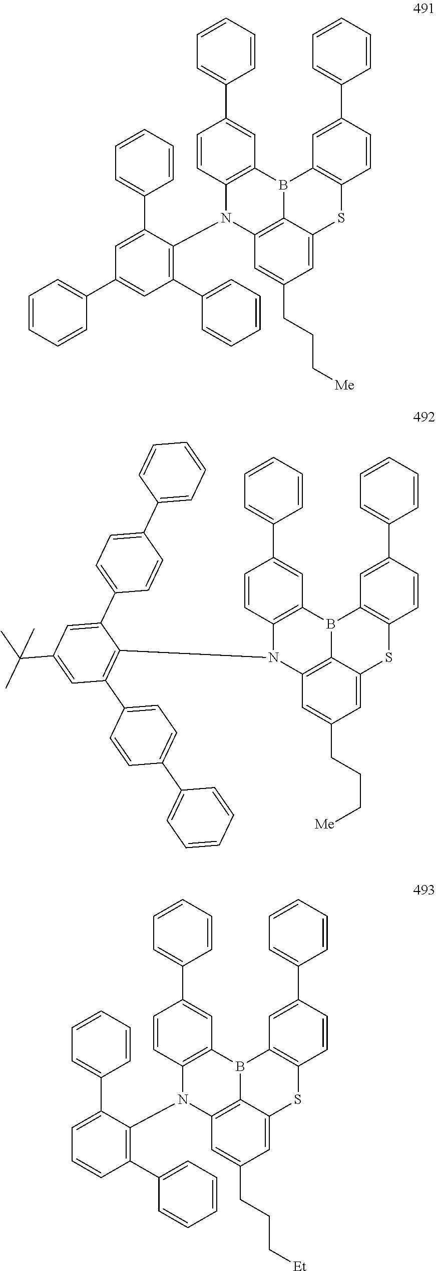 [SMILES: CCCCc1cc2c3c(c1)N(c1c(-c4ccccc4)cc(-c4ccccc4)cc1-c1ccccc1)c1ccc(-c4ccccc4)cc1B3c1cc(-c3ccccc3)ccc1S2 ; CCCCc1cc2c3c(c1)N(c1c(-c4ccc(-c5ccccc5)cc4)cc(C(C)(C)C)cc1-c1ccc(-c4ccccc4)cc1)c1ccc(-c4ccccc4)cc1B3c1cc(-c3ccccc3)ccc1S2 ; CCCCCc1cc2c3c(c1)N(c1c(-c4ccccc4)cccc1-c1ccccc1)c1ccc(-c4ccccc4)cc1B3c1cc(-c3ccccc3)ccc1S2] 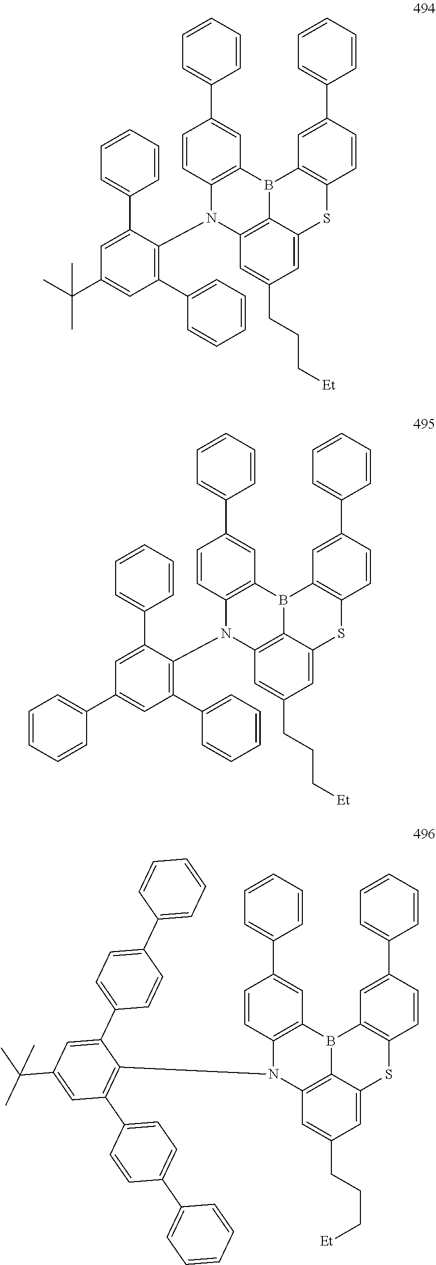 [SMILES: CCCCCc1cc2c3c(c1)N(c1c(-c4ccccc4)cc(C(C)(C)C)cc1-c1ccccc1)c1ccc(-c4ccccc4)cc1B3c1cc(-c3ccccc3)ccc1S2 ; CCCCCc1cc2c3c(c1)N(c1c(-c4ccccc4)cc(-c4ccccc4)cc1-c1ccccc1)c1ccc(-c4ccccc4)cc1B3c1cc(-c3ccccc3)ccc1S2 ; CCCCCc1cc2c3c(c1)N(c1c(-c4ccc(-c5ccccc5)cc4)cc(C(C)(C)C)cc1-c1ccc(-c4ccccc4)cc1)c1ccc(-c4ccccc4)cc1B3c1cc(-c3ccccc3)ccc1S2] 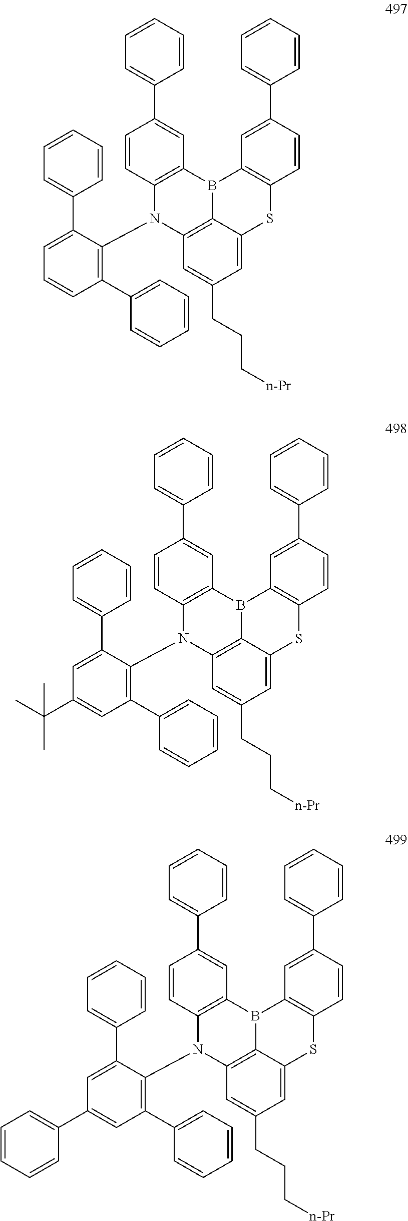 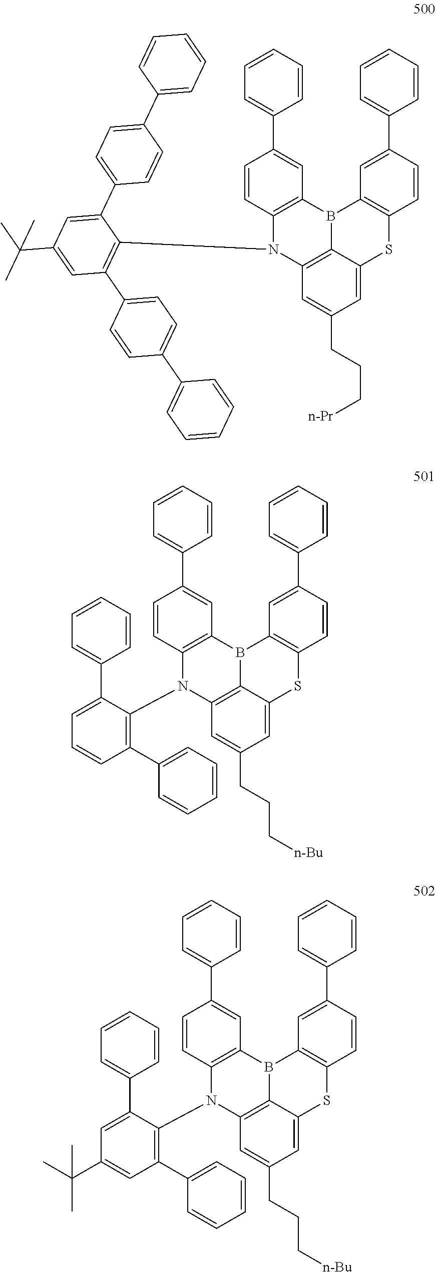 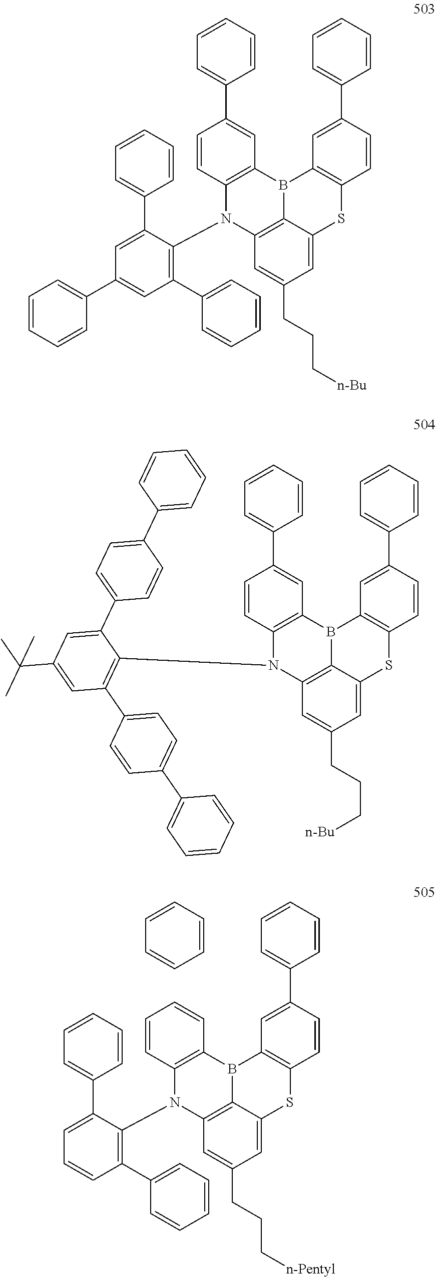 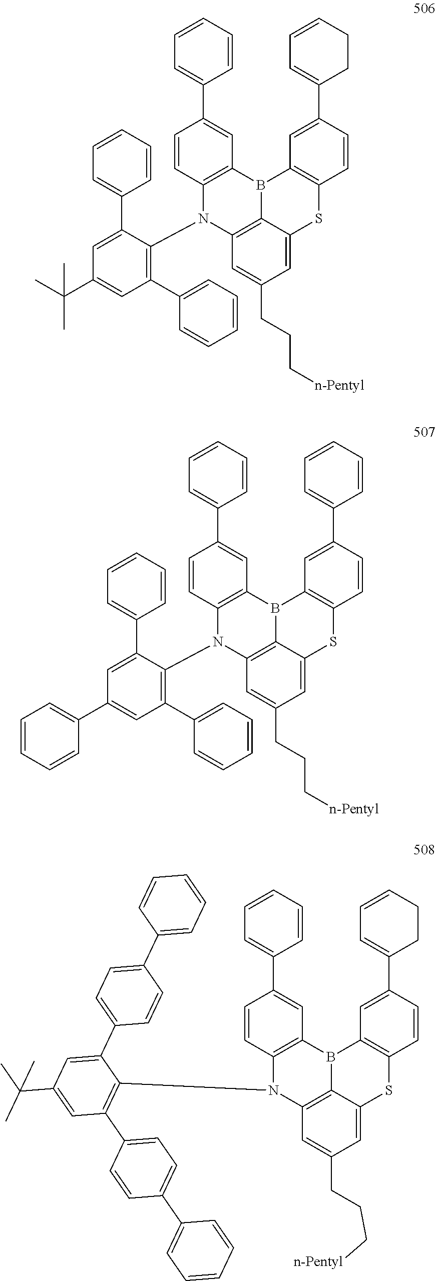 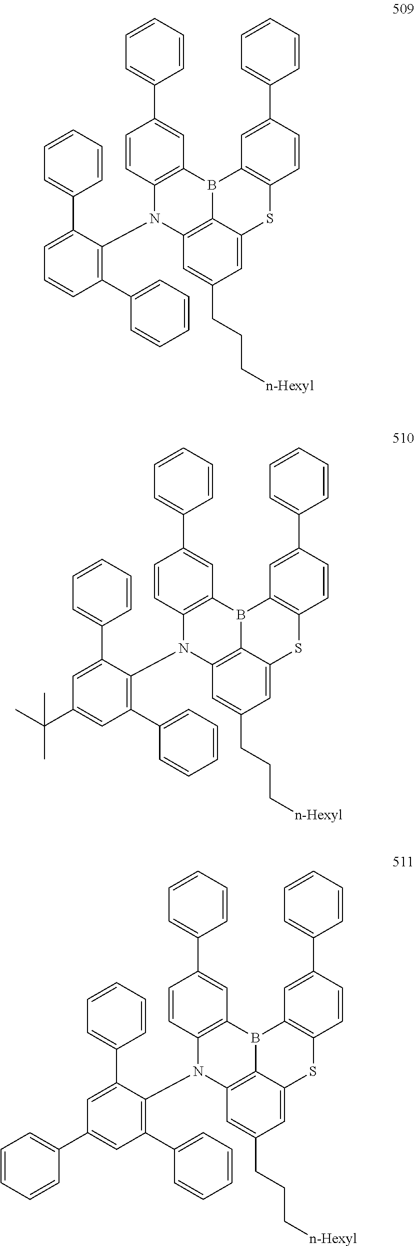 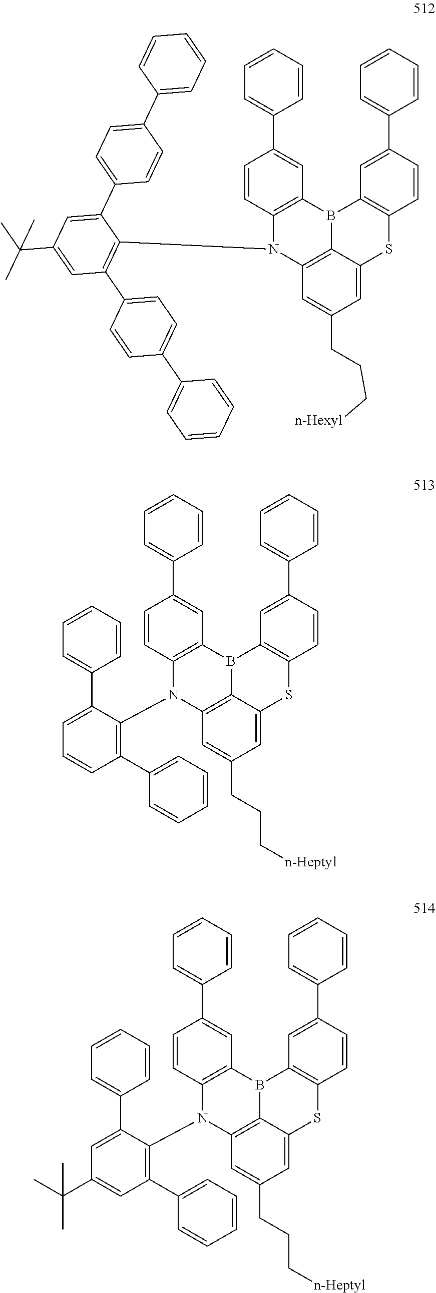 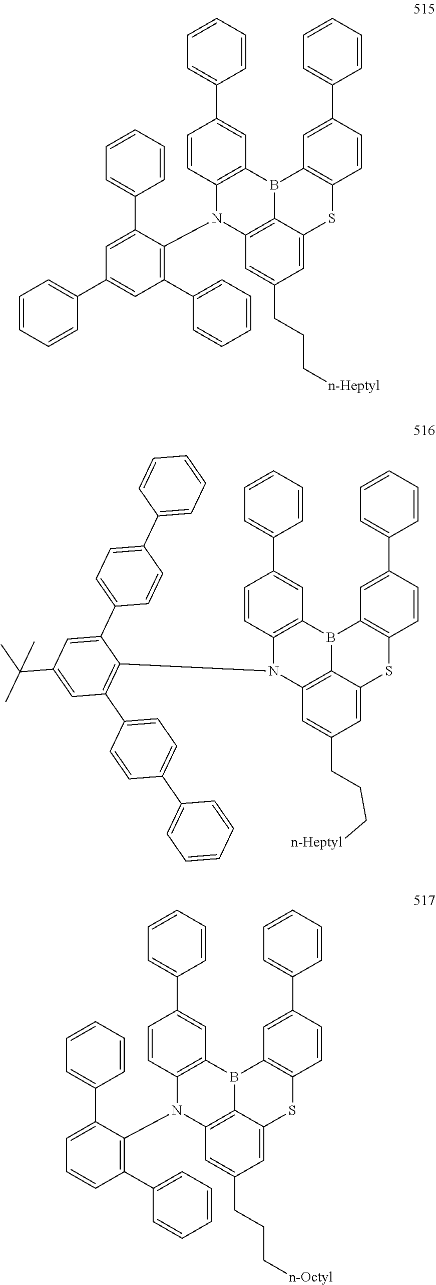 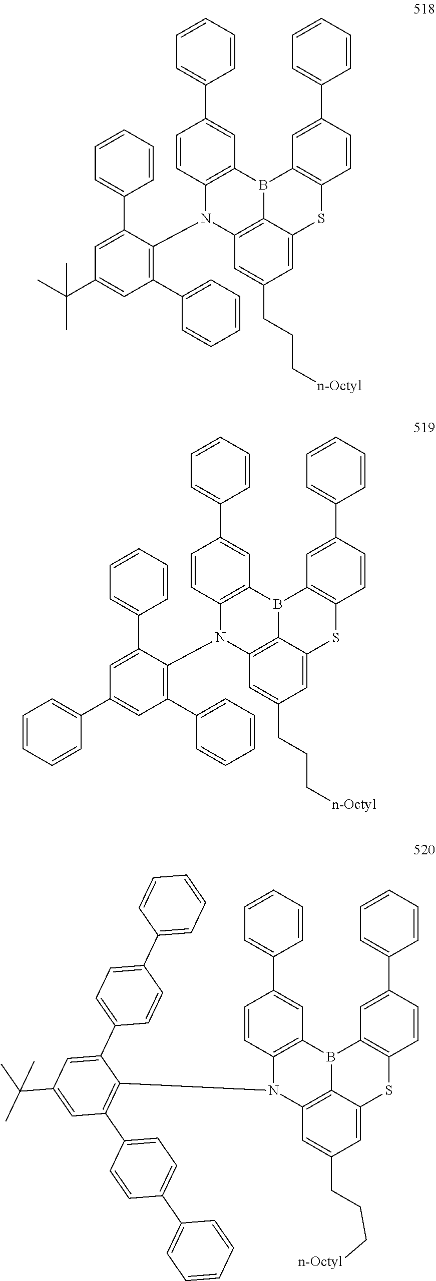 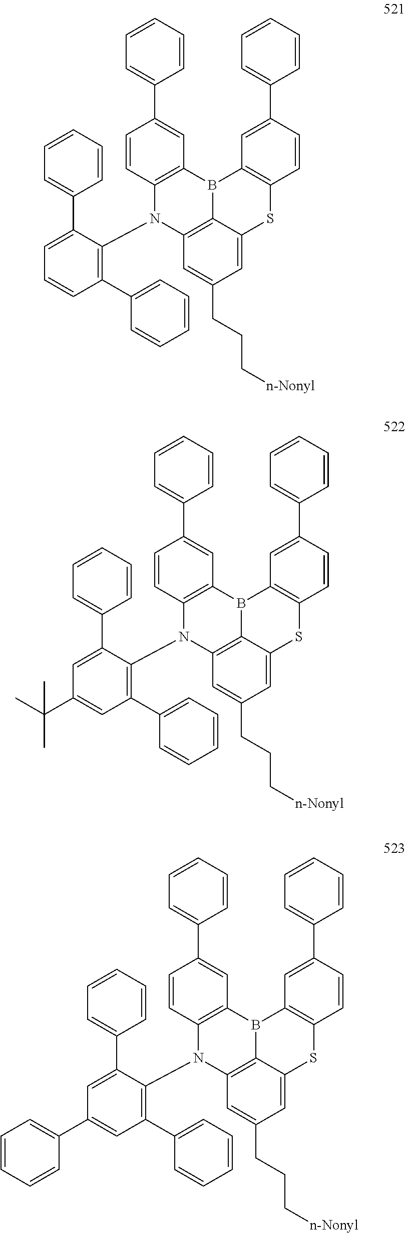 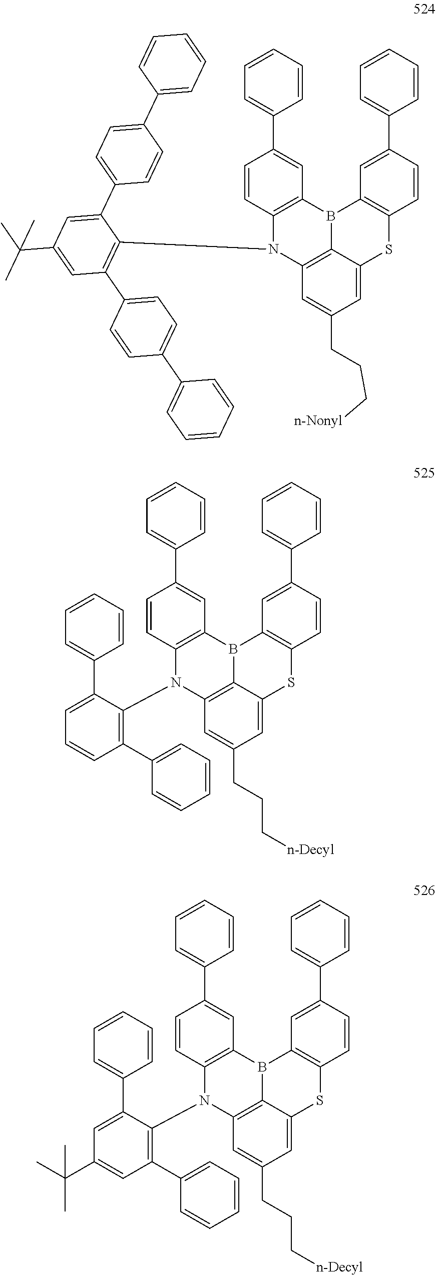 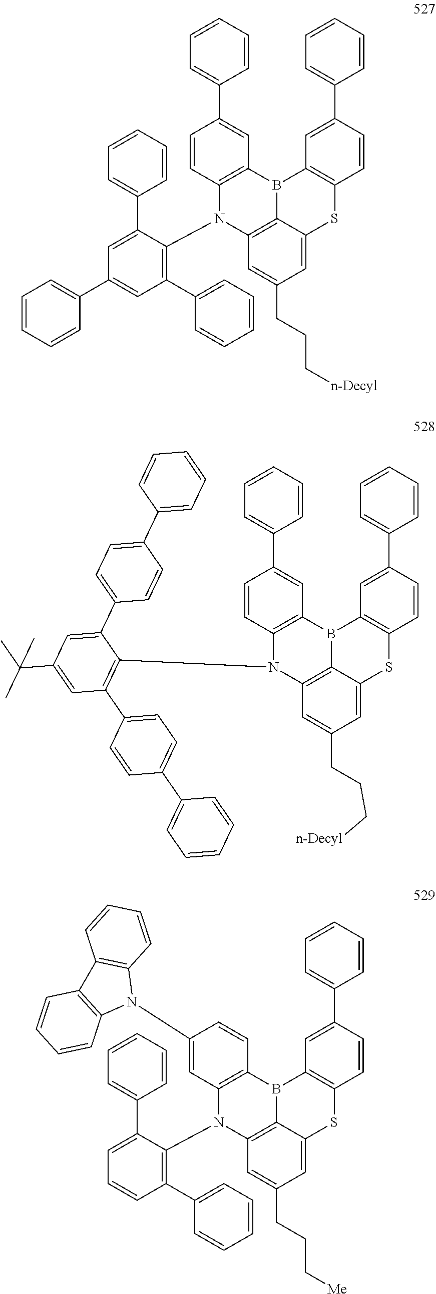 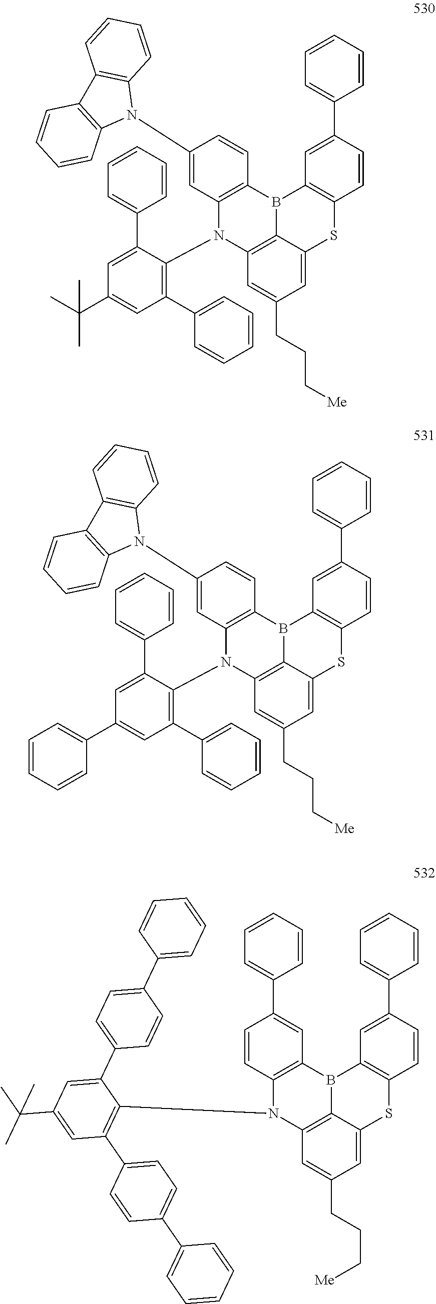 [SMILES: CCCCc1cc2c3c(c1)N(c1c(-c4ccccc4)cc(C(C)(C)C)cc1-c1ccccc1)c1cc(-n4c5ccccc5c5ccccc54)ccc1B3c1cc(-c3ccccc3)ccc1S2 ; CCCCc1cc2c3c(c1)N(c1c(-c4ccccc4)cc(-c4ccccc4)cc1-c1ccccc1)c1cc(-n4c5ccccc5c5ccccc54)ccc1B3c1cc(-c3ccccc3)ccc1S2 ; CCCCc1cc2c3c(c1)N(c1c(-c4ccc(-c5ccccc5)cc4)cc(C(C)(C)C)cc1-c1ccc(-c4ccccc4)cc1)c1ccc(-c4ccccc4)cc1B3c1cc(-c3ccccc3)ccc1S2] 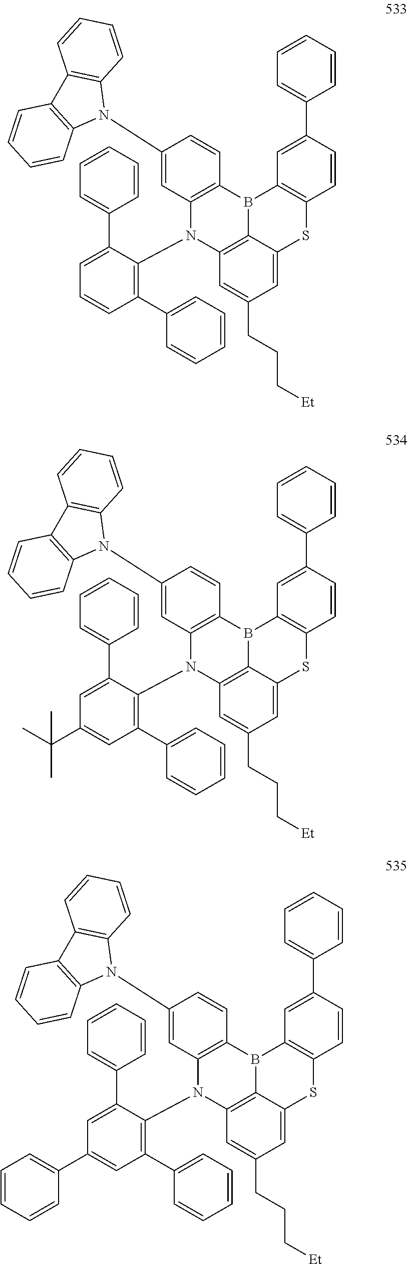 [SMILES: CCCCCc1cc2c3c(c1)N(c1c(-c4ccccc4)cccc1-c1ccccc1)c1cc(-n4c5ccccc5c5ccccc54)ccc1B3c1cc(-c3ccccc3)ccc1S2 ; CCCCCc1cc2c3c(c1)N(c1c(-c4ccccc4)cc(C(C)(C)C)cc1-c1ccccc1)c1cc(-n4c5ccccc5c5ccccc54)ccc1B3c1cc(-c3ccccc3)ccc1S2 ; CCCCCc1cc2c3c(c1)N(c1c(-c4ccccc4)cc(-c4ccccc4)cc1-c1ccccc1)c1cc(-n4c5ccccc5c5ccccc54)ccc1B3c1cc(-c3ccccc3)ccc1S2] 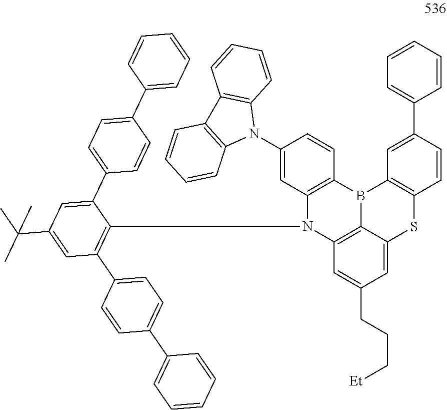 [SMILES: CCCCCc1cc2c3c(c1)N(c1c(-c4ccc(-c5ccccc5)cc4)cc(C(C)(C)C)cc1-c1ccc(-c4ccccc4)cc1)c1cc(-n4c5ccccc5c5ccccc54)ccc1B3c1cc(-c3ccccc3)ccc1S2] 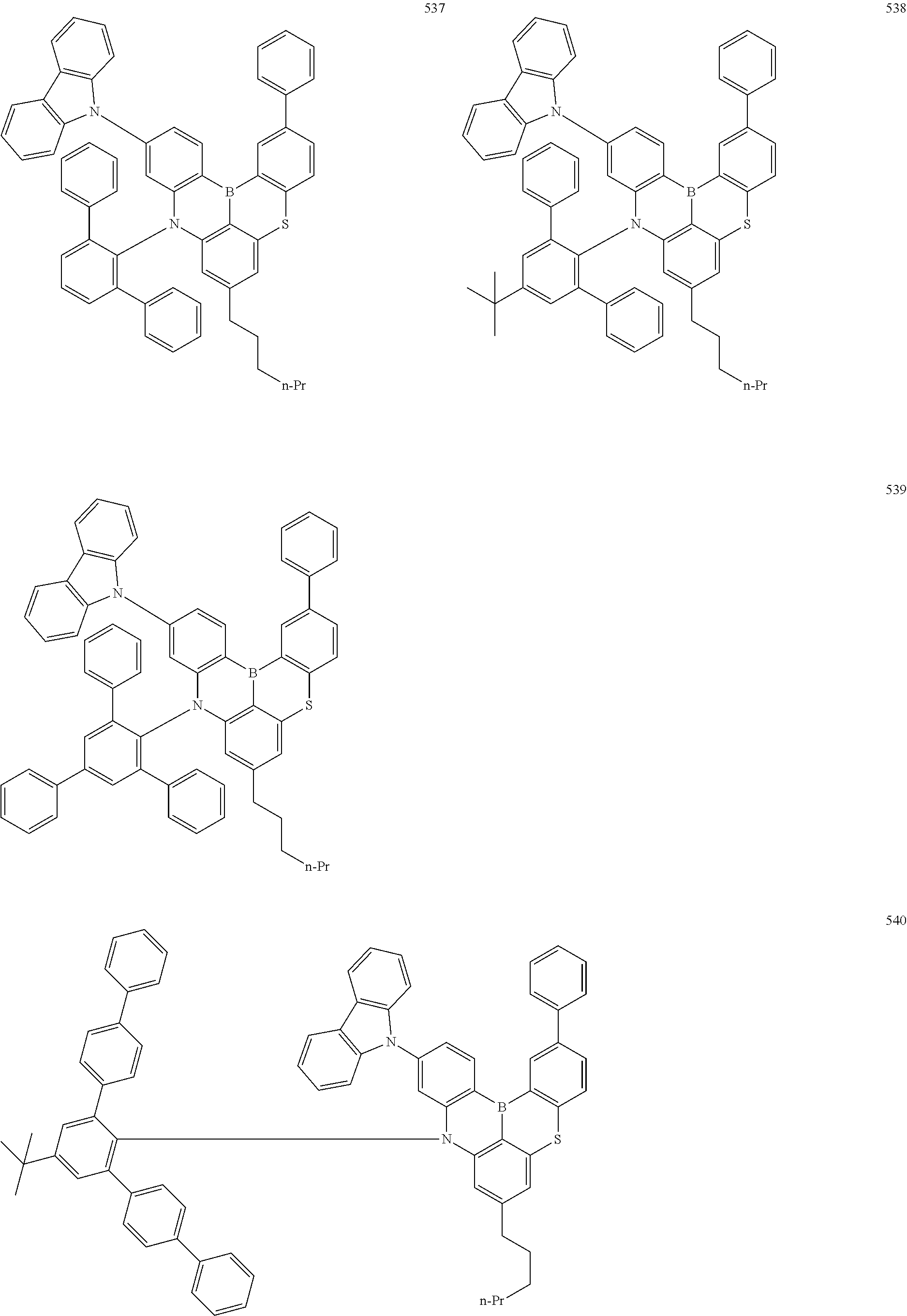 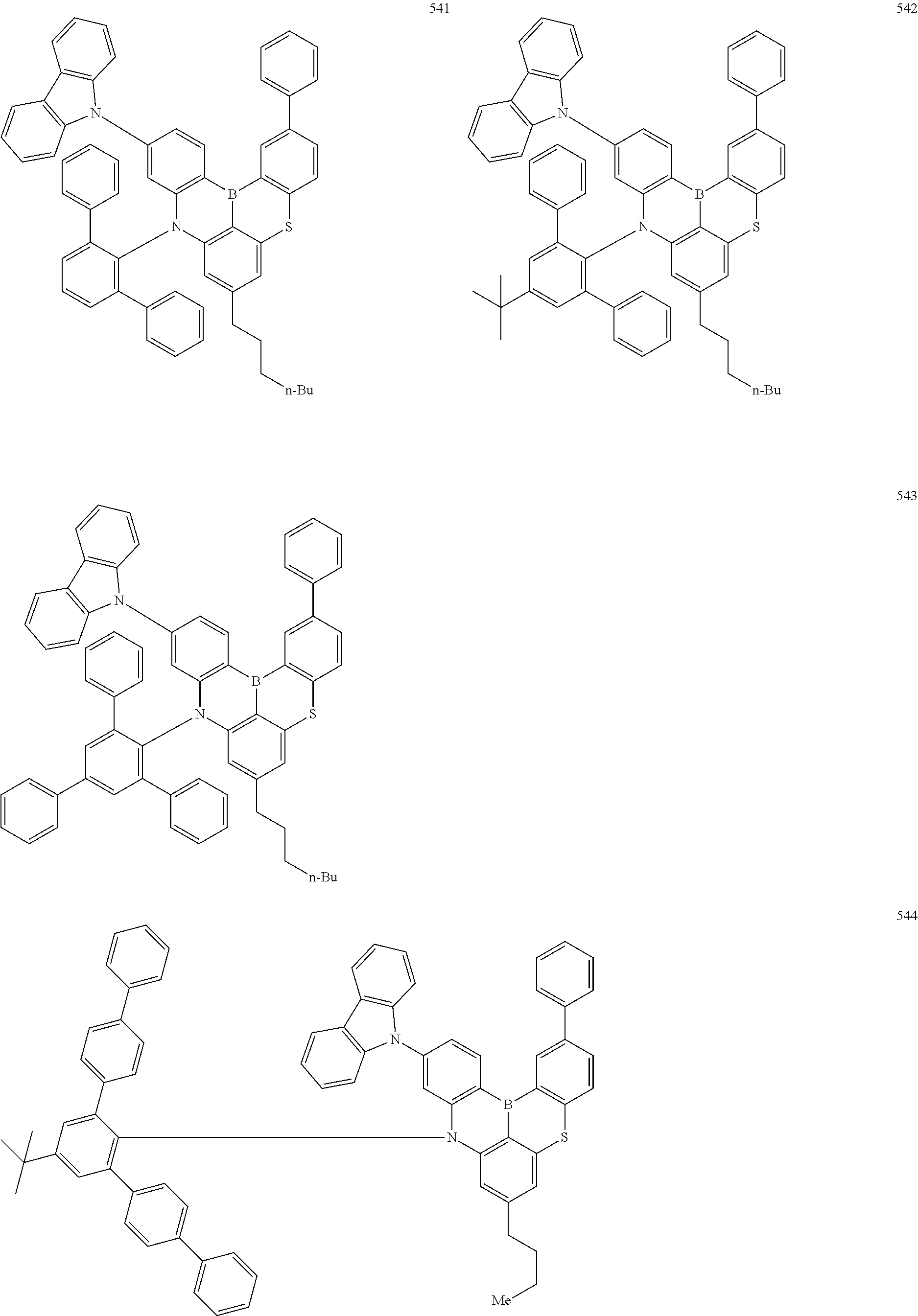 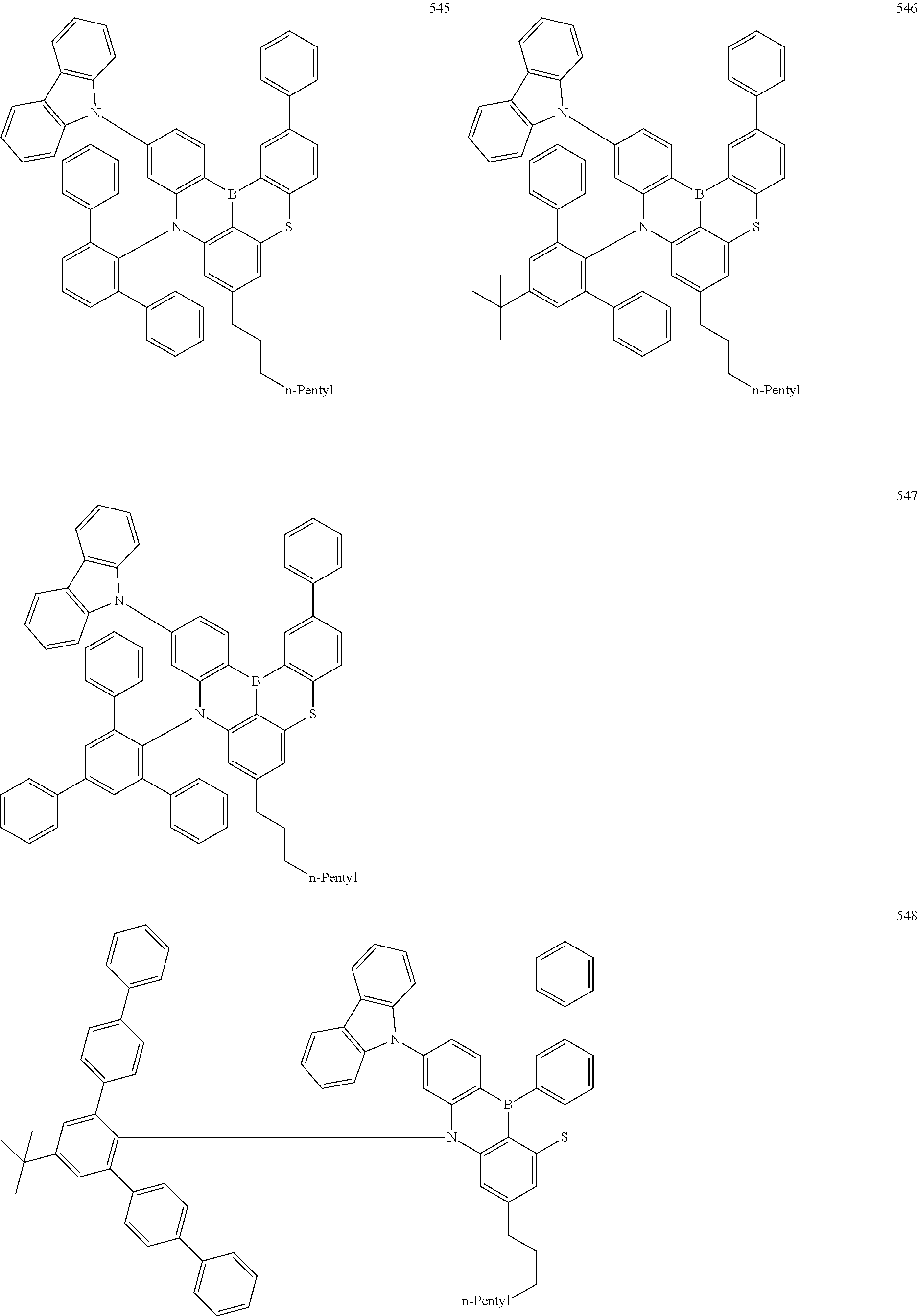 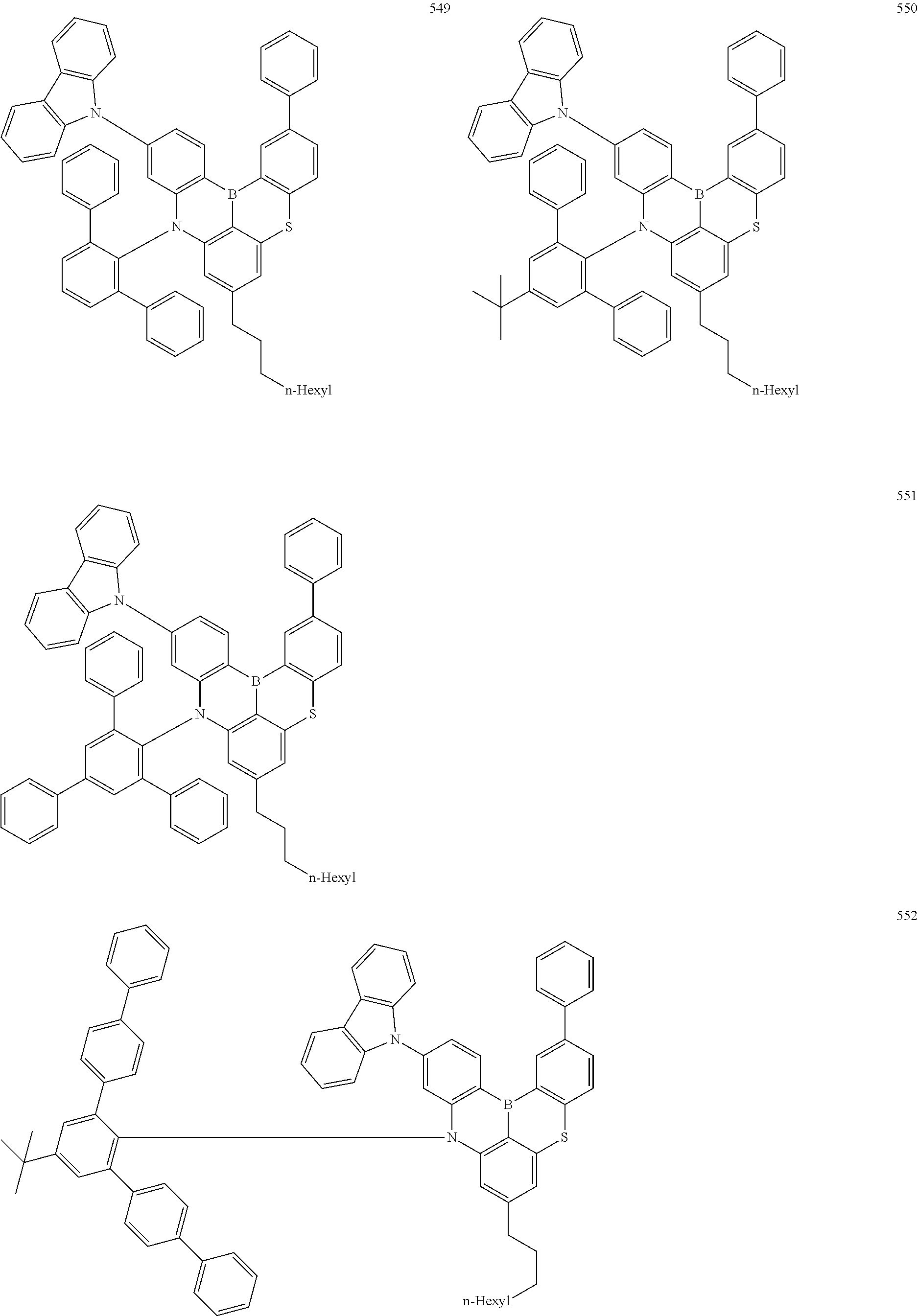 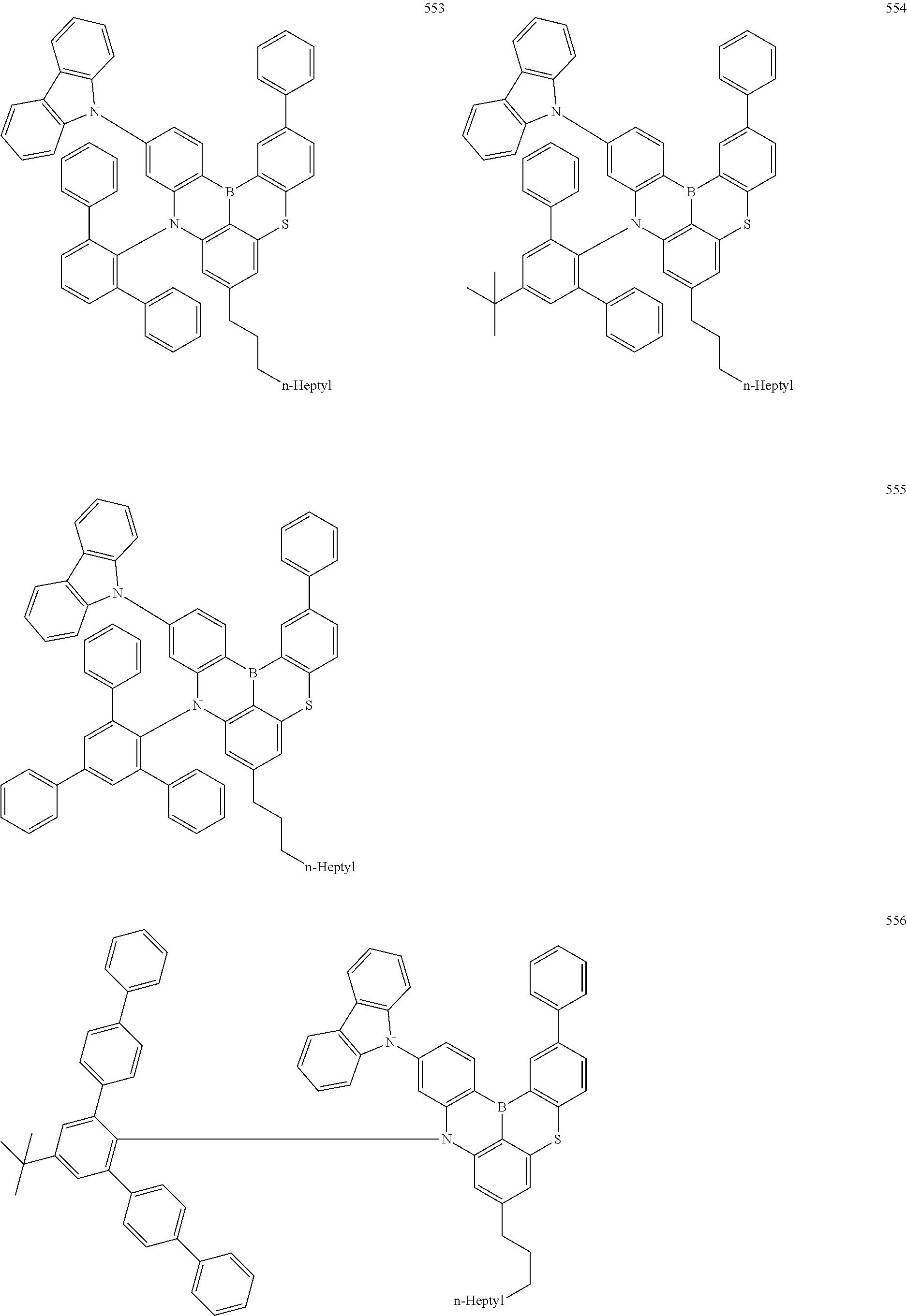 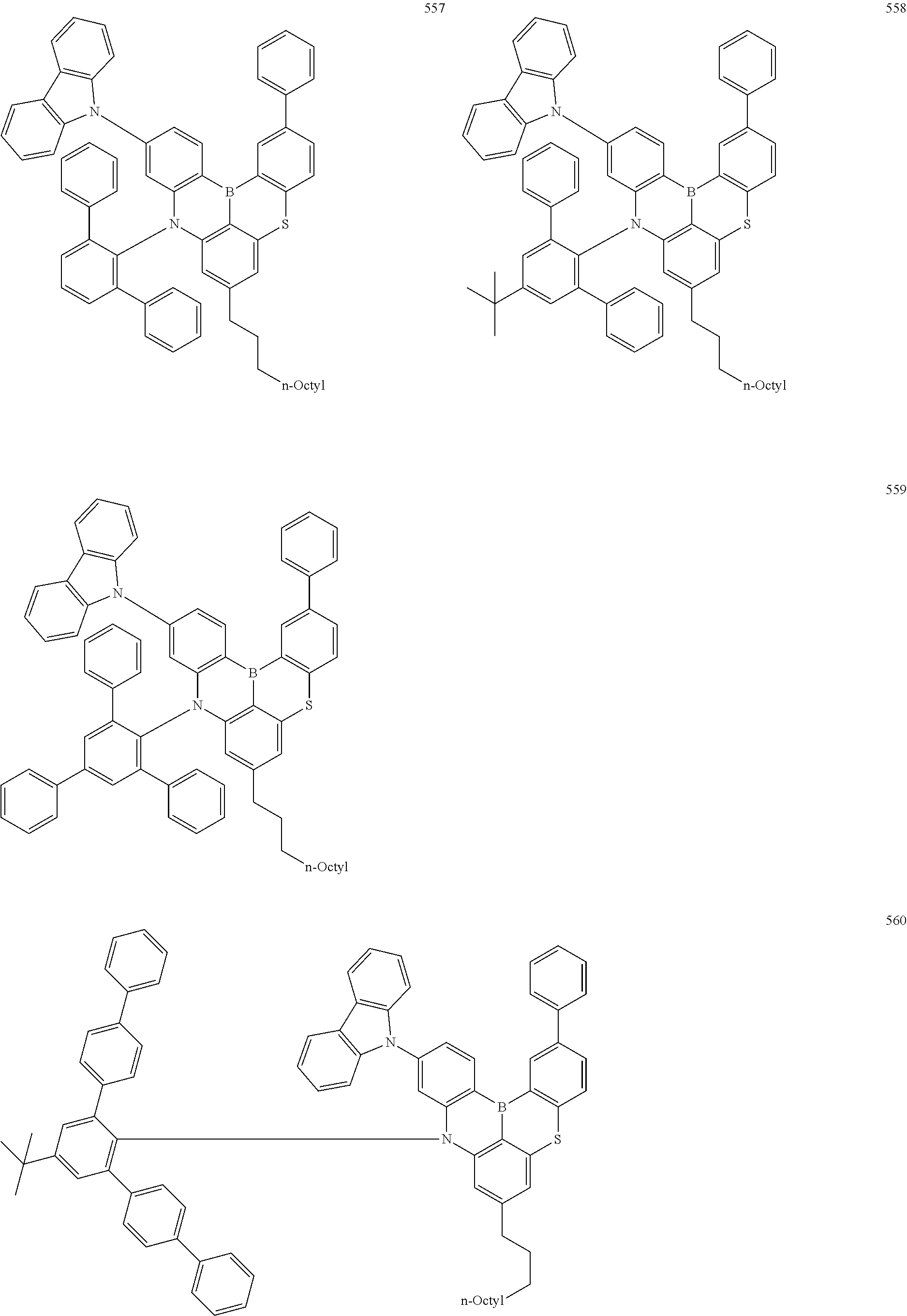 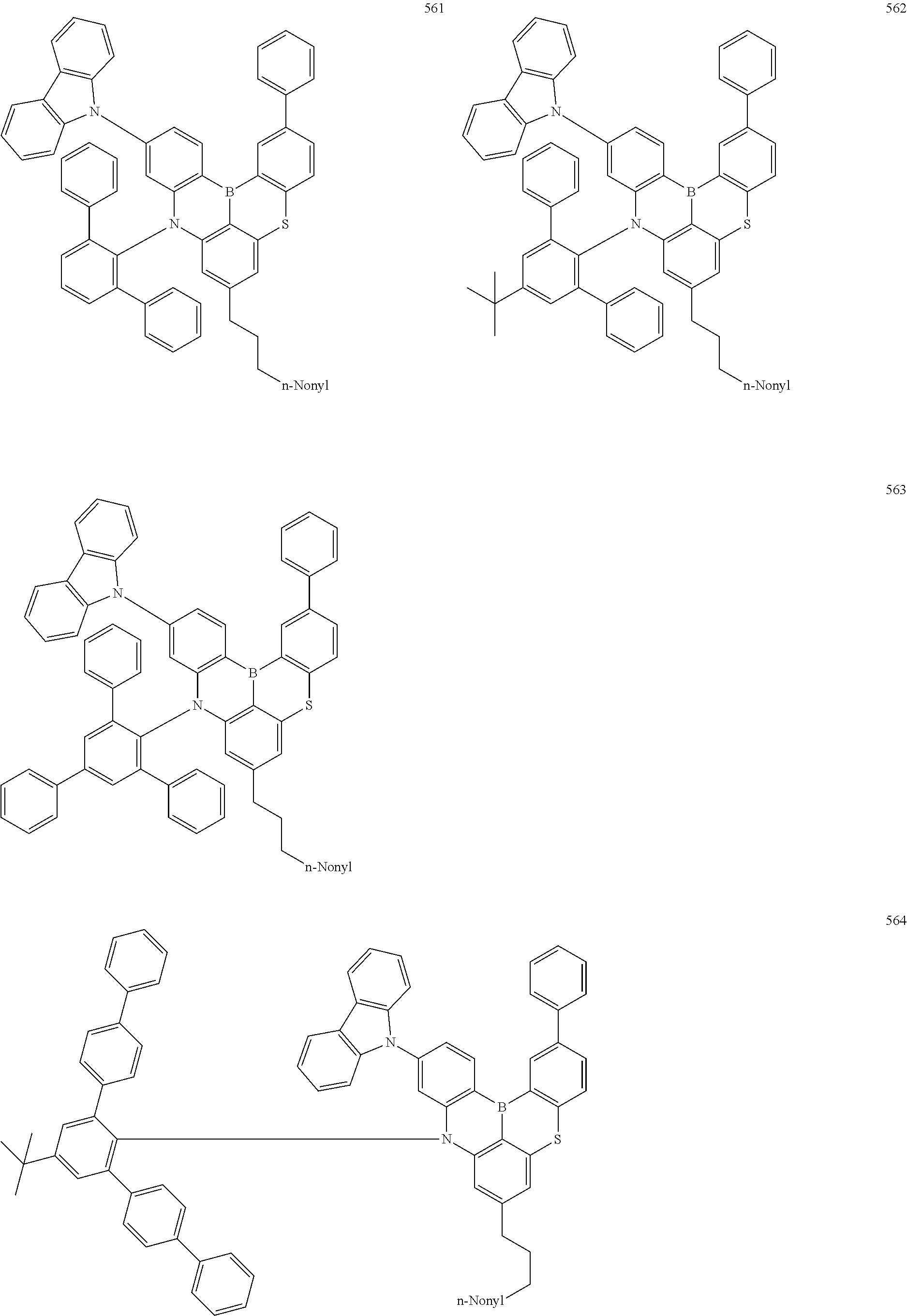 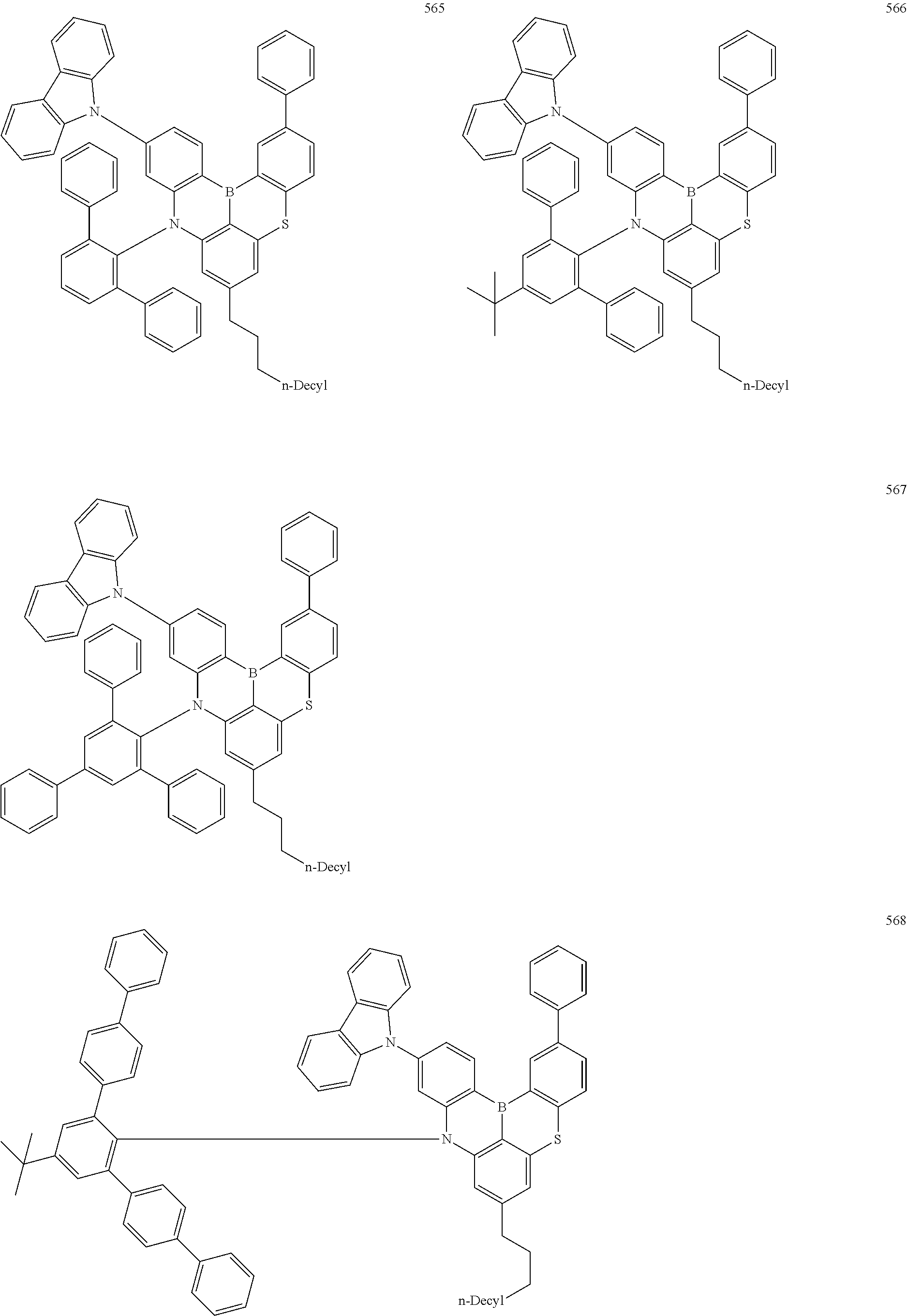 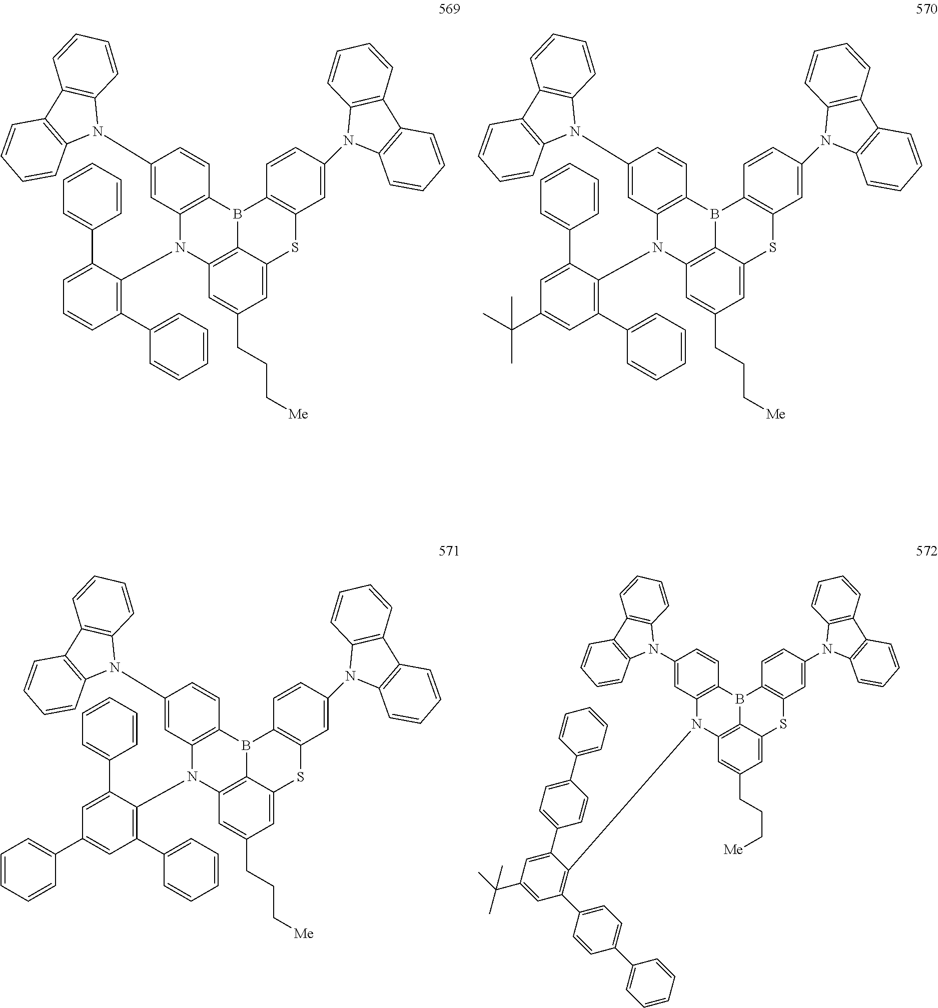 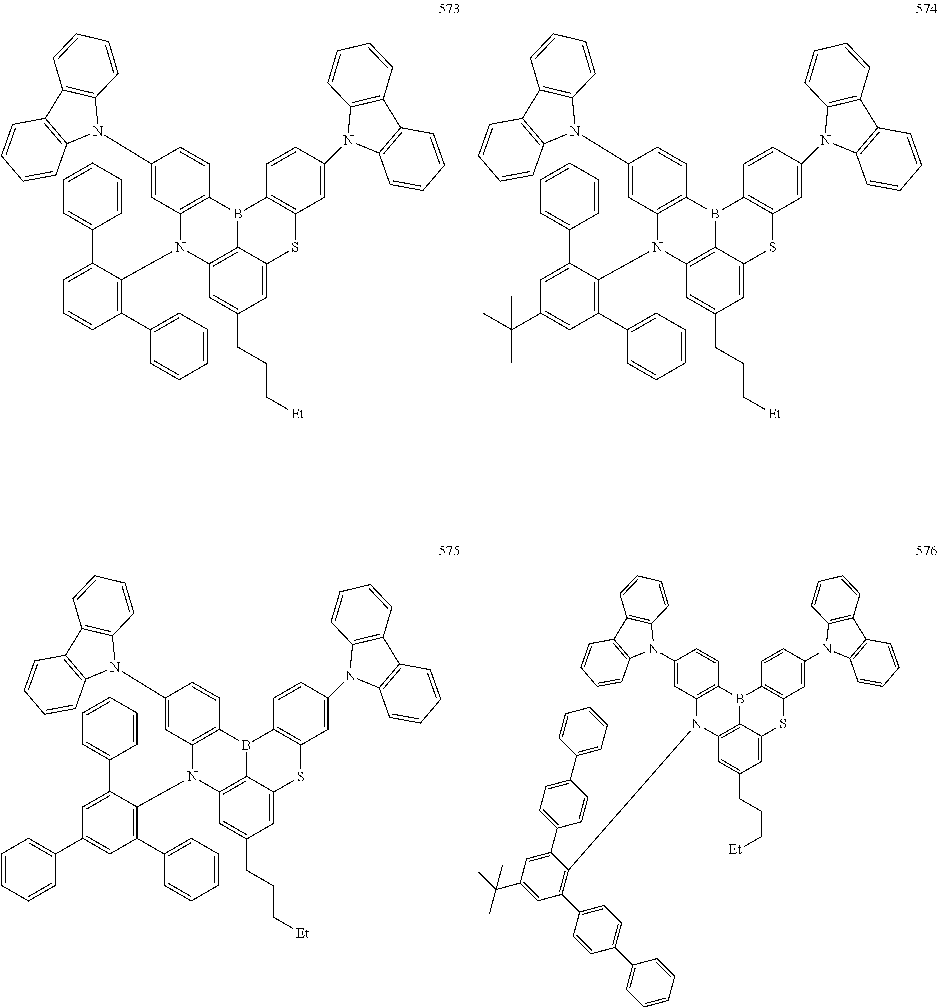 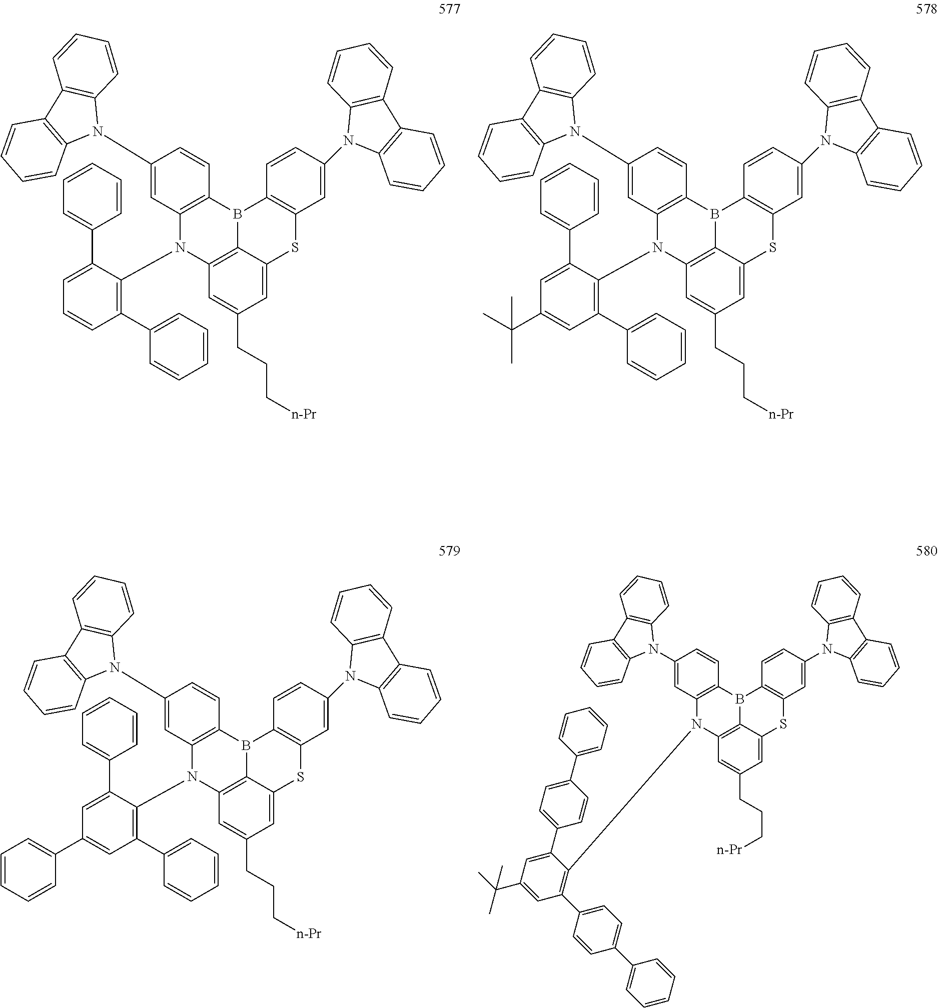 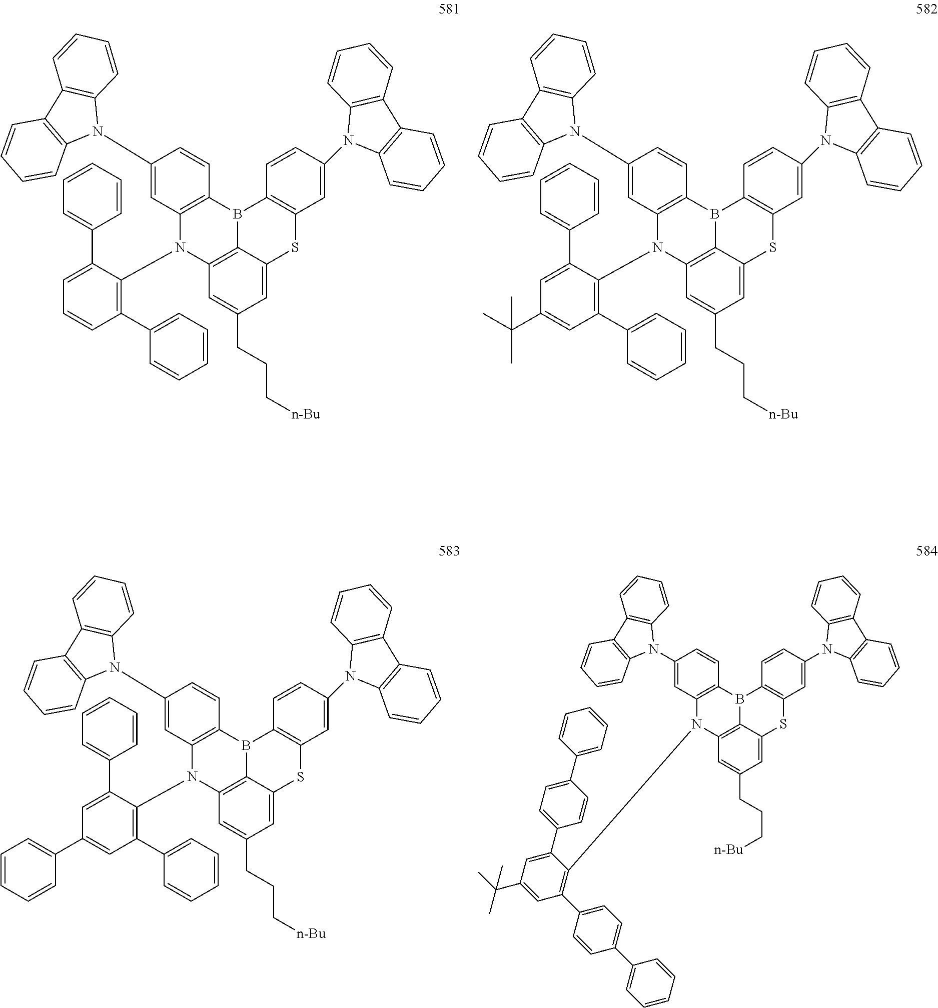 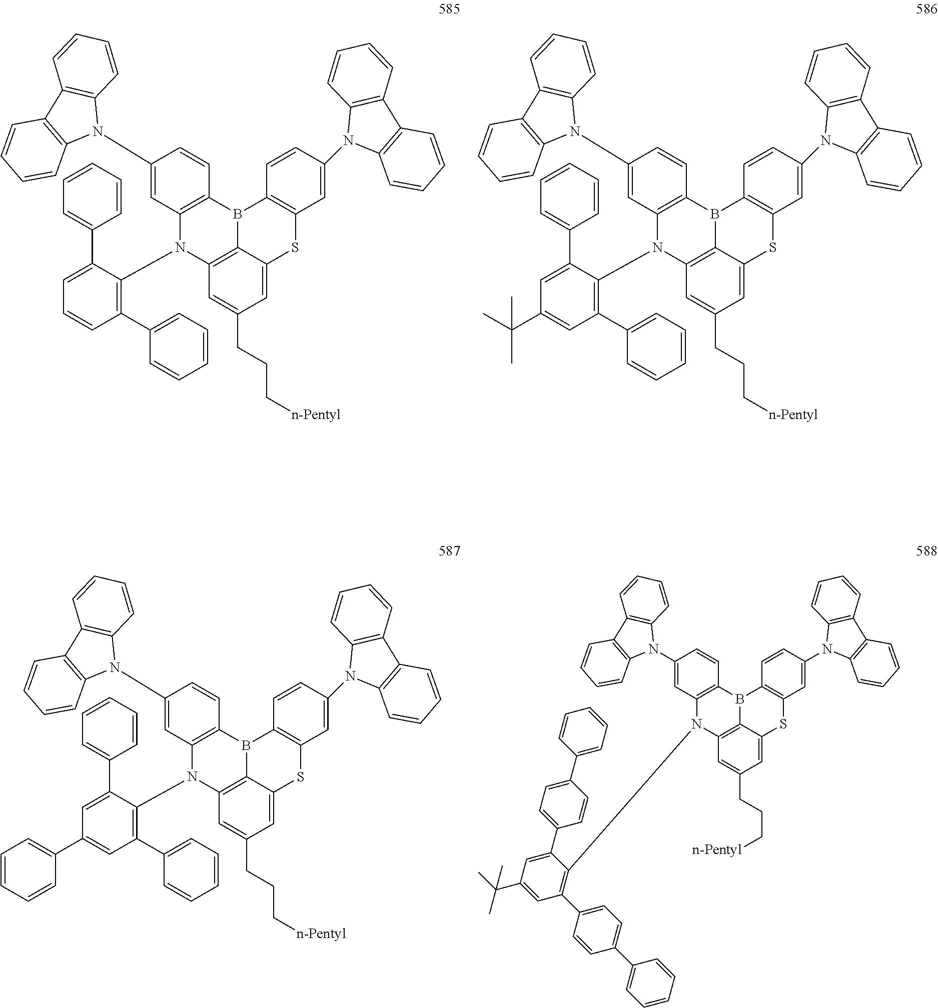 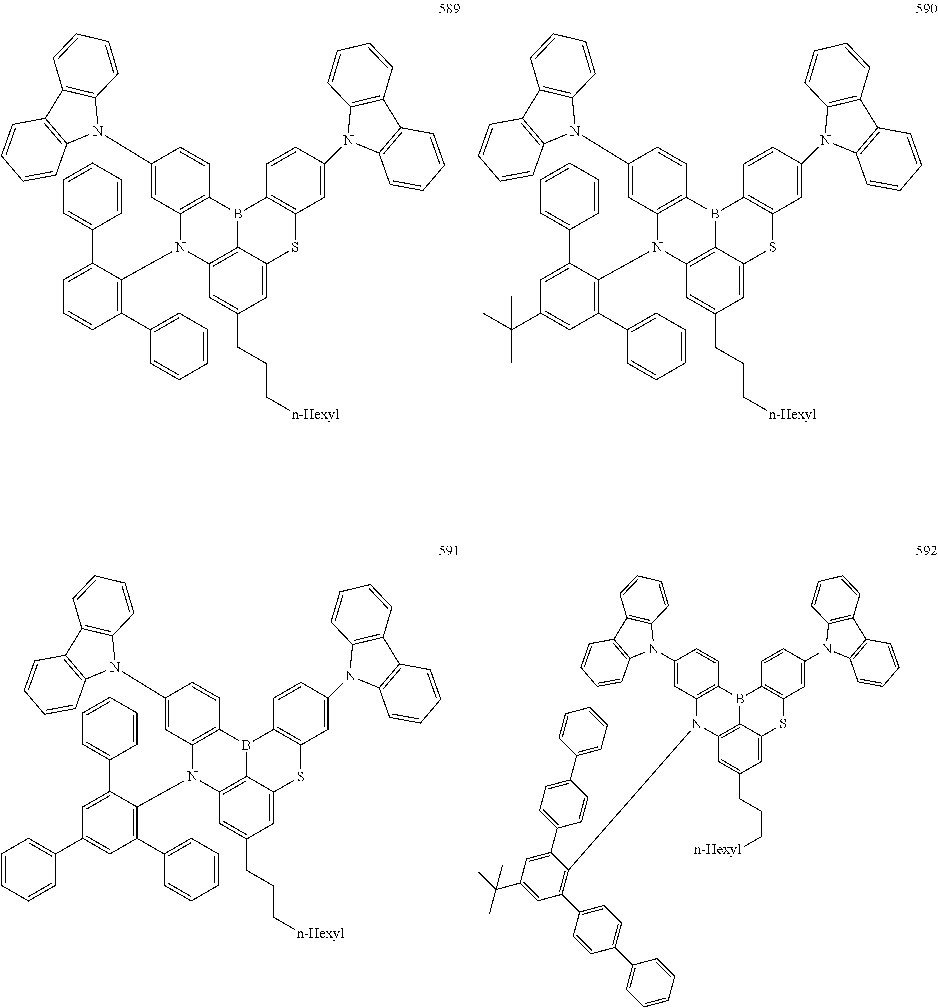 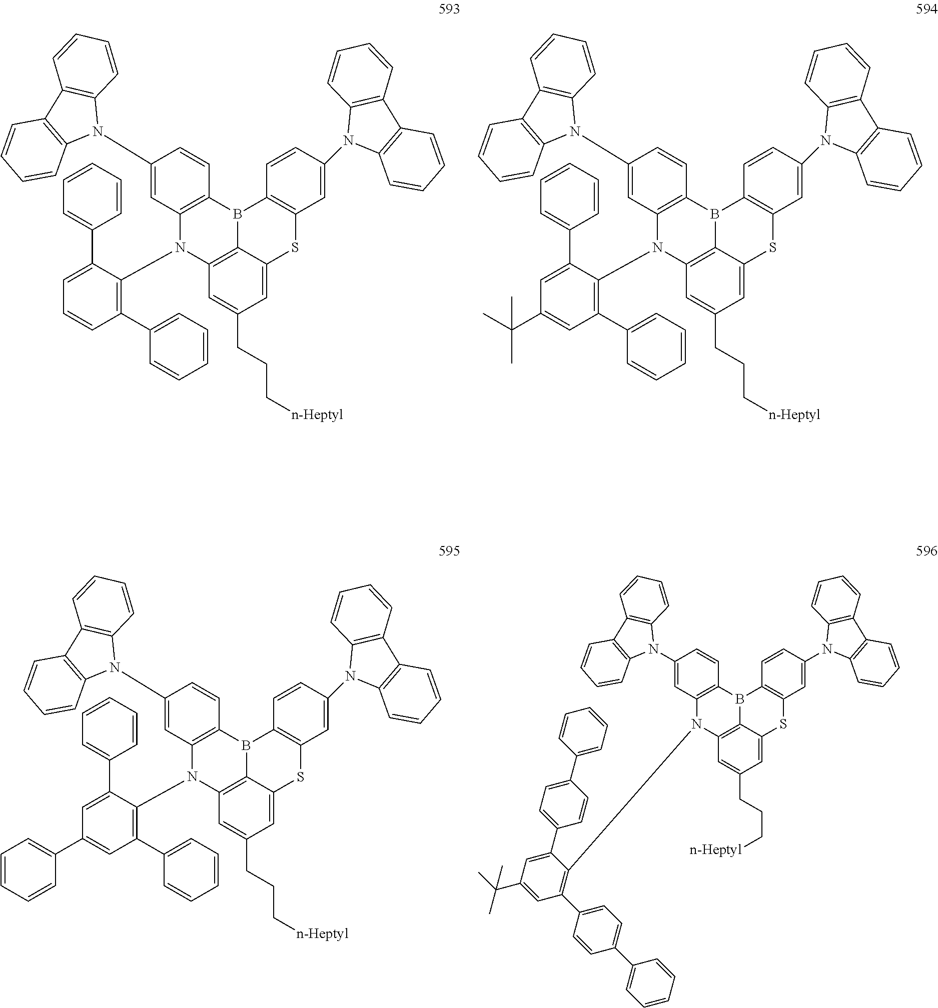 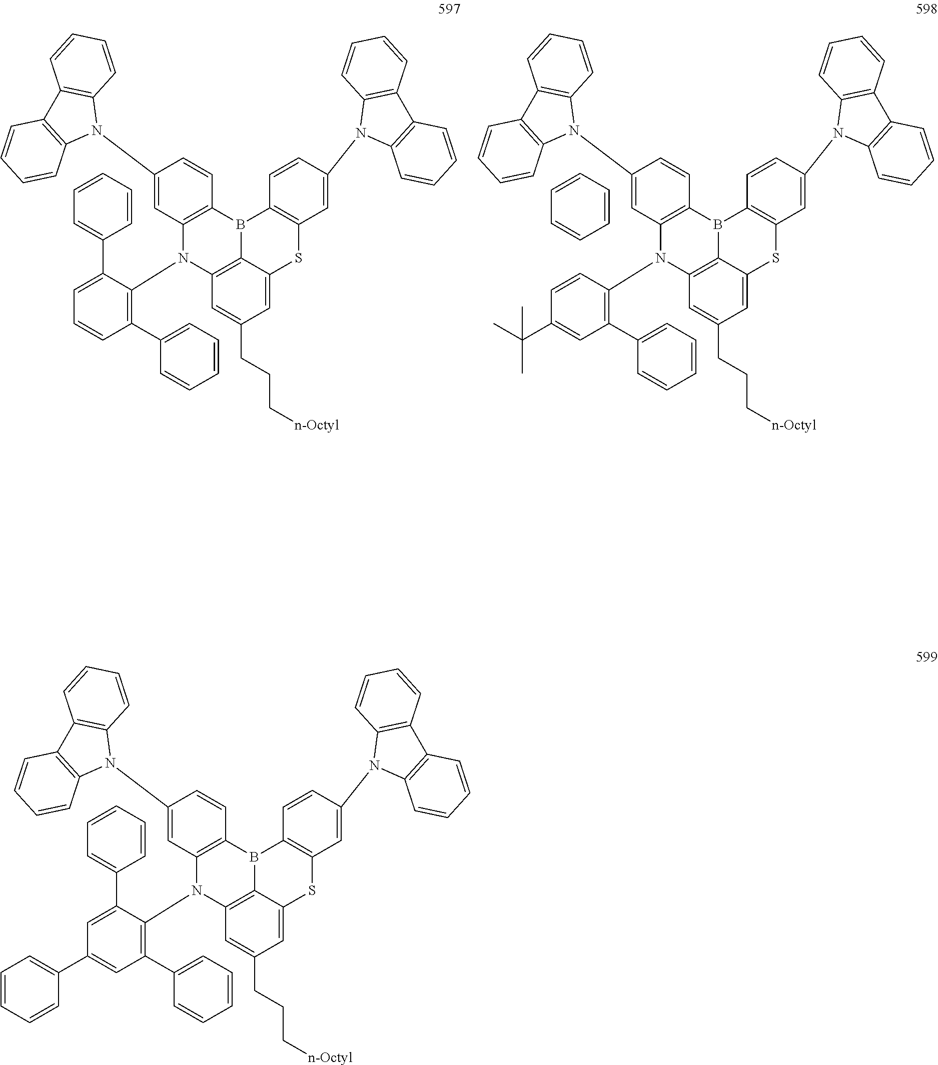 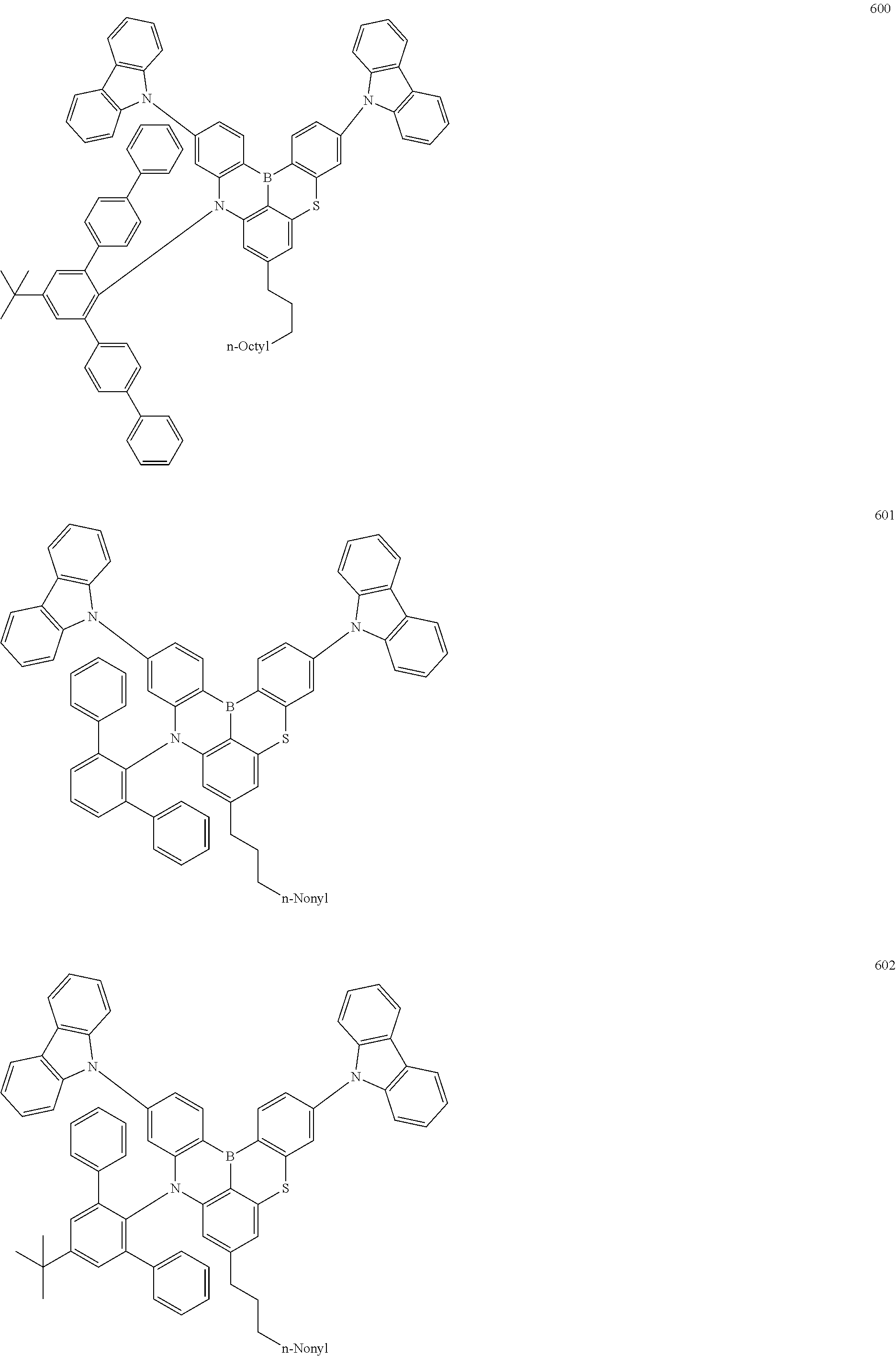 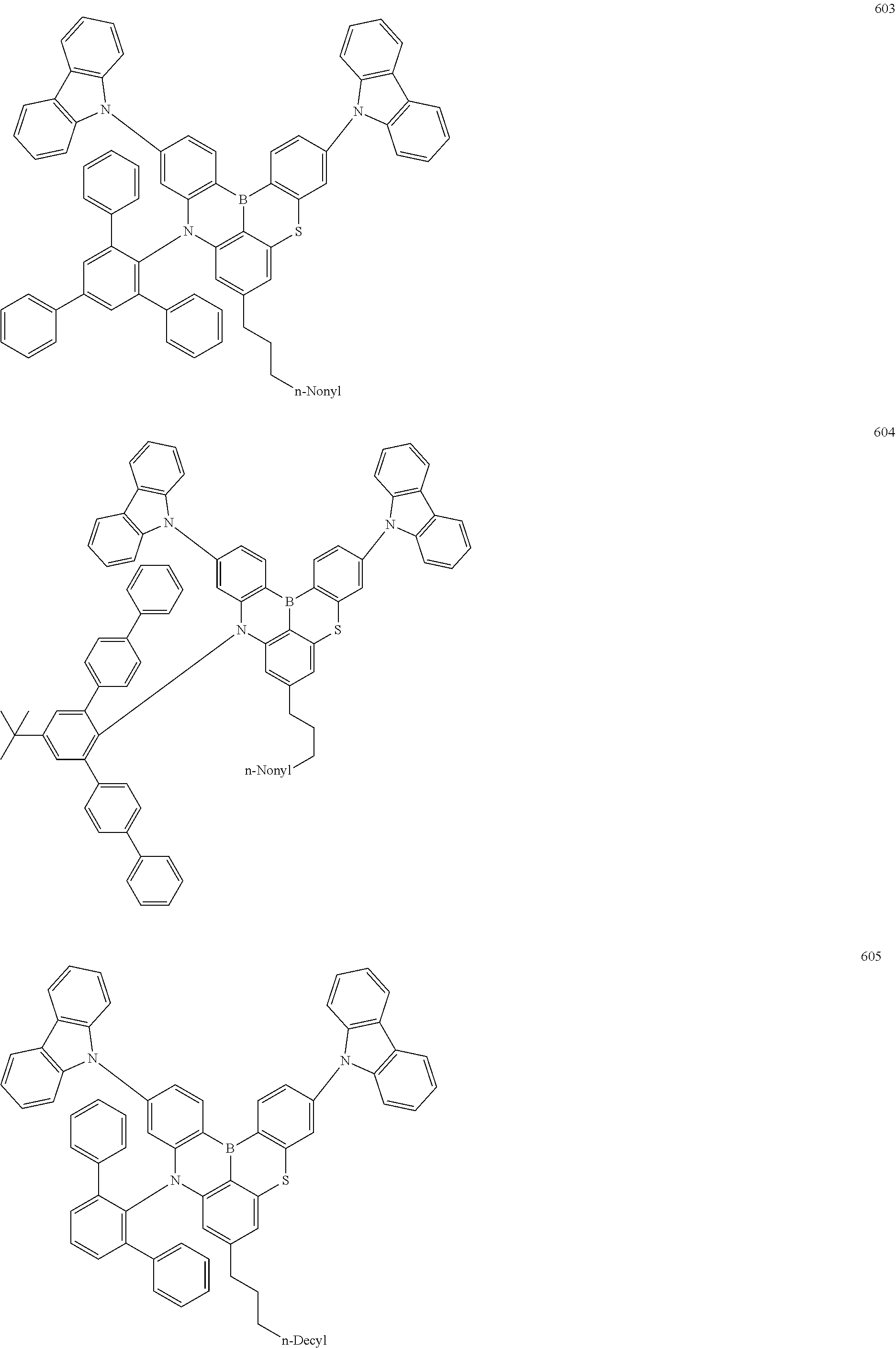 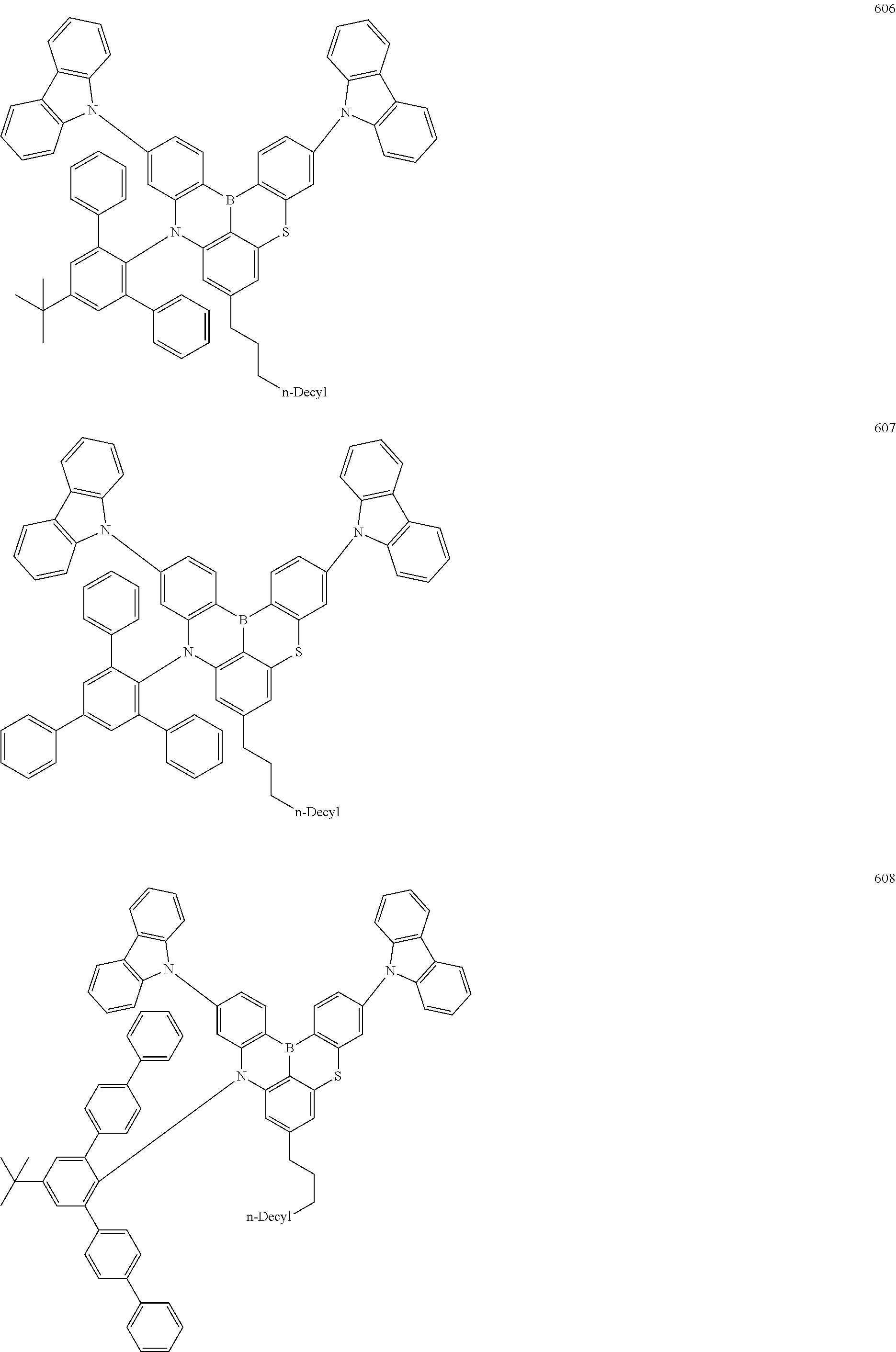 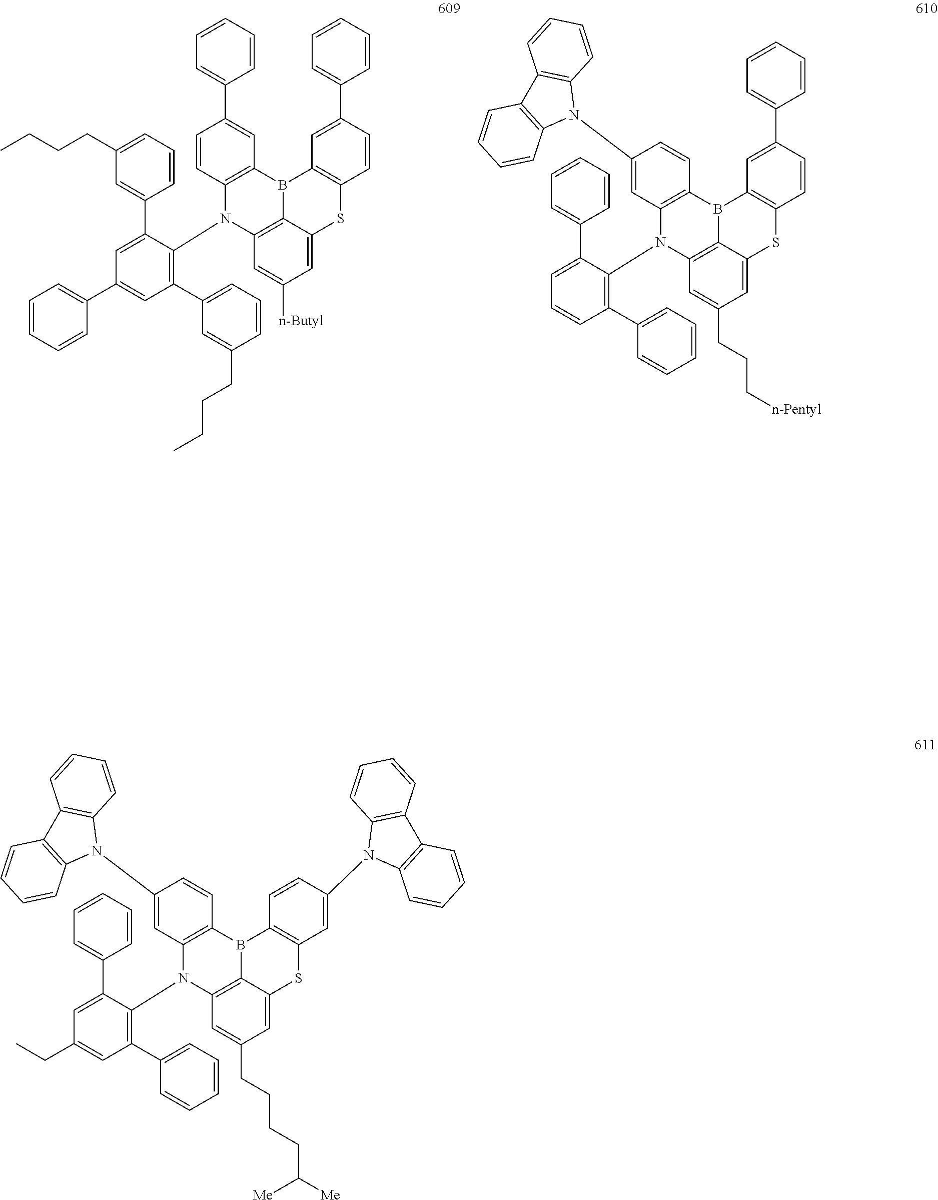 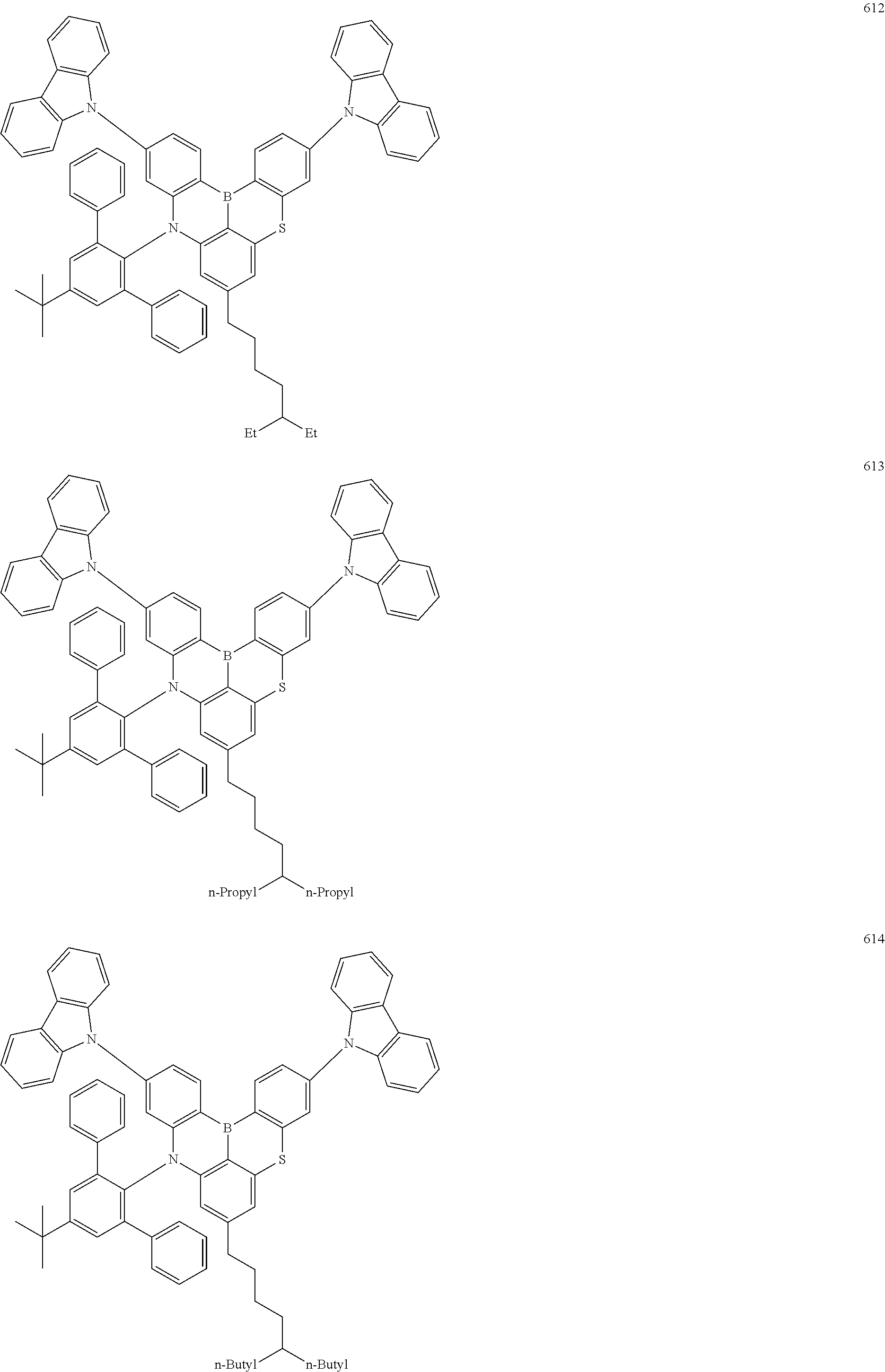 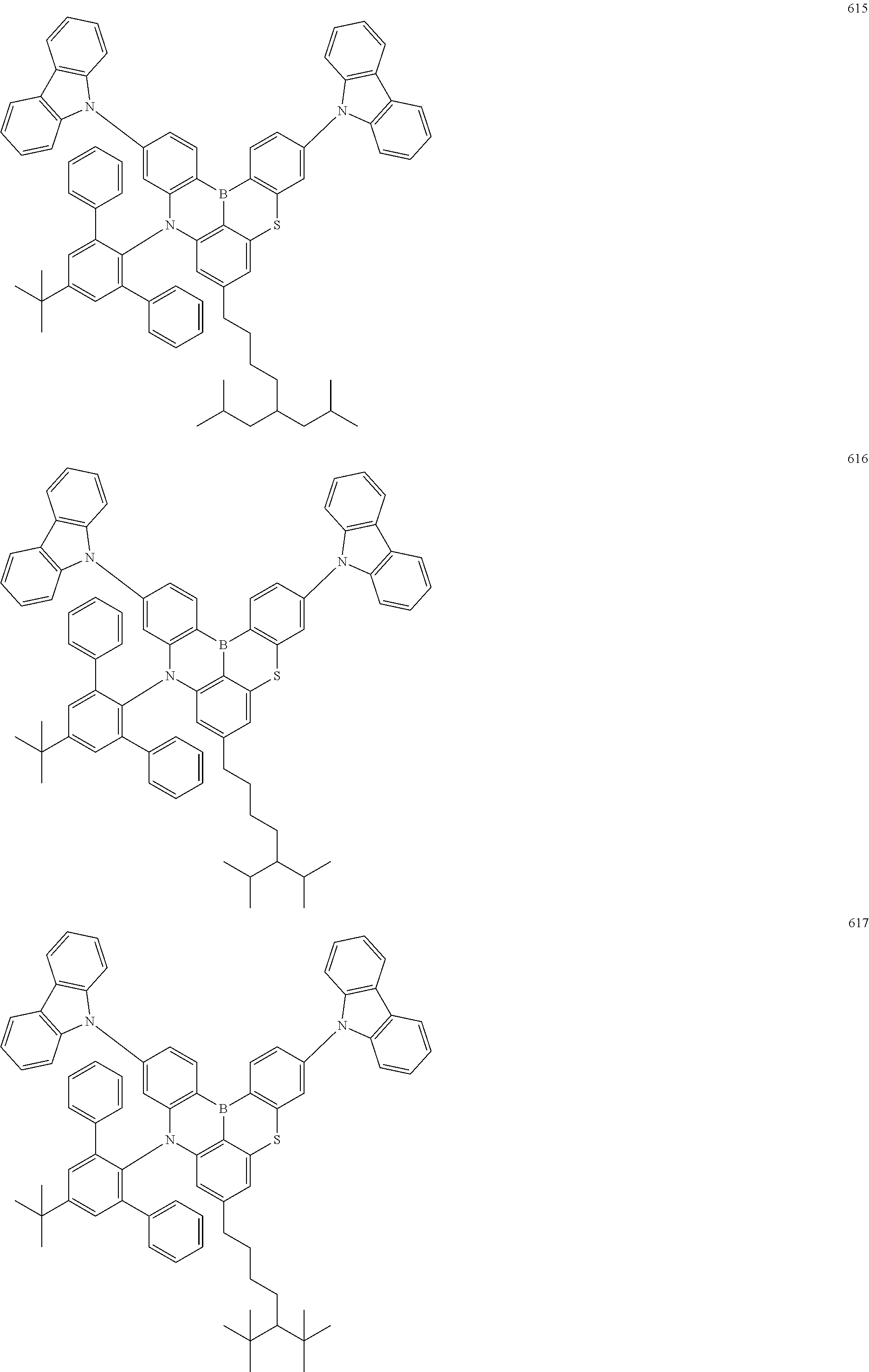 [SMILES: CC(C)CC(CCCCc1cc2c3c(c1)N(c1c(-c4ccccc4)cc(C(C)(C)C)cc1-c1ccccc1)c1cc(-n4c5ccccc5c5ccccc54)ccc1B3c1ccc(-n3c4ccccc4c4ccccc43)cc1S2)CC(C)C ; CC(C)C(CCCCc1cc2c3c(c1)N(c1c(-c4ccccc4)cc(C(C)(C)C)cc1-c1ccccc1)c1cc(-n4c5ccccc5c5ccccc54)ccc1B3c1ccc(-n3c4ccccc4c4ccccc43)cc1S2)C(C)C ; CC(C)(C)c1cc(-c2ccccc2)c(N2c3cc(-n4c5ccccc5c5ccccc54)ccc3B3c4ccc(-n5c6ccccc6c6ccccc65)cc4Sc4cc(CCCCC(C(C)(C)C)C(C)(C)C)cc2c43)c(-c2ccccc2)c1] 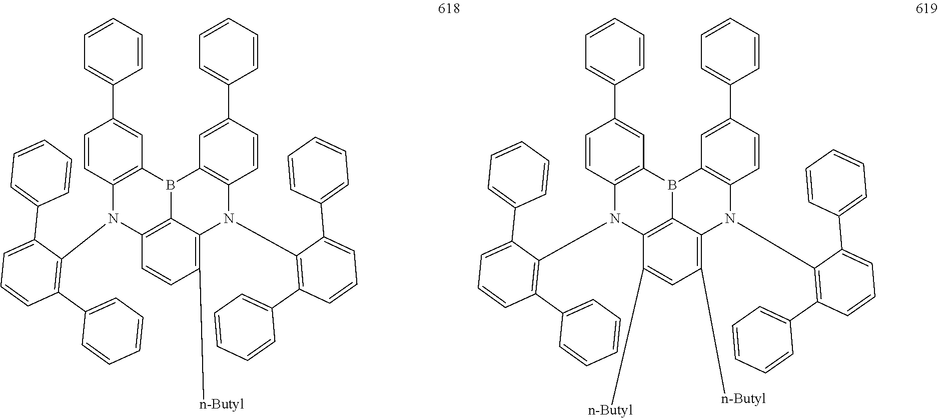 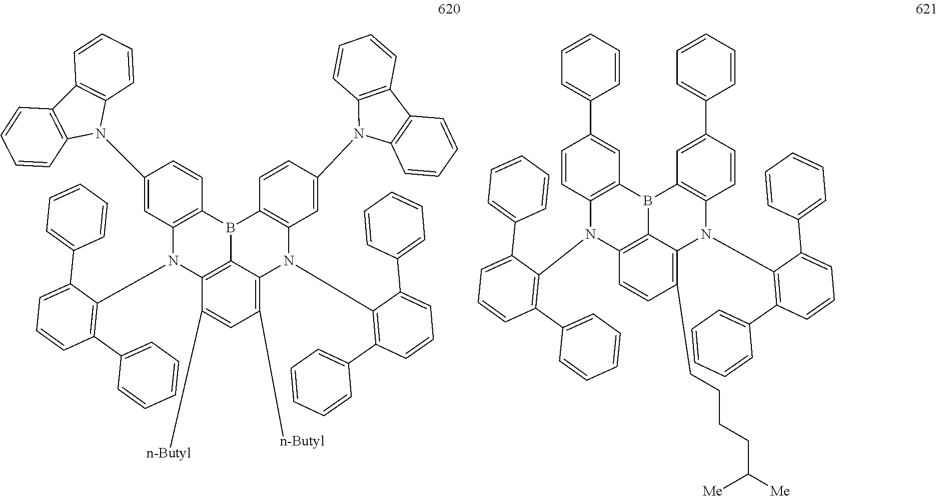 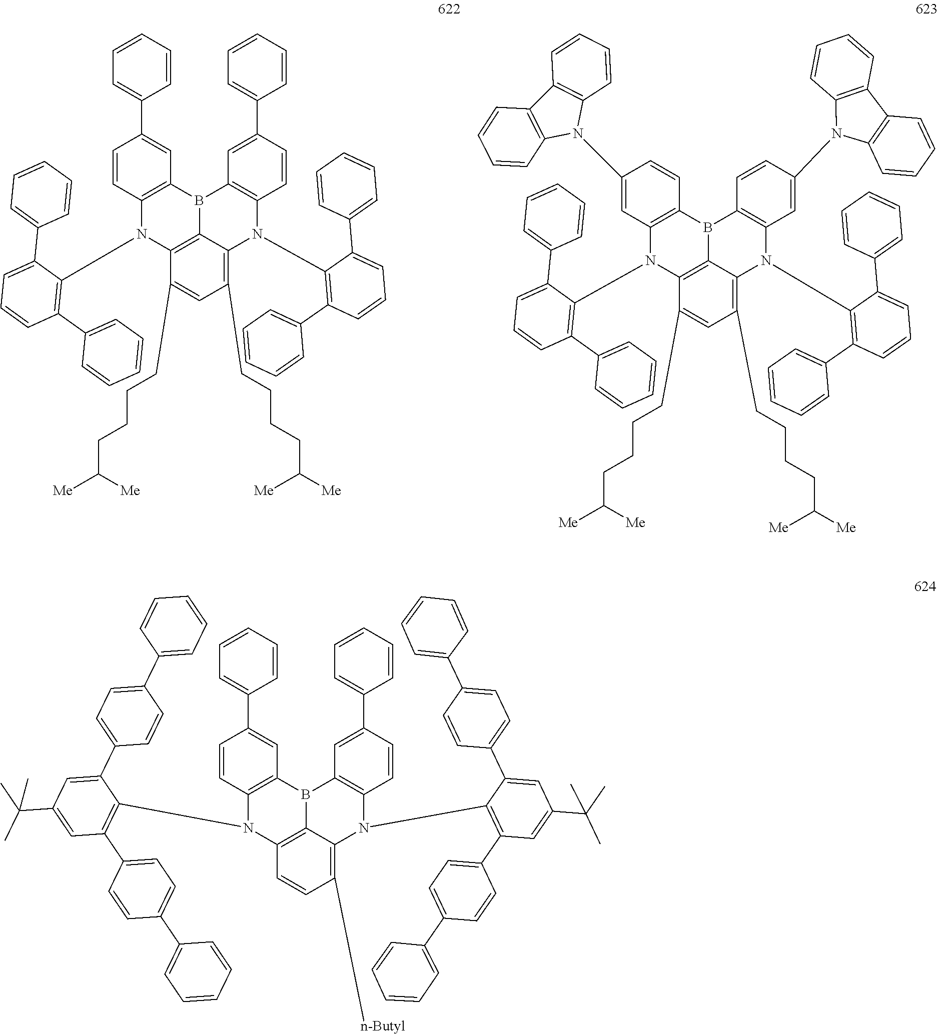 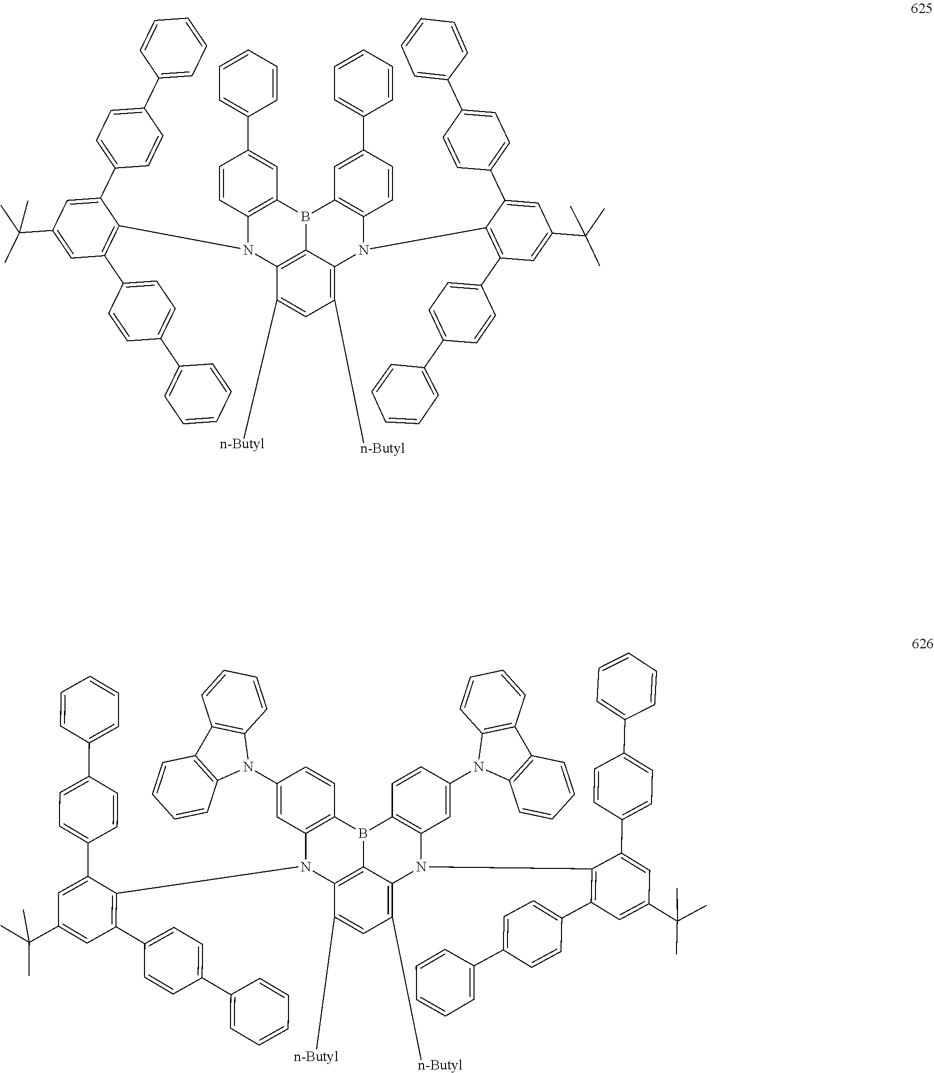 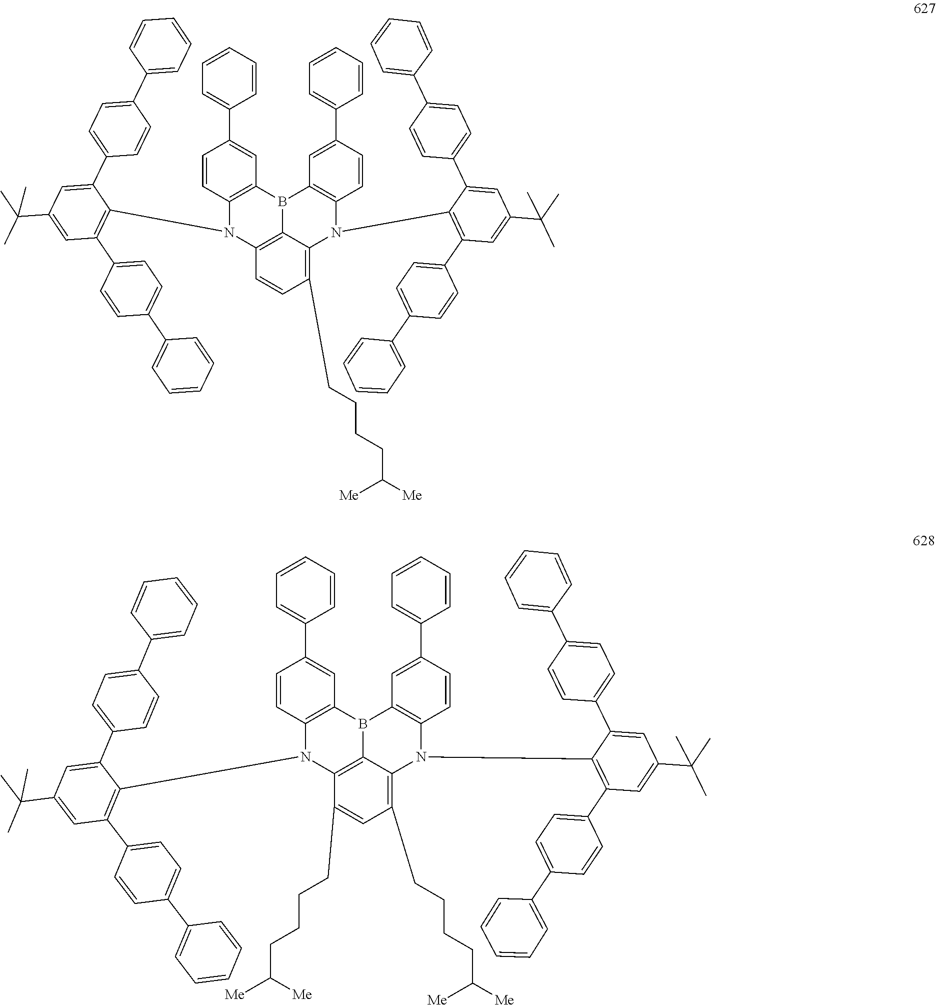 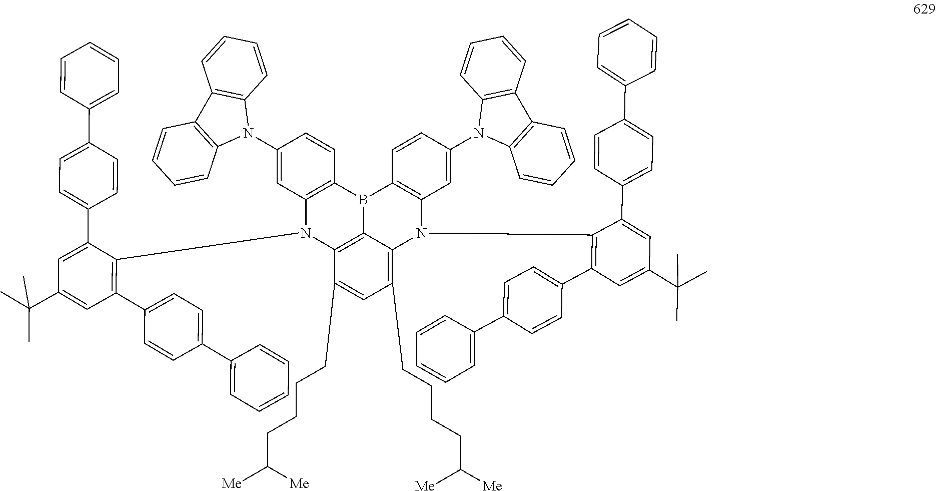 [SMILES: CC(C)CCCCc1cc(CCCCC(C)C)c2c3c1N(c1c(-c4ccc(-c5ccccc5)cc4)cc(C(C)(C)C)cc1-c1ccc(-c4ccccc4)cc1)c1cc(-n4c5ccccc5c5ccccc54)ccc1B3c1ccc(-n3c4ccccc4c4ccccc43)cc1N2c1c(-c2ccc(-c3ccccc3)cc2)cc(C(C)(C)C)cc1-c1ccc(-c2ccccc2)cc1]
wherein in Compound Group 1,
D represents a deuterium atom,
Me represents an unsubstituted methyl group,
Et represents an unsubstituted ethyl group,
n-Pr represents an n-propyl group,
n-Bu and n-Butyl each represent an n-butyl group,
n-Pentyl represents an n-pentyl group,
n-Hexyl represents an n-hexyl group,
n-Heptyl represents an n-heptyl group,
n-Octyl represents an n-octyl group,
n-Nonyl represents an n-nonyl group, and
n-Decyl represents an n-decyl group.

13. A fused polycyclic compound represented by Formula 1: 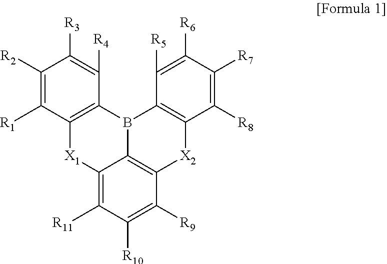
wherein in Formula 1,
X₁ and X₂ are each independently O, S, or N(Rₓ),
R₁ to R₁₁ and Rₓ are each independently a hydrogen atom, a deuterium atom, a halogen atom, a cyano group, a hydroxyl group, a substituted or unsubstituted oxy group, a substituted or unsubstituted thio group, a substituted or unsubstituted boron group, a substituted or unsubstituted silyl group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, a substituted or unsubstituted heteroaryl group of 2 to 30 ring-forming carbon atoms, a group represented by Formula 2, or combined with an adjacent group to form a ring, and
at least one of R₉ to R₁₁ is each independently a group represented by Formula 2: 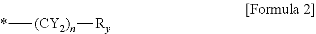
wherein in Formula 2,
n is an integer from 3 to 20,
Y is a hydrogen atom or a deuterium atom,
R_{y} is a substituted or unsubstituted alkyl group of 1 to 20 carbon atoms, and 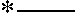 [SMILES: *C]
represents a bond to Formula 1.

14. The fused polycyclic compound of claim 13, wherein in Formula 2, R_{y} is a group represented by one of Formula 3-1 to Formula 3-11: 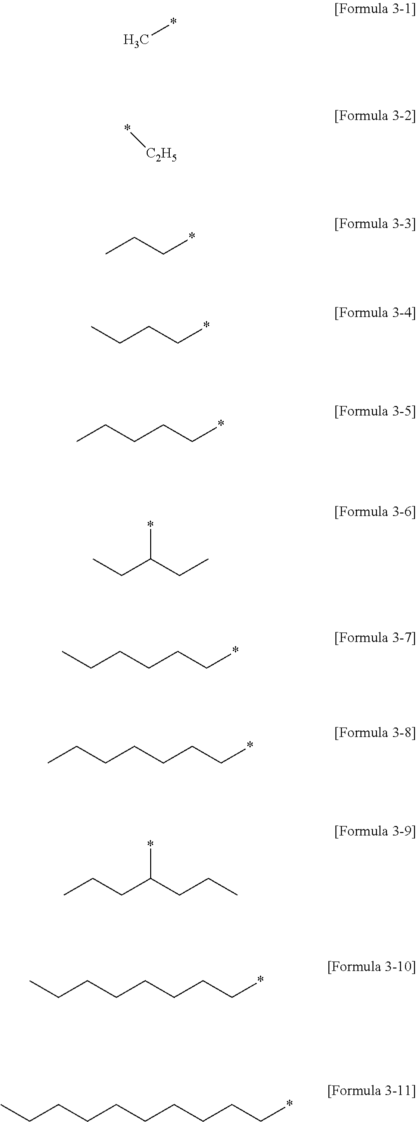
wherein in Formula 3-1 to Formula 3-11,
at least one hydrogen atom is optionally substituted with a deuterium atom.

15. The fused polycyclic compound of claim 13, wherein the fused polycyclic compound represented by Formula 1 is represented by Formula 1-1: 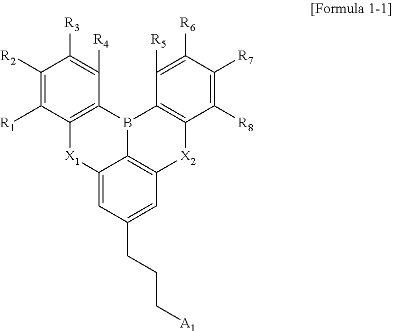
wherein in Formula 1-1,
A₁ is a substituted or unsubstituted linear alkyl group of 1 to 10 carbon atoms or a substituted or unsubstituted branched alkyl group of 1 to 10 carbon atoms, and
R₁ to R₈, Rₓ, X₁, and X₂ are the same as defined in Formula 1.

16. The fused polycyclic compound of claim 13, wherein the fused polycyclic compound represented by Formula 1 is represented by Formula 1-2 or Formula 1-3: 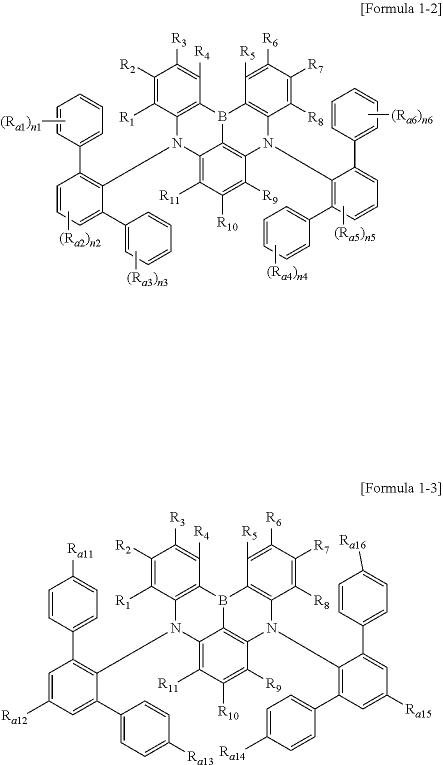
wherein in Formula 1-2 and Formula 1-3,
Rai to Rₐ₆ and Rₐ₁₁ to Rₐ₁₆ are each independently a hydrogen atom, a deuterium atom, a halogen atom, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
n1, n3, n4, and n6 are each independently an integer from 0 to 5,
n2 and n5 are each independently an integer from 0 to 3, and
R₁ to R₁₁ are the same as defined in Formula 1.

17. The fused polycyclic compound of claim 13, wherein in Formula 1,
at least one of R₁ to R₄ is each independently a group represented by Formula 2, Formula 4-1, or Formula 4-2, and
at least one of R₅ to R₈ is each independently a group represented by Formula 2, Formula 4-1, or Formula 4-2: 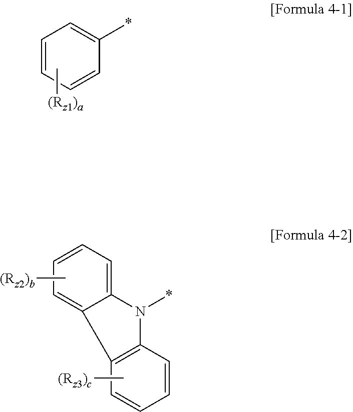
wherein in Formula 4-1 and Formula 4-2,
R_{z1} to R_{z3} are each independently a hydrogen atom, a deuterium atom, a halogen atom, a substituted or unsubstituted linear alkyl group of 1 to 20 carbon atoms, or a substituted or unsubstituted branched alkyl group of 1 to 20 carbon atoms,
a is an integer from 0 to 5, and
b and c are each independently an integer from 0 to 4.

18. The fused polycyclic compound of claim 13, wherein the fused polycyclic compound represented by Formula 1 is represented by one of Formula 1-4 to Formula 1-6: 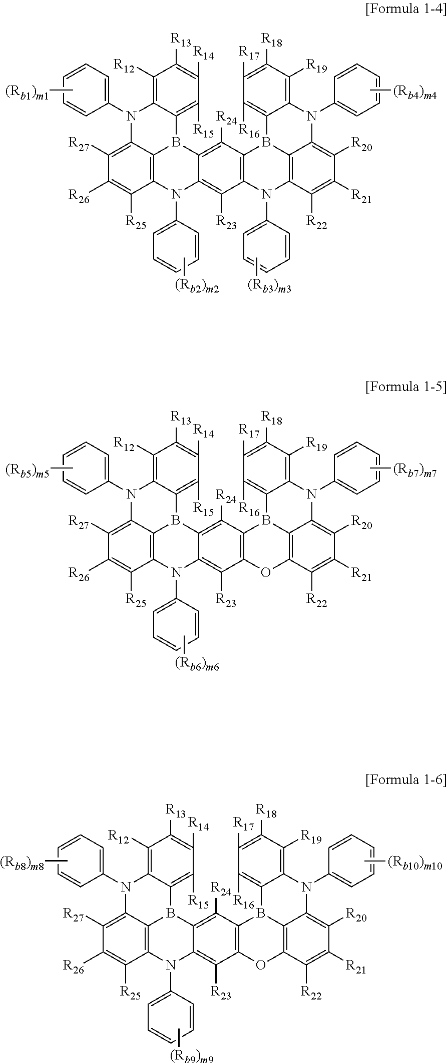
wherein in Formula 1-4 to Formula 1-6,
R₁₂ to R₂₇ are each independently a hydrogen atom, a deuterium atom, a halogen atom, a cyano group, a hydroxyl group, a substituted or unsubstituted oxy group, a substituted or unsubstituted thio group, a substituted or unsubstituted boron group, a substituted or unsubstituted silyl group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, a substituted or unsubstituted heteroaryl group of 2 to 30 ring-forming carbon atoms, or a group represented by Formula 2,
R_{b1} to R_{b10} are each independently a hydrogen atom, a deuterium atom, a halogen atom, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
m1 to m10 are each independently an integer from 0 to 5,
at least one of R₂₅ to R₂₇ is each independently a group represented by Formula 2, and at least one hydrogen atom is optionally substituted with a deuterium atom.

19. The fused polycyclic compound of claim 13, wherein the fused polycyclic compound represented by Formula 1 is represented by Formula 1-7 or Formula 1-8: 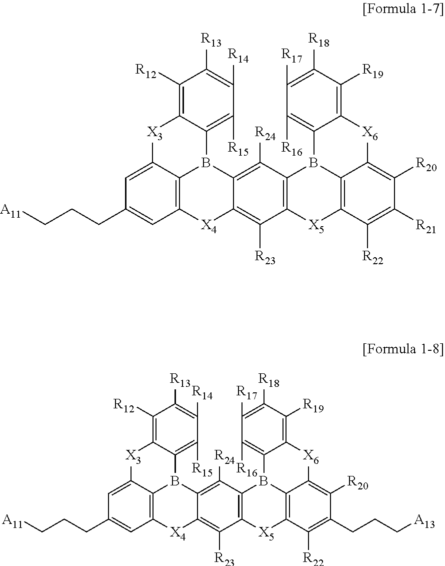
wherein in Formula 1-7 and Formula 1-8,
X₃ to X₆ are each independently O, S, or N(Rₓ),
A₁₁ to A₁₃ are each independently a substituted or unsubstituted linear alkyl group of 1 to 10 carbon atoms or a substituted or unsubstituted branched alkyl group of 1 to 10 carbon atoms,
R₁₂ to R₂₄ are each independently a hydrogen atom, a deuterium atom, a halogen atom, a cyano group, a hydroxyl group, a substituted or unsubstituted oxy group, a substituted or unsubstituted thio group, a substituted or unsubstituted boron group, a substituted or unsubstituted silyl group, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, a substituted or unsubstituted heteroaryl group of 2 to 30 ring-forming carbon atoms, or a group represented by Formula 2,
Rₓ is the same as defined in Formula 1, and
at least one hydrogen atom is optionally substituted with a deuterium atom.

20. The fused polycyclic compound of claim 13, wherein the fused polycyclic compound represented by Formula 1 is selected from Compound Group 1: 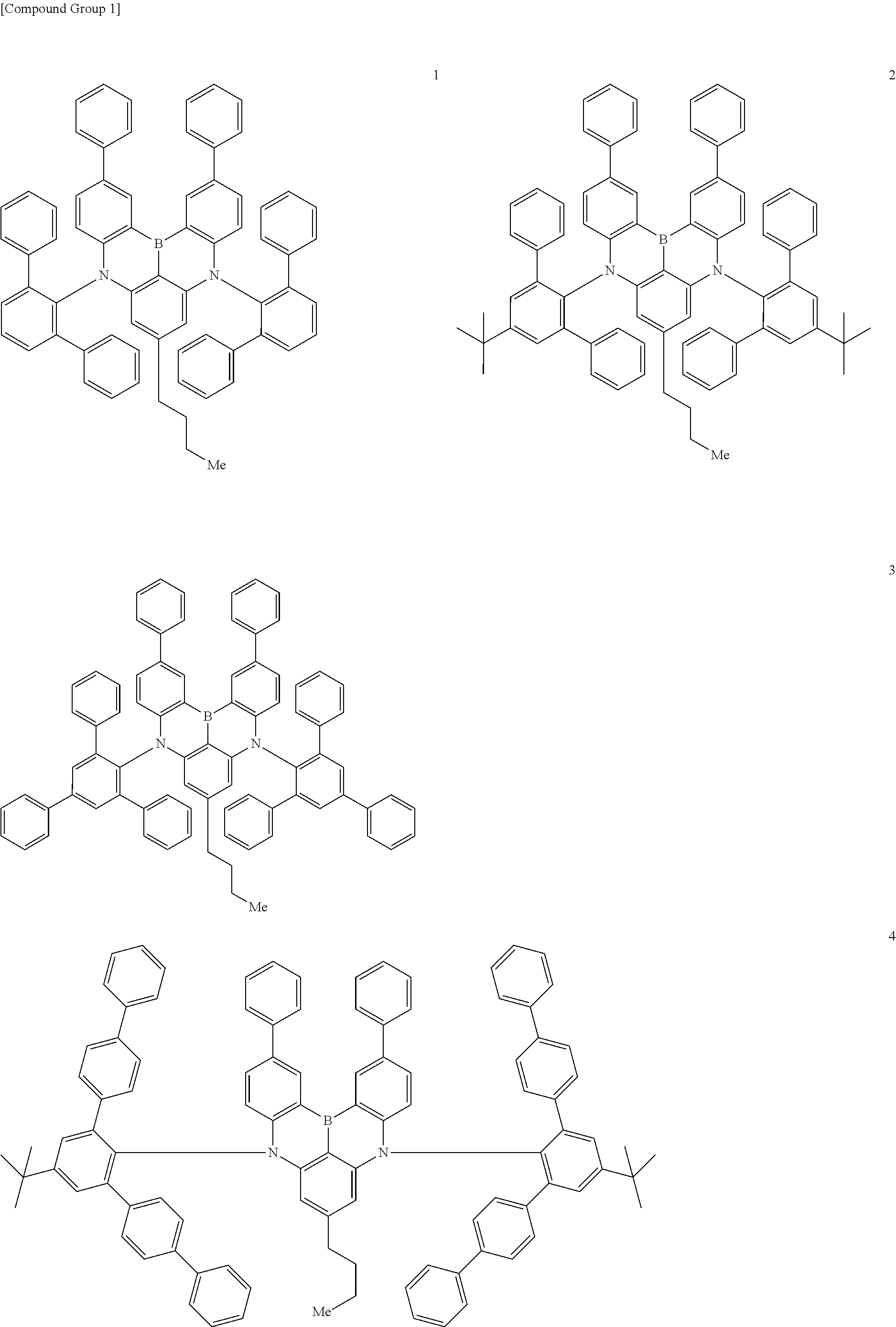 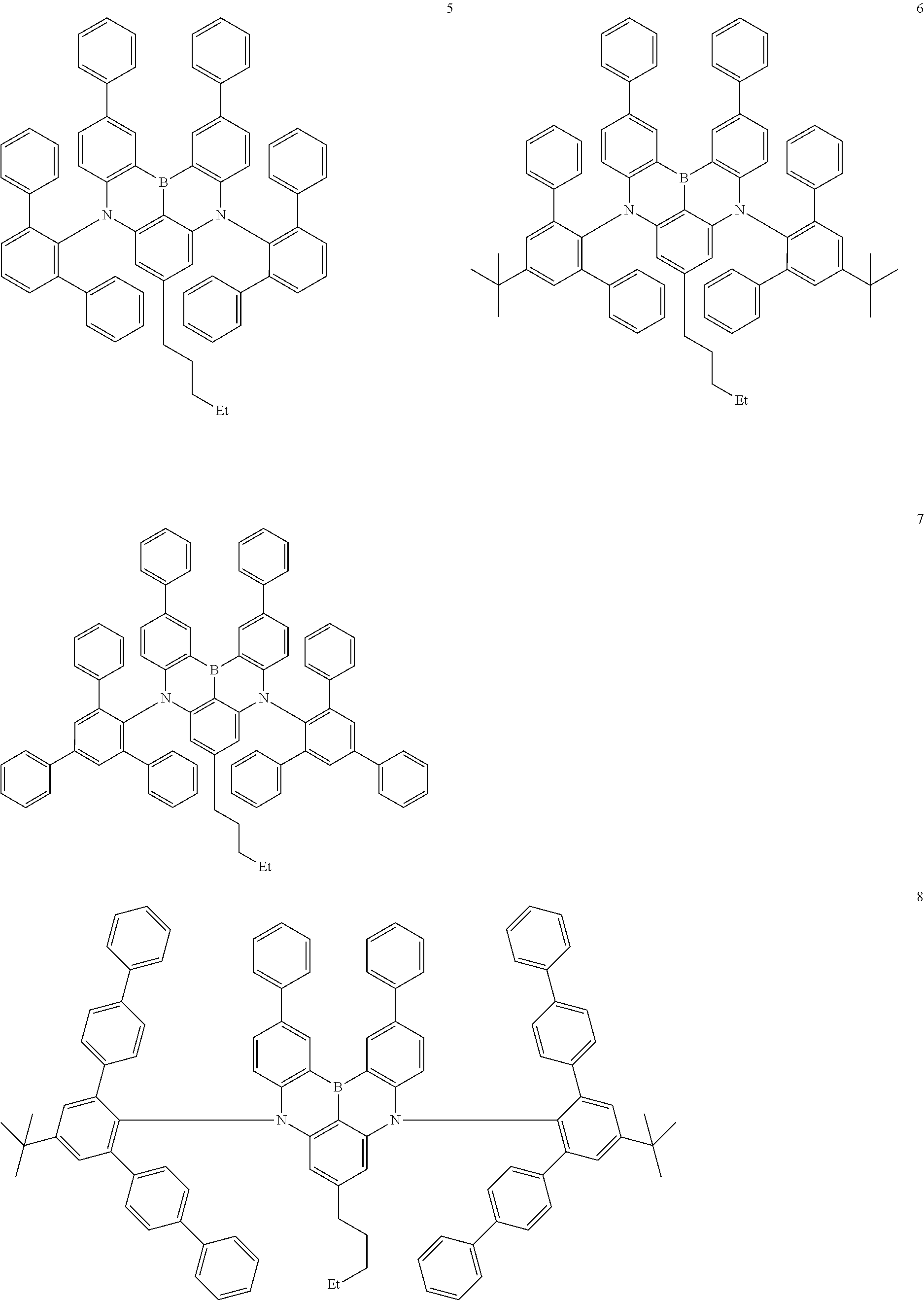 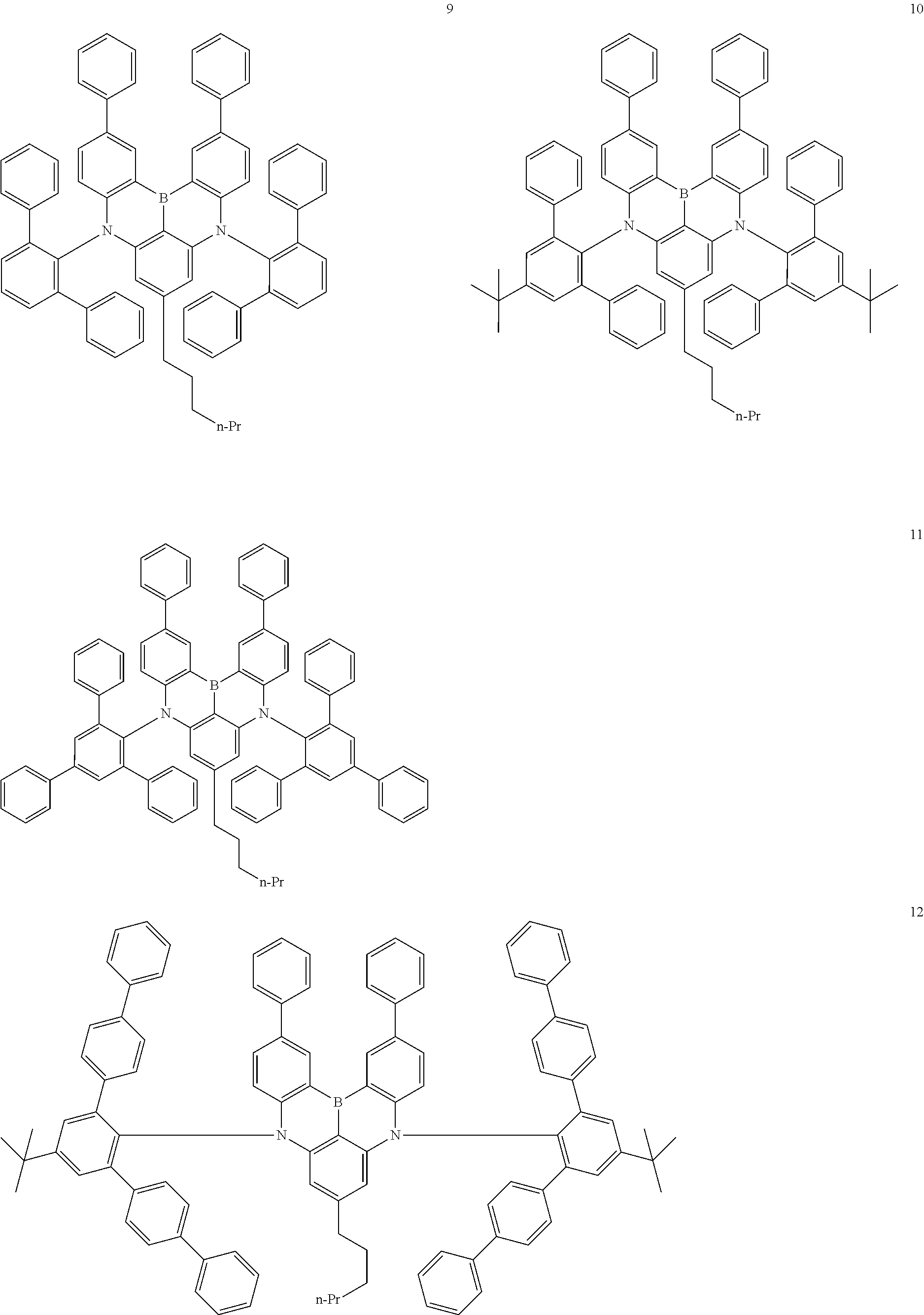 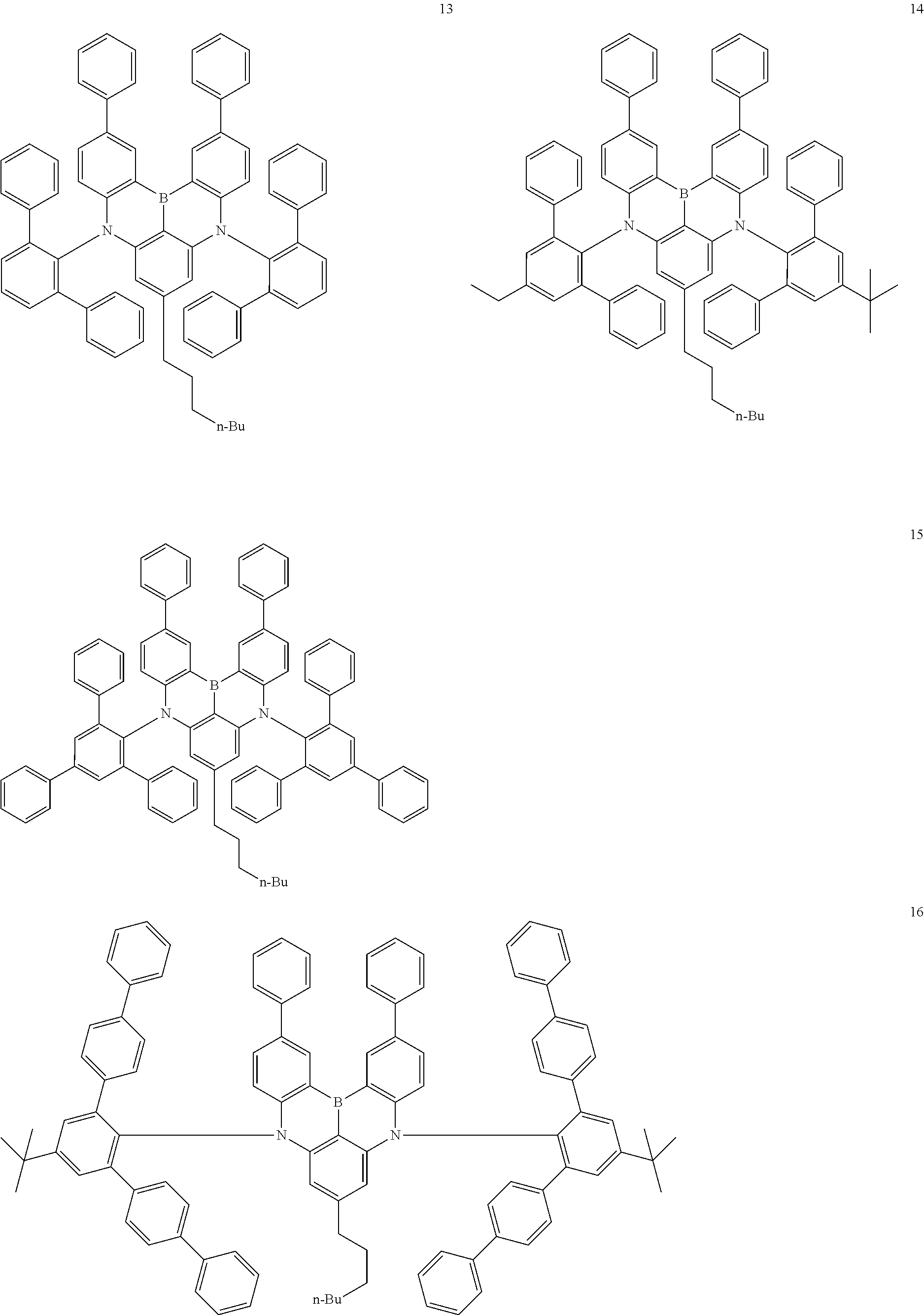 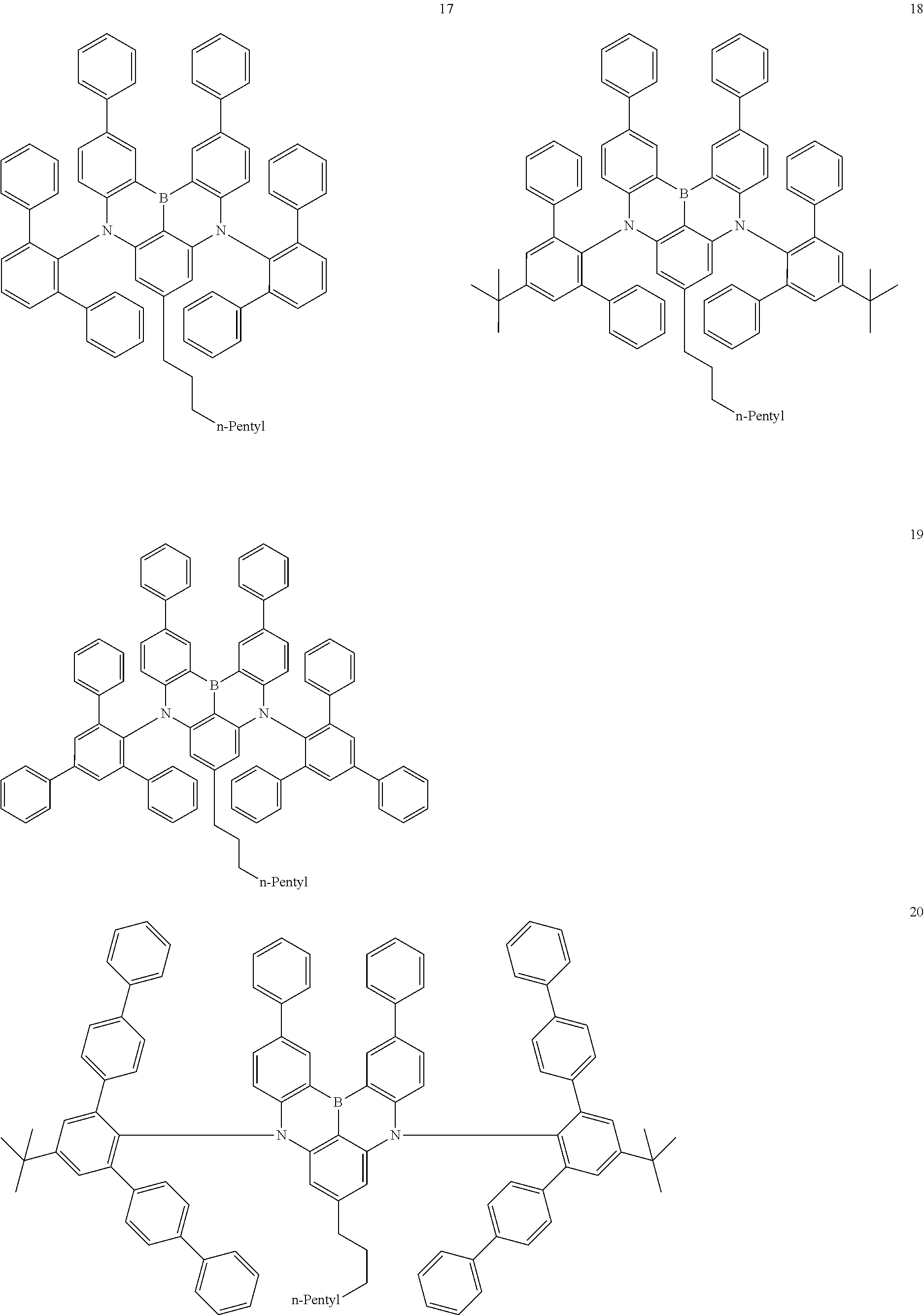 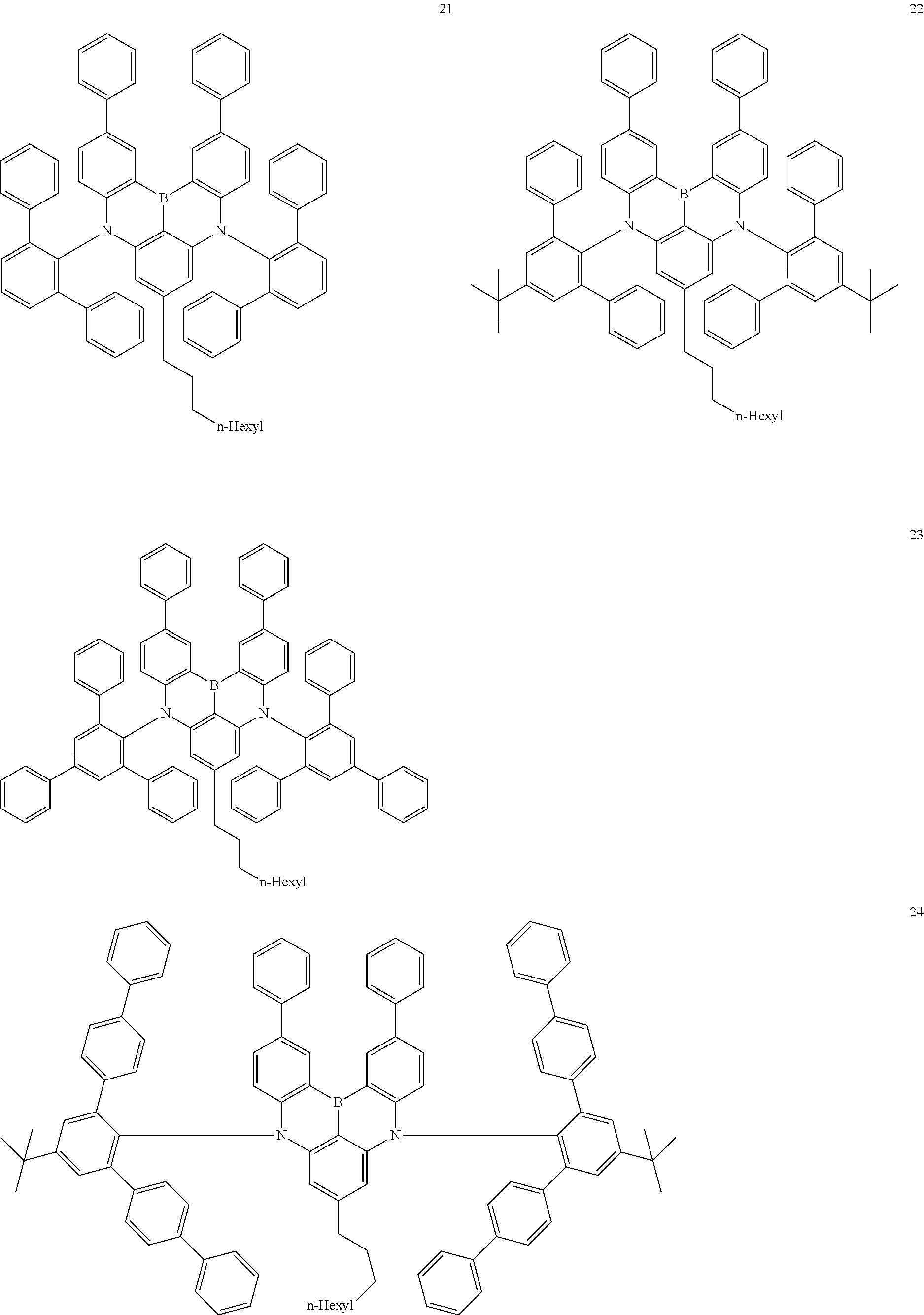 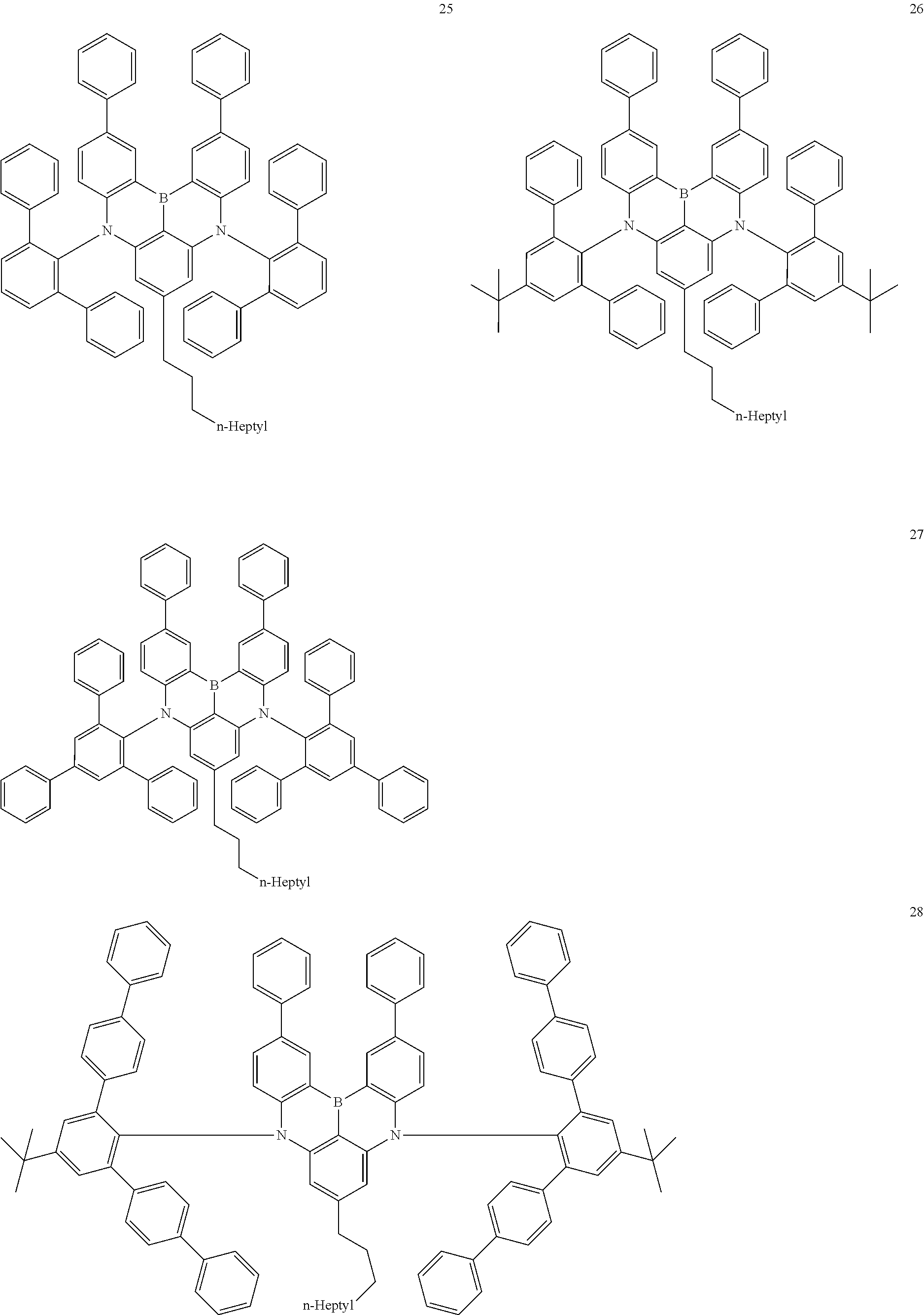 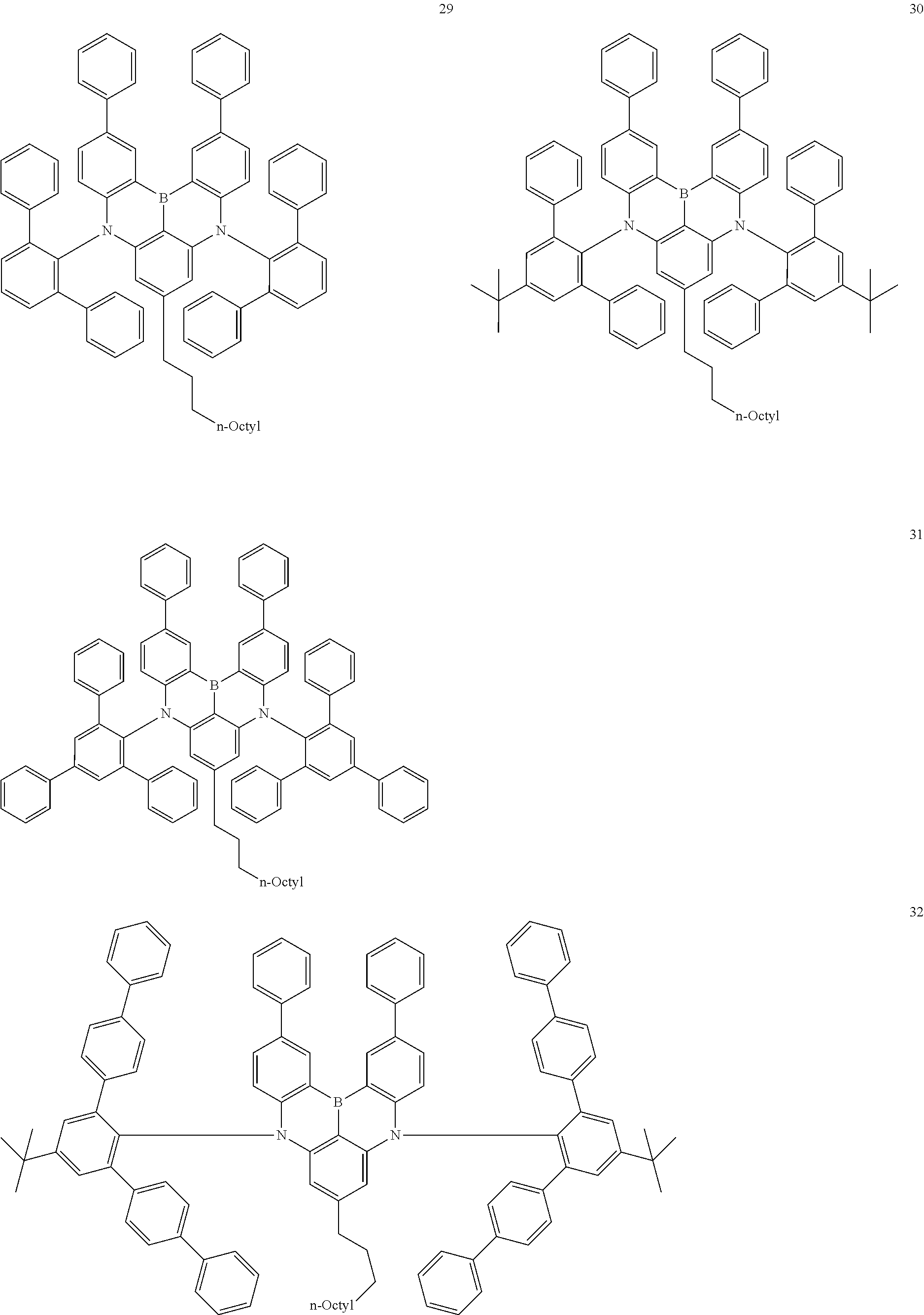 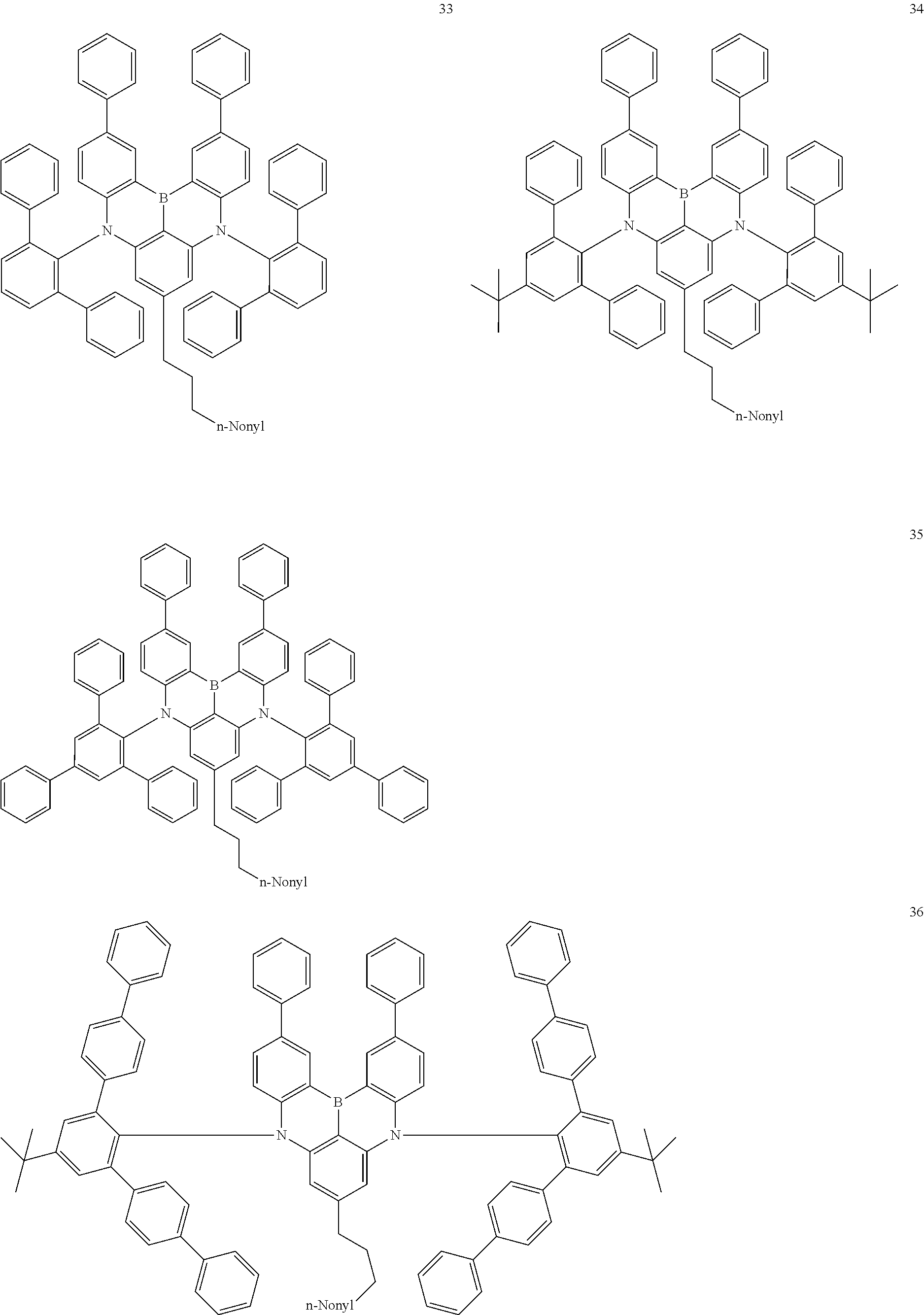 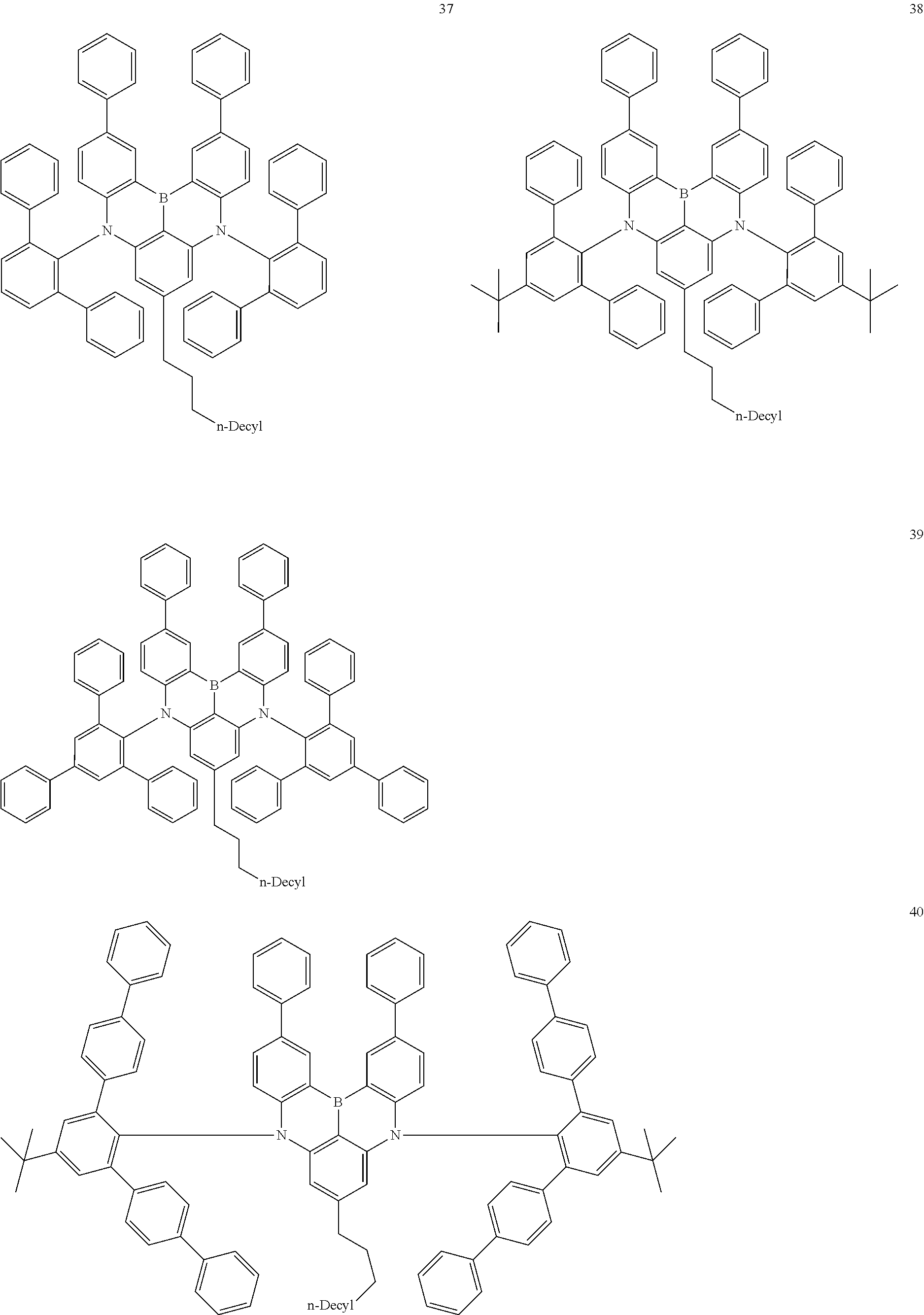 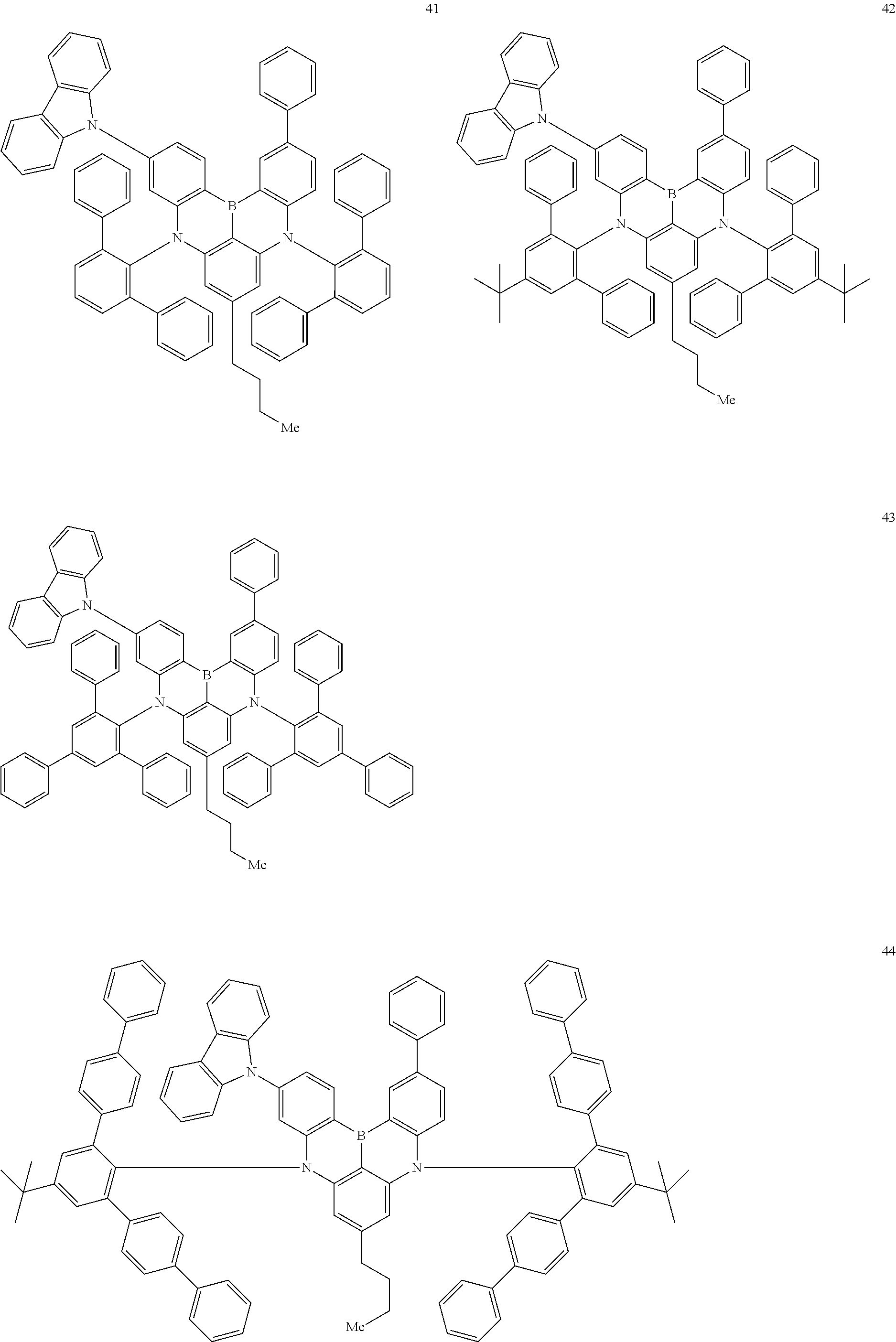 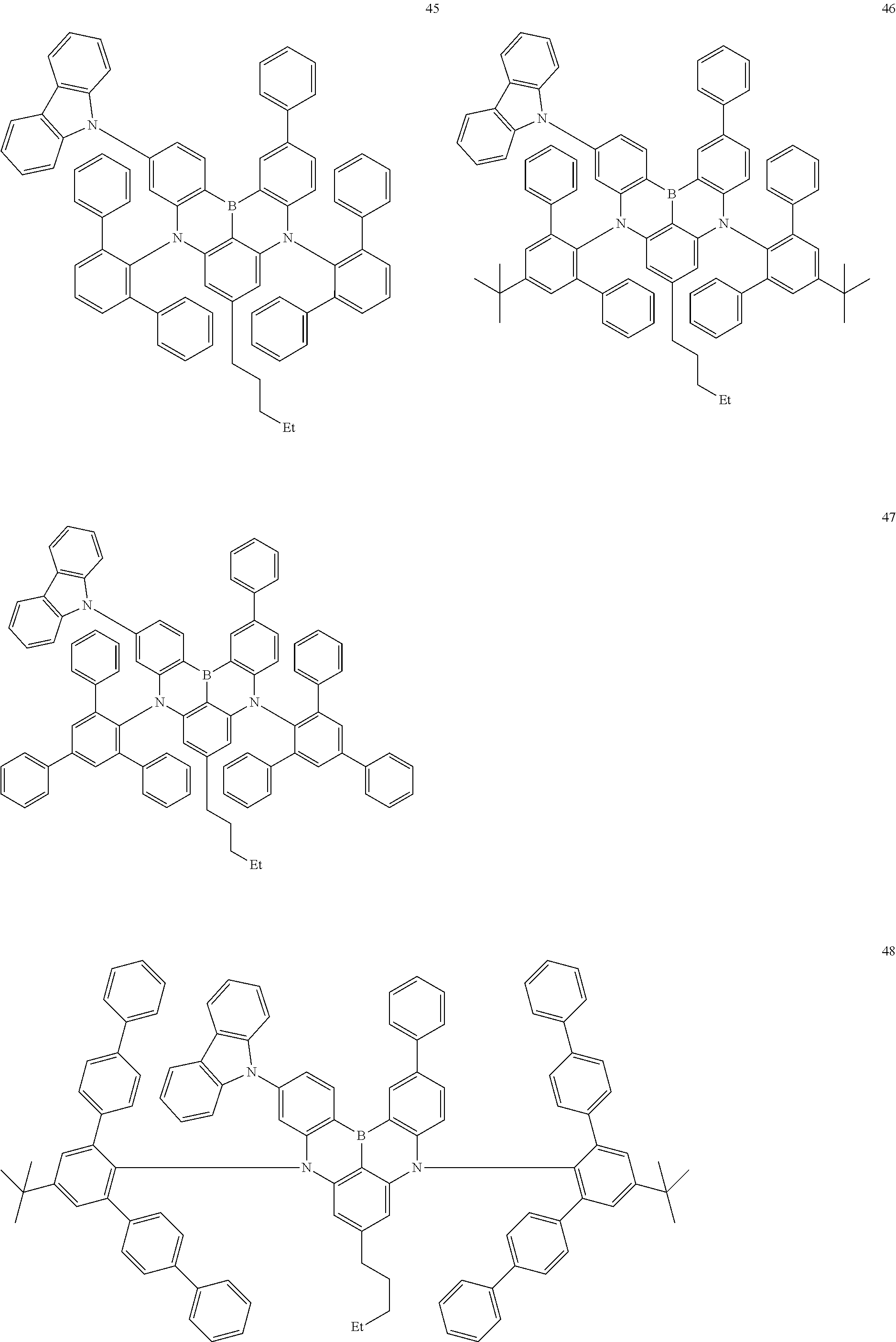 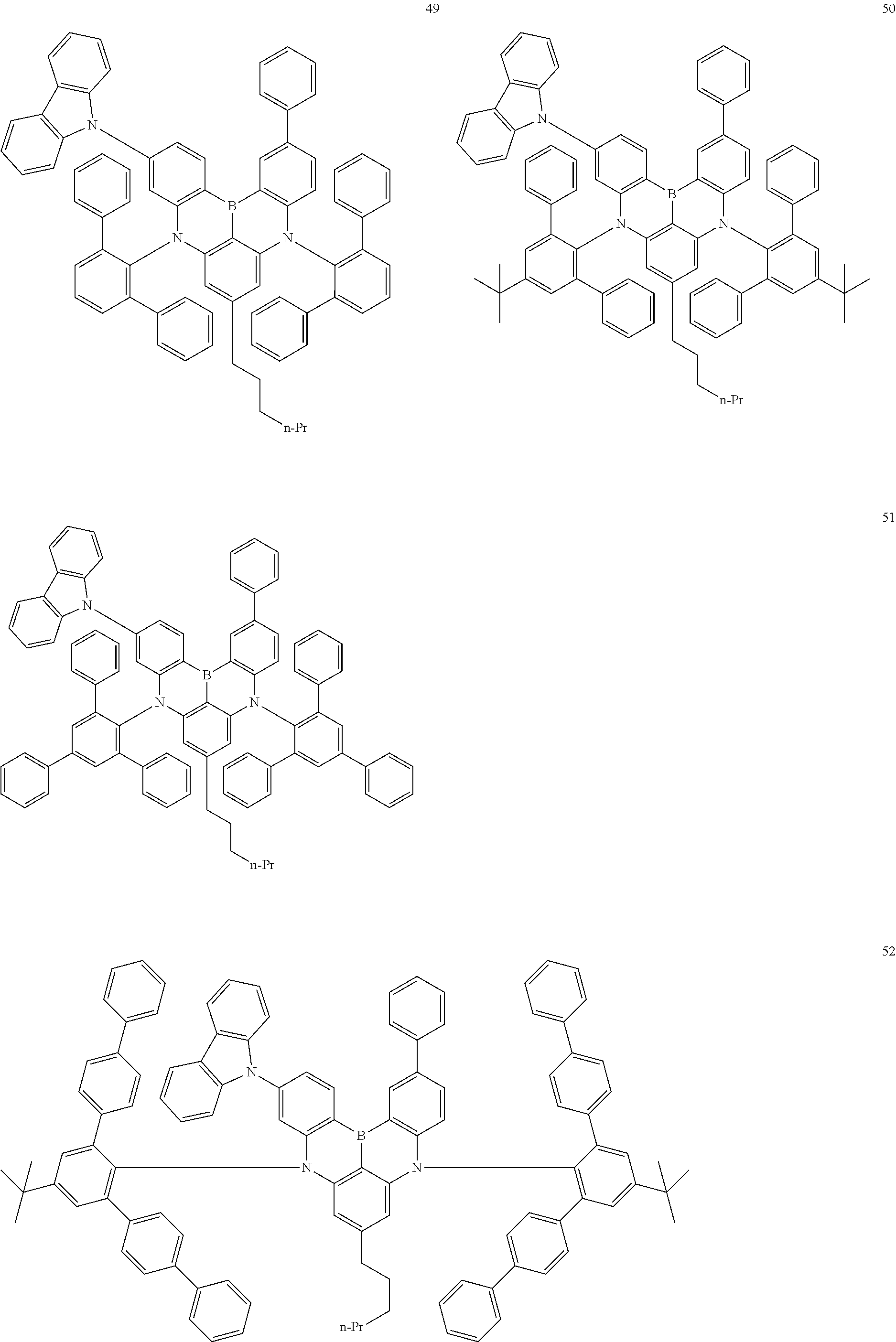 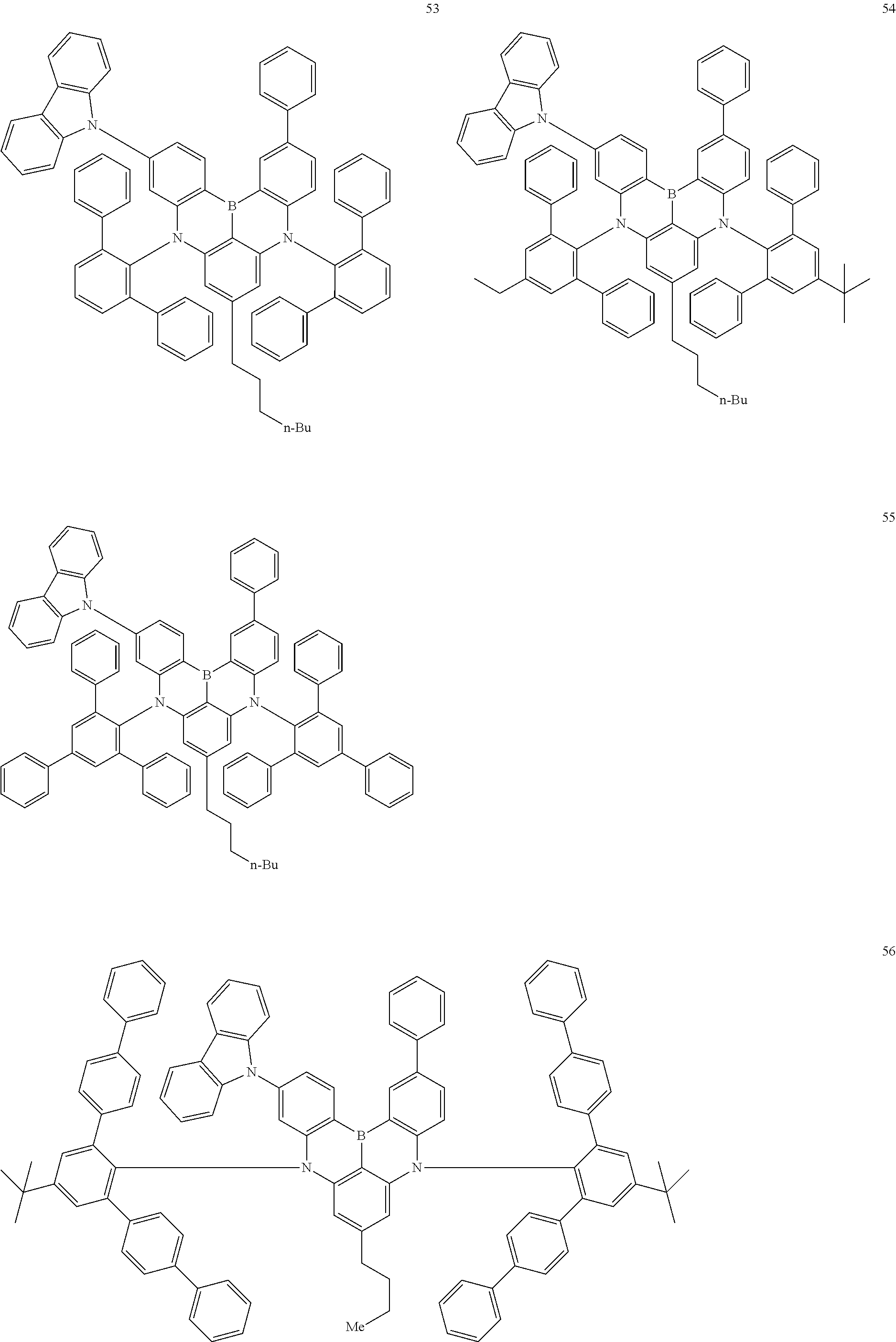 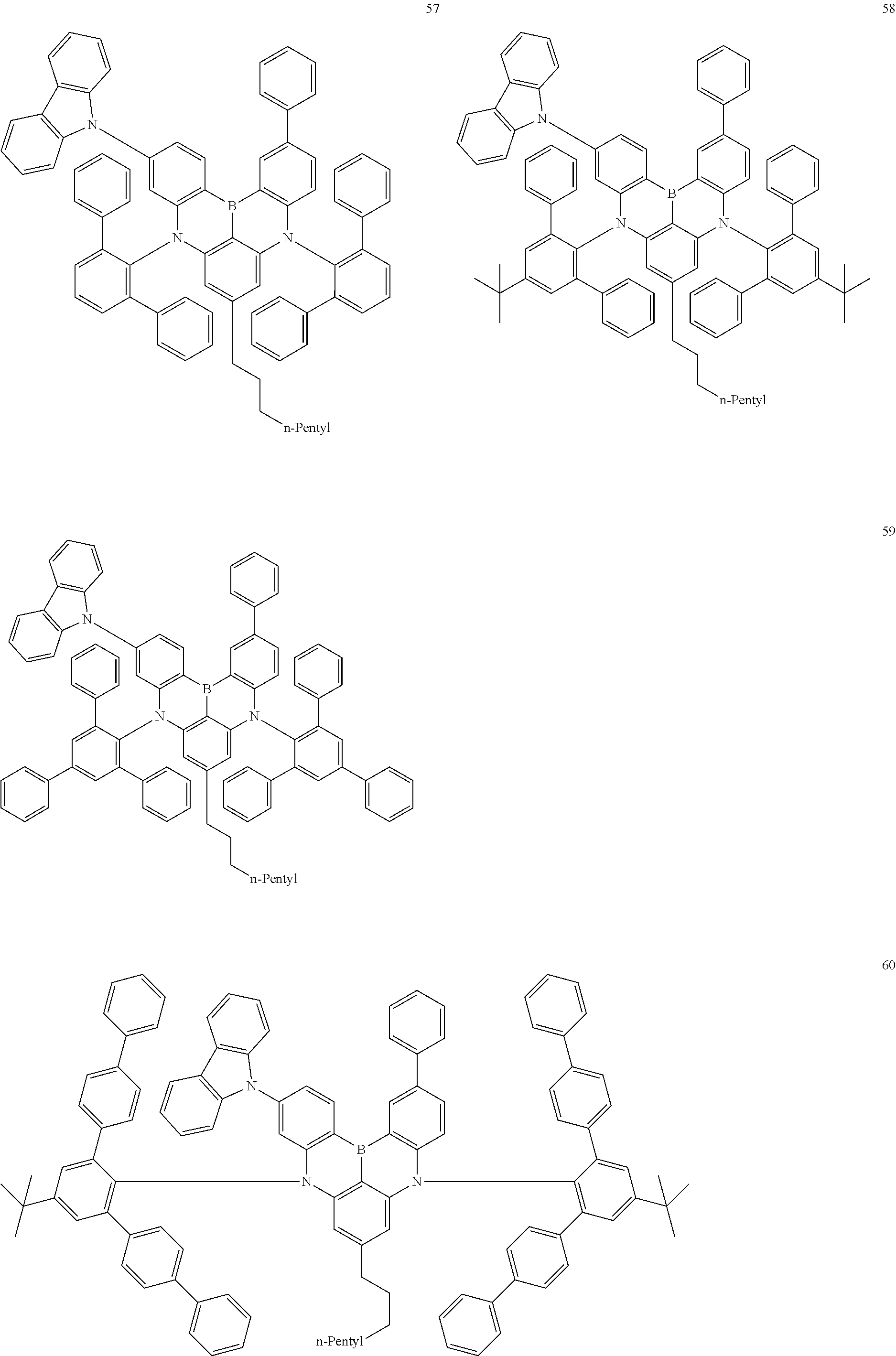 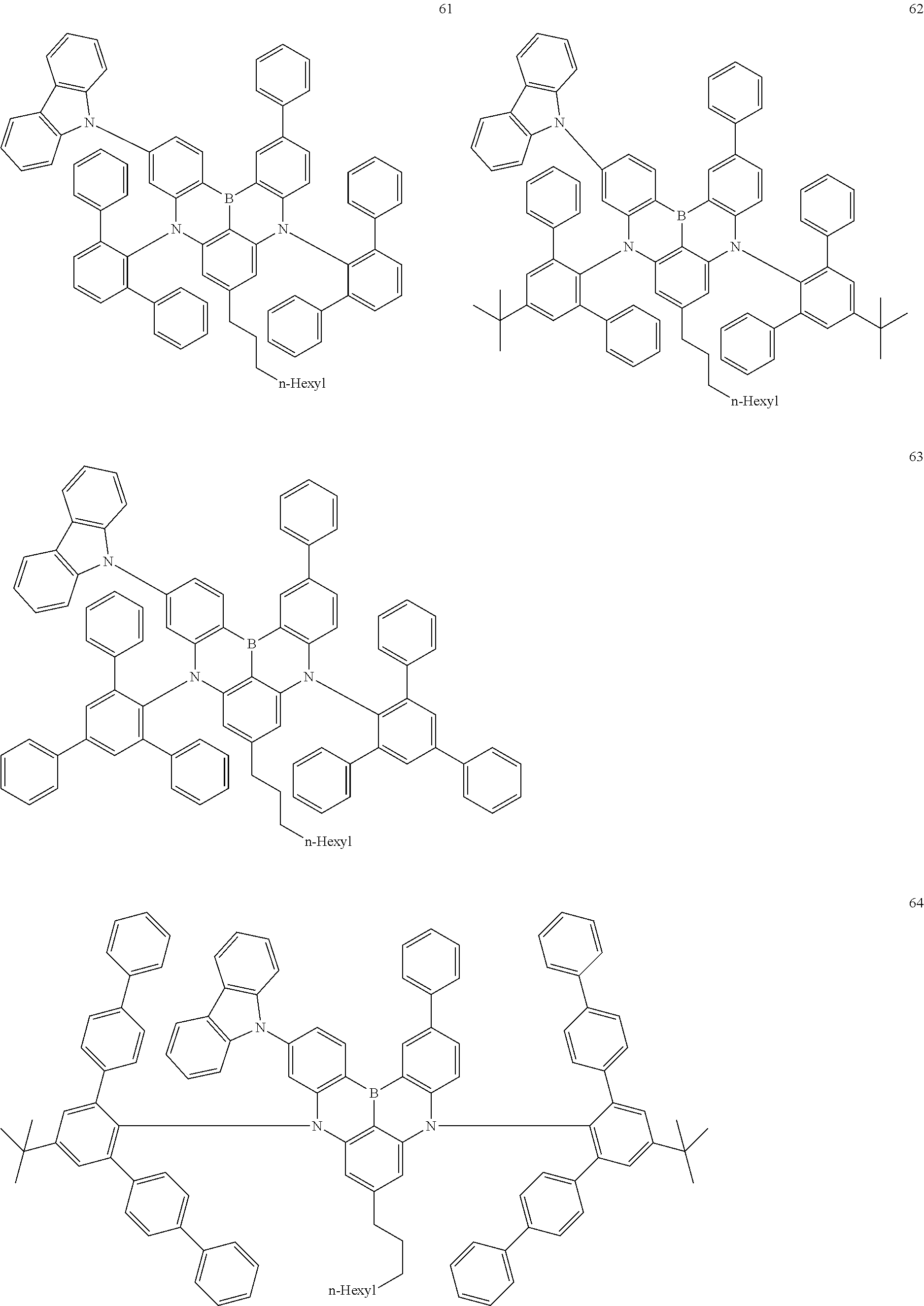 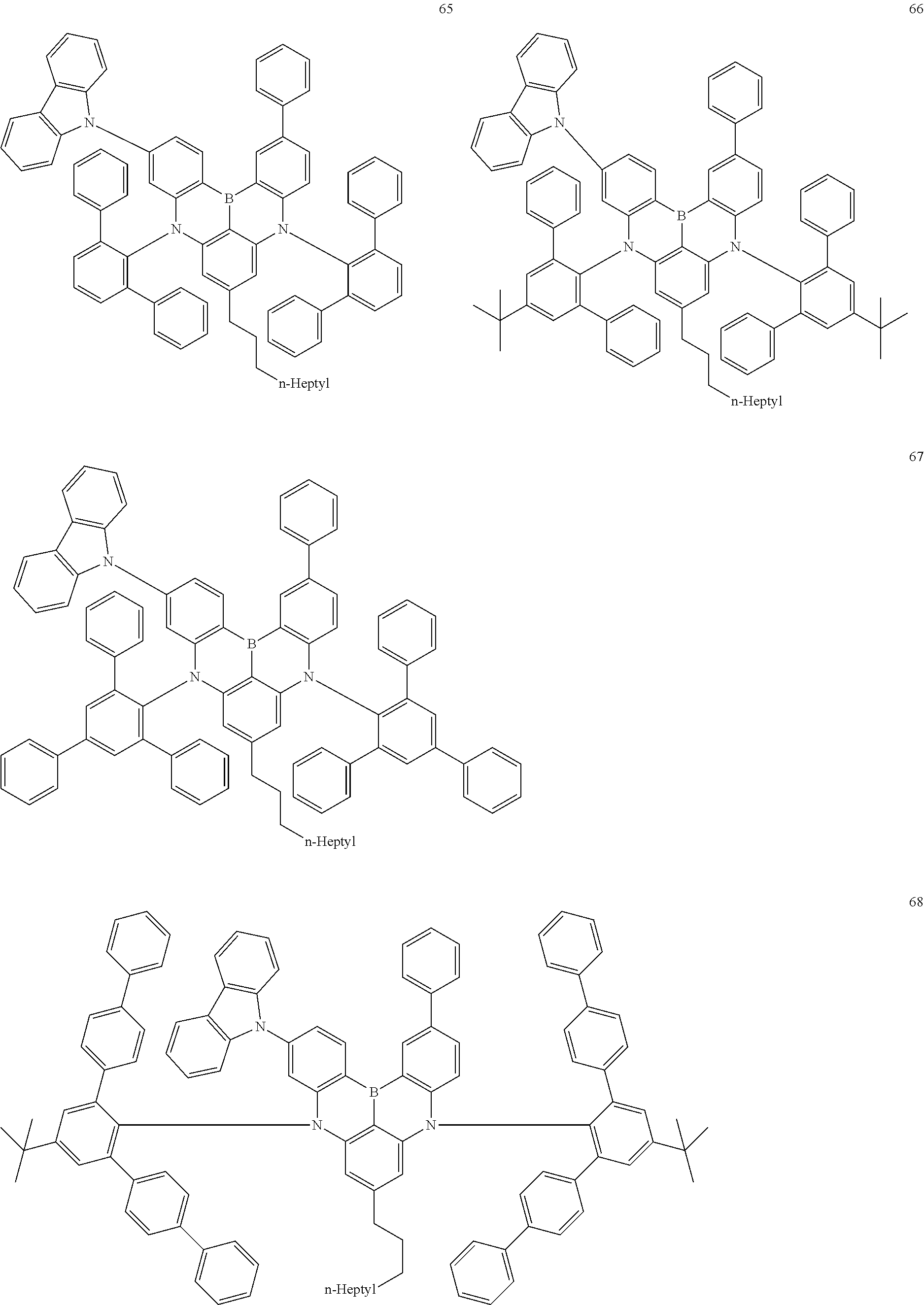 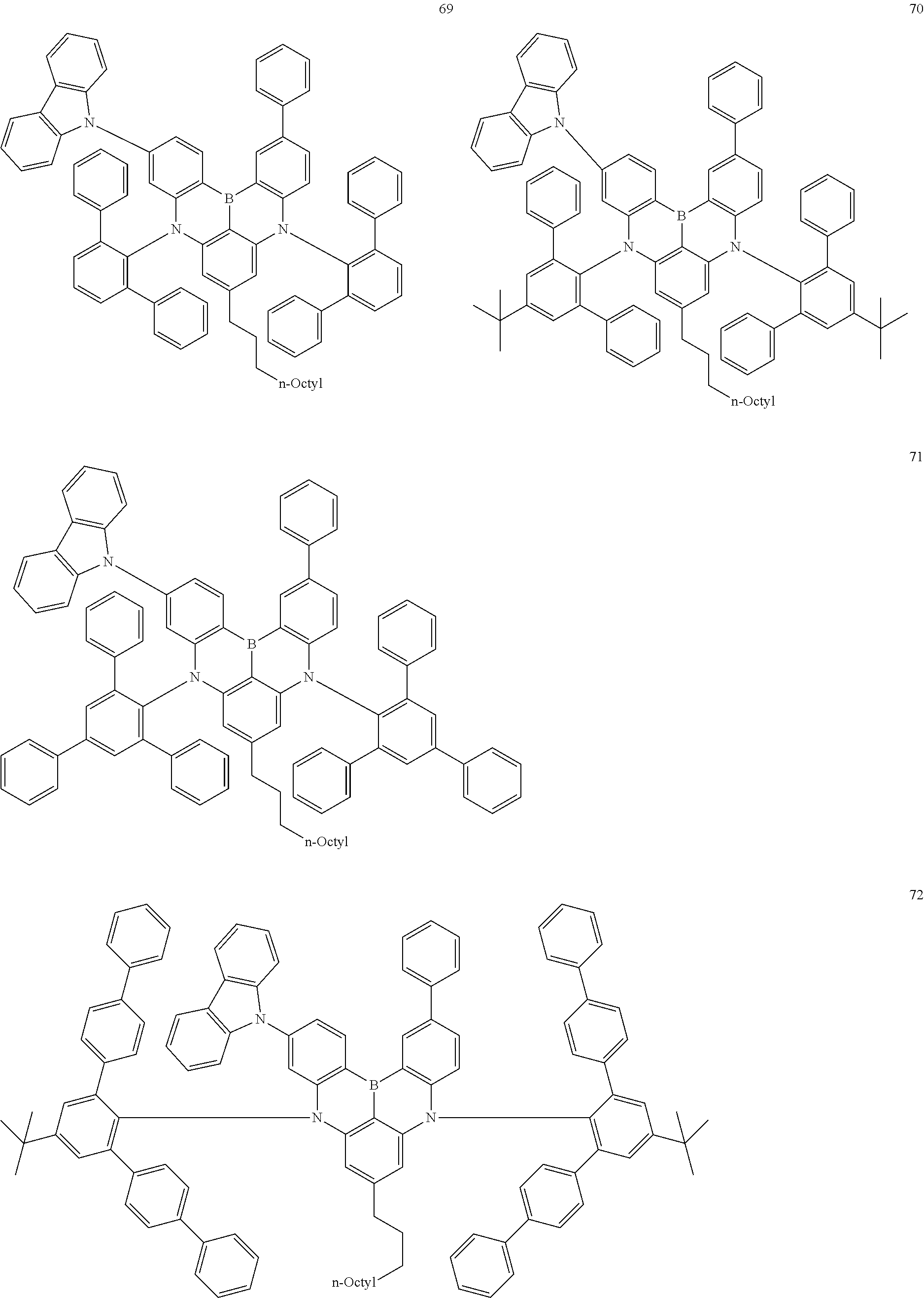 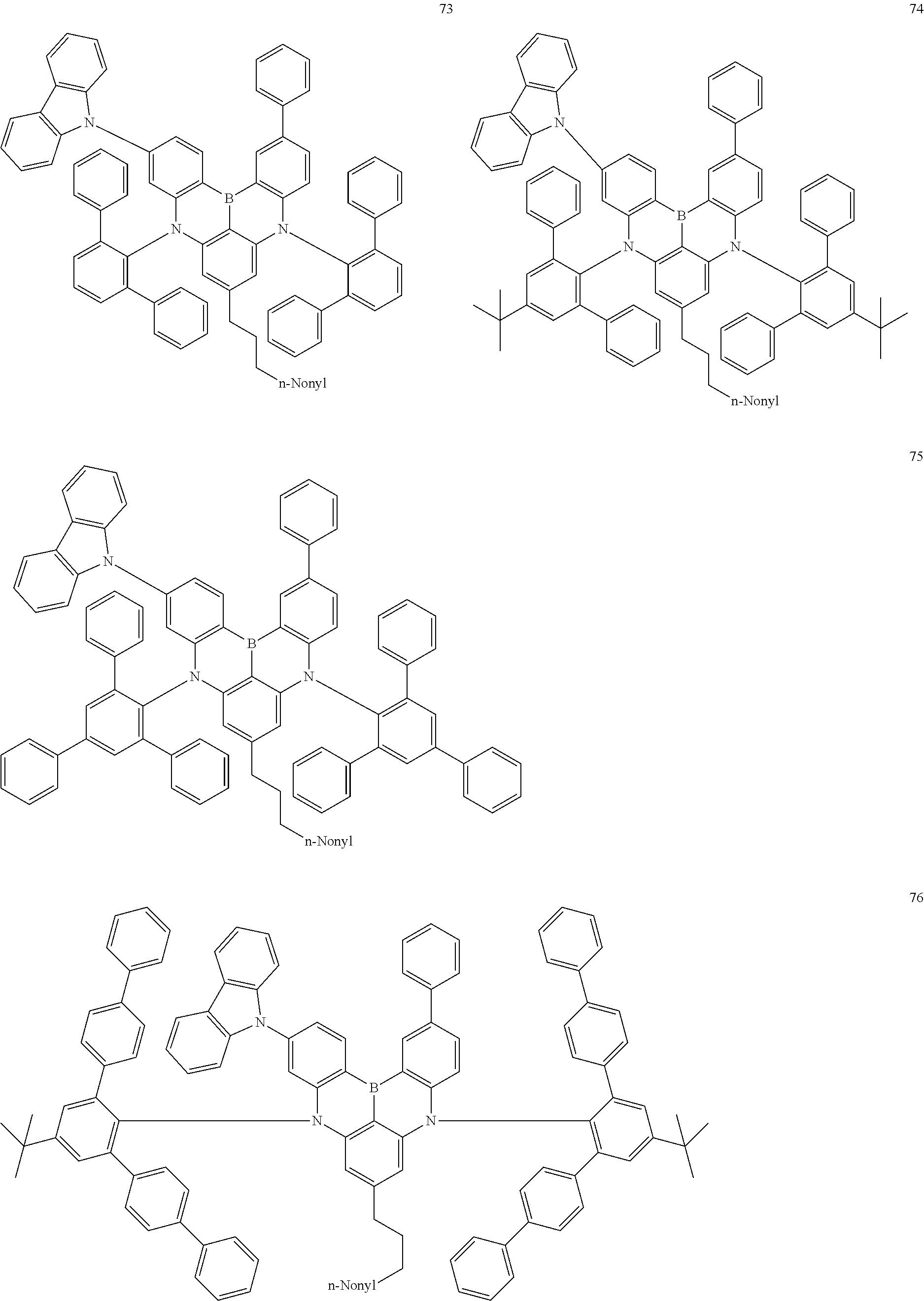 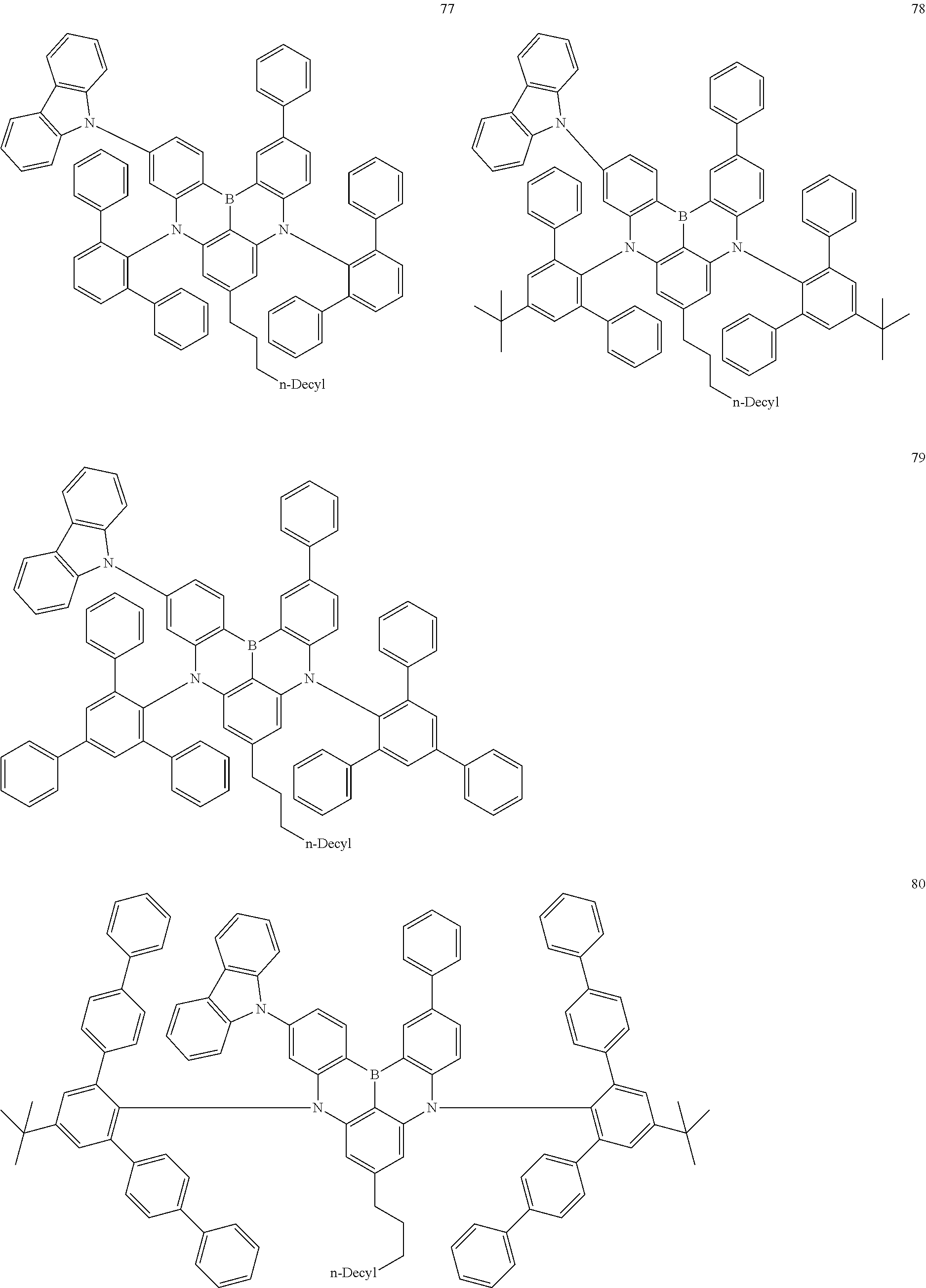 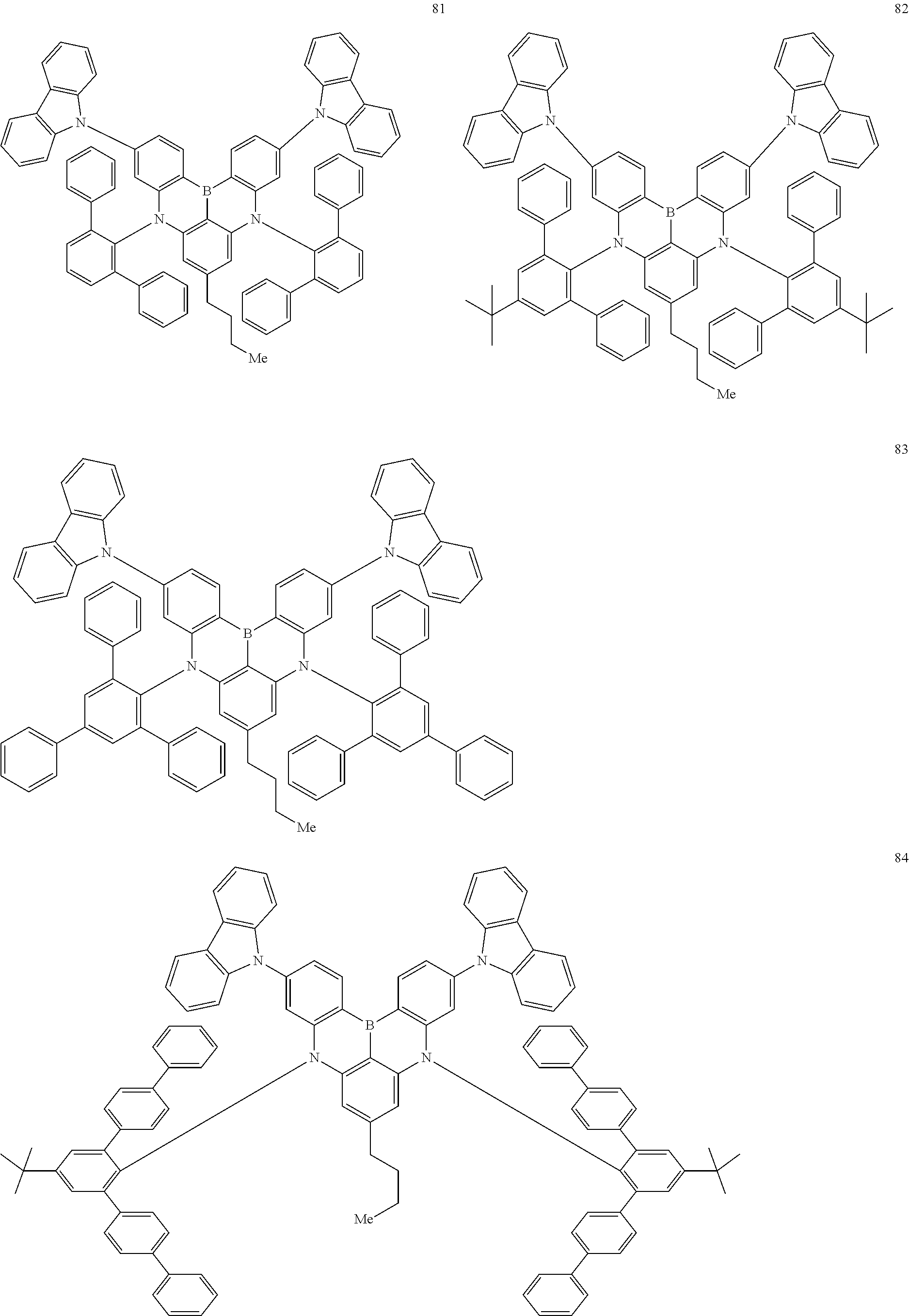 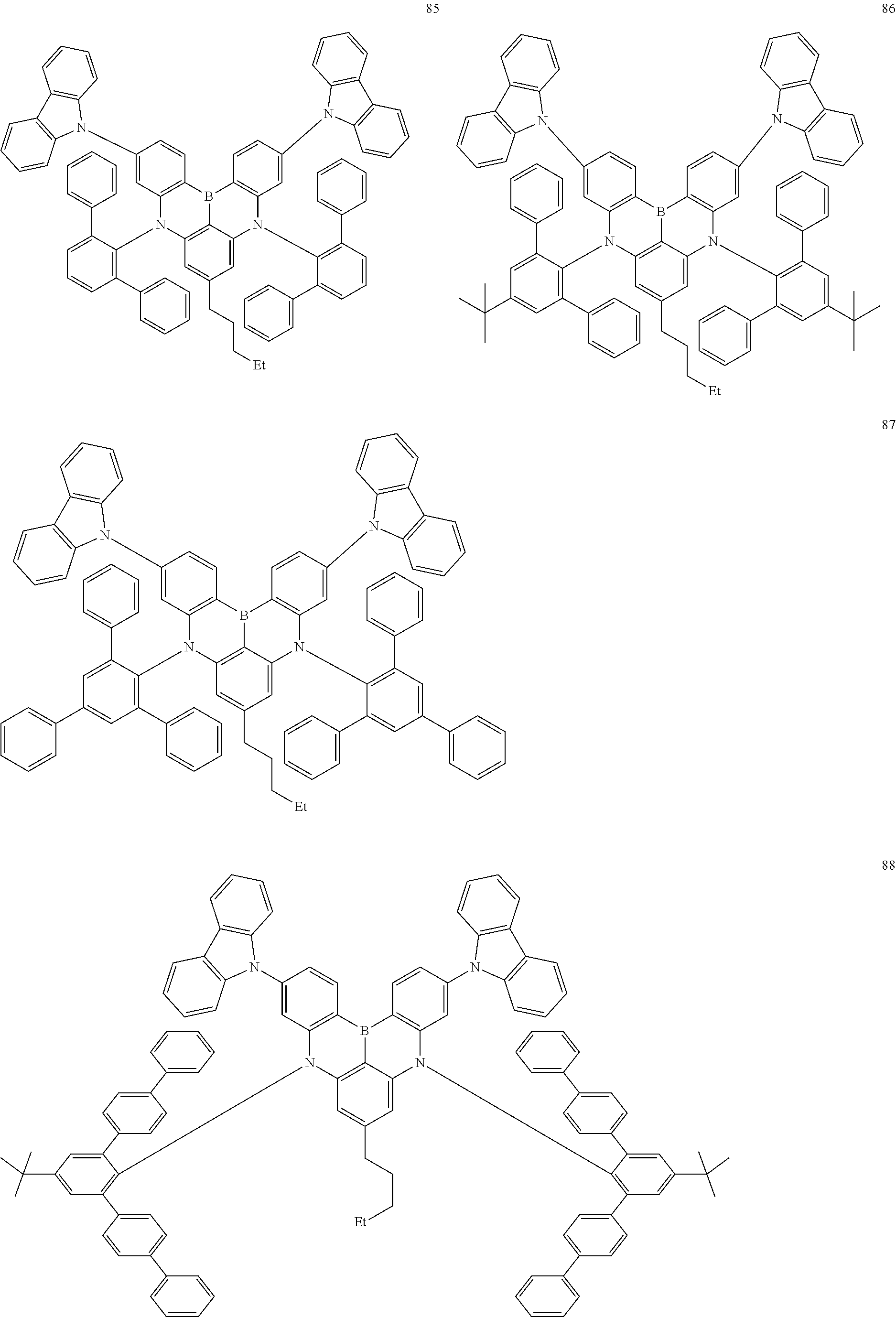 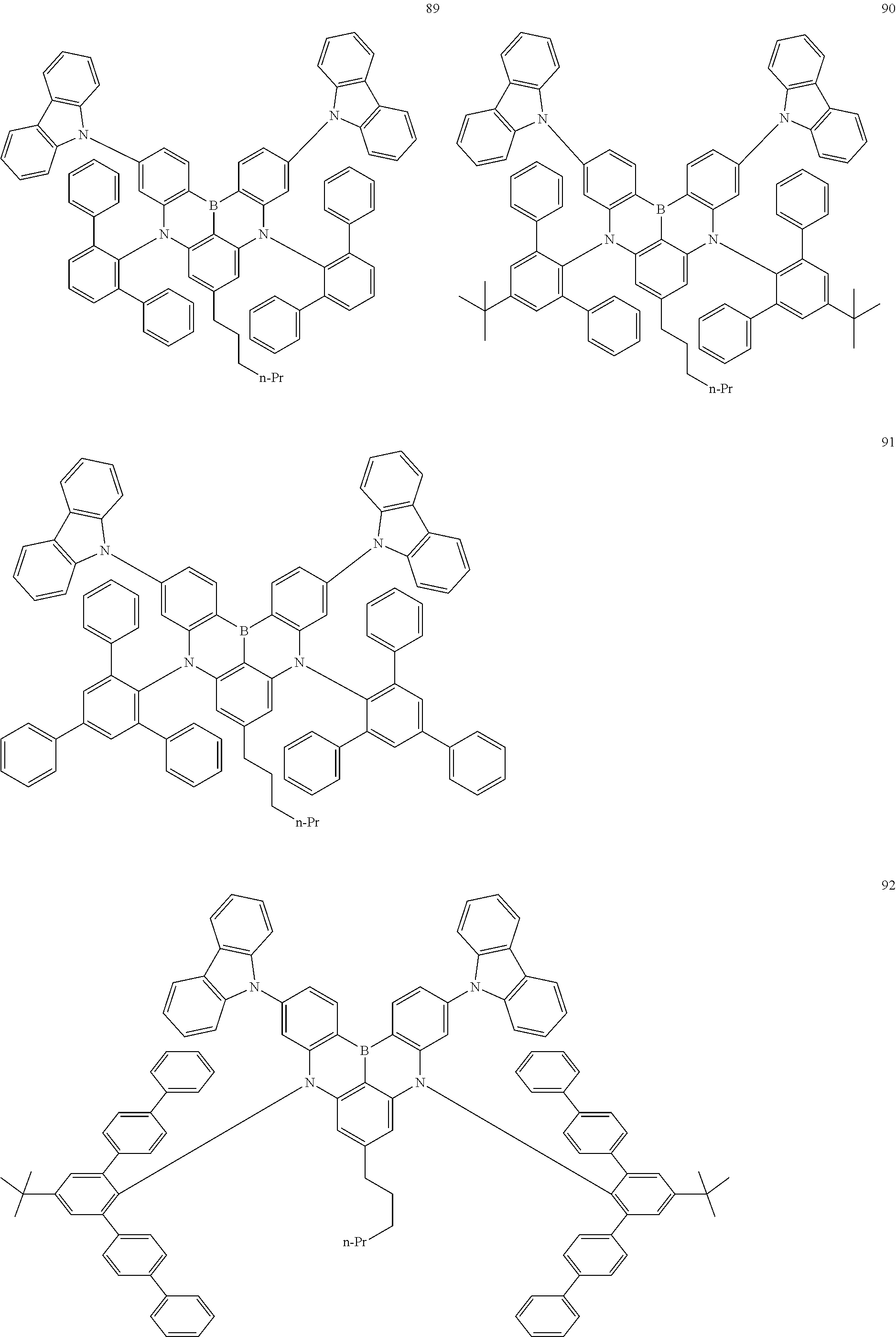 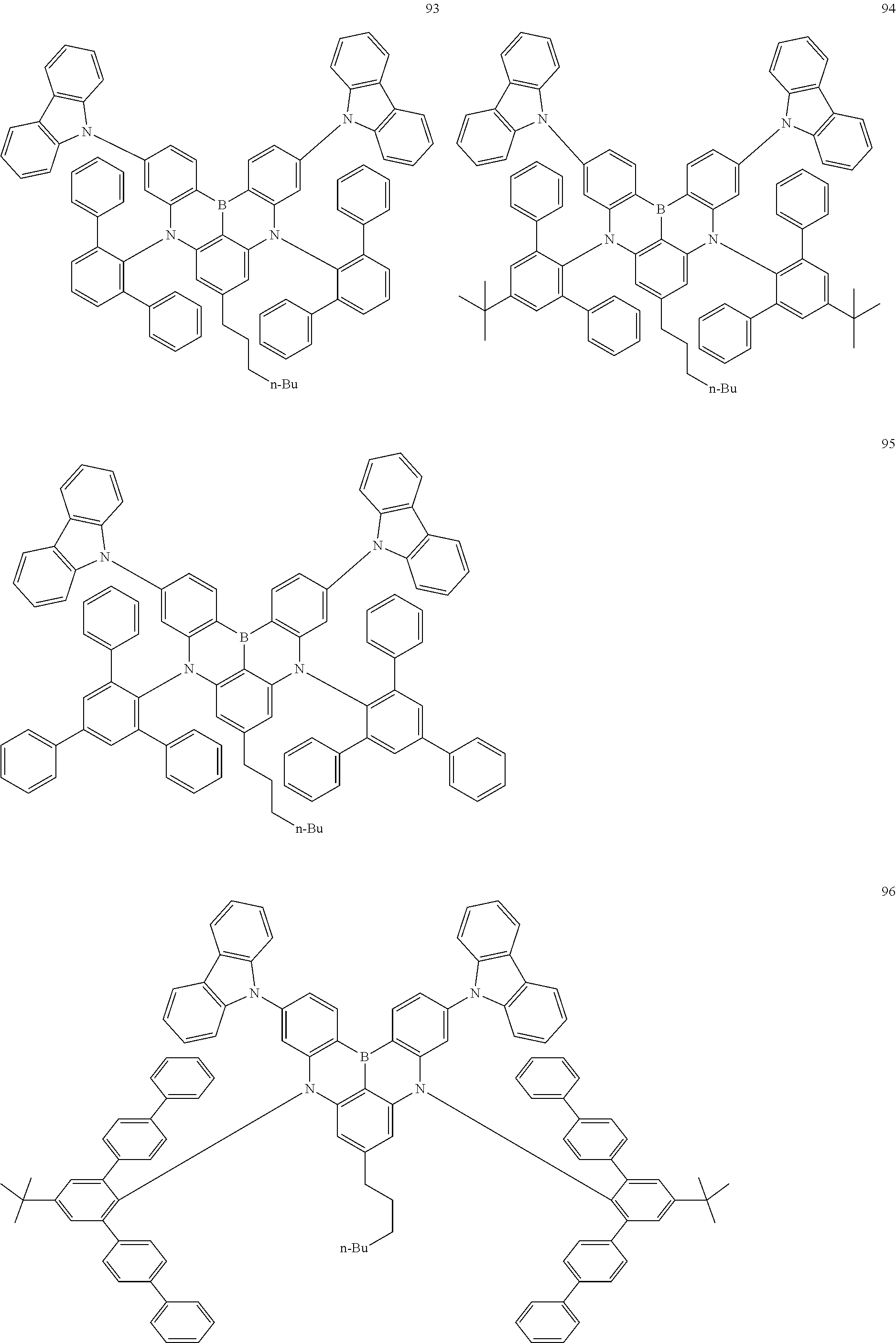 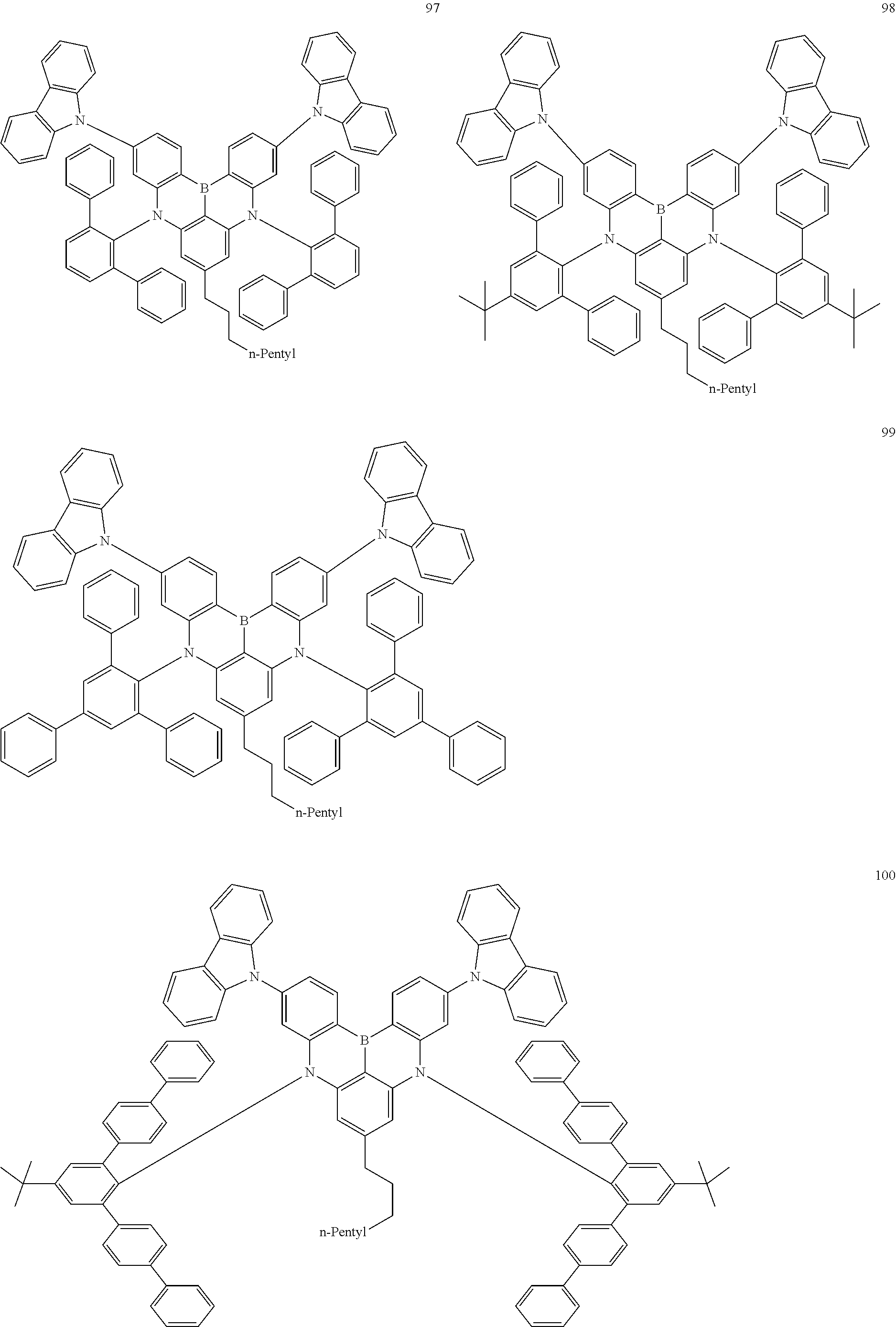 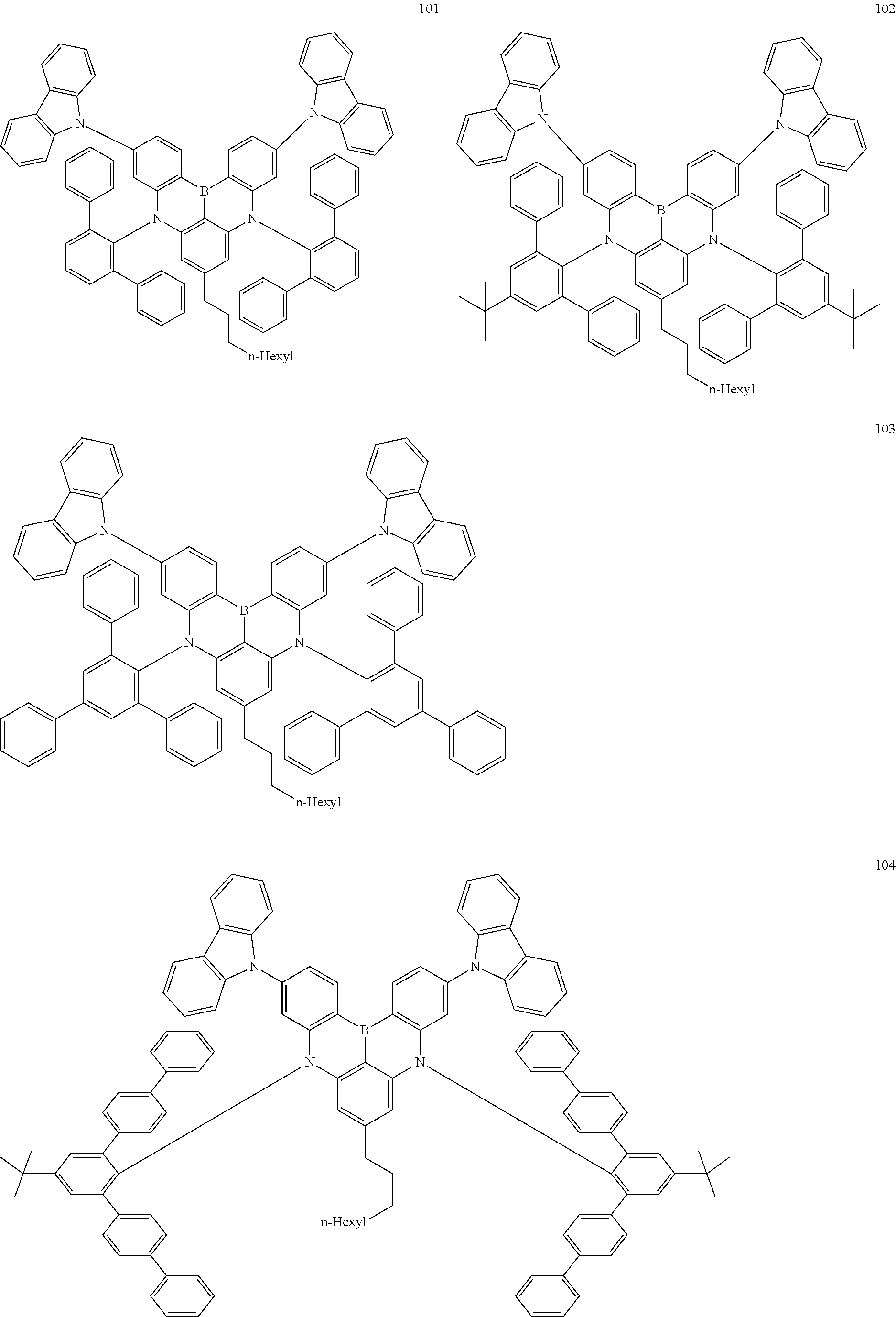 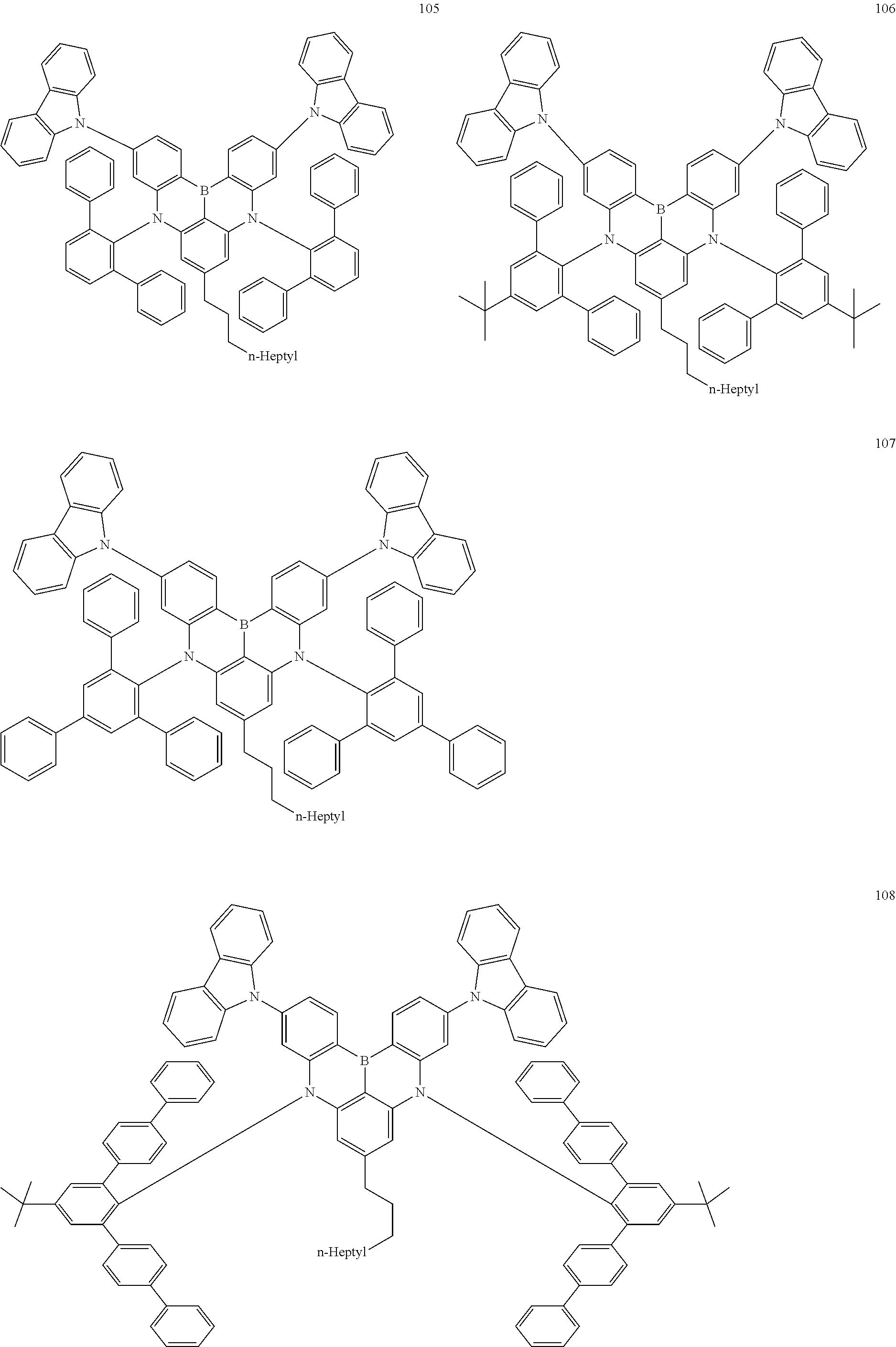 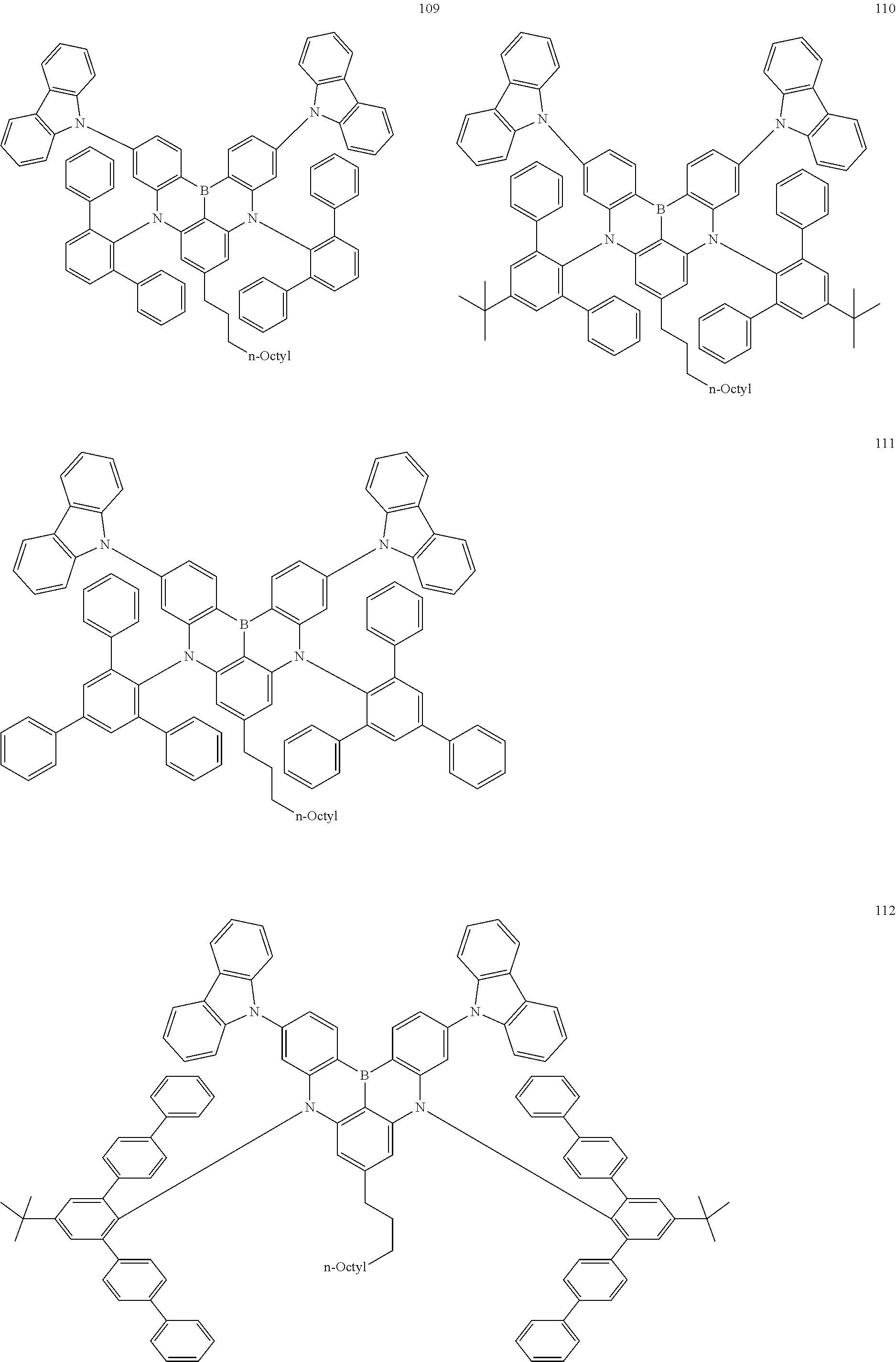 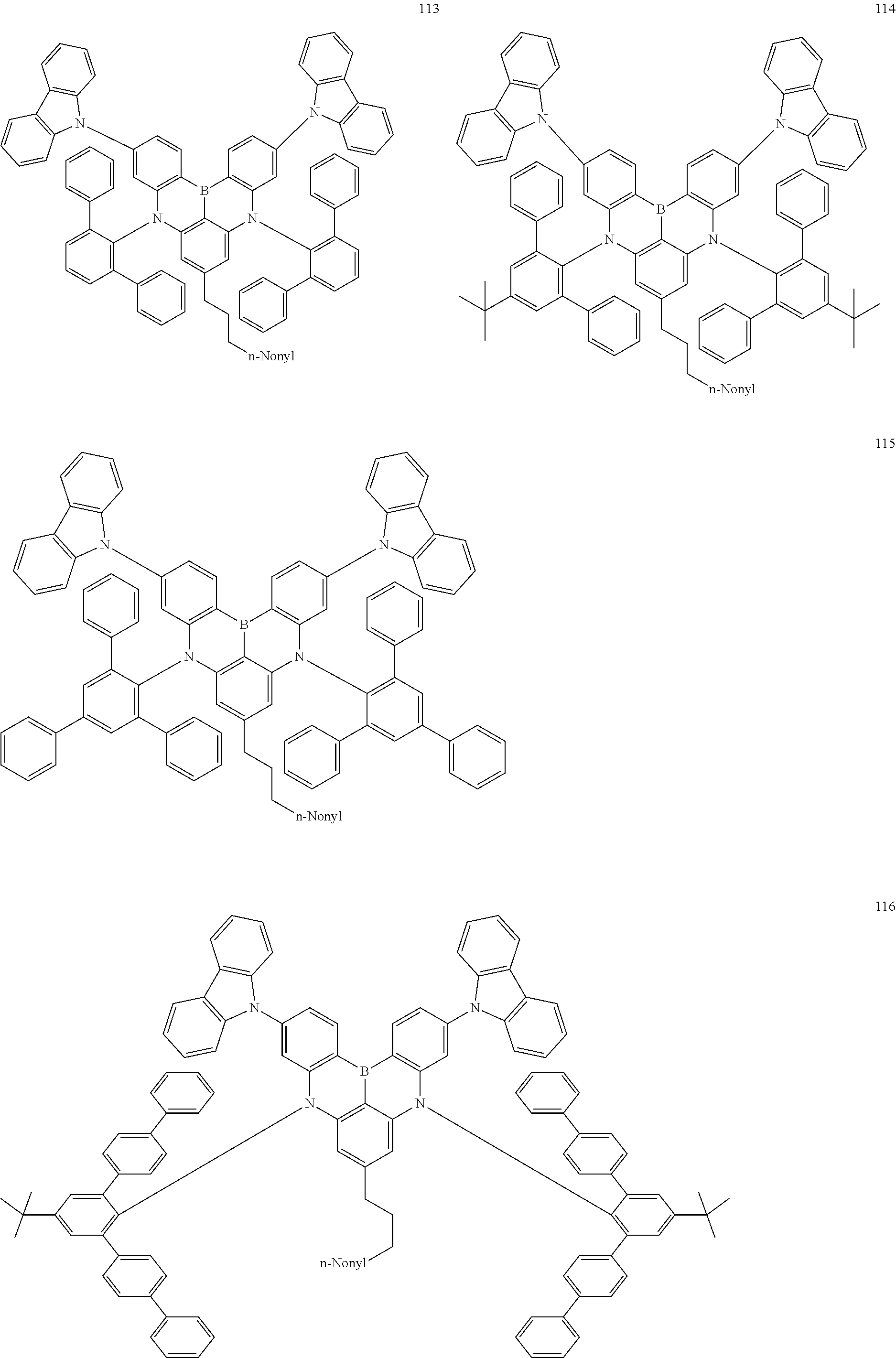 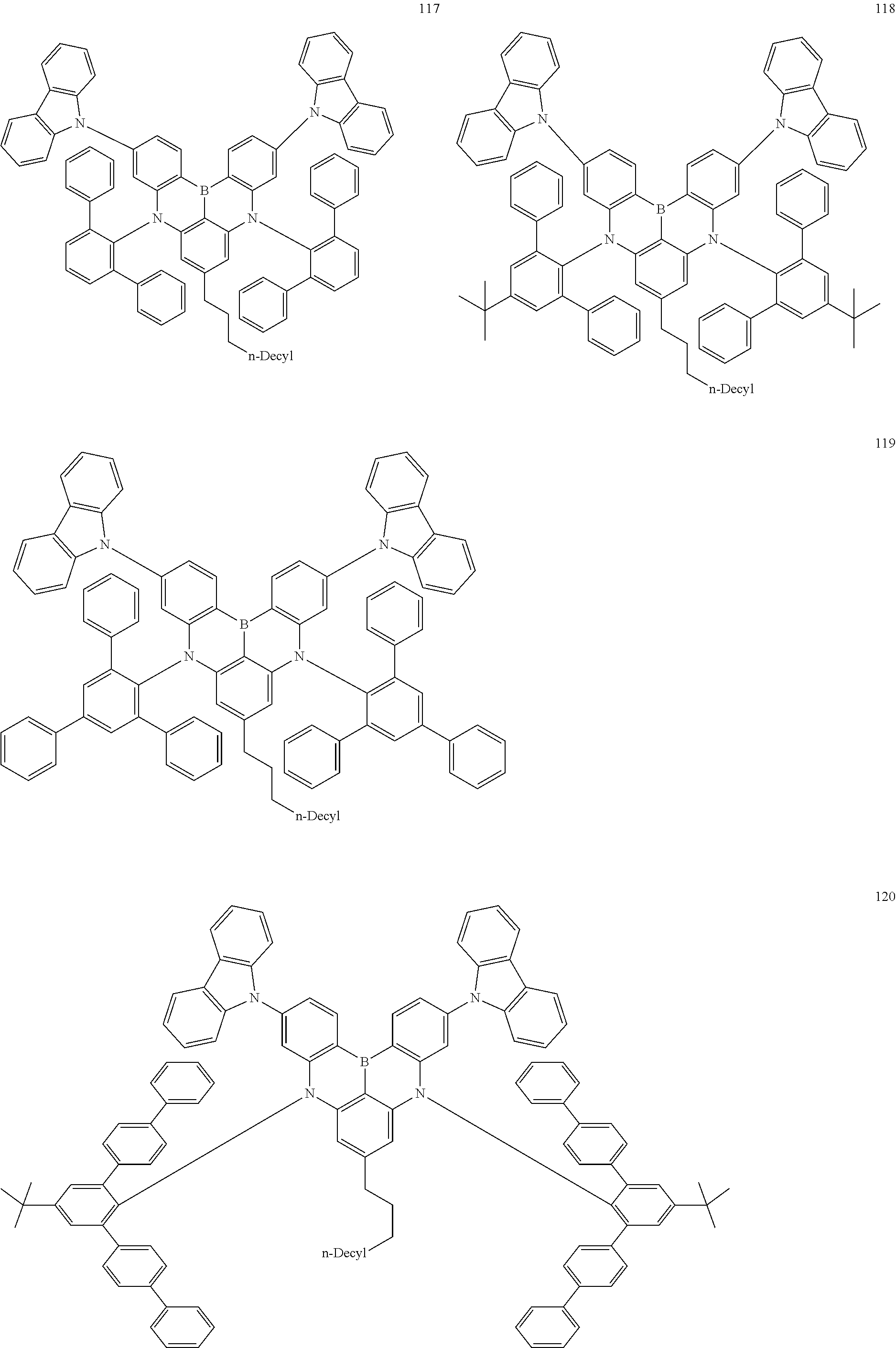 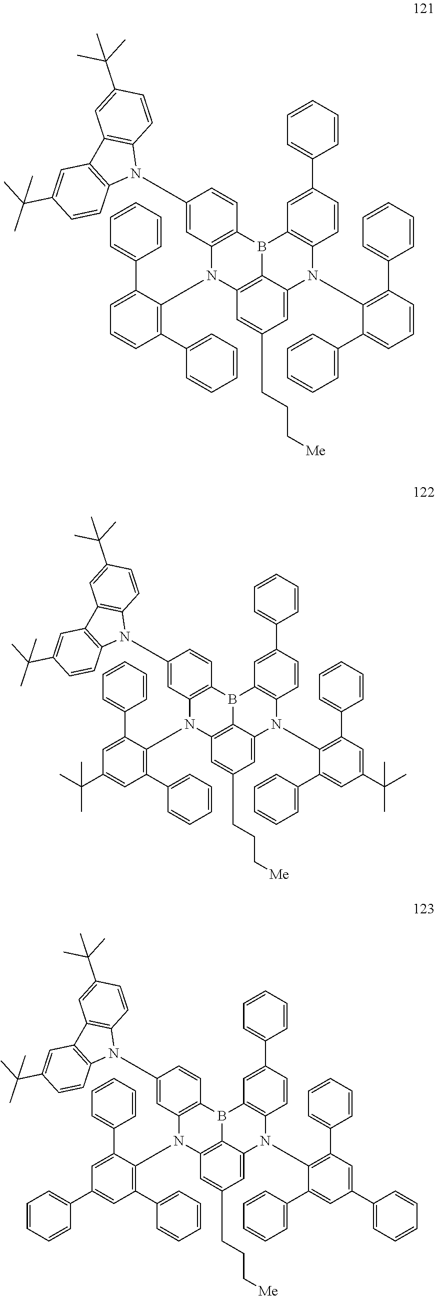 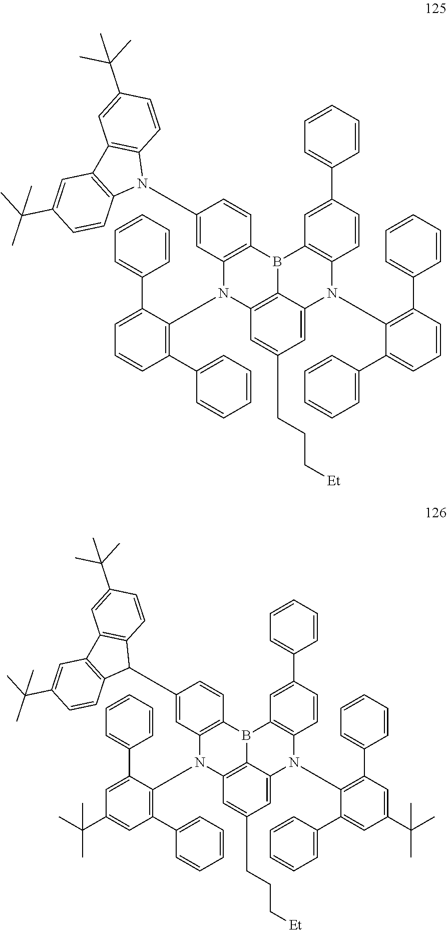 [SMILES: CCCCCCc1cc2c3c(c1)N(Cc1c(-c4ccccc4)cccc1-c1ccccc1)c1cc(Cn4c5ccc(C(C)(C)C)cc5c5cc(C(C)(C)C)ccc54)ccc1B3c1cc(-c3ccccc3)ccc1N2Cc1c(-c2ccccc2)cccc1-c1ccccc1 ; CCCCCCc1cc2c3c(c1)N(Cc1c(-c4ccccc4)cc(C(C)(C)C)cc1-c1ccccc1)c1cc(CC4c5ccc(C(C)(C)C)cc5-c5cc(C(C)(C)C)ccc54)ccc1B3c1cc(-c3ccccc3)ccc1N2Cc1c(-c2ccccc2)cc(C(C)(C)C)cc1-c1ccccc1] 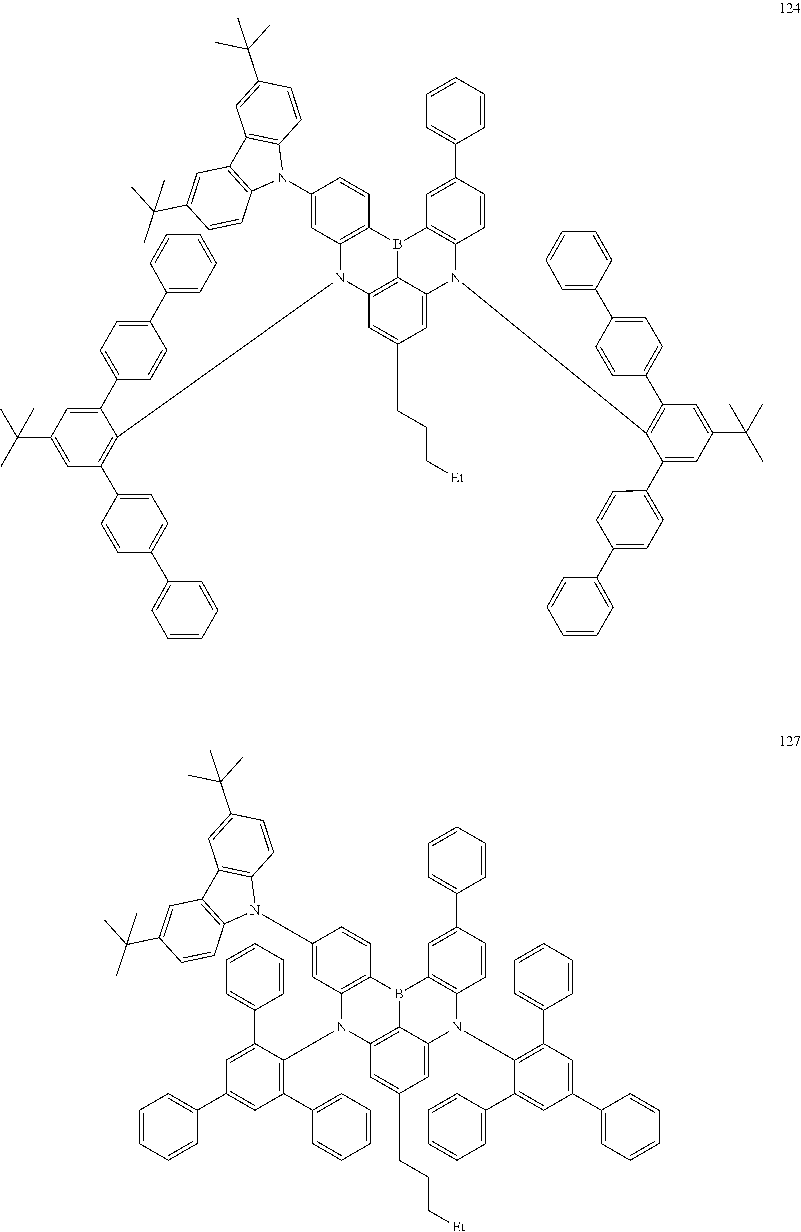 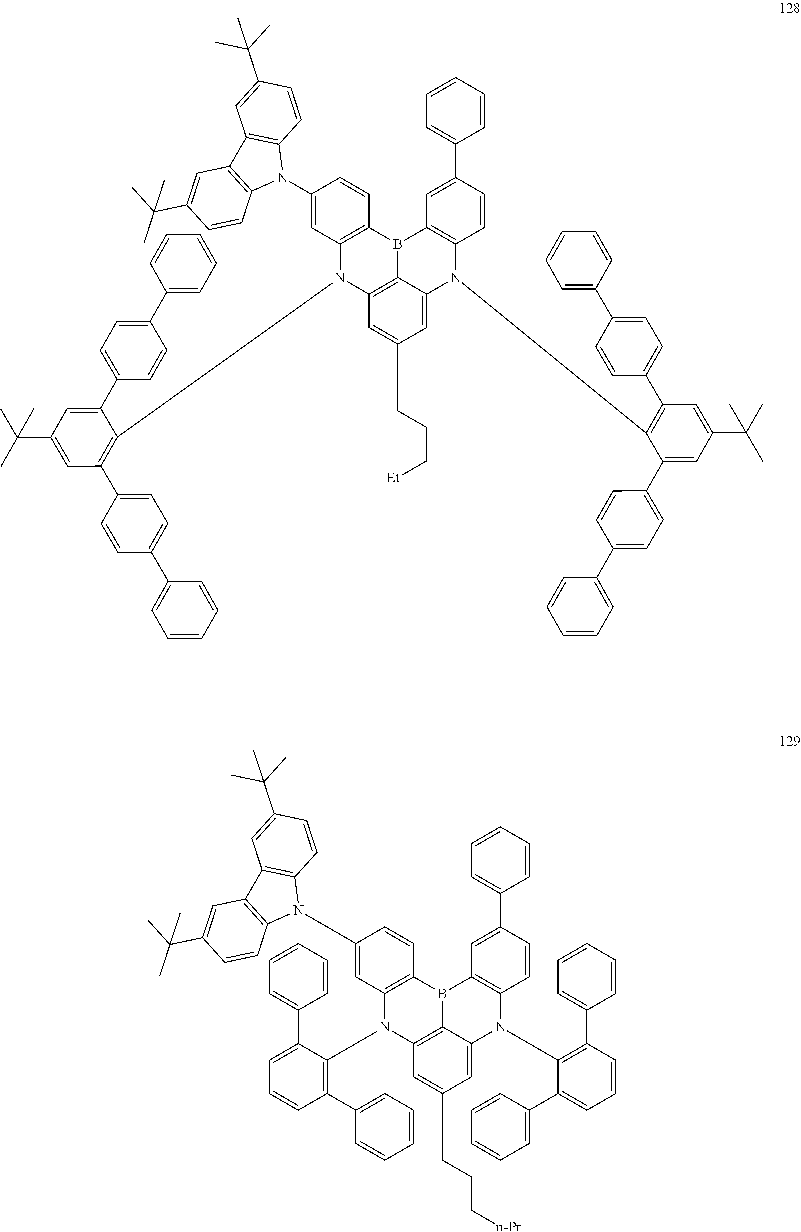 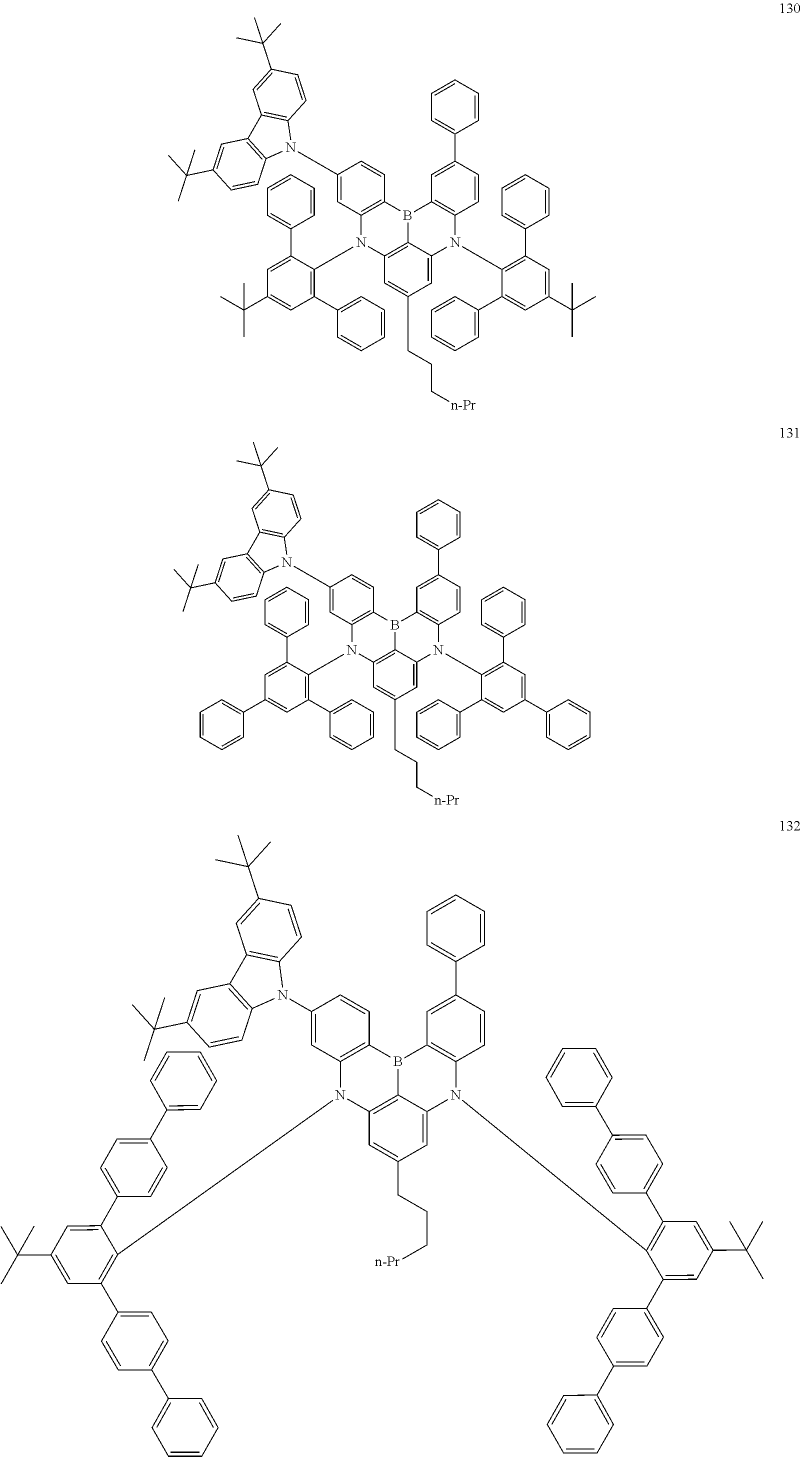 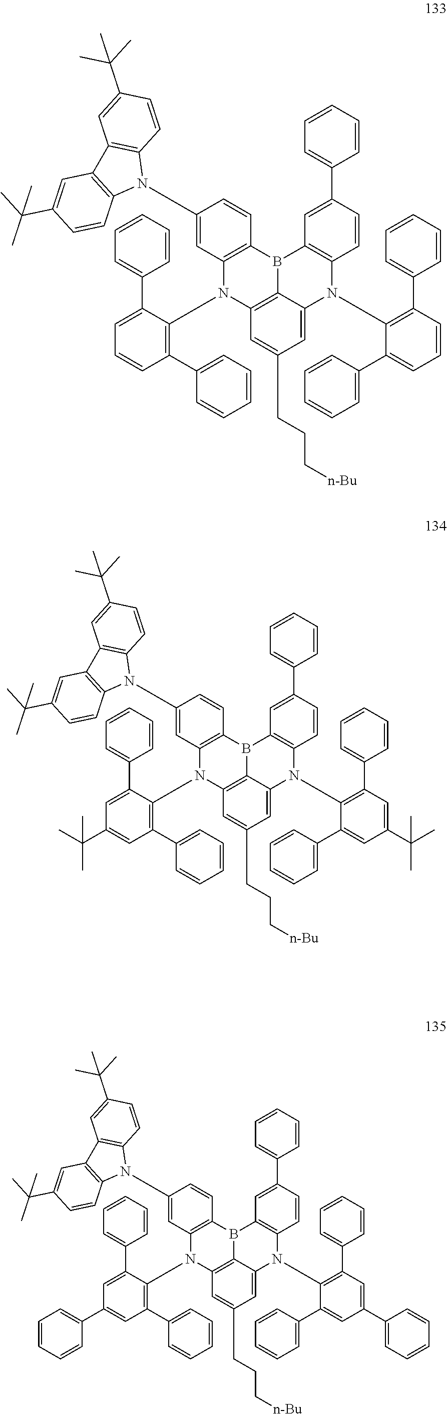 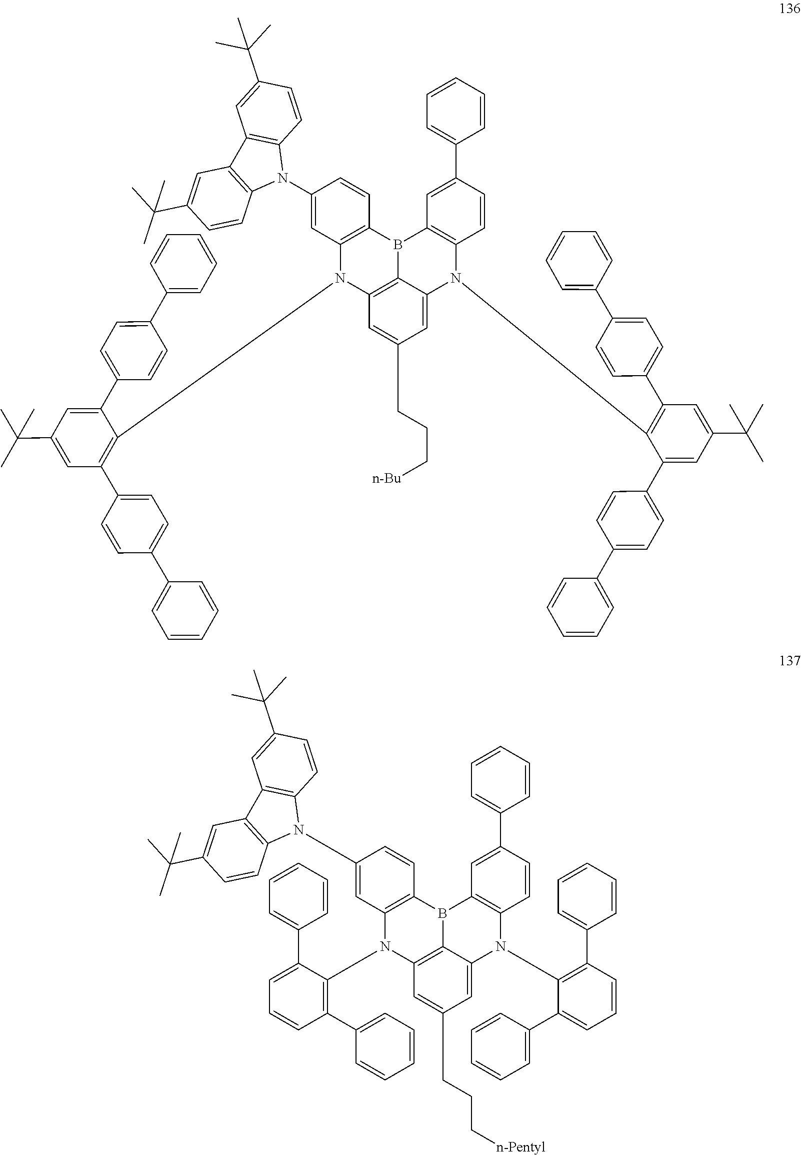 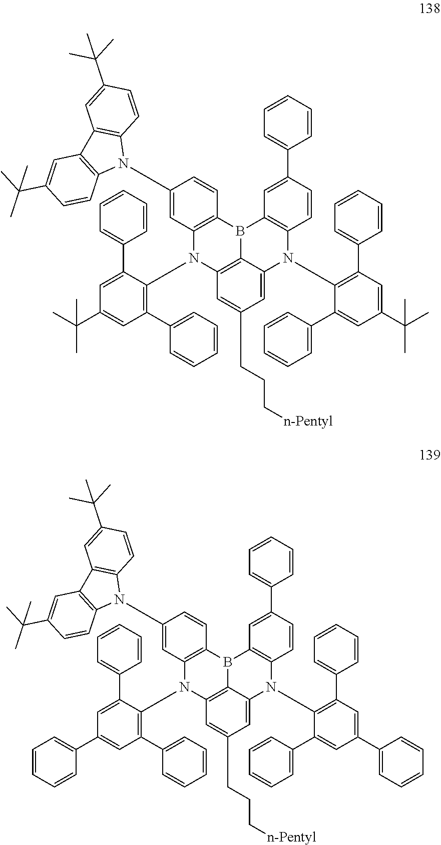 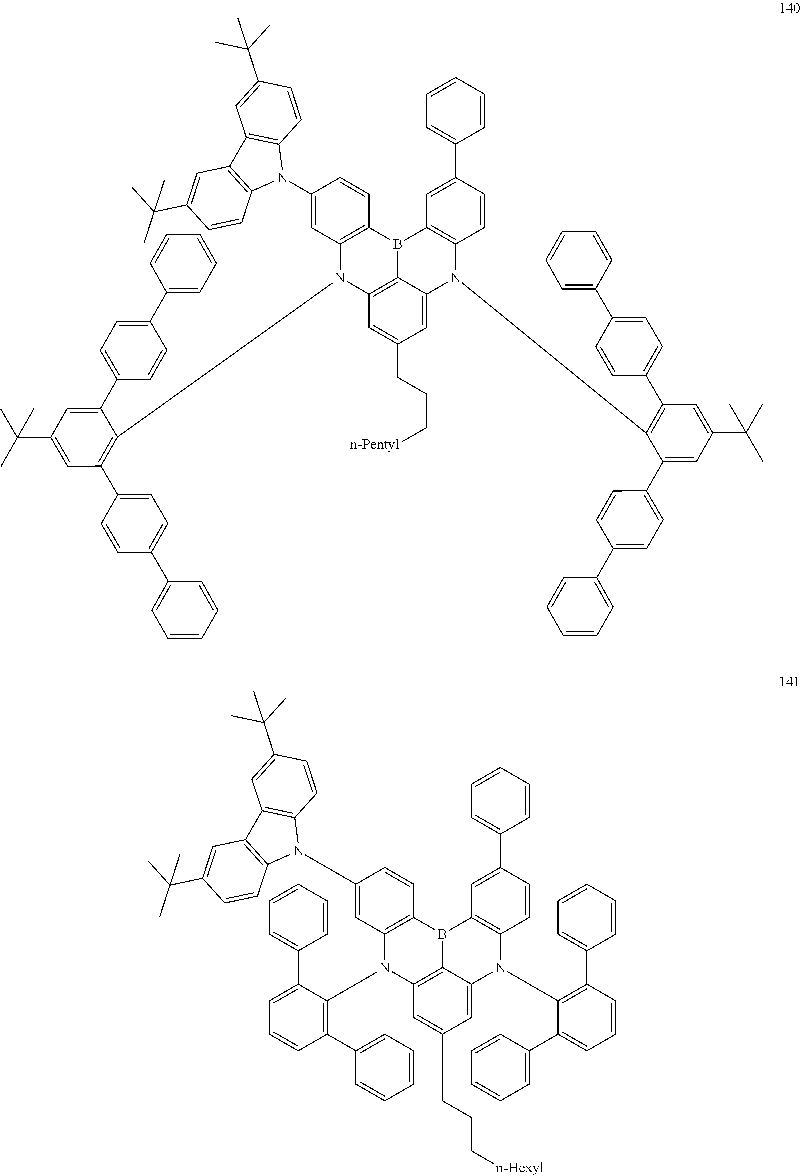 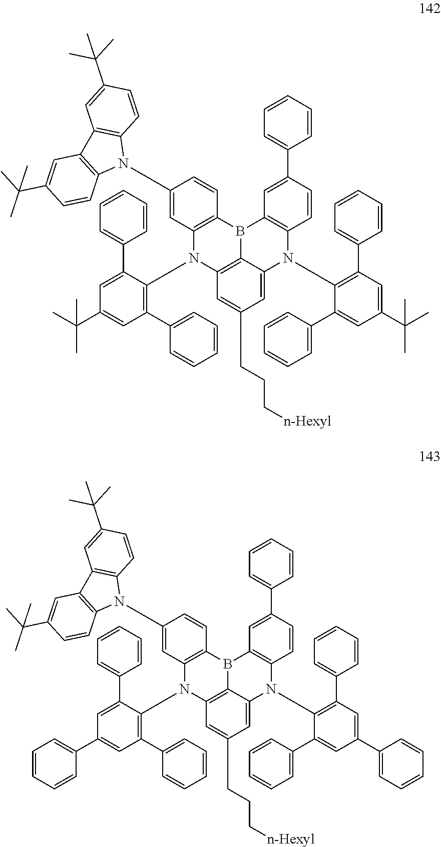 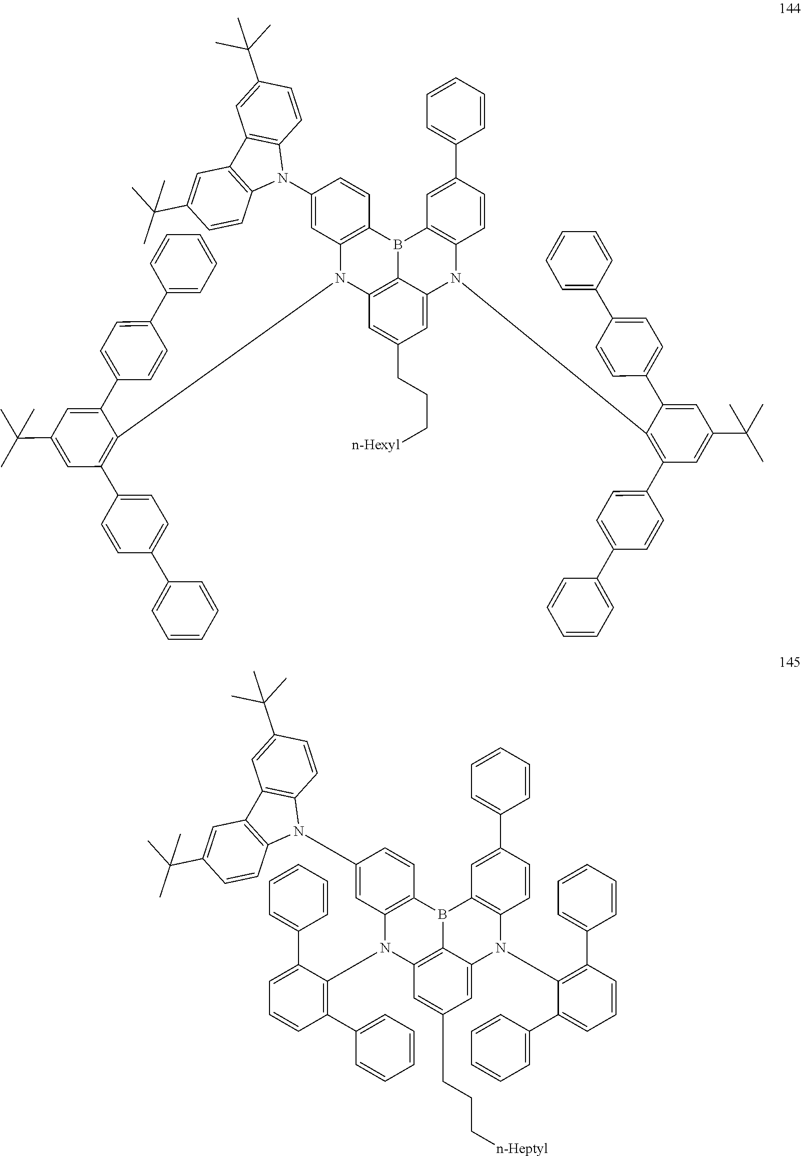 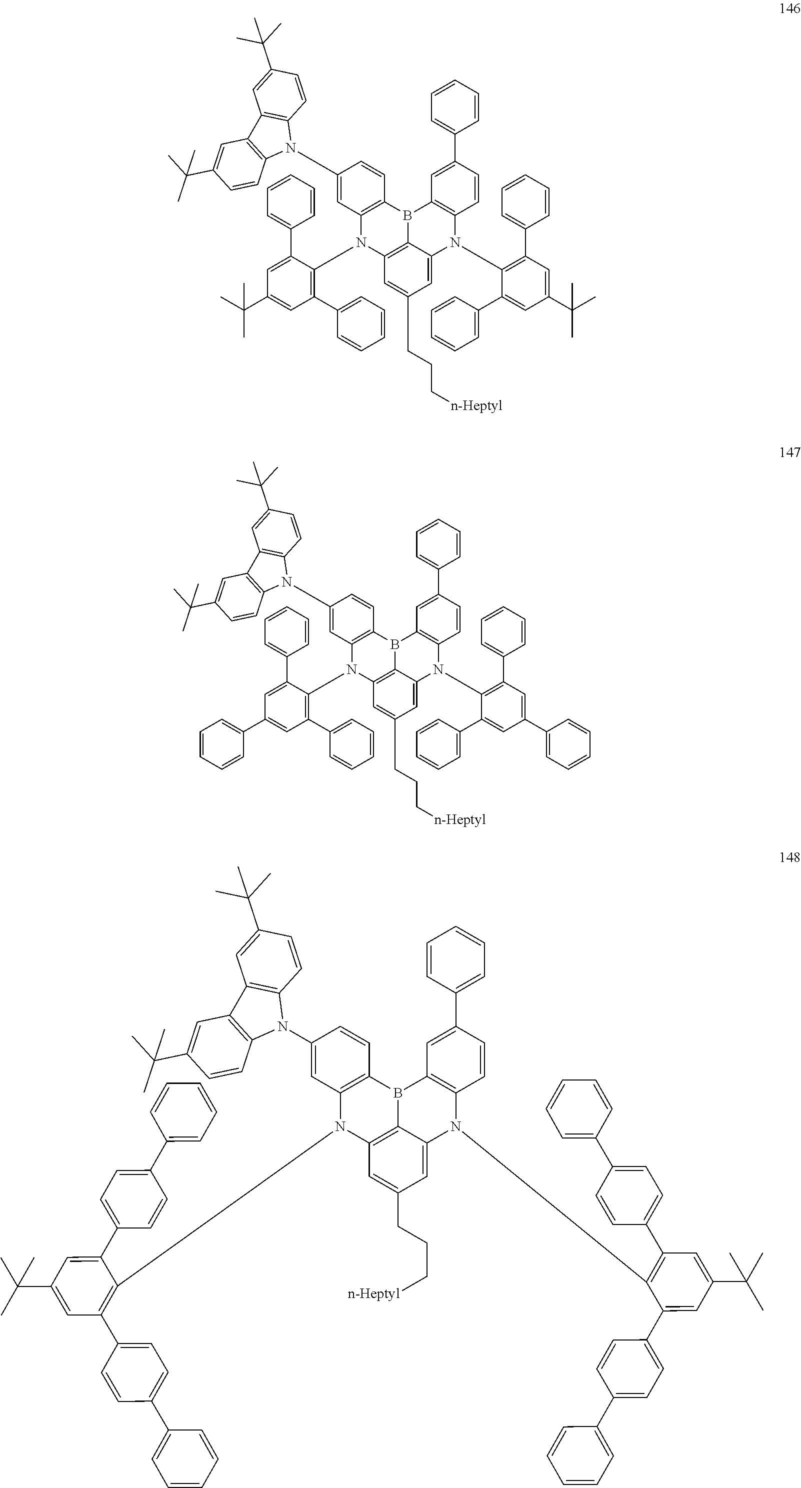 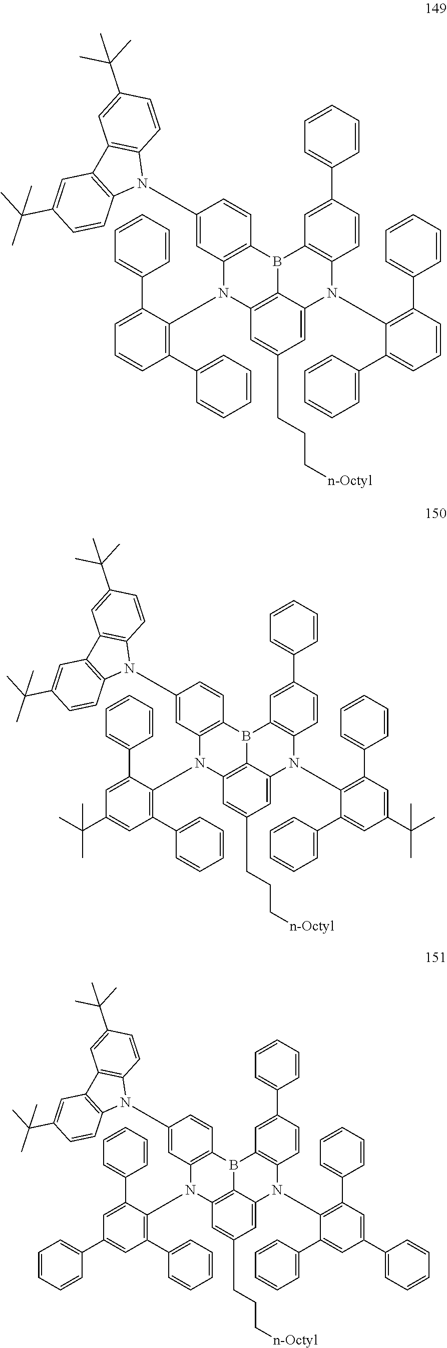 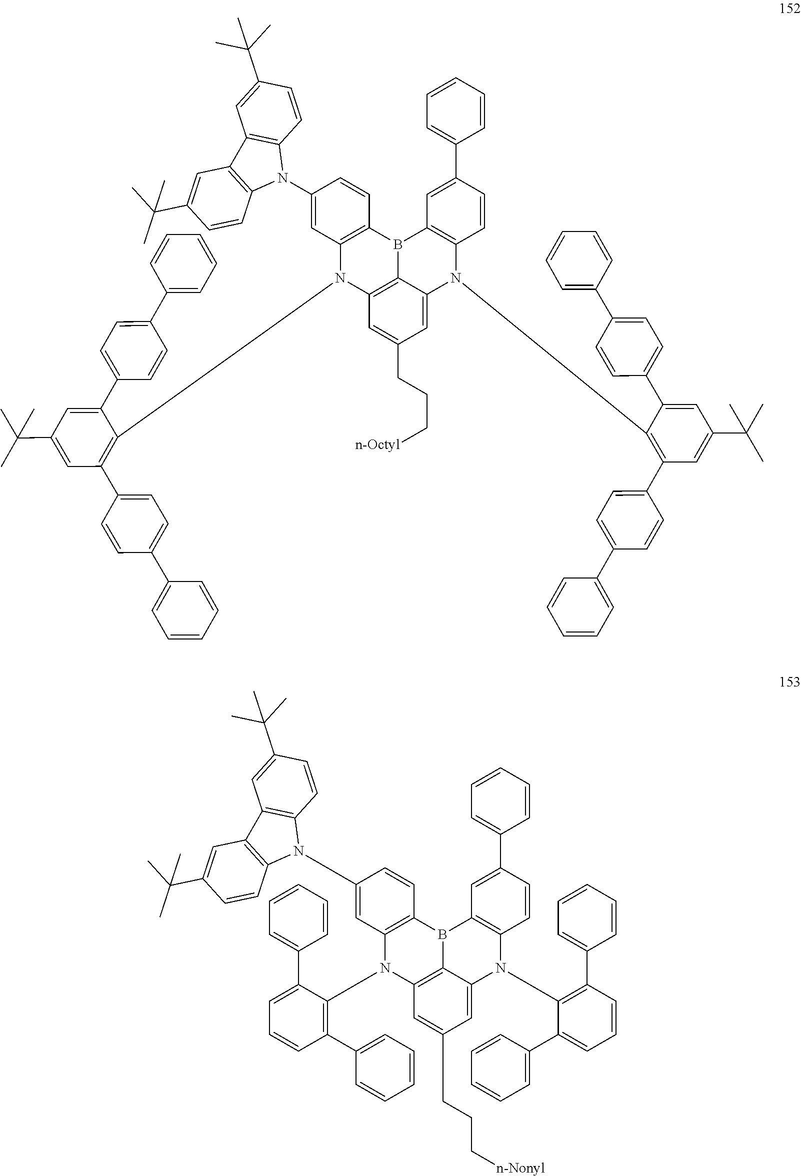 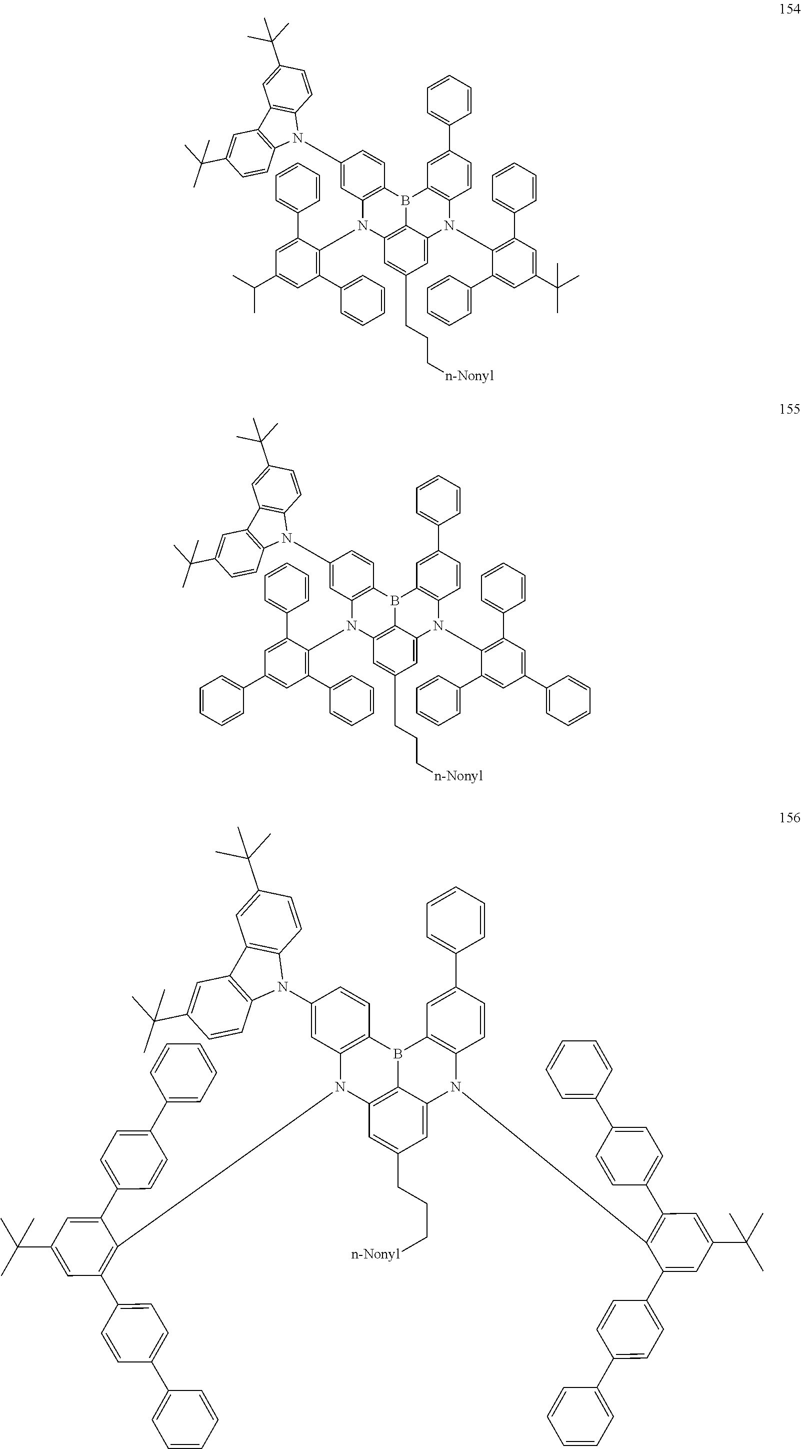 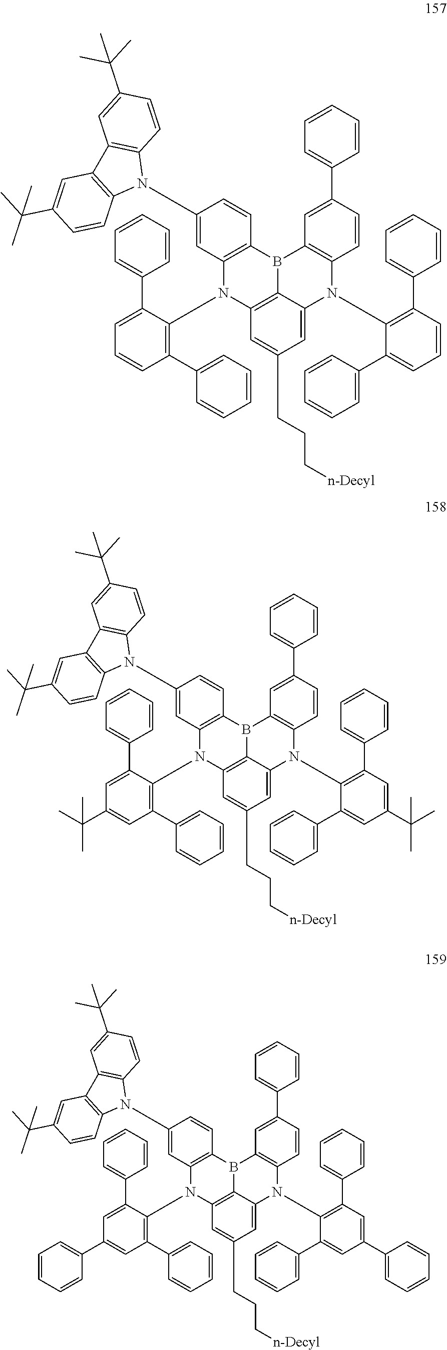 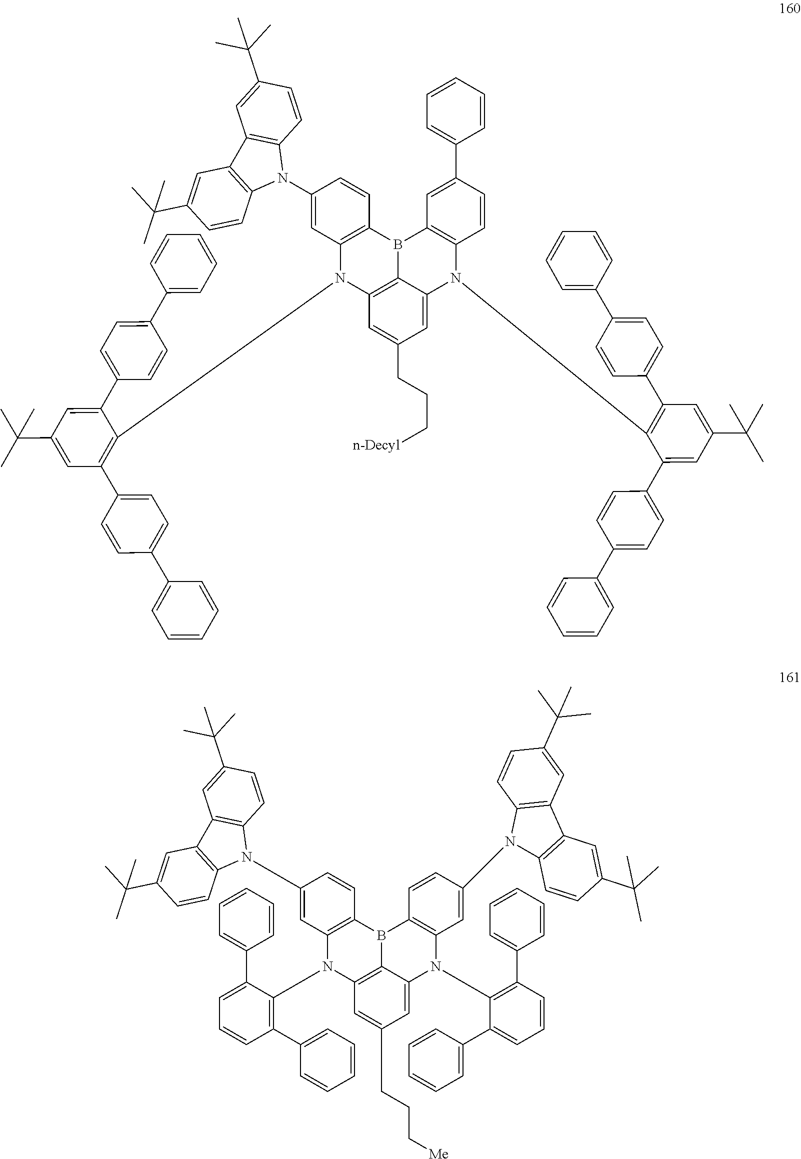 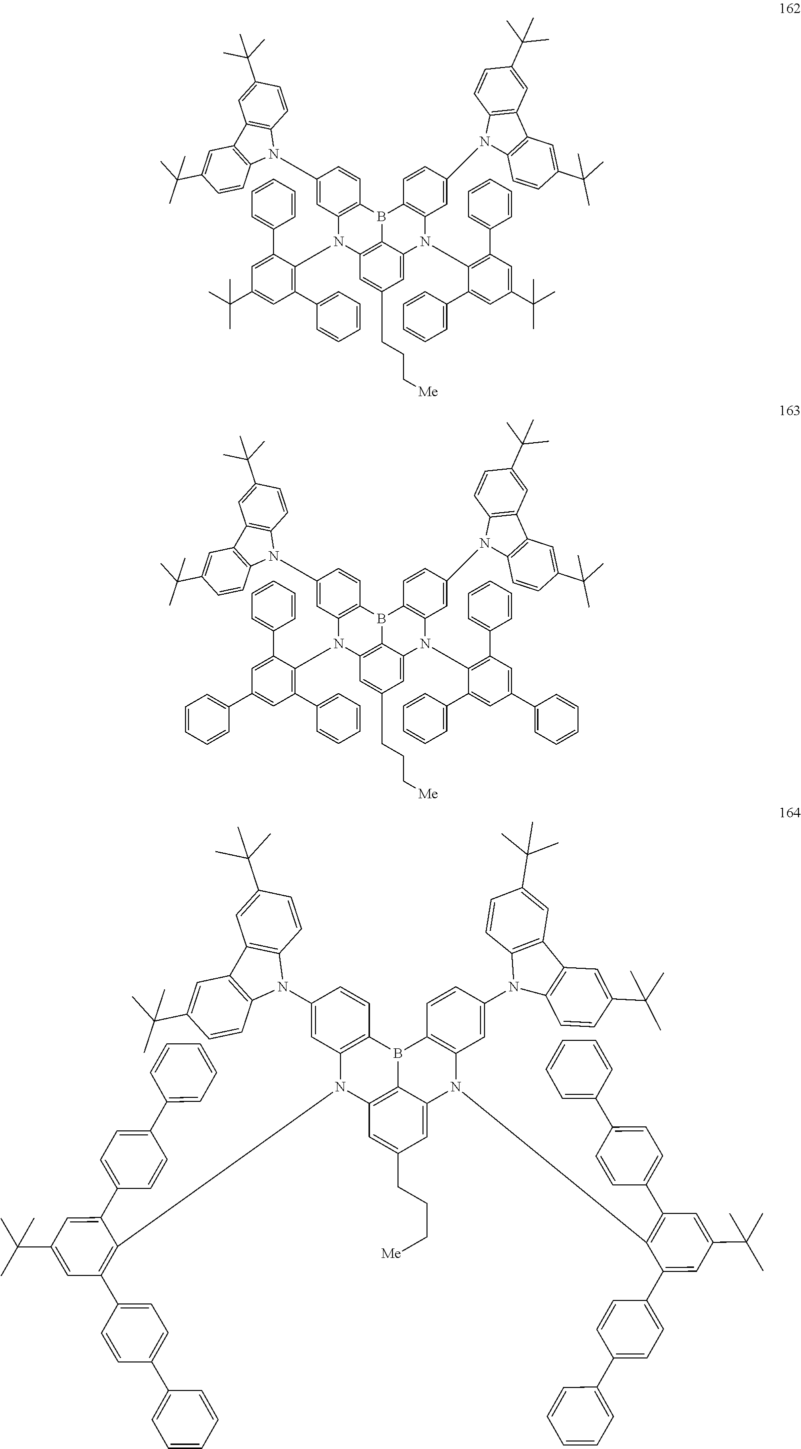 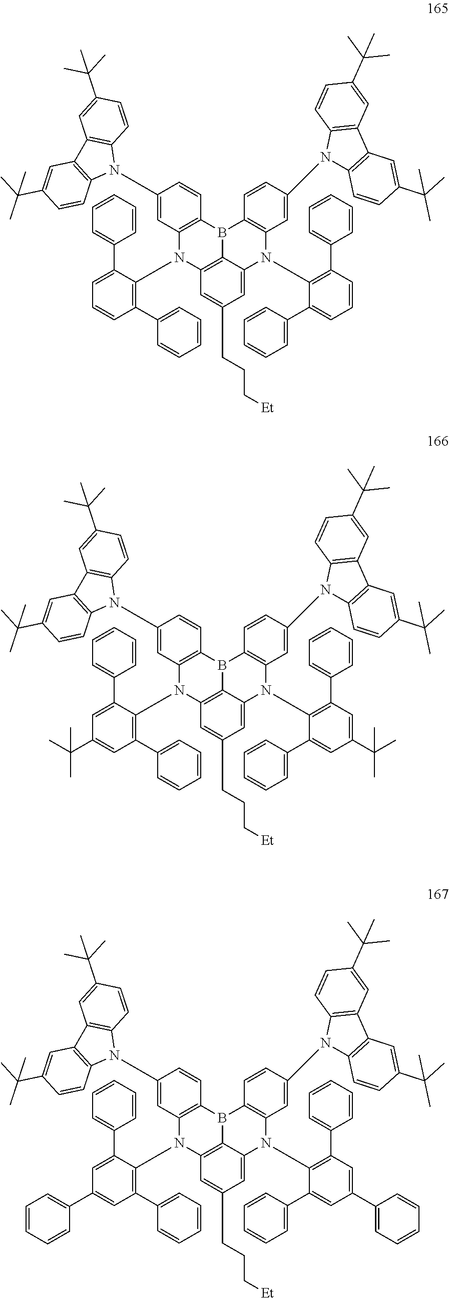 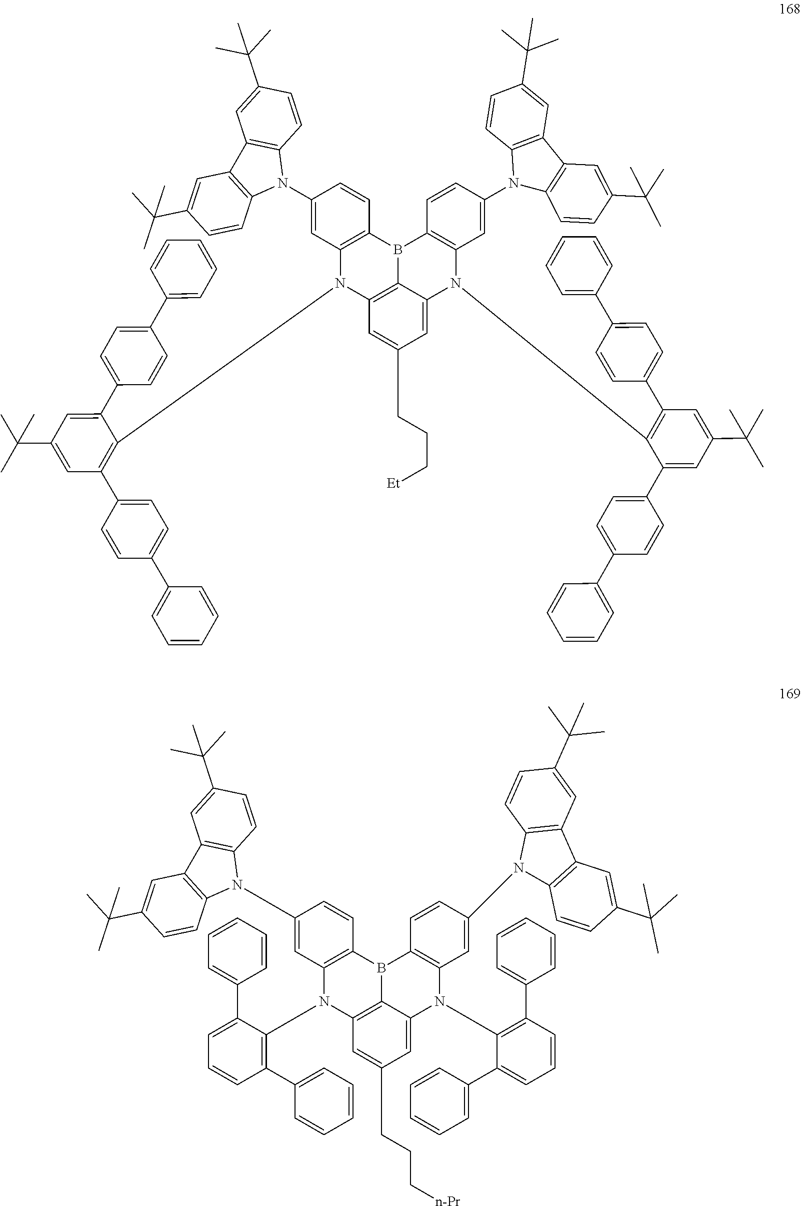 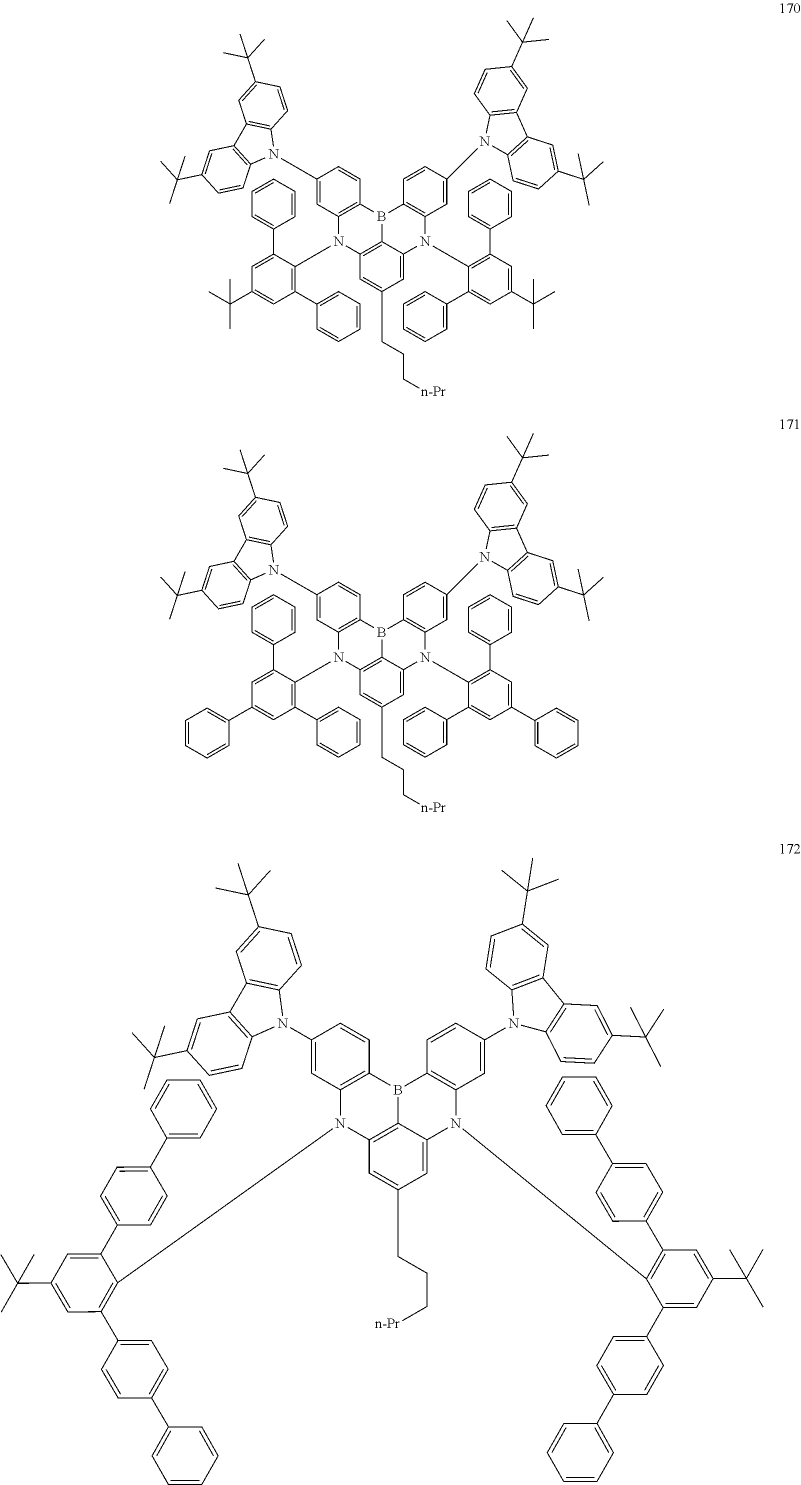 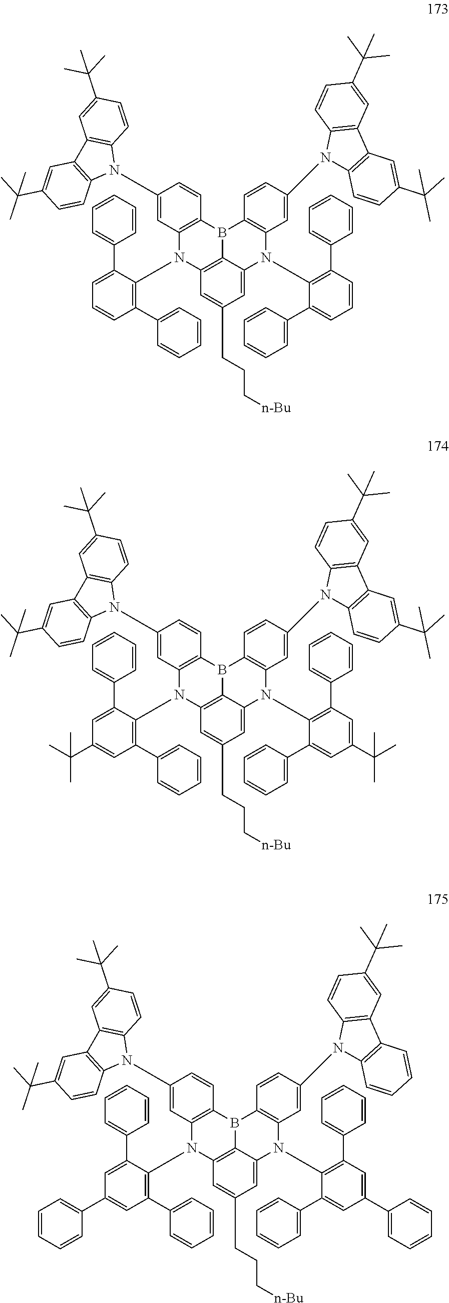 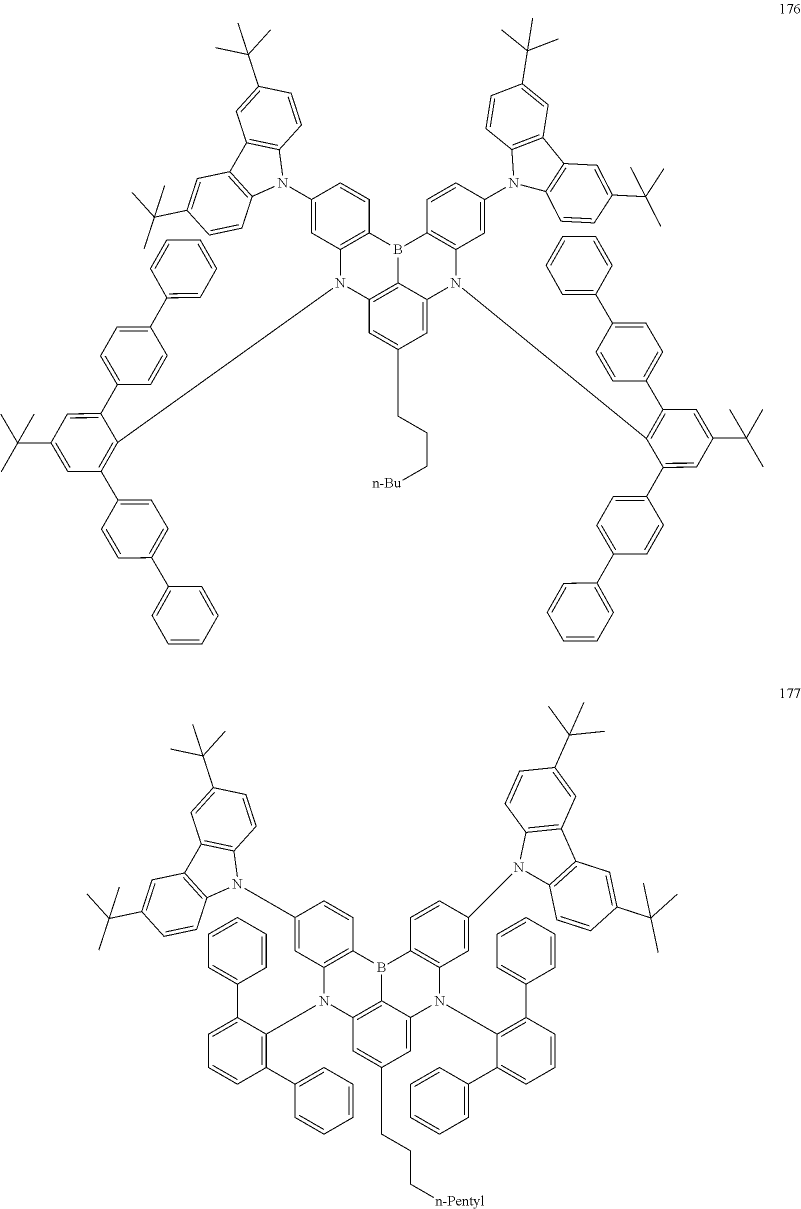 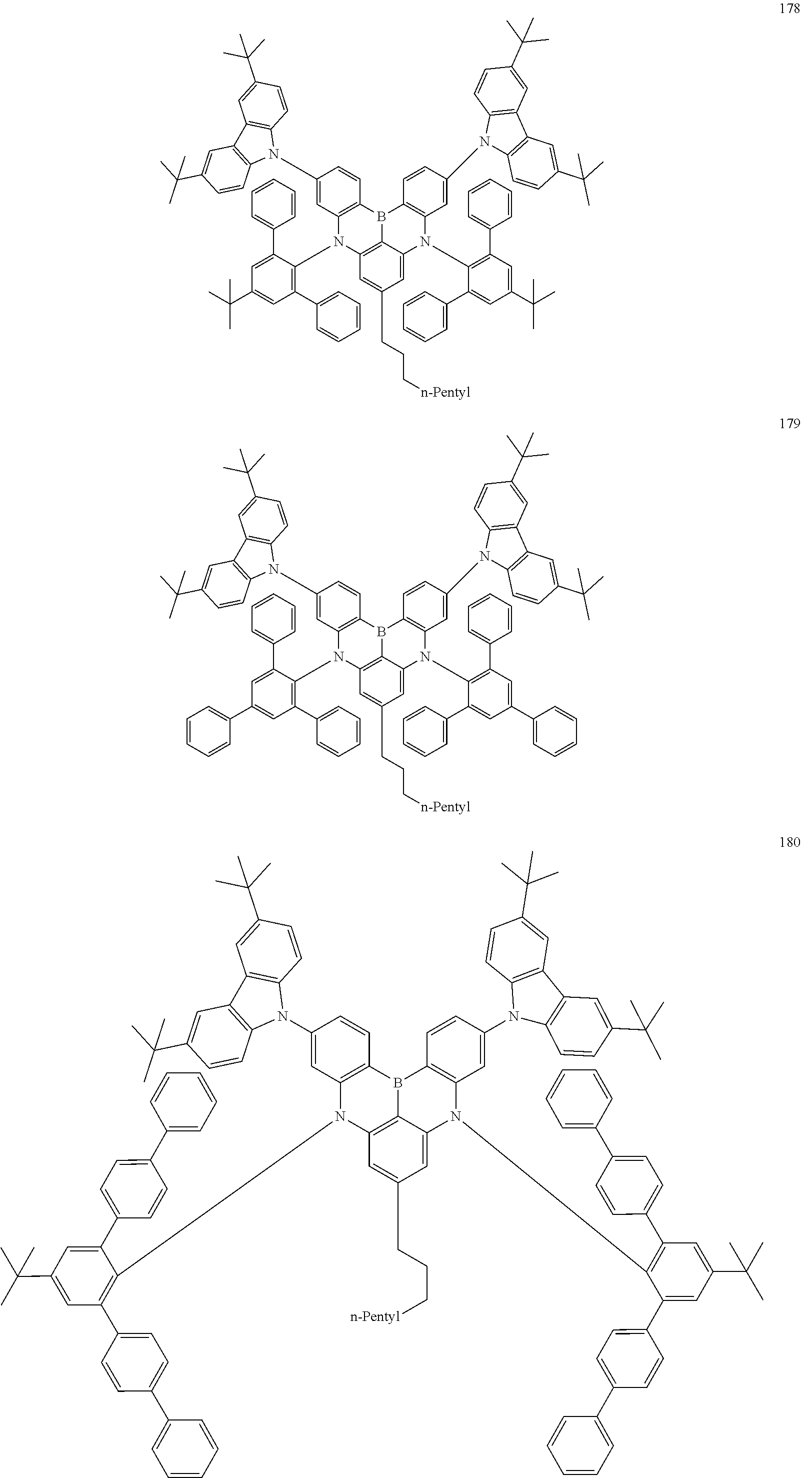 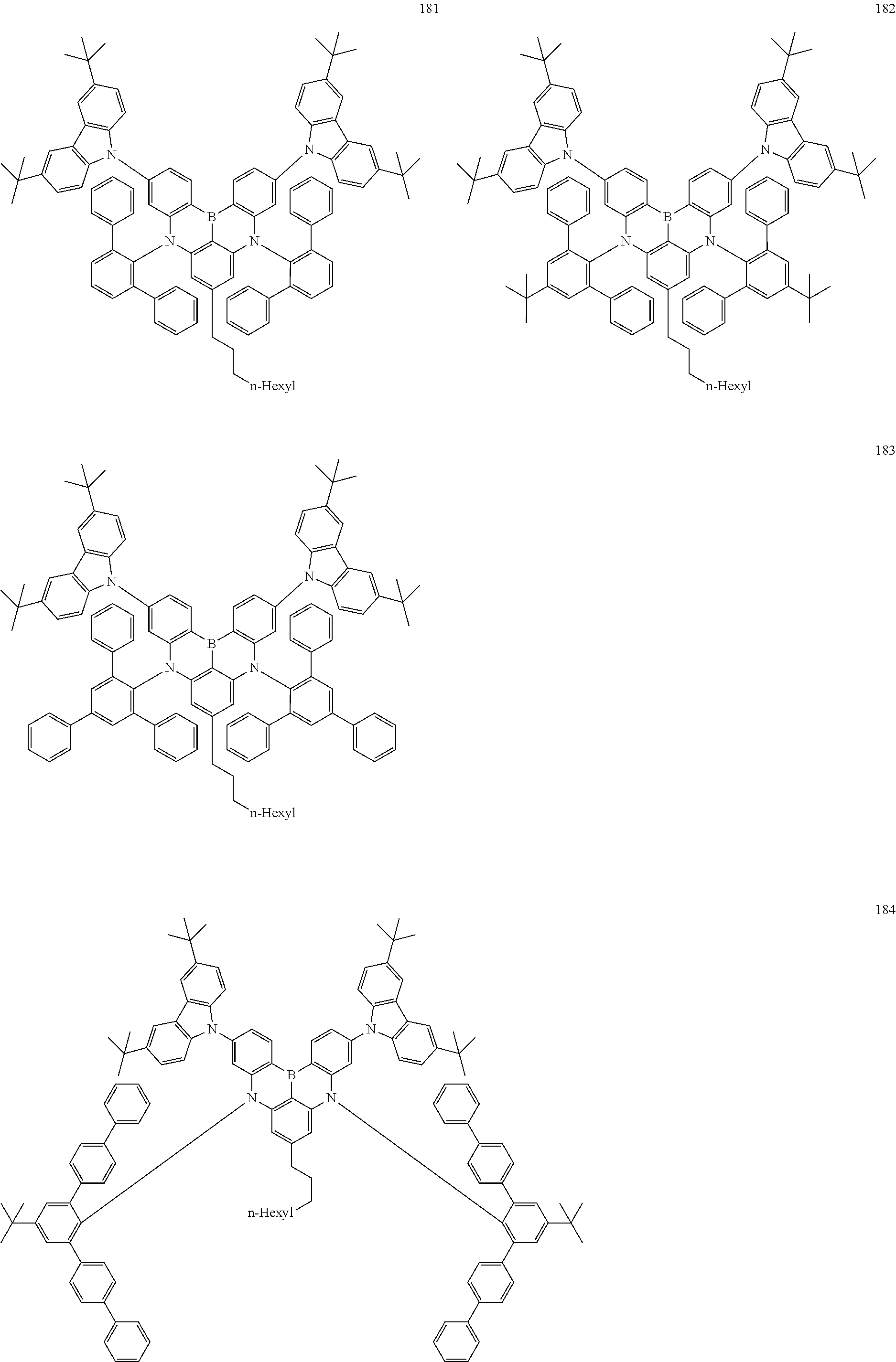 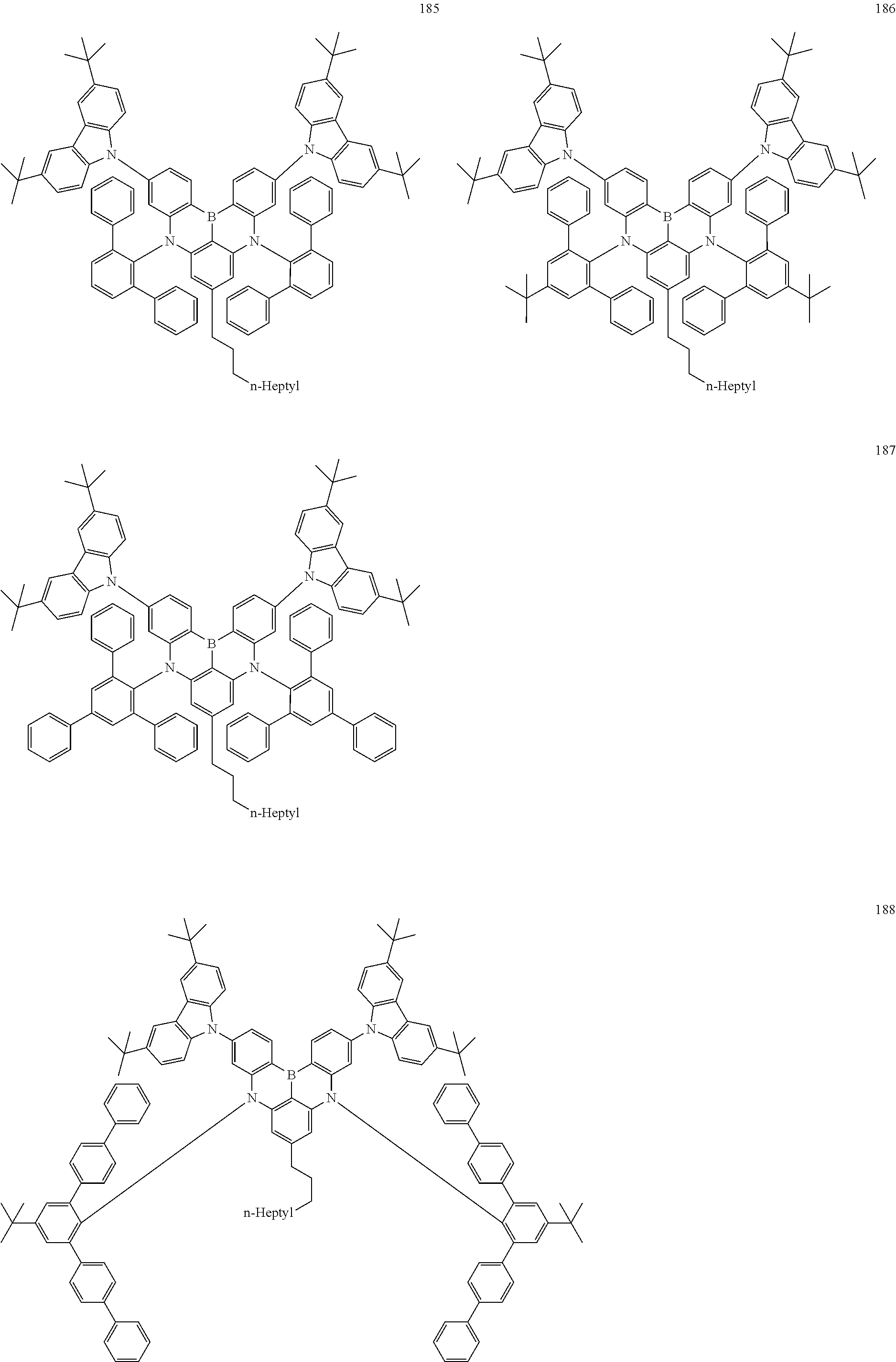 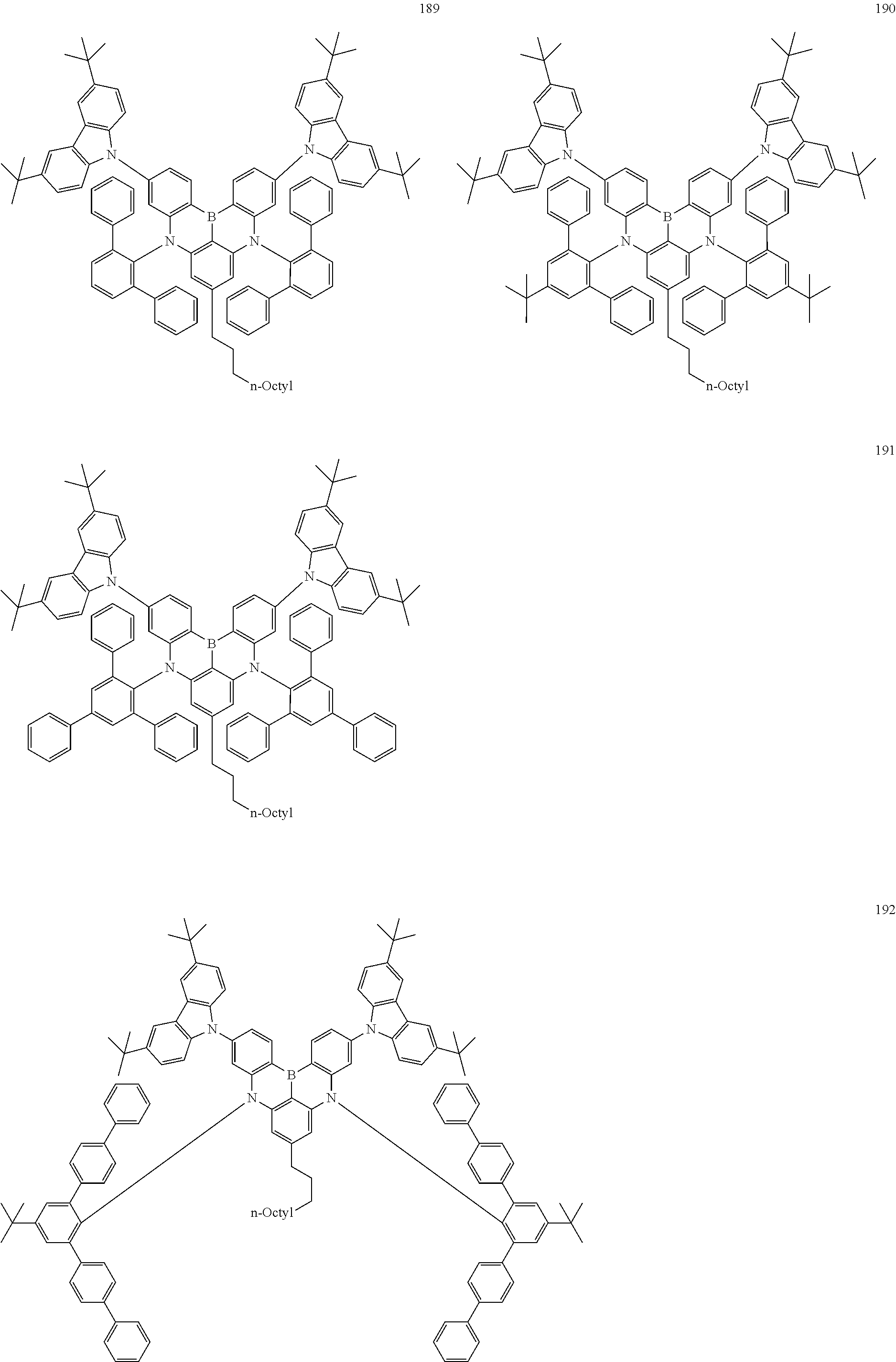 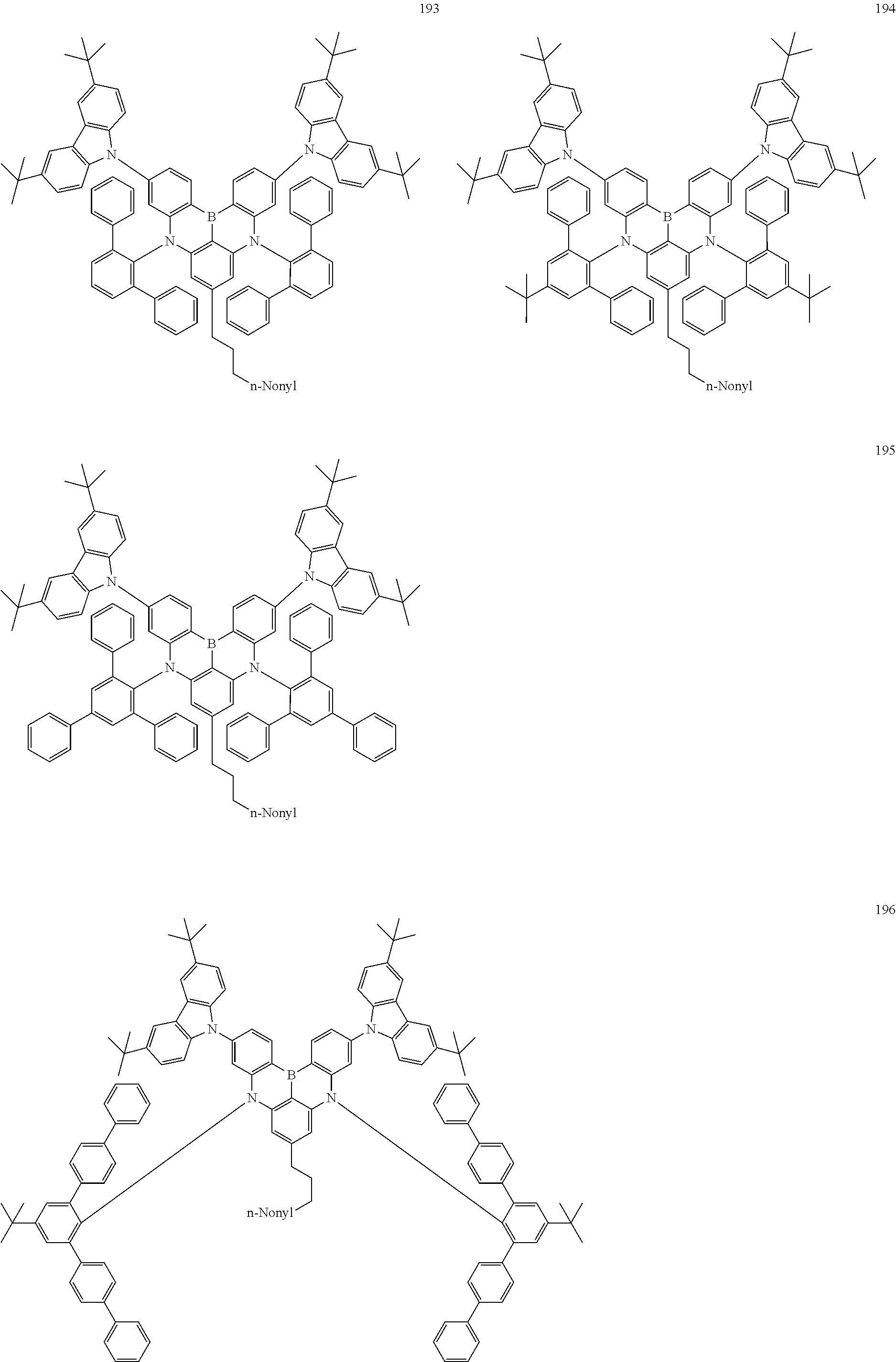 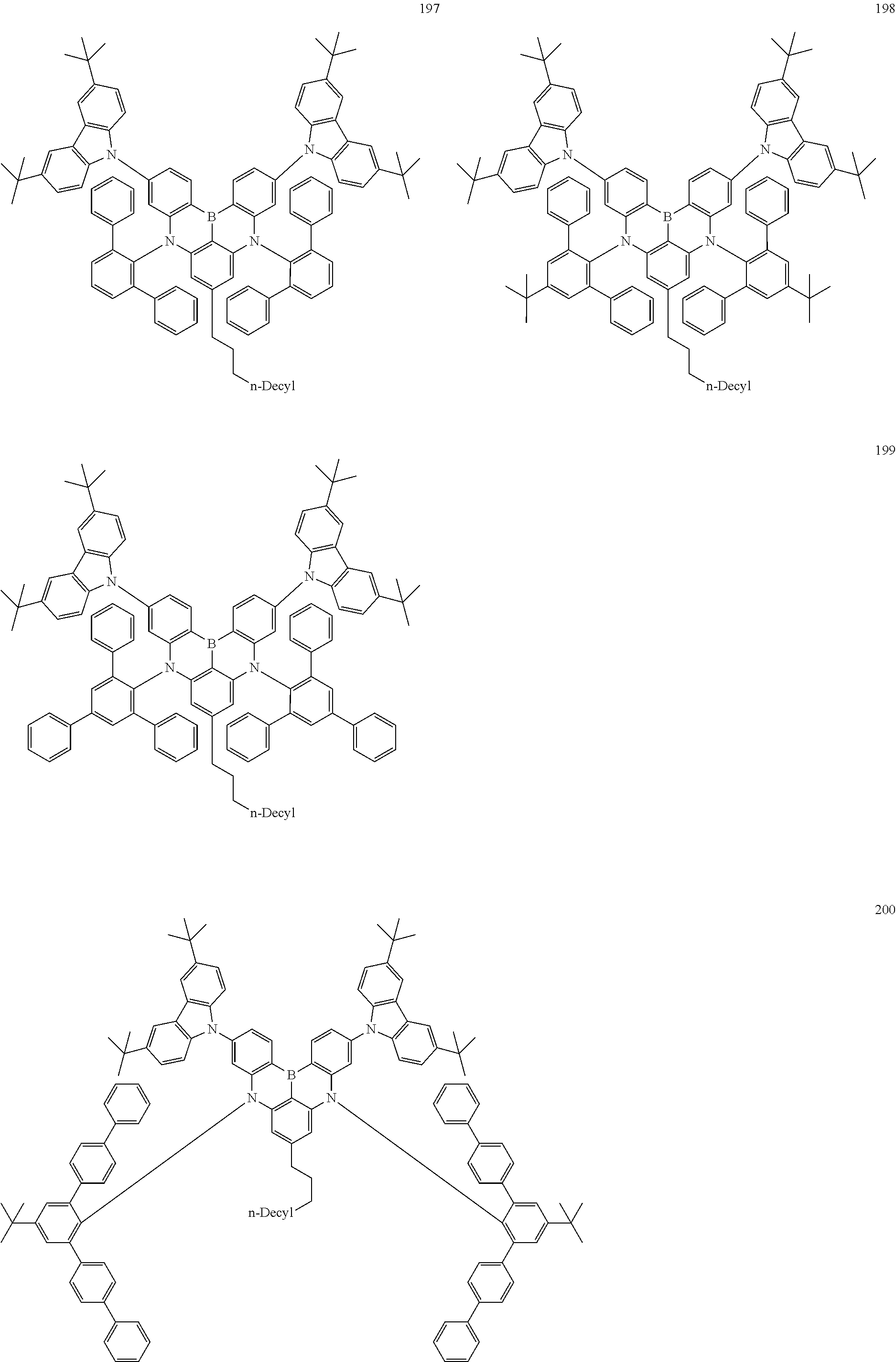 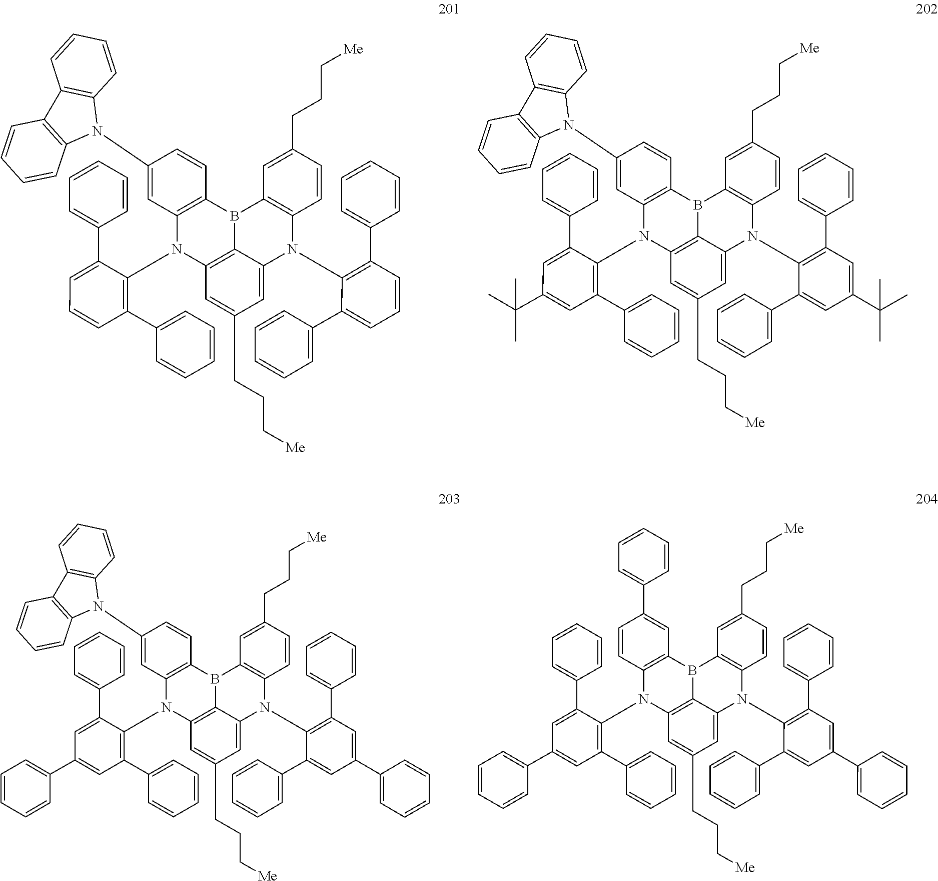 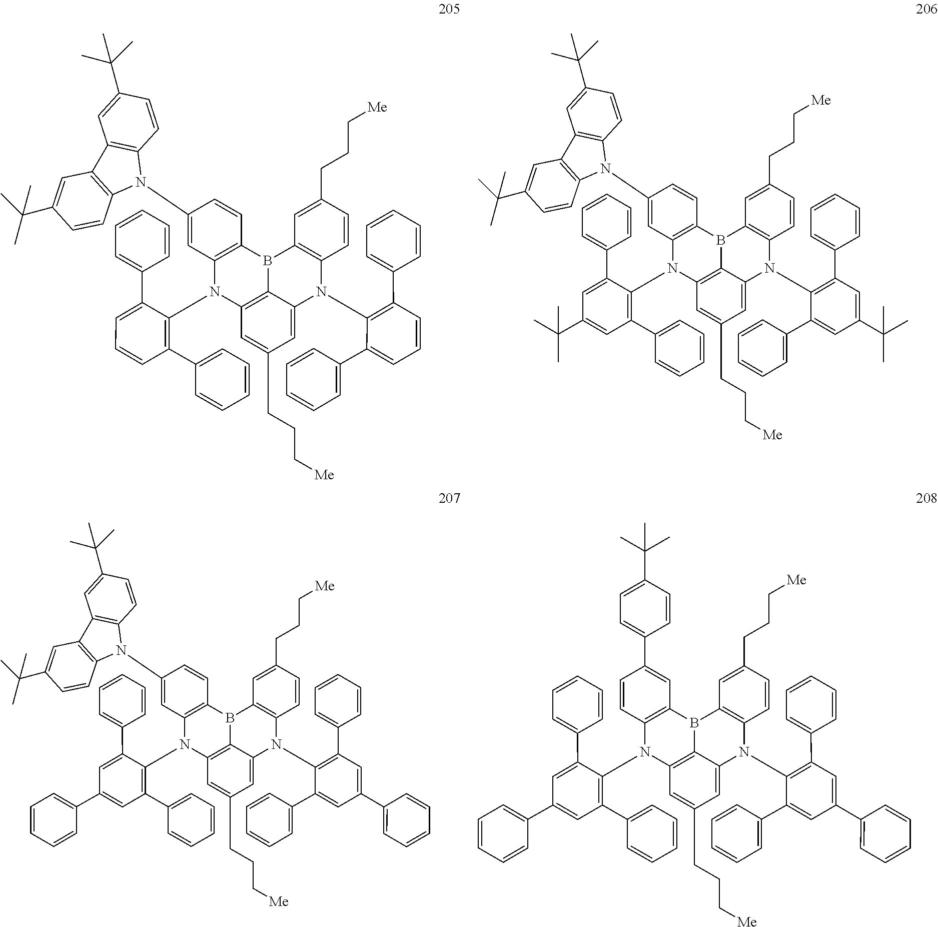 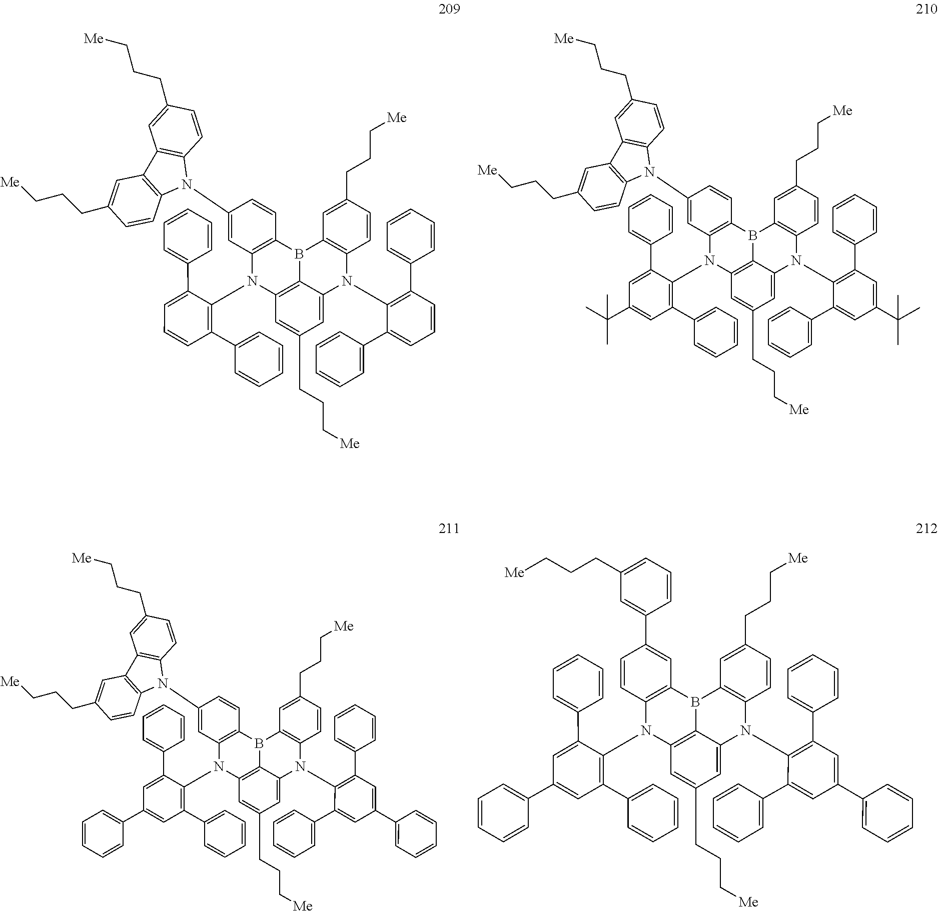 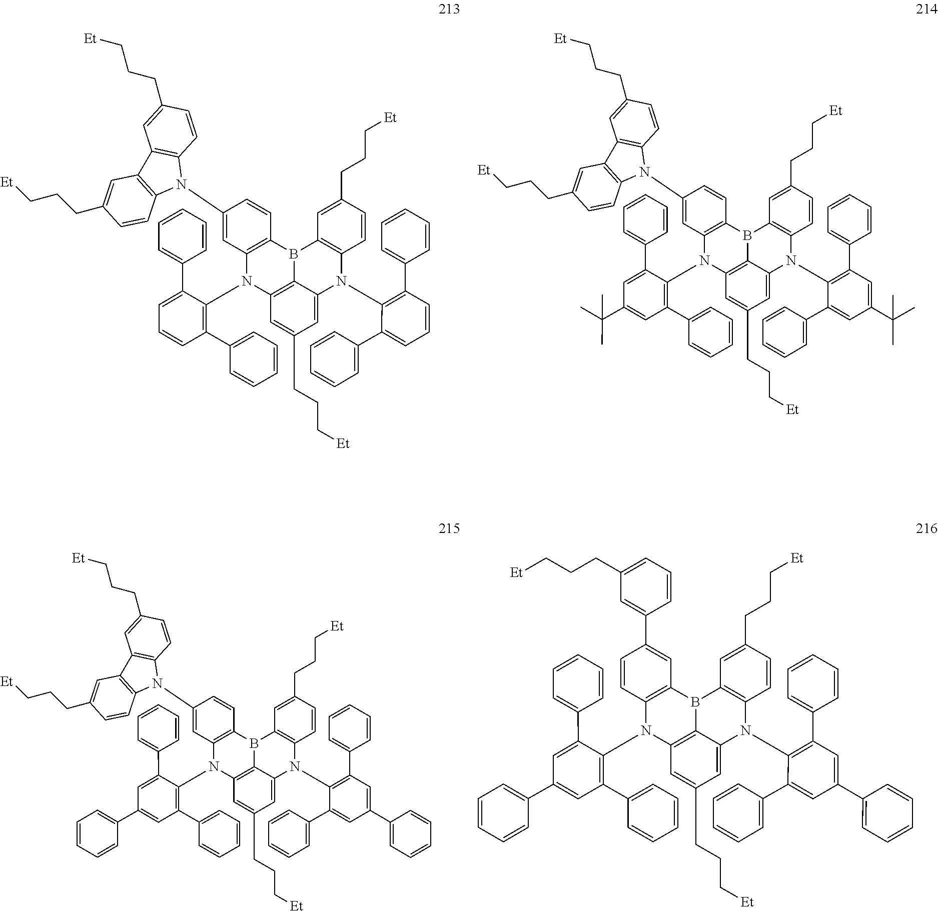 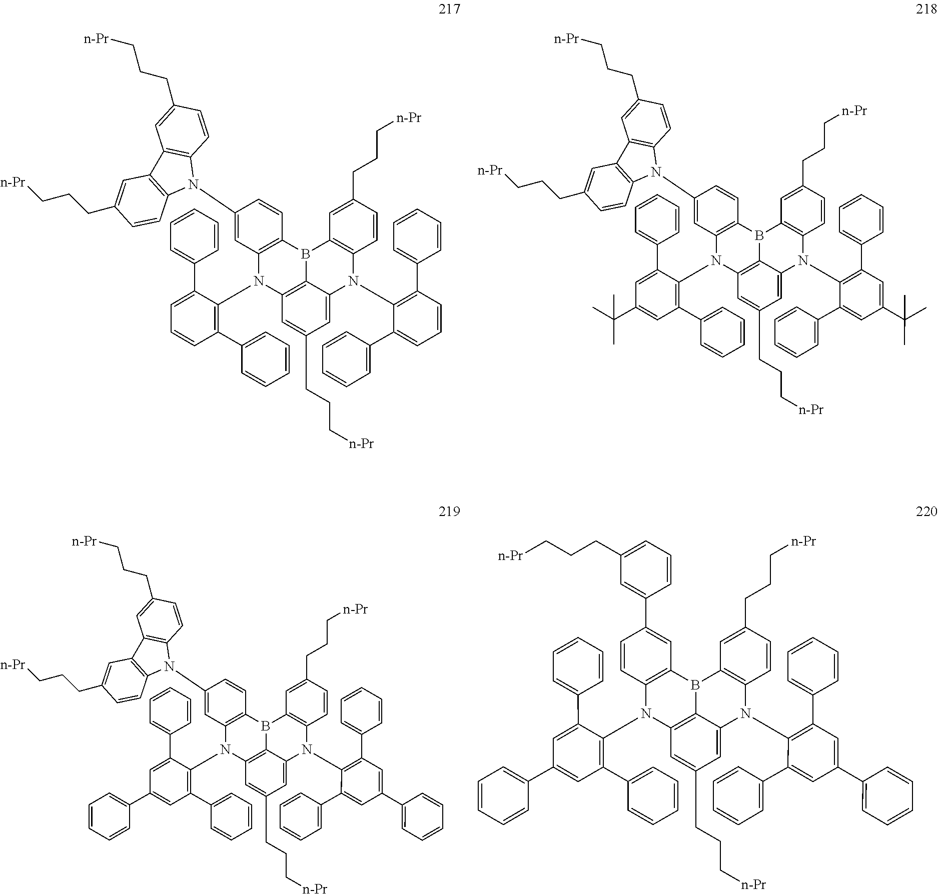 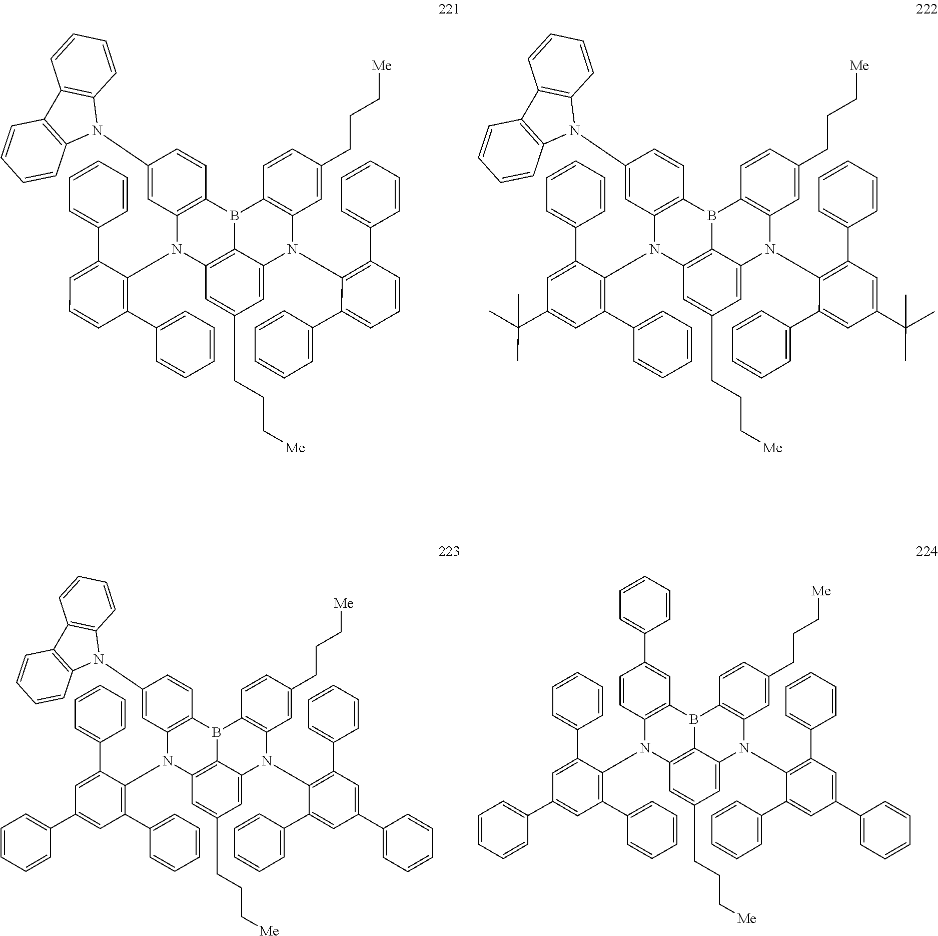 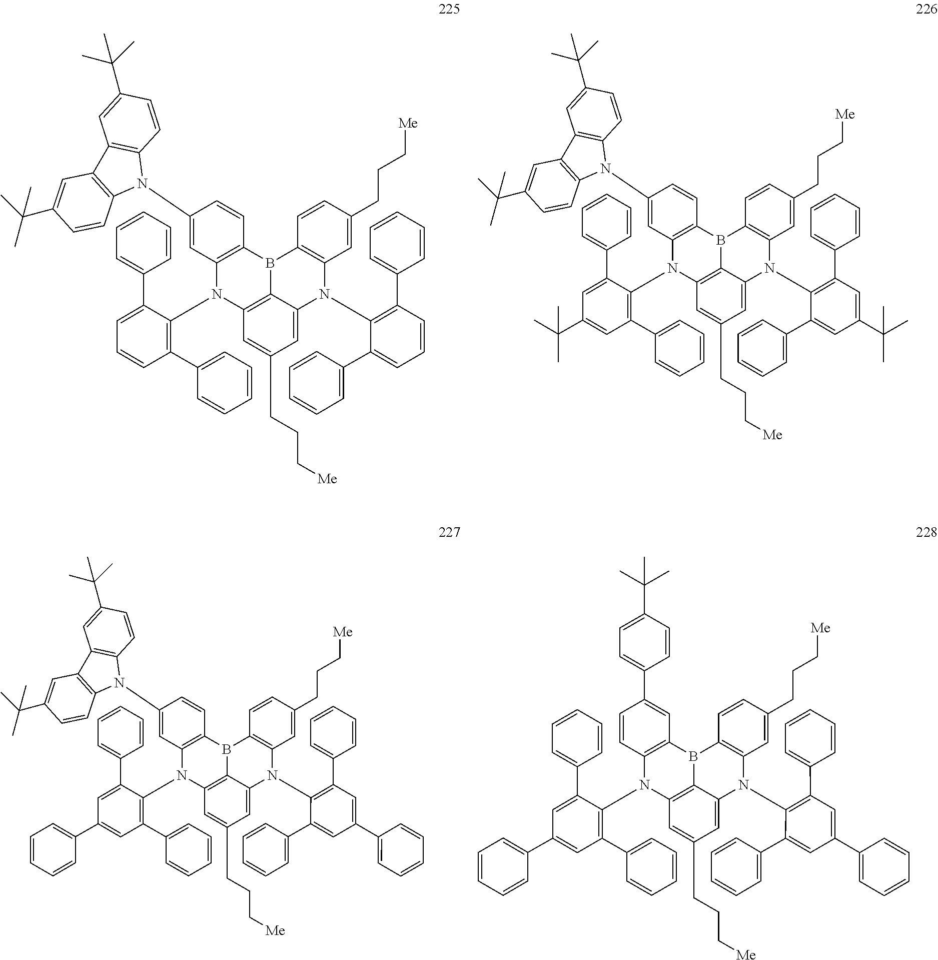 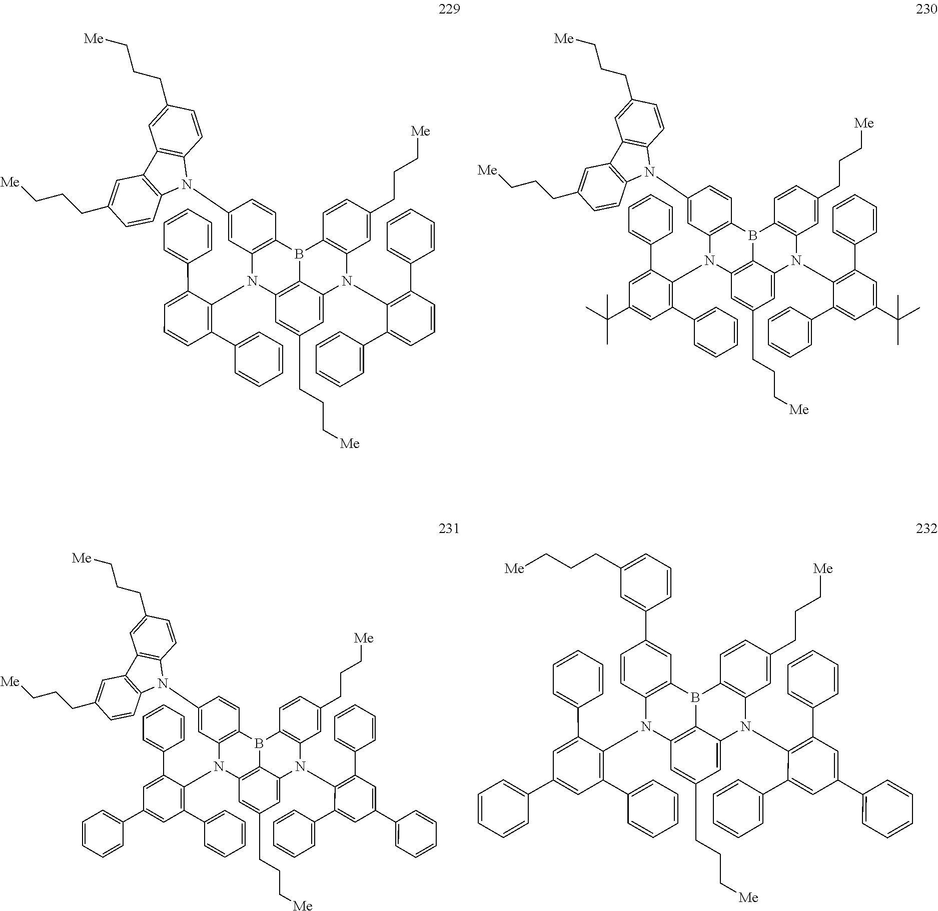 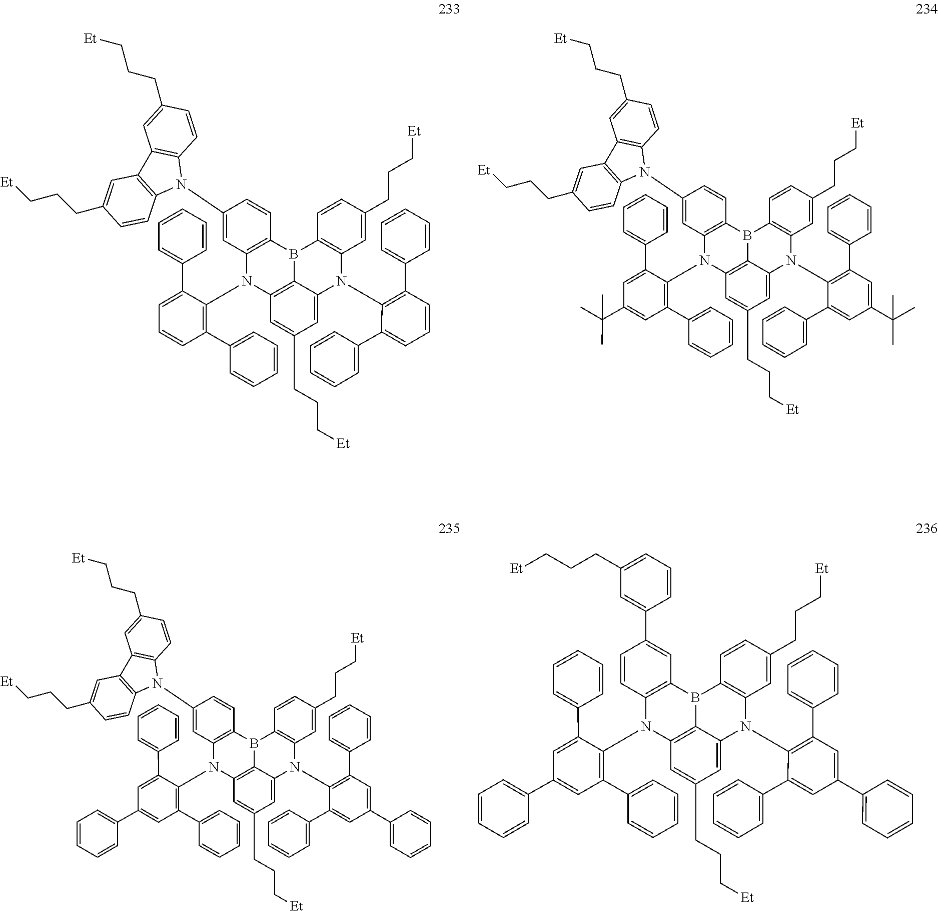 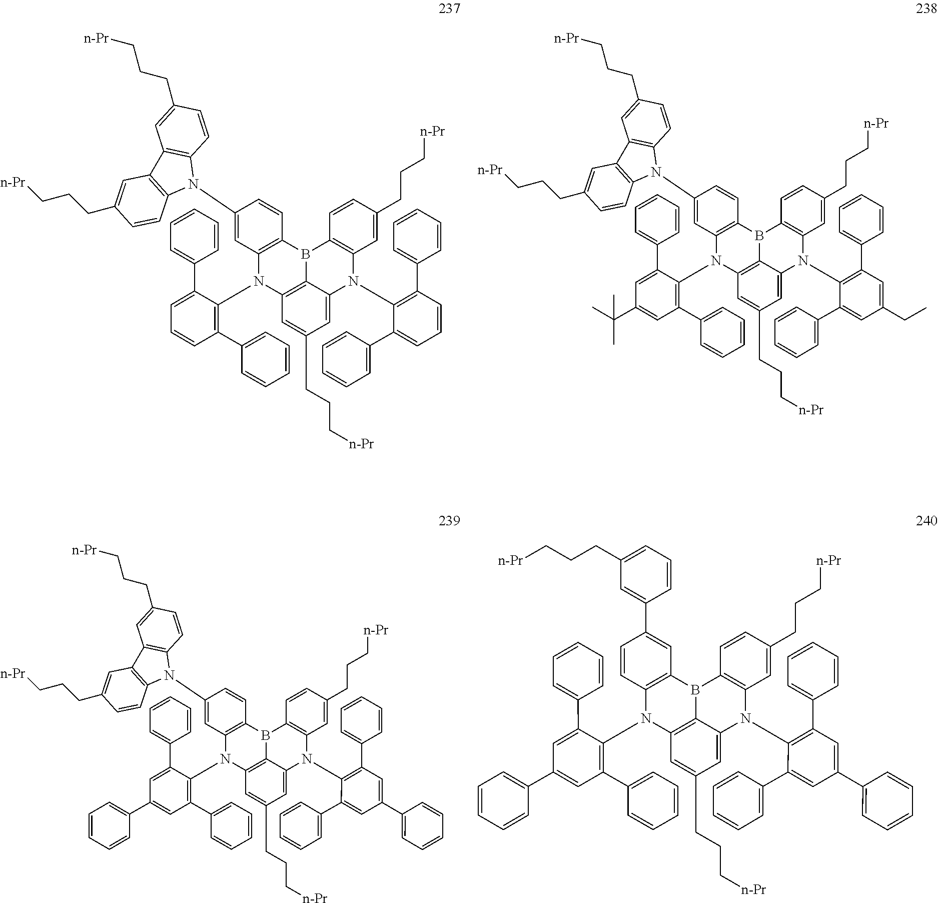 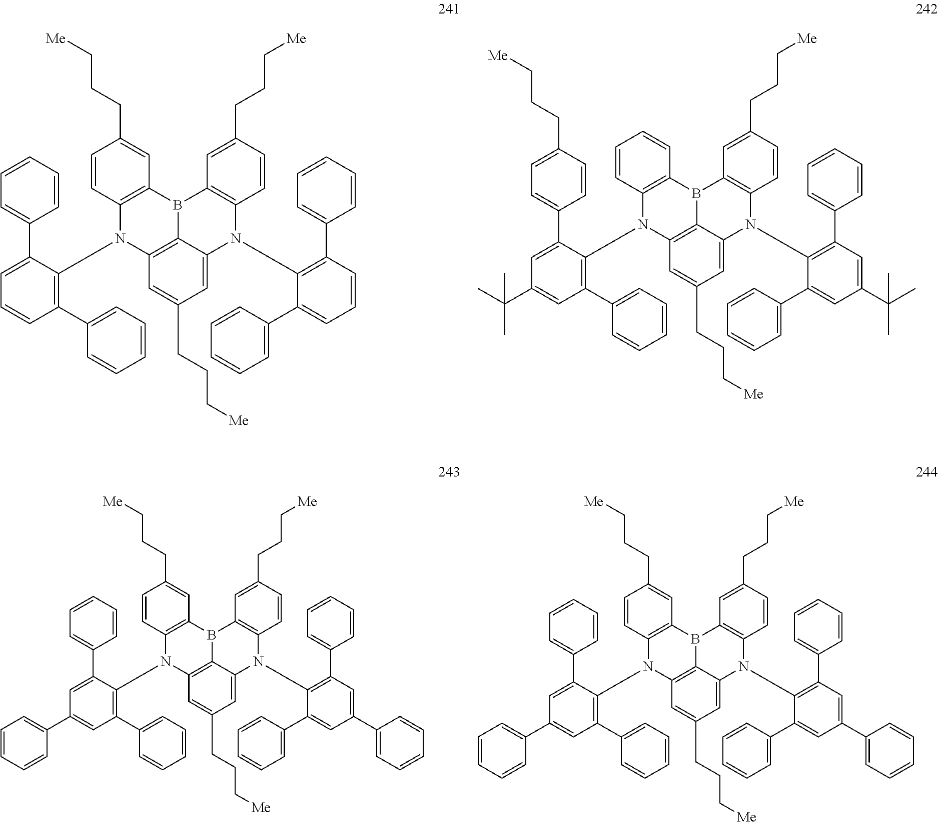 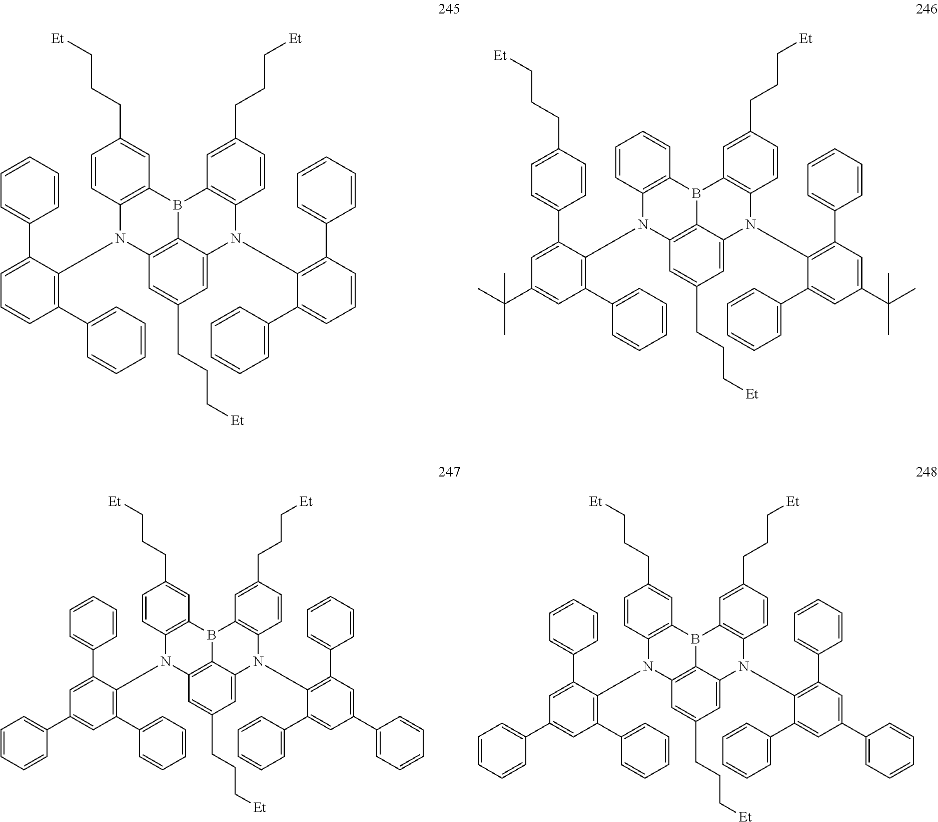 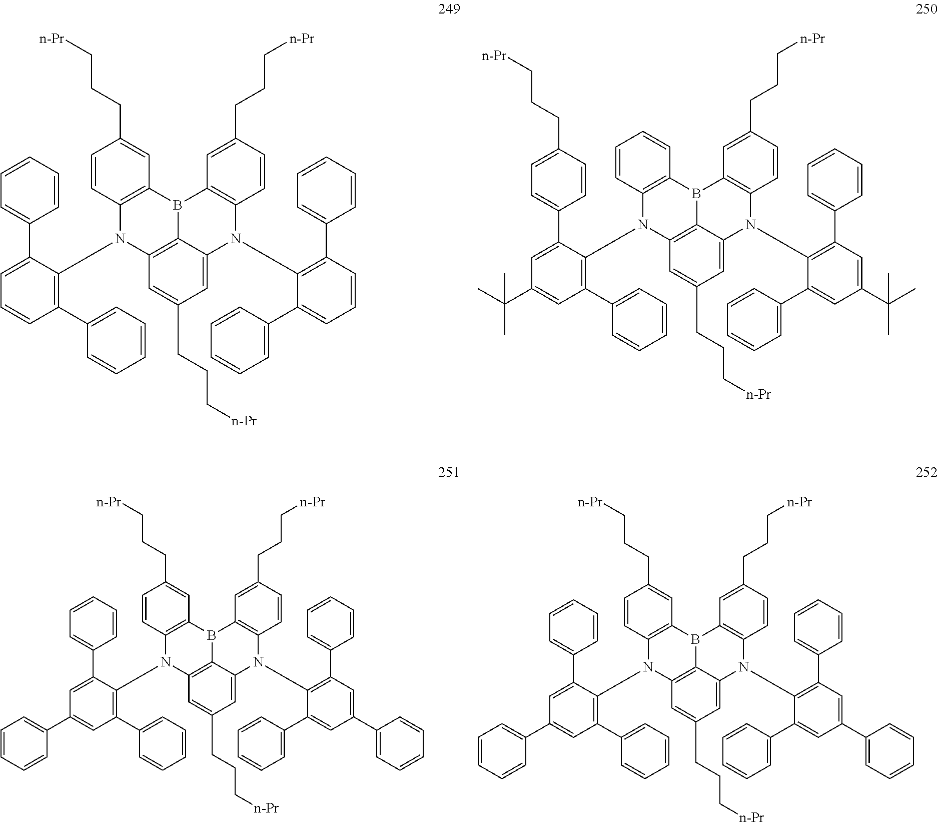 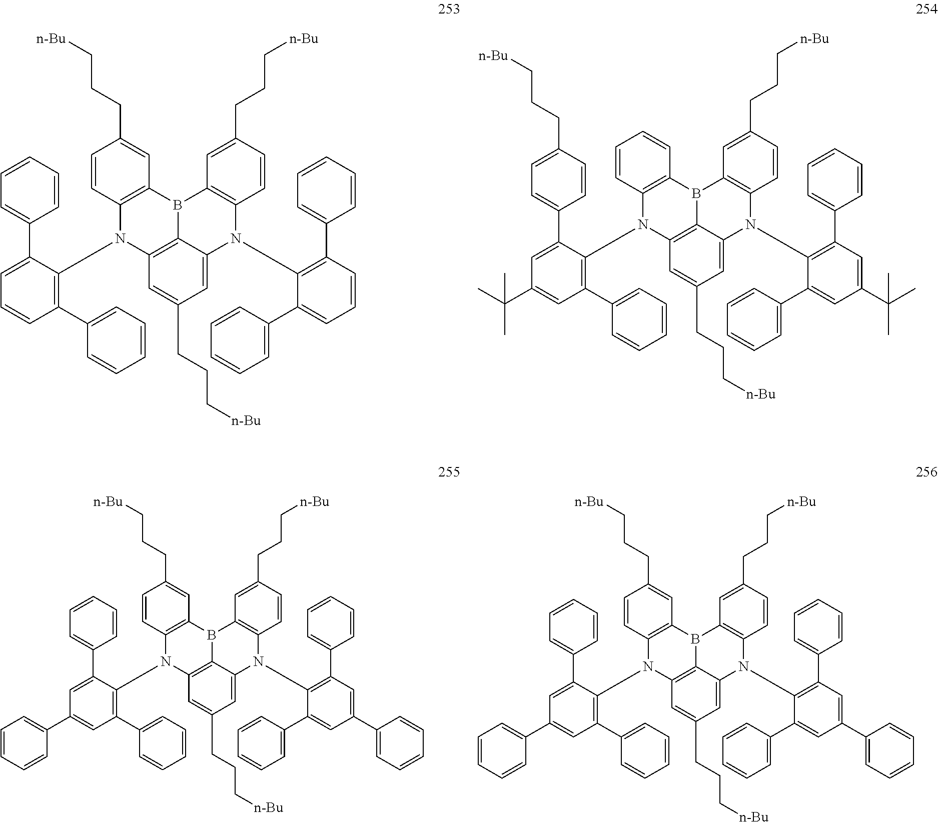 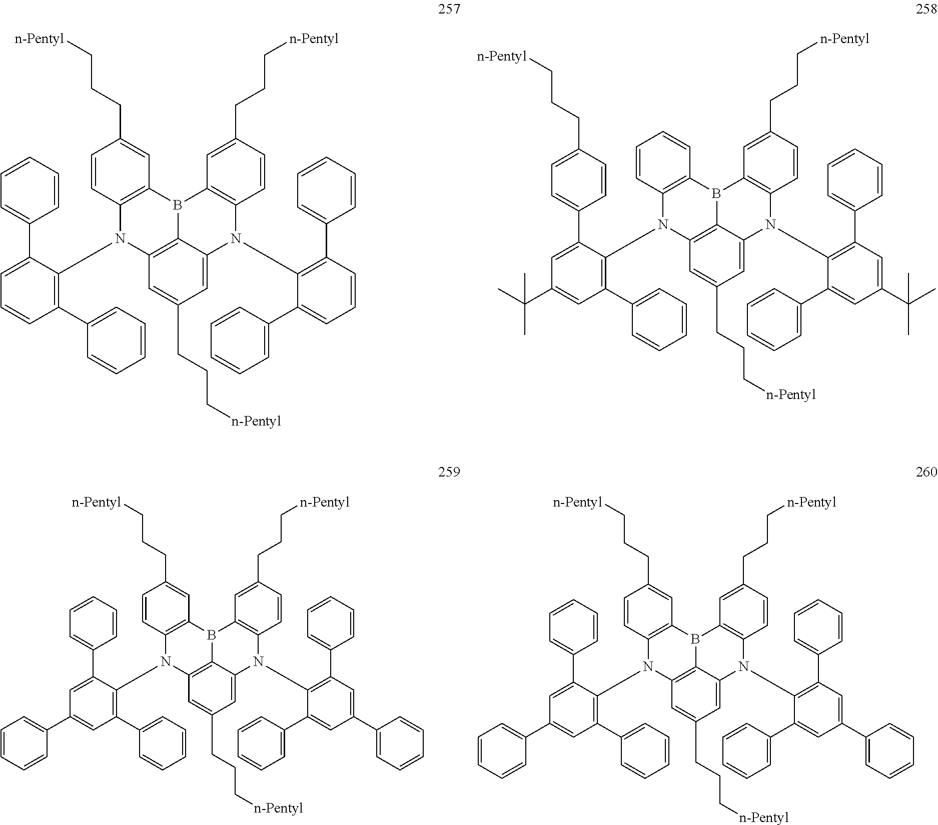 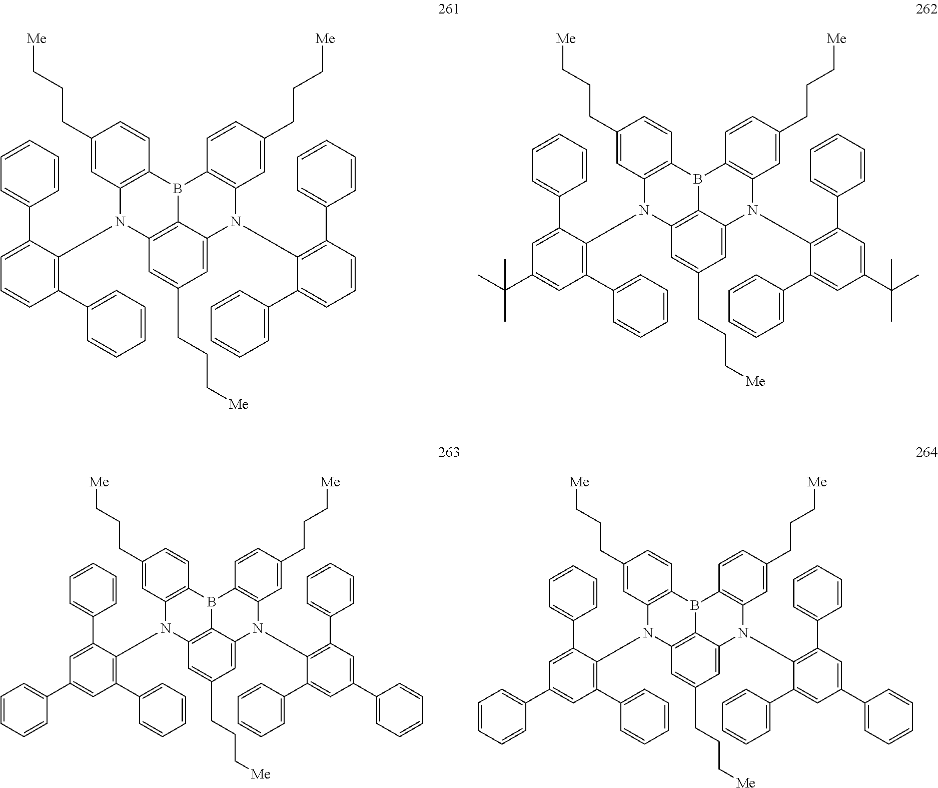 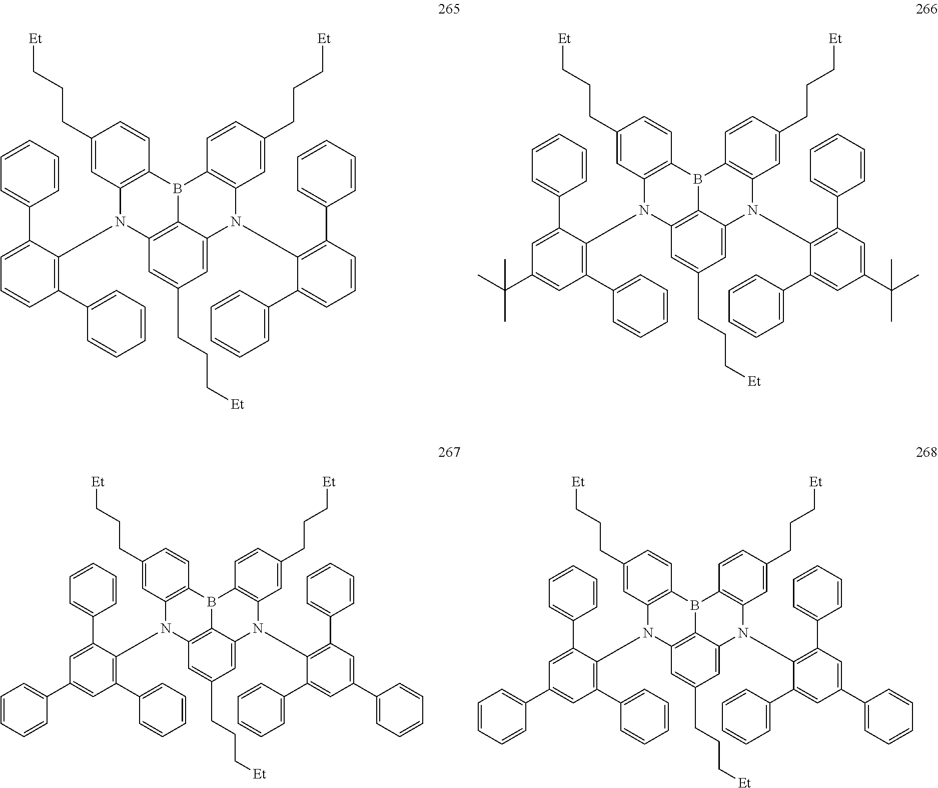 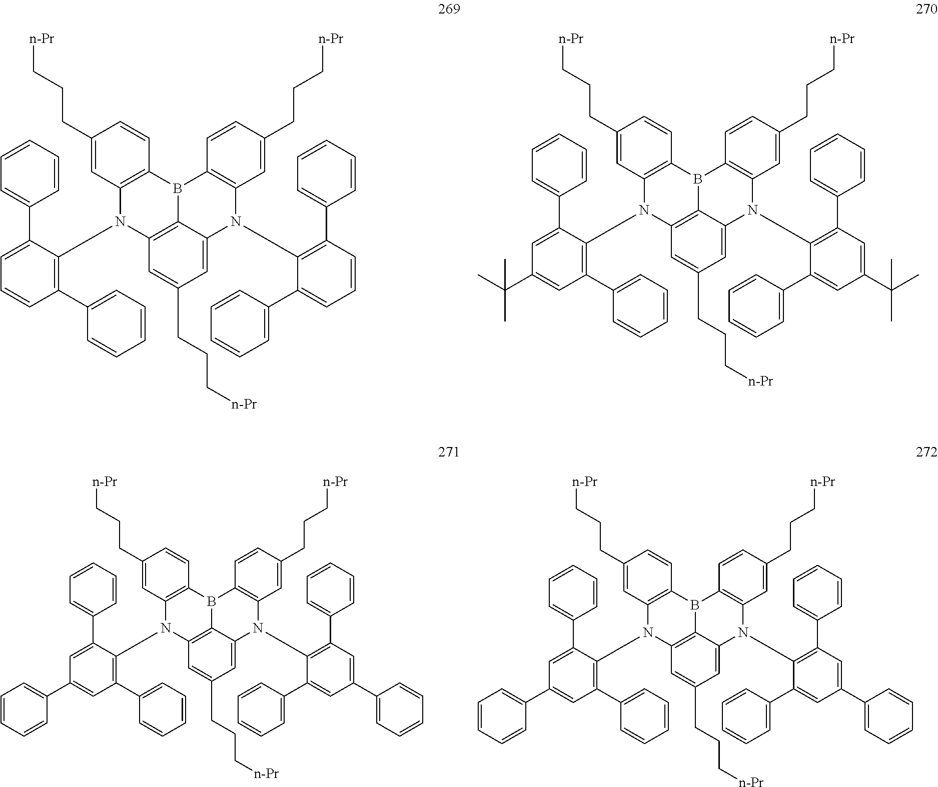 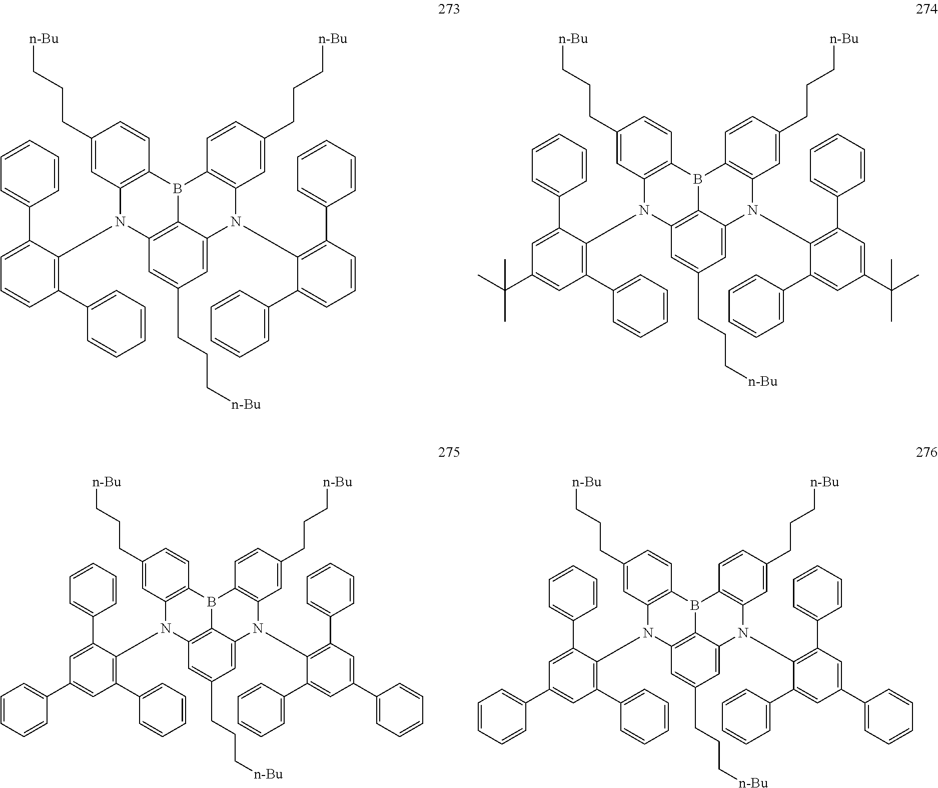 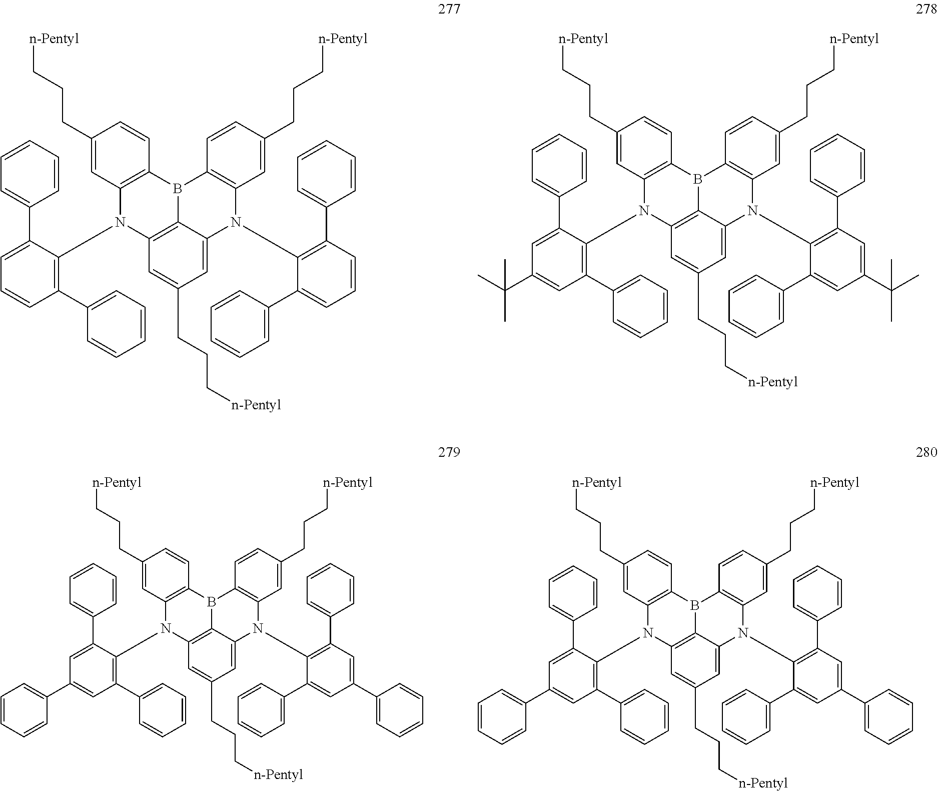 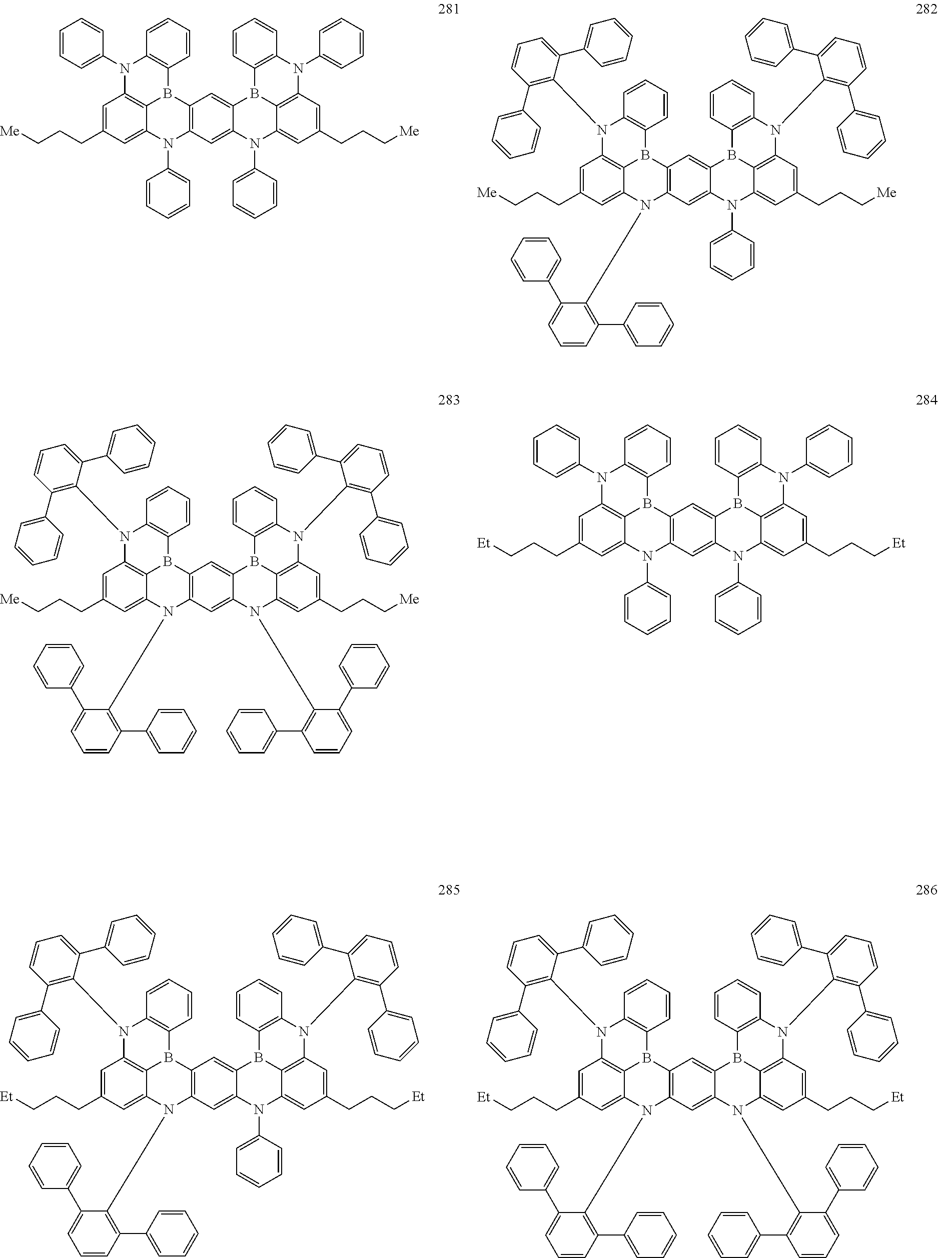 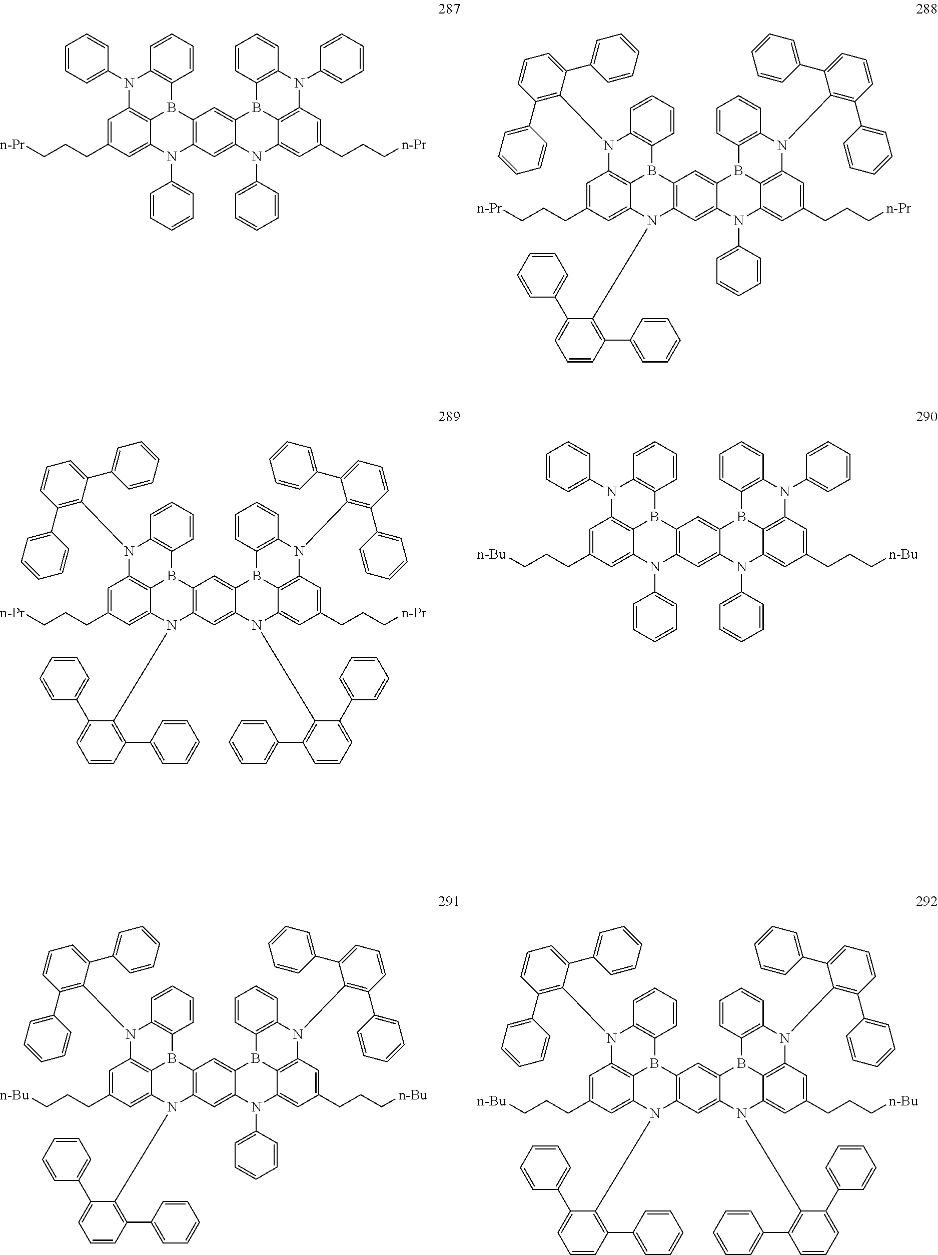 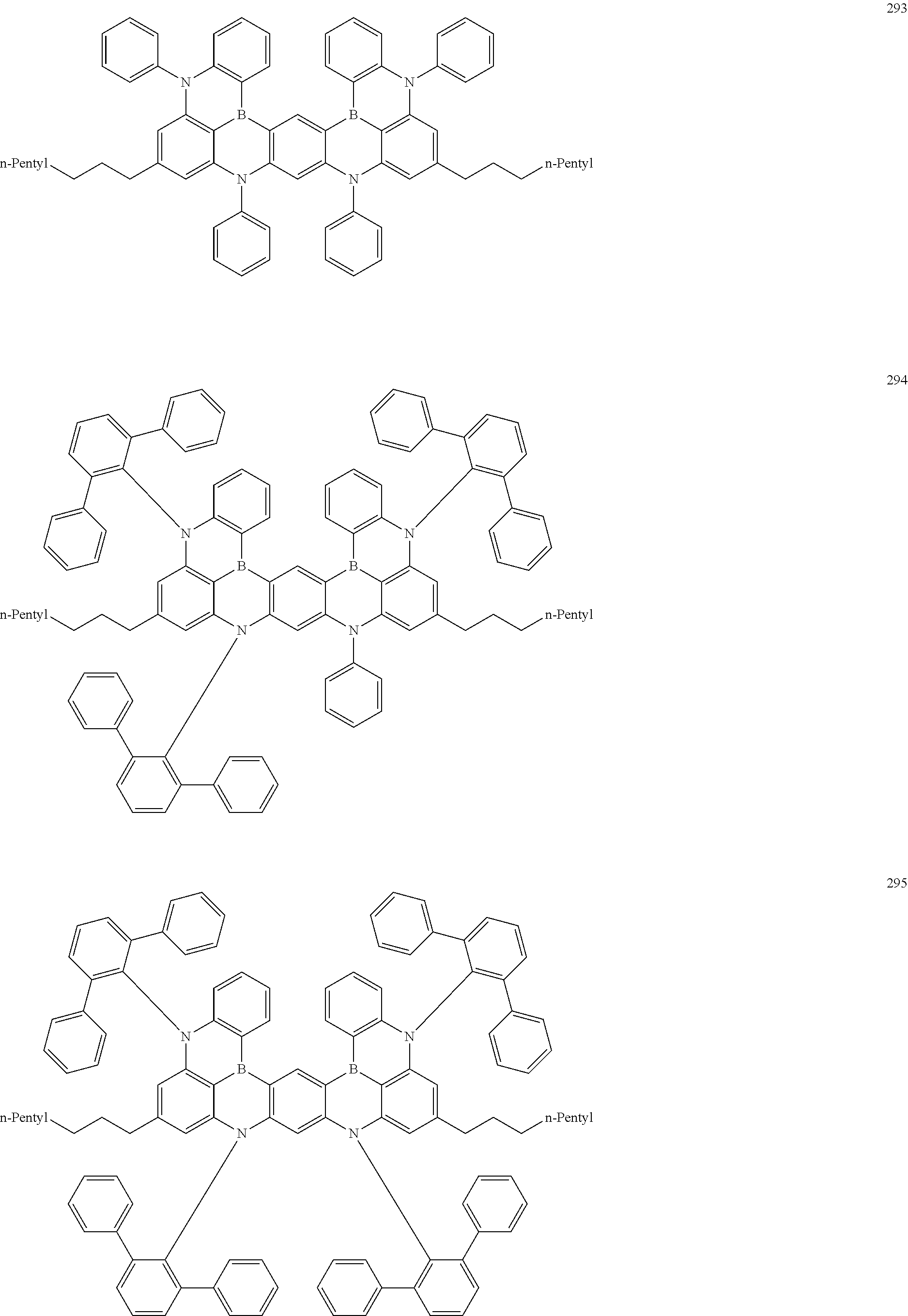 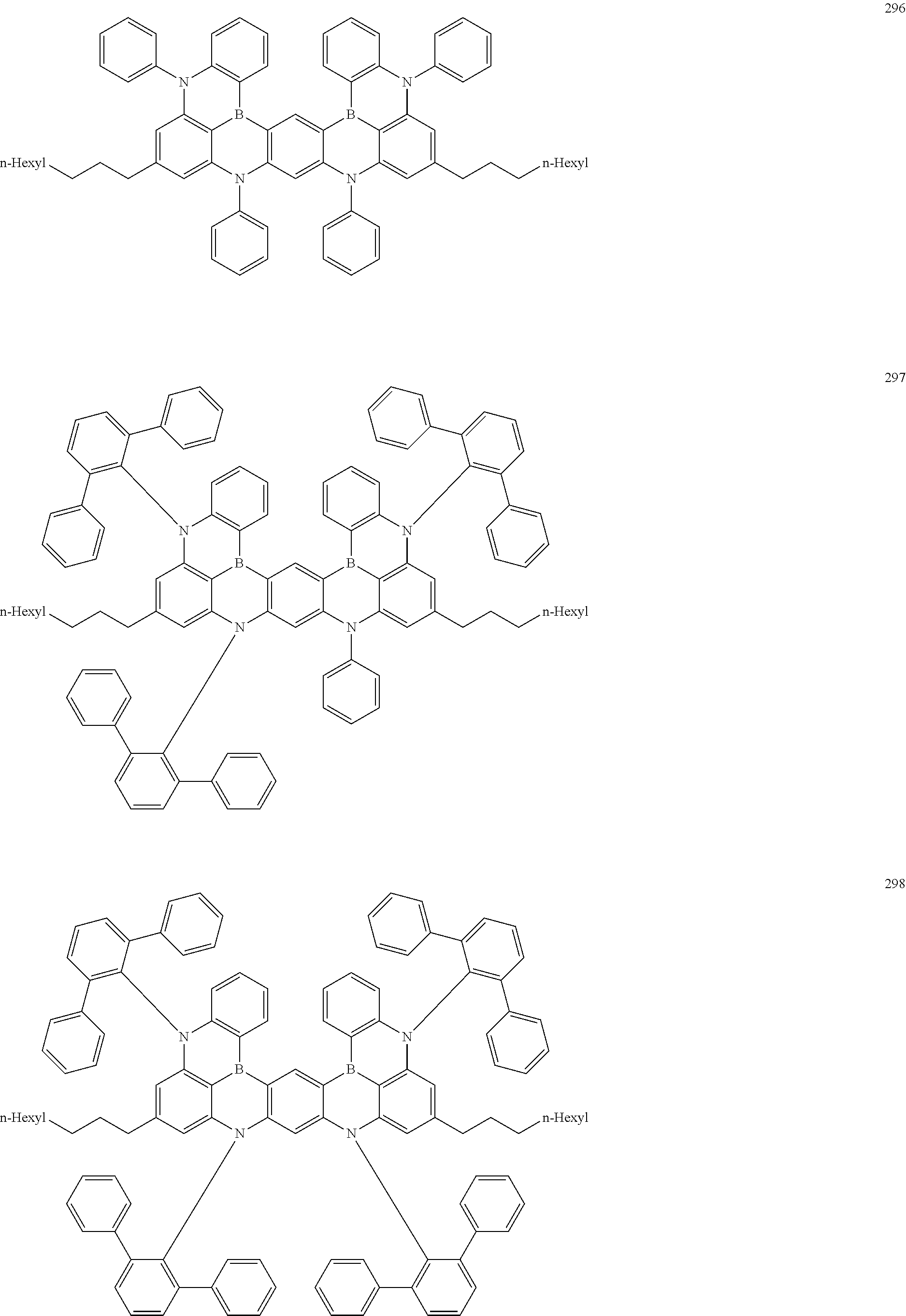 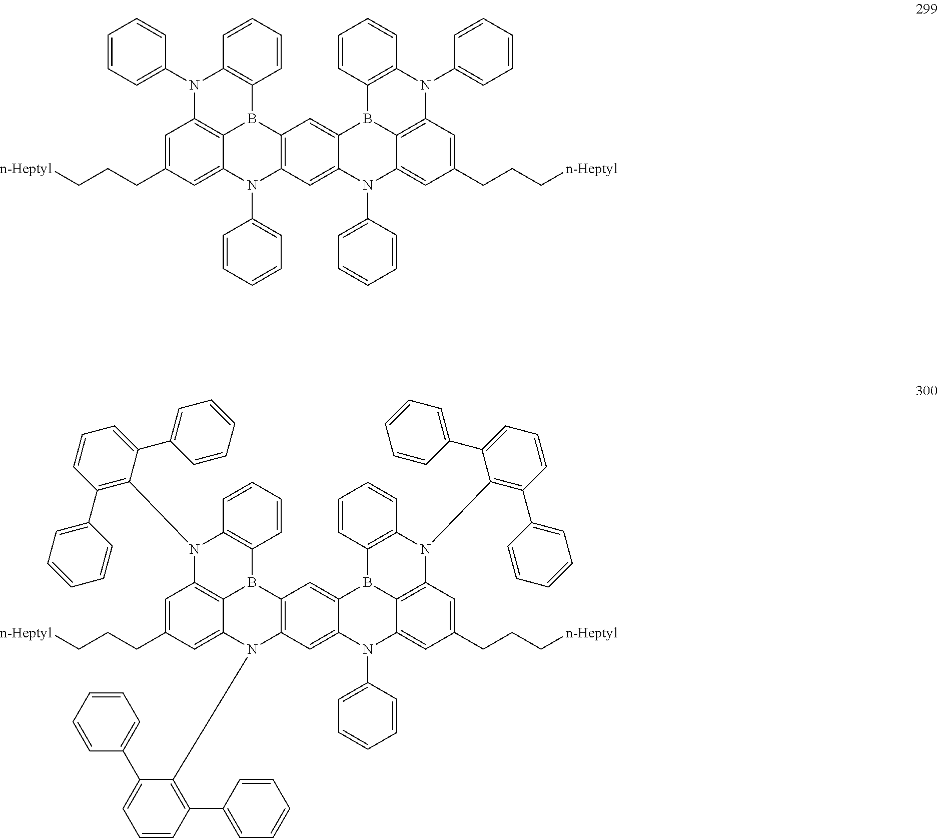 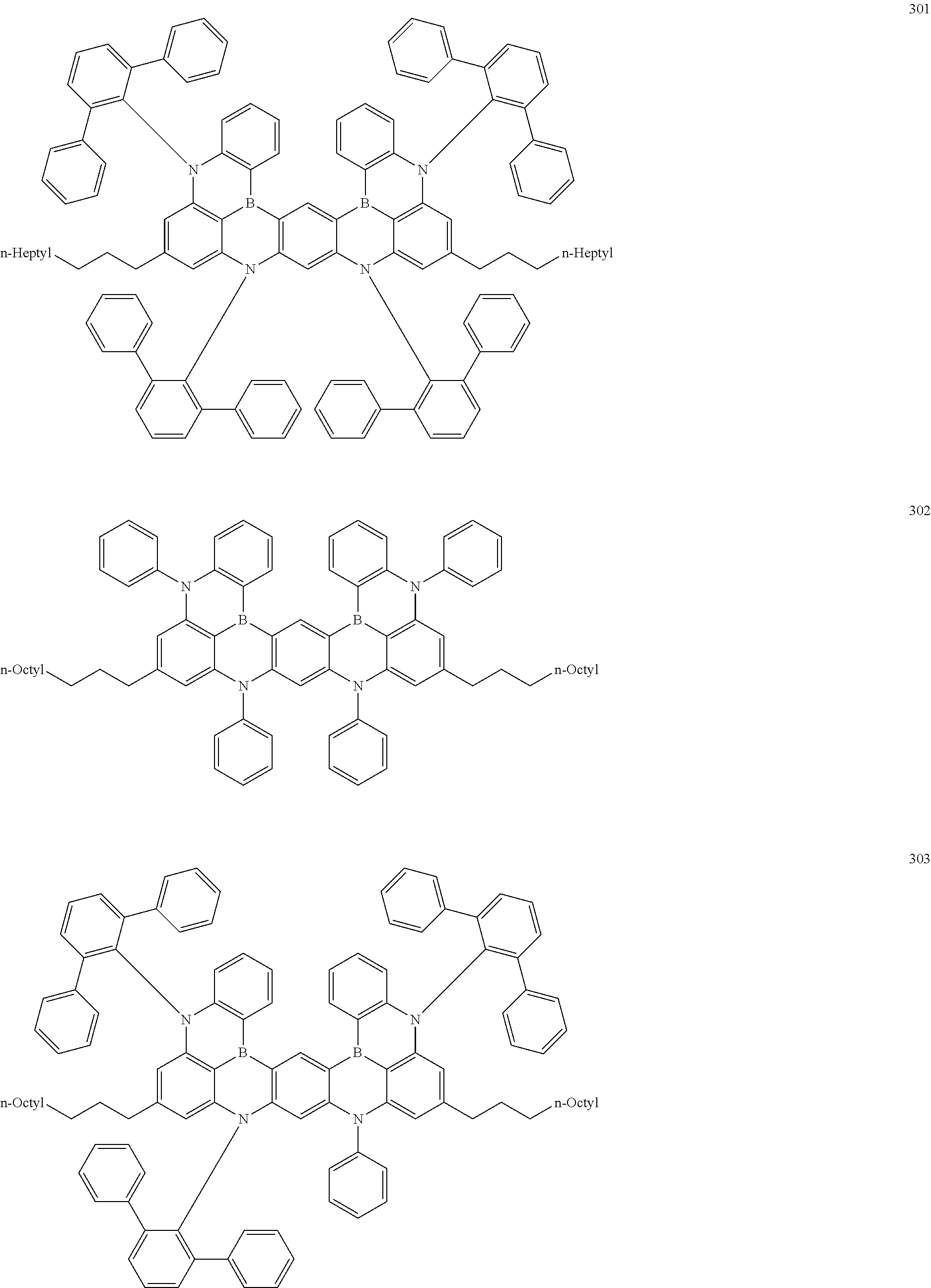 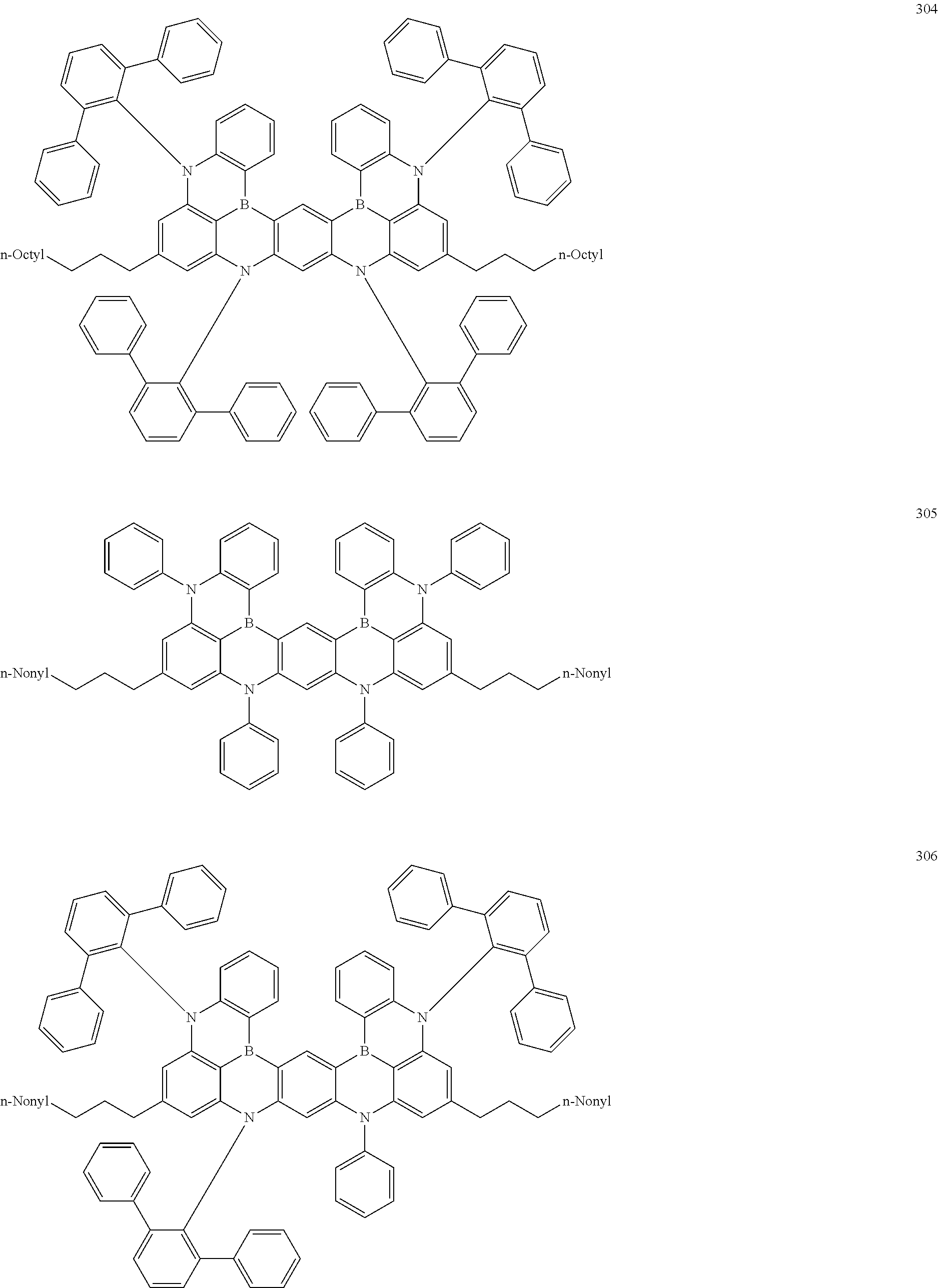 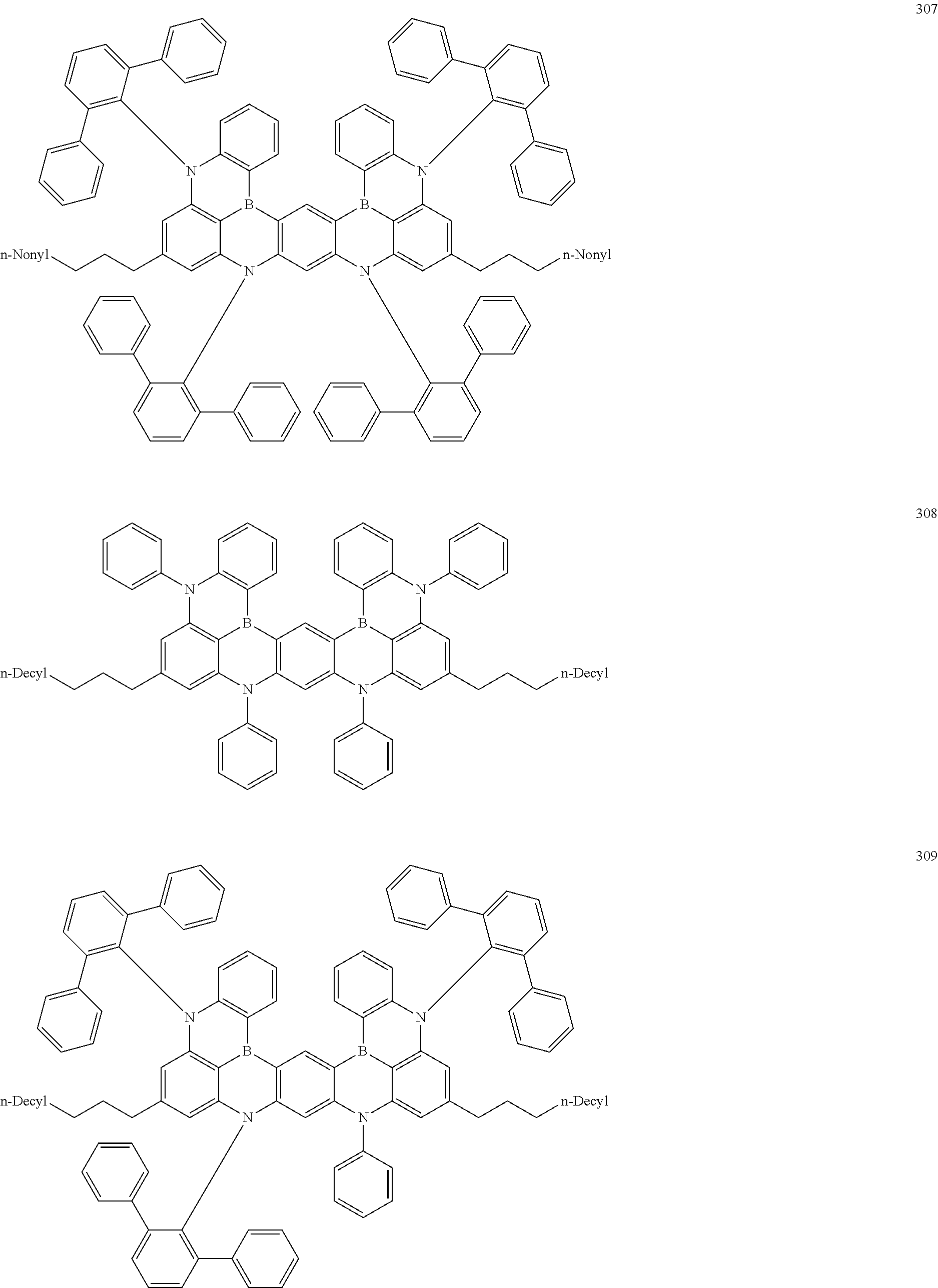 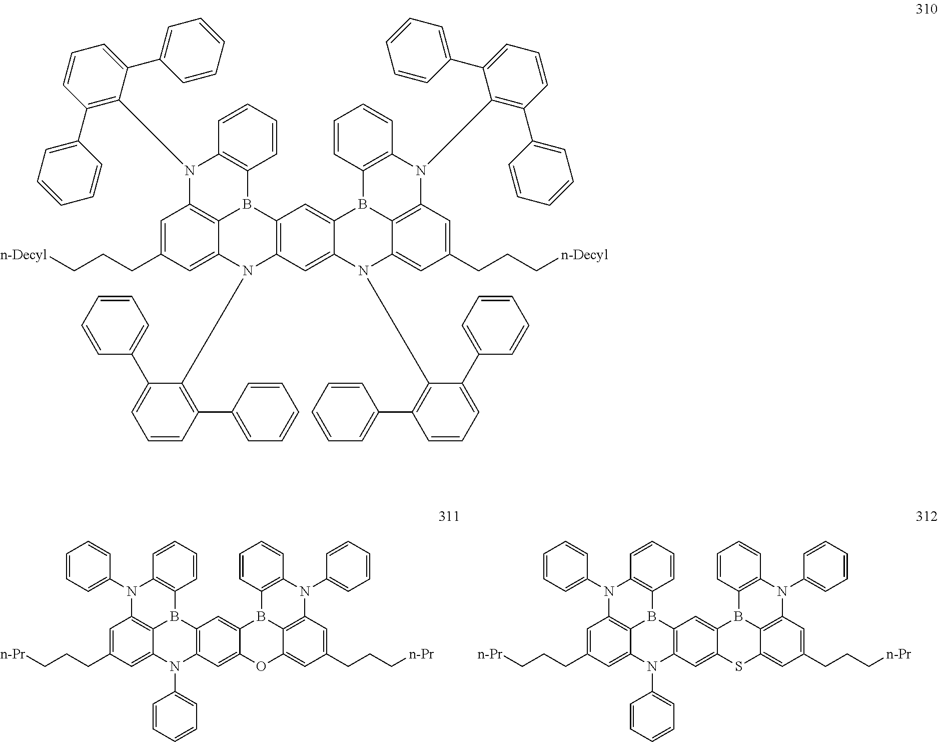 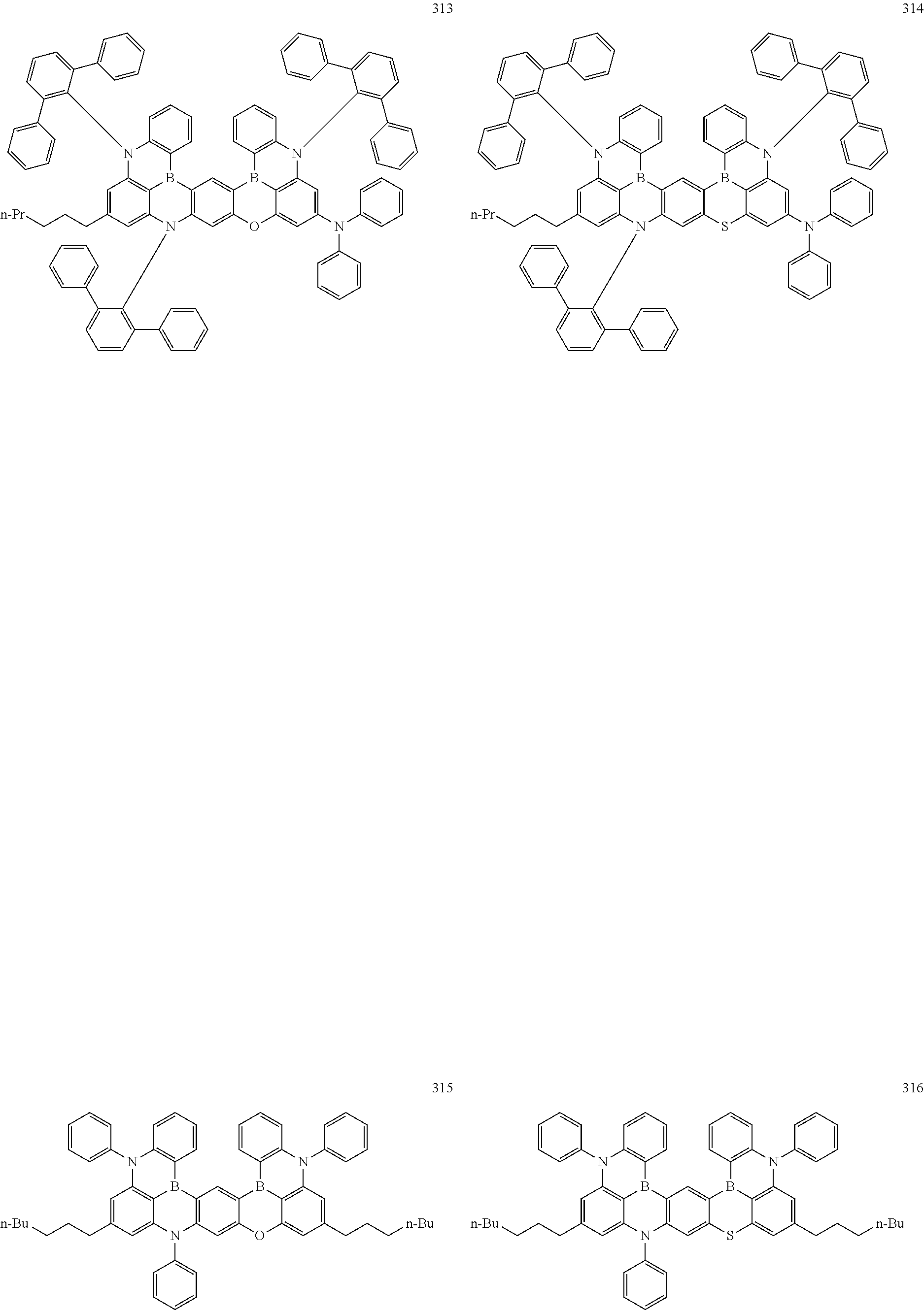 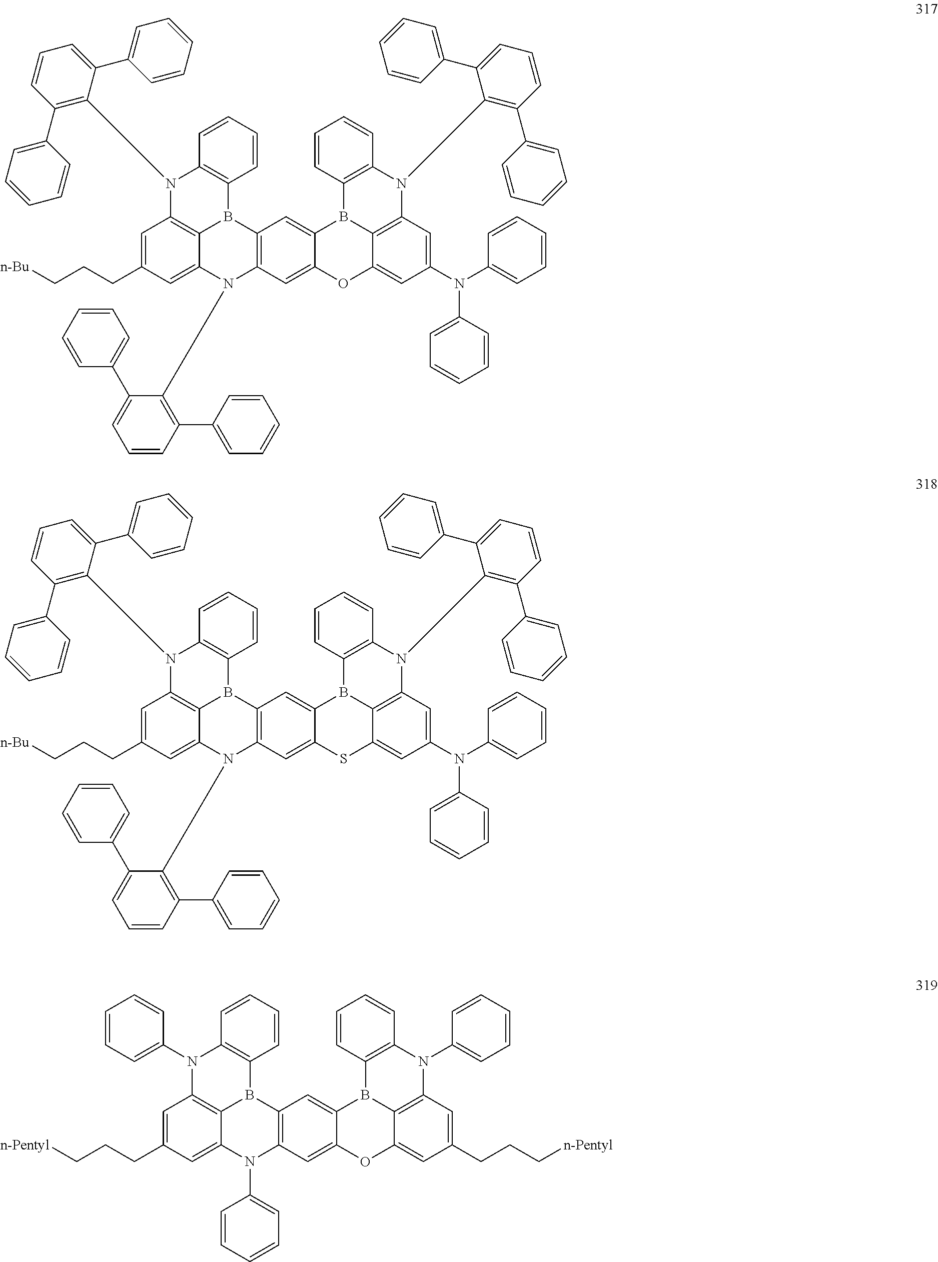 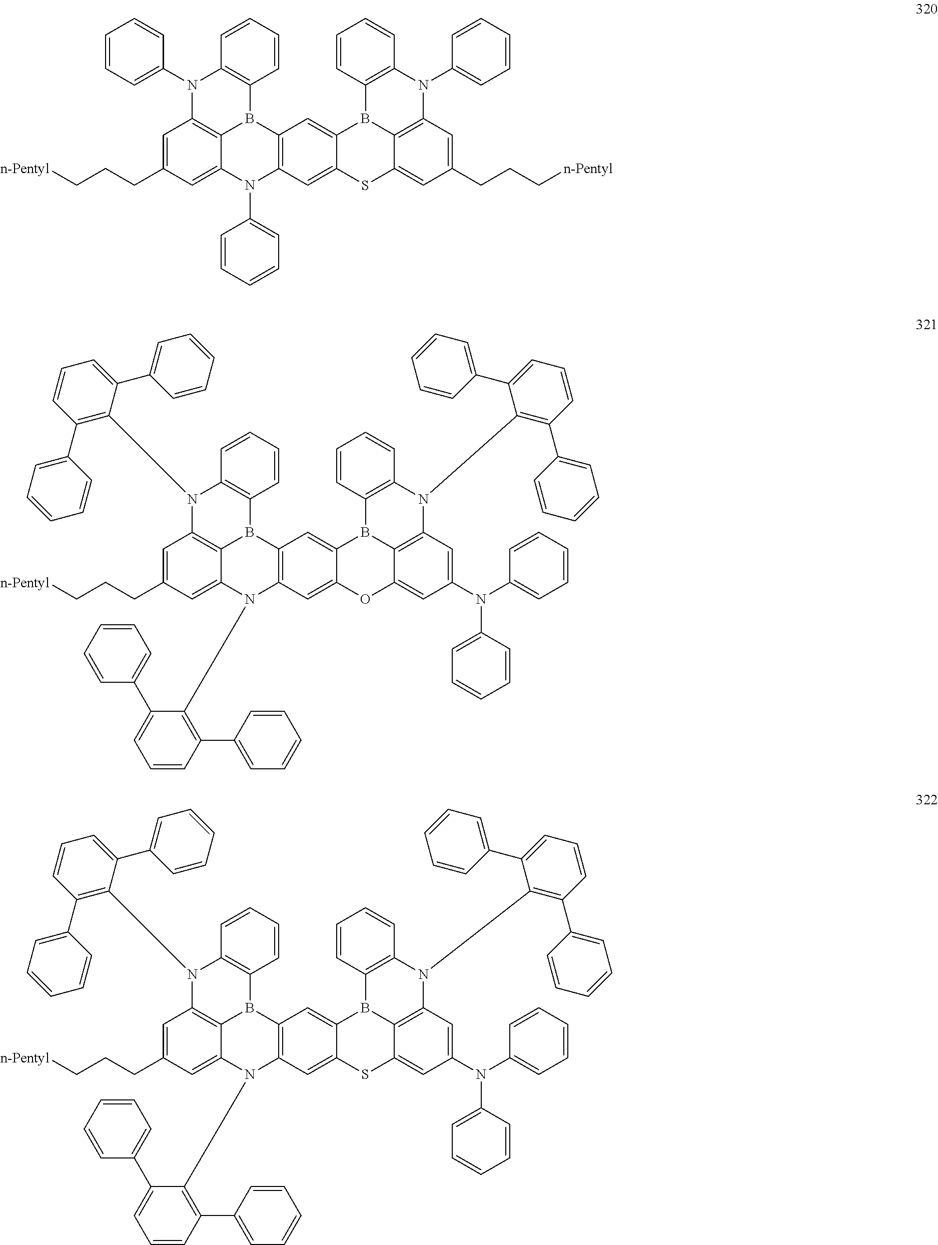 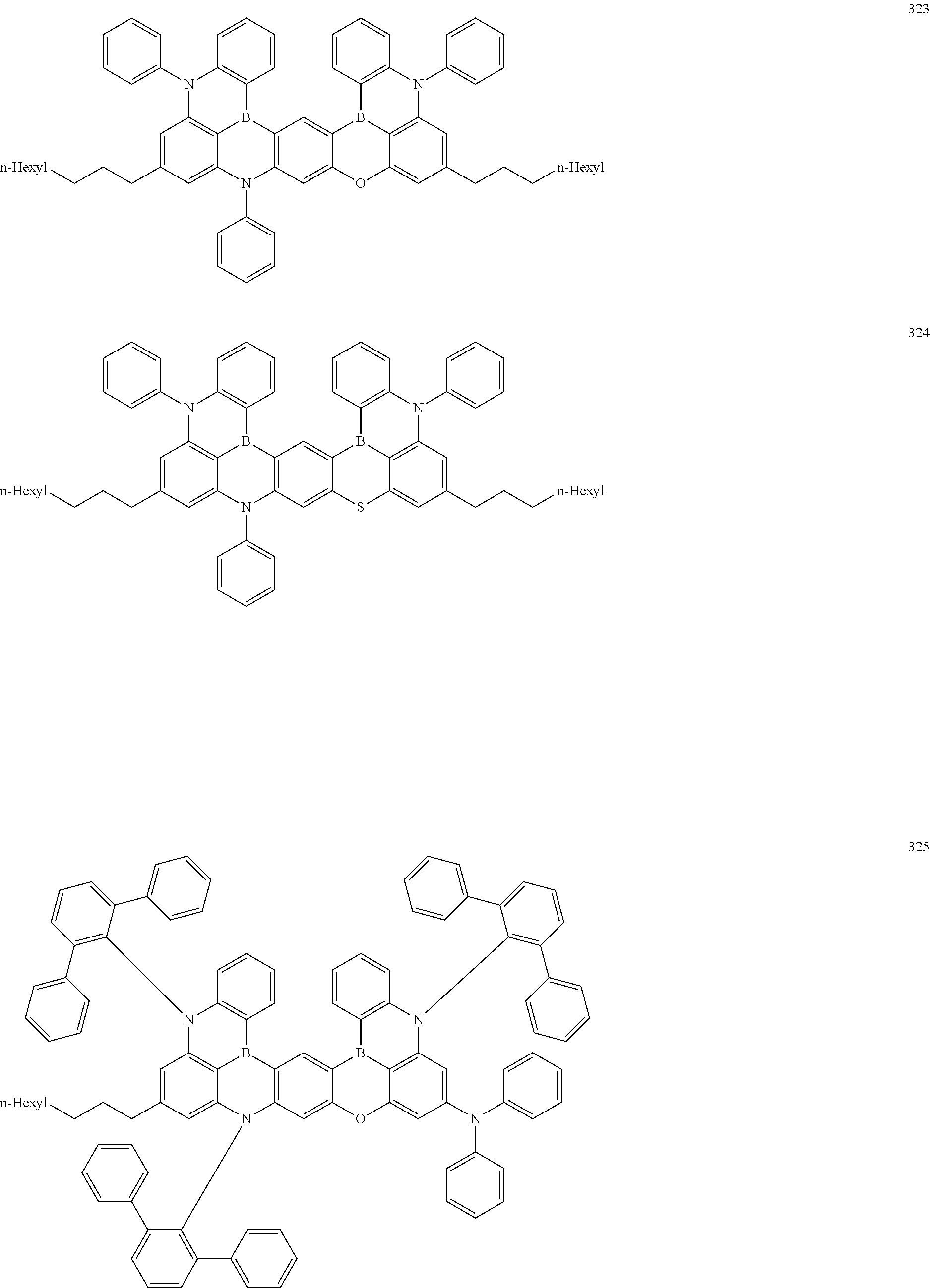 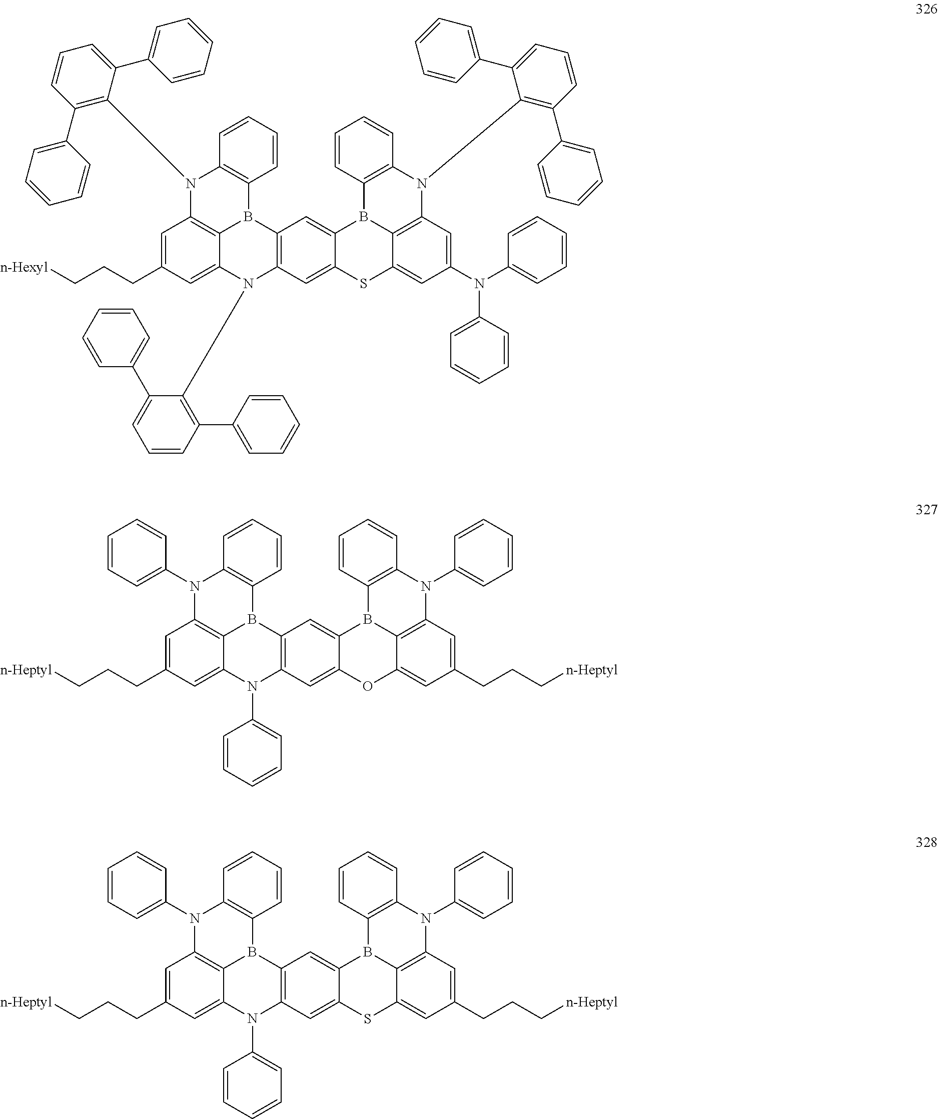 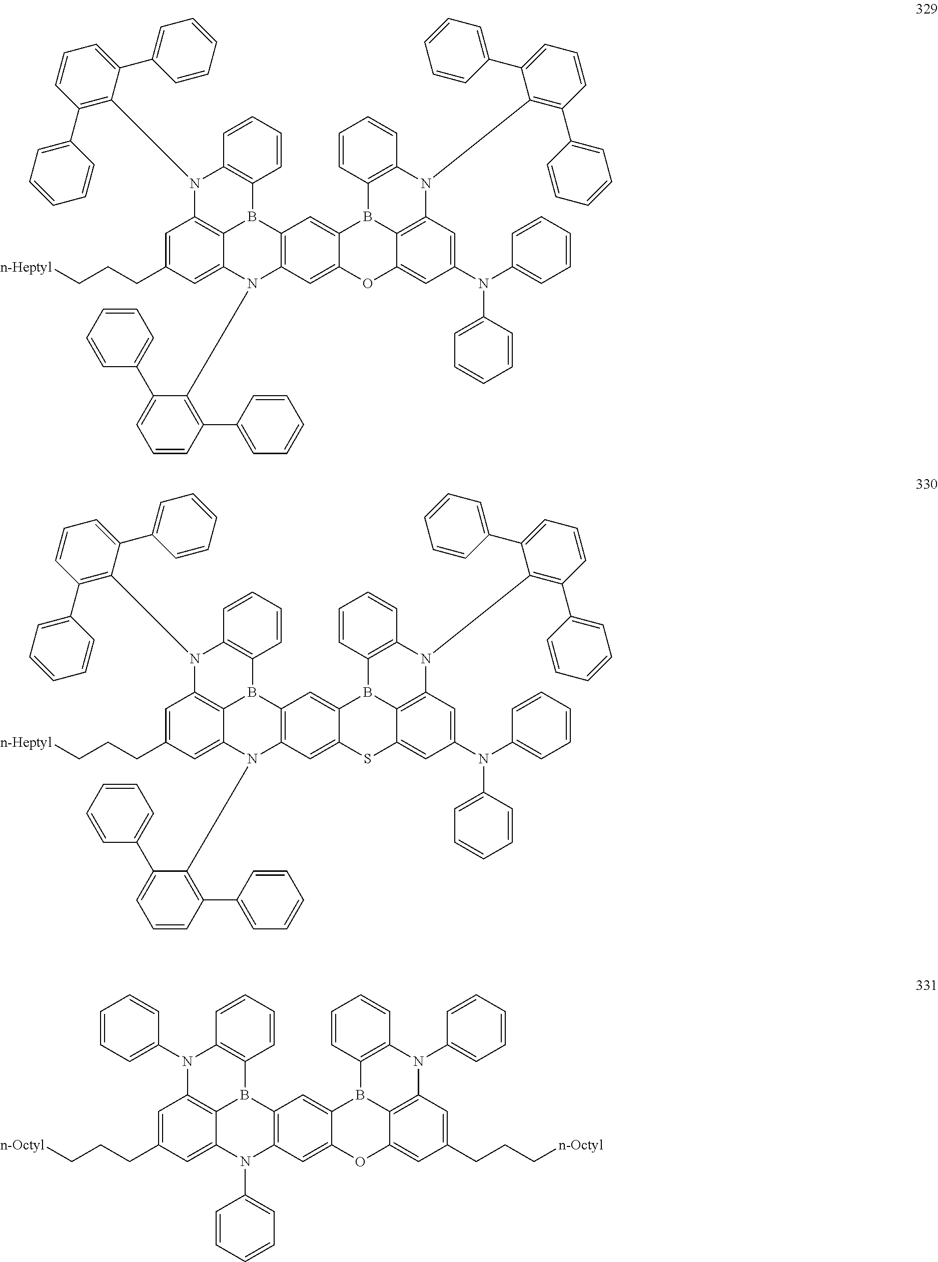 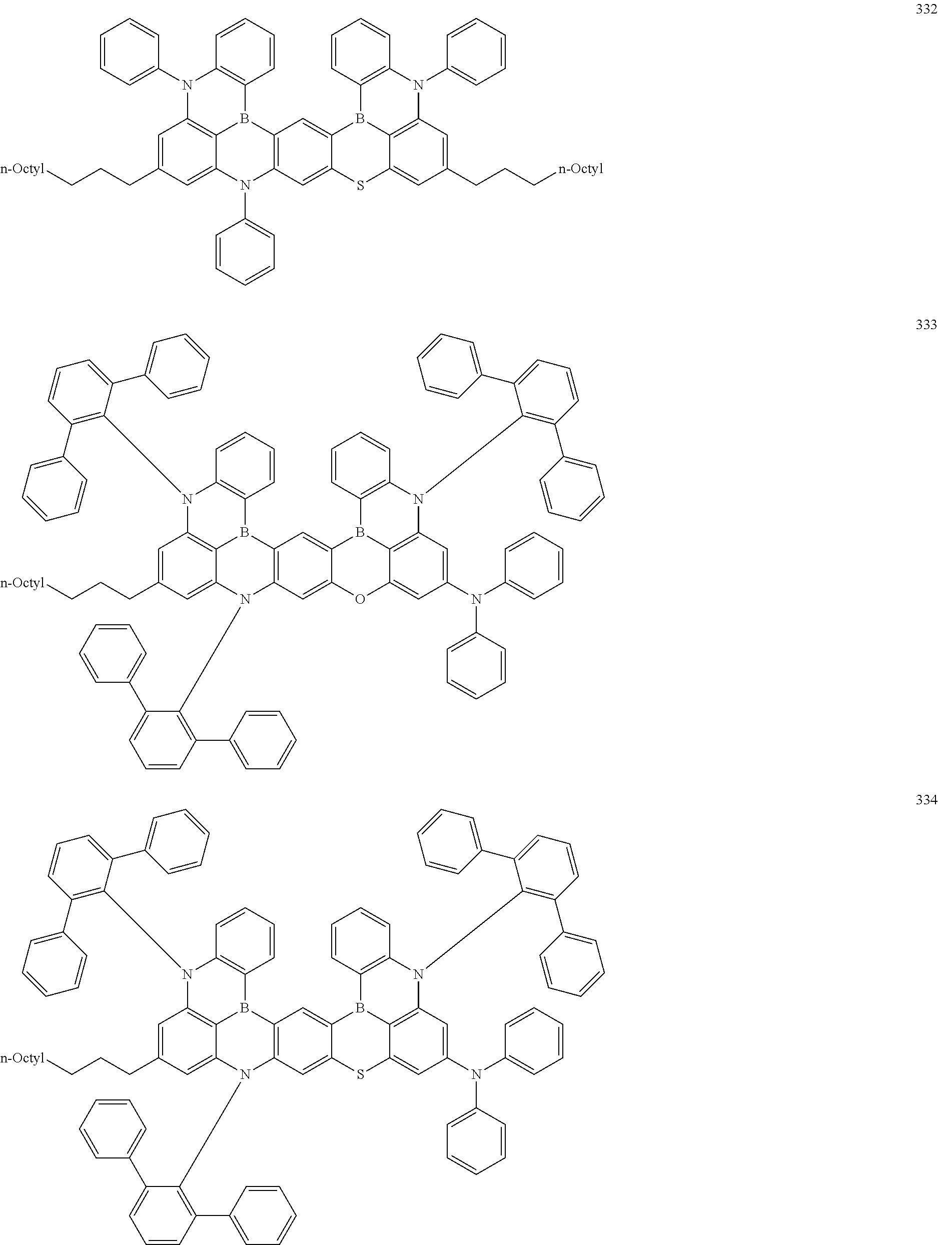 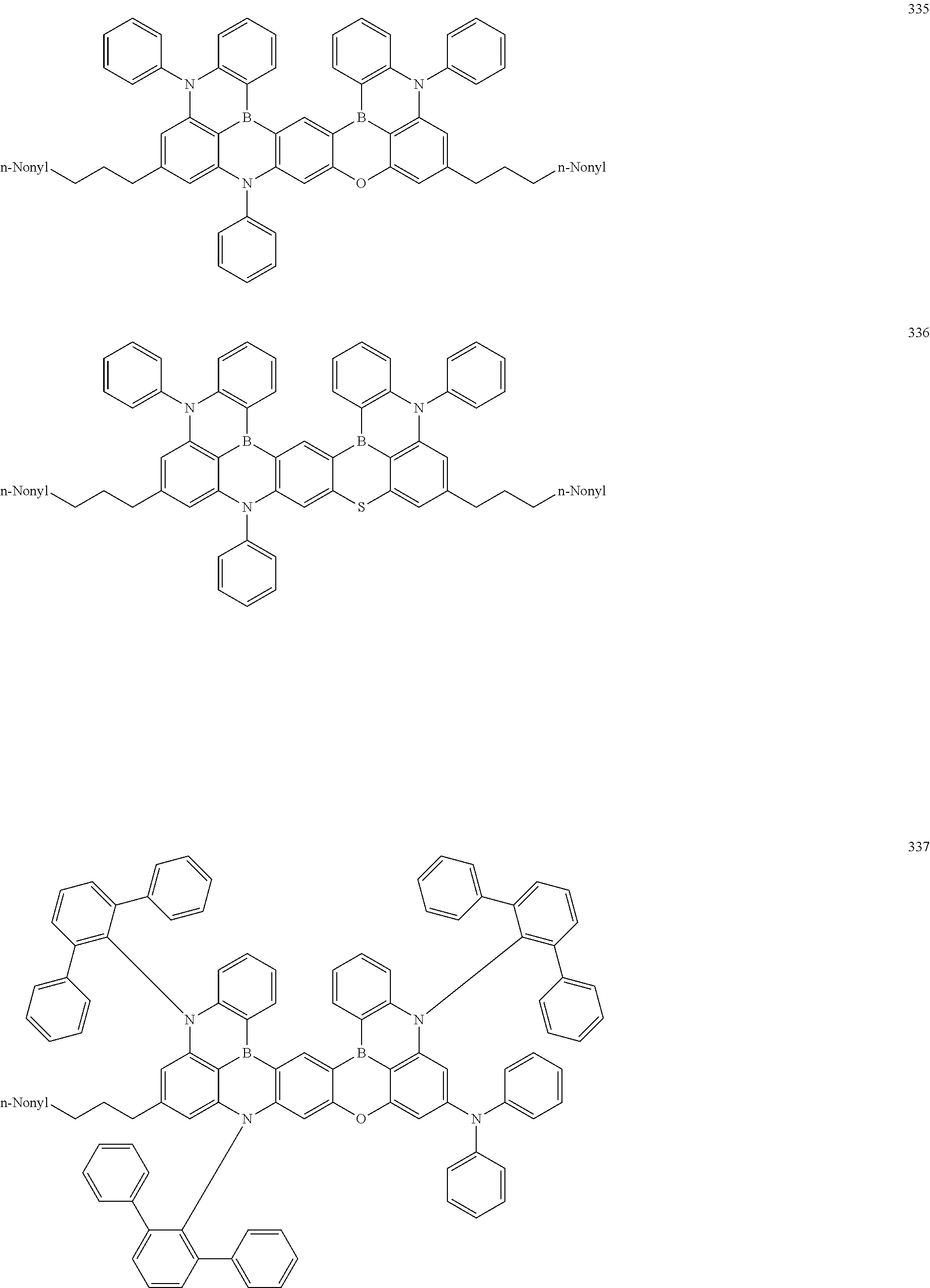 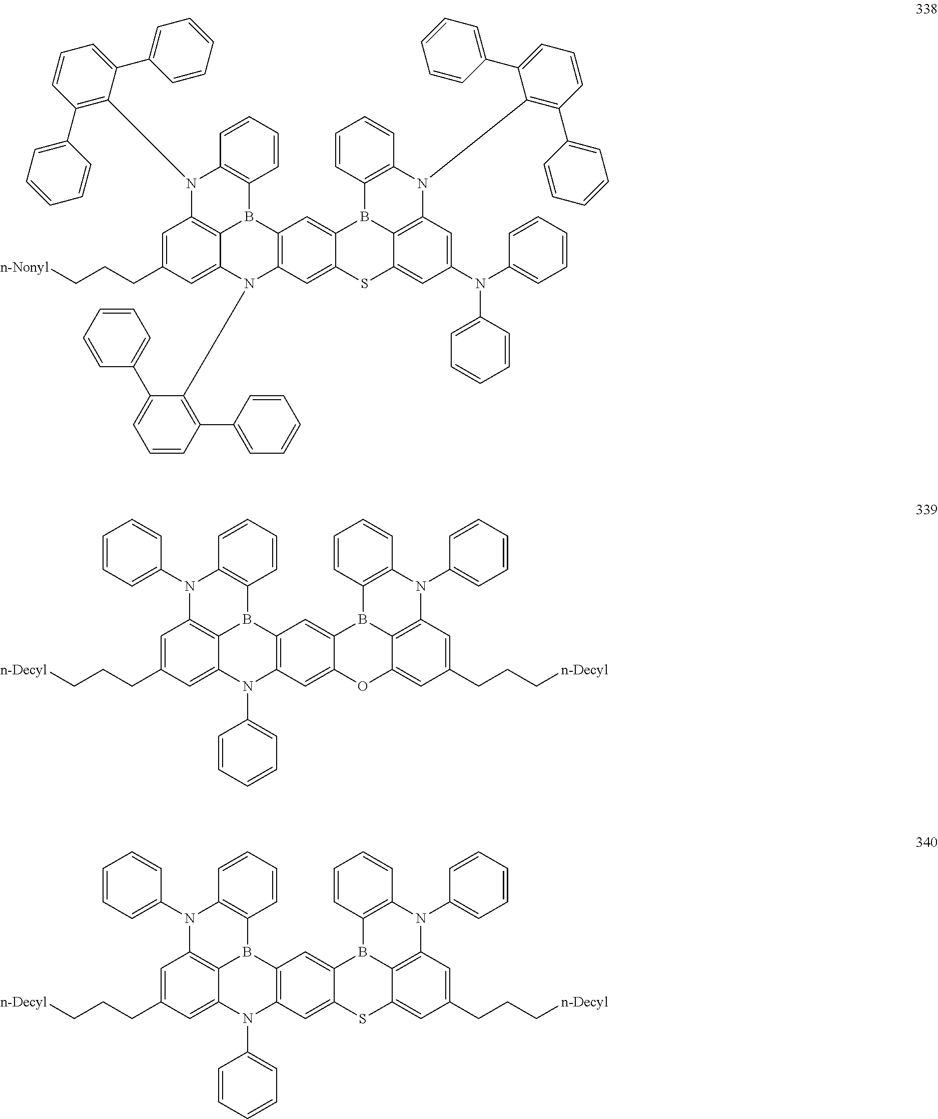 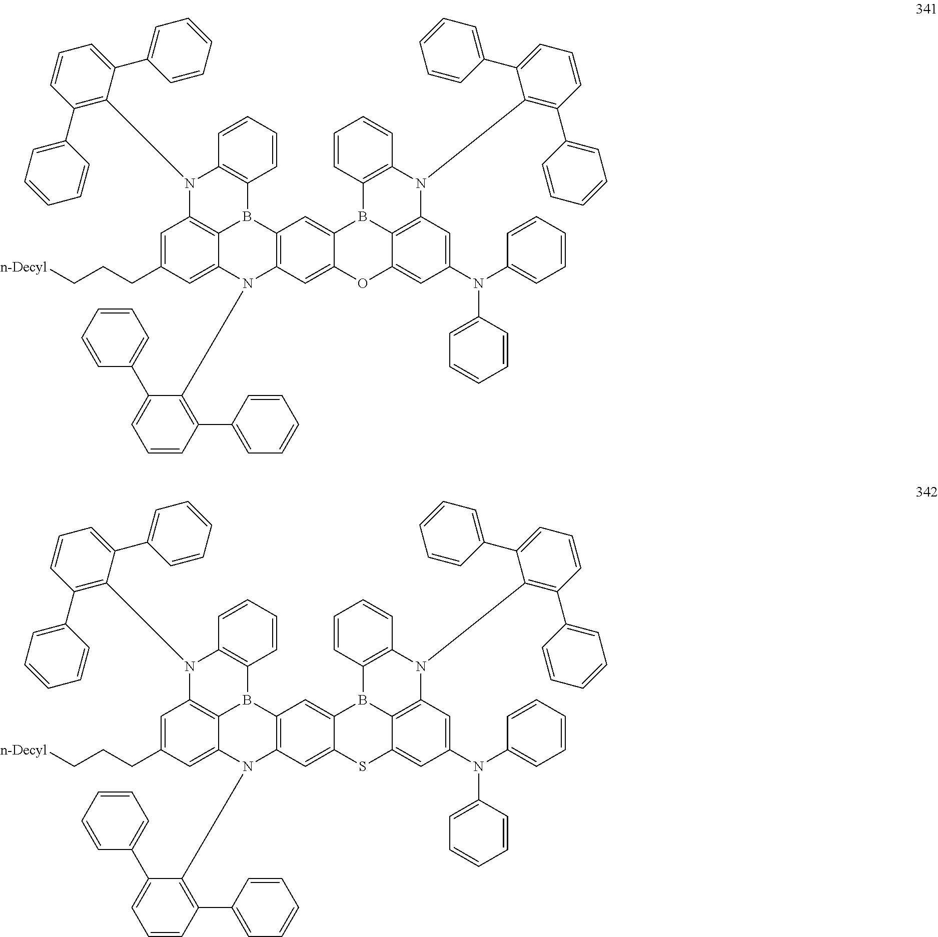 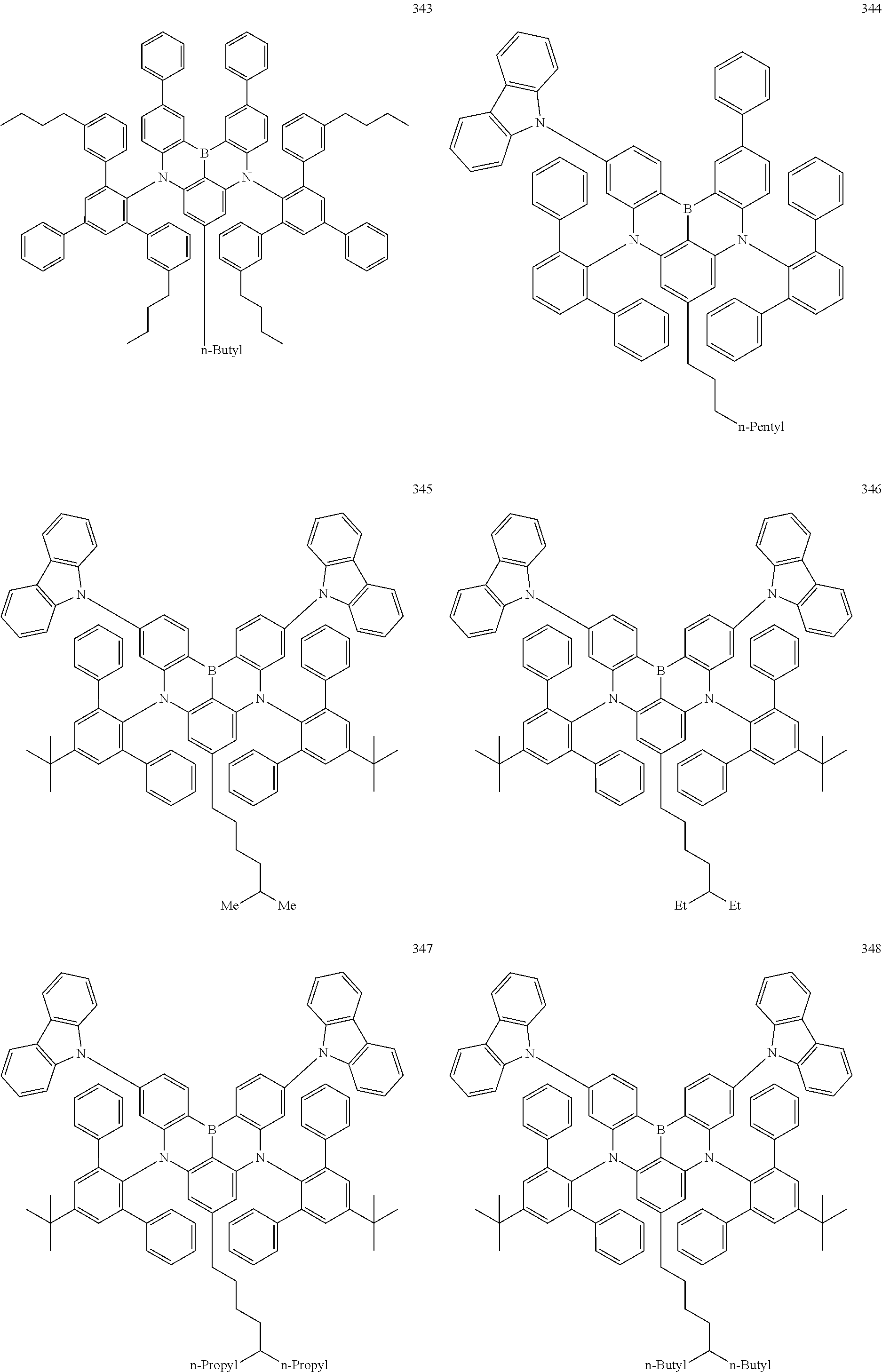 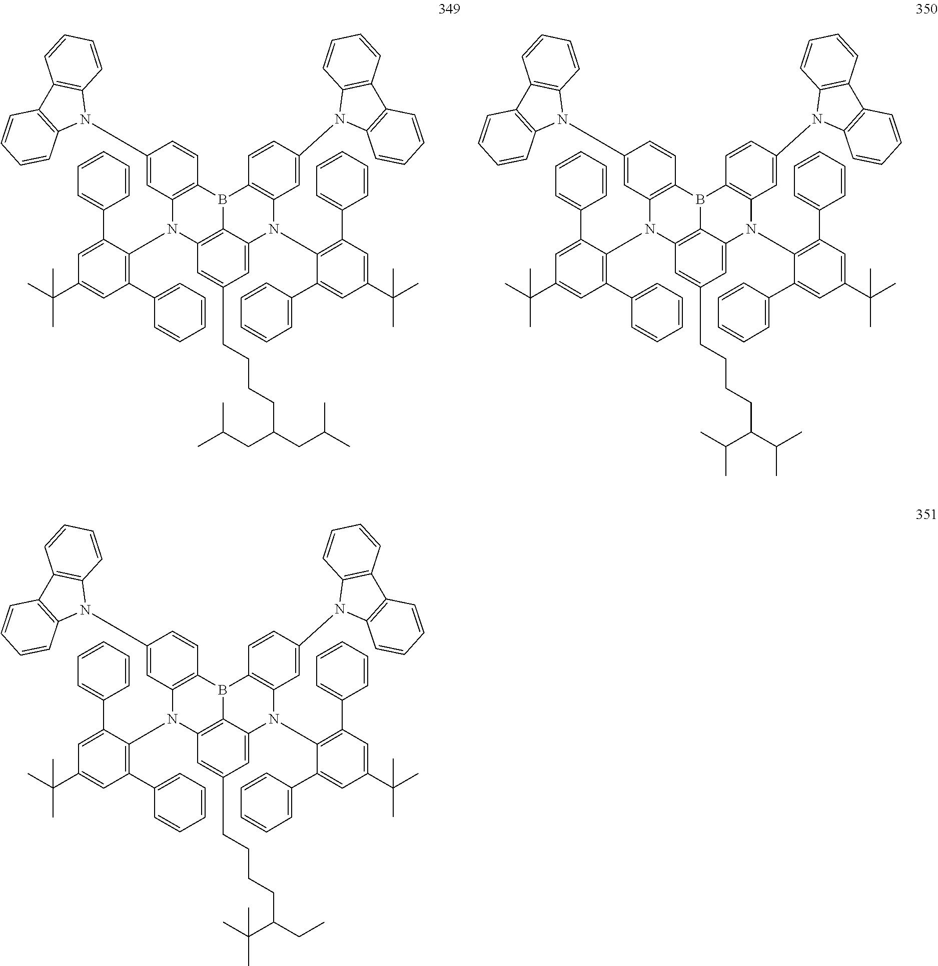 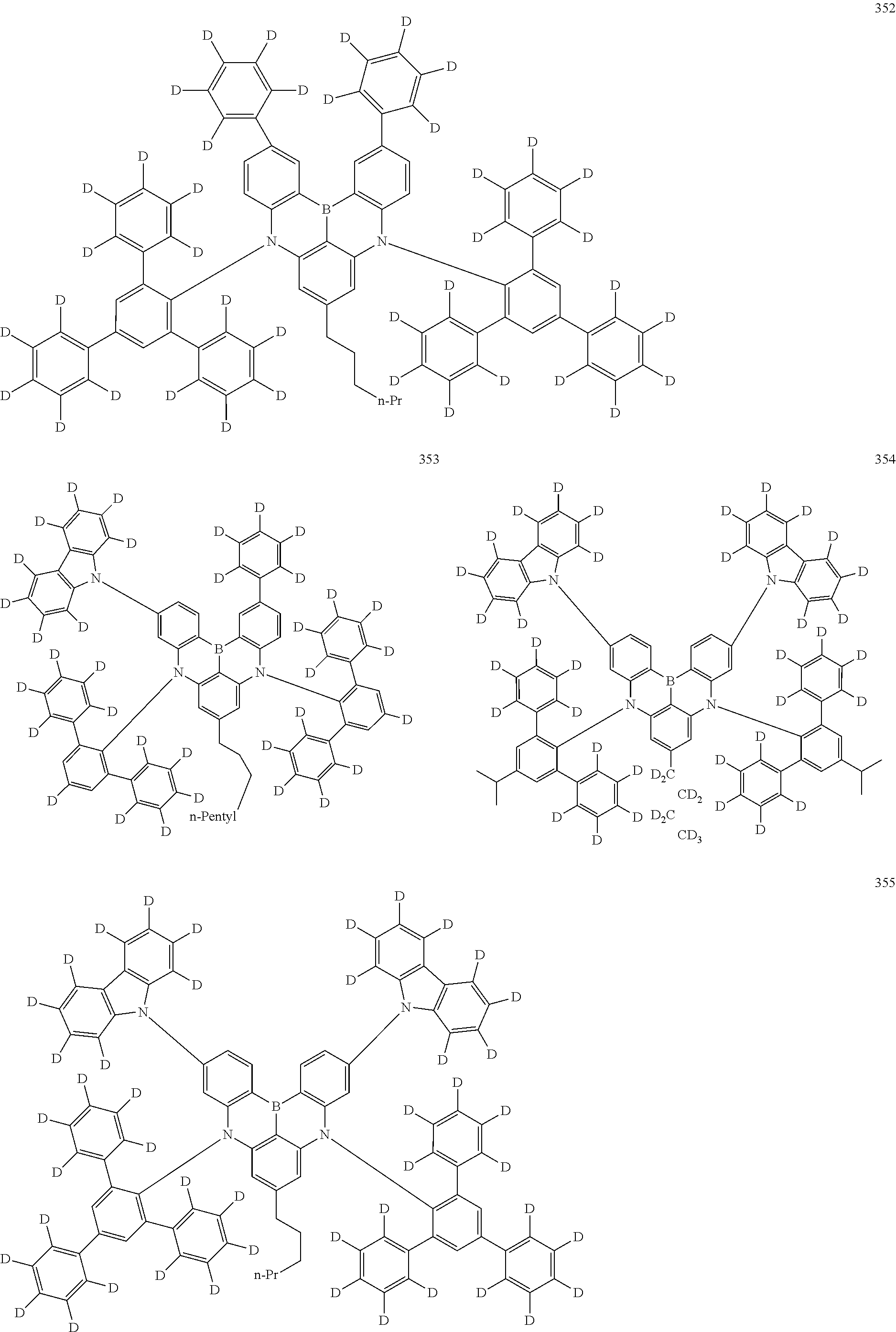 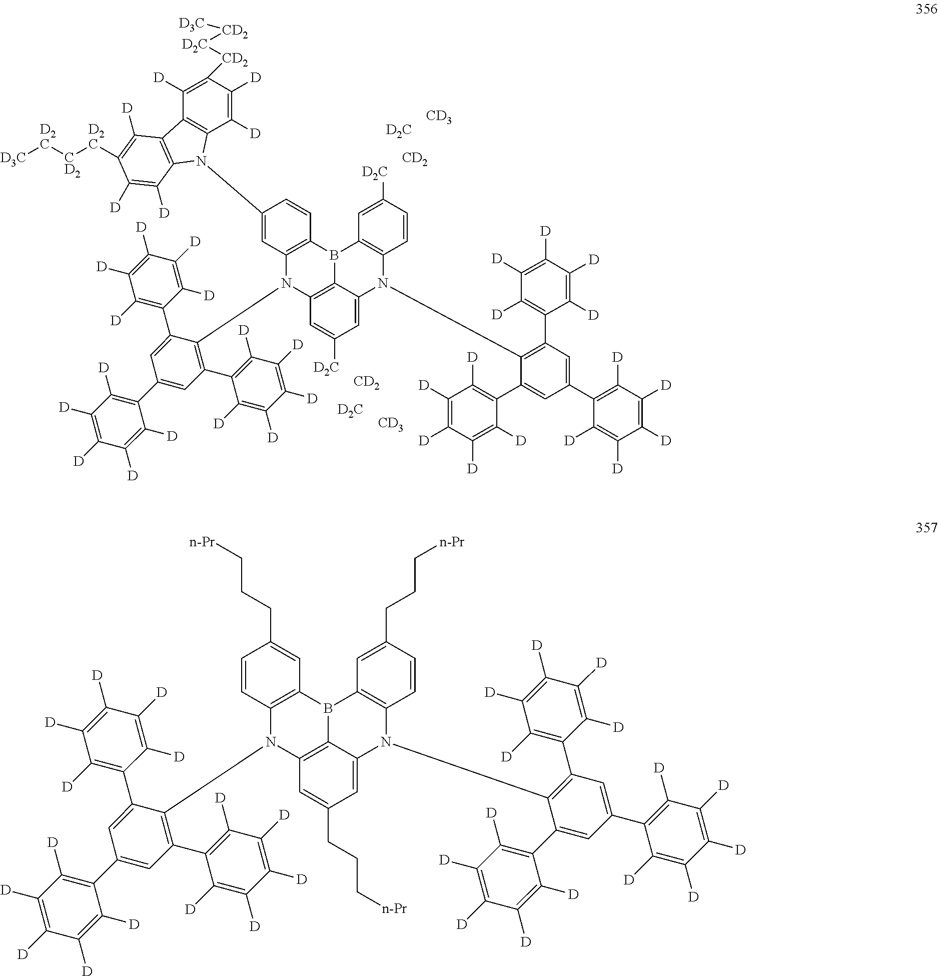 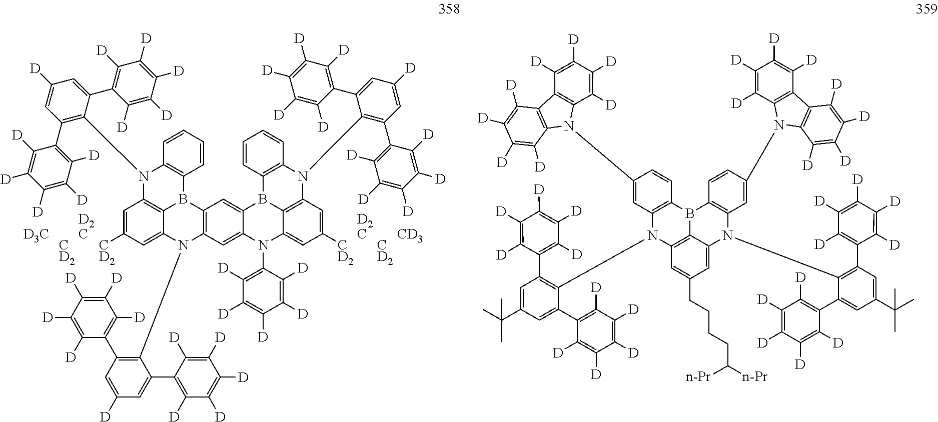 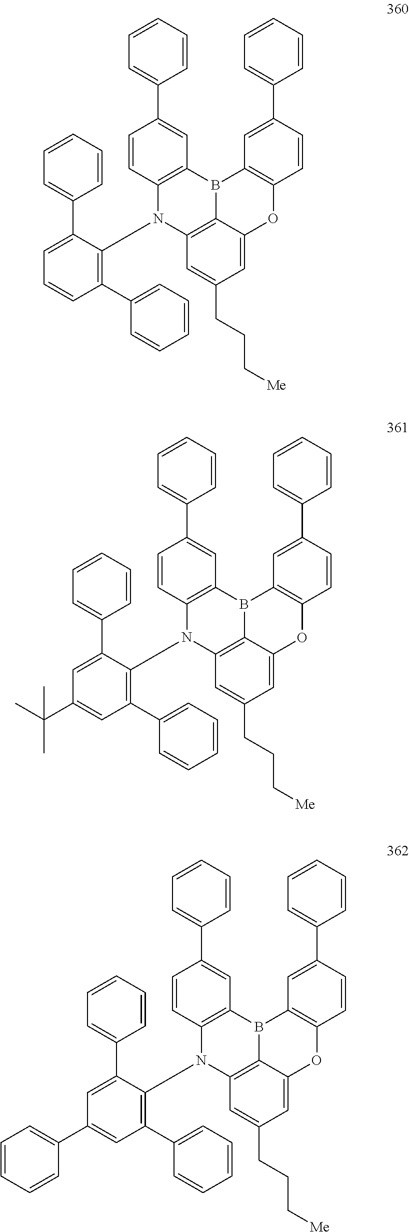 [SMILES: CCCCc1cc2c3c(c1)N(c1c(-c4ccccc4)cccc1-c1ccccc1)c1ccc(-c4ccccc4)cc1B3c1cc(-c3ccccc3)ccc1O2 ; CCCCc1cc2c3c(c1)N(c1c(-c4ccccc4)cc(C(C)(C)C)cc1-c1ccccc1)c1ccc(-c4ccccc4)cc1B3c1cc(-c3ccccc3)ccc1O2 ; CCCCc1cc2c3c(c1)N(c1c(-c4ccccc4)cc(-c4ccccc4)cc1-c1ccccc1)c1ccc(-c4ccccc4)cc1B3c1cc(-c3ccccc3)ccc1O2] 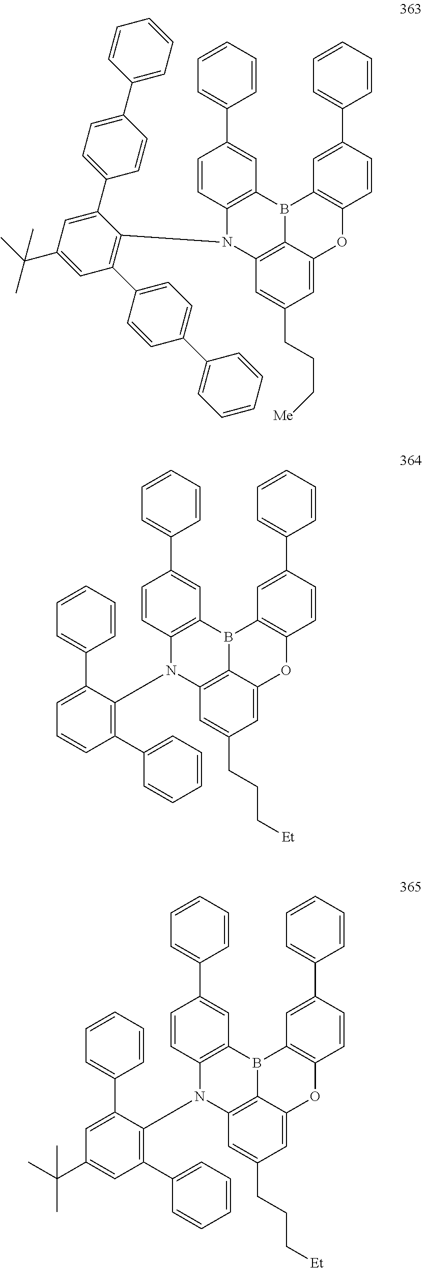 [SMILES: CCCCc1cc2c3c(c1)N(c1c(-c4ccc(-c5ccccc5)cc4)cc(C(C)(C)C)cc1-c1ccc(-c4ccccc4)cc1)c1ccc(-c4ccccc4)cc1B3c1cc(-c3ccccc3)ccc1O2 ; CCCCCc1cc2c3c(c1)N(c1c(-c4ccccc4)cccc1-c1ccccc1)c1ccc(-c4ccccc4)cc1B3c1cc(-c3ccccc3)ccc1O2 ; CCCCCc1cc2c3c(c1)N(c1c(-c4ccccc4)cc(C(C)(C)C)cc1-c1ccccc1)c1ccc(-c4ccccc4)cc1B3c1cc(-c3ccccc3)ccc1O2] 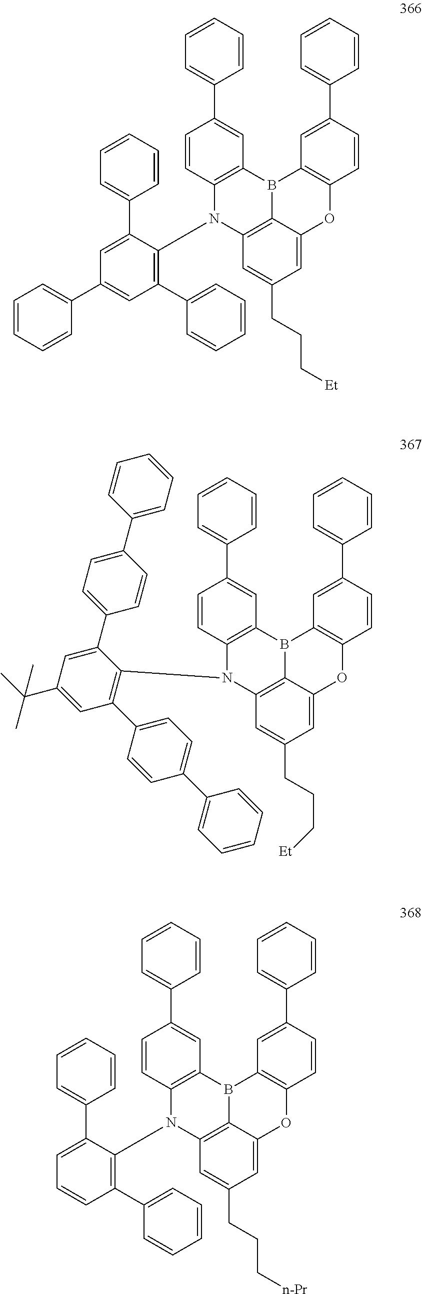 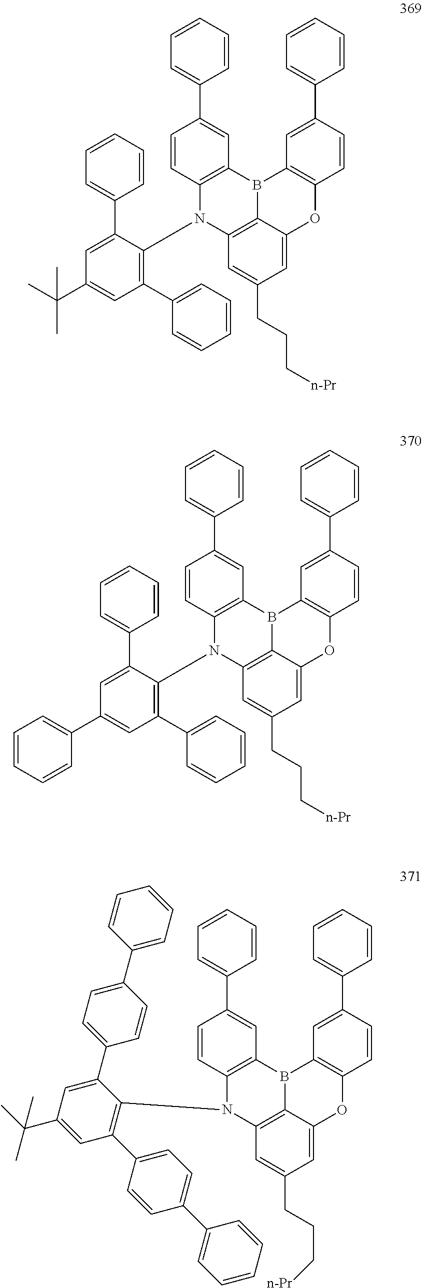 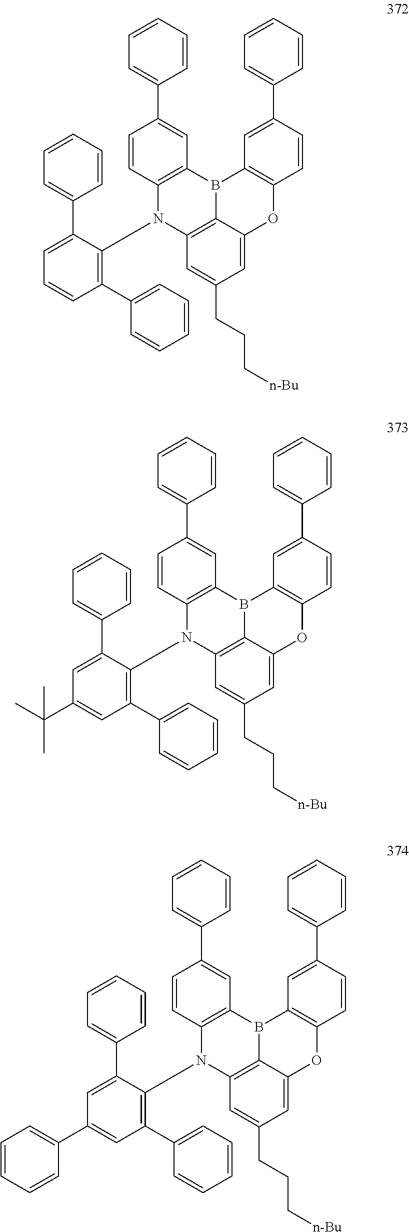 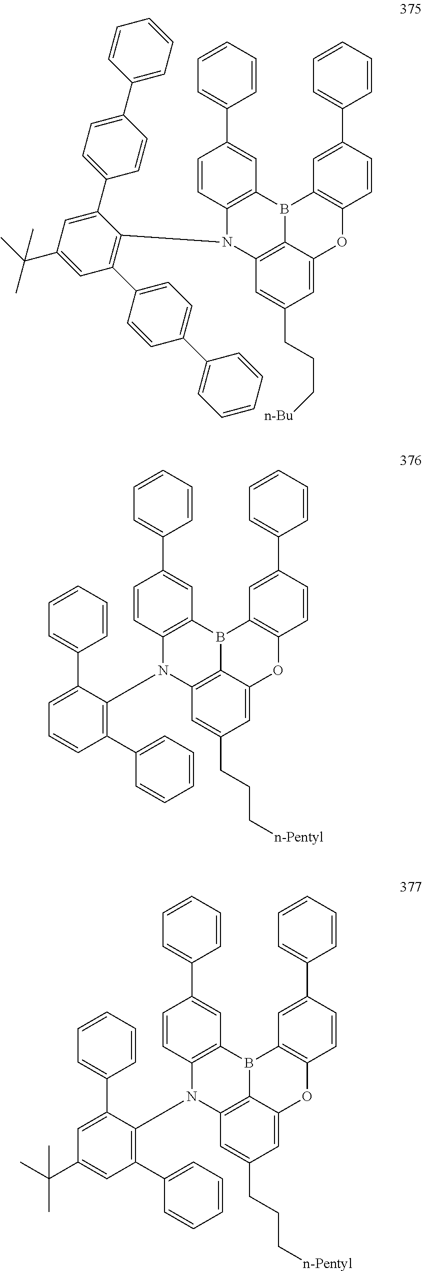 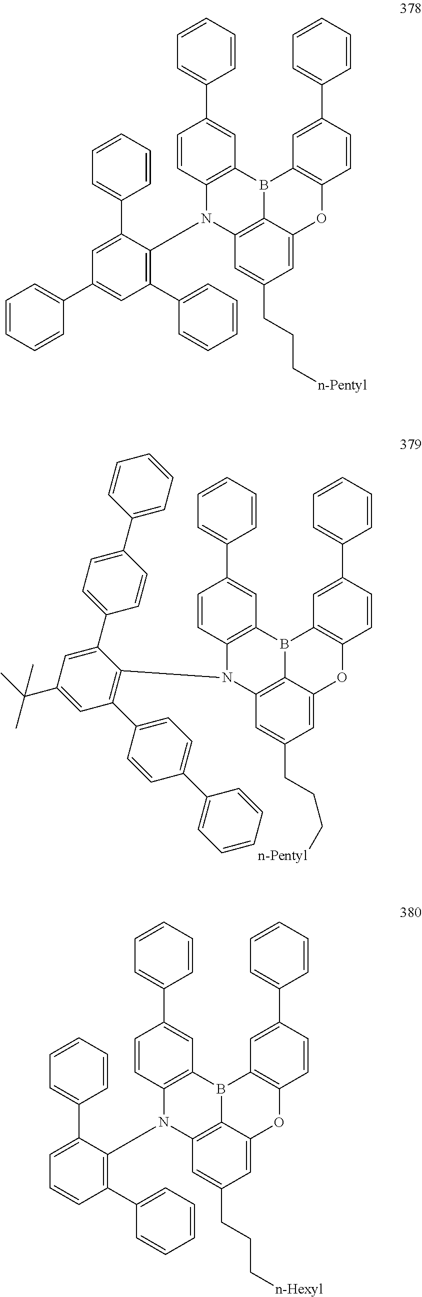 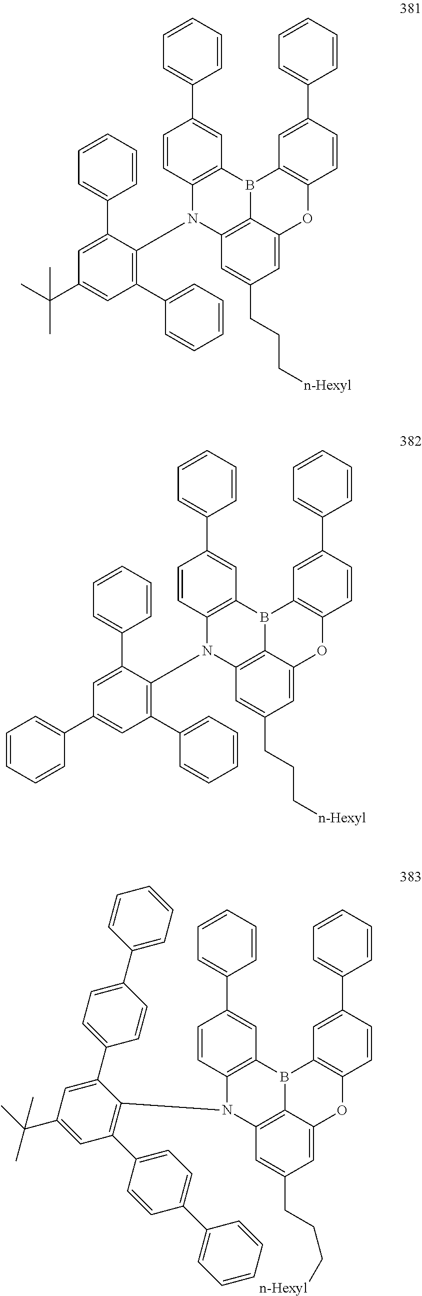 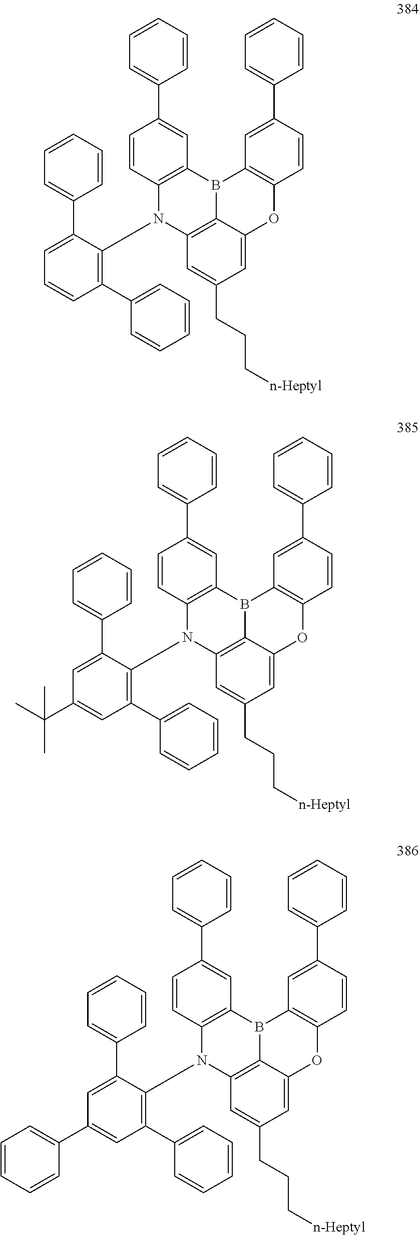 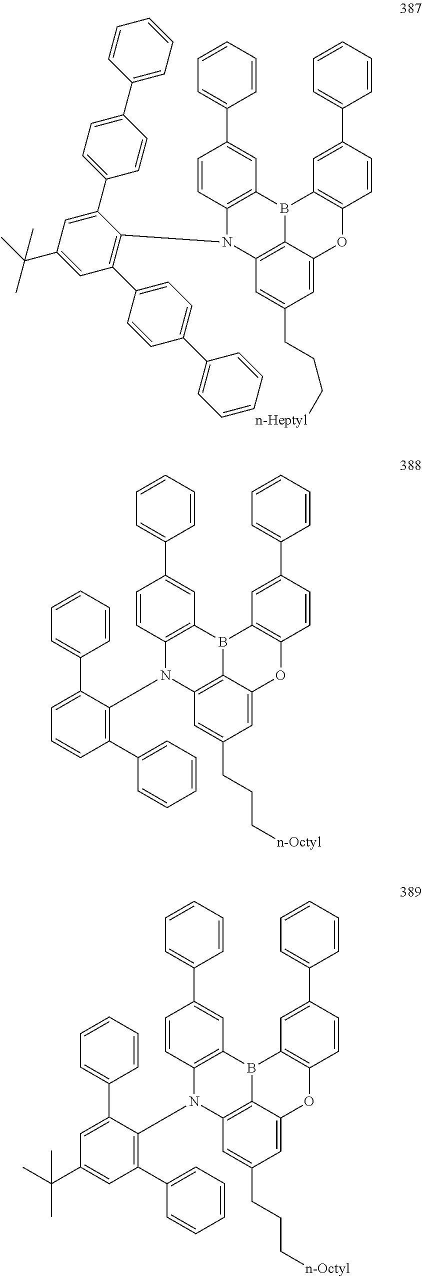 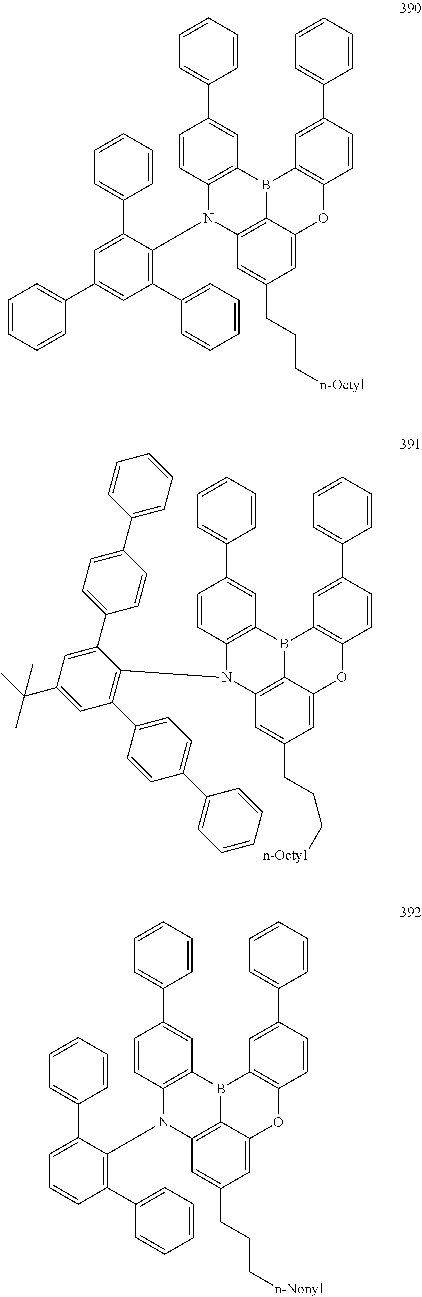 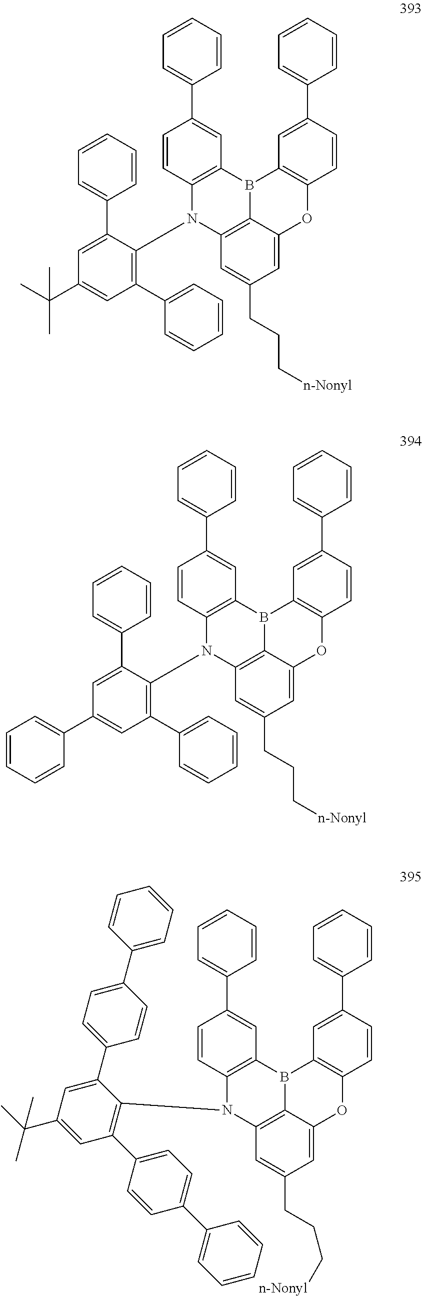 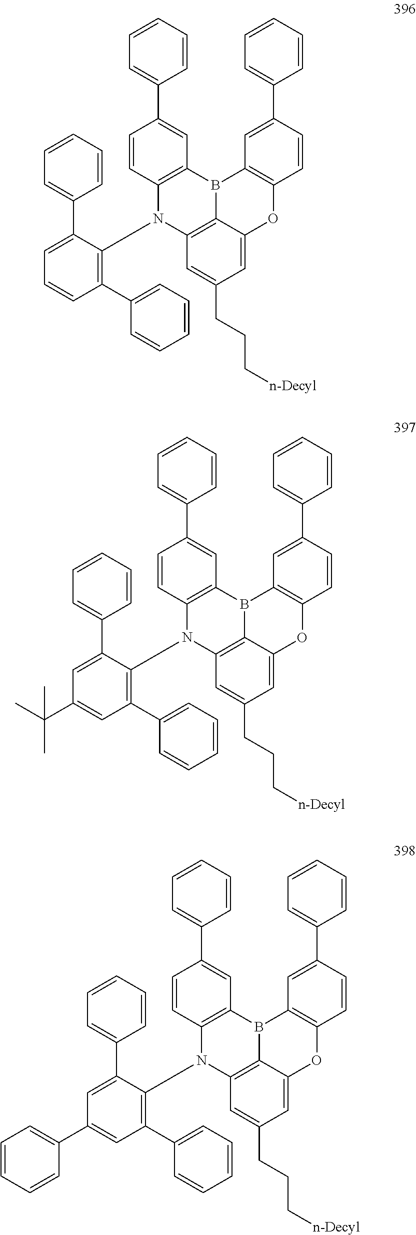 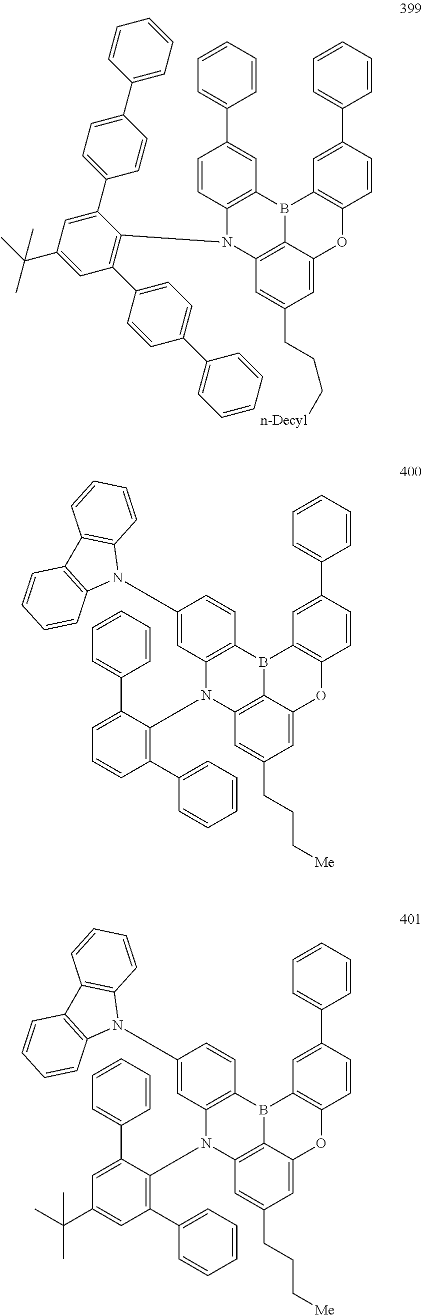 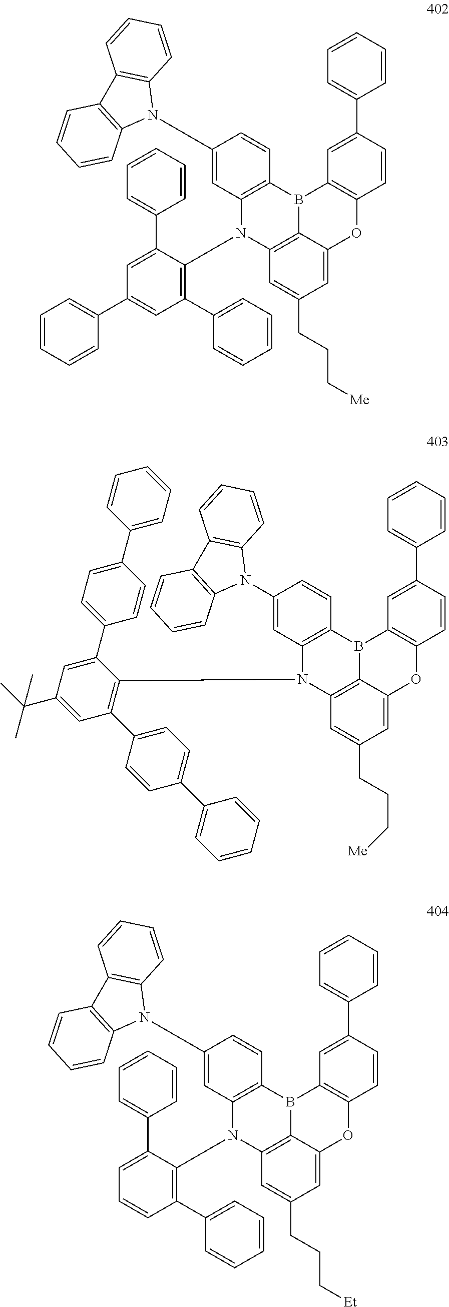 [SMILES: CCCCc1cc2c3c(c1)N(c1c(-c4ccccc4)cc(-c4ccccc4)cc1-c1ccccc1)c1cc(-n4c5ccccc5c5ccccc54)ccc1B3c1cc(-c3ccccc3)ccc1O2 ; CCCCc1cc2c3c(c1)N(c1c(-c4ccc(-c5ccccc5)cc4)cc(C(C)(C)C)cc1-c1ccc(-c4ccccc4)cc1)c1cc(-n4c5ccccc5c5ccccc54)ccc1B3c1cc(-c3ccccc3)ccc1O2 ; CCCCCc1cc2c3c(c1)N(c1c(-c4ccccc4)cccc1-c1ccccc1)c1cc(-n4c5ccccc5c5ccccc54)ccc1B3c1cc(-c3ccccc3)ccc1O2] 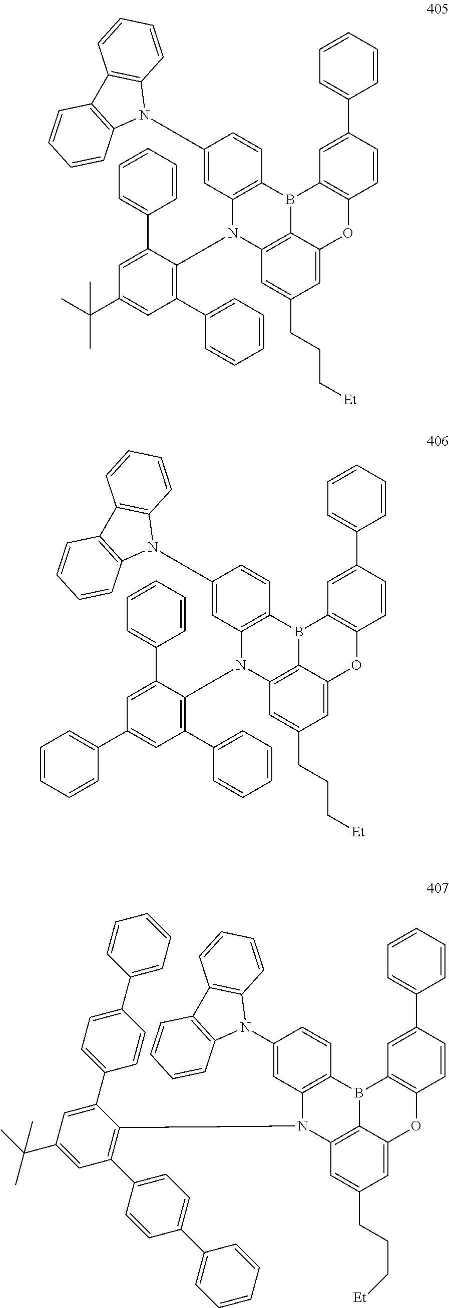 [SMILES: CCCCCc1cc2c3c(c1)N(c1c(-c4ccccc4)cc(C(C)(C)C)cc1-c1ccccc1)c1cc(-n4c5ccccc5c5ccccc54)ccc1B3c1cc(-c3ccccc3)ccc1O2 ; CCCCCc1cc2c3c(c1)N(c1c(-c4ccccc4)cc(-c4ccccc4)cc1-c1ccccc1)c1cc(-n4c5ccccc5c5ccccc54)ccc1B3c1cc(-c3ccccc3)ccc1O2 ; CCCCCc1cc2c3c(c1)N(c1c(-c4ccc(-c5ccccc5)cc4)cc(C(C)(C)C)cc1-c1ccc(-c4ccccc4)cc1)c1cc(-n4c5ccccc5c5ccccc54)ccc1B3c1cc(-c3ccccc3)ccc1O2] 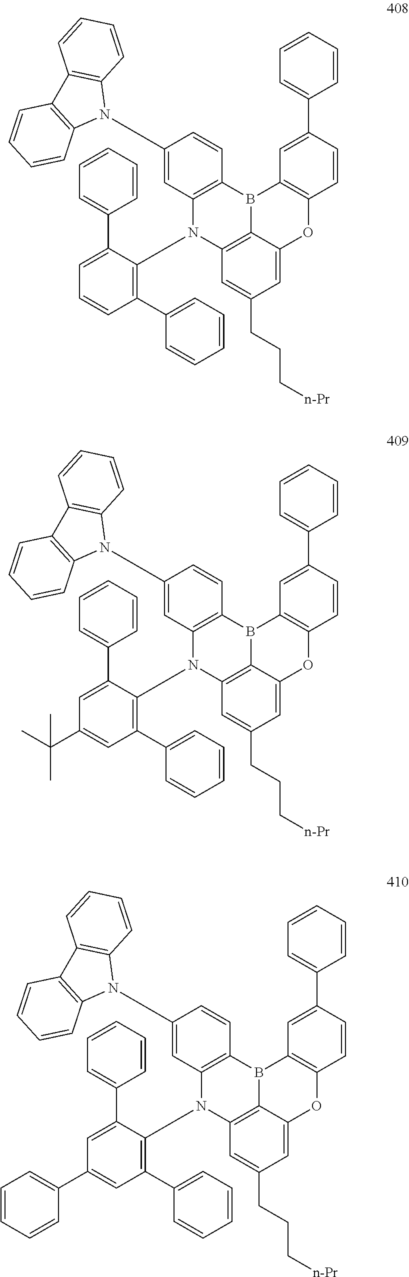 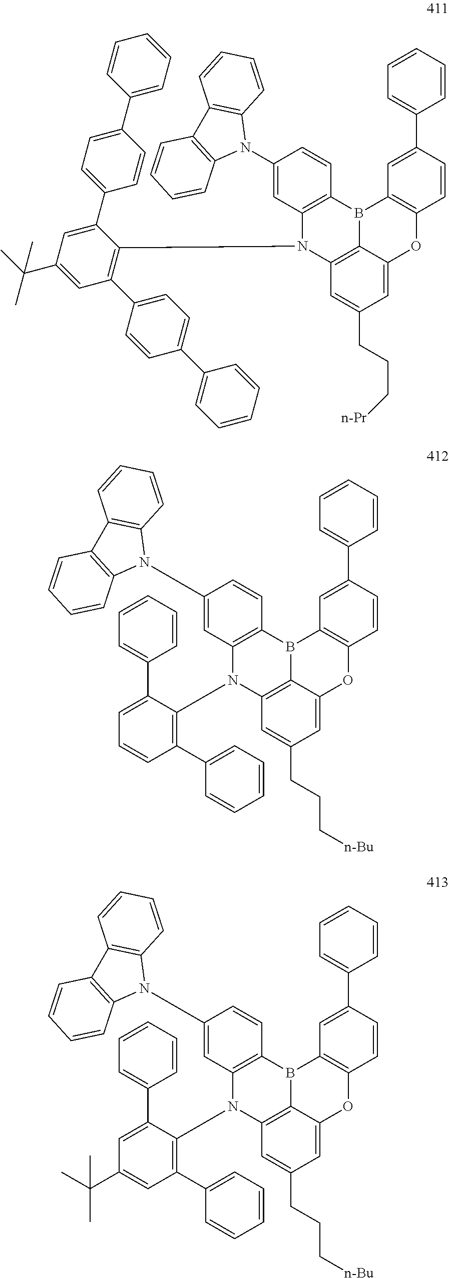 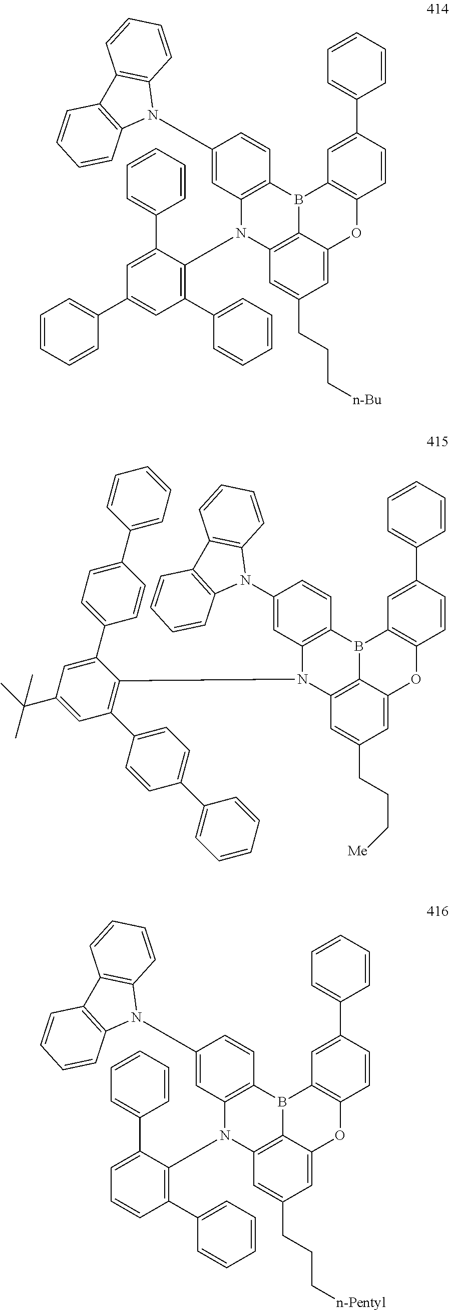 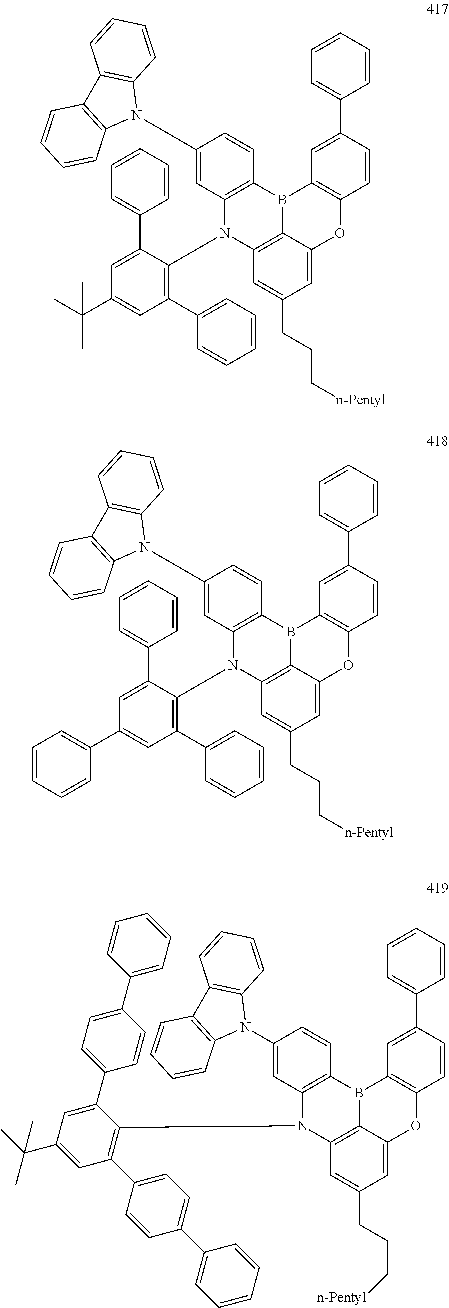 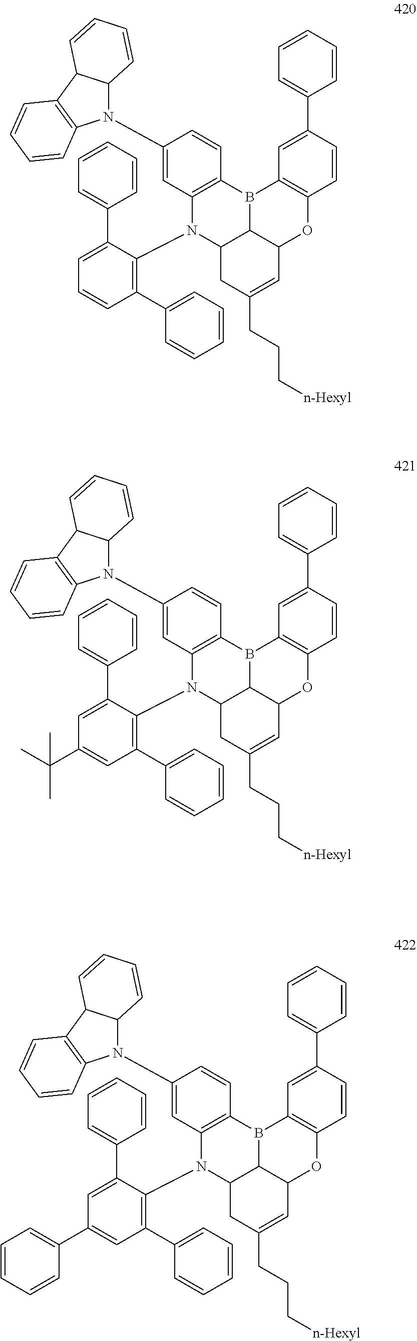 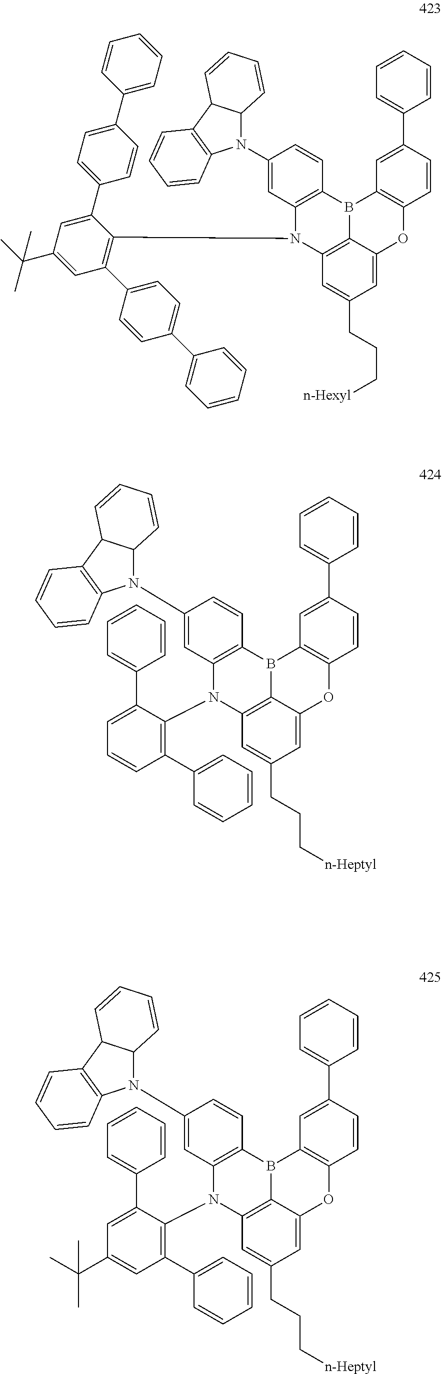 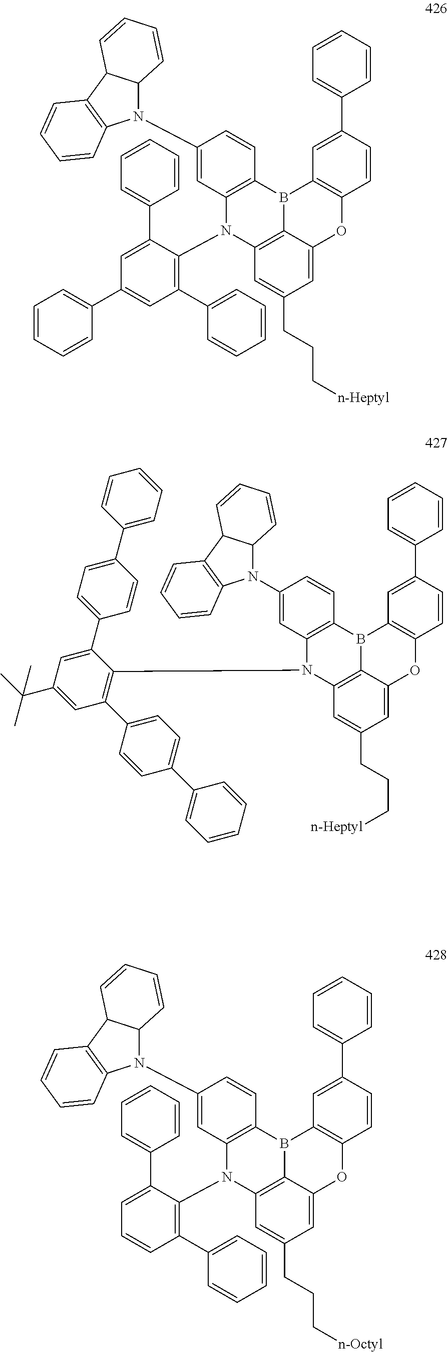 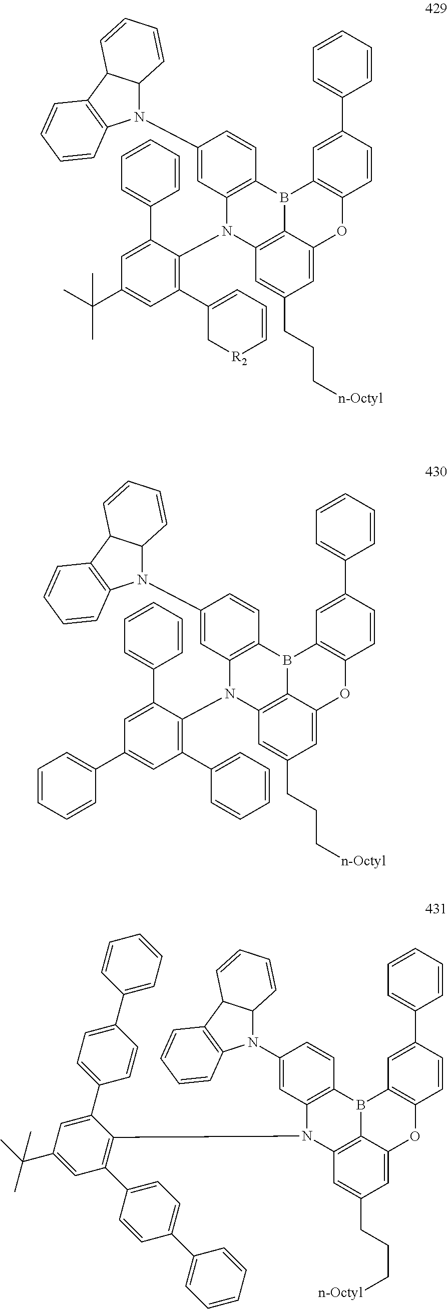 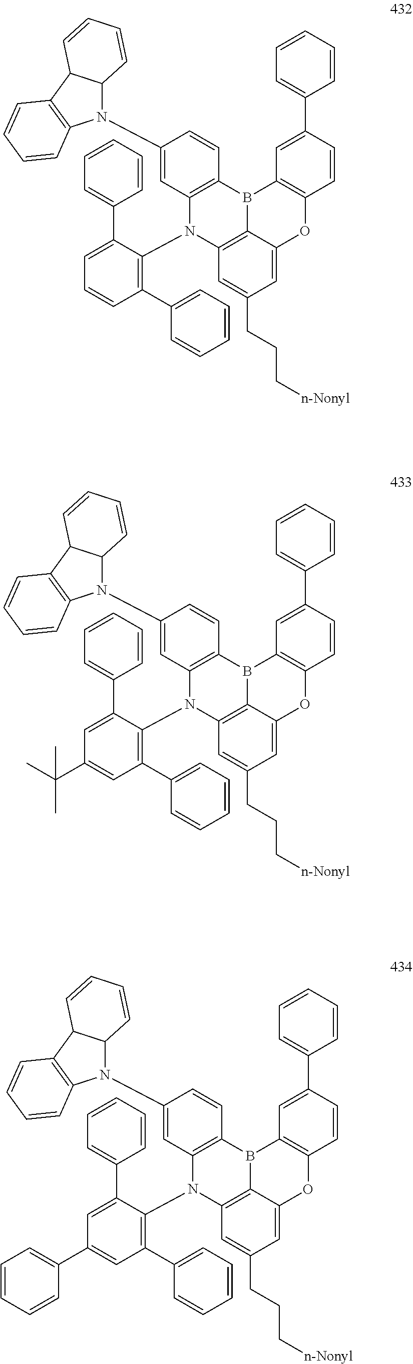 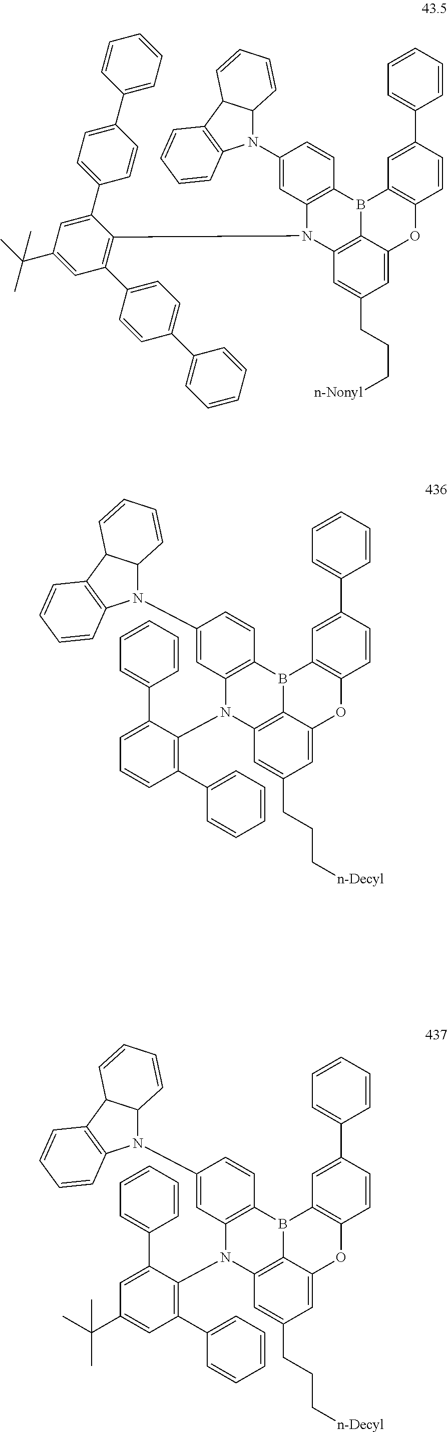 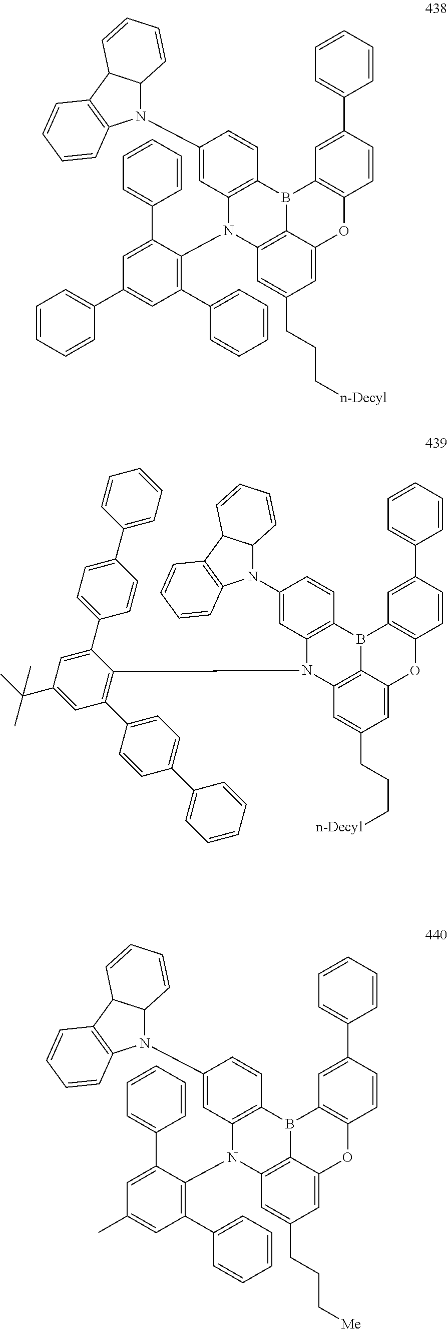 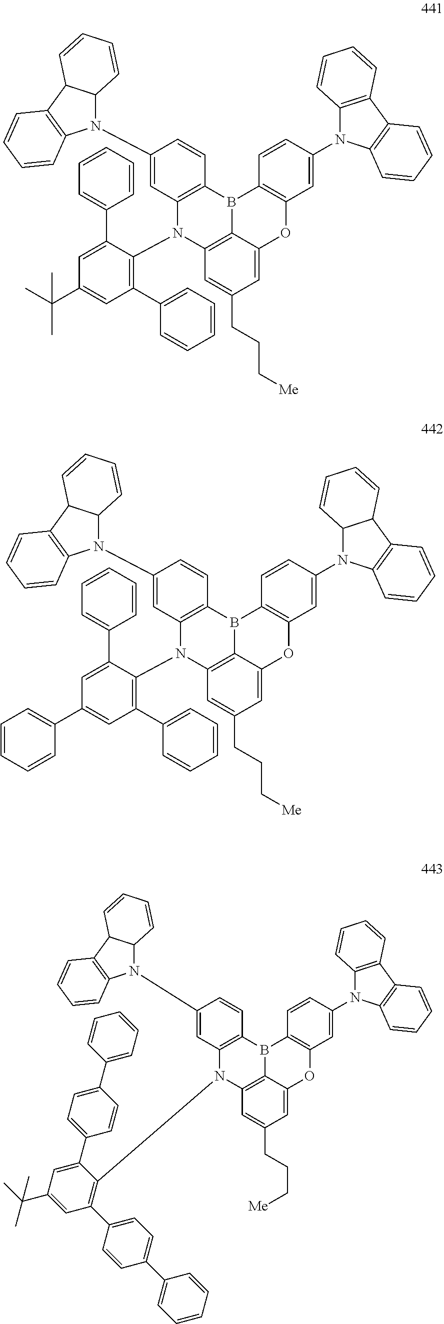 [SMILES: CCCCc1cc2c3c(c1)N(c1c(-c4ccccc4)cc(C(C)(C)C)cc1-c1ccccc1)c1cc(N4c5ccccc5C5C=CC=CC54)ccc1B3c1ccc(-n3c4ccccc4c4ccccc43)cc1O2 ; CCCCc1cc2c3c(c1)N(c1c(-c4ccccc4)cc(-c4ccccc4)cc1-c1ccccc1)c1cc(N4c5ccccc5C5C=CC=CC54)ccc1B3c1ccc(N3c4ccccc4C4C=CC=CC43)cc1O2 ; CCCCc1cc2c3c(c1)N(c1c(-c4ccc(-c5ccccc5)cc4)cc(C(C)(C)C)cc1-c1ccc(-c4ccccc4)cc1)c1cc(N4c5ccccc5C5C=CC=CC54)ccc1B3c1ccc(-n3c4ccccc4c4ccccc43)cc1O2] 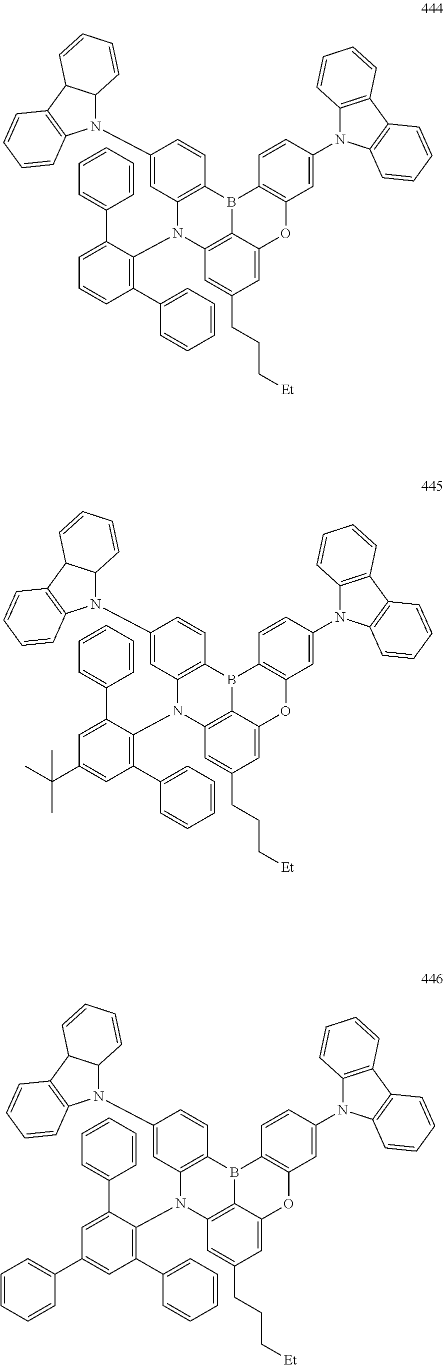 [SMILES: CCCCCc1cc2c3c(c1)N(c1c(-c4ccccc4)cccc1-c1ccccc1)c1cc(N4c5ccccc5C5C=CC=CC54)ccc1B3c1ccc(-n3c4ccccc4c4ccccc43)cc1O2 ; CCCCCc1cc2c3c(c1)N(c1c(-c4ccccc4)cc(C(C)(C)C)cc1-c1ccccc1)c1cc(N4c5ccccc5C5C=CC=CC54)ccc1B3c1ccc(-n3c4ccccc4c4ccccc43)cc1O2 ; CCCCCc1cc2c3c(c1)N(c1c(-c4ccccc4)cc(-c4ccccc4)cc1-c1ccccc1)c1cc(N4c5ccccc5C5C=CC=CC54)ccc1B3c1ccc(-n3c4ccccc4c4ccccc43)cc1O2] 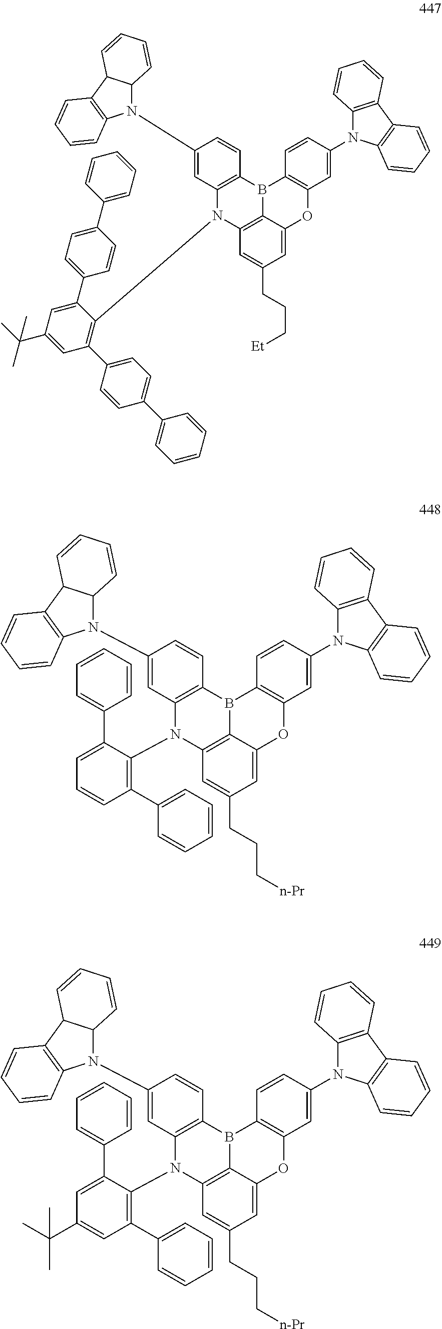 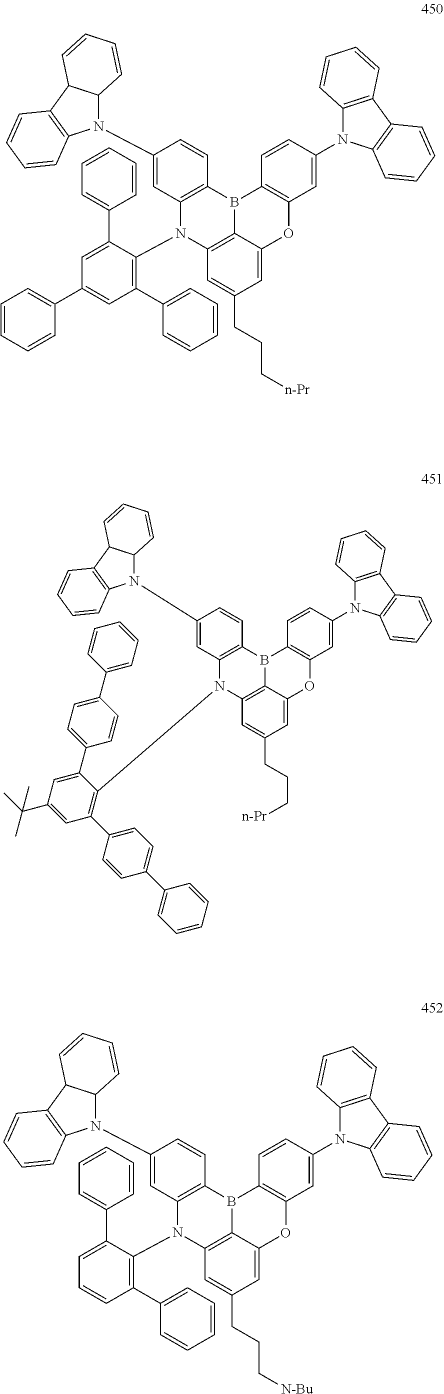 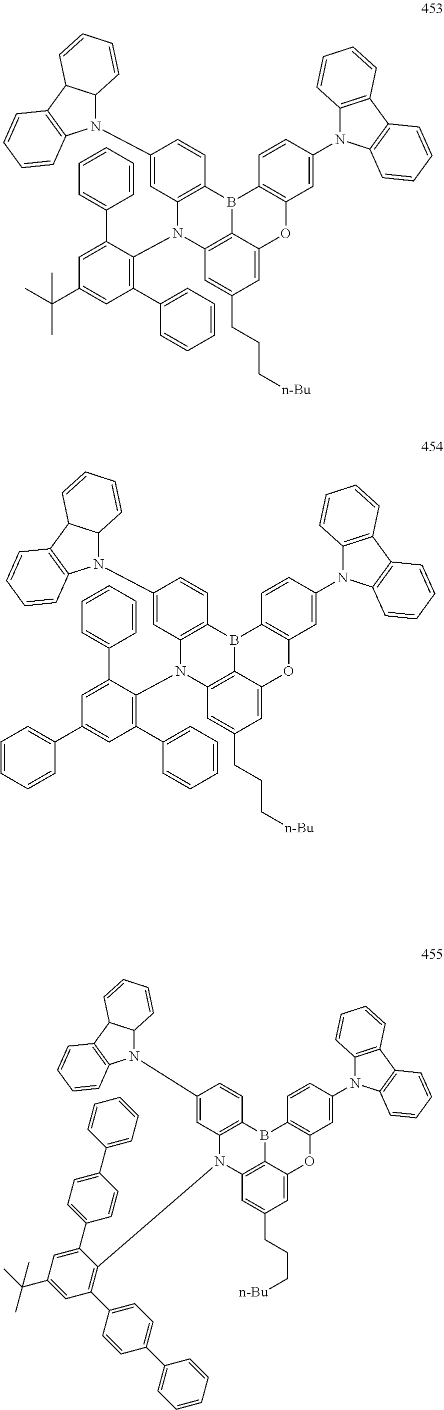 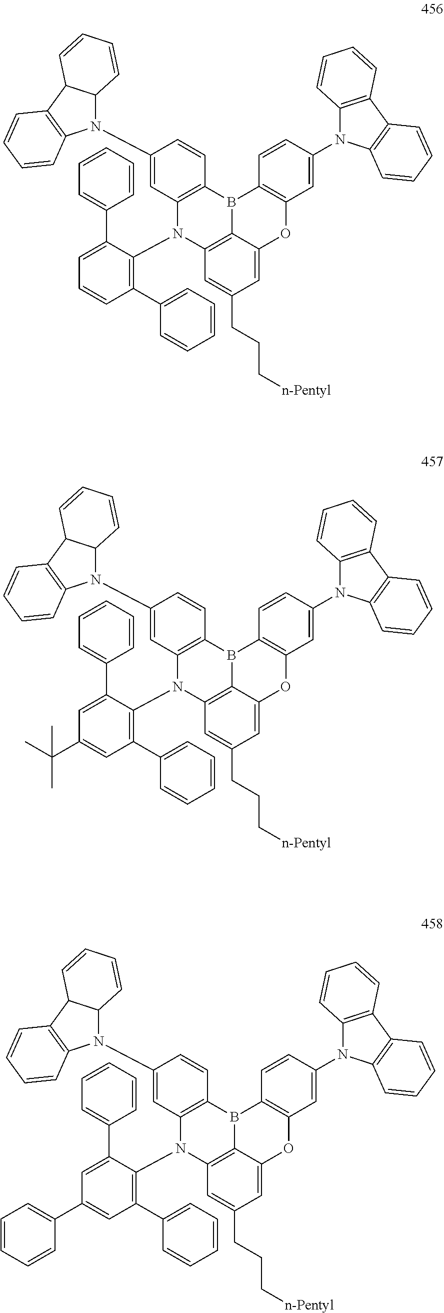 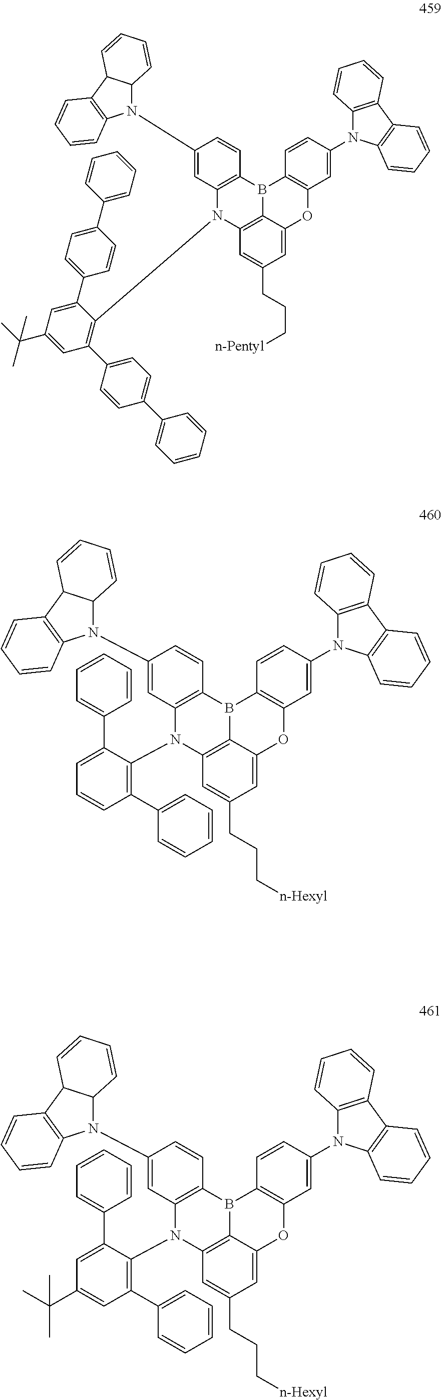 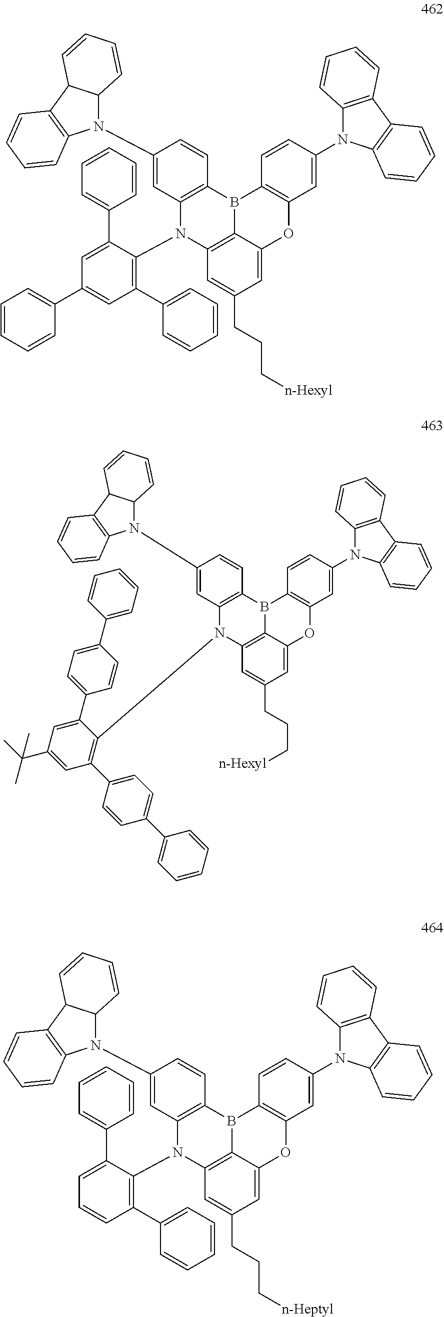 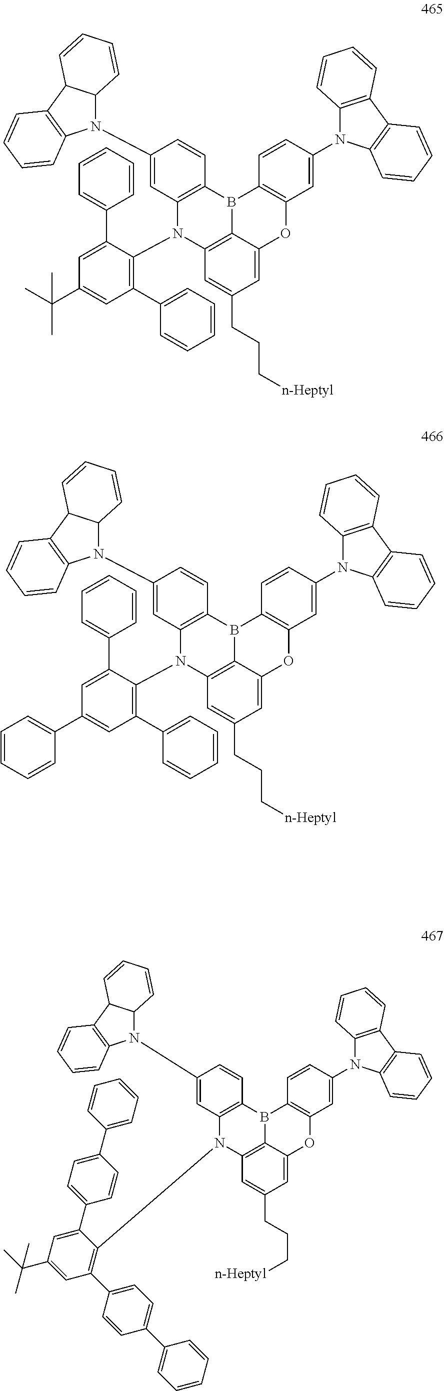 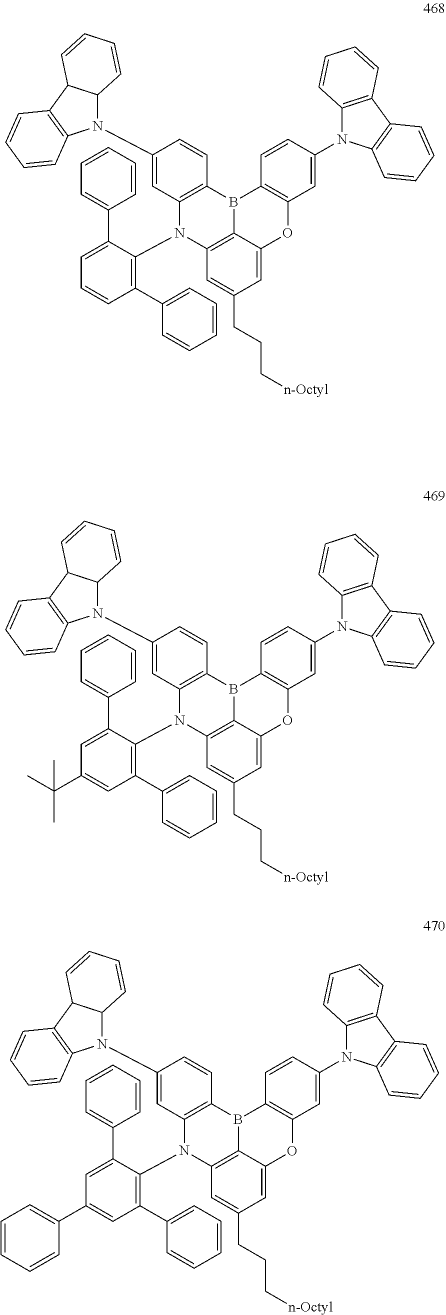 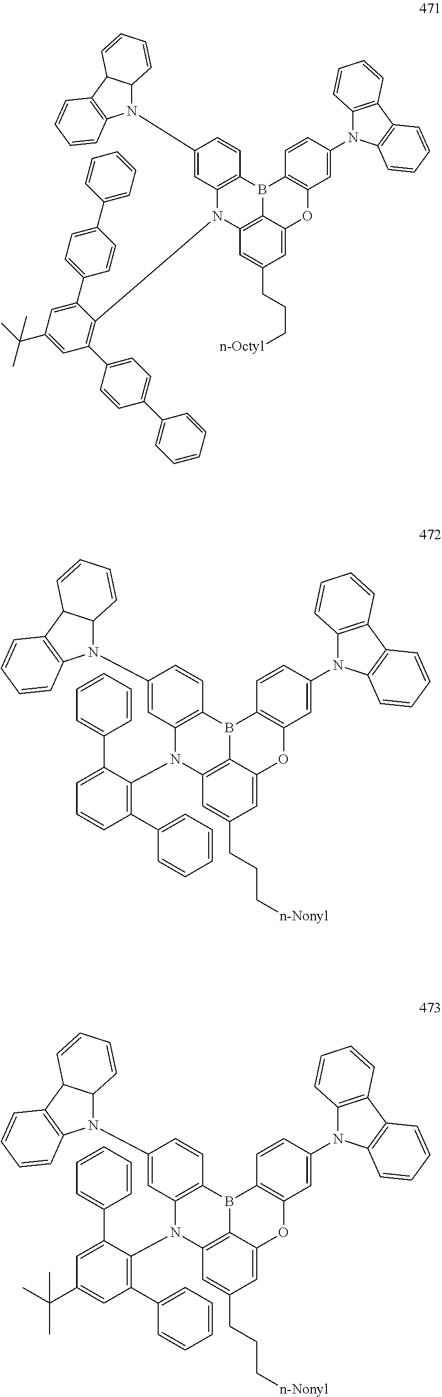 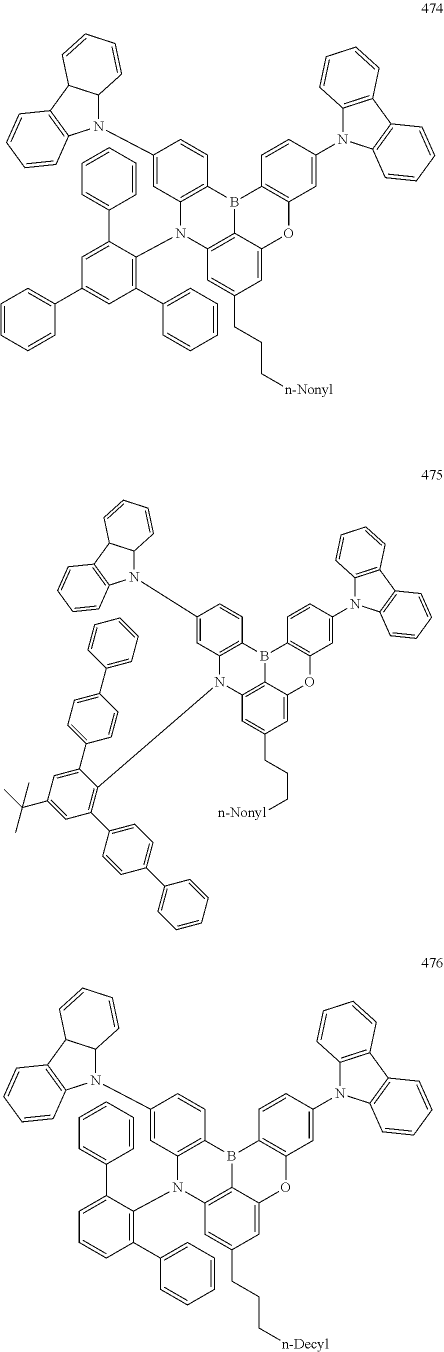 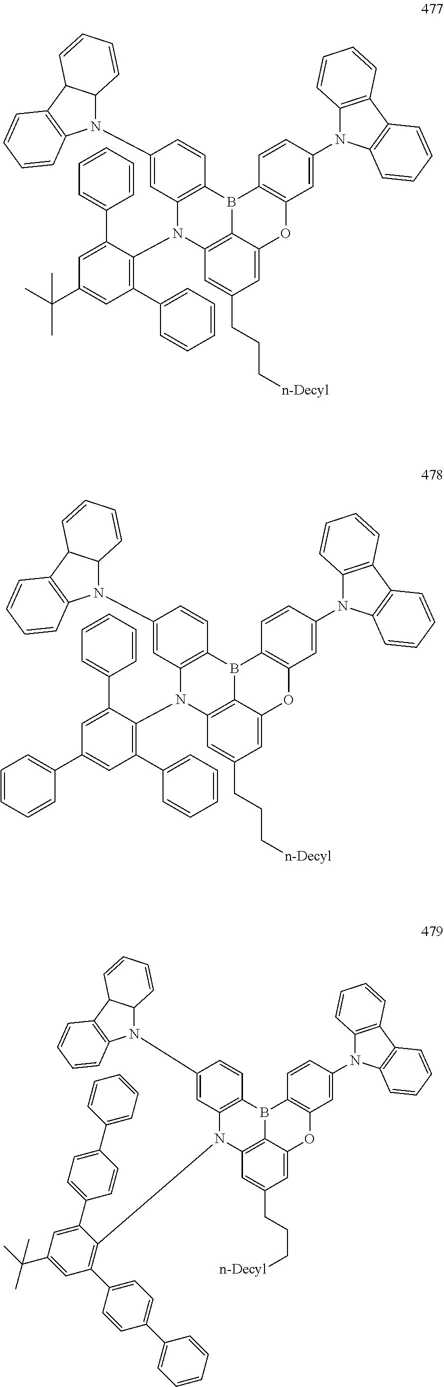 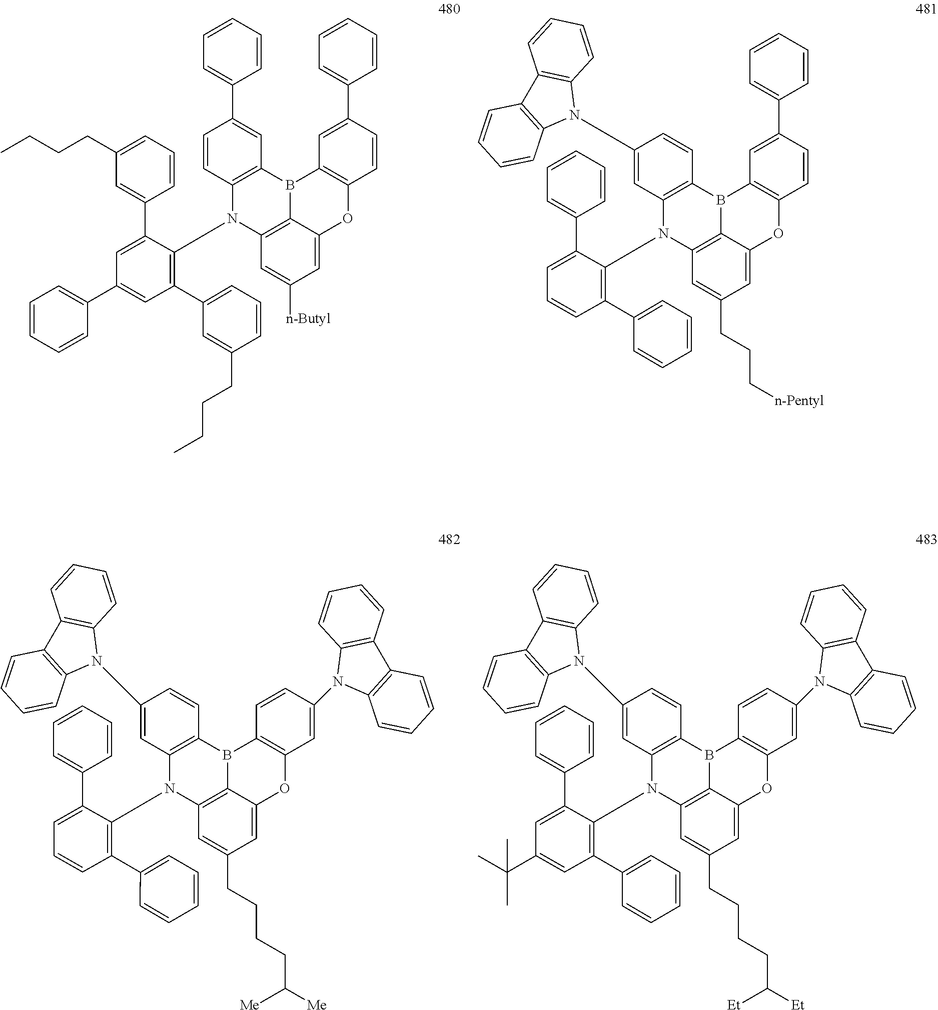 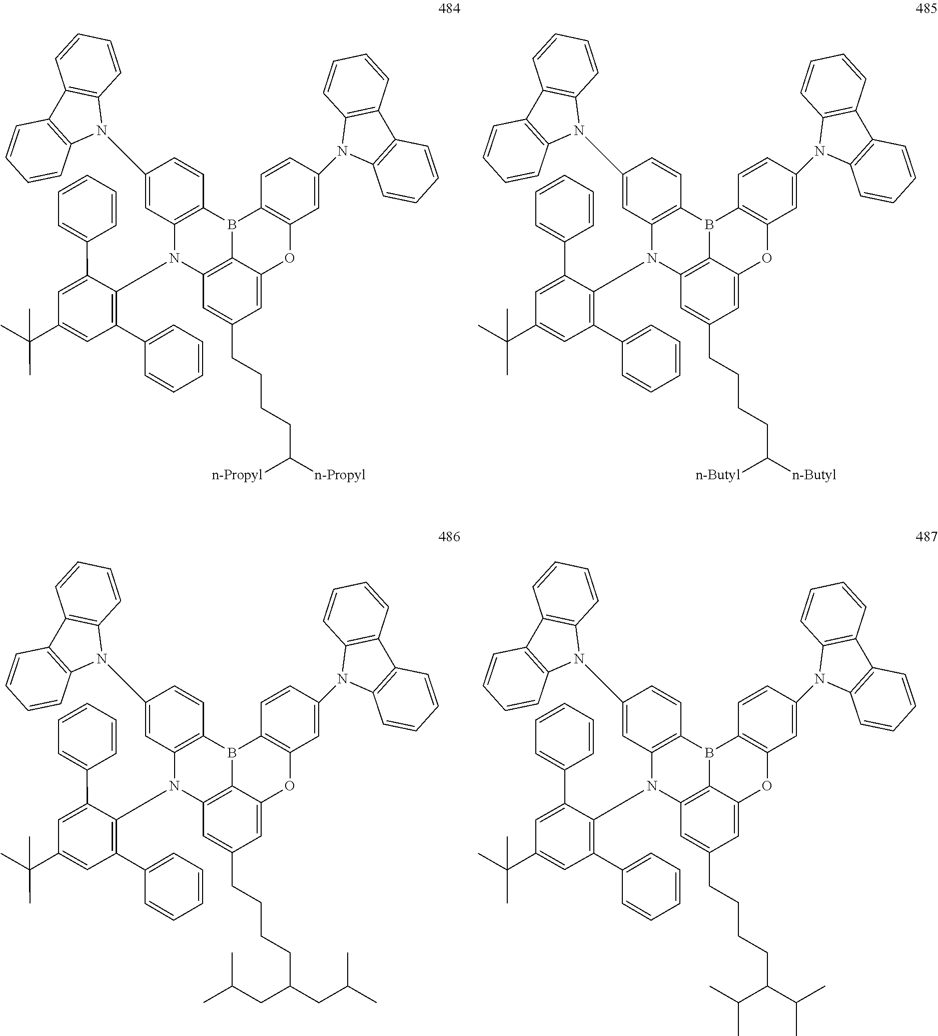 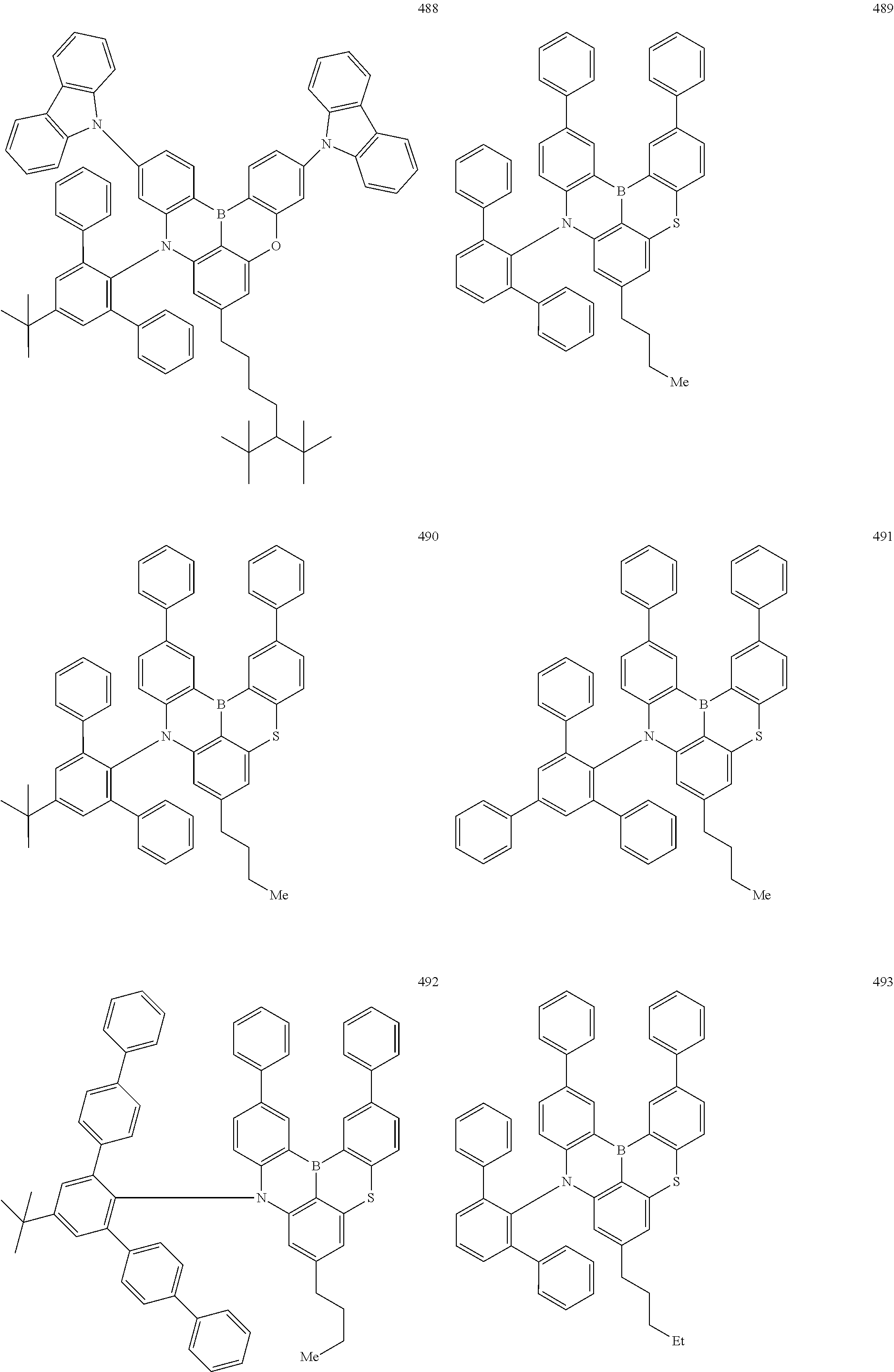 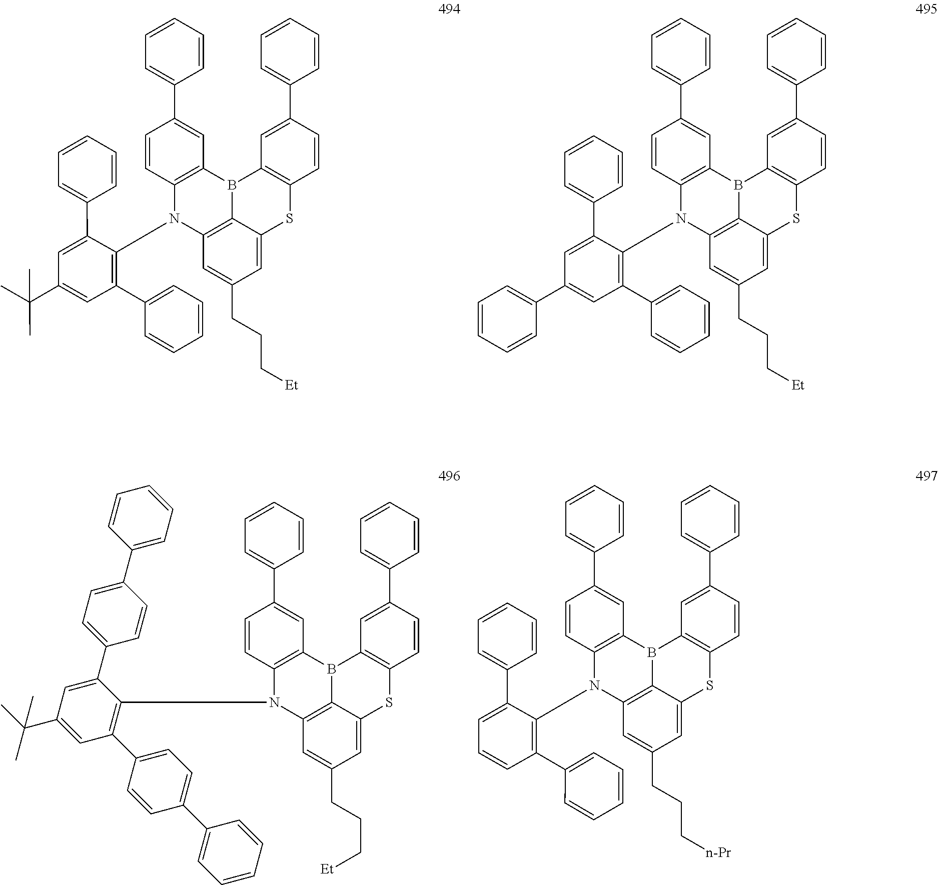 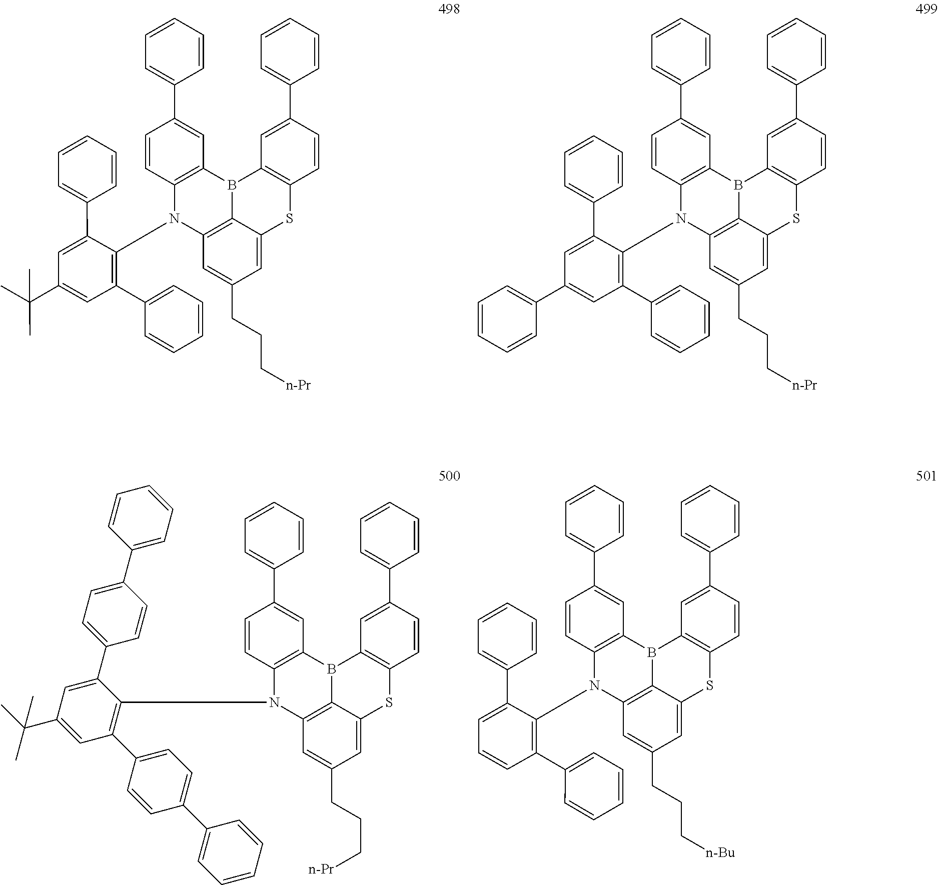 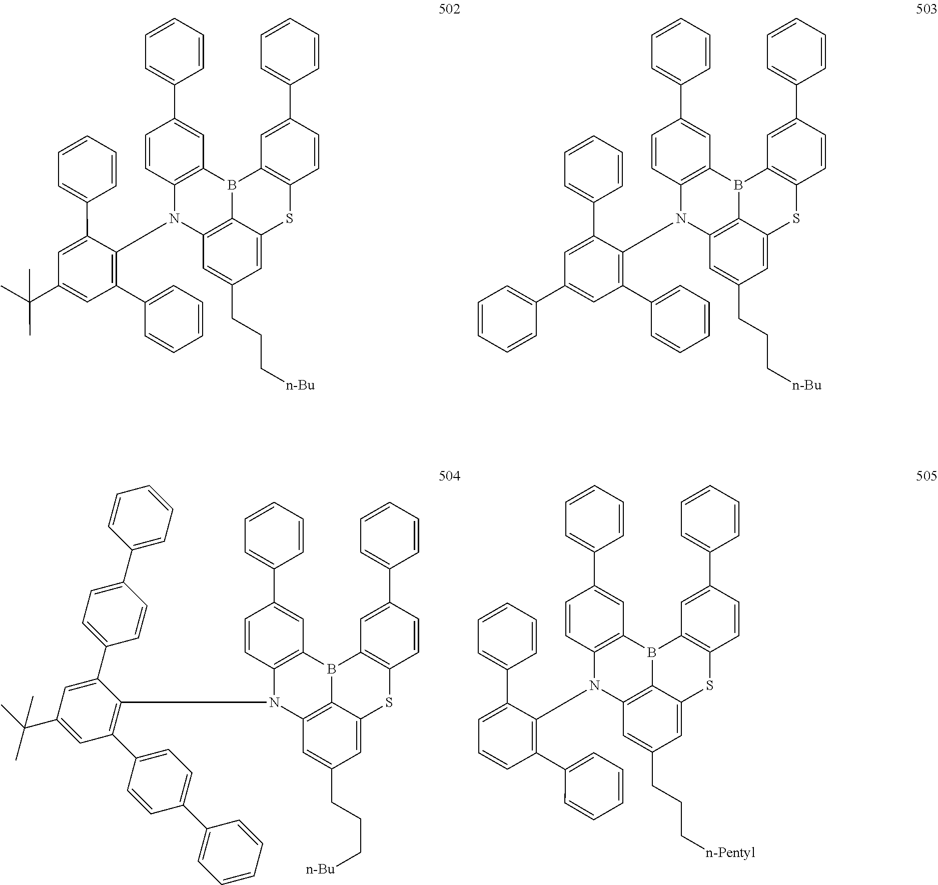 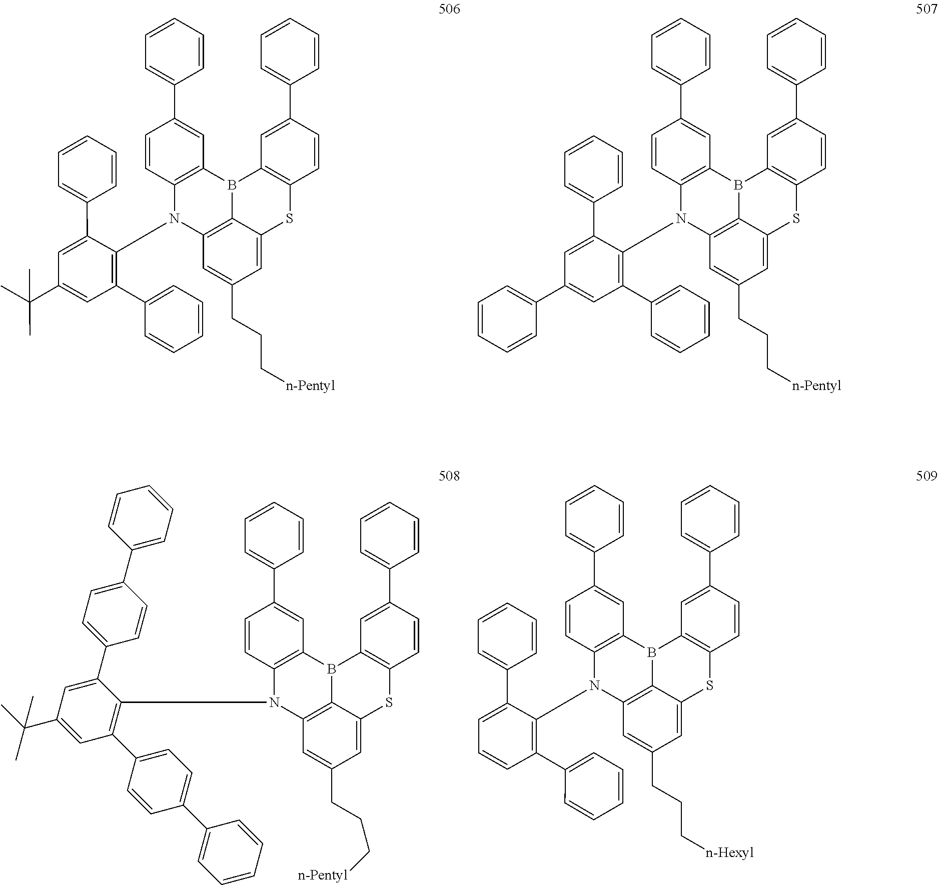 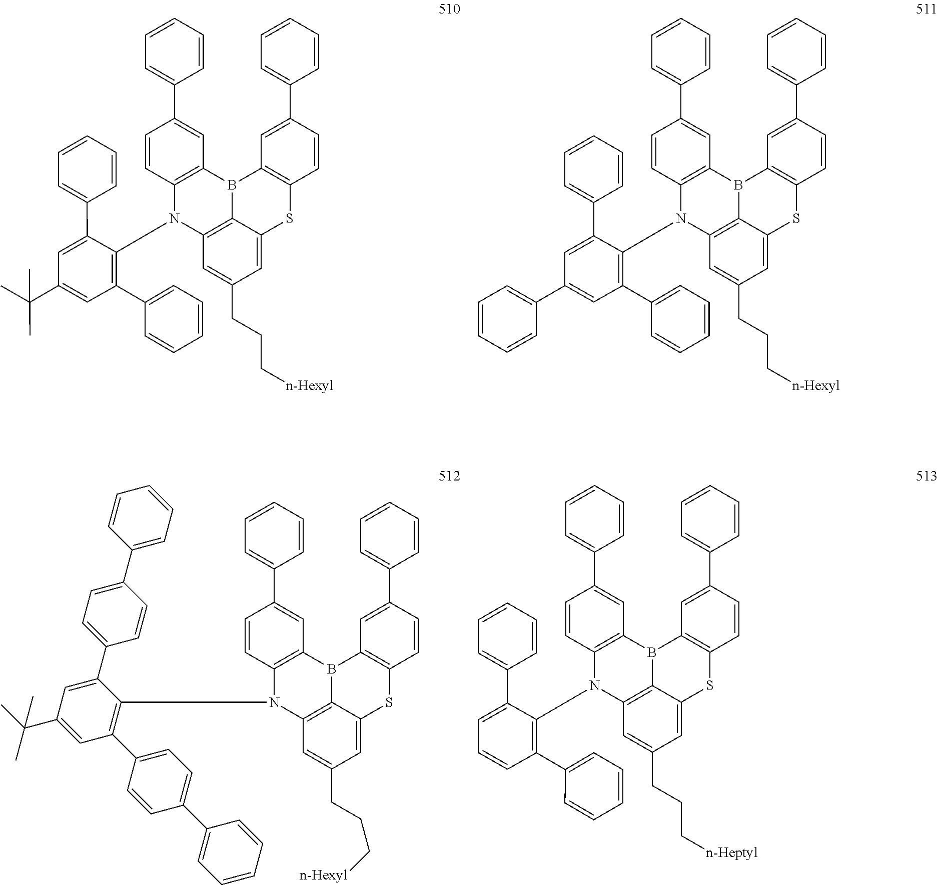 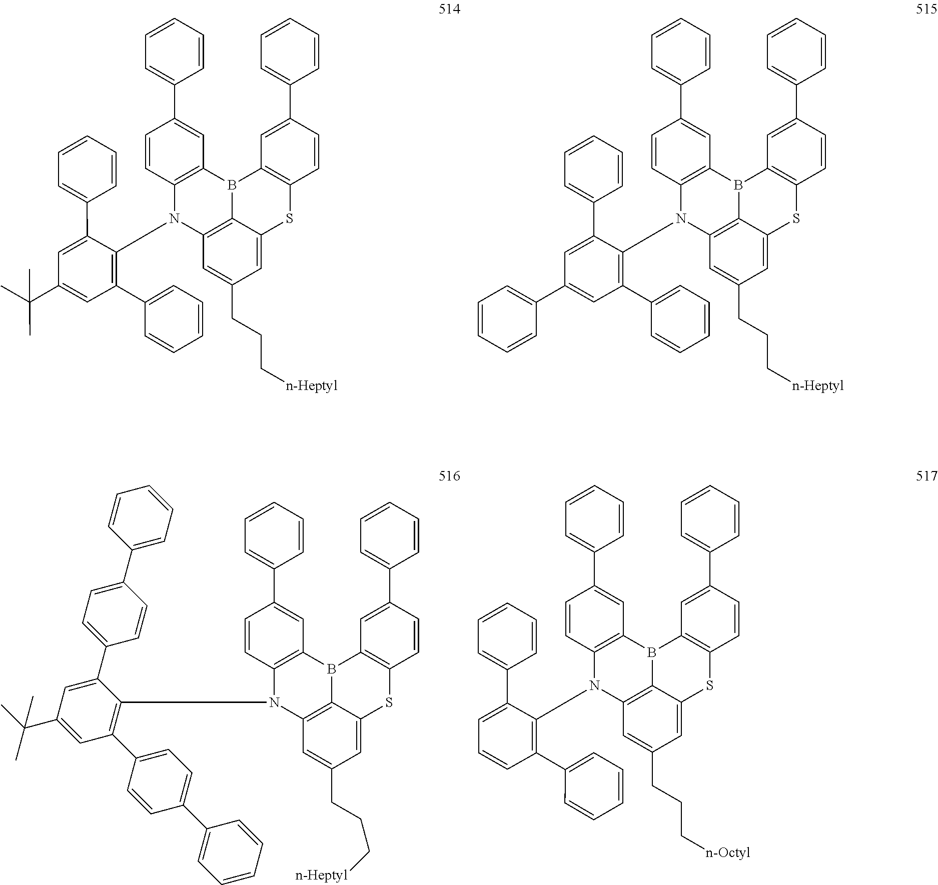 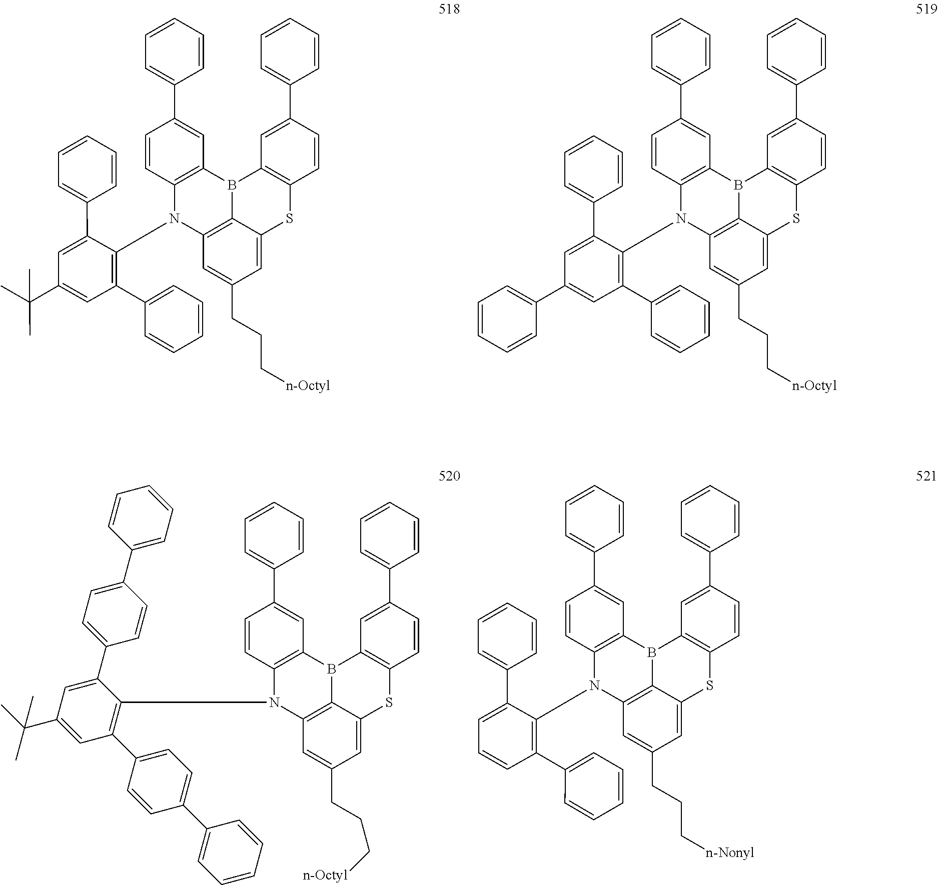 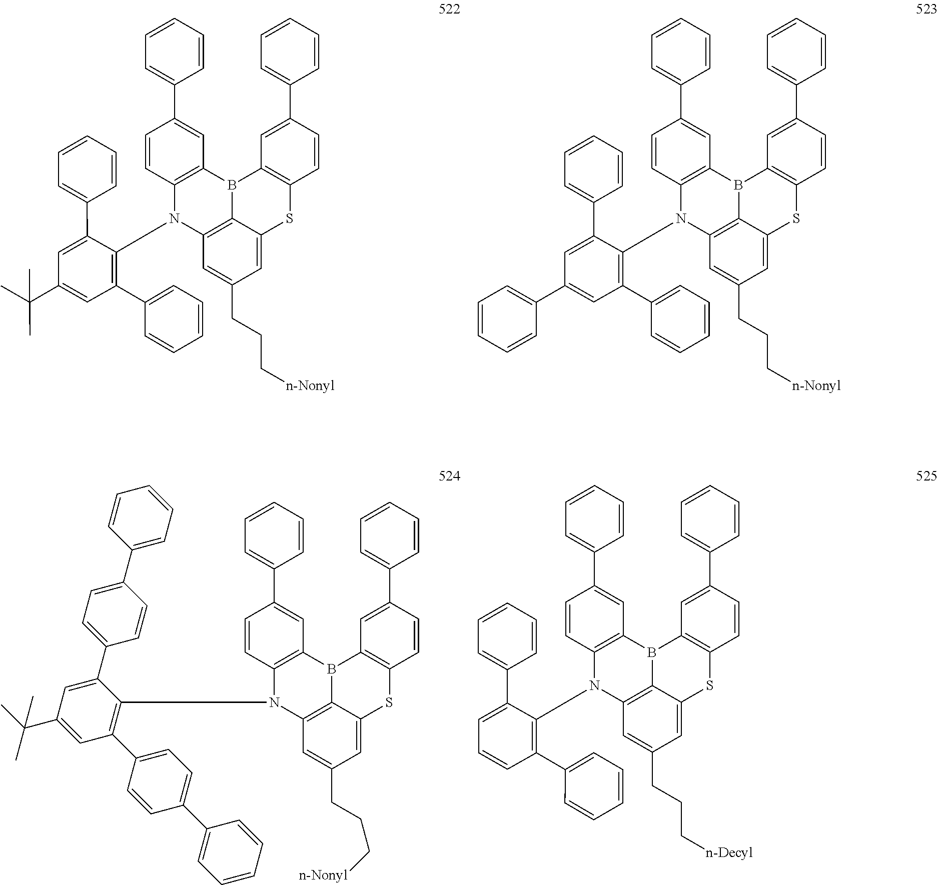 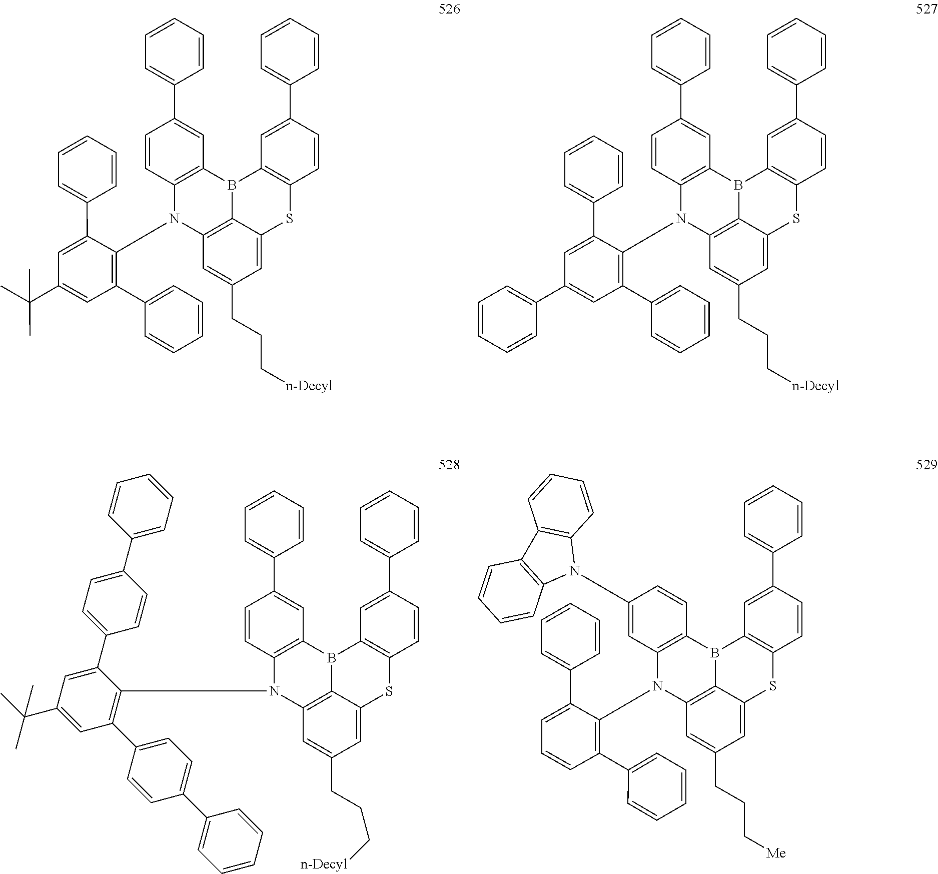 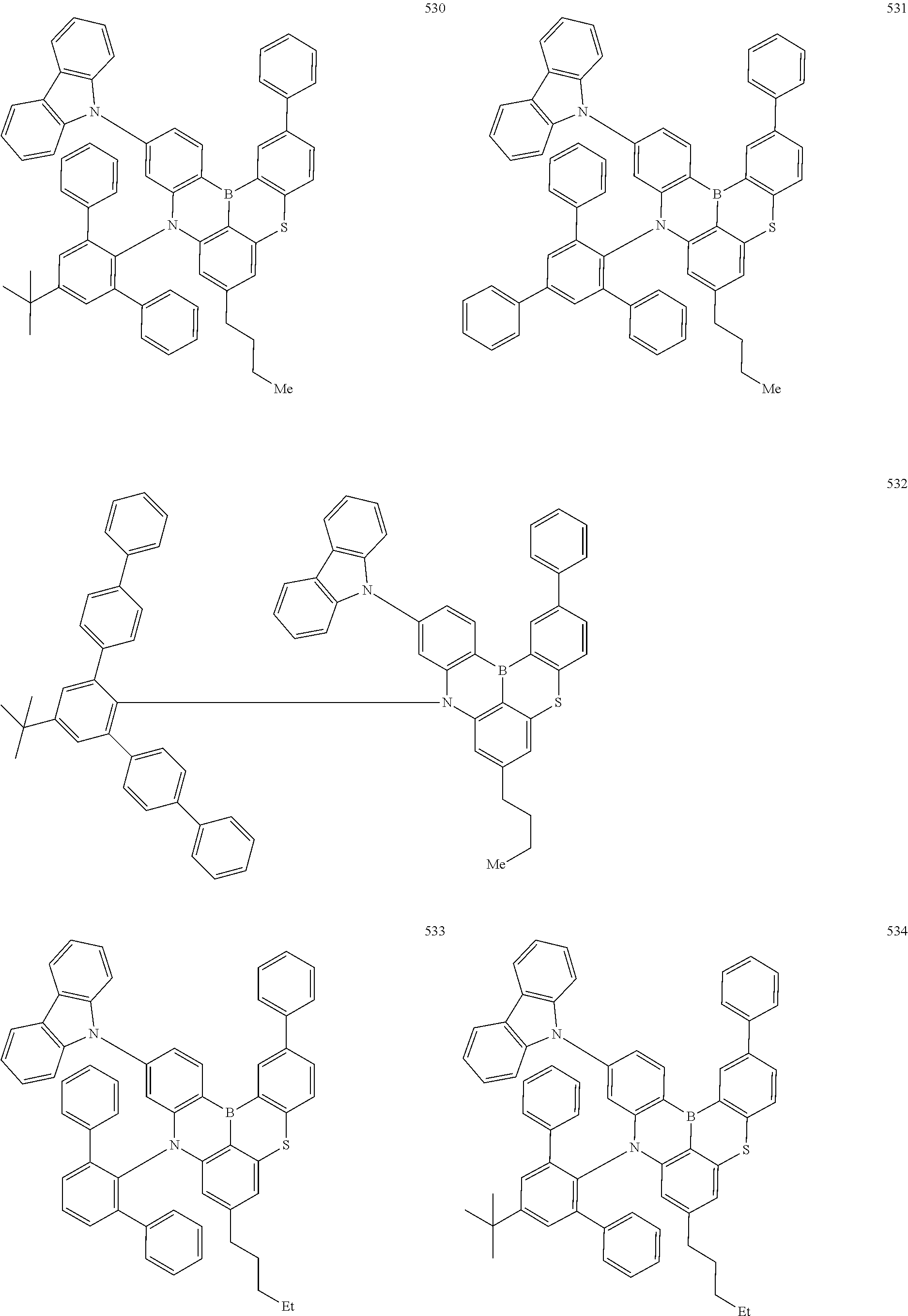 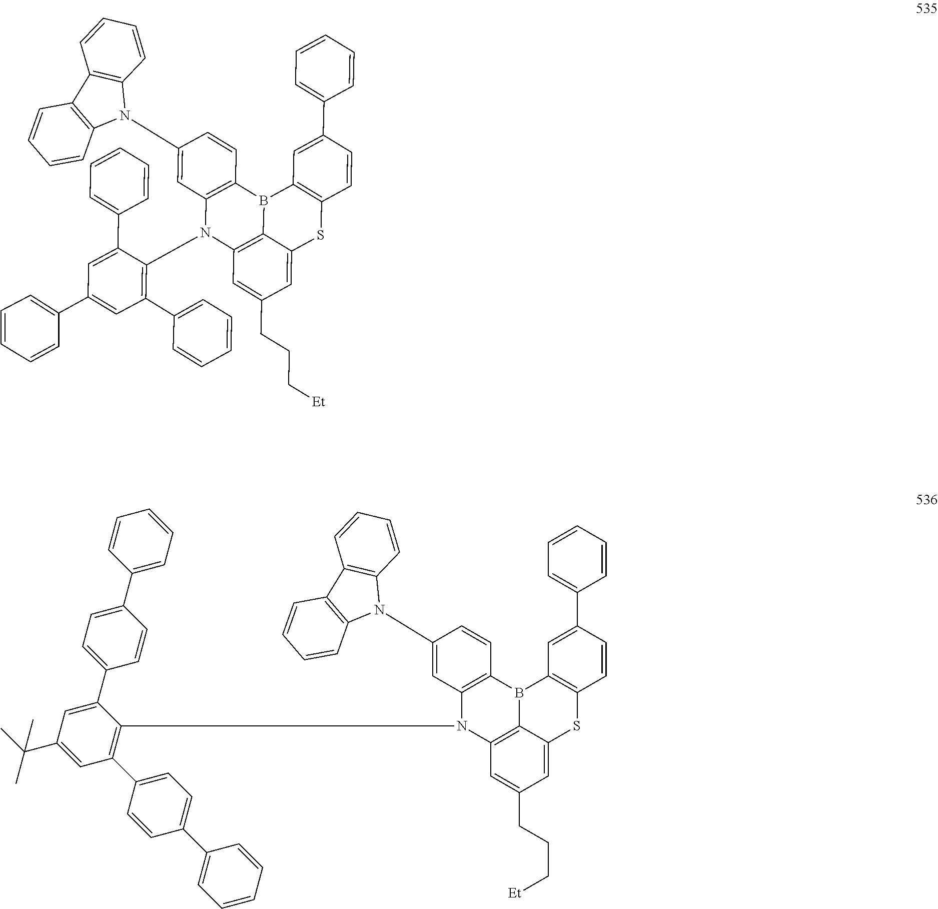 [SMILES: CCCCCc1cc2c3c(c1)N(c1c(-c4ccccc4)cc(-c4ccccc4)cc1-c1ccccc1)c1cc(-n4c5ccccc5c5ccccc54)ccc1B3c1cc(-c3ccccc3)ccc1S2 ; CCCCCc1cc2c3c(c1)N(c1c(-c4ccc(-c5ccccc5)cc4)cc(C(C)(C)C)cc1-c1ccc(-c4ccccc4)cc1)c1cc(-n4c5ccccc5c5ccccc54)ccc1B3c1cc(-c3ccccc3)ccc1S2] 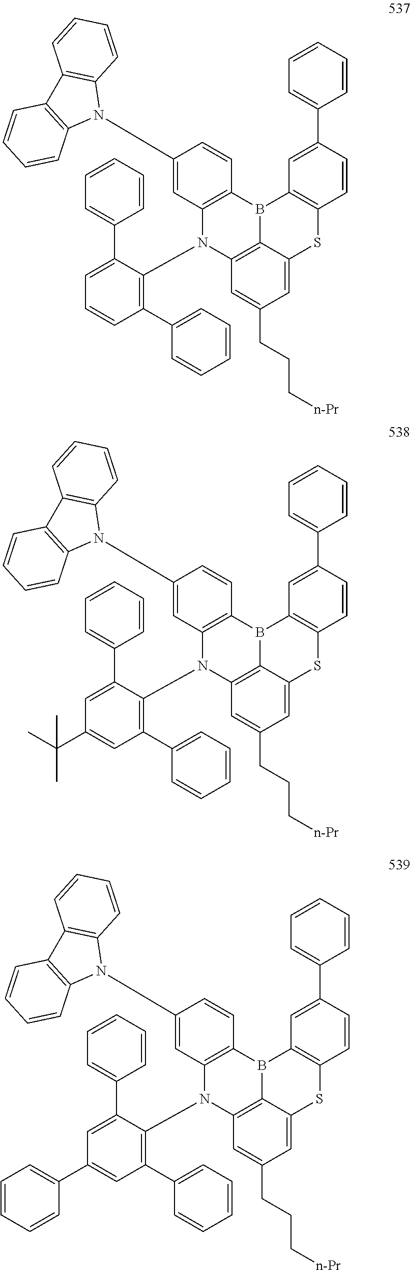 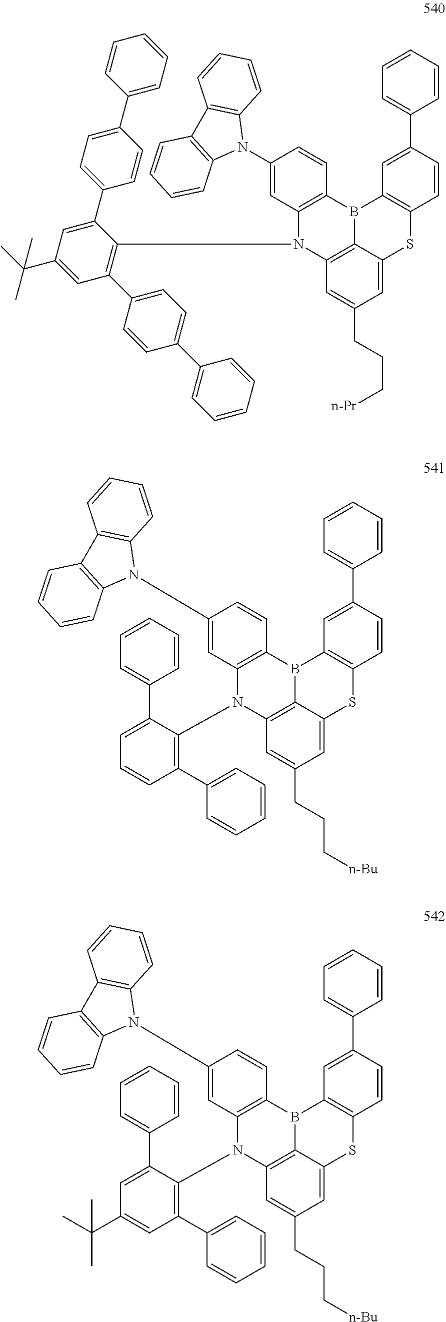 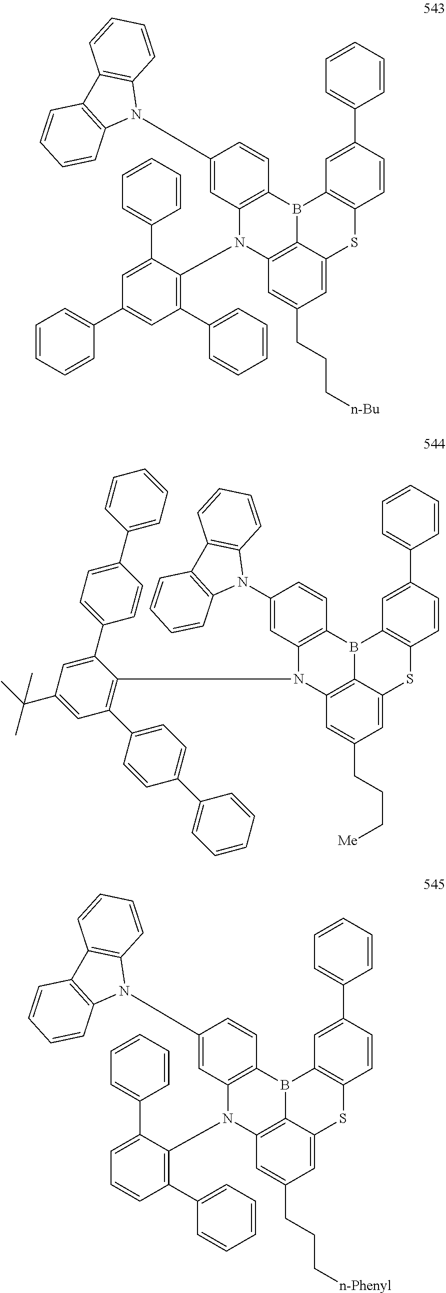 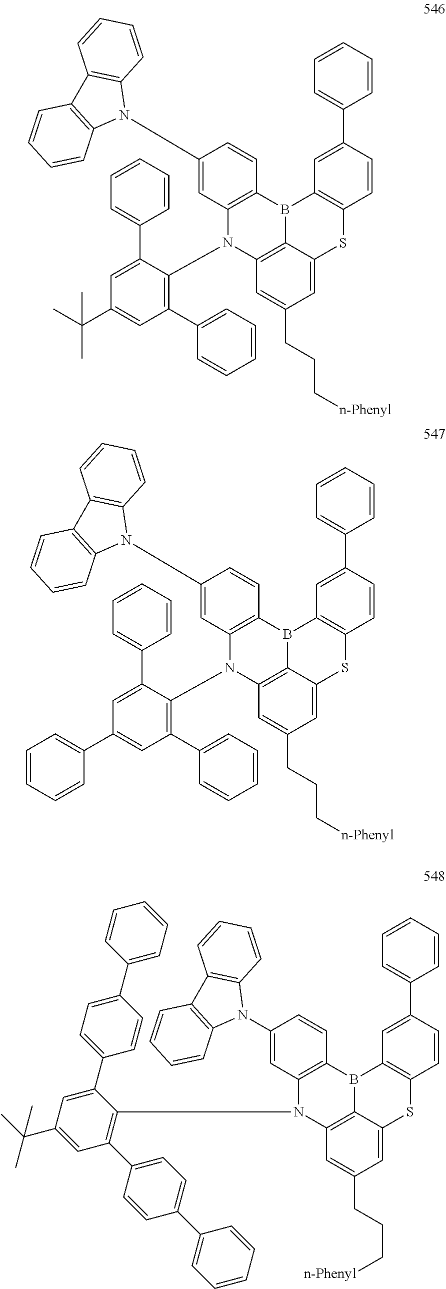 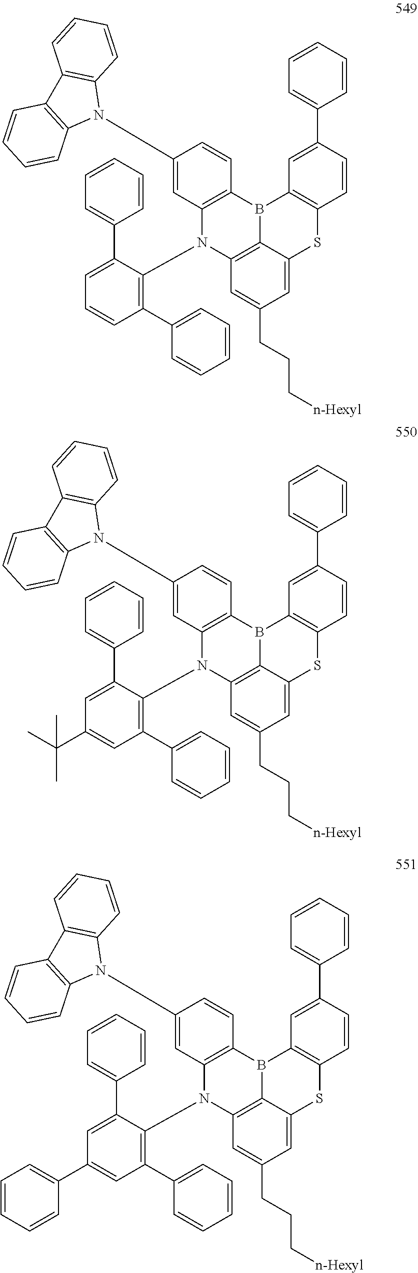 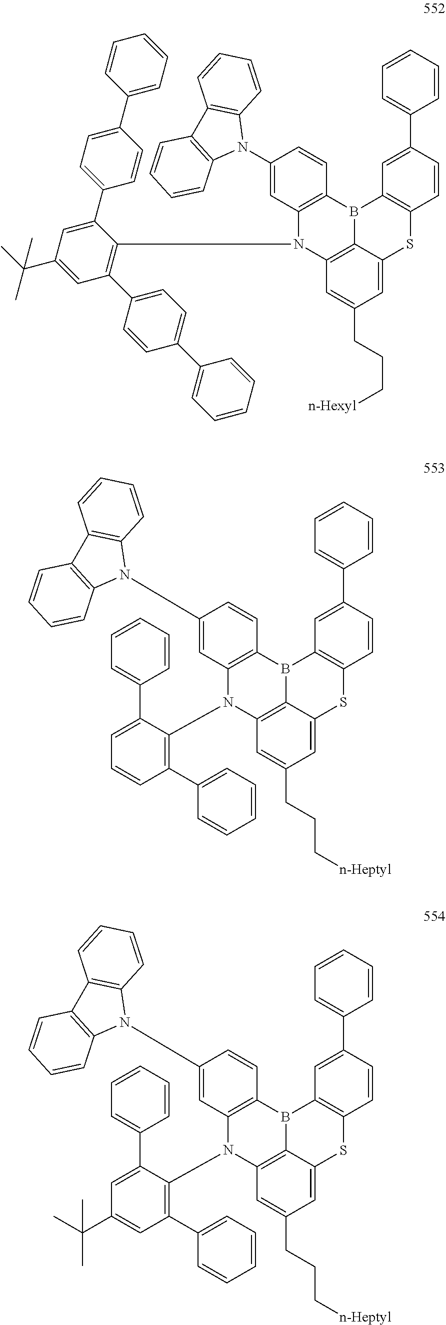 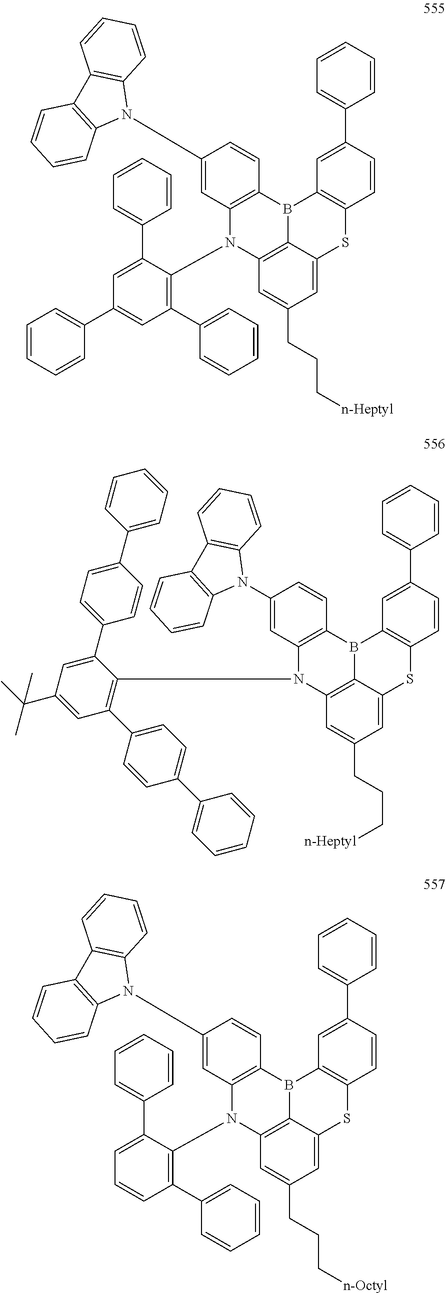 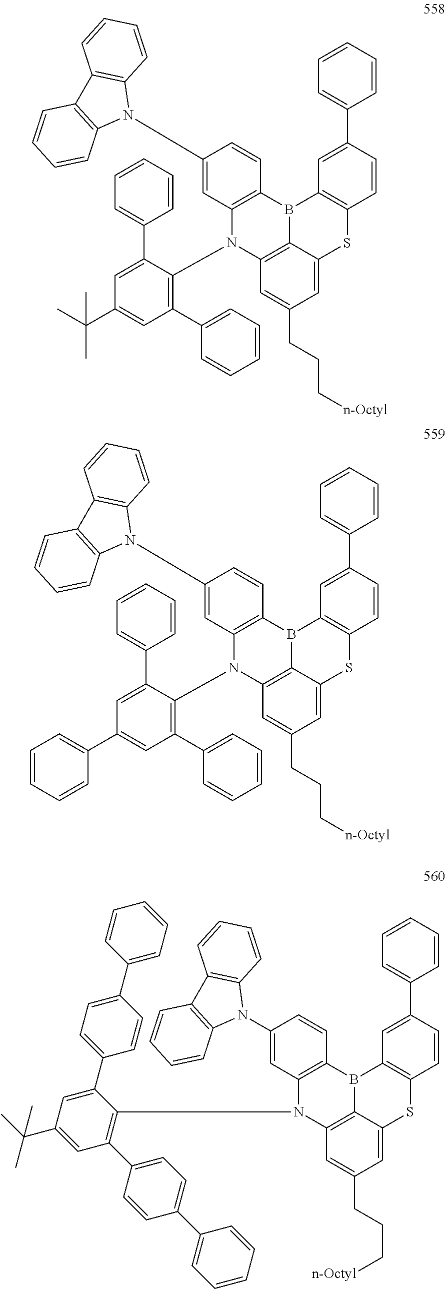 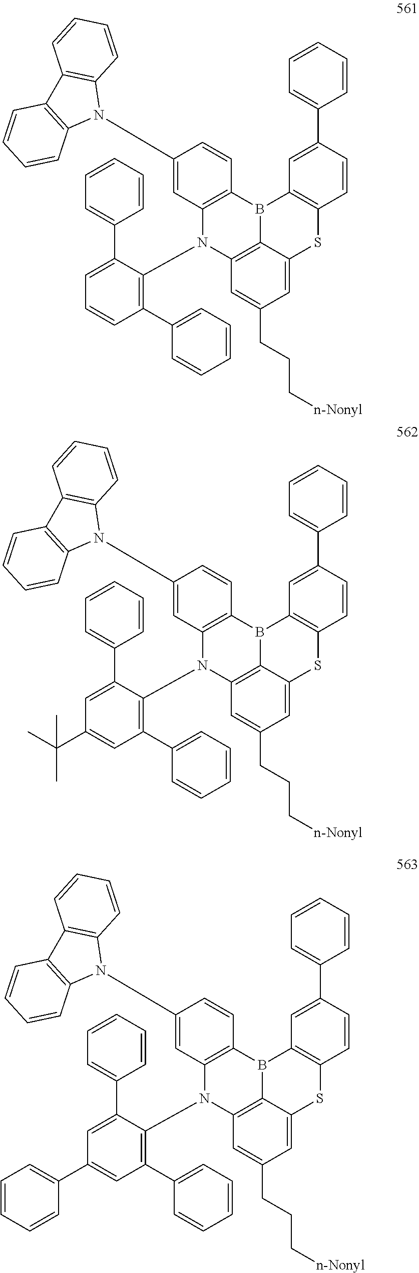 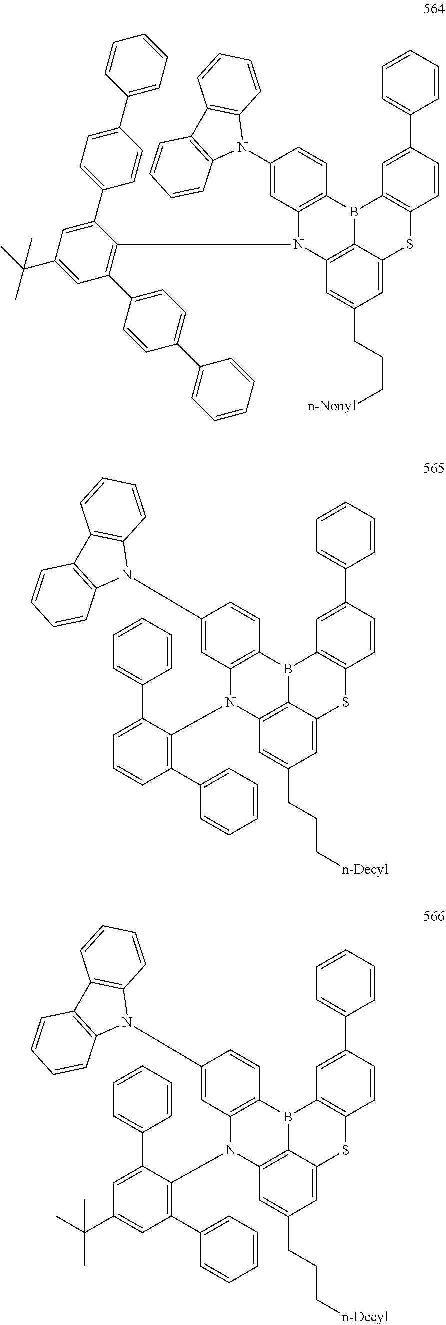 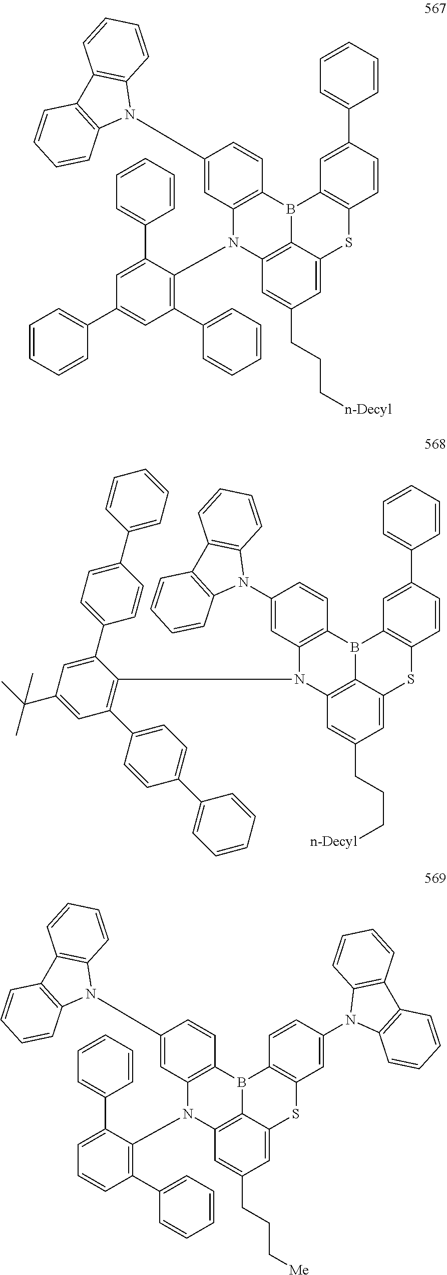 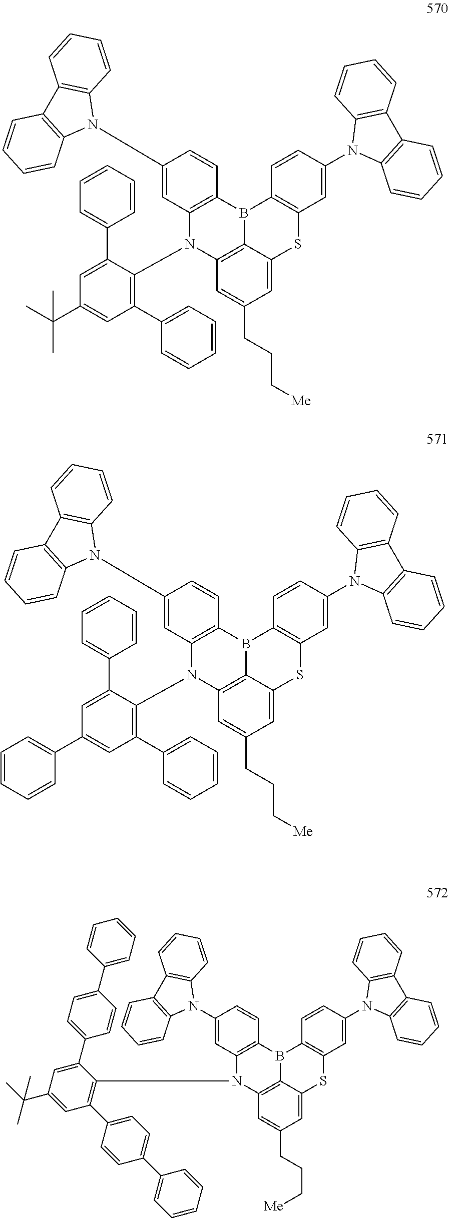 [SMILES: CCCCc1cc2c3c(c1)N(c1c(-c4ccccc4)cc(C(C)(C)C)cc1-c1ccccc1)c1cc(-n4c5ccccc5c5ccccc54)ccc1B3c1ccc(-n3c4ccccc4c4ccccc43)cc1S2 ; CCCCc1cc2c3c(c1)N(c1c(-c4ccccc4)cc(-c4ccccc4)cc1-c1ccccc1)c1cc(-n4c5ccccc5c5ccccc54)ccc1B3c1ccc(-n3c4ccccc4c4ccccc43)cc1S2 ; CCCCc1cc2c3c(c1)N(c1c(-c4ccc(-c5ccccc5)cc4)cc(C(C)(C)C)cc1-c1ccc(-c4ccccc4)cc1)c1cc(-n4c5ccccc5c5ccccc54)ccc1B3c1ccc(-n3c4ccccc4c4ccccc43)cc1S2] 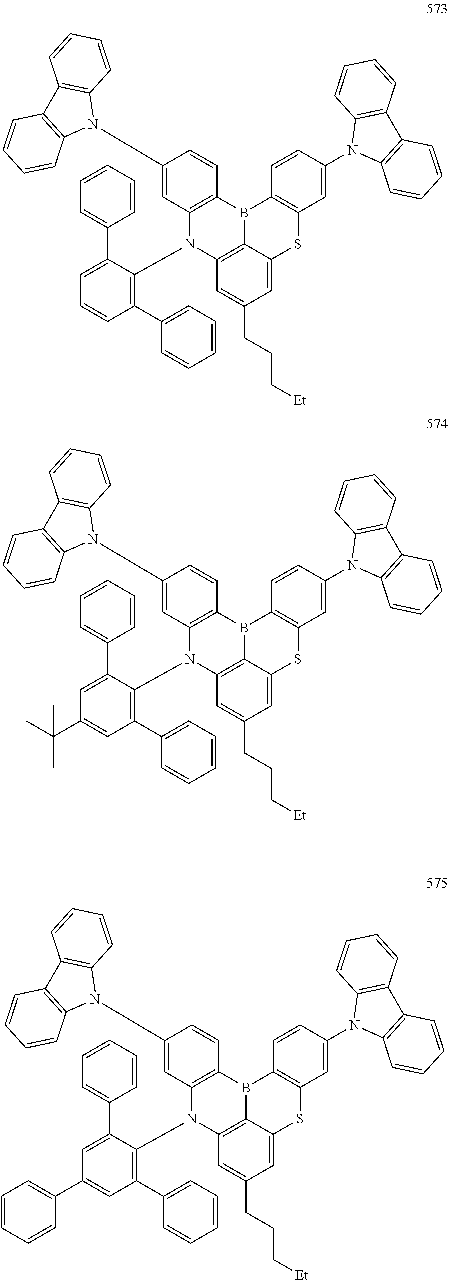 [SMILES: CCCCCc1cc2c3c(c1)N(c1c(-c4ccccc4)cccc1-c1ccccc1)c1cc(-n4c5ccccc5c5ccccc54)ccc1B3c1ccc(-n3c4ccccc4c4ccccc43)cc1S2 ; CCCCCc1cc2c3c(c1)N(c1c(-c4ccccc4)cc(C(C)(C)C)cc1-c1ccccc1)c1cc(-n4c5ccccc5c5ccccc54)ccc1B3c1ccc(-n3c4ccccc4c4ccccc43)cc1S2 ; CCCCCc1cc2c3c(c1)N(c1c(-c4ccccc4)cc(-c4ccccc4)cc1-c1ccccc1)c1cc(-n4c5ccccc5c5ccccc54)ccc1B3c1ccc(-n3c4ccccc4c4ccccc43)cc1S2] 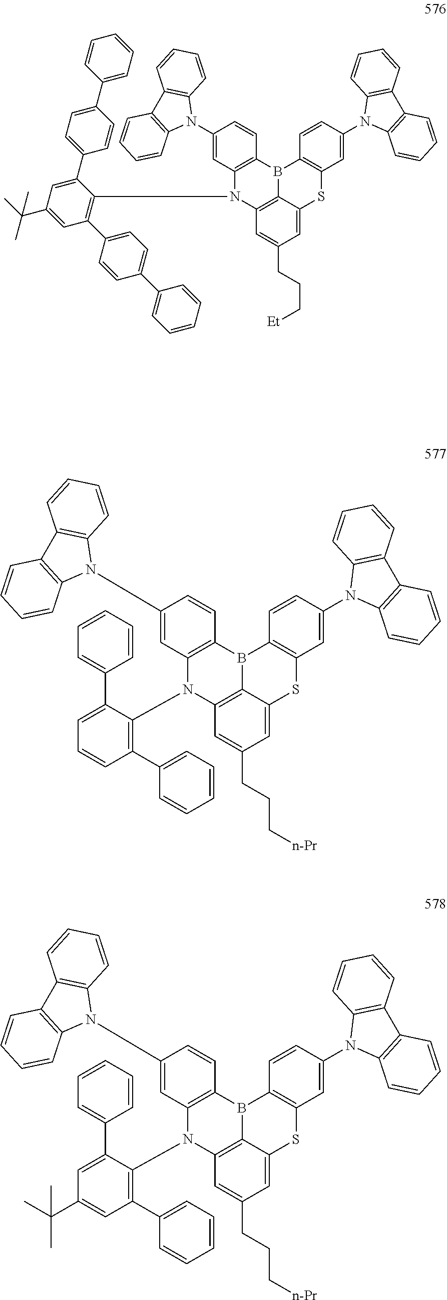 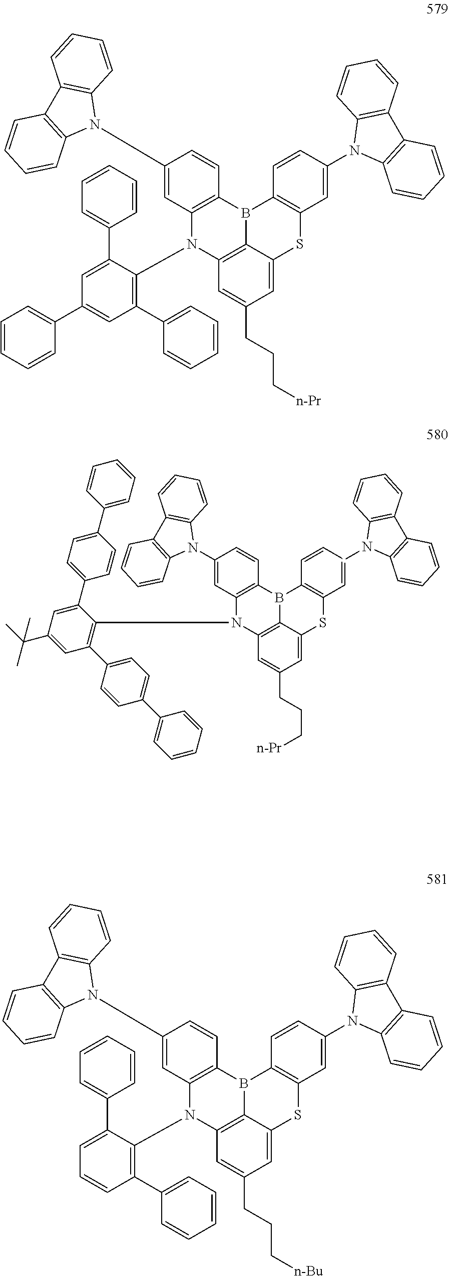 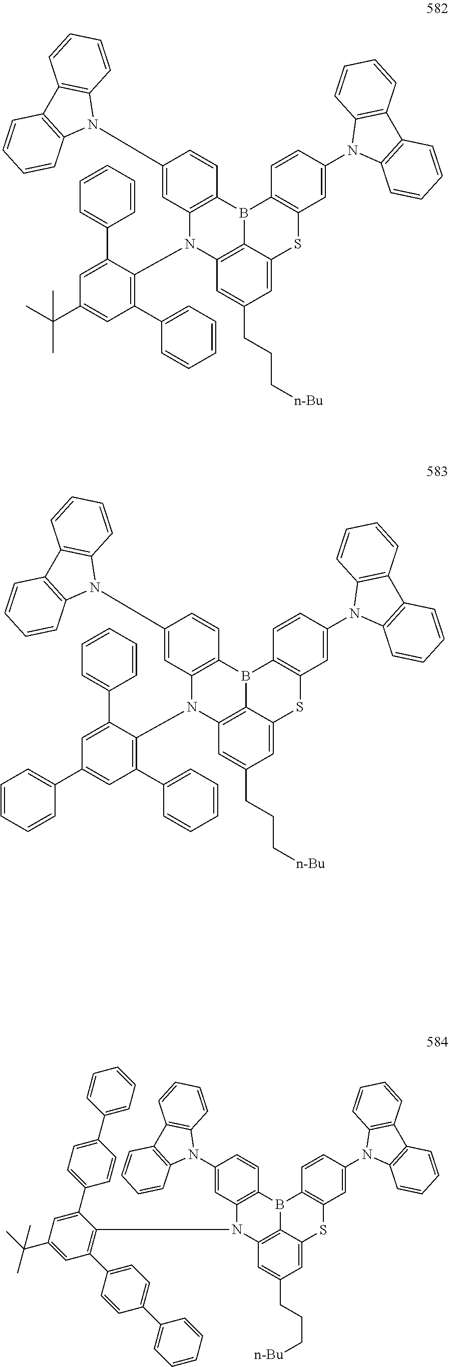 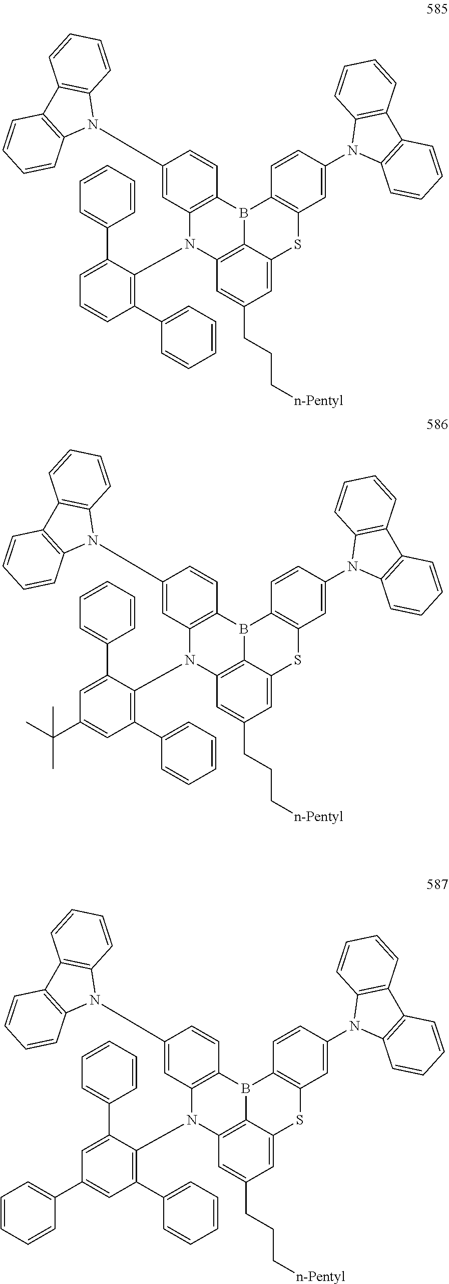 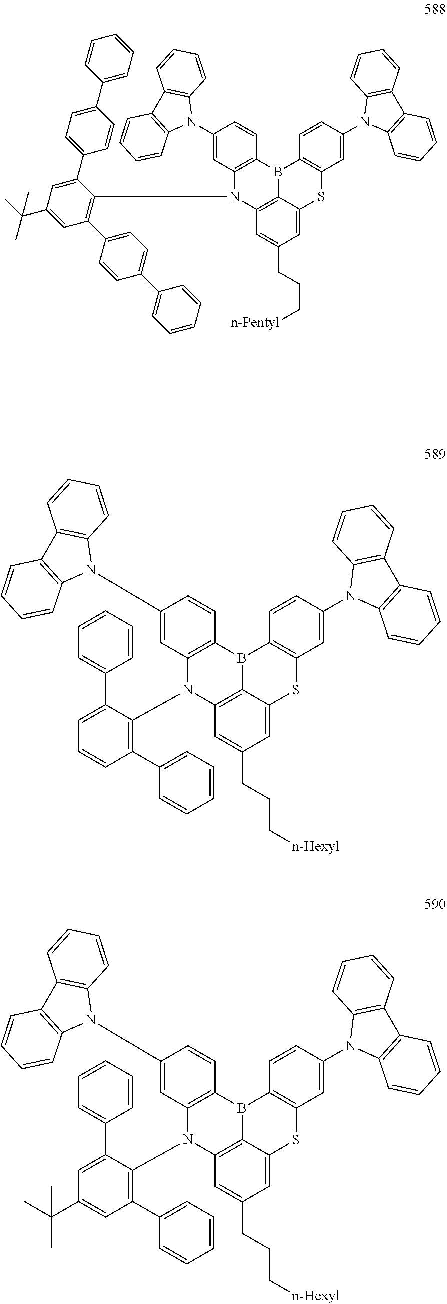 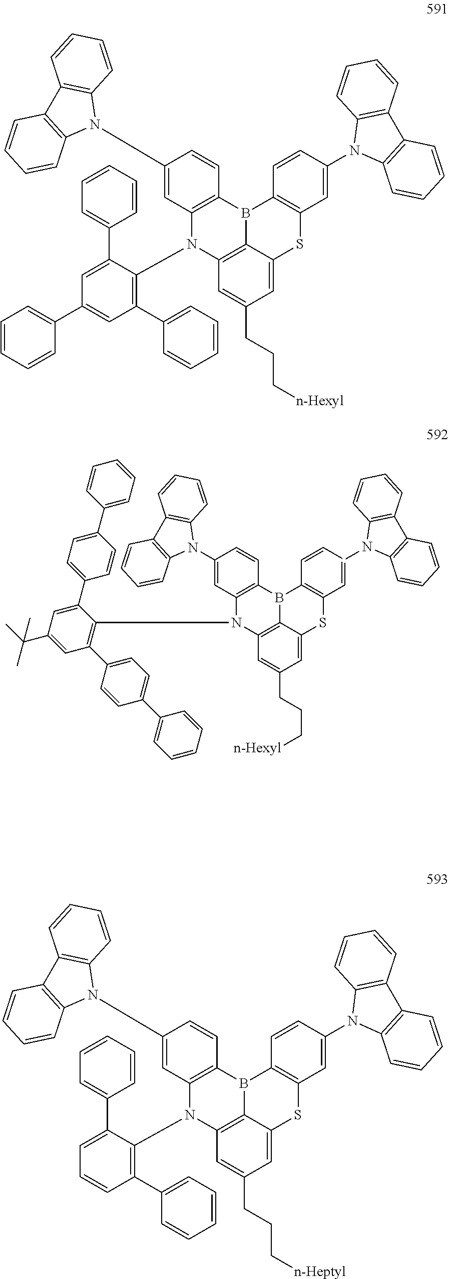 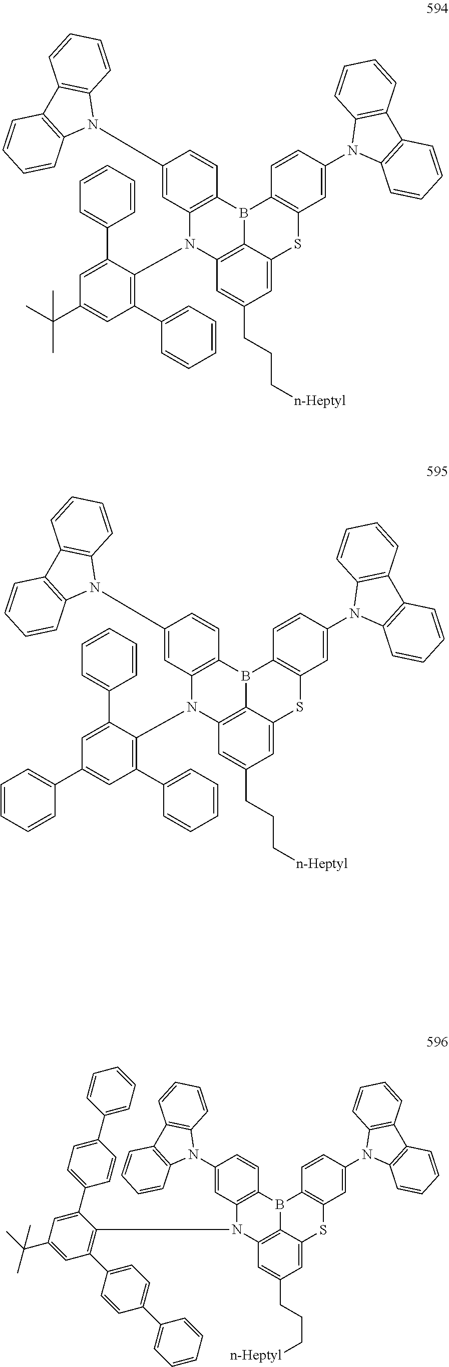 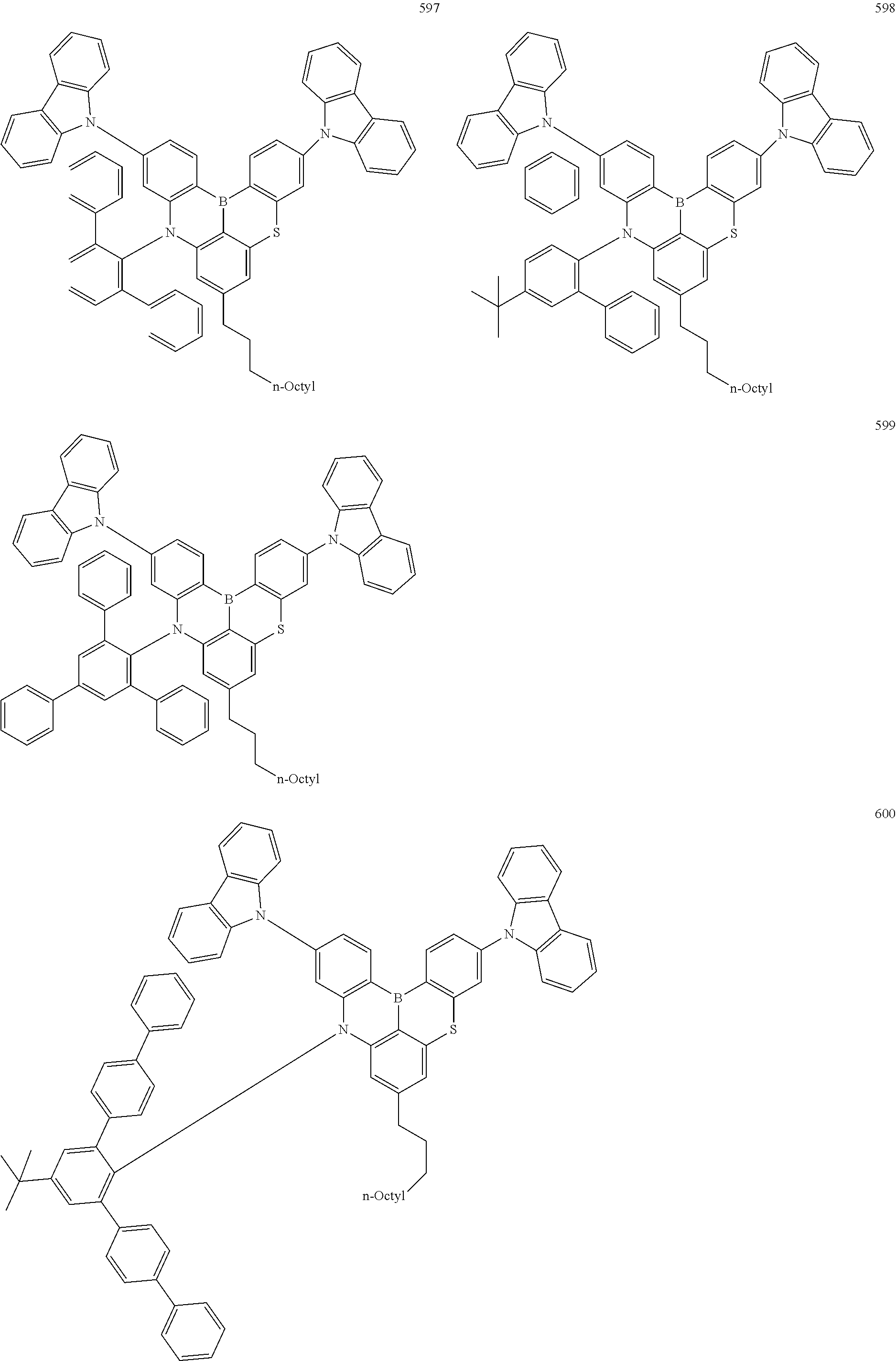 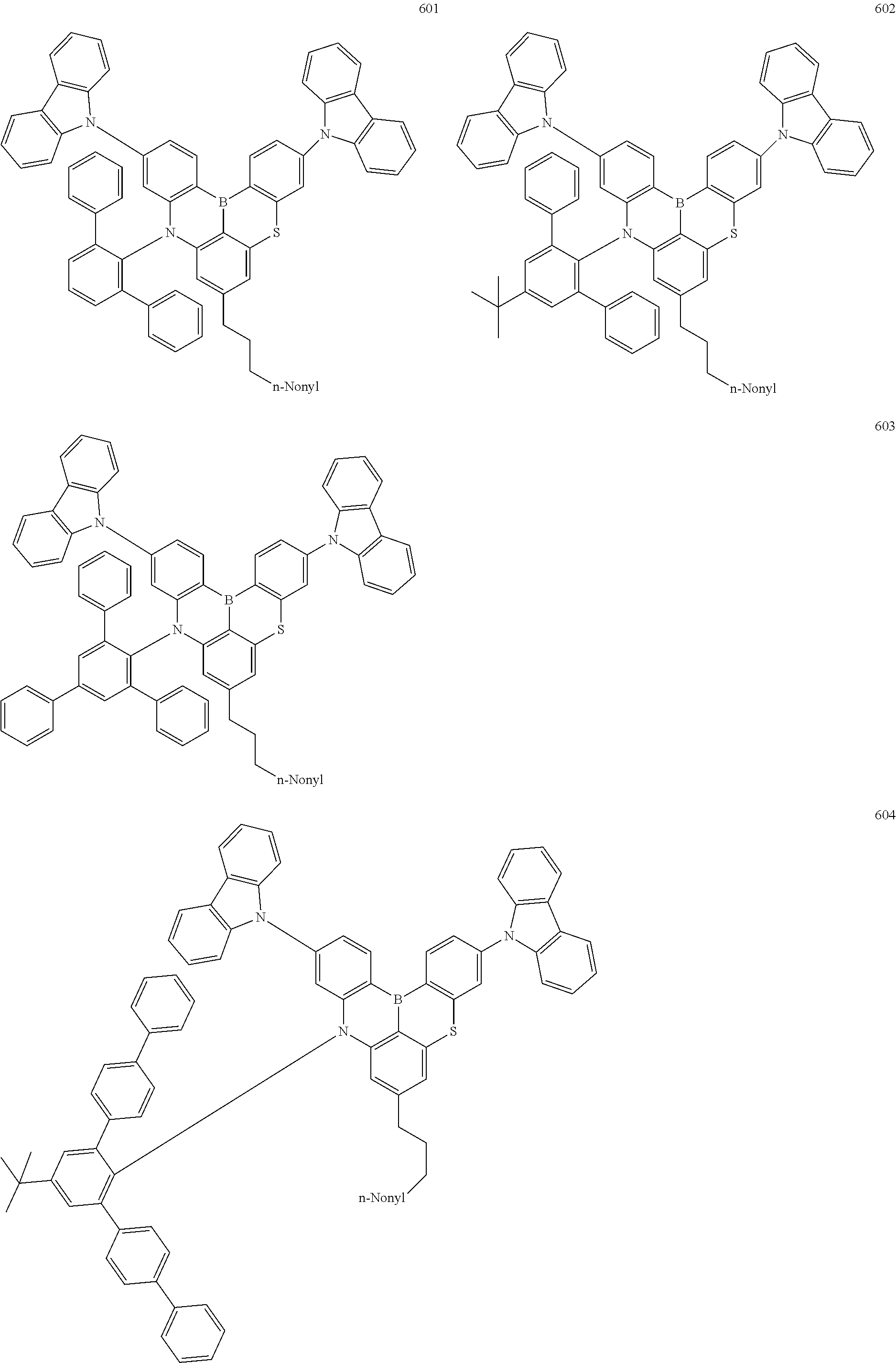 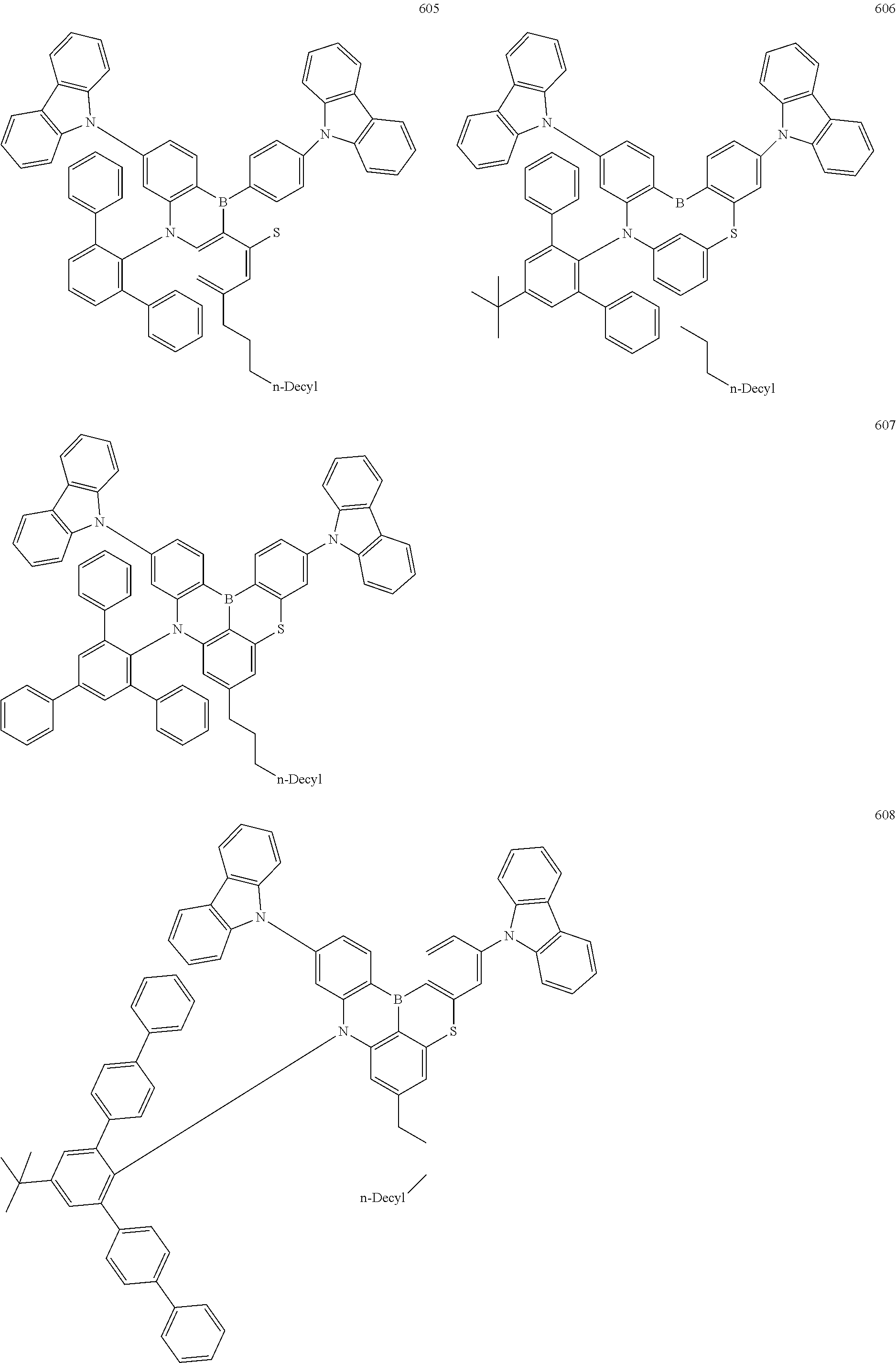 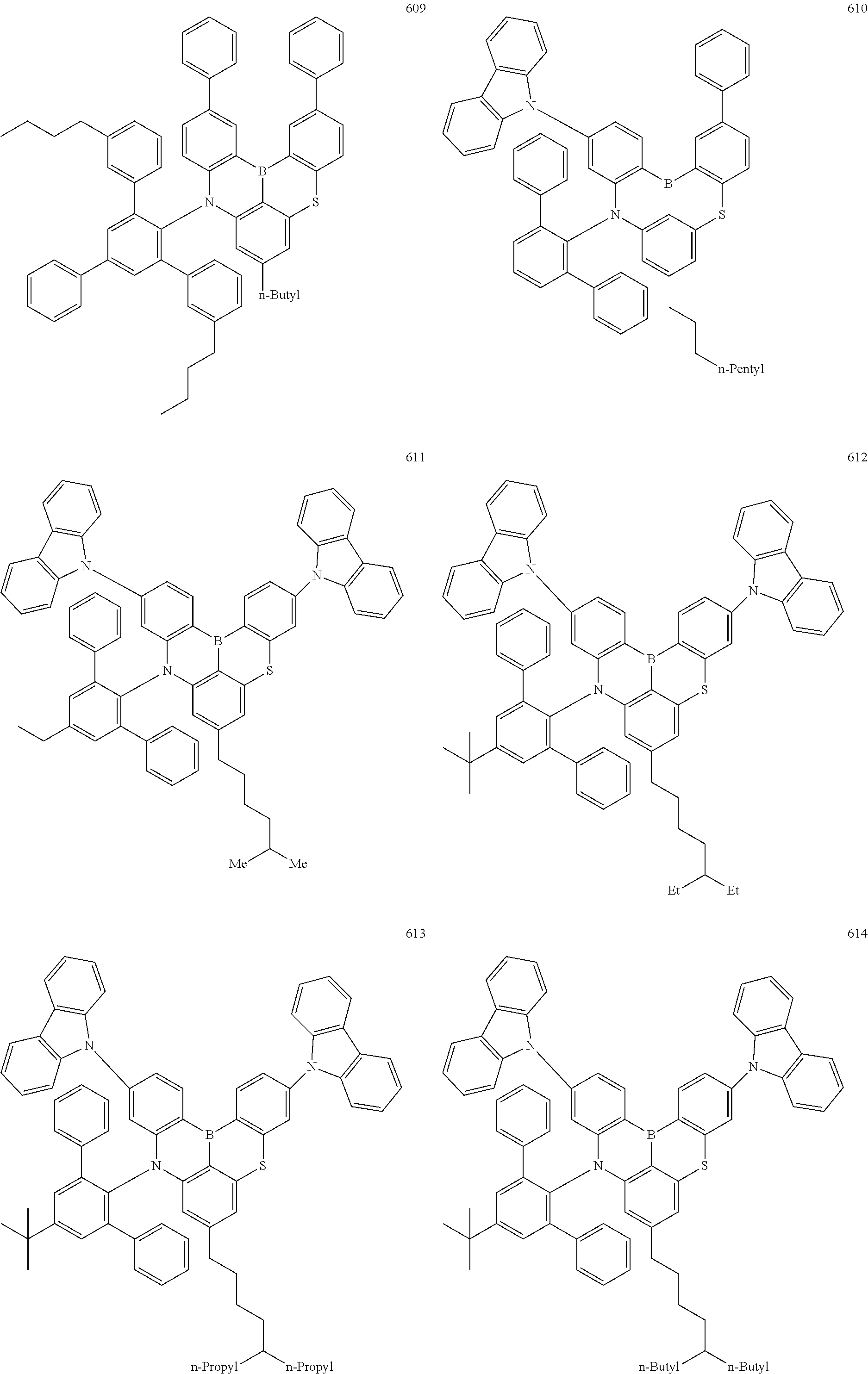 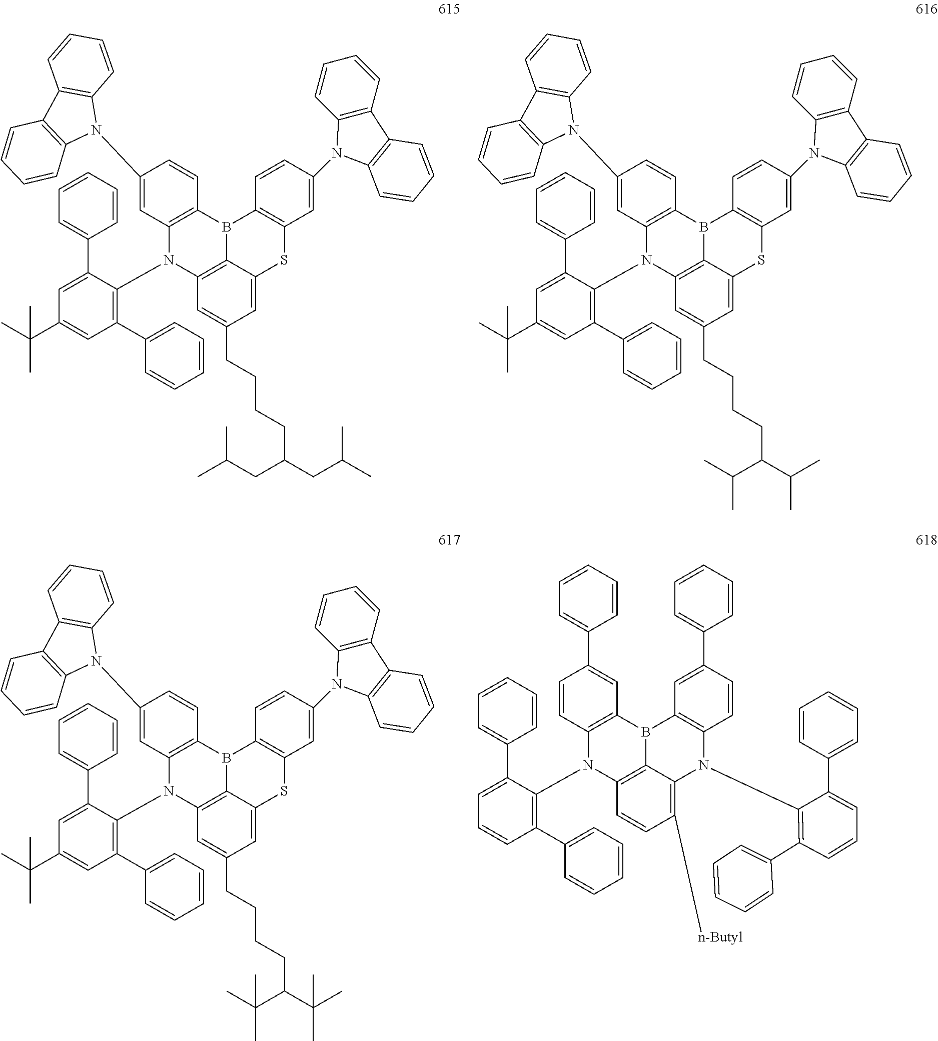 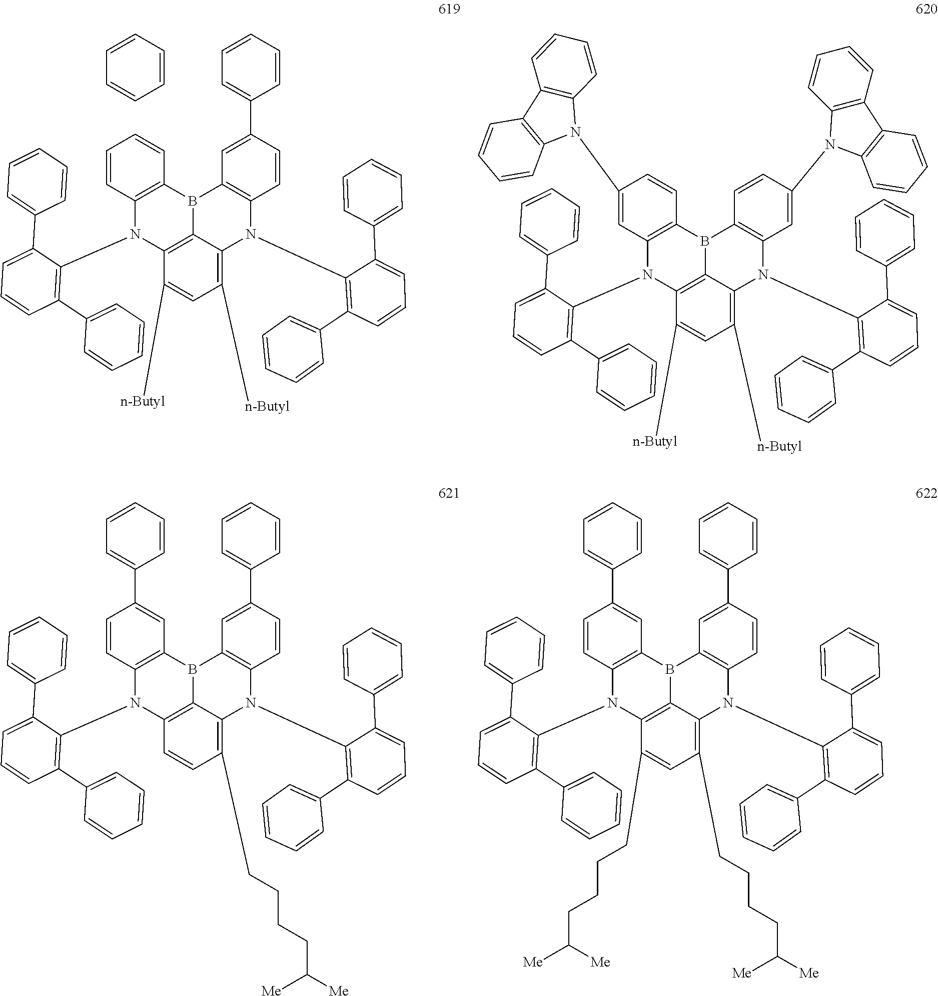 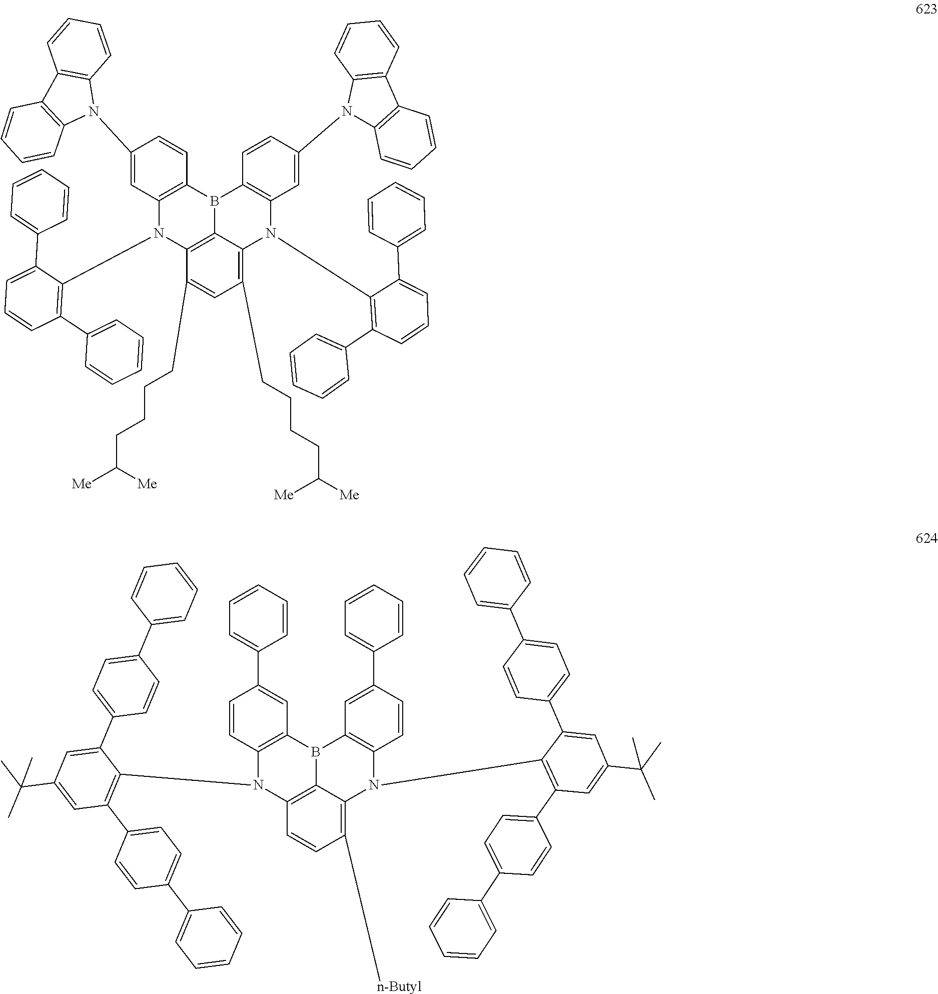 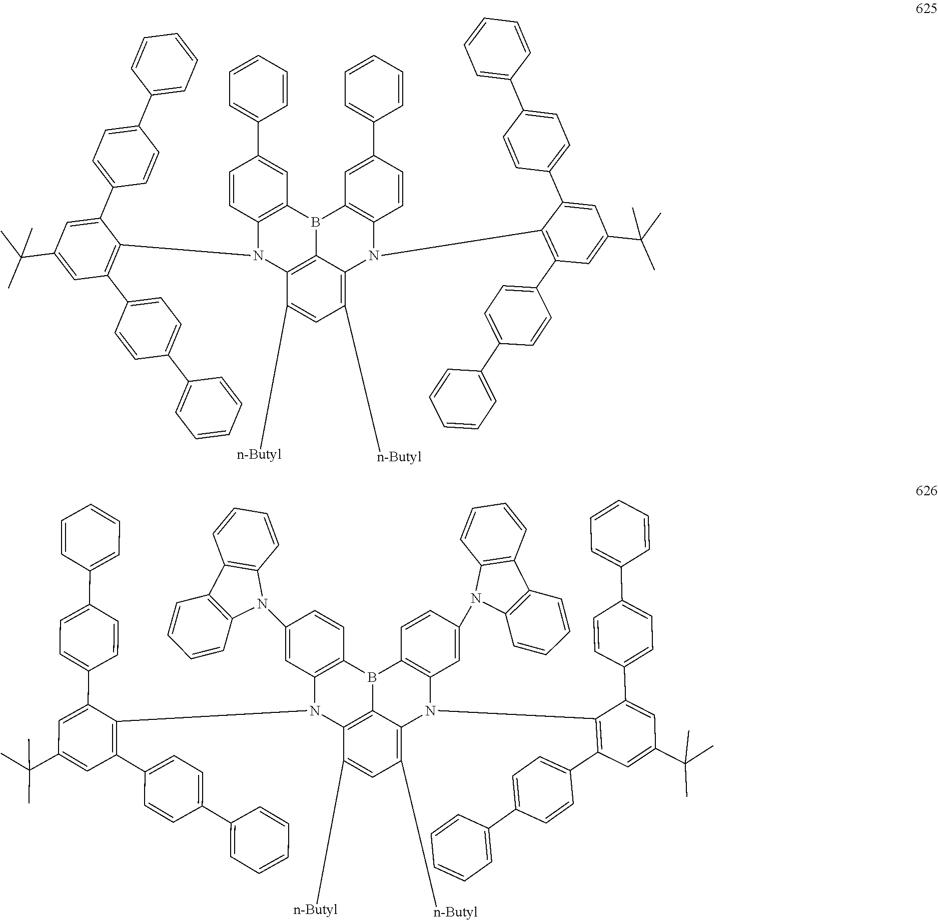 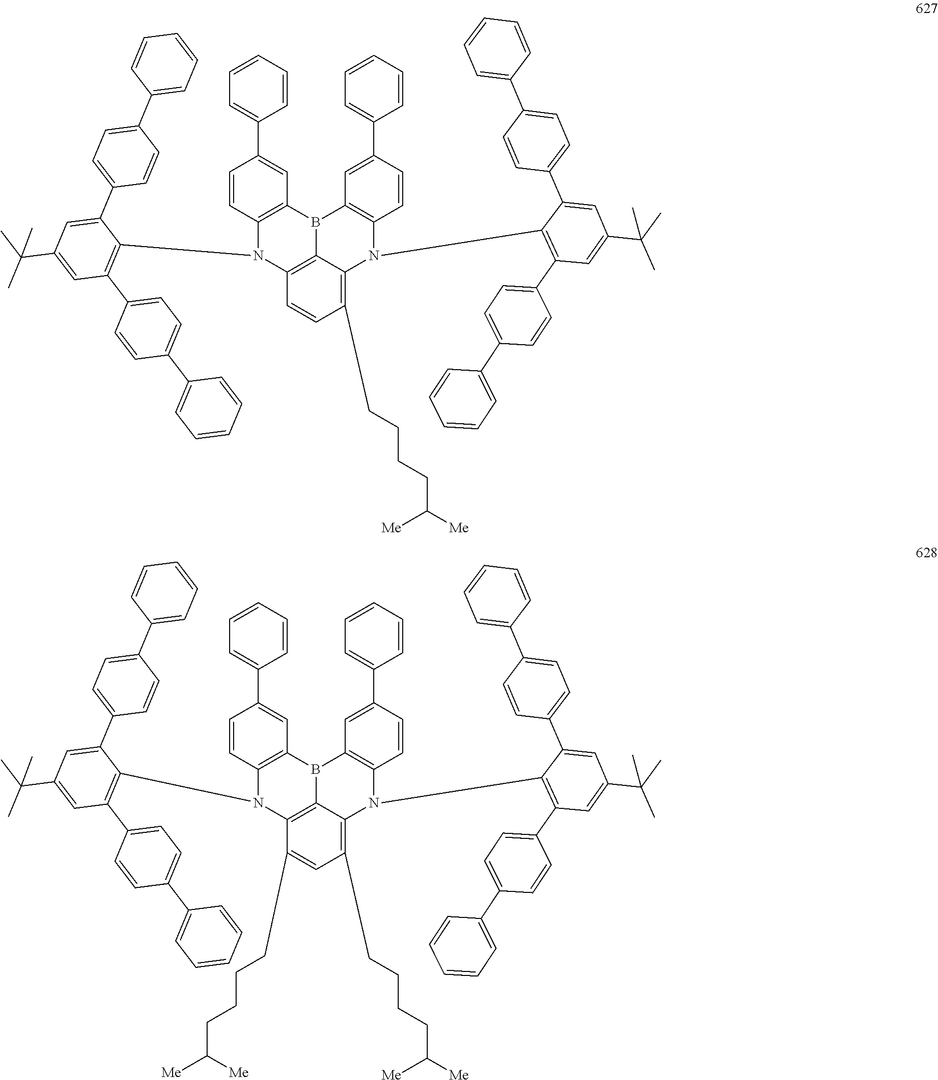 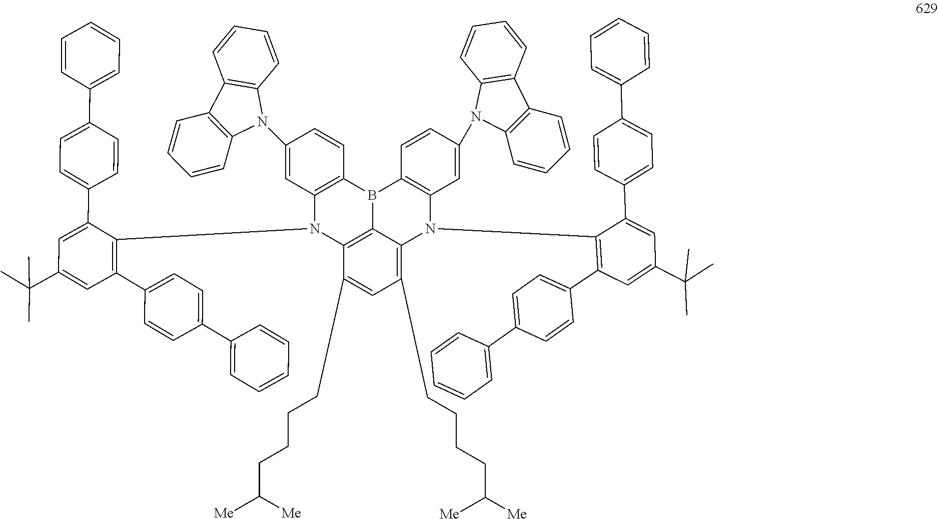 [SMILES: CC(C)CCCCc1cc(CCCCC(C)C)c2c3c1N(c1c(-c4ccc(-c5ccccc5)cc4)cc(C(C)(C)C)cc1-c1ccc(-c4ccccc4)cc1)c1cc(-n4c5ccccc5c5ccccc54)ccc1B3c1ccc(-n3c4ccccc4c4ccccc43)cc1N2c1c(-c2ccc(-c3ccccc3)cc2)cc(C(C)(C)C)cc1-c1ccc(-c2ccccc2)cc1]
wherein in Compound Group 1,
D represents a deuterium atom,
Me represents an unsubstituted methyl group,
Et represents an unsubstituted ethyl group,
n-Pr represents an n-propyl group,
n-Bu and n-Butyl each represent an n-butyl group,
n-Pentyl represents an n-pentyl group,
n-Hexyl represents an n-hexyl group,
n-Heptyl represents an n-heptyl group,
n-Octyl represents an n-octyl group,
n-Nonyl represents an n-nonyl group, and
n-Decyl represents an n-decyl group.
